(19) United States
(12) Patent Application Publication
(10) Pub. No.: US 2026/0059934 A1
(43) Pub. Date: Feb. 26, 2026

(54) ORGANIC ELECTROLUMINESCENCE ELEMENT, ORGANIC ELECTROLUMINESCENCE DEVICE, ELECTRONIC APPARATUS, EMITTER, SOLAR CELL, AND LIGHT SENSOR

(71) Applicant: IDEMITSU KOSAN CO.,LTD., Tokyo (JP)

(72) Inventors: Yuichiro KAWAMURA, Tokyo (JP); Ryo NAGATA, Tokyo (JP); Kazuki NISHIMURA, Tokyo (JP)

(73) Assignee: IDEMITSU KOSAN CO.,LTD., Tokyo (JP)

(21) Appl. No.: 18/877,664

(22) PCT Filed: Jun. 22, 2023
(86) PCT No.: PCT/JP2023/023198

§ 371 Date: Dec. 20, 2024

(30) Foreign Application Priority Data
Jun. 23, 2022 (JP) 2022-100872

(51) Int. Cl. H10K 50/12; H10K 101/20; H10K 101/30

(52) U.S. Cl. CPC H10K 50/121; H10K 2101/20; H10K 2101/30

(57) ABSTRACT

An organic electroluminescence device includes an anode, a cathode, and an emitting region interposed between the anode and the cathode. The emitting region includes a first sensitizing layer and a first emitting layer. The first sensitizing layer contains a first host material and a first sensitizing material; and the first emitting layer contains a second host material and a first luminescent compound. The first host material and the second host material are mutually different; and the first sensitizing material and the first luminescent compound are mutually different. The lowest singlet energy S₁(G1) and the energy gap T_{77K}(G1) at 77K of the first sensitizing material satisfy (Numerical Formula 1): ΔST(G1)=S₁(G1)−T_{77K}(G1)<0.5 eV.

### TECHNICAL FIELD

The present invention relates to an organic electroluminescence device, organic electroluminescence apparatus, electronic device, light emitter, solar cell, and light sensor.

### BACKGROUND ART

Upconversion has attracted attention as a technique for converting low-energy light into high-energy light.

Upconversion has attracted attention as a technique capable of driving an organic electroluminescence device by lower energy than energy of light-emitting photon.

When the technique of upconversion is applied to light excitation, excited light having a longer wavelength than light emission is obtainable.

For instance, it has been known that in upconversion using inorganic compounds, multi-stage excitation using f-f transition of rare earth ions can generate visible light from infrared light.

It has also been known that in optical upconversion using organic substances, long-wavelength light excitation actually generates short-wavelength light due to interactions between multiple excited states (e.g., Triplet-Triplet Fusion=TTF).

On the other hand, if the upconversion technique is applied to electrical excitation, it is expected to emit light at a lower energy than the energy of light emission (indicated in electron volts (eV) for volts (V)), i.e., at a lower applied voltage. In other words, light emission at a lower applied voltage means that a drive voltage can be decreased.

A material for a fluorescent device used for an organic electroluminescent device (sometimes referred to as organic EL device) achieves high efficiency by converting triplets into singlets by causing TTF in a host of the emitting layer, followed by energy transfer to a dopant, and then reused as light emission (e.g., Patent Literature 1). This is one type of upconversion luminescence in an organic solid film.

For instance, Non-Patent Literature 1 describes an upconversion device in which a phosphorescent complex (PtOEP) is introduced as a sensitizing material into a layered structure formed of an organic solid film.

### CITATION LIST

### Patent Literature(S)

Patent Literature 1: International Publication No. WO 2010/134350

### Non-Patent Literature(S)

Non-Patent Literature 1: Ting-An Lin et al., ADVANCED MATERIALS COMMUNICATION, 2020, 32, 1908175

### SUMMARY OF THE INVENTION

### Problem(s) to be Solved by the Invention

However, in the upconversion device of Non-Patent Literature 1, external quantum efficiency (EQE) is low (about 0.024%), possibly achieving lower voltage, but it is not expected to decrease power consumption as the device. This is considered to be because a phosphorescent complex causes concentration quenching, and when a phosphorescent complex is introduced into an emitting layer (solid thin film) of an organic EL device, the phosphorescent complex does not work efficiently in the emitting layer.

In recent years, lower power consumption is desired as a need for further performance improvement of the organic EL device, such as for longer-lasting batteries in mobile devices.

An organic EL device is desired that efficiently expresses upconversion in the emitting layer and that is driven at a low power consumption.

An object of the invention is to provide an organic electroluminescence device and an organic electroluminescence apparatus, which have a low light-emission start voltage and emit light with high efficiency, and an electronic device including the organic electroluminescence device or the organic electroluminescence apparatus.

Another object of the invention is to provide a light emitter having a low light-emission start voltage and emitting light with high efficiency, and a solar cell and a light sensor which include the light emitter.

### Means for Solving the Problem(s)

According to an aspect of the invention, there is provided an organic electroluminescence device including an anode, a cathode, and an emitting region provided between the anode and the cathode, in which the emitting region includes a first sensitizing layer and a first emitting layer, the first sensitizing layer contains a first host material and a first sensitizing material, the first emitting layer contains a second host material and a first luminescent compound, the first host material and the second host material are mutually different, the first sensitizing material and the first luminescent compound are mutually different, and a difference ΔST(G1) between a lowest singlet energy S₁(G1) of the first sensitizing material and an energy gap T_{77K}(G1) at 77K of the first sensitizing material satisfies a relationship represented by a numerical formula (Numerical Formula 1) below.

$$Δ S T ( G 1 ) = {S}_{1} ( G 1 ) - {T}_{77 K} ( G 1 ) < 0.5 eV \qquad ( Numerical Formula 1 )$$

According to another aspect of the invention, there is provided an organic electroluminescence apparatus including: the organic electroluminescence device according to the above aspect of the invention; and a power source, in which the power source includes a power generating element configured to generate a potential difference or an electric current by an external stimulus.

According to still another aspect of the invention, there is provided an electronic device including the organic electroluminescence device according to the above aspect of the invention or the organic electroluminescence apparatus according to the above aspect of the invention.

According to a further aspect of the invention, there is provided a light emitter including a first sensitizing moiety and a first emitting moiety, in which the first sensitizing moiety includes a first host material and a first sensitizing material, the first emitting moiety includes a second host material and a first luminescent compound, the first host material and the second host material are mutually different, the first sensitizing material and the first luminescent compound are mutually different, a difference ΔST(G1) between a lowest singlet energy S₁(G1) of the first sensitizing material and an energy gap T_{77K}(G1) at 77K of the first sensitizing material satisfies a relationship represented by a numerical formula (Numerical Formula 1) below, an energy gap T_{77K}(G1) at 77K of the first sensitizing material, an energy gap T_{77K}(H1) at 77K of the first host material, and an energy gap T_{77K}(H2) at 77K of the second host material satisfy a relationship represented by a numerical formula (Numerical Formula 2) below, and a lowest singlet energy S₁(G1) of the first sensitizing material and a lowest singlet energy S₁(BD1) of the first luminescent compound satisfy a relationship of a numerical formula (Numerical Formula 3) below.

$$Δ S T ( G 1 ) = {S}_{1} ( G 1 ) - {T}_{77 K} ( G 1 ) < 0.5 eV \qquad ( Numerical Formula 1 )$$

$${T}_{77 K} ( G 1 ) > {T}_{77 K} ( H 1 ) > {T}_{77 K} ( H 2 ) \qquad ( Numerical Formula 2 )$$

$${S}_{1} ( {BD}_{1} ) > {S}_{1} ( G 1 ) \qquad ( Numerical Formula 3 )$$

According to a still further aspect of the invention, there is provided a solar cell including the light emitter according to the above aspect of the invention.

According to a still further aspect of the invention, there is provided a light sensor including the light emitter according to the above aspect of the invention.

According to the above aspects of the invention, there can be provided an organic electroluminescence device and an organic electroluminescence apparatus, which have a low light-emission start voltage and emit light with high efficiency, and an electronic device including the organic electroluminescence device or the organic electroluminescence apparatus.

According to the above aspects of the invention, there can be provided a light emitter having a low light-emission start voltage and emitting light with high efficiency, and a solar cell and a light sensor which include the light emitter.

### BRIEF EXPLANATION OF DRAWINGS

FIG. 1 illustrates a light emission mechanism of multi-layered emitting layers according to a first exemplary embodiment.

FIG. 2A illustrates a light emission mechanism of a fluorescent layer (a single layer).

FIG. 2B illustrates a light emission mechanism of multi-layered emitting layers containing a Pt complex.

FIG. 3 schematically illustrates an exemplary arrangement of an organic EL device according to the first exemplary embodiment.

FIG. 4 schematically illustrates another exemplary arrangement of the organic EL device according to the first exemplary embodiment.

FIG. 5 schematically illustrates an apparatus for measuring transient PL.

FIG. 6 illustrates an example of decay curves of the transient PL.

FIG. 7 illustrates a measurement system for transient EL waveforms.

FIG. 8A illustrates a measurement method of a delayed fluorescence-derived luminous intensity ratio and is a graph showing a temporal change in a luminous intensity of each of organic EL devices in Examples 1 and 2 and Comparative 1.

FIG. 8B illustrates the measurement method of the delayed fluorescence-derived luminous intensity ratio and is a graph showing a temporal change in an inverse of a square root of the luminous intensity of each of the organic EL devices in Examples 1 and 2 and Comparative 1.

FIG. 9 schematically illustrates an exemplary arrangement of an organic EL device according to a second exemplary embodiment.

FIG. 10 schematically illustrates another exemplary arrangement of the organic EL device according to the second exemplary embodiment.

FIG. 11 schematically illustrates still another exemplary arrangement of the organic EL device according to the second exemplary embodiment.

FIG. 12 schematically illustrates an exemplary arrangement of an organic EL apparatus according to a third exemplary embodiment.

FIG. 13A schematically illustrates an exemplary arrangement of a light emitter according to a fifth exemplary embodiment.

FIG. 13B schematically illustrates another exemplary arrangement of the light emitter according to the fifth exemplary embodiment.

FIG. 14A illustrates spectral radiance spectra of the organic EL devices of Examples 1 and 2 and Comparative 1 when the devices are energized at a measurement voltage of 2.40 V.

FIG. 14B illustrates spectral radiance spectra of the organic EL devices of Examples 1 and 2 and Comparative 1 when the devices are energized at a measurement voltage of 2.45 V.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and and heterocyclic compound) in which the atoms are bonded to each other to form the ring. When the ring is substituted by a substituent(s), carbon atom(s) included in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine pyridine ring has 5 ring carbon atoms, and a furan ring 4 ring carbon atoms. For instance, a 9,9-diphenylfluorenyl group has 13 ring carbon atoms and 9,9′-spirobifluorenyl group has 25 ring carbon atoms.

When a benzene ring is substituted by a substituent (e.g., an alkyl group), the number of carbon atoms of the alkyl group is not counted in the number of the ring carbon atoms. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Mentioned Herein

Substituents mentioned herein will be described below.

An “unsubstituted aryl group” mentioned herein has, unless otherwise specified herein, 6 to 50, preferably 6 to 30, and more preferably 6 to 18 ring carbon atoms.

An “unsubstituted heterocyclic group” mentioned herein has, unless otherwise specified herein, 5 to 50, preferably 5 to 30, and more preferably 5 to 18 ring atoms.

An “unsubstituted alkyl group” mentioned herein has, unless otherwise specified herein, 1 to 50, preferably 1 to 20, and more preferably 1 to 6 carbon atoms.

An “unsubstituted alkenyl group” mentioned herein has, unless otherwise specified herein, 2 to 50, preferably 2 to 20, and more preferably 2 to 6 carbon atoms.

An “unsubstituted alkynyl group” mentioned herein has, unless otherwise specified herein, 2 to 50, preferably 2 to 20, and more preferably 2 to 6 carbon atoms.

An “unsubstituted cycloalkyl group” mentioned herein has, unless otherwise specified herein, 3 to 50, preferably 3 to 20, and more preferably 3 to 6 ring carbon atoms.

An “unsubstituted arylene group” mentioned herein has, unless otherwise specified herein, 6 to 50, preferably 6 to 30, and more preferably 6 to 18 ring carbon atoms.

An “unsubstituted divalent heterocyclic group” mentioned herein has, unless otherwise specified herein, 5 to 50, preferably 5 to 30, and more preferably 5 to 18 ring atoms.

An “unsubstituted alkylene group” mentioned herein has, unless otherwise specified herein, 1 to 50, preferably 1 to 20, and more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.” A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below with a substituent, and a group derived by further substituting a hydrogen atom of a substituent of the “substituted aryl group” in the specific example group G1B below with a substituent.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

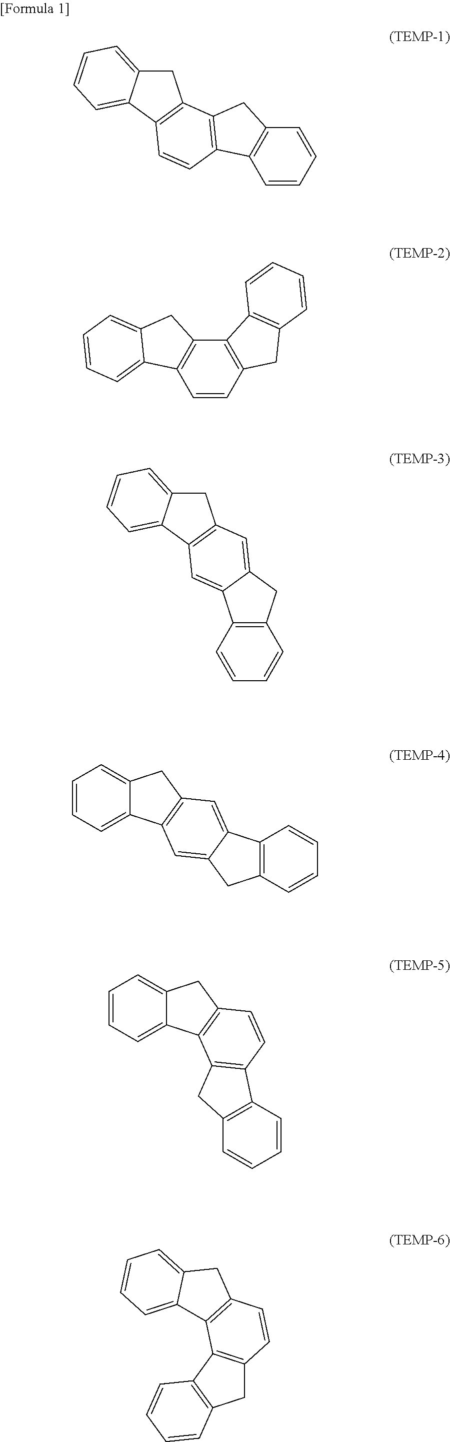

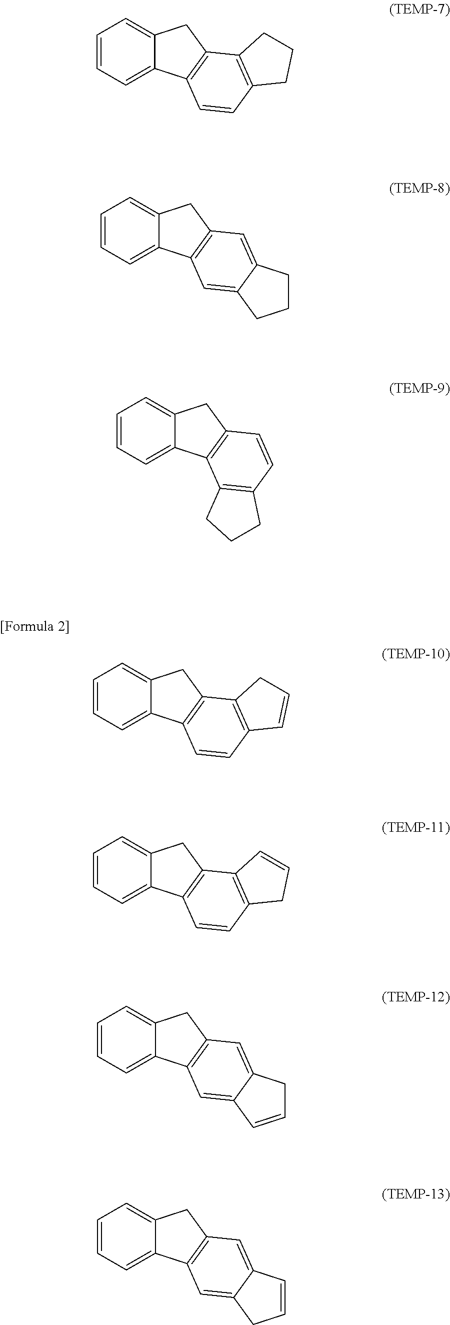

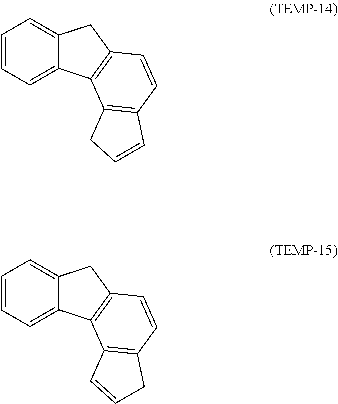

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include examples of a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below with a substituent, and a group derived by further substituting a hydrogen atom of a substituent of the “substituted heterocyclic group” in the specific example group G2B below with a substituent.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4), with a substituent, derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

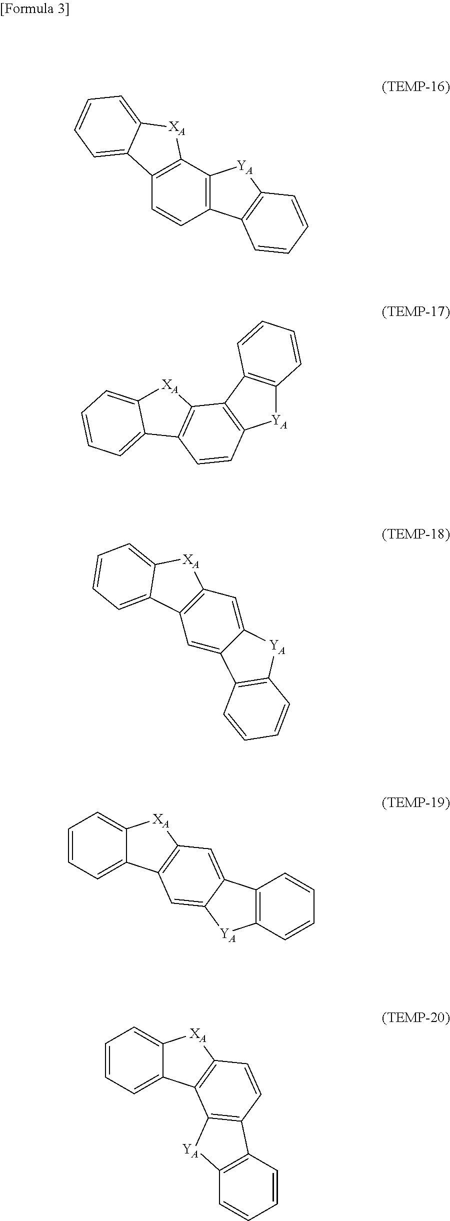

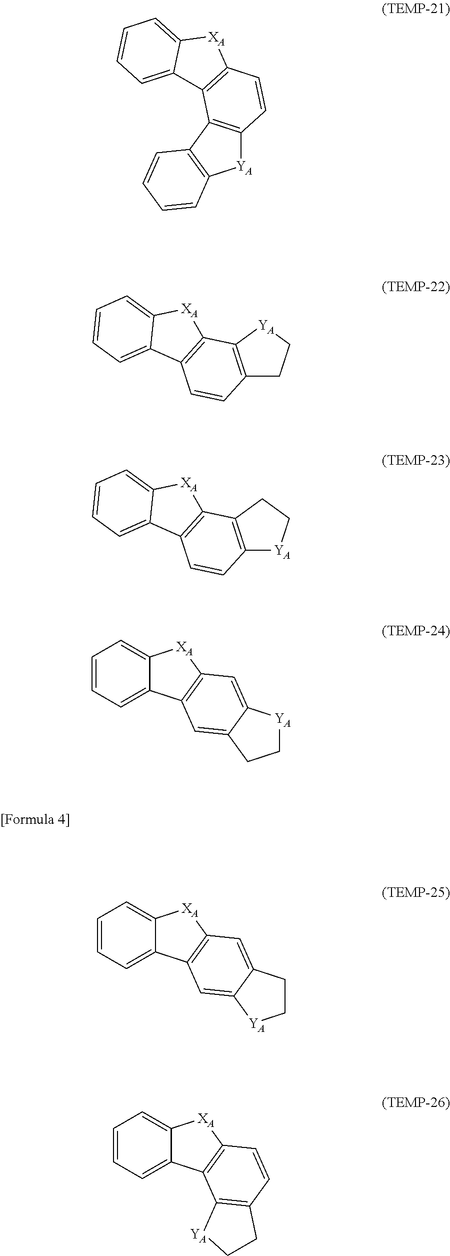

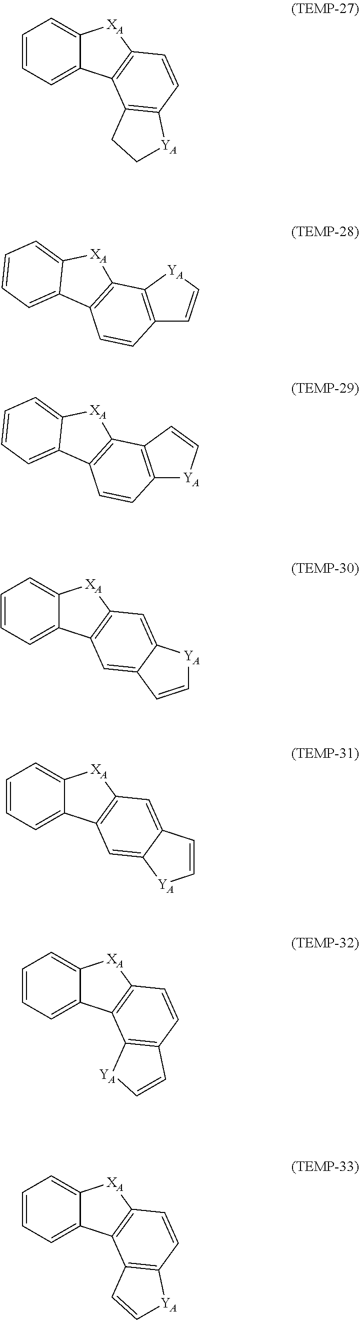

In the formulae (TEMP-16) to (TEMP-33), X_{A} and Y_{A} are each independently an oxygen atom, a sulfur atom, NH or CH₂, and at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.” A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B with a substituent, and a group derived by further substituting a hydrogen atom of a substituent of the “substituted alkyl group” in the specific example group G3B with a substituent.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. Herein, an unsubstituted alkynyl group refers to an “unsubstituted alkynyl group” in a “substituted or unsubstituted alkynyl group.” A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.” A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include: —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

A plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

A plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is occasionally referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

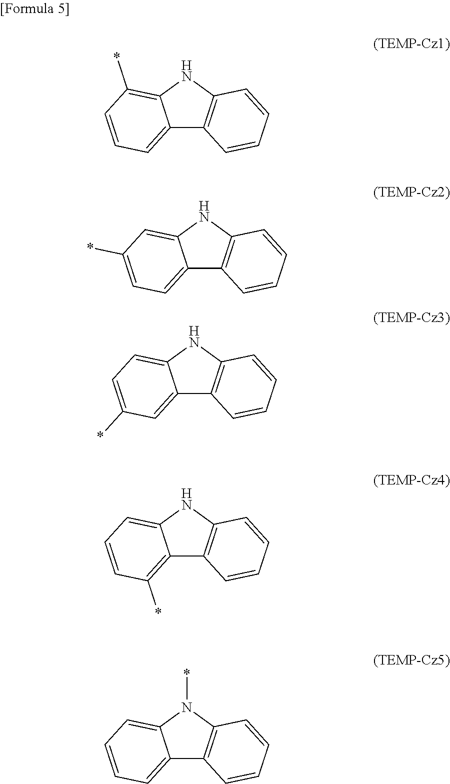 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

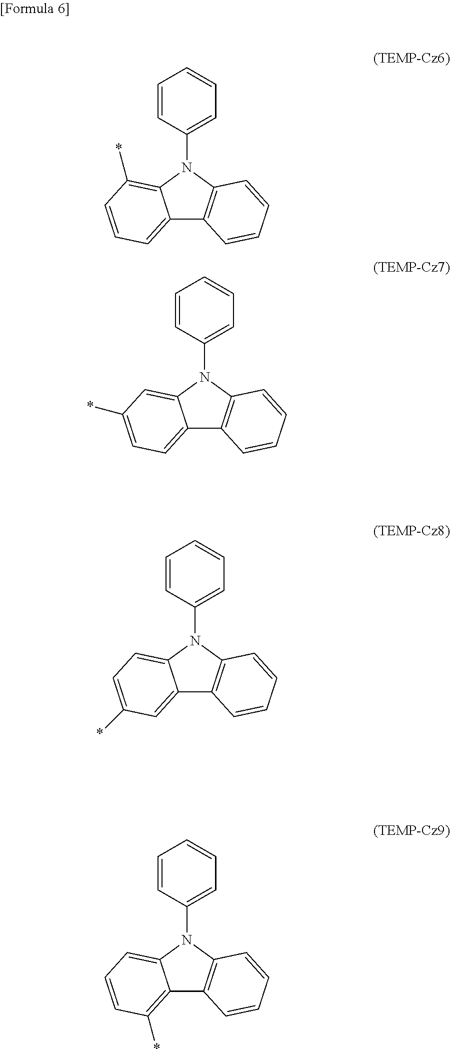

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

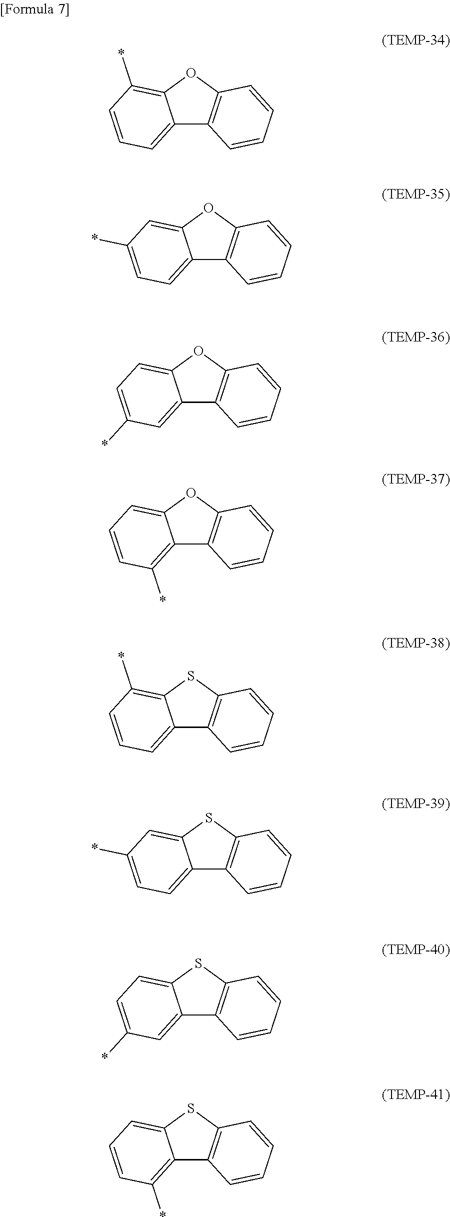

In the formulae (TEMP-34) to (TEMP-41), each * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocyclic ring of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

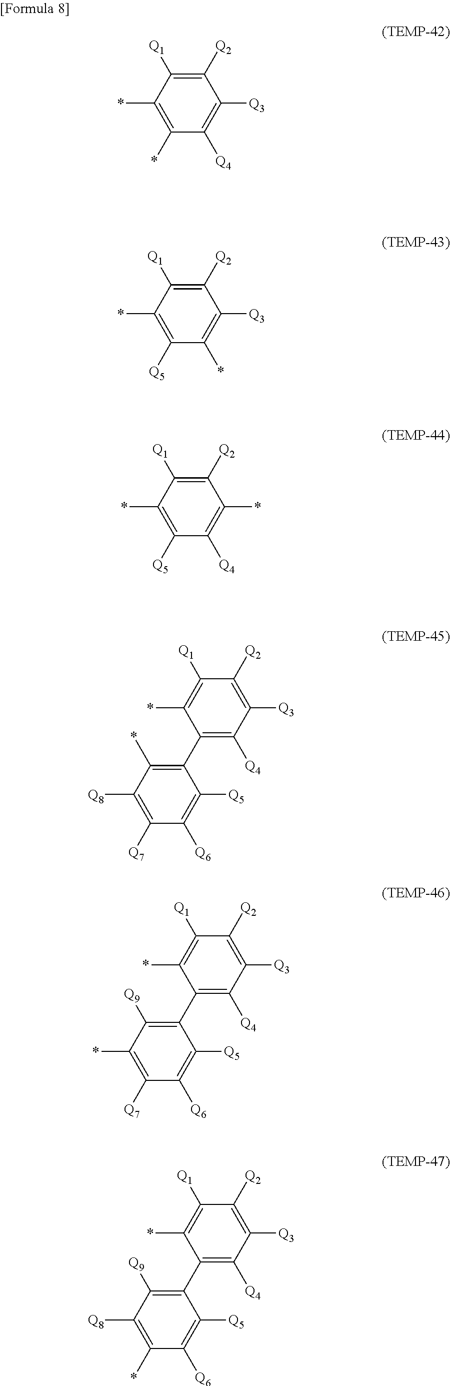

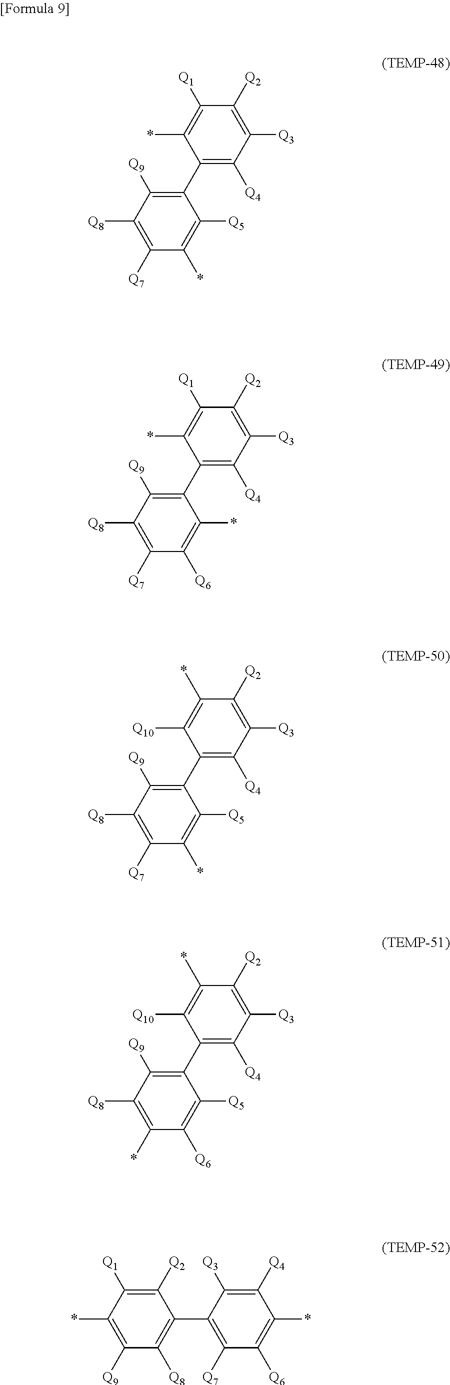

In the formulae (TEMP-42) to (TEMP-52), Q₁ to Q₁₀ are each independently a hydrogen atom or a substituent.

In the formulae (TEMP-42) to (TEMP-52), each * represents a bonding position.

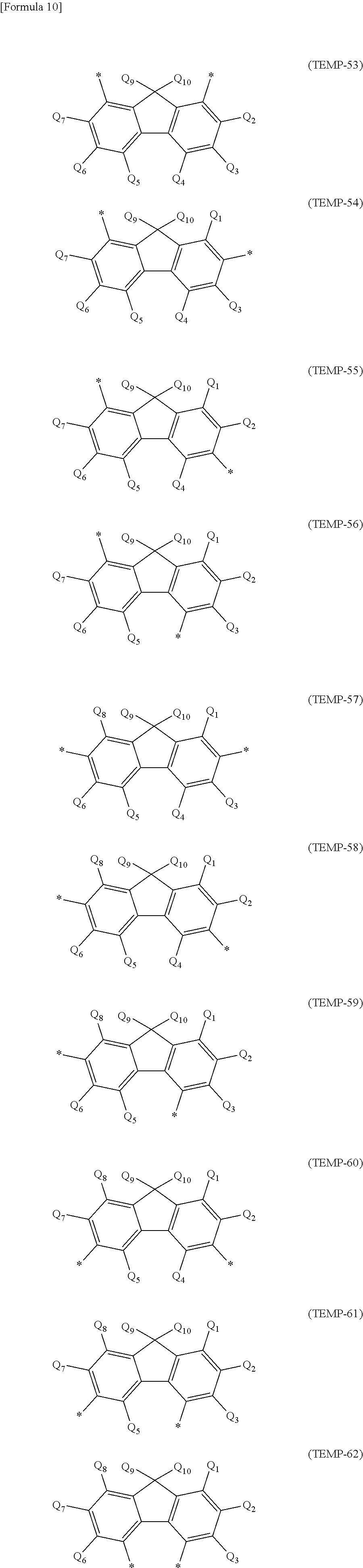

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), each * represents a bonding position.

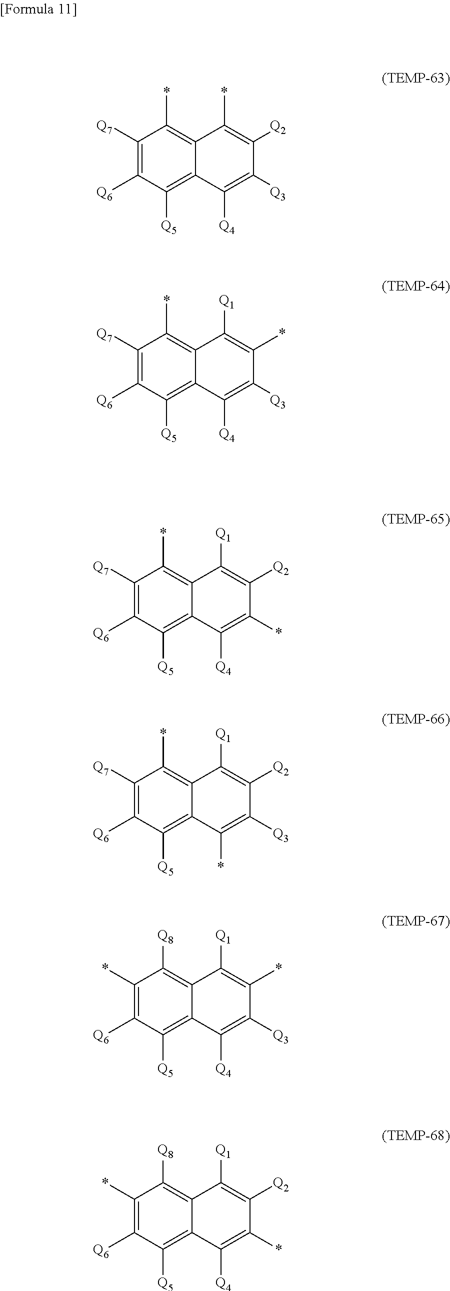

In the formulae (TEMP-63) to (TEMP-68), Q₁ to Q₈ are each independently a hydrogen atom or a substituent.

In the formulae (TEMP-63) to (TEMP-68), each * represents a bonding position.

The substituted or unsubstituted divalent heterocyclic group mentioned herein is, unless otherwise specified herein, preferably a group represented by any one of formulae (TEMP-69) to (TEMP-102) below.

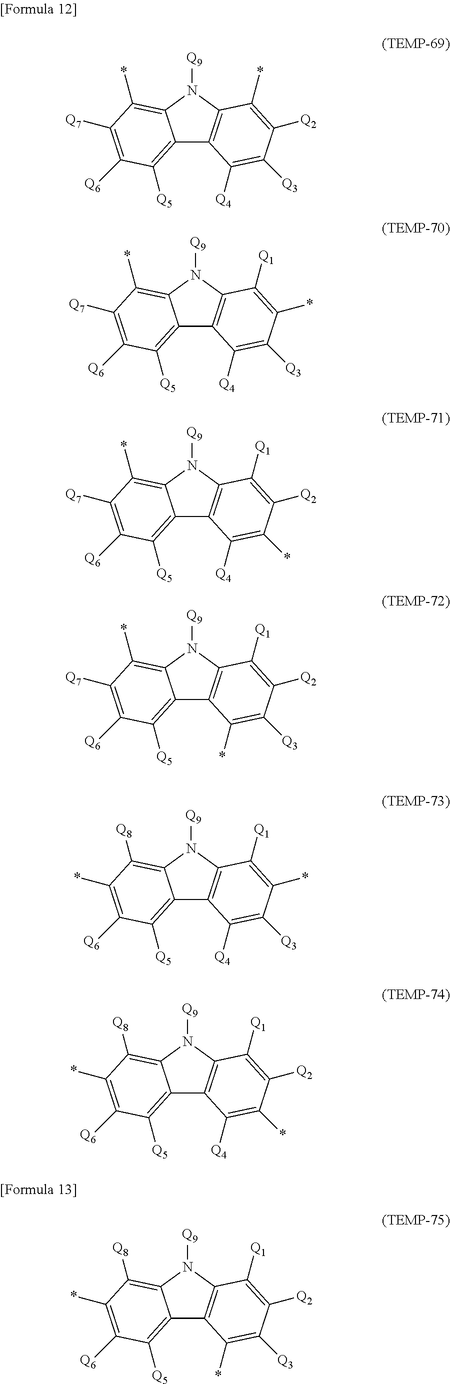

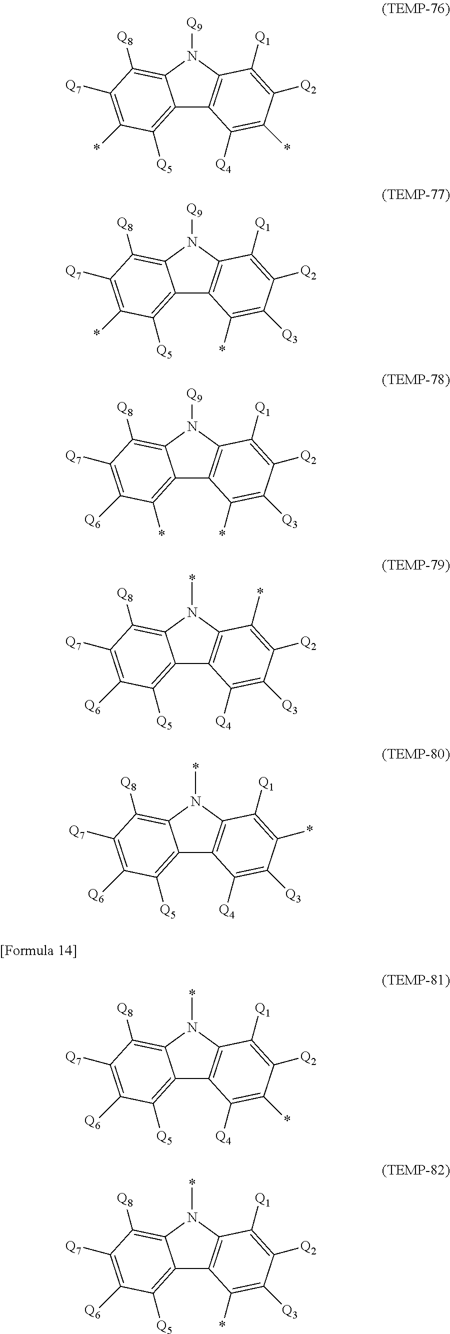

In the formulae (TEMP-69) to (TEMP-82), Q₁ to Q₉ are each independently a hydrogen atom or a substituent.

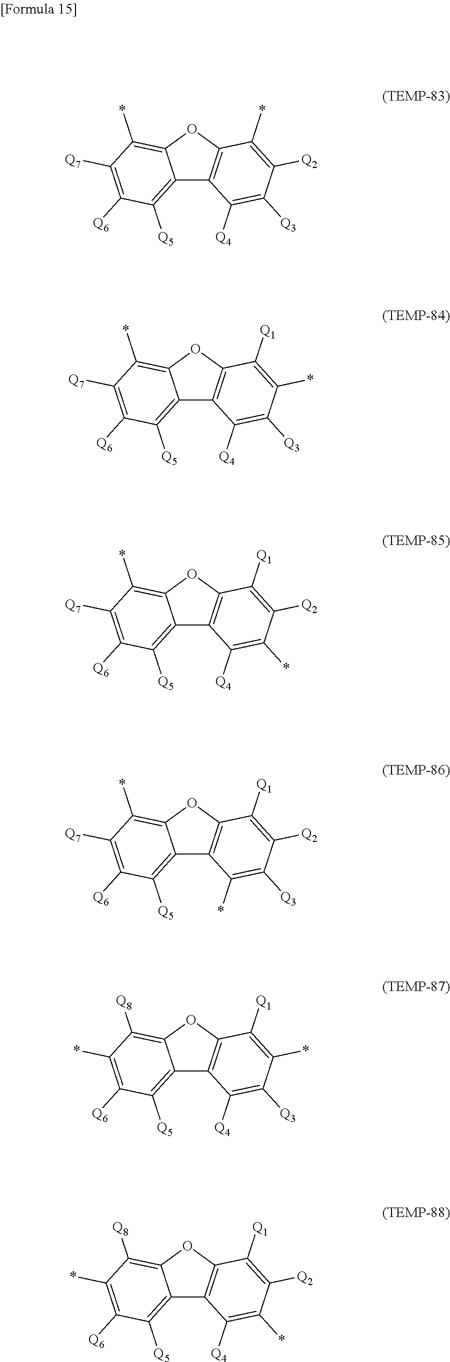

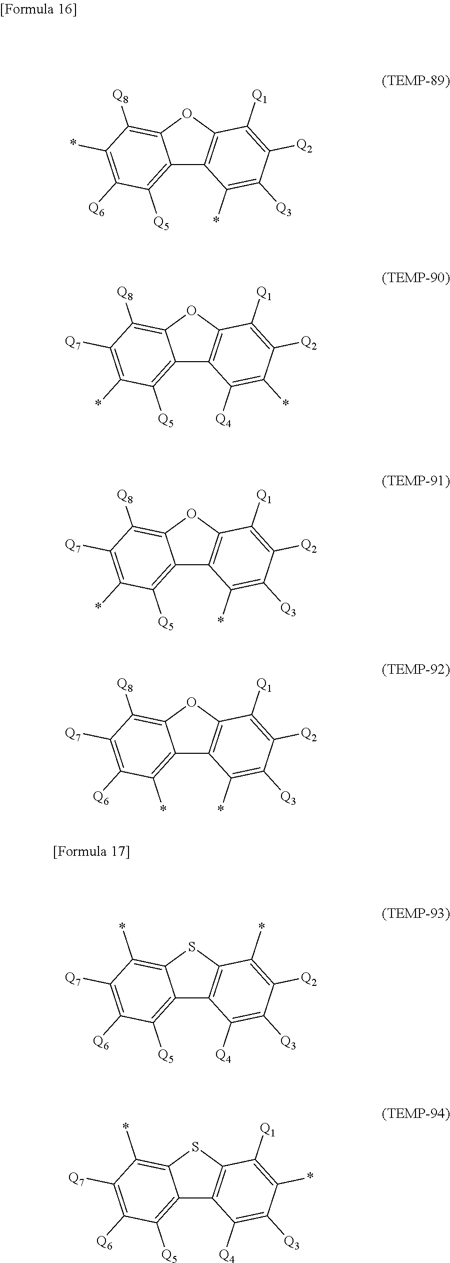

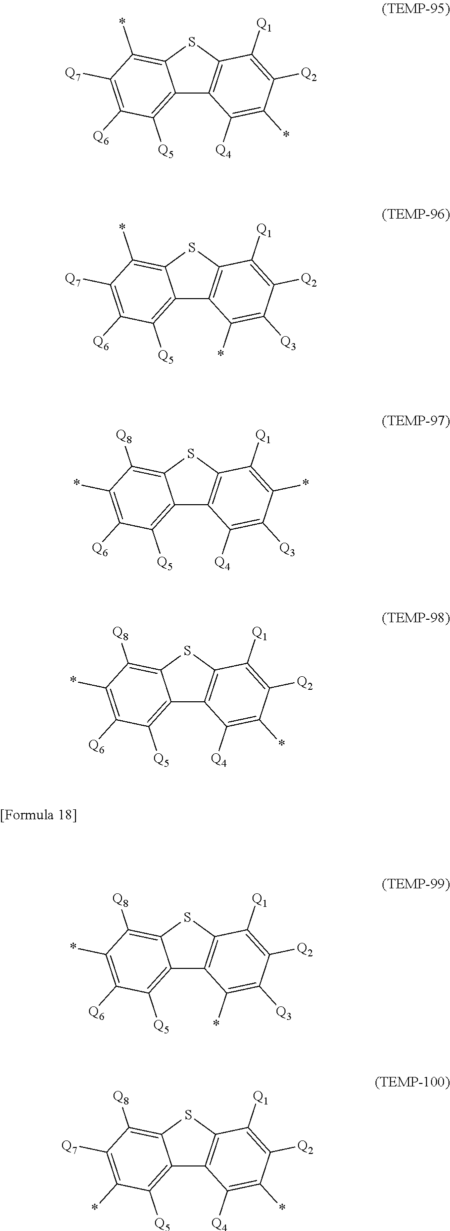

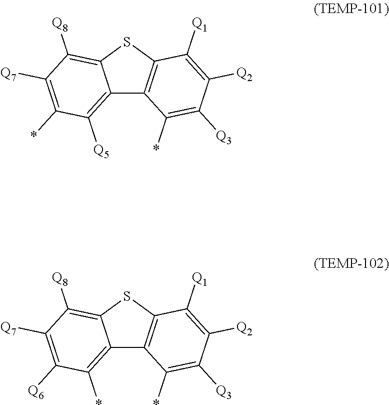

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

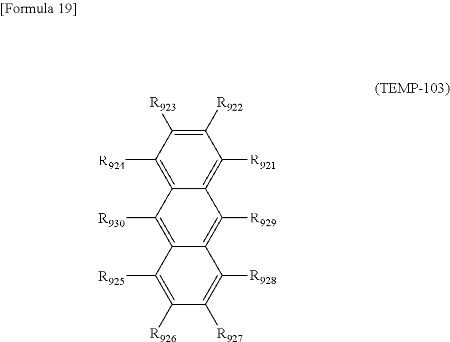

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

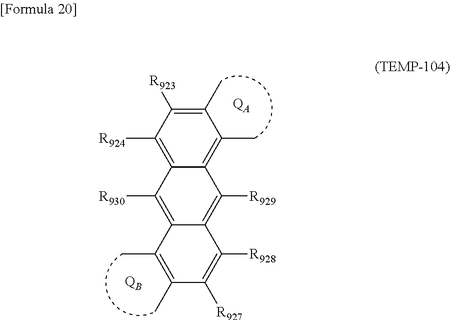

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

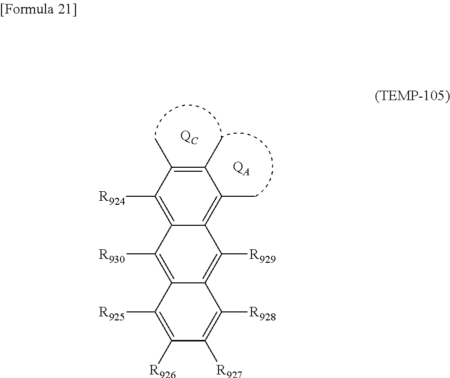

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocyclic ring include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes any other optional element than the carbon atom, the resultant ring is a heterocyclic ring.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter), is for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

Herein, a numerical formula represented by “A B” means that the value A is equal to the value B, or the value A is larger than the value B.

Herein, a numerical formula represented by “A s B” means that the value A is equal to the value B, or the value A is smaller than the value B.

### First Exemplary Embodiment

### Organic Electroluminescence Device

An organic electroluminescence device of the exemplary embodiment includes an anode, a cathode, and an emitting region interposed between the anode and the cathode, in which the emitting region includes a first sensitizing layer and a first emitting layer, the first sensitizing layer contains a first host material and a first sensitizing material, the first emitting layer contains a second host material and a first luminescent compound, the first host material and the second host material are mutually different, the first sensitizing material and the first luminescent compound are mutually different, and a difference ΔST(G1) between a lowest singlet energy S₁(G1) of the first sensitizing material and an energy gap T_{77K}(G1) at 77K of the first sensitizing material satisfy a numerical formula (Numerical Formula 1) below.

$$Δ S T ( G 1 ) = {S}_{1} ( G 1 ) - {T}_{77 K} ( G 1 ) < 0.5 eV \qquad ( Numerical Formula 1 )$$

A typical organic EL device employs a structure in which two or more emitting layers are layered as emitting layers (hereinafter, sometimes referred to as multi-layered emitting layers), thereby spatially separating an emitting layer that generates excitons upon electrical excitation from a layer that expresses upconversion by TTF, thus enhancing efficiency of the device.

However, it is usually difficult to selectively generate only triplets by electrical excitation in order to lower voltage, and it is especially difficult to emit blue light.

For instance, in an organic EL device employing multi-layered emitting layers, a threshold voltage for causing a blue fluorescent device to emit light using TTF is around 2.7 eV, which is just around energy for light emission.

Meanwhile, a device having multi-layered emitting layers (upconversion device) using a phosphorescent complex as a sensitizing material has been known for an efficient generation of a triplet state: a device using triplet energy transfer from a phosphorescent complex to TTF molecules through upconversion has been known (see Non-Patent Literature 1). However, as described above, the device having the multi-layered emitting layers using the phosphorescent complex exhibits low external quantum efficiency (EQE) (about 0.024%).

In light of the foregoing, the inventors have found that by introducing a first sensitizing material satisfying the numerical formula (Numerical Formula 1) (ΔST(G1)=S₁(G1)−T_{77K}(G1)<0.5 eV) in place of the phosphorescent complex functioning as the sensitizing material to the organic EL device having multi-layered emitting layers, a light-emission start voltage is reducible while a luminous efficiency is kept high.

The first sensitizing material satisfying the numerical formula (Numerical Formula 1) exhibits a small difference ΔST(G1) between a lowest singlet energy S₁(G1) and an energy gap T_{77K}(G1) at 77 K. This means that energy required for excitation to the triplet state can be smaller, reducing energy loss. The first sensitizing material is preferably a delayed fluorescent material.

On the other hand, a phosphorescent complex (e.g. Pt complex) as the sensitizing material has a relatively low light absorption intensity for excitation to the triplet state. Therefore, in order to express the function as the sensitizing material, it is necessary to increase a concentration of the phosphorescent complex in the film or to excite the phosphorescent complex with high energy, even if energy is lost. The concentration of the phosphorescent complex in the film cannot be increased due to the fact that the phosphorescent complex is prone to concentration quenching.

In contrast, the first sensitizing material (preferably a delayed fluorescent material) of the exemplary embodiment absorbs energy to become the triplet state, including the pathway through the singlet state. The first sensitizing material has a light absorption intensity larger than the phosphorescent complex. Accordingly, the first sensitizing material of the exemplary embodiment can generate an excited state efficiently within a film even if the concentration of the first sensitizing material in the film is made lower than that of the phosphorescent complex. Further, the first sensitizing material of the exemplary embodiment also reduces energy loss due to having a small ΔST.

Thus, the first sensitizing material of the exemplary embodiment has a small ΔST in principle and a higher light absorption intensity than the phosphorescent complex, resulting in having a suitable performance as the sensitizing material.

Accordingly, the organic EL device of the exemplary embodiment exhibits a low light-emission start voltage and emits light with high efficiency.

Specifically, for instance, organic EL devices in Examples 1 to 12 described later emit light with external quantum efficiency (EQE) of 2.2% or more and have the light-emission start voltage in a range from 2.40 V to 2.50 V at which luminance of 0.01 cd/m² is obtained. The EQE of each of the organic EL devices in Examples 1 to 12 described later is approximately 1000 times higher than that of the upconversion device in Non-Patent Literature 1. The light-emission start voltage of each of the organic EL devices in Examples 1 to 12 described later is a value approximately equal to a band gap of a material used for the first sensitizing material.

In view of the above, the organic EL device of the exemplary embodiment is promising for the need for low voltage consumption.

In an exemplary arrangement of the organic EL device of the exemplary embodiment, a difference ΔST(G1) between the lowest singlet energy S₁(G1) of the first sensitizing material and an energy gap T_{77K}(G1) at 77 K of the first sensitizing material satisfies any one of relationships represented by numerical formulae (Numerical Formula 11A to Numerical Formula 11D) below.

$$Δ S T ( G 1 ) = {S}_{1} ( G 1 ) - {T}_{77 K} ( G 1 ) < 0.4 eV \qquad ( Numerical Formula 11 A )$$

$$Δ S T ( G 1 ) = {S}_{1} ( G 1 ) - {T}_{77 K} ( G 1 ) < 0.3 eV \qquad ( Numerical Formula 11 B )$$

$$Δ S T ( G 1 ) = {S}_{1} ( G 1 ) - {T}_{77 K} ( G 1 ) < 0.2 eV \qquad ( Numerical Formula 11 C )$$

$$Δ S T ( G 1 ) = {S}_{1} ( G 1 ) - {T}_{77 K} ( G 1 ) < 0.1 eV \qquad ( Numerical Formula 11 D )$$

In an exemplary arrangement of the organic EL device of the exemplary embodiment, the energy gap T_{77K}(G1) at 77 K of the first sensitizing material, an energy gap T_{77K}(H1) at 77K of the first host material, and an energy gap T_{77K}(H2) at 77K of the second host material satisfy a relationship represented by a numerical formula (Numerical Formula 2) below.

$${T}_{77 K} ( G 1 ) > {T}_{77 K} ( H 1 ) > {T}_{77 K} ( H 2 ) \qquad ( Numerical Formula 2 )$$

When the first host material, the first sensitizing material, and the second host material satisfy the numerical formula (Numerical Formula 2), triplet excitons generated in the first sensitizing layer transfer on the first host material, not on the first sensitizing material having higher triplet energy, and further transfer easily from the first host material onto the second host material in the first emitting layer.

In an exemplary arrangement of the organic EL device of the exemplary exemplary embodiment, the energy gap T_{77K}(G1) at 77 K of the first sensitizing material and the energy gap T_{77K}(H1) at 77K of the first host material satisfy a relationship represented by a numerical formula (Numerical Formula 21) below.

$${T}_{77 K} ( G 1 ) - {T}_{77 K} ( H 1 ) < 0.5 eV \qquad ( Numerical Formula 21 )$$

In an exemplary arrangement of the organic EL device of the exemplary exemplary embodiment, the energy gap T_{77K}(G1) at 77 K of the first sensitizing material and the energy gap T_{77K}(H1) at 77K of the first host material satisfy a relationship represented by a numerical formula (Numerical Formula 21A) below.

$${T}_{77 K} ( G 1 ) - {T}_{77 K} ( H 1 ) < 0.4 eV \qquad ( Numerical Formula 21 A )$$

When the first sensitizing material and the first host material satisfy the numerical formula (Numerical Formula 21 or Numerical Formula 21A), triplet excitons generated in the first sensitizing layer transfer on the first sensitizing material and then easily transfer therefrom onto the first host material with efficiency.

In an exemplary arrangement of the organic EL device of the exemplary exemplary embodiment, the energy gap T_{77K}(H1) at 77 K of the first host material and the energy gap T_{77K}(H2) at 77K of the second host material satisfy a relationship represented by a numerical formula (Numerical Formula 22) below.

$${T}_{77 K} ( H 1 ) - {T}_{77 K} ( H 2 ) < 0.3 eV \qquad ( Numerical Formula 22 )$$

When the first host material and the second host material satisfy the relationship of the numerical formula (Numerical Formula 22), the excited triplet energy is efficiently transferred from the first sensitizing layer containing the first host material to the first emitting layer containing the second host material, and upconversion in the emission region is advantageously achieved.

In an exemplary arrangement of the organic EL device of the exemplary embodiment, the lowest singlet energy S₁(G1) of the first sensitizing material and the lowest singlet energy S₁(BD1) of the first luminescent compound satisfy a relationship of a numerical formula (Numerical Formula 3) below.

$${S}_{1} ( {BD}_{1} ) > {S}_{1} ( G 1 ) \qquad ( Numerical Formula 3 )$$

When the first sensitizing material and the first luminescent compound satisfy the relationship of the numerical formula (Numerical Formula 3), upconversion luminescence, in which the organic EL device emits light when the first sensitizing layer is given an energy smaller than the lowest singlet energy of the first luminescent compound, is produced.

In an exemplary arrangement of the organic EL device of the exemplary embodiment, the first sensitizing layer and the first emitting layer are in direct contact with each other.

In an exemplary arrangement of the organic EL device of the exemplary embodiment, the first sensitizing layer is disposed between the anode and the cathode, and the first emitting layer is disposed between the first sensitizing layer and the cathode. In this arrangement, the emitting region includes the first sensitizing layer and the first emitting layer in this order from a side close to the anode.

In an exemplary arrangement of the organic EL device of the exemplary embodiment, in a case where the emitting region includes the first sensitizing layer and the first emitting layer in this order from a side close to the anode, an absolute value of an energy level LUMO(G1) of the lowest unoccupied molecular orbital of the first sensitizing material and an absolute value of the energy level LUMO(H1) of the lowest unoccupied molecular orbital of the first host material satisfy a relationship represented by a numerical formula (Numerical Formula 4) below.

$$\vert LUMO ( G 1 ) \vert > \vert LUMO ( H 1 ) \vert \qquad ( Numerical Formula 4 )$$

When the first sensitizing material and the first host material satisfy the relationship of the numerical formula (Numerical Formula 4), electrons are easily trapped in the first sensitizing material in the first sensitizing layer and, consequently, recombination of holes and electrons in the first sensitizing layer is promoted.

In an exemplary arrangement of the organic EL device of the exemplary embodiment, in a case where the emitting region includes the first sensitizing layer and the first emitting layer in this order from a side close to the anode, in addition to the first sensitizing material and the first host material satisfying the relationship of the numerical formula (Numerical Formula 4), an absolute value of the energy level LUMO(H2) of the lowest unoccupied molecular orbital of the second host material and an absolute value of the energy level LUMO(BD1) of the lowest unoccupied molecular orbital of the first luminescent compound satisfy a relationship represented by a numerical formula (Numerical Formula 41) below.

$$\vert LUMO ( H 2 ) \vert > \vert LUMO ( BD 1 ) \vert \qquad ( Numerical Formula 41 )$$

When the second host material and the first luminescent compound satisfy the relationship of the numerical formula (Numerical Formula 41), electrons are unlikely to be trapped in the first luminescent compound in the first emitting layer and, consequently, recombination of holes and electrons in the first sensitizing layer is promoted.

In an exemplary arrangement of the organic EL device of the exemplary embodiment, the first sensitizing layer is disposed between the anode and the cathode, and the first emitting layer is disposed between the first sensitizing layer and anode. In this arrangement, the emitting region includes the first emitting layer and the first sensitizing layer in this order from a side close to the anode.

In an exemplary arrangement of the organic EL device of the exemplary embodiment, in a case where the emitting region includes the first emitting layer and the first sensitizing layer in this order from a side close to the anode, an absolute value of an energy level HOMO(G1) of the highest occupied molecular orbital of the first sensitizing material and an absolute value of an energy level HOMO(H1) of the highest occupied molecular orbital of the first host material satisfy a relationship represented by a numerical formula (Numerical Formula 5) below.

$$\vert HOMO ( G 1 ) \vert < \vert HOMO ( H 1 ) \vert \qquad ( Numerical Formula 5 )$$

When the first sensitizing material and the first host material satisfy the relationship of the numerical formula (Numerical Formula 5), holes are easily trapped in the first sensitizing material in the first sensitizing layer and, consequently, recombination of holes and electrons in the first sensitizing layer is promoted.

In an exemplary arrangement of the organic EL device of the exemplary embodiment, in a case where the emitting region includes the first emitting layer and the first sensitizing layer in this order from a side close to the anode, in addition to the first sensitizing material and the first host material satisfying the relationship of the numerical formula (Numerical Formula 5), an absolute value of an energy level HOMO(H2) of the highest occupied molecular orbital of the second host material and an absolute value of an energy level HOMO(BD1) of the highest occupied molecular orbital of the first luminescent compound satisfy a relationship represented by a numerical formula (Numerical Formula 51) below.

$$\vert HOMO ( H 2 ) \vert > \vert HOMO ( BD1 ) \vert \qquad ( Numerical Formula 51 )$$

When the second host material and the first luminescent compound satisfy the relationship of the numerical formula (Numerical Formula 51), holes are unlikely to be trapped in the first luminescent compound in the first emitting layer and, consequently, recombination of holes and electrons in the first sensitizing layer is promoted.

A measurement method of HOMO and LUMO is as follows.

### Energy Level HOMO of Highest Occupied Molecular Orbital

The energy level HOMO of the highest occupied molecular orbital is measured by irradiating a compound (compound or material) to be measured with light and measuring the amount of electrons produced by charge separation using a photoelectron spectrometer under air (AC-3 manufactured by RIKEN KEIKI CO., LTD.).

### Energy Level LUMO of Lowest Unoccupied Molecular Orbital

The energy level LUMO of the lowest unoccupied molecular orbital is measured by a differential pulse voltammetry method. Details of the differential pulse voltammetry method are as follows.

The energy level LUMO of the lowest unoccupied molecular orbital of the measured object (compound or material) is a value calculated by a numerical formula (Numerical Formula 1Y) below. A unit of the energy level LUMO of the lowest unoccupied molecular orbital is eV.

$$LUMO = - 1.19 \times ( Ere - Efc ) - 4.78 eV \qquad ( Numerical Formula 1 Y )$$

In the numerical formula (Numerical Formula 1Y), Ere and Efc are as follows.

Ere is the first reduction potential of the measured object (DPV, Negative scan).

Efc is the first oxidation potential of ferrocene (DPV, Positive scan), (ca.+0.55V vs Ag/AgCl).

A redox potential is measured by a differential pulse voltammetry (DPV) method using an electrochemical analyzer (CHI852D manufactured by ALS).

A sample solution used for the measurement is prepared by dissolving a measured object in N,N-dimethylformamide (DMF) as a solvent so as to reach a concentration of 1.0 mmol/L, and dissolving tetrabuthylammonium hexafluorophosphate (TBHP) as support electrolyte in the solvent so as to reach a concentration of 100 mmol/L. A glassy carbon electrode is used as a working electrode. A platinum (Pt) electrode is used as a counter electrode.
Reference Literature: M. E. Thompson, et. al., Organic Electronics, 6(2005), p.11-20, Organic Electronics, 10(2009), p.515-520

In an exemplary arrangement of the organic electroluminescence device of the exemplary embodiment, a difference between energy E_{PE} (eV) at peak of an emission spectrum and energy E_{TH} (eV) imparted to the device when a luminance of 0.01 cd/m² is obtained satisfies a relationship of a numerical formula (Numerical Formula 6) below.

$${E}_{TH} - {E}_{PE} \leq 0.05 eV \qquad ( Numerical Formula 6 )$$

Herein, the light-emission start voltage V_{TH} (unit: V) means a voltage when the device is driven at a current density where a luminance of 0.01 cd/m² is obtained.

Herein, “energy E_{TH} (eV) imparted to the device when a luminance of 0.01 cd/m² is obtained” means a value calculated according to a numerical formula (Numerical Formula Y1) below.

$${E}_{TH} ( eV ) = light ‐ emission start voltage {V}_{TH} ( V ) \times elementary electric charge ( e ) \qquad ( Numerical Formula Y 1 )$$

Herein, “energy E_{PE} (eV) at peak of an emission spectrum” means a value (unit: eV) of energy required for exciting a luminescent compound contained in the emitting layer to be measured to the singlet state S1. The “energy E_{PE} (eV) at peak of an emission spectrum” substantially corresponds to a band gap of the luminescent compound.

The measurement method of the light-emission start voltage V_{TH} is as described in Examples.

Herein, as the “energy E_{PE} (eV) at peak of an emission spectrum”, a measurement value of the lowest singlet energy S₁ of the luminescent compound contained in the emitting layer to be measured is used. The measurement method of the lowest singlet energy S₁ is as described in Examples.

An example of a light emission mechanism of the exemplary embodiment will be described.

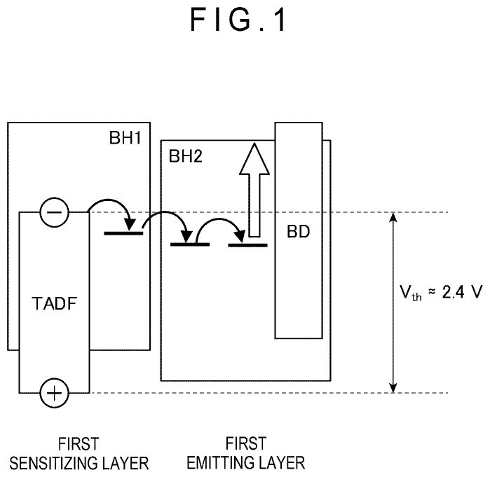

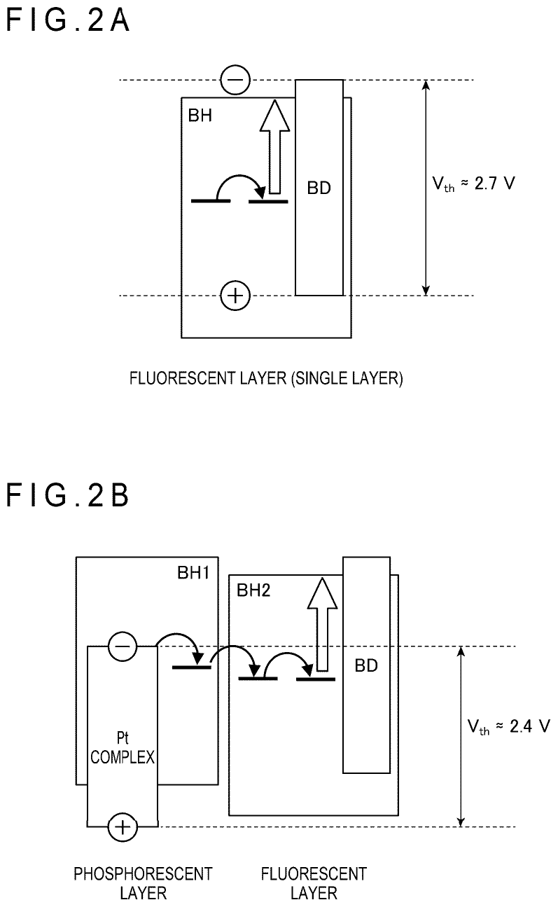

FIG. 1 illustrates a light emission mechanism of multi-layered emitting layers according to the exemplary embodiment. FIG. 2A illustrates a light emission mechanism of a fluorescent layer (a single layer). FIG. 2B illustrates a light emission mechanism of multi-layered emitting layers containing a Pt complex.

In FIGS. 1, 2A, and 2B, TADF represents a delayed fluorescent material (corresponding to the first sensitizing material in the exemplary embodiment), BH1 represents the first host material, BH2 represents the second host material, BH represents a host material in a fluorescent layer (single layer), BD represents a luminescent compound (corresponding to the first luminescent compound in the exemplary embodiment), and V_{TH} represents a light-emission start voltage.

### Example of Light Emission Mechanism of the Exemplary Embodiment

TADF (delayed fluorescent material) illustrated in FIG. 1 is, for instance, a compound TADF-a used in Example 1 described later and has a band gap of about 2.4 eV. Accordingly, by imparting energy of about 2.4 eV to the multi-layered emitting layers illustrated in FIG. 1, TADF (delayed fluorescent material) in the first sensitizing layer becomes excited. This energy of about 2.4 eV corresponds to “energy E_{PE} (eV) at peak of an emission spectrum” in the numerical formula (Numerical Formula 6).

As described above, by imparting energy corresponding to the band gap of TADF (delayed fluorescent material), the singlet state S1 and the triplet state T1 of TADF (delayed fluorescent material) are generated, and further TADF (delayed fluorescent material) satisfies the numerical formula (Numerical Formula 1), so that intersystem crossing from the singlet state S1 to the triplet state T1 in this TADF occurs with a small energy loss. In the triplet state T1 generated by intersystem crossing, energy transfers to the first host material (BH1) in the first sensitizing layer and further transfers to the second host material (BH2) in the first emitting layer (the numerical formula (Numerical Formula 2)). In the second host material (BH2), TTF phenomenon occurs to convert the triplet state T1 of the second host material (BH2) to the singlet state S1. Since the energy of this converted singlet state S1 transfers to a luminescent compound (BD) that is in the singlet state S1 higher than the singlet state S1 of TADF (delayed fluorescent material) (the numerical formula (Numerical Formula 3)), the luminescent compound (BD) emits blue light with energy of about 2.4 eV (light-emission start voltage V_{TH}≈2.4 V). This energy of about 2.4 eV corresponds to the energy E_{TH} (eV) imparted to the device when a luminance of 0.01 cd/m² is obtained in the numerical formula (Numerical Formula 6).

As described above, in the light emission mechanism of the exemplary embodiment, by simply imparting energy for bringing TADF (delayed fluorescent material) into an excited state to the multi-layered emitting layers, almost all of the triplet state generated by intersystem crossing in the TADF can be transferred to the first emitting layer, thereby enabling the luminescent compound (BD) to emit blue light. In other words, the multi-layered emitting layers illustrated in FIG. 1 can be said to be emitting layers enabling upconversion, since the multi-layered emitting layers can emit blue light with energy (E_{PE} in the numerical formula (Numerical Formula 6)) corresponding to the band gap of TADF (delayed fluorescent material).

Accordingly, the organic EL device including the multi-layered emitting layers exhibits a low light-emission start voltage V_{TH} and emits light with high efficiency.

### Light Emission Mechanism of Single-Layered Fluorescent Layer

The luminescent compound (BD) illustrated in FIG. 2A is a blue-emitting compound. In a case of FIG. 2A, by imparting energy (about 2.7 eV of the band gap of the blue-emitting compound), which is for bringing a blue-emitting compound to an excited state, to a single-layered fluorescent layer, the luminescent compound (BD) is brought into the singlet state S1 by direct recombination of charges on the luminescent compound (BD), whereby the blue-emitting compound emits blue light.

### Light Emission Mechanism of Multi-Layered Emitting Layers

In a case of FIG. 2B, by imparting energy (about 2.4 eV of the band gap of a Pt complex), which is for bringing the Pt complex as a phosphorescent complex to an excited state, to the multi-layered emitting layers, the Pt complex is brought into an excited state.

Subsequent steps in the light emission mechanism are similar to those in the light emission mechanism illustrated in FIG. 1. However, as a Pt complex has low light absorption intensity and is prone to concentration quenching, only the energy required for bringing the Pt complex into an excited state is not sufficient to make the luminescent compound (BD) emit blue light.

In order to make the luminescent compound (BD) emit blue light, it is required to increase the energy to be imparted to the multi-layered emitting layers illustrated in FIG. 2B or increase the concentration of the Pt complex. Therefore, the organic EL device including the multi-layered emitting layers containing the Pt complex cannot emit light with high efficiency.

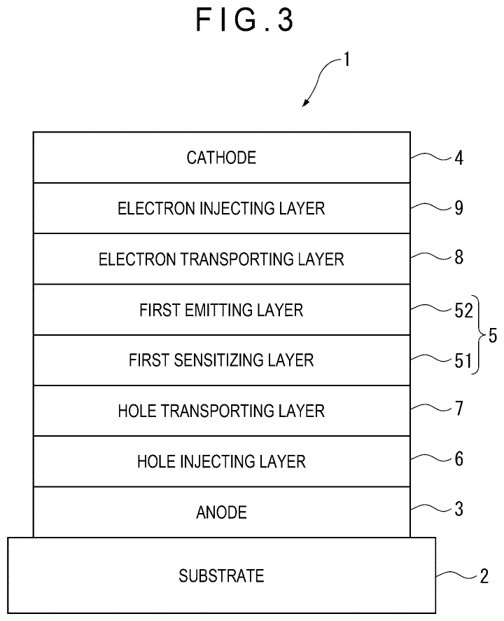

FIG. 3 schematically depicts an exemplary arrangement of the organic EL device according to the first exemplary embodiment.

An organic EL device 1 includes a light-transmissive substrate 2, an anode 3, a cathode 4, and an organic layer disposed between the anode 3 and the cathode 4. The organic layer includes a hole injecting layer 6, a hole transporting layer 7, a first sensitizing layer 51, a first emitting layer 52, an electron transporting layer 8, and an electron injecting layer 9 that are layered in this order from a side close to the anode 3. An emitting region 5 includes the first sensitizing layer 51 and the first emitting layer 52 in this order from a side close to the anode 3. The first sensitizing layer 51 and the first emitting layer 52 are preferably in direct contact with each other.

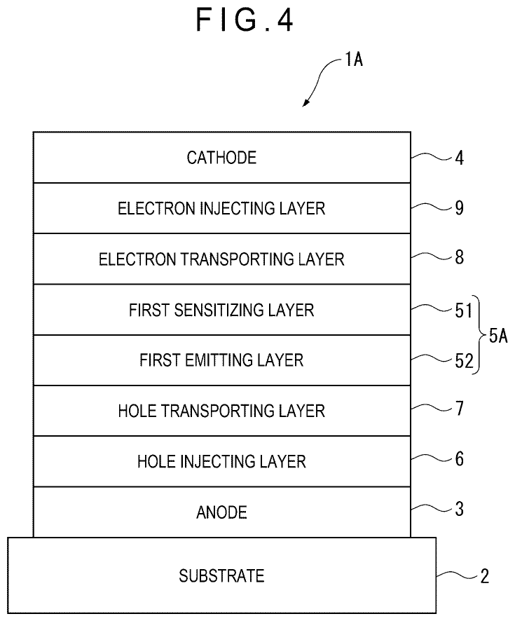

FIG. 4 schematically illustrates another exemplary arrangement of the organic EL device according to the first exemplary embodiment.

An organic EL device 1A includes the light-transmissive substrate 2, the anode 3, the cathode 4, and an organic layer disposed between the anode 3 and the cathode 4. The organic layer includes the hole injecting layer 6, the hole transporting layer 7, the first emitting layer 52, the first sensitizing layer 51, the electron transporting layer 8, and the electron injecting layer 9 that are layered in this order from a side close to the anode 3. An emitting region 5A includes the first emitting layer 52 and the first sensitizing layer 51 in this order from a side close to the anode 3. The first emitting layer 52 and the first sensitizing layer 51 are preferably in direct contact with each other.

The invention is not limited to the exemplary arrangements of the organic EL device illustrated in FIGS. 3 and 4. Examples of another arrangement of the organic EL device include an arrangement of the organic EL device in which an interposed layer is disposed between the first sensitizing layer 51 and the first emitting layer 52. In a case illustrated in FIG. 3, the emitting region 5 may include the first sensitizing layer 51, the interposed layer, and the first emitting layer 52 in this order from a side close to the anode 3. In a case illustrated in FIG. 4, the emitting region 5A may include the first emitting layer 52, the interposed layer, and the first sensitizing layer 51 in this order from a side close to the anode 3.

Arrangements of the organic EL device according to the first exemplary embodiment will be described. It should be noted that the codes are occasionally omitted below.

### Emitting Region

The organic EL device according to the exemplary embodiment includes the emitting region including the first sensitizing layer and the first emitting layer. The emitting region of the exemplary embodiment may include only the first sensitizing layer and the first emitting layer, or may include a further organic layer different from the first sensitizing layer and the first emitting layer.

### First Sensitizing Layer

The first sensitizing layer contains the first host material and the first sensitizing material.

The first host material and the second host material are mutually different compounds. The first sensitizing material and the first luminescent compound are mutually different compounds.

The first host material is exemplified by at least one compound selected from the group consisting of a first compound and a second compound described below.

The first sensitizing material is not limited to a particular compound. Any compound satisfying the numerical formula (Numerical Formula 1) is usable as the first sensitizing material. The first sensitizing material is exemplified by at least one compound selected from the group consisting of compounds represented by formulae (2), (22), (11) to (13), (1000) to (1003), (1004A) to (1004D), (1005A) to (1005D), (1006), (1007A), (1007B), (1008), (1008A), (1009A) to (1009C), (1010), (1011A), (1011B), (1012A), (1012B), (1013) to (1015), (1016A), and (1016B).

In an exemplary arrangement of the exemplary embodiment, the first sensitizing material is not a complex.

In an exemplary arrangement of the exemplary embodiment, the first sensitizing material contains no heavy metal element. Examples of the heavy metal element include iridium, osmium, and platinum.

In an exemplary arrangement of the exemplary embodiment, the first sensitizing layer contains no metal complex.

In an exemplary arrangement of the exemplary embodiment, the first sensitizing material contains no heavy metal element.

In an exemplary arrangement of the exemplary embodiment, the first sensitizing material is a compound exhibiting delayed fluorescence (delayed fluorescent material). In an exemplary arrangement of the exemplary embodiment, the first sensitizing material is a compound exhibiting no delayed fluorescence.

In an exemplary arrangement of the exemplary embodiment, the first sensitizing layer contains 10 mass % or more, or 25 mass % or more, of the first sensitizing material with respect to a total mass of the first sensitizing layer.

In an exemplary arrangement of the exemplary embodiment, the first sensitizing layer contains 50 mass % or less, or 25 mass % or less, of the first sensitizing material with respect to the total mass of the first sensitizing layer.

In an exemplary arrangement of the exemplary embodiment, the first sensitizing layer contains 50 mass % or more, 60 mass % or more, 70 mass % or more, 80 mass % or more, 90 mass % or more, or 95 mass % or more, of the first host material with respect to the total mass of the first sensitizing layer.

In an exemplary arrangement of the exemplary embodiment, the first sensitizing layer contains 90 mass % or less of the first host material with respect to the total mass of the first sensitizing layer.

In an exemplary arrangement of the exemplary embodiment, the upper limit of the total of the content ratios of the first host material and the first sensitizing material in the first sensitizing layer is 100 mass %.

In an exemplary arrangement of the exemplary embodiment, a film thickness of the first sensitizing layer is 3 nm or more, or 5 nm or more. When the film thickness of the first sensitizing layer is 3 nm or more, the film thickness is sufficient to cause recombination of holes and electrons in the first sensitizing layer.

In an exemplary arrangement of the exemplary embodiment, the film thickness of the first sensitizing layer is 20 nm or less, or 15 nm or less. When the film thickness of the first sensitizing layer is 20 nm or less, the film thickness is sufficiently thin to allow for transfer of triplet excitons to the first emitting layer.

### First Sensitizing Material

In an exemplary arrangement of the exemplary embodiment, the first sensitizing material is a compound represented by a formula (2) or (22) below.

### Compound Represented by Formula (2)

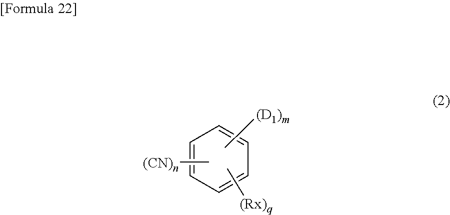

In the formula (2):
n is 1, 2, 3 or 4;
m is 1, 2, 3 or 4;
q is 0, 1, 2, 3 or 4;
m+n+q=6 is satisfied;
CN is a cyano group;
D₁ is a group represented by a formula (2a), (2b) or (2c) below, and when a plurality of D₁ are present, the plurality of D₁ are mutually the same or different;
at least one combination of adjacent two or more of Rx are mutually bonded to form a substituted or unsubstituted monocyclic ring, or mutually bonded to form a substituted or unsubstituted fused ring;
when a plurality of Rx are present, the plurality of Rx are mutually the same or different;
Rx forming neither the substituted or unsubstituted monocyclic ring nor the substituted or unsubstituted fused ring are each independently a hydrogen atom, a halogen atom, a substituted or unsubstituted aryl group having 6 to 30 ring carbon atoms, a substituted or unsubstituted heterocyclic group having 5 to 30 ring atoms, a substituted or unsubstituted amino group, a substituted or unsubstituted carbonyl group a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted alkylsilyl group having 3 to 30 carbon atoms, or a substituted or unsubstituted arylsilyl group having 6 to 60 ring carbon atoms; and
CN, D₁, and Rx are bonded to respective carbon atoms of a six-membered ring.

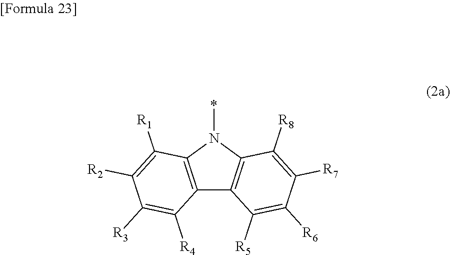

In the formula (2a):
at least one combination of adjacent two or more of R₁ to R₈ are mutually bonded to form a substituted or unsubstituted monocyclic ring, or mutually bonded to form a substituted or unsubstituted fused ring;
R₁ to R₈ forming neither the substituted or unsubstituted monocyclic ring nor the substituted or unsubstituted fused ring are each independently a hydrogen atom, a halogen atom, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted alkylsilyl group having 3 to 30 carbon atoms, a substituted or unsubstituted arylsilyl group having 6 to 60 ring carbon atoms, a hydroxy group, a substituted or unsubstituted alkoxy group having 1 to 30 carbon atoms, a substituted or unsubstituted alkoxy halide group having 1 to 30 carbon atoms, a substituted or unsubstituted aryloxy group having 6 to 30 ring carbon atoms, a substituted or unsubstituted alkylamino group having 2 to 30 carbon atoms, a substituted or unsubstituted arylamino group having 6 to 60 ring carbon atoms, a thiol group, a substituted or unsubstituted alkylthio group having 1 to 30 carbon atoms, or a substituted or unsubstituted arylthio group having 6 to 30 ring carbon atoms; and
* represents a bonding position to a carbon atom in a six-membered ring in the formula (2).

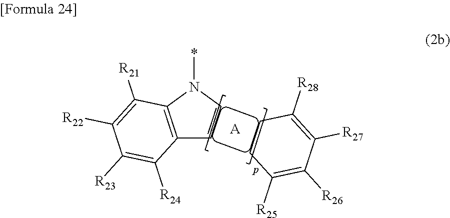

In the formula (2b):
at least one combination of adjacent two or more of R₂₁ to R₂₈ are mutually bonded to form a substituted or unsubstituted monocyclic ring, or mutually bonded to form a substituted or unsubstituted fused ring;
R₂₁ to R₂₈ forming neither the substituted or unsubstituted monocyclic ring nor the substituted or unsubstituted fused ring each independently represent the same as R₁ to R₈ in the formula (2a);
A represents a cyclic structure represented by a formula (211) or (212) below, and the cyclic structure A is fused with adjacent cyclic structure(s) at any position(s);
p is 1, 2, 3 or 4;
when p is 2, 3 or 4, a plurality of cyclic structures A are mutually the same or different; and
* represents a bonding position to a carbon atom in a six-membered ring in the formula (2).

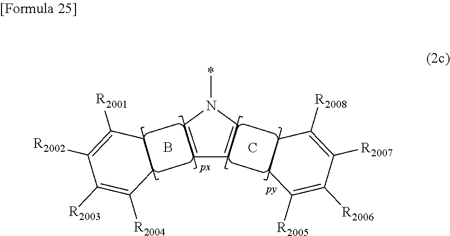

In the formula (2c):
at least one combination of adjacent two or more of R₂₀₀₁ to R₂₀₀₈ are mutually bonded to form a substituted or unsubstituted monocyclic ring, or mutually bonded to form a substituted or unsubstituted fused ring;
R₂₀₀₁ to R₂₀₀₈ forming neither the substituted or unsubstituted monocyclic ring nor the substituted or unsubstituted fused ring each independently represent the same as R₁ to R₈ as a substituent in the formula (2a);
B represents a cyclic structure represented by the formula (211) or (212), and the cyclic structure B is fused with adjacent cyclic structure(s) at any position(s);
px is 1, 2, 3 or 4;
when px is 2, 3 or 4, a plurality of cyclic structures B are mutually the same or different;
C represents a cyclic structure represented by the formula (211) or (212), and the cyclic structure C is fused with adjacent cyclic structure(s) at any position(s);
py is 1, 2, 3 or 4;
when py is 2, 3 or 4, a plurality of cyclic structures C are mutually the same or different; and
* represents a bonding position to a carbon atom in a six-membered ring in the formula (2).

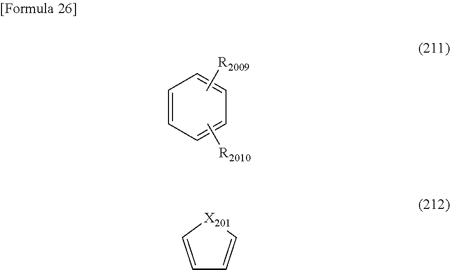

In the formula (211):
a combination of R₂₀₀₉ and R₂₀₁₀ are mutually bonded to form a substituted or unsubstituted monocyclic ring, mutually bonded to form a substituted or unsubstituted fused ring, or bonded to a part of an adjacent cyclic structure to form a ring.

In the formula (212): X₂₀₁ is CR₂₀₁₁R₂₀₁₂, NR₂₀₁₃, a sulfur atom, or an oxygen atom;
a combination of R₂₀₁₁ and R₂₀₁₂ are mutually bonded to form a substituted or unsubstituted monocyclic ring, or mutually bonded to form a substituted or unsubstituted fused ring; and
R₂₀₀₉, R₂₀₁₀, R₂₀₁₁, and R₂₀₁₂ forming neither the substituted or unsubstituted monocyclic ring nor the substituted or unsubstituted fused ring and R₂₀₁₃ each independently represent the same as R₁ to R₈ as a substituent in the formula (2a).

In the formula (211), R₂₀₀₉ and R₂₀₁₀ are each independently bonded to a part of an adjacent cyclic structure to form a ring, which specifically means any of (I) to (IV) below.

In the formula (211), a combination of R₂₀₀₉ and R₂₀₁₀ being mutually bonded to form a ring specifically refers to (V) below.
(I) When the cyclic structures represented by the formula (211) are adjacent to each other, between the two adjacent rings, at least one combination of the following are mutually bonded to form a ring: R₂₀₀₉ of one of the rings and R₂₀₀₉ of the other of the rings; R₂₀₀₉ of one of the rings and R₂₀₁₀ of the other of the rings; or R₂₀₁₀ of one of the rings and R₂₀₁₀ of the other of the rings.
(II) When the cyclic structure represented by the formula (211) and the benzene ring having R₂₅ to R₂₈ in the formula (2b) are adjacent to each other, between the two adjacent rings, at least one combination of the following are mutually bonded to form a ring: R₂₀₀₉ of one of the rings and R₂₅ of the other of the rings; R₂₀₀₉ of one of the rings and R₂₈ of the other of the rings; R₂₀₁₀ of one of the rings and R₂₅ of the other of the rings; or R₂₀₁₀ of one of the rings and R₂₈ of the other of the rings.
(III) When the cyclic structure represented by the formula (211) and the benzene ring having R₂₀₀₁ to R₂₀₀₄ in the formula (2c) are adjacent to each other, between the two adjacent rings, at least one combination of the following are mutually bonded to form a ring: R₂₀₀₉ of one of the rings and R₂₀₀₁ of the other of the rings; R₂₀₀₉ of one of the rings and R₂₀₀₄ of the other of the rings; R₂₀₁₀ of one of the rings and R₂₀₀₁ of the other of the rings; or R₂₀₁₀ of one of the rings and R₂₀₀₄ of the other of the rings.
(IV) When the cyclic structure represented by the formula (211) and the benzene ring having R₂₀₀₅ to R₂₀₀₈ in the formula (2c) are adjacent to each other, between the two adjacent rings, at least one combination of the following are mutually bonded to form a ring: R₂₀₀₉ of one of the rings and R₂₀₀₅ of the other of the rings; R₂₀₀₉ of one of the rings and R₂₀₀₈ of the other of the rings; R₂₀₁₀ of one of the rings and R₂₀₀₅ of the other of the rings; or R₂₀₁₀ of one of the rings and R₂₀₀₈ of the other of the rings.
(V) A combination of R₂₀₀₉ and R₂₀₁₀ in the cyclic structure represented by the formula (211) are mutually bonded to form a ring. In other words, (V) refers to a combination of R₂₀₀₉ and R₂₀₁₀ bonded to the same ring being mutually bonded to form a ring.

In the formula (2): Rx is preferably each independently a hydrogen atom, an unsubstituted aryl group having 6 to 30 ring carbon atoms, an unsubstituted heterocyclic group having 5 to 30 ring atoms, or an unsubstituted alkyl group having 1 to 30 carbon atoms.

When Rx is an unsubstituted heterocyclic group having 5 to 30 ring atoms, Rx as an unsubstituted heterocyclic group having 5 to 30 ring atoms is a pyridyl group, pyrimidinyl group, triazinyl group, dibenzofuranyl group, or dibenzothienyl group.

Herein, the triazinyl group refers to a group obtained by excluding one hydrogen atom from 1,3,5-triazine, 1,2,4-triazine, or 1,2,3-triazine.

The triazinyl group is preferably a group obtained by excluding one hydrogen atom from 1,3,5-triazine.

In the formula (2), Rx is more preferably each independently a hydrogen atom, an unsubstituted aryl group having 6 to 30 ring carbon atoms, an unsubstituted dibenzofuranyl group, or an unsubstituted dibenzothienyl group.

In the formula (2), Rx is still more preferably a hydrogen atom.

In the formula (2), R₁ to R₈, R₂₁ to R₂₈, R₂₀₀₁ to R₂₀₀₈, R₂₀₀₉ to R₂₀₁₀, and R₂₀₁₁ to R₂₀₁₃ as a substituent are preferably each independently an unsubstituted aryl group having 6 to 30 ring carbon atoms, an unsubstituted heterocyclic group having 5 to 30 ring atoms, or an unsubstituted alkyl group having 1 to 30 carbon atoms.

In the formula (2), D₁ is preferably a group represented by any one of formulae (D-21) to (D-37) below.

### Groups Represented by Formulae (D-21) to (D-25)

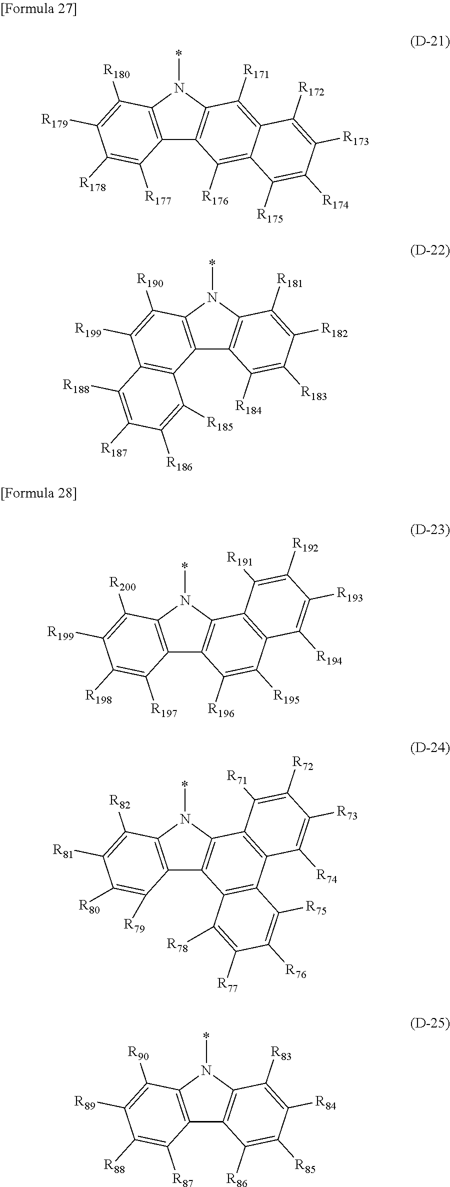

In the formulae (D-21) to (D-25):
at least one combination of adjacent two or more of R₁₇₁ to R₁₈₀ are mutually bonded to form a substituted or unsubstituted monocyclic ring, or mutually bonded to form a substituted or unsubstituted fused ring;
at least one combination of adjacent two or more of R₁₈₁ to R₁₉₀ are mutually bonded to form a substituted or unsubstituted monocyclic ring, or mutually bonded to form a substituted or unsubstituted fused ring;
at least one combination of adjacent two or more of R₁₉₁ to R₂₀₀ are mutually bonded to form a substituted or unsubstituted monocyclic ring, or mutually bonded to form a substituted or unsubstituted fused ring;
at least one combination of adjacent two or more of R₇₁ to R₈₂ are mutually bonded to form a substituted or unsubstituted monocyclic ring, or mutually bonded to form a substituted or unsubstituted fused ring;
at least one combination of adjacent two or more of R₈₃ to R₉₀ are mutually bonded to form a substituted or unsubstituted monocyclic ring, or mutually bonded to form a substituted or unsubstituted fused ring;
R₁₇₁ to R₂₀₀ and R₇₁ to R₉₀ forming and neither the substituted or unsubstituted monocyclic ring nor the substituted or unsubstituted fused ring are each independently a hydrogen atom, a halogen atom, a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted alkyl halide group having 1 to 30 carbon atoms, a substituted or unsubstituted cycloalkyl group having 3 to 30 ring carbon atoms, a substituted or unsubstituted alkylsilyl group having 3 to 6 carbon atoms, a hydroxy group, a substituted or unsubstituted alkoxy group having 1 to 6 carbon atoms, a substituted or unsubstituted alkoxy halide group having 1 to 6 carbon atoms, a substituted or unsubstituted aryloxy group having 6 to 14 ring carbon atoms, a substituted or unsubstituted alkylamino group having 2 to 12 carbon atoms, a thiol group, a substituted or unsubstituted alkylthio group having 1 to 6 carbon atoms, or a substituted or unsubstituted arylthio group having 6 to 14 ring carbon atoms; and
* represents a bonding position to a carbon atom in a six-membered ring in the formula (2).

In the formula (2), R₁₇₁ to R₂₀₀ and R₇₁ to R₉₀ as a substituent are preferably each independently an unsubstituted aryl group having 6 to 14 ring carbon atoms, an unsubstituted heterocyclic group having 5 to 14 ring atoms, or an unsubstituted alkyl group having 1 to 6 carbon atoms.

In the formula (2), R₁₇₁ to R₂₀₀ and R₇₁ to R₉₀ are also preferably each a hydrogen atom.

A group represented by each of the formulae (D-21) to (D-25) is preferably any one of groups represented by formulae (2-5) to (2-14) below.

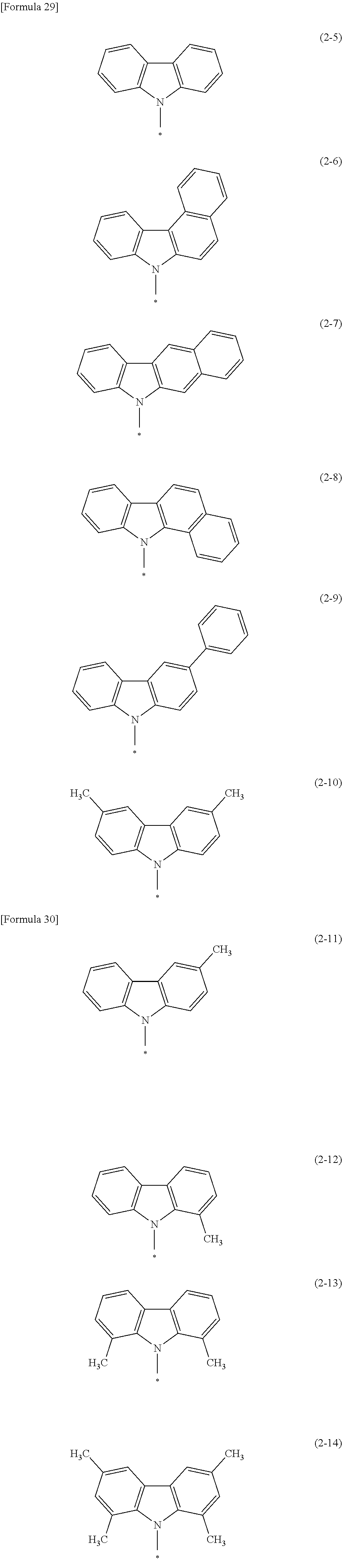

In the formulae (2-5) to (2-14), * represents a bonding position to a carbon atom in a six-membered ring in the formula (2).

### Groups Represented by Formulae (D-26) to (D-31)

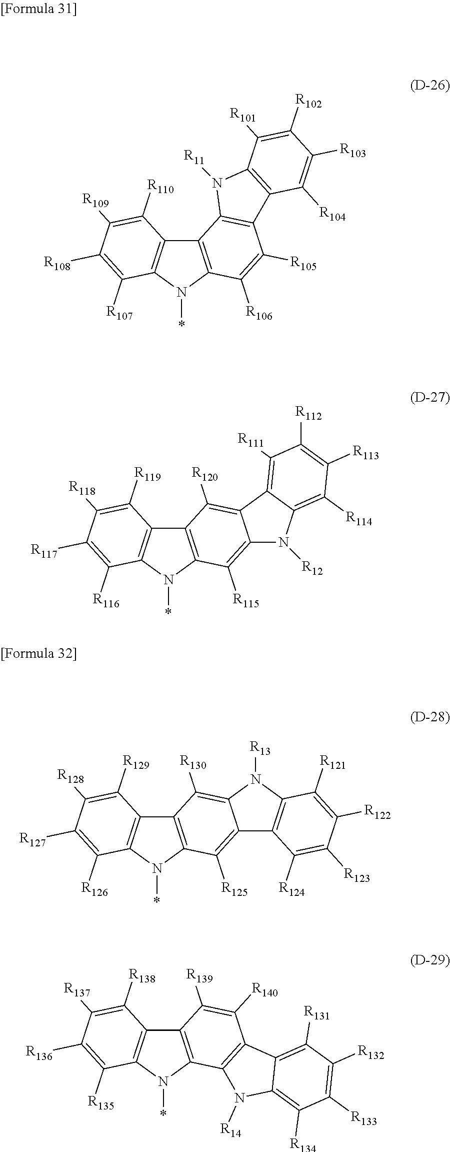

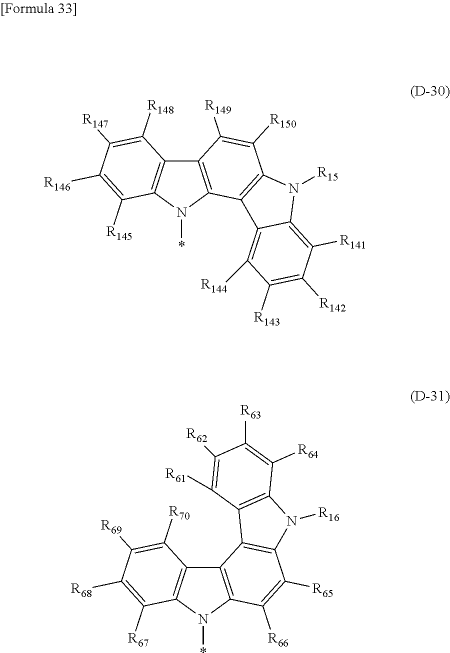

In the formulae (D-26) to (D-31):
at least one combination of adjacent two or more of R₁₀₁ to R₁₁₀ are mutually bonded to form a substituted or unsubstituted monocyclic ring, or mutually bonded to form a substituted or unsubstituted fused ring;
at least one combination of adjacent two or more of R₁₁₁ to R₁₂₀ are mutually bonded to form a substituted or unsubstituted monocyclic ring, or mutually bonded to form a substituted or unsubstituted fused ring;
at least one combination of adjacent two or more of R₁₂₁ to R₁₃₀ are mutually bonded to form a substituted or unsubstituted monocyclic ring, or mutually bonded to form a substituted or unsubstituted fused ring;
at least one combination of adjacent two or more of R₁₃₁ to R₁₄₀ are mutually bonded to form a substituted or unsubstituted monocyclic ring, or mutually bonded to form a substituted or unsubstituted fused ring;
at least one combination of adjacent two or more of R₁₄₁ to R₁₅₀ are mutually bonded to form a substituted or unsubstituted monocyclic ring, or mutually bonded to form a substituted or unsubstituted fused ring;
at least one combination of adjacent two or more of R₆₁ to R₇₀ are mutually bonded to form a substituted or unsubstituted monocyclic ring, or mutually bonded to form a substituted or unsubstituted fused ring;
R₁₀₁ to R₁₅₀ and R₆₁ to R₇₀ forming and neither the substituted or unsubstituted monocyclic ring nor the substituted or unsubstituted fused ring, and R₁₁ to R₁₆ are each independently a hydrogen atom, a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted alkyl halide group having 1 to 30 carbon atoms, a substituted or unsubstituted cycloalkyl group having 3 to 30 ring carbon atoms, a substituted or unsubstituted alkylsilyl group having 3 to 6 carbon atoms, a hydroxy group, a substituted or unsubstituted alkoxy group having 1 to 6 carbon atoms, a substituted or unsubstituted aryloxy group having 6 to 14 ring carbon atoms, a substituted or unsubstituted arylamino group having 6 to 28 ring carbon atoms, a substituted or unsubstituted alkylamino group having 2 to 12 carbon atoms, a thiol group, a substituted or unsubstituted alkylthio group having 1 to 6 carbon atoms, or a substituted or unsubstituted arylthio group having 6 to 14 ring carbon atoms;
R₁₁ to R₁₆ as a substituent are each independently a substituted or unsubstituted alkyl group having 1 to 6 carbon atoms, a substituted or unsubstituted aryl group having 6 to 14 ring carbon atoms, a substituted or unsubstituted heterocyclic group having 5 to 14 ring atoms, a substituted or unsubstituted alkylsilyl group having 3 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms; and
* represents a bonding position to a carbon atom in a six-membered ring in the formula (2).

In the formula (2): R₁₀₁ to R₁₅₀ and R₆₁ to R₇₀ as a substituent are preferably each independently an unsubstituted aryl group having 6 to 14 ring carbon atoms, an unsubstituted heterocyclic group having 5 to 14 ring atoms, or an unsubstituted alkyl group having 1 to 6 carbon atoms; and R₁₁ to R₁₆ as a substituent are preferably each independently an unsubstituted aryl group having 6 to 14 ring carbon atoms or an unsubstituted heterocyclic group having 5 to 14 ring atoms.

In the formula (2), also preferably, R₁₀₁ to R₁₅₀ and R₆₁ to R₇₀ are each a hydrogen atom, and R₁₁ to R₁₆ as a substituent are each independently an unsubstituted aryl group having 6 to 14 ring carbon atoms or an unsubstituted heterocyclic group having 5 to 14 ring atoms.

### Groups Represented by Formulae (D-32) to (D-37)

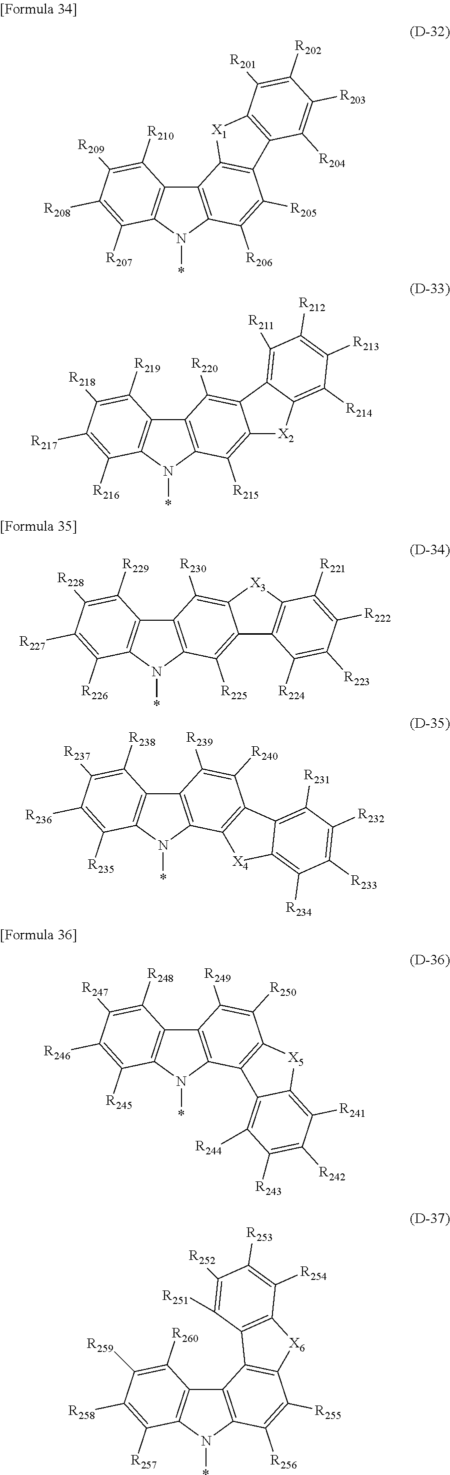

In the formulae (D-32) to (D-37):
X₁ to X₆ are each independently an oxygen atom, a sulfur atom, or CR₁₅₁R₁₅₂;
a combination of R₁₅₁ and R₁₅₂ are mutually bonded to form a substituted or unsubstituted monocyclic ring, or mutually bonded to form a substituted or unsubstituted fused ring;
at least one combination of adjacent two or more of R₂₀₁ to R₂₁₀ are mutually bonded to form a substituted or unsubstituted monocyclic ring, or mutually bonded to form a substituted or unsubstituted fused ring;
at least one combination of adjacent two or more of R₂₁₁ to R₂₂₀ are mutually bonded to form a substituted or unsubstituted monocyclic ring, or mutually bonded to form a substituted or unsubstituted fused ring;
at least one combination of adjacent two or more of R₂₂₁ to R₂₃₀ are mutually bonded to form a substituted or unsubstituted monocyclic ring, or mutually bonded to form a substituted or unsubstituted fused ring;
at least one combination of adjacent two or more of R₂₃₁ to R₂₄₀ are mutually bonded to form a substituted or unsubstituted monocyclic ring, or mutually bonded to form a substituted or unsubstituted fused ring;
at least one combination of adjacent two or more of R₂₄₁ to R₂₅₀ are mutually bonded to form a substituted or unsubstituted monocyclic ring, or mutually bonded to form a substituted or unsubstituted fused ring;
at least one combination of adjacent two or more of R₂₅₁ to R₂₆₀ are mutually bonded to form a substituted or unsubstituted monocyclic ring, or mutually bonded to form a substituted or unsubstituted fused ring;
R₁₅₁, R₁₅₂ and R₂₀₁ to R₂₆₀ forming neither the substituted or unsubstituted monocyclic ring nor the substituted or unsubstituted fused ring are each independently a hydrogen atom, a halogen atom, a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted alkyl halide group having 1 to 6 carbon atoms, a substituted or unsubstituted cycloalkyl group having 3 to 30 ring carbon atoms, a substituted or unsubstituted alkylsilyl group having 3 to 6 carbon atoms, a hydroxy group, a substituted or unsubstituted alkoxy group having 1 to 6 carbon atoms, a substituted or unsubstituted alkoxy halide group having 1 to 6 carbon atoms, a substituted or unsubstituted aryloxy group having 6 to 14 ring carbon atoms, a substituted or unsubstituted arylamino group having 6 to 28 ring carbon atoms, a substituted or unsubstituted alkylamino group having 2 to 12 carbon atoms, a thiol group, a substituted or unsubstituted alkylthio group having 1 to 6 carbon atoms, or a substituted or unsubstituted arylthio group having 6 to 14 ring carbon atoms; and
* represents a bonding position to a carbon atom in a six-membered ring in the formula (2).

In the formula (2): R₂₀₁ to R₂₆₀ as a substituent are preferably each independently a halogen atom, an unsubstituted aryl group having 6 to 14 ring carbon atoms, an unsubstituted heterocyclic group having 5 to 14 ring atoms, or an unsubstituted alkyl group having 1 to 6 carbon atoms; and
R₁₅₁ and R₁₅₂ as a substituent are preferably each independently an unsubstituted aryl group having 6 to 14 ring carbon atoms or an unsubstituted alkyl group having 1 to 6 carbon atoms.

In the compound M2: R₂₀₁ to R₂₆₀ as a substituent are more preferably each independently an unsubstituted aryl group having 6 to 14 ring carbon atoms, an unsubstituted heterocyclic group having 5 to 14 ring atoms, or an unsubstituted alkyl group having 1 to 6 carbon atoms; and
R₁₅₁ and R₁₅₂ as a substituent are more preferably each independently an unsubstituted aryl group having 6 to 14 ring carbon atoms or an unsubstituted alkyl group having 1 to 6 carbon atoms.

In the formula (2):
R₂₀₁ to R₂₆₀ are also preferably each a hydrogen atom; and
R₁₅₁ and R₁₅₂ as a substituent are also preferably each independently an unsubstituted aryl group having 6 to 14 ring carbon atoms, or an unsubstituted alkyl group having 1 to 6 carbon atoms.

### Compound Represented by Formula (22)

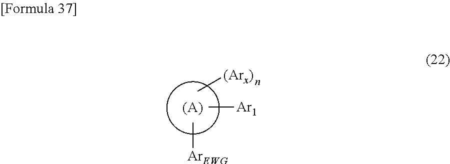

In the formula (22): Ar₁ is a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, a carboxy group, and groups represented by formulae (1a) to (1j) below;
Ar_{EWG} is a substituted or unsubstituted heteroaryl group having 5 to 30 ring atoms that includes at least one nitrogen atom in a ring, or an aryl group having 6 to 30 ring carbon atoms that is substituted by at least one cyano group;
Ar_{X} is each independently a hydrogen atom or a substituent, and Ar_{X} as a substituent is a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, a carboxy group, and groups represented by the formulae (1a) to (1j);
n is 0, 1, 2, 3, 4 or 5, and when n is 2, 3, 4 or 5, a plurality of Ar_{X} are mutually the same or different;
a ring (A) is a substituted or unsubstituted aromatic hydrocarbon ring or a substituted or unsubstituted heterocycle, the ring (A) being a five-membered ring, a six-membered ring, or a seven-membered ring, Ar_{EWG}, Ar₁ and Ar_{X} being bonded to respective ones of elements forming the ring (A); and
at least one of Ar₁ or Ar_{X} is any group selected from the group consisting of groups represented by the formulae (1a) to (1j) below.

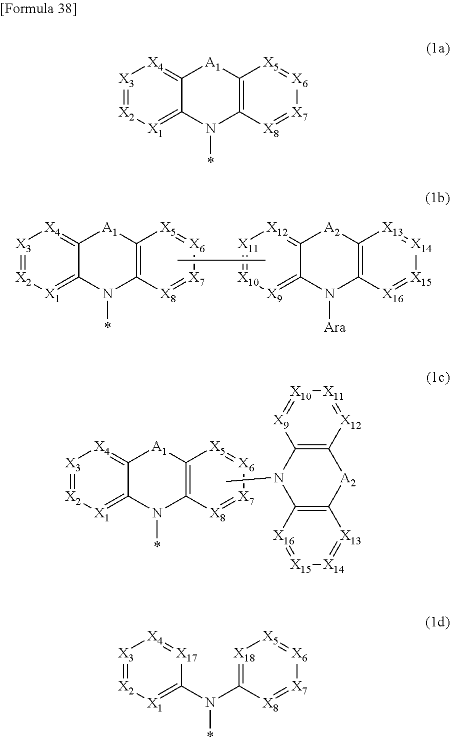

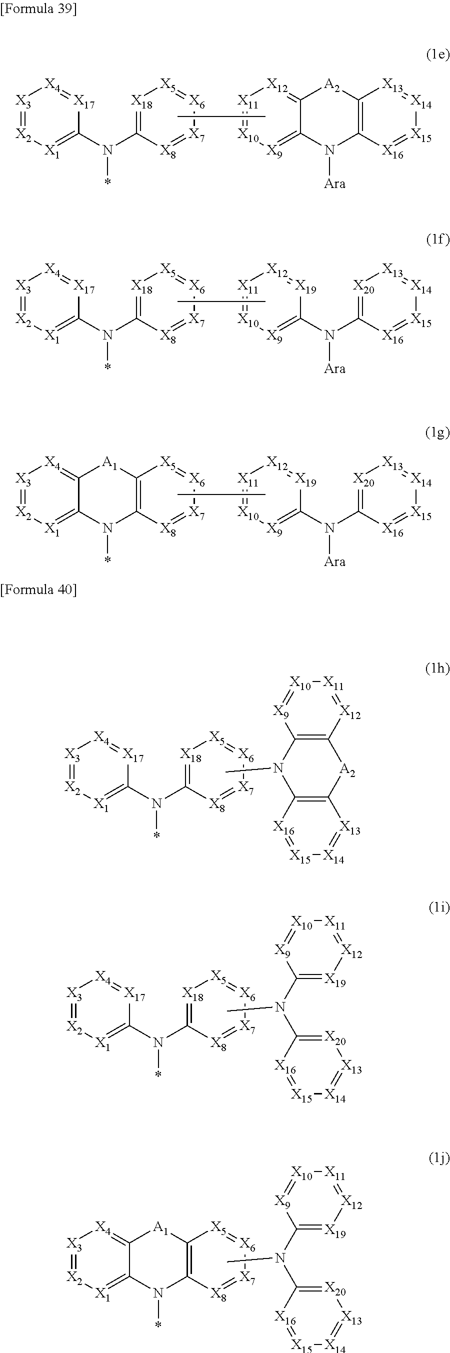

In the formulae (1a) to (1j): X₁ to X₂₀ are each independently a nitrogen atom (N) or a carbon atom bonded with R_{A1} (C—R_{A1});
in the formula (1b): one of X₅ to X₈ is a carbon atom bonded to one of X₉ to X₁₂, and one of X₉ to X₁₂ is a carbon atom bonded to one of X₅ to X₈;
in the formula (1c): one of X₅ to X₈ is a carbon atom bonded to a nitrogen atom in a ring including A₂;
in the formula (1e): one of X₅ to X₈ and X₁₈ is a carbon atom bonded to one of X₉ to X₁₂, and one of X₉ to X₁₂ is a carbon atom bonded to one of X₅ to X₈ and X₁₈;
in the formula (1f): one of X₅ to X₈ and X₁₈ is a carbon atom bonded to one of X₉ to X₁₂ and X₁₉, and one of X₉ to X₁₂ and X₁₉ is a carbon atom bonded to one of X₅ to X₈ and X₁₈;
in the formula (1g): one of X₅ to X₈ is a carbon atom bonded to one of X₉ to X₁₂ and X₁₉, and one of X₉ to X₁₂ and X₁₉ is a carbon atom bonded to one of X₅ to X₈;
in the formula (1h): one of X₅ to X₈ and X₁₈ is a carbon atom bonded to a nitrogen atom in a ring including A2;
in the formula (1i): one of X₅ to X₈ and X₁₈ is a carbon atom bonded to a nitrogen atom that links a ring including X₉ to X₁₂ and X₁₉ with a ring including X₁₃ to X₁₆ and X₂₀;
in the formula (1j): one of X₅ to X₈ is a carbon atom bonded to a nitrogen atom that links a ring including X₉ to X₁₂ and X₁₉ with a ring including X₁₃ to X₁₆ and X₂₀;
at least one combination of adjacent two or more of a plurality of R_{A1} are mutually bonded to form a substituted or unsubstituted monocyclic ring, or mutually bonded to form a substituted or unsubstituted fused ring; and
R_{A1} forming neither the substituted or unsubstituted monocyclic ring nor the substituted or unsubstituted fused ring are each independently a group selected from the group consisting of a hydrogen atom, a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;
a plurality of R_{A1} are mutually the same or different;
in the formulae (1a) to (1j), * represents a bonding position to the ring (A);
in the formulae (1a) to (1j): A₁ and A₂ are each independently a single bond, an oxygen atom (O), a sulfur atom (S), C(R₂₀₂₁)(R₂₀₂₂), Si(R₂₀₂₃)(R₂₀₂₄), C(═O), S(═O), SO₂ or N(R₂₀₂₅); R₂₀₂₁ to R₂₀₂₅ are each independently a hydrogen atom or a substituent, and R₂₀₂₁ to R₂₀₂₅ as a substituent are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group; and
in the formulae (1a) to (1j): Ara is a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, and a substituted silyl group.

In the formula (1a), when X₁ to X₈ are each a carbon atom bonded with R_{A1} (C—R_{A1}), a plurality of R_{A1} preferably form no ring.

Ara is preferably a substituted or unsubstituted aryl group having 6 to 30 ring carbon atoms or a substituted or unsubstituted heterocyclic group having 5 to 30 ring atoms.

The formula (1a) is represented by a formula (1aa) when A₁ is a single bond, by a formula (lab) when A₁ is O, by a formula (lac) when A₁ is S, by a formula (lad) when A₁ is C(R₂₀₂₁)(R₂₀₂₂), by a formula (1ae) when A₁ is Si(R₂₀₂₃)(R₂₀₂₄), by a formula (1af) when A₁ is C(═O), by a formula (lag) when A₁ is S(═O), by a formula (1ah) when A₁ is SO₂, and by a formula (1ai) when A₁ is N(R₂₀₂₅). In the formulae (1aa) to (1ai), X₁ to X₈ and R₂₀₂₁ to R₂₀₂₅ represent the same as described above. Linkages between rings via A₁ and A₂ in the formulae (1b), (1c), (1e) and (1g) to (1j) are the same as those in the formulae (1aa) to (1ai). In the formula (1aa), when X₁ to X₈ are each a carbon atom bonded with R_{A1} (C—R_{A1}), a plurality of R_{A1} as a substituent preferably form no ring.

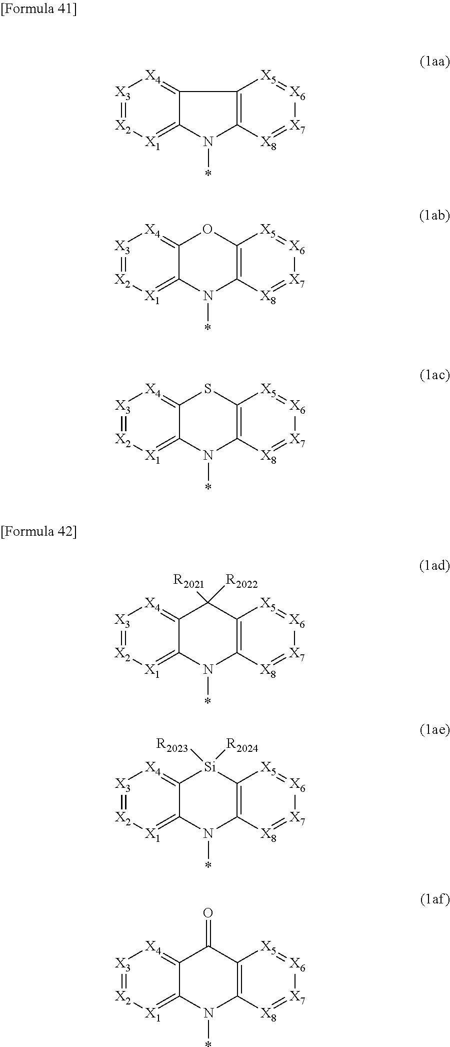

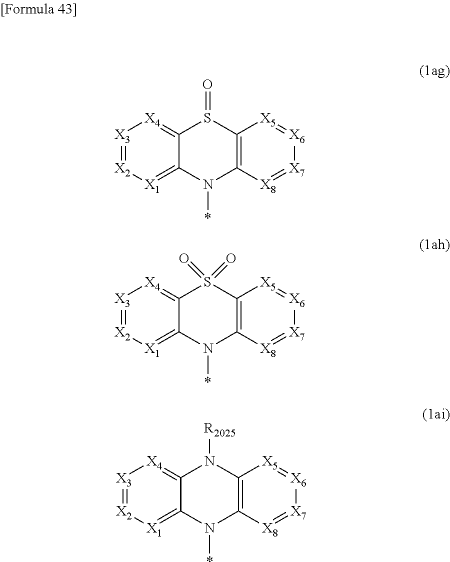

The first sensitizing material of the exemplary embodiment is also preferably represented by a formula (221) below.

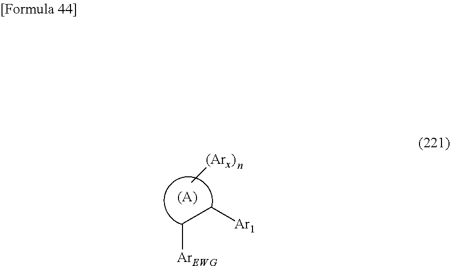

Ar₁, Ar_{EWG}, Ar_{X}, n and a ring (A) in the formula (221) respectively represent the same as Ar₁, Ar_{EWG}, Ar_{X}, n and the ring (A) in the formula (22).

In an exemplary arrangement of the exemplary embodiment, the first sensitizing material is a compound represented by a formula (222) below.

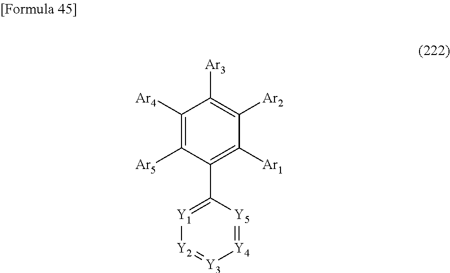

In the formula (222):
Y₁ to Y₅ are each independently a nitrogen atom (N), a carbon atom bonded with a cyano group (C—CN), or a carbon atom bonded with R_{A2} (C—R_{A2}), and at least one of Y₁ to Y₅ is N or C—CN; a plurality of R_{A2} are mutually the same or different;
at least one combination of adjacent two or more of a plurality of R_{A2} are mutually bonded to form a substituted or unsubstituted monocyclic ring, or mutually bonded to form a substituted or unsubstituted fused ring;
R_{A2} forming neither the substituted or unsubstituted monocyclic ring nor the substituted or unsubstituted fused ring are each independently a group selected from the group consisting of a hydrogen atom, a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group; and
a plurality of R_{A2} are mutually the same or different.

In the formula (222), Ar₁ represents the same as Ar₁ in the formula (22).

In the formula (222), Ar₂ to Ar₅ are each independently a hydrogen atom or a substituent, and Ar₂ to Ar₅ as a substituent are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, a carboxy group, and groups represented by the formulae (1a) to (1c).

In the formula (222), when one or more of Ar₂ to Ar₅ are each a hydrogen atom, it is preferable that all of the hydrogen atom(s) are protium atoms, at least one of the hydrogen atom(s) is a deuterium atom, or all of the hydrogen atom(s) are deuterium atoms.

In the formula (222), when one or more of Ar₂ to Ar₅ are each a substituent and the substituent has one or more hydrogen atoms, it is preferable that all of the hydrogen atom(s) are protium atoms, at least one of the hydrogen atom(s) is a deuterium atom, or all of the hydrogen atom(s) are deuterium atoms.

In the formula (222), at least one of Ar₁ to Ar₅ is a group selected from the group consisting of groups represented by the formulae (1a) to (1c).

In an exemplary arrangement of the exemplary embodiment, the first sensitizing material is a compound represented by a formula (11aa), (11bb) or (11cc) below.

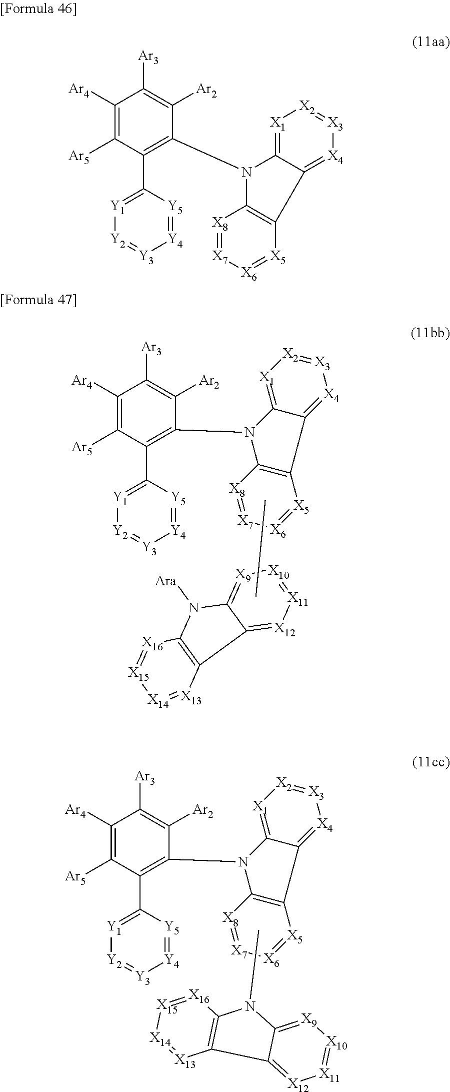

In the formulae (11aa), (11bb) and (11cc), Y₁ to Y₅, R_{A2}, Ar₂ to Ar₅, X₁ to X₁₆, R_{A1} and Ara respectively represent the same as the above-described Y₁ to Y₅, R_{A2}, Ar₂ to Ar₅, X₁ to X₁₆, R_{A1} and Ara.

In an exemplary arrangement of the exemplary embodiment, the first sensitizing material is, for instance, a compound represented by a formula (23) below.

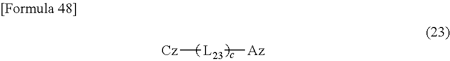

In the formula (23):
Az is a cyclic structure selected from the group consisting of a substituted or unsubstituted pyridine ring, a substituted or unsubstituted pyrimidine ring, a substituted or unsubstituted triazine ring, and a substituted or unsubstituted pyrazine ring,
c is 0, 1, 2, 3, 4 or 5;
when c is 0, Cz and Az are bonded by a single bond;
when c is 1, 2, 3, 4 or 5, L₂₃ is a linking group selected from the group consisting of a substituted or unsubstituted arylene group having 6 to 30 ring carbon atoms, and a substituted or unsubstituted heteroarylene group having 5 to 30 ring atoms;
when c is 2, 3, 4, or 5, a plurality of L₂₃ are mutually the same or different;
the plurality of L₂₃ are mutually bonded to form a ring or not bonded; and
Cz is represented by a formula (23a) below.

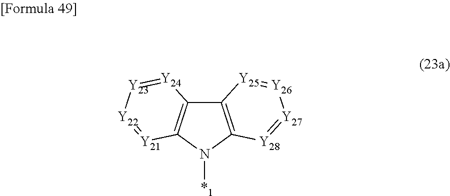

In the formula (23a):
Y₂₁ to Y₂₈ are each independently a nitrogen atom or CR_{A3};
at least one combination of adjacent two or more of a plurality of R_{A3} are mutually bonded to form a substituted or unsubstituted monocyclic ring, or mutually bonded to form a substituted or unsubstituted fused ring;
R_{A3} forming neither the substituted or unsubstituted monocyclic ring nor the substituted or unsubstituted fused ring are each independently a group selected from the group consisting of a hydrogen atom, a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;
a plurality of R_{A3} are mutually the same or different; and
*1 represents a bonding position to a carbon atom in a structure of a linking group represented by L₂₃, or a bonding position to a carbon atom in a cyclic structure represented by Az.
Y₂₁ to Y₂₈ are also preferably CR_{A3}.

In the formula (23), c is preferably 0 or 1.
Cz is also preferably represented by a formula (23b), (23c) or (23d) below.

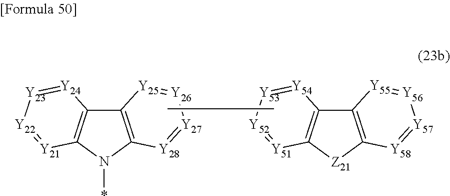

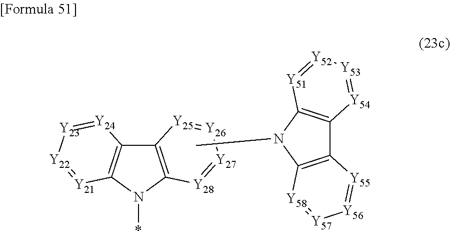

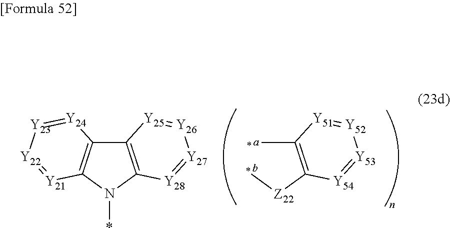

In the formulae (23b), (23c) and (23d), Y₂₁ to Y₂₈ and Y₅₁ to Y₅₈ are each independently a nitrogen atom or CR_{A4}.

In the formula (23b), at least one of Y₂₅ to Y₂₈ is a carbon atom bonded to one of Y₅₁ to Y₅₄, and at least one of Y₅₁ to Y₅₄ is a carbon atom bonded to one of Y₂₅ to Y₂₈.

In the formula (23c), at least one of Y₂₅ to Y₂₈ is a carbon atom bonded to a nitrogen atom in a five-membered ring of a nitrogen-containing fused ring including Y₅₁ to Y₅₈.

In the formula (23d): *a and *b each represent a bonding position to one of Y₂₁ to Y₂₈, at least one of Y₂₅ to Y₂₈ is the bonding position represented by *a, and at least one of Y₂₅ to Y₂₈ is the bonding position represented by *b;
n is 1, 2, 3 or 4;
at least one combination of adjacent two or more of a plurality of R_{A4} are mutually bonded to form a substituted or unsubstituted monocyclic ring, or mutually bonded to form a substituted or unsubstituted fused ring;
R_{A4} forming neither the substituted or unsubstituted monocyclic ring nor the substituted or unsubstituted fused ring are each independently a substituent selected from the group consisting of a hydrogen atom, a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;
a plurality of R_{A4} are mutually the same or different; and
Z₂₁ and Z₂₁ are each independently any one selected from the group consisting of an oxygen atom, a sulfur atom, NR₄₅ and CR₄₆R₄₇;
a combination of R₄₆ and R₄₇ are mutually bonded to form a substituted or unsubstituted monocyclic ring, or mutually bonded to form a substituted or unsubstituted fused ring;
R₄₆ and R₄₇ forming neither the substituted or unsubstituted monocyclic ring nor the substituted or unsubstituted fused ring, and R₄₅ are each independently a substituent selected from the group consisting of a hydrogen atom, a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;
a plurality of R₄₅ are mutually the same or different;
a plurality of R₄₆ are mutually the same or different;
a plurality of R₄₇ are mutually the same or different; and
* represents a bonding position to a carbon atom in a cyclic structure represented by Az.
Z₂₁ is preferably NR₄₅.

When Z₂₁ is NR₄₅, R₄₅ is preferably a substituted or unsubstituted aryl group having 6 to 30 ring carbon atoms.
Z₂₂ is preferably NR₄₅.

When Z₂₂ is NR₄₅, R₄₅ is preferably a substituted or unsubstituted aryl group having 6 to 30 ring carbon atoms.
Y₅₁ to Y₅₈ are preferably CR_{A4}, provided that at least one of Y₅₁ to Y₅₈ is a carbon atom bonded to a cyclic structure represented by the formula (23a).

It is also preferable that Cz is represented by the formula (23d) and n is 1.

Az is preferably a cyclic structure selected from the group consisting of a substituted or unsubstituted pyrimidine group and a substituted or unsubstituted triazine group.

Az is a cyclic structure selected from the group consisting of a substituted pyrimidine ring and a substituted triazine ring, in which a substituent for each of the substituted pyrimidine ring and the substituted triazine ring is more preferably a group selected from the group consisting of a substituted or unsubstituted aryl group having 6 to 30 ring carbon atoms and a substituted or unsubstituted heteroaryl group having 5 to 30 ring atoms, still more preferably a substituted or unsubstituted aryl group having 6 to 30 ring carbon atoms.

When a pyrimidine ring and a triazine ring as Az have a substituted or unsubstituted aryl group as a substituent, the aryl group preferably has 6 to 20 ring carbon atoms, more preferably 6 to 14 ring carbon atoms, still more preferably 6 to 12 ring carbon atoms.

When Az has a substituted or unsubstituted aryl group as a substituent, the substituent is preferably a substituent selected from the group consisting of a substituted or unsubstituted phenyl group, a substituted or unsubstituted biphenyl group, a substituted or unsubstituted naphthyl group, a substituted or unsubstituted phenanthryl group, a substituted or unsubstituted terphenyl group, and a substituted or unsubstituted fluorenyl group, more preferably a substituent selected from the group consisting of a substituted or unsubstituted phenyl group, a substituted or unsubstituted biphenyl group, and a substituted or unsubstituted naphthyl group.

When Az has a substituted or unsubstituted heteroaryl group as a substituent, the substituent is preferably a substituent selected from the group consisting of a substituted or unsubstituted carbazolyl group, a substituted or unsubstituted dibenzofuranyl group, and a substituted or unsubstituted dibenzothiophenyl group.

It is preferable that R_{A4} is each independently a hydrogen atom or a substituent, and R_{A4} as a substituent is a substituent selected from the group consisting of a substituted or unsubstituted aryl group having 6 to 30 ring carbon atoms and a substituted or unsubstituted heteroaryl group having 5 to 30 ring atoms.

When R_{A4} as a substituent is a substituted or unsubstituted aryl group having 6 to 30 ring carbon atoms, R_{A4} as a substituent is preferably a substituent selected from the group consisting of a substituted or unsubstituted phenyl group, a substituted or unsubstituted biphenyl group, a substituted or unsubstituted naphthyl group, a substituted or unsubstituted phenanthryl group, a substituted or unsubstituted terphenyl group, and a substituted or unsubstituted fluorenyl group, more preferably a substituent selected from the group consisting of a substituted or unsubstituted phenyl group, a substituted or unsubstituted biphenyl group, and a substituted or unsubstituted naphthyl group.

When R_{A4} as a substituent is a substituted or unsubstituted heteroaryl group having 5 to 30 ring atoms, R_{A4} as a substituent is preferably a substituent selected from the group consisting of a substituted or unsubstituted carbazolyl group, a substituted or unsubstituted dibenzofuranyl group, and a substituted or unsubstituted dibenzothiophenyl group.

R₄₅, R₄₆ and R₄₇ as a substituent are preferably each independently a substituent selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

### Production Method of First Sensitizing Material

The first sensitizing material is producible by a known method.

Specific examples of the first sensitizing material (a compound represented by the formula (2) or (22)) include compounds below. It should however be noted that the first sensitizing material is not limited to the specific examples of these compounds.

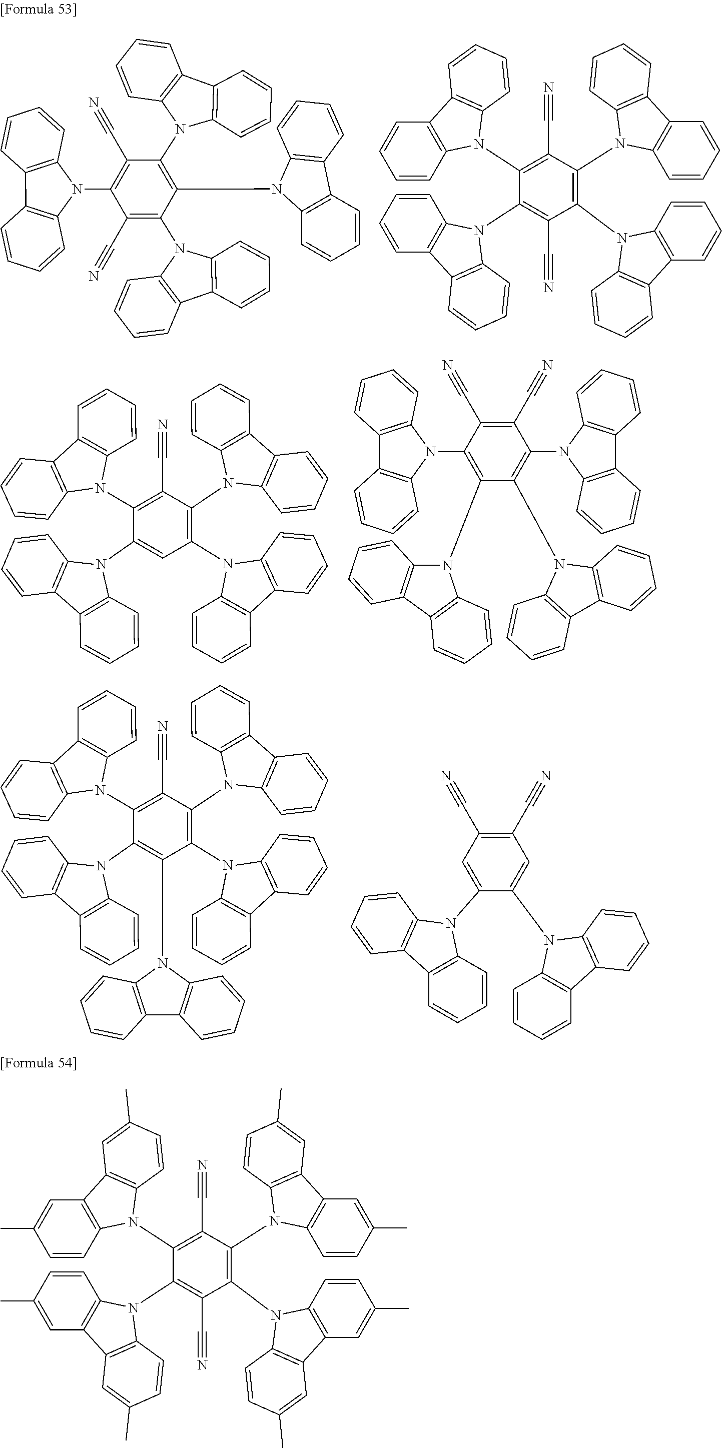

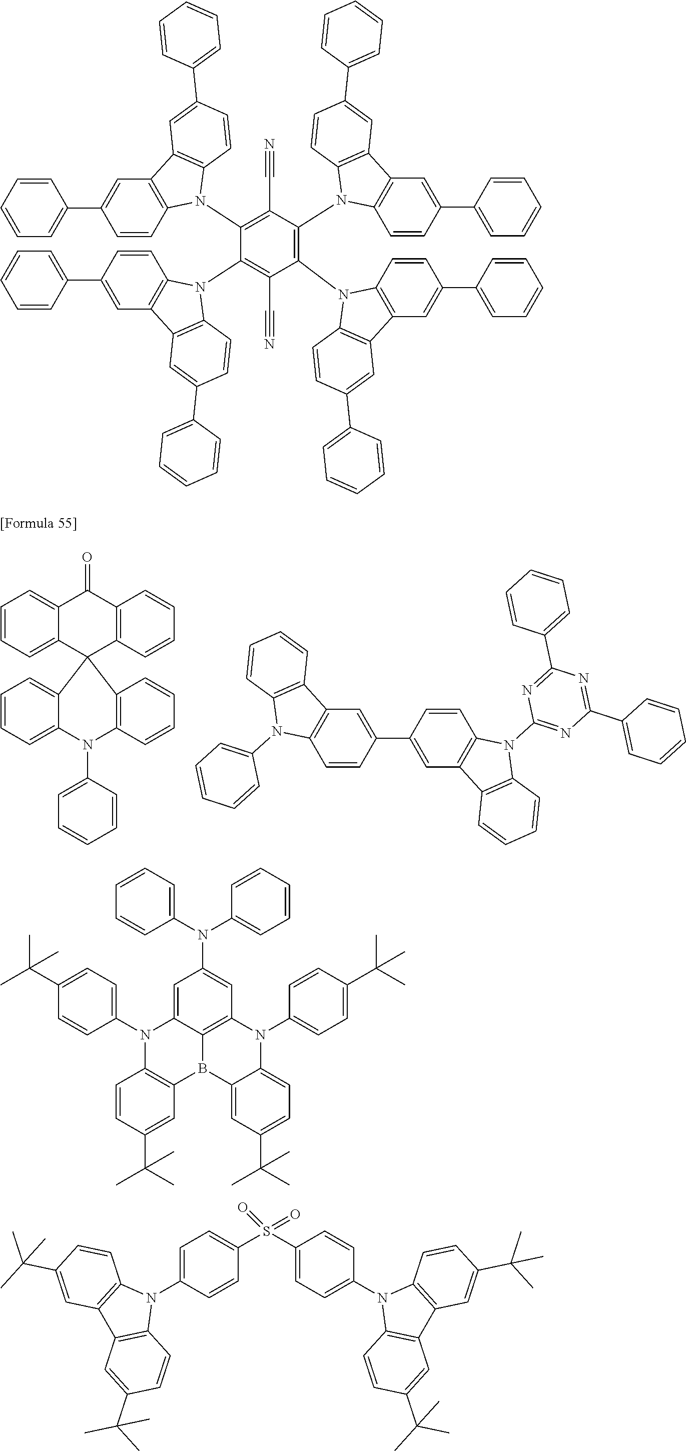

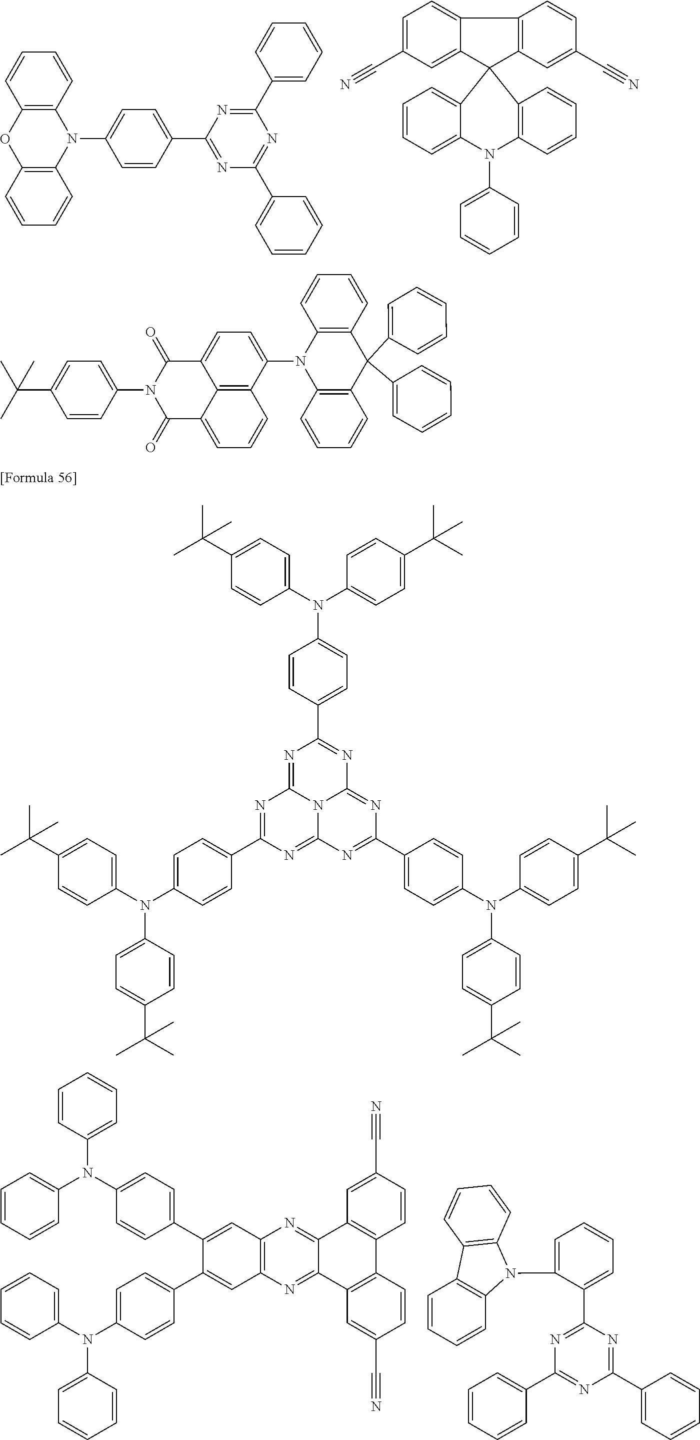

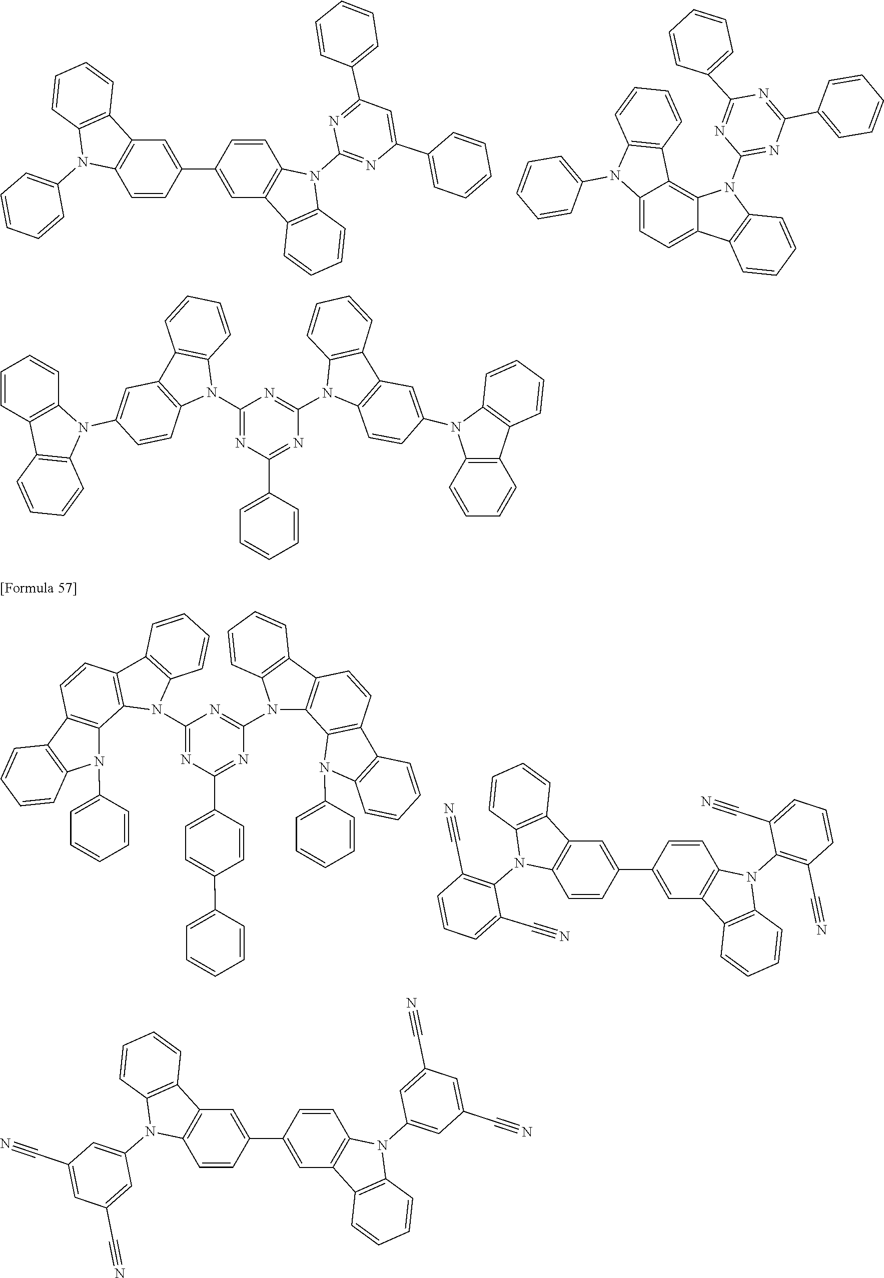

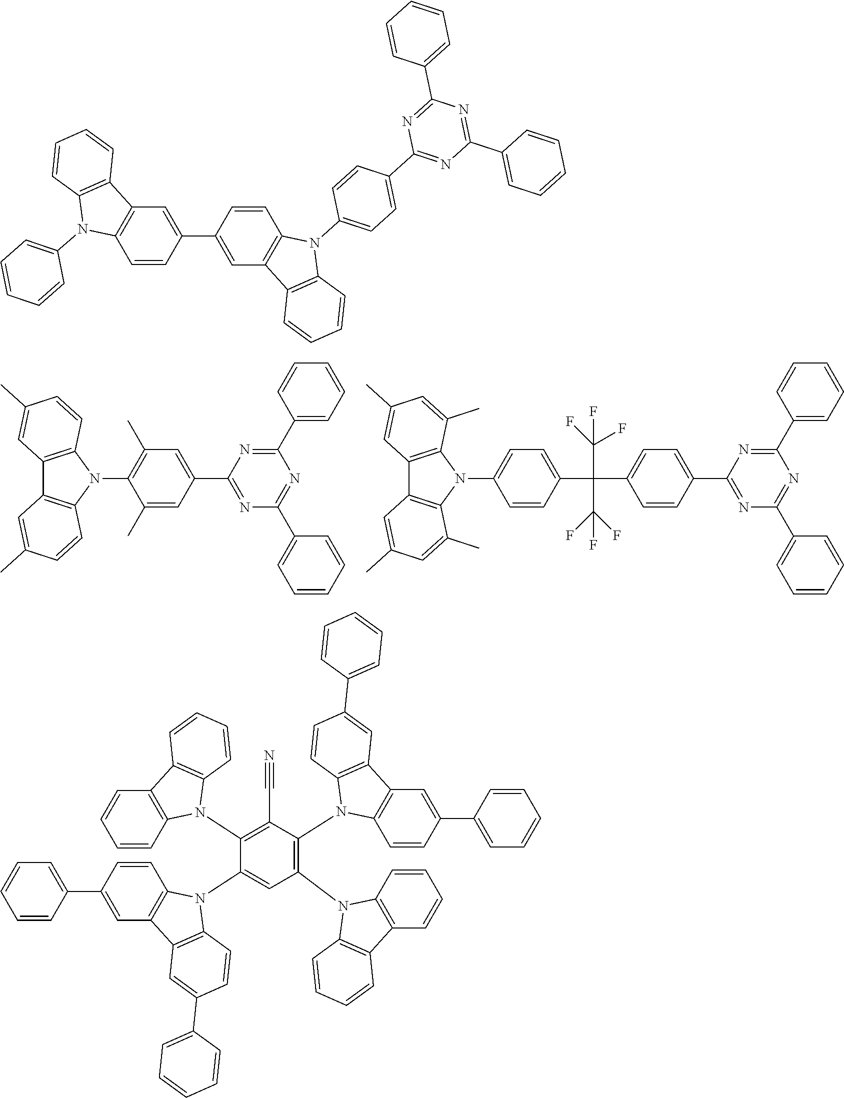

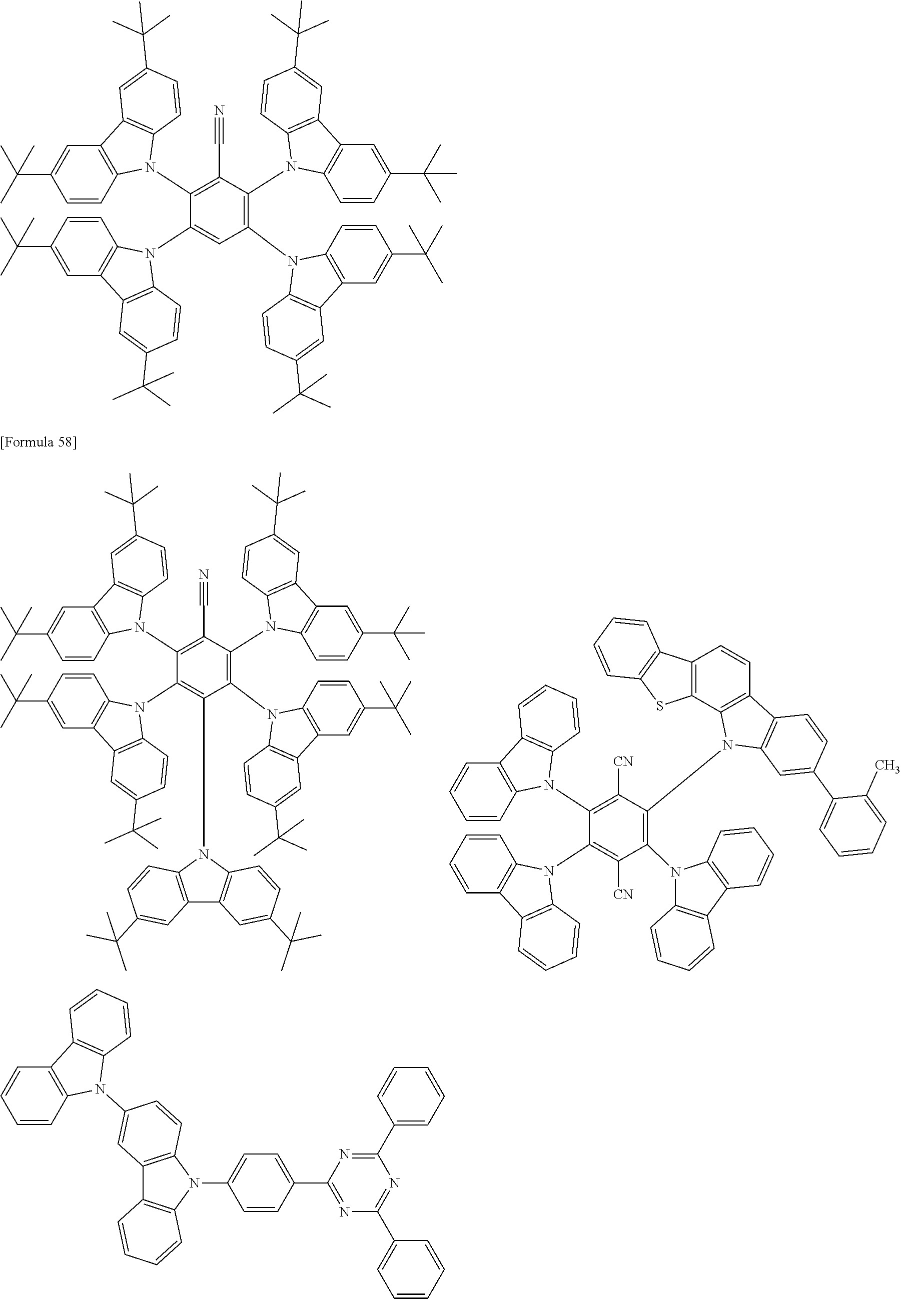

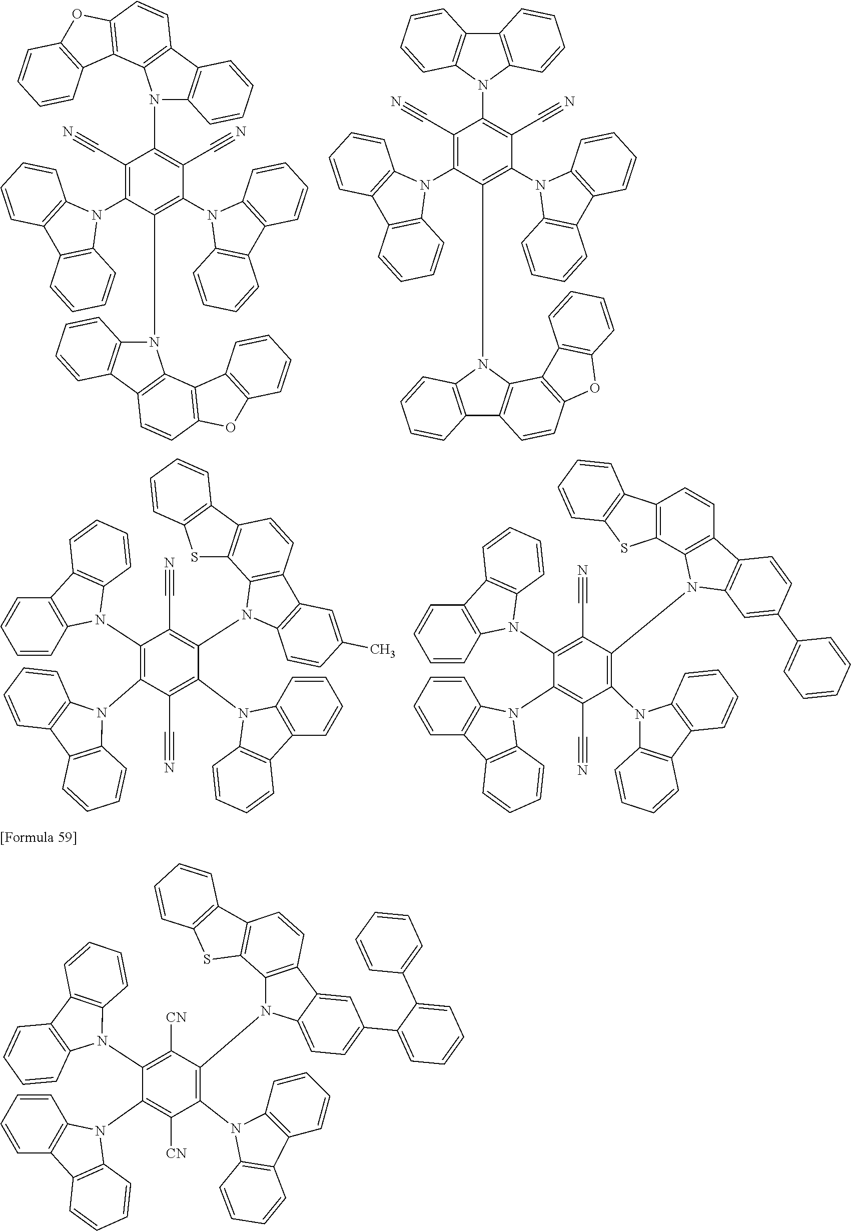

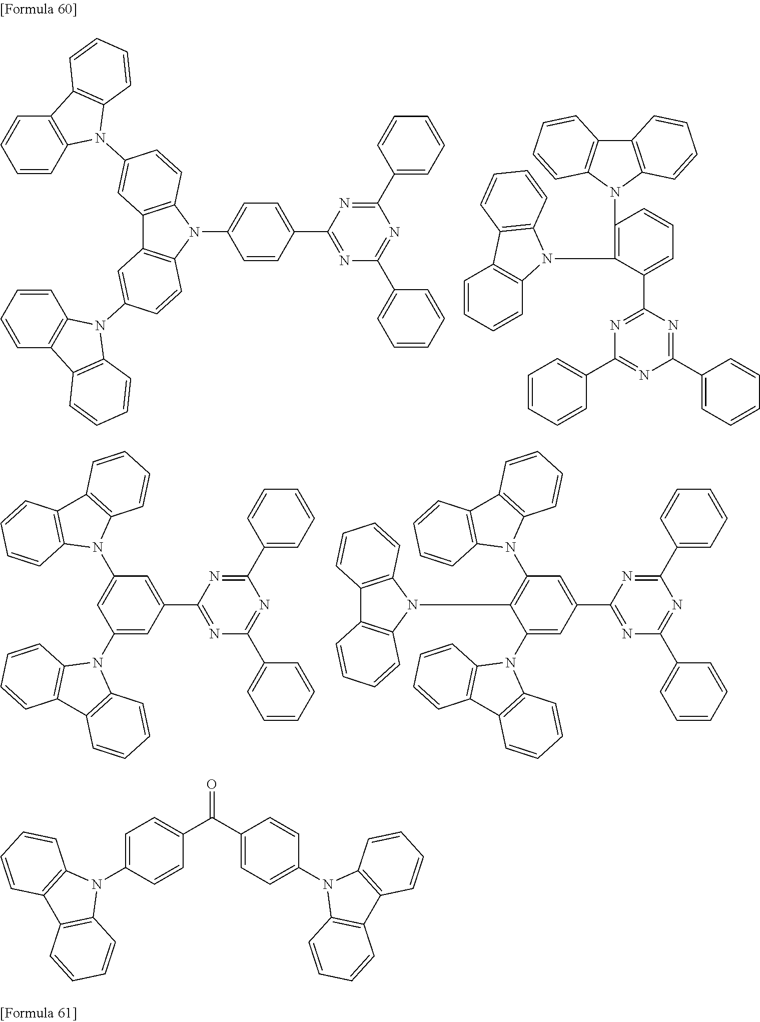

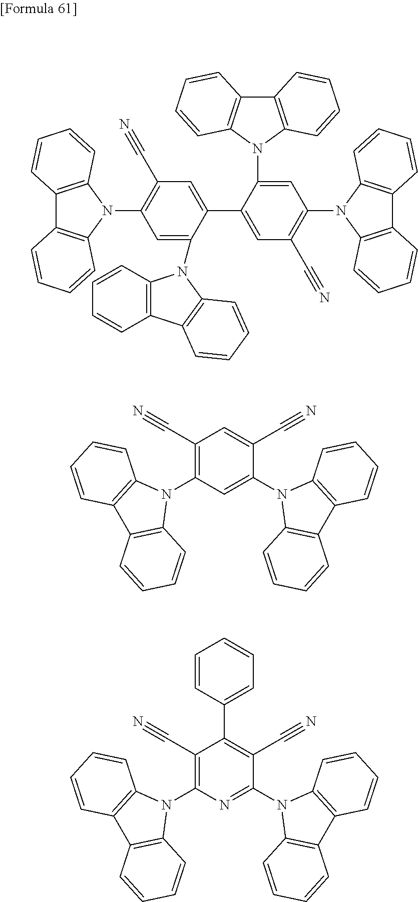 [SMILES: N#Cc1cc(-c2cc(C#N)c(-n3c4ccccc4c4ccccc43)cc2-n2c3ccccc3c3ccccc32)c(-n2c3ccccc3c3ccccc32)cc1-n1c2ccccc2c2ccccc21 ; N#Cc1cc(C#N)c(-n2c3ccccc3c3ccccc32)cc1-n1c2ccccc2c2ccccc21 ; N#Cc1c(-n2c3ccccc3c3ccccc32)nc(-n2c3ccccc3c3ccccc32)c(C#N)c1-c1ccccc1]

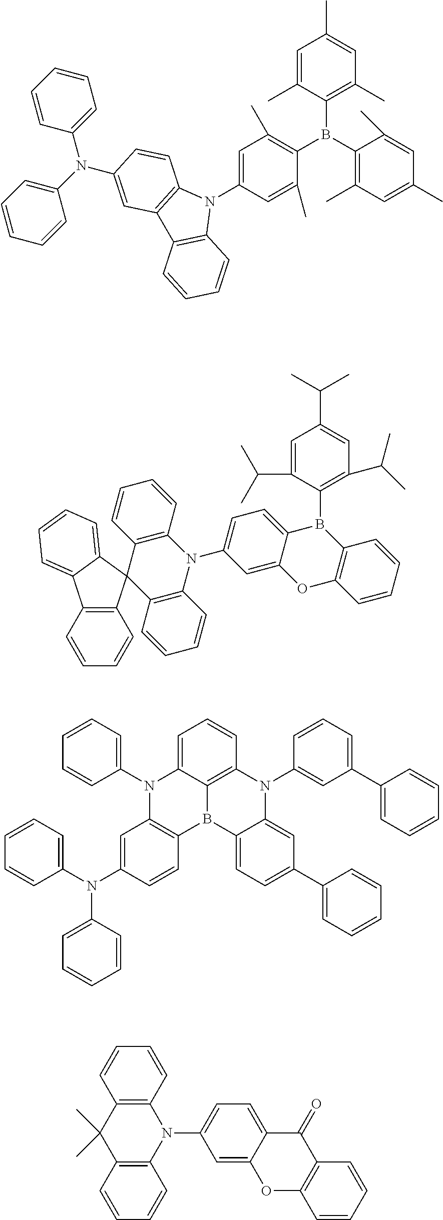

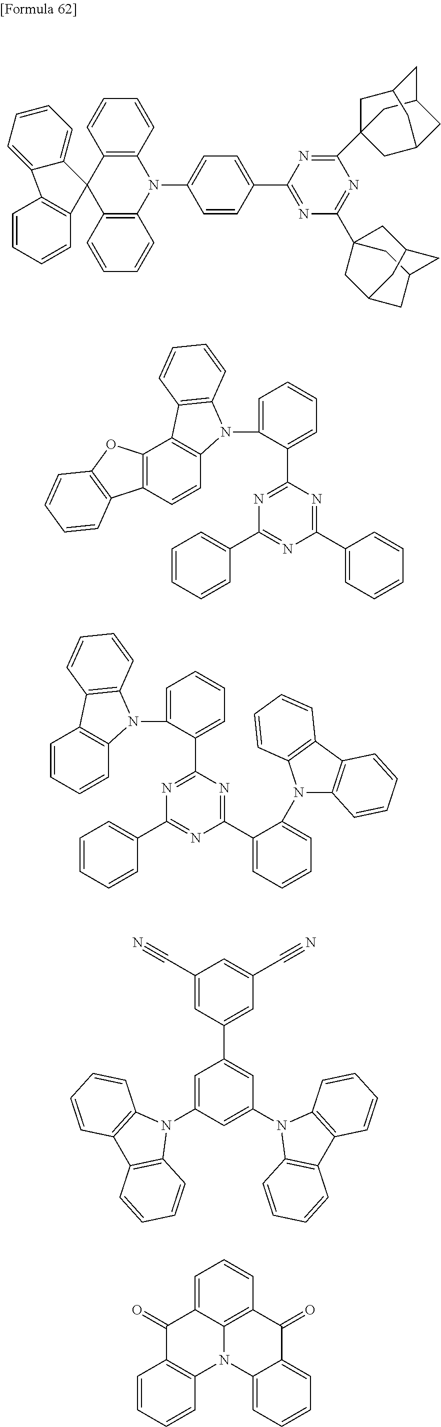 [SMILES: c1ccc2c(c1)-c1ccccc1C21c2ccccc2N(c2ccc(-c3nc(C45CC6CC(CC(C6)C4)C5)nc(C45CC6CC(CC(C6)C4)C5)n3)cc2)c2ccccc21 ; c1ccc(-c2nc(-c3ccccc3)nc(-c3ccccc3-n3c4ccccc4c4c5oc6ccccc6c5ccc43)n2)cc1 ; c1ccc(-c2nc(-c3ccccc3-n3c4ccccc4c4ccccc43)nc(-c3ccccc3-n3c4ccccc4c4ccccc43)n2)cc1 ; N#Cc1cc(C#N)cc(-c2cc(-n3c4ccccc4c4ccccc43)cc(-n3c4ccccc4c4ccccc43)c2)c1 ; O=c1c2ccccc2n2c3ccccc3c(=O)c3cccc1c32]

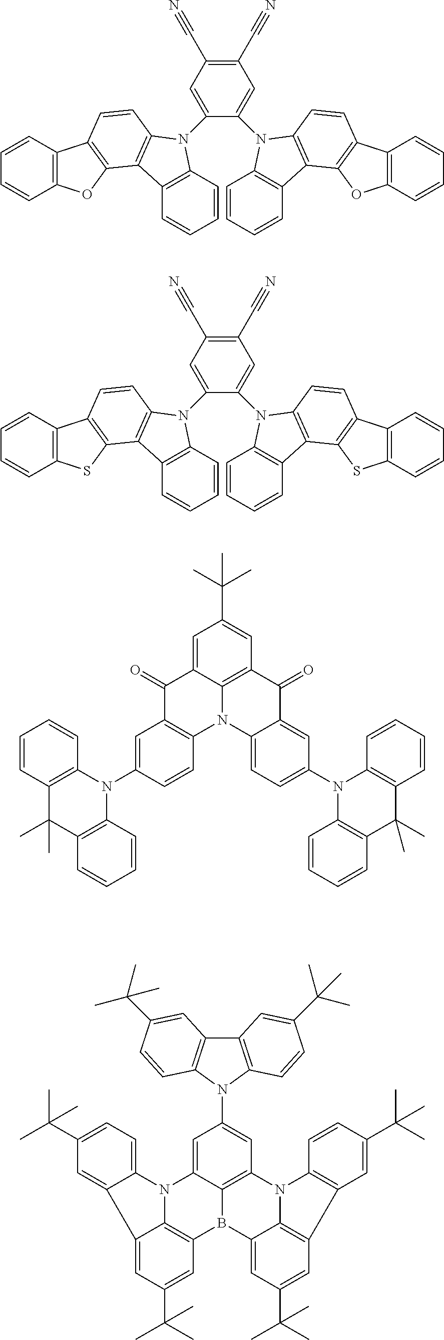

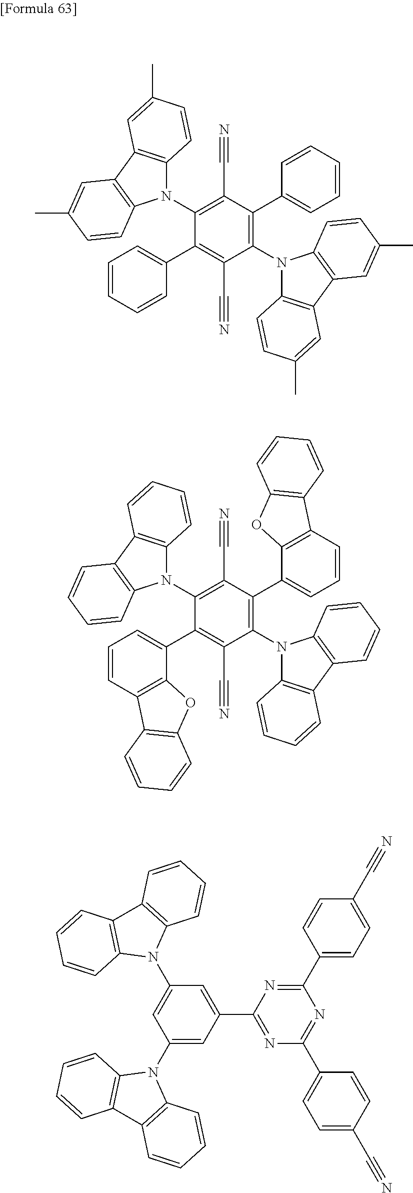

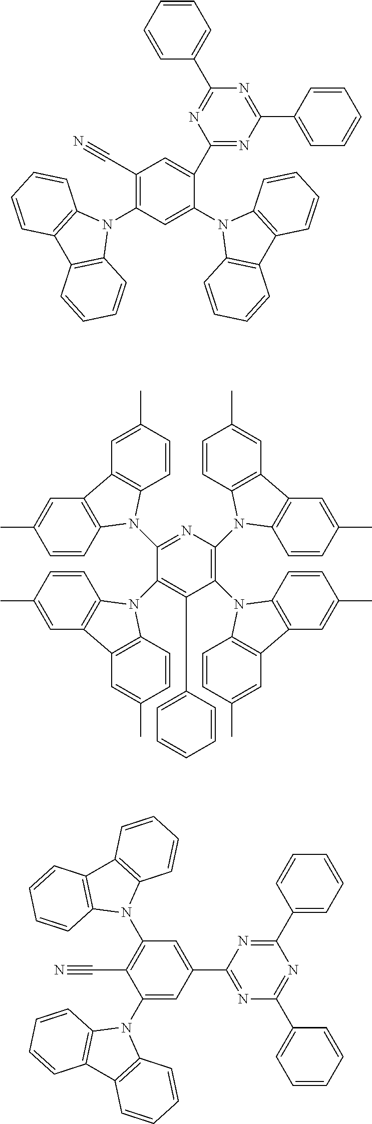

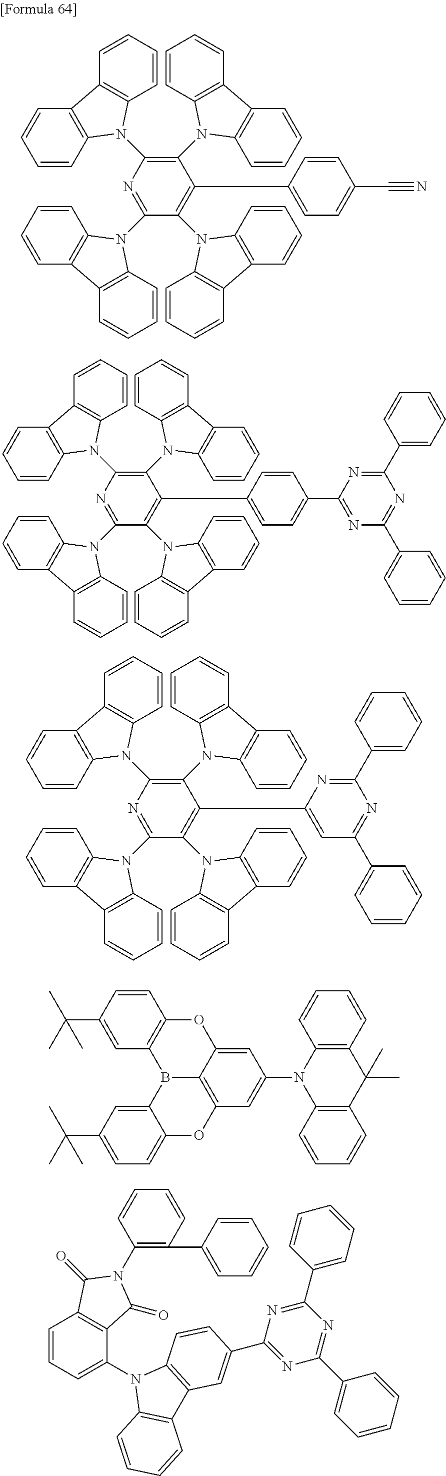

In an exemplary arrangement of the exemplary embodiment, the first sensitizing material is a compound represented by any one of formulae (11) to (13) below.

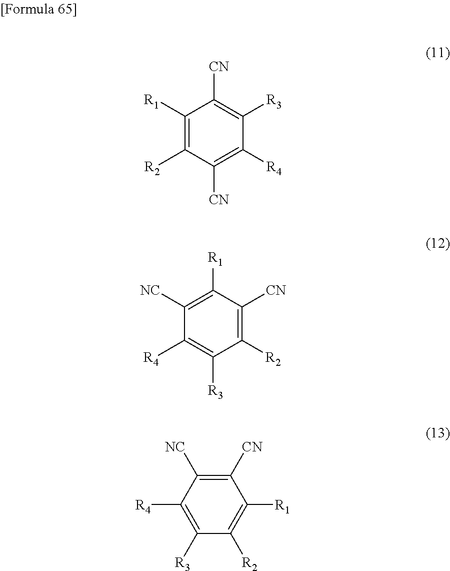

In the formulae (11) to (13): R₁ to R₄ are each independently a group represented by any one of formulae (1-1) to (1-6) below or a group represented by any one of formulae (2-1) to (2-4) below; and at least one of R₁ to R₄ is a group represented by any one of the formulae (1-1) to (1-6) and at least one of R₁ to R₄ is a group represented by any one of the formulae (2-1) to (2-4).

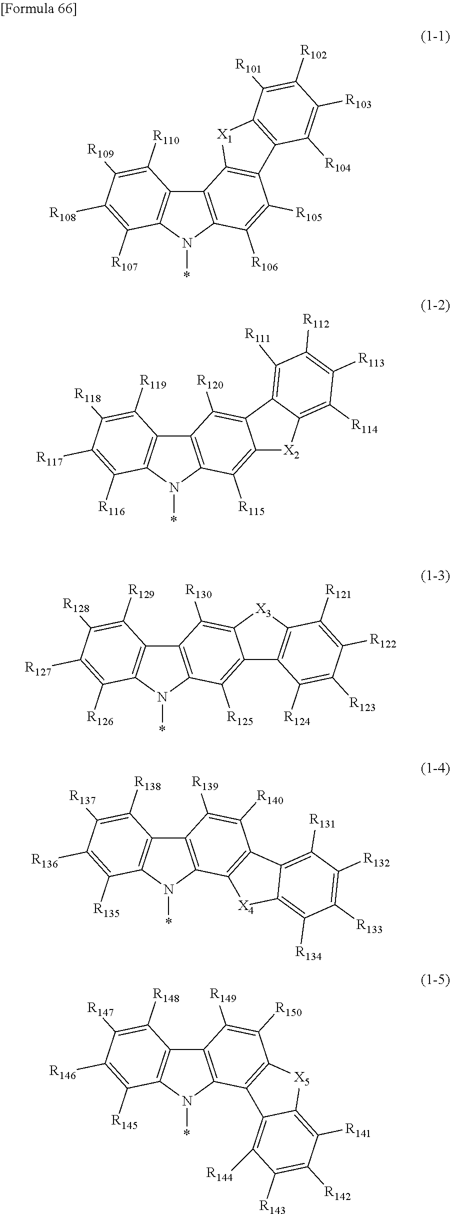

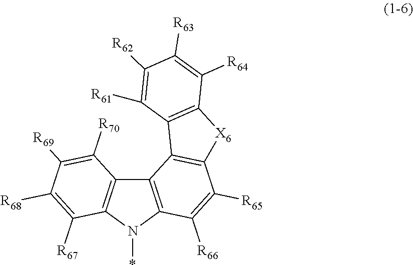

In the formula (1-1):
X₁ is an oxygen atom, a sulfur atom, or CR₁₅₁R₁₅₂; R₁₀₁ to R₁₁₀ are each independently a hydrogen atom or a substituent; R₁₅₁ and R₁₅₂ are each independently a hydrogen atom or a substituent, or R₁₅₁ and R₁₅₂ are bonded to each other to form a ring;
R₁₀₁ to R₁₁₀, R₁₅₁, and R₁₅₂ as a substituent are each independently a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms.

In the formula (1-2), X₂ and R₁₁₁ to R₁₂₀ respectively represent the same as X₁ and R₁₁₁ to R₁₁₀ in the formula (1-1).

In the formula (1-3), X₃ and R₁₂₁ to R₁₃₀ respectively represent the same as X₁ and R₁₁₁ to R₁₁₀ in the formula (1-1).

In the formula (1-4), X₄ and R₁₃₁ to R₁₄₀ respectively represent the same as X₁ and R₁₁₁ to R₁₁₀ in the formula (1-1).

In the formula (1-5), X₅ and R₁₄₁ to R₁₅₀ respectively represent the same as X₁ and R₁₁₁ to R₁₁₀ in the formula (1-1).

In the formula (1-6), X₆ and R₆₁ to R₇₀ respectively represent the same as X₁ and R₁₀₁ to R₁₁₀ in the formula (1-1). Each * independently represents a bonding position with a carbon atom of the benzene ring in each of the formulae (11) to (13).

In the formulae (1-1) to (1-6), when one or more of R₁₀₁ to R₁₁₀, R₁₁₁ to R₁₂₀, R₁₂₁ to R₁₃₀, R₁₃₁ to R₁₄₀, R₁₄₁ to R₁₅₀, R₆₁ to R₇₀, R₁₅₁, and R₁₅₂ are each a hydrogen atom, it is preferable that all of the hydrogen atom(s) are protium atoms, at least one of the hydrogen atom(s) is a deuterium atom, or all of the hydrogen atom(s) are deuterium atoms.

In the formulae (1-1) to (1-6), when one or more of R₁₀₁ to R₁₁₀, R₁₁₁ to R₁₂₀, R₁₂₁ to R₁₃₀, R₁₃₁ to R₁₄₀, R₁₄₁ to R₁₅₀, R₆₁ to R₇₀, R₁₅₁, and R₁₅₂ are each a substituent and each substituent has one or more hydrogen atoms, it is preferable that all of the hydrogen atom(s) are protium atoms, at least one of the hydrogen atom(s) is a deuterium atom, or all of the hydrogen atom(s) are deuterium atoms.

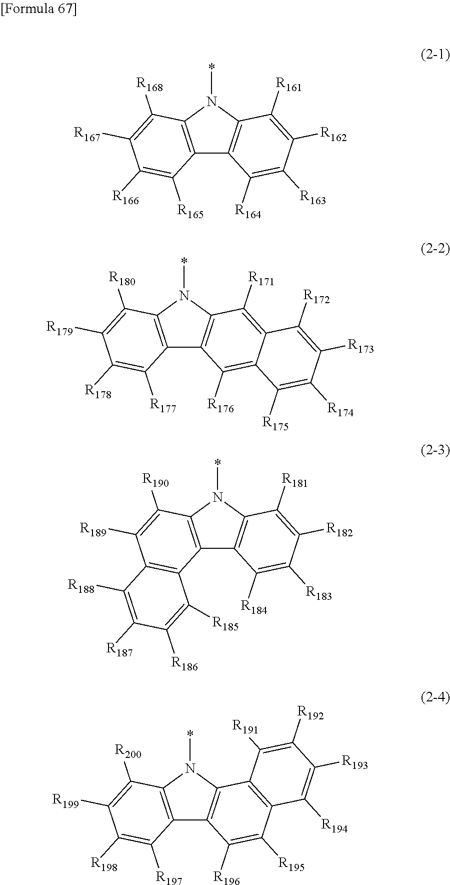

In the formula (2-1): R₁₆₁ to R₁₆₈ are each independently a hydrogen atom or a substituent, a halogen atom; and
R₁₆₁ to R₁₆₈ as a substituent are each independently a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted alkyl halide group having 1 to 30 carbon atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms.

In the formula (2-2), R₁₇₁ to R₁₈₀ are each independently a hydrogen atom or a substituent and R₁₇₁ to R₁₈₀ as the substituent each independently represent the same as the examples of the substituent for R₁₆₁ to R₁₆₈ in the formula (2-1). in

In the formula (2-3), R₁₈₁ to R₁₉₀ are each independently a hydrogen atom or a substituent and R₁₈₁ to R₁₉₀ as the substituent each independently represent the same as the examples of the substituent for R₁₆₁ to R₁₆₈ in the formula (2-1).

In the formula (2-4), R₁₉₁ to R₂₀₀ are each independently a hydrogen atom or a substituent and R₁₉₁ to R₂₀₀ as the substituent each independently represent the same as the examples of the substituent for R₁₆₁ to R₁₆₈ in the formula (2-1). Each * independently represents a bonding position with a carbon atom of the benzene ring in each of the formulae (11) to (13).

In the formulae (2-1) to (2-4), when one or more of R₁₆₁ to R₁₆₈, R₁₇₁ to R₁₈₀, R₁₈₁ to R₁₉₀, and R₁₉₁ to R₂₀₀ are each a hydrogen atom, it is preferable that all of the hydrogen atom(s) are protium atoms, at least one of the hydrogen atom(s) is a deuterium atom, or all of the hydrogen atom(s) are deuterium atoms.

In the formulae (2-1) to (2-4), when one or more of R₁₆₁ to R₁₆₈, R₁₇₁ to R₁₈₀, R₁₈₁ to R₁₉₀, and R₁₉₁ to R₂₀₀ are each a substituent and each substituent has one or more hydrogen atoms, it is preferable that all of the hydrogen atom(s) are protium atoms, at least one of the hydrogen atom(s) is a deuterium atom, or all of the hydrogen atom(s) are deuterium atoms.

In the first sensitizing material according to the exemplary embodiment:
when a plurality of groups represented by the formula (1-1) are present as the groups of R₁ to R₄, the plurality of groups represented by the formula (1-1) are preferably the same as each other, including substituents thereof;
when a plurality of groups represented by the formula (1-2) are present as the groups of R₁ to R₄, the plurality of groups represented by the formula (1-2) are preferably the same as each other, including substituents thereof;
when a plurality of groups represented by the formula (1-3) are present as the groups of R₁ to R₄, the plurality of groups represented by the formula (1-3) are preferably the same as each other, including substituents thereof;
when a plurality of groups represented by the formula (1-4) are present as the groups of R₁ to R₄, the plurality of groups represented by the formula (1-4) are preferably the same as each other, including substituents thereof;
when a plurality of groups represented by the formula (1-5) are present as the groups of R₁ to R₄, the plurality of groups represented by the formula (1-5) are preferably the same as each other, including substituents thereof; and
when a plurality of groups represented by the formula (1-6) are present as the groups of R₁ to R₄, the plurality of groups represented by the formula (1-6) are preferably the same as each other, including substituents thereof.

Specifically, for instance, when two groups represented by the formula (1-1) are selected as the groups of R₁ and R₂, one group represented by the formula (1-2) is selected as the group of R₃, and one group represented by the formula (2-1) is selected as the group of R₄, the two groups represented by the formula (1-1) (the groups of R₁ and R₂) are preferably the same as each other, including substituents thereof.

Alternatively, for instance, when three groups represented by the formula (1-1) are selected as the groups of R₁ to R₃, the three groups represented by the formula (1-1) (the groups of R₁ to R₃) are preferably the same as each other, including substituents thereof.

In an exemplary arrangement of the exemplary embodiment, when two of R₁ to R₄ are selected from the groups represented by the formulae (1-1) to (1-6) and the remaining two of R₁ to R₄ are selected from the groups represented by the formulae (2-1) to (2-4), it is preferable that both of two groups represented by the formulae (1-1) to (1-6) are represented by one of the formulae (1-1) to (1-6) and are the same as each other, including substituents thereof.

Alternatively, for instance, when three of R₁ to R₄ are selected from the groups represented by the formulae (1-1) to (1-6) and the remaining one of R₁ to R₄ is selected from the groups represented by the formulae (2-1) to (2-4), it is preferable that all of three groups represented by the formulae (1-1) to (1-6) are represented by one of the formulae (1-1) to (1-6) and are the same as each other, including substituents thereof.

For instance, when three groups represented by the formula (1-1) are selected as the groups of R₁ to R₄, it is preferable that the three selected groups are a group represented by the formula (1-1) and are the same as each other, including substituents thereof.

In an exemplary arrangement of the exemplary embodiment:
when a plurality of groups represented by the formula (2-1) are present as the groups of R₁ to R₄, the plurality of groups represented by the formula (2-1) are preferably the same as each other, including substituents thereof;
when a plurality of groups represented by the formula (2-2) are present as the groups of R₁ to R₄, the plurality of groups represented by the formula (2-2) are preferably the same as each other, including substituents thereof;
when a plurality of groups represented by the formula (2-3) are present as the groups of R₁ to R₄, the plurality of groups represented by the formula (2-3) are preferably the same as each other, including substituents thereof; and
when a plurality of groups represented by the formula (2-4) are present as the groups of R₁ to R₄, the plurality of groups represented by the formula (2-4) are preferably the same as each other, including substituents thereof.

Specifically, for instance, when two groups represented by the formula (2-1) are selected as the groups of R₁ and R₂, one group represented by the formula (2-2) is selected as the group of R₃, and one group represented by the formula (1-1) is selected as the group of R₄, the two groups represented by the formula (2-1) (the groups of R₁ and R₂) are preferably the same as each other, including substituents thereof.

Alternatively, for instance, when three groups represented by the formula (2-1) are selected as the groups of R₁ to R₃, the three groups represented by the formula (2-1) (the groups of R₁ to R₃) are preferably the same as each other, including substituents thereof.

In an exemplary arrangement of the exemplary embodiment, when two of R₁ to R₄ are selected from the groups represented by the formulae (2-1) to (2-4) and the remaining two of R₁ to R₄ are selected from the groups represented by the formulae (1-1) to (1-6), it is preferable that both of the two groups represented by the formulae (2-1) to (2-4) are represented by one of the formulae (1-1) to (1-4) and are the same as each other, including substituents thereof.

Alternatively, for instance, when three of R₁ to R₄ are selected from the groups represented by the formulae (2-1) to (2-4) and the remaining one of R₁ to R₄ is selected from the groups represented by the formulae (1-1) to (1-6), it is preferable that all of the three groups represented by the formulae (2-1) to (2-4) are represented by one of the formulae (2-1) to (2-4) and are the same as each other, including substituents thereof.

For instance, when three groups represented by the formula (2-1) are selected as the groups of R₁ to R₄, it is preferable that the three selected groups are a group represented by the formula (2-1) and are the same as each other, including substituents thereof.

In an exemplary arrangement of the exemplary embodiment, the first sensitizing material is a compound represented by any one of formulae (101) to (123) below.

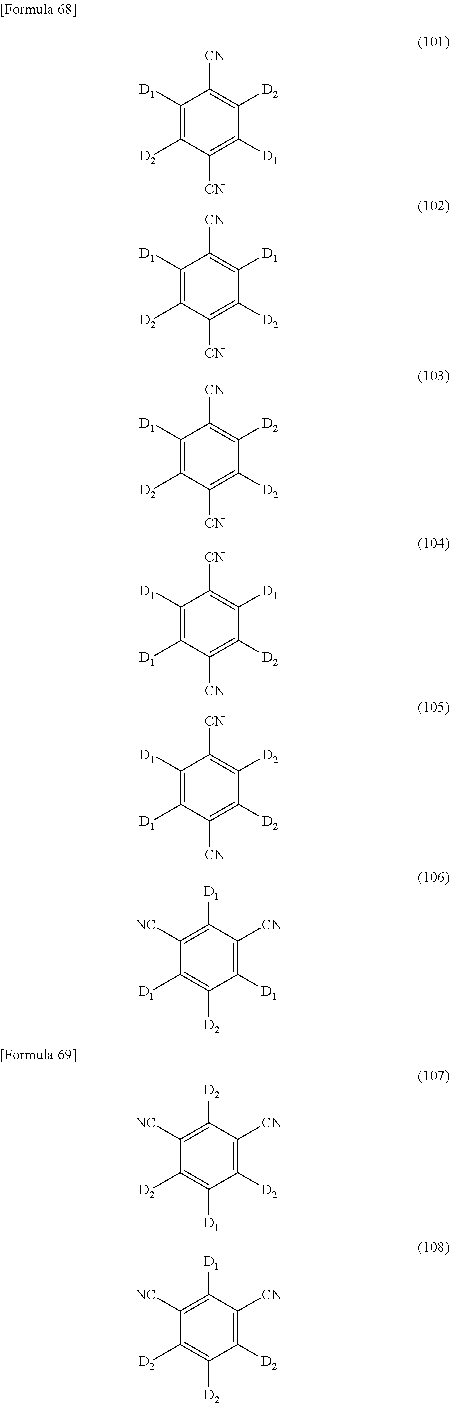

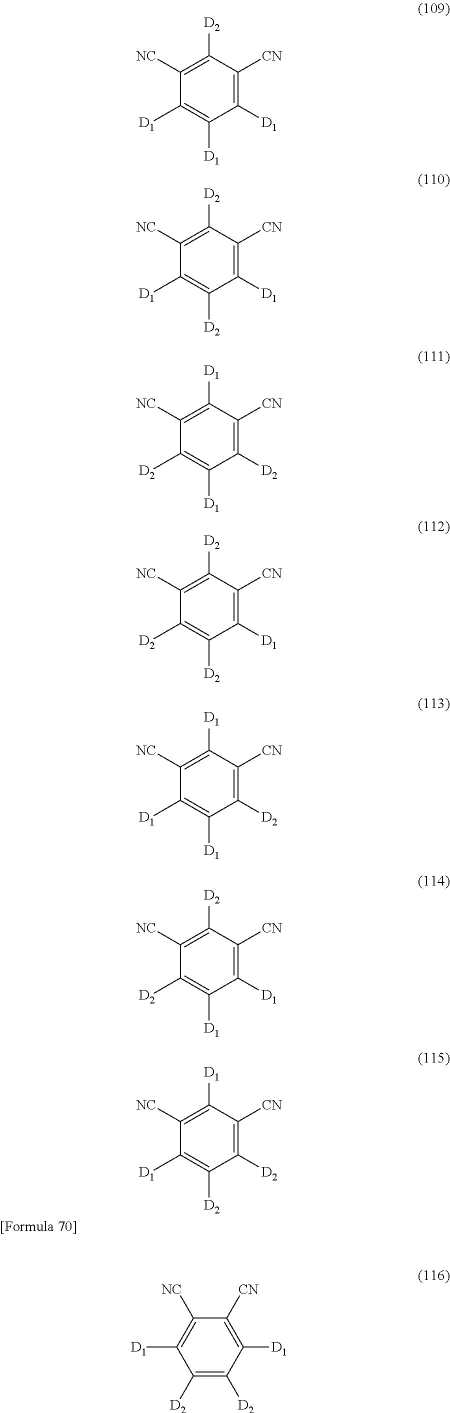

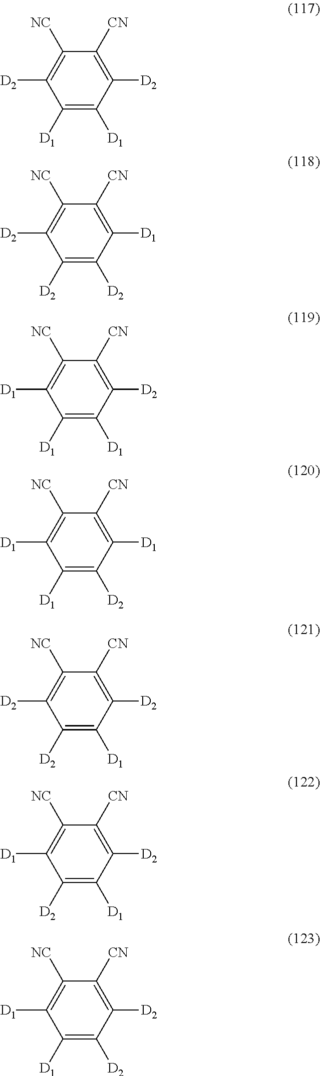

In the formulae (101) to (123), each D₁ is independently any one of the groups represented by the formulae (1-1) to (1-6), each D₂ is independently any one of the groups represented by the formulae (2-1) to (2-4), a plurality of D₁ are mutually the same or different, and a plurality of D₂ are mutually the same or different.

In an exemplary arrangement of the exemplary embodiment, D₁ in the formulae (101) to (123) are preferably the same group as each other.

In an exemplary arrangement of the exemplary embodiment, D₂ in the formulae (101) to (123) are preferably the same group as each other.

That is, in an exemplary arrangement of the exemplary embodiment, it is more preferable that D₁ are the same group as each other and D₂ are the same group as each other in the formulae (101) to (123).

In an exemplary arrangement of the exemplary embodiment, the first sensitizing material is preferably a compound represented by any one of the formulae (101), (106), (107), (110), (111), and (116) to (119).

In the formulae (1-1) to (1-6), X₁ to X₆ are preferably each an oxygen atom.

In the formulae (1-1) to (1-6), X₁ to X₆ are also preferably each a sulfur atom.

In the formulae (1-1) to (1-6), X₁ to X₆ are also preferably each CR₁₅₁R₁₅₂.

In an exemplary arrangement of the exemplary embodiment, the groups represented by the formulae (1-1) to (1-6) are preferably a group represented by the formula (1-1), a group represented by the formula (1-2), or a group represented by the formula (1-4).

In an exemplary arrangement of the exemplary embodiment, the groups represented by the formulae (2-1) to (2-4) are preferably any one of the groups represented by the formulae (2-5) to (2-14) and formulae (2-15) to (2-17) below.

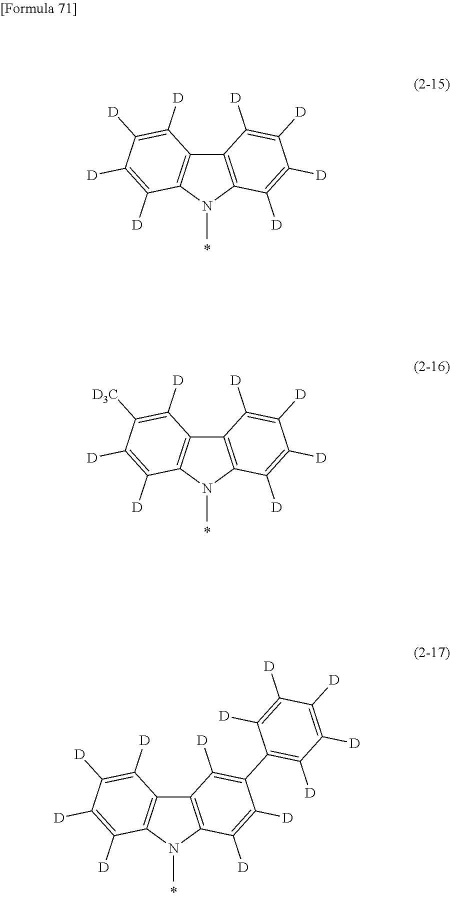 [SMILES: [2H]c1c([2H])c([2H])c2c(c1[2H])c1c([2H])c([2H])c([2H])c([2H])c1n2C ; [2H]c1c([2H])c([2H])c2c(c1[2H])c1c([2H])c(C([2H])([2H])[2H])c([2H])c([2H])c1n2C ; [2H]c1c([2H])c([2H])c(-c2c([2H])c([2H])c3c(c2[2H])c2c([2H])c([2H])c([2H])c([2H])c2n3C)c([2H])c1[2H]]

In the formulae (2-5) to (2-17), each * independently represents a bonding position with a carbon atom of the benzene ring in each of the formulae (11) to (13), and D represents a deuterium atom.

In an exemplary arrangement of the exemplary embodiment, the groups represented by the formulae (2-1) to (2-4) are a group represented by the formula (2-2), a group represented by the formula (2-3), or a group represented by the formula (2-4).

In an exemplary arrangement of the exemplary embodiment, all of the groups represented by the formulae (2-1) to (2-4) are also preferably a group represented by the formula (2-1).

In an exemplary arrangement of the exemplary embodiment, the group represented by the formula (2-1) is a group represented by the formula (2-5) or a group represented by the formula (2-15).

In an exemplary arrangement of the exemplary embodiment, when the first sensitizing material has a group represented by the formula (2-1), R₁₆₁ to R₁₆₈ are each independently a hydrogen atom, a substituted or unsubstituted aryl group having 6 to 14 ring carbon atoms, or a substituted or unsubstituted alkyl group having 1 to 6 carbon atoms.

In an exemplary arrangement of the exemplary embodiment: when the first sensitizing material has a group represented by the formula (2-1), at least one of R₁₆₁, R₁₆₃, R₁₆₆, or R₁₆₈ has a substituent;
the substituent is each independently a substituted or unsubstituted aryl group having 6 to 14 ring carbon atoms, or a substituted or unsubstituted alkyl group having 1 to 6 carbon atoms; and
R₁₆₂, R₁₆₄, R₁₆₅, and R₁₆₇ are each a hydrogen atom.

In an exemplary arrangement of the exemplary embodiment, the first sensitizing material is any one of the compounds represented by the formulae (101), (106), (107), (110), (111), and (116) to (119). In the formulae (101), (106), (107), (110), (111), and (116) to (119), each D₁ independently represents a group represented by a formula (1-1), a group represented by a formula (1-2), or a group represented by a formula (1-4), and each D₂ independently represents any one of groups represented by formulae (2-5) to (2-14).

A plurality of D₁ are mutually the same or different. A plurality of D₂ are mutually the same or different.

In an exemplary arrangement of the exemplary embodiment, the first sensitizing material is a compound represented by the formula (11).

In an exemplary arrangement of the exemplary embodiment, the first sensitizing material is a compound represented by the formula (12).

In an exemplary arrangement of the exemplary embodiment, the first sensitizing material is a compound represented by the formula (13).

In the formulae (1-1) to (1-6) and (2-1) to (2-4):
R₁₀₁ to R₁₅₀, R₁₅₁, R₁₅₂, R₁₆₁ to R₁₆₈, R₁₇₁ to R₂₀₀, R₁₇₁ to R₂₀₀, and R₁₇₁ to R₁₈₀, and R₆₁ to R₇₀ as a substituent are preferably each independently a halogen atom, an unsubstituted aryl group having 6 to 14 ring carbon atoms, an unsubstituted heterocyclic group having 5 to 14 ring atoms, an unsubstituted alkyl group having 1 to 6 carbon atoms, an unsubstituted alkyl halide group having 1 to 6 carbon atoms, an unsubstituted alkylsilyl group having 3 to 6 carbon atoms, an unsubstituted alkoxy group having 1 to 6 carbon atoms, an unsubstituted aryloxy group having 6 to 14 ring carbon atoms, an unsubstituted alkylamino group having 2 to 12 carbon atoms, an unsubstituted alkylthio group having 1 to 6 carbon atoms, or an unsubstituted arylthio group having 6 to 14 ring carbon atoms.

In the formulae (1-1) to (1-6) and (2-1) to (2-4):
R₁₀₁ to R₁₅₀, R₁₅₁, R₁₅₂, R₁₆₁ to R₁₆₈, R₁₇₁ to R₂₀₀, and R₆₁ to R₇₀ are preferably each independently an unsubstituted aryl group having 6 to 14 ring carbon atoms, or an unsubstituted alkyl group having 1 to 6 carbon atoms.

In the formulae (1-1) to (1-6): it is also preferable that R₁₀₁ to R₁₅₀ and R₆₁ to R₇₀ are each a hydrogen atom; and
R₁₅₁ and R₁₅₂ are an unsubstituted aryl group having 6 to 14 ring carbon atoms or an unsubstituted alkyl group having 1 to 6 carbon atoms.

In the formulae (2-1) to (2-4):
R₁₆₁ to R₁₆₈ and R₁₇₁ to R₂₀₀ are also preferably each a hydrogen atom.

In an exemplary arrangement of the exemplary embodiment, the first sensitizing material is a compound represented by a formula (103A) below.

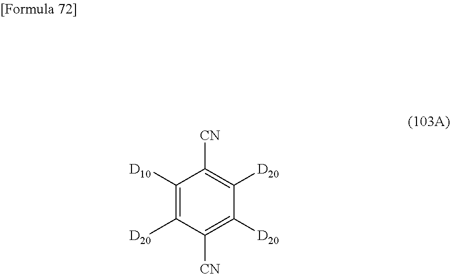

In the formula (103A), D₁₀ represents a group represented by a formula (1-4A) below and D₂₀ represents a group represented by the formula (2-1). A plurality of D₂₀ in the formula (103A) are mutually the same group.

That “a plurality of D₂₀ are mutually the same group” means that all variables represented by the same symbol in the formula (2-1) are the same. The variables in the formula (2-1) refer to R₁₆₁ to R₁₆₈. Specifically, in the formula (103A), in the “group represented by the formula (2-1)” for each D₂₀, a plurality of R₁₆₁ are the same, a plurality of R₁₆₂ are the same, a plurality of R₁₆₃ are the same, a plurality of R₁₆₄ are the same, a plurality of R₁₆₅ are the same, a plurality of R₁₆₆ are the same, a plurality of R₁₆₇ are the same, and a plurality of R₁₆₈ are the same. That is, three D₂₀ in the formula (103A) are mutually the same group, including substituents thereof.

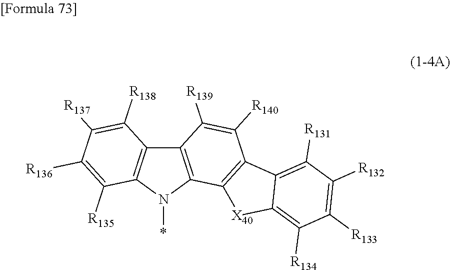

In the formula (1-4A): X₄₀ represents an oxygen atom or a sulfur atom; R₁₃₁ to R₁₄₀ each represent the same as R₁₃₁ to R₁₄₀ in the formula (1-4); and * represents a bonding position to the benzene ring in the formula (103A).

In the formula (1-4A), X₄₀ is preferably a sulfur atom.

In the formula (1-4A), X₄₀ is also preferably an oxygen atom.

In a compound represented by the formula (103A), a group represented by the formula (2-1) is preferably any one of groups represented by the formulae (2-5) and (2-9) to (2-17).

In the formulae (2-5) and (2-9) to (2-17), each * independently represents a bonding position to the benzene ring in the formula (103A), and D represents a deuterium atom.

In the formula (2-1), R₁₆₁ to R₁₆₈ are preferably each independently a hydrogen atom, a substituted or unsubstituted aryl group having 6 to 14 ring carbon atoms, or a substituted or unsubstituted alkyl group having 1 to 6 carbon atoms, more preferably a hydrogen atom or a substituted or unsubstituted alkyl group having 1 to 6 carbon atoms.

In the formula (2-1), it is also preferable that: at least one of R₁₆₁, R₁₆₃, R₁₆₆, or R₁₆₈ has a substituent, each substituent being independently a substituted or unsubstituted aryl group having 6 to 14 ring carbon atoms or a substituted or unsubstituted alkyl group having 1 to 6 carbon atoms; and R₁₆₂, R₁₆₄, R₁₆₅, and R₁₆₇ are each a hydrogen atom.

In the formula (2-1), when one or more of R₁₆₁ to R₁₆₈ are each a hydrogen atom, it is preferable that all of the hydrogen atom(s) are protium atoms, at least one of the hydrogen atom(s) is a deuterium atom, or all of the hydrogen atom(s) are deuterium atoms.

In the formulae (1-4A) and (2-1), R₁₃₁ to R₁₄₀ and R₁₆₁ to R₁₆₈as a substituent are preferably each independently a halogen atom, an unsubstituted aryl group having 6 to 14 ring carbon atoms, an unsubstituted heterocyclic group having 5 to 14 ring atoms, an unsubstituted alkyl group having 1 to 6 carbon atoms, an unsubstituted alkyl halide group having 1 to 6 carbon atoms, an unsubstituted alkylsilyl group having 3 to 6 carbon atoms, an unsubstituted alkoxy group having 1 to 6 carbon atoms, an unsubstituted aryloxy group having 6 to 14 ring carbon atoms, an unsubstituted alkylamino group having 2 to 12 carbon atoms, an unsubstituted alkylthio group having 1 to 6 carbon atoms, or an unsubstituted arylthio group having 6 to 14 ring carbon atoms.

In the formulae (1-4A) and (2-1), R₁₃₁ to R₁₄₀ and R₁₆₁ to R₁₆₈ are preferably each independently a hydrogen atom, a substituted or unsubstituted aryl group having 6 to 14 ring carbon atoms, a substituted or unsubstituted heterocyclic group having 5 to 14 ring atoms, or a substituted or unsubstituted alkyl group having 1 to 6 carbon atoms, more preferably a hydrogen atom, a substituted or unsubstituted aryl group having 6 to 14 ring carbon atoms, or a substituted or unsubstituted alkyl group having 1 to 6 carbon atoms, and still more preferably a hydrogen atom or a substituted or unsubstituted alkyl group having 1 to 6 carbon atoms.

In the formulae (1-4A) and (2-1), R₁₃₁ to R₁₄₀ and R₁₆₁ to R₁₆₈ as a substituent are still further more preferably each independently an unsubstituted aryl group having 6 to 14 ring carbon atoms or an unsubstituted alkyl group having 1 to 6 carbon atoms.

In the formulae (1-4A) and (2-1), it is also preferable that: R₁₃₇ is a substituent and R₁₃₇ as the substituent is a substituted or unsubstituted aryl group having 6 to 14 ring carbon atoms or a substituted or unsubstituted alkyl group having 1 to 6 carbon atoms; and R₁₃₁ to R₁₃₆ and R₁₃₈ to R₁₄₀ are each a hydrogen atom.

In the formulae (1-4A) and (2-1), R₁₃₁ to R₁₄₀ and R₁₆₁ to R₁₆₈ are also preferably each a hydrogen atom.

Specific examples of the first sensitizing material in the exemplary embodiment (compound represented by any one of the formulae (11) to (13)) include compounds shown below. It should however be noted that the first sensitizing material is not limited to the specific examples of these compounds. Me represents a methyl group.

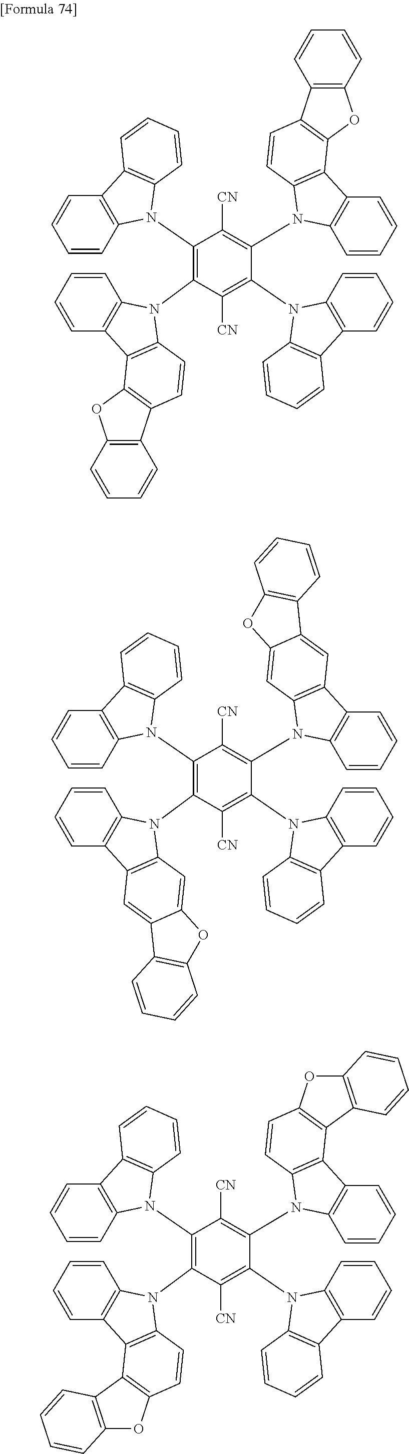 [SMILES: N#Cc1c(-n2c3ccccc3c3ccccc32)c(-n2c3ccccc3c3c4oc5ccccc5c4ccc32)c(C#N)c(-n2c3ccccc3c3ccccc32)c1-n1c2ccccc2c2c3oc4ccccc4c3ccc21 ; N#Cc1c(-n2c3ccccc3c3ccccc32)c(-n2c3ccccc3c3cc4c(cc32)oc2ccccc24)c(C#N)c(-n2c3ccccc3c3ccccc32)c1-n1c2ccccc2c2cc3c(cc21)oc1ccccc13 ; N#Cc1c(-n2c3ccccc3c3ccccc32)c(-n2c3ccccc3c3c4c(ccc32)oc2ccccc24)c(C#N)c(-n2c3ccccc3c3ccccc32)c1-n1c2ccccc2c2c3c(ccc21)oc1ccccc13]

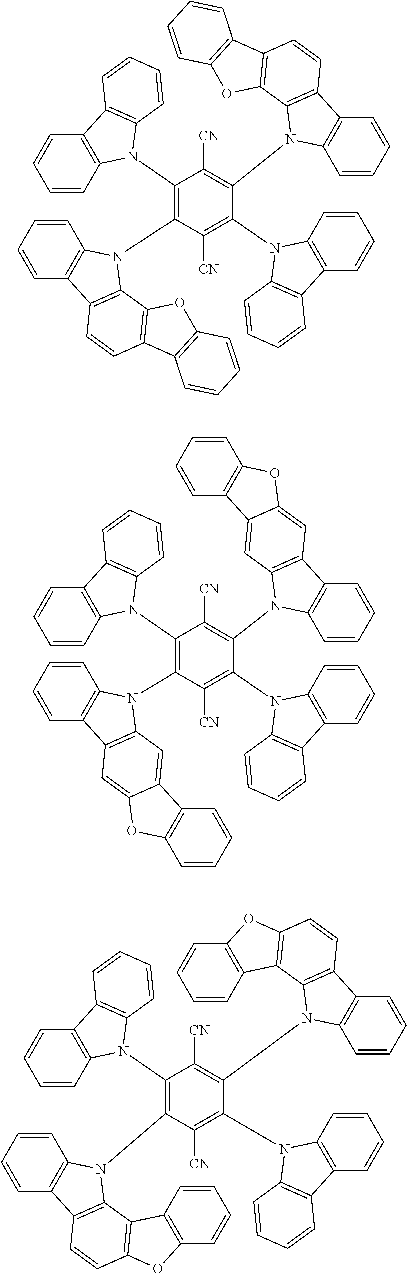

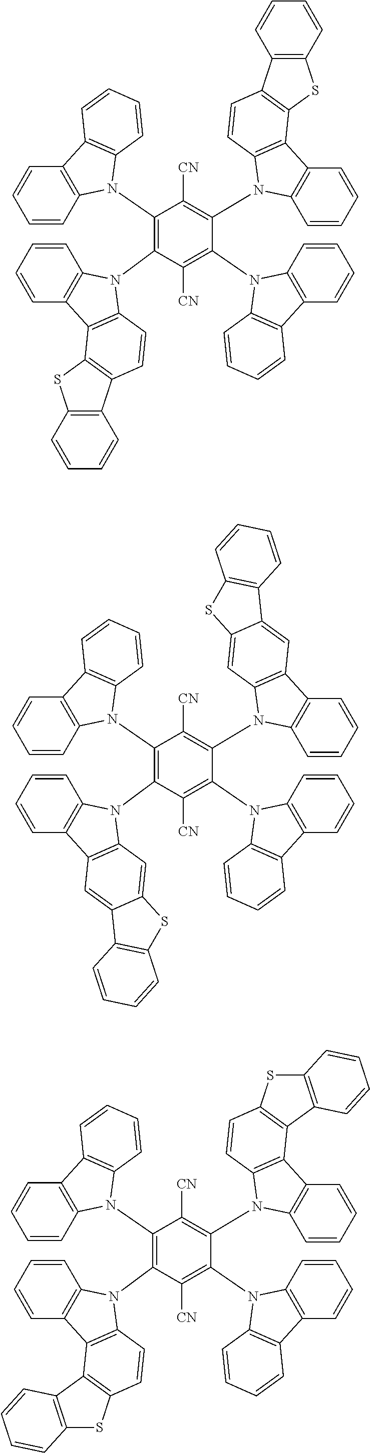 [SMILES: N#Cc1c(-n2c3ccccc3c3ccccc32)c(-n2c3ccccc3c3c4sc5ccccc5c4ccc32)c(C#N)c(-n2c3ccccc3c3ccccc32)c1-n1c2ccccc2c2c3sc4ccccc4c3ccc21 ; N#Cc1c(-n2c3ccccc3c3ccccc32)c(-n2c3ccccc3c3cc4c(cc32)sc2ccccc24)c(C#N)c(-n2c3ccccc3c3ccccc32)c1-n1c2ccccc2c2cc3c(cc21)sc1ccccc13 ; N#Cc1c(-n2c3ccccc3c3ccccc32)c(-n2c3ccccc3c3c4c(ccc32)sc2ccccc24)c(C#N)c(-n2c3ccccc3c3ccccc32)c1-n1c2ccccc2c2c3c(ccc21)sc1ccccc13]

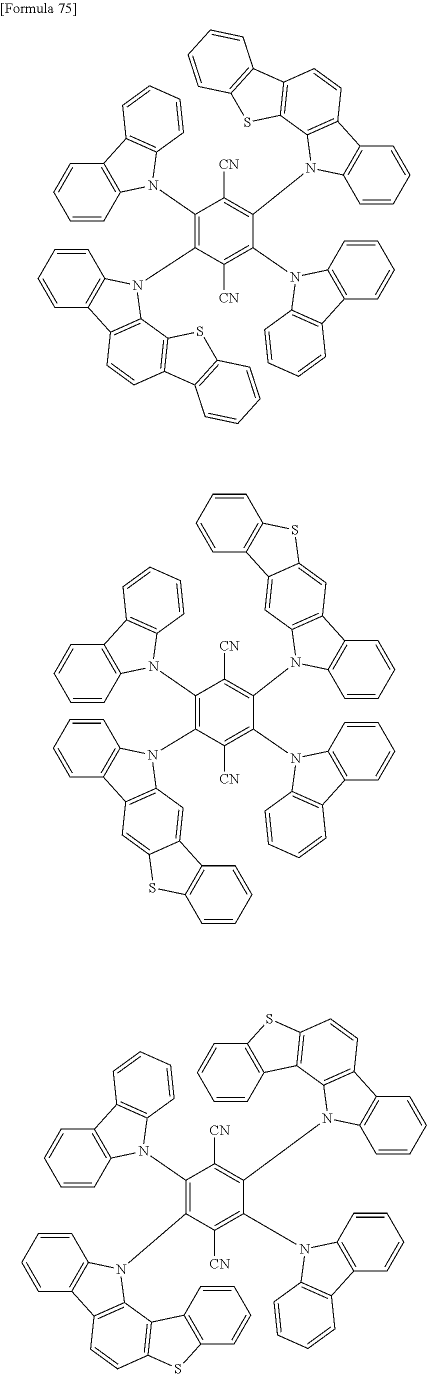 [SMILES: N#Cc1c(-n2c3ccccc3c3ccccc32)c(-n2c3ccccc3c3ccc4c5ccccc5sc4c32)c(C#N)c(-n2c3ccccc3c3ccccc32)c1-n1c2ccccc2c2ccc3c4ccccc4sc3c21 ; N#Cc1c(-n2c3ccccc3c3ccccc32)c(-n2c3ccccc3c3cc4sc5ccccc5c4cc32)c(C#N)c(-n2c3ccccc3c3ccccc32)c1-n1c2ccccc2c2cc3sc4ccccc4c3cc21 ; N#Cc1c(-n2c3ccccc3c3ccccc32)c(-n2c3ccccc3c3ccc4sc5ccccc5c4c32)c(C#N)c(-n2c3ccccc3c3ccccc32)c1-n1c2ccccc2c2ccc3sc4ccccc4c3c21]

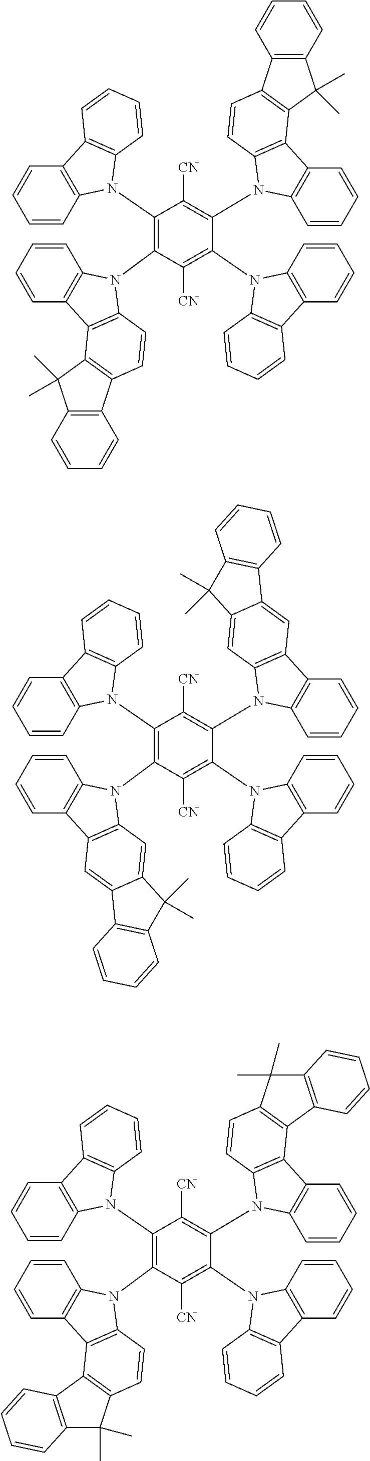 [SMILES: CC1(C)c2ccccc2-c2ccc3c(c21)c1ccccc1n3-c1c(C#N)c(-n2c3ccccc3c3ccccc32)c(-n2c3ccccc3c3c4c(ccc32)-c2ccccc2C4(C)C)c(C#N)c1-n1c2ccccc2c2ccccc21 ; CC1(C)c2ccccc2-c2cc3c4ccccc4n(-c4c(C#N)c(-n5c6ccccc6c6ccccc65)c(-n5c6ccccc6c6cc7c(cc65)C(C)(C)c5ccccc5-7)c(C#N)c4-n4c5ccccc5c5ccccc54)c3cc21 ; CC1(C)c2ccccc2-c2c1ccc1c2c2ccccc2n1-c1c(C#N)c(-n2c3ccccc3c3ccccc32)c(-n2c3ccccc3c3c4c(ccc32)C(C)(C)c2ccccc2-4)c(C#N)c1-n1c2ccccc2c2ccccc21]

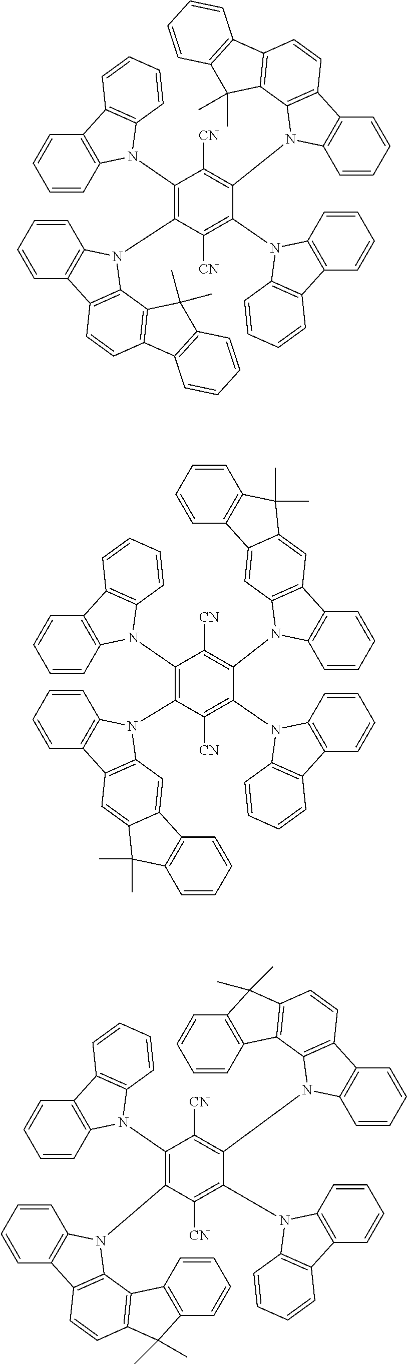 [SMILES: CC1(C)c2ccccc2-c2ccc3c4ccccc4n(-c4c(C#N)c(-n5c6ccccc6c6ccccc65)c(-n5c6ccccc6c6ccc7c(c65)C(C)(C)c5ccccc5-7)c(C#N)c4-n4c5ccccc5c5ccccc54)c3c21 ; CC1(C)c2ccccc2-c2cc3c(cc21)c1ccccc1n3-c1c(C#N)c(-n2c3ccccc3c3ccccc32)c(-n2c3ccccc3c3cc4c(cc32)-c2ccccc2C4(C)C)c(C#N)c1-n1c2ccccc2c2ccccc21 ; CC1(C)c2ccccc2-c2c1ccc1c3ccccc3n(-c3c(C#N)c(-n4c5ccccc5c5ccccc54)c(-n4c5ccccc5c5ccc6c(c54)-c4ccccc4C6(C)C)c(C#N)c3-n3c4ccccc4c4ccccc43)c21]

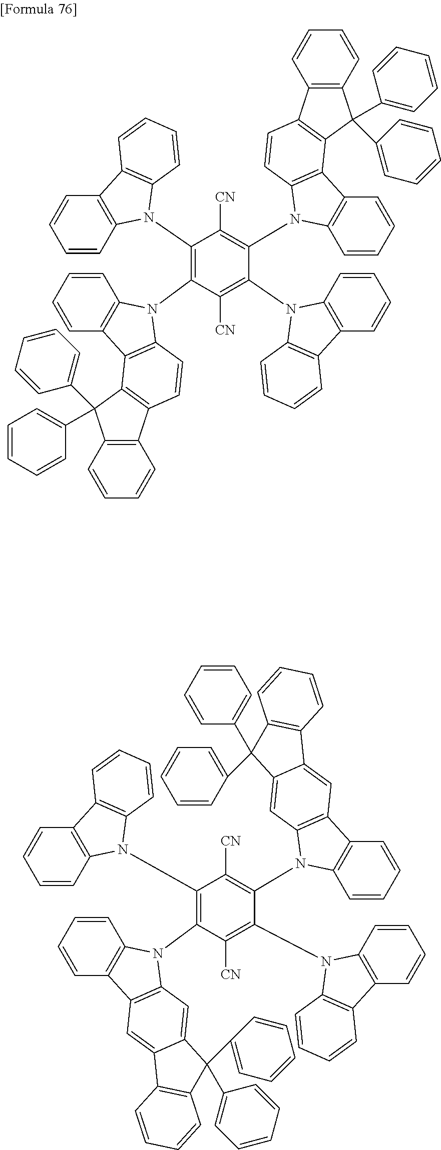 [SMILES: N#Cc1c(-n2c3ccccc3c3ccccc32)c(-n2c3ccccc3c3c4c(ccc32)-c2ccccc2C4(c2ccccc2)c2ccccc2)c(C#N)c(-n2c3ccccc3c3ccccc32)c1-n1c2ccccc2c2c3c(ccc21)-c1ccccc1C3(c1ccccc1)c1ccccc1 ; N#Cc1c(-n2c3ccccc3c3ccccc32)c(-n2c3ccccc3c3cc4c(cc32)C(c2ccccc2)(c2ccccc2)c2ccccc2-4)c(C#N)c(-n2c3ccccc3c3ccccc32)c1-n1c2ccccc2c2cc3c(cc21)C(c1ccccc1)(c1ccccc1)c1ccccc1-3]

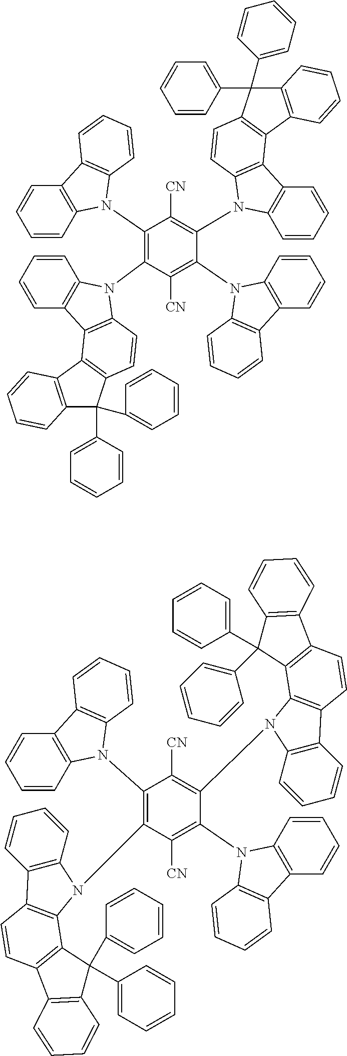 [SMILES: N#Cc1c(-n2c3ccccc3c3ccccc32)c(-n2c3ccccc3c3c4c(ccc32)C(c2ccccc2)(c2ccccc2)c2ccccc2-4)c(C#N)c(-n2c3ccccc3c3ccccc32)c1-n1c2ccccc2c2c3c(ccc21)C(c1ccccc1)(c1ccccc1)c1ccccc1-3 ; N#Cc1c(-n2c3ccccc3c3ccccc32)c(-n2c3ccccc3c3ccc4c(c32)C(c2ccccc2)(c2ccccc2)c2ccccc2-4)c(C#N)c(-n2c3ccccc3c3ccccc32)c1-n1c2ccccc2c2ccc3c(c21)C(c1ccccc1)(c1ccccc1)c1ccccc1-3]

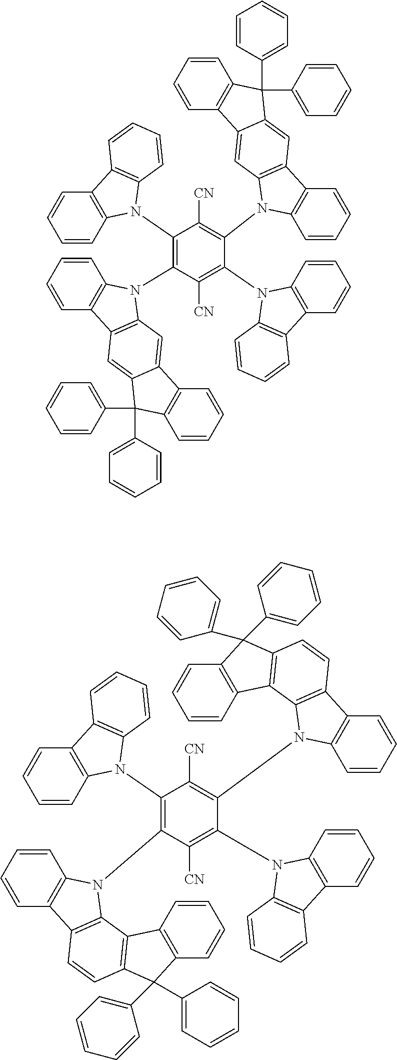 [SMILES: N#Cc1c(-n2c3ccccc3c3ccccc32)c(-n2c3ccccc3c3cc4c(cc32)-c2ccccc2C4(c2ccccc2)c2ccccc2)c(C#N)c(-n2c3ccccc3c3ccccc32)c1-n1c2ccccc2c2cc3c(cc21)-c1ccccc1C3(c1ccccc1)c1ccccc1 ; N#Cc1c(-n2c3ccccc3c3ccccc32)c(-n2c3ccccc3c3ccc4c(c32)-c2ccccc2C4(c2ccccc2)c2ccccc2)c(C#N)c(-n2c3ccccc3c3ccccc32)c1-n1c2ccccc2c2ccc3c(c21)-c1ccccc1C3(c1ccccc1)c1ccccc1]

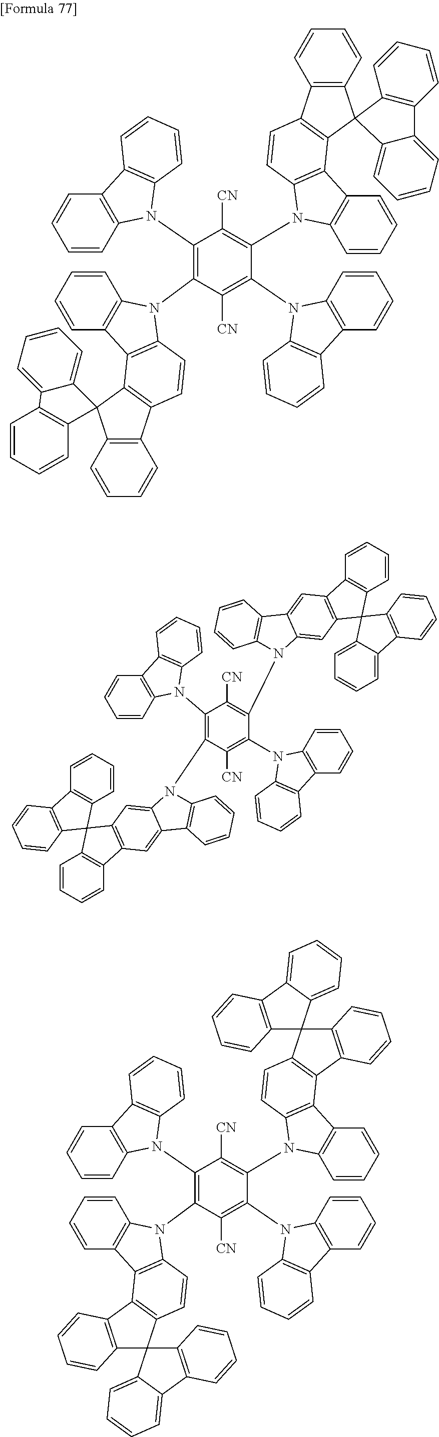

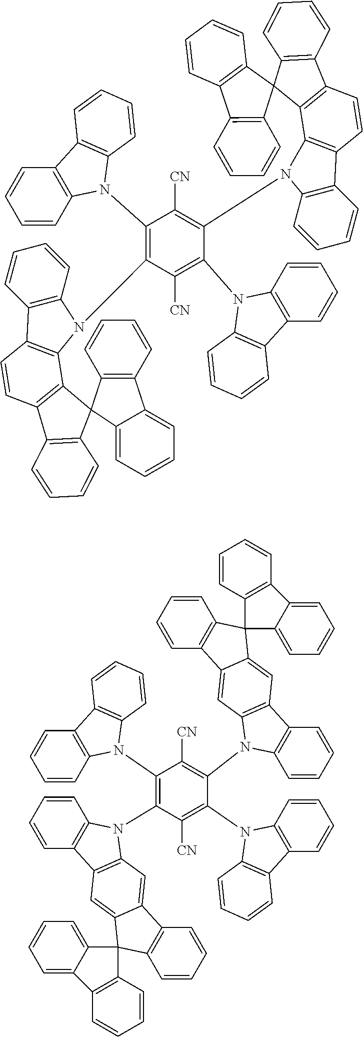 [SMILES: N#Cc1c(-n2c3ccccc3c3ccccc32)c(-n2c3ccccc3c3ccc4c(c32)C2(c3ccccc3-c3ccccc32)c2ccccc2-4)c(C#N)c(-n2c3ccccc3c3ccccc32)c1-n1c2ccccc2c2ccc3c(c21)C1(c2ccccc2-c2ccccc21)c1ccccc1-3 ; N#Cc1c(-n2c3ccccc3c3ccccc32)c(-n2c3ccccc3c3cc4c(cc32)-c2ccccc2C42c3ccccc3-c3ccccc32)c(C#N)c(-n2c3ccccc3c3ccccc32)c1-n1c2ccccc2c2cc3c(cc21)-c1ccccc1C31c2ccccc2-c2ccccc21]

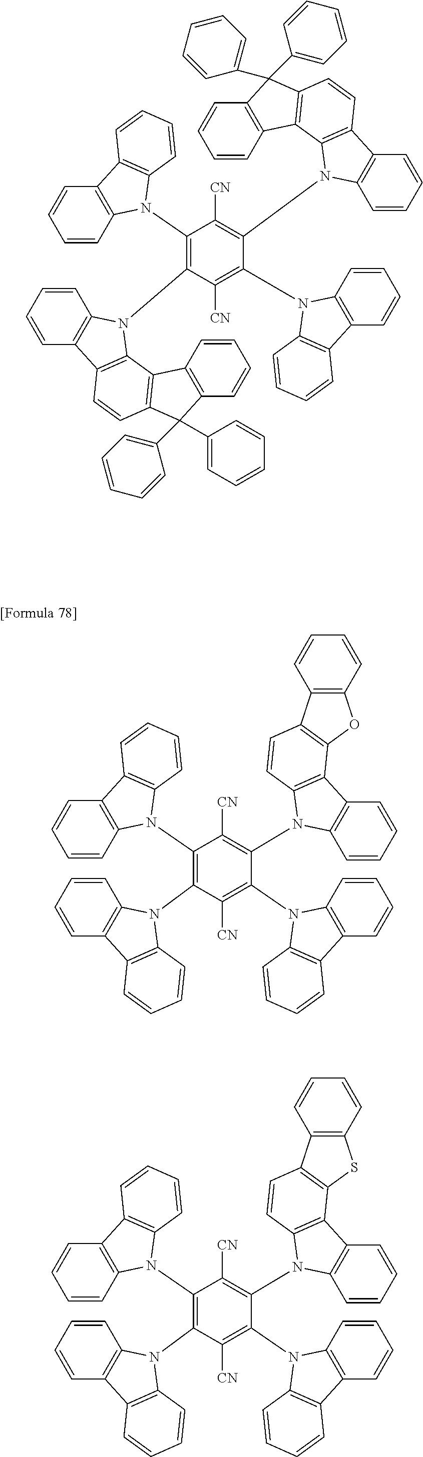 [SMILES: N#Cc1c(-n2c3ccccc3c3ccccc32)c(-n2c3ccccc3c3ccc4c(c32)-c2ccccc2C4(c2ccccc2)c2ccccc2)c(C#N)c(-n2c3ccccc3c3ccccc32)c1-n1c2ccccc2c2ccc3c(c21)-c1ccccc1C3(c1ccccc1)c1ccccc1 ; N#Cc1c(-n2c3ccccc3c3ccccc32)c(-n2c3ccccc3c3ccccc32)c(C#N)c(-n2c3ccccc3c3c4oc5ccccc5c4ccc32)c1-n1c2ccccc2c2ccccc21 ; N#Cc1c(-n2c3ccccc3c3ccccc32)c(-n2c3ccccc3c3ccccc32)c(C#N)c(-n2c3ccccc3c3c4sc5ccccc5c4ccc32)c1-n1c2ccccc2c2ccccc21]

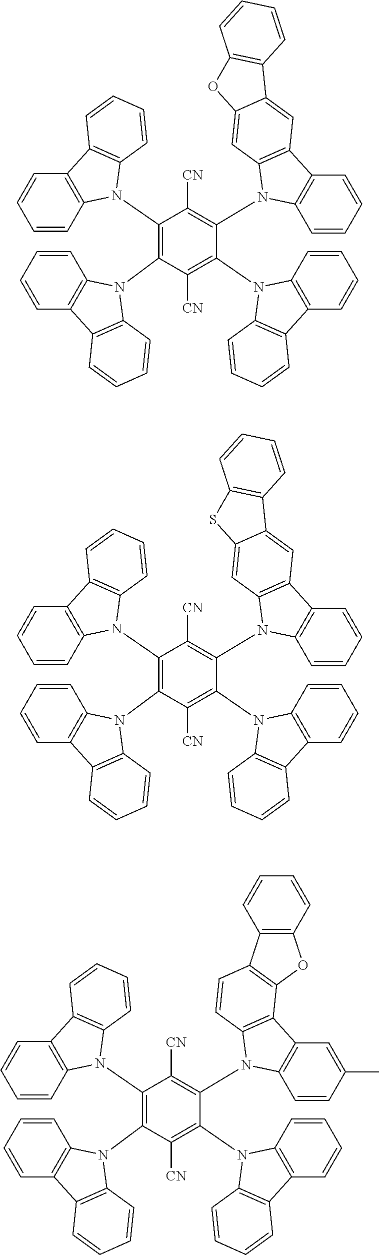 [SMILES: N#Cc1c(-n2c3ccccc3c3ccccc32)c(-n2c3ccccc3c3ccccc32)c(C#N)c(-n2c3ccccc3c3cc4c(cc32)oc2ccccc24)c1-n1c2ccccc2c2ccccc21 ; N#Cc1c(-n2c3ccccc3c3ccccc32)c(-n2c3ccccc3c3ccccc32)c(C#N)c(-n2c3ccccc3c3cc4c(cc32)sc2ccccc24)c1-n1c2ccccc2c2ccccc21 ; Cc1ccc2c(c1)c1c3oc4ccccc4c3ccc1n2-c1c(C#N)c(-n2c3ccccc3c3ccccc32)c(-n2c3ccccc3c3ccccc32)c(C#N)c1-n1c2ccccc2c2ccccc21]

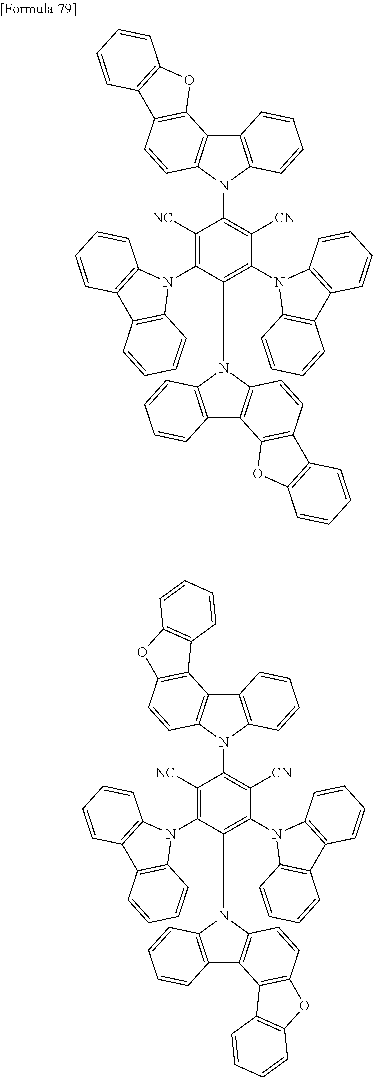 [SMILES: N#Cc1c(-n2c3ccccc3c3ccccc32)c(-n2c3ccccc3c3c4oc5ccccc5c4ccc32)c(-n2c3ccccc3c3ccccc32)c(C#N)c1-n1c2ccccc2c2c3oc4ccccc4c3ccc21 ; N#Cc1c(-n2c3ccccc3c3ccccc32)c(-n2c3ccccc3c3c4c(ccc32)oc2ccccc24)c(-n2c3ccccc3c3ccccc32)c(C#N)c1-n1c2ccccc2c2c3c(ccc21)oc1ccccc13]

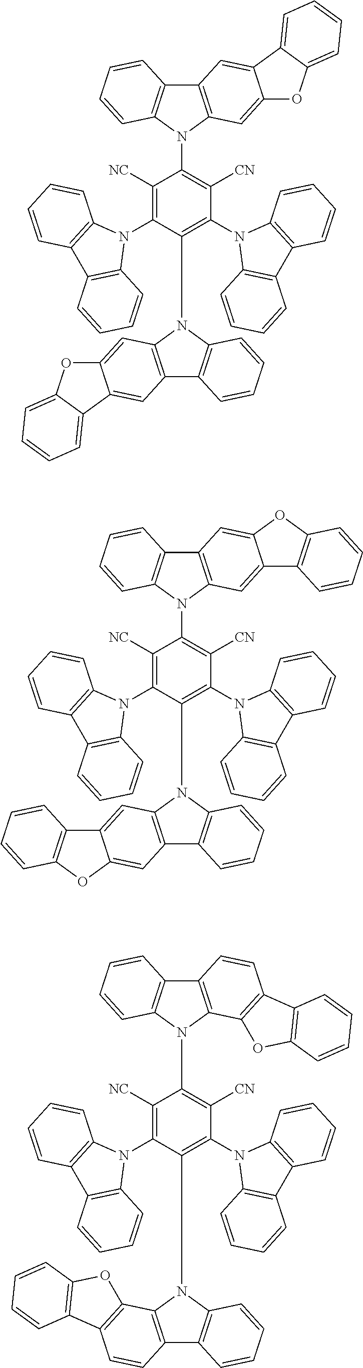 [SMILES: N#Cc1c(-n2c3ccccc3c3cc4c(cc32)oc2ccccc24)c(C#N)c(-n2c3ccccc3c3ccccc32)c(-n2c3ccccc3c3cc4c(cc32)oc2ccccc24)c1-n1c2ccccc2c2ccccc21 ; N#Cc1c(-n2c3ccccc3c3cc4oc5ccccc5c4cc32)c(C#N)c(-n2c3ccccc3c3ccccc32)c(-n2c3ccccc3c3cc4oc5ccccc5c4cc32)c1-n1c2ccccc2c2ccccc21 ; N#Cc1c(-n2c3ccccc3c3ccccc32)c(-n2c3ccccc3c3ccc4c5ccccc5oc4c32)c(-n2c3ccccc3c3ccccc32)c(C#N)c1-n1c2ccccc2c2ccc3c4ccccc4oc3c21]

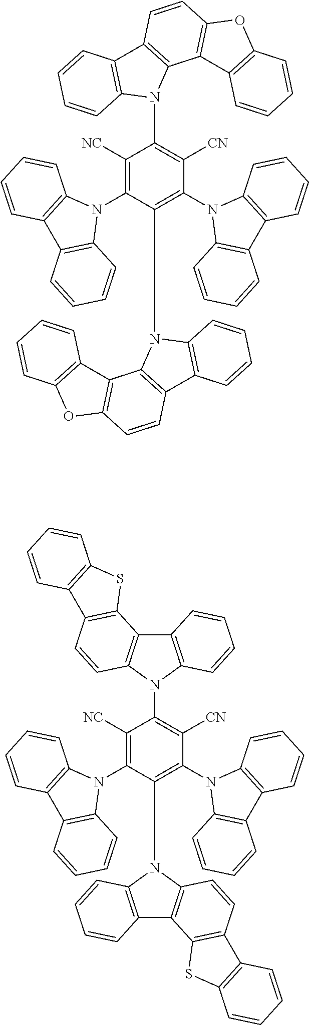 [SMILES: N#Cc1c(-n2c3ccccc3c3ccccc32)c(-n2c3ccccc3c3ccc4oc5ccccc5c4c32)c(-n2c3ccccc3c3ccccc32)c(C#N)c1-n1c2ccccc2c2ccc3oc4ccccc4c3c21 ; N#Cc1c(-n2c3ccccc3c3ccccc32)c(-n2c3ccccc3c3c4sc5ccccc5c4ccc32)c(-n2c3ccccc3c3ccccc32)c(C#N)c1-n1c2ccccc2c2c3sc4ccccc4c3ccc21]

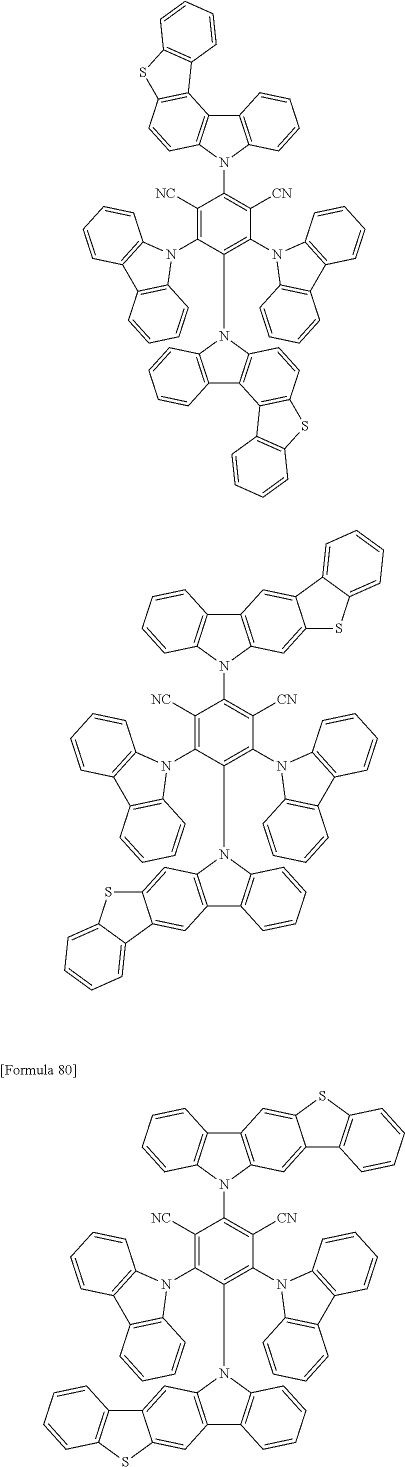 [SMILES: N#Cc1c(-n2c3ccccc3c3ccccc32)c(-n2c3ccccc3c3c4c(ccc32)sc2ccccc24)c(-n2c3ccccc3c3ccccc32)c(C#N)c1-n1c2ccccc2c2c3c(ccc21)sc1ccccc13 ; N#Cc1c(-n2c3ccccc3c3cc4c(cc32)sc2ccccc24)c(C#N)c(-n2c3ccccc3c3ccccc32)c(-n2c3ccccc3c3cc4c(cc32)sc2ccccc24)c1-n1c2ccccc2c2ccccc21 ; N#Cc1c(-n2c3ccccc3c3cc4sc5ccccc5c4cc32)c(C#N)c(-n2c3ccccc3c3ccccc32)c(-n2c3ccccc3c3cc4sc5ccccc5c4cc32)c1-n1c2ccccc2c2ccccc21]

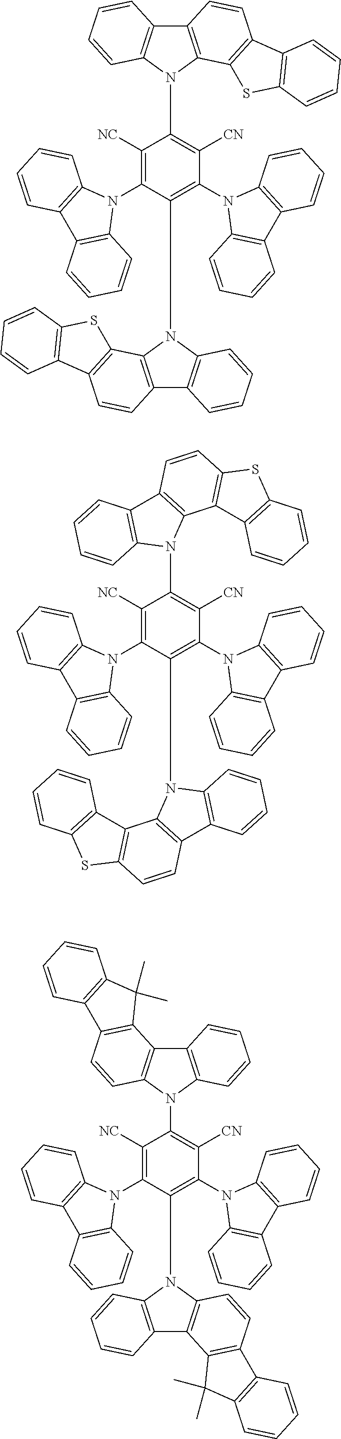

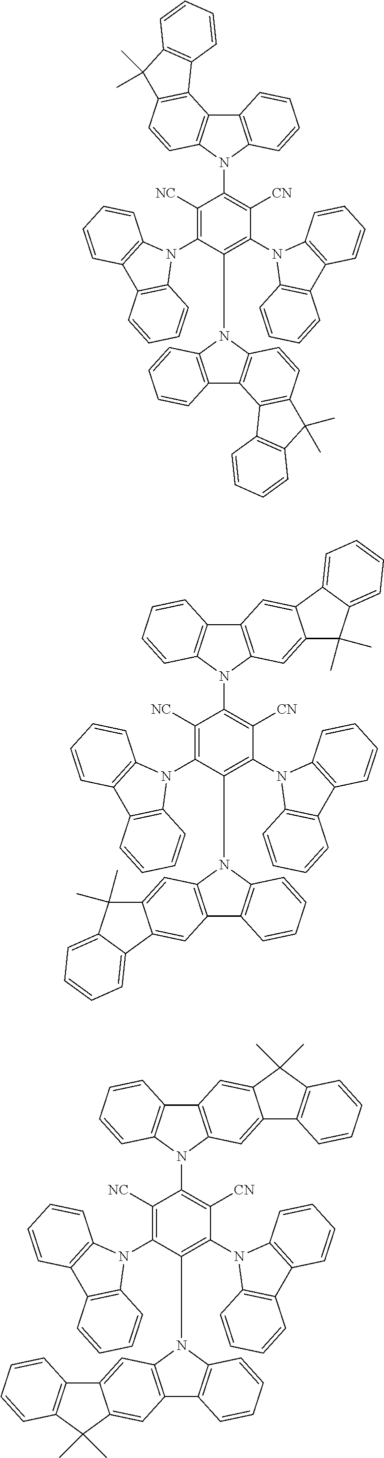 [SMILES: CC1(C)c2ccccc2-c2c1ccc1c2c2ccccc2n1-c1c(C#N)c(-n2c3ccccc3c3ccccc32)c(-n2c3ccccc3c3c4c(ccc32)C(C)(C)c2ccccc2-4)c(-n2c3ccccc3c3ccccc32)c1C#N ; CC1(C)c2ccccc2-c2cc3c4ccccc4n(-c4c(C#N)c(-n5c6ccccc6c6ccccc65)c(-n5c6ccccc6c6cc7c(cc65)C(C)(C)c5ccccc5-7)c(-n5c6ccccc6c6ccccc65)c4C#N)c3cc21 ; CC1(C)c2ccccc2-c2cc3c(cc21)c1ccccc1n3-c1c(C#N)c(-n2c3ccccc3c3ccccc32)c(-n2c3ccccc3c3cc4c(cc32)-c2ccccc2C4(C)C)c(-n2c3ccccc3c3ccccc32)c1C#N]

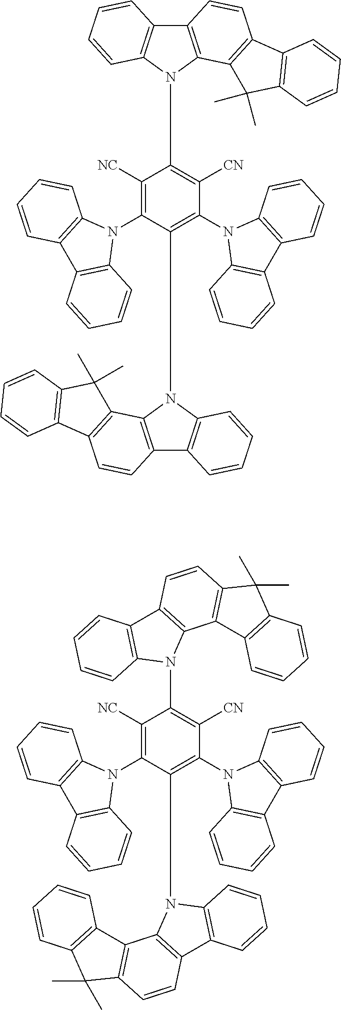 [SMILES: CC1(C)c2ccccc2-c2ccc3c4ccccc4n(-c4c(C#N)c(-n5c6ccccc6c6ccccc65)c(-n5c6ccccc6c6ccc7c(c65)C(C)(C)c5ccccc5-7)c(-n5c6ccccc6c6ccccc65)c4C#N)c3c21 ; CC1(C)c2ccccc2-c2c1ccc1c3ccccc3n(-c3c(C#N)c(-n4c5ccccc5c5ccccc54)c(-n4c5ccccc5c5ccc6c(c54)-c4ccccc4C6(C)C)c(-n4c5ccccc5c5ccccc54)c3C#N)c21]

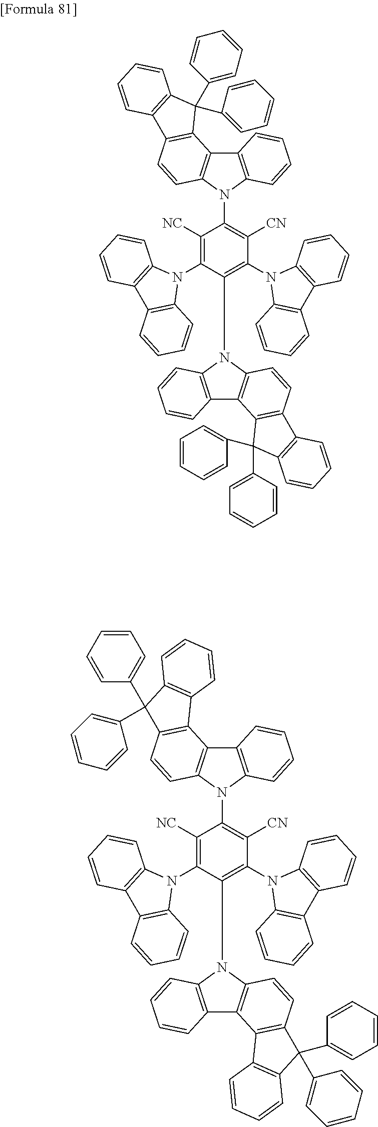 [SMILES: N#Cc1c(-n2c3ccccc3c3ccccc32)c(-n2c3ccccc3c3c4c(ccc32)-c2ccccc2C4(c2ccccc2)c2ccccc2)c(-n2c3ccccc3c3ccccc32)c(C#N)c1-n1c2ccccc2c2c3c(ccc21)-c1ccccc1C3(c1ccccc1)c1ccccc1 ; N#Cc1c(-n2c3ccccc3c3ccccc32)c(-n2c3ccccc3c3c4c(ccc32)C(c2ccccc2)(c2ccccc2)c2ccccc2-4)c(-n2c3ccccc3c3ccccc32)c(C#N)c1-n1c2ccccc2c2c3c(ccc21)C(c1ccccc1)(c1ccccc1)c1ccccc1-3]

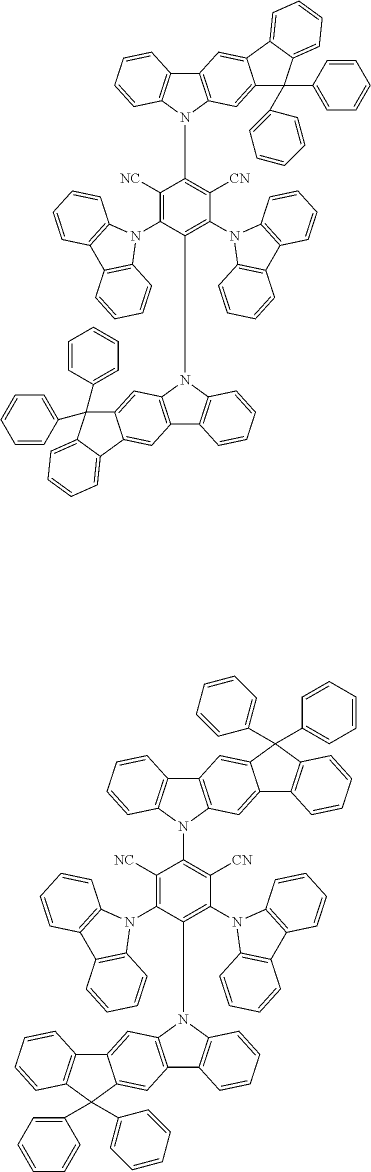 [SMILES: N#Cc1c(-n2c3ccccc3c3cc4c(cc32)C(c2ccccc2)(c2ccccc2)c2ccccc2-4)c(C#N)c(-n2c3ccccc3c3ccccc32)c(-n2c3ccccc3c3cc4c(cc32)C(c2ccccc2)(c2ccccc2)c2ccccc2-4)c1-n1c2ccccc2c2ccccc21 ; N#Cc1c(-n2c3ccccc3c3cc4c(cc32)-c2ccccc2C4(c2ccccc2)c2ccccc2)c(C#N)c(-n2c3ccccc3c3ccccc32)c(-n2c3ccccc3c3cc4c(cc32)-c2ccccc2C4(c2ccccc2)c2ccccc2)c1-n1c2ccccc2c2ccccc21]

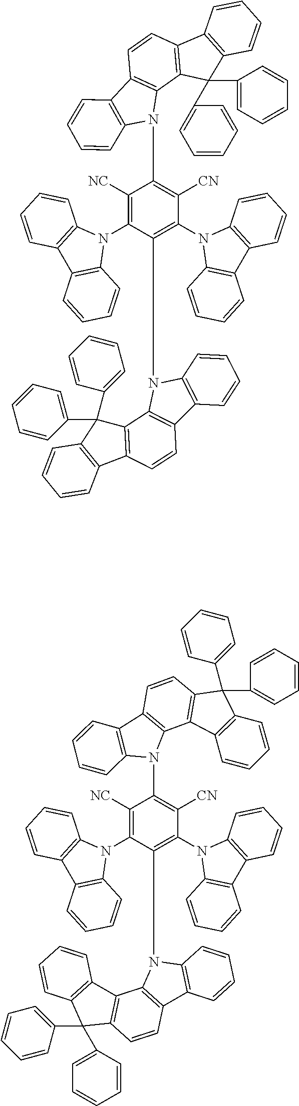 [SMILES: N#Cc1c(-n2c3ccccc3c3ccccc32)c(-n2c3ccccc3c3ccc4c(c32)C(c2ccccc2)(c2ccccc2)c2ccccc2-4)c(-n2c3ccccc3c3ccccc32)c(C#N)c1-n1c2ccccc2c2ccc3c(c21)C(c1ccccc1)(c1ccccc1)c1ccccc1-3 ; N#Cc1c(-n2c3ccccc3c3ccccc32)c(-n2c3ccccc3c3ccc4c(c32)-c2ccccc2C4(c2ccccc2)c2ccccc2)c(-n2c3ccccc3c3ccccc32)c(C#N)c1-n1c2ccccc2c2ccc3c(c21)-c1ccccc1C3(c1ccccc1)c1ccccc1]

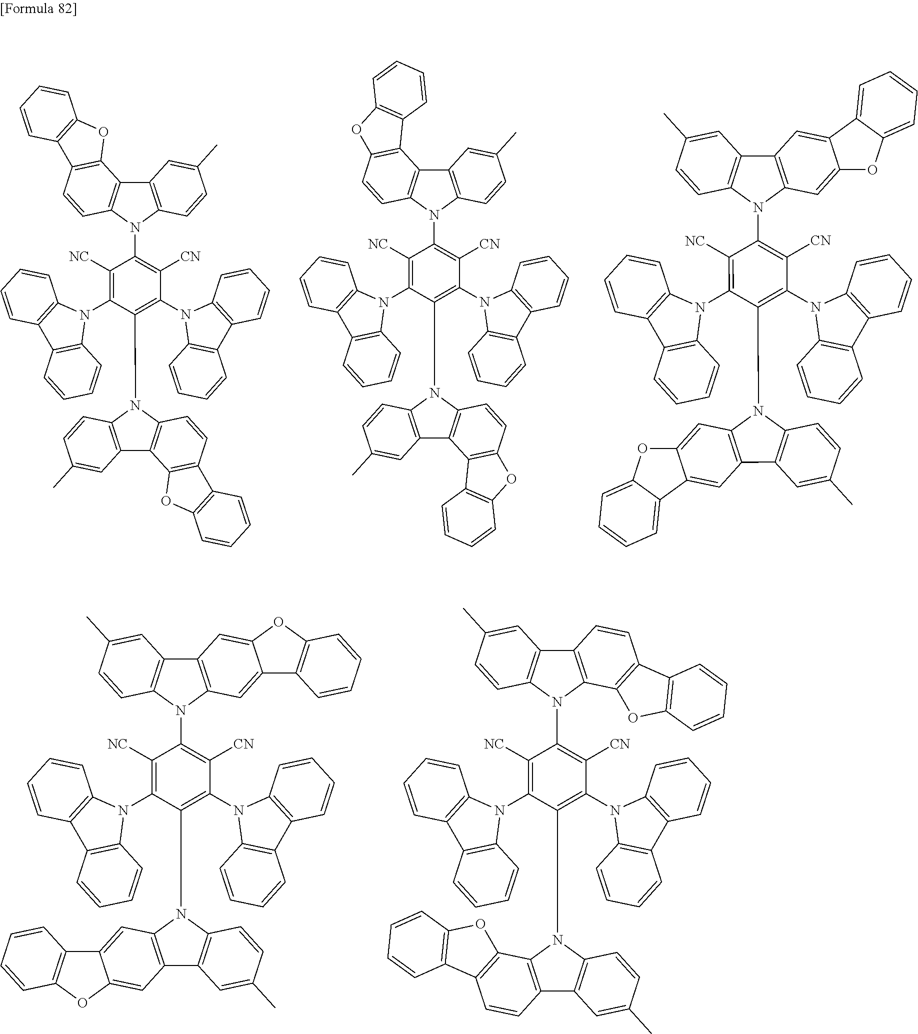

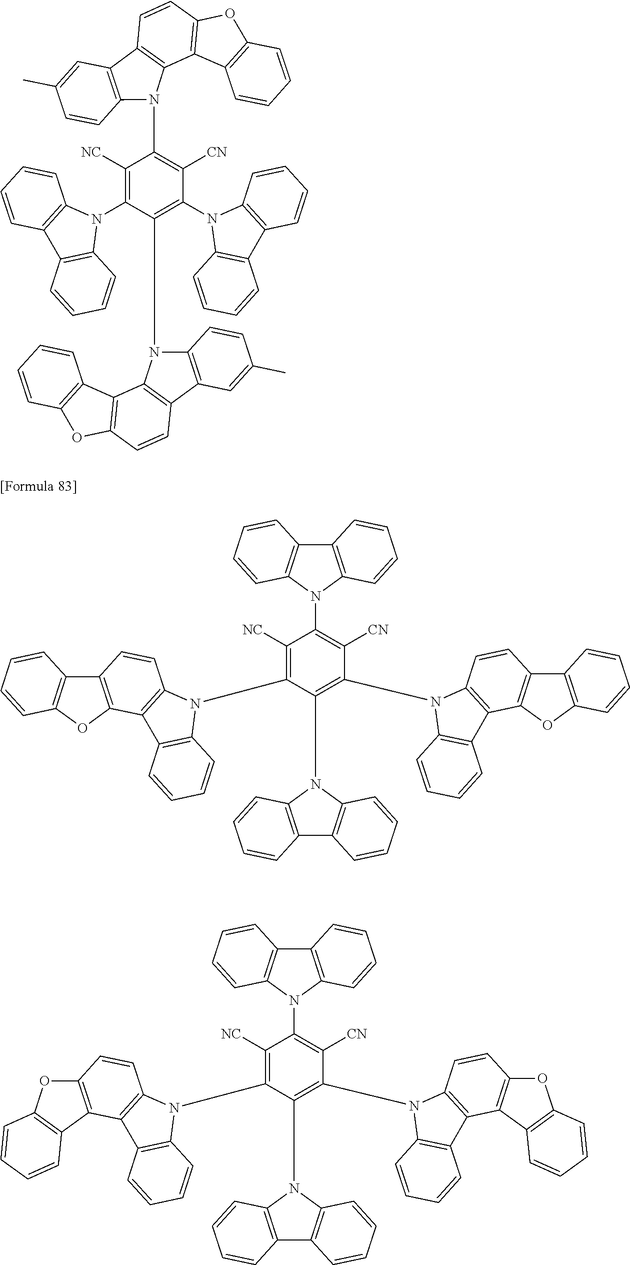 [SMILES: Cc1ccc2c(c1)c1ccc3oc4ccccc4c3c1n2-c1c(C#N)c(-n2c3ccccc3c3ccccc32)c(-n2c3ccc(C)cc3c3ccc4oc5ccccc5c4c32)c(-n2c3ccccc3c3ccccc32)c1C#N ; N#Cc1c(-n2c3ccccc3c3ccccc32)c(C#N)c(-n2c3ccccc3c3c4oc5ccccc5c4ccc32)c(-n2c3ccccc3c3ccccc32)c1-n1c2ccccc2c2c3oc4ccccc4c3ccc21 ; N#Cc1c(-n2c3ccccc3c3ccccc32)c(C#N)c(-n2c3ccccc3c3c4c(ccc32)oc2ccccc24)c(-n2c3ccccc3c3ccccc32)c1-n1c2ccccc2c2c3c(ccc21)oc1ccccc13]

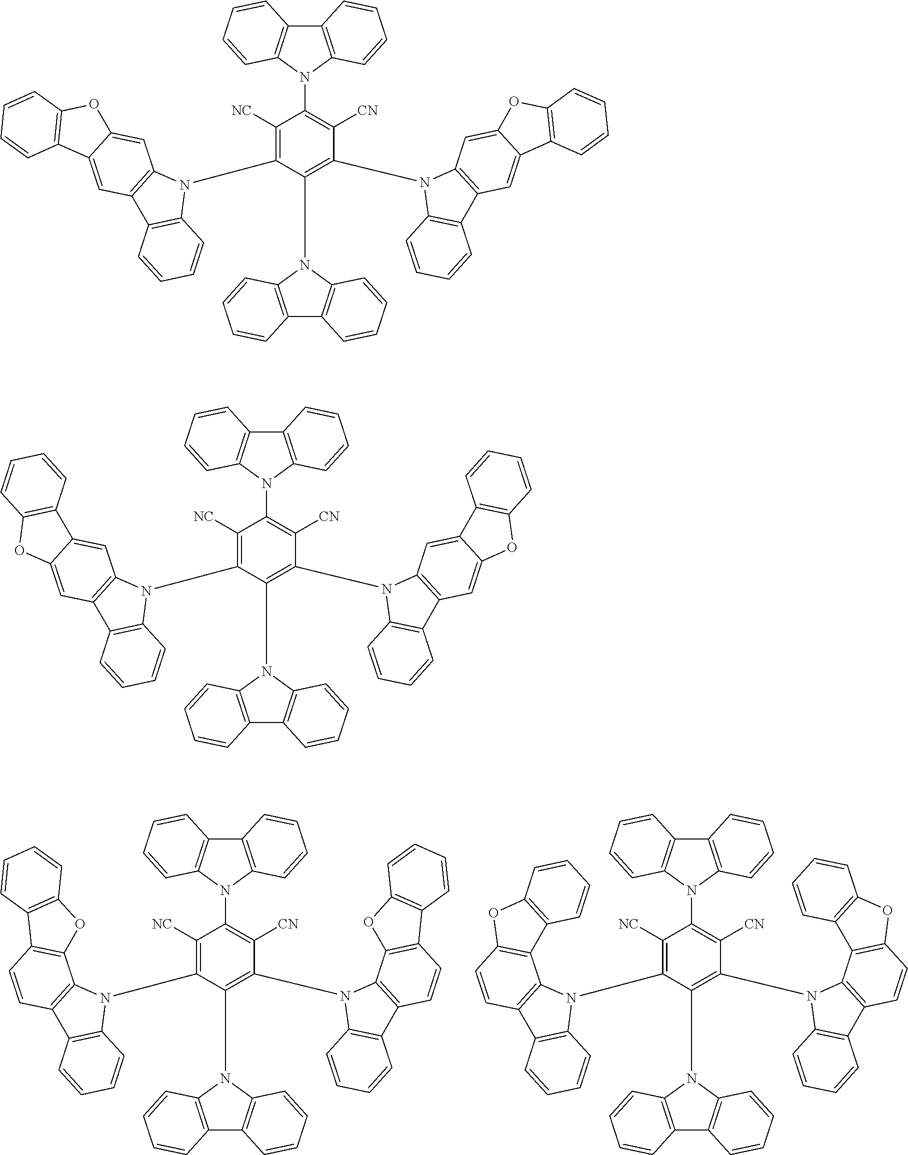

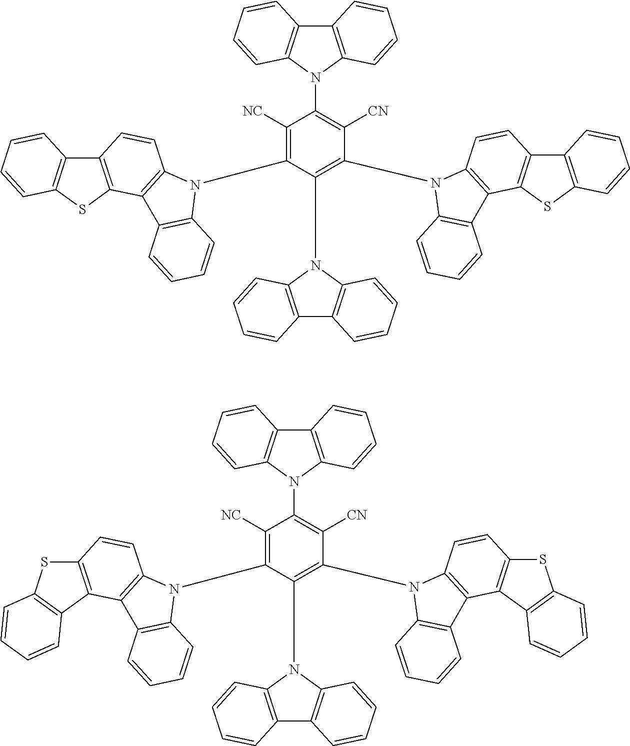 [SMILES: N#Cc1c(-n2c3ccccc3c3ccccc32)c(C#N)c(-n2c3ccccc3c3c4sc5ccccc5c4ccc32)c(-n2c3ccccc3c3ccccc32)c1-n1c2ccccc2c2c3sc4ccccc4c3ccc21 ; N#Cc1c(-n2c3ccccc3c3ccccc32)c(C#N)c(-n2c3ccccc3c3c4c(ccc32)sc2ccccc24)c(-n2c3ccccc3c3ccccc32)c1-n1c2ccccc2c2c3c(ccc21)sc1ccccc13]

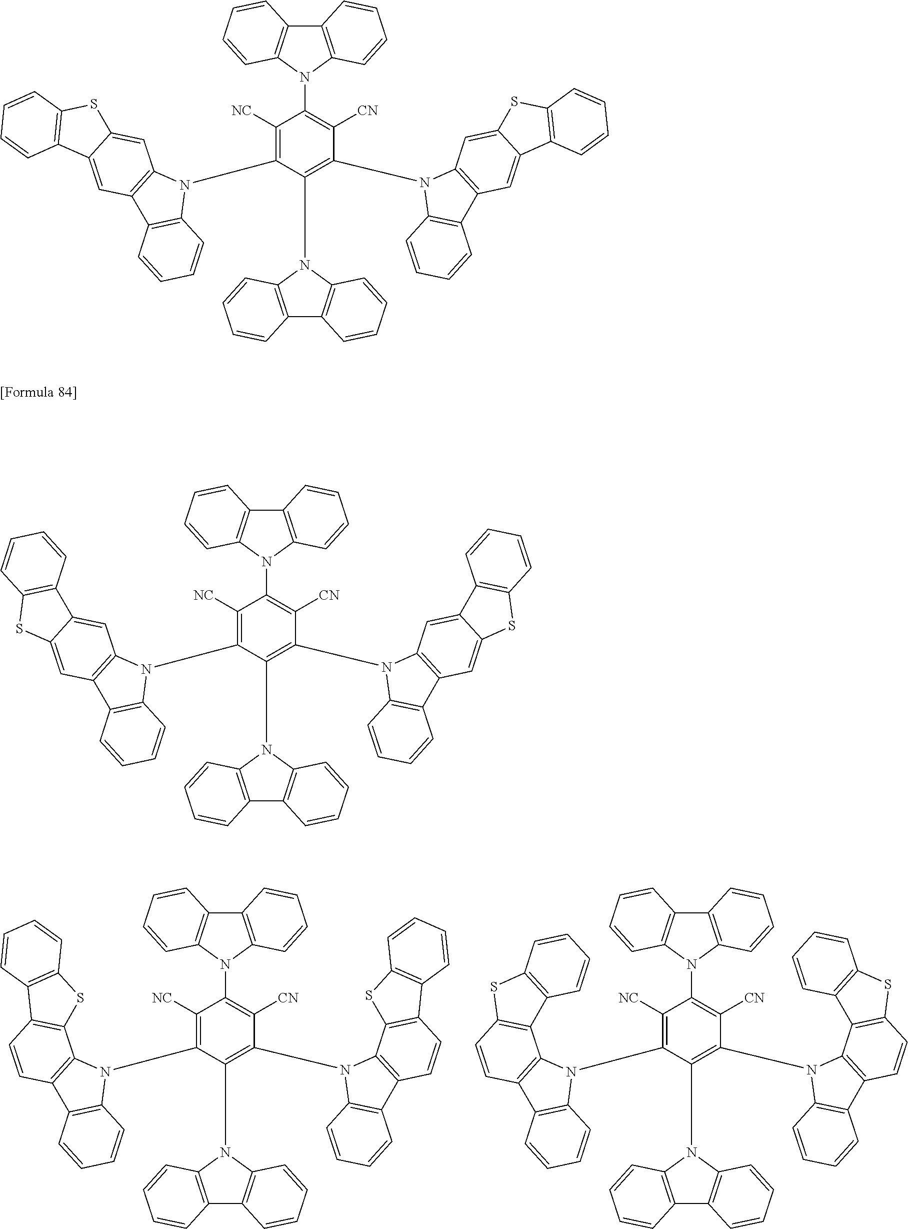

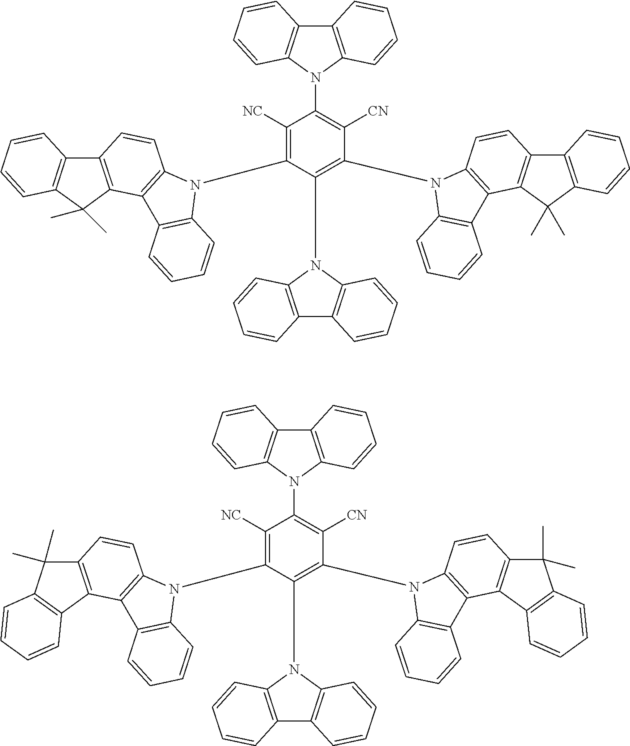 [SMILES: CC1(C)c2ccccc2-c2ccc3c(c21)c1ccccc1n3-c1c(C#N)c(-n2c3ccccc3c3ccccc32)c(C#N)c(-n2c3ccccc3c3c4c(ccc32)-c2ccccc2C4(C)C)c1-n1c2ccccc2c2ccccc21 ; CC1(C)c2ccccc2-c2c1ccc1c2c2ccccc2n1-c1c(C#N)c(-n2c3ccccc3c3ccccc32)c(C#N)c(-n2c3ccccc3c3c4c(ccc32)C(C)(C)c2ccccc2-4)c1-n1c2ccccc2c2ccccc21]

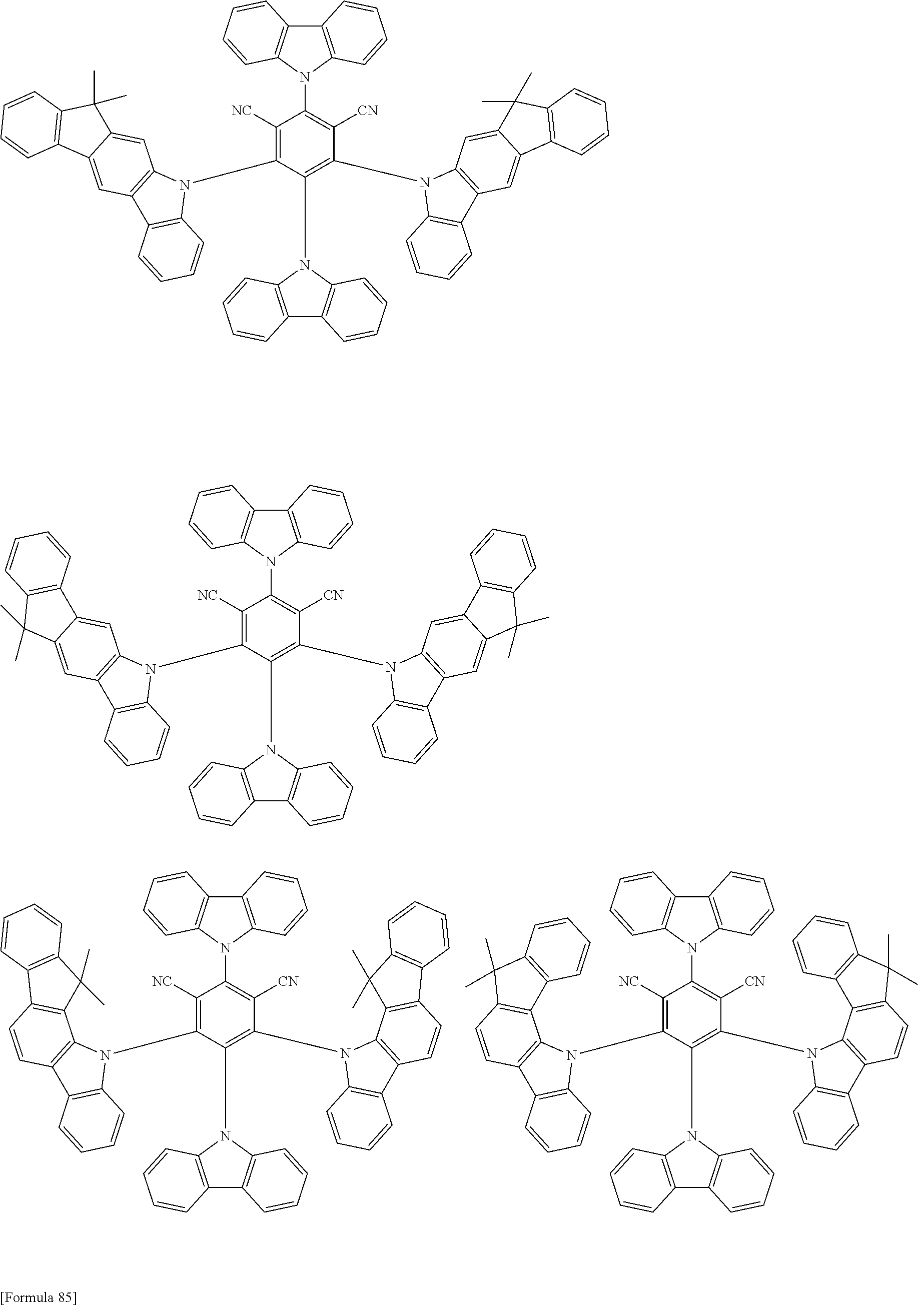

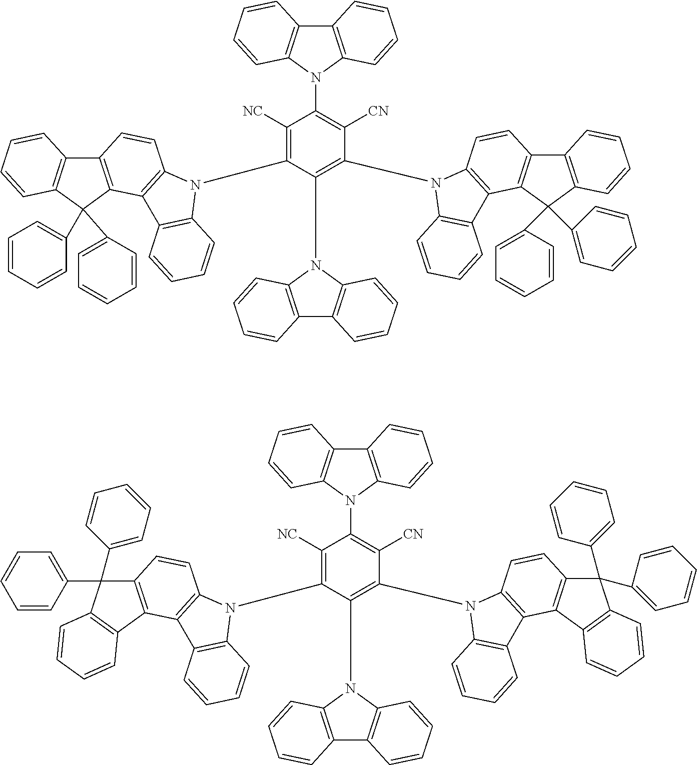 [SMILES: N#Cc1c(-n2c3ccccc3c3ccccc32)c(C#N)c(-n2c3ccccc3c3c4c(ccc32)-c2ccccc2C4(c2ccccc2)c2ccccc2)c(-n2c3ccccc3c3ccccc32)c1-n1c2ccccc2c2c3c(ccc21)-c1ccccc1C3(c1ccccc1)c1ccccc1 ; N#Cc1c(-n2c3ccccc3c3ccccc32)c(C#N)c(-n2c3ccccc3c3c4c(ccc32)C(c2ccccc2)(c2ccccc2)c2ccccc2-4)c(-n2c3ccccc3c3ccccc32)c1-n1c2ccccc2c2c3c(ccc21)C(c1ccccc1)(c1ccccc1)c1ccccc1-3]

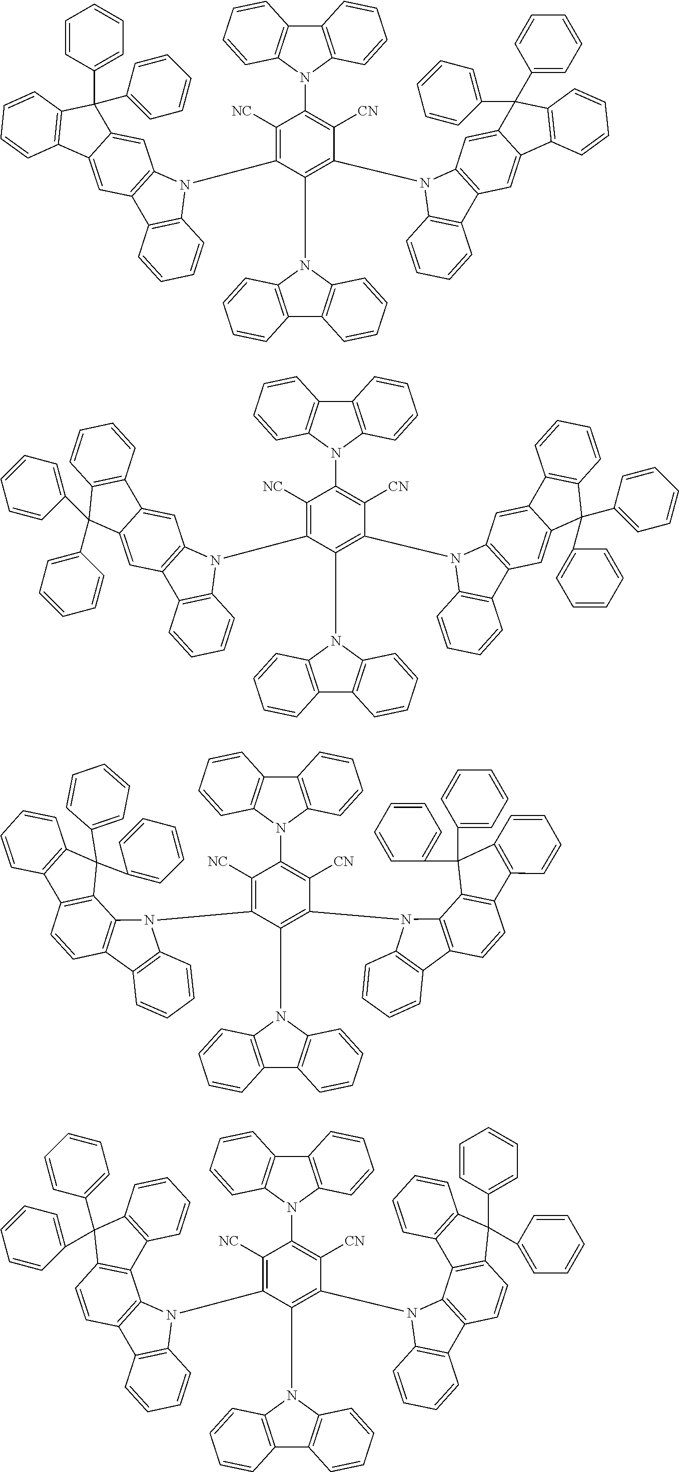

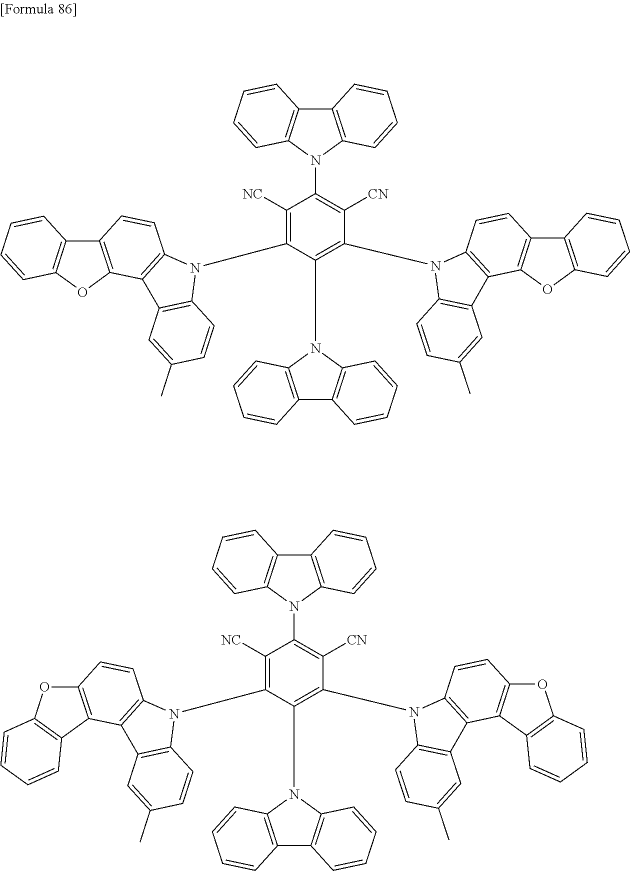 [SMILES: Cc1ccc2c(c1)c1c3oc4ccccc4c3ccc1n2-c1c(C#N)c(-n2c3ccccc3c3ccccc32)c(C#N)c(-n2c3ccc(C)cc3c3c4oc5ccccc5c4ccc32)c1-n1c2ccccc2c2ccccc21 ; Cc1ccc2c(c1)c1c3c(ccc1n2-c1c(C#N)c(-n2c4ccccc4c4ccccc42)c(C#N)c(-n2c4ccc(C)cc4c4c5c(ccc42)oc2ccccc25)c1-n1c2ccccc2c2ccccc21)oc1ccccc13]

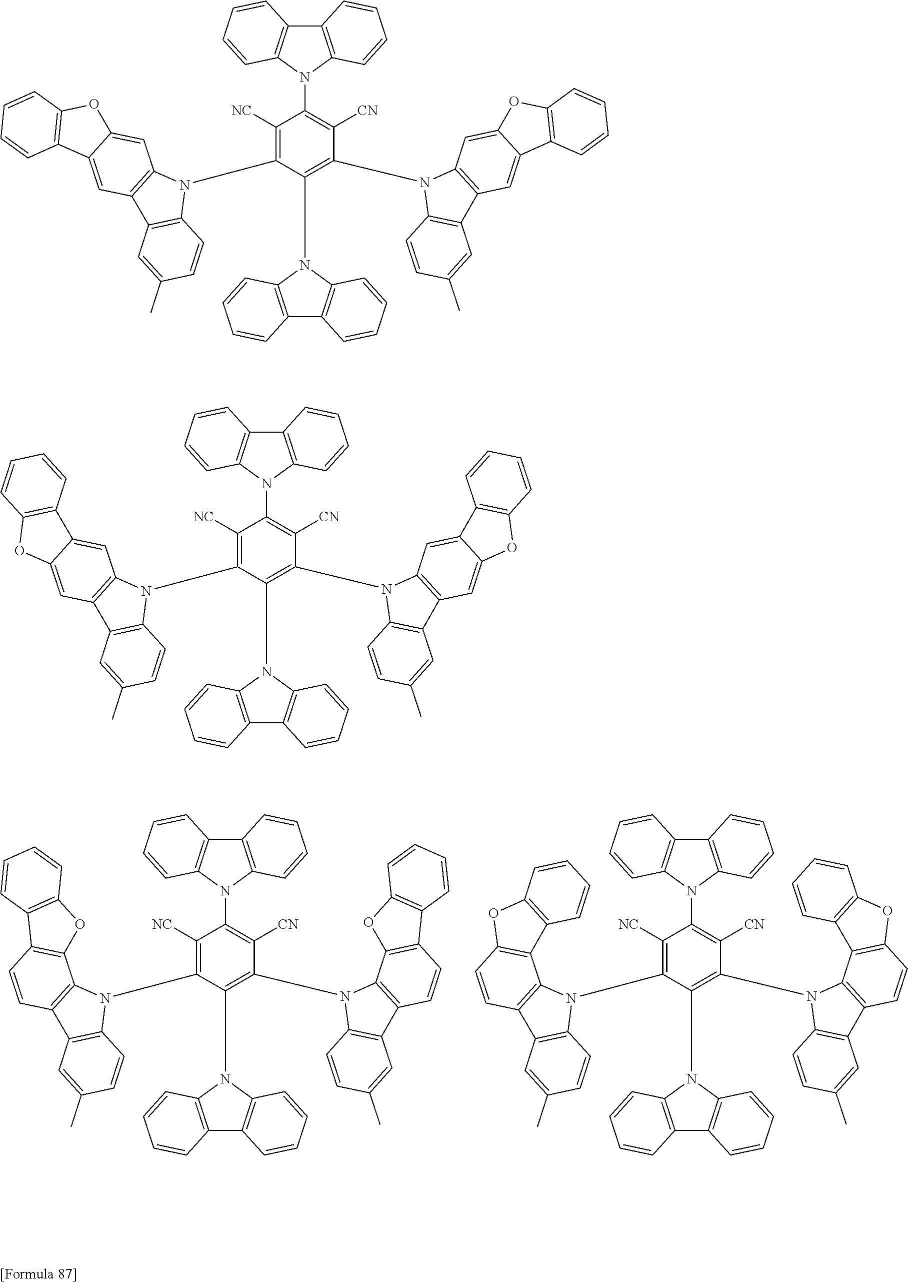

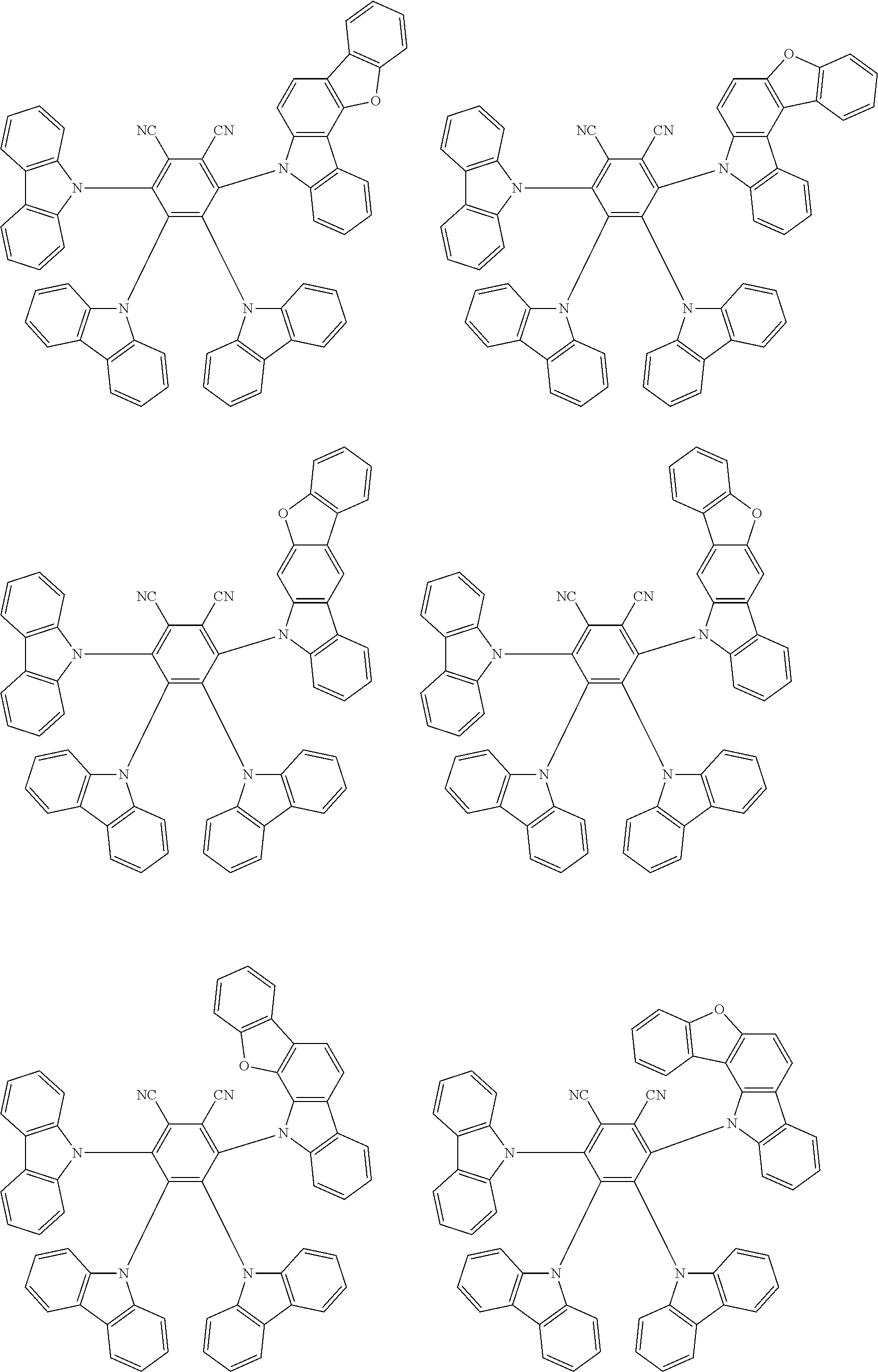

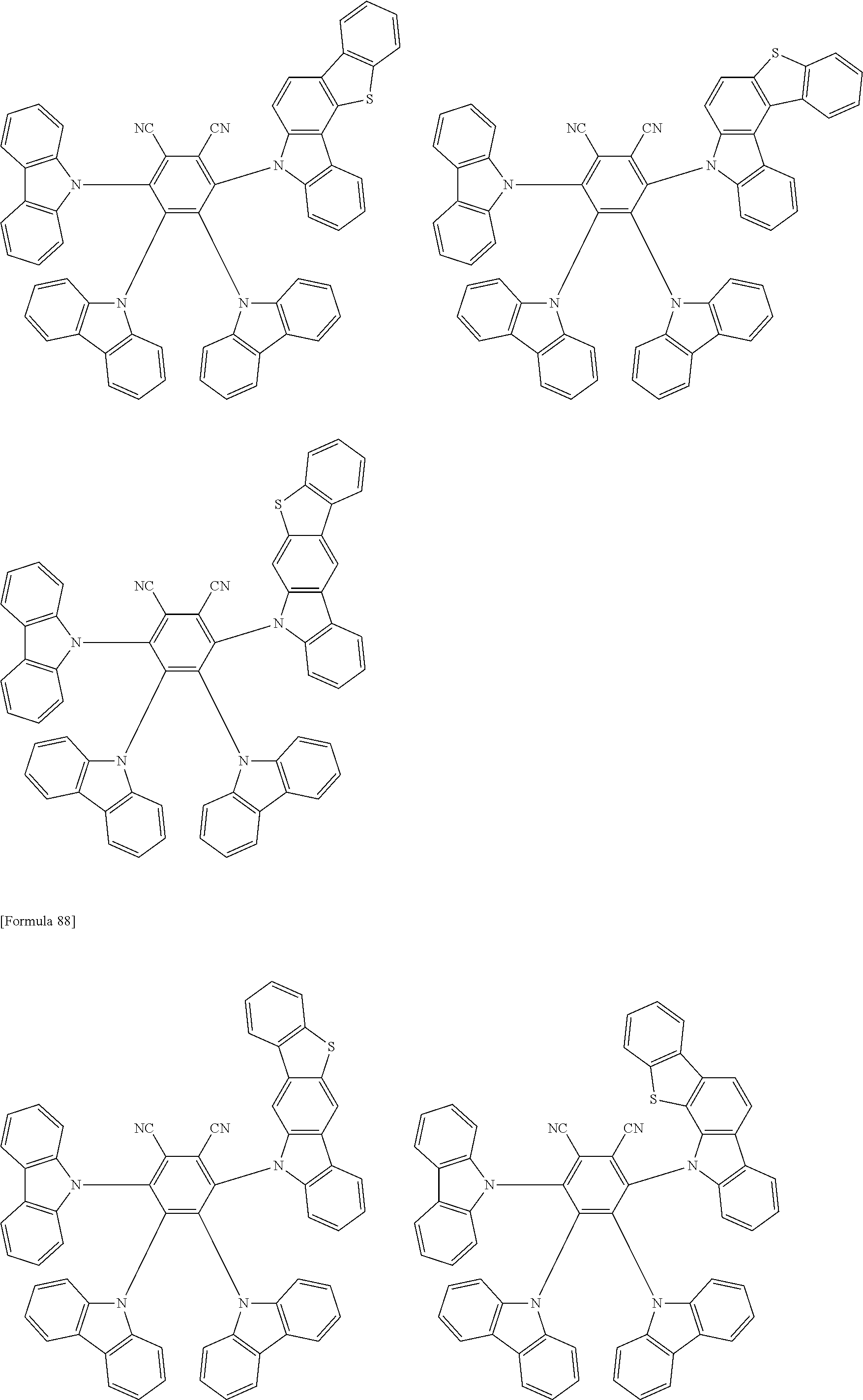

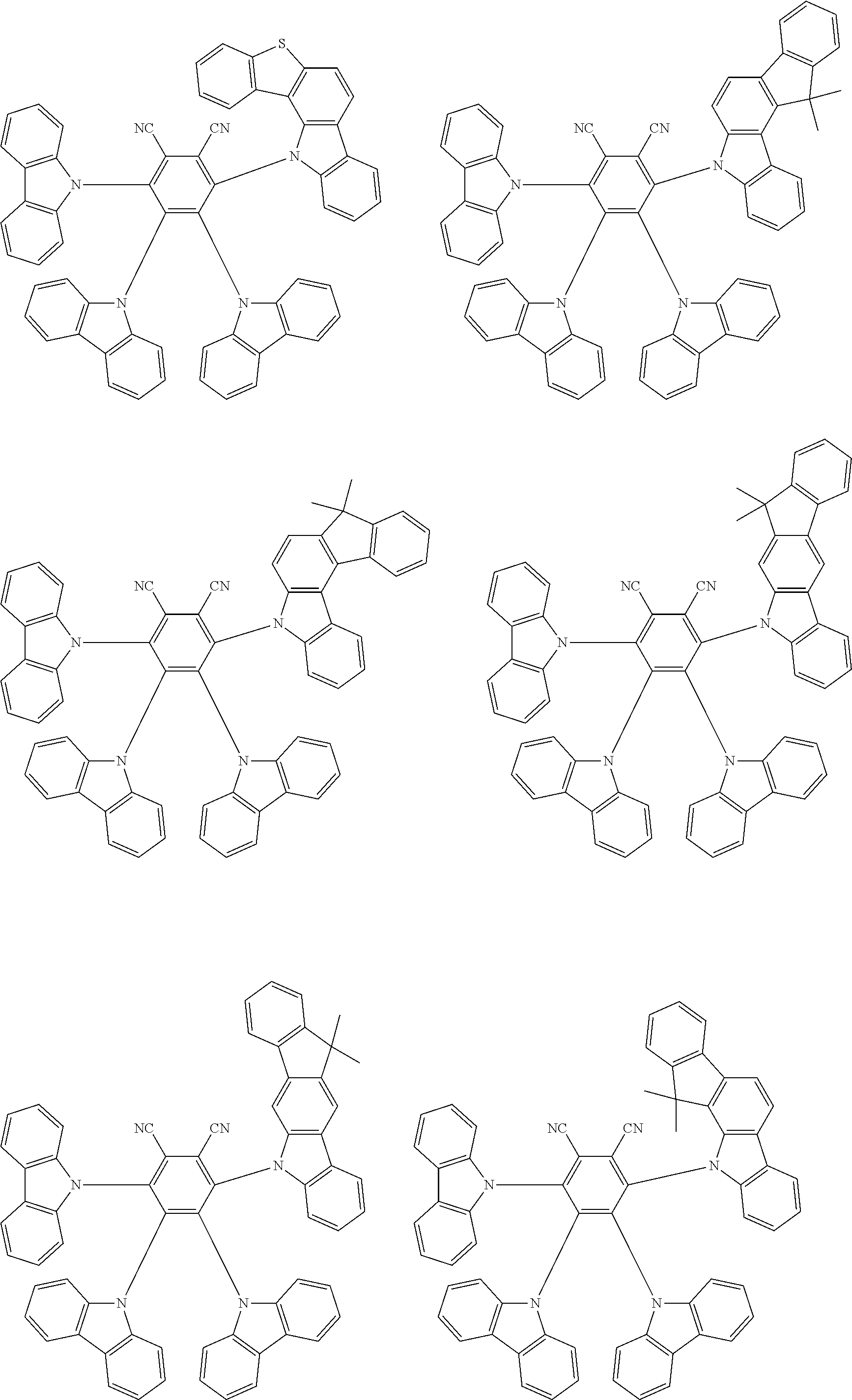

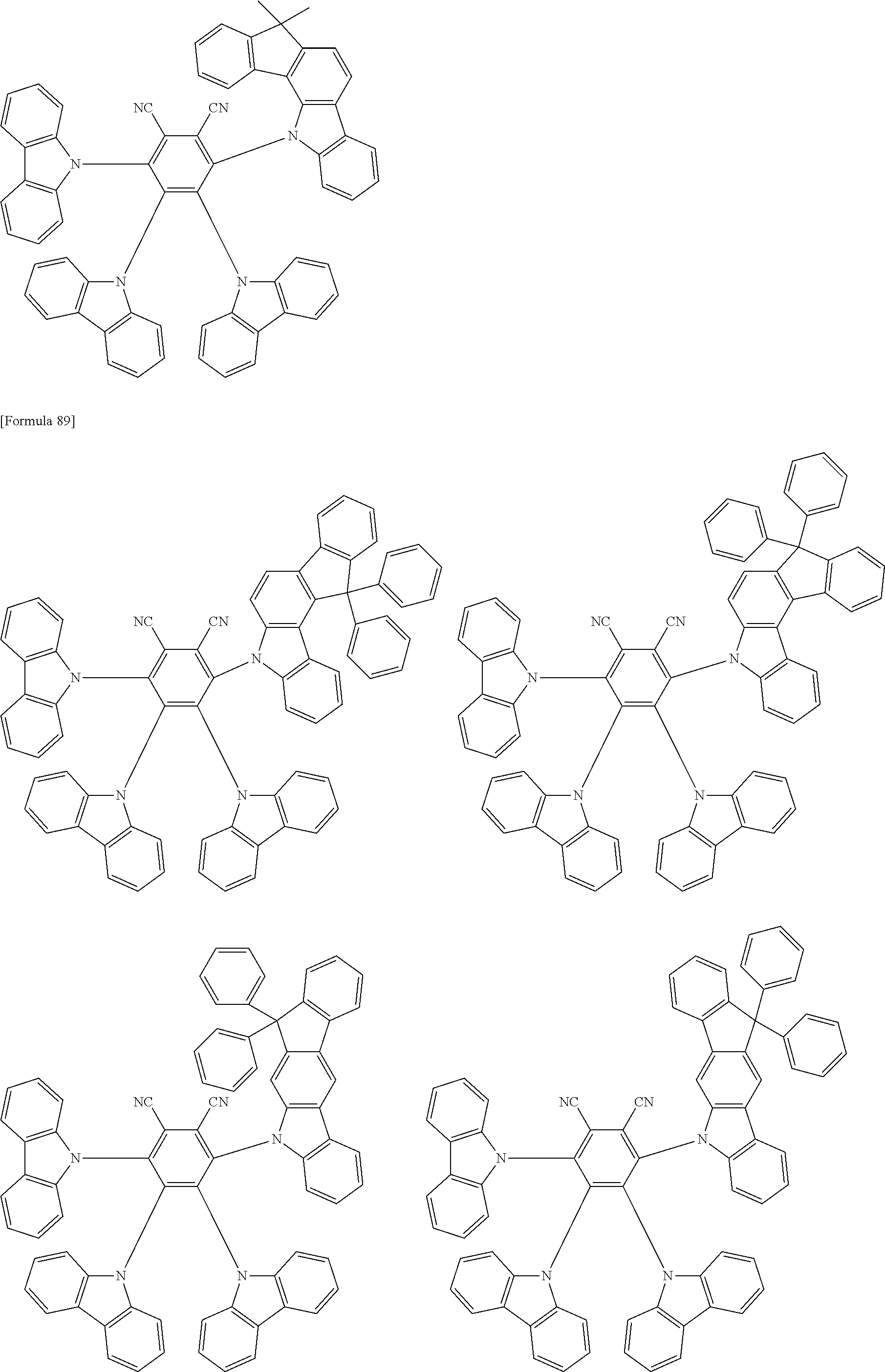

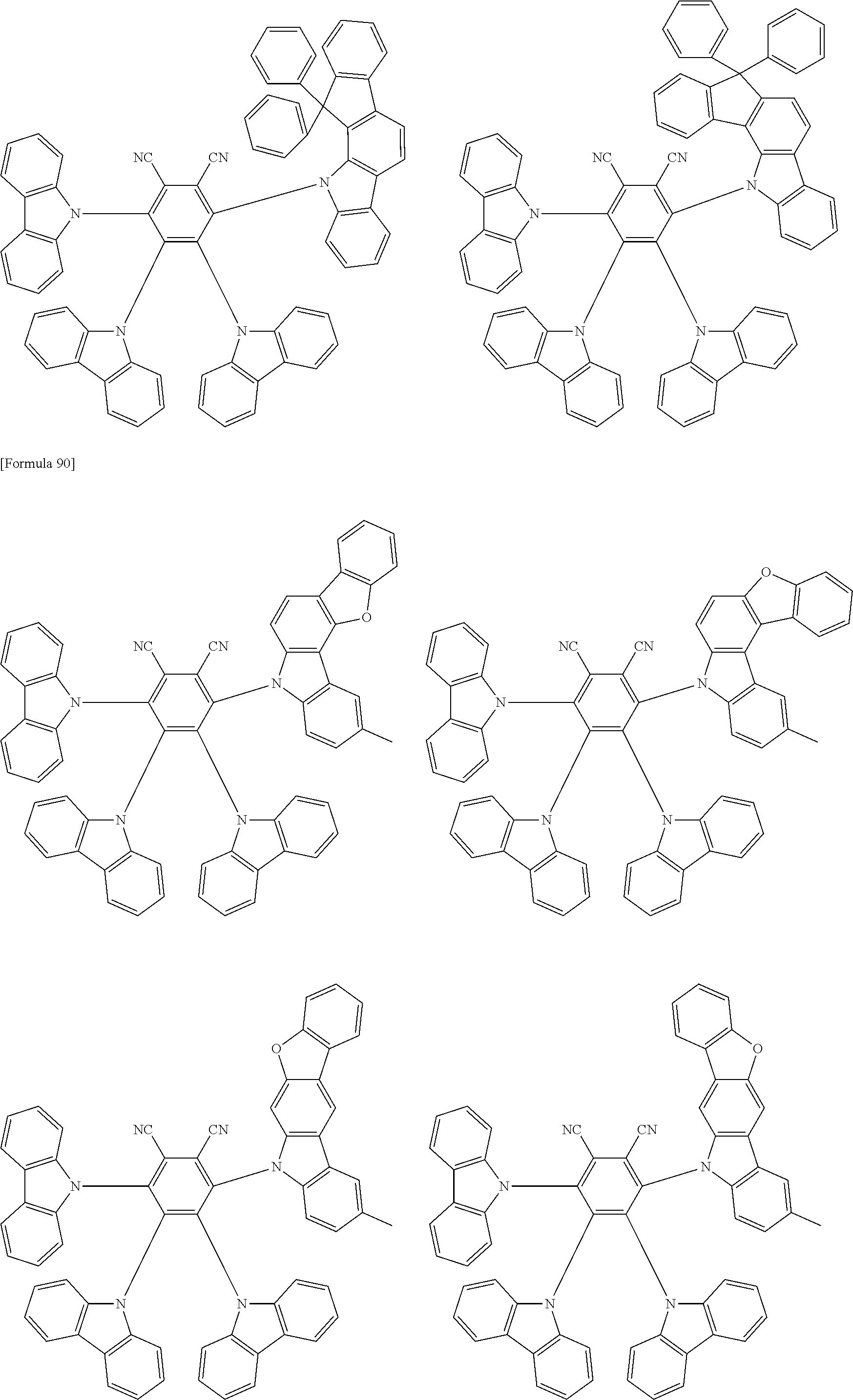

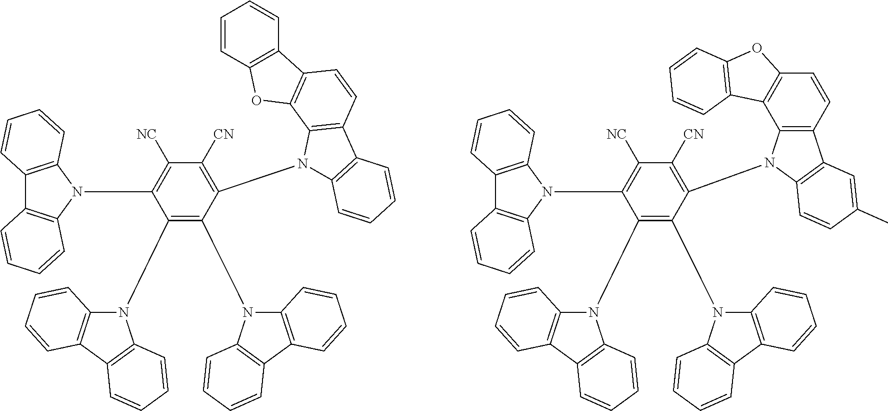 [SMILES: N#Cc1c(C#N)c(-n2c3ccccc3c3ccc4c5ccccc5oc4c32)c(-n2c3ccccc3c3ccccc32)c(-n2c3ccccc3c3ccccc32)c1-n1c2ccccc2c2ccccc21 ; Cc1ccc2c(c1)c1ccc3oc4ccccc4c3c1n2-c1c(C#N)c(C#N)c(-n2c3ccccc3c3ccccc32)c(-n2c3ccccc3c3ccccc32)c1-n1c2ccccc2c2ccccc21]

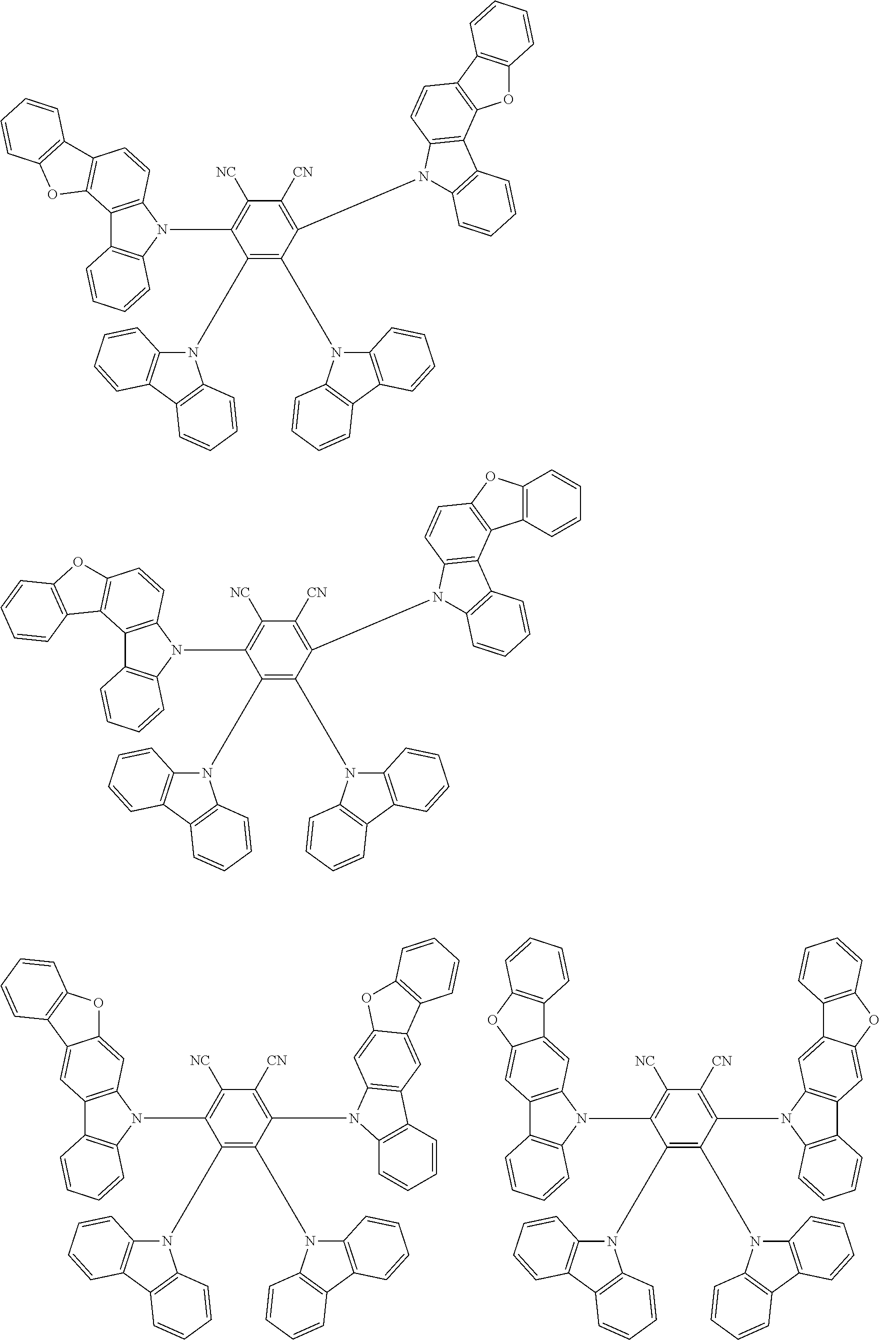

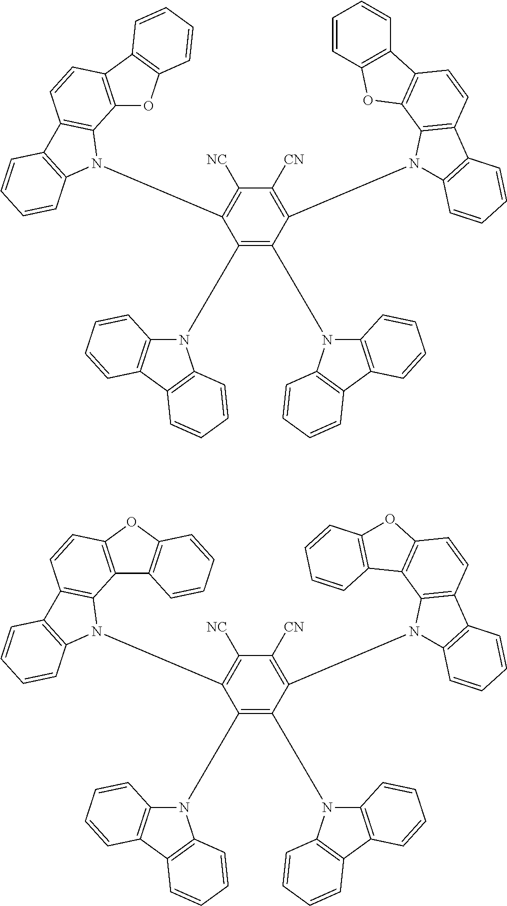 [SMILES: N#Cc1c(C#N)c(-n2c3ccccc3c3ccc4c5ccccc5oc4c32)c(-n2c3ccccc3c3ccccc32)c(-n2c3ccccc3c3ccccc32)c1-n1c2ccccc2c2ccc3c4ccccc4oc3c21 ; N#Cc1c(C#N)c(-n2c3ccccc3c3ccc4oc5ccccc5c4c32)c(-n2c3ccccc3c3ccccc32)c(-n2c3ccccc3c3ccccc32)c1-n1c2ccccc2c2ccc3oc4ccccc4c3c21]

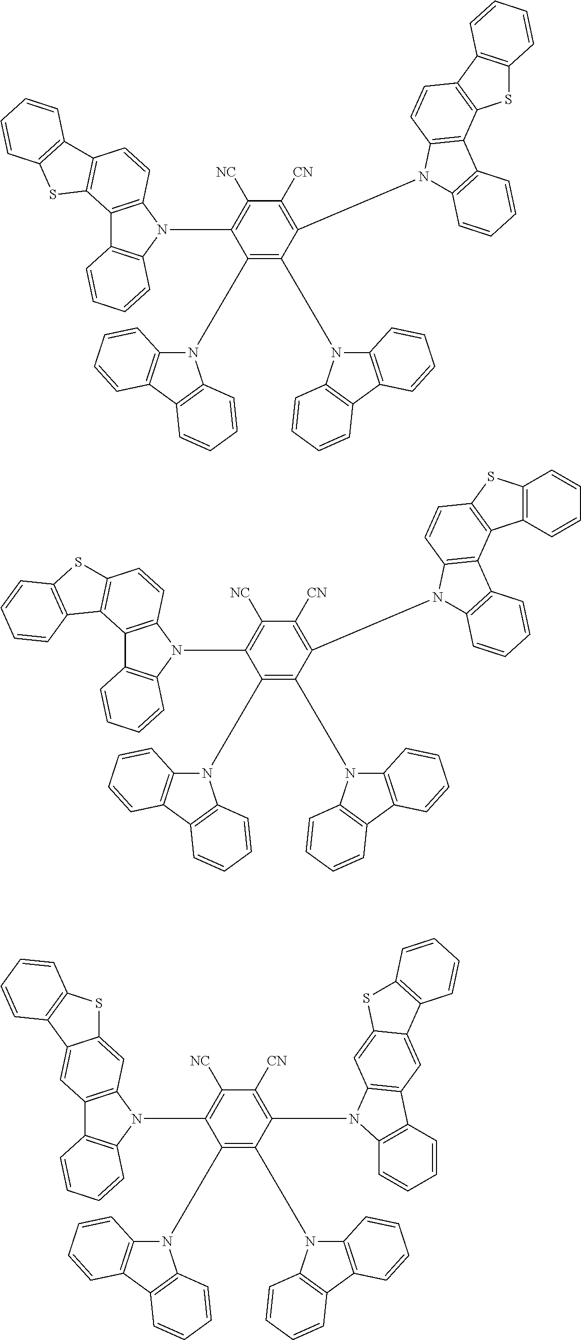 [SMILES: N#Cc1c(C#N)c(-n2c3ccccc3c3c4sc5ccccc5c4ccc32)c(-n2c3ccccc3c3ccccc32)c(-n2c3ccccc3c3ccccc32)c1-n1c2ccccc2c2c3sc4ccccc4c3ccc21 ; N#Cc1c(C#N)c(-n2c3ccccc3c3c4c(ccc32)sc2ccccc24)c(-n2c3ccccc3c3ccccc32)c(-n2c3ccccc3c3ccccc32)c1-n1c2ccccc2c2c3c(ccc21)sc1ccccc13 ; N#Cc1c(C#N)c(-n2c3ccccc3c3cc4c(cc32)sc2ccccc24)c(-n2c3ccccc3c3ccccc32)c(-n2c3ccccc3c3ccccc32)c1-n1c2ccccc2c2cc3c(cc21)sc1ccccc13]

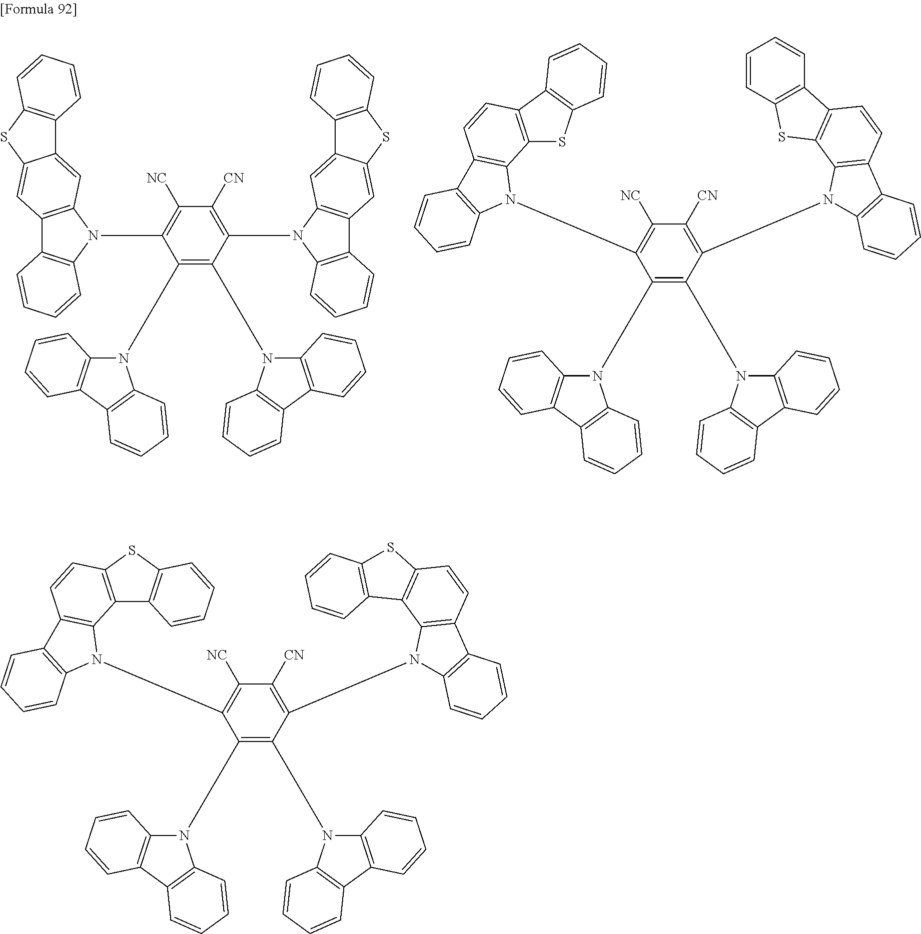 [SMILES: N#Cc1c(C#N)c(-n2c3ccccc3c3cc4sc5ccccc5c4cc32)c(-n2c3ccccc3c3ccccc32)c(-n2c3ccccc3c3ccccc32)c1-n1c2ccccc2c2cc3sc4ccccc4c3cc21 ; N#Cc1c(C#N)c(-n2c3ccccc3c3ccc4c5ccccc5sc4c32)c(-n2c3ccccc3c3ccccc32)c(-n2c3ccccc3c3ccccc32)c1-n1c2ccccc2c2ccc3c4ccccc4sc3c21 ; N#Cc1c(C#N)c(-n2c3ccccc3c3ccc4sc5ccccc5c4c32)c(-n2c3ccccc3c3ccccc32)c(-n2c3ccccc3c3ccccc32)c1-n1c2ccccc2c2ccc3sc4ccccc4c3c21]

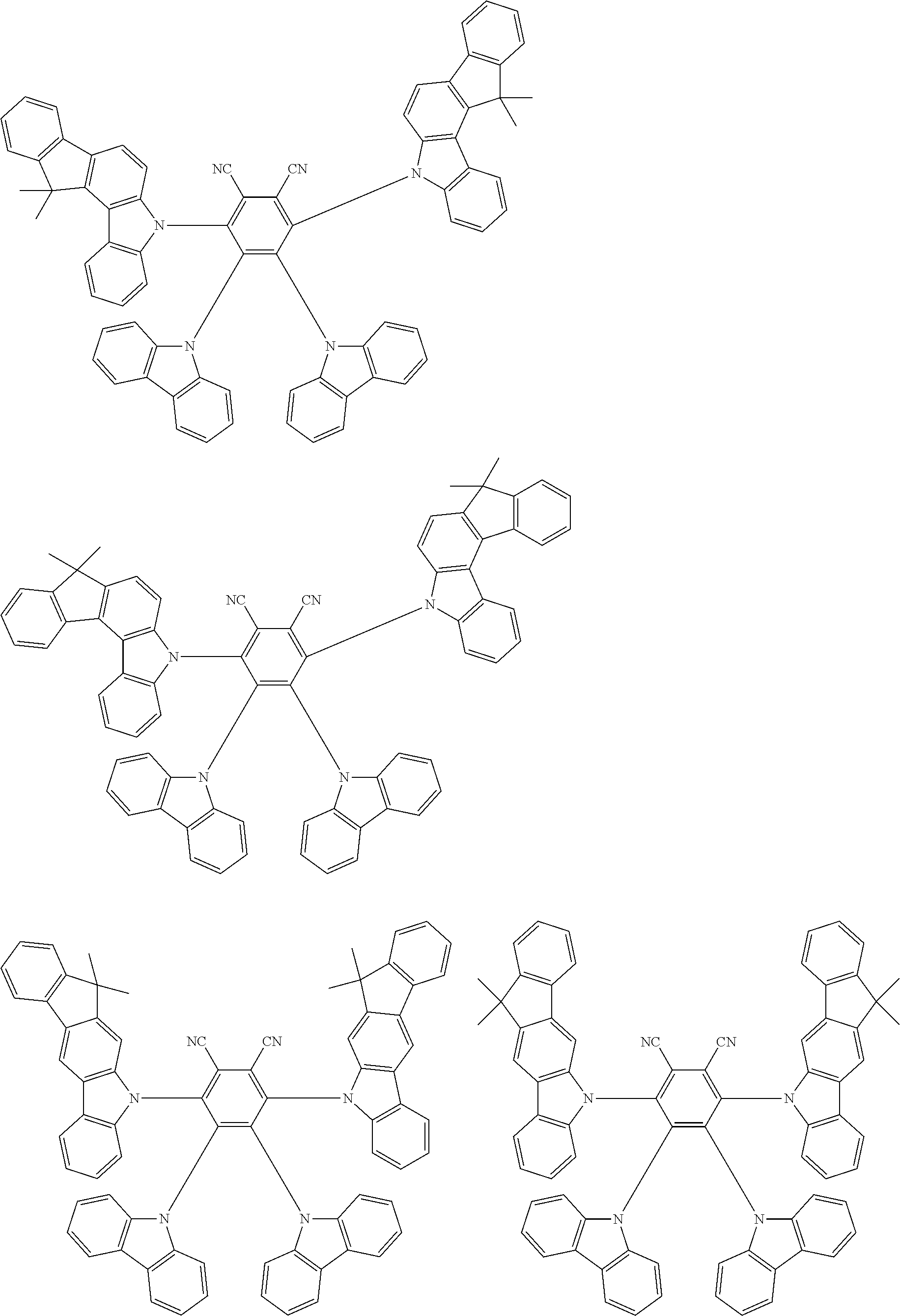

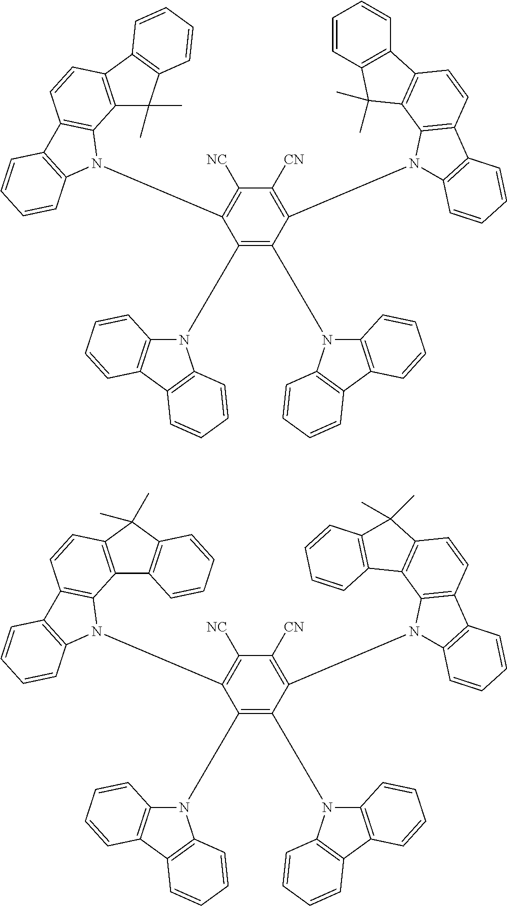 [SMILES: CC1(C)c2ccccc2-c2ccc3c4ccccc4n(-c4c(C#N)c(C#N)c(-n5c6ccccc6c6ccc7c(c65)C(C)(C)c5ccccc5-7)c(-n5c6ccccc6c6ccccc65)c4-n4c5ccccc5c5ccccc54)c3c21 ; CC1(C)c2ccccc2-c2c1ccc1c3ccccc3n(-c3c(C#N)c(C#N)c(-n4c5ccccc5c5ccc6c(c54)-c4ccccc4C6(C)C)c(-n4c5ccccc5c5ccccc54)c3-n3c4ccccc4c4ccccc43)c21]

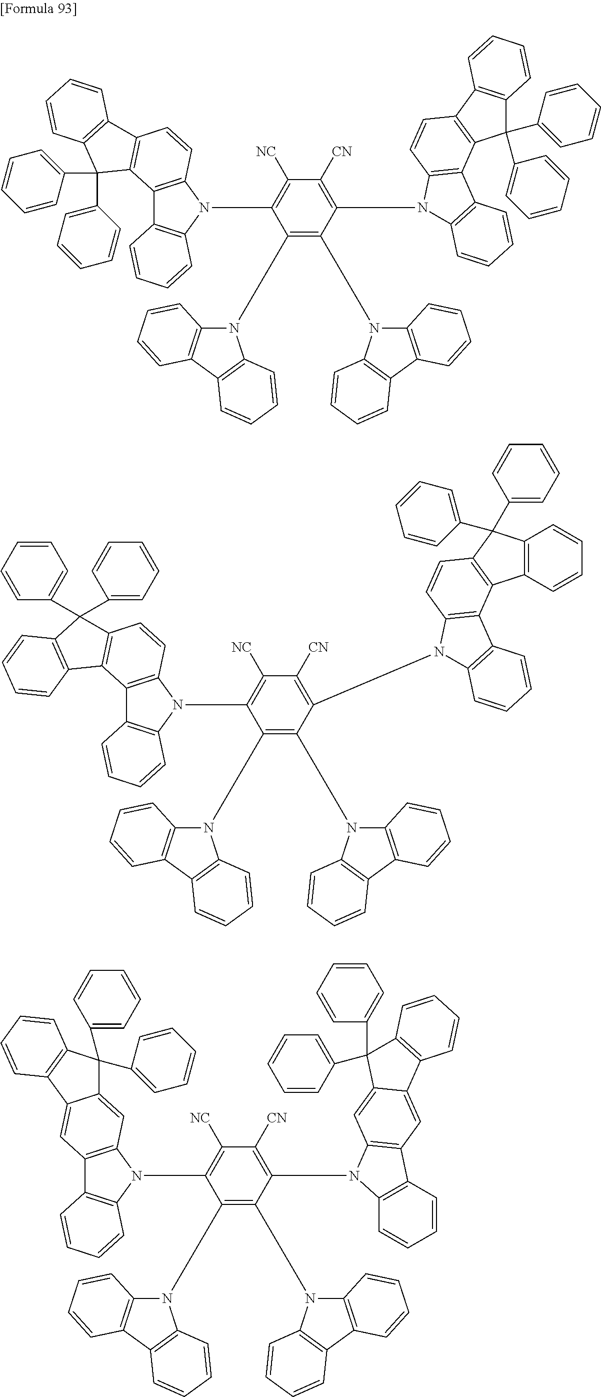

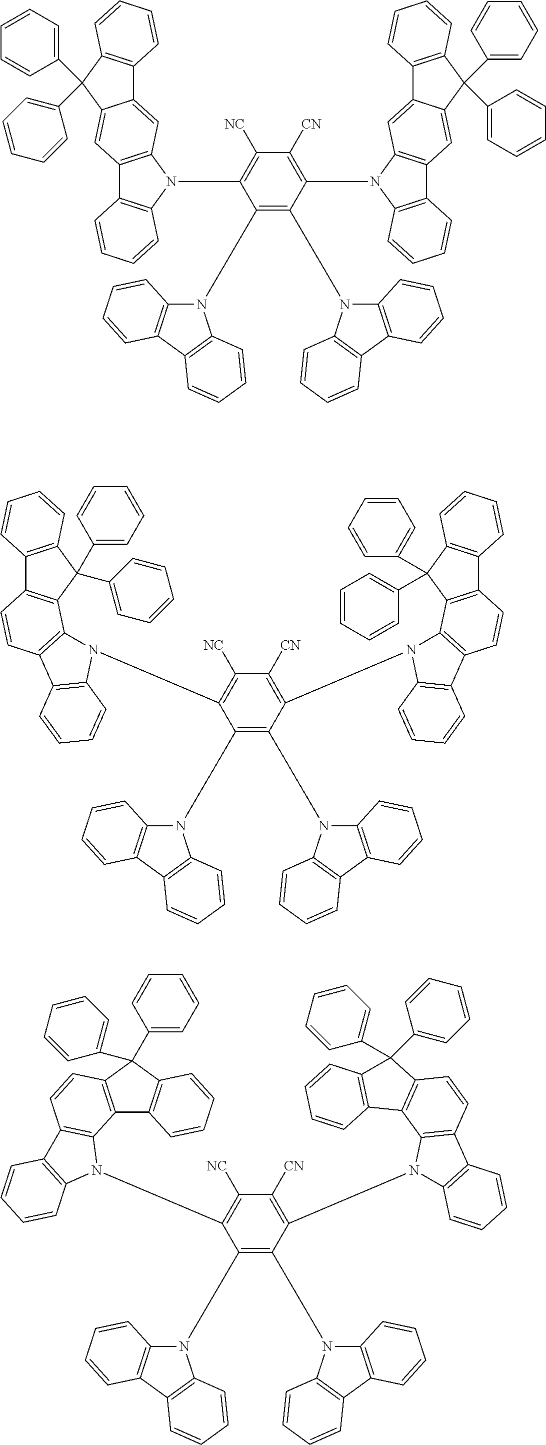

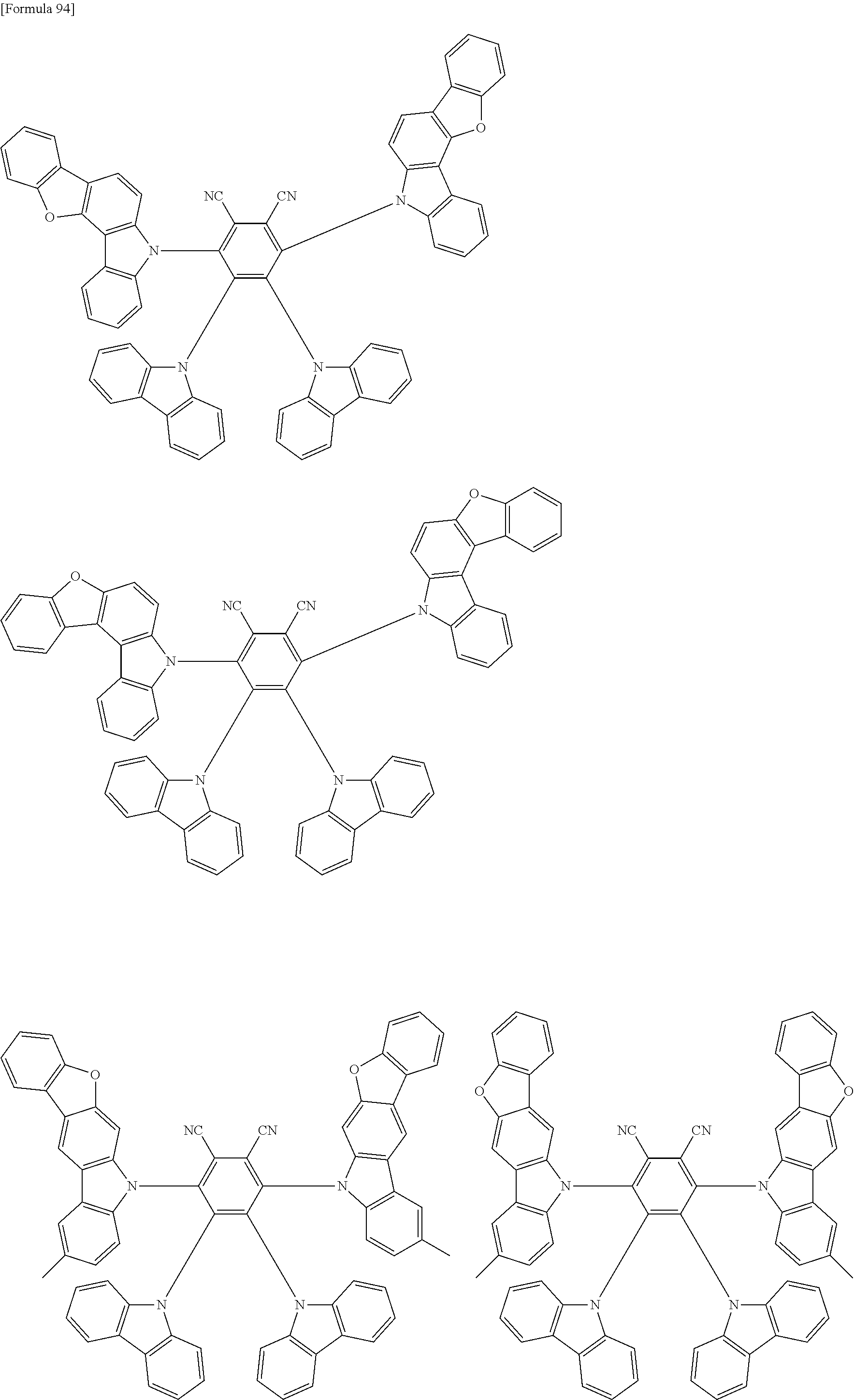

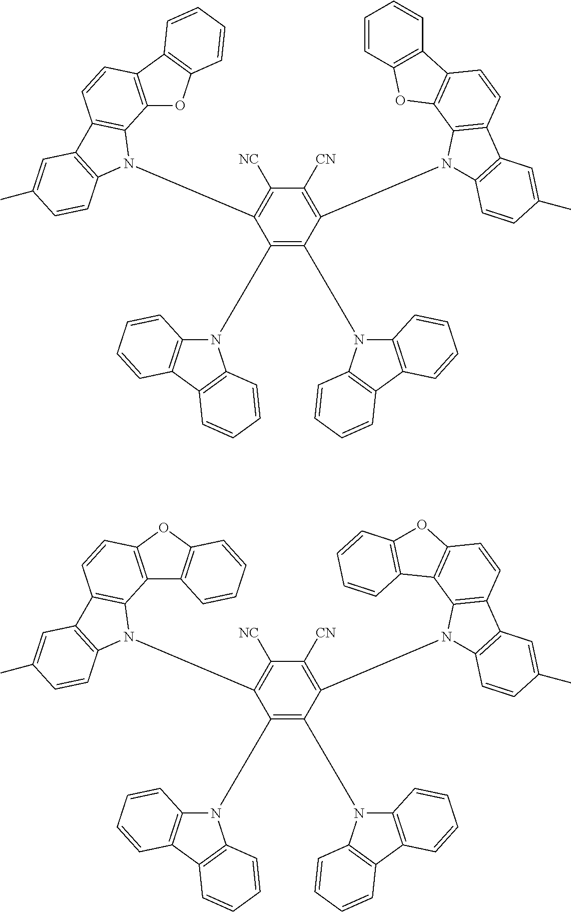

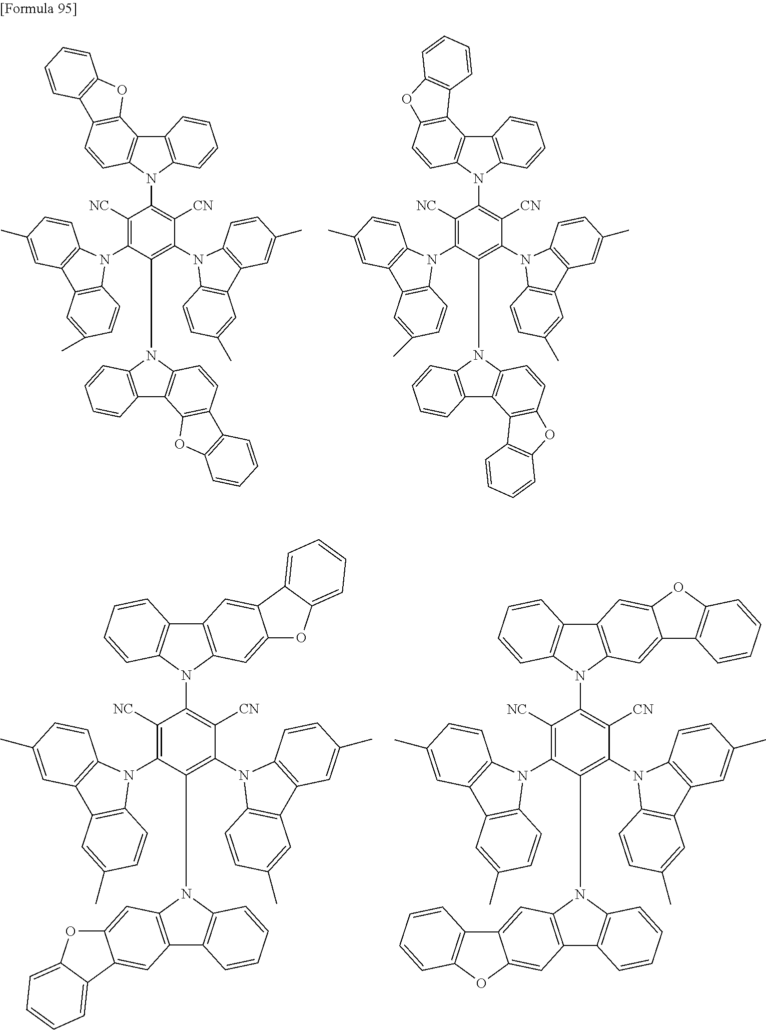

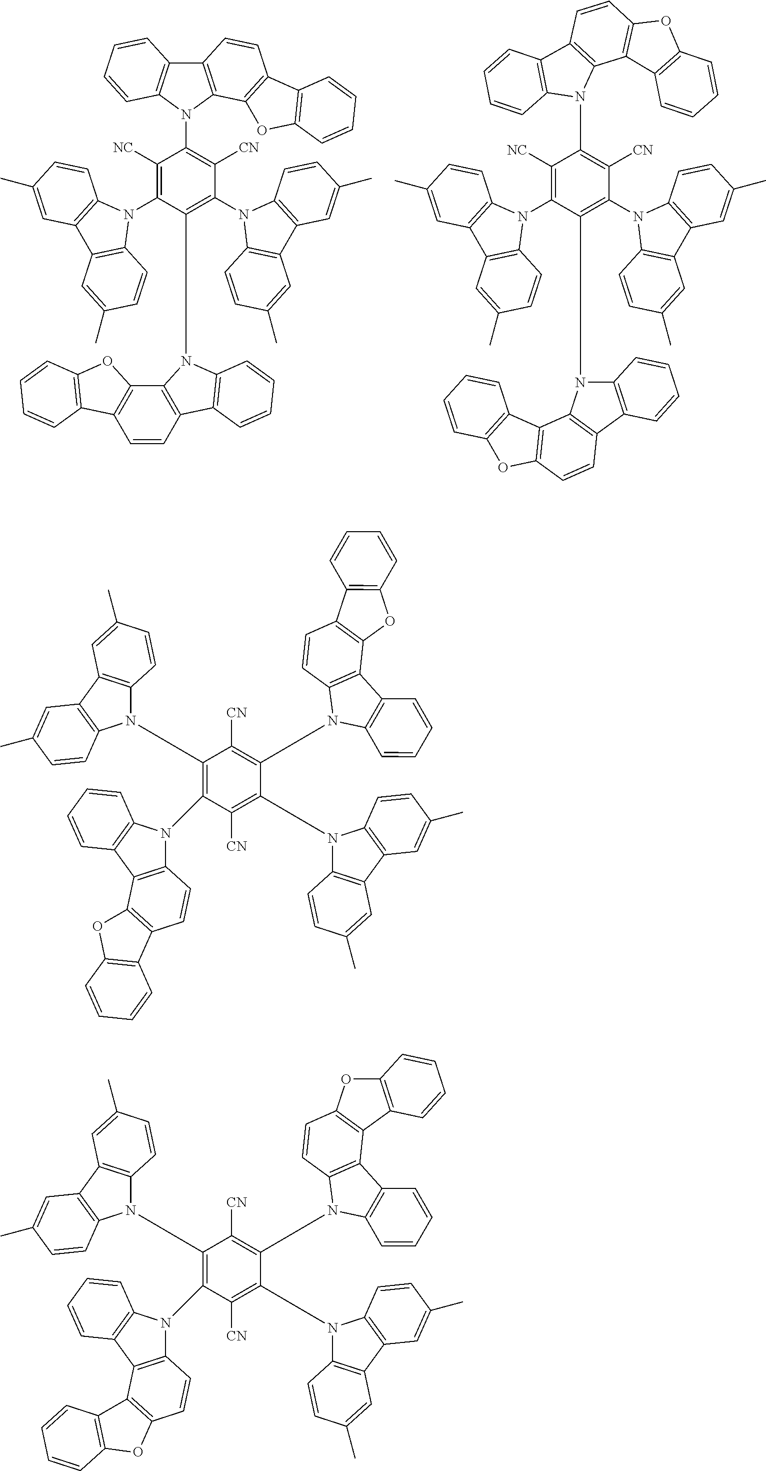

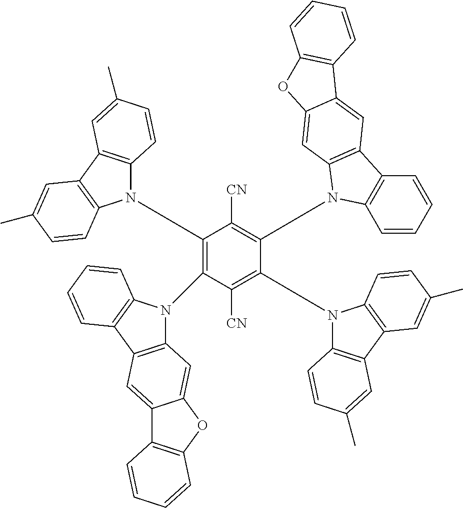

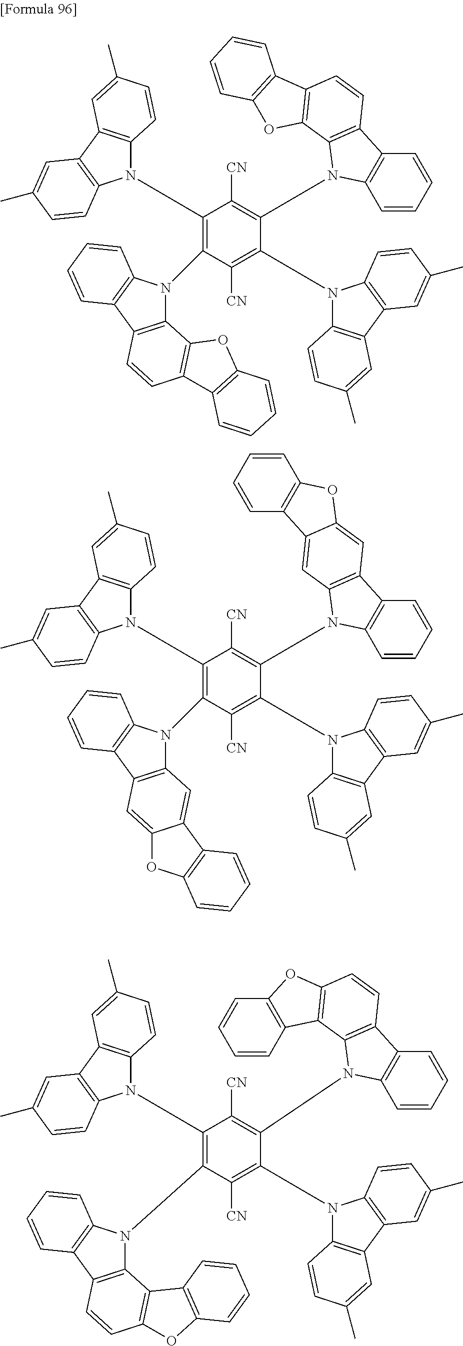

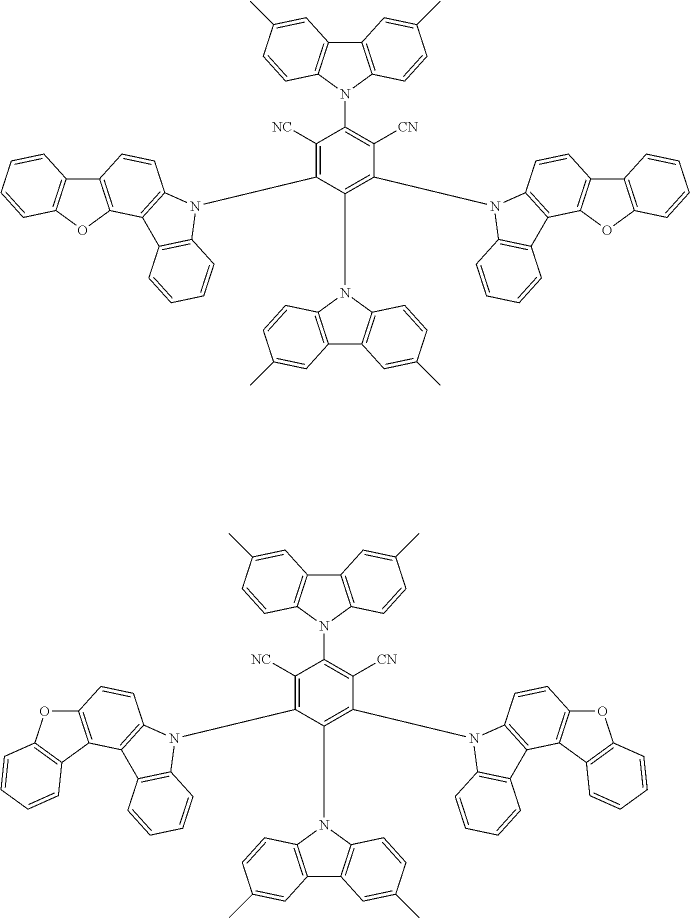 [SMILES: Cc1ccc2c(c1)c1cc(C)ccc1n2-c1c(C#N)c(-n2c3ccccc3c3c4oc5ccccc5c4ccc32)c(-n2c3ccc(C)cc3c3cc(C)ccc32)c(-n2c3ccccc3c3c4oc5ccccc5c4ccc32)c1C#N ; Cc1ccc2c(c1)c1cc(C)ccc1n2-c1c(C#N)c(-n2c3ccccc3c3c4c(ccc32)oc2ccccc24)c(-n2c3ccc(C)cc3c3cc(C)ccc32)c(-n2c3ccccc3c3c4c(ccc32)oc2ccccc24)c1C#N]

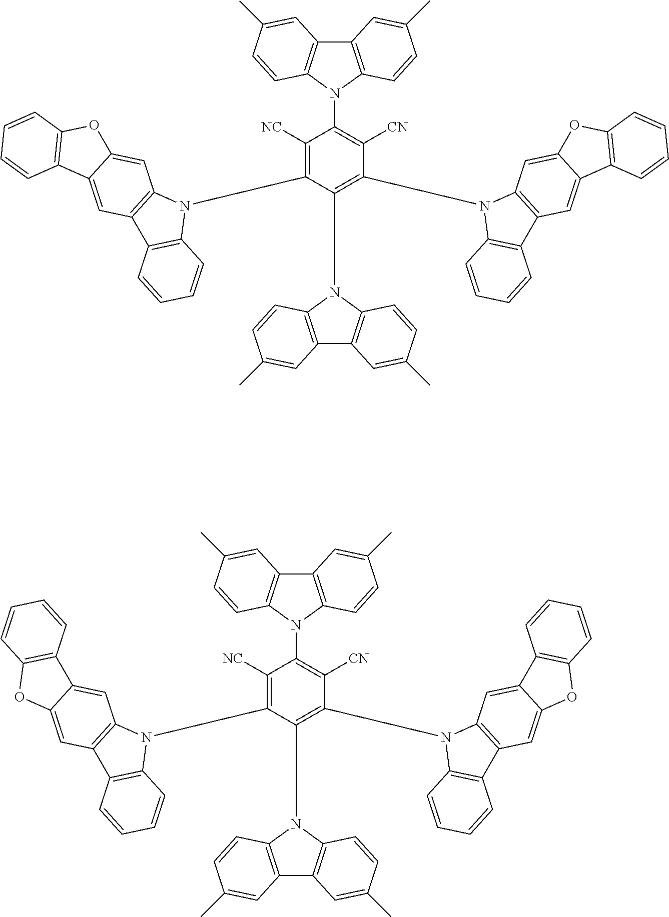 [SMILES: Cc1ccc2c(c1)c1cc(C)ccc1n2-c1c(C#N)c(-n2c3ccccc3c3cc4c(cc32)oc2ccccc24)c(-n2c3ccc(C)cc3c3cc(C)ccc32)c(-n2c3ccccc3c3cc4c(cc32)oc2ccccc24)c1C#N ; Cc1ccc2c(c1)c1cc(C)ccc1n2-c1c(C#N)c(-n2c3ccccc3c3cc4oc5ccccc5c4cc32)c(-n2c3ccc(C)cc3c3cc(C)ccc32)c(-n2c3ccccc3c3cc4oc5ccccc5c4cc32)c1C#N]

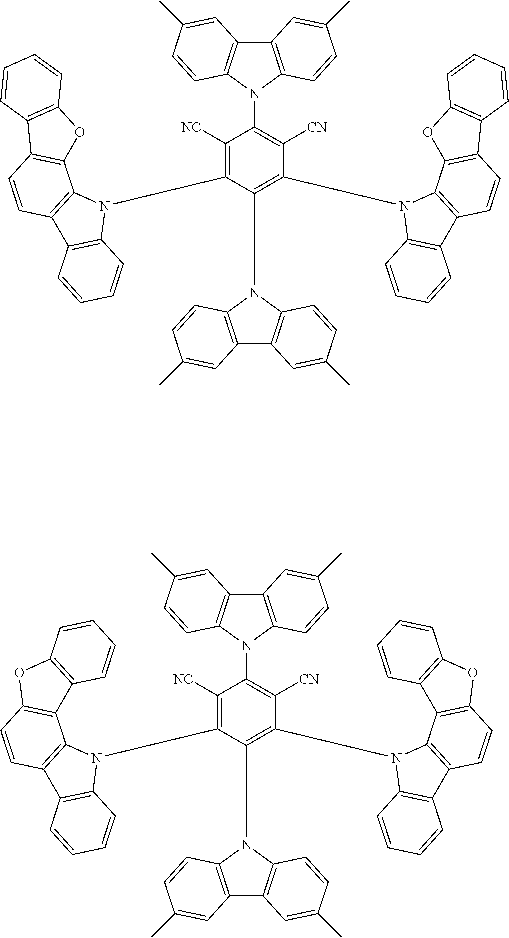 [SMILES: Cc1ccc2c(c1)c1cc(C)ccc1n2-c1c(C#N)c(-n2c3ccccc3c3ccc4c5ccccc5oc4c32)c(-n2c3ccc(C)cc3c3cc(C)ccc32)c(-n2c3ccccc3c3ccc4c5ccccc5oc4c32)c1C#N ; Cc1ccc2c(c1)c1cc(C)ccc1n2-c1c(C#N)c(-n2c3ccccc3c3ccc4oc5ccccc5c4c32)c(-n2c3ccc(C)cc3c3cc(C)ccc32)c(-n2c3ccccc3c3ccc4oc5ccccc5c4c32)c1C#N]

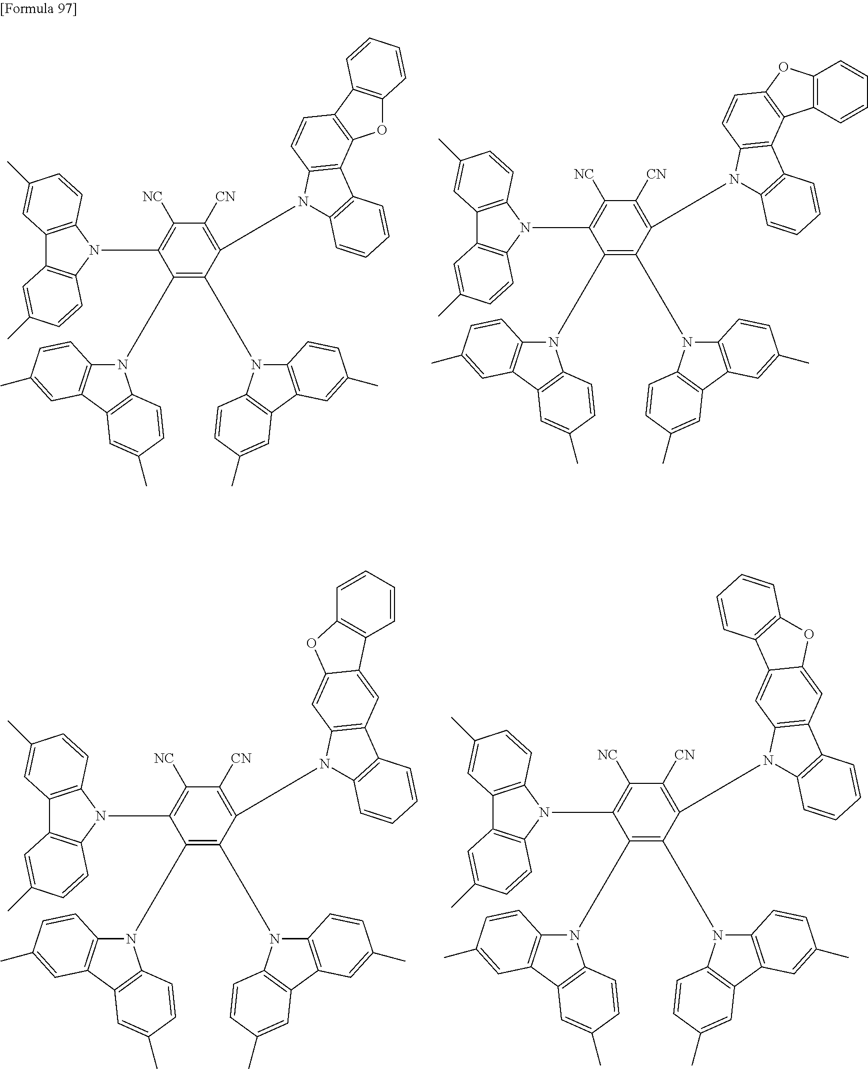

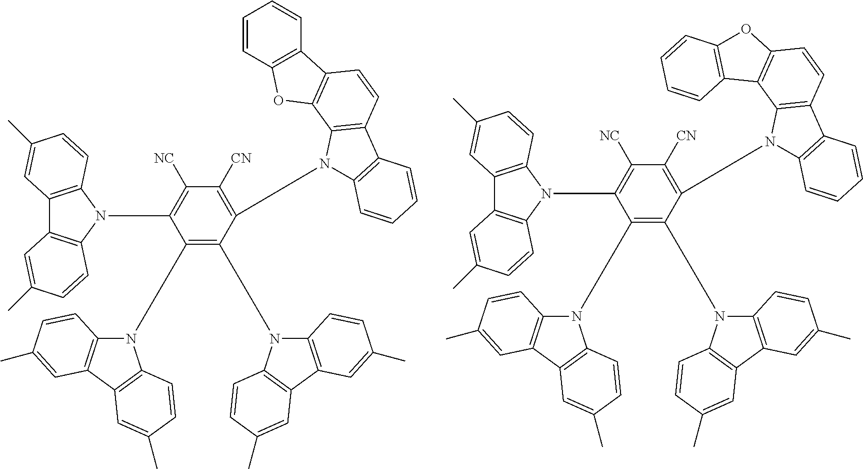

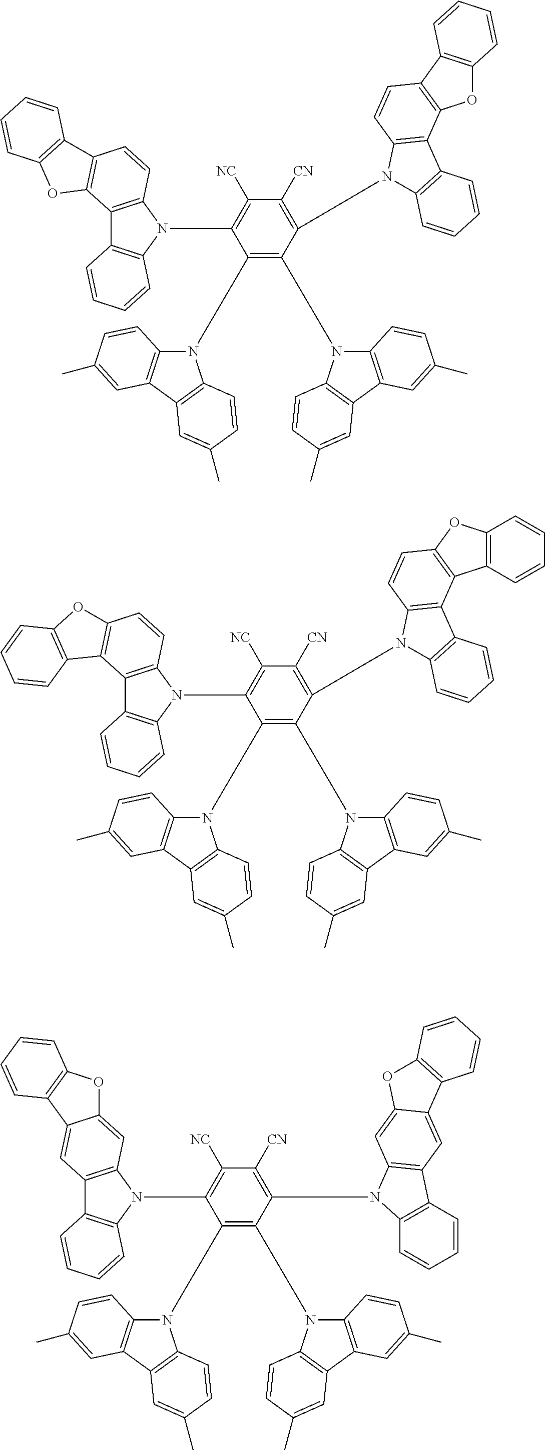 [SMILES: Cc1ccc2c(c1)c1cc(C)ccc1n2-c1c(-n2c3ccc(C)cc3c3cc(C)ccc32)c(-n2c3ccccc3c3c4oc5ccccc5c4ccc32)c(C#N)c(C#N)c1-n1c2ccccc2c2c3oc4ccccc4c3ccc21 ; Cc1ccc2c(c1)c1cc(C)ccc1n2-c1c(-n2c3ccc(C)cc3c3cc(C)ccc32)c(-n2c3ccccc3c3c4c(ccc32)oc2ccccc24)c(C#N)c(C#N)c1-n1c2ccccc2c2c3c(ccc21)oc1ccccc13 ; Cc1ccc2c(c1)c1cc(C)ccc1n2-c1c(-n2c3ccccc3c3cc4c(cc32)oc2ccccc24)c(C#N)c(C#N)c(-n2c3ccccc3c3cc4c(cc32)oc2ccccc24)c1-n1c2ccc(C)cc2c2cc(C)ccc21]

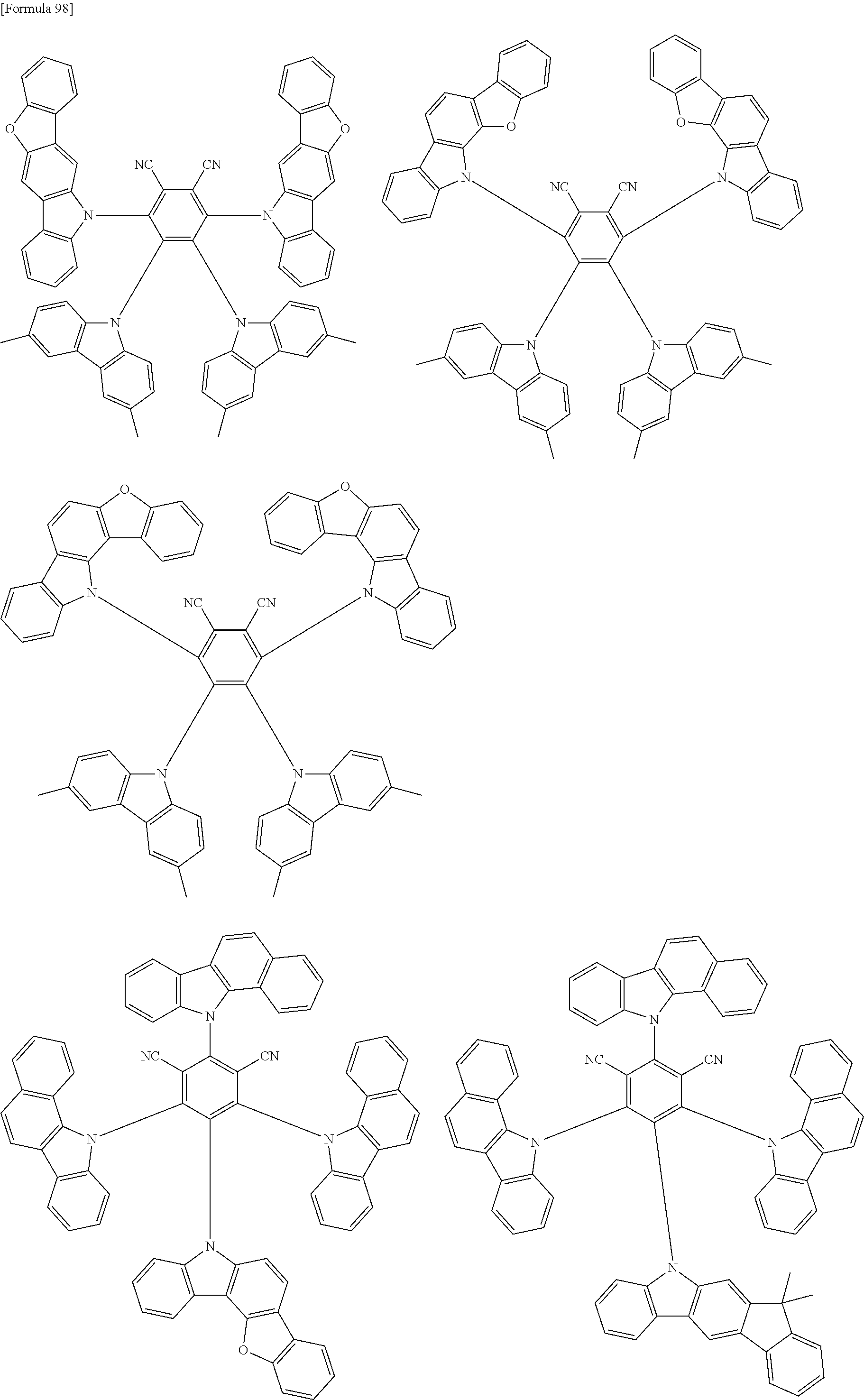

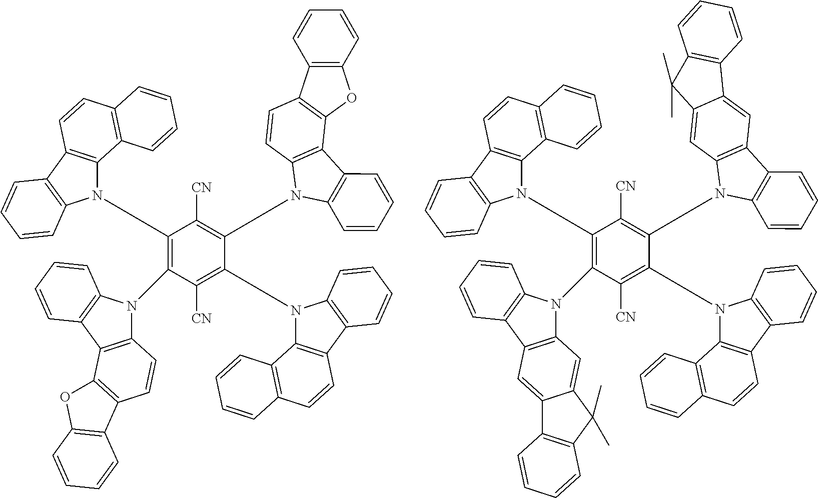

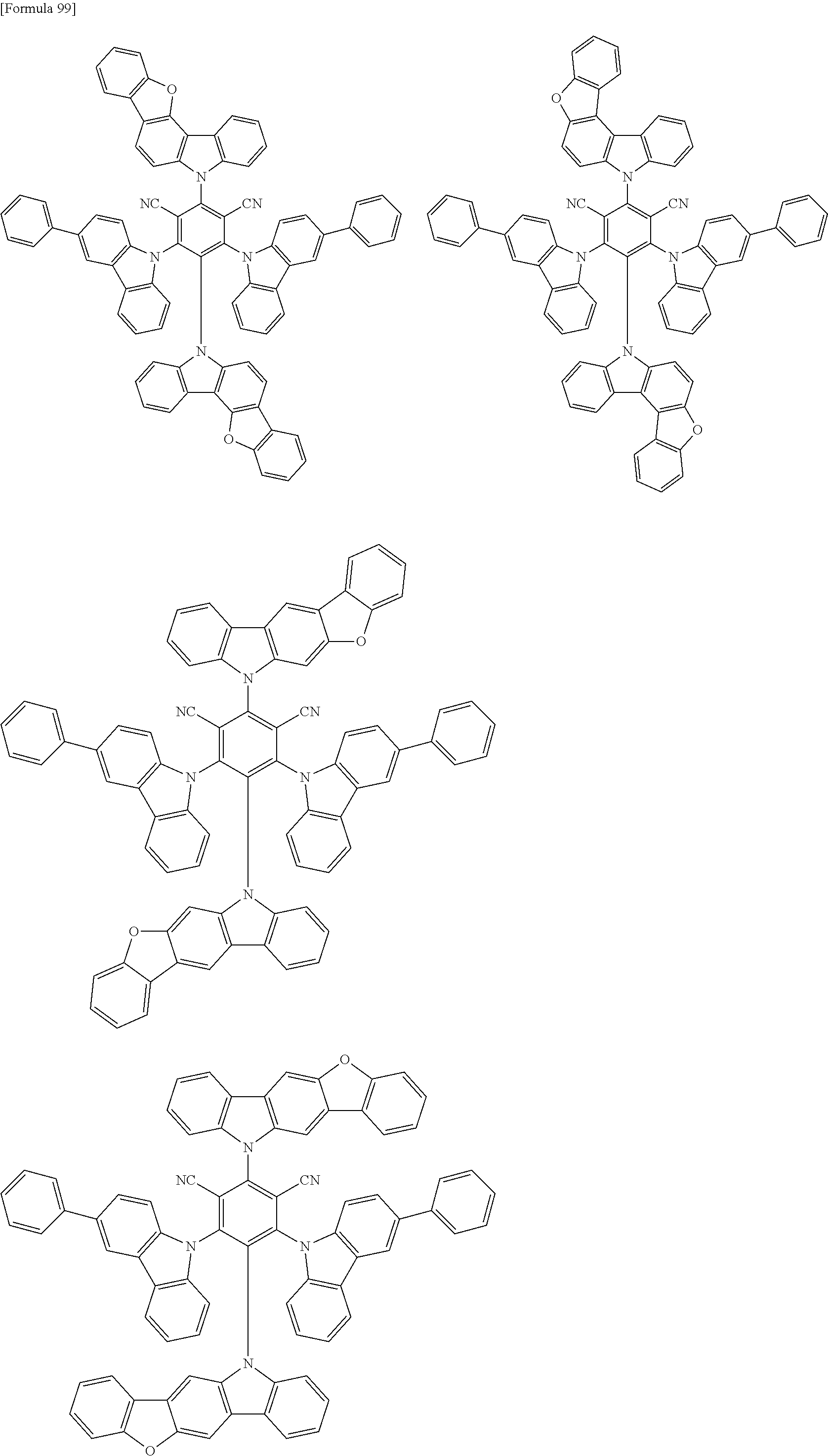

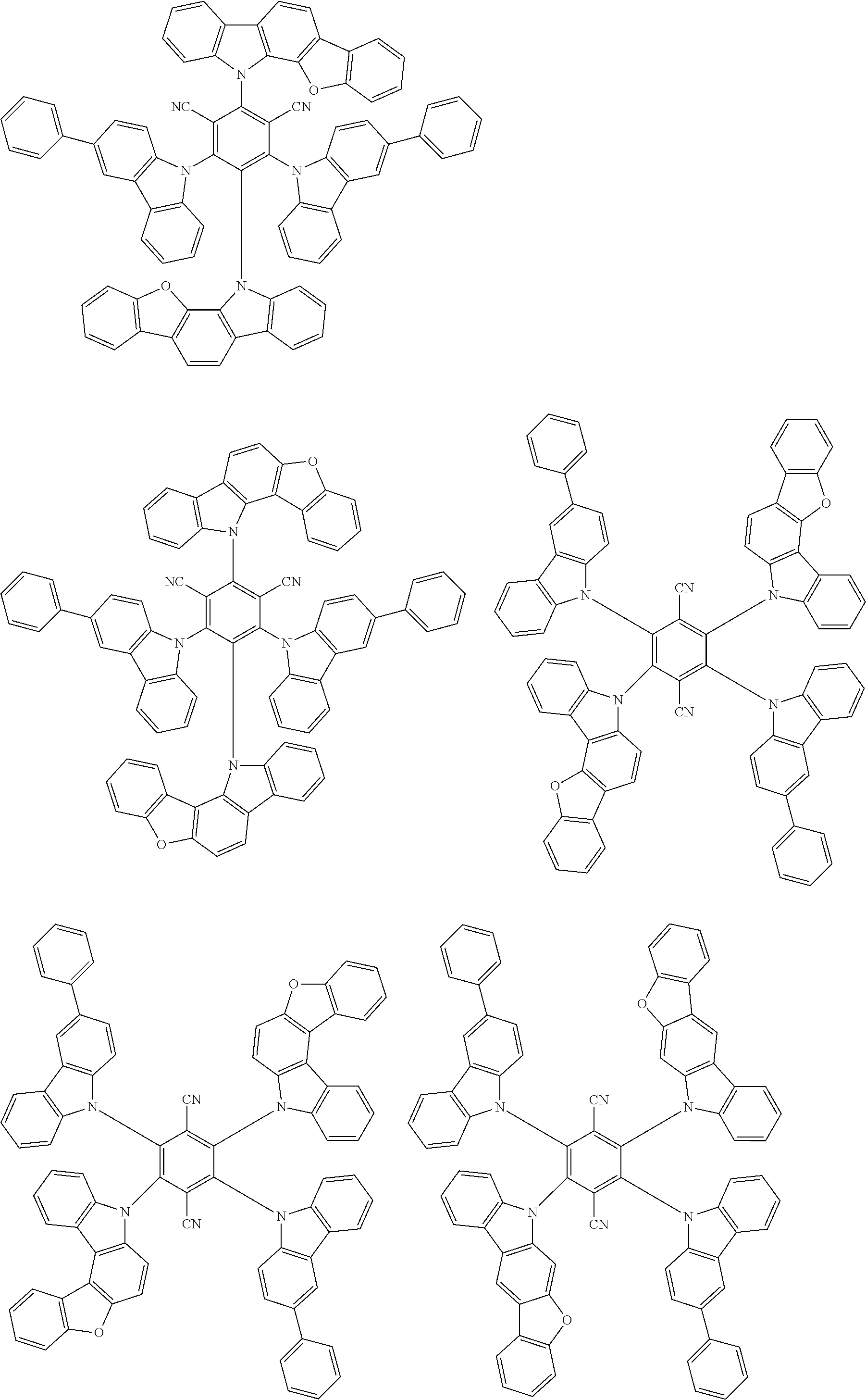

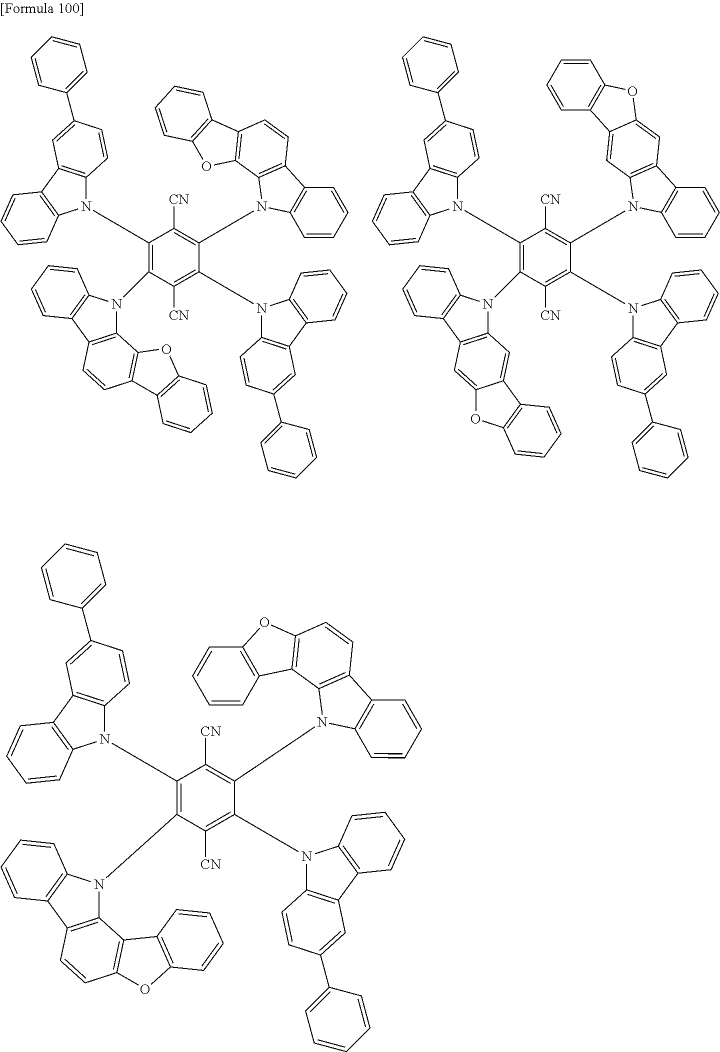

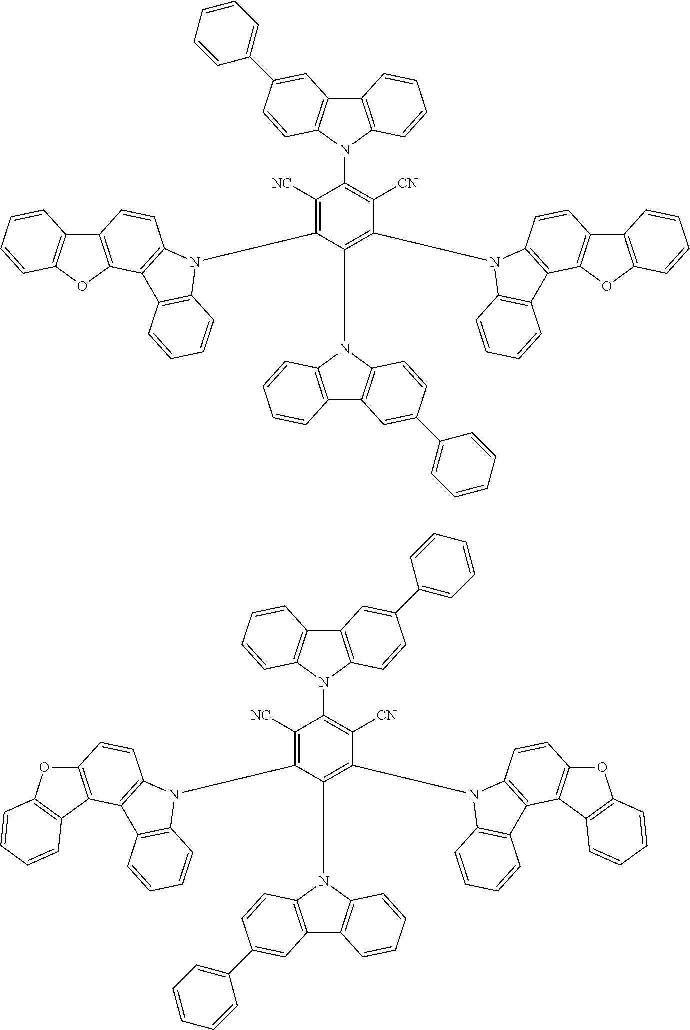

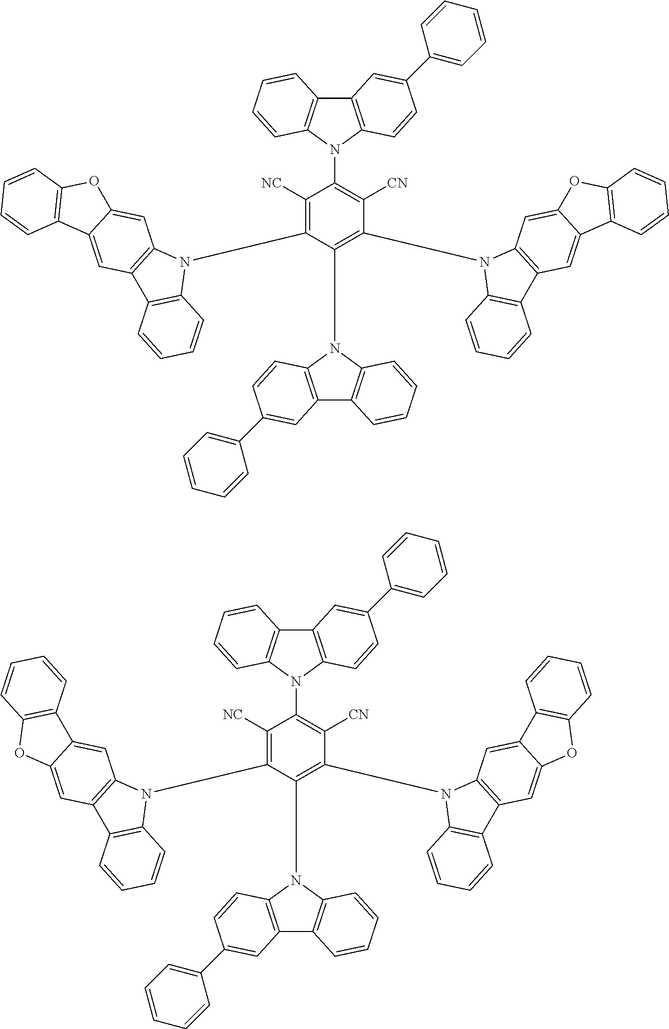 [SMILES: N#Cc1c(-n2c3ccccc3c3cc(-c4ccccc4)ccc32)c(C#N)c(-n2c3ccccc3c3cc4c(cc32)oc2ccccc24)c(-n2c3ccccc3c3cc(-c4ccccc4)ccc32)c1-n1c2ccccc2c2cc3c(cc21)oc1ccccc13 ; N#Cc1c(-n2c3ccccc3c3cc(-c4ccccc4)ccc32)c(C#N)c(-n2c3ccccc3c3cc4oc5ccccc5c4cc32)c(-n2c3ccccc3c3cc(-c4ccccc4)ccc32)c1-n1c2ccccc2c2cc3oc4ccccc4c3cc21]

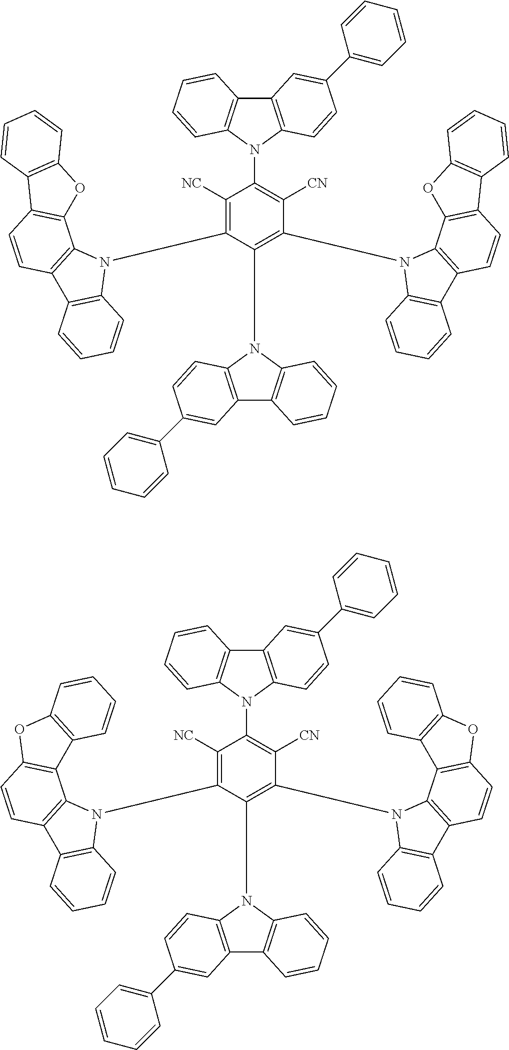 [SMILES: N#Cc1c(-n2c3ccccc3c3cc(-c4ccccc4)ccc32)c(C#N)c(-n2c3ccccc3c3ccc4c5ccccc5oc4c32)c(-n2c3ccccc3c3cc(-c4ccccc4)ccc32)c1-n1c2ccccc2c2ccc3c4ccccc4oc3c21 ; N#Cc1c(-n2c3ccccc3c3cc(-c4ccccc4)ccc32)c(C#N)c(-n2c3ccccc3c3ccc4oc5ccccc5c4c32)c(-n2c3ccccc3c3cc(-c4ccccc4)ccc32)c1-n1c2ccccc2c2ccc3oc4ccccc4c3c21]

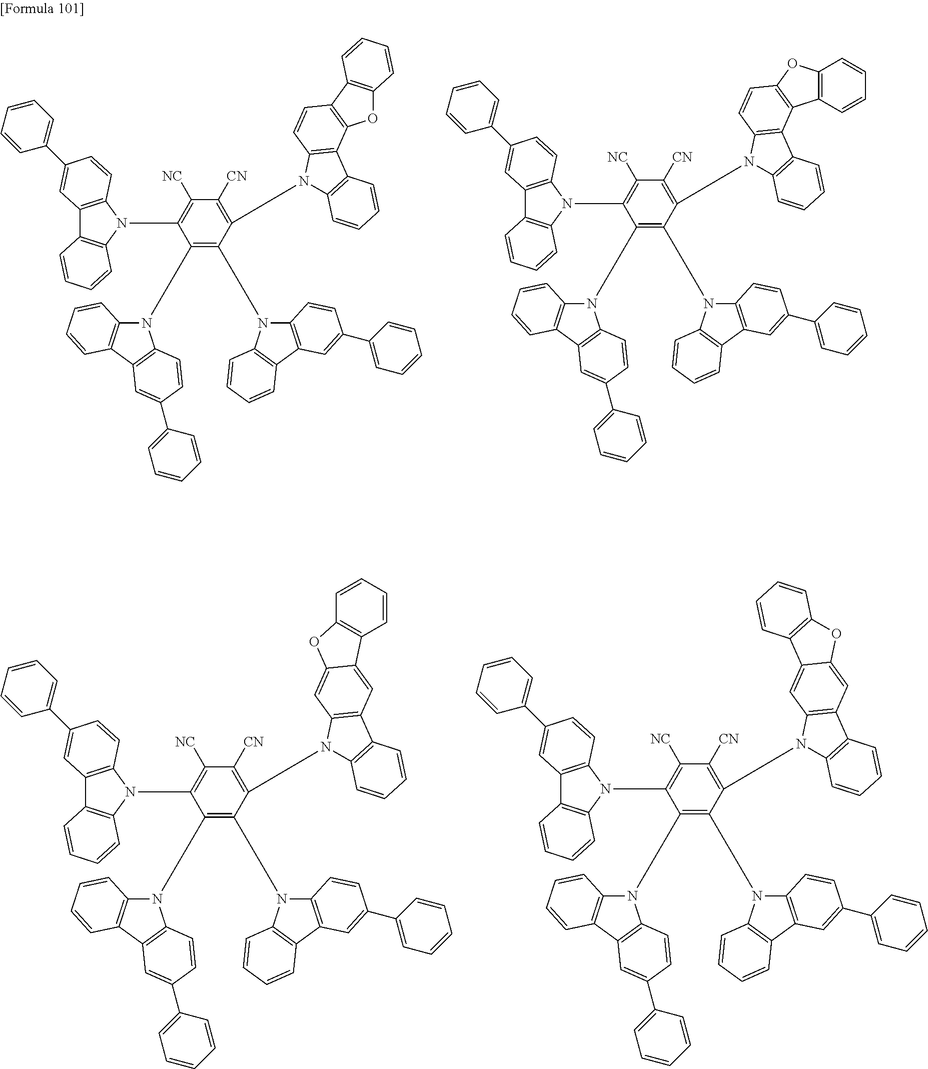

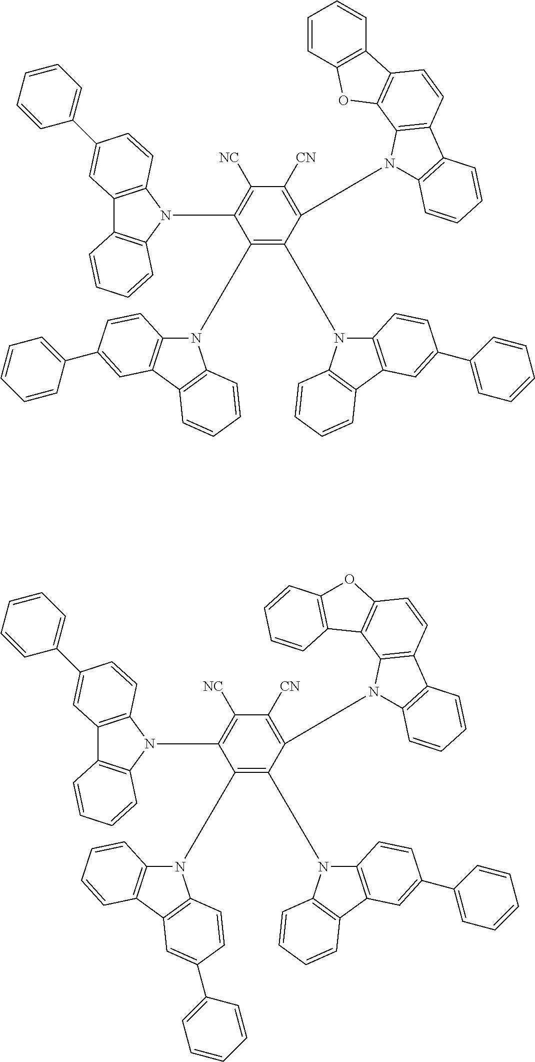 [SMILES: N#Cc1c(C#N)c(-n2c3ccccc3c3ccc4c5ccccc5oc4c32)c(-n2c3ccccc3c3cc(-c4ccccc4)ccc32)c(-n2c3ccccc3c3cc(-c4ccccc4)ccc32)c1-n1c2ccccc2c2cc(-c3ccccc3)ccc21 ; N#Cc1c(C#N)c(-n2c3ccccc3c3ccc4oc5ccccc5c4c32)c(-n2c3ccccc3c3cc(-c4ccccc4)ccc32)c(-n2c3ccccc3c3cc(-c4ccccc4)ccc32)c1-n1c2ccccc2c2cc(-c3ccccc3)ccc21]

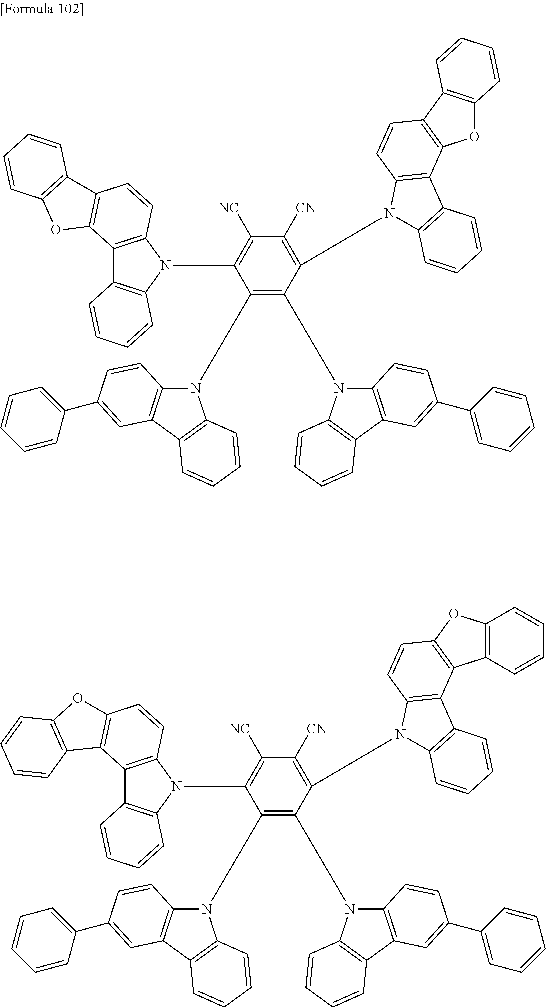 [SMILES: N#Cc1c(C#N)c(-n2c3ccccc3c3c4oc5ccccc5c4ccc32)c(-n2c3ccccc3c3cc(-c4ccccc4)ccc32)c(-n2c3ccccc3c3cc(-c4ccccc4)ccc32)c1-n1c2ccccc2c2c3oc4ccccc4c3ccc21 ; N#Cc1c(C#N)c(-n2c3ccccc3c3c4c(ccc32)oc2ccccc24)c(-n2c3ccccc3c3cc(-c4ccccc4)ccc32)c(-n2c3ccccc3c3cc(-c4ccccc4)ccc32)c1-n1c2ccccc2c2c3c(ccc21)oc1ccccc13]

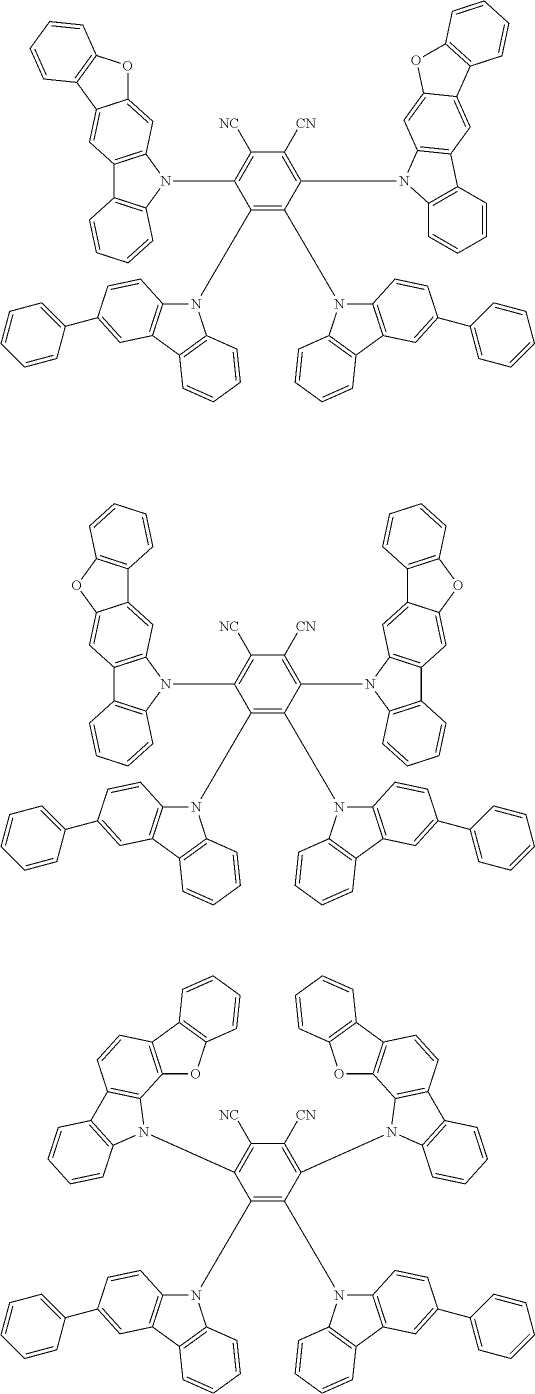 [SMILES: N#Cc1c(C#N)c(-n2c3ccccc3c3cc4c(cc32)oc2ccccc24)c(-n2c3ccccc3c3cc(-c4ccccc4)ccc32)c(-n2c3ccccc3c3cc(-c4ccccc4)ccc32)c1-n1c2ccccc2c2cc3c(cc21)oc1ccccc13 ; N#Cc1c(C#N)c(-n2c3ccccc3c3cc4oc5ccccc5c4cc32)c(-n2c3ccccc3c3cc(-c4ccccc4)ccc32)c(-n2c3ccccc3c3cc(-c4ccccc4)ccc32)c1-n1c2ccccc2c2cc3oc4ccccc4c3cc21 ; N#Cc1c(C#N)c(-n2c3ccccc3c3ccc4c5ccccc5oc4c32)c(-n2c3ccccc3c3cc(-c4ccccc4)ccc32)c(-n2c3ccccc3c3cc(-c4ccccc4)ccc32)c1-n1c2ccccc2c2ccc3c4ccccc4oc3c21]

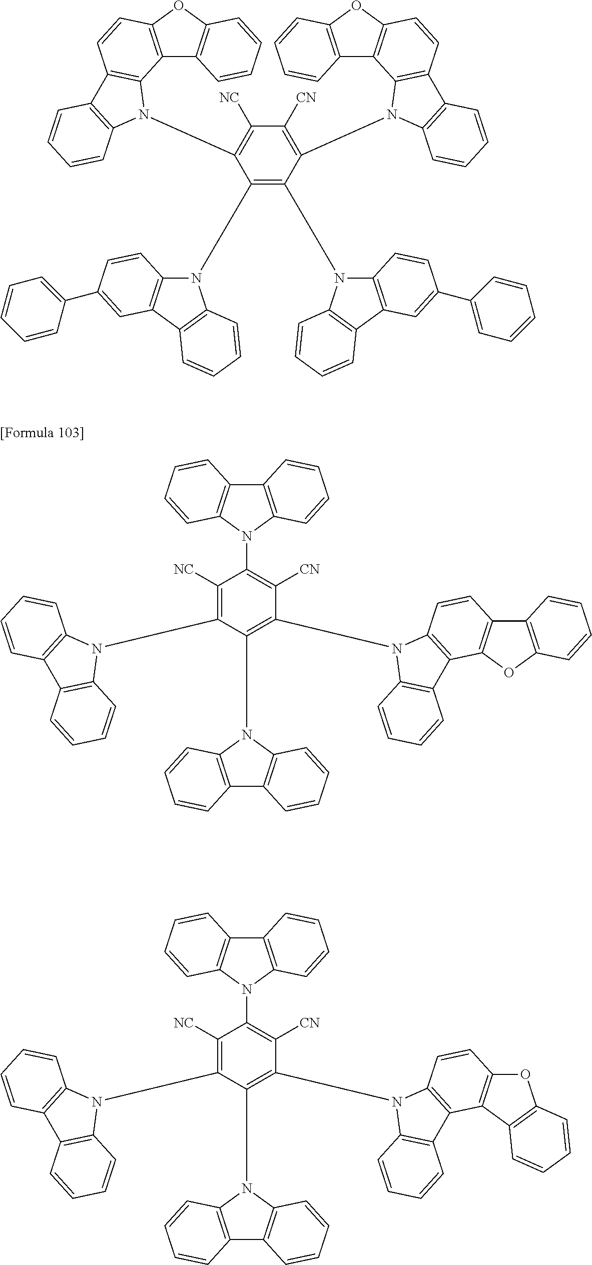 [SMILES: N#Cc1c(C#N)c(-n2c3ccccc3c3ccc4oc5ccccc5c4c32)c(-n2c3ccccc3c3cc(-c4ccccc4)ccc32)c(-n2c3ccccc3c3cc(-c4ccccc4)ccc32)c1-n1c2ccccc2c2ccc3oc4ccccc4c3c21 ; N#Cc1c(-n2c3ccccc3c3ccccc32)c(C#N)c(-n2c3ccccc3c3c4oc5ccccc5c4ccc32)c(-n2c3ccccc3c3ccccc32)c1-n1c2ccccc2c2ccccc21 ; N#Cc1c(-n2c3ccccc3c3ccccc32)c(C#N)c(-n2c3ccccc3c3c4c(ccc32)oc2ccccc24)c(-n2c3ccccc3c3ccccc32)c1-n1c2ccccc2c2ccccc21]

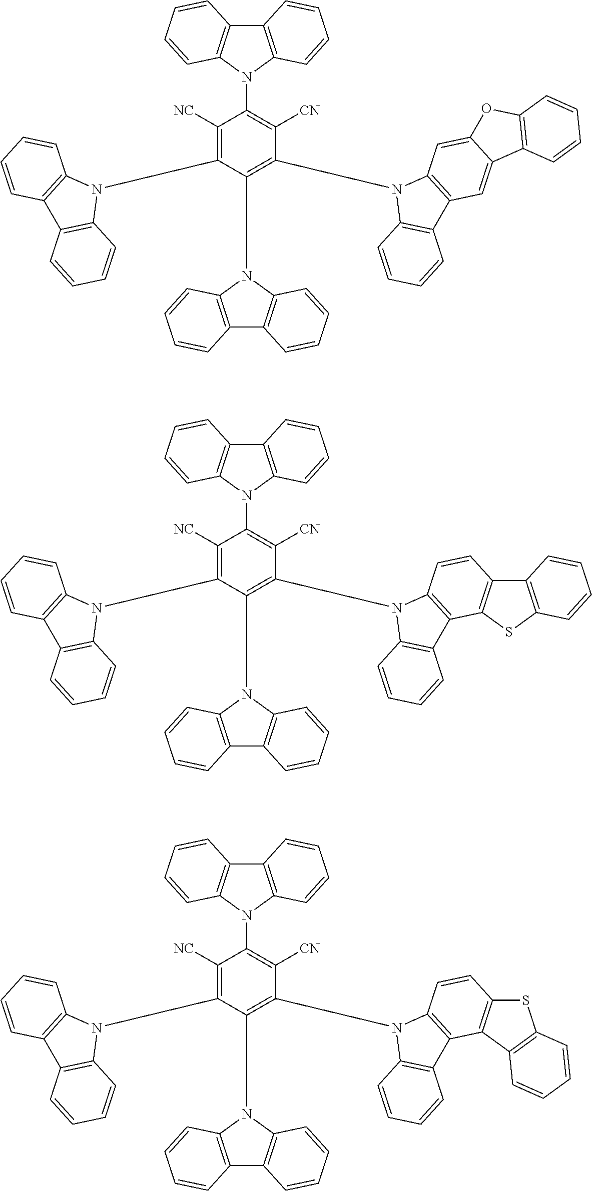 [SMILES: N#Cc1c(-n2c3ccccc3c3ccccc32)c(C#N)c(-n2c3ccccc3c3cc4c(cc32)oc2ccccc24)c(-n2c3ccccc3c3ccccc32)c1-n1c2ccccc2c2ccccc21 ; N#Cc1c(-n2c3ccccc3c3ccccc32)c(C#N)c(-n2c3ccccc3c3c4sc5ccccc5c4ccc32)c(-n2c3ccccc3c3ccccc32)c1-n1c2ccccc2c2ccccc21 ; N#Cc1c(-n2c3ccccc3c3ccccc32)c(C#N)c(-n2c3ccccc3c3c4c(ccc32)sc2ccccc24)c(-n2c3ccccc3c3ccccc32)c1-n1c2ccccc2c2ccccc21]

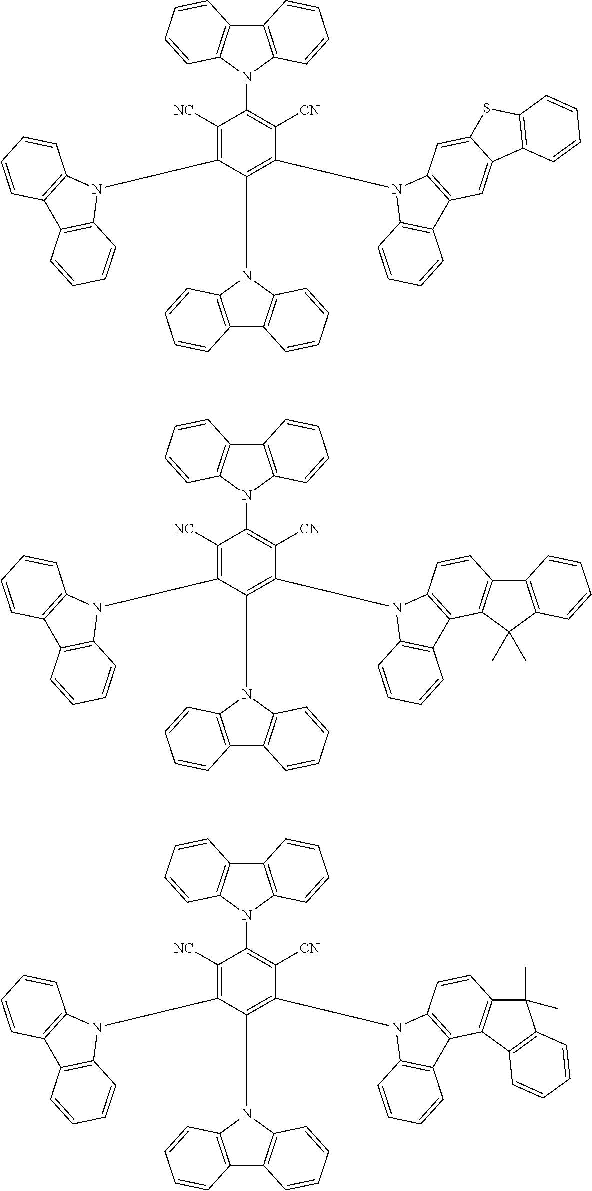 [SMILES: N#Cc1c(-n2c3ccccc3c3ccccc32)c(C#N)c(-n2c3ccccc3c3cc4c(cc32)sc2ccccc24)c(-n2c3ccccc3c3ccccc32)c1-n1c2ccccc2c2ccccc21 ; CC1(C)c2ccccc2-c2ccc3c(c21)c1ccccc1n3-c1c(C#N)c(-n2c3ccccc3c3ccccc32)c(C#N)c(-n2c3ccccc3c3ccccc32)c1-n1c2ccccc2c2ccccc21 ; CC1(C)c2ccccc2-c2c1ccc1c2c2ccccc2n1-c1c(C#N)c(-n2c3ccccc3c3ccccc32)c(C#N)c(-n2c3ccccc3c3ccccc32)c1-n1c2ccccc2c2ccccc21]

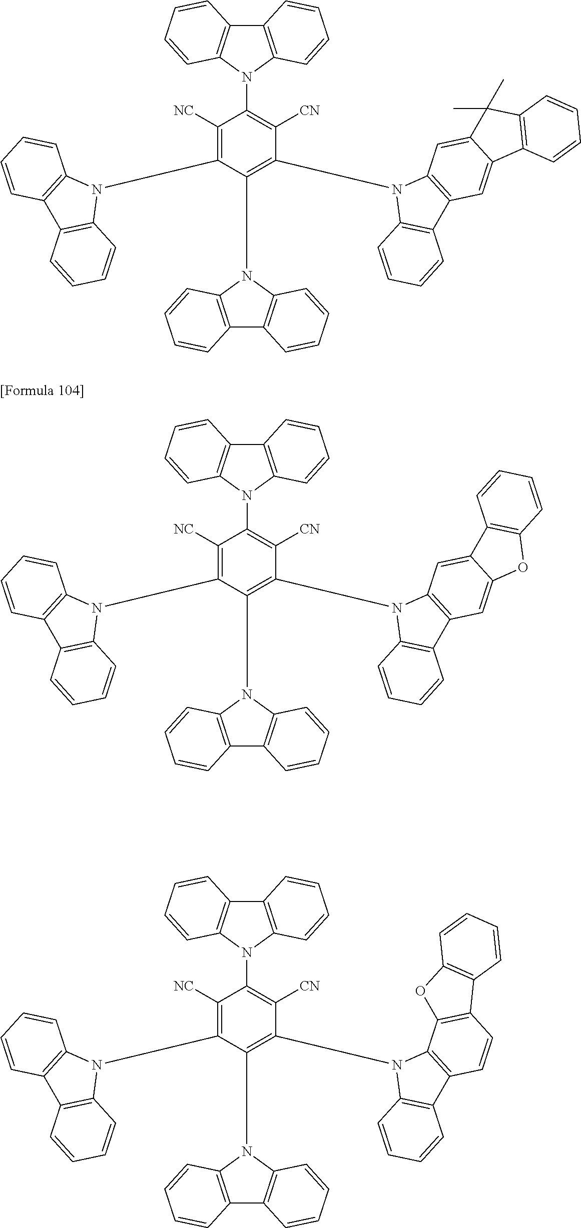 [SMILES: CC1(C)c2ccccc2-c2cc3c4ccccc4n(-c4c(C#N)c(-n5c6ccccc6c6ccccc65)c(C#N)c(-n5c6ccccc6c6ccccc65)c4-n4c5ccccc5c5ccccc54)c3cc21 ; N#Cc1c(-n2c3ccccc3c3ccccc32)c(C#N)c(-n2c3ccccc3c3cc4oc5ccccc5c4cc32)c(-n2c3ccccc3c3ccccc32)c1-n1c2ccccc2c2ccccc21 ; N#Cc1c(-n2c3ccccc3c3ccccc32)c(C#N)c(-n2c3ccccc3c3ccc4c5ccccc5oc4c32)c(-n2c3ccccc3c3ccccc32)c1-n1c2ccccc2c2ccccc21]

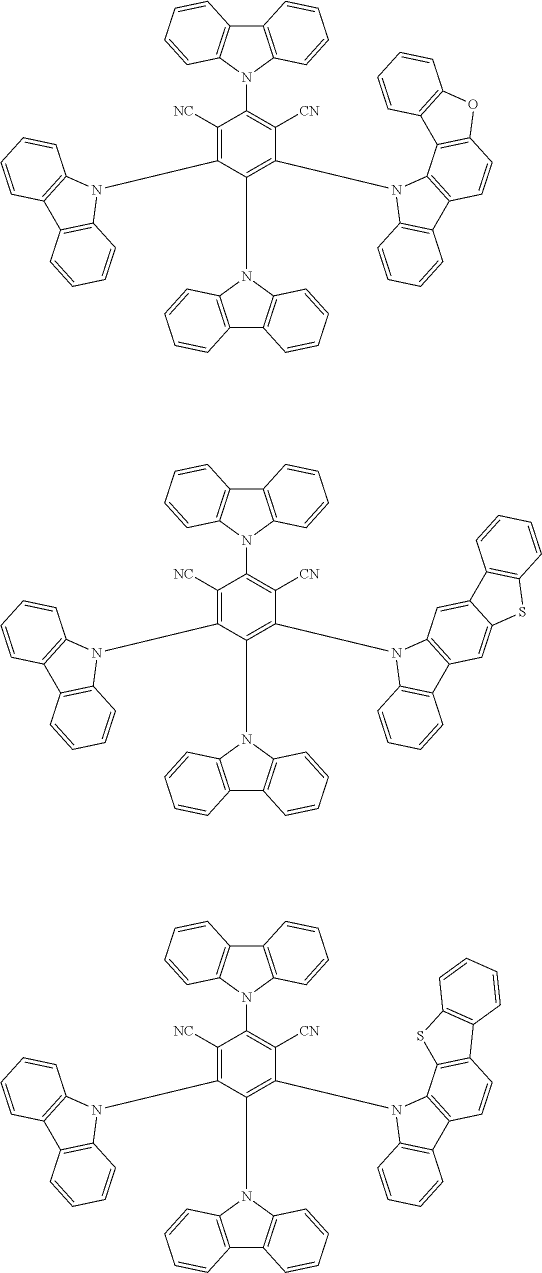 [SMILES: N#Cc1c(-n2c3ccccc3c3ccccc32)c(C#N)c(-n2c3ccccc3c3ccc4oc5ccccc5c4c32)c(-n2c3ccccc3c3ccccc32)c1-n1c2ccccc2c2ccccc21 ; N#Cc1c(-n2c3ccccc3c3ccccc32)c(C#N)c(-n2c3ccccc3c3cc4sc5ccccc5c4cc32)c(-n2c3ccccc3c3ccccc32)c1-n1c2ccccc2c2ccccc21 ; N#Cc1c(-n2c3ccccc3c3ccccc32)c(C#N)c(-n2c3ccccc3c3ccc4c5ccccc5sc4c32)c(-n2c3ccccc3c3ccccc32)c1-n1c2ccccc2c2ccccc21]

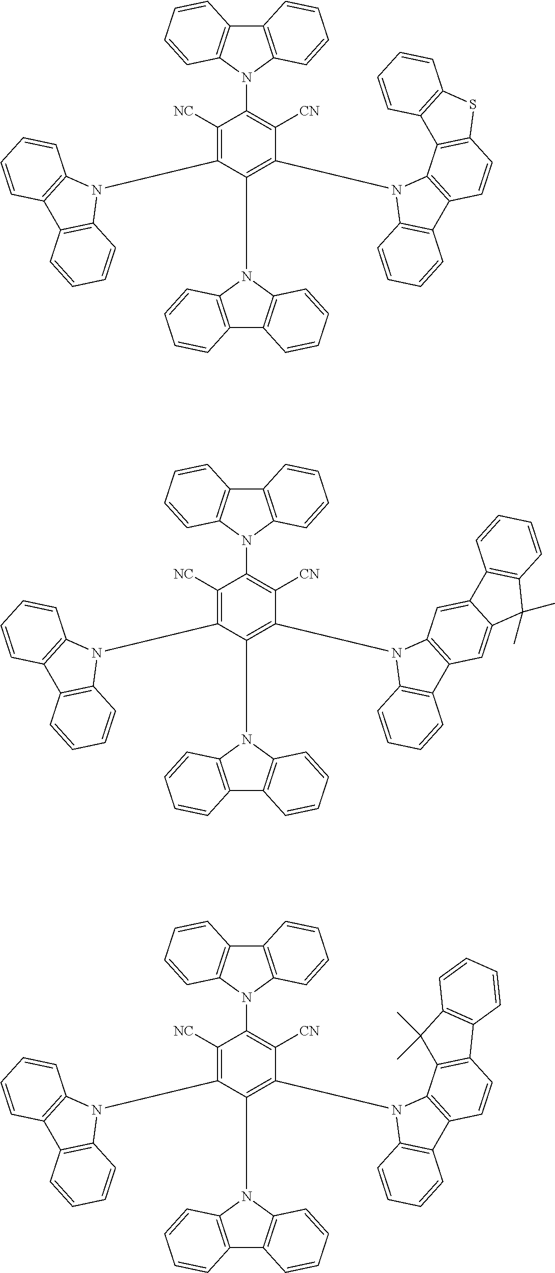 [SMILES: N#Cc1c(-n2c3ccccc3c3ccccc32)c(C#N)c(-n2c3ccccc3c3ccc4sc5ccccc5c4c32)c(-n2c3ccccc3c3ccccc32)c1-n1c2ccccc2c2ccccc21 ; CC1(C)c2ccccc2-c2cc3c(cc21)c1ccccc1n3-c1c(C#N)c(-n2c3ccccc3c3ccccc32)c(C#N)c(-n2c3ccccc3c3ccccc32)c1-n1c2ccccc2c2ccccc21 ; CC1(C)c2ccccc2-c2ccc3c4ccccc4n(-c4c(C#N)c(-n5c6ccccc6c6ccccc65)c(C#N)c(-n5c6ccccc6c6ccccc65)c4-n4c5ccccc5c5ccccc54)c3c21]

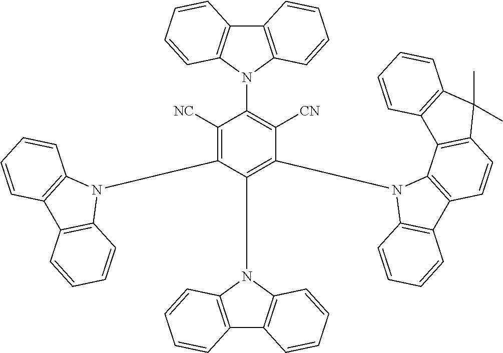 [SMILES: CC1(C)c2ccccc2-c2c1ccc1c3ccccc3n(-c3c(C#N)c(-n4c5ccccc5c5ccccc54)c(C#N)c(-n4c5ccccc5c5ccccc54)c3-n3c4ccccc4c4ccccc43)c21]

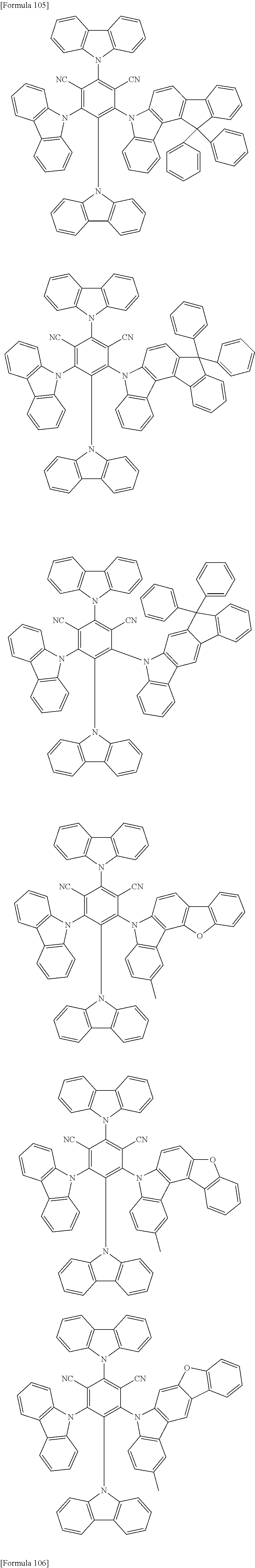

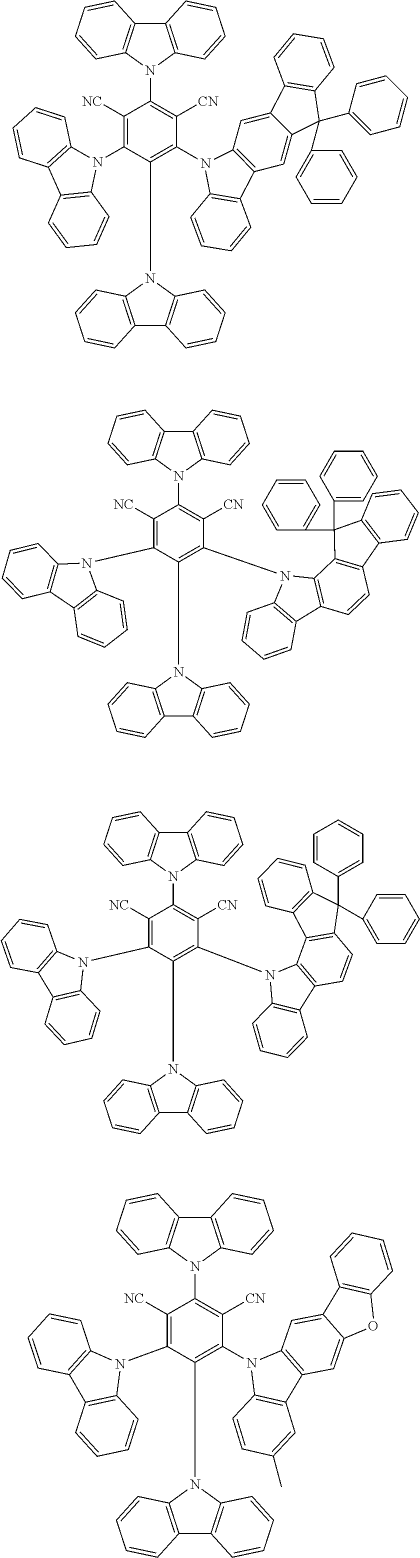

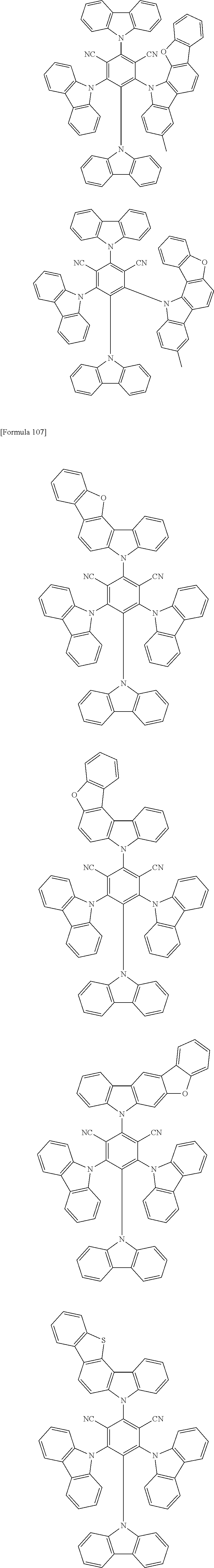

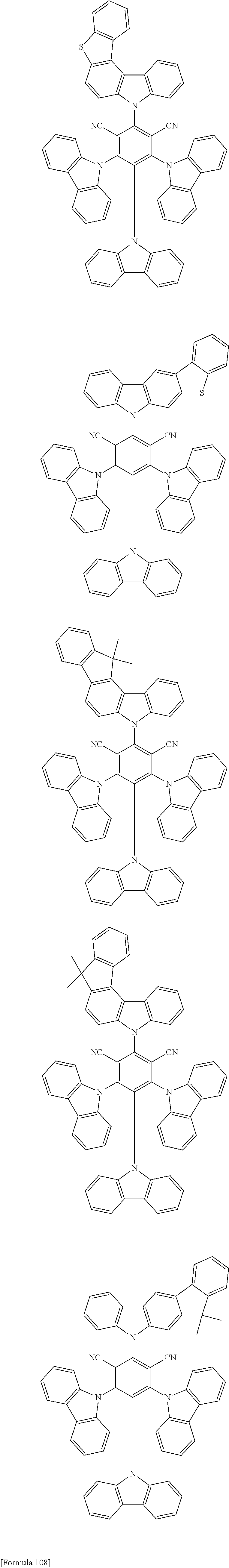

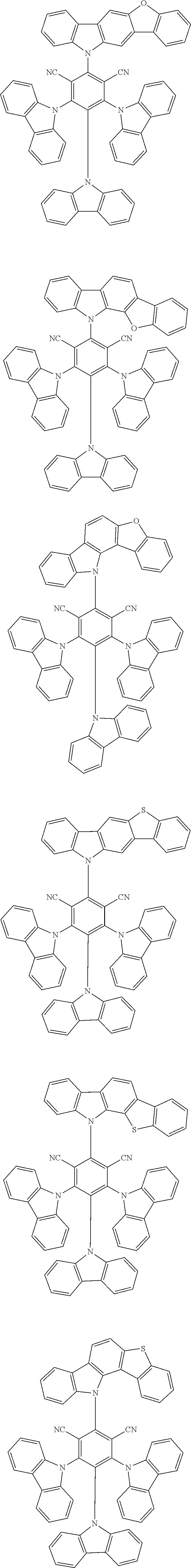

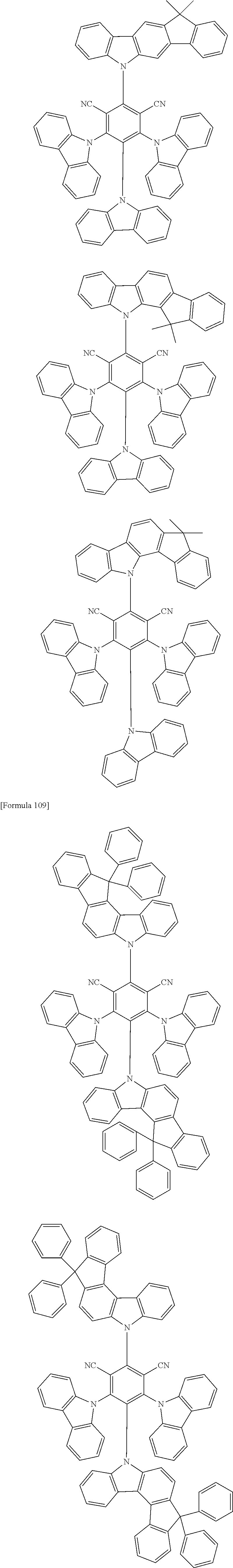

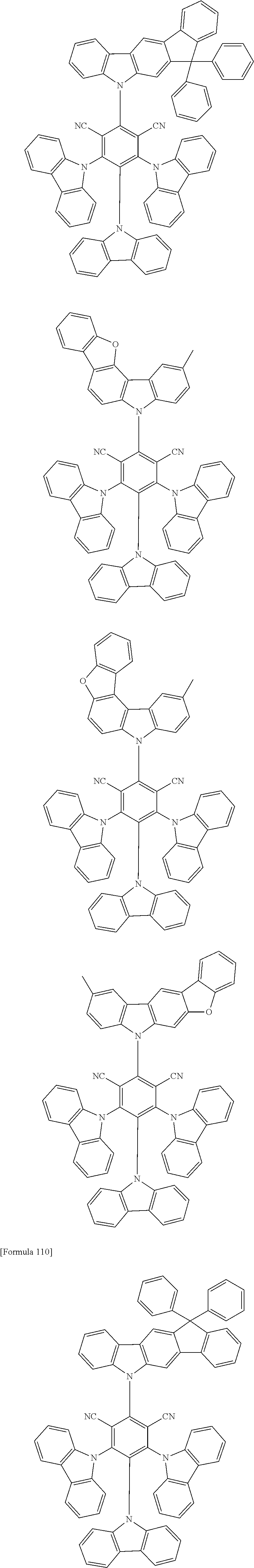

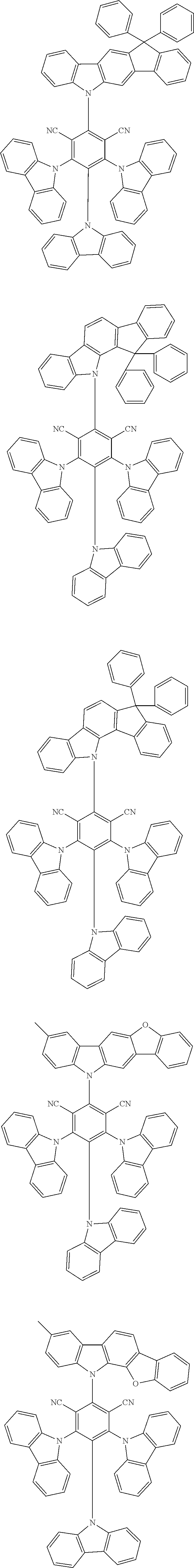

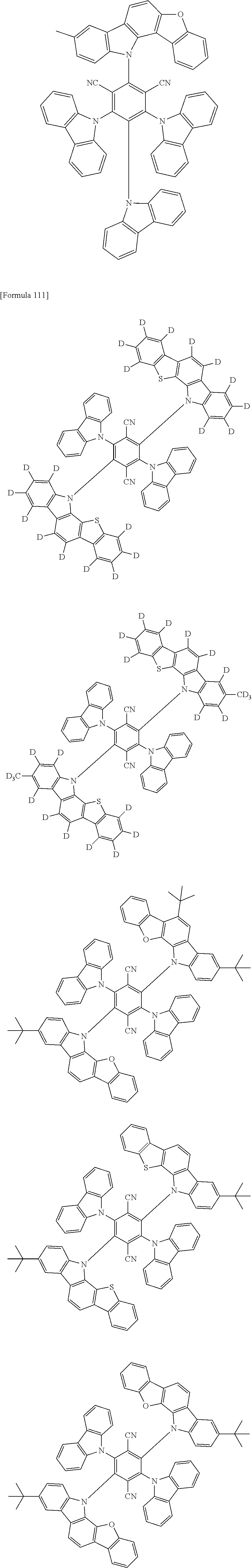

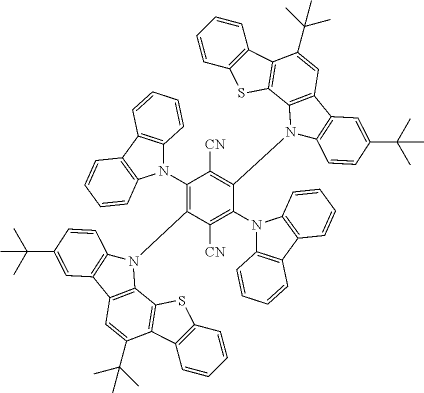 [SMILES: CC(C)(C)c1ccc2c(c1)c1cc(C(C)(C)C)c3c4ccccc4sc3c1n2-c1c(C#N)c(-n2c3ccccc3c3ccccc32)c(-n2c3ccc(C(C)(C)C)cc3c3cc(C(C)(C)C)c4c5ccccc5sc4c32)c(C#N)c1-n1c2ccccc2c2ccccc21]

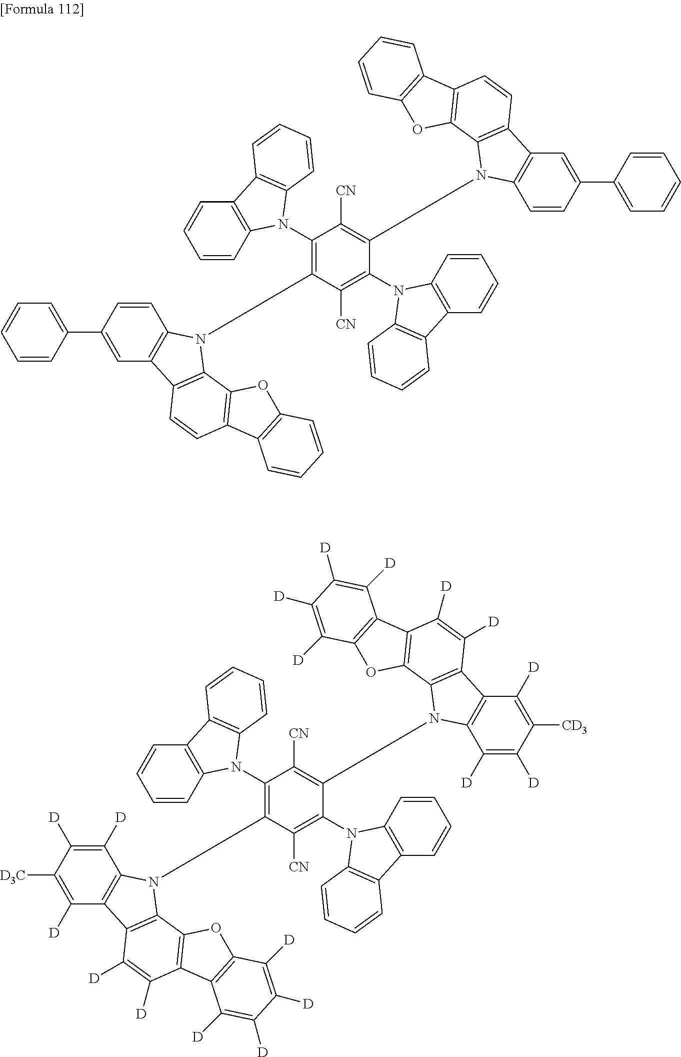 [SMILES: N#Cc1c(-n2c3ccccc3c3ccccc32)c(-n2c3ccc(-c4ccccc4)cc3c3ccc4c5ccccc5oc4c32)c(C#N)c(-n2c3ccccc3c3ccccc32)c1-n1c2ccc(-c3ccccc3)cc2c2ccc3c4ccccc4oc3c21 ; [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6c([2H])c([2H])c(C([2H])([2H])[2H])c([2H])c6c6c([2H])c([2H])c7c(oc8c([2H])c([2H])c([2H])c([2H])c87)c65)c(C#N)c4-n4c5ccccc5c5ccccc54)c32)c1[2H]]

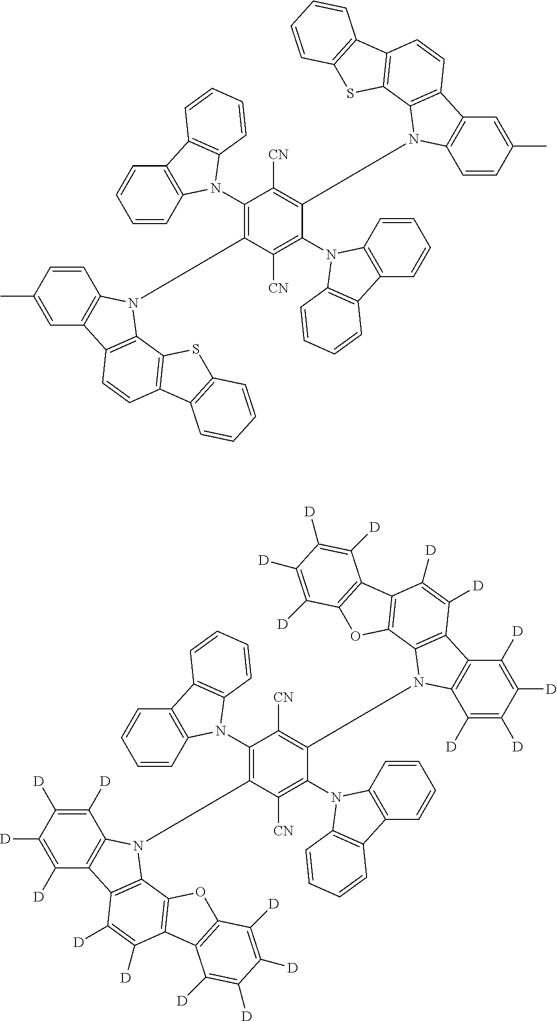

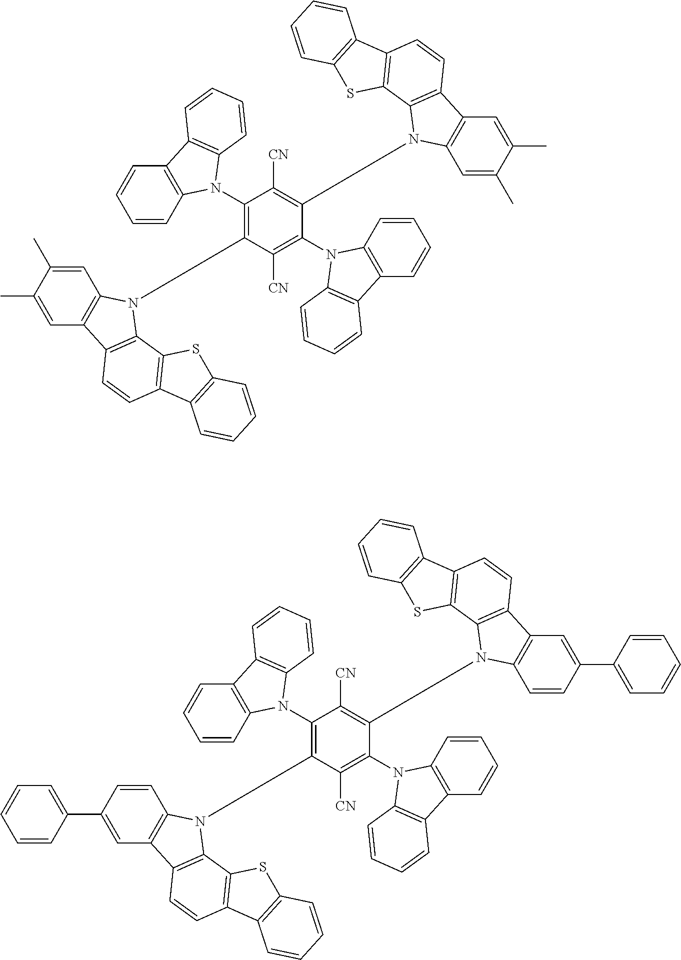

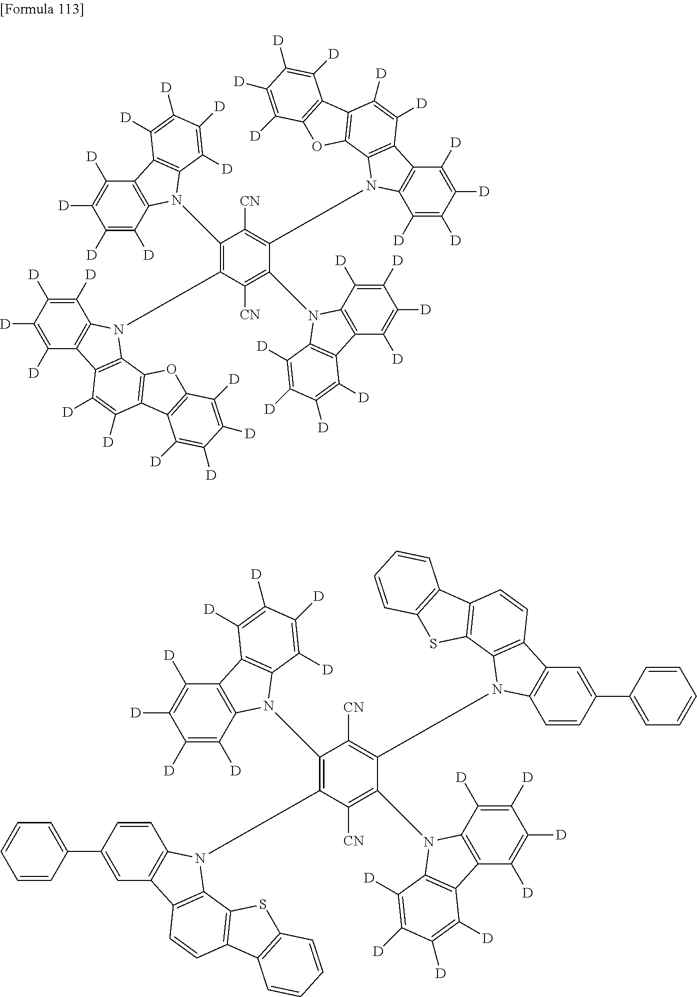

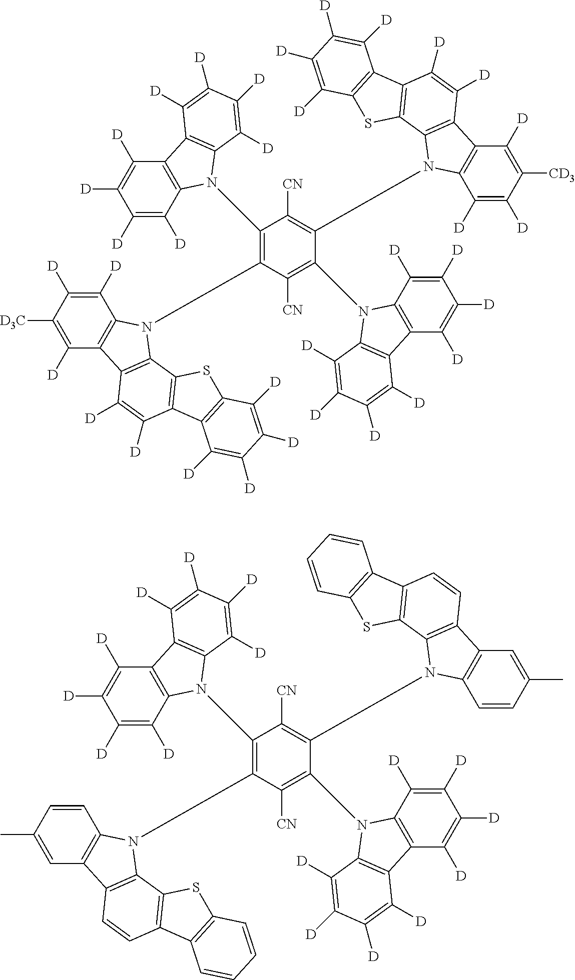

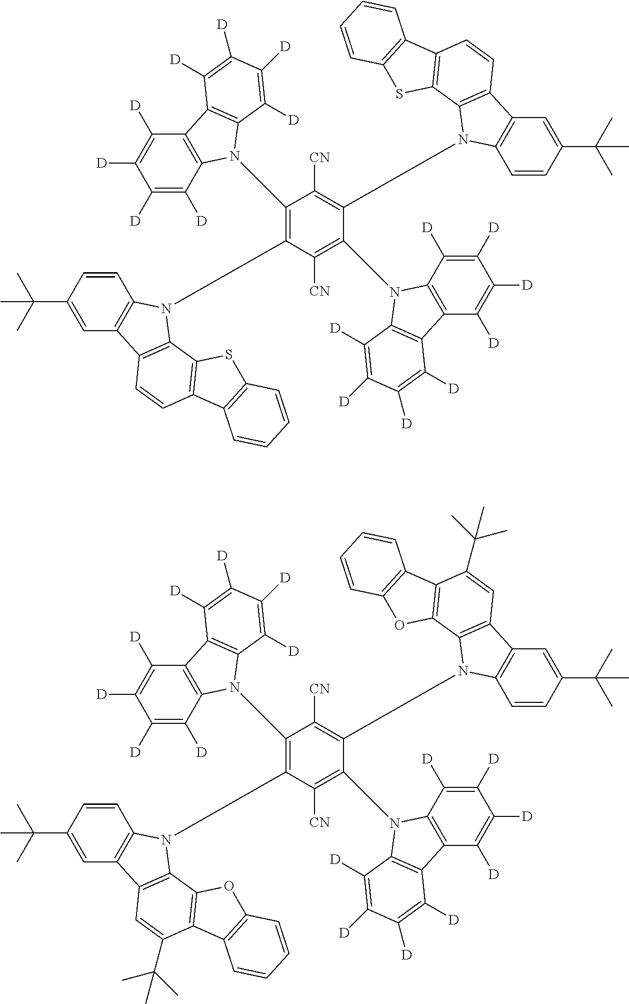

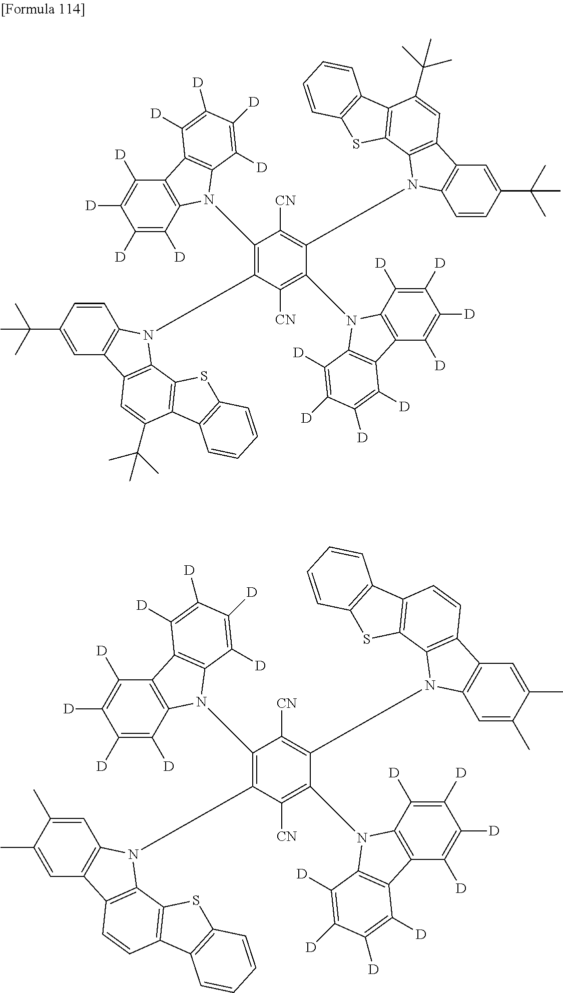

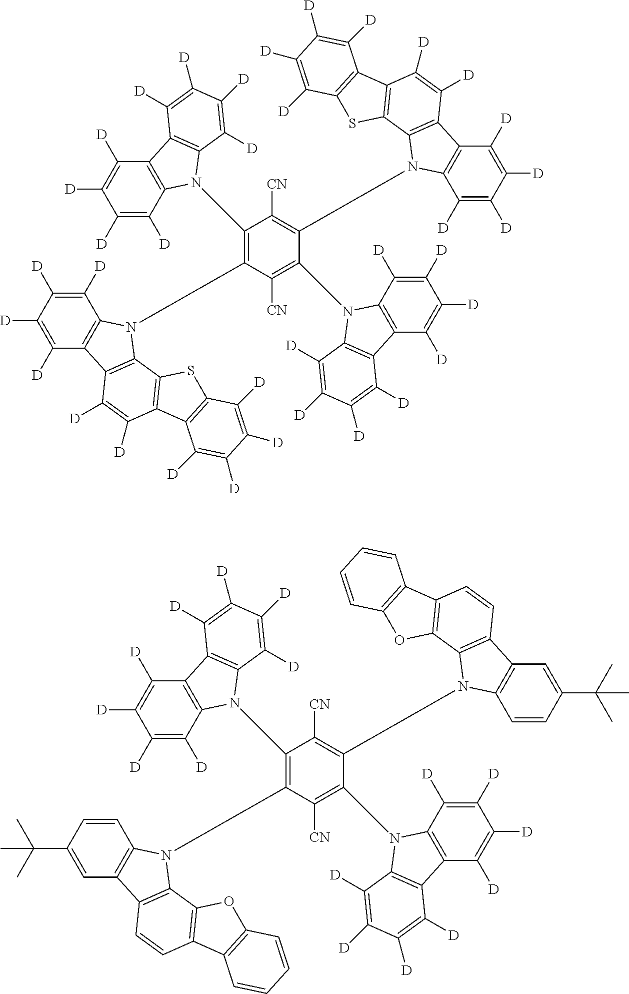

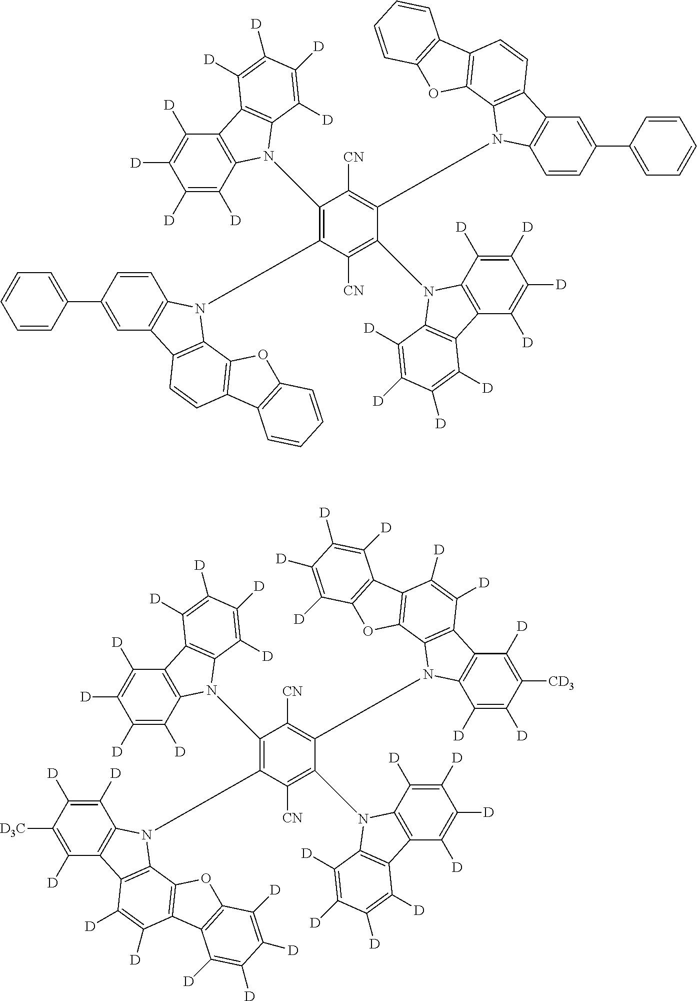

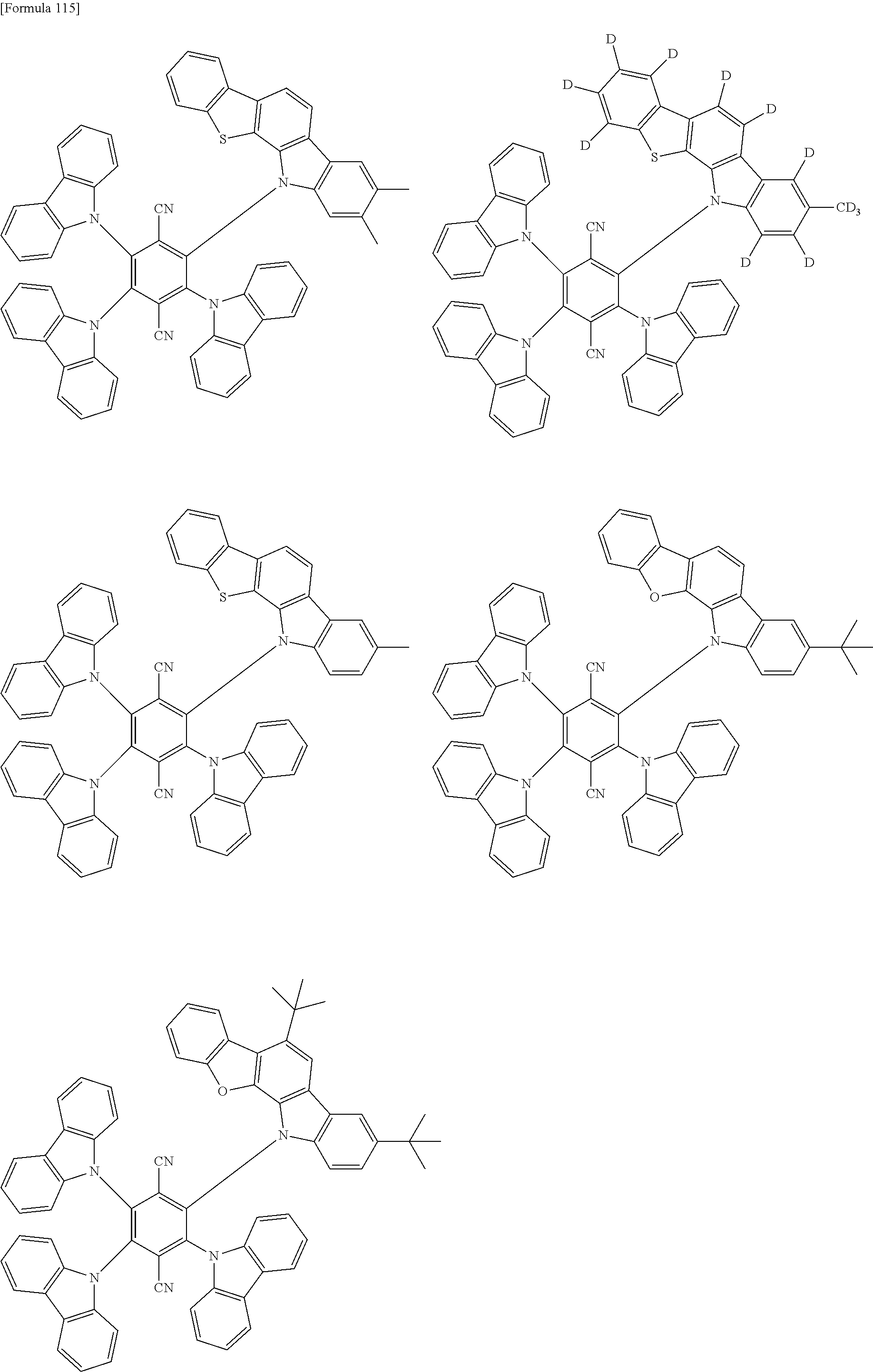

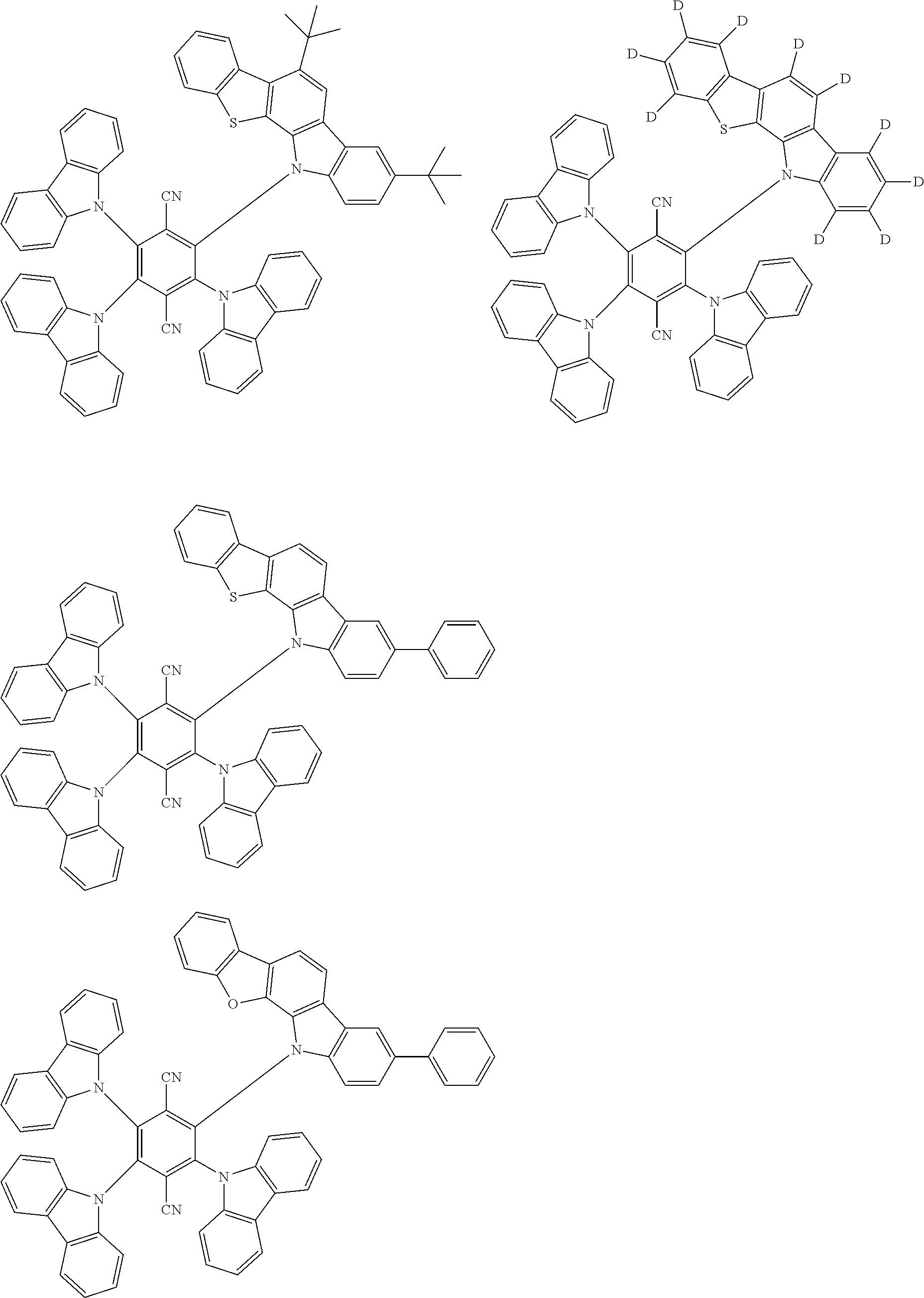

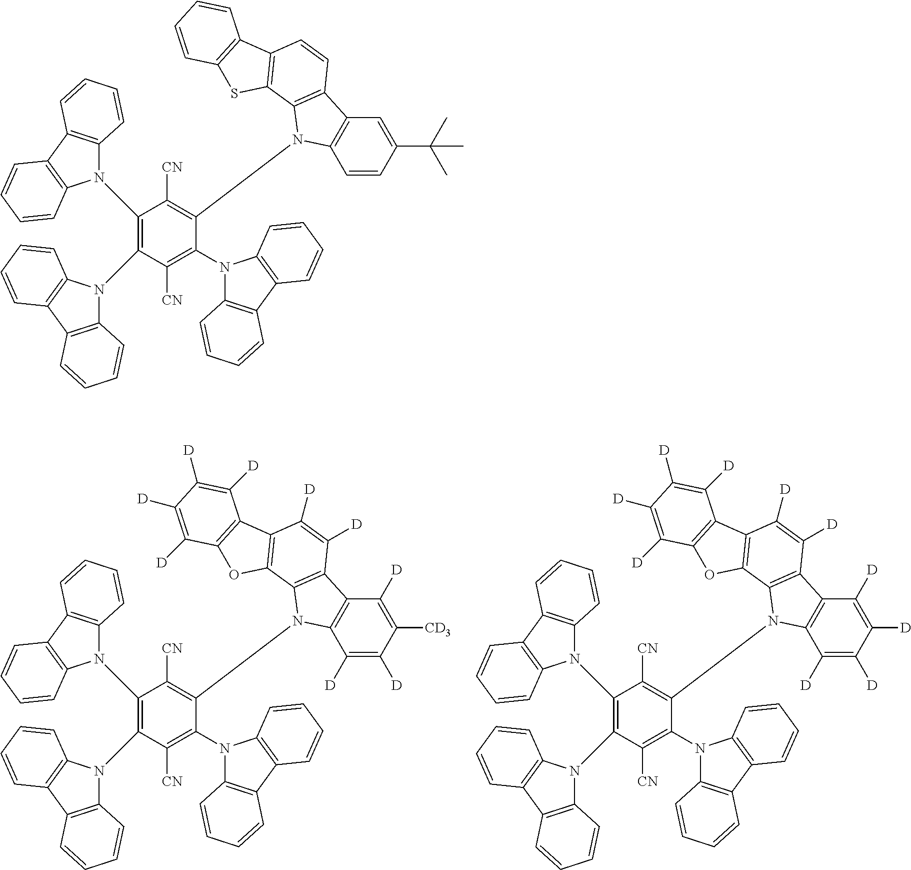 [SMILES: CC(C)(C)c1ccc2c(c1)c1ccc3c4ccccc4sc3c1n2-c1c(C#N)c(-n2c3ccccc3c3ccccc32)c(-n2c3ccccc3c3ccccc32)c(C#N)c1-n1c2ccccc2c2ccccc21 ; [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccccc6c6ccccc65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6ccccc6c6ccccc65)c(C#N)c4-n4c5ccccc5c5ccccc54)c32)c1[2H]]

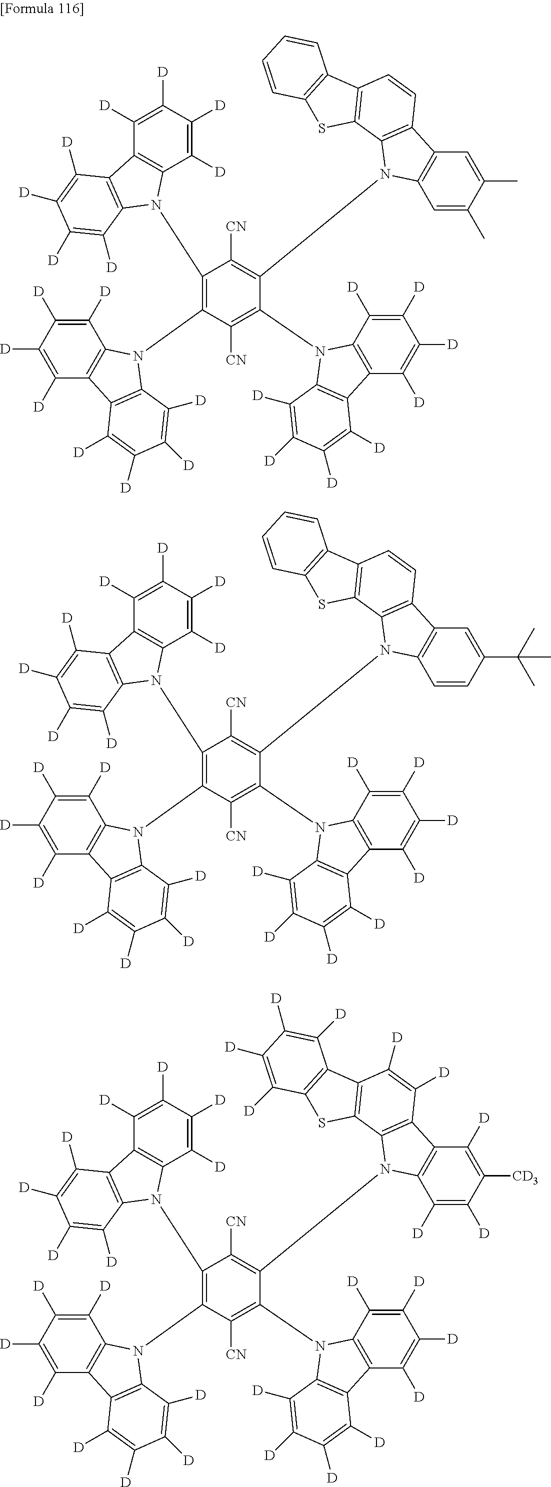

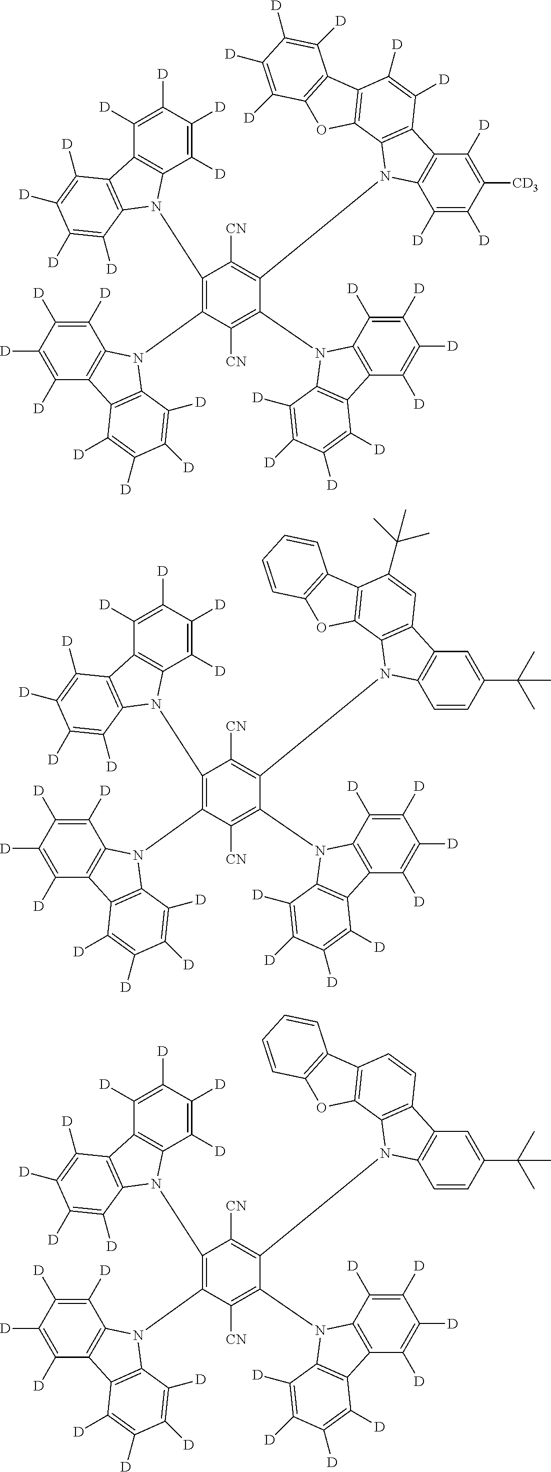

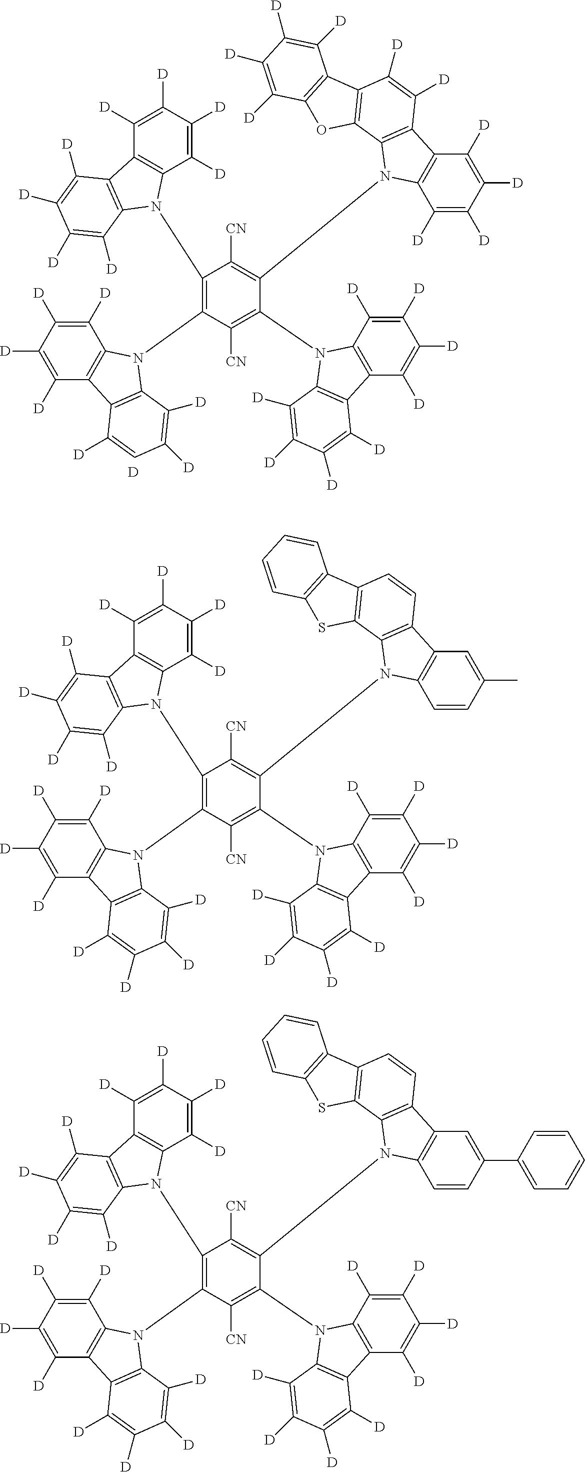

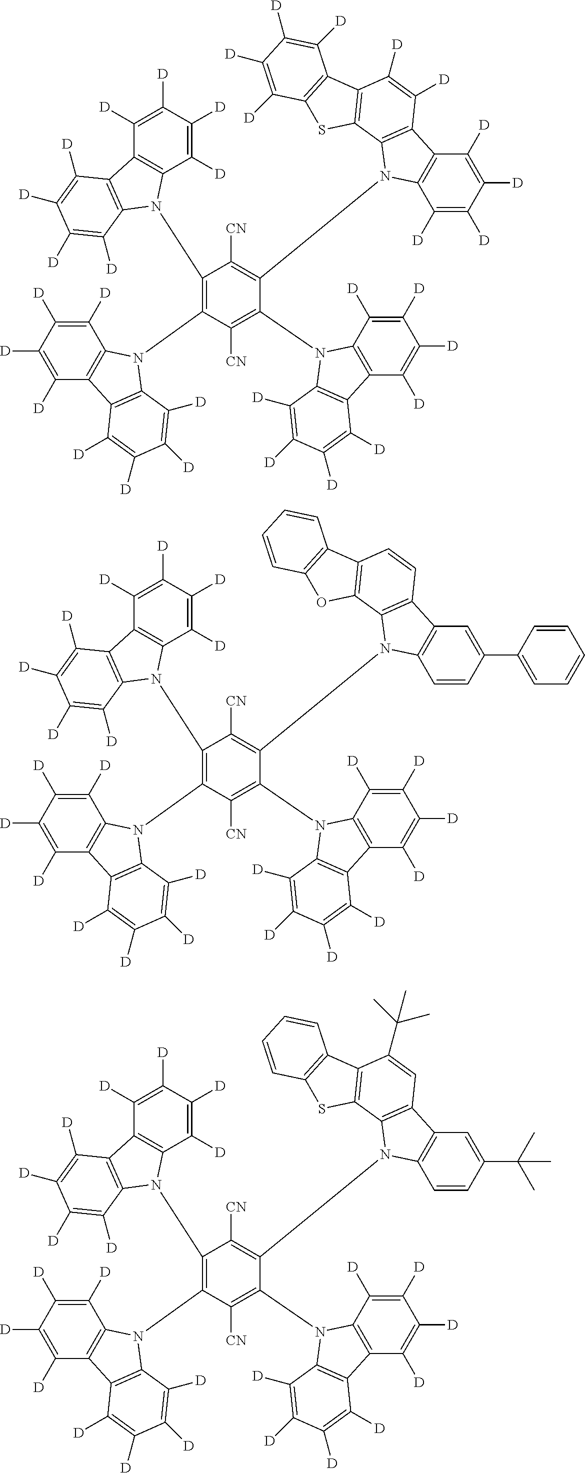

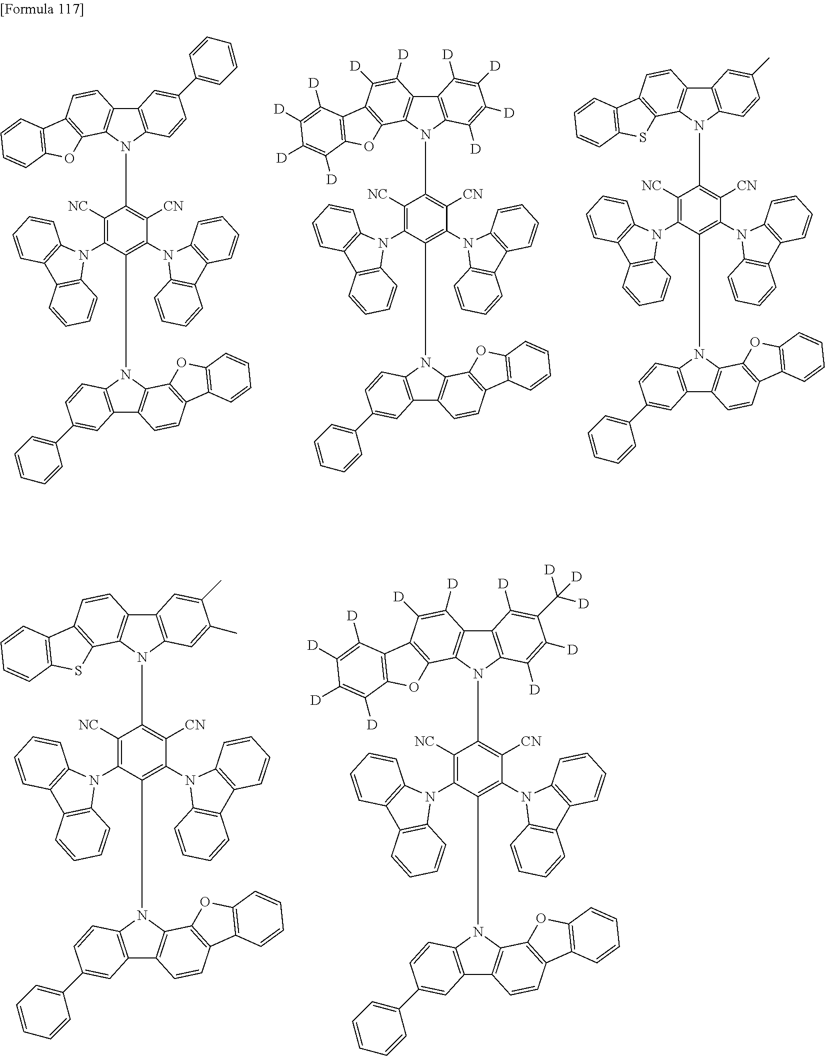

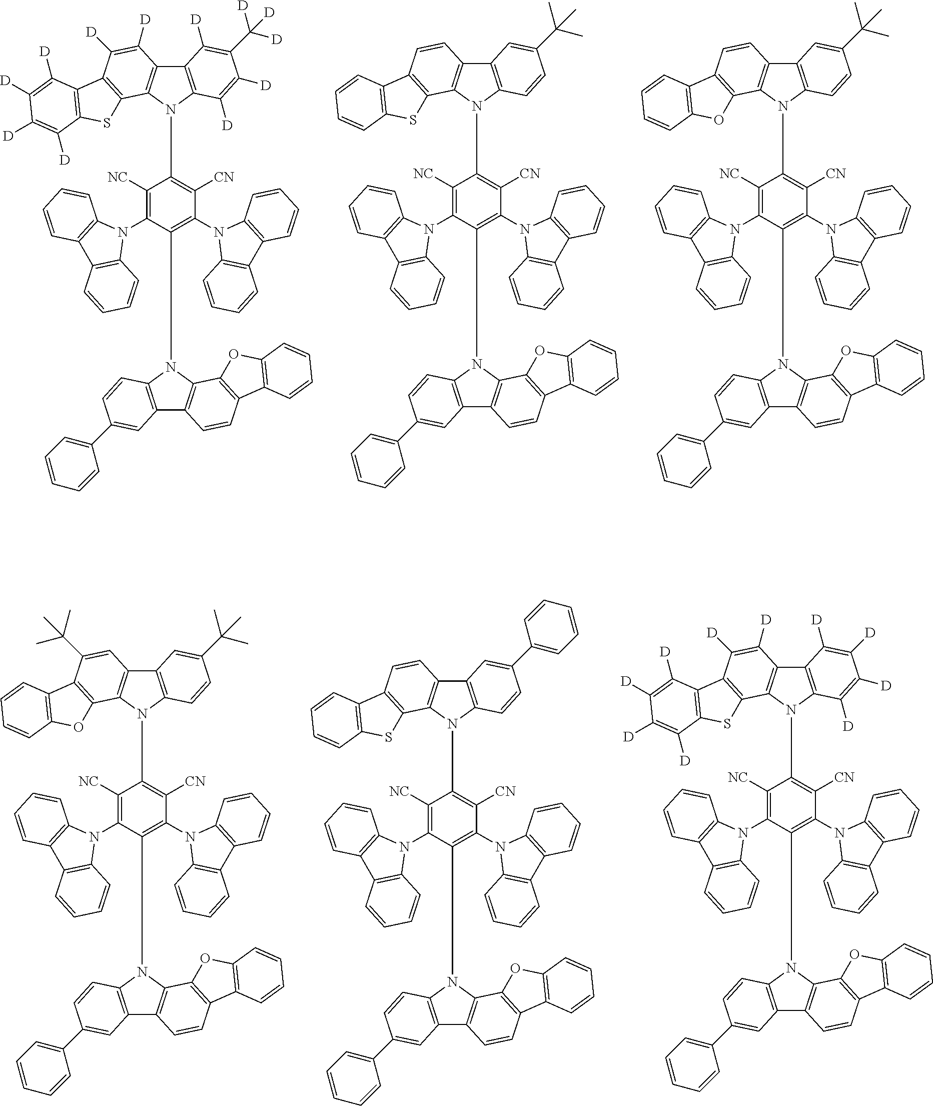

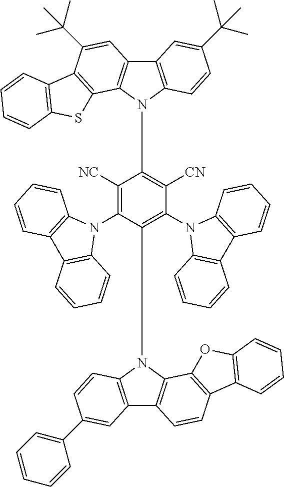 [SMILES: CC(C)(C)c1ccc2c(c1)c1cc(C(C)(C)C)c3c4ccccc4sc3c1n2-c1c(C#N)c(-n2c3ccccc3c3ccccc32)c(-n2c3ccc(-c4ccccc4)cc3c3ccc4c5ccccc5oc4c32)c(-n2c3ccccc3c3ccccc32)c1C#N]

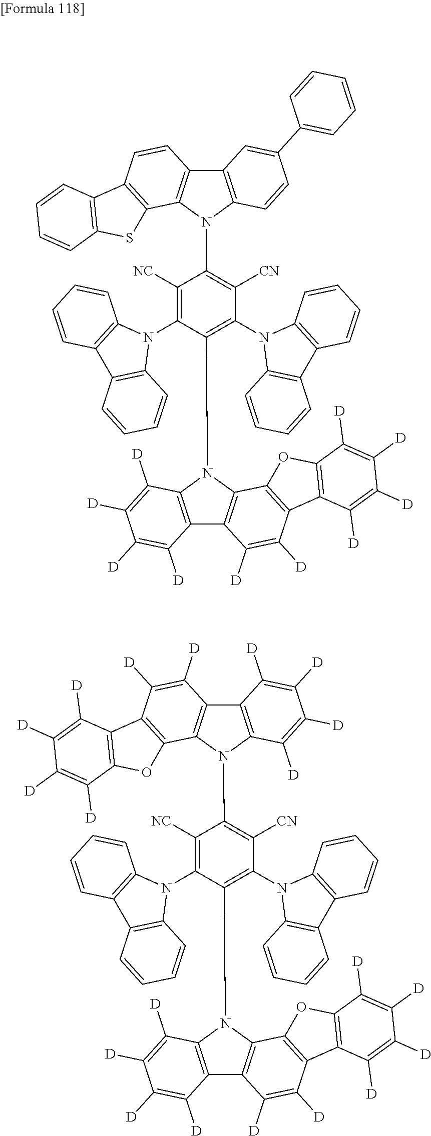 [SMILES: [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6ccc(-c7ccccc7)cc6c6ccc7c8ccccc8sc7c65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6c([2H])c([2H])c([2H])c([2H])c6c6c([2H])c([2H])c7c(oc8c([2H])c([2H])c([2H])c([2H])c87)c65)c(-n5c6ccccc6c6ccccc65)c4C#N)c32)c1[2H]]

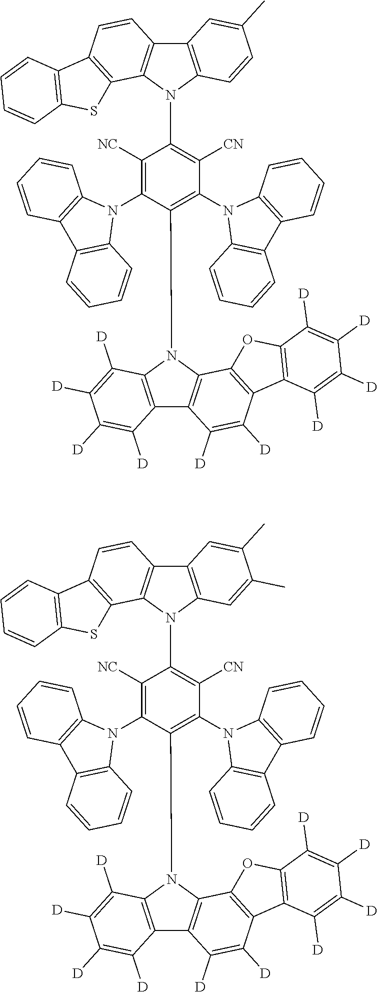 [SMILES: [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6ccc(C)cc6c6ccc7c8ccccc8sc7c65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6cc(C)c(C)cc6c6ccc7c8ccccc8sc7c65)c(C#N)c4-n4c5ccccc5c5ccccc54)c32)c1[2H]]

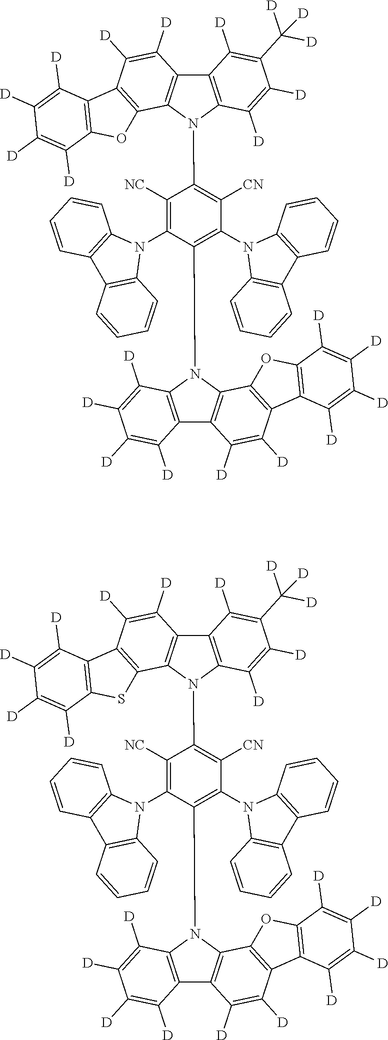

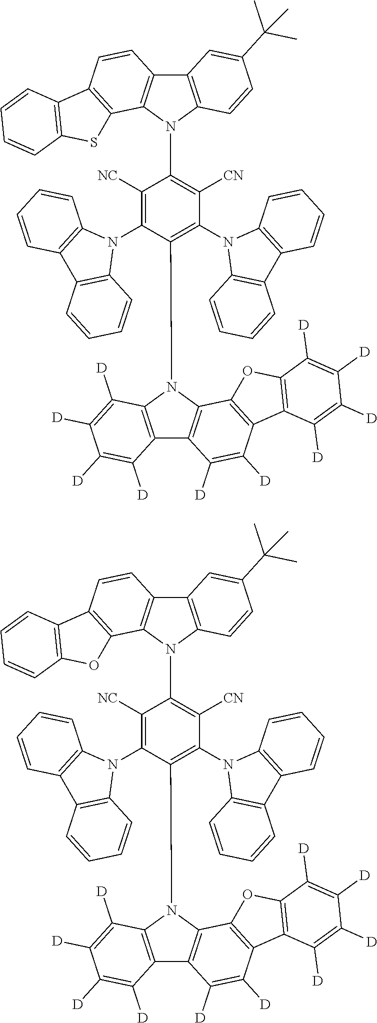

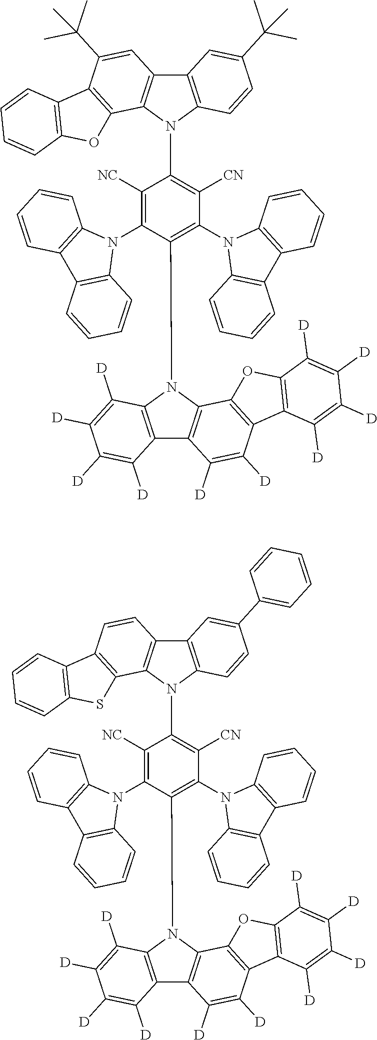 [SMILES: [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6ccc(C(C)(C)C)cc6c6cc(C(C)(C)C)c7c8ccccc8oc7c65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6ccc(-c7ccccc7)cc6c6ccc7c8ccccc8sc7c65)c(C#N)c4-n4c5ccccc5c5ccccc54)c32)c1[2H]]

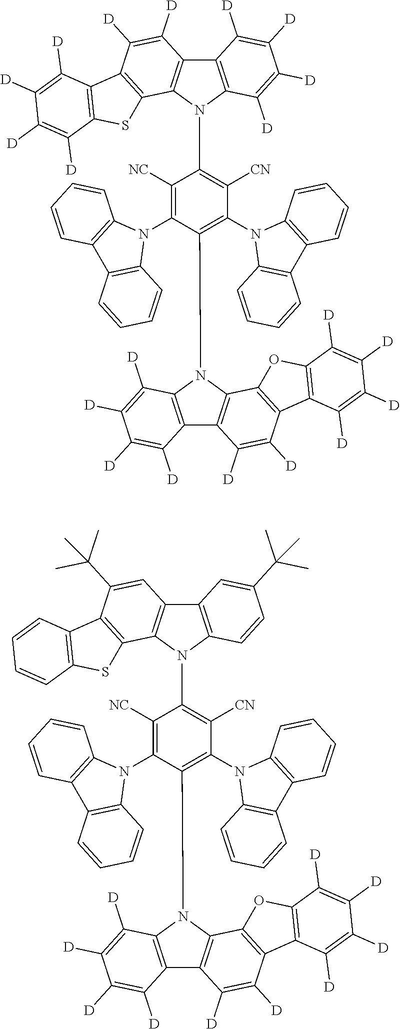 [SMILES: [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6c([2H])c([2H])c([2H])c([2H])c6c6c([2H])c([2H])c7c(sc8c([2H])c([2H])c([2H])c([2H])c87)c65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(-n5c6ccccc6c6ccccc65)c(C#N)c(-n5c6ccc(C(C)(C)C)cc6c6cc(C(C)(C)C)c7c8ccccc8sc7c65)c(C#N)c4-n4c5ccccc5c5ccccc54)c32)c1[2H]]

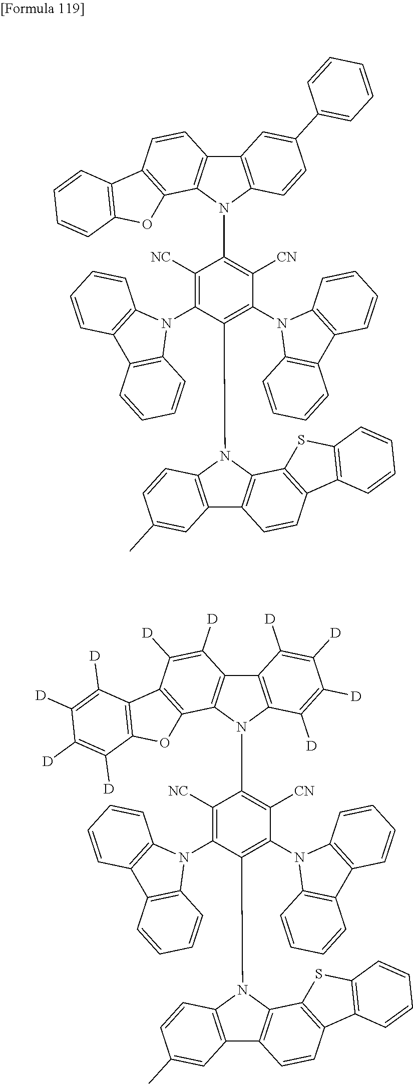 [SMILES: Cc1ccc2c(c1)c1ccc3c4ccccc4sc3c1n2-c1c(-n2c3ccccc3c3ccccc32)c(C#N)c(-n2c3ccc(-c4ccccc4)cc3c3ccc4c5ccccc5oc4c32)c(C#N)c1-n1c2ccccc2c2ccccc21 ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6ccc(C)cc6c6ccc7c8ccccc8sc7c65)c(-n5c6ccccc6c6ccccc65)c4C#N)c32)c1[2H]]

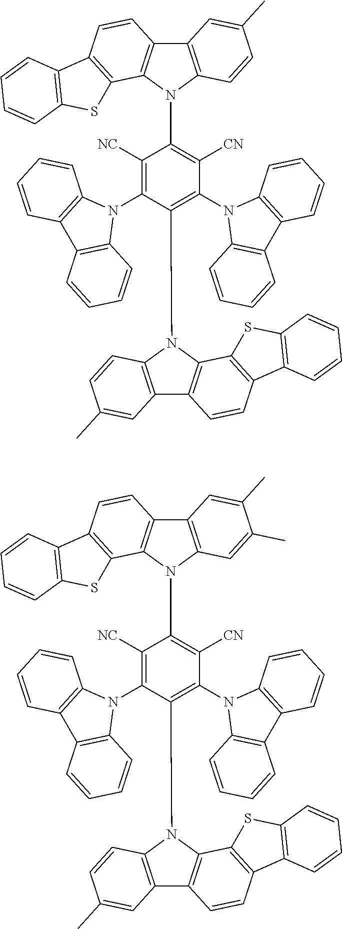 [SMILES: Cc1ccc2c(c1)c1ccc3c4ccccc4sc3c1n2-c1c(C#N)c(-n2c3ccccc3c3ccccc32)c(-n2c3ccc(C)cc3c3ccc4c5ccccc5sc4c32)c(-n2c3ccccc3c3ccccc32)c1C#N ; Cc1ccc2c(c1)c1ccc3c4ccccc4sc3c1n2-c1c(-n2c3ccccc3c3ccccc32)c(C#N)c(-n2c3cc(C)c(C)cc3c3ccc4c5ccccc5sc4c32)c(C#N)c1-n1c2ccccc2c2ccccc21]

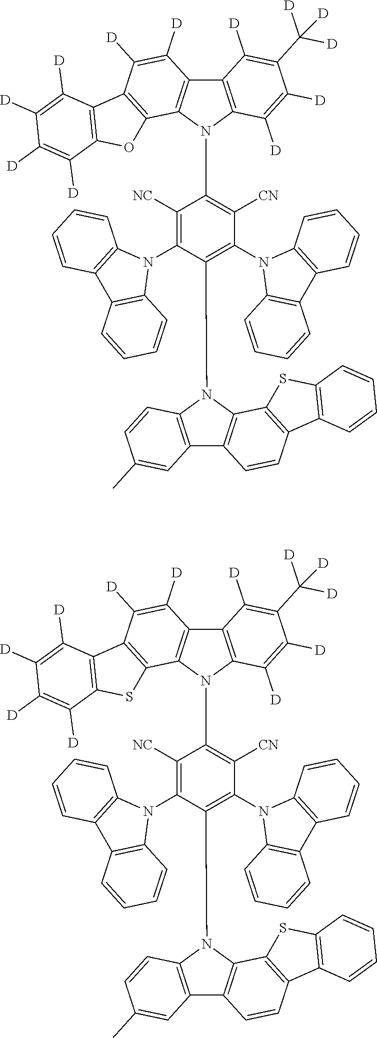 [SMILES: [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(C)cc6c6ccc7c8ccccc8sc7c65)c(-n5c6ccccc6c6ccccc65)c4C#N)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(C)cc6c6ccc7c8ccccc8sc7c65)c(-n5c6ccccc6c6ccccc65)c4C#N)c32)c1[2H]]

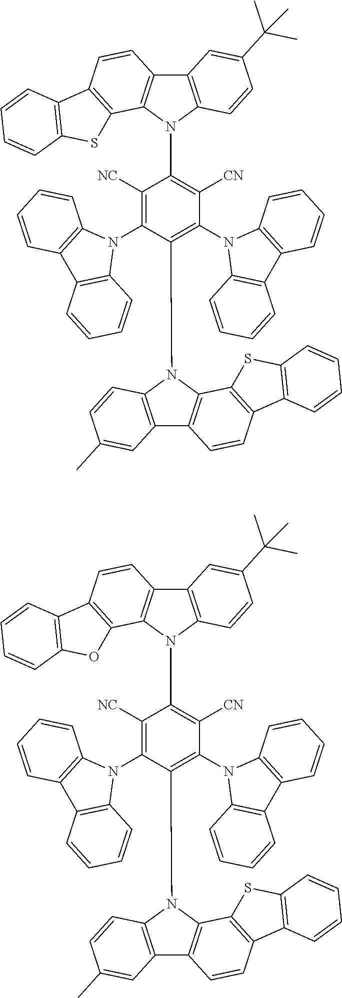 [SMILES: Cc1ccc2c(c1)c1ccc3c4ccccc4sc3c1n2-c1c(-n2c3ccccc3c3ccccc32)c(C#N)c(-n2c3ccc(C(C)(C)C)cc3c3ccc4c5ccccc5sc4c32)c(C#N)c1-n1c2ccccc2c2ccccc21 ; Cc1ccc2c(c1)c1ccc3c4ccccc4sc3c1n2-c1c(-n2c3ccccc3c3ccccc32)c(C#N)c(-n2c3ccc(C(C)(C)C)cc3c3ccc4c5ccccc5oc4c32)c(C#N)c1-n1c2ccccc2c2ccccc21]

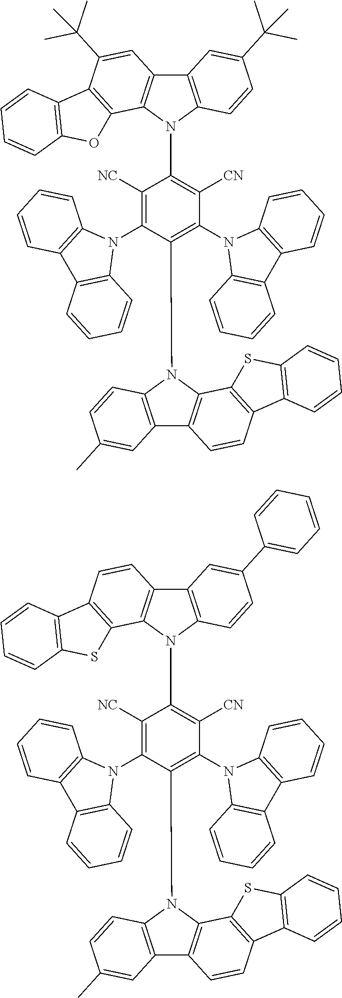 [SMILES: Cc1ccc2c(c1)c1ccc3c4ccccc4sc3c1n2-c1c(-n2c3ccccc3c3ccccc32)c(C#N)c(-n2c3ccc(C(C)(C)C)cc3c3cc(C(C)(C)C)c4c5ccccc5oc4c32)c(C#N)c1-n1c2ccccc2c2ccccc21 ; Cc1ccc2c(c1)c1ccc3c4ccccc4sc3c1n2-c1c(-n2c3ccccc3c3ccccc32)c(C#N)c(-n2c3ccc(-c4ccccc4)cc3c3ccc4c5ccccc5sc4c32)c(C#N)c1-n1c2ccccc2c2ccccc21]

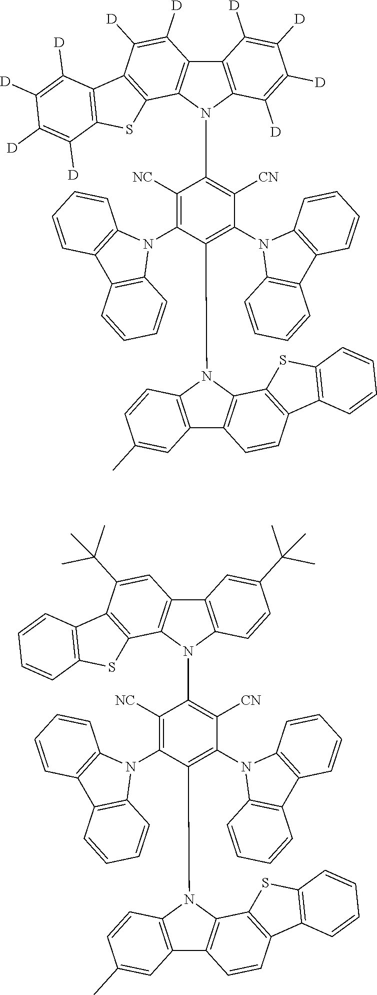 [SMILES: [2H]c1c([2H])c([2H])c2c(sc3c2c([2H])c([2H])c2c4c([2H])c([2H])c([2H])c([2H])c4n(-c4c(C#N)c(-n5c6ccccc6c6ccccc65)c(-n5c6ccc(C)cc6c6ccc7c8ccccc8sc7c65)c(-n5c6ccccc6c6ccccc65)c4C#N)c32)c1[2H] ; Cc1ccc2c(c1)c1ccc3c4ccccc4sc3c1n2-c1c(-n2c3ccccc3c3ccccc32)c(C#N)c(-n2c3ccc(C(C)(C)C)cc3c3cc(C(C)(C)C)c4c5ccccc5sc4c32)c(C#N)c1-n1c2ccccc2c2ccccc21]

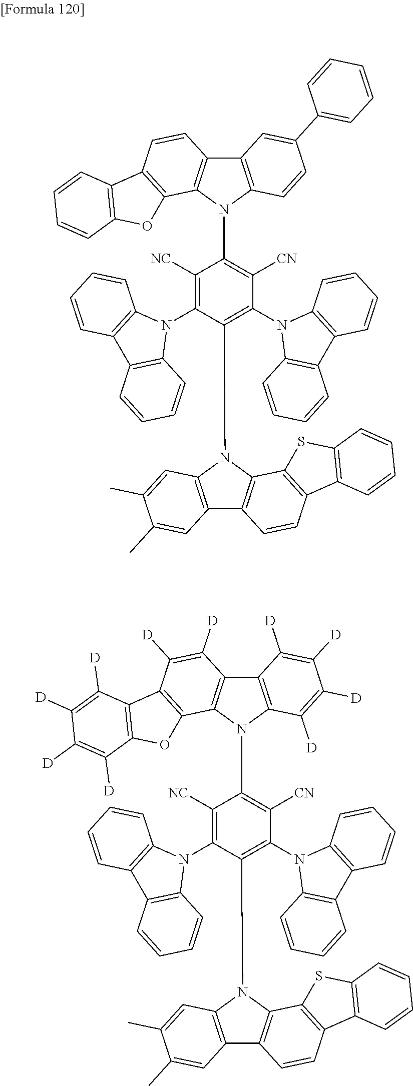 [SMILES: Cc1cc2c3ccc4c5ccccc5sc4c3n(-c3c(-n4c5ccccc5c5ccccc54)c(C#N)c(-n4c5ccc(-c6ccccc6)cc5c5ccc6c7ccccc7oc6c54)c(C#N)c3-n3c4ccccc4c4ccccc43)c2cc1C ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6cc(C)c(C)cc6c6ccc7c8ccccc8sc7c65)c(-n5c6ccccc6c6ccccc65)c4C#N)c32)c1[2H]]

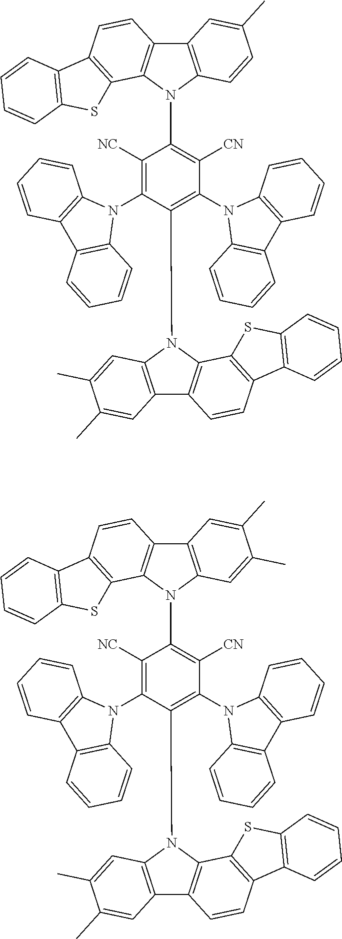 [SMILES: Cc1ccc2c(c1)c1ccc3c4ccccc4sc3c1n2-c1c(C#N)c(-n2c3ccccc3c3ccccc32)c(-n2c3cc(C)c(C)cc3c3ccc4c5ccccc5sc4c32)c(-n2c3ccccc3c3ccccc32)c1C#N ; Cc1cc2c3ccc4c5ccccc5sc4c3n(-c3c(C#N)c(-n4c5ccccc5c5ccccc54)c(-n4c5cc(C)c(C)cc5c5ccc6c7ccccc7sc6c54)c(-n4c5ccccc5c5ccccc54)c3C#N)c2cc1C]

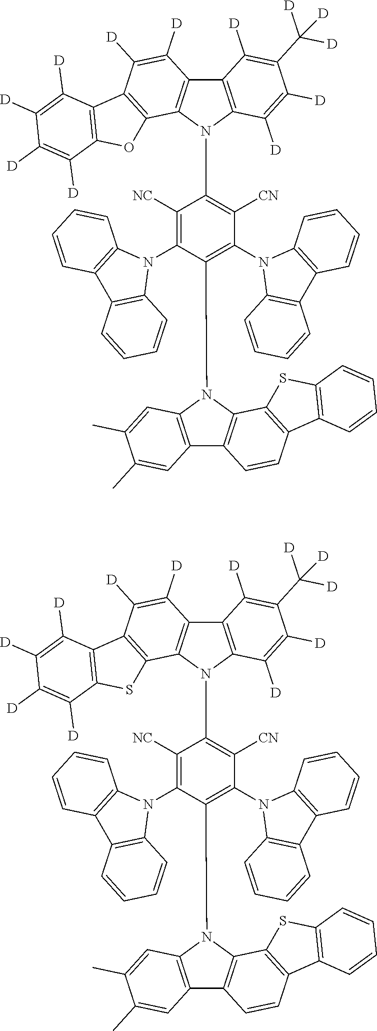 [SMILES: [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6cc(C)c(C)cc6c6ccc7c8ccccc8sc7c65)c(-n5c6ccccc6c6ccccc65)c4C#N)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(C#N)c(-n5c6ccccc6c6ccccc65)c(-n5c6cc(C)c(C)cc6c6ccc7c8ccccc8sc7c65)c(-n5c6ccccc6c6ccccc65)c4C#N)c32)c1[2H]]

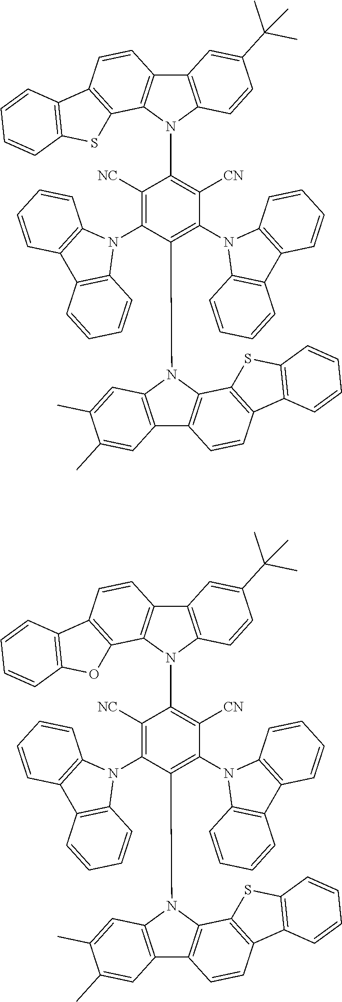 [SMILES: Cc1cc2c3ccc4c5ccccc5sc4c3n(-c3c(-n4c5ccccc5c5ccccc54)c(C#N)c(-n4c5ccc(C(C)(C)C)cc5c5ccc6c7ccccc7sc6c54)c(C#N)c3-n3c4ccccc4c4ccccc43)c2cc1C ; Cc1cc2c3ccc4c5ccccc5sc4c3n(-c3c(-n4c5ccccc5c5ccccc54)c(C#N)c(-n4c5ccc(C(C)(C)C)cc5c5ccc6c7ccccc7oc6c54)c(C#N)c3-n3c4ccccc4c4ccccc43)c2cc1C]

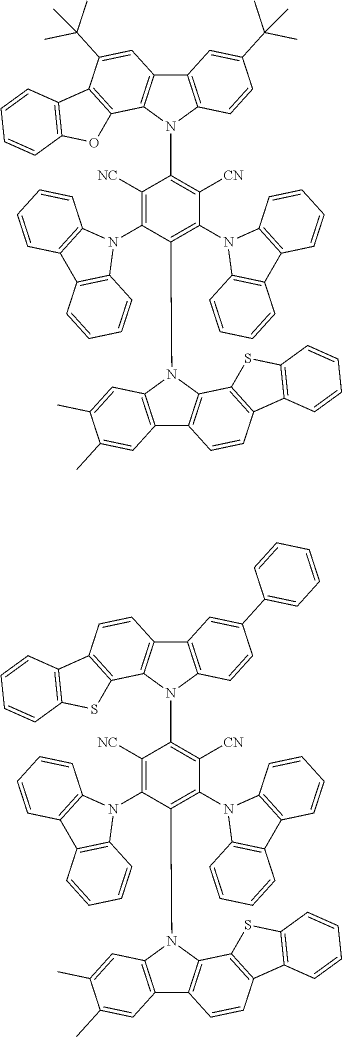 [SMILES: Cc1cc2c3ccc4c5ccccc5sc4c3n(-c3c(-n4c5ccccc5c5ccccc54)c(C#N)c(-n4c5ccc(C(C)(C)C)cc5c5cc(C(C)(C)C)c6c7ccccc7oc6c54)c(C#N)c3-n3c4ccccc4c4ccccc43)c2cc1C ; Cc1cc2c3ccc4c5ccccc5sc4c3n(-c3c(-n4c5ccccc5c5ccccc54)c(C#N)c(-n4c5ccc(-c6ccccc6)cc5c5ccc6c7ccccc7sc6c54)c(C#N)c3-n3c4ccccc4c4ccccc43)c2cc1C]

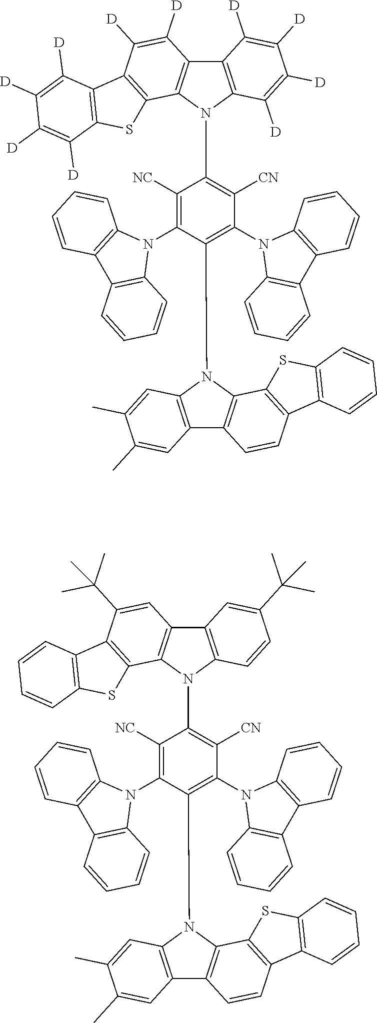 [SMILES: [2H]c1c([2H])c([2H])c2c(sc3c2c([2H])c([2H])c2c4c([2H])c([2H])c([2H])c([2H])c4n(-c4c(C#N)c(-n5c6ccccc6c6ccccc65)c(-n5c6cc(C)c(C)cc6c6ccc7c8ccccc8sc7c65)c(-n5c6ccccc6c6ccccc65)c4C#N)c32)c1[2H] ; Cc1cc2c3ccc4c5ccccc5sc4c3n(-c3c(-n4c5ccccc5c5ccccc54)c(C#N)c(-n4c5ccc(C(C)(C)C)cc5c5cc(C(C)(C)C)c6c7ccccc7sc6c54)c(C#N)c3-n3c4ccccc4c4ccccc43)c2cc1C]

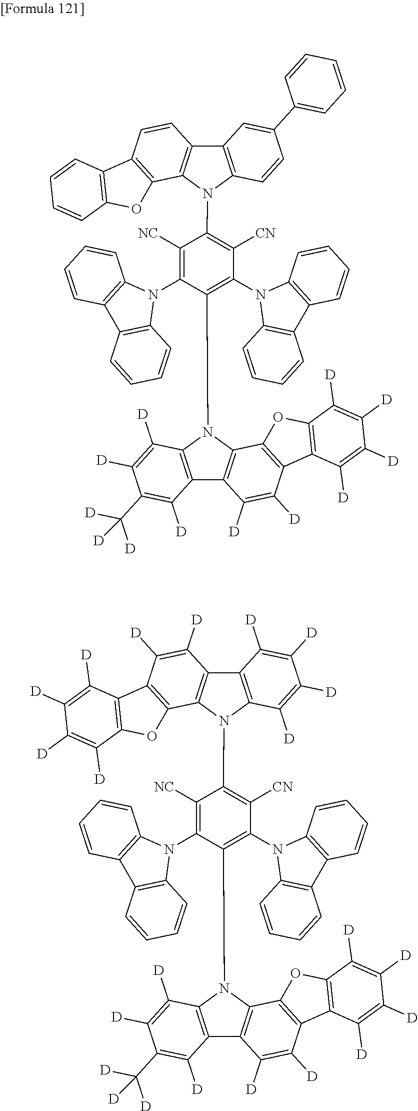 [SMILES: [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(-c7ccccc7)cc6c6ccc7c8ccccc8oc7c65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6c([2H])c([2H])c(C([2H])([2H])[2H])c([2H])c6c6c([2H])c([2H])c7c(oc8c([2H])c([2H])c([2H])c([2H])c87)c65)c(-n5c6ccccc6c6ccccc65)c4C#N)c32)c1[2H]]

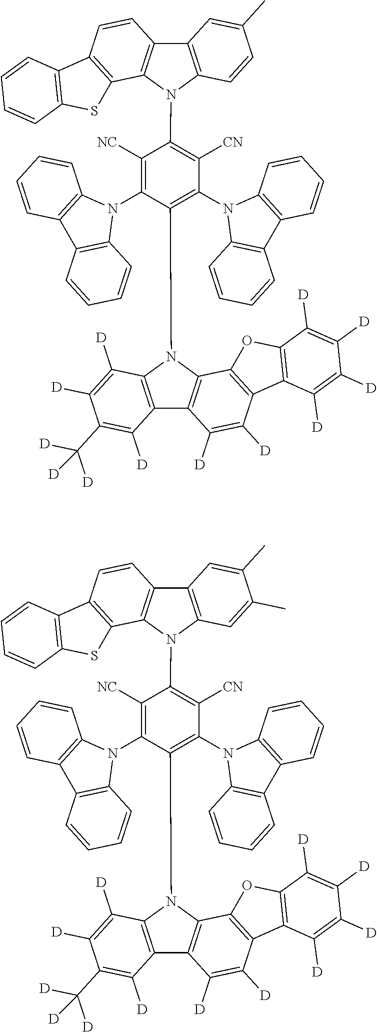 [SMILES: [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C)cc6c6ccc7c8ccccc8sc7c65)c(C#N)c4-n4c5ccccc5c5ccccc54)c32)c1[2H] ; [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6cc(C)c(C)cc6c6ccc7c8ccccc8sc7c65)c(C#N)c4-n4c5ccccc5c5ccccc54)c32)c1[2H]]

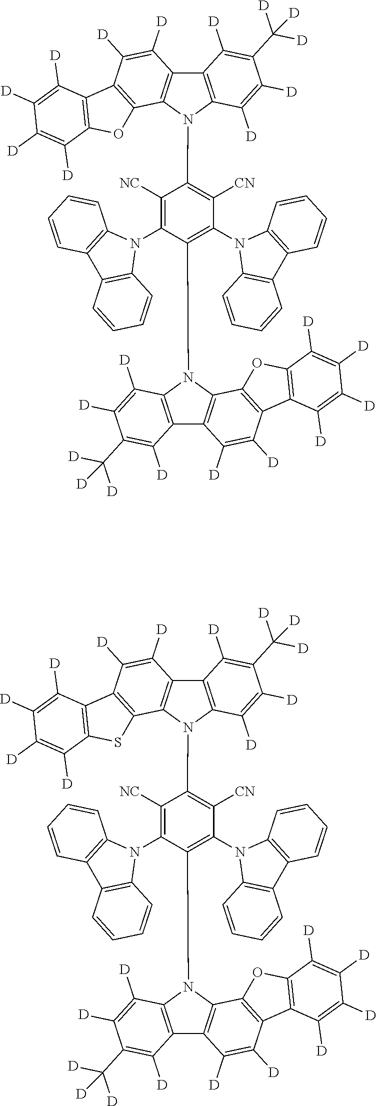

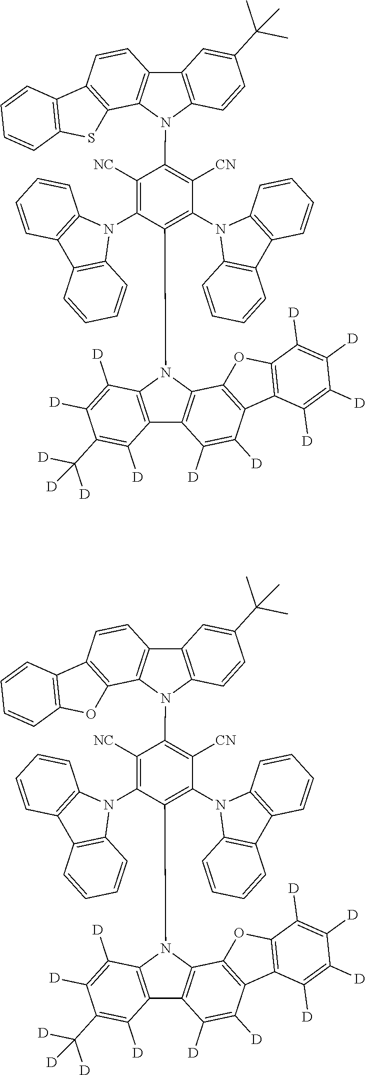 [SMILES: [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6ccc7c8ccccc8sc7c65)c(C#N)c4-n4c5ccccc5c5ccccc54)c32)c1[2H] ; [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6ccc7c8ccccc8oc7c65)c(C#N)c4-n4c5ccccc5c5ccccc54)c32)c1[2H]]

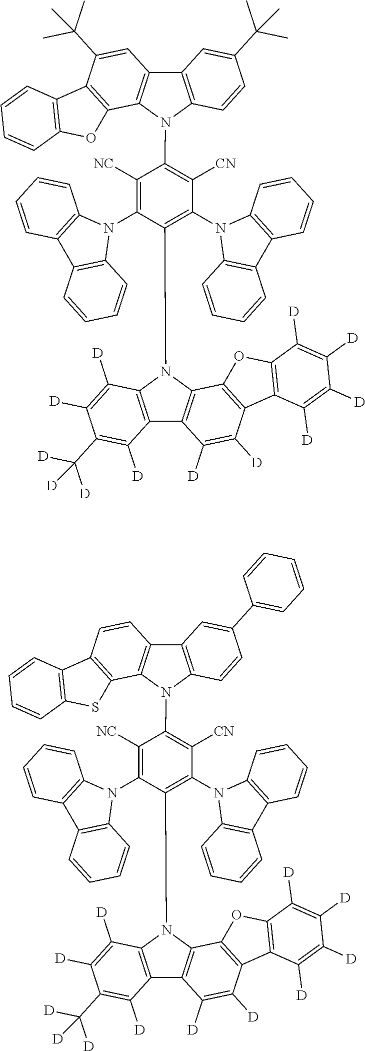 [SMILES: [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6cc(C(C)(C)C)c7c8ccccc8oc7c65)c(C#N)c4-n4c5ccccc5c5ccccc54)c32)c1[2H] ; [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(-c7ccccc7)cc6c6ccc7c8ccccc8sc7c65)c(C#N)c4-n4c5ccccc5c5ccccc54)c32)c1[2H]]

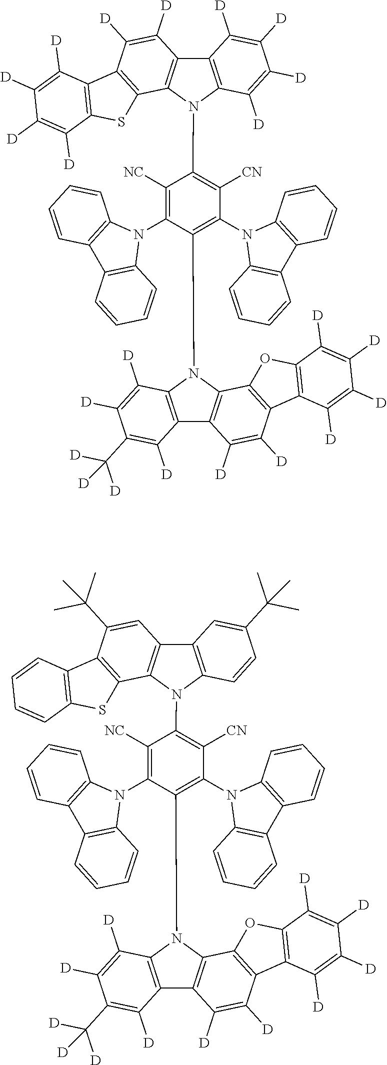 [SMILES: [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6c([2H])c([2H])c([2H])c([2H])c6c6c([2H])c([2H])c7c(sc8c([2H])c([2H])c([2H])c([2H])c87)c65)c(C#N)c4-n4c5ccccc5c5ccccc54)c32)c1[2H] ; [2H]c1c([2H])c([2H])c2c(oc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6cc(C(C)(C)C)c7c8ccccc8sc7c65)c(C#N)c4-n4c5ccccc5c5ccccc54)c32)c1[2H]]

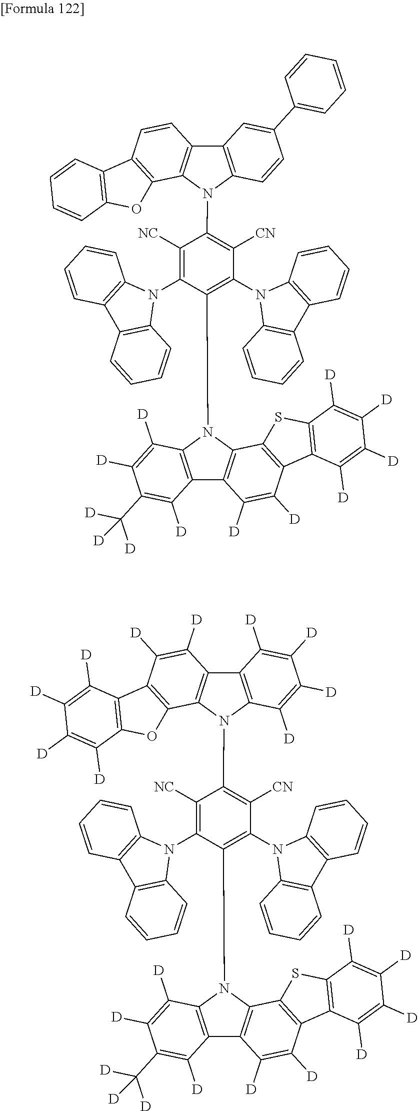 [SMILES: [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(-c7ccccc7)cc6c6ccc7c8ccccc8oc7c65)c(C#N)c4-n4c5ccccc5c5ccccc54)c32)c1[2H] ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6c([2H])c([2H])c(C([2H])([2H])[2H])c([2H])c6c6c([2H])c([2H])c7c(sc8c([2H])c([2H])c([2H])c([2H])c87)c65)c(-n5c6ccccc6c6ccccc65)c4C#N)c32)c1[2H]]

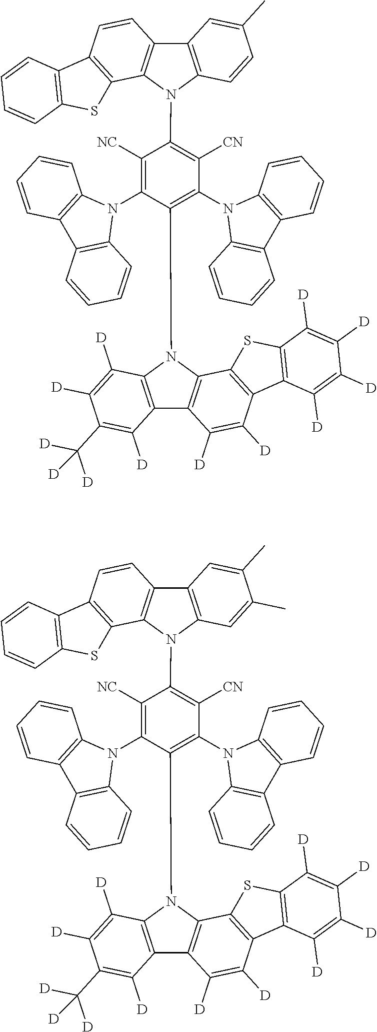 [SMILES: [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C)cc6c6ccc7c8ccccc8sc7c65)c(C#N)c4-n4c5ccccc5c5ccccc54)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6cc(C)c(C)cc6c6ccc7c8ccccc8sc7c65)c(C#N)c4-n4c5ccccc5c5ccccc54)c32)c1[2H]]

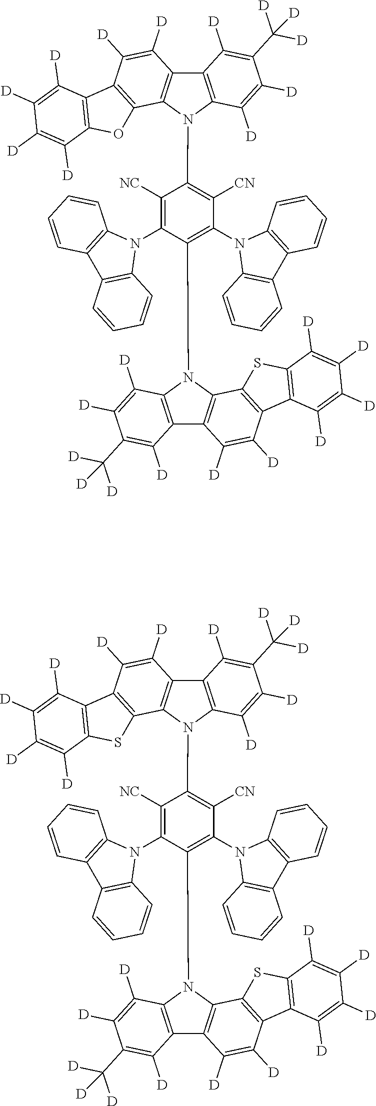

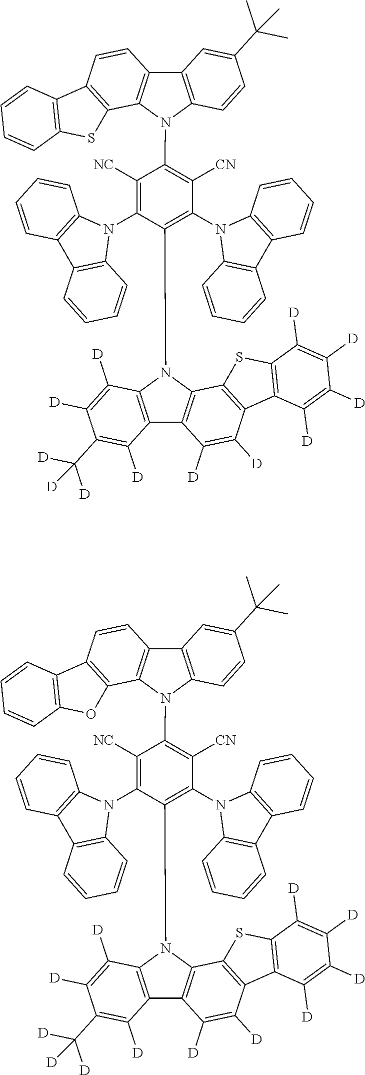 [SMILES: [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6ccc7c8ccccc8sc7c65)c(C#N)c4-n4c5ccccc5c5ccccc54)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6ccc7c8ccccc8oc7c65)c(C#N)c4-n4c5ccccc5c5ccccc54)c32)c1[2H]]

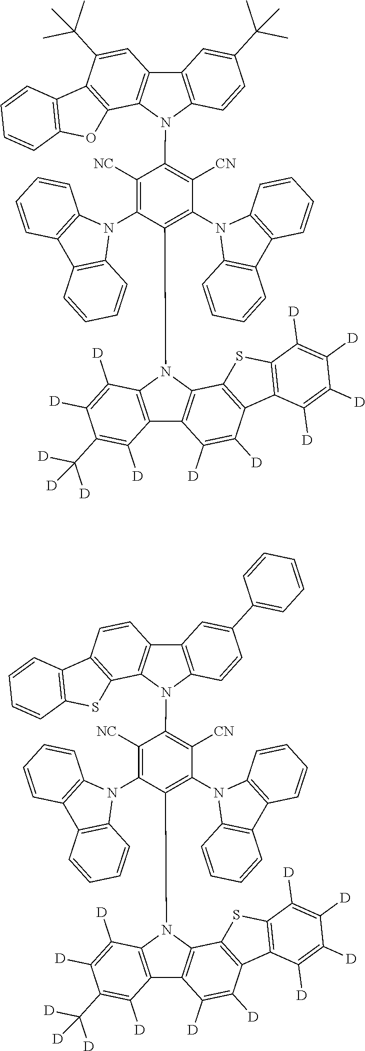 [SMILES: [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6cc(C(C)(C)C)c7c8ccccc8oc7c65)c(C#N)c4-n4c5ccccc5c5ccccc54)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(-c7ccccc7)cc6c6ccc7c8ccccc8sc7c65)c(C#N)c4-n4c5ccccc5c5ccccc54)c32)c1[2H]]

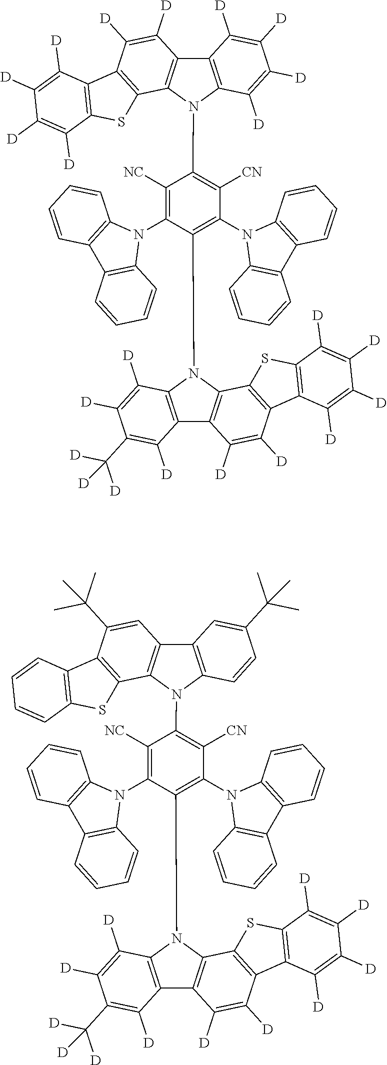 [SMILES: [2H]c1c([2H])c([2H])c2c(sc3c2c([2H])c([2H])c2c4c([2H])c([2H])c([2H])c([2H])c4n(-c4c(C#N)c(-n5c6ccccc6c6ccccc65)c(-n5c6c([2H])c([2H])c(C([2H])([2H])[2H])c([2H])c6c6c([2H])c([2H])c7c(sc8c([2H])c([2H])c([2H])c([2H])c87)c65)c(-n5c6ccccc6c6ccccc65)c4C#N)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(-n5c6ccccc6c6ccccc65)c(C#N)c(-n5c6ccc(C(C)(C)C)cc6c6cc(C(C)(C)C)c7c8ccccc8sc7c65)c(C#N)c4-n4c5ccccc5c5ccccc54)c32)c1[2H]]

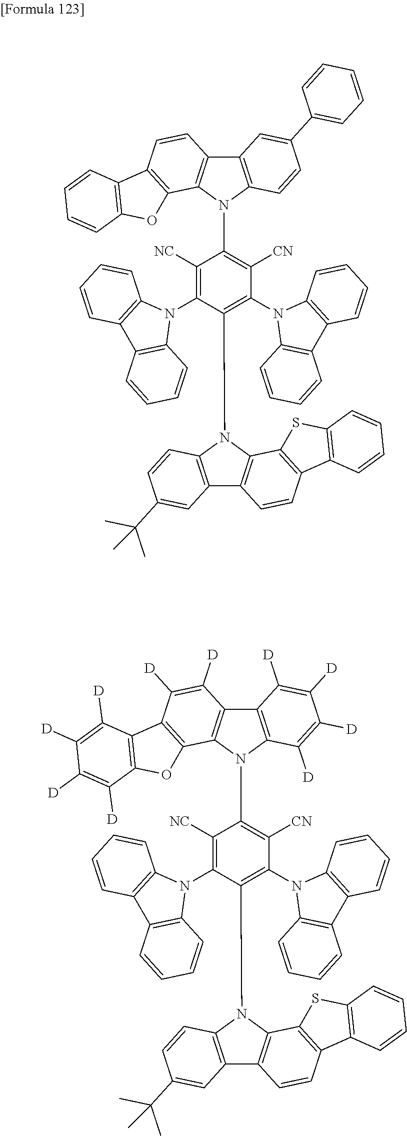 [SMILES: CC(C)(C)c1ccc2c(c1)c1ccc3c4ccccc4sc3c1n2-c1c(-n2c3ccccc3c3ccccc32)c(C#N)c(-n2c3ccc(-c4ccccc4)cc3c3ccc4c5ccccc5oc4c32)c(C#N)c1-n1c2ccccc2c2ccccc21 ; [2H]c1c([2H])c([2H])c2c(oc3c2c([2H])c([2H])c2c4c([2H])c([2H])c([2H])c([2H])c4n(-c4c(C#N)c(-n5c6ccccc6c6ccccc65)c(-n5c6ccc(C(C)(C)C)cc6c6ccc7c8ccccc8sc7c65)c(-n5c6ccccc6c6ccccc65)c4C#N)c32)c1[2H]]

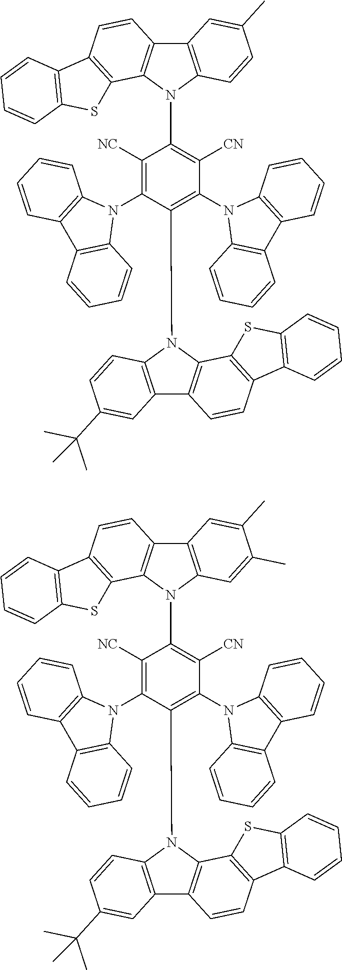 [SMILES: Cc1ccc2c(c1)c1ccc3c4ccccc4sc3c1n2-c1c(C#N)c(-n2c3ccccc3c3ccccc32)c(-n2c3ccc(C(C)(C)C)cc3c3ccc4c5ccccc5sc4c32)c(-n2c3ccccc3c3ccccc32)c1C#N ; Cc1cc2c3ccc4c5ccccc5sc4c3n(-c3c(C#N)c(-n4c5ccccc5c5ccccc54)c(-n4c5ccc(C(C)(C)C)cc5c5ccc6c7ccccc7sc6c54)c(-n4c5ccccc5c5ccccc54)c3C#N)c2cc1C]

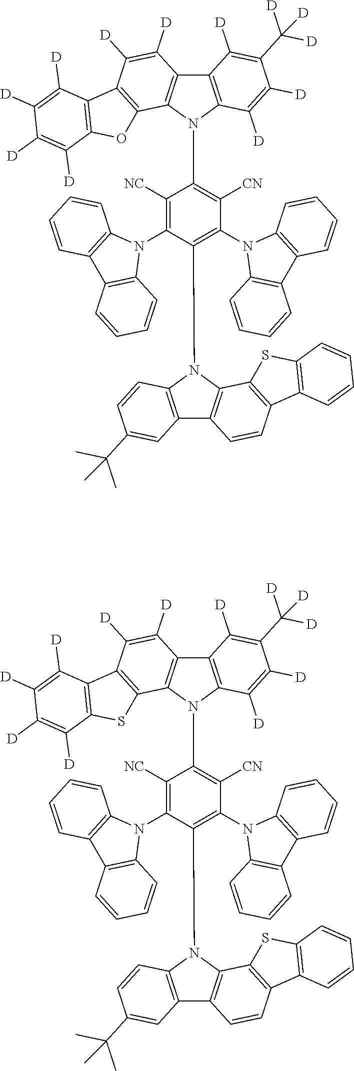 [SMILES: [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(C(C)(C)C)cc6c6ccc7c8ccccc8sc7c65)c(-n5c6ccccc6c6ccccc65)c4C#N)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(C(C)(C)C)cc6c6ccc7c8ccccc8sc7c65)c(-n5c6ccccc6c6ccccc65)c4C#N)c32)c1[2H]]

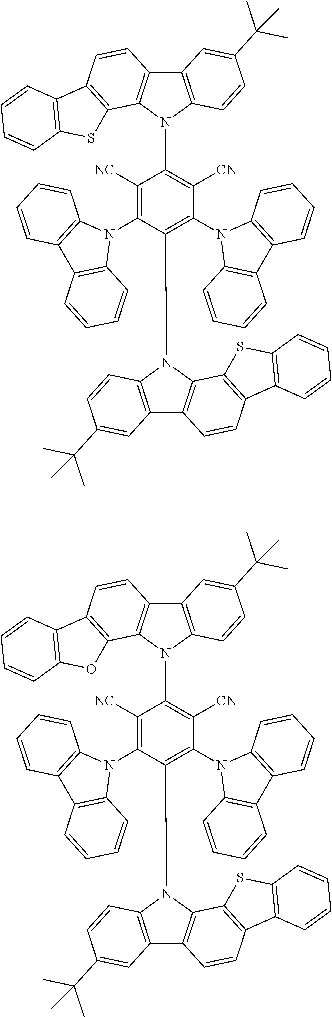 [SMILES: CC(C)(C)c1ccc2c(c1)c1ccc3c4ccccc4sc3c1n2-c1c(C#N)c(-n2c3ccccc3c3ccccc32)c(-n2c3ccc(C(C)(C)C)cc3c3ccc4c5ccccc5sc4c32)c(-n2c3ccccc3c3ccccc32)c1C#N ; CC(C)(C)c1ccc2c(c1)c1ccc3c4ccccc4oc3c1n2-c1c(C#N)c(-n2c3ccccc3c3ccccc32)c(-n2c3ccc(C(C)(C)C)cc3c3ccc4c5ccccc5sc4c32)c(-n2c3ccccc3c3ccccc32)c1C#N]

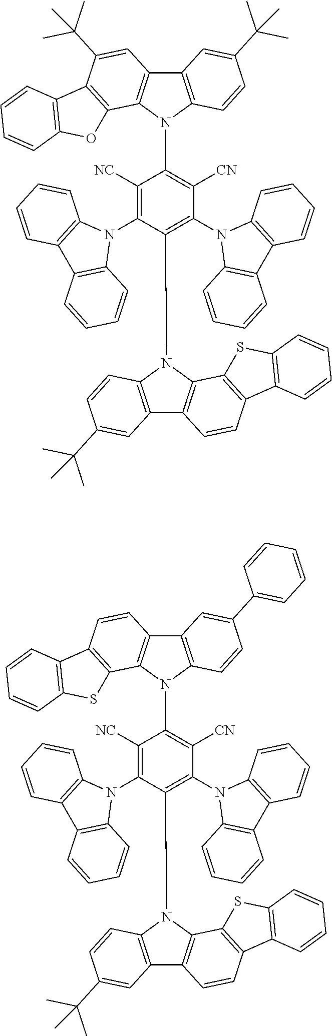 [SMILES: CC(C)(C)c1ccc2c(c1)c1cc(C(C)(C)C)c3c4ccccc4oc3c1n2-c1c(C#N)c(-n2c3ccccc3c3ccccc32)c(-n2c3ccc(C(C)(C)C)cc3c3ccc4c5ccccc5sc4c32)c(-n2c3ccccc3c3ccccc32)c1C#N ; CC(C)(C)c1ccc2c(c1)c1ccc3c4ccccc4sc3c1n2-c1c(-n2c3ccccc3c3ccccc32)c(C#N)c(-n2c3ccc(-c4ccccc4)cc3c3ccc4c5ccccc5sc4c32)c(C#N)c1-n1c2ccccc2c2ccccc21]

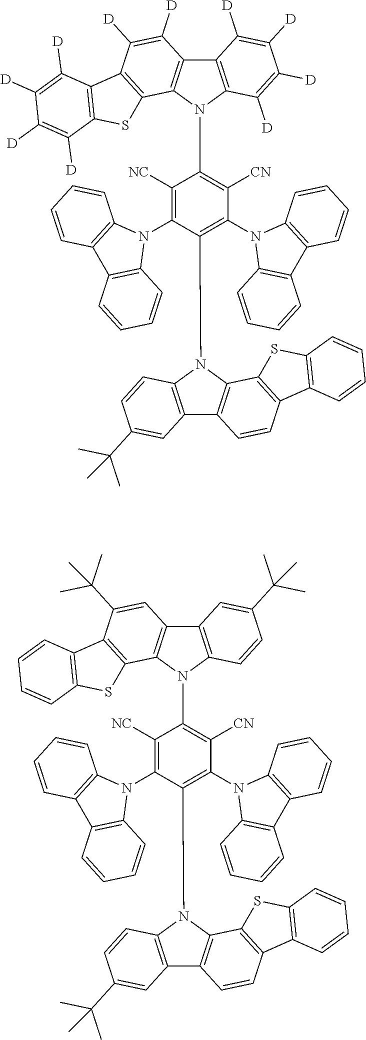 [SMILES: [2H]c1c([2H])c([2H])c2c(sc3c2c([2H])c([2H])c2c4c([2H])c([2H])c([2H])c([2H])c4n(-c4c(C#N)c(-n5c6ccccc6c6ccccc65)c(-n5c6ccc(C(C)(C)C)cc6c6ccc7c8ccccc8sc7c65)c(-n5c6ccccc6c6ccccc65)c4C#N)c32)c1[2H] ; CC(C)(C)c1ccc2c(c1)c1ccc3c4ccccc4sc3c1n2-c1c(-n2c3ccccc3c3ccccc32)c(C#N)c(-n2c3ccc(C(C)(C)C)cc3c3cc(C(C)(C)C)c4c5ccccc5sc4c32)c(C#N)c1-n1c2ccccc2c2ccccc21]

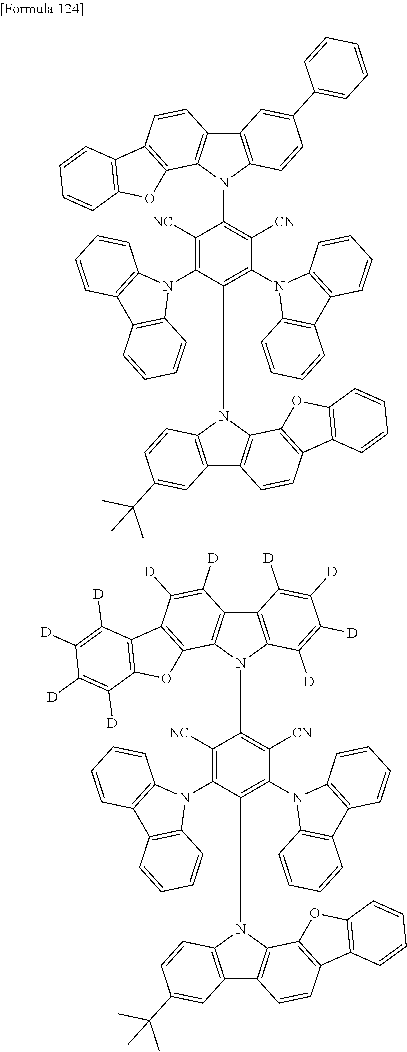

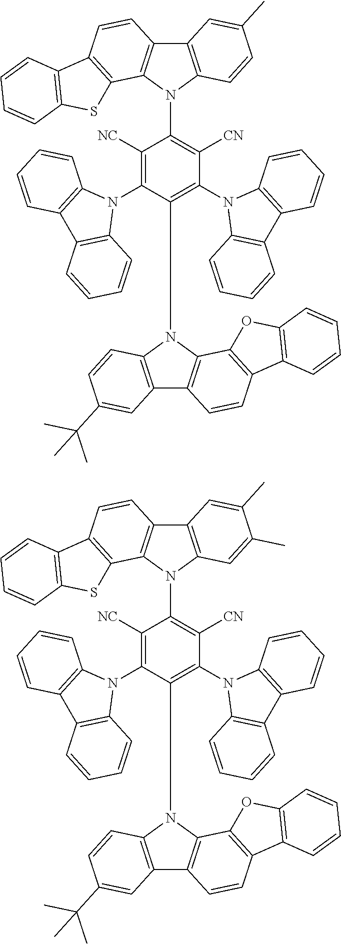

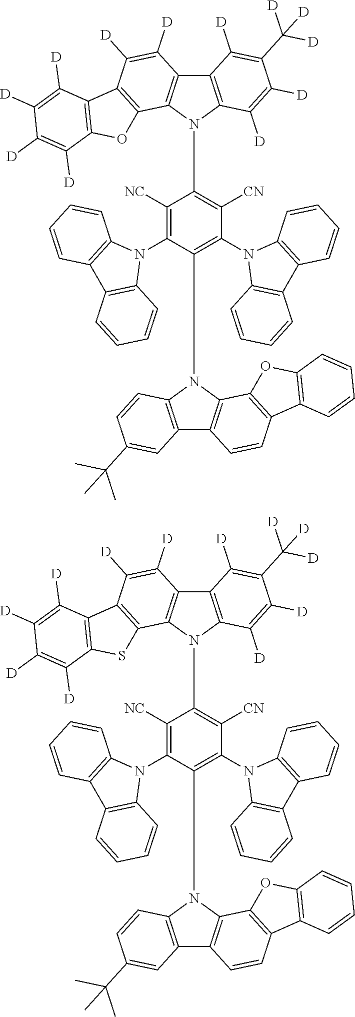 [SMILES: [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(C(C)(C)C)cc6c6ccc7c8ccccc8oc7c65)c(-n5c6ccccc6c6ccccc65)c4C#N)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(C(C)(C)C)cc6c6ccc7c8ccccc8oc7c65)c(-n5c6ccccc6c6ccccc65)c4C#N)c32)c1[2H]]

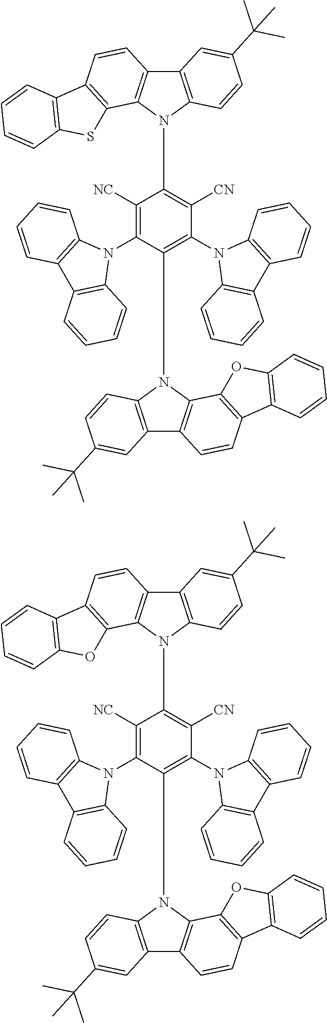 [SMILES: CC(C)(C)c1ccc2c(c1)c1ccc3c4ccccc4oc3c1n2-c1c(-n2c3ccccc3c3ccccc32)c(C#N)c(-n2c3ccc(C(C)(C)C)cc3c3ccc4c5ccccc5sc4c32)c(C#N)c1-n1c2ccccc2c2ccccc21 ; CC(C)(C)c1ccc2c(c1)c1ccc3c4ccccc4oc3c1n2-c1c(C#N)c(-n2c3ccccc3c3ccccc32)c(-n2c3ccc(C(C)(C)C)cc3c3ccc4c5ccccc5oc4c32)c(-n2c3ccccc3c3ccccc32)c1C#N]

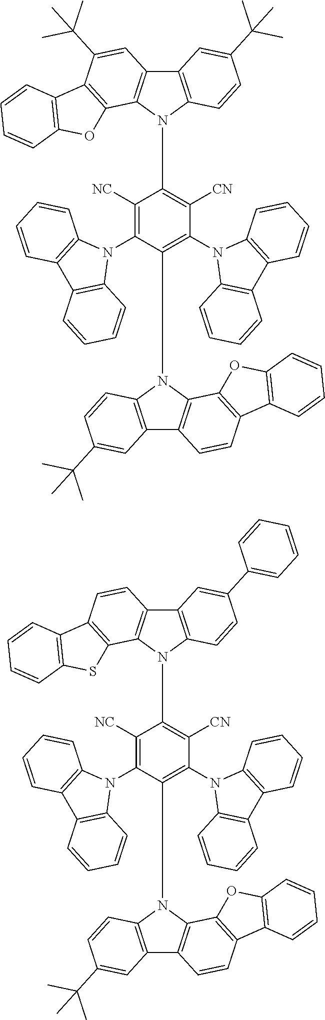 [SMILES: CC(C)(C)c1ccc2c(c1)c1ccc3c4ccccc4oc3c1n2-c1c(-n2c3ccccc3c3ccccc32)c(C#N)c(-n2c3ccc(C(C)(C)C)cc3c3cc(C(C)(C)C)c4c5ccccc5oc4c32)c(C#N)c1-n1c2ccccc2c2ccccc21 ; CC(C)(C)c1ccc2c(c1)c1ccc3c4ccccc4oc3c1n2-c1c(-n2c3ccccc3c3ccccc32)c(C#N)c(-n2c3ccc(-c4ccccc4)cc3c3ccc4c5ccccc5sc4c32)c(C#N)c1-n1c2ccccc2c2ccccc21]

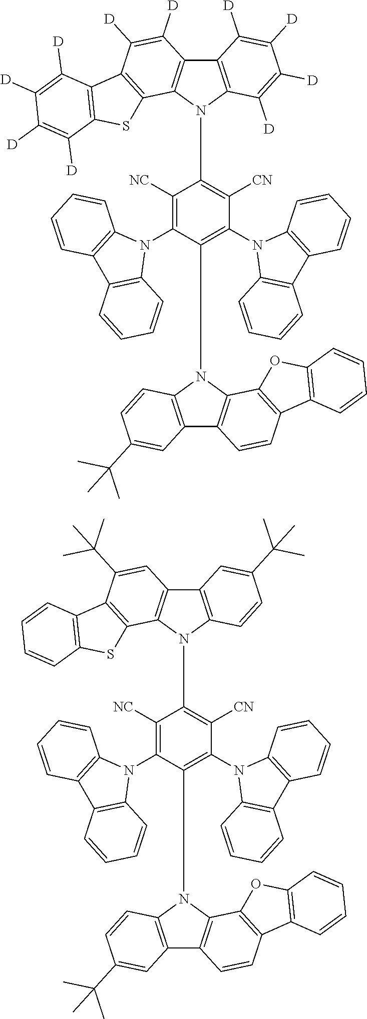

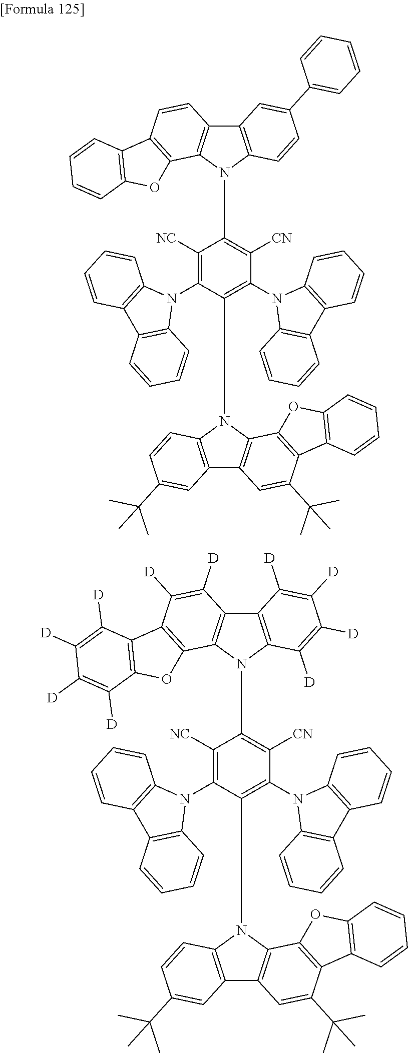

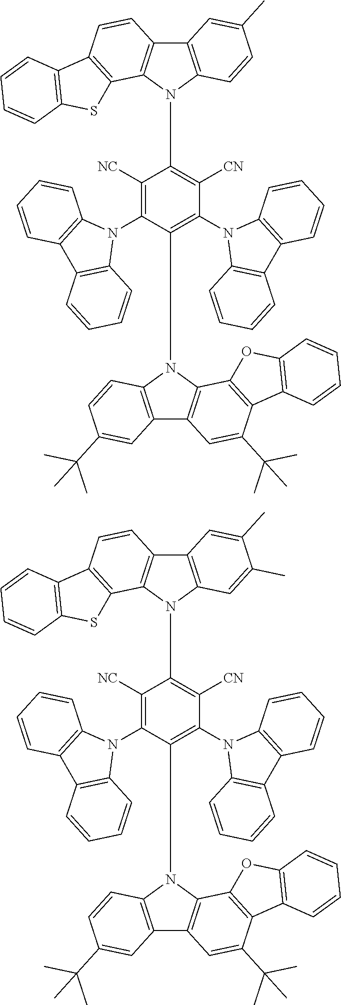

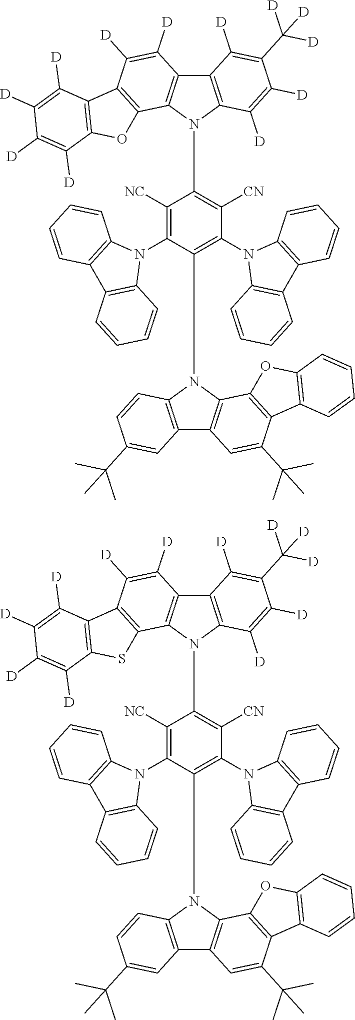

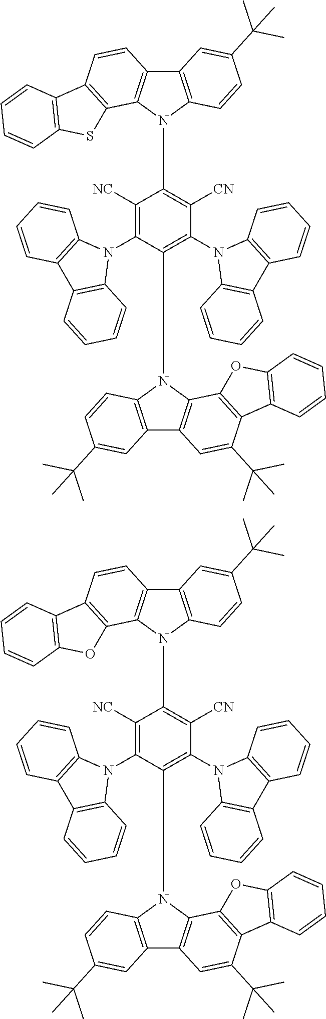

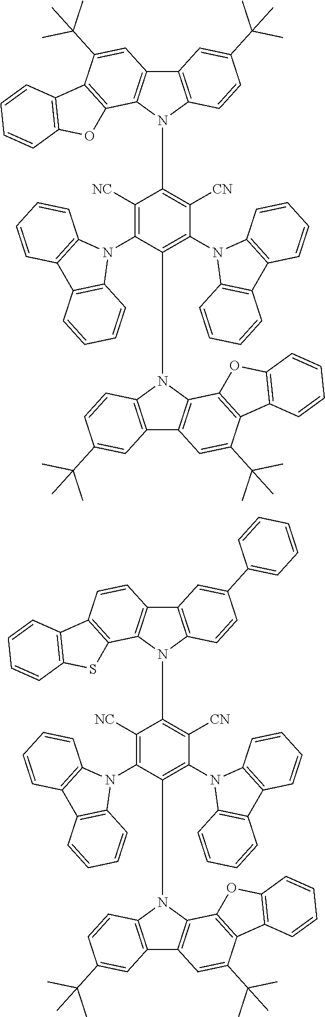

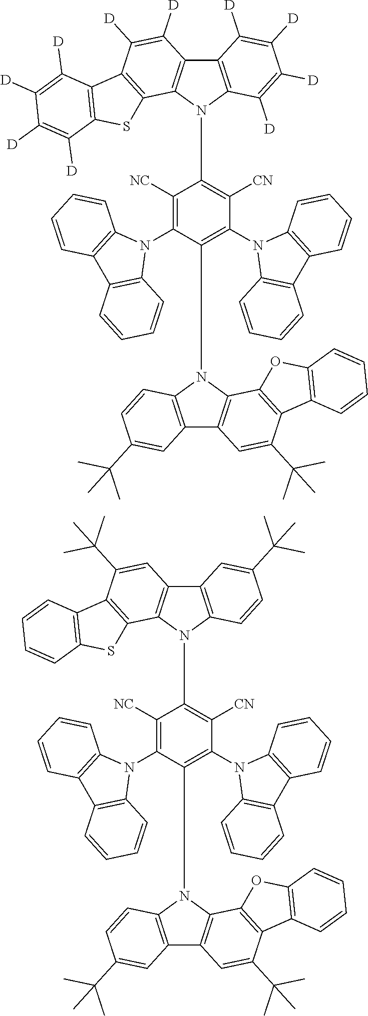

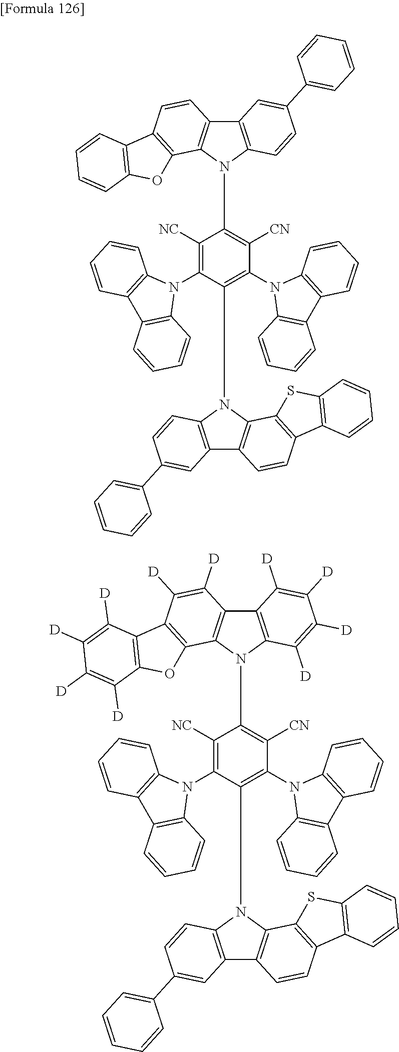

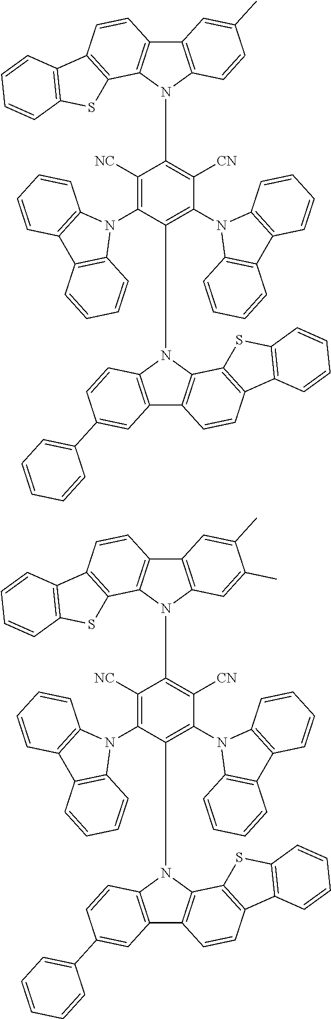 [SMILES: Cc1ccc2c(c1)c1ccc3c4ccccc4sc3c1n2-c1c(C#N)c(-n2c3ccccc3c3ccccc32)c(-n2c3ccc(-c4ccccc4)cc3c3ccc4c5ccccc5sc4c32)c(-n2c3ccccc3c3ccccc32)c1C#N ; Cc1cc2c3ccc4c5ccccc5sc4c3n(-c3c(C#N)c(-n4c5ccccc5c5ccccc54)c(-n4c5ccc(-c6ccccc6)cc5c5ccc6c7ccccc7sc6c54)c(-n4c5ccccc5c5ccccc54)c3C#N)c2cc1C]

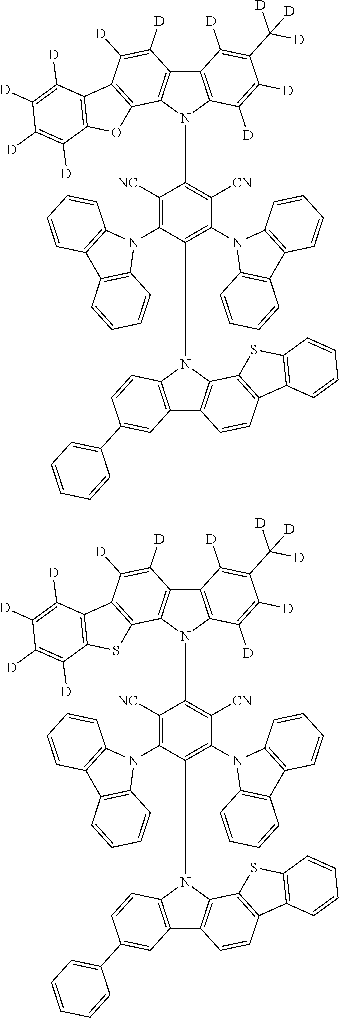 [SMILES: [2H]c1c([2H])c([2H])c2c(oc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(-c7ccccc7)cc6c6ccc7c8ccccc8sc7c65)c(-n5c6ccccc6c6ccccc65)c4C#N)c32)c1[2H] ; [2H]c1c([2H])c([2H])c2c(sc3c2c([2H])c([2H])c2c4c([2H])c(C([2H])([2H])[2H])c([2H])c([2H])c4n(-c4c(C#N)c(-n5c6ccccc6c6ccccc65)c(-n5c6ccc(-c7ccccc7)cc6c6ccc7c8ccccc8sc7c65)c(-n5c6ccccc6c6ccccc65)c4C#N)c32)c1[2H]]

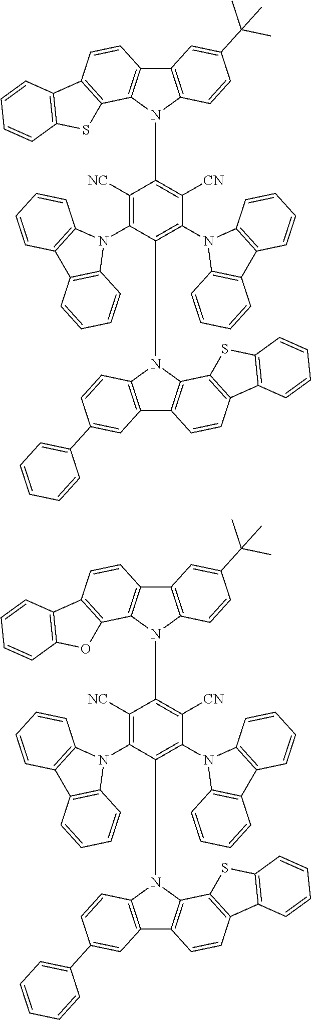 [SMILES: CC(C)(C)c1ccc2c(c1)c1ccc3c4ccccc4sc3c1n2-c1c(C#N)c(-n2c3ccccc3c3ccccc32)c(-n2c3ccc(-c4ccccc4)cc3c3ccc4c5ccccc5sc4c32)c(-n2c3ccccc3c3ccccc32)c1C#N ; CC(C)(C)c1ccc2c(c1)c1ccc3c4ccccc4oc3c1n2-c1c(C#N)c(-n2c3ccccc3c3ccccc32)c(-n2c3ccc(-c4ccccc4)cc3c3ccc4c5ccccc5sc4c32)c(-n2c3ccccc3c3ccccc32)c1C#N]

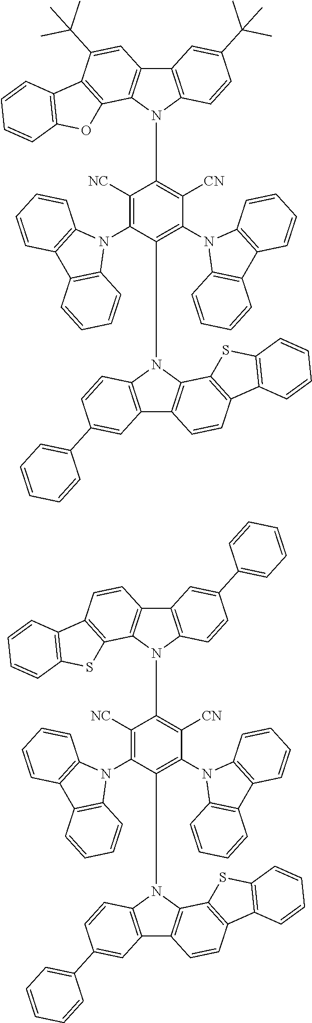 [SMILES: CC(C)(C)c1ccc2c(c1)c1cc(C(C)(C)C)c3c4ccccc4oc3c1n2-c1c(C#N)c(-n2c3ccccc3c3ccccc32)c(-n2c3ccc(-c4ccccc4)cc3c3ccc4c5ccccc5sc4c32)c(-n2c3ccccc3c3ccccc32)c1C#N ; N#Cc1c(-n2c3ccccc3c3ccccc32)c(-n2c3ccc(-c4ccccc4)cc3c3ccc4c5ccccc5sc4c32)c(-n2c3ccccc3c3ccccc32)c(C#N)c1-n1c2ccc(-c3ccccc3)cc2c2ccc3c4ccccc4sc3c21]

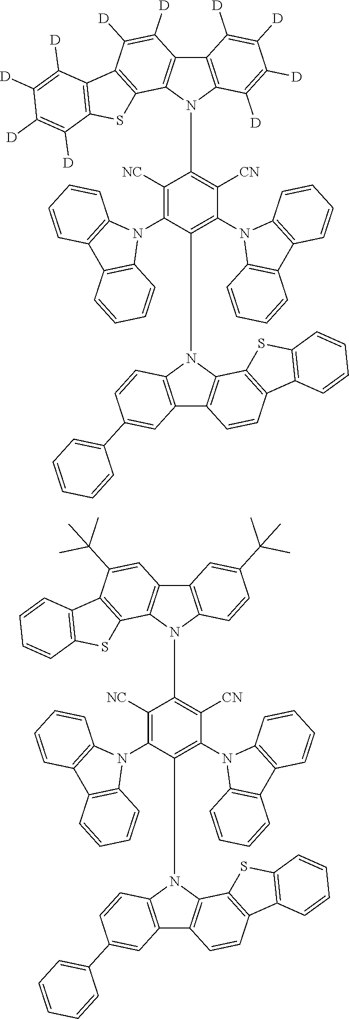

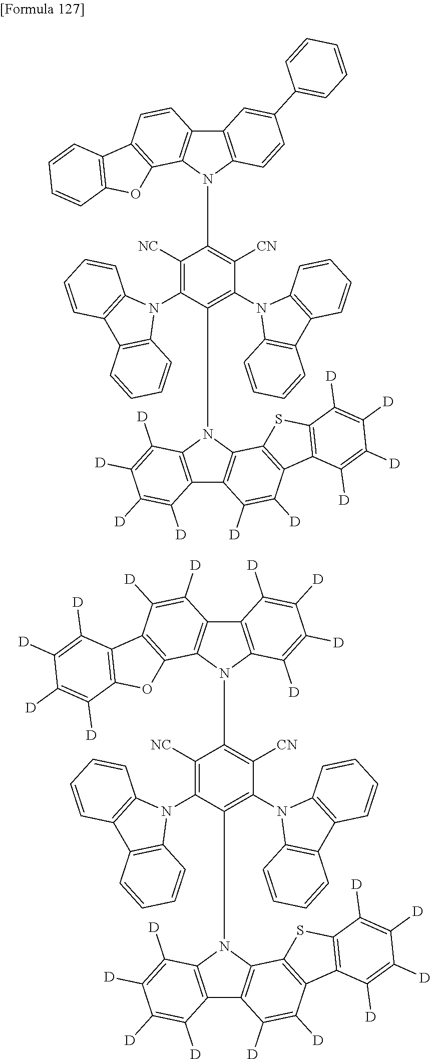

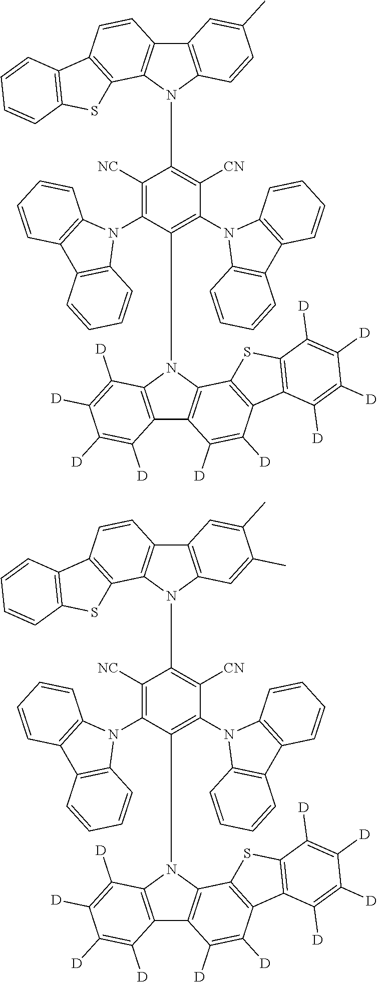

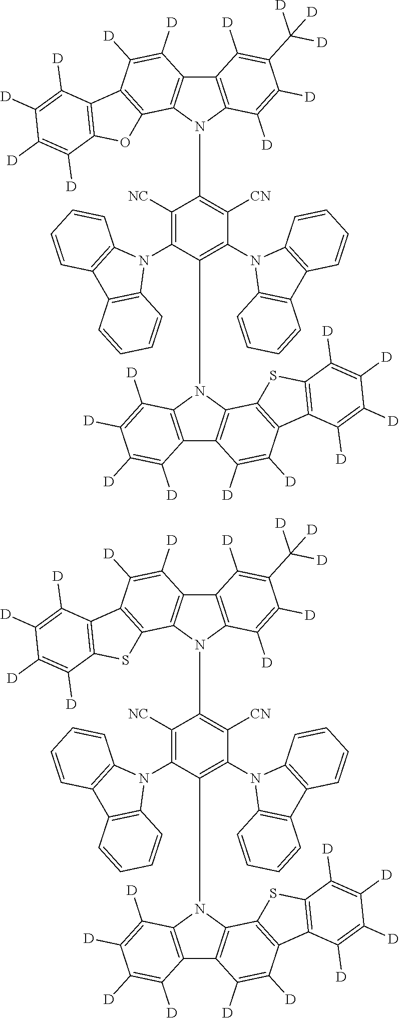

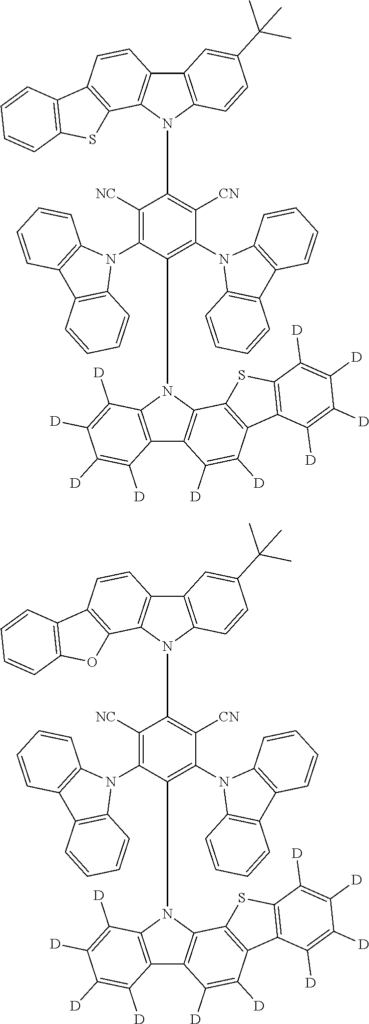

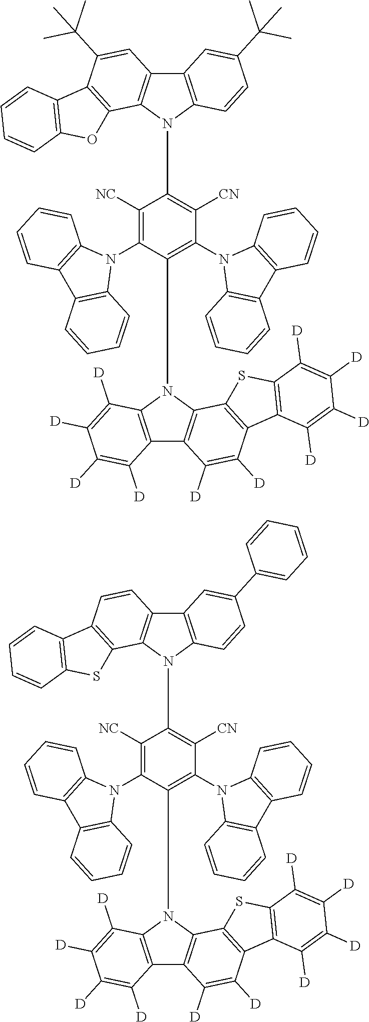

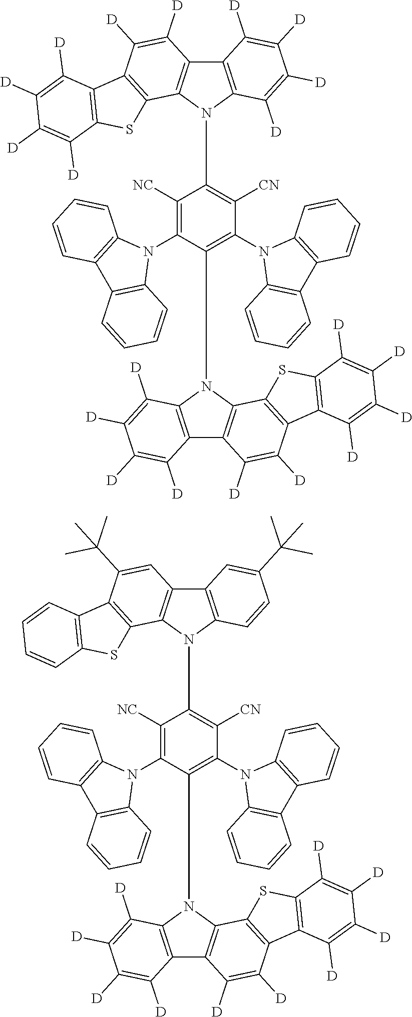

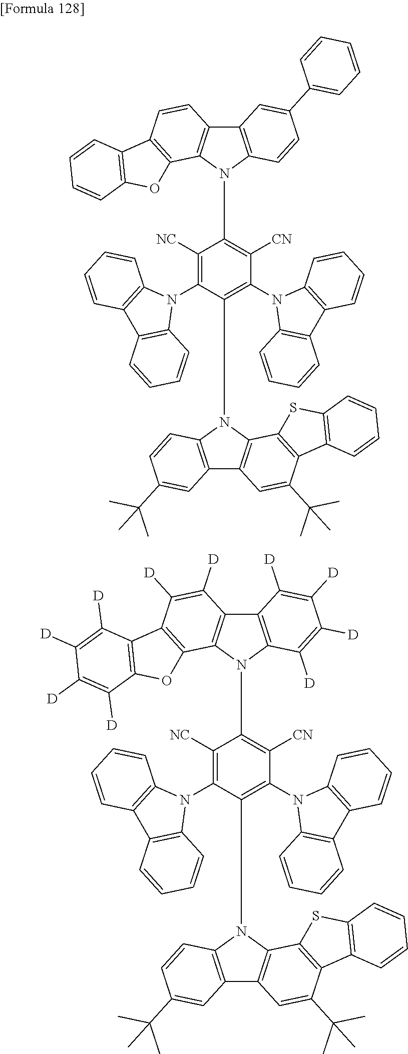

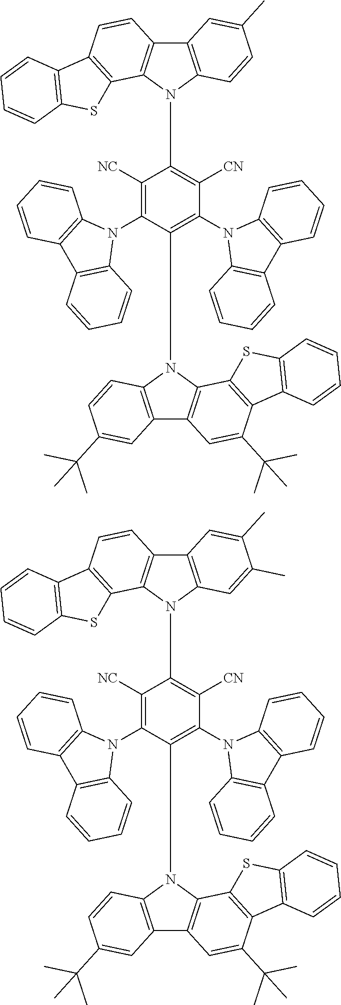

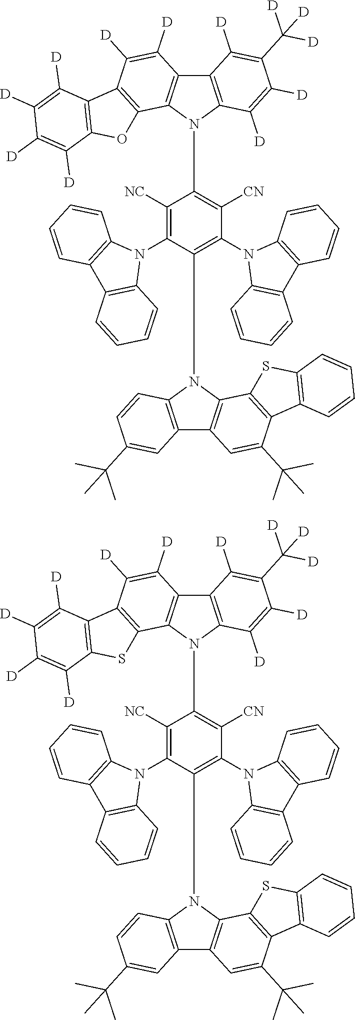

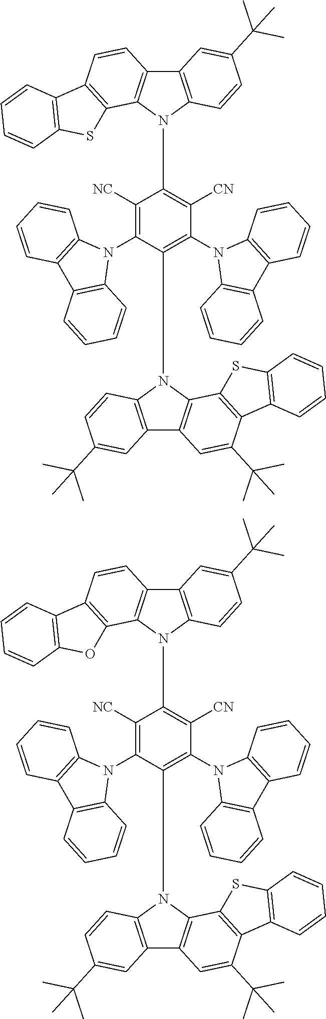

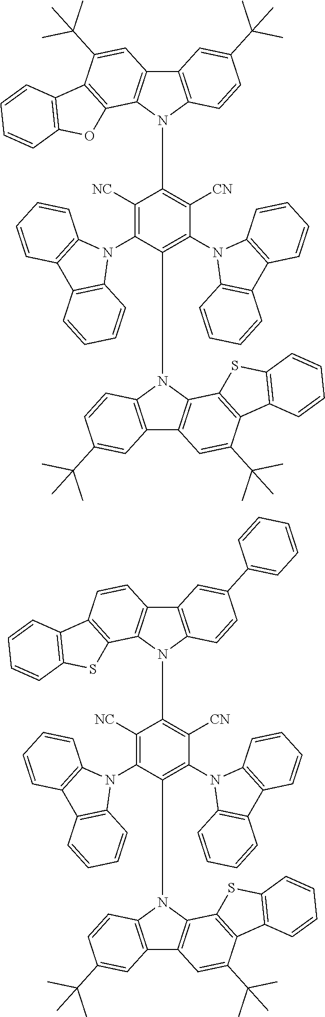

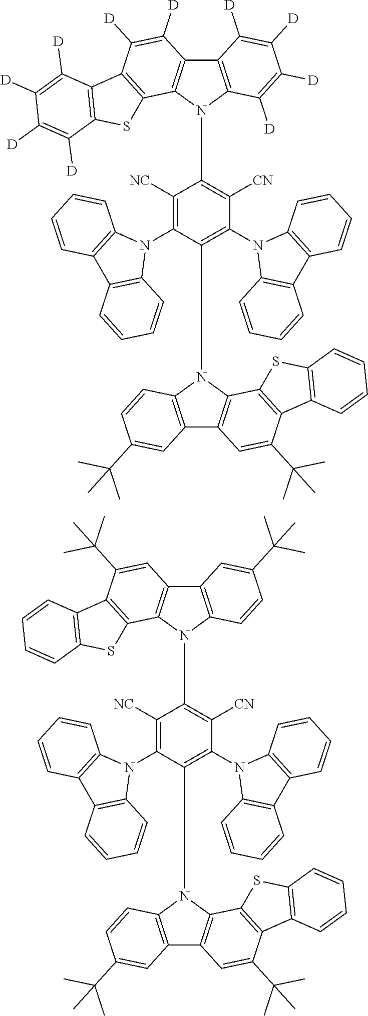

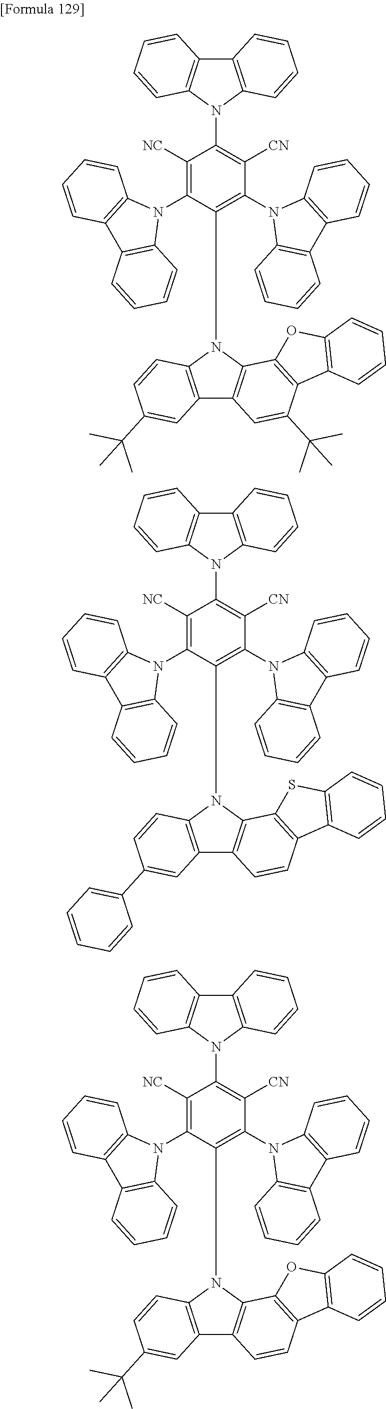

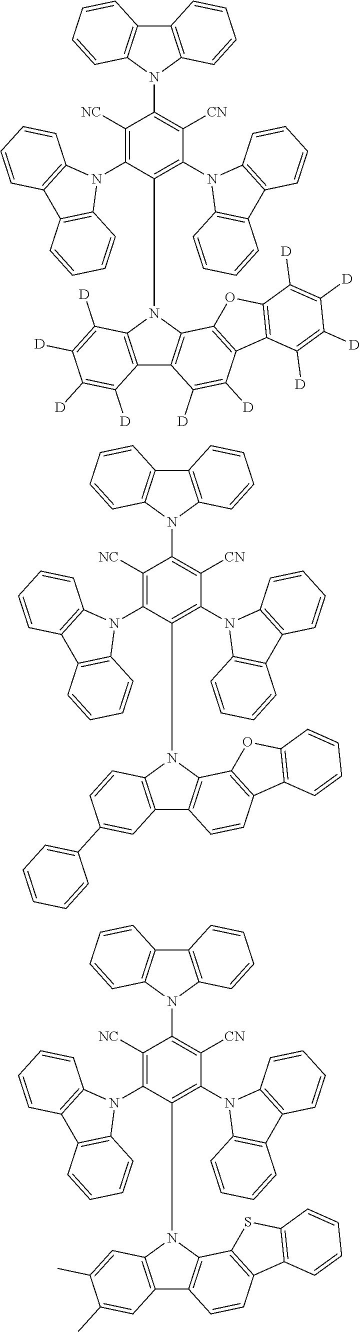

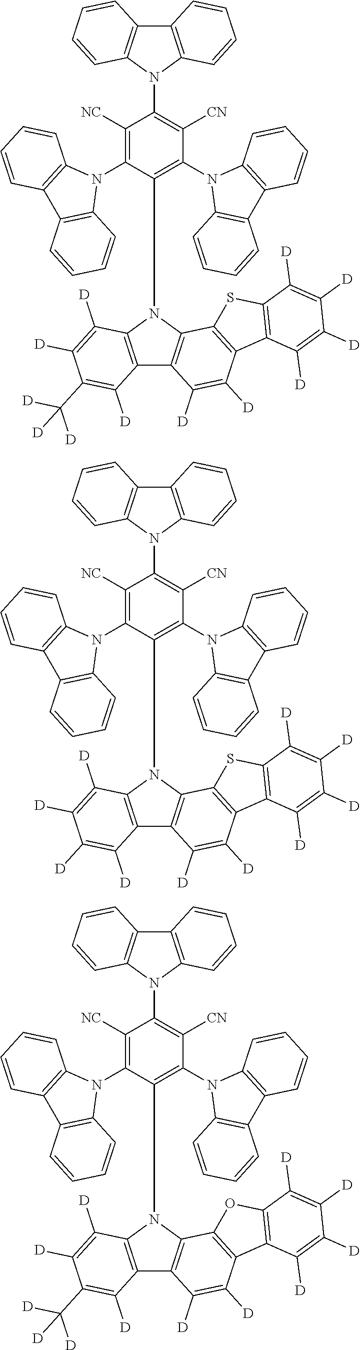

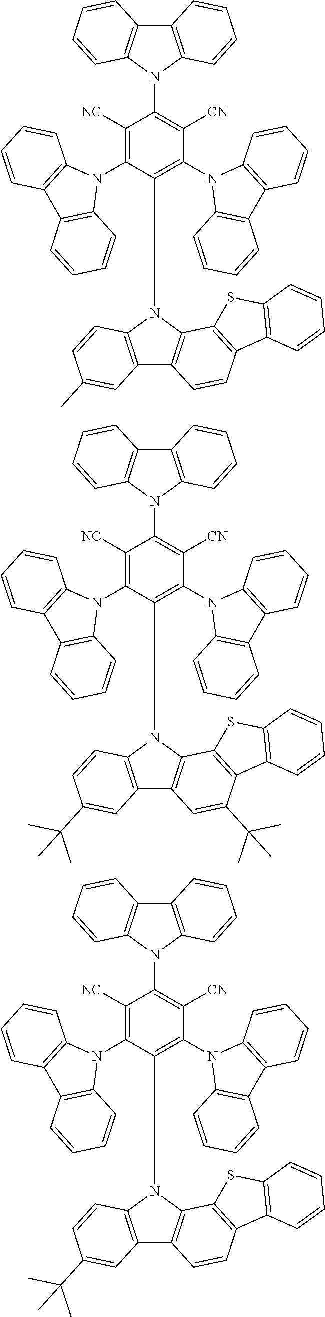

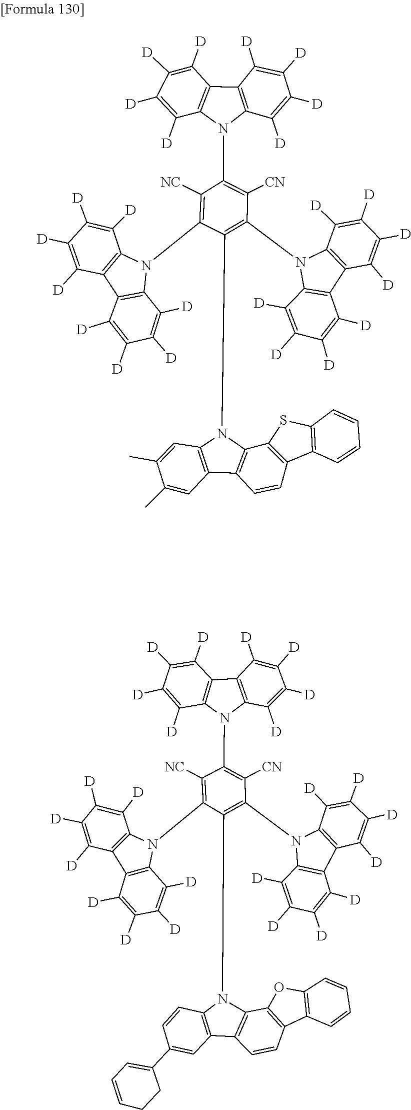

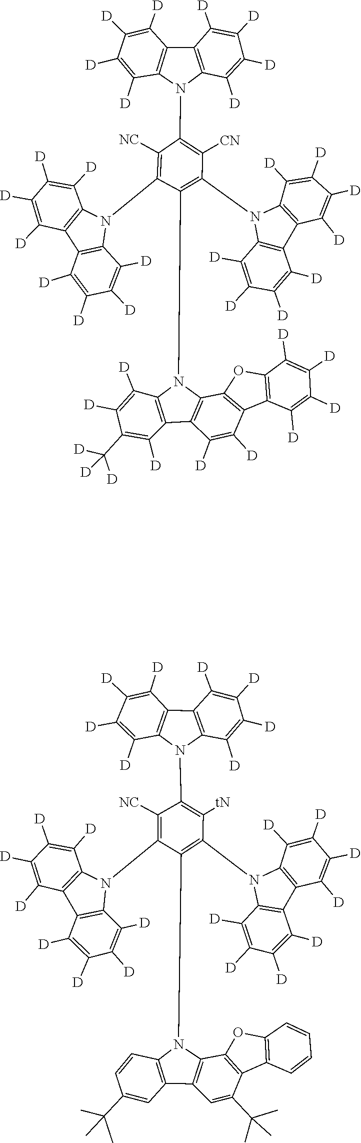

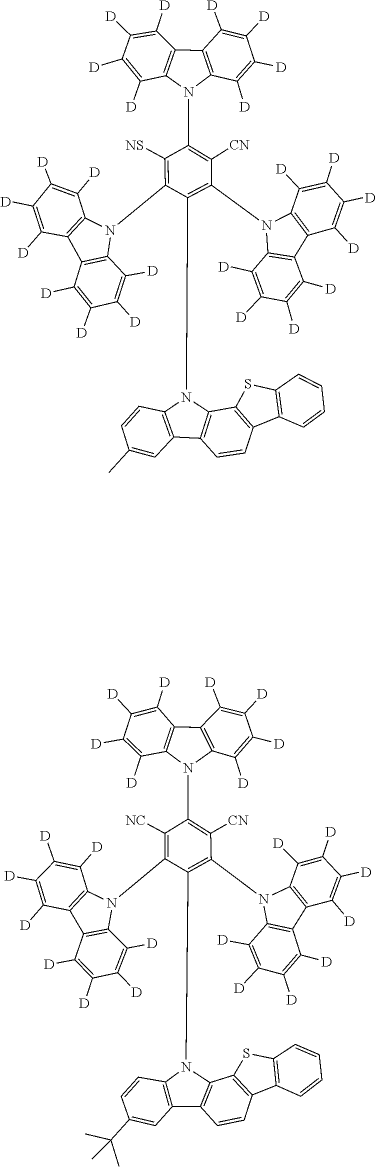

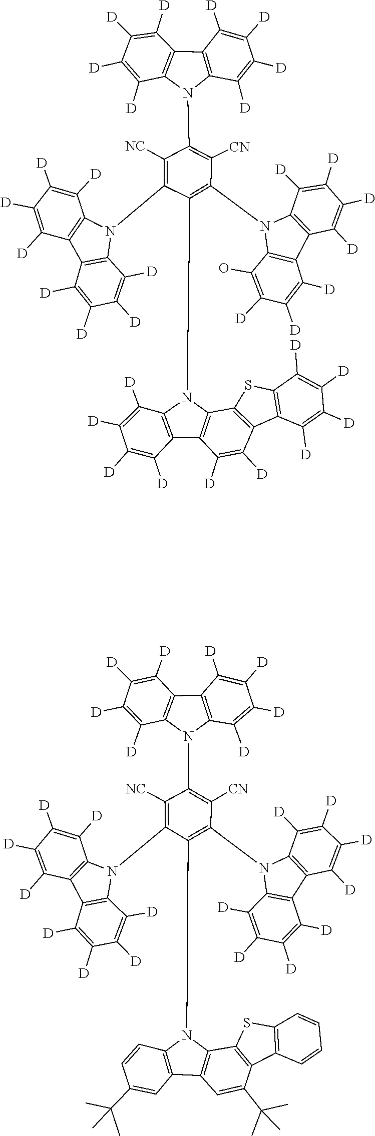

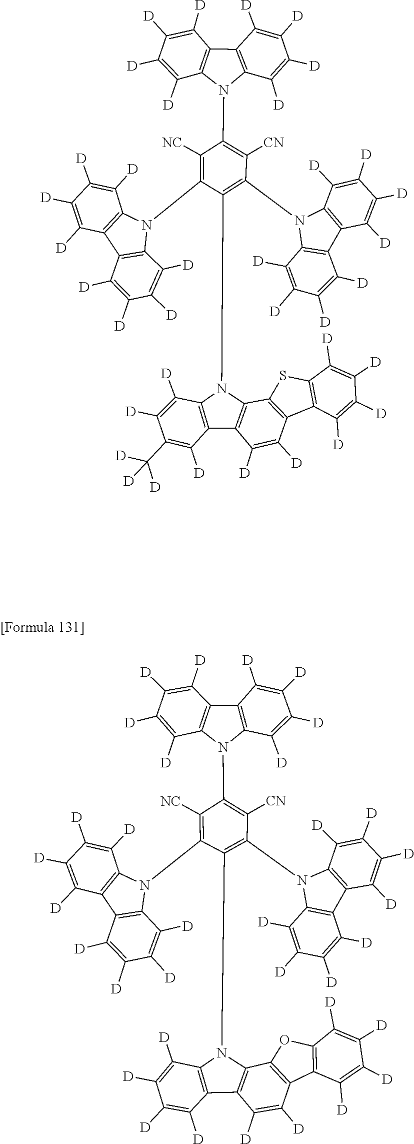

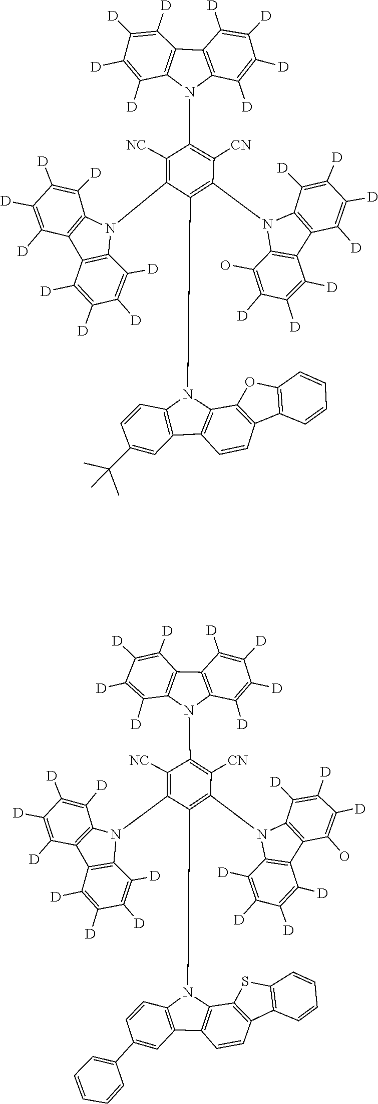

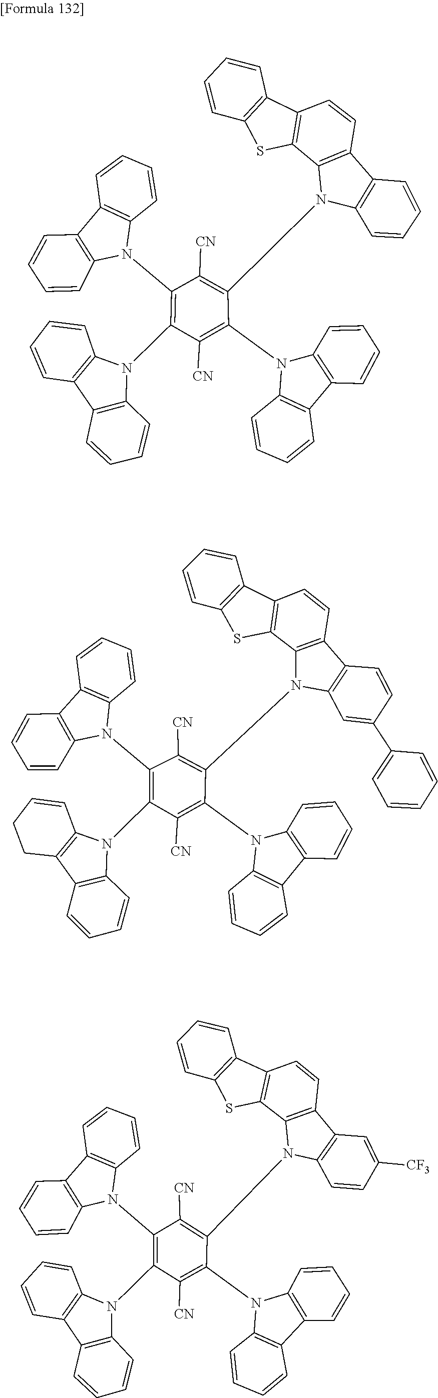 [SMILES: N#Cc1c(-n2c3ccccc3c3ccccc32)c(-n2c3ccccc3c3ccccc32)c(C#N)c(-n2c3ccccc3c3ccc4c5ccccc5sc4c32)c1-n1c2ccccc2c2ccccc21 ; N#Cc1c(-n2c3c(c4ccccc42)CCC=C3)c(-n2c3ccccc3c3ccccc32)c(C#N)c(-n2c3cc(-c4ccccc4)ccc3c3ccc4c5ccccc5sc4c32)c1-n1c2ccccc2c2ccccc21 ; N#Cc1c(-n2c3ccccc3c3ccccc32)c(-n2c3ccccc3c3ccccc32)c(C#N)c(-n2c3ccc(C(F)(F)F)cc3c3ccc4c5ccccc5sc4c32)c1-n1c2ccccc2c2ccccc21]

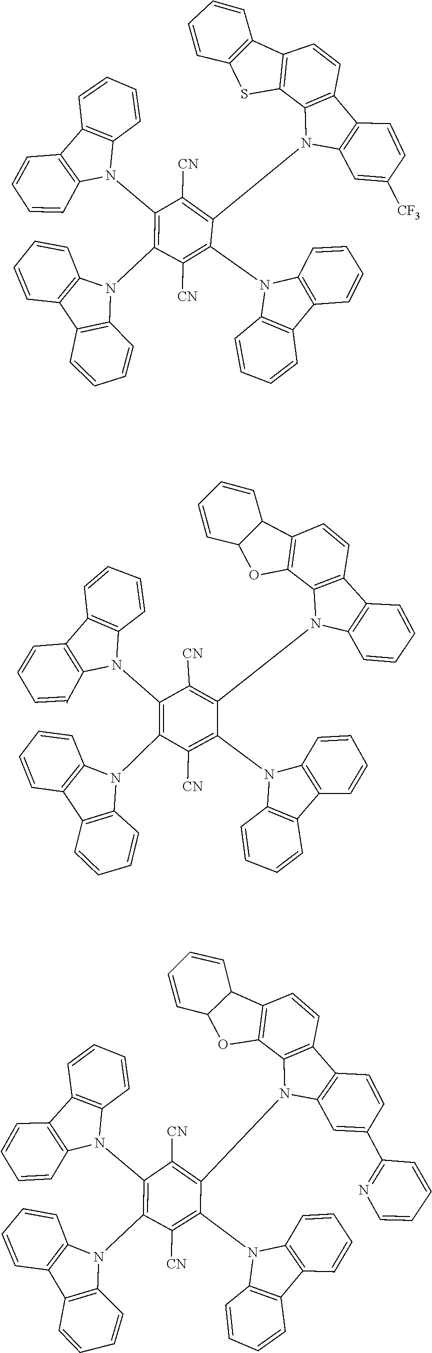 [SMILES: N#Cc1c(-n2c3ccccc3c3ccccc32)c(-n2c3ccccc3c3ccccc32)c(C#N)c(-n2c3cc(C(F)(F)F)ccc3c3ccc4c5ccccc5sc4c32)c1-n1c2ccccc2c2ccccc21 ; Cc1cccc2c3ccccc3n(-c3c(C#N)c(-n4c5ccccc5c5ccc6c(c54)OC4C=CC=CC64)c(-n4c5ccccc5c5ccccc54)c(C#N)c3-n3c4ccccc4c4ccccc43)c12 ; N#Cc1c(-n2c3ccccc3c3ccccc32)c(-n2c3ccccc3c3ccccc32)c(C#N)c(-n2c3cc(-c4ccccn4)ccc3c3ccc4c(c32)OC2C=CC=CC42)c1-n1c2ccccc2c2ccccc21]

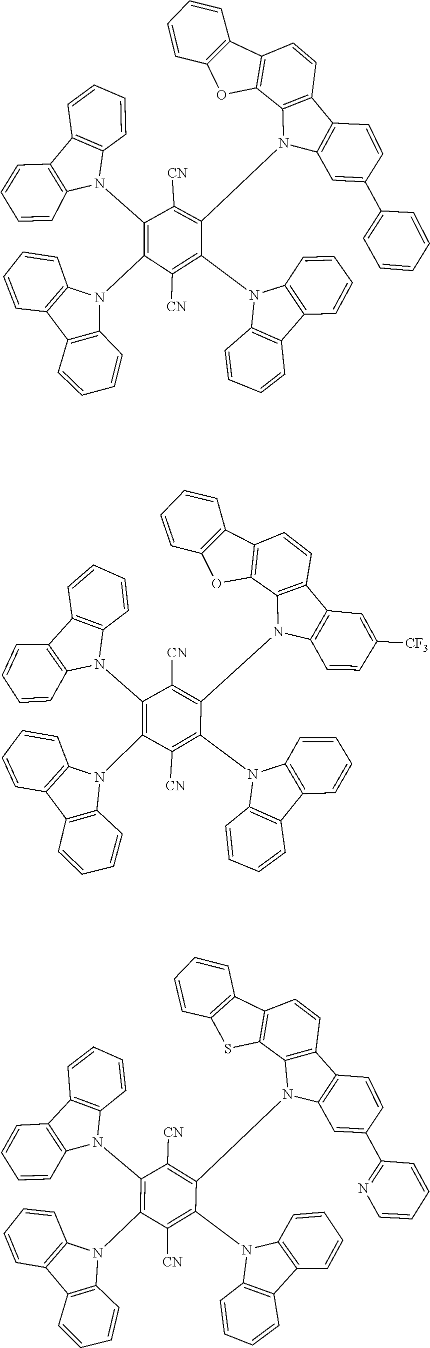 [SMILES: N#Cc1c(-n2c3ccccc3c3ccccc32)c(-n2c3ccccc3c3ccccc32)c(C#N)c(-n2c3cc(-c4ccccc4)ccc3c3ccc4c5ccccc5oc4c32)c1-n1c2ccccc2c2ccccc21 ; N#Cc1c(-n2c3ccccc3c3ccccc32)c(-n2c3ccccc3c3ccccc32)c(C#N)c(-n2c3ccc(C(F)(F)F)cc3c3ccc4c5ccccc5oc4c32)c1-n1c2ccccc2c2ccccc21 ; N#Cc1c(-n2c3ccccc3c3ccccc32)c(-n2c3ccccc3c3ccccc32)c(C#N)c(-n2c3cc(-c4ccccn4)ccc3c3ccc4c5ccccc5sc4c32)c1-n1c2ccccc2c2ccccc21]

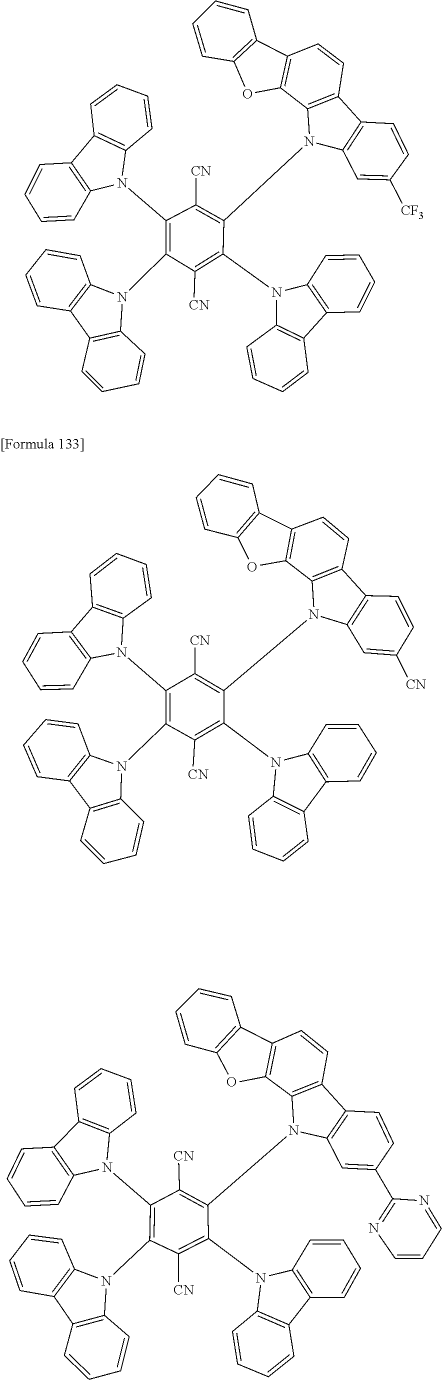 [SMILES: N#Cc1c(-n2c3ccccc3c3ccccc32)c(-n2c3ccccc3c3ccccc32)c(C#N)c(-n2c3cc(C(F)(F)F)ccc3c3ccc4c5ccccc5oc4c32)c1-n1c2ccccc2c2ccccc21 ; N#Cc1ccc2c3ccc4c5ccccc5oc4c3n(-c3c(C#N)c(-n4c5ccccc5c5ccccc54)c(-n4c5ccccc5c5ccccc54)c(C#N)c3-n3c4ccccc4c4ccccc43)c2c1 ; N#Cc1c(-n2c3ccccc3c3ccccc32)c(-n2c3ccccc3c3ccccc32)c(C#N)c(-n2c3cc(-c4ncccn4)ccc3c3ccc4c5ccccc5oc4c32)c1-n1c2ccccc2c2ccccc21]

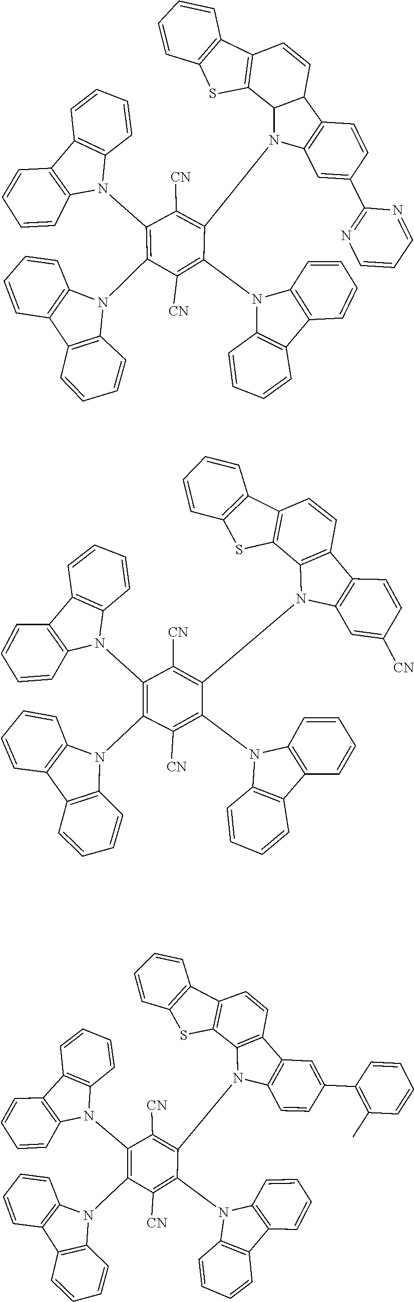 [SMILES: N#Cc1c(N2c3cc(-c4ncccn4)ccc3C3C=Cc4c(sc5ccccc45)C32)c(-n2c3ccccc3c3ccccc32)c(C#N)c(-n2c3ccccc3c3ccccc32)c1-n1c2ccccc2c2ccccc21 ; N#Cc1ccc2c3ccc4c5ccccc5sc4c3n(-c3c(C#N)c(-n4c5ccccc5c5ccccc54)c(-n4c5ccccc5c5ccccc54)c(C#N)c3-n3c4ccccc4c4ccccc43)c2c1 ; Cc1ccccc1-c1ccc2c(c1)c1ccc3c4ccccc4sc3c1n2-c1c(C#N)c(-n2c3ccccc3c3ccccc32)c(-n2c3ccccc3c3ccccc32)c(C#N)c1-n1c2ccccc2c2ccccc21]

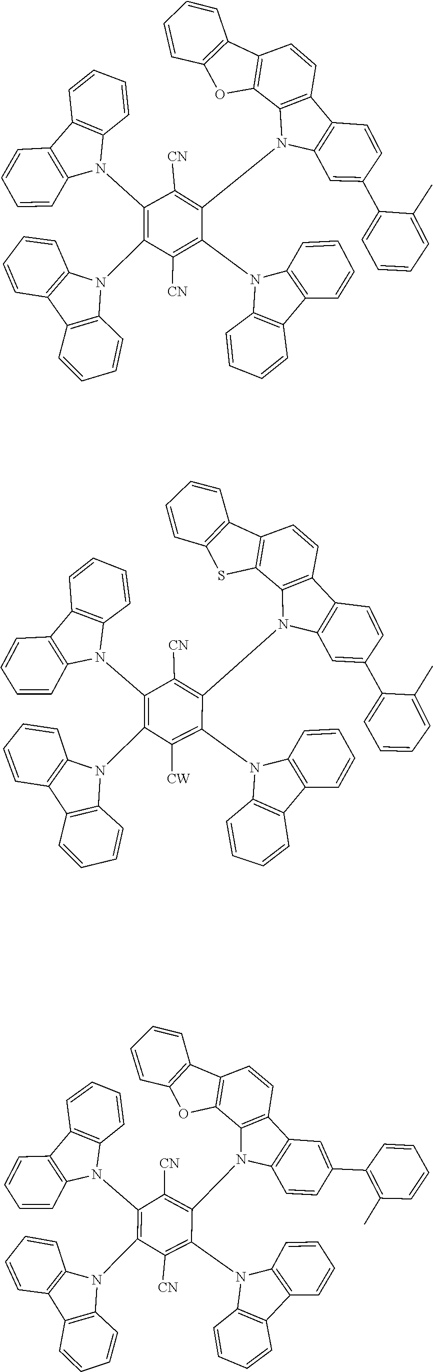

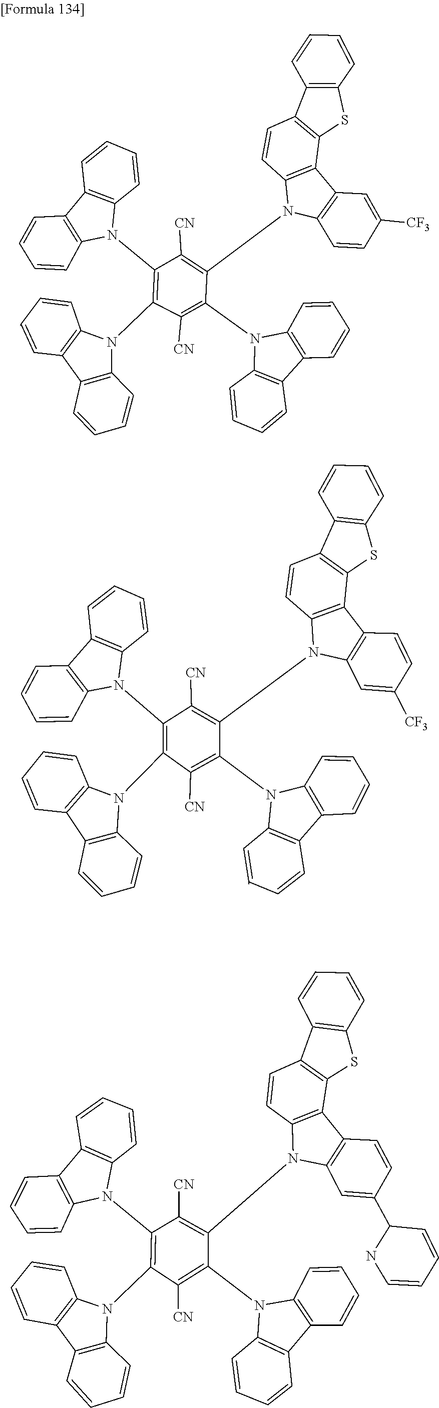

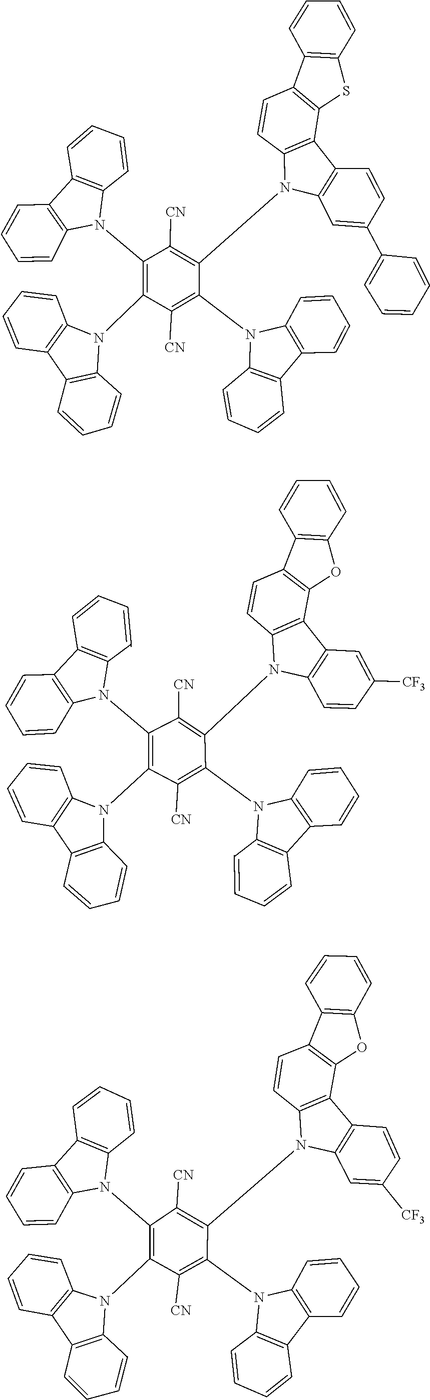 [SMILES: N#Cc1c(-n2c3ccccc3c3ccccc32)c(-n2c3ccccc3c3ccccc32)c(C#N)c(-n2c3cc(-c4ccccc4)ccc3c3c4sc5ccccc5c4ccc32)c1-n1c2ccccc2c2ccccc21 ; Cc1cccc2c3ccccc3n(-c3c(C#N)c(-n4c5ccc(C(F)(F)F)cc5c5c6oc7ccccc7c6ccc54)c(-n4c5ccccc5c5cccc(C)c54)c(C#N)c3-n3c4ccccc4c4ccccc43)c12 ; N#Cc1c(-n2c3ccccc3c3ccccc32)c(-n2c3ccccc3c3ccccc32)c(C#N)c(-n2c3cc(C(F)(F)F)ccc3c3c4oc5ccccc5c4ccc32)c1-n1c2ccccc2c2ccccc21]

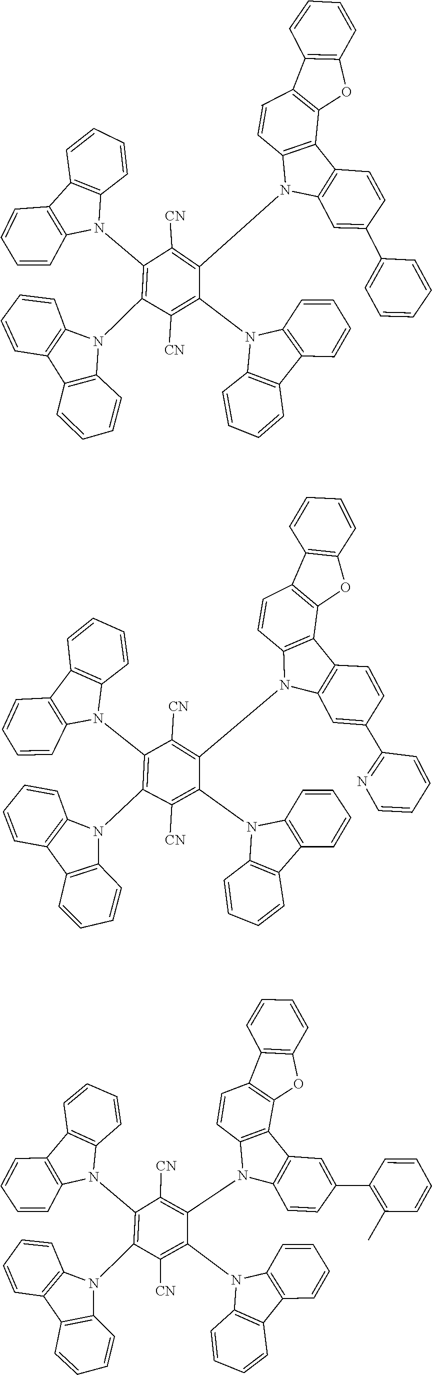 [SMILES: Cc1cc2c(c3ccc(-c4ccccc4)cc3n2-c2c(C#N)c(-n3c4ccccc4c4ccccc43)c(-n3c4ccccc4c4ccccc43)c(C#N)c2-n2c3ccccc3c3ccccc32)c2oc3ccccc3c12 ; N#Cc1c(-n2c3ccccc3c3ccccc32)c(-n2c3ccccc3c3ccccc32)c(C#N)c(-n2c3cc(-c4ccccn4)ccc3c3c4oc5ccccc5c4ccc32)c1-n1c2ccccc2c2ccccc21 ; Cc1ccccc1-c1ccc2c(c1)c1c3oc4ccccc4c3ccc1n2-c1c(C#N)c(-n2c3ccccc3c3ccccc32)c(-n2c3ccccc3c3ccccc32)c(C#N)c1-n1c2ccccc2c2ccccc21]

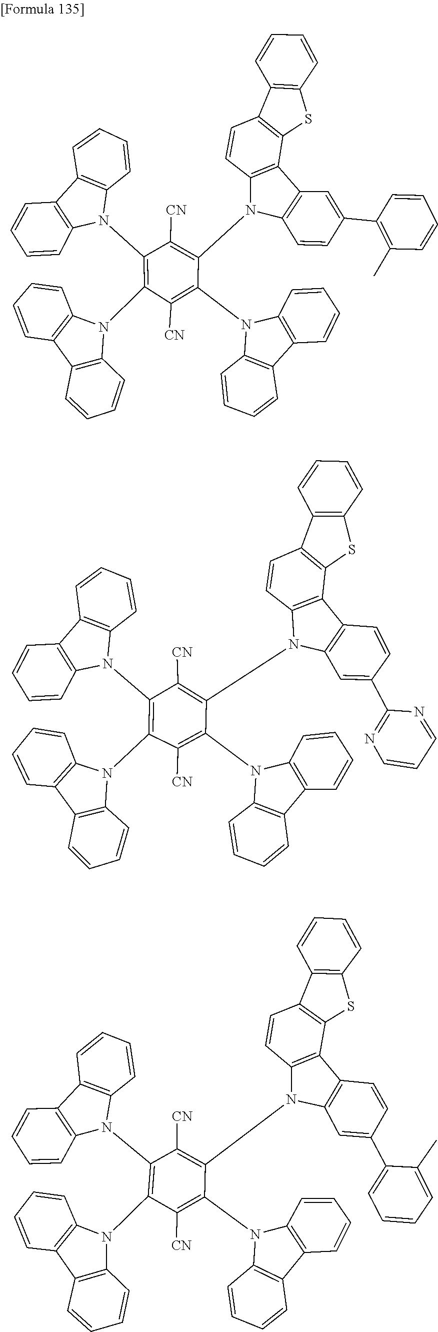 [SMILES: Cc1ccccc1-c1ccc2c(c1)c1c3sc4ccccc4c3ccc1n2-c1c(C#N)c(-n2c3ccccc3c3ccccc32)c(-n2c3ccccc3c3ccccc32)c(C#N)c1-n1c2ccccc2c2ccccc21 ; N#Cc1c(-n2c3ccccc3c3ccccc32)c(-n2c3ccccc3c3ccccc32)c(C#N)c(-n2c3cc(-c4ncccn4)ccc3c3c4sc5ccccc5c4ccc32)c1-n1c2ccccc2c2ccccc21 ; Cc1ccccc1-c1ccc2c3c4sc5ccccc5c4ccc3n(-c3c(C#N)c(-n4c5ccccc5c5ccccc54)c(-n4c5ccccc5c5ccccc54)c(C#N)c3-n3c4ccccc4c4ccccc43)c2c1]

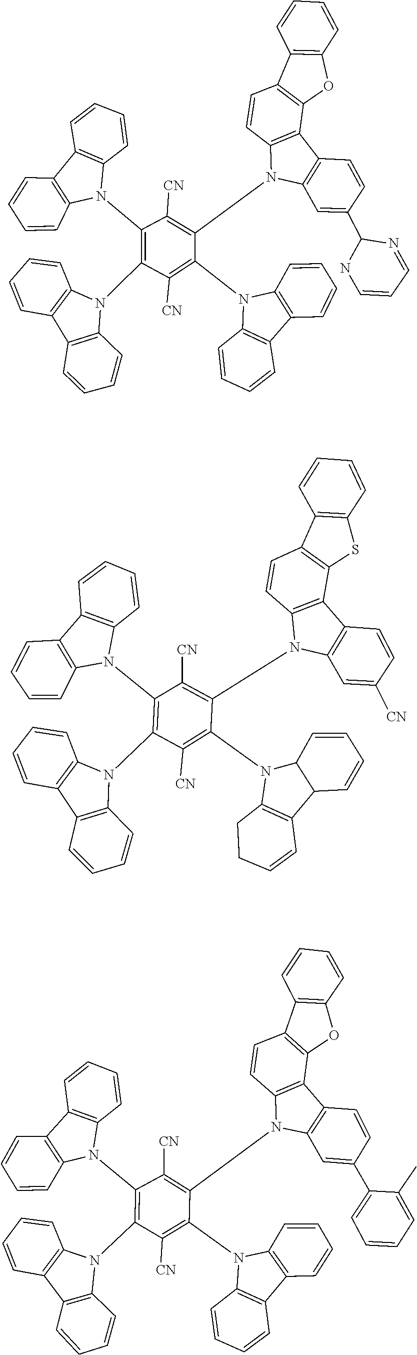

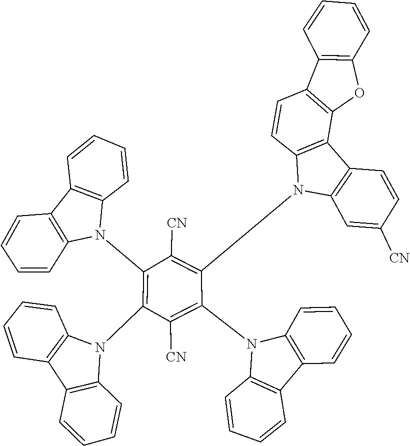 [SMILES: N#Cc1ccc2c3c4oc5ccccc5c4ccc3n(-c3c(C#N)c(-n4c5ccccc5c5ccccc54)c(-n4c5ccccc5c5ccccc54)c(C#N)c3-n3c4ccccc4c4ccccc43)c2c1]

In an exemplary arrangement of the exemplary embodiment, the first sensitizing material is a compound represented by a formula (1000) below.

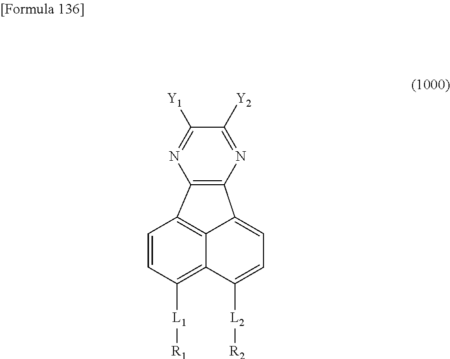

In the formula (1000):
Y₁ and Y₂ are each independently a hydrogen atom or a cyano group;
R₁ and R₂ are each independently a hydrogen atom, a cyano group, a substituted or unsubstituted aryl group having 6 to 40 ring carbon atoms, a substituted or unsubstituted heteroaryl group having 5 to 40 ring atoms, or a group represented by —N(Rz₁)(Rz₂);
R₁ and R₂ are not each a hydrogen atom at the same time;
a combination of Rz₁ and Rz₂ are mutually bonded to form a substituted or unsubstituted monocyclic ring, mutually bonded to form a substituted or unsubstituted fused ring, or not mutually bonded;
a combination of L₁ and Rz₁ are mutually bonded to form a substituted or unsubstituted monocyclic ring, mutually bonded to form a substituted or unsubstituted fused ring, or not mutually bonded;
a combination of L₁ and Rz₂ are mutually bonded to form a substituted or unsubstituted monocyclic ring, mutually bonded to form a substituted or unsubstituted fused ring, or not mutually bonded;
a combination of L₂ and Rz₁ are mutually bonded to form a substituted or unsubstituted monocyclic ring, mutually bonded to form a substituted or unsubstituted fused ring, or not mutually bonded;
a combination of L₂ and Rz₂ are mutually bonded to form a substituted or unsubstituted monocyclic ring, mutually bonded to form a substituted or unsubstituted fused ring, or not mutually bonded;
L₁ and L₂ forming neither the substituted or unsubstituted monocyclic ring nor the substituted or unsubstituted fused ring are each independently a single bond, a substituted or unsubstituted alkynylene group having 2 to 18 carbon atoms, a substituted or unsubstituted arylene group having 6 to 18 ring carbon atoms, a substituted or unsubstituted heteroarylene group having 5 to 18 ring atoms, or a group formed by bonding two groups of the above groups; and
Rz₁ and Rz₂ forming neither the substituted or unsubstituted monocyclic ring nor the substituted or unsubstituted fused ring are each independently a substituted or unsubstituted aryl group having 6 to 40 ring carbon atoms.

As an exemplary arrangement of a compound represented by the formula (1000), a compound represented by a formula (1000A) or (1000B) below is given.

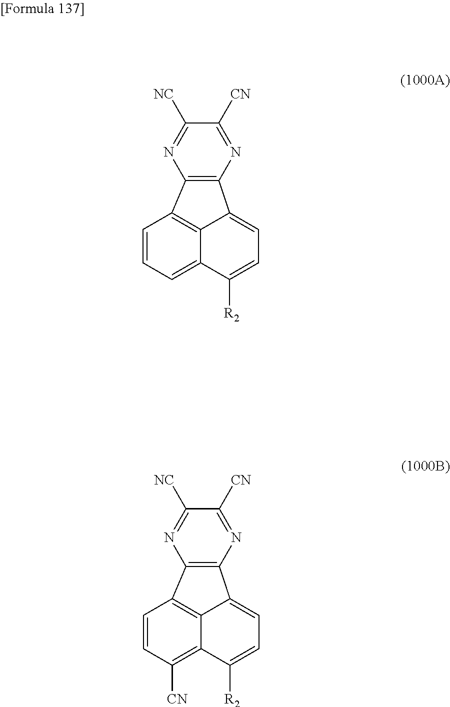

In the formulae (1000A) and (1000B), R₂ represents the same as R₂ in the formula (1000).

In an exemplary arrangement of the exemplary embodiment, the first sensitizing material is a compound represented by a formula (1001) below.

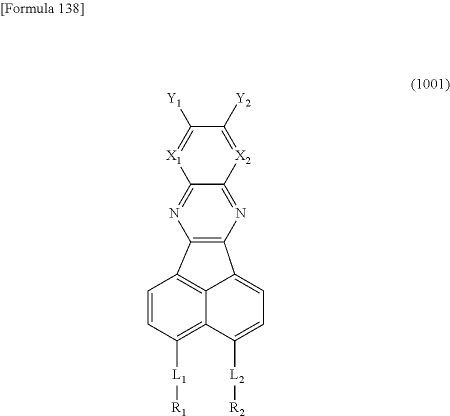

In the formula (1001):
Y₁ and Y₂ are each independently a hydrogen atom or a cyano group;
X₁ and X₂ are each independently CH or a nitrogen atom; and
L₁, L₂, R₁ and R₂ each independently represent the same as L₁, L₂, R₁ and R₂ in the formula (1000).

As an exemplary arrangement of a compound represented by the formula (1001), a compound represented by a formula (1001A) or (1001B) below is given.

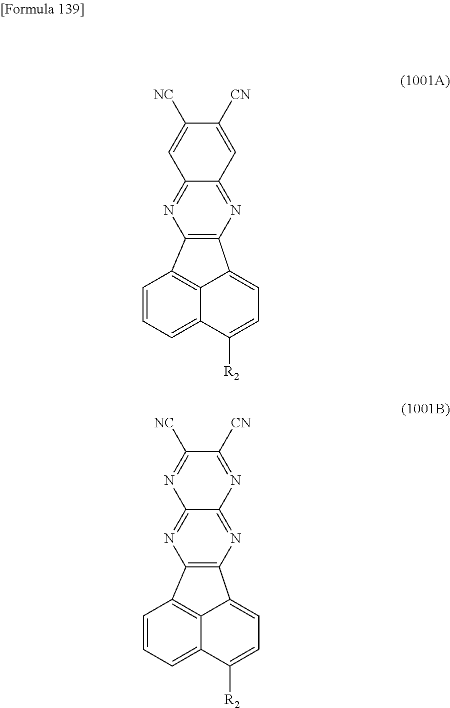

In the formulae (1001A) and (1001B), R₂ represents the same as R₂ in the formula (1001).

In an exemplary arrangement of the exemplary embodiment, the first sensitizing material is a compound represented by a formula (1002) below.

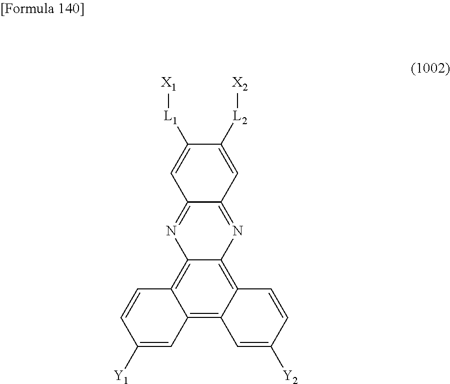

In the formula (1002):
L₁ and L₂ are each independently a single bond, a substituted or unsubstituted phenylene group, a substituted or unsubstituted biphenylene group, or a divalent group derived from a substituted or unsubstituted trans-distyryl group;
X₁ and X₂ are each independently a hydrogen atom, a substituted or unsubstituted aryl group having 6 to 40 ring carbon atoms, a substituted or unsubstituted heteroaryl group having 5 to 40 ring atoms, or a group represented by —N(Rz₁)(Rz₂);
a combination of Rz₁ and Rz₂ are mutually bonded to form a substituted or unsubstituted monocyclic ring, mutually bonded to form a substituted or unsubstituted fused ring, or not mutually bonded;
Rz₁ and Rz₂ forming neither the substituted or unsubstituted monocyclic ring nor the substituted or unsubstituted fused ring are each independently a substituted or unsubstituted aryl group having 6 to 40 ring carbon atoms, or a substituted or unsubstituted heteroaryl group having 5 to 40 ring carbon atoms; and
Y₁ and Y₂ are each independently a group represented by any one of formulae (W-1) to (W-21) below.

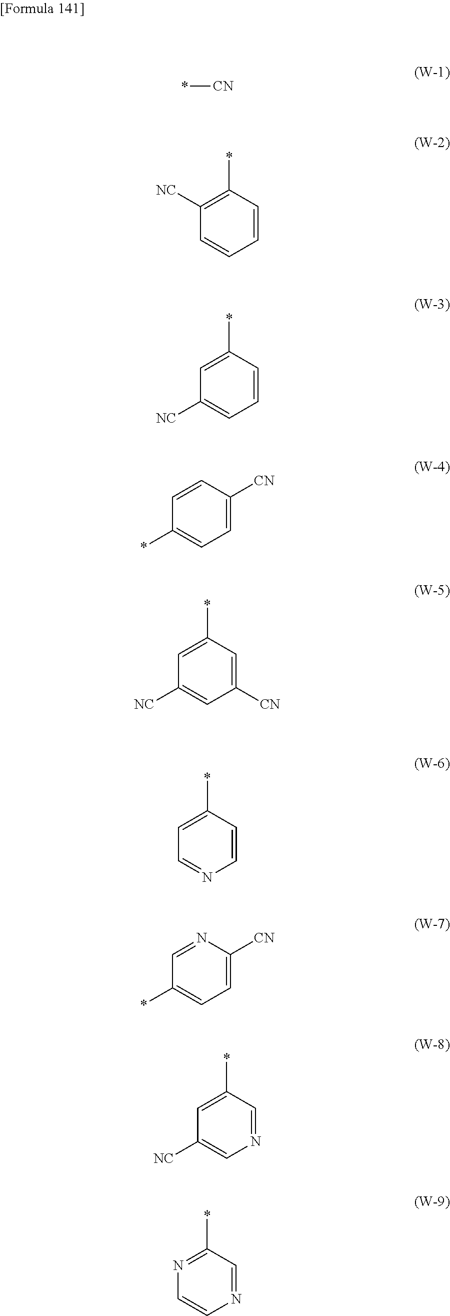

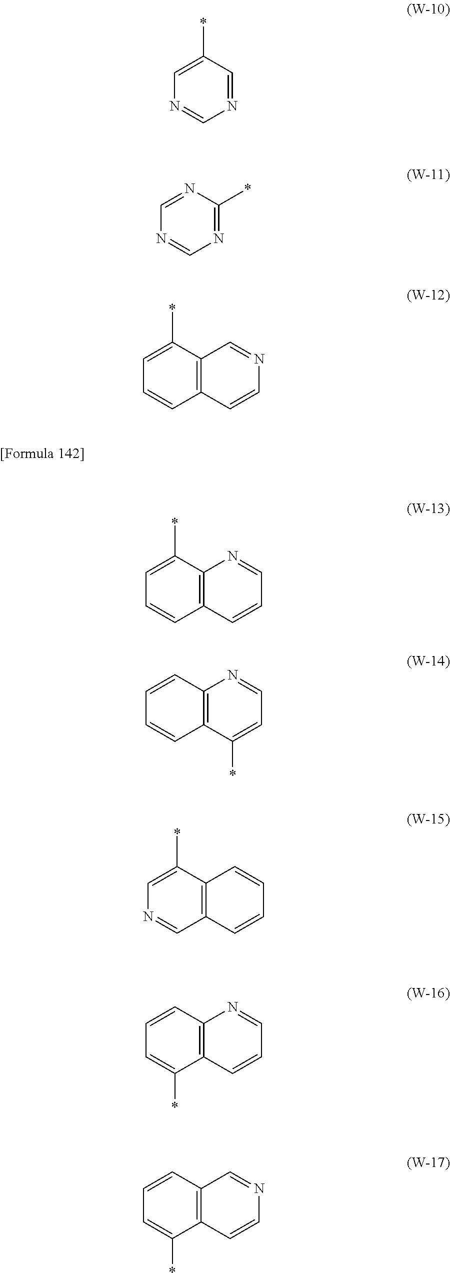

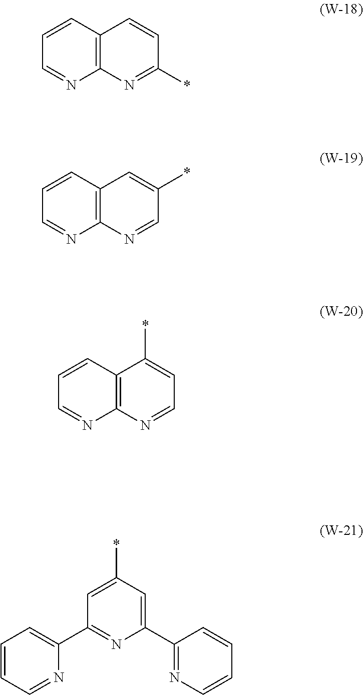 [SMILES: *c1ccc2cccnc2n1 ; *c1cnc2ncccc2c1 ; *c1ccnc2ncccc12 ; *c1cc(-c2ccccn2)nc(-c2ccccn2)c1]

In the formulae (W-1) to (W-21), each * represents a bonding position.

As an exemplary arrangement of a compound represented by the formula (1002), a compound represented by a formula (1002A) below is given.

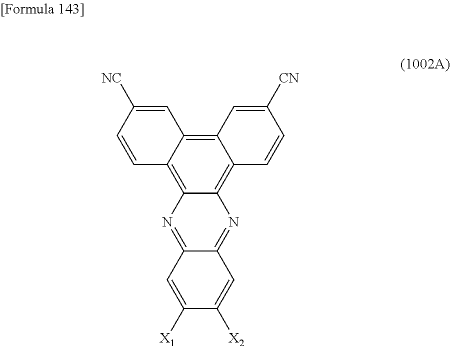

In the formula (1002A), X₁ and X₂ each independently represent the same as X₁ and X₂ in the formula (1002).

In an exemplary arrangement of the exemplary embodiment, the first sensitizing material is a compound represented by a formula (1003) below.

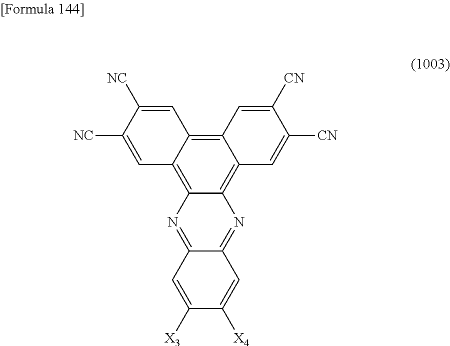

In the formula (1003):
X₃ and X₄ are each independently a hydrogen atom, a substituted or unsubstituted aryl group having 6 to 40 ring carbon atoms, a substituted or unsubstituted heteroaryl group having 5 to 40 ring atoms, or a group represented by —N(Rz₁)(Rz₂);
a combination of Rz₁ and Rz₂ are mutually bonded to form a substituted or unsubstituted monocyclic ring, mutually bonded to form a substituted or unsubstituted fused ring, or not mutually bonded; and
Rz₁ and Rz₂ forming neither the substituted or unsubstituted monocyclic ring nor the substituted or unsubstituted fused ring are each independently a substituted or unsubstituted aryl group having 6 to 40 ring carbon atoms, or a substituted or unsubstituted heteroaryl group having 5 to 40 ring carbon atoms.

In an exemplary arrangement of the exemplary embodiment, the first sensitizing material is a compound represented by any one of formulae (1004A) to (1004D) below.

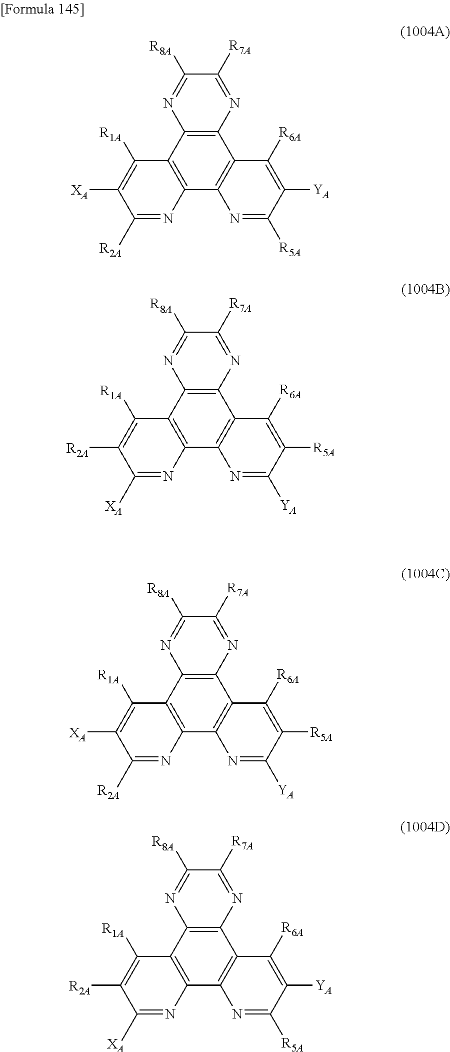

In the formulae (1004A) to (1004D):
X_{A} is a substituted or unsubstituted aryl group having 6 to 50 ring carbon atoms, a substituted or unsubstituted heteroaryl group having 5 to 50 ring atoms, or a group represented by —N(Rz₁)(Rz₂);
Y_{A} is a hydrogen atom, a fluorine atom, a chlorine atom, a cyano group, a nitro group, a substituted or unsubstituted alkyl group having 1 to 6 carbon atoms, a substituted or unsubstituted cycloalkyl group having 5 to 10 ring carbon atoms, a substituted or unsubstituted alkenyl group having 2 to 6 carbon atoms, a substituted or unsubstituted alkyloxy group having 1 to 6 carbon atoms, a substituted or unsubstituted cycloalkyloxy group having 5 to 10 ring carbon atoms, a substituted or unsubstituted aryl group having 6 to 50 ring carbon atoms, a substituted or unsubstituted heteroaryl group having 5 to 50 ring carbon atoms, a substituted or unsubstituted aryloxy group having 6 to 50 ring carbon atoms, or a group represented by —N(Rz₁)(Rz₂);
R_{1A} to R_{2A} and R_{5A} to R_{8A} are each independently a hydrogen atom, a fluorine atom, a chlorine atom, a cyano group, a nitro group, a substituted or unsubstituted alkyl group having 1 to 10 carbon atoms, a substituted or unsubstituted cycloalkyl group having 5 to 10 ring carbon atoms, a substituted or unsubstituted alkenyl group having 2 to 6 carbon atoms, a substituted or unsubstituted alkyloxy group having 1 to 6 carbon atoms, a substituted or unsubstituted cycloalkyloxy group having 5 to 10 ring carbon atoms, a substituted or unsubstituted aryl group having 6 to 50 ring carbon atoms, a substituted or unsubstituted heteroaryl group having 5 to 50 ring carbon atoms, a substituted or unsubstituted aryloxy group having 6 to 50 ring carbon atoms, or a group represented by —N(Rz₁)(Rz₂);
a combination of Rz₁ and Rz₂ are mutually bonded to form a substituted or unsubstituted monocyclic ring, mutually bonded to form a substituted or unsubstituted fused ring, or not mutually bonded; and
Rz₁ and Rz₂ forming neither the substituted or unsubstituted monocyclic ring nor the substituted or unsubstituted fused ring are each independently a substituted or unsubstituted aryl group having 6 to 50 ring carbon atoms, or a substituted or unsubstituted heteroaryl group having 5 to 50 ring carbon atoms.

When Rz₁ and Rz₂ in —N(Rz₁)(Rz₂) form the substituted or unsubstituted monocyclic ring or the substituted or unsubstituted fused ring, Rz₁ and Rz₂ may be mutually bonded via a single bond to form a monocyclic ring or a fused ring, mutually bonded via a substituted or unsubstituted methylene group to form a monocyclic ring or a fused ring, or mutually bonded via an oxygen atom or a sulfur atom to form a monocyclic ring or a fused ring.

As an exemplary arrangement of a compound represented by the formula (1004B), a compound represented by a formula (1004B-1) below is given.

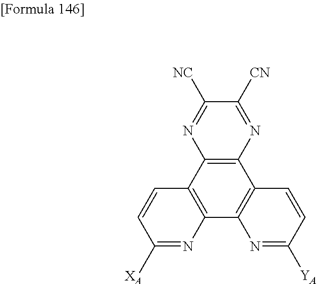

In the formula (1004B-1), X_{A} and Y_{A} each independently represent the same as X_{A} and Y_{A} in the formula (1004B).

In an exemplary arrangement of the exemplary embodiment, the first sensitizing material is a compound represented by any one of formulae (1005A) to (1005D) below.

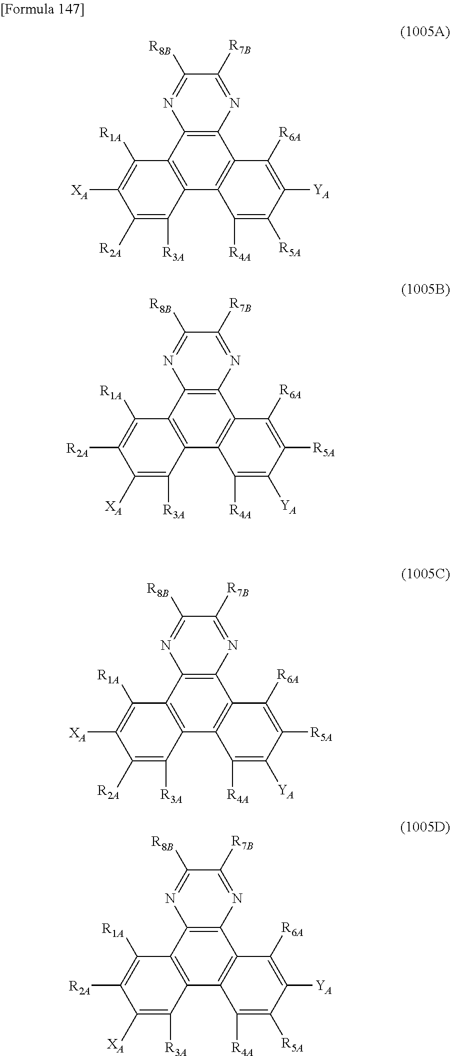

In the formulae (1005A) to (1005D):
X_{A} and Y_{A} each independently represent the same as X_{A} and Y_{A} in the formulae (1004A) to (1004D);
R_{1A} to R_{6A} each independently represent the same as R_{1A} to R_{2A} and R_{5A} to R_{8A} in the formulae (1004A) to (1004D);
a combination of R_{7B} and R_{8B} are mutually bonded to form a substituted or unsubstituted monocyclic ring, mutually bonded to form a substituted or unsubstituted fused ring, or not mutually bonded; and
R_{7B} and R_{8B} forming neither the substituted or unsubstituted monocyclic ring nor the substituted or unsubstituted fused ring each independently represent the same as R_{1A} to R_{2A} and R_{5A} to R_{8A} in the formulae (1004A) to (1004D).

As an exemplary arrangement of a compound represented by the formula (1005B), a compound represented by a formula (1005B-1), (1005B-2), (1005B-3), or (1005B-4) below is given.

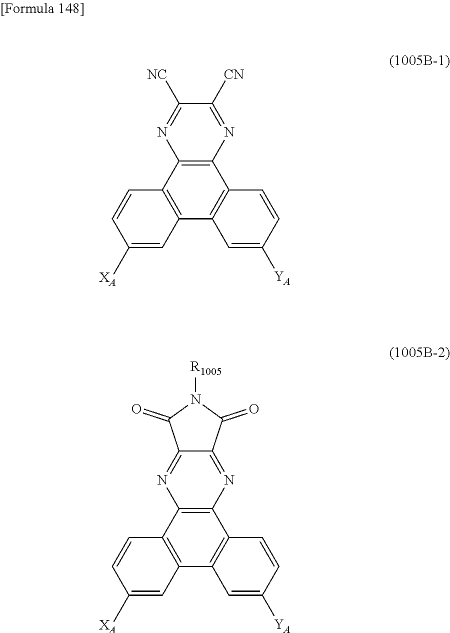

In the formulae (1005B-1) and (1005B-2): X_{A} and Y_{A} each independently represent the same as X_{A} and Y_{A} in the formula (1005B); and R₁₀₀₅ is a substituted or unsubstituted aryl group having 6 to 50 ring carbon atoms or a substituted or unsubstituted heteroaryl group having 5 to 50 ring carbon atoms.

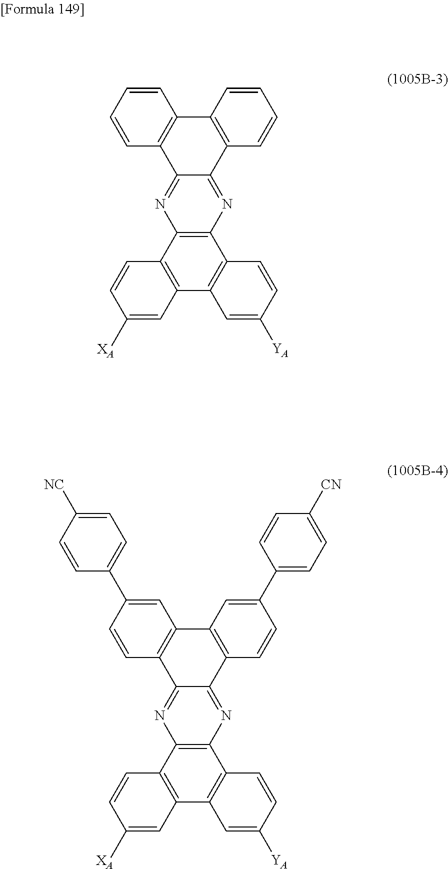

In the formulae (1005B-3) and (1005B-4), X_{A} and Y_{A} each independently represent the same as X_{A} and Y_{A} in the formula (1005B).

In an exemplary arrangement of the exemplary embodiment, the first sensitizing material is a compound represented by a formula (1006) below.

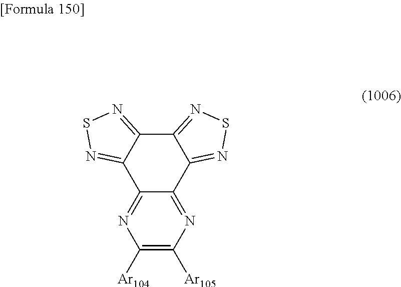

In the formula (1006): Ar₁₀₄ and Ar₁₀₅ are each independently a substituted or unsubstituted aryl group having 6 to 50 ring carbon atoms or a substituted or unsubstituted heteroaryl group having 5 to 50 ring atoms; and at least one of Ar₁₀₄ or Ar₁₀₅ is an aryl group substituted by an N,N-diarylamino group.

In the formula (1006): one of Ar₁₀₄ and Ar₁₀₅ may be an aryl group substituted by an N,N-diarylamino group or both of Ar₁₀₄ and Ar₁₀₅ may be each an aryl group substituted by an N,N-diarylamino group. However, both of Ar₁₀₄ and Ar₁₀₅ are preferably each an aryl group substituted by an N,N-diarylamino group. When both of Ar₁₀₄ and Ar₁₀₅ are each an aryl group substituted by an N,N-diarylamino group, the N,N-diarylamino groups may be the same or different, preferably the same.

As an exemplary arrangement of an aryl group substituted by an N,N-diarylamino group in the formula (1006), a group represented by a formula (1006A) below is given.

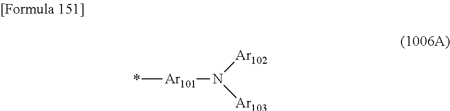

In the formula (1006A):
Ar₁₀₁ is a substituted or unsubstituted arylene group having 6 to 18 ring carbon atoms or a substituted or unsubstituted heteroarylene group having 5 to 18 ring atoms;
Ar₁₀₂ and Ar₁₀₃ are each independently a substituted or unsubstituted aryl group having 6 to 18 ring carbon atoms, a combination of Ar₁₀₂ and Ar₁₀₃ may be mutually bonded by a single bond or be linked via a linking group A; and
* represents a bonding position to a pyrazine ring in the formula (1006).

In the formula (1006A), the linking group A is exemplified by a substituted or unsubstituted methylene group, a substituted or unsubstituted ethylene group, a substituted or unsubstituted vinylene group, a substituted or unsubstituted imino group, an oxygen atom, or a sulfur atom. When the ethylene group and the vinylene group of the above groups are substituted by a plurality of substituents, adjacent two of the substituents may be mutually bonded to form a cyclic structure.

In an exemplary arrangement of the exemplary embodiment, the first sensitizing material is a compound represented by a formula (1007A) or (1007B) below.

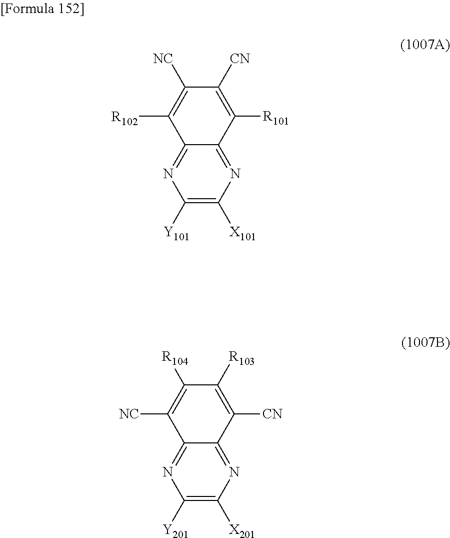

In the formulae (1007A) and (1007B):
R₁₀₁ to R₁₀₄ are each independently a hydrogen atom, a substituted or unsubstituted alkyl group having 1 to 5 carbon atoms, a substituted or unsubstituted alkoxy group having 1 to 5 carbon atoms, or a substituted or unsubstituted phenyl group, and
X₁₀₁, Y₁₀₁, X₂₀₁, and Y₂₀₁ are each independently a hydrogen atom, a substituted or unsubstituted alkyl group having 1 to 5 carbon atoms, a substituted or unsubstituted aromatic amino group, or a substituted or unsubstituted aromatic phosphineoxy group.

In the formulae (1007A) and (1007B), examples of the aromatic amino group include an alkylamino group, an arylamino group, a dialkylamino group, and a diarylamino group.

As an exemplary arrangement of a compound represented by the formula (1007A), a compound represented by a formula (1007A-1) below is given. As an exemplary arrangement of a compound represented by the formula (1007B), a compound represented by a formula (1007B-1) below is given.

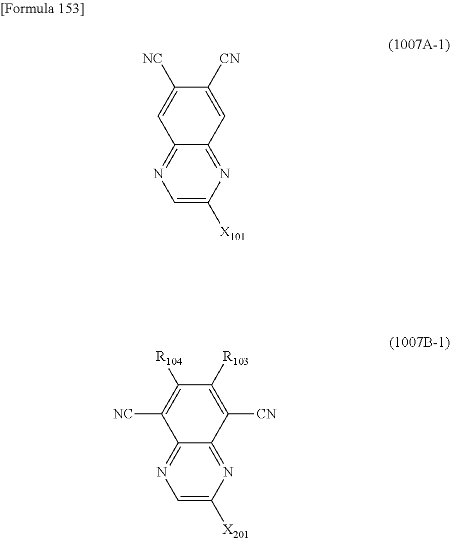

In the formula (1007A-1), Xioi represents the same as Xioi in the formula (1007A).

In the formula (1007B-1), R₁₀₃, R₁₀₄ and X₂₀₁ represent the same as R₁₀₃, R₁₀₄ and X₂₀₁ in the formula (1007B).

In an exemplary arrangement of the exemplary embodiment, the first sensitizing material is a compound represented by a formula (1008) or (1008A) below.

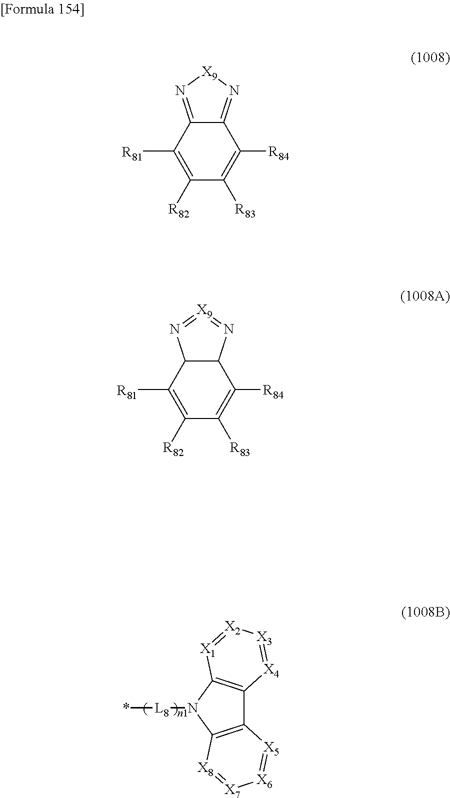

In the formulae (1008) and (1008A):
X₉ is a sulfur atom or a selenium atom;
a combination of R₈₂ and R₈₃ are mutually bonded to form a substituted or unsubstituted monocyclic ring, mutually bonded to form a substituted or unsubstituted fused ring, or not mutually bonded;
R₈₁ and R₈₄, and R₈₂ and R₈₃ forming neither the substituted or unsubstituted monocyclic ring nor the substituted or unsubstituted fused ring are each independently a hydrogen atom, a hydroxy group, a halogen atom, a cyano group, a substituted or unsubstituted alkyl group having 1 to 20 carbon atoms, a substituted or unsubstituted alkoxy group having 1 to 20 carbon atoms, a substituted or unsubstituted alkylthio group having 1 to 20 carbon atoms, a substituted or unsubstituted alkyl-substituted amino group having 1 to 20 carbon atoms, a substituted or unsubstituted aryl-substituted amino group having 6 to 40 carbon atoms, a substituted or unsubstituted acyl group having 2 to 20 carbon atoms, a substituted or unsubstituted aryl group having 6 to 40 carbon atoms, a substituted or unsubstituted heteroaryl group having 3 to 40 ring atoms, a substituted or unsubstituted alkenyl group having 2 to 10 carbon atoms, a substituted or unsubstituted alkynyl group having 2 to 10 carbon atoms, a substituted or unsubstituted alkoxycarbonyl group having 2 to 10 carbon atoms, a substituted or unsubstituted alkylsulfonyl group having 1 to 10 carbon atoms, a substituted or unsubstituted haloalkyl group having 1 to 10 carbon atoms, a substituted or unsubstituted amide group, a substituted or unsubstituted alkylamide group having 2 to 10 carbon atoms, a substituted or unsubstituted trialkylsilyl group having 3 to 20 carbon atoms, a substituted or unsubstituted trialkylsilylalkyl group having 4 to 20 carbon atoms, a substituted or unsubstituted trialkylsilylalkenyl group having 5 to 20 carbon atoms, a substituted or unsubstituted trialkylsilylalkynyl group having 5 to 20 carbon atoms, or nitro group; and
at least two of R₈₁ to R₈₄ are each independently a group represented by the formula (1008B).

In the formula (1008B):
L₈ is a substituted or unsubstituted arylene group having 6 to 40 ring carbon atoms or a substituted or unsubstituted heteroarylene group having 5 to 40 ring atoms;
n1 is 0 or 1;
X₁ to X₈ are each independently a nitrogen atom or CR₁₀₀₈; at least one of X₁ to X₈ is CR₁₀₀₈;
at least one combination of adjacent ones of R₁₀₀₈ are mutually bonded to form a substituted or unsubstituted monocyclic ring, mutually bonded to form a substituted or unsubstituted fused ring, or not mutually bonded;
R₁₀₀₈ forming neither the substituted or unsubstituted monocyclic ring nor the substituted or unsubstituted fused ring each independently represent the same as R₈₁ and R₈₄ in the formulae (1008) and (1008A); and
a plurality of R₁₀₀₈ are mutually the same or different.

As an exemplary arrangement of compounds represented by the formulae (1008) and (1008A), a compound represented by any one of formulae (1008-1) to (1008-7) below is given.

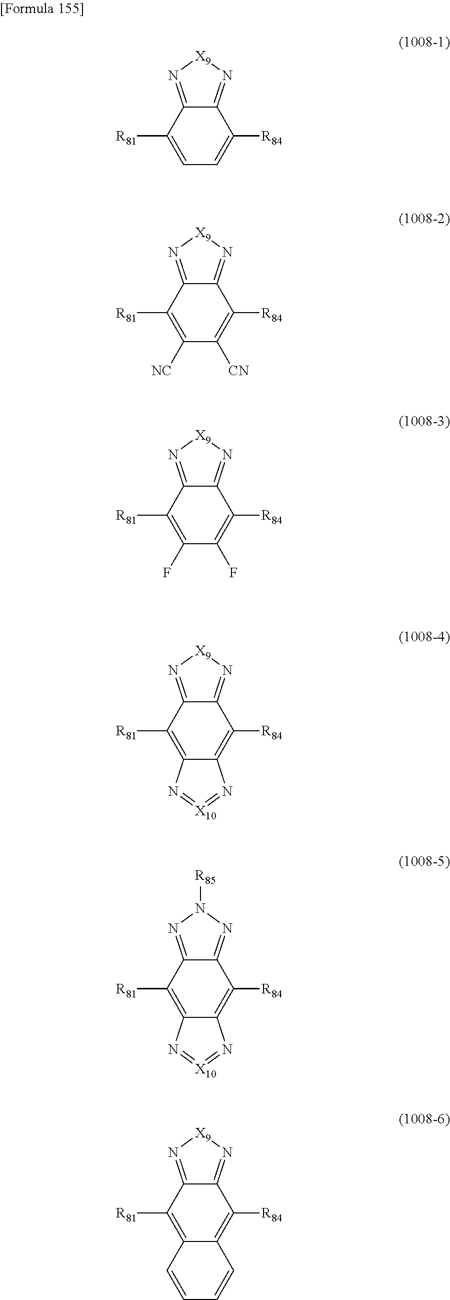

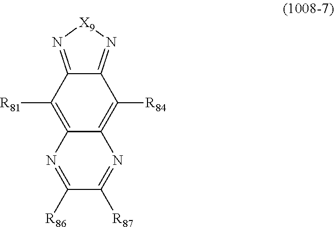

In the formulae (1008-1) to (1008-7): X₁₀ is a sulfur atom or a selenium atom; R₈₅ to R₈₇ each independently represent the same as R₈₁ in the formulae (1008) and (1008A); and X₉, R₈₁, and R₈₄ each independently represent the same as X₉, R₈₁, and R₈₄ in the formulae (1008) and (1008A).

In an exemplary arrangement of the exemplary embodiment, the first sensitizing material is a compound represented by any one of formulae (1009A) to (1009C) below.

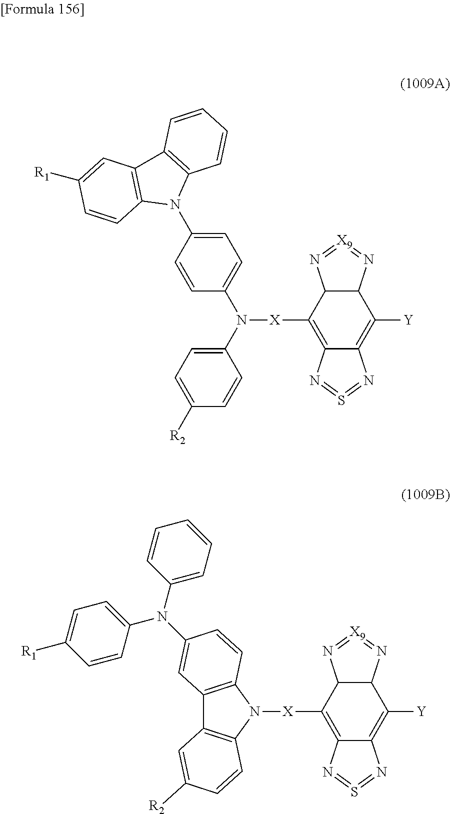

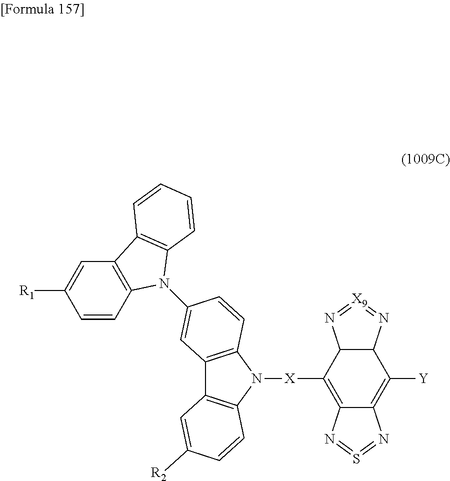

In the formulae (1009A) to (1009C):
X₉ is a sulfur atom or a selenium atom;
X is a substituted or unsubstituted arylene group having 6 to 20 ring carbon atoms, a substituted or unsubstituted heteroarylene group having 3 to 20 ring atoms, a substituted or unsubstituted arylene group having 6 to 20 ring carbon atoms, and a group formed by bonding two or three groups selected from a substituted or unsubstituted heteroarylene group having 3 to 20 ring atoms;
Y is a substituted or unsubstituted aryl group having 6 to 20 ring carbon atoms, a substituted or unsubstituted heteroaryl group having 3 to 20 ring atoms, or a group represented by —N(Rz₁)(Rz₂);
Rz₁ and Rz₂ are each independently a substituted or unsubstituted aryl group having 6 to 50 ring carbon atoms, or a substituted or unsubstituted heteroaryl group having 5 to 50 ring carbon atoms;
R₁ and R₂ are each independently a hydrogen atom, a substituted or unsubstituted carbazolyl group, or a substituted or unsubstituted diphenylamine group; and
at least one of R₁ or R₂ is a hydrogen atom.

In an exemplary arrangement of the exemplary embodiment, the first sensitizing material is a compound represented by a formula (1010) below.

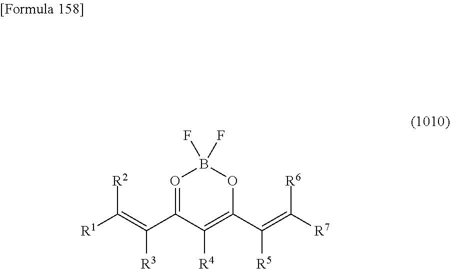

In the formula (1010): R¹ to R⁷ each independently represent a hydrogen atom or a substituent; at least one combination of a combination of R¹ and R², a combination of R² and R³, a combination of R³ and R⁴, a combination of R⁴ and R⁵ a combination of R⁵ and R⁶, or a combination of R⁶ and R⁷ may be mutually bonded to form a ring; and R⁷ represents a group represented by a formula (1010A) or (1010B) below.

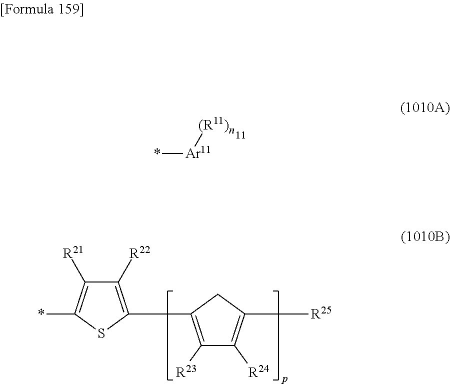

In the formula (1010A):
Ar¹¹ is a group derived from a substituted or unsubstituted aryl group having 6 to 40 ring carbon atoms;
R¹¹ represents a substituent other than an aryl group;
n₁₁ represents an integer from 1 to the number of possible substitution positions in Ar¹¹;
when n₁₁ is 2 or more, a plurality of R¹¹ are the same or different; and at least one R¹¹ is an electron donating group.
   In the formula (1010B): R²¹ to R²⁵ are each independently a hydrogen atom or a substituent; and p is an integer from 0 to 2.

In the formulae (1010), (1010A), and (1010B), R¹ to R⁶, R¹¹, and R²¹ to R²⁵ as a substituent are each independently a halogen atom, alkyl group, alkenyl group, alkynyl group, aryl group, heteroaryl group, halogen atom, hydroxyl group, nitro group, carboxyl group, cyano group, alkoxy group, aryloxy group, acyl group, acyloxy group, carbamoyloxy group (alkoxycarbonyloxy group etc.), primary amino group, alkylamino group, arylamino group, dialkylamino group, diarylamino group, alkylarylamino group, acylamino group, aminocarbonylamino group, alkoxycarbonylamino group, aryloxycarbonylamino group, sulfamoylamino group, alkylsulfonylamino group, arylsulfonylamino group, alkylthio group, arylthio group, sulfo group, sulfamoyl group, alkylsulfinyl group, arylsulfinyl group, alkylsulfonyl group, arylsulfonyl group, alkoxycarbonyl group, aryloxycarbonyl group, carbamoyl group, imide group, alkoxysulfonyl group, aryloxysulfonyl group, trialkylsilyl group, or trialkylsilyloxy group. These groups can be further substituted.

In an exemplary arrangement of the exemplary embodiment, the first sensitizing material is a compound represented by a formula (1011A) or (1011B) below.

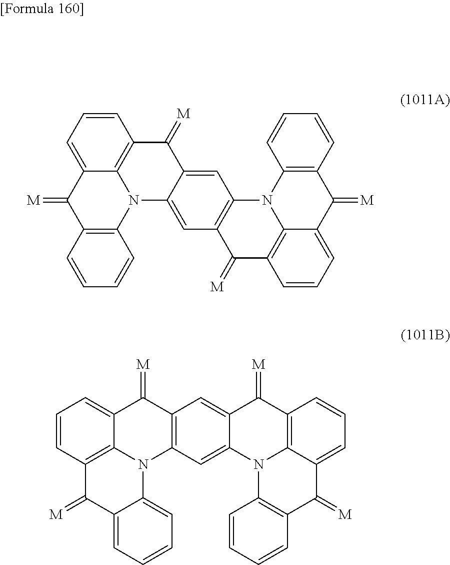

In the formulae (1011A) and (1011B):
M is each independently selected from the group consisting of C(R₁)₂, NR₁, oxygen atom, sulfur atom, SO₂, P(═O)R₁, Si(R₁)₂, Ge(R₁)₂ and groups represented by formulae (M-1) to (M-5) below;
R₁ is each independently a hydrogen atom, fluorine atom, chlorine atom, bromine atom, iodine atom, cyano group, —NO₂, —N(R₂)₂, —OR₂, —SR₂, —C(═O)R₂, —P(═O)R₂, —Si(R₂)₃, a substituted or unsubstituted alkyl group having 1 to 20 carbon atoms, a substituted or unsubstituted alkenyl group having 2 to 20 carbon atoms, a substituted or unsubstituted alkynyl group having 1 to 20 carbon atoms, a substituted or unsubstituted aryl group having 6 to 40 ring carbon atoms, or a substituted or unsubstituted heteroaryl group having 3 to 40 ring atoms;
R₂ is each independently a hydrogen atom, fluorine atom, cyano group, a substituted or unsubstituted alkyl group having 1 to 20 carbon atoms, a substituted or unsubstituted aryl group having 6 to 30 ring carbon atoms, or a substituted or unsubstituted heteroaryl group having 3 to 30 ring atoms;
a plurality of M are mutually the same or different;
when a plurality of R₁ are present, the plurality of R₁ are mutually the same or different; and
when a plurality of R₂ are present, the plurality of R₁ are mutually the same or different.

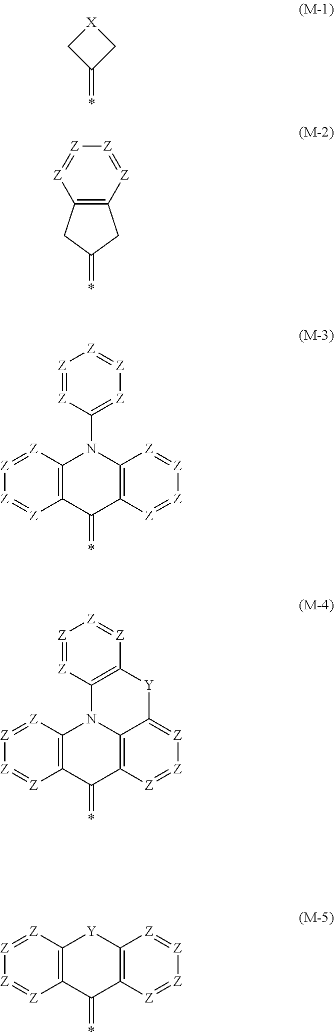

In the formulae (M-1) to (M-5):
X is a substituted or unsubstituted alkyl group having 1 to 8 carbon atoms or a single bond;
Y is C(R₁)₂, NR₁, carbonyl group, oxygen atom, sulfur atom, SO₂, P(═O)R₁, Si(R₁)₂, Ge(R₁)₂, or a single bond;
Z is CR₁ or a sulfur atom;
R₁ in Y and R₁ in Z each independently represent the same as R₁ in the formula (1011A); and
when a plurality of R₁ are present, the plurality of R₁ are mutually the same or different; a plurality of Z are mutually the same or different; and * represents a bonding position.

In an exemplary arrangement of the exemplary embodiment, the first sensitizing material is a compound represented by a formula (1012A) or (1012B) below.

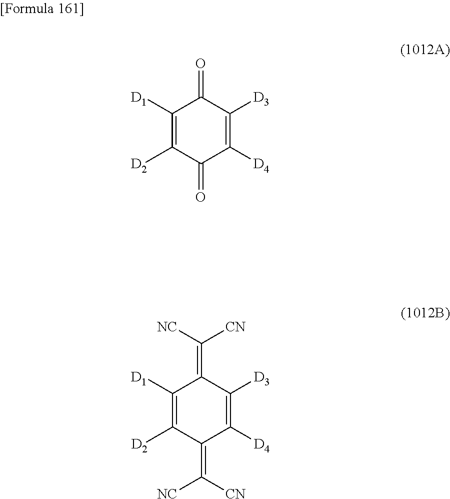

In the formulae (1012A) and (1012B):
D₁ and D₄ are the same electron-donating group or a hydrogen atom, or D₁ and D₄ are different electron-donating groups;
D₂ and D₃ are the same electron-donating group or a hydrogen atom, or D₂ and D₃ are different electron-donating groups; and
the electron-donating group is selected from one of a substituted or unsubstituted carbazolyl group, substituted or unsubstituted acridine group, substituted or unsubstituted phenoxazinyl group, substituted or unsubstituted phenazinyl group, substituted or unsubstituted phenazinyl group, and substituted or unsubstituted phenothiazinyl group. A substituent for a substituted or unsubstituted group is one or more of a methyl group, ethyl group, isopropyl group, tert-butyl group, phenyl group, carbazolyl group, substituted or unsubstituted amino group, acridine group, phenazinyl group, fluorenyl group, dibenzofuran group, and dibenzothiophene.

In an exemplary arrangement of the exemplary embodiment, the first sensitizing material is a compound represented by a formula (1013) below.

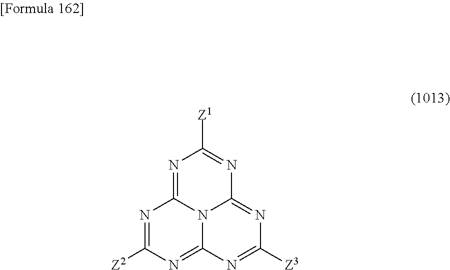

In the formula (1013), Z¹, Z², and Z³ each independently represent a substituent, in which the substituent is an atom or a group of atoms other than a hydrogen atom.

In the formula (1013), substituents represented by Z¹, Z², and Z³ are each independently preferably a substituted amino group (e.g., dialkylamino group, diarylamino group, and alkylarylamino group), a substituted or unsubstituted aryl group having 6 to 50 ring carbon atoms, or a substituted or unsubstituted heteroaryl group having 5 to 50 ring atoms. Z¹, Z², and Z³ are preferably the same as each other.

In an exemplary arrangement of the exemplary embodiment, the first sensitizing material is a compound represented by a formula (1014) below.

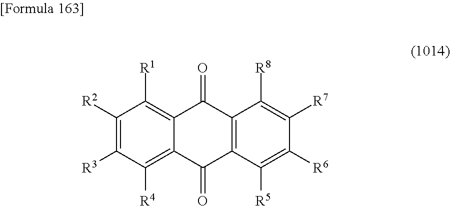

In the formula (1014):
at least one combination of adjacent two or more of R¹ to R⁸ are mutually bonded to form a substituted or unsubstituted monocyclic ring, mutually bonded to form a substituted or unsubstituted fused ring, or not mutually bonded; and
R¹ to R⁸ forming neither the substituted or unsubstituted monocyclic ring nor the substituted or unsubstituted fused ring each independently represent a hydrogen atom or a substituent; and at least one of R¹ to R⁸ is each independently a group represented by a formula (1014A) below.

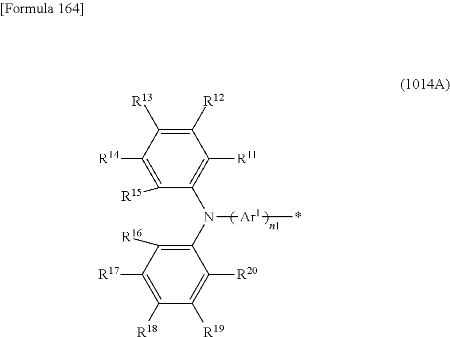

In the formula (1014A):
Ar¹ is a substituted or unsubstituted phenylene group or a substituted or unsubstituted naphthylene group; n1 is 0 or 1;
at least one combination of adjacent two or more of R¹¹ to R²⁰ are mutually bonded to form a substituted or unsubstituted monocyclic ring, mutually bonded to form a substituted or unsubstituted fused ring, or not mutually bonded; and
R¹¹ to R²⁰ forming neither the substituted or unsubstituted monocyclic ring nor the substituted or unsubstituted fused ring each independently represent a hydrogen atom or a substituent.

In the formulae (1014) and (1014A), R¹ to R⁸ and R¹¹ to R²⁰ are preferably each independently a hydrogen atom, hydroxy group, halogen atom, cyano group, alkyl group having 1 to 20 carbon atoms, alkoxy group having 1 to 20 carbon atoms, alkylthio group having 1 to 20 carbon atoms, alkyl-substituted amino group having 1 to 20 carbon atoms, acyl group having 2 to 20 carbon atoms, aryl group having 6 to 40 carbon atoms, heteroaryl group having 3 to 40 carbon atoms, alkenyl group having 2 to 10 carbon atoms, alkynyl group having 2 to 10 carbon atoms, alkoxycarbonyl group having 2 to 10 carbon atoms, alkylsulfonyl group having 1 to 10 carbon atoms, haloalkyl group having 1 to 10 carbon atoms, amide group, alkylamide group having 2 to 10 carbon atoms, trialkylsilyl group having 3 to 20 carbon atoms, trialkylsilylalkyl group having 4 to 20 carbon atoms, trialkylsilylalkenyl group having 5 to 20 carbon atoms, trialkylsilylalkynyl group having 5 to 20 carbon atoms, or nitro group.

In the formula (1014A), a substituent for a substituted or unsubstituted group of Ar¹ each independently represents the same as R¹ to R⁸ and R¹¹ to R²⁰ (other than a hydrogen atom) in the formulae (1014) and (1014A).

In an exemplary arrangement of the exemplary embodiment, the first sensitizing material is a compound represented by a formula (1015) below.

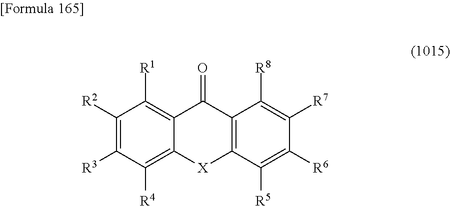

In the formula (1015):
X is an oxygen atom or a sulfur atom;
at least one combination of adjacent two or more of R¹ to R⁸ are mutually bonded to form a substituted or unsubstituted monocyclic ring, mutually bonded to form a substituted or unsubstituted fused ring, or not mutually bonded; and
R¹ to R⁸ forming neither the substituted or unsubstituted monocyclic ring nor the substituted or unsubstituted fused ring each independently represent a hydrogen atom or a substituent; and at least one of R¹ to R⁸ is each independently a group represented by any one of formulae (1015A) to (1015E) below.

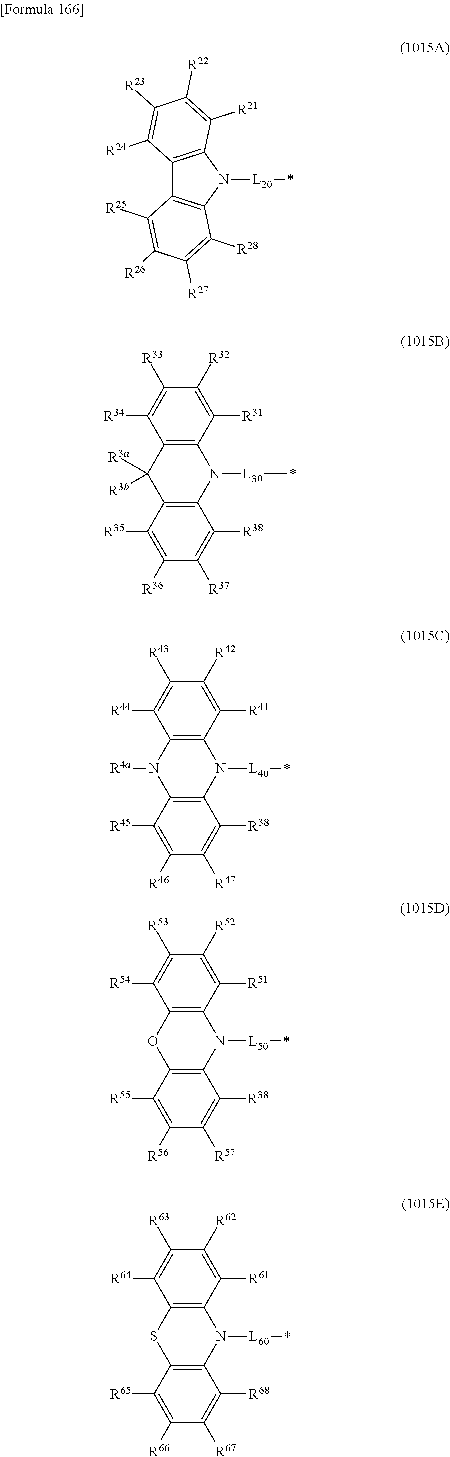

In the formulae (1015A) to (1015E):
L₂₀, L₃₀, L₄₀, L₅₀, and L₆₀ each independently represent a single bond or a divalent linking group;
* is bonded to a ring skeleton of the formula (1015);
at least one combination of adjacent two or more of R²¹ to R²⁸ are mutually bonded to form a substituted or unsubstituted monocyclic ring, mutually bonded to form a substituted or unsubstituted fused ring, or not mutually bonded;
at least one combination of adjacent two or more of R³¹ to R³⁸ are mutually bonded to form a substituted or unsubstituted monocyclic ring, mutually bonded to form a substituted or unsubstituted fused ring, or not mutually bonded;
a combination of R^{3a} and R^{3b} are mutually bonded to form a substituted or unsubstituted monocyclic ring, mutually bonded to form a substituted or unsubstituted fused ring, or not mutually bonded;
at least one combination of adjacent two or more of R⁴¹ to R⁴⁸ are mutually bonded to form a substituted or unsubstituted monocyclic ring, mutually bonded to form a substituted or unsubstituted fused ring, or not mutually bonded;
at least one combination of adjacent two or more of R⁵¹ to R⁵⁸ are mutually bonded to form a substituted or unsubstituted monocyclic ring, mutually bonded to form a substituted or unsubstituted fused ring, or not mutually bonded;
at least one combination of adjacent two or more of R⁶¹ to R⁶⁸ are mutually bonded to form a substituted or unsubstituted monocyclic ring, mutually bonded to form a substituted or unsubstituted fused ring, or not mutually bonded; and
R²¹ to R²⁸, R³¹ to R³⁸, R^{3a}, R^{3b}, R⁴¹ to R⁴⁸, R^{4a}, R⁵¹ to R⁵⁸, and R⁶¹ to R⁶⁸ forming neither the substituted or unsubstituted monocyclic ring nor the substituted or unsubstituted fused ring each independently represent a hydrogen atom or a substituent.

In the formulae (1015A) to (1015E): L₂₀, L₃₀, L₄₀, L₅₀, and L₆₀ are preferably each independently a single bond, a substituted or unsubstituted alkenylene group having 2 to 10 carbon atoms, a substituted or unsubstituted alkynylene group having 2 to 10 carbon atoms, a substituted or unsubstituted arylene group having 6 to 10 ring carbon atoms, a substituted or unsubstituted thiophenediyl group, or a group of a combination thereof. Examples of a thiophenediyl group include a 3,4-thiophenediyl group and a 2,5-thiophenediyl group.

In the formulae (1015) and (1015A) to (1015E), R¹ to R⁸, R²¹ to R²⁸, R³¹ to R³⁸, R^{3a}, R^{3b}, R⁴¹ to R⁴⁸, R^{4a}, R⁵¹ to R⁵⁸, and R⁶¹ to R⁶⁸ are preferably each independently a hydrogen atom, hydroxy group, halogen atom, cyano group, alkyl group having 1 to 20 carbon atoms, alkoxy group having 1 to 20 carbon atoms, alkylthio group having 1 to 20 carbon atoms, alkyl-substituted amino group having 1 to 20 carbon atoms, acyl group having 2 to 20 carbon atoms, aryl group having 6 to 40 carbon atoms, heteroaryl group having 3 to 40 carbon atoms, alkenyl group having 2 to 10 carbon atoms, alkynyl group having 2 to 10 carbon atoms, alkoxycarbonyl group having 2 to 10 carbon atoms, alkylsulfonyl group having 1 to 10 carbon atoms, haloalkyl group having 1 to 10 carbon atoms, amide group, alkylamide group having 2 to 10 carbon atoms, trialkylsilyl group having 3 to 20 carbon atoms, trialkylsilylalkyl group having 4 to 20 carbon atoms, trialkylsilylalkenyl group having 5 to 20 carbon atoms, trialkylsilylalkynyl group having 5 to 20 carbon atoms, or nitro group.

In an exemplary arrangement of the exemplary embodiment, the first sensitizing material is a compound represented by a formula (1016A) or (1016B) below.

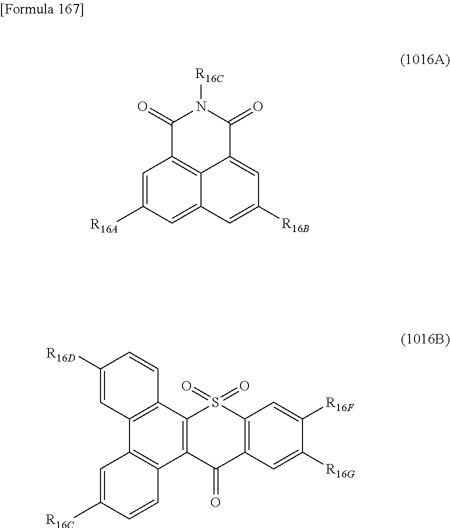

In the formula (1016A), R_{16A}, R_{16B}, and R_{16C} each independently represent a substituent, in which the substituent is an atom or a group of atoms other than a hydrogen atom.

In the formula (1016B), R_{16D}, R_{16E}, R_{16F}, and R_{16G} each independently represent a hydrogen atom or a substituent.

In the formula (1016A), substituents represented by R_{16A}, R_{16B}, and R_{16C} are preferably each independently a substituted amino group (e.g., dialkylamino group, diarylamino group, and alkylarylamino group), a substituted or unsubstituted aryl group having 6 to 50 ring carbon atoms, or a substituted or unsubstituted heteroaryl group having 5 to 50 ring atoms.

In the formula (1016B), R_{16D}, R_{16E}, R_{16F}, and R_{16G} are preferably each independently a hydrogen atom, hydroxy group, halogen atom, cyano group, alkyl group having 1 to 20 carbon atoms, alkoxy group having 1 to 20 carbon atoms, alkylthio group having 1 to 20 carbon atoms, alkyl-substituted amino group having 1 to 20 carbon atoms, acyl group having 2 to 20 carbon atoms, aryl group having 6 to 40 carbon atoms, heteroaryl group having 3 to 40 carbon atoms, alkenyl group having 2 to 10 carbon atoms, alkynyl group having 2 to 10 carbon atoms, alkoxycarbonyl group having 2 to 10 carbon atoms, alkylsulfonyl group having 1 to 10 carbon atoms, haloalkyl group having 1 to 10 carbon atoms, amide group, alkylamide group having 2 to 10 carbon atoms, trialkylsilyl group having 3 to 20 carbon atoms, trialkylsilylalkyl group having 4 to 20 carbon atoms, trialkylsilylalkenyl group having 5 to 20 carbon atoms, trialkylsilylalkynyl group having 5 to 20 carbon atoms, or nitro group.

In the first sensitizing material of the exemplary embodiment, specific examples of a compound represented by any one of the formulae (1000) to (1003), (1004A) to (1004D), (1005A) to (1005D), (1006), (1007A), (1007B), (1008), (1008A), (1009A) to (1009C), (1010), (1011A), (1011B), (1012A), (1012B), (1013) to (1015), (1016A), and (1016B) include compounds below. It should however be noted that the first sensitizing material is not limited to the specific examples of these compounds. t-C₄H₉ represents a tertiary butyl group.

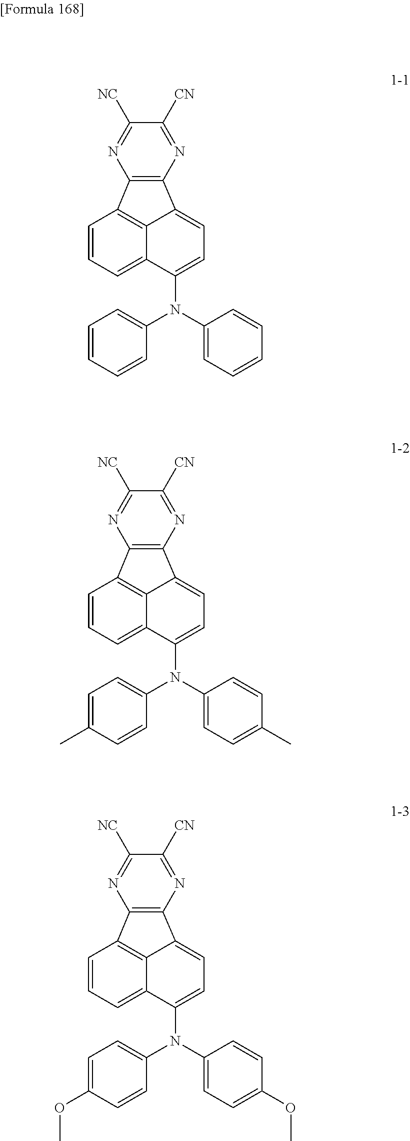

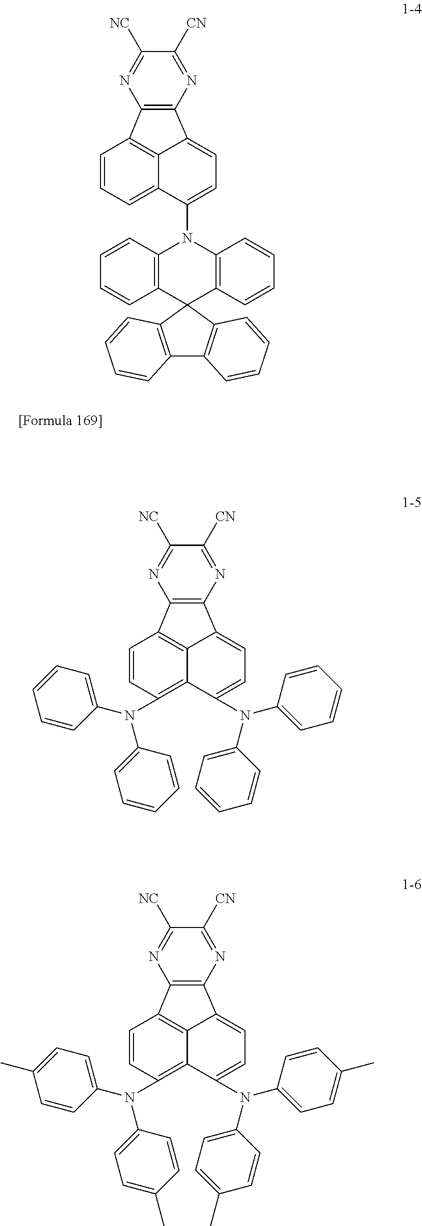

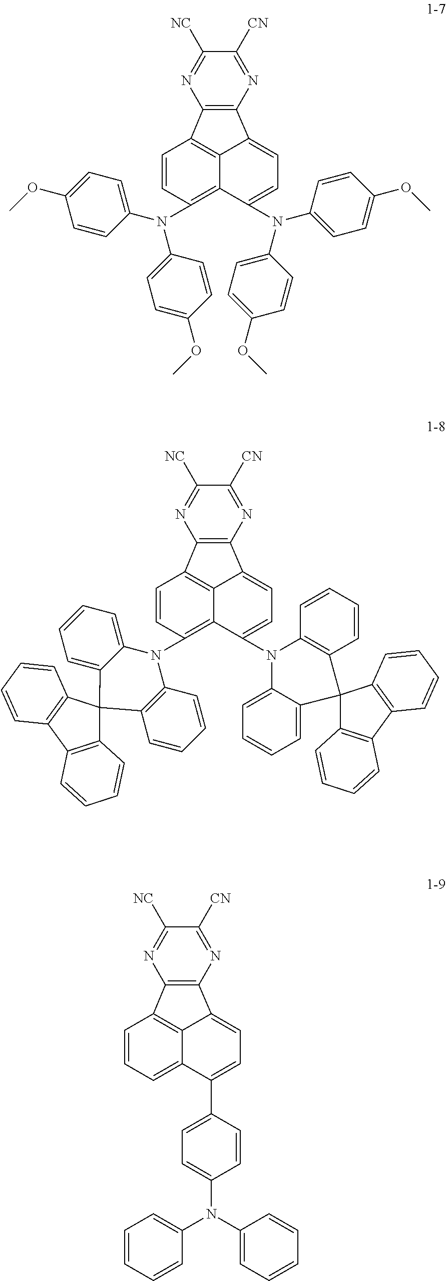

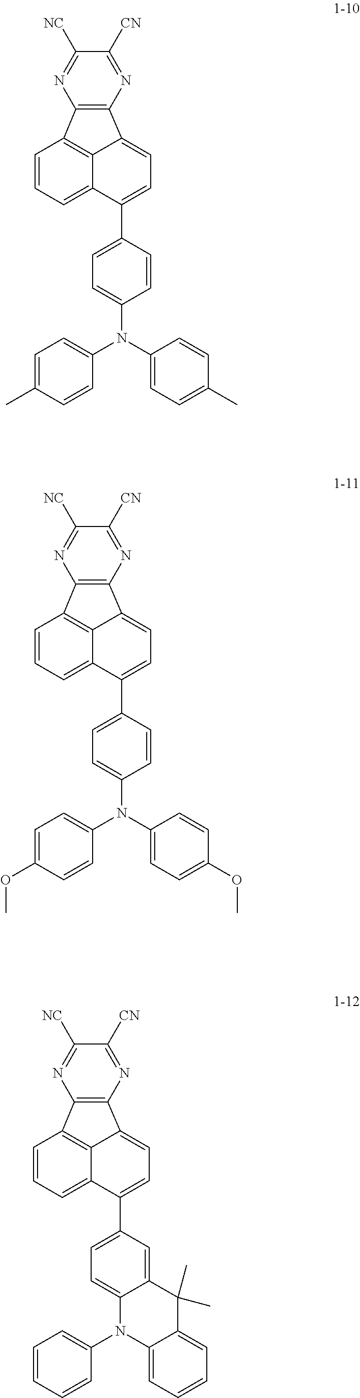

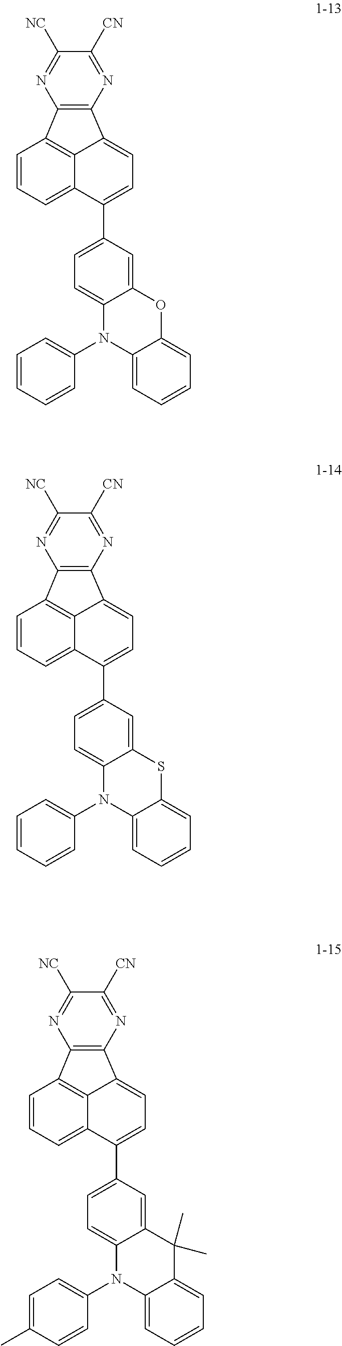

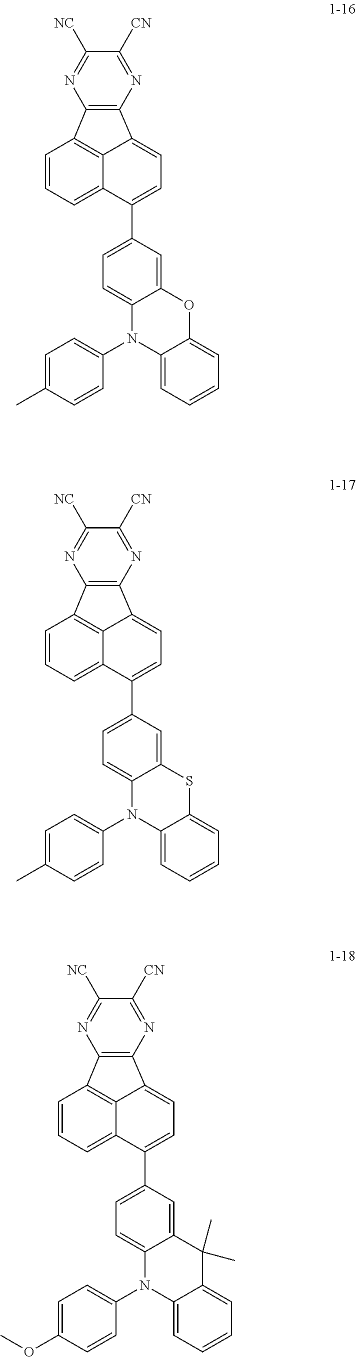

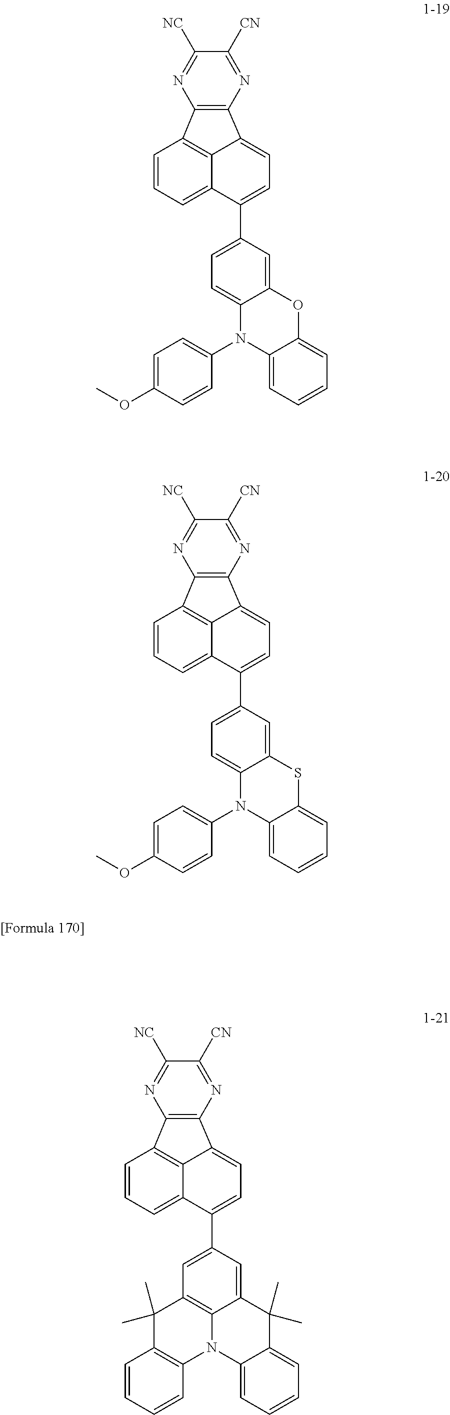

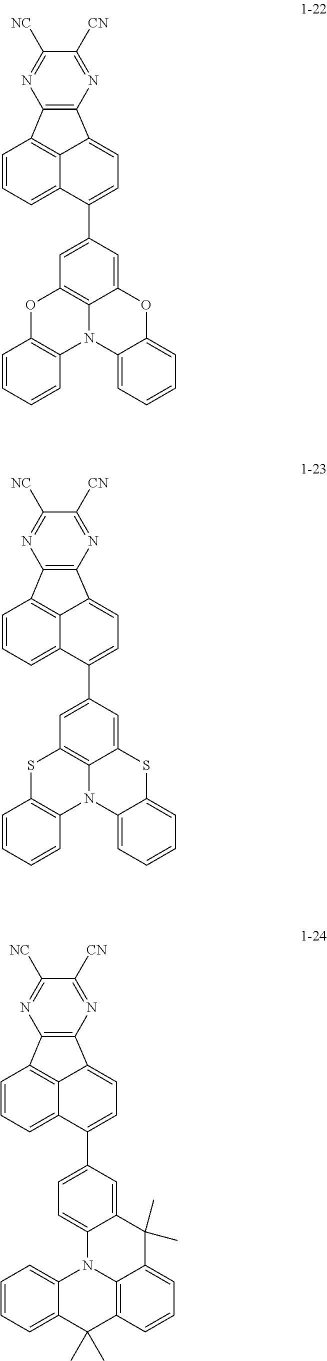 [SMILES: N#Cc1nc2c(nc1C#N)-c1ccc(-c3cc4c5c(c3)Oc3ccccc3N5c3ccccc3O4)c3cccc-2c13 ; N#Cc1nc2c(nc1C#N)-c1ccc(-c3cc4c5c(c3)Sc3ccccc3N5c3ccccc3S4)c3cccc-2c13 ; CC1(C)c2ccccc2N2c3ccc(-c4ccc5c6c(cccc46)-c4nc(C#N)c(C#N)nc4-5)cc3C(C)(C)c3cccc1c32]

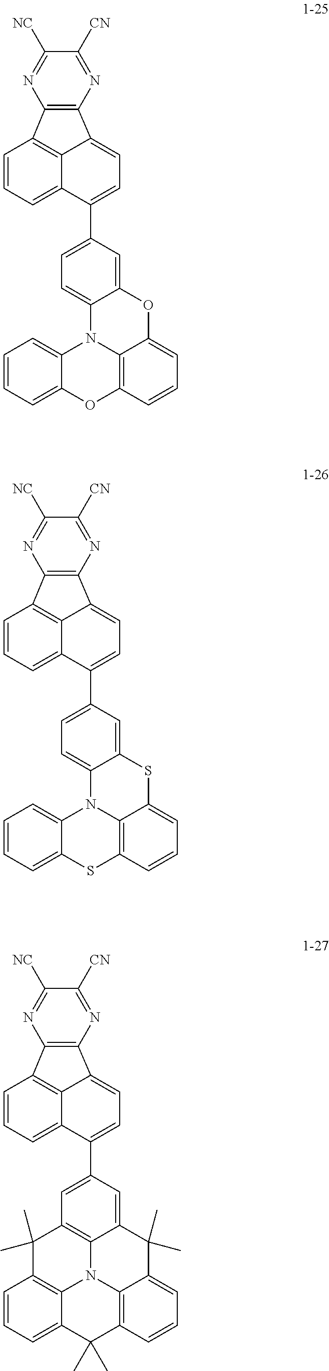

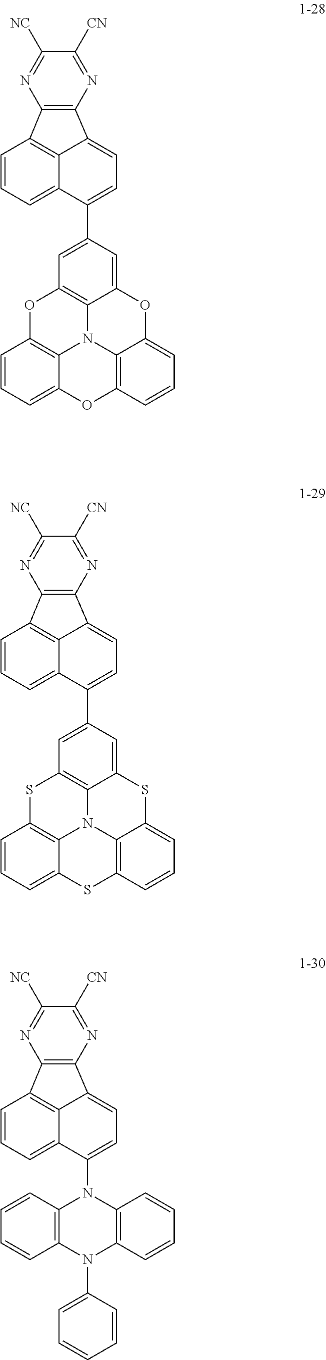 [SMILES: N#Cc1nc2c(nc1C#N)-c1ccc(-c3cc4c5c(c3)Oc3cccc6c3N5c3c(cccc3O4)O6)c3cccc-2c13 ; N#Cc1nc2c(nc1C#N)-c1ccc(-c3cc4c5c(c3)Sc3cccc6c3N5c3c(cccc3S4)S6)c3cccc-2c13 ; N#Cc1nc2c(nc1C#N)-c1ccc(N3c4ccccc4N(c4ccccc4)c4ccccc43)c3cccc-2c13]

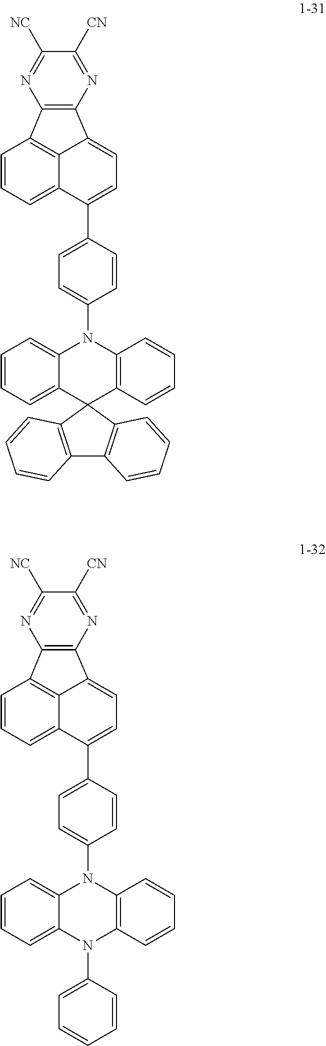 [SMILES: N#Cc1nc2c(nc1C#N)-c1ccc(-c3ccc(N4c5ccccc5C5(c6ccccc6-c6ccccc65)c5ccccc54)cc3)c3cccc-2c13 ; N#Cc1nc2c(nc1C#N)-c1ccc(-c3ccc(N4c5ccccc5N(c5ccccc5)c5ccccc54)cc3)c3cccc-2c13]

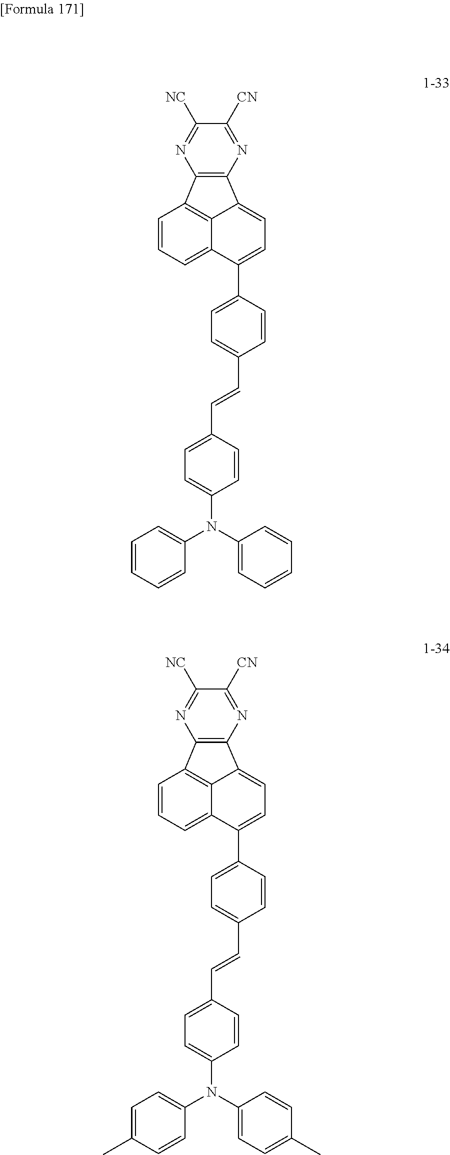

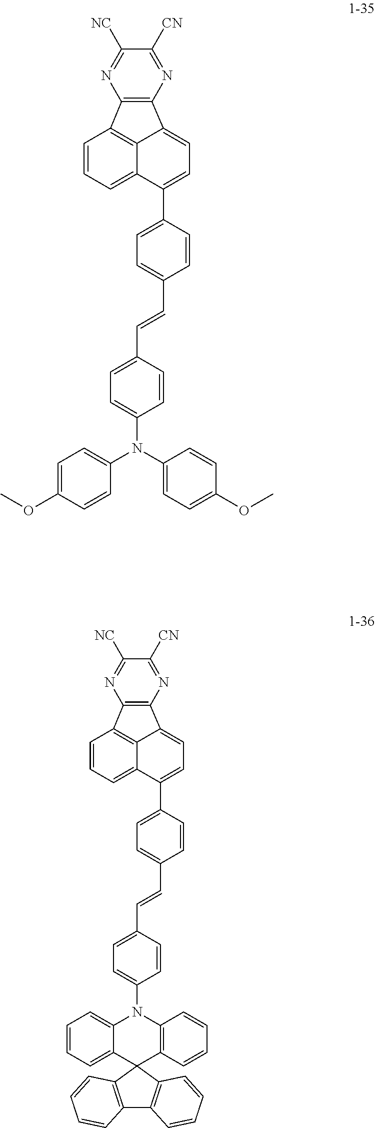

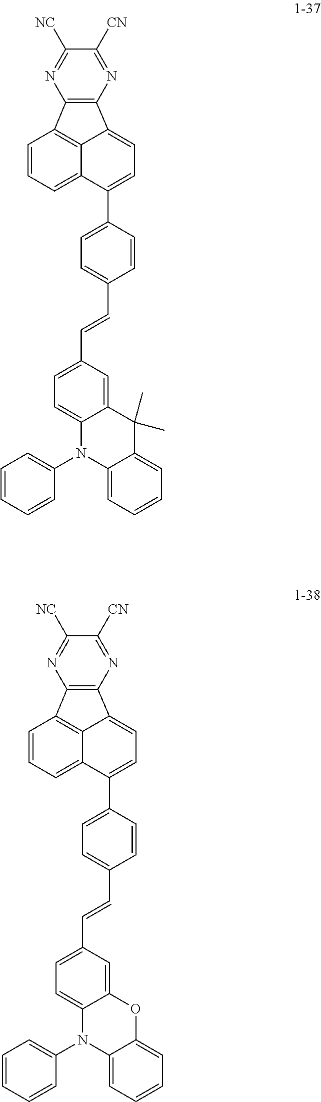 [SMILES: CC1(C)c2ccccc2N(c2ccccc2)c2ccc(/C=C/c3ccc(-c4ccc5c6c(cccc46)-c4nc(C#N)c(C#N)nc4-5)cc3)cc21 ; N#Cc1nc2c(nc1C#N)-c1ccc(-c3ccc(/C=C/c4ccc5c(c4)Oc4ccccc4N5c4ccccc4)cc3)c3cccc-2c13]

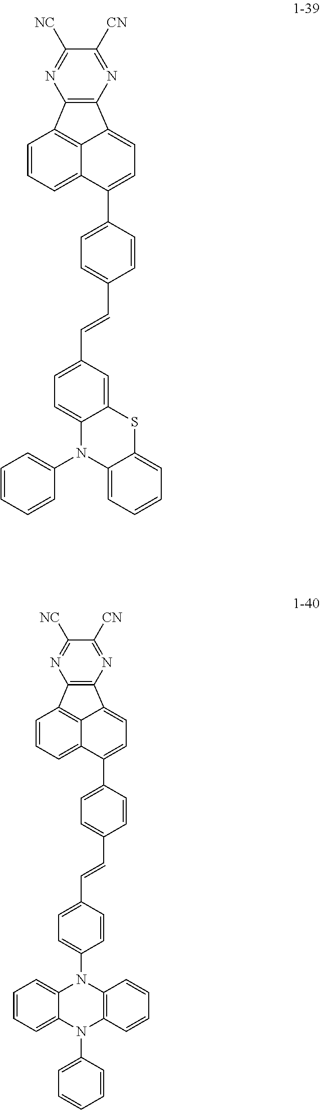 [SMILES: N#Cc1nc2c(nc1C#N)-c1ccc(-c3ccc(/C=C/c4ccc5c(c4)Sc4ccccc4N5c4ccccc4)cc3)c3cccc-2c13 ; N#Cc1nc2c(nc1C#N)-c1ccc(-c3ccc(/C=C/c4ccc(N5c6ccccc6N(c6ccccc6)c6ccccc65)cc4)cc3)c3cccc-2c13]

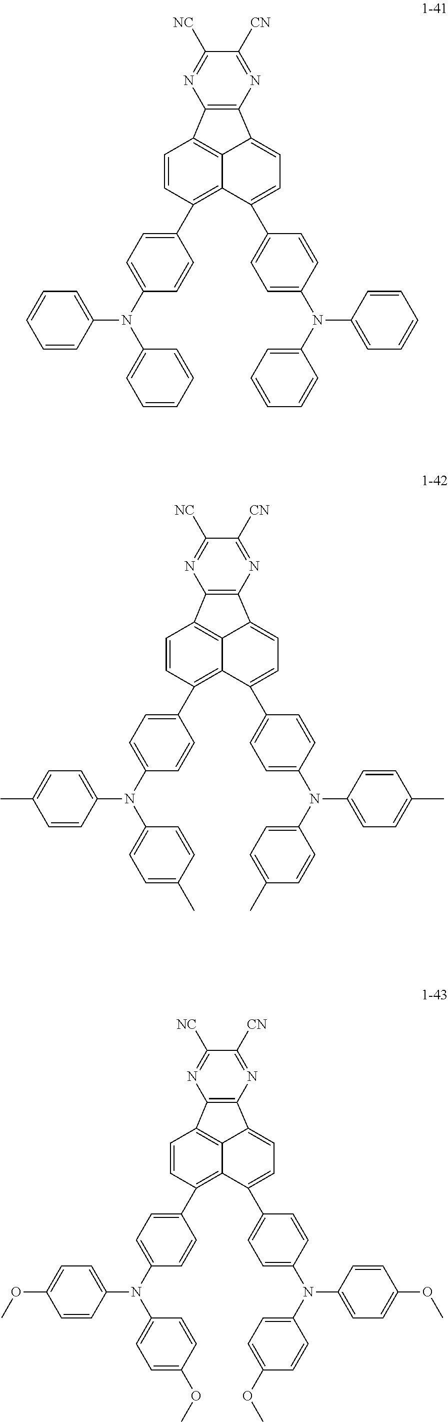

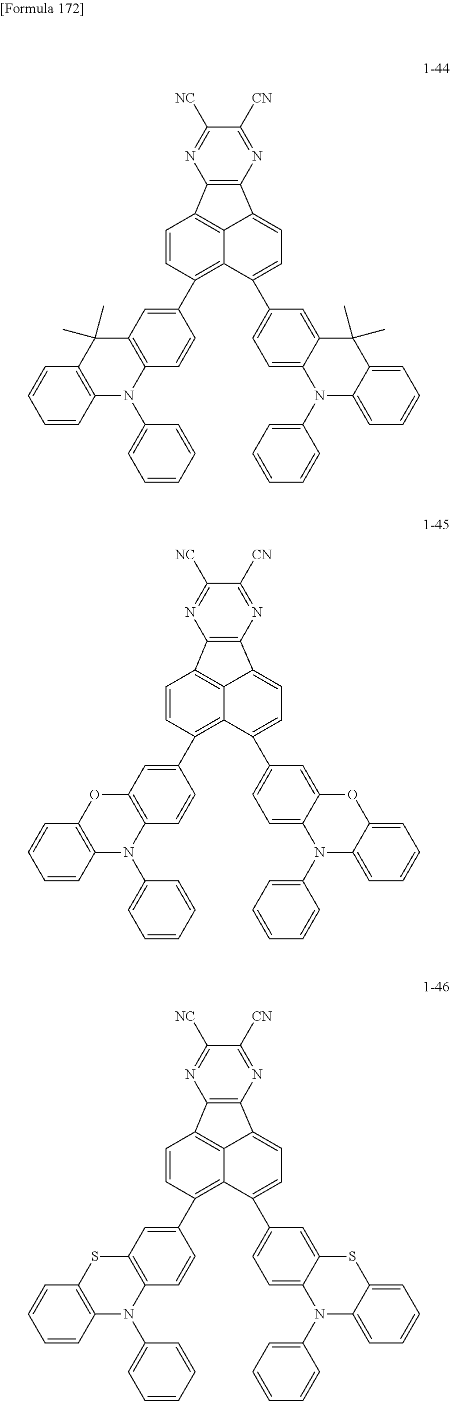 [SMILES: CC1(C)c2ccccc2N(c2ccccc2)c2ccc(-c3ccc4c5c(ccc(-c6ccc7c(c6)C(C)(C)c6ccccc6N7c6ccccc6)c35)-c3nc(C#N)c(C#N)nc3-4)cc21 ; N#Cc1nc2c(nc1C#N)-c1ccc(-c3ccc4c(c3)Oc3ccccc3N4c3ccccc3)c3c(-c4ccc5c(c4)Oc4ccccc4N5c4ccccc4)ccc-2c13 ; N#Cc1nc2c(nc1C#N)-c1ccc(-c3ccc4c(c3)Sc3ccccc3N4c3ccccc3)c3c(-c4ccc5c(c4)Sc4ccccc4N5c4ccccc4)ccc-2c13]

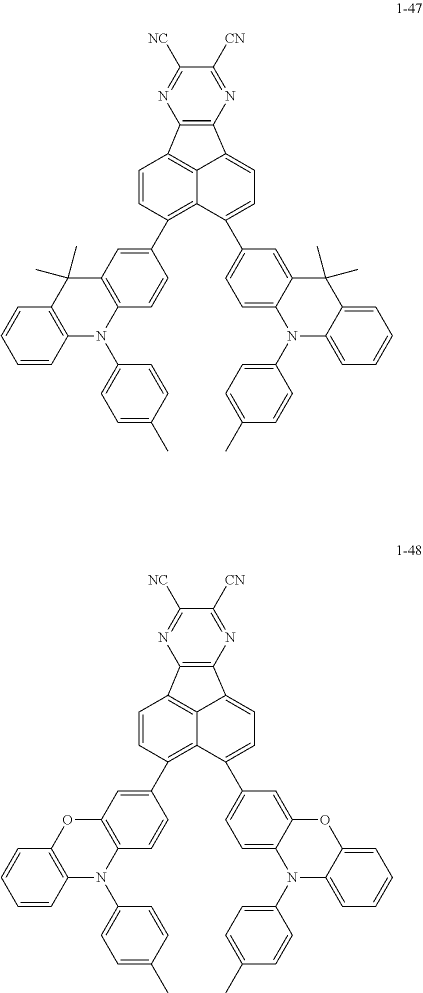 [SMILES: Cc1ccc(N2c3ccccc3C(C)(C)c3cc(-c4ccc5c6c(ccc(-c7ccc8c(c7)C(C)(C)c7ccccc7N8c7ccc(C)cc7)c46)-c4nc(C#N)c(C#N)nc4-5)ccc32)cc1 ; Cc1ccc(N2c3ccccc3Oc3cc(-c4ccc5c6c(ccc(-c7ccc8c(c7)Oc7ccccc7N8c7ccc(C)cc7)c46)-c4nc(C#N)c(C#N)nc4-5)ccc32)cc1]

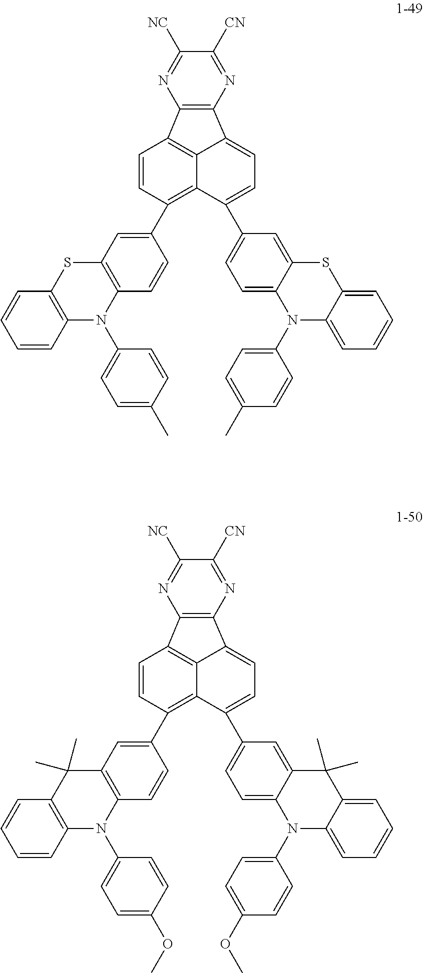 [SMILES: Cc1ccc(N2c3ccccc3Sc3cc(-c4ccc5c6c(ccc(-c7ccc8c(c7)Sc7ccccc7N8c7ccc(C)cc7)c46)-c4nc(C#N)c(C#N)nc4-5)ccc32)cc1 ; COc1ccc(N2c3ccccc3C(C)(C)c3cc(-c4ccc5c6c(ccc(-c7ccc8c(c7)C(C)(C)c7ccccc7N8c7ccc(OC)cc7)c46)-c4nc(C#N)c(C#N)nc4-5)ccc32)cc1]

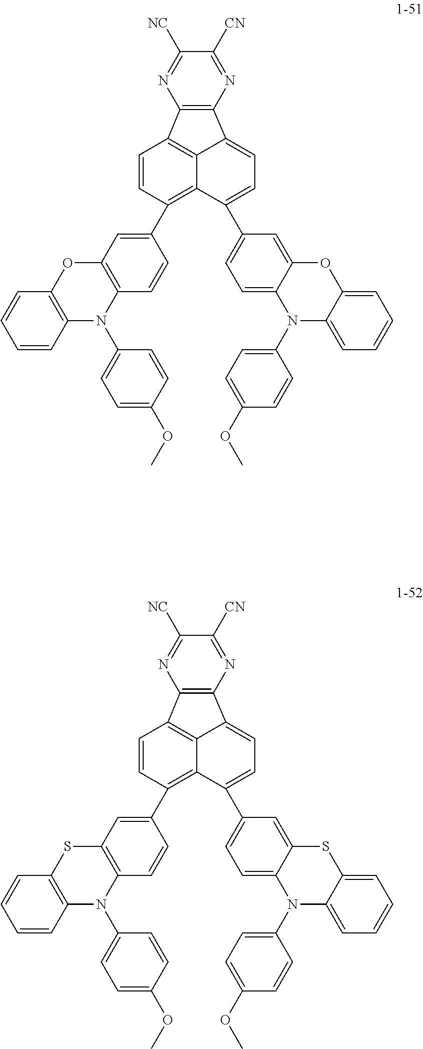 [SMILES: COc1ccc(N2c3ccccc3Oc3cc(-c4ccc5c6c(ccc(-c7ccc8c(c7)Oc7ccccc7N8c7ccc(OC)cc7)c46)-c4nc(C#N)c(C#N)nc4-5)ccc32)cc1 ; COc1ccc(N2c3ccccc3Sc3cc(-c4ccc5c6c(ccc(-c7ccc8c(c7)Sc7ccccc7N8c7ccc(OC)cc7)c46)-c4nc(C#N)c(C#N)nc4-5)ccc32)cc1]

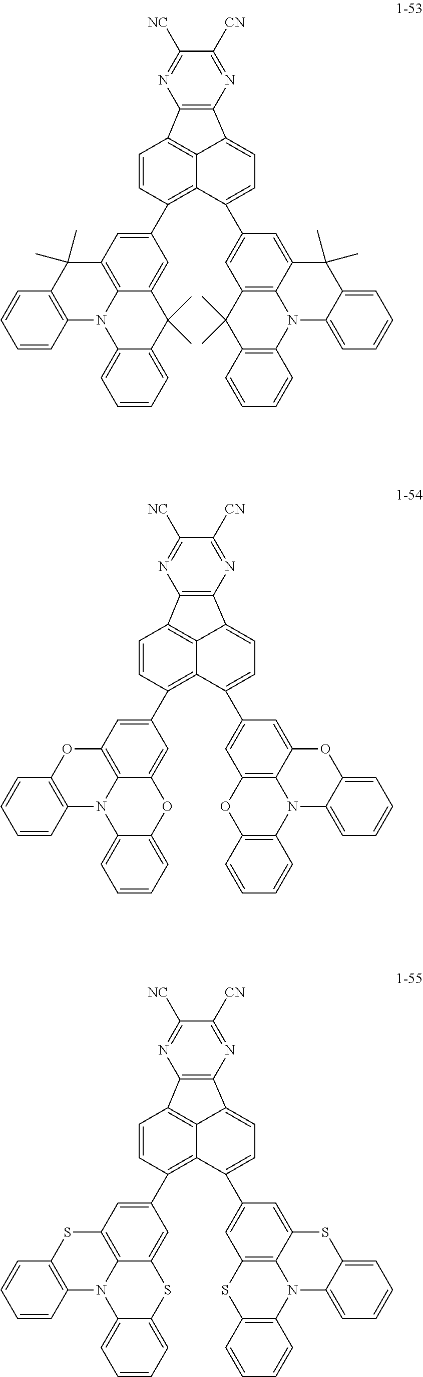 [SMILES: CC1(C)c2ccccc2N2c3ccccc3C(C)(C)c3cc(-c4ccc5c6c(ccc(-c7cc8c9c(c7)C(C)(C)c7ccccc7N9c7ccccc7C8(C)C)c46)-c4nc(C#N)c(C#N)nc4-5)cc1c32 ; N#Cc1nc2c(nc1C#N)-c1ccc(-c3cc4c5c(c3)Oc3ccccc3N5c3ccccc3O4)c3c(-c4cc5c6c(c4)Oc4ccccc4N6c4ccccc4O5)ccc-2c13 ; N#Cc1nc2c(nc1C#N)-c1ccc(-c3cc4c5c(c3)Sc3ccccc3N5c3ccccc3S4)c3c(-c4cc5c6c(c4)Sc4ccccc4N6c4ccccc4S5)ccc-2c13]

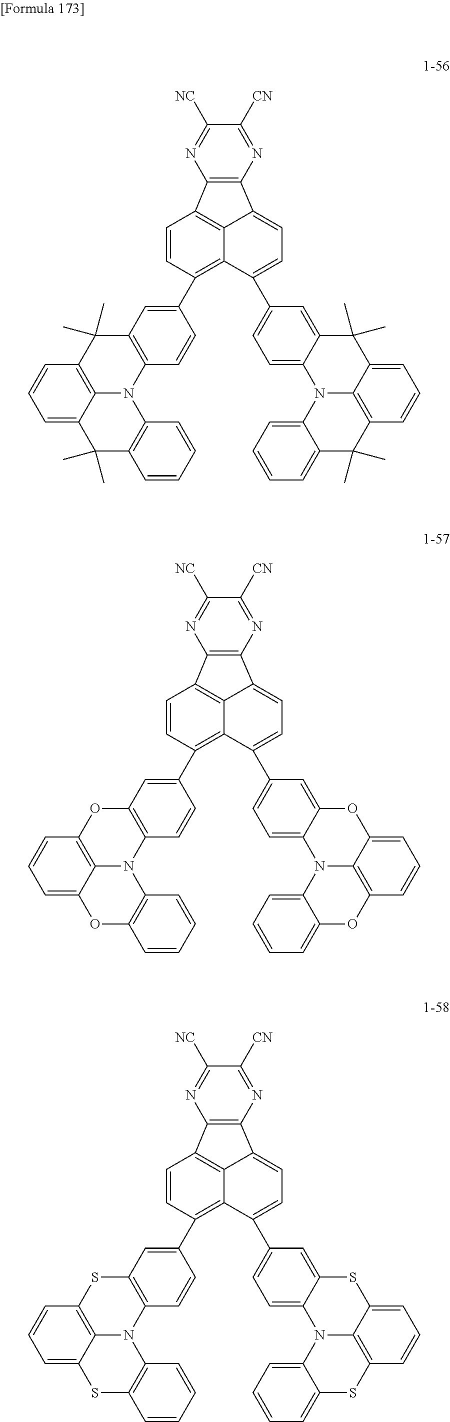 [SMILES: CC1(C)c2ccccc2N2c3ccc(-c4ccc5c6c(ccc(-c7ccc8c(c7)C(C)(C)c7cccc9c7N8c7ccccc7C9(C)C)c46)-c4nc(C#N)c(C#N)nc4-5)cc3C(C)(C)c3cccc1c32 ; N#Cc1nc2c(nc1C#N)-c1ccc(-c3ccc4c(c3)Oc3cccc5c3N4c3ccccc3O5)c3c(-c4ccc5c(c4)Oc4cccc6c4N5c4ccccc4O6)ccc-2c13 ; N#Cc1nc2c(nc1C#N)-c1ccc(-c3ccc4c(c3)Sc3cccc5c3N4c3ccccc3S5)c3c(-c4ccc5c(c4)Sc4cccc6c4N5c4ccccc4S6)ccc-2c13]

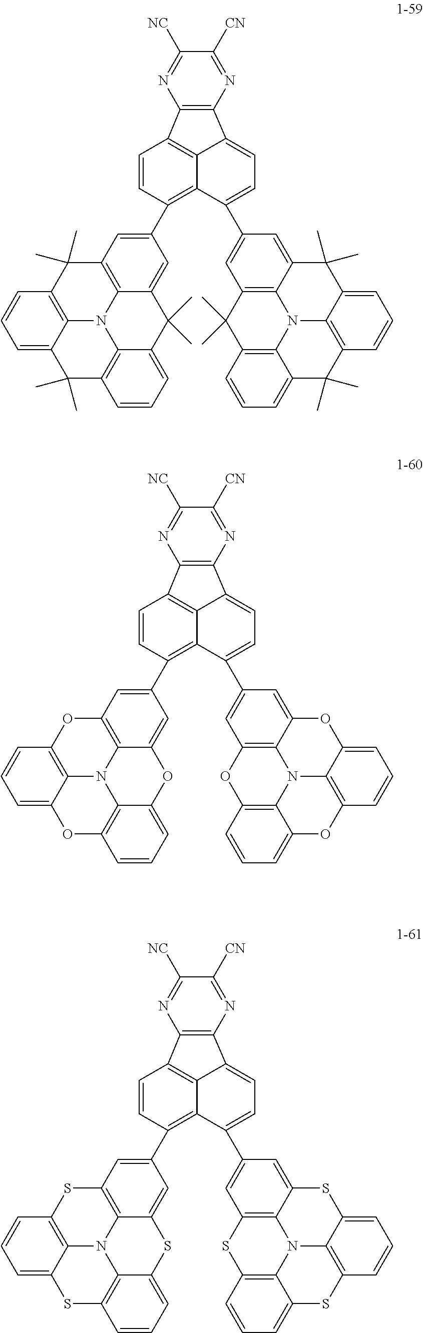 [SMILES: CC1(C)c2cccc3c2N2c4c1cccc4C(C)(C)c1cc(-c4ccc5c6c(ccc(-c7cc8c9c(c7)C(C)(C)c7cccc%10c7N9c7c(cccc7C8(C)C)C%10(C)C)c46)-c4nc(C#N)c(C#N)nc4-5)cc(c12)C3(C)C ; N#Cc1nc2c(nc1C#N)-c1ccc(-c3cc4c5c(c3)Oc3cccc6c3N5c3c(cccc3O4)O6)c3c(-c4cc5c6c(c4)Oc4cccc7c4N6c4c(cccc4O5)O7)ccc-2c13 ; N#Cc1nc2c(nc1C#N)-c1ccc(-c3cc4c5c(c3)Sc3cccc6c3N5c3c(cccc3S4)S6)c3c(-c4cc5c6c(c4)Sc4cccc7c4N6c4c(cccc4S5)S7)ccc-2c13]

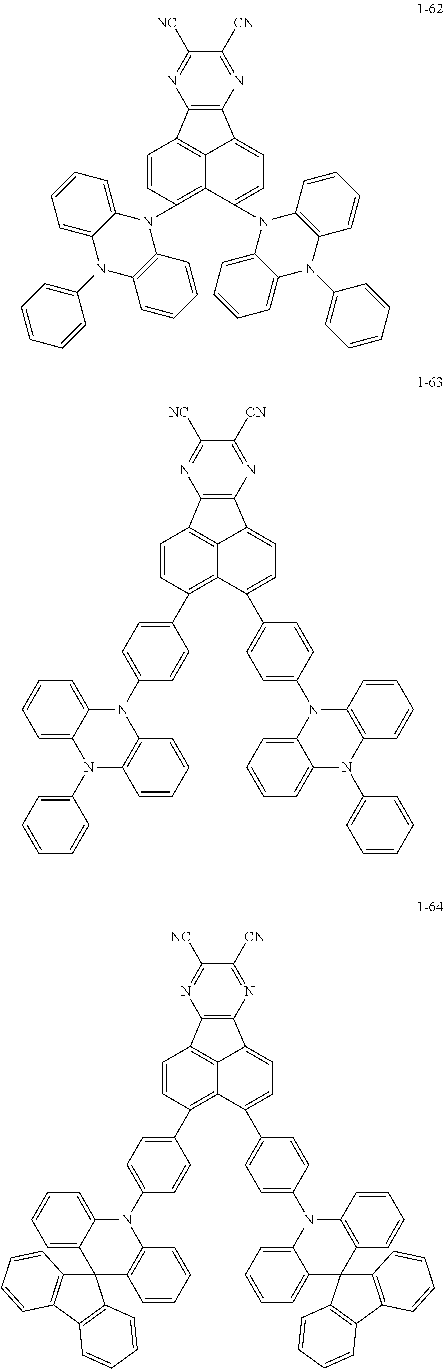 [SMILES: N#Cc1nc2c(nc1C#N)-c1ccc(N3c4ccccc4N(c4ccccc4)c4ccccc43)c3c(N4c5ccccc5N(c5ccccc5)c5ccccc54)ccc-2c13 ; N#Cc1nc2c(nc1C#N)-c1ccc(-c3ccc(N4c5ccccc5N(c5ccccc5)c5ccccc54)cc3)c3c(-c4ccc(N5c6ccccc6N(c6ccccc6)c6ccccc65)cc4)ccc-2c13 ; N#Cc1nc2c(nc1C#N)-c1ccc(-c3ccc(N4c5ccccc5C5(c6ccccc6-c6ccccc65)c5ccccc54)cc3)c3c(-c4ccc(N5c6ccccc6C6(c7ccccc7-c7ccccc76)c6ccccc65)cc4)ccc-2c13]

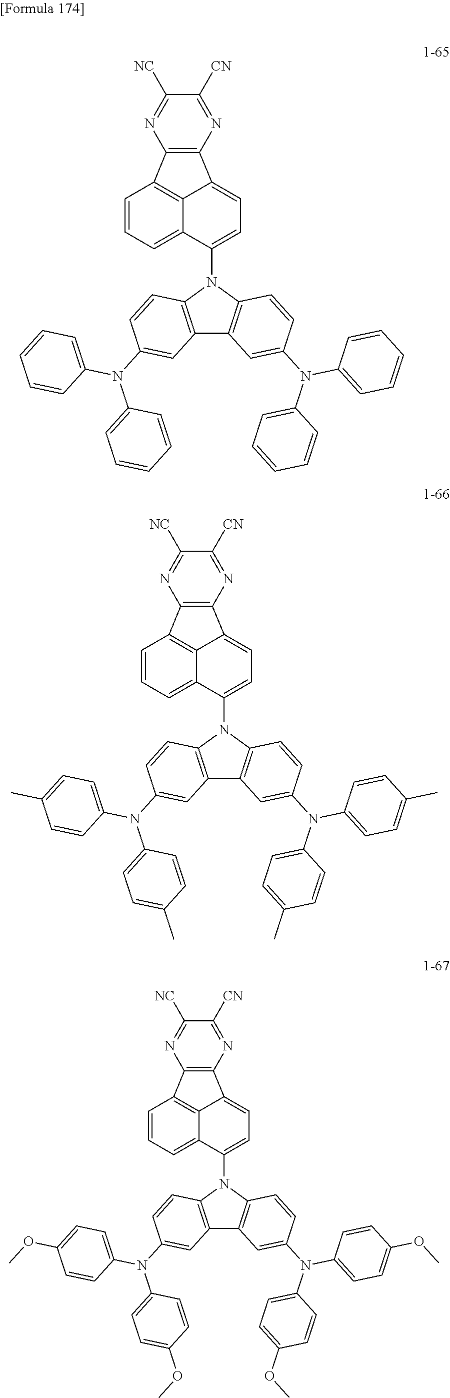

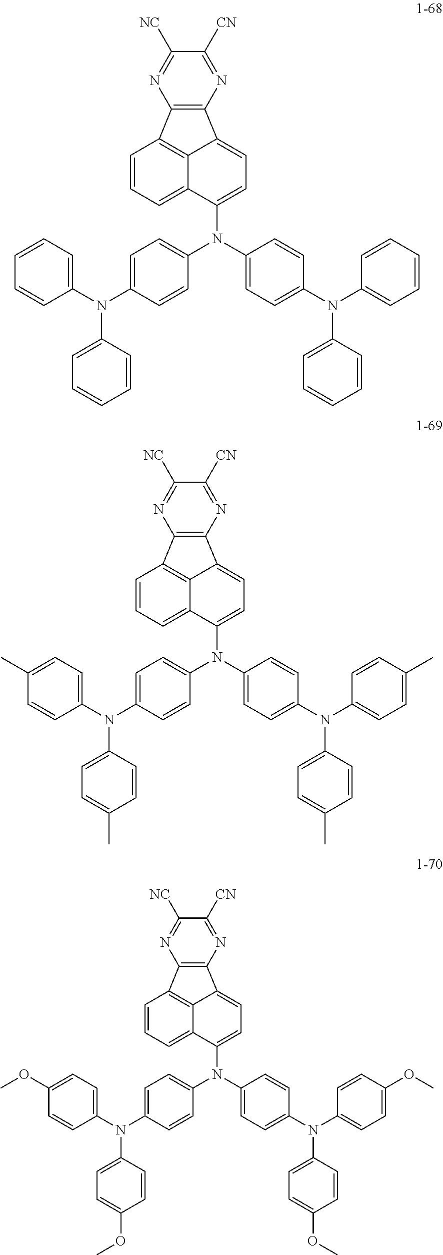

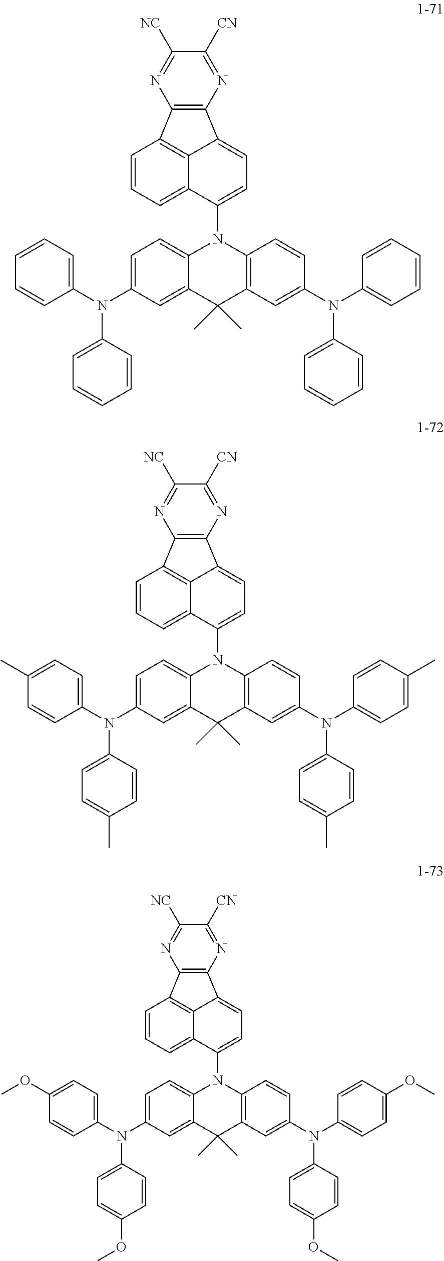

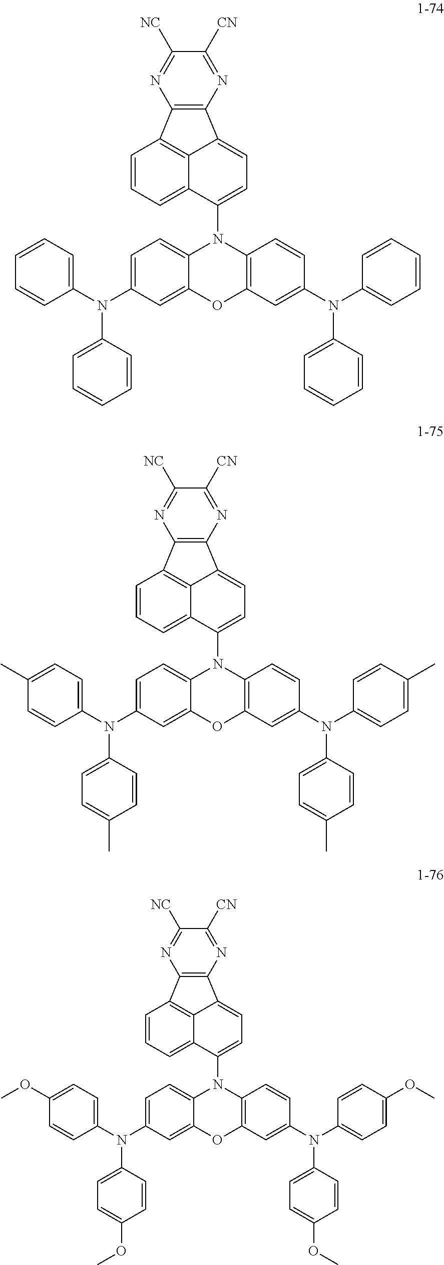

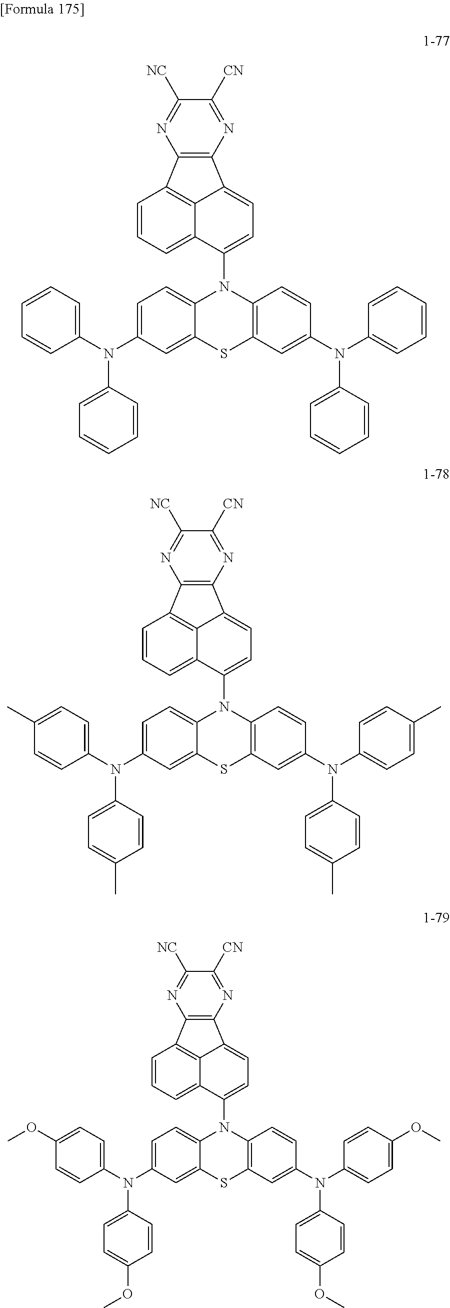

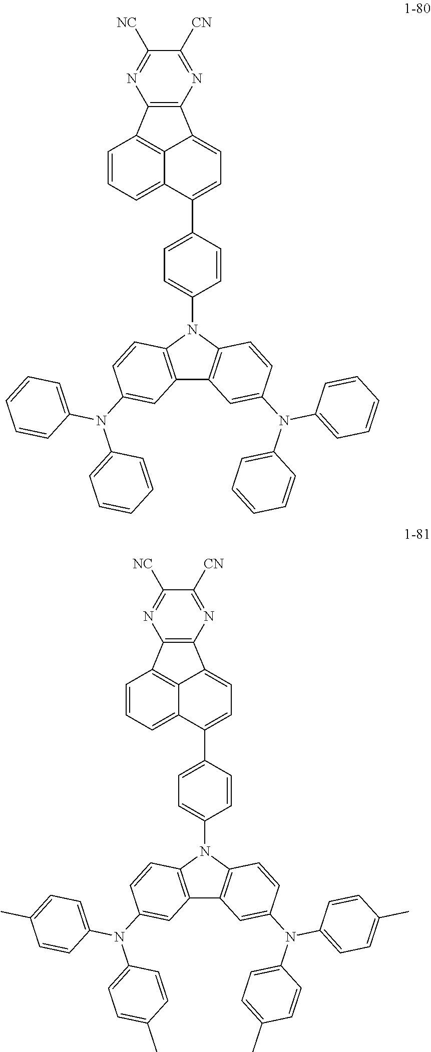

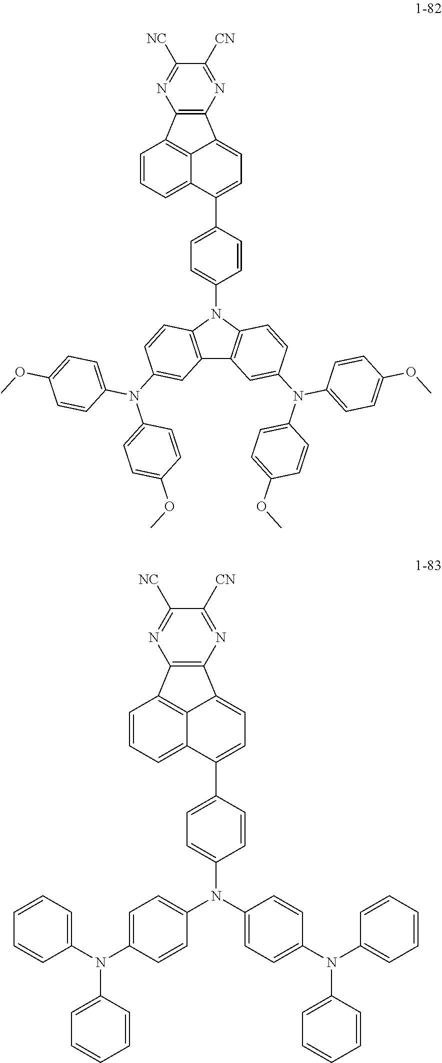

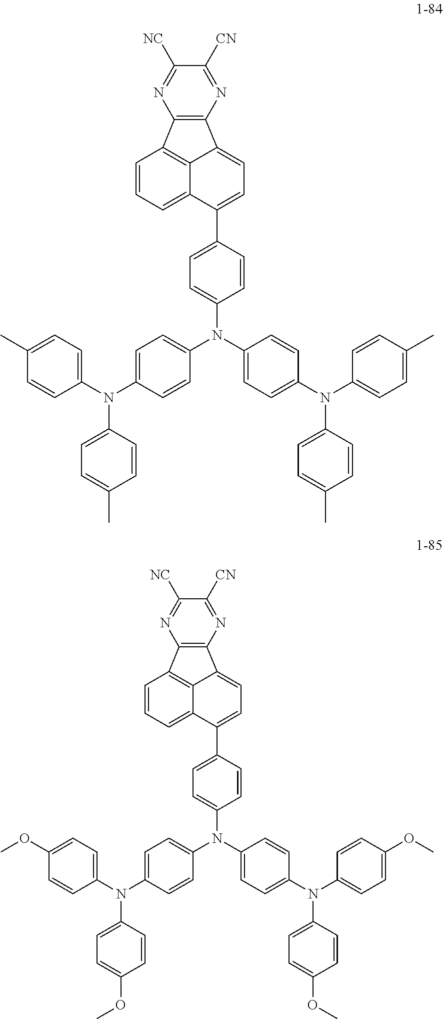

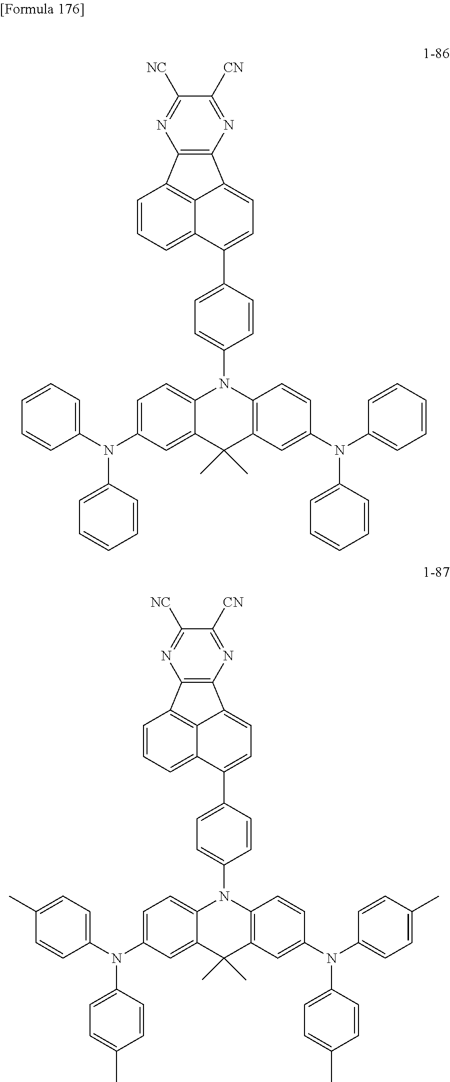

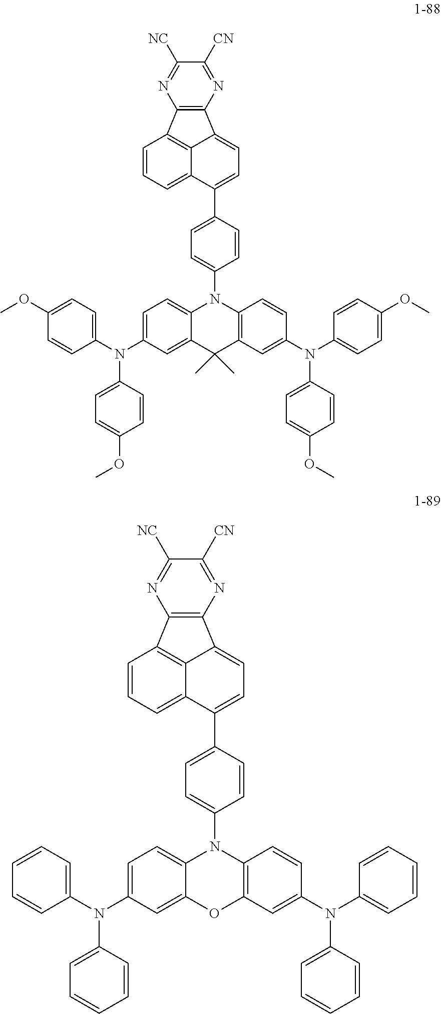

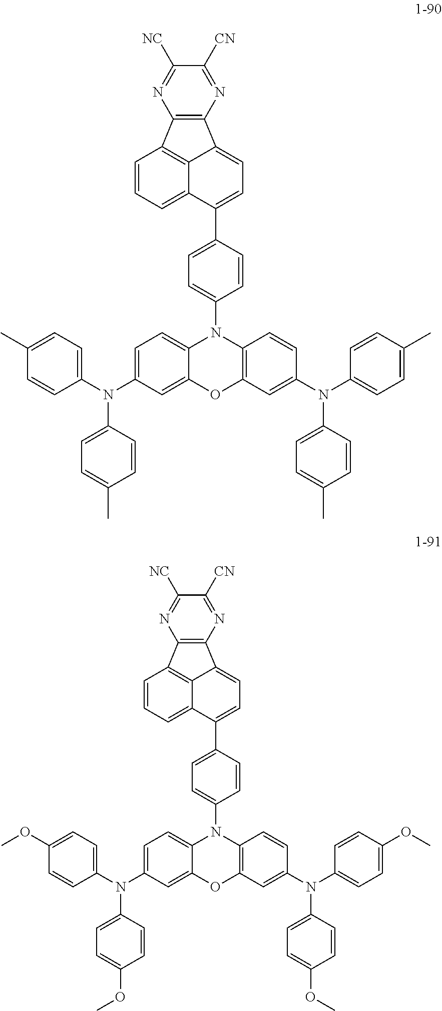

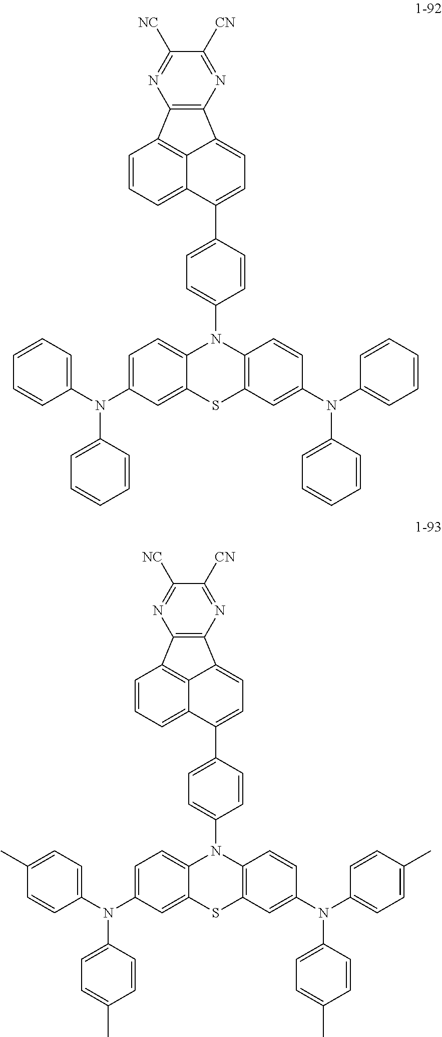

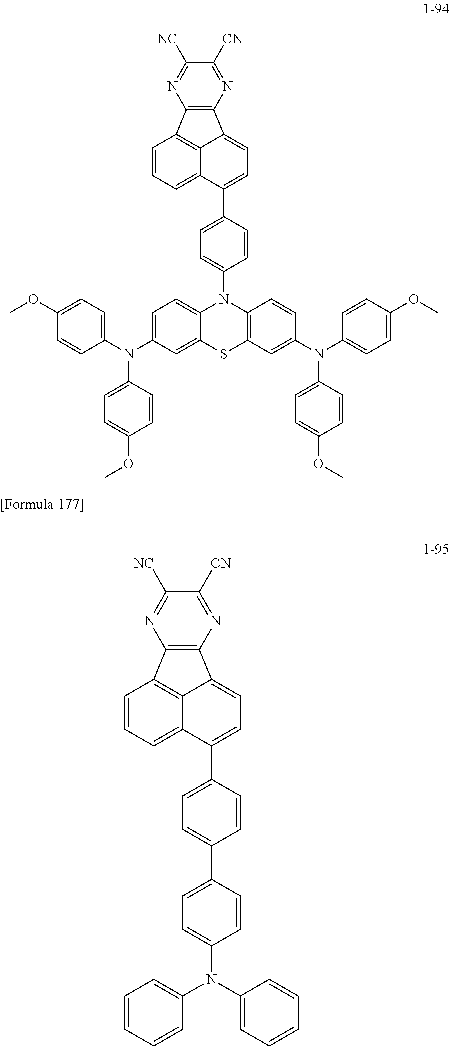

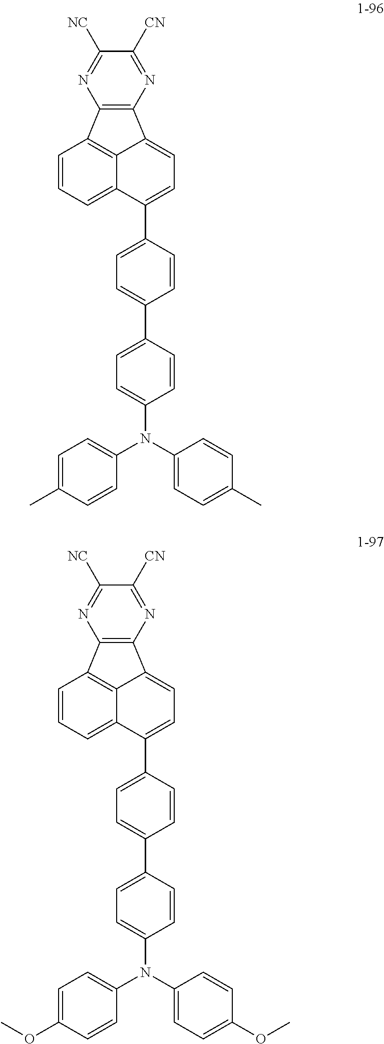

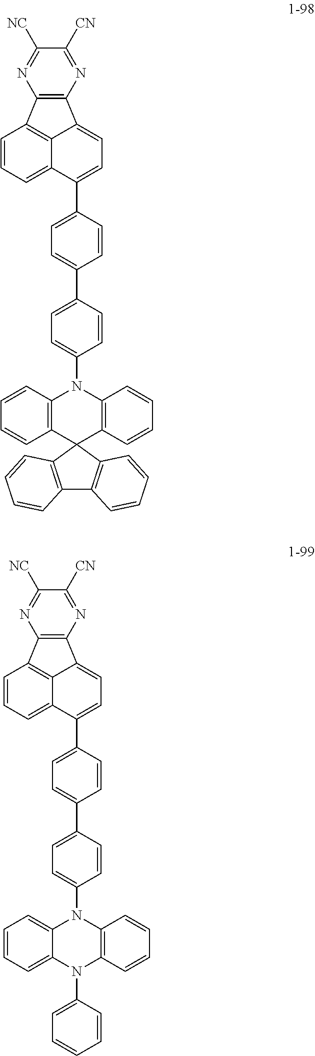 [SMILES: N#Cc1nc2c(nc1C#N)-c1ccc(-c3ccc(-c4ccc(N5c6ccccc6C6(c7ccccc7-c7ccccc76)c6ccccc65)cc4)cc3)c3cccc-2c13 ; N#Cc1nc2c(nc1C#N)-c1ccc(-c3ccc(-c4ccc(N5c6ccccc6N(c6ccccc6)c6ccccc65)cc4)cc3)c3cccc-2c13]

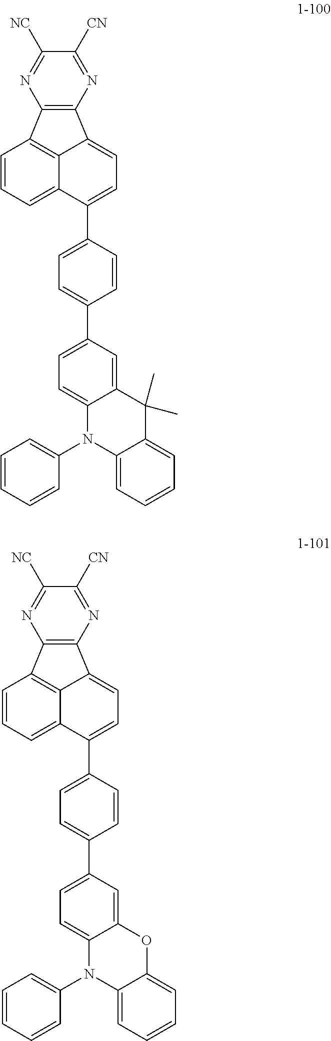 [SMILES: CC1(C)c2ccccc2N(c2ccccc2)c2ccc(-c3ccc(-c4ccc5c6c(cccc46)-c4nc(C#N)c(C#N)nc4-5)cc3)cc21 ; N#Cc1nc2c(nc1C#N)-c1ccc(-c3ccc(-c4ccc5c(c4)Oc4ccccc4N5c4ccccc4)cc3)c3cccc-2c13]

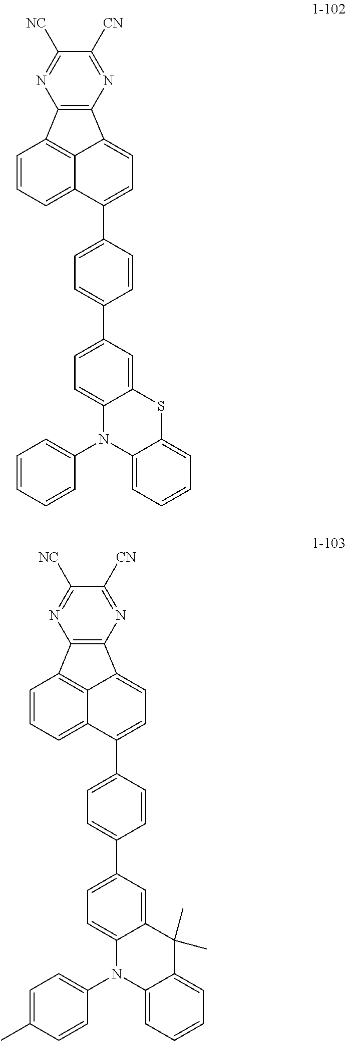

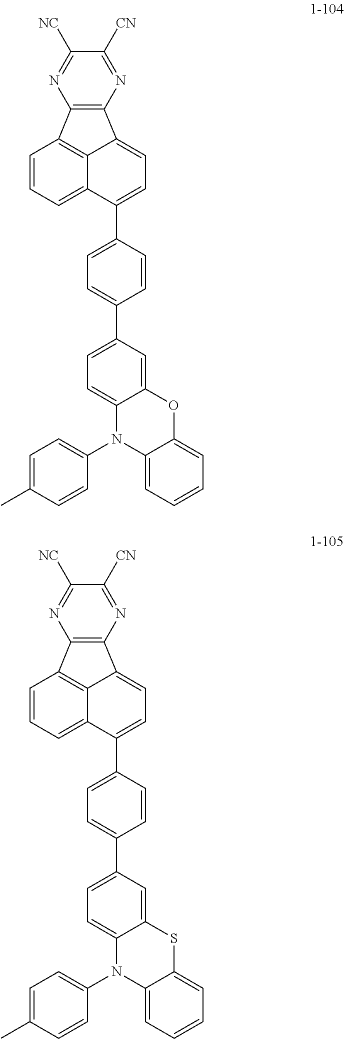 [SMILES: Cc1ccc(N2c3ccccc3Oc3cc(-c4ccc(-c5ccc6c7c(cccc57)-c5nc(C#N)c(C#N)nc5-6)cc4)ccc32)cc1 ; Cc1ccc(N2c3ccccc3Sc3cc(-c4ccc(-c5ccc6c7c(cccc57)-c5nc(C#N)c(C#N)nc5-6)cc4)ccc32)cc1]

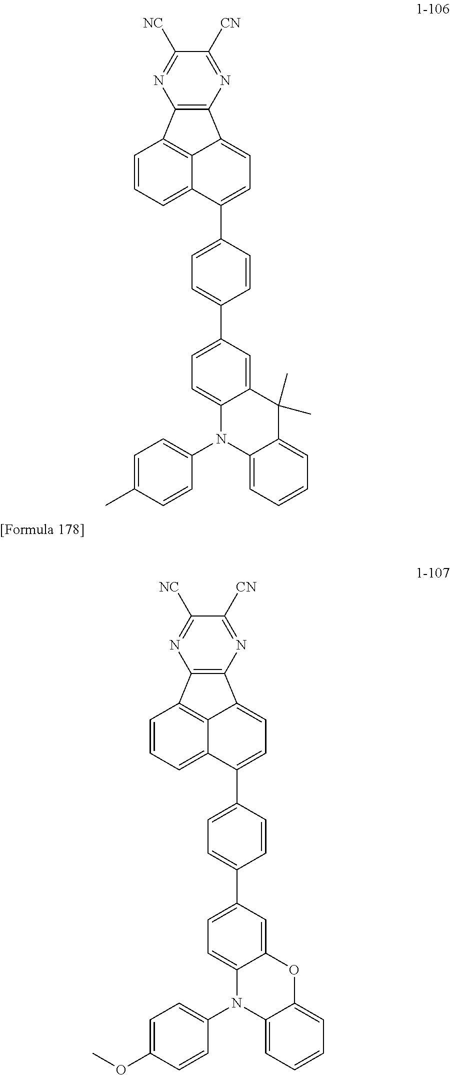

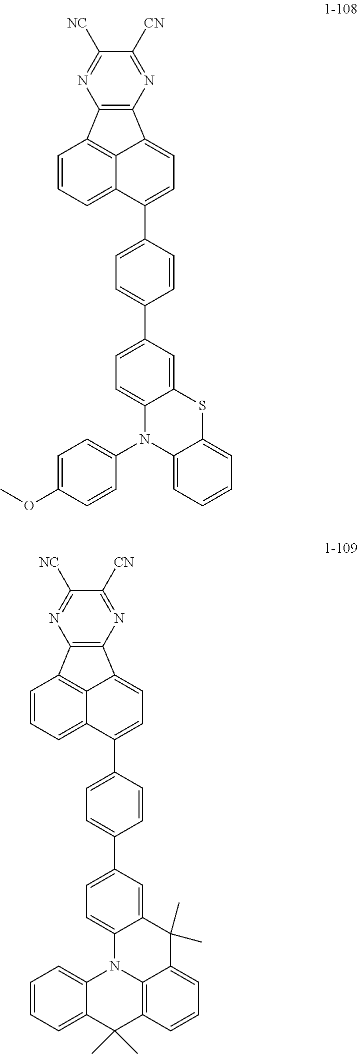 [SMILES: COc1ccc(N2c3ccccc3Sc3cc(-c4ccc(-c5ccc6c7c(cccc57)-c5nc(C#N)c(C#N)nc5-6)cc4)ccc32)cc1 ; CC1(C)c2ccccc2N2c3ccc(-c4ccc(-c5ccc6c7c(cccc57)-c5nc(C#N)c(C#N)nc5-6)cc4)cc3C(C)(C)c3cccc1c32]

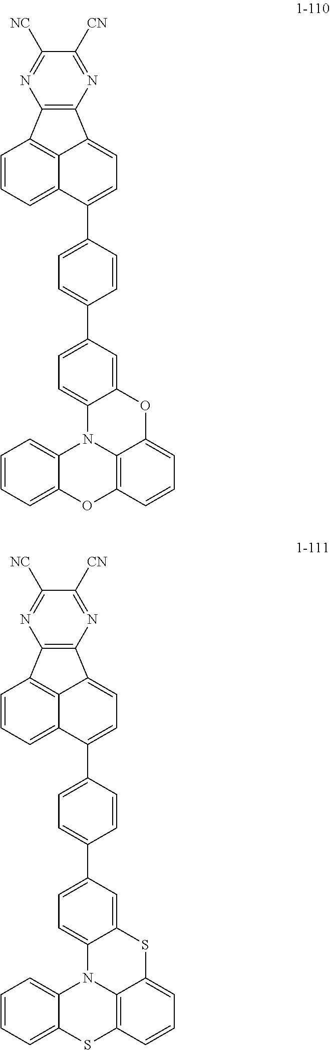 [SMILES: N#Cc1nc2c(nc1C#N)-c1ccc(-c3ccc(-c4ccc5c(c4)Oc4cccc6c4N5c4ccccc4O6)cc3)c3cccc-2c13 ; N#Cc1nc2c(nc1C#N)-c1ccc(-c3ccc(-c4ccc5c(c4)Sc4cccc6c4N5c4ccccc4S6)cc3)c3cccc-2c13]

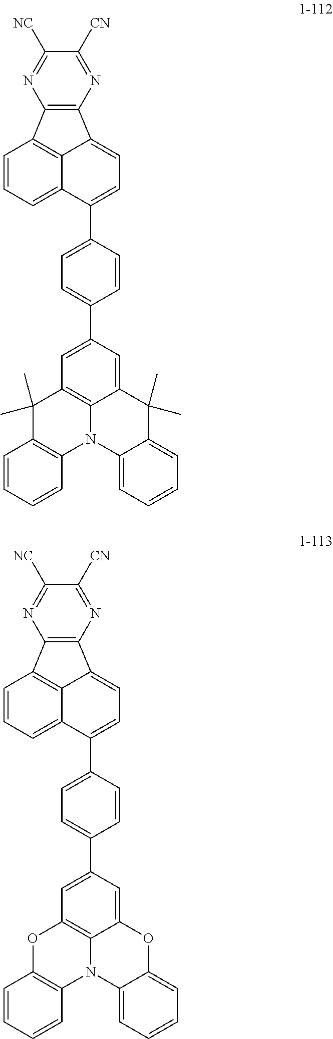

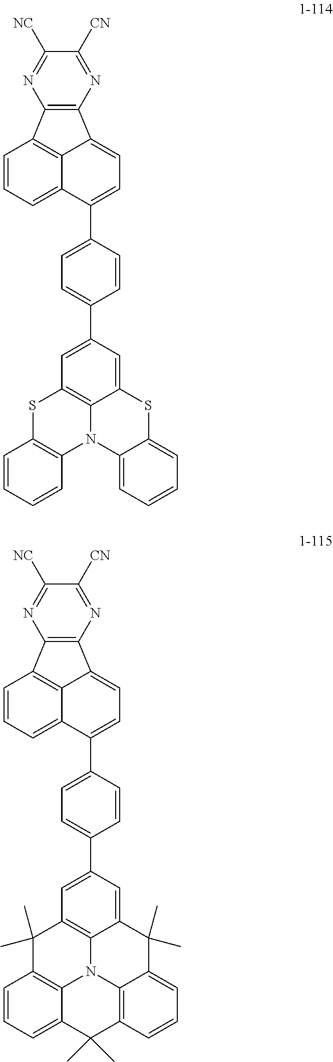

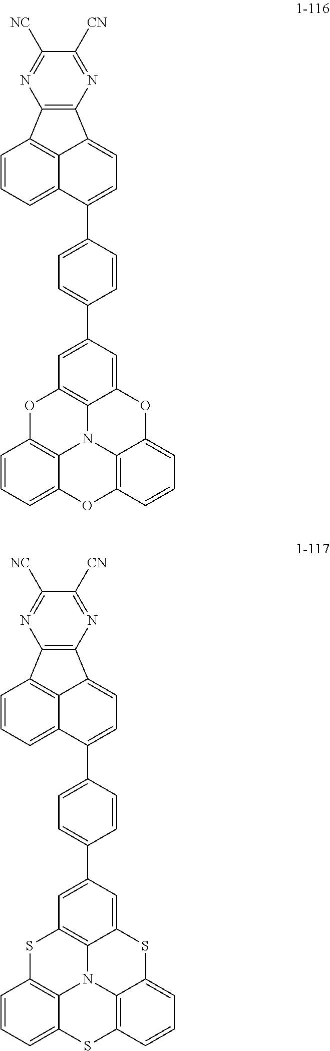 [SMILES: N#Cc1nc2c(nc1C#N)-c1ccc(-c3ccc(-c4cc5c6c(c4)Oc4cccc7c4N6c4c(cccc4O5)O7)cc3)c3cccc-2c13 ; N#Cc1nc2c(nc1C#N)-c1ccc(-c3ccc(-c4cc5c6c(c4)Sc4cccc7c4N6c4c(cccc4S5)S7)cc3)c3cccc-2c13]

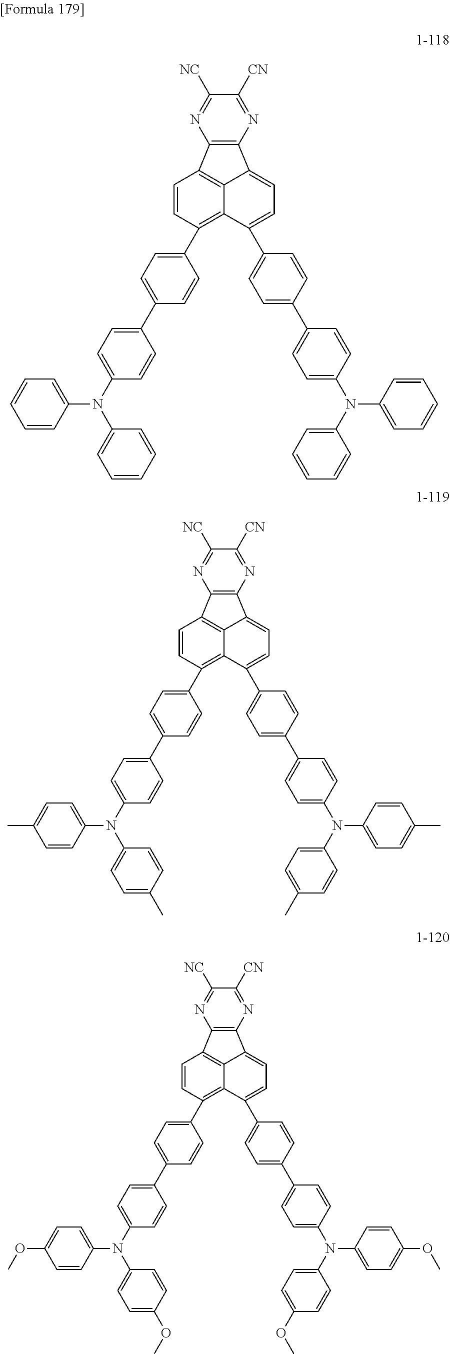

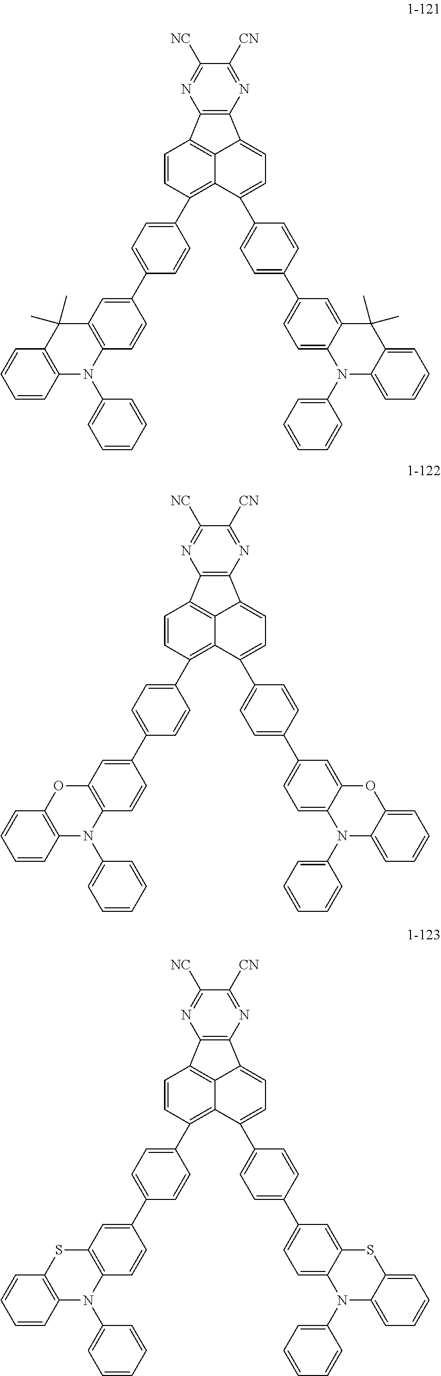 [SMILES: CC1(C)c2ccccc2N(c2ccccc2)c2ccc(-c3ccc(-c4ccc5c6c(ccc(-c7ccc(-c8ccc9c(c8)C(C)(C)c8ccccc8N9c8ccccc8)cc7)c46)-c4nc(C#N)c(C#N)nc4-5)cc3)cc21 ; N#Cc1nc2c(nc1C#N)-c1ccc(-c3ccc(-c4ccc5c(c4)Oc4ccccc4N5c4ccccc4)cc3)c3c(-c4ccc(-c5ccc6c(c5)Oc5ccccc5N6c5ccccc5)cc4)ccc-2c13 ; N#Cc1nc2c(nc1C#N)-c1ccc(-c3ccc(-c4ccc5c(c4)Sc4ccccc4N5c4ccccc4)cc3)c3c(-c4ccc(-c5ccc6c(c5)Sc5ccccc5N6c5ccccc5)cc4)ccc-2c13]

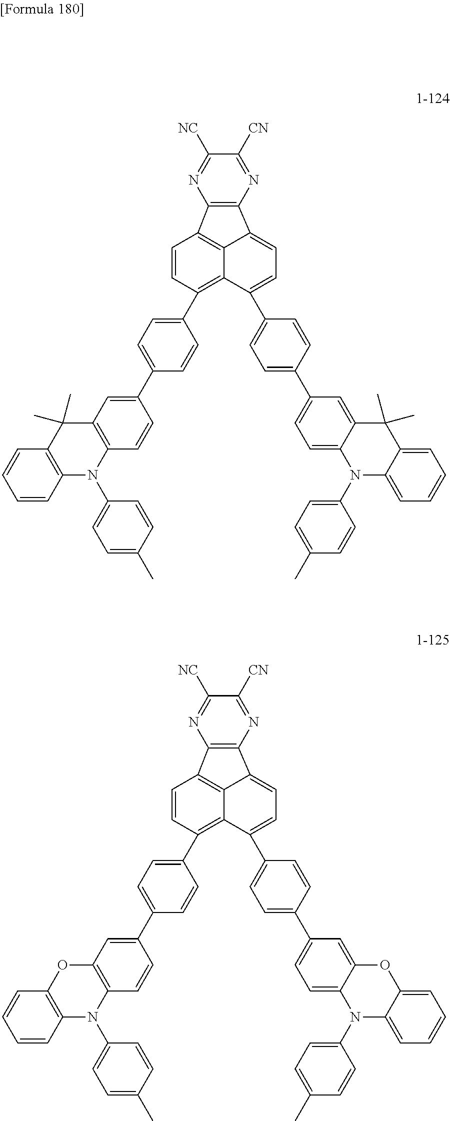 [SMILES: Cc1ccc(N2c3ccccc3C(C)(C)c3cc(-c4ccc(-c5ccc6c7c(ccc(-c8ccc(-c9ccc%10c(c9)C(C)(C)c9ccccc9N%10c9ccc(C)cc9)cc8)c57)-c5nc(C#N)c(C#N)nc5-6)cc4)ccc32)cc1 ; Cc1ccc(N2c3ccccc3Oc3cc(-c4ccc(-c5ccc6c7c(ccc(-c8ccc(-c9ccc%10c(c9)Oc9ccccc9N%10c9ccc(C)cc9)cc8)c57)-c5nc(C#N)c(C#N)nc5-6)cc4)ccc32)cc1]

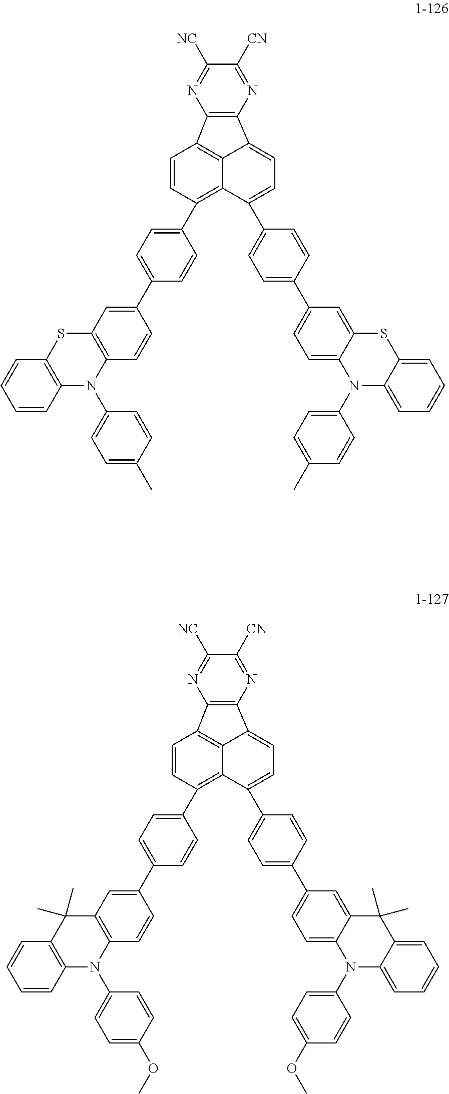 [SMILES: Cc1ccc(N2c3ccccc3Sc3cc(-c4ccc(-c5ccc6c7c(ccc(-c8ccc(-c9ccc%10c(c9)Sc9ccccc9N%10c9ccc(C)cc9)cc8)c57)-c5nc(C#N)c(C#N)nc5-6)cc4)ccc32)cc1 ; COc1ccc(N2c3ccccc3C(C)(C)c3cc(-c4ccc(-c5ccc6c7c(ccc(-c8ccc(-c9ccc%10c(c9)C(C)(C)c9ccccc9N%10c9ccc(OC)cc9)cc8)c57)-c5nc(C#N)c(C#N)nc5-6)cc4)ccc32)cc1]

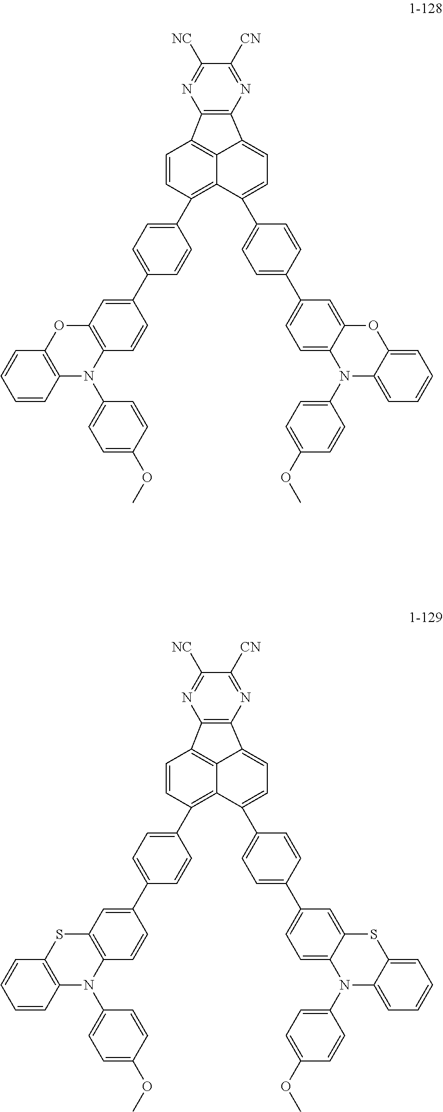 [SMILES: COc1ccc(N2c3ccccc3Oc3cc(-c4ccc(-c5ccc6c7c(ccc(-c8ccc(-c9ccc%10c(c9)Oc9ccccc9N%10c9ccc(OC)cc9)cc8)c57)-c5nc(C#N)c(C#N)nc5-6)cc4)ccc32)cc1 ; COc1ccc(N2c3ccccc3Sc3cc(-c4ccc(-c5ccc6c7c(ccc(-c8ccc(-c9ccc%10c(c9)Sc9ccccc9N%10c9ccc(OC)cc9)cc8)c57)-c5nc(C#N)c(C#N)nc5-6)cc4)ccc32)cc1]

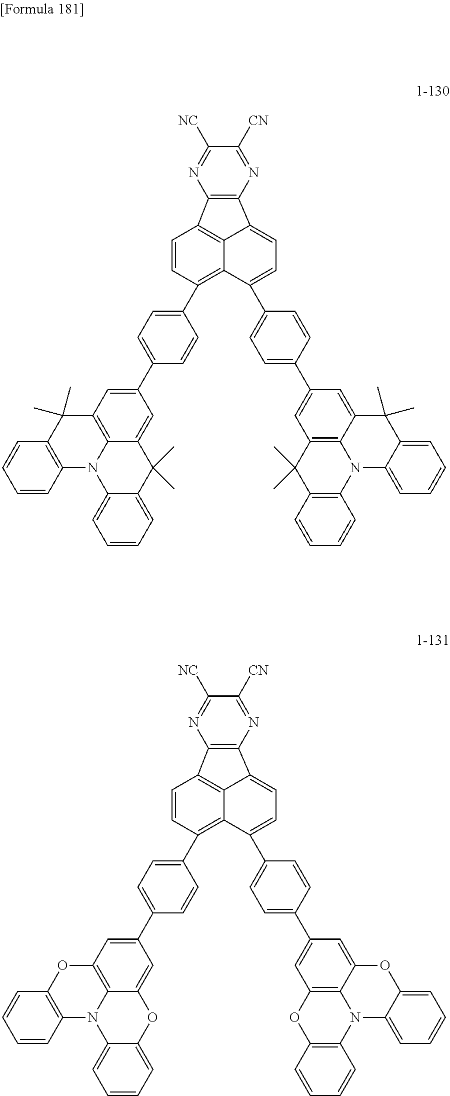 [SMILES: CC1(C)c2ccccc2N2c3ccccc3C(C)(C)c3cc(-c4ccc(-c5ccc6c7c(ccc(-c8ccc(-c9cc%10c%11c(c9)C(C)(C)c9ccccc9N%11c9ccccc9C%10(C)C)cc8)c57)-c5nc(C#N)c(C#N)nc5-6)cc4)cc1c32 ; N#Cc1nc2c(nc1C#N)-c1ccc(-c3ccc(-c4cc5c6c(c4)Oc4ccccc4N6c4ccccc4O5)cc3)c3c(-c4ccc(-c5cc6c7c(c5)Oc5ccccc5N7c5ccccc5O6)cc4)ccc-2c13]

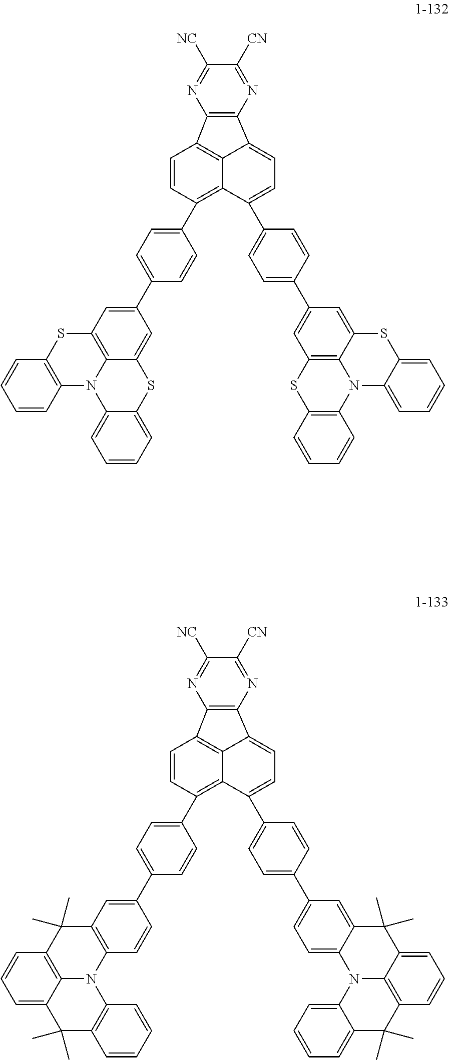 [SMILES: N#Cc1nc2c(nc1C#N)-c1ccc(-c3ccc(-c4cc5c6c(c4)Sc4ccccc4N6c4ccccc4S5)cc3)c3c(-c4ccc(-c5cc6c7c(c5)Sc5ccccc5N7c5ccccc5S6)cc4)ccc-2c13 ; CC1(C)c2ccccc2N2c3ccc(-c4ccc(-c5ccc6c7c(ccc(-c8ccc(-c9ccc%10c(c9)C(C)(C)c9cccc%11c9N%10c9ccccc9C%11(C)C)cc8)c57)-c5nc(C#N)c(C#N)nc5-6)cc4)cc3C(C)(C)c3cccc1c32]

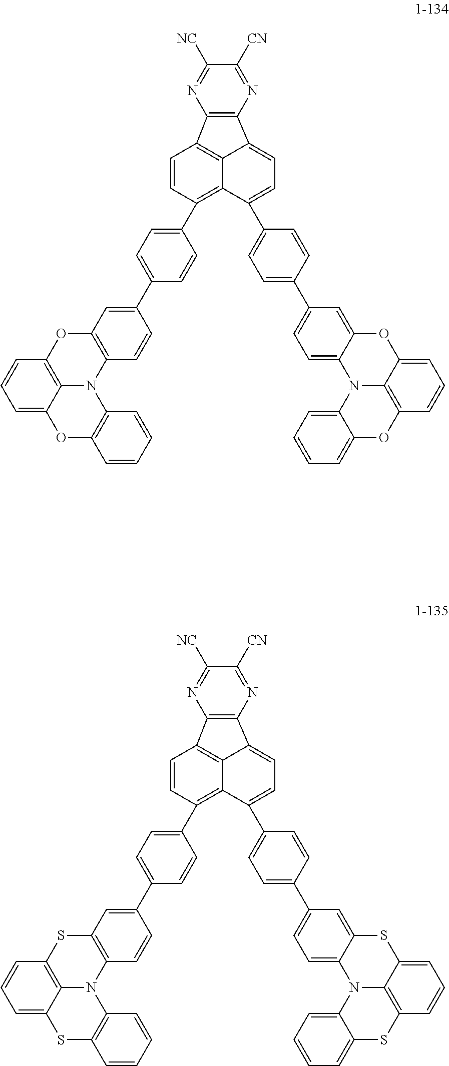 [SMILES: N#Cc1nc2c(nc1C#N)-c1ccc(-c3ccc(-c4ccc5c(c4)Oc4cccc6c4N5c4ccccc4O6)cc3)c3c(-c4ccc(-c5ccc6c(c5)Oc5cccc7c5N6c5ccccc5O7)cc4)ccc-2c13 ; N#Cc1nc2c(nc1C#N)-c1ccc(-c3ccc(-c4ccc5c(c4)Sc4cccc6c4N5c4ccccc4S6)cc3)c3c(-c4ccc(-c5ccc6c(c5)Sc5cccc7c5N6c5ccccc5S7)cc4)ccc-2c13]

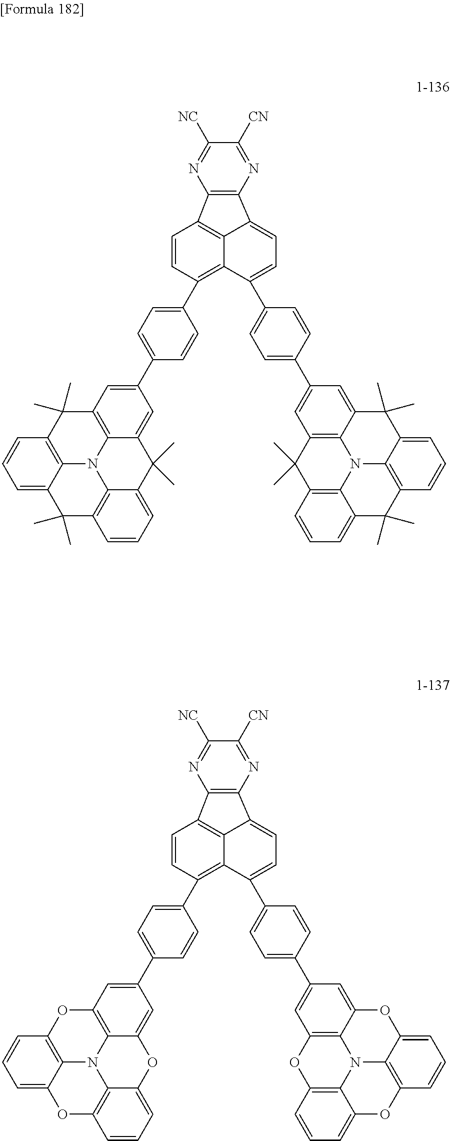 [SMILES: CC1(C)c2cccc3c2N2c4c1cccc4C(C)(C)c1cc(-c4ccc(-c5ccc6c7c(ccc(-c8ccc(-c9cc%10c%11c(c9)C(C)(C)c9cccc%12c9N%11c9c(cccc9C%10(C)C)C%12(C)C)cc8)c57)-c5nc(C#N)c(C#N)nc5-6)cc4)cc(c12)C3(C)C ; N#Cc1nc2c(nc1C#N)-c1ccc(-c3ccc(-c4cc5c6c(c4)Oc4cccc7c4N6c4c(cccc4O5)O7)cc3)c3c(-c4ccc(-c5cc6c7c(c5)Oc5cccc8c5N7c5c(cccc5O6)O8)cc4)ccc-2c13]

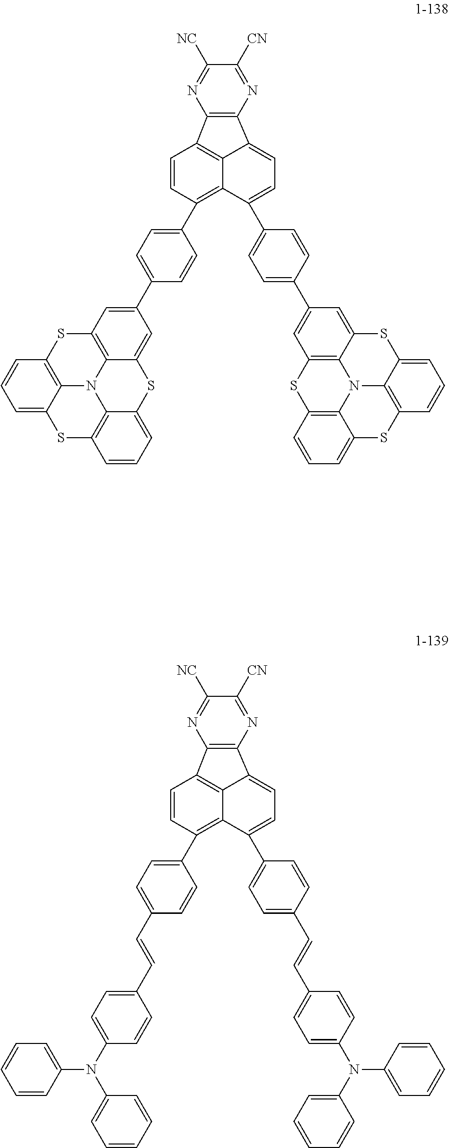 [SMILES: N#Cc1nc2c(nc1C#N)-c1ccc(-c3ccc(-c4cc5c6c(c4)Sc4cccc7c4N6c4c(cccc4S5)S7)cc3)c3c(-c4ccc(-c5cc6c7c(c5)Sc5cccc8c5N7c5c(cccc5S6)S8)cc4)ccc-2c13 ; N#Cc1nc2c(nc1C#N)-c1ccc(-c3ccc(/C=C/c4ccc(N(c5ccccc5)c5ccccc5)cc4)cc3)c3c(-c4ccc(/C=C/c5ccc(N(c6ccccc6)c6ccccc6)cc5)cc4)ccc-2c13]

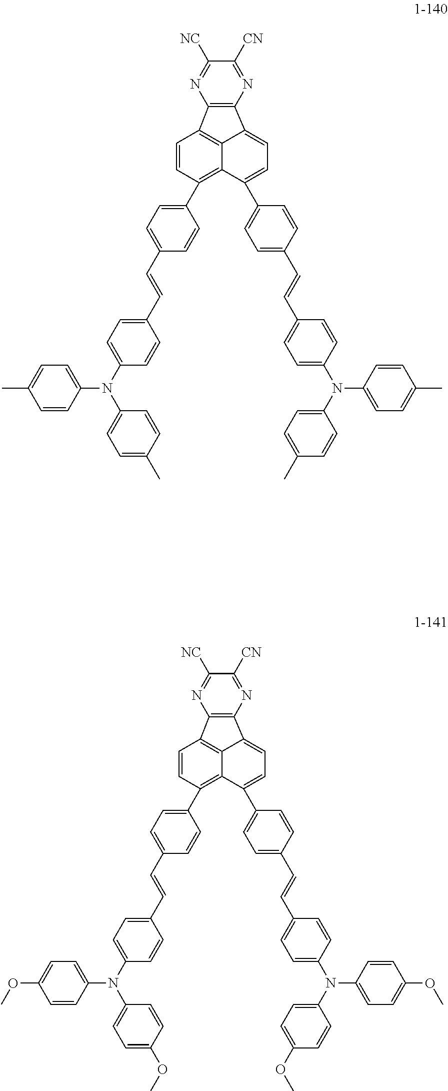

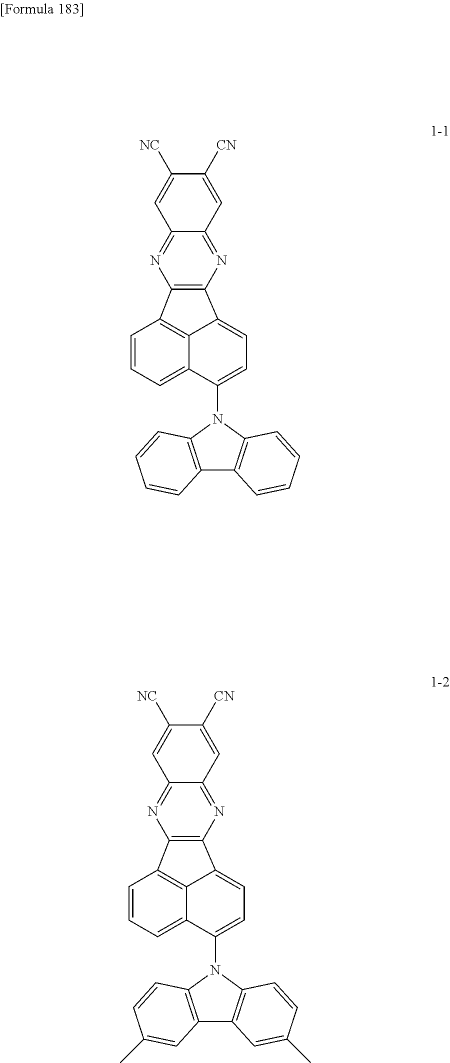

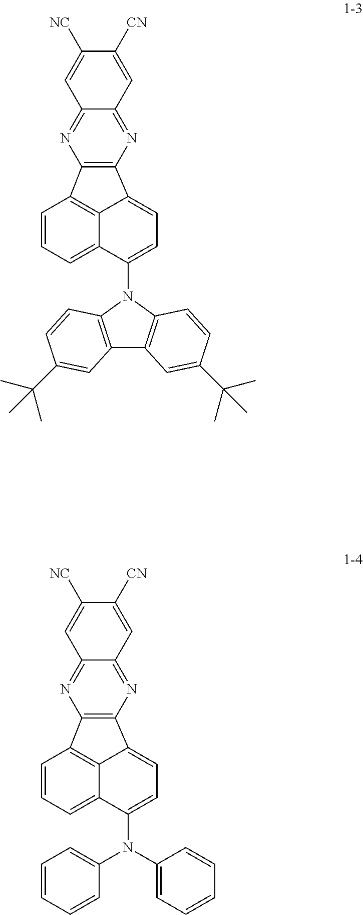 [SMILES: CC(C)(C)c1ccc2c(c1)c1cc(C(C)(C)C)ccc1n2-c1ccc2c3c(cccc13)-c1nc3cc(C#N)c(C#N)cc3nc1-2 ; N#Cc1cc2nc3c(nc2cc1C#N)-c1ccc(N(c2ccccc2)c2ccccc2)c2cccc-3c12]

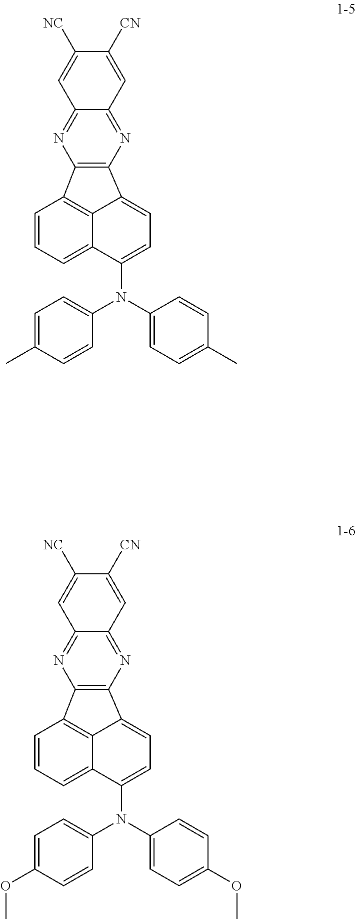

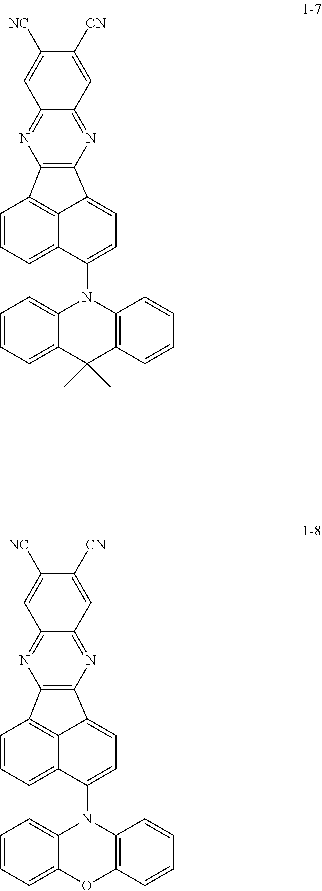 [SMILES: CC1(C)c2ccccc2N(c2ccc3c4c(cccc24)-c2nc4cc(C#N)c(C#N)cc4nc2-3)c2ccccc21 ; N#Cc1cc2nc3c(nc2cc1C#N)-c1ccc(N2c4ccccc4Oc4ccccc42)c2cccc-3c12]

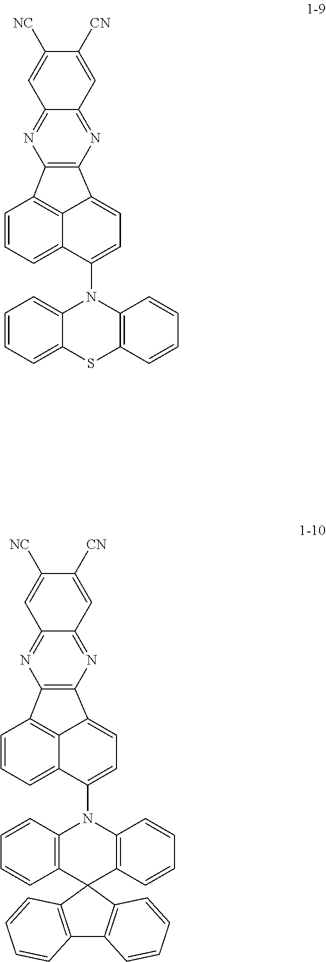 [SMILES: N#Cc1cc2nc3c(nc2cc1C#N)-c1ccc(N2c4ccccc4Sc4ccccc42)c2cccc-3c12 ; N#Cc1cc2nc3c(nc2cc1C#N)-c1ccc(N2c4ccccc4C4(c5ccccc5-c5ccccc54)c4ccccc42)c2cccc-3c12]

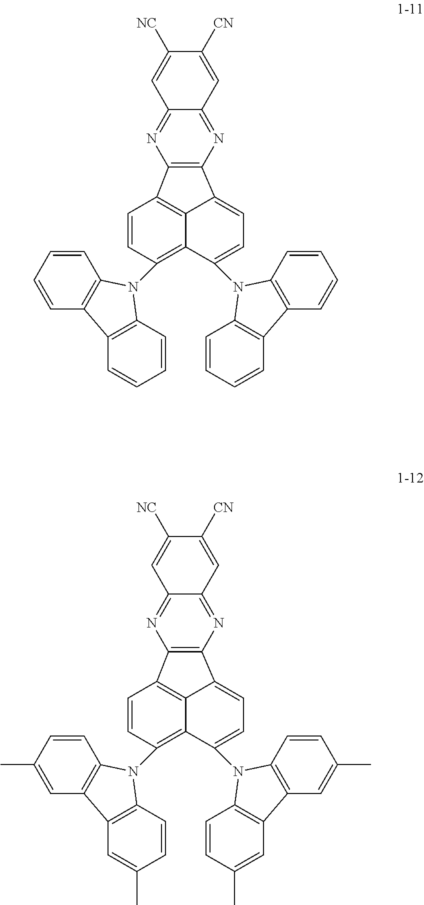

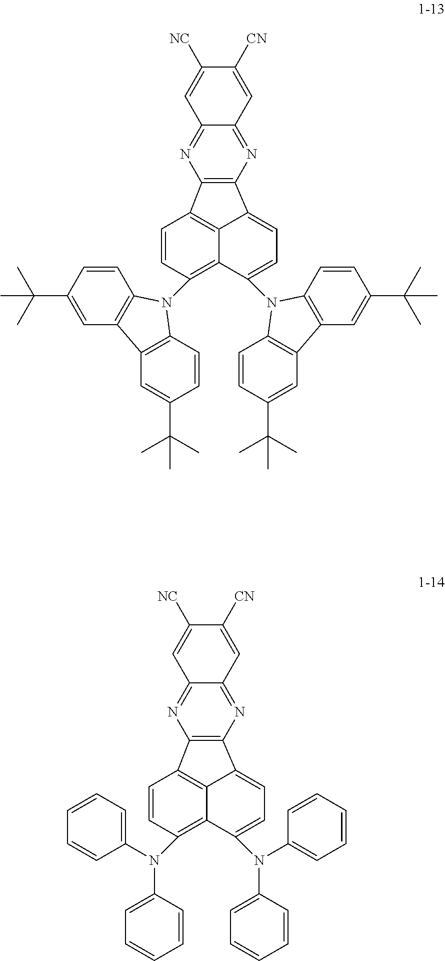 [SMILES: CC(C)(C)c1ccc2c(c1)c1cc(C(C)(C)C)ccc1n2-c1ccc2c3c(ccc(-n4c5ccc(C(C)(C)C)cc5c5cc(C(C)(C)C)ccc54)c13)-c1nc3cc(C#N)c(C#N)cc3nc1-2 ; N#Cc1cc2nc3c(nc2cc1C#N)-c1ccc(N(c2ccccc2)c2ccccc2)c2c(N(c4ccccc4)c4ccccc4)ccc-3c12]

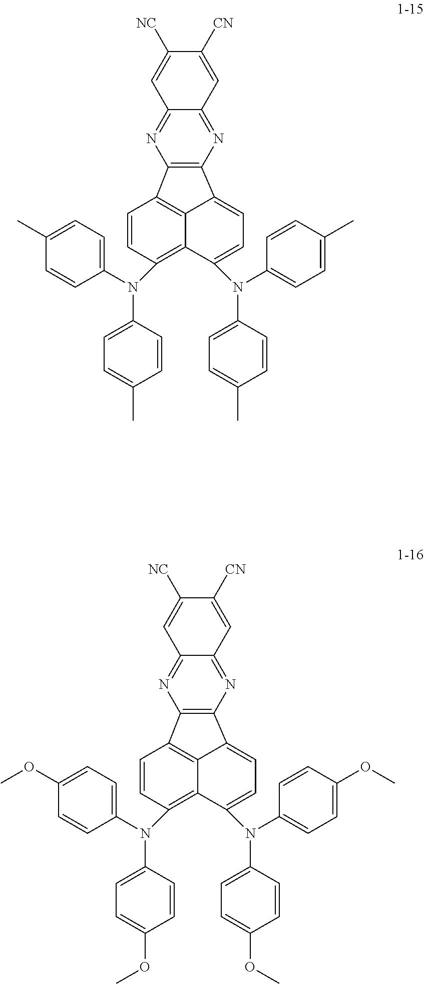

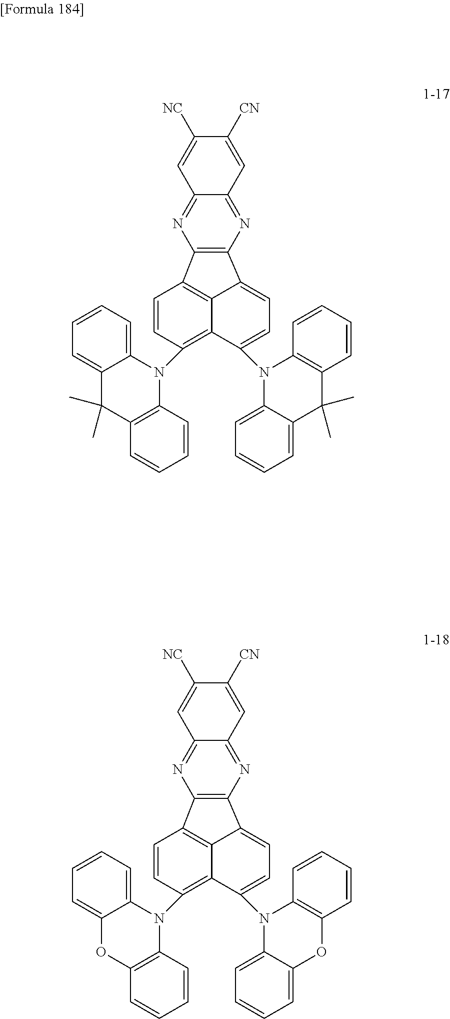

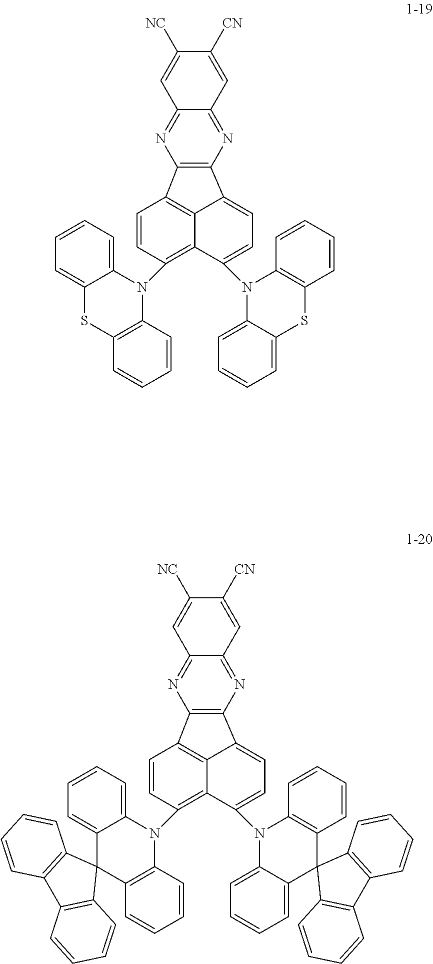 [SMILES: N#Cc1cc2nc3c(nc2cc1C#N)-c1ccc(N2c4ccccc4Sc4ccccc42)c2c(N4c5ccccc5Sc5ccccc54)ccc-3c12 ; N#Cc1cc2nc3c(nc2cc1C#N)-c1ccc(N2c4ccccc4C4(c5ccccc5-c5ccccc54)c4ccccc42)c2c(N4c5ccccc5C5(c6ccccc6-c6ccccc65)c5ccccc54)ccc-3c12]

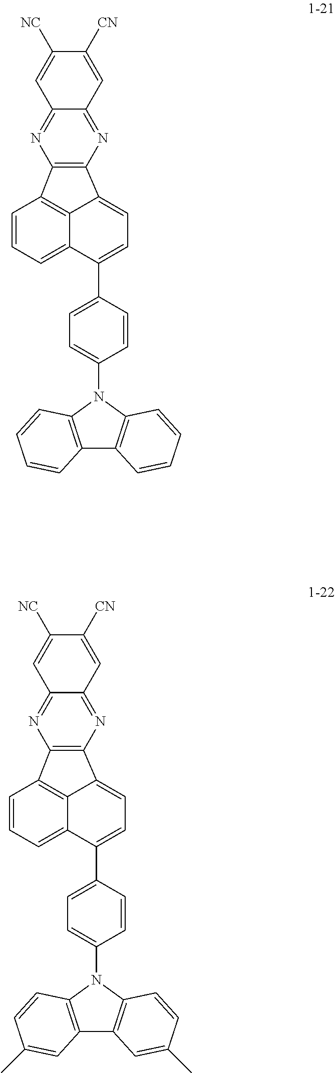

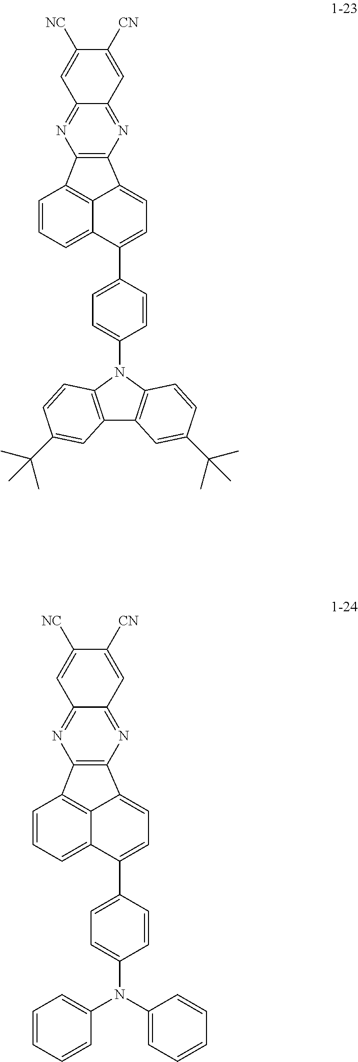 [SMILES: CC(C)(C)c1ccc2c(c1)c1cc(C(C)(C)C)ccc1n2-c1ccc(-c2ccc3c4c(cccc24)-c2nc4cc(C#N)c(C#N)cc4nc2-3)cc1 ; N#Cc1cc2nc3c(nc2cc1C#N)-c1ccc(-c2ccc(N(c4ccccc4)c4ccccc4)cc2)c2cccc-3c12]

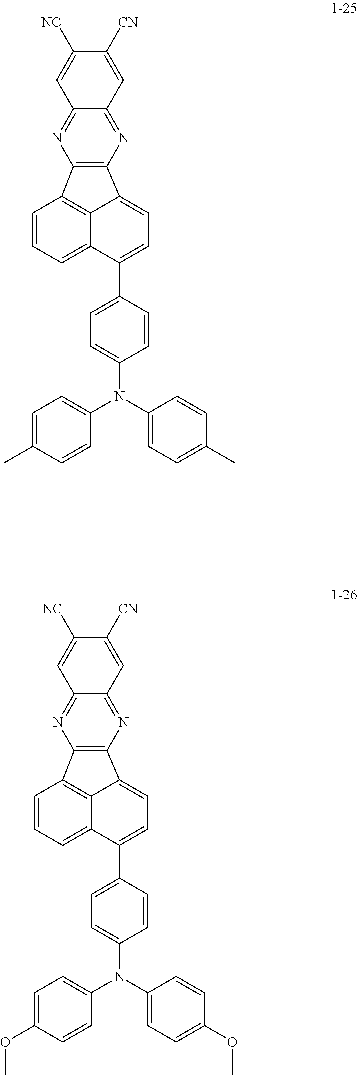

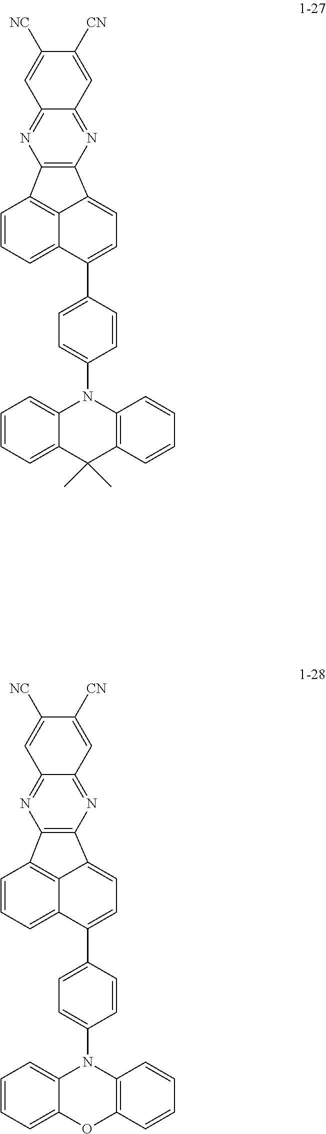 [SMILES: CC1(C)c2ccccc2N(c2ccc(-c3ccc4c5c(cccc35)-c3nc5cc(C#N)c(C#N)cc5nc3-4)cc2)c2ccccc21 ; N#Cc1cc2nc3c(nc2cc1C#N)-c1ccc(-c2ccc(N4c5ccccc5Oc5ccccc54)cc2)c2cccc-3c12]

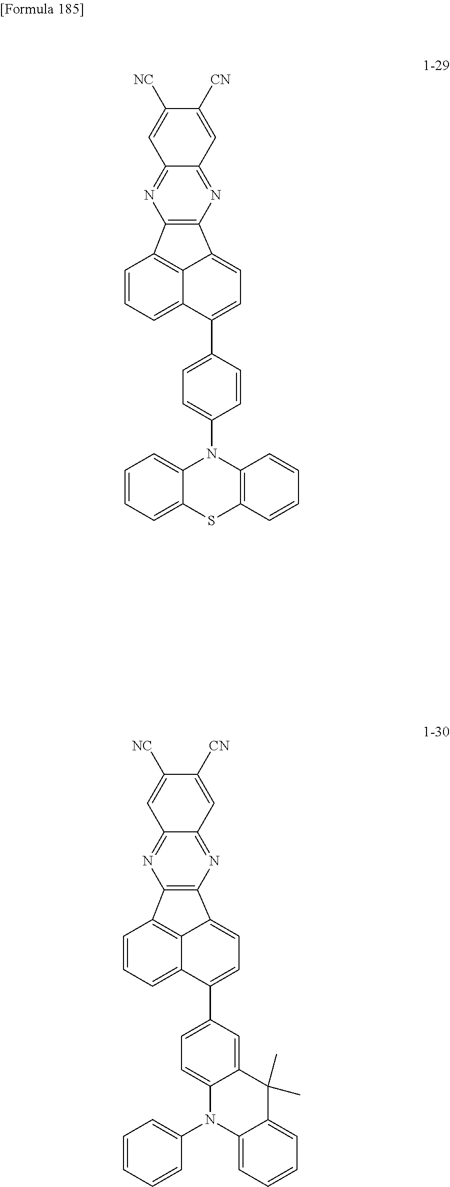 [SMILES: N#Cc1cc2nc3c(nc2cc1C#N)-c1ccc(-c2ccc(N4c5ccccc5Sc5ccccc54)cc2)c2cccc-3c12 ; CC1(C)c2ccccc2N(c2ccccc2)c2ccc(-c3ccc4c5c(cccc35)-c3nc5cc(C#N)c(C#N)cc5nc3-4)cc21]

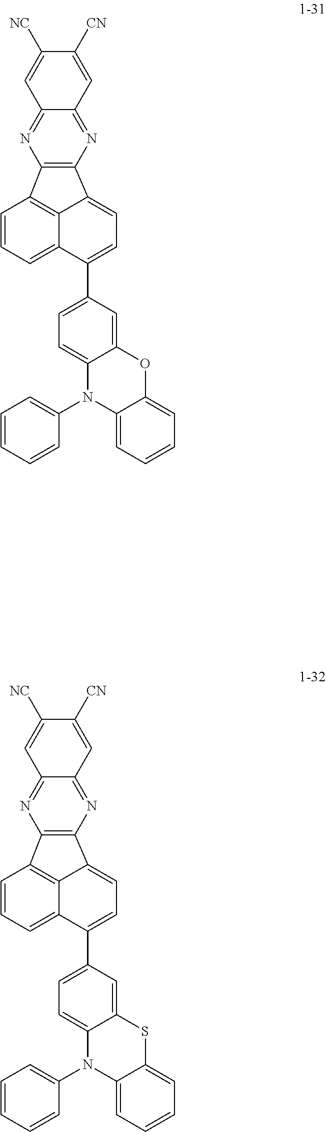 [SMILES: N#Cc1cc2nc3c(nc2cc1C#N)-c1ccc(-c2ccc4c(c2)Oc2ccccc2N4c2ccccc2)c2cccc-3c12 ; N#Cc1cc2nc3c(nc2cc1C#N)-c1ccc(-c2ccc4c(c2)Sc2ccccc2N4c2ccccc2)c2cccc-3c12]

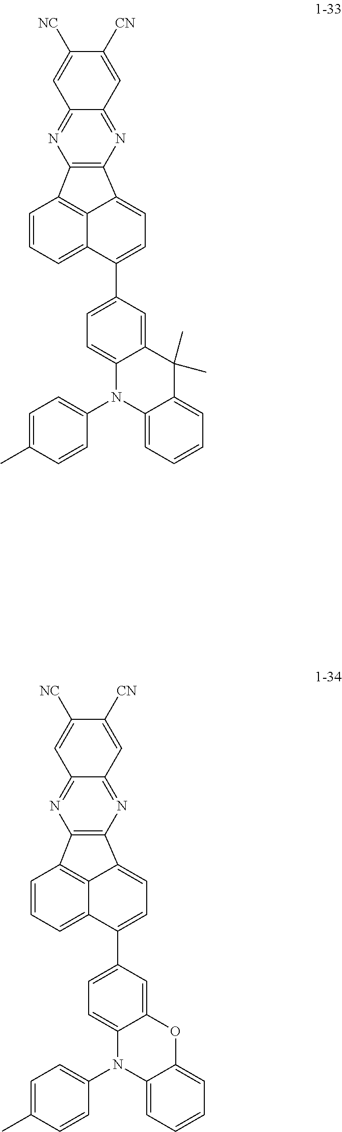

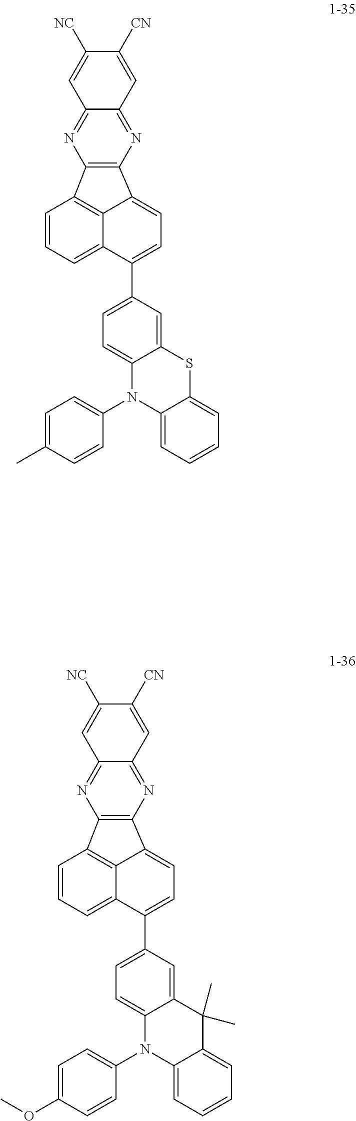

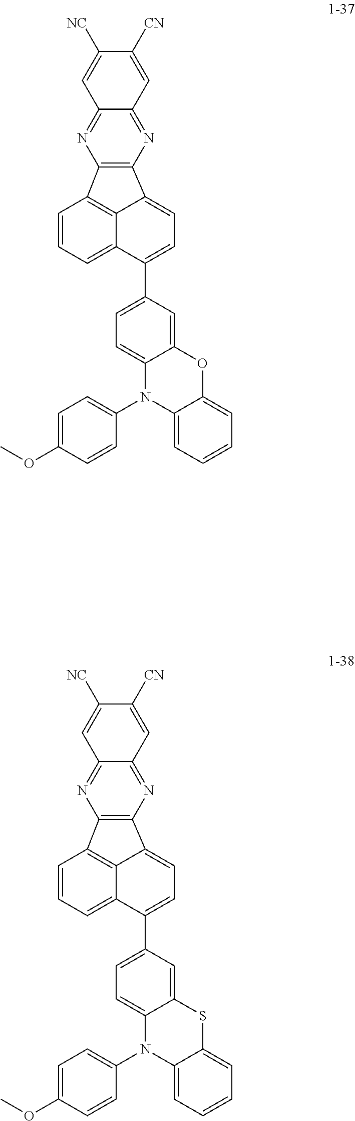 [SMILES: COc1ccc(N2c3ccccc3Oc3cc(-c4ccc5c6c(cccc46)-c4nc6cc(C#N)c(C#N)cc6nc4-5)ccc32)cc1 ; COc1ccc(N2c3ccccc3Sc3cc(-c4ccc5c6c(cccc46)-c4nc6cc(C#N)c(C#N)cc6nc4-5)ccc32)cc1]

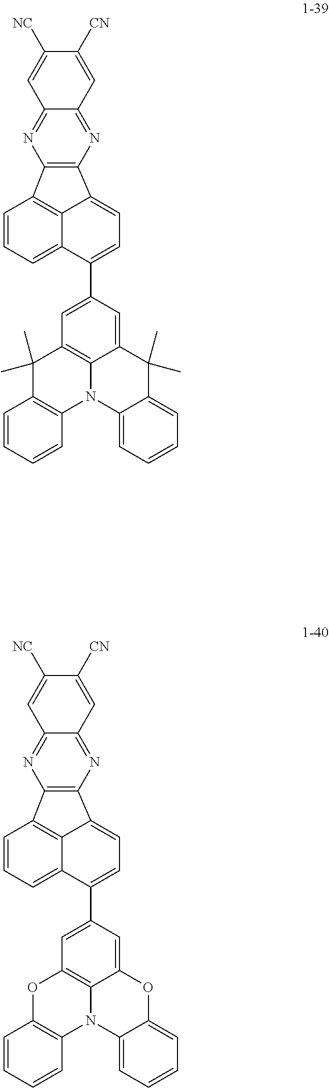

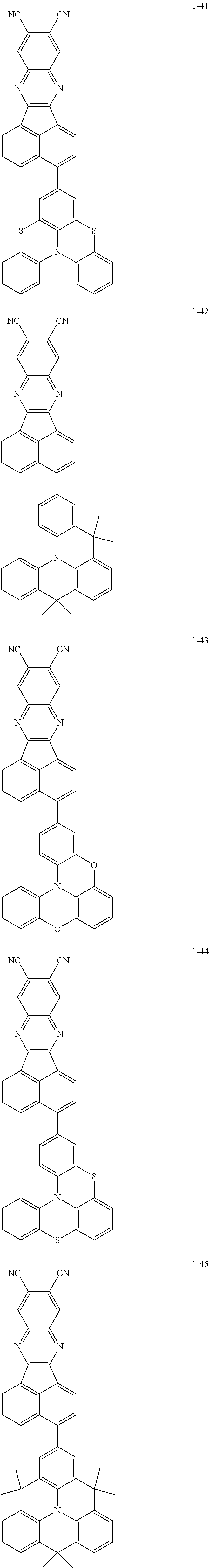

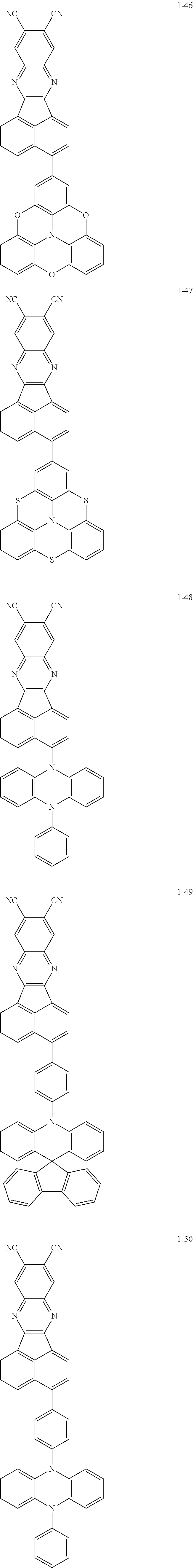

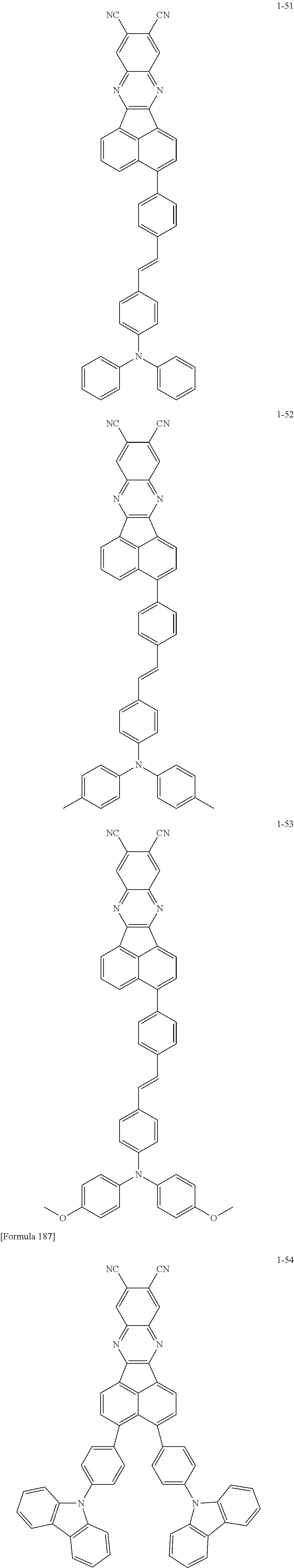

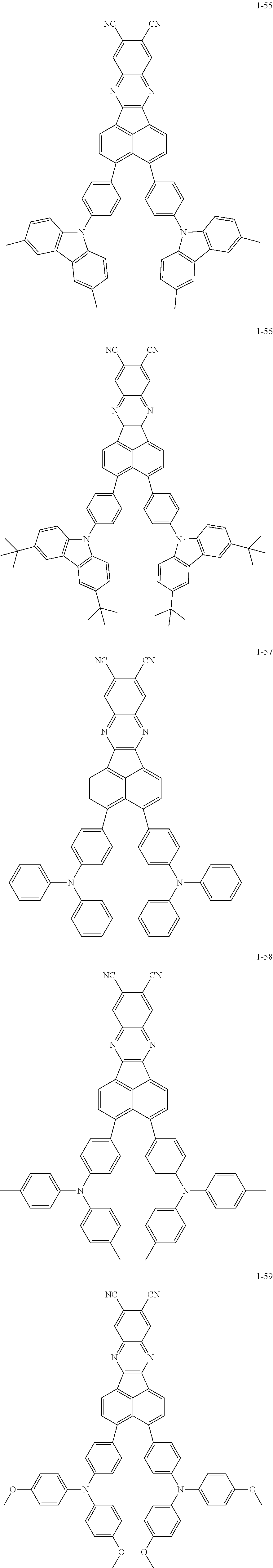

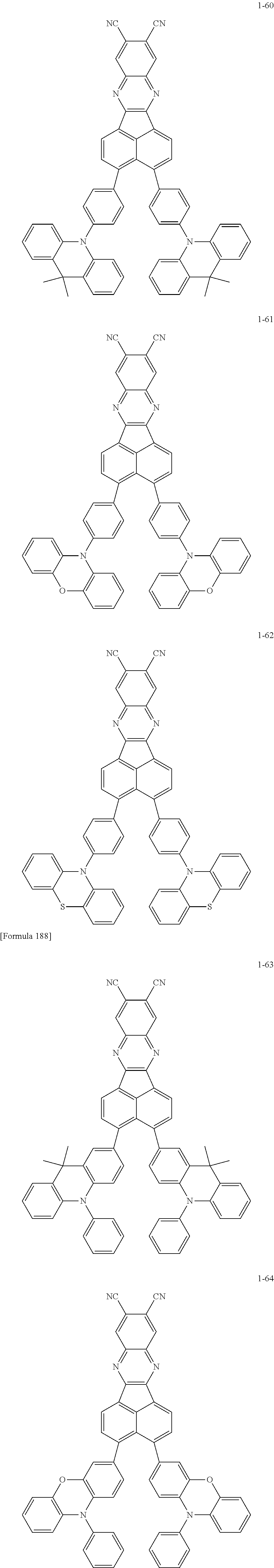

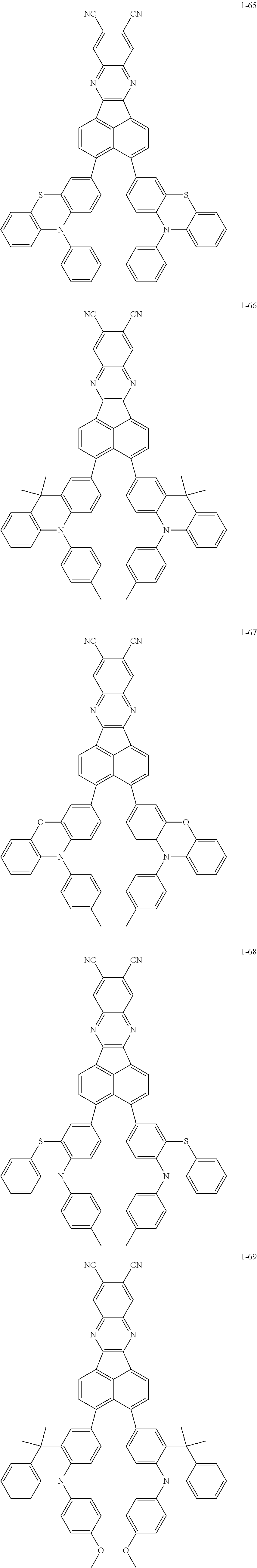

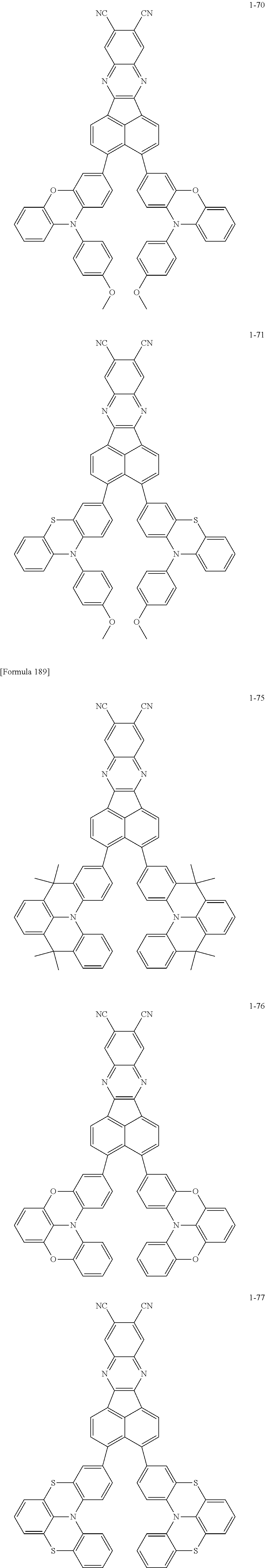

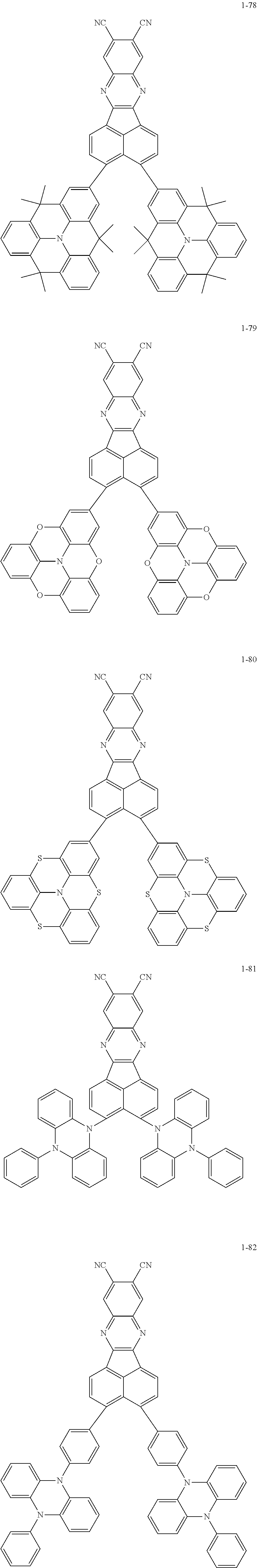

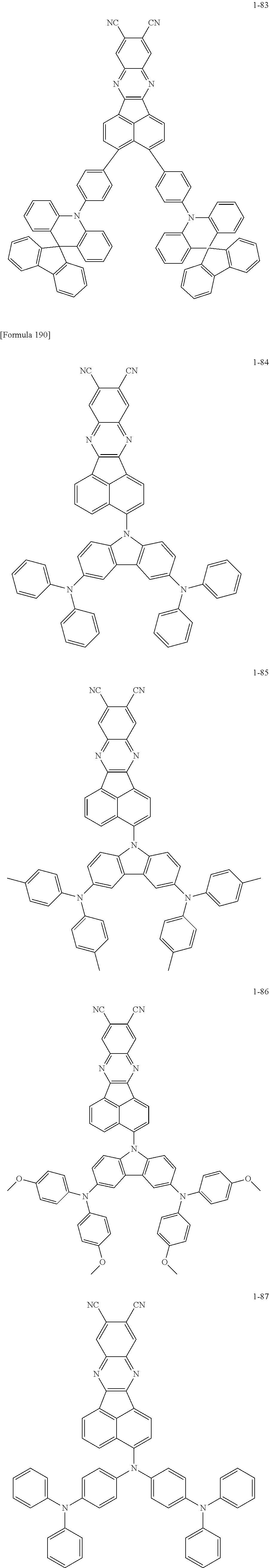

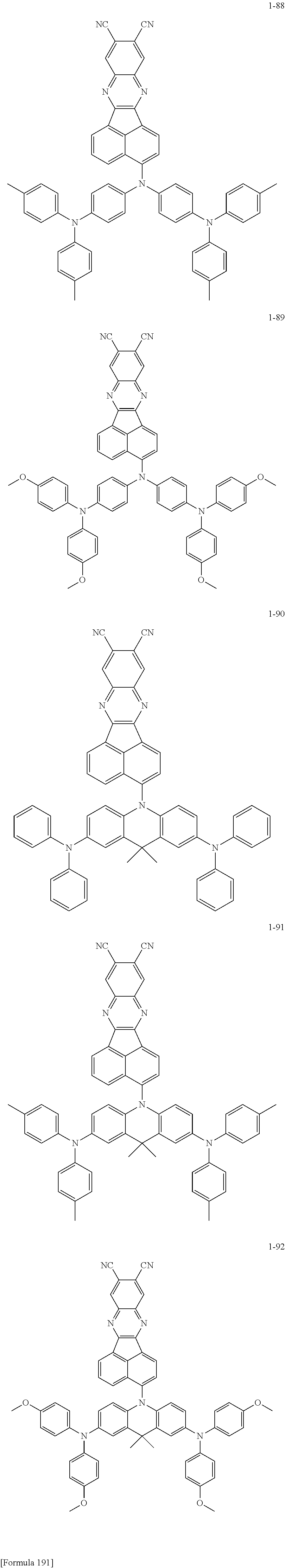

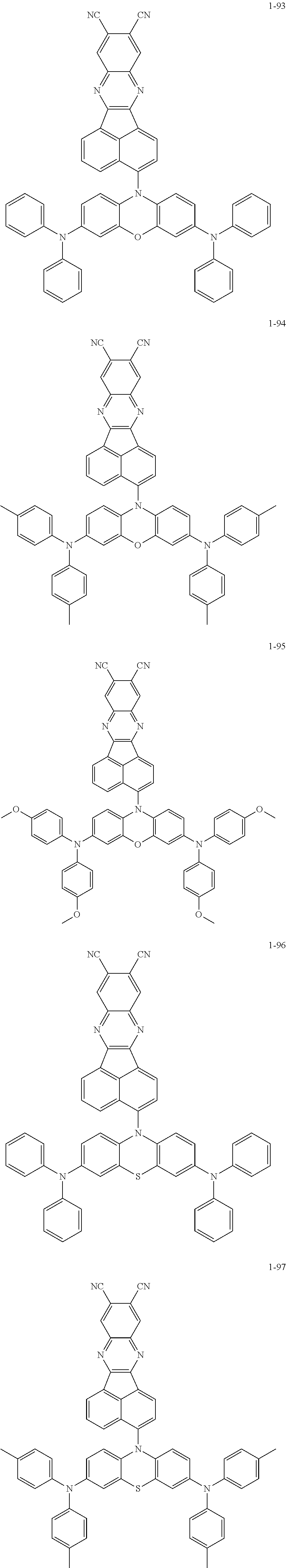

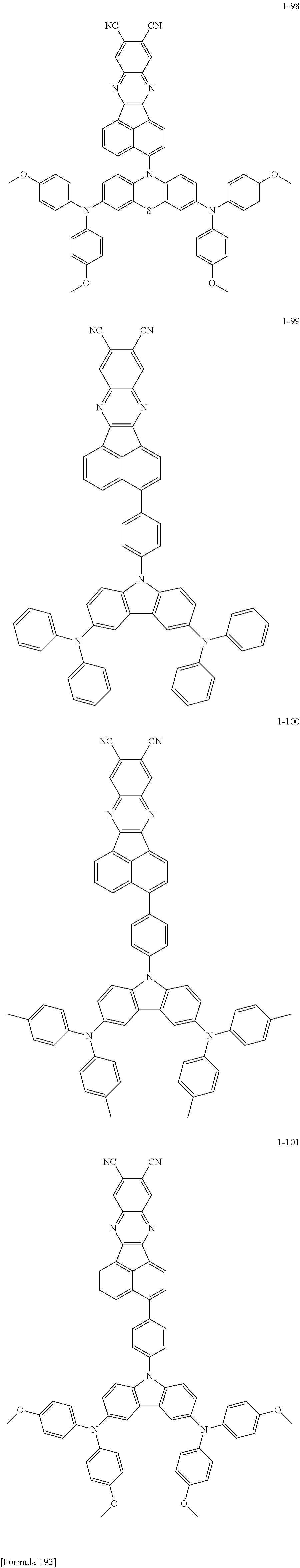

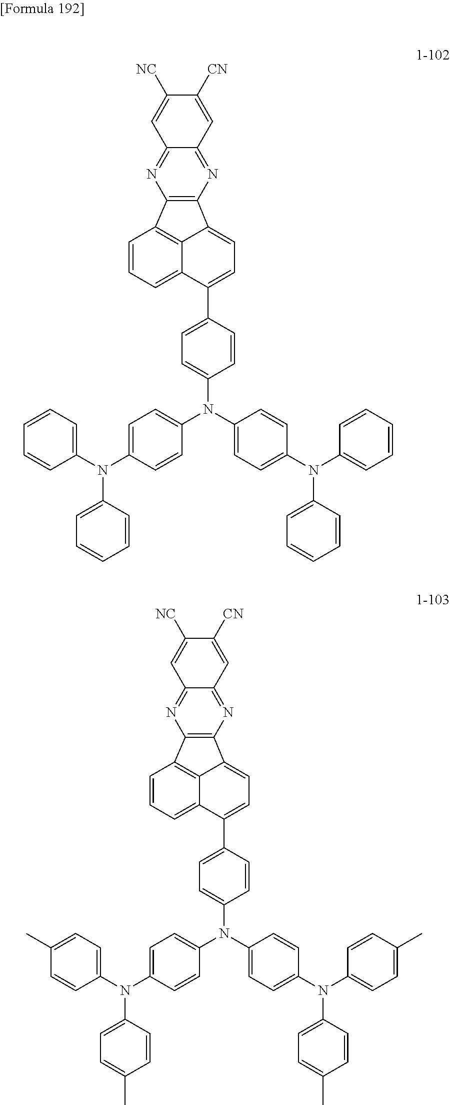

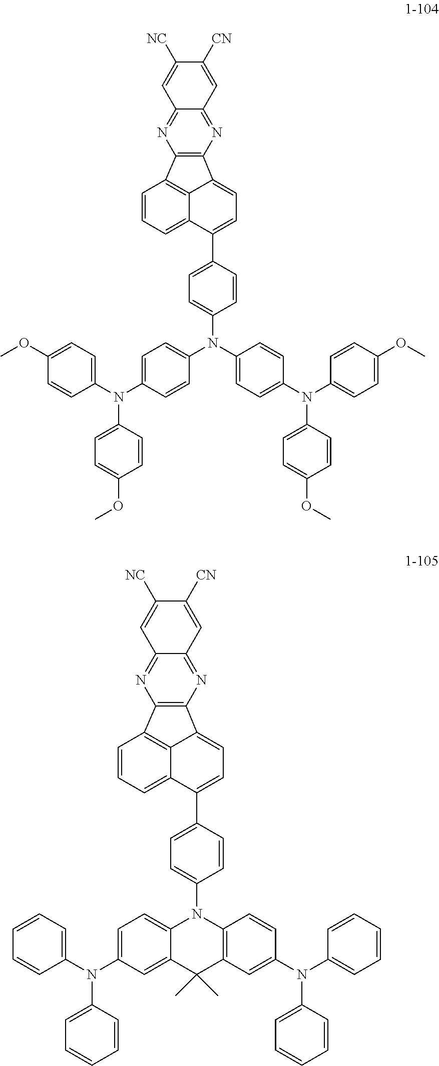

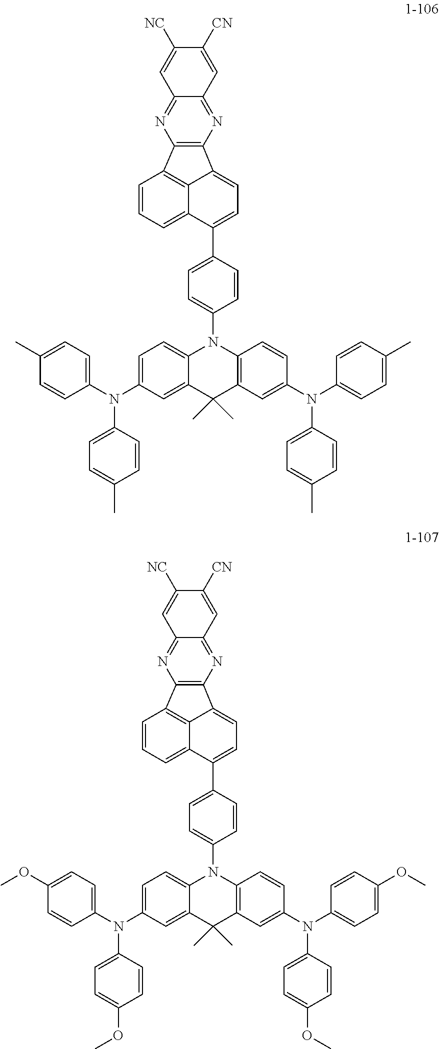

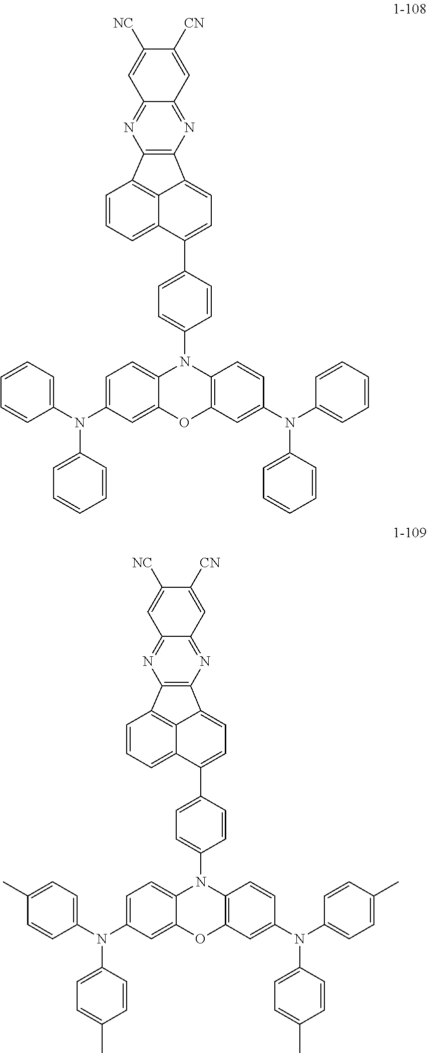

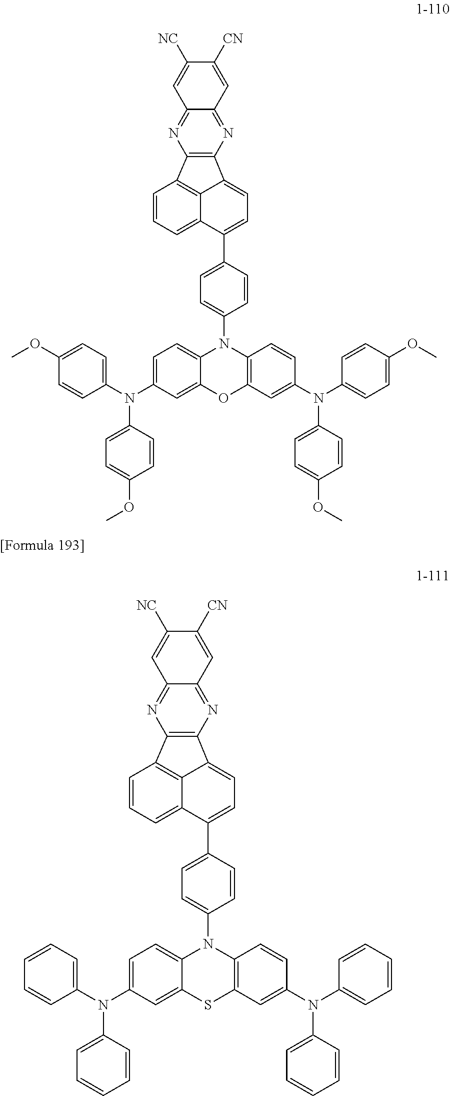

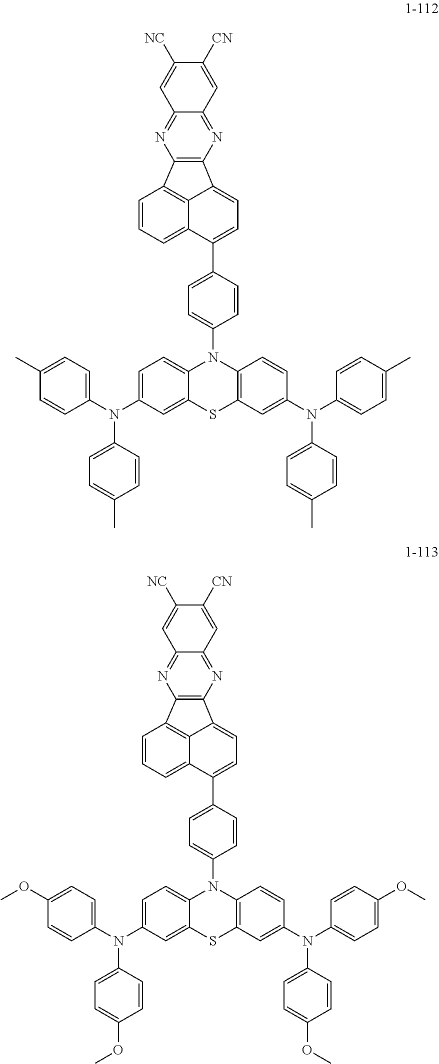

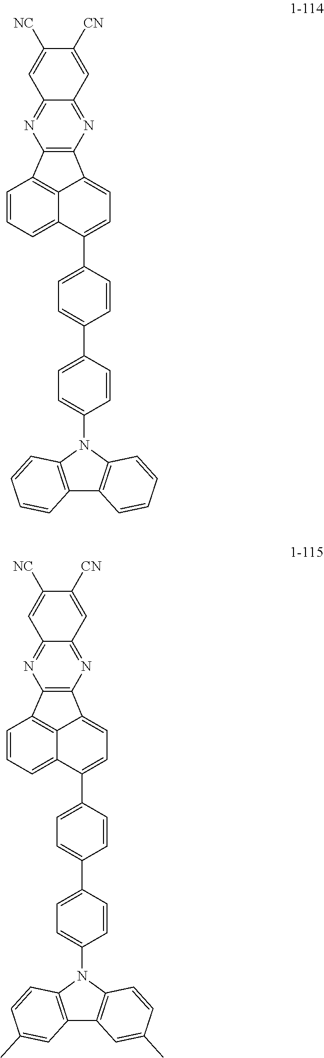

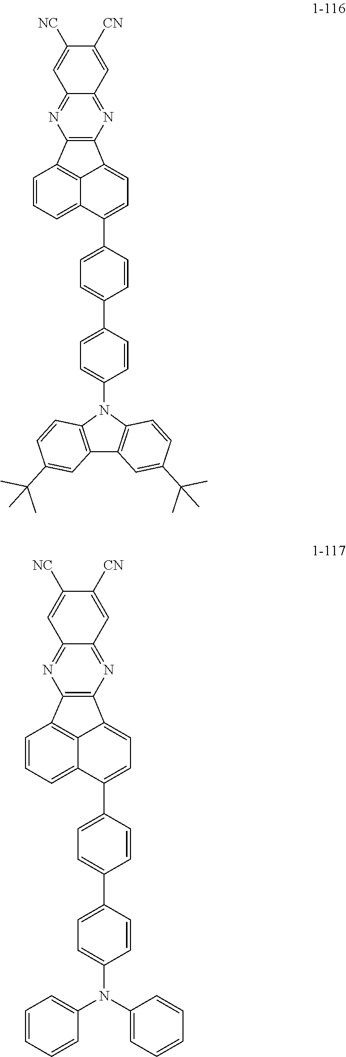 [SMILES: CC(C)(C)c1ccc2c(c1)c1cc(C(C)(C)C)ccc1n2-c1ccc(-c2ccc(-c3ccc4c5c(cccc35)-c3nc5cc(C#N)c(C#N)cc5nc3-4)cc2)cc1 ; N#Cc1cc2nc3c(nc2cc1C#N)-c1ccc(-c2ccc(-c4ccc(N(c5ccccc5)c5ccccc5)cc4)cc2)c2cccc-3c12]

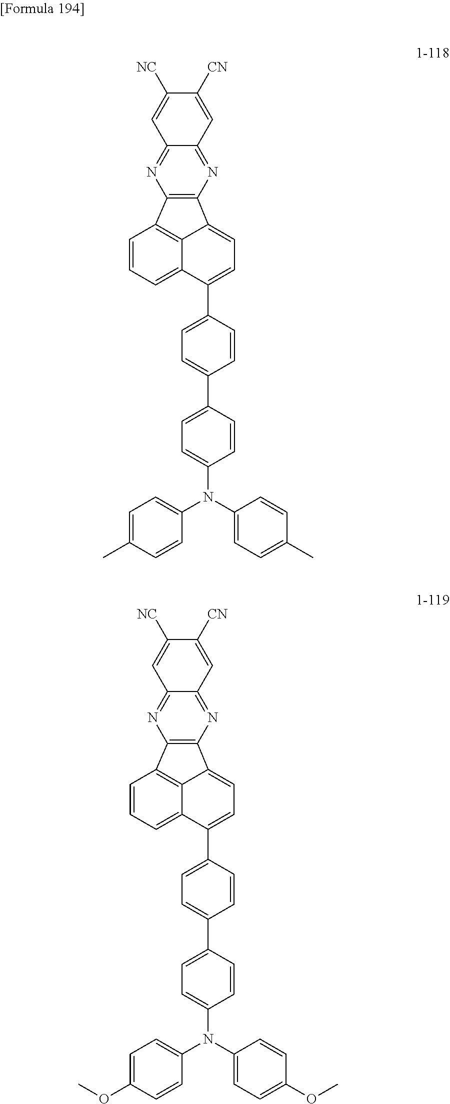

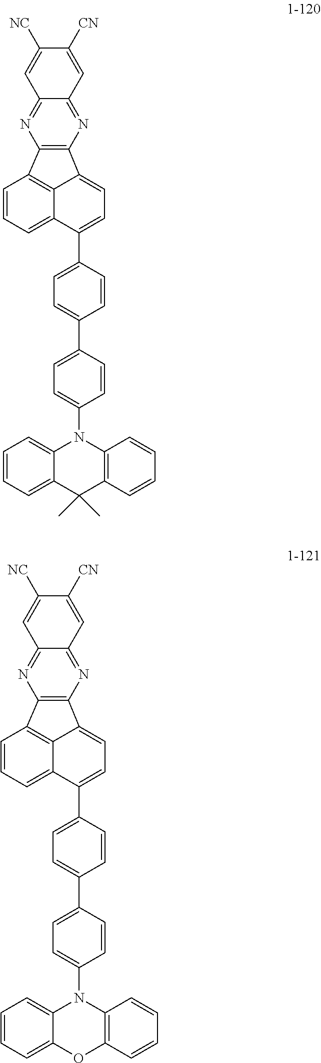 [SMILES: CC1(C)c2ccccc2N(c2ccc(-c3ccc(-c4ccc5c6c(cccc46)-c4nc6cc(C#N)c(C#N)cc6nc4-5)cc3)cc2)c2ccccc21 ; N#Cc1cc2nc3c(nc2cc1C#N)-c1ccc(-c2ccc(-c4ccc(N5c6ccccc6Oc6ccccc65)cc4)cc2)c2cccc-3c12]

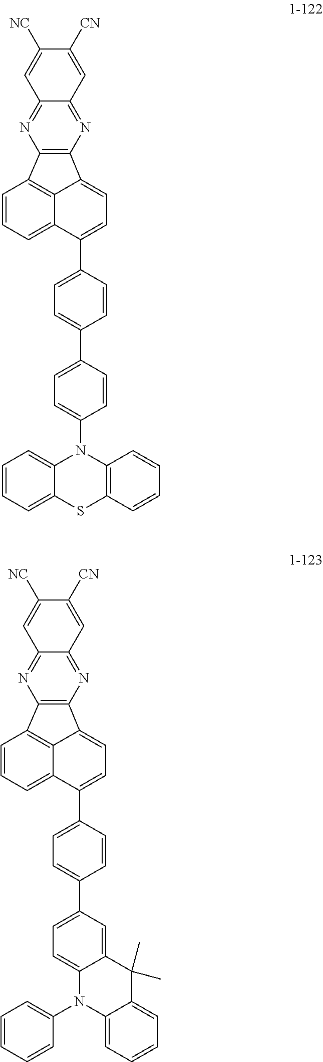 [SMILES: N#Cc1cc2nc3c(nc2cc1C#N)-c1ccc(-c2ccc(-c4ccc(N5c6ccccc6Sc6ccccc65)cc4)cc2)c2cccc-3c12 ; CC1(C)c2ccccc2N(c2ccccc2)c2ccc(-c3ccc(-c4ccc5c6c(cccc46)-c4nc6cc(C#N)c(C#N)cc6nc4-5)cc3)cc21]

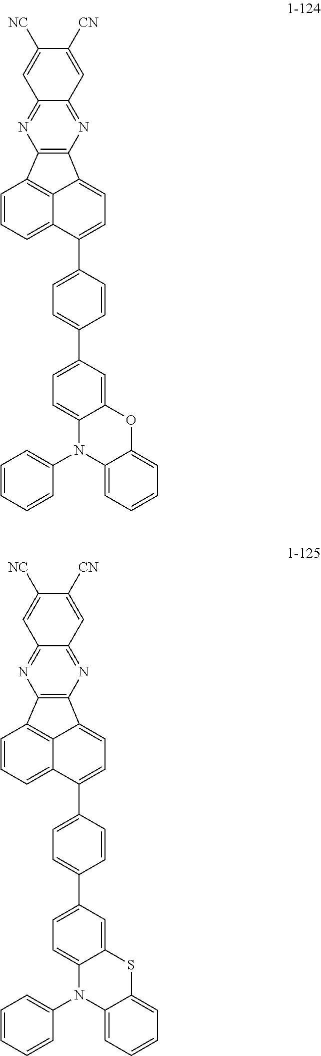 [SMILES: N#Cc1cc2nc3c(nc2cc1C#N)-c1ccc(-c2ccc(-c4ccc5c(c4)Oc4ccccc4N5c4ccccc4)cc2)c2cccc-3c12 ; N#Cc1cc2nc3c(nc2cc1C#N)-c1ccc(-c2ccc(-c4ccc5c(c4)Sc4ccccc4N5c4ccccc4)cc2)c2cccc-3c12]

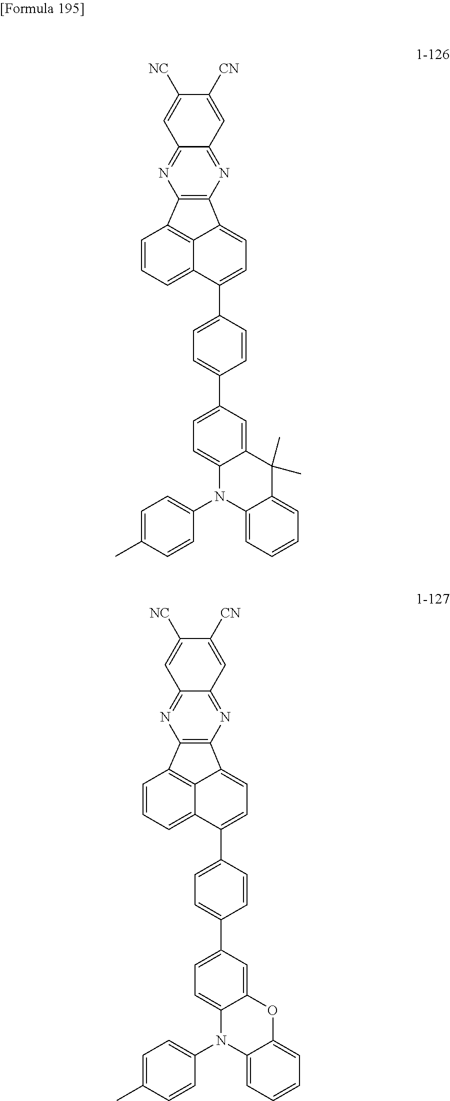

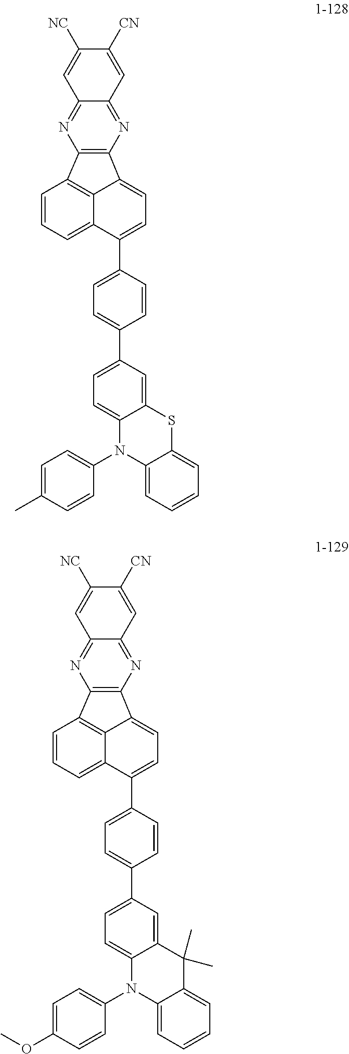

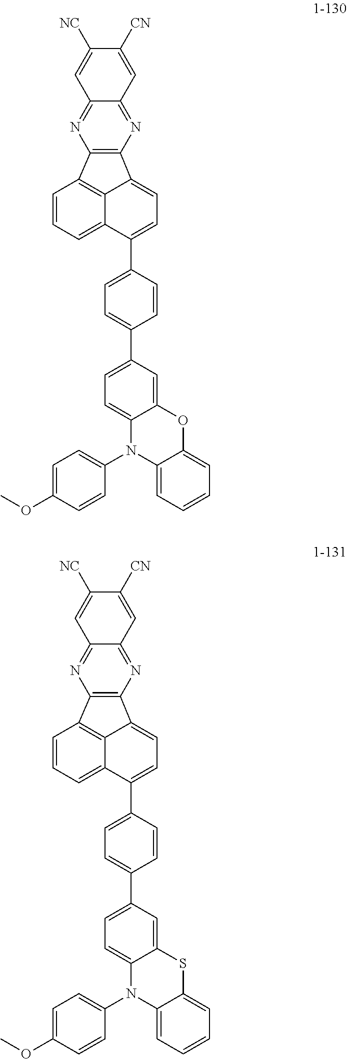 [SMILES: COc1ccc(N2c3ccccc3Oc3cc(-c4ccc(-c5ccc6c7c(cccc57)-c5nc7cc(C#N)c(C#N)cc7nc5-6)cc4)ccc32)cc1 ; COc1ccc(N2c3ccccc3Sc3cc(-c4ccc(-c5ccc6c7c(cccc57)-c5nc7cc(C#N)c(C#N)cc7nc5-6)cc4)ccc32)cc1]

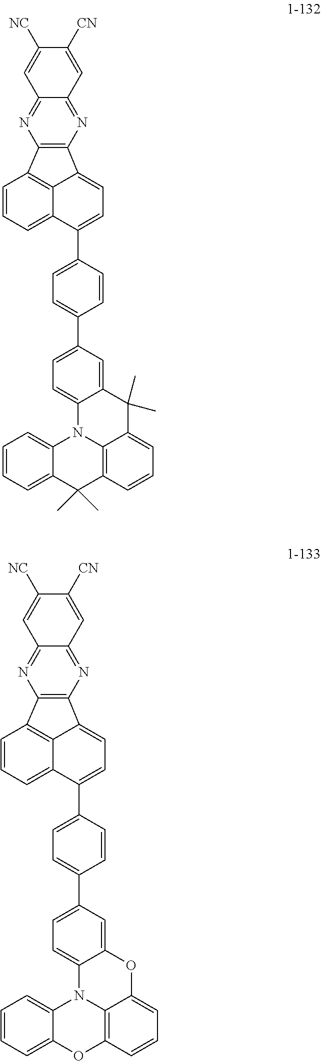 [SMILES: CC1(C)c2ccccc2N2c3ccc(-c4ccc(-c5ccc6c7c(cccc57)-c5nc7cc(C#N)c(C#N)cc7nc5-6)cc4)cc3C(C)(C)c3cccc1c32 ; N#Cc1cc2nc3c(nc2cc1C#N)-c1ccc(-c2ccc(-c4ccc5c(c4)Oc4cccc6c4N5c4ccccc4O6)cc2)c2cccc-3c12]

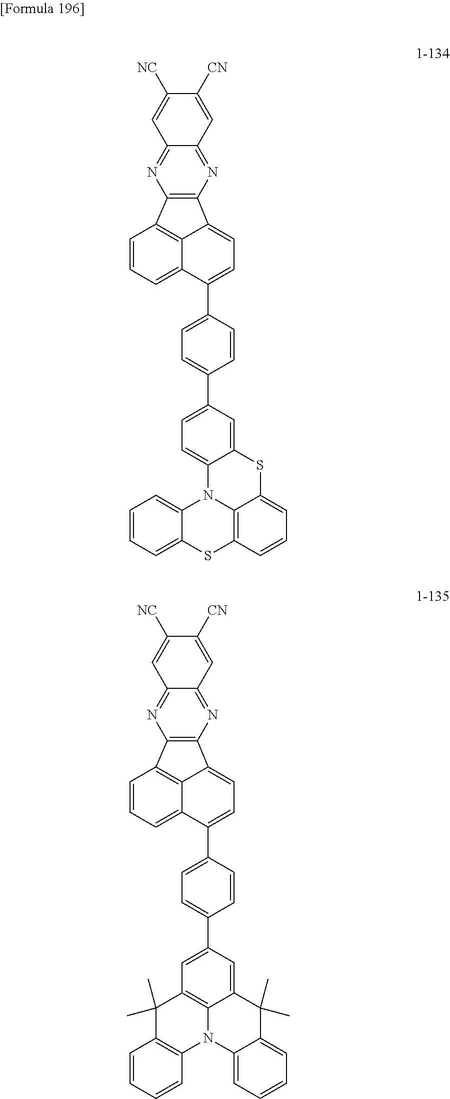

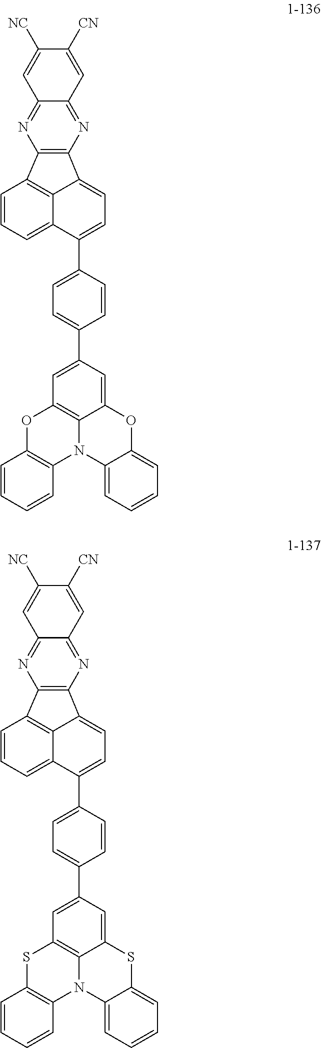 [SMILES: N#Cc1cc2nc3c(nc2cc1C#N)-c1ccc(-c2ccc(-c4cc5c6c(c4)Oc4ccccc4N6c4ccccc4O5)cc2)c2cccc-3c12 ; N#Cc1cc2nc3c(nc2cc1C#N)-c1ccc(-c2ccc(-c4cc5c6c(c4)Sc4ccccc4N6c4ccccc4S5)cc2)c2cccc-3c12]

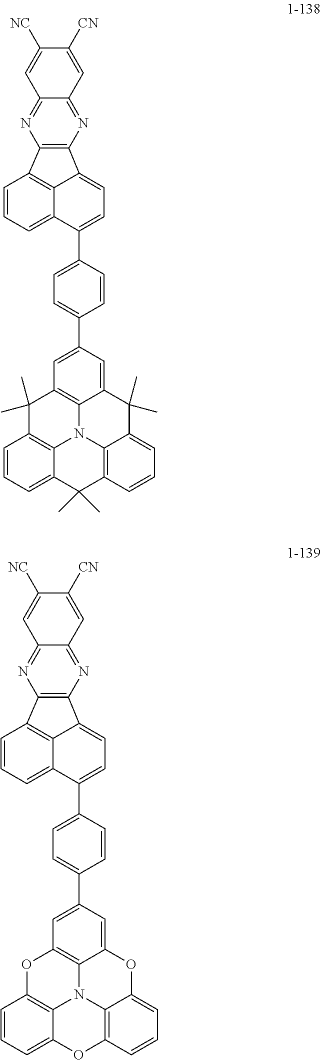

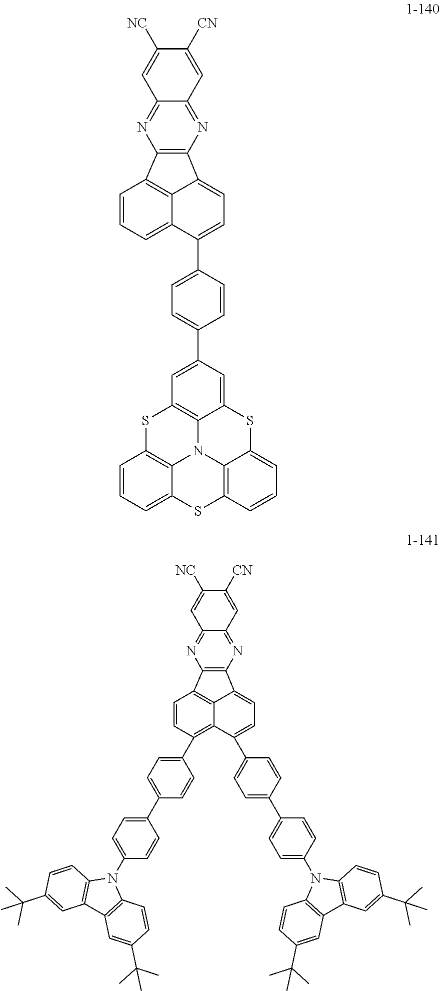 [SMILES: N#Cc1cc2nc3c(nc2cc1C#N)-c1ccc(-c2ccc(-c4cc5c6c(c4)Sc4cccc7c4N6c4c(cccc4S5)S7)cc2)c2cccc-3c12 ; CC(C)(C)c1ccc2c(c1)c1cc(C(C)(C)C)ccc1n2-c1ccc(-c2ccc(-c3ccc4c5c(ccc(-c6ccc(-c7ccc(-n8c9ccc(C(C)(C)C)cc9c9cc(C(C)(C)C)ccc98)cc7)cc6)c35)-c3nc5cc(C#N)c(C#N)cc5nc3-4)cc2)cc1]

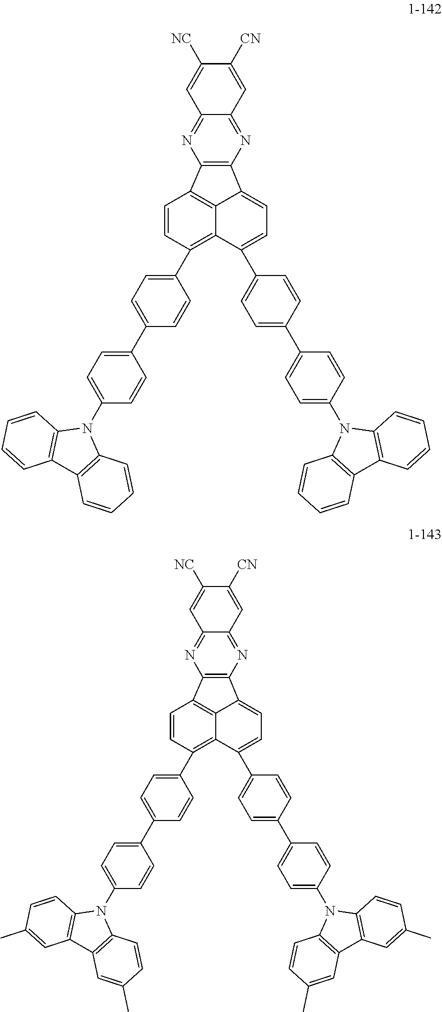

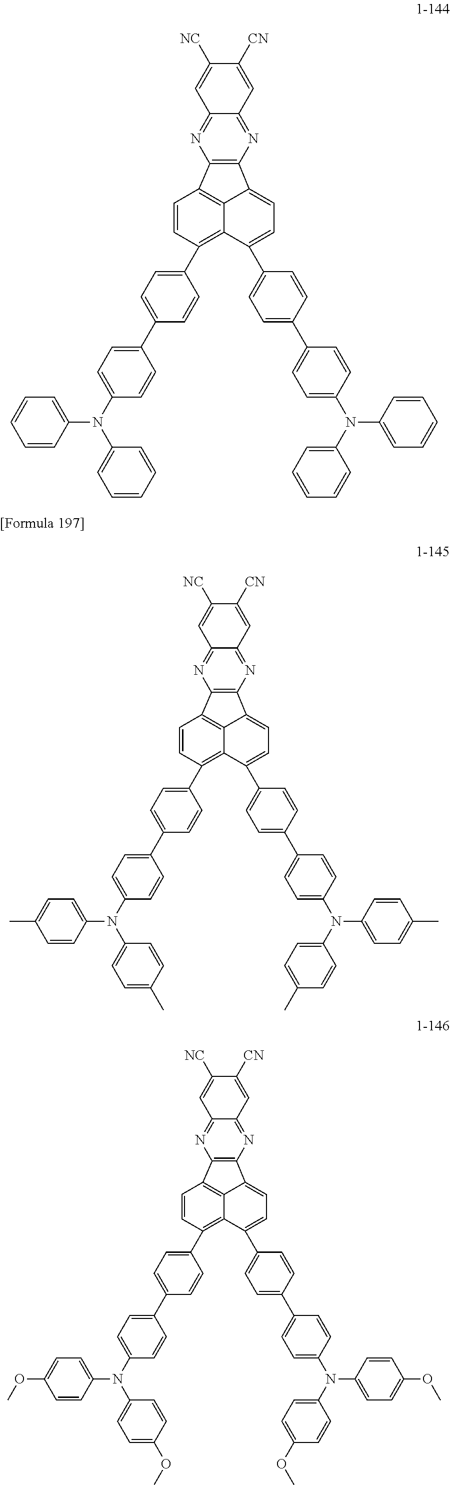

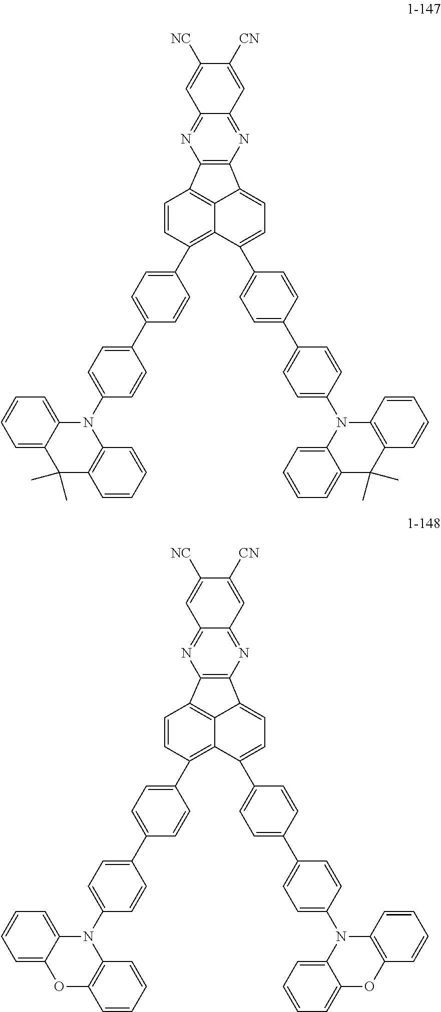 [SMILES: CC1(C)c2ccccc2N(c2ccc(-c3ccc(-c4ccc5c6c(ccc(-c7ccc(-c8ccc(N9c%10ccccc%10C(C)(C)c%10ccccc%109)cc8)cc7)c46)-c4nc6cc(C#N)c(C#N)cc6nc4-5)cc3)cc2)c2ccccc21 ; N#Cc1cc2nc3c(nc2cc1C#N)-c1ccc(-c2ccc(-c4ccc(N5c6ccccc6Oc6ccccc65)cc4)cc2)c2c(-c4ccc(-c5ccc(N6c7ccccc7Oc7ccccc76)cc5)cc4)ccc-3c12]

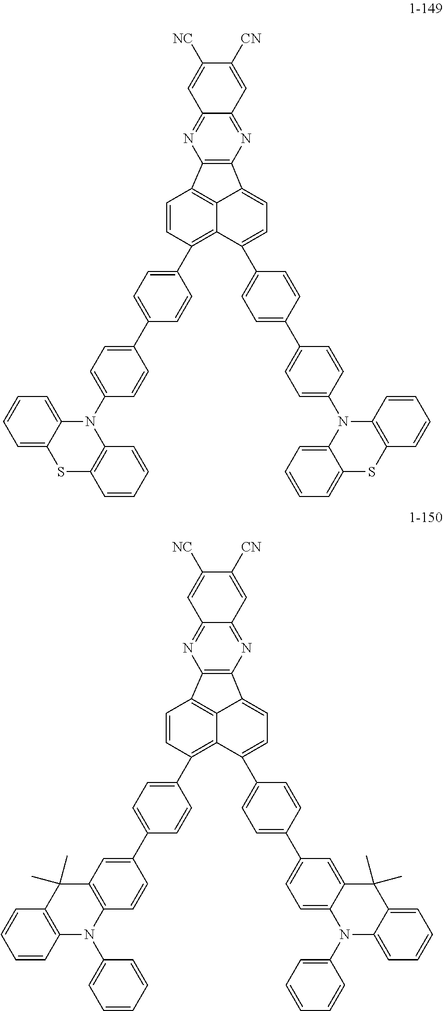 [SMILES: N#Cc1cc2nc3c(nc2cc1C#N)-c1ccc(-c2ccc(-c4ccc(N5c6ccccc6Sc6ccccc65)cc4)cc2)c2c(-c4ccc(-c5ccc(N6c7ccccc7Sc7ccccc76)cc5)cc4)ccc-3c12 ; CC1(C)c2ccccc2N(c2ccccc2)c2ccc(-c3ccc(-c4ccc5c6c(ccc(-c7ccc(-c8ccc9c(c8)C(C)(C)c8ccccc8N9c8ccccc8)cc7)c46)-c4nc6cc(C#N)c(C#N)cc6nc4-5)cc3)cc21]

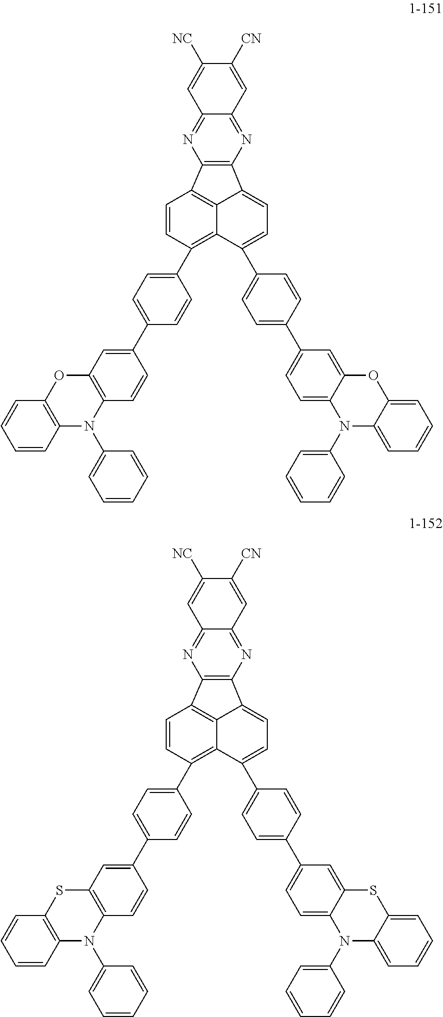 [SMILES: N#Cc1cc2nc3c(nc2cc1C#N)-c1ccc(-c2ccc(-c4ccc5c(c4)Oc4ccccc4N5c4ccccc4)cc2)c2c(-c4ccc(-c5ccc6c(c5)Oc5ccccc5N6c5ccccc5)cc4)ccc-3c12 ; N#Cc1cc2nc3c(nc2cc1C#N)-c1ccc(-c2ccc(-c4ccc5c(c4)Sc4ccccc4N5c4ccccc4)cc2)c2c(-c4ccc(-c5ccc6c(c5)Sc5ccccc5N6c5ccccc5)cc4)ccc-3c12]

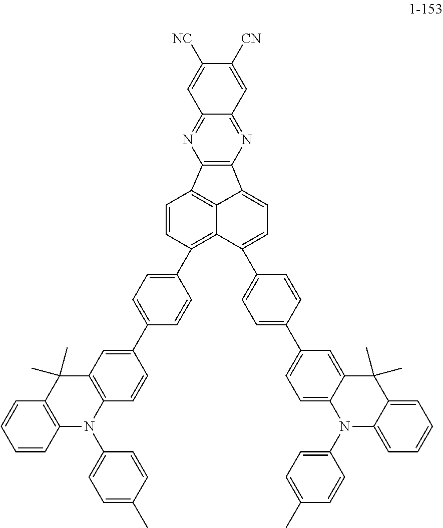 [SMILES: Cc1ccc(N2c3ccccc3C(C)(C)c3cc(-c4ccc(-c5ccc6c7c(ccc(-c8ccc(-c9ccc%10c(c9)C(C)(C)c9ccccc9N%10c9ccc(C)cc9)cc8)c57)-c5nc7cc(C#N)c(C#N)cc7nc5-6)cc4)ccc32)cc1]

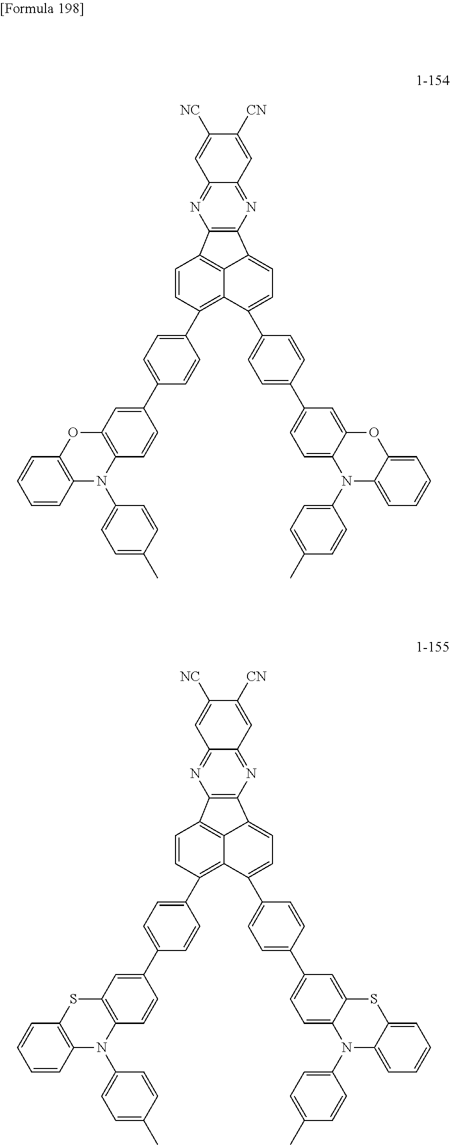 [SMILES: Cc1ccc(N2c3ccccc3Oc3cc(-c4ccc(-c5ccc6c7c(ccc(-c8ccc(-c9ccc%10c(c9)Oc9ccccc9N%10c9ccc(C)cc9)cc8)c57)-c5nc7cc(C#N)c(C#N)cc7nc5-6)cc4)ccc32)cc1 ; Cc1ccc(N2c3ccccc3Sc3cc(-c4ccc(-c5ccc6c7c(ccc(-c8ccc(-c9ccc%10c(c9)Sc9ccccc9N%10c9ccc(C)cc9)cc8)c57)-c5nc7cc(C#N)c(C#N)cc7nc5-6)cc4)ccc32)cc1]

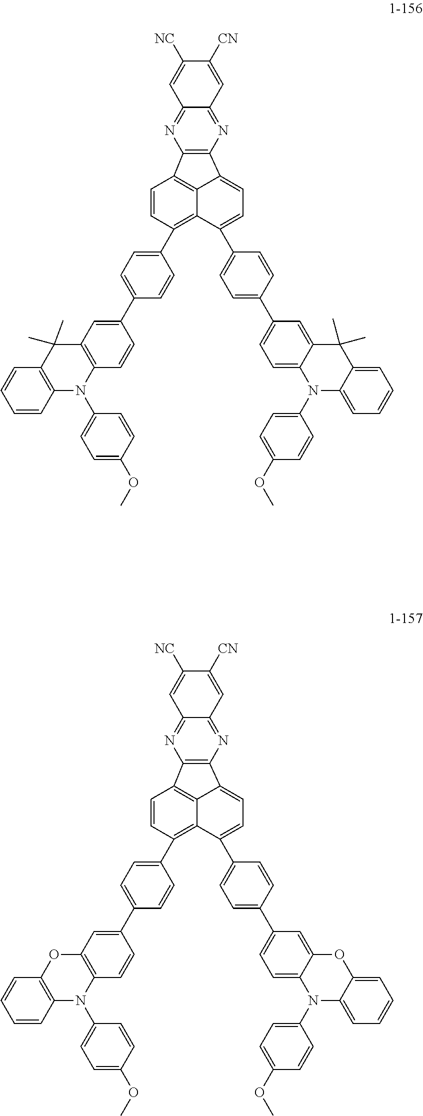 [SMILES: COc1ccc(N2c3ccccc3C(C)(C)c3cc(-c4ccc(-c5ccc6c7c(ccc(-c8ccc(-c9ccc%10c(c9)C(C)(C)c9ccccc9N%10c9ccc(OC)cc9)cc8)c57)-c5nc7cc(C#N)c(C#N)cc7nc5-6)cc4)ccc32)cc1 ; COc1ccc(N2c3ccccc3Oc3cc(-c4ccc(-c5ccc6c7c(ccc(-c8ccc(-c9ccc%10c(c9)Oc9ccccc9N%10c9ccc(OC)cc9)cc8)c57)-c5nc7cc(C#N)c(C#N)cc7nc5-6)cc4)ccc32)cc1]

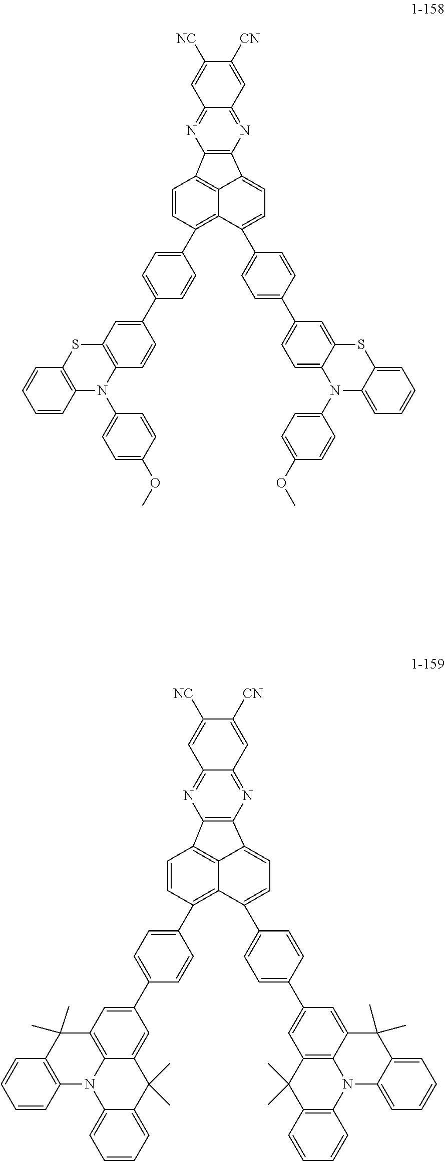 [SMILES: COc1ccc(N2c3ccccc3Sc3cc(-c4ccc(-c5ccc6c7c(ccc(-c8ccc(-c9ccc%10c(c9)Sc9ccccc9N%10c9ccc(OC)cc9)cc8)c57)-c5nc7cc(C#N)c(C#N)cc7nc5-6)cc4)ccc32)cc1 ; CC1(C)c2ccccc2N2c3ccccc3C(C)(C)c3cc(-c4ccc(-c5ccc6c7c(ccc(-c8ccc(-c9cc%10c%11c(c9)C(C)(C)c9ccccc9N%11c9ccccc9C%10(C)C)cc8)c57)-c5nc7cc(C#N)c(C#N)cc7nc5-6)cc4)cc1c32]

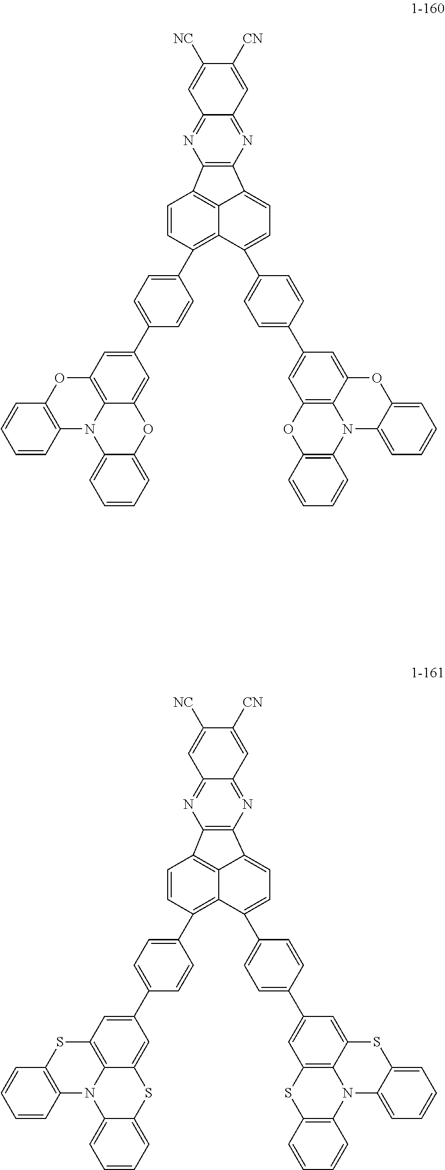 [SMILES: N#Cc1cc2nc3c(nc2cc1C#N)-c1ccc(-c2ccc(-c4cc5c6c(c4)Oc4ccccc4N6c4ccccc4O5)cc2)c2c(-c4ccc(-c5cc6c7c(c5)Oc5ccccc5N7c5ccccc5O6)cc4)ccc-3c12 ; N#Cc1cc2nc3c(nc2cc1C#N)-c1ccc(-c2ccc(-c4cc5c6c(c4)Sc4ccccc4N6c4ccccc4S5)cc2)c2c(-c4ccc(-c5cc6c7c(c5)Sc5ccccc5N7c5ccccc5S6)cc4)ccc-3c12]

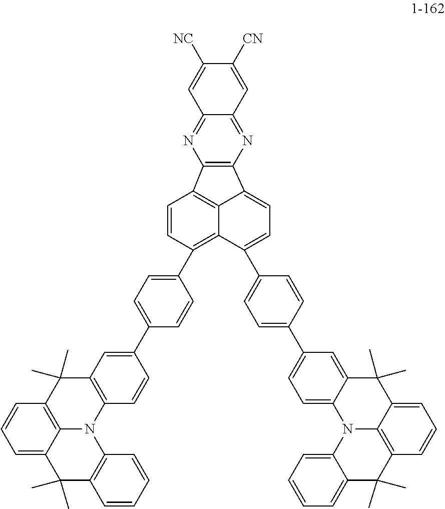 [SMILES: CC1(C)c2ccccc2N2c3ccc(-c4ccc(-c5ccc6c7c(ccc(-c8ccc(-c9ccc%10c(c9)C(C)(C)c9cccc%11c9N%10c9ccccc9C%11(C)C)cc8)c57)-c5nc7cc(C#N)c(C#N)cc7nc5-6)cc4)cc3C(C)(C)c3cccc1c32]

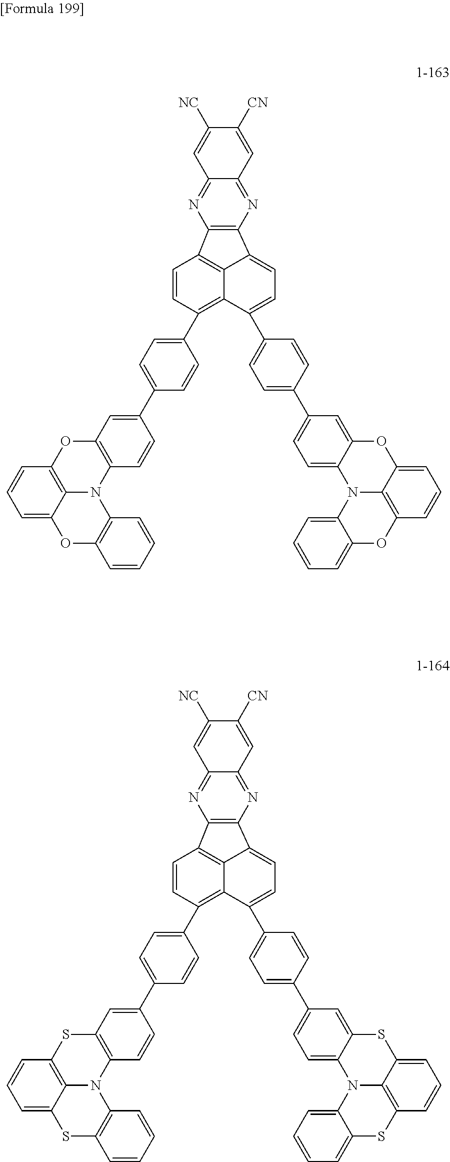 [SMILES: N#Cc1cc2nc3c(nc2cc1C#N)-c1ccc(-c2ccc(-c4ccc5c(c4)Oc4cccc6c4N5c4ccccc4O6)cc2)c2c(-c4ccc(-c5ccc6c(c5)Oc5cccc7c5N6c5ccccc5O7)cc4)ccc-3c12 ; N#Cc1cc2nc3c(nc2cc1C#N)-c1ccc(-c2ccc(-c4ccc5c(c4)Sc4cccc6c4N5c4ccccc4S6)cc2)c2c(-c4ccc(-c5ccc6c(c5)Sc5cccc7c5N6c5ccccc5S7)cc4)ccc-3c12]

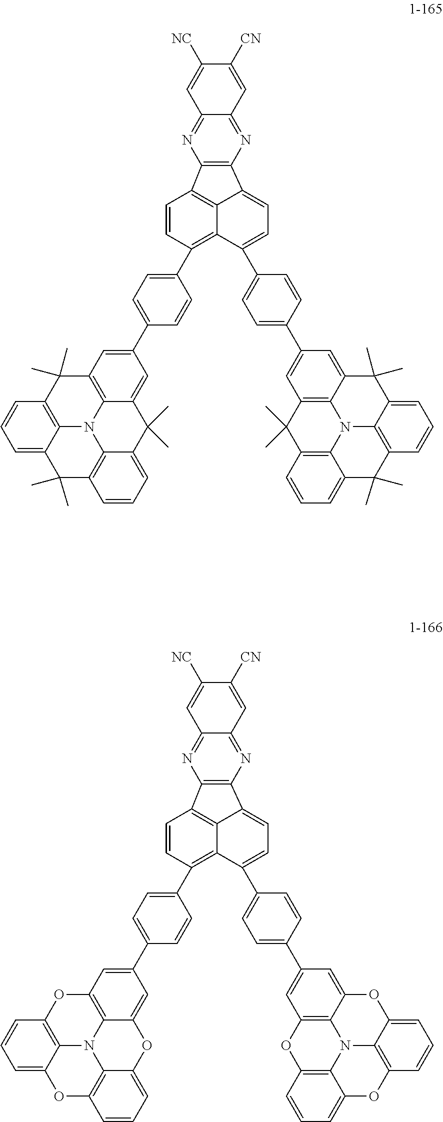 [SMILES: CC1(C)c2cccc3c2N2c4c1cccc4C(C)(C)c1cc(-c4ccc(-c5ccc6c7c(ccc(-c8ccc(-c9cc%10c%11c(c9)C(C)(C)c9cccc%12c9N%11c9c(cccc9C%10(C)C)C%12(C)C)cc8)c57)-c5nc7cc(C#N)c(C#N)cc7nc5-6)cc4)cc(c12)C3(C)C ; N#Cc1cc2nc3c(nc2cc1C#N)-c1ccc(-c2ccc(-c4cc5c6c(c4)Oc4cccc7c4N6c4c(cccc4O5)O7)cc2)c2c(-c4ccc(-c5cc6c7c(c5)Oc5cccc8c5N7c5c(cccc5O6)O8)cc4)ccc-3c12]

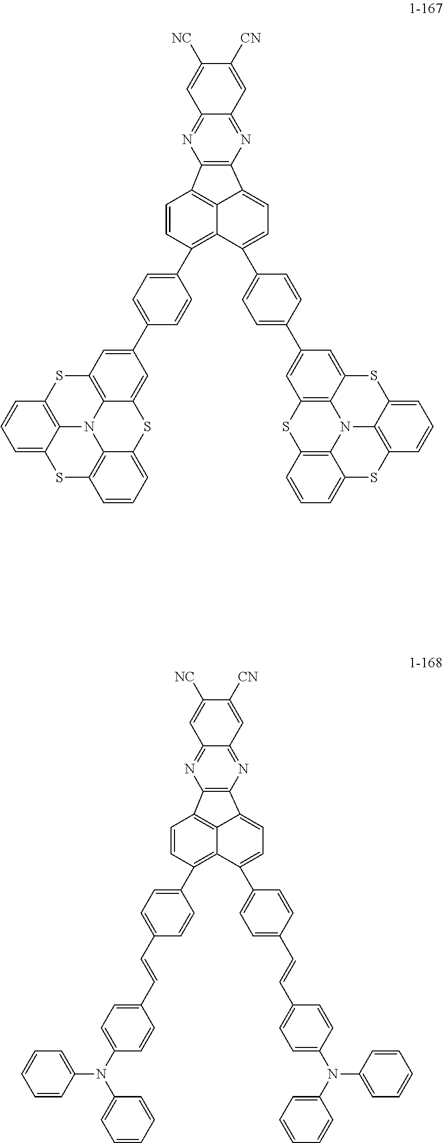 [SMILES: N#Cc1cc2nc3c(nc2cc1C#N)-c1ccc(-c2ccc(-c4cc5c6c(c4)Sc4cccc7c4N6c4c(cccc4S5)S7)cc2)c2c(-c4ccc(-c5cc6c7c(c5)Sc5cccc8c5N7c5c(cccc5S6)S8)cc4)ccc-3c12 ; N#Cc1cc2nc3c(nc2cc1C#N)-c1ccc(-c2ccc(/C=C/c4ccc(N(c5ccccc5)c5ccccc5)cc4)cc2)c2c(-c4ccc(/C=C/c5ccc(N(c6ccccc6)c6ccccc6)cc5)cc4)ccc-3c12]

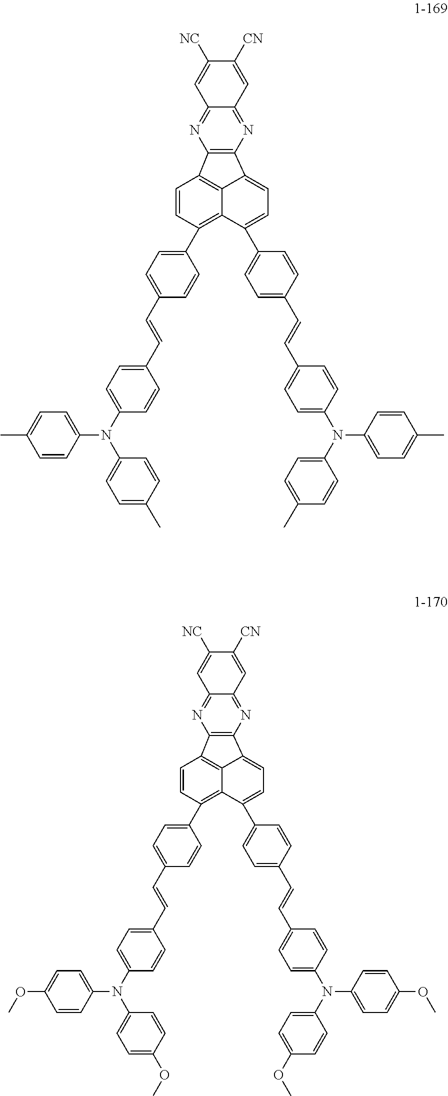

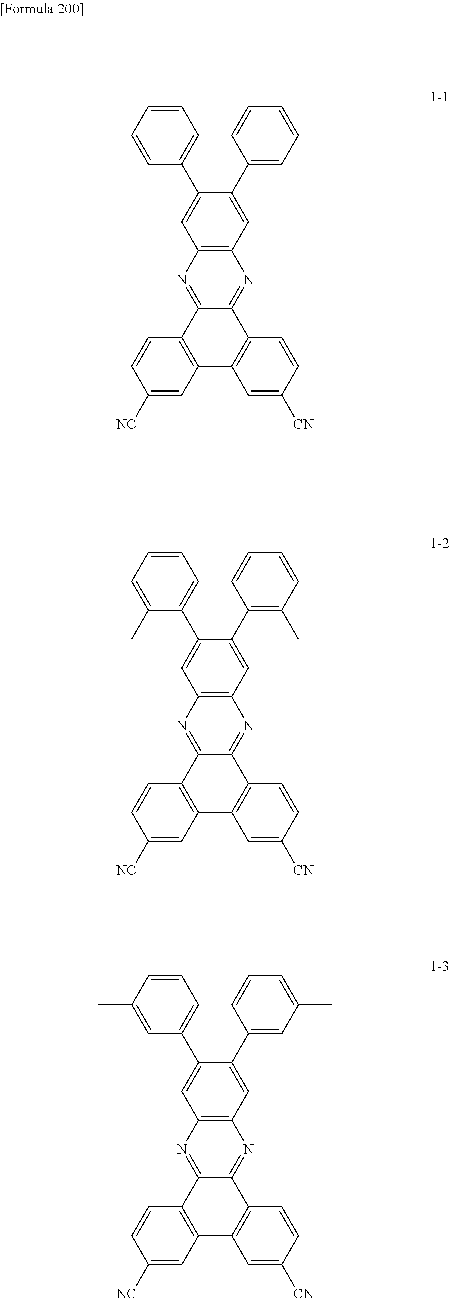

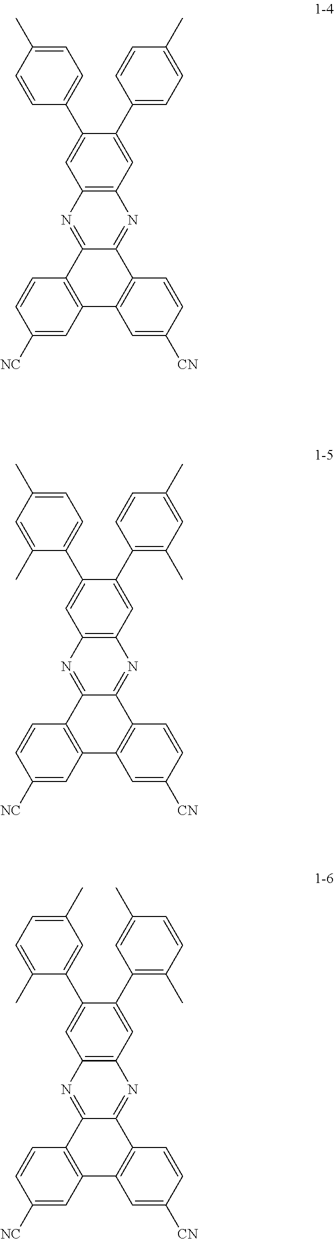 [SMILES: Cc1ccc(-c2cc3nc4c5ccc(C#N)cc5c5cc(C#N)ccc5c4nc3cc2-c2ccc(C)cc2)cc1 ; Cc1ccc(-c2cc3nc4c5ccc(C#N)cc5c5cc(C#N)ccc5c4nc3cc2-c2ccc(C)cc2C)c(C)c1 ; Cc1ccc(C)c(-c2cc3nc4c5ccc(C#N)cc5c5cc(C#N)ccc5c4nc3cc2-c2cc(C)ccc2C)c1]

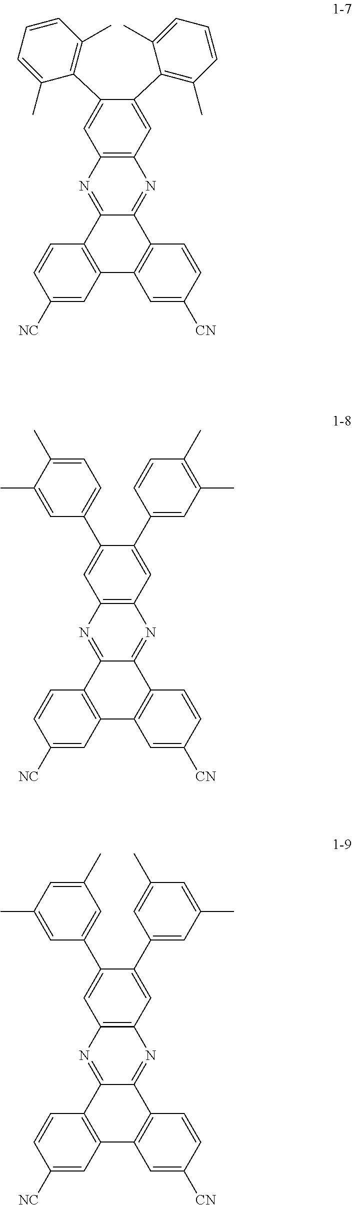

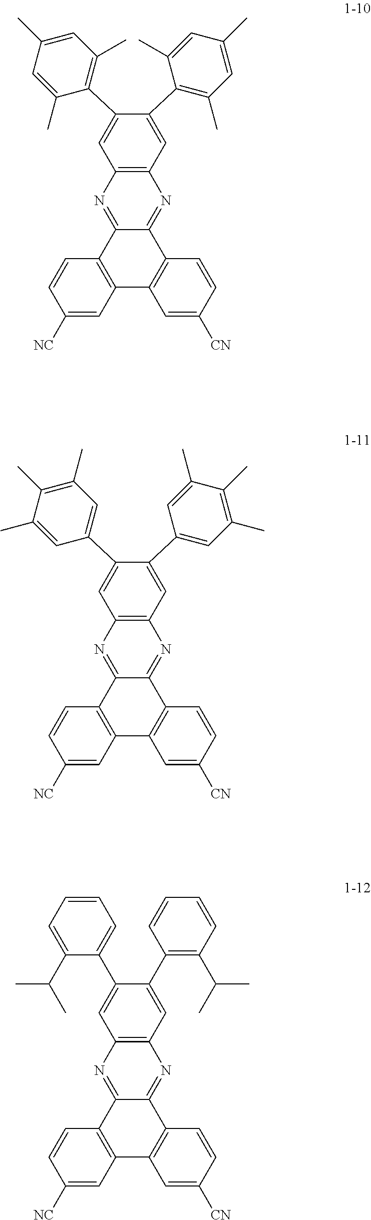

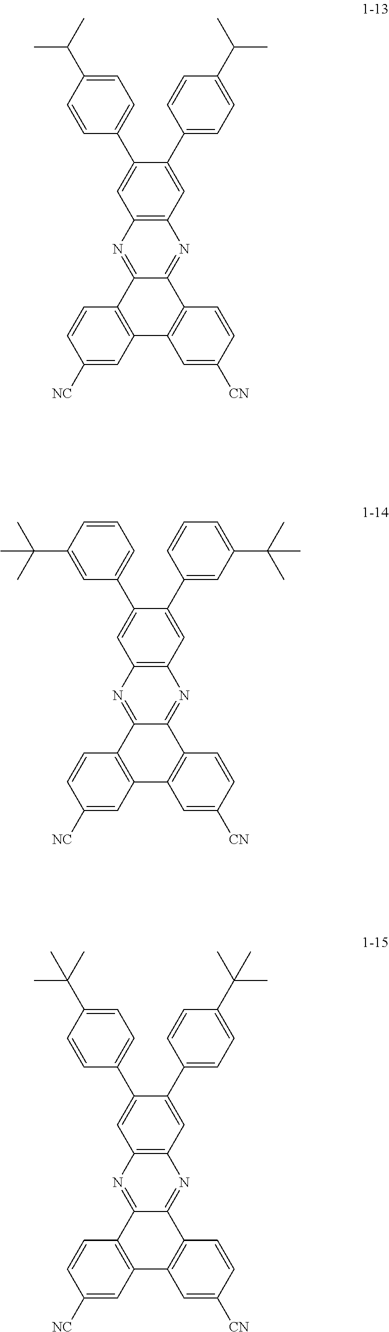

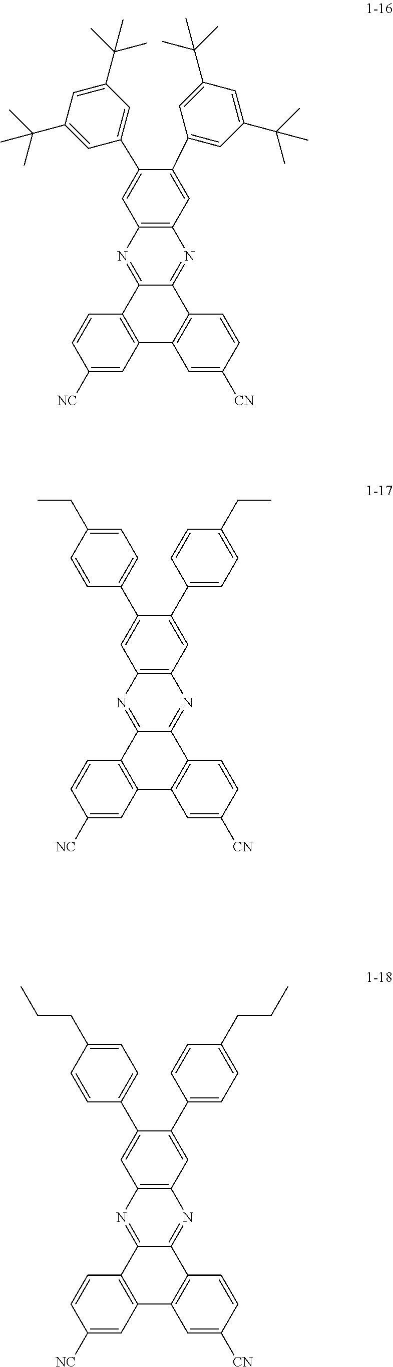

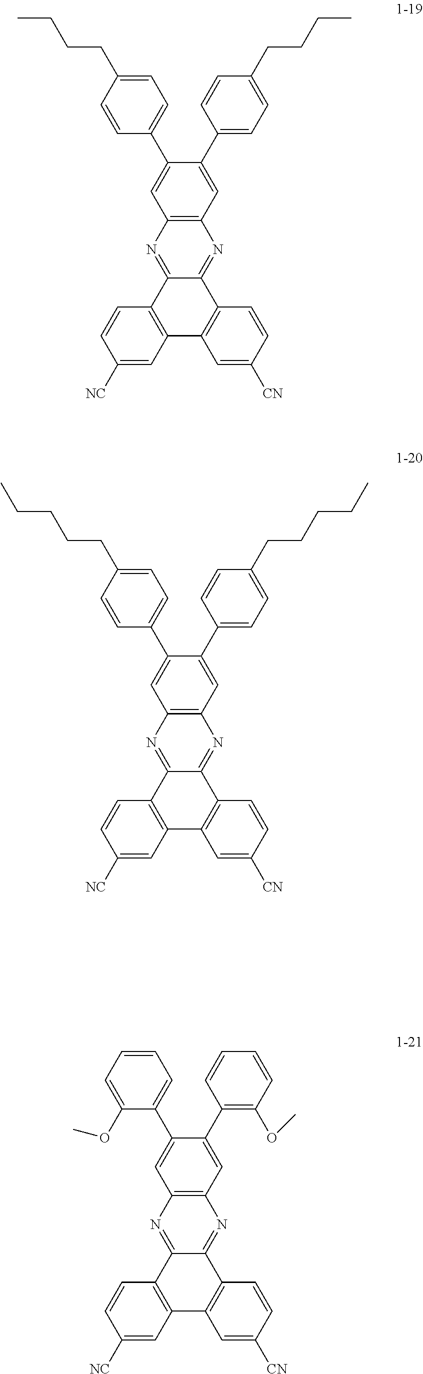

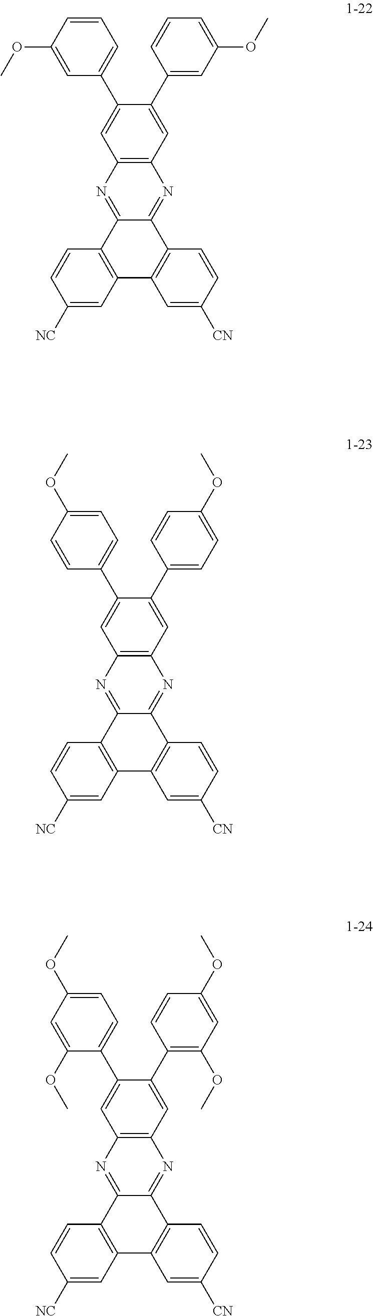

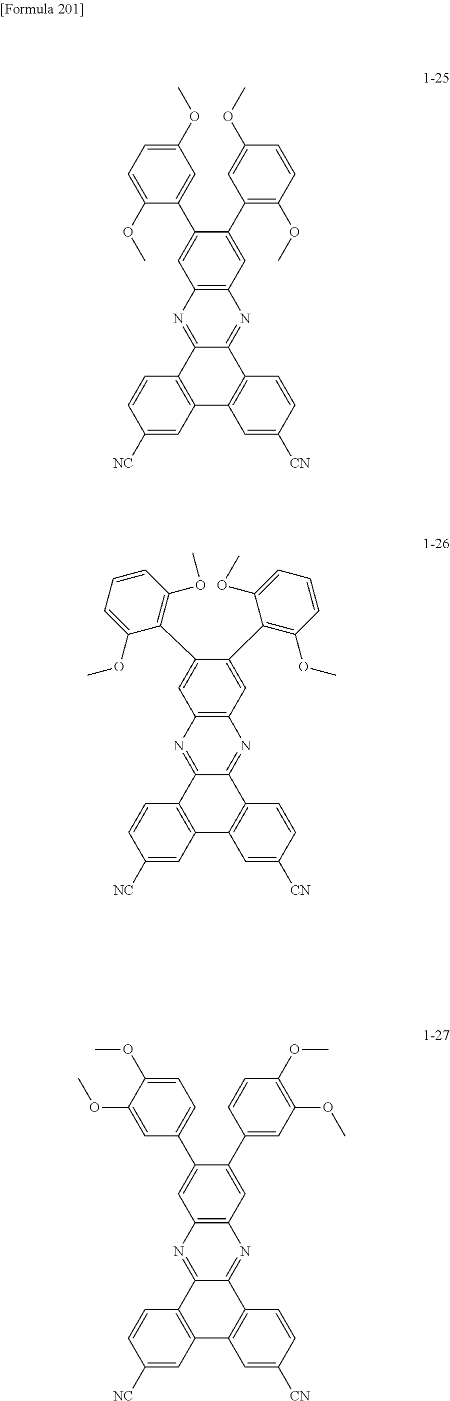

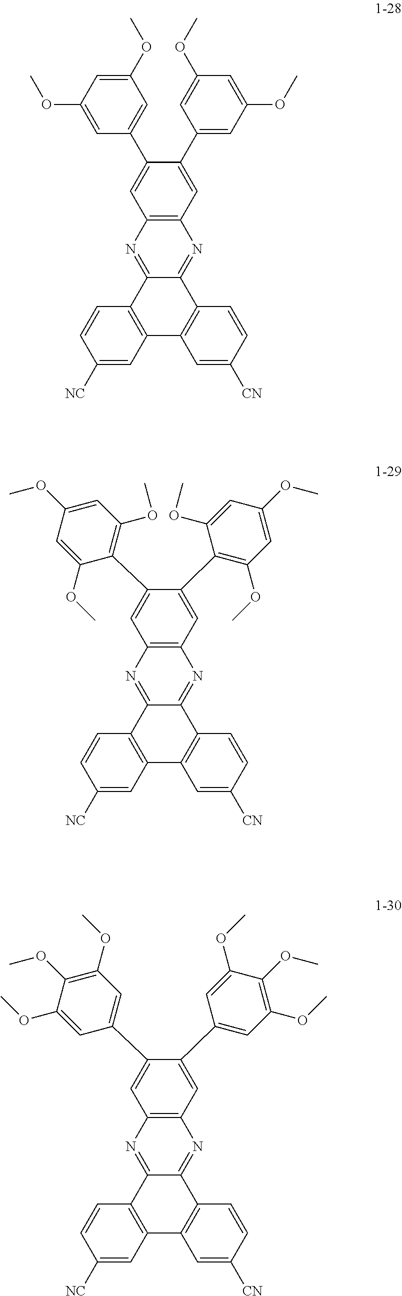

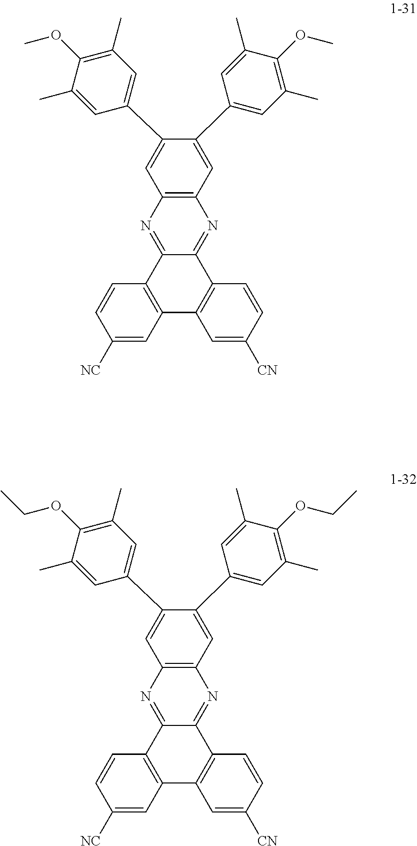

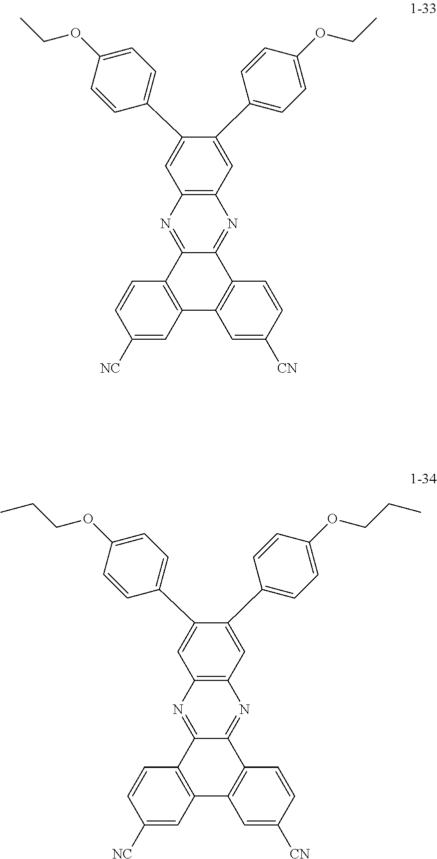

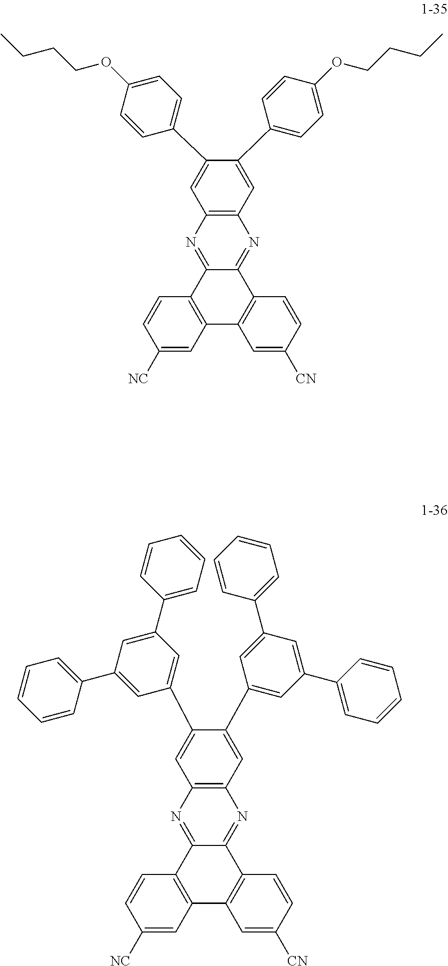 [SMILES: CCCCOc1ccc(-c2cc3nc4c5ccc(C#N)cc5c5cc(C#N)ccc5c4nc3cc2-c2ccc(OCCCC)cc2)cc1 ; N#Cc1ccc2c(c1)c1cc(C#N)ccc1c1nc3cc(-c4cc(-c5ccccc5)cc(-c5ccccc5)c4)c(-c4cc(-c5ccccc5)cc(-c5ccccc5)c4)cc3nc21]

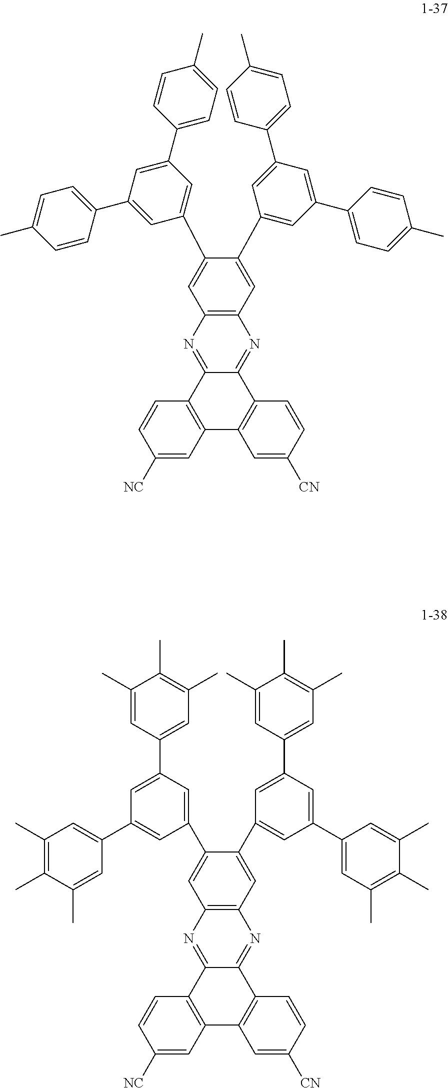

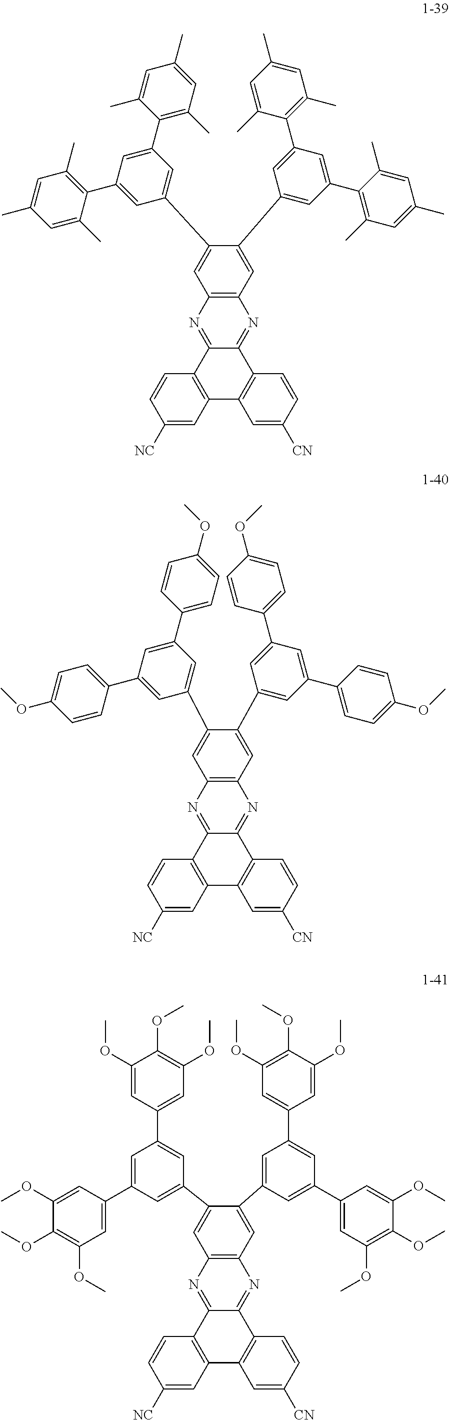

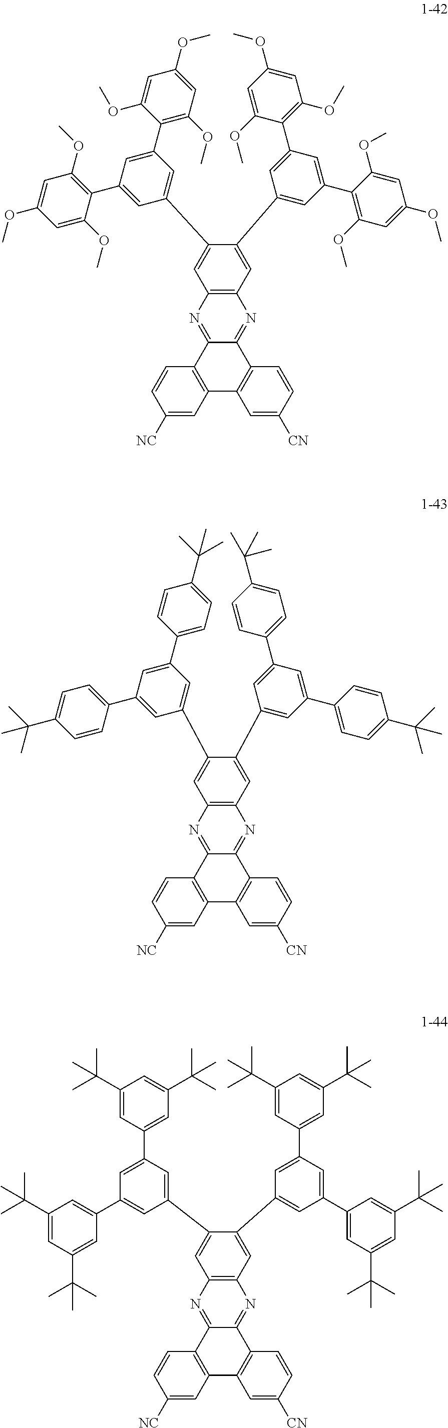

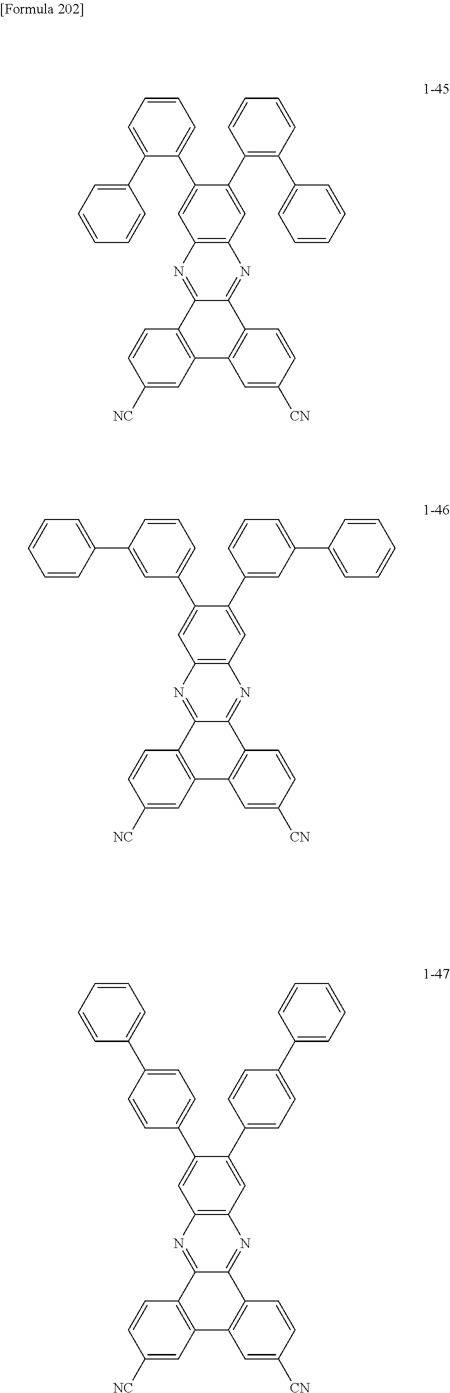 [SMILES: N#Cc1ccc2c(c1)c1cc(C#N)ccc1c1nc3cc(-c4ccccc4-c4ccccc4)c(-c4ccccc4-c4ccccc4)cc3nc21 ; N#Cc1ccc2c(c1)c1cc(C#N)ccc1c1nc3cc(-c4cccc(-c5ccccc5)c4)c(-c4cccc(-c5ccccc5)c4)cc3nc21 ; N#Cc1ccc2c(c1)c1cc(C#N)ccc1c1nc3cc(-c4ccc(-c5ccccc5)cc4)c(-c4ccc(-c5ccccc5)cc4)cc3nc21]

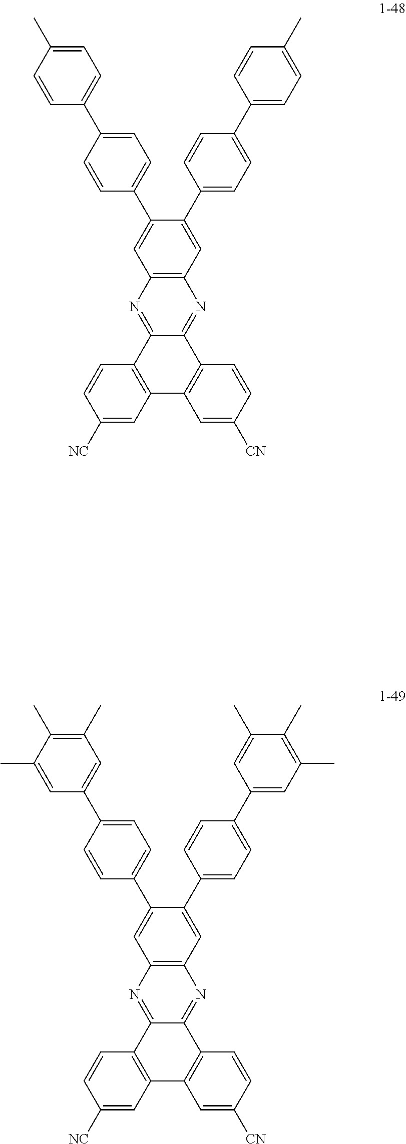

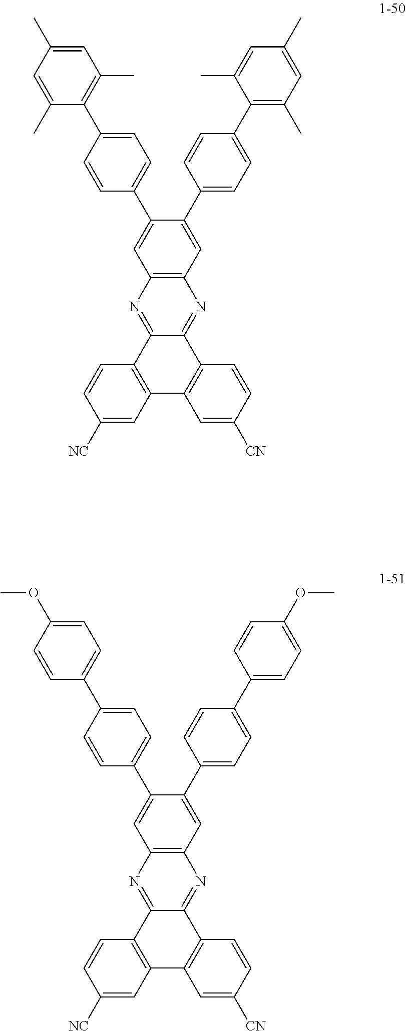

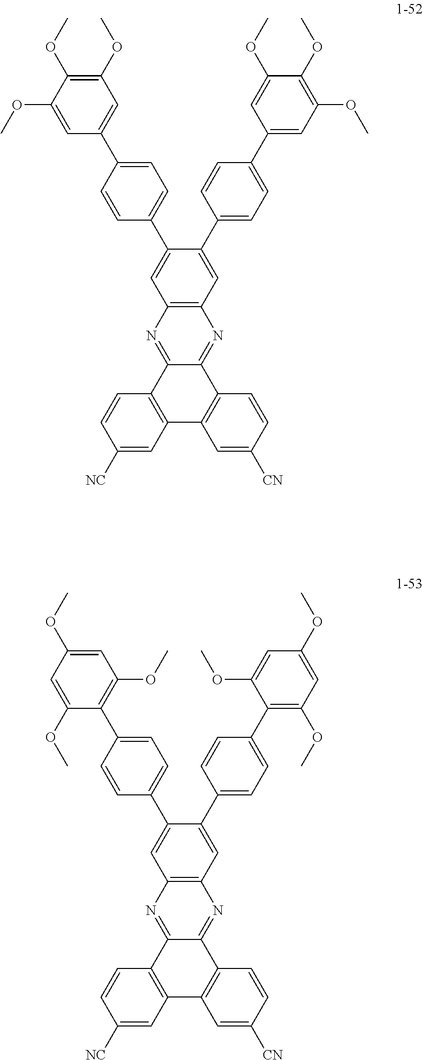

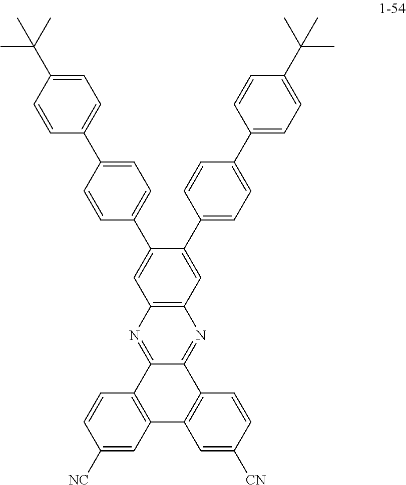 [SMILES: CC(C)(C)c1ccc(-c2ccc(-c3cc4nc5c6ccc(C#N)cc6c6cc(C#N)ccc6c5nc4cc3-c3ccc(-c4ccc(C(C)(C)C)cc4)cc3)cc2)cc1]

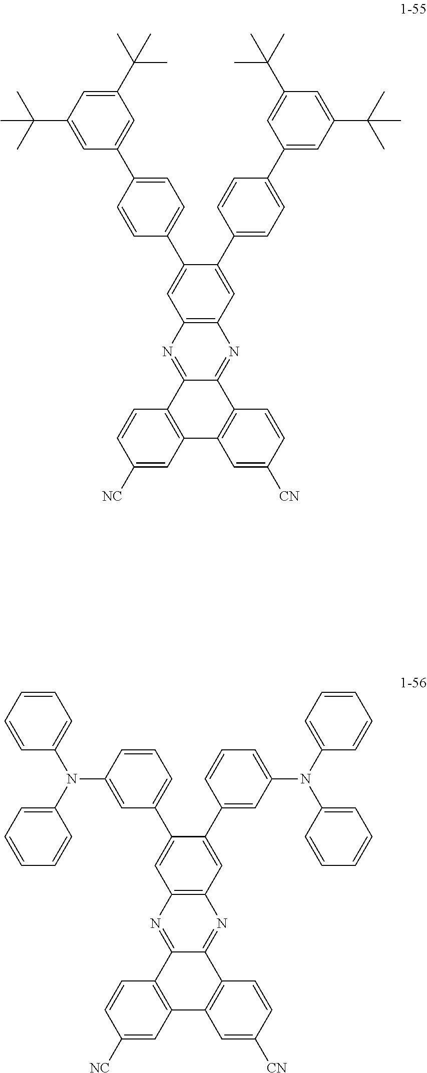 [SMILES: CC(C)(C)c1cc(-c2ccc(-c3cc4nc5c6ccc(C#N)cc6c6cc(C#N)ccc6c5nc4cc3-c3ccc(-c4cc(C(C)(C)C)cc(C(C)(C)C)c4)cc3)cc2)cc(C(C)(C)C)c1 ; N#Cc1ccc2c(c1)c1cc(C#N)ccc1c1nc3cc(-c4cccc(N(c5ccccc5)c5ccccc5)c4)c(-c4cccc(N(c5ccccc5)c5ccccc5)c4)cc3nc21]

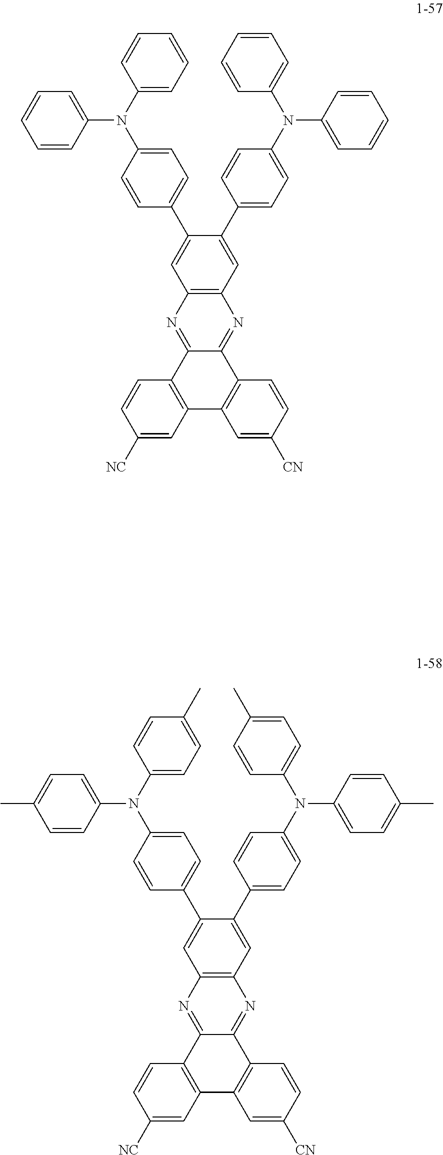

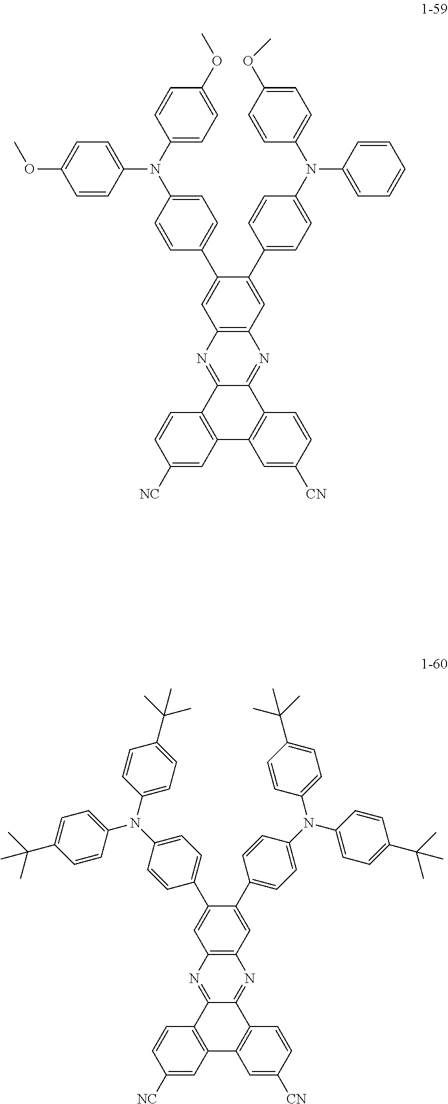 [SMILES: COc1ccc(N(c2ccccc2)c2ccc(-c3cc4nc5c6ccc(C#N)cc6c6cc(C#N)ccc6c5nc4cc3-c3ccc(N(c4ccc(OC)cc4)c4ccc(OC)cc4)cc3)cc2)cc1 ; CC(C)(C)c1ccc(N(c2ccc(-c3cc4nc5c6ccc(C#N)cc6c6cc(C#N)ccc6c5nc4cc3-c3ccc(N(c4ccc(C(C)(C)C)cc4)c4ccc(C(C)(C)C)cc4)cc3)cc2)c2ccc(C(C)(C)C)cc2)cc1]

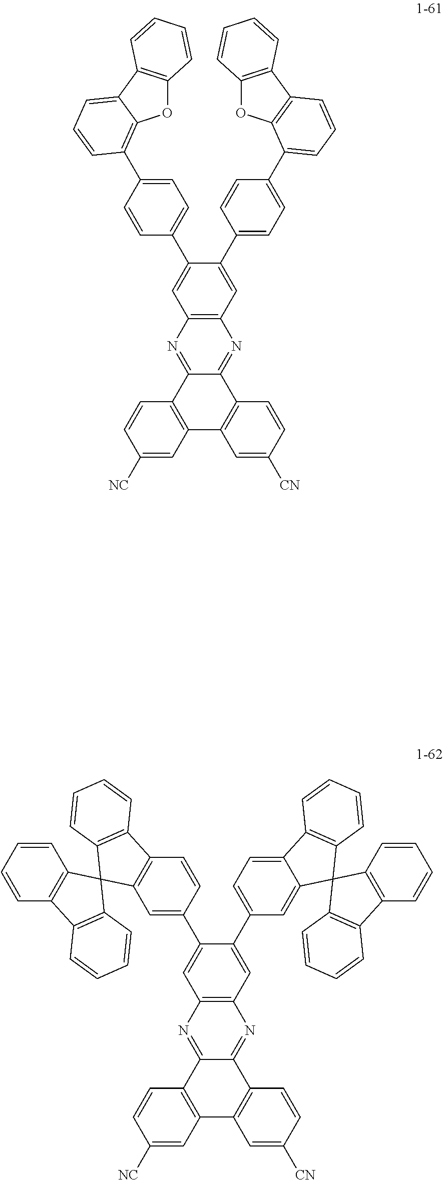 [SMILES: N#Cc1ccc2c(c1)c1cc(C#N)ccc1c1nc3cc(-c4ccc(-c5cccc6c5oc5ccccc56)cc4)c(-c4ccc(-c5cccc6c5oc5ccccc56)cc4)cc3nc21 ; N#Cc1ccc2c(c1)c1cc(C#N)ccc1c1nc3cc(-c4ccc5c(c4)C4(c6ccccc6-c6ccccc64)c4ccccc4-5)c(-c4ccc5c(c4)C4(c6ccccc6-c6ccccc64)c4ccccc4-5)cc3nc21]

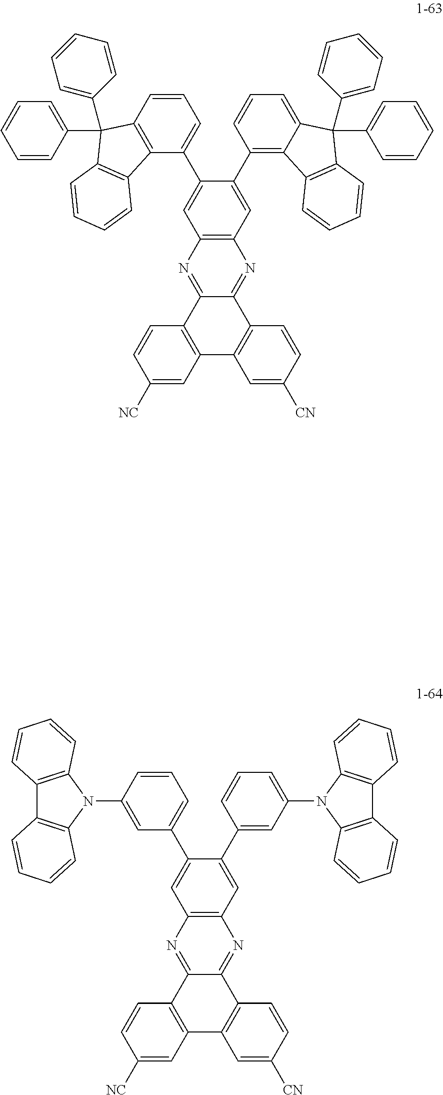 [SMILES: N#Cc1ccc2c(c1)c1cc(C#N)ccc1c1nc3cc(-c4cccc5c4-c4ccccc4C5(c4ccccc4)c4ccccc4)c(-c4cccc5c4-c4ccccc4C5(c4ccccc4)c4ccccc4)cc3nc21 ; N#Cc1ccc2c(c1)c1cc(C#N)ccc1c1nc3cc(-c4cccc(-n5c6ccccc6c6ccccc65)c4)c(-c4cccc(-n5c6ccccc6c6ccccc65)c4)cc3nc21]

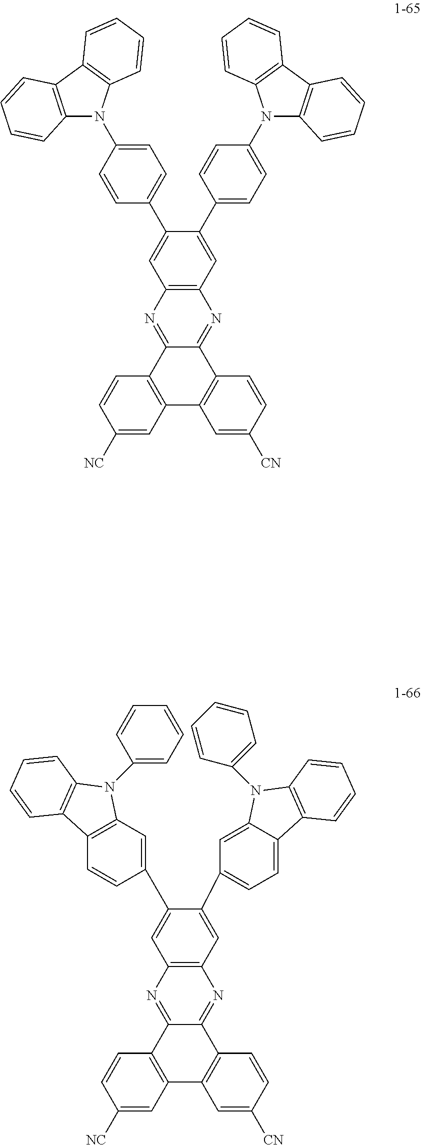 [SMILES: N#Cc1ccc2c(c1)c1cc(C#N)ccc1c1nc3cc(-c4ccc(-n5c6ccccc6c6ccccc65)cc4)c(-c4ccc(-n5c6ccccc6c6ccccc65)cc4)cc3nc21 ; N#Cc1ccc2c(c1)c1cc(C#N)ccc1c1nc3cc(-c4ccc5c6ccccc6n(-c6ccccc6)c5c4)c(-c4ccc5c6ccccc6n(-c6ccccc6)c5c4)cc3nc21]

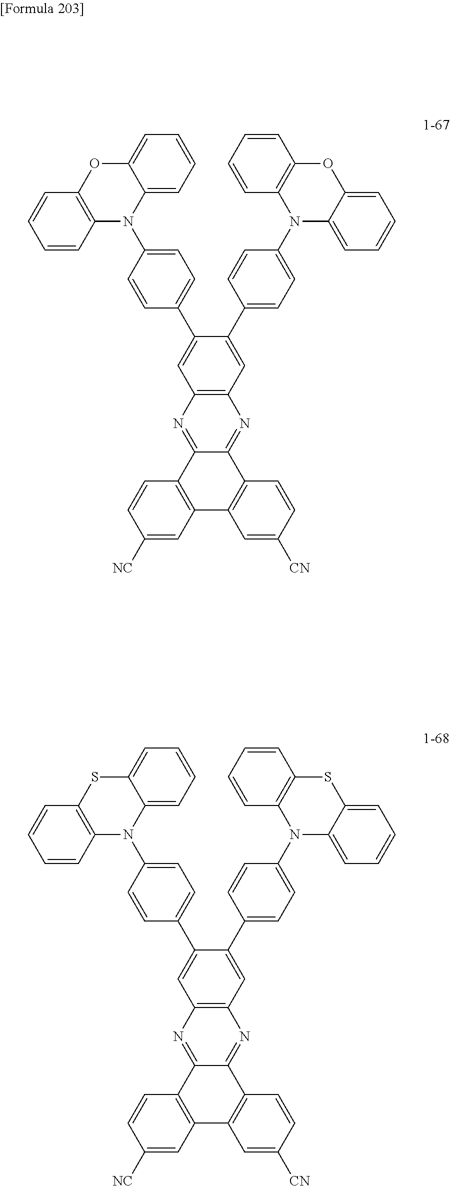 [SMILES: N#Cc1ccc2c(c1)c1cc(C#N)ccc1c1nc3cc(-c4ccc(N5c6ccccc6Oc6ccccc65)cc4)c(-c4ccc(N5c6ccccc6Oc6ccccc65)cc4)cc3nc21 ; N#Cc1ccc2c(c1)c1cc(C#N)ccc1c1nc3cc(-c4ccc(N5c6ccccc6Sc6ccccc65)cc4)c(-c4ccc(N5c6ccccc6Sc6ccccc65)cc4)cc3nc21]

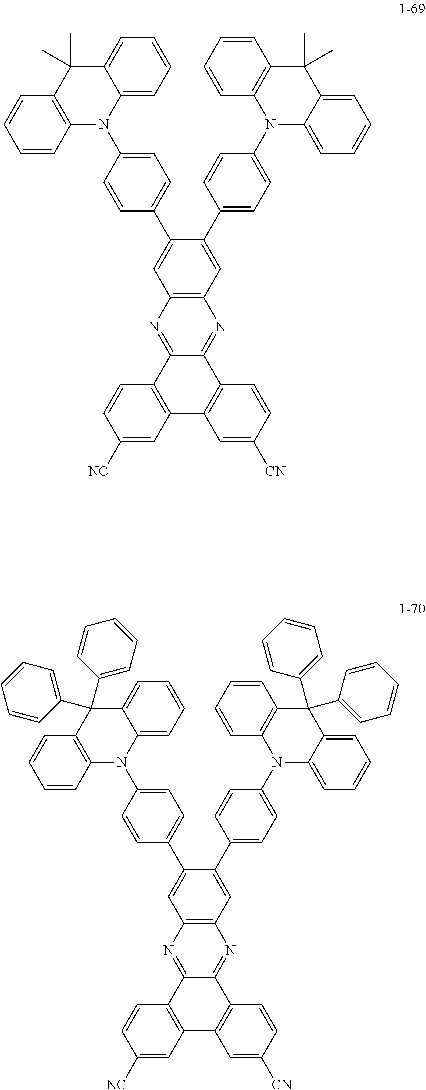 [SMILES: CC1(C)c2ccccc2N(c2ccc(-c3cc4nc5c6ccc(C#N)cc6c6cc(C#N)ccc6c5nc4cc3-c3ccc(N4c5ccccc5C(C)(C)c5ccccc54)cc3)cc2)c2ccccc21 ; N#Cc1ccc2c(c1)c1cc(C#N)ccc1c1nc3cc(-c4ccc(N5c6ccccc6C(c6ccccc6)(c6ccccc6)c6ccccc65)cc4)c(-c4ccc(N5c6ccccc6C(c6ccccc6)(c6ccccc6)c6ccccc65)cc4)cc3nc21]

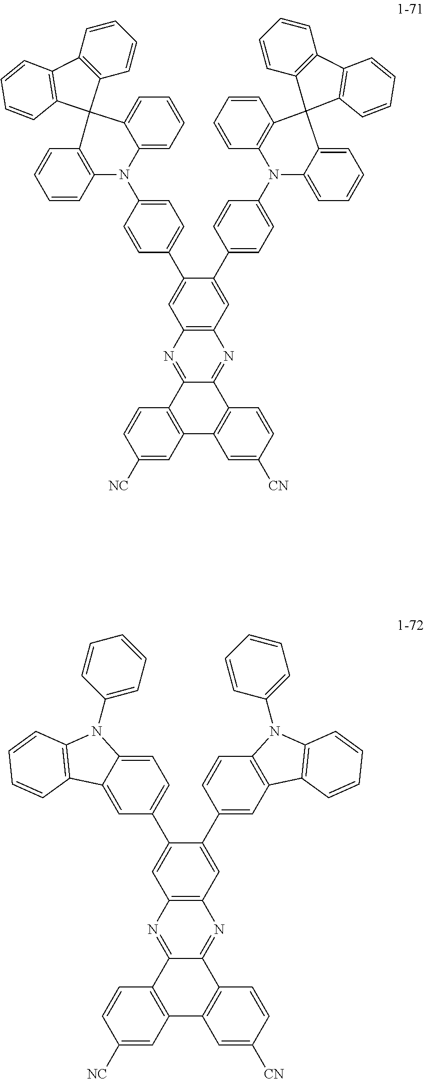 [SMILES: N#Cc1ccc2c(c1)c1cc(C#N)ccc1c1nc3cc(-c4ccc(N5c6ccccc6C6(c7ccccc7-c7ccccc76)c6ccccc65)cc4)c(-c4ccc(N5c6ccccc6C6(c7ccccc7-c7ccccc76)c6ccccc65)cc4)cc3nc21 ; N#Cc1ccc2c(c1)c1cc(C#N)ccc1c1nc3cc(-c4ccc5c(c4)c4ccccc4n5-c4ccccc4)c(-c4ccc5c(c4)c4ccccc4n5-c4ccccc4)cc3nc21]

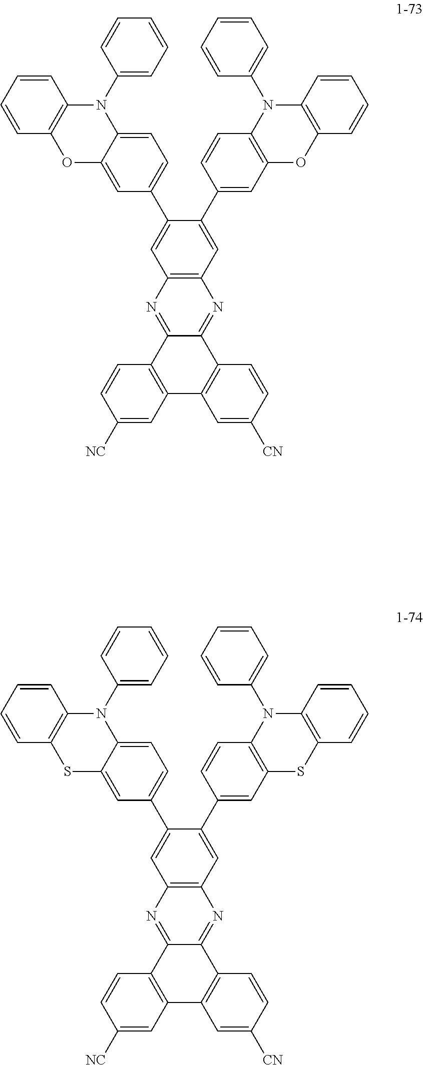 [SMILES: N#Cc1ccc2c(c1)c1cc(C#N)ccc1c1nc3cc(-c4ccc5c(c4)Oc4ccccc4N5c4ccccc4)c(-c4ccc5c(c4)Oc4ccccc4N5c4ccccc4)cc3nc21 ; N#Cc1ccc2c(c1)c1cc(C#N)ccc1c1nc3cc(-c4ccc5c(c4)Sc4ccccc4N5c4ccccc4)c(-c4ccc5c(c4)Sc4ccccc4N5c4ccccc4)cc3nc21]

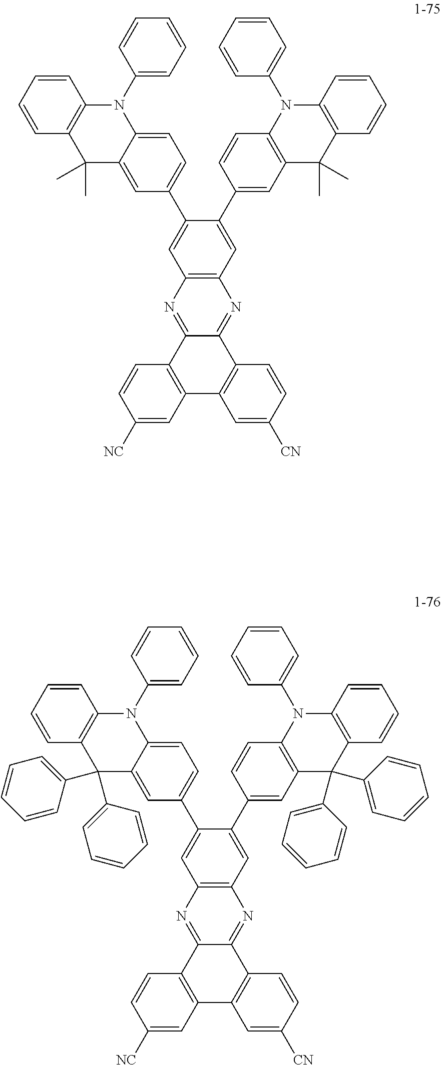 [SMILES: CC1(C)c2ccccc2N(c2ccccc2)c2ccc(-c3cc4nc5c6ccc(C#N)cc6c6cc(C#N)ccc6c5nc4cc3-c3ccc4c(c3)C(C)(C)c3ccccc3N4c3ccccc3)cc21 ; N#Cc1ccc2c(c1)c1cc(C#N)ccc1c1nc3cc(-c4ccc5c(c4)C(c4ccccc4)(c4ccccc4)c4ccccc4N5c4ccccc4)c(-c4ccc5c(c4)C(c4ccccc4)(c4ccccc4)c4ccccc4N5c4ccccc4)cc3nc21]

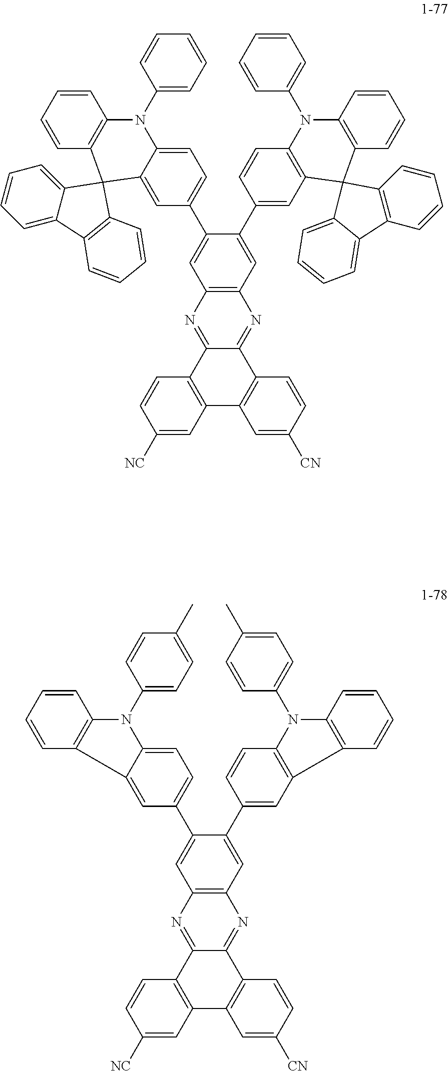 [SMILES: N#Cc1ccc2c(c1)c1cc(C#N)ccc1c1nc3cc(-c4ccc5c(c4)C4(c6ccccc6-c6ccccc64)c4ccccc4N5c4ccccc4)c(-c4ccc5c(c4)C4(c6ccccc6-c6ccccc64)c4ccccc4N5c4ccccc4)cc3nc21 ; Cc1ccc(-n2c3ccccc3c3cc(-c4cc5nc6c7ccc(C#N)cc7c7cc(C#N)ccc7c6nc5cc4-c4ccc5c(c4)c4ccccc4n5-c4ccc(C)cc4)ccc32)cc1]

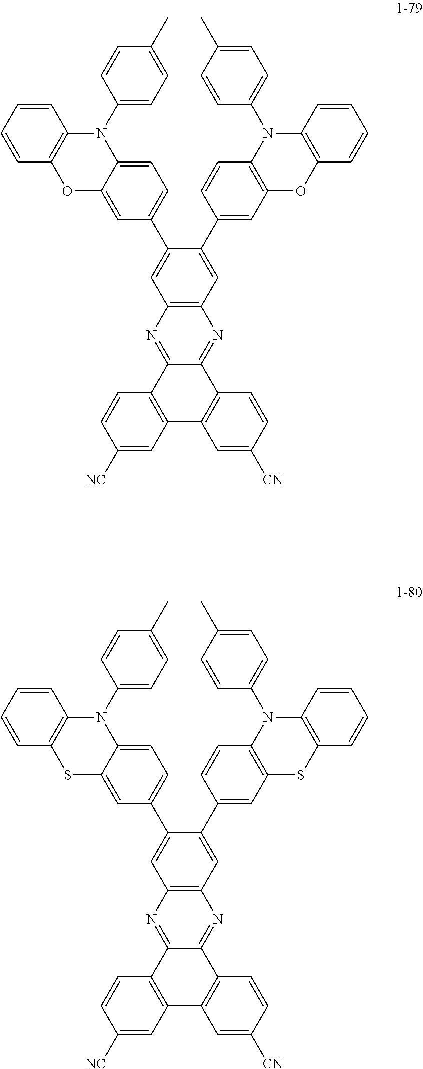 [SMILES: Cc1ccc(N2c3ccccc3Oc3cc(-c4cc5nc6c7ccc(C#N)cc7c7cc(C#N)ccc7c6nc5cc4-c4ccc5c(c4)Oc4ccccc4N5c4ccc(C)cc4)ccc32)cc1 ; Cc1ccc(N2c3ccccc3Sc3cc(-c4cc5nc6c7ccc(C#N)cc7c7cc(C#N)ccc7c6nc5cc4-c4ccc5c(c4)Sc4ccccc4N5c4ccc(C)cc4)ccc32)cc1]

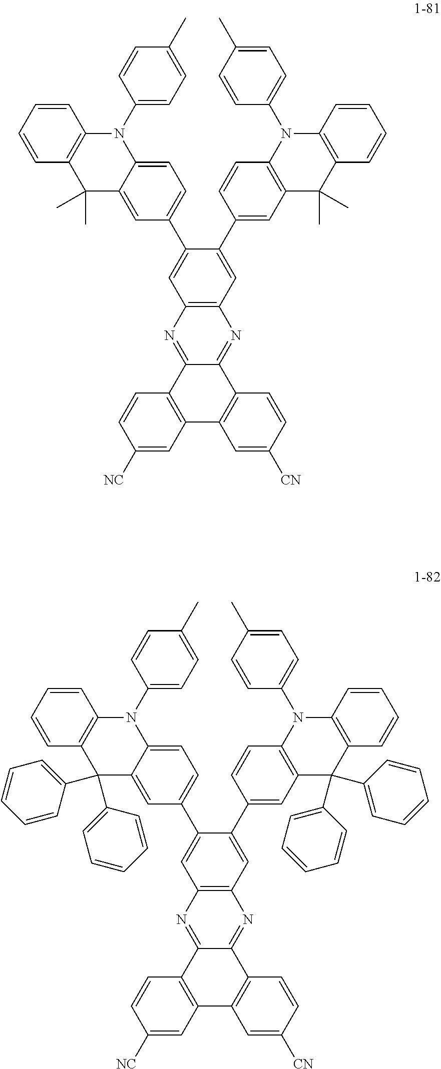 [SMILES: Cc1ccc(N2c3ccccc3C(C)(C)c3cc(-c4cc5nc6c7ccc(C#N)cc7c7cc(C#N)ccc7c6nc5cc4-c4ccc5c(c4)C(C)(C)c4ccccc4N5c4ccc(C)cc4)ccc32)cc1 ; Cc1ccc(N2c3ccccc3C(c3ccccc3)(c3ccccc3)c3cc(-c4cc5nc6c7ccc(C#N)cc7c7cc(C#N)ccc7c6nc5cc4-c4ccc5c(c4)C(c4ccccc4)(c4ccccc4)c4ccccc4N5c4ccc(C)cc4)ccc32)cc1]

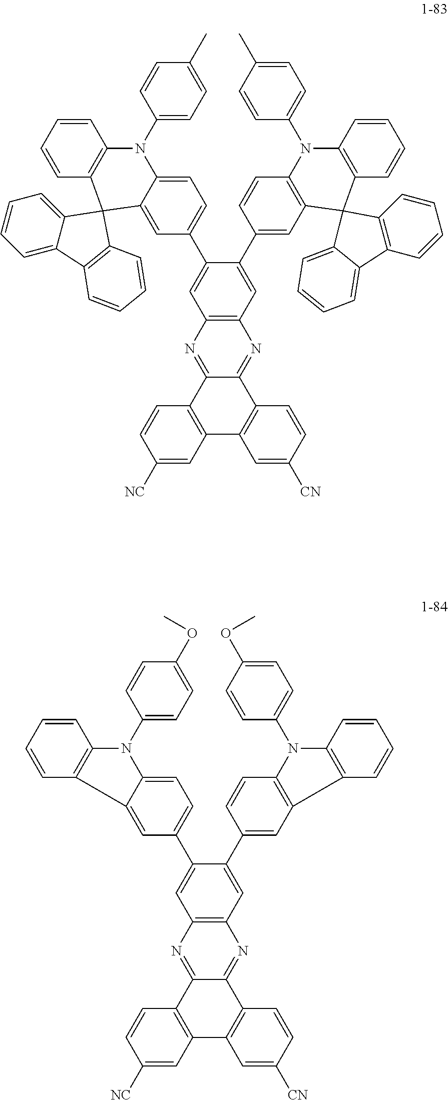 [SMILES: Cc1ccc(N2c3ccccc3C3(c4ccccc4-c4ccccc43)c3cc(-c4cc5nc6c7ccc(C#N)cc7c7cc(C#N)ccc7c6nc5cc4-c4ccc5c(c4)C4(c6ccccc6-c6ccccc64)c4ccccc4N5c4ccc(C)cc4)ccc32)cc1 ; COc1ccc(-n2c3ccccc3c3cc(-c4cc5nc6c7ccc(C#N)cc7c7cc(C#N)ccc7c6nc5cc4-c4ccc5c(c4)c4ccccc4n5-c4ccc(OC)cc4)ccc32)cc1]

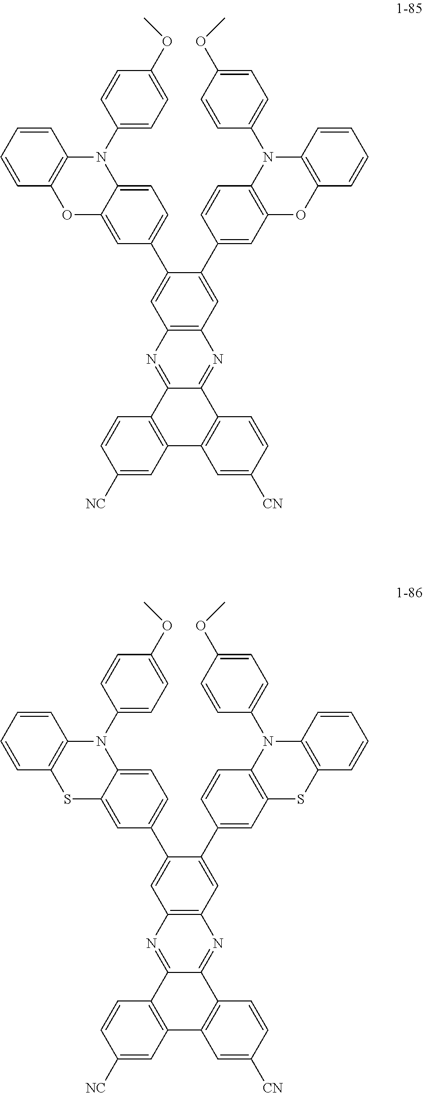 [SMILES: COc1ccc(N2c3ccccc3Oc3cc(-c4cc5nc6c7ccc(C#N)cc7c7cc(C#N)ccc7c6nc5cc4-c4ccc5c(c4)Oc4ccccc4N5c4ccc(OC)cc4)ccc32)cc1 ; COc1ccc(N2c3ccccc3Sc3cc(-c4cc5nc6c7ccc(C#N)cc7c7cc(C#N)ccc7c6nc5cc4-c4ccc5c(c4)Sc4ccccc4N5c4ccc(OC)cc4)ccc32)cc1]

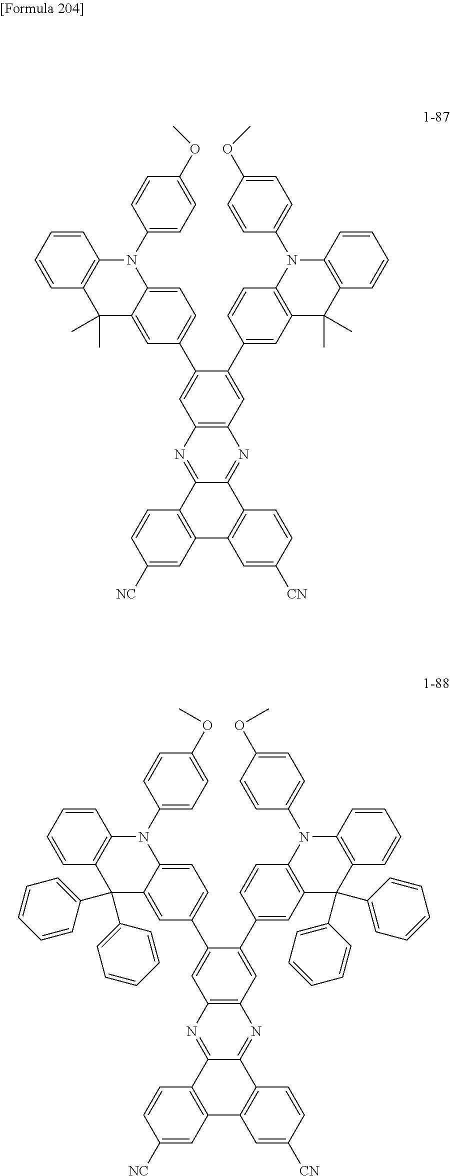 [SMILES: COc1ccc(N2c3ccccc3C(C)(C)c3cc(-c4cc5nc6c7ccc(C#N)cc7c7cc(C#N)ccc7c6nc5cc4-c4ccc5c(c4)C(C)(C)c4ccccc4N5c4ccc(OC)cc4)ccc32)cc1 ; COc1ccc(N2c3ccccc3C(c3ccccc3)(c3ccccc3)c3cc(-c4cc5nc6c7ccc(C#N)cc7c7cc(C#N)ccc7c6nc5cc4-c4ccc5c(c4)C(c4ccccc4)(c4ccccc4)c4ccccc4N5c4ccc(OC)cc4)ccc32)cc1]

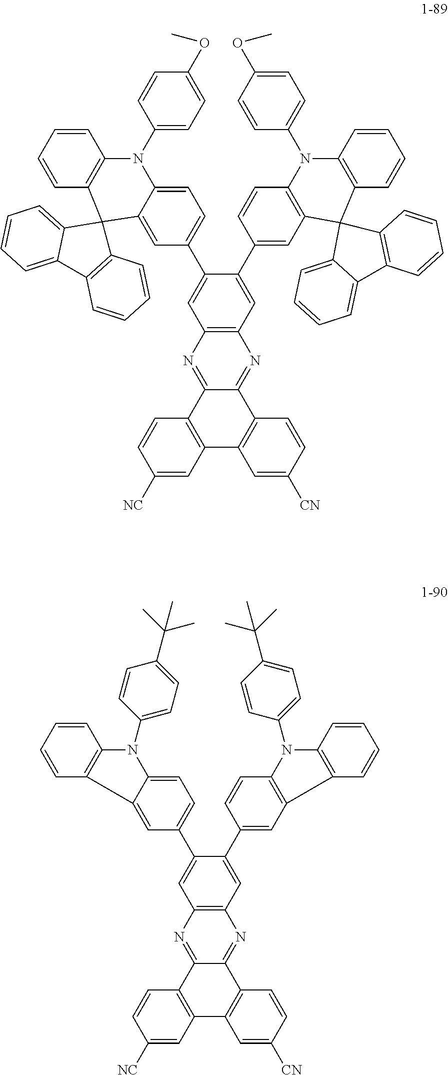 [SMILES: COc1ccc(N2c3ccccc3C3(c4ccccc4-c4ccccc43)c3cc(-c4cc5nc6c7ccc(C#N)cc7c7cc(C#N)ccc7c6nc5cc4-c4ccc5c(c4)C4(c6ccccc6-c6ccccc64)c4ccccc4N5c4ccc(OC)cc4)ccc32)cc1 ; CC(C)(C)c1ccc(-n2c3ccccc3c3cc(-c4cc5nc6c7ccc(C#N)cc7c7cc(C#N)ccc7c6nc5cc4-c4ccc5c(c4)c4ccccc4n5-c4ccc(C(C)(C)C)cc4)ccc32)cc1]

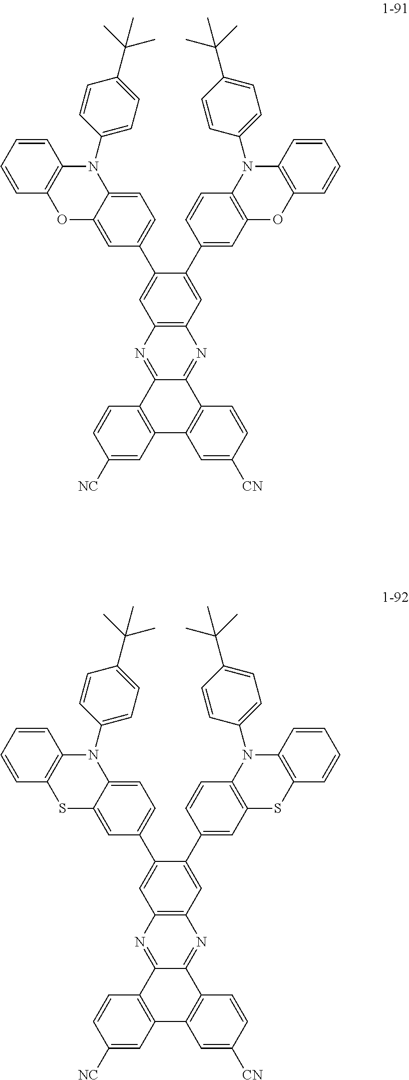 [SMILES: CC(C)(C)c1ccc(N2c3ccccc3Oc3cc(-c4cc5nc6c7ccc(C#N)cc7c7cc(C#N)ccc7c6nc5cc4-c4ccc5c(c4)Oc4ccccc4N5c4ccc(C(C)(C)C)cc4)ccc32)cc1 ; CC(C)(C)c1ccc(N2c3ccccc3Sc3cc(-c4cc5nc6c7ccc(C#N)cc7c7cc(C#N)ccc7c6nc5cc4-c4ccc5c(c4)Sc4ccccc4N5c4ccc(C(C)(C)C)cc4)ccc32)cc1]

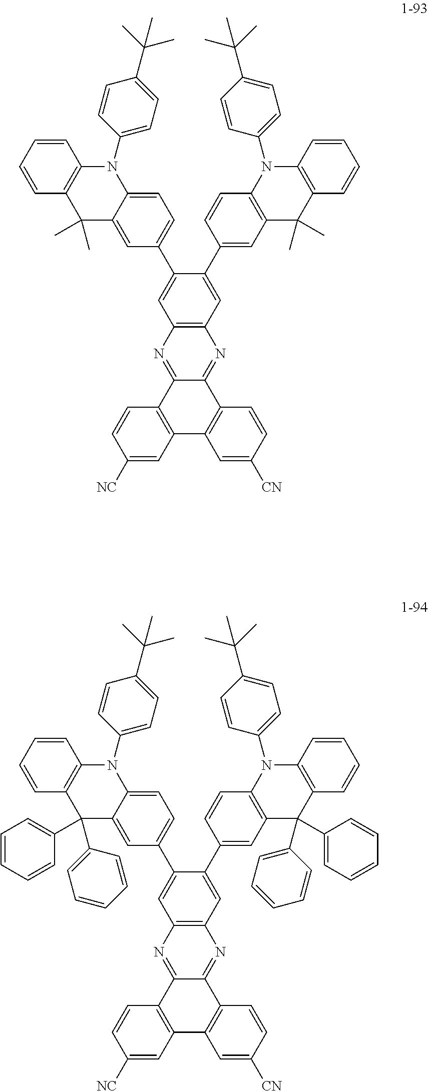 [SMILES: CC(C)(C)c1ccc(N2c3ccccc3C(C)(C)c3cc(-c4cc5nc6c7ccc(C#N)cc7c7cc(C#N)ccc7c6nc5cc4-c4ccc5c(c4)C(C)(C)c4ccccc4N5c4ccc(C(C)(C)C)cc4)ccc32)cc1 ; CC(C)(C)c1ccc(N2c3ccccc3C(c3ccccc3)(c3ccccc3)c3cc(-c4cc5nc6c7ccc(C#N)cc7c7cc(C#N)ccc7c6nc5cc4-c4ccc5c(c4)C(c4ccccc4)(c4ccccc4)c4ccccc4N5c4ccc(C(C)(C)C)cc4)ccc32)cc1]

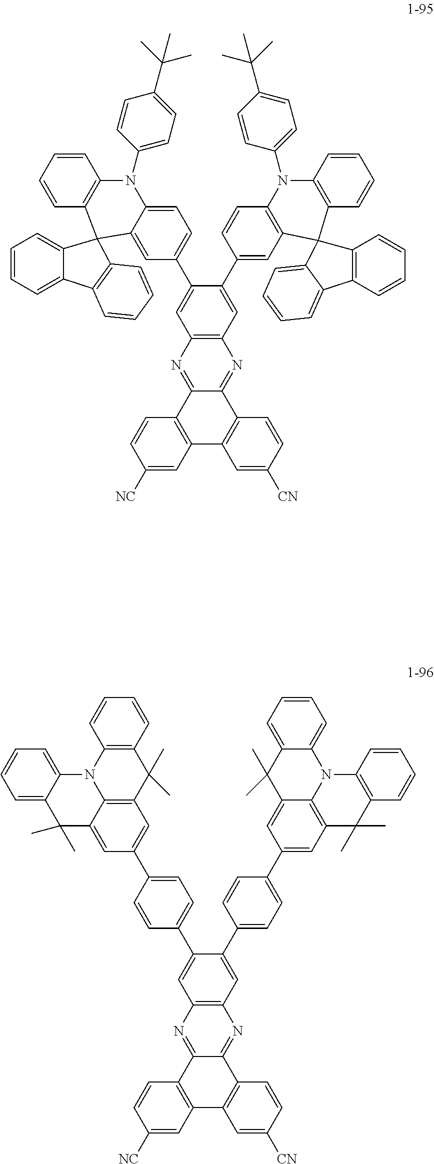 [SMILES: CC(C)(C)c1ccc(N2c3ccccc3C3(c4ccccc4-c4ccccc43)c3cc(-c4cc5nc6c7ccc(C#N)cc7c7cc(C#N)ccc7c6nc5cc4-c4ccc5c(c4)C4(c6ccccc6-c6ccccc64)c4ccccc4N5c4ccc(C(C)(C)C)cc4)ccc32)cc1 ; CC1(C)c2ccccc2N2c3ccccc3C(C)(C)c3cc(-c4ccc(-c5cc6nc7c8ccc(C#N)cc8c8cc(C#N)ccc8c7nc6cc5-c5ccc(-c6cc7c8c(c6)C(C)(C)c6ccccc6N8c6ccccc6C7(C)C)cc5)cc4)cc1c32]

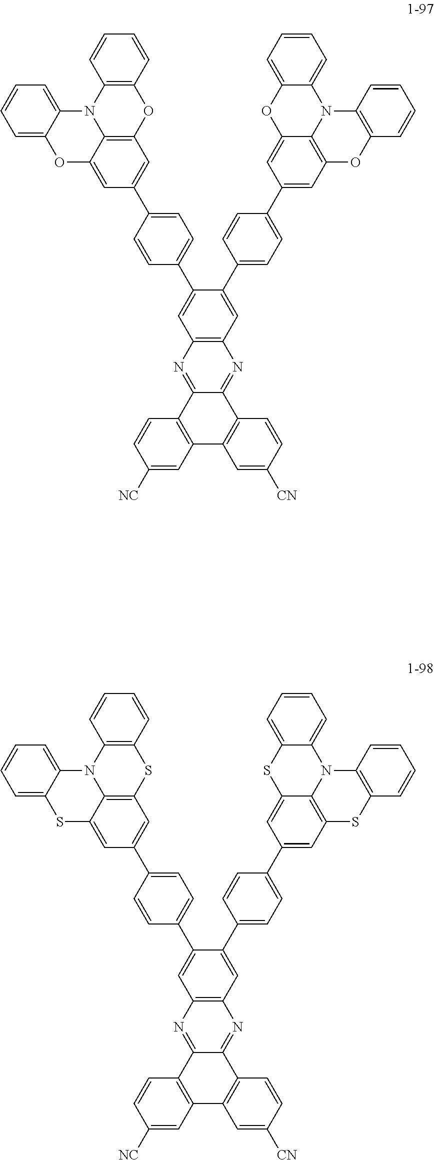 [SMILES: N#Cc1ccc2c(c1)c1cc(C#N)ccc1c1nc3cc(-c4ccc(-c5cc6c7c(c5)Oc5ccccc5N7c5ccccc5O6)cc4)c(-c4ccc(-c5cc6c7c(c5)Oc5ccccc5N7c5ccccc5O6)cc4)cc3nc21 ; N#Cc1ccc2c(c1)c1cc(C#N)ccc1c1nc3cc(-c4ccc(-c5cc6c7c(c5)Sc5ccccc5N7c5ccccc5S6)cc4)c(-c4ccc(-c5cc6c7c(c5)Sc5ccccc5N7c5ccccc5S6)cc4)cc3nc21]

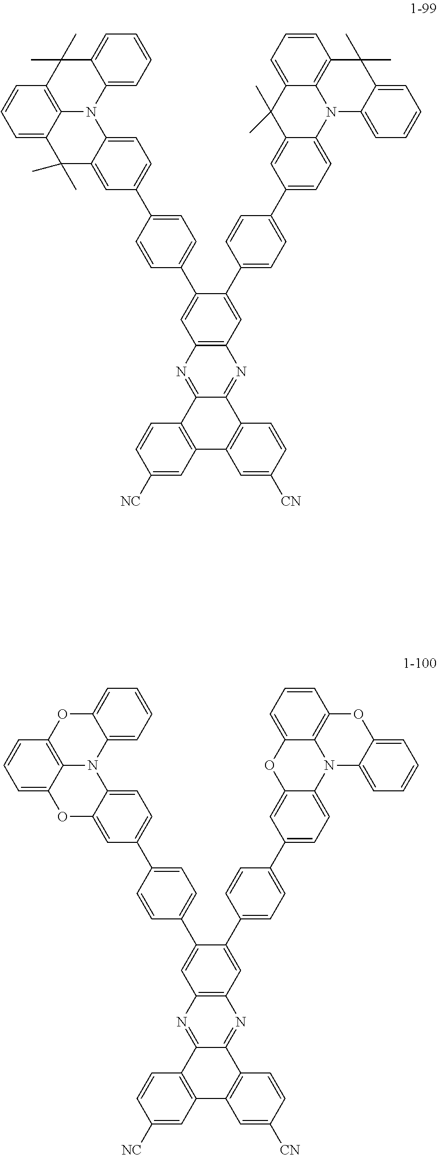 [SMILES: CC1(C)c2ccccc2N2c3ccc(-c4ccc(-c5cc6nc7c8ccc(C#N)cc8c8cc(C#N)ccc8c7nc6cc5-c5ccc(-c6ccc7c(c6)C(C)(C)c6cccc8c6N7c6ccccc6C8(C)C)cc5)cc4)cc3C(C)(C)c3cccc1c32 ; N#Cc1ccc2c(c1)c1cc(C#N)ccc1c1nc3cc(-c4ccc(-c5ccc6c(c5)Oc5cccc7c5N6c5ccccc5O7)cc4)c(-c4ccc(-c5ccc6c(c5)Oc5cccc7c5N6c5ccccc5O7)cc4)cc3nc21]

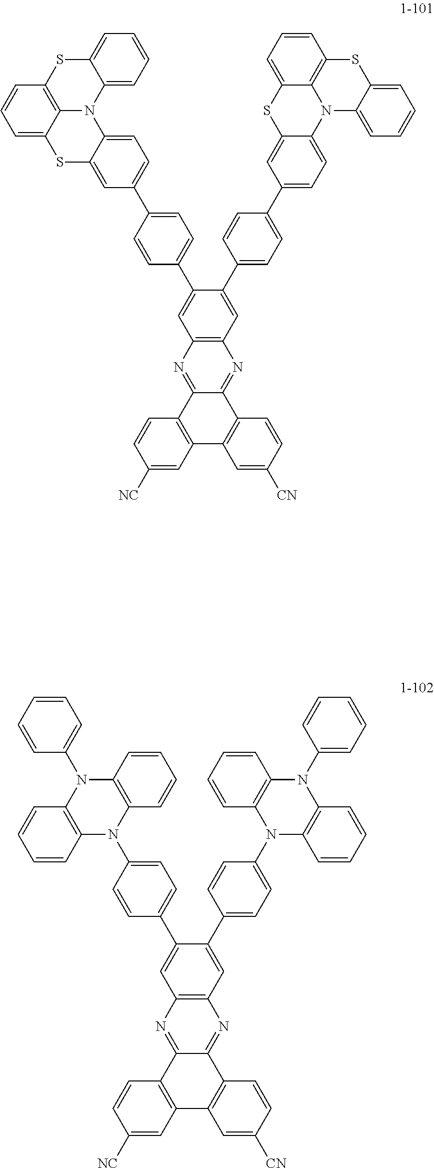 [SMILES: N#Cc1ccc2c(c1)c1cc(C#N)ccc1c1nc3cc(-c4ccc(-c5ccc6c(c5)Sc5cccc7c5N6c5ccccc5S7)cc4)c(-c4ccc(-c5ccc6c(c5)Sc5cccc7c5N6c5ccccc5S7)cc4)cc3nc21 ; N#Cc1ccc2c(c1)c1cc(C#N)ccc1c1nc3cc(-c4ccc(N5c6ccccc6N(c6ccccc6)c6ccccc65)cc4)c(-c4ccc(N5c6ccccc6N(c6ccccc6)c6ccccc65)cc4)cc3nc21]

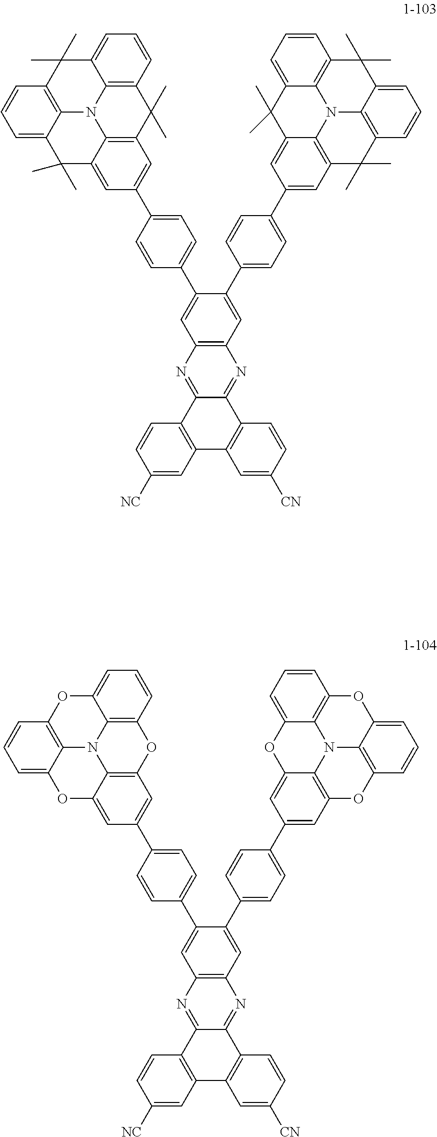 [SMILES: CC1(C)c2cccc3c2N2c4c1cccc4C(C)(C)c1cc(-c4ccc(-c5cc6nc7c8ccc(C#N)cc8c8cc(C#N)ccc8c7nc6cc5-c5ccc(-c6cc7c8c(c6)C(C)(C)c6cccc9c6N8c6c(cccc6C7(C)C)C9(C)C)cc5)cc4)cc(c12)C3(C)C ; N#Cc1ccc2c(c1)c1cc(C#N)ccc1c1nc3cc(-c4ccc(-c5cc6c7c(c5)Oc5cccc8c5N7c5c(cccc5O6)O8)cc4)c(-c4ccc(-c5cc6c7c(c5)Oc5cccc8c5N7c5c(cccc5O6)O8)cc4)cc3nc21]

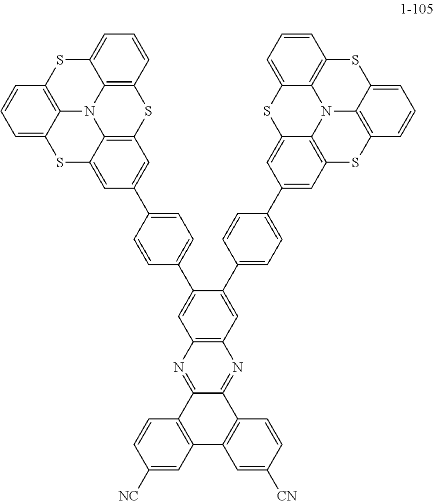 [SMILES: N#Cc1ccc2c(c1)c1cc(C#N)ccc1c1nc3cc(-c4ccc(-c5cc6c7c(c5)Sc5cccc8c5N7c5c(cccc5S6)S8)cc4)c(-c4ccc(-c5cc6c7c(c5)Sc5cccc8c5N7c5c(cccc5S6)S8)cc4)cc3nc21]

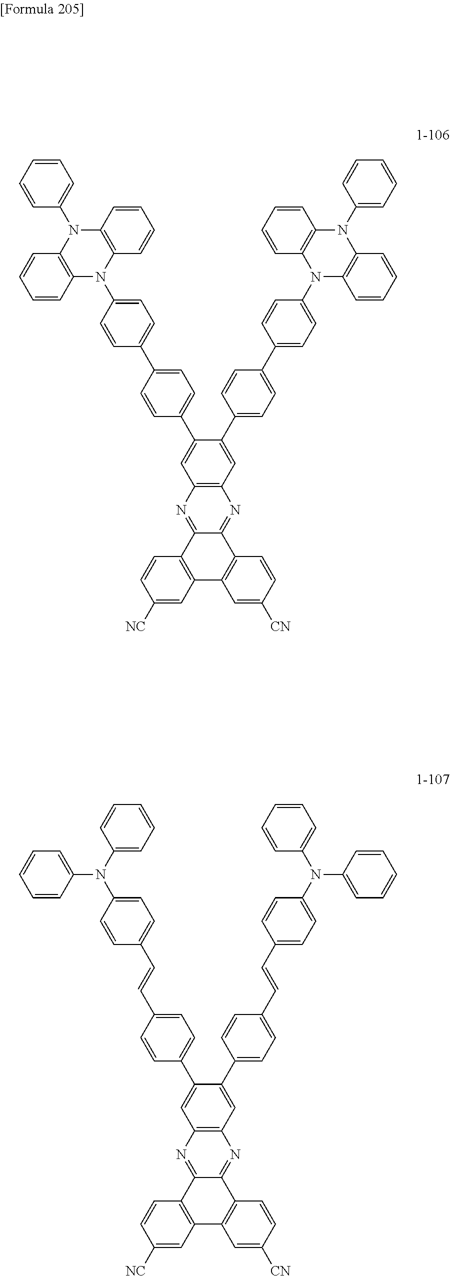 [SMILES: N#Cc1ccc2c(c1)c1cc(C#N)ccc1c1nc3cc(-c4ccc(-c5ccc(N6c7ccccc7N(c7ccccc7)c7ccccc76)cc5)cc4)c(-c4ccc(-c5ccc(N6c7ccccc7N(c7ccccc7)c7ccccc76)cc5)cc4)cc3nc21 ; N#Cc1ccc2c(c1)c1cc(C#N)ccc1c1nc3cc(-c4ccc(/C=C/c5ccc(N(c6ccccc6)c6ccccc6)cc5)cc4)c(-c4ccc(/C=C/c5ccc(N(c6ccccc6)c6ccccc6)cc5)cc4)cc3nc21]

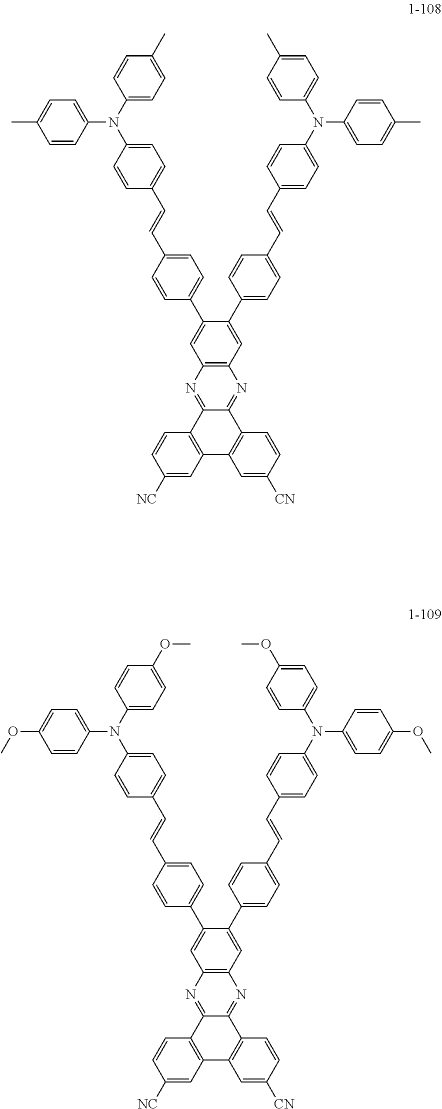

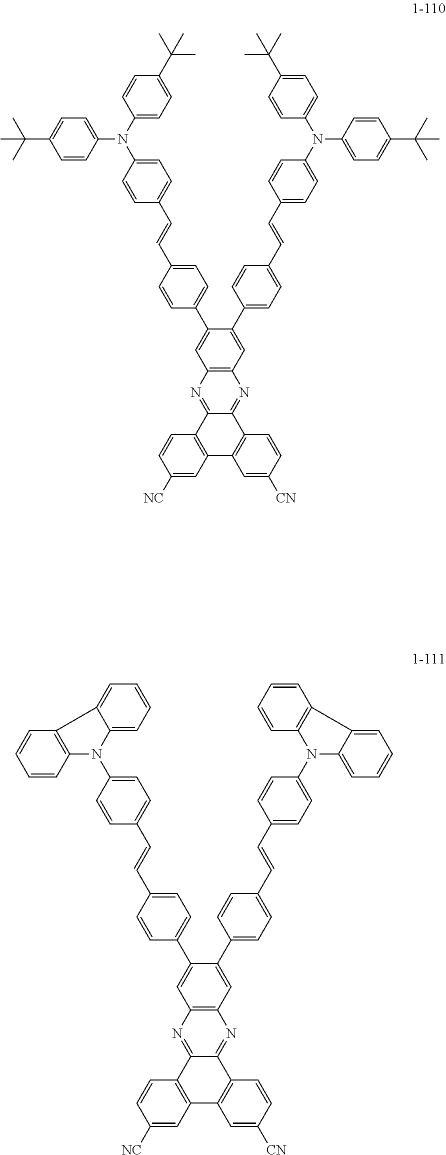 [SMILES: CC(C)(C)c1ccc(N(c2ccc(/C=C/c3ccc(-c4cc5nc6c7ccc(C#N)cc7c7cc(C#N)ccc7c6nc5cc4-c4ccc(/C=C/c5ccc(N(c6ccc(C(C)(C)C)cc6)c6ccc(C(C)(C)C)cc6)cc5)cc4)cc3)cc2)c2ccc(C(C)(C)C)cc2)cc1 ; N#Cc1ccc2c(c1)c1cc(C#N)ccc1c1nc3cc(-c4ccc(/C=C/c5ccc(-n6c7ccccc7c7ccccc76)cc5)cc4)c(-c4ccc(/C=C/c5ccc(-n6c7ccccc7c7ccccc76)cc5)cc4)cc3nc21]

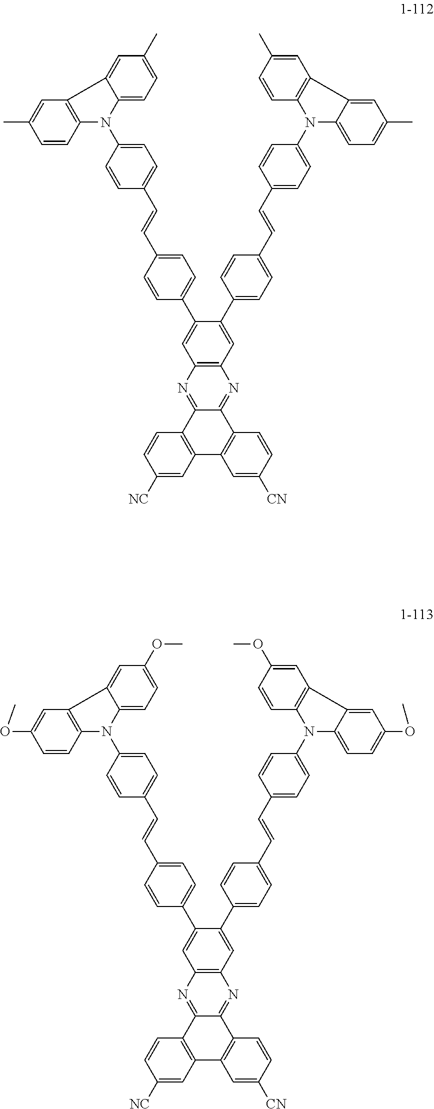

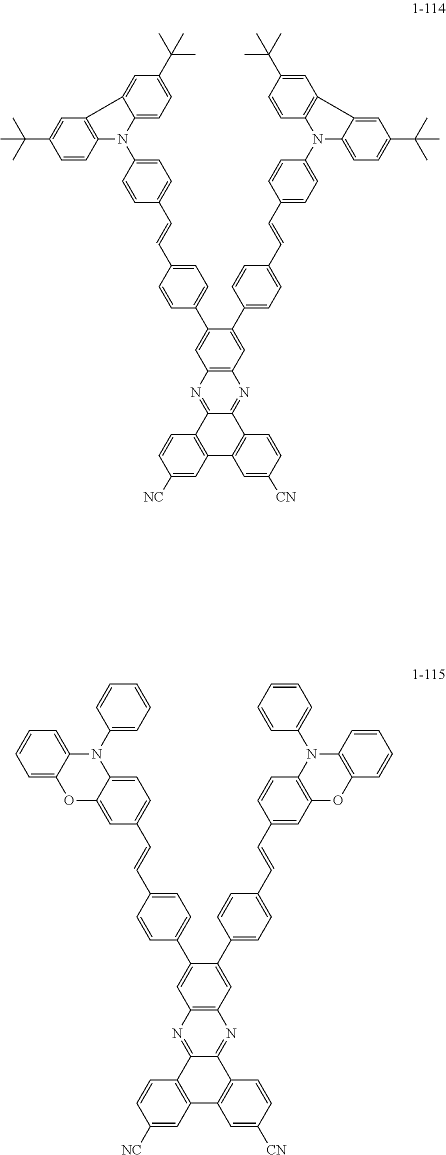 [SMILES: CC(C)(C)c1ccc2c(c1)c1cc(C(C)(C)C)ccc1n2-c1ccc(/C=C/c2ccc(-c3cc4nc5c6ccc(C#N)cc6c6cc(C#N)ccc6c5nc4cc3-c3ccc(/C=C/c4ccc(-n5c6ccc(C(C)(C)C)cc6c6cc(C(C)(C)C)ccc65)cc4)cc3)cc2)cc1 ; N#Cc1ccc2c(c1)c1cc(C#N)ccc1c1nc3cc(-c4ccc(/C=C/c5ccc6c(c5)Oc5ccccc5N6c5ccccc5)cc4)c(-c4ccc(/C=C/c5ccc6c(c5)Oc5ccccc5N6c5ccccc5)cc4)cc3nc21]

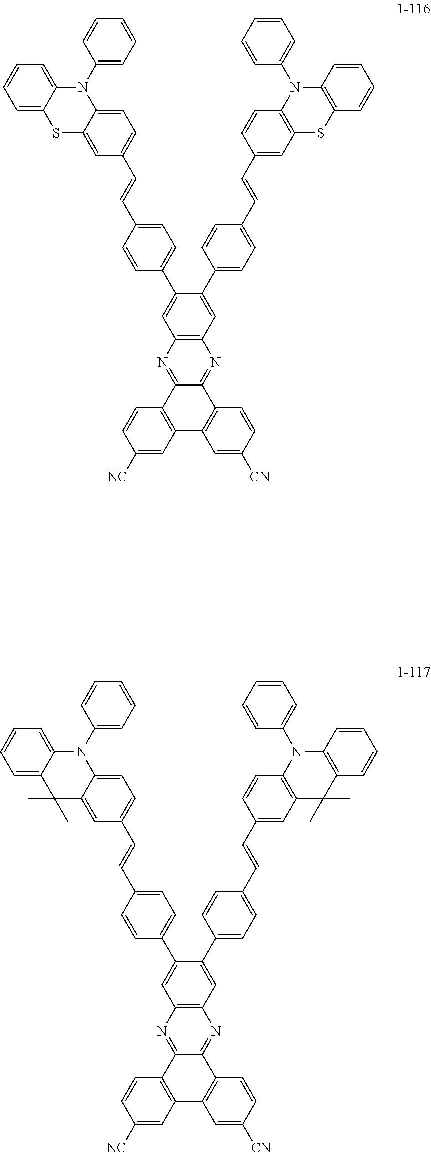 [SMILES: N#Cc1ccc2c(c1)c1cc(C#N)ccc1c1nc3cc(-c4ccc(/C=C/c5ccc6c(c5)Sc5ccccc5N6c5ccccc5)cc4)c(-c4ccc(/C=C/c5ccc6c(c5)Sc5ccccc5N6c5ccccc5)cc4)cc3nc21 ; CC1(C)c2ccccc2N(c2ccccc2)c2ccc(/C=C/c3ccc(-c4cc5nc6c7ccc(C#N)cc7c7cc(C#N)ccc7c6nc5cc4-c4ccc(/C=C/c5ccc6c(c5)C(C)(C)c5ccccc5N6c5ccccc5)cc4)cc3)cc21]

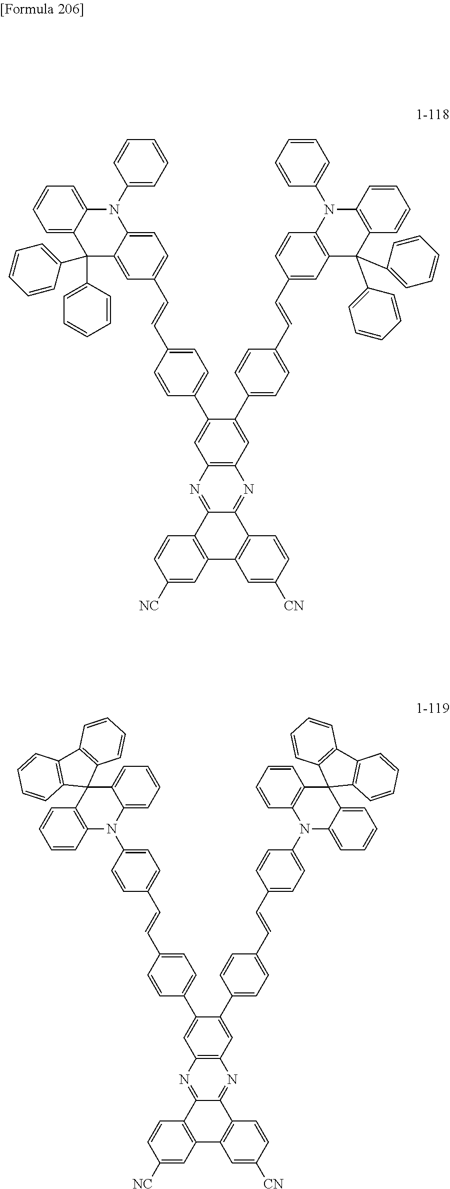 [SMILES: N#Cc1ccc2c(c1)c1cc(C#N)ccc1c1nc3cc(-c4ccc(/C=C/c5ccc6c(c5)C(c5ccccc5)(c5ccccc5)c5ccccc5N6c5ccccc5)cc4)c(-c4ccc(/C=C/c5ccc6c(c5)C(c5ccccc5)(c5ccccc5)c5ccccc5N6c5ccccc5)cc4)cc3nc21 ; N#Cc1ccc2c(c1)c1cc(C#N)ccc1c1nc3cc(-c4ccc(/C=C/c5ccc(N6c7ccccc7C7(c8ccccc8-c8ccccc87)c7ccccc76)cc5)cc4)c(-c4ccc(/C=C/c5ccc(N6c7ccccc7C7(c8ccccc8-c8ccccc87)c7ccccc76)cc5)cc4)cc3nc21]

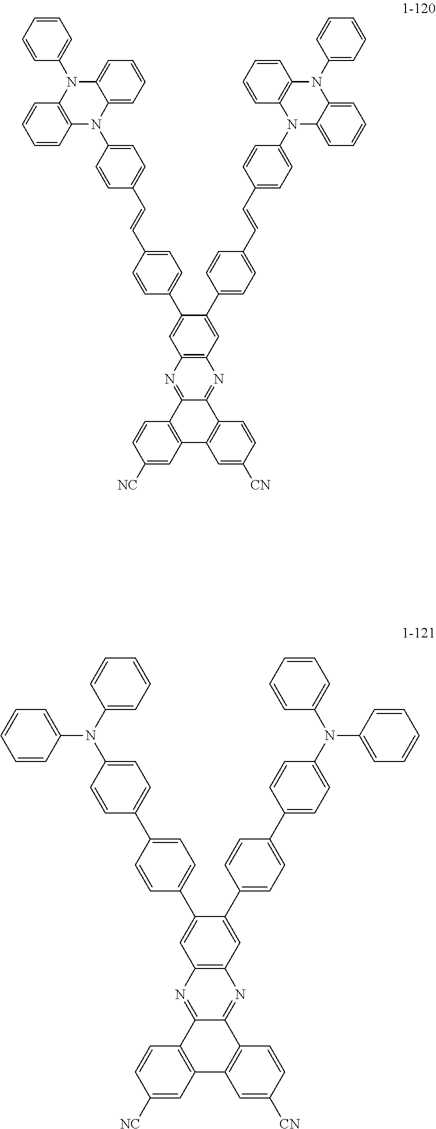 [SMILES: N#Cc1ccc2c(c1)c1cc(C#N)ccc1c1nc3cc(-c4ccc(/C=C/c5ccc(N6c7ccccc7N(c7ccccc7)c7ccccc76)cc5)cc4)c(-c4ccc(/C=C/c5ccc(N6c7ccccc7N(c7ccccc7)c7ccccc76)cc5)cc4)cc3nc21 ; N#Cc1ccc2c(c1)c1cc(C#N)ccc1c1nc3cc(-c4ccc(-c5ccc(N(c6ccccc6)c6ccccc6)cc5)cc4)c(-c4ccc(-c5ccc(N(c6ccccc6)c6ccccc6)cc5)cc4)cc3nc21]

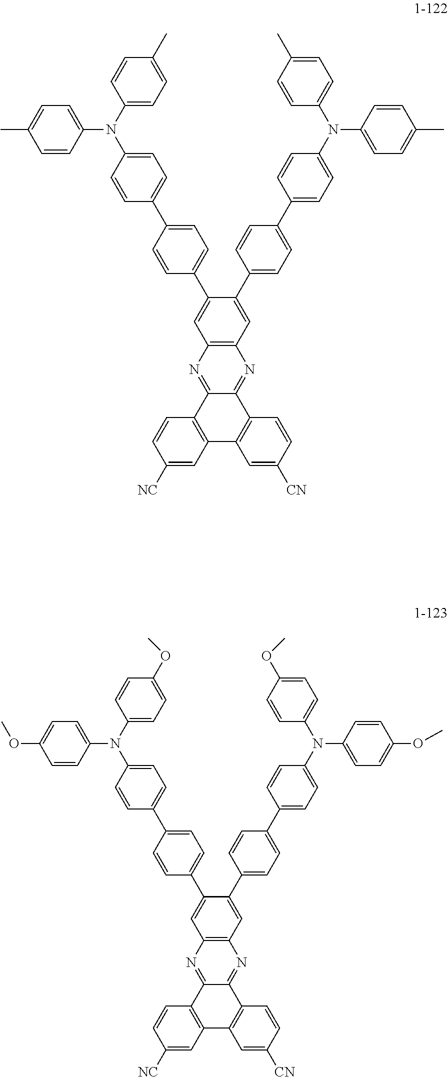

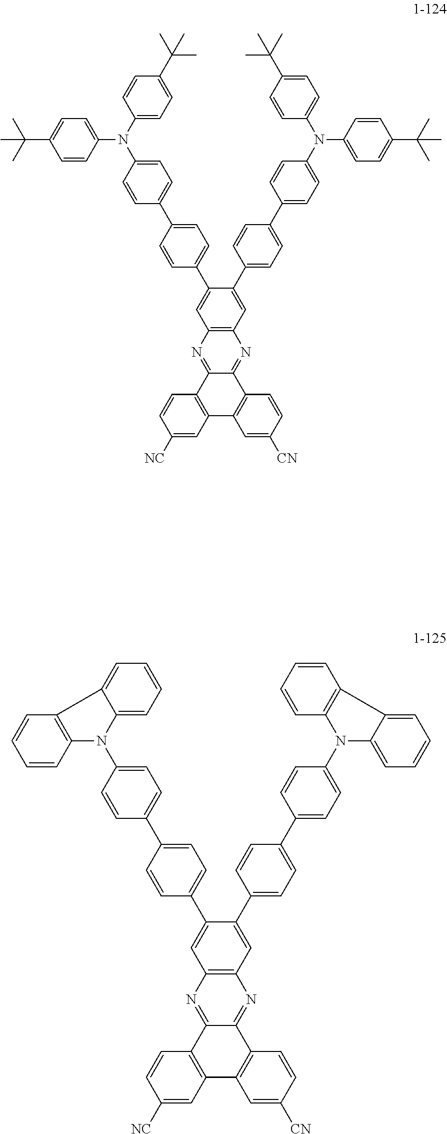 [SMILES: CC(C)(C)c1ccc(N(c2ccc(-c3ccc(-c4cc5nc6c7ccc(C#N)cc7c7cc(C#N)ccc7c6nc5cc4-c4ccc(-c5ccc(N(c6ccc(C(C)(C)C)cc6)c6ccc(C(C)(C)C)cc6)cc5)cc4)cc3)cc2)c2ccc(C(C)(C)C)cc2)cc1 ; N#Cc1ccc2c(c1)c1cc(C#N)ccc1c1nc3cc(-c4ccc(-c5ccc(-n6c7ccccc7c7ccccc76)cc5)cc4)c(-c4ccc(-c5ccc(-n6c7ccccc7c7ccccc76)cc5)cc4)cc3nc21]

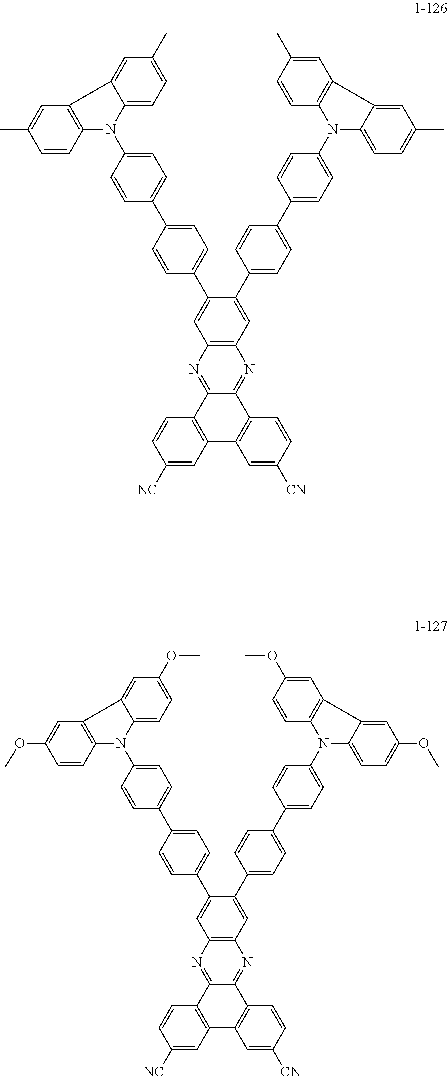

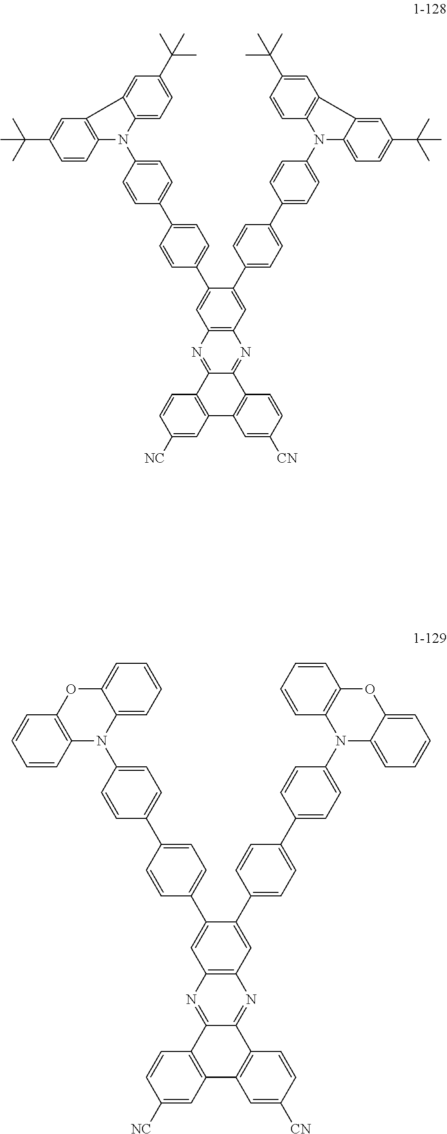 [SMILES: CC(C)(C)c1ccc2c(c1)c1cc(C(C)(C)C)ccc1n2-c1ccc(-c2ccc(-c3cc4nc5c6ccc(C#N)cc6c6cc(C#N)ccc6c5nc4cc3-c3ccc(-c4ccc(-n5c6ccc(C(C)(C)C)cc6c6cc(C(C)(C)C)ccc65)cc4)cc3)cc2)cc1 ; N#Cc1ccc2c(c1)c1cc(C#N)ccc1c1nc3cc(-c4ccc(-c5ccc(N6c7ccccc7Oc7ccccc76)cc5)cc4)c(-c4ccc(-c5ccc(N6c7ccccc7Oc7ccccc76)cc5)cc4)cc3nc21]

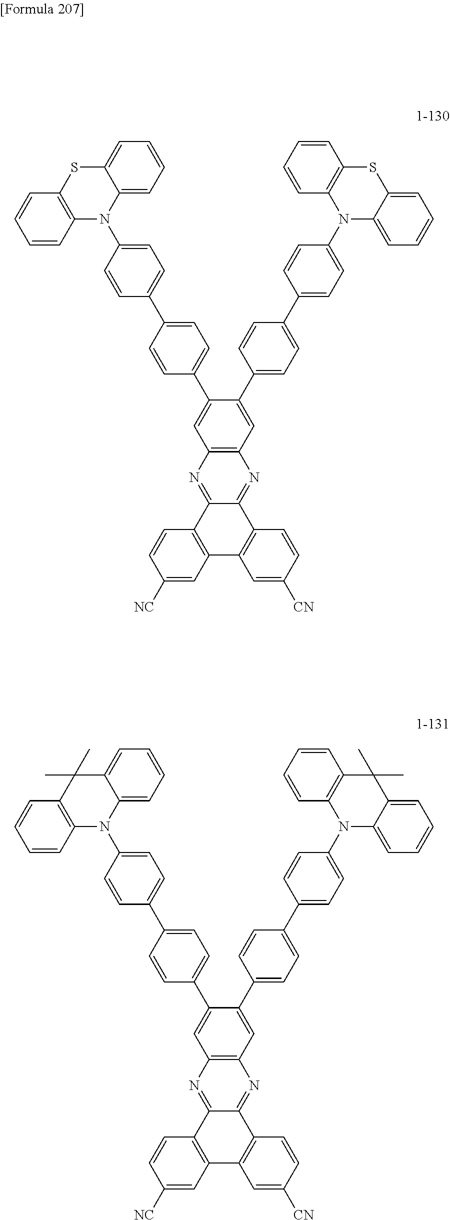 [SMILES: N#Cc1ccc2c(c1)c1cc(C#N)ccc1c1nc3cc(-c4ccc(-c5ccc(N6c7ccccc7Sc7ccccc76)cc5)cc4)c(-c4ccc(-c5ccc(N6c7ccccc7Sc7ccccc76)cc5)cc4)cc3nc21 ; CC1(C)c2ccccc2N(c2ccc(-c3ccc(-c4cc5nc6c7ccc(C#N)cc7c7cc(C#N)ccc7c6nc5cc4-c4ccc(-c5ccc(N6c7ccccc7C(C)(C)c7ccccc76)cc5)cc4)cc3)cc2)c2ccccc21]

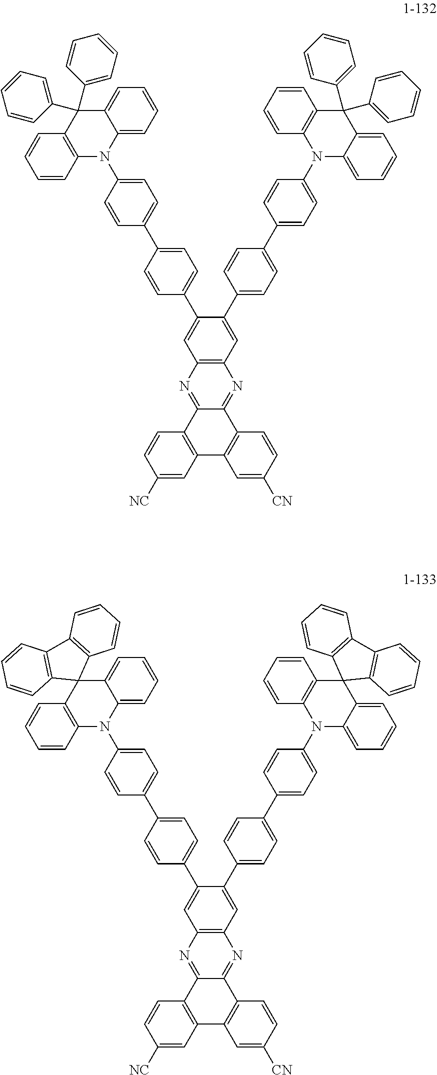 [SMILES: N#Cc1ccc2c(c1)c1cc(C#N)ccc1c1nc3cc(-c4ccc(-c5ccc(N6c7ccccc7C(c7ccccc7)(c7ccccc7)c7ccccc76)cc5)cc4)c(-c4ccc(-c5ccc(N6c7ccccc7C(c7ccccc7)(c7ccccc7)c7ccccc76)cc5)cc4)cc3nc21 ; N#Cc1ccc2c(c1)c1cc(C#N)ccc1c1nc3cc(-c4ccc(-c5ccc(N6c7ccccc7C7(c8ccccc8-c8ccccc87)c7ccccc76)cc5)cc4)c(-c4ccc(-c5ccc(N6c7ccccc7C7(c8ccccc8-c8ccccc87)c7ccccc76)cc5)cc4)cc3nc21]

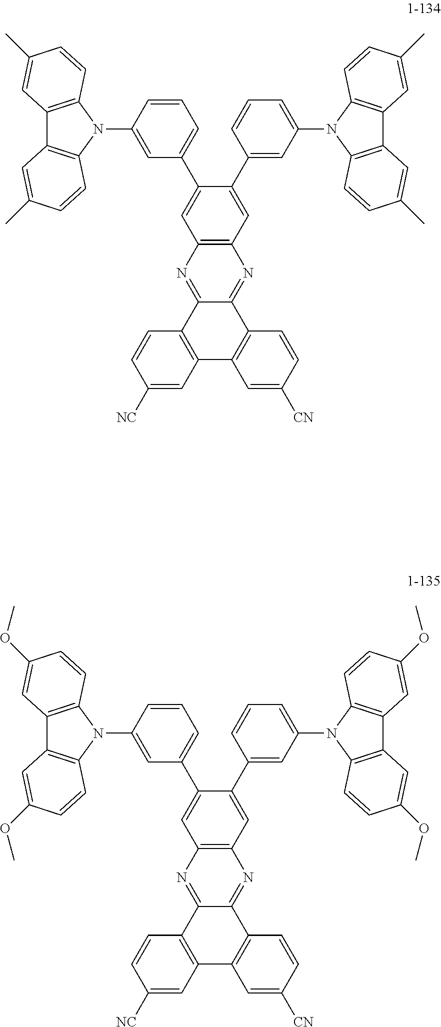

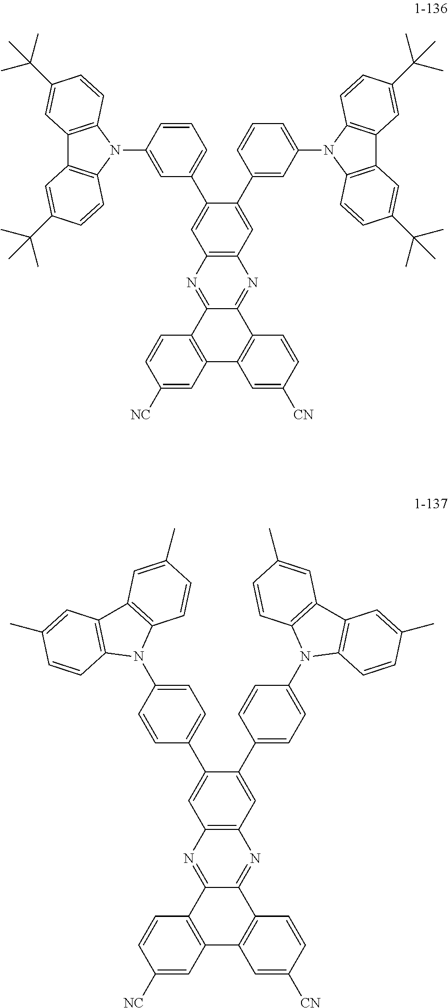

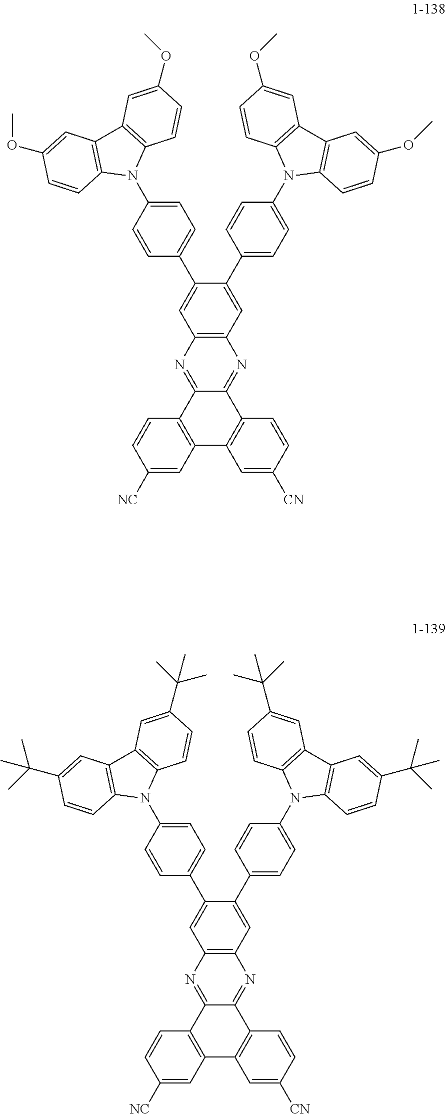

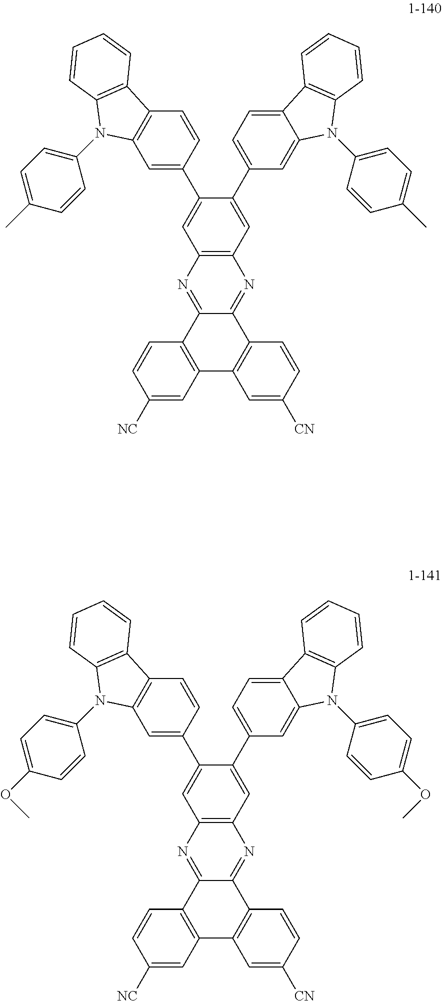

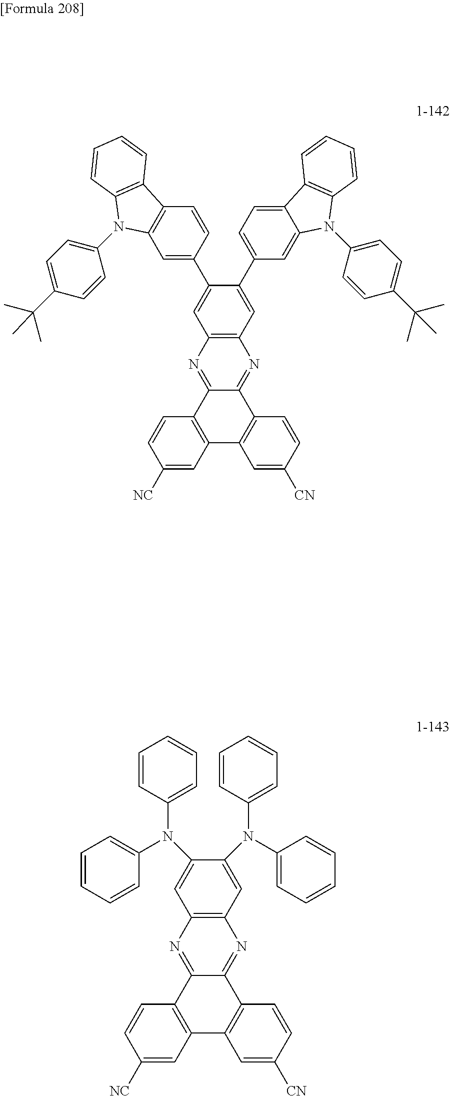 [SMILES: CC(C)(C)c1ccc(-n2c3ccccc3c3ccc(-c4cc5nc6c7ccc(C#N)cc7c7cc(C#N)ccc7c6nc5cc4-c4ccc5c6ccccc6n(-c6ccc(C(C)(C)C)cc6)c5c4)cc32)cc1 ; N#Cc1ccc2c(c1)c1cc(C#N)ccc1c1nc3cc(N(c4ccccc4)c4ccccc4)c(N(c4ccccc4)c4ccccc4)cc3nc21]

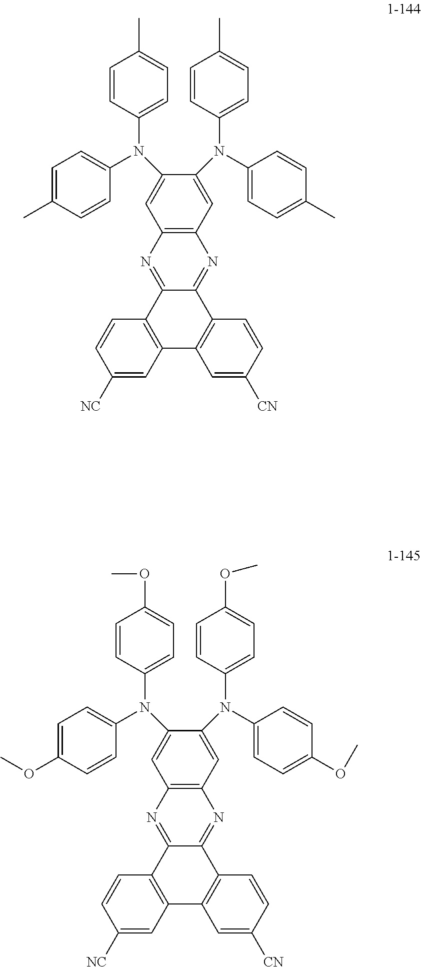

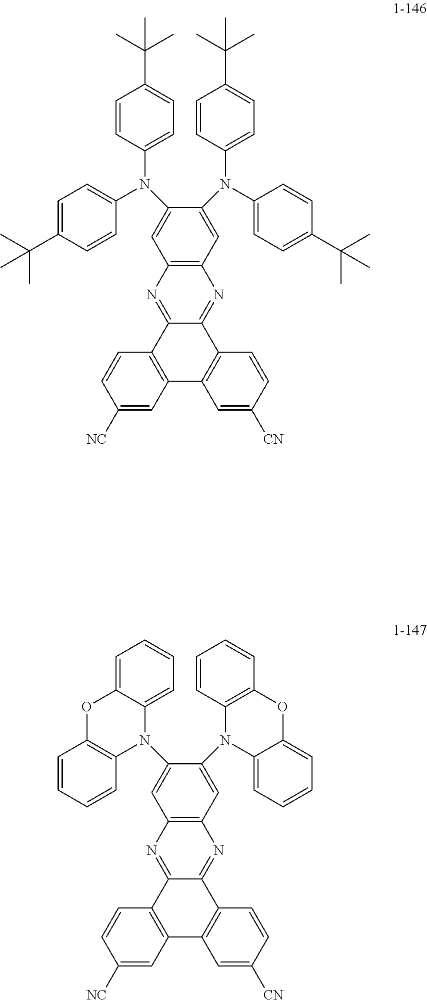 [SMILES: CC(C)(C)c1ccc(N(c2ccc(C(C)(C)C)cc2)c2cc3nc4c5ccc(C#N)cc5c5cc(C#N)ccc5c4nc3cc2N(c2ccc(C(C)(C)C)cc2)c2ccc(C(C)(C)C)cc2)cc1 ; N#Cc1ccc2c(c1)c1cc(C#N)ccc1c1nc3cc(N4c5ccccc5Oc5ccccc54)c(N4c5ccccc5Oc5ccccc54)cc3nc21]

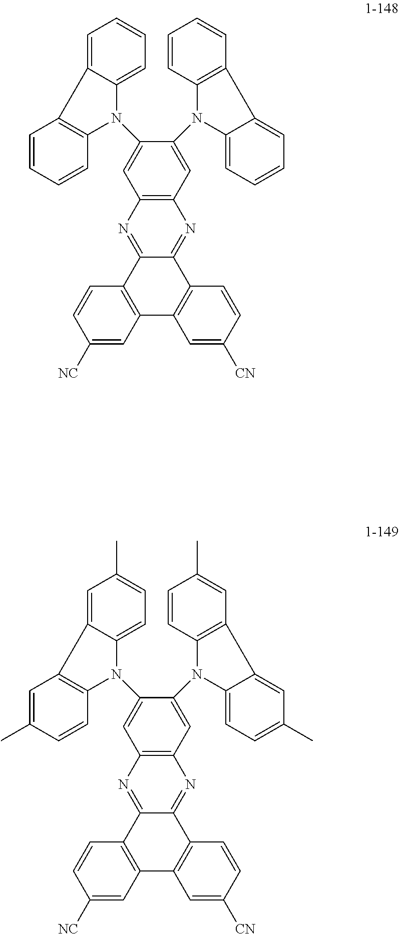

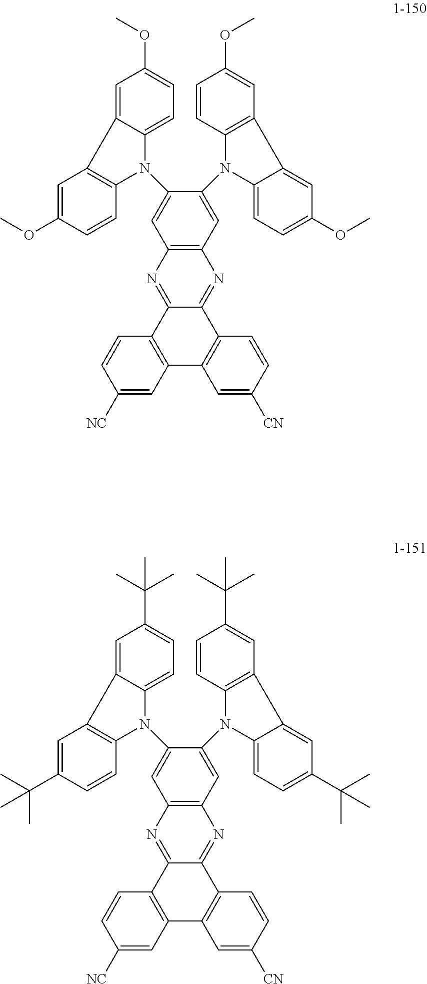

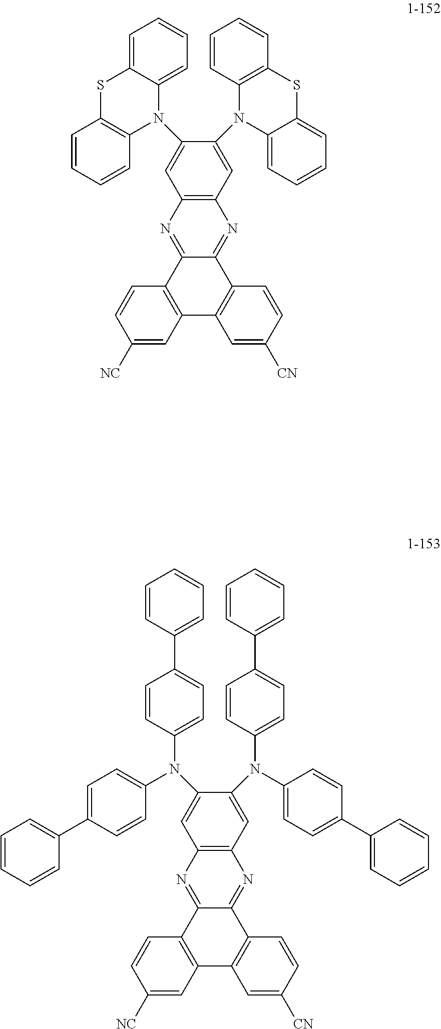 [SMILES: N#Cc1ccc2c(c1)c1cc(C#N)ccc1c1nc3cc(N4c5ccccc5Sc5ccccc54)c(N4c5ccccc5Sc5ccccc54)cc3nc21 ; N#Cc1ccc2c(c1)c1cc(C#N)ccc1c1nc3cc(N(c4ccc(-c5ccccc5)cc4)c4ccc(-c5ccccc5)cc4)c(N(c4ccc(-c5ccccc5)cc4)c4ccc(-c5ccccc5)cc4)cc3nc21]

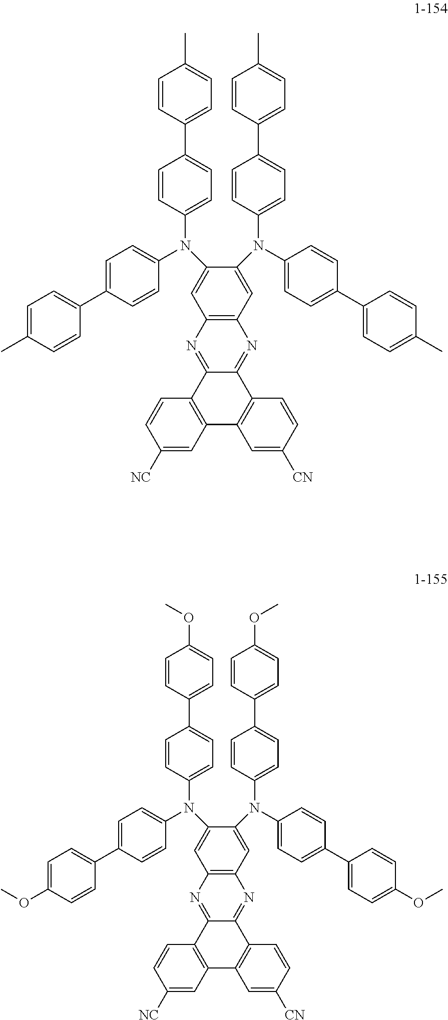

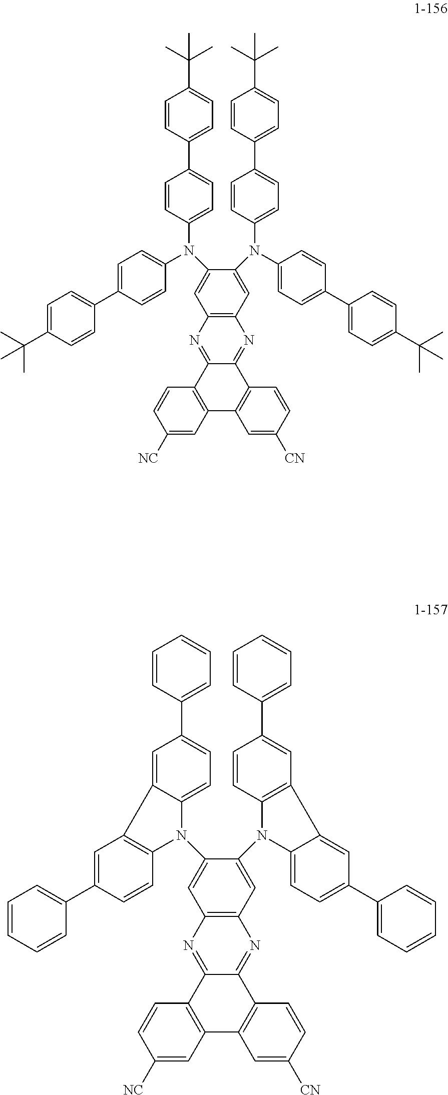 [SMILES: CC(C)(C)c1ccc(-c2ccc(N(c3ccc(-c4ccc(C(C)(C)C)cc4)cc3)c3cc4nc5c6ccc(C#N)cc6c6cc(C#N)ccc6c5nc4cc3N(c3ccc(-c4ccc(C(C)(C)C)cc4)cc3)c3ccc(-c4ccc(C(C)(C)C)cc4)cc3)cc2)cc1 ; N#Cc1ccc2c(c1)c1cc(C#N)ccc1c1nc3cc(-n4c5ccc(-c6ccccc6)cc5c5cc(-c6ccccc6)ccc54)c(-n4c5ccc(-c6ccccc6)cc5c5cc(-c6ccccc6)ccc54)cc3nc21]

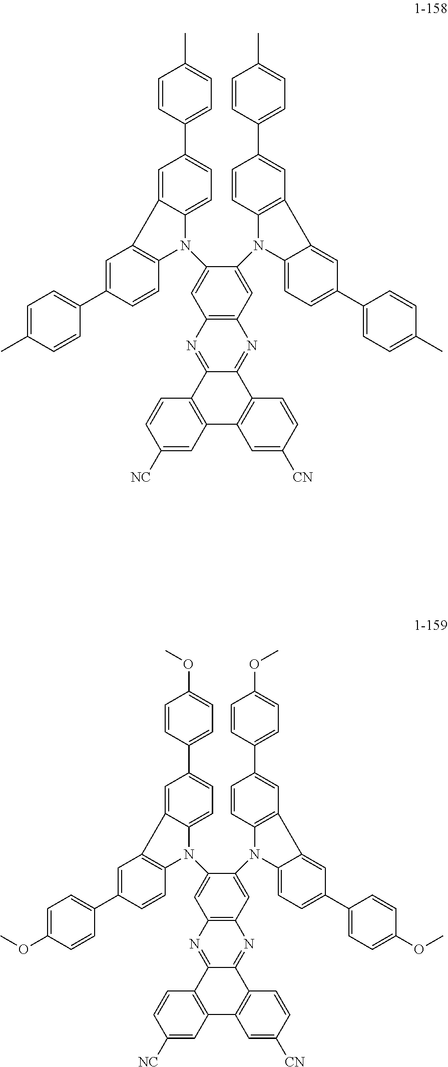

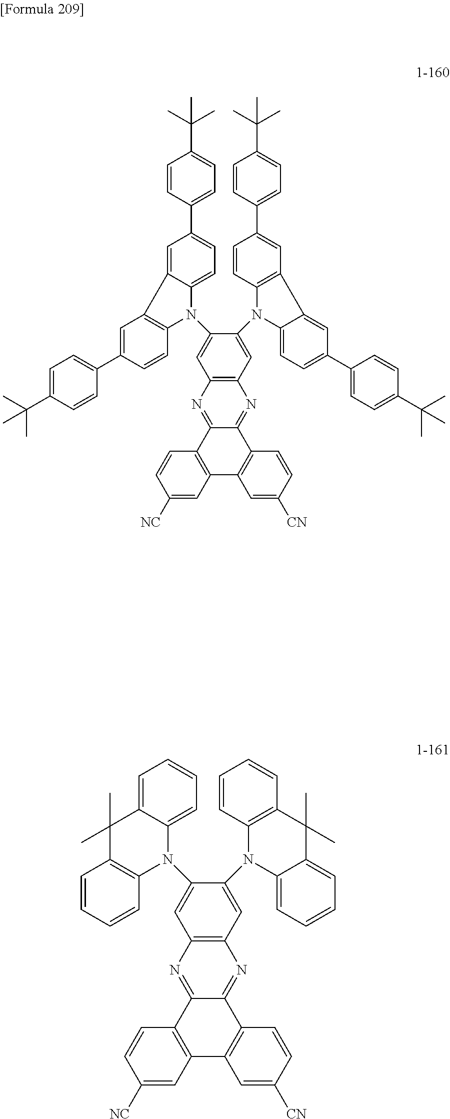 [SMILES: CC(C)(C)c1ccc(-c2ccc3c(c2)c2cc(-c4ccc(C(C)(C)C)cc4)ccc2n3-c2cc3nc4c5ccc(C#N)cc5c5cc(C#N)ccc5c4nc3cc2-n2c3ccc(-c4ccc(C(C)(C)C)cc4)cc3c3cc(-c4ccc(C(C)(C)C)cc4)ccc32)cc1 ; CC1(C)c2ccccc2N(c2cc3nc4c5ccc(C#N)cc5c5cc(C#N)ccc5c4nc3cc2N2c3ccccc3C(C)(C)c3ccccc32)c2ccccc21]

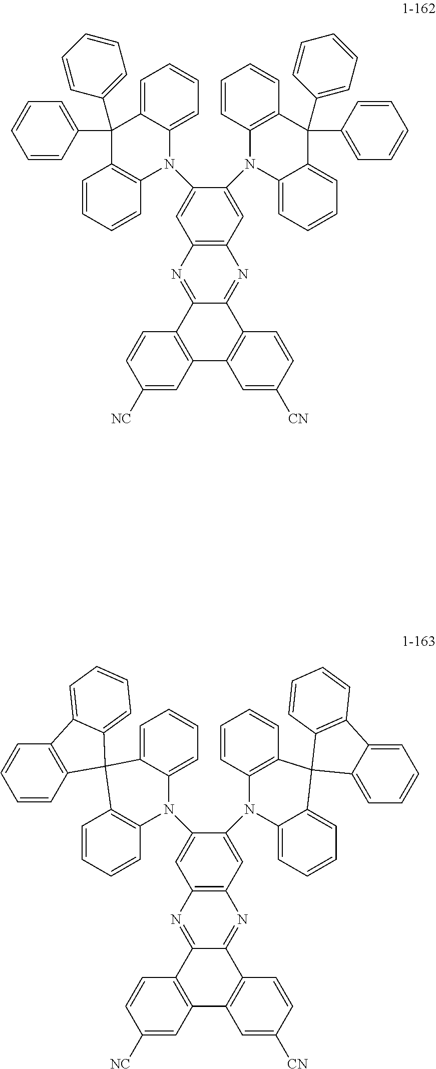 [SMILES: N#Cc1ccc2c(c1)c1cc(C#N)ccc1c1nc3cc(N4c5ccccc5C(c5ccccc5)(c5ccccc5)c5ccccc54)c(N4c5ccccc5C(c5ccccc5)(c5ccccc5)c5ccccc54)cc3nc21 ; N#Cc1ccc2c(c1)c1cc(C#N)ccc1c1nc3cc(N4c5ccccc5C5(c6ccccc6-c6ccccc65)c5ccccc54)c(N4c5ccccc5C5(c6ccccc6-c6ccccc65)c5ccccc54)cc3nc21]

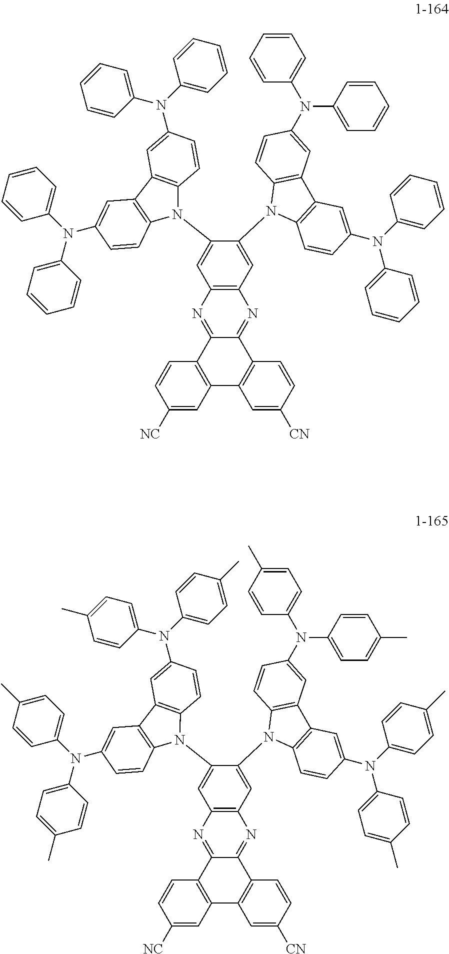

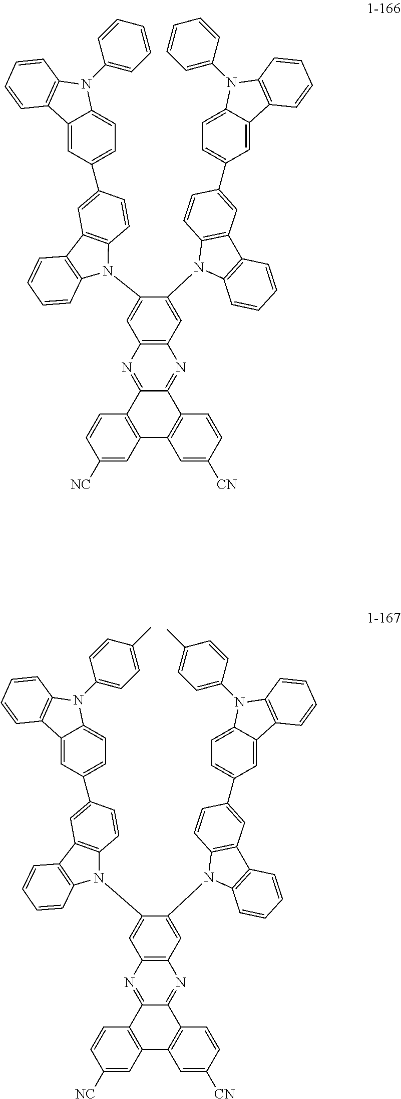 [SMILES: N#Cc1ccc2c(c1)c1cc(C#N)ccc1c1nc3cc(-n4c5ccccc5c5cc(-c6ccc7c(c6)c6ccccc6n7-c6ccccc6)ccc54)c(-n4c5ccccc5c5cc(-c6ccc7c(c6)c6ccccc6n7-c6ccccc6)ccc54)cc3nc21 ; Cc1ccc(-n2c3ccccc3c3cc(-c4ccc5c(c4)c4ccccc4n5-c4cc5nc6c7ccc(C#N)cc7c7cc(C#N)ccc7c6nc5cc4-n4c5ccccc5c5cc(-c6ccc7c(c6)c6ccccc6n7-c6ccc(C)cc6)ccc54)ccc32)cc1]

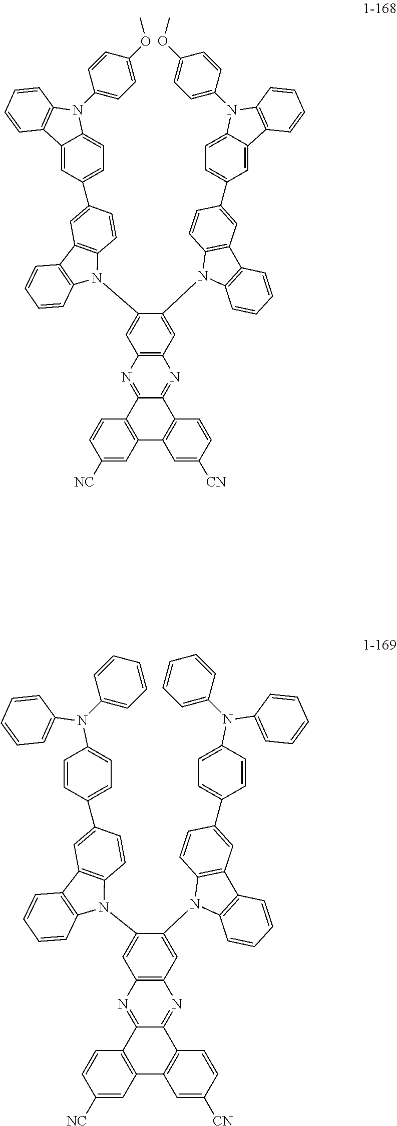 [SMILES: COc1ccc(-n2c3ccccc3c3cc(-c4ccc5c(c4)c4ccccc4n5-c4cc5nc6c7ccc(C#N)cc7c7cc(C#N)ccc7c6nc5cc4-n4c5ccccc5c5cc(-c6ccc7c(c6)c6ccccc6n7-c6ccc(OC)cc6)ccc54)ccc32)cc1 ; N#Cc1ccc2c(c1)c1cc(C#N)ccc1c1nc3cc(-n4c5ccccc5c5cc(-c6ccc(N(c7ccccc7)c7ccccc7)cc6)ccc54)c(-n4c5ccccc5c5cc(-c6ccc(N(c7ccccc7)c7ccccc7)cc6)ccc54)cc3nc21]

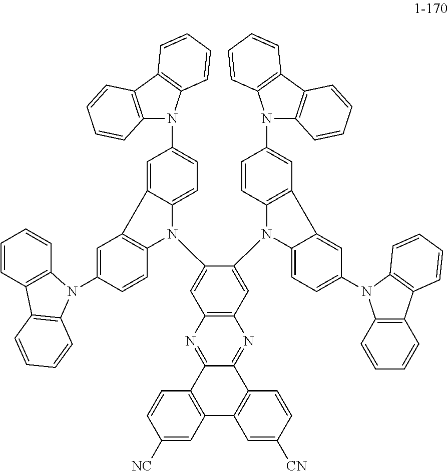 [SMILES: N#Cc1ccc2c(c1)c1cc(C#N)ccc1c1nc3cc(-n4c5ccc(-n6c7ccccc7c7ccccc76)cc5c5cc(-n6c7ccccc7c7ccccc76)ccc54)c(-n4c5ccc(-n6c7ccccc7c7ccccc76)cc5c5cc(-n6c7ccccc7c7ccccc76)ccc54)cc3nc21]

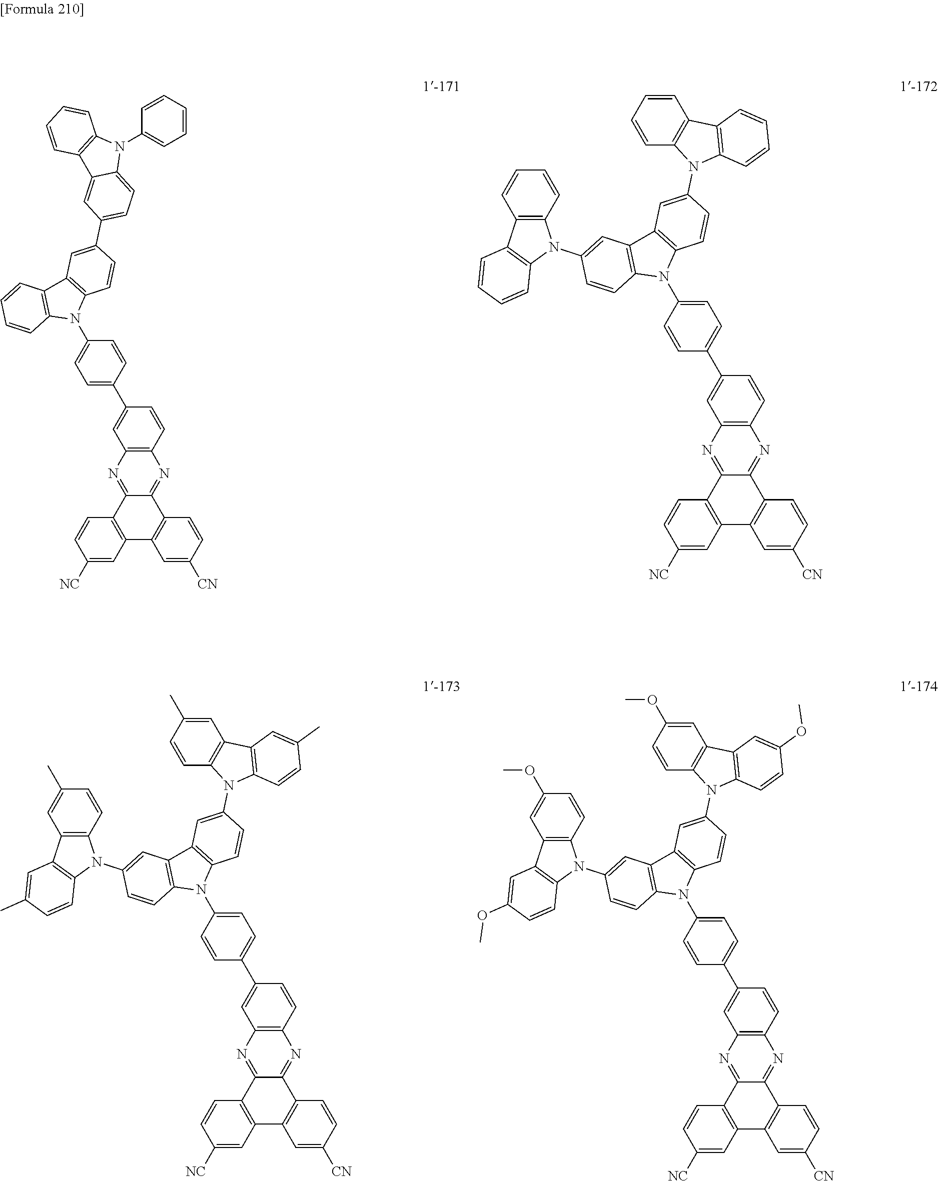 [SMILES: N#Cc1ccc2c(c1)c1cc(C#N)ccc1c1nc3cc(-c4ccc(-n5c6ccccc6c6cc(-c7ccc8c(c7)c7ccccc7n8-c7ccccc7)ccc65)cc4)ccc3nc21 ; N#Cc1ccc2c(c1)c1cc(C#N)ccc1c1nc3cc(-c4ccc(-n5c6ccc(-n7c8ccccc8c8ccccc87)cc6c6cc(-n7c8ccccc8c8ccccc87)ccc65)cc4)ccc3nc21 ; Cc1ccc2c(c1)c1cc(C)ccc1n2-c1ccc2c(c1)c1cc(-n3c4ccc(C)cc4c4cc(C)ccc43)ccc1n2-c1ccc(-c2ccc3nc4c5ccc(C#N)cc5c5cc(C#N)ccc5c4nc3c2)cc1 ; COc1ccc2c(c1)c1cc(OC)ccc1n2-c1ccc2c(c1)c1cc(-n3c4ccc(OC)cc4c4cc(OC)ccc43)ccc1n2-c1ccc(-c2ccc3nc4c5ccc(C#N)cc5c5cc(C#N)ccc5c4nc3c2)cc1]

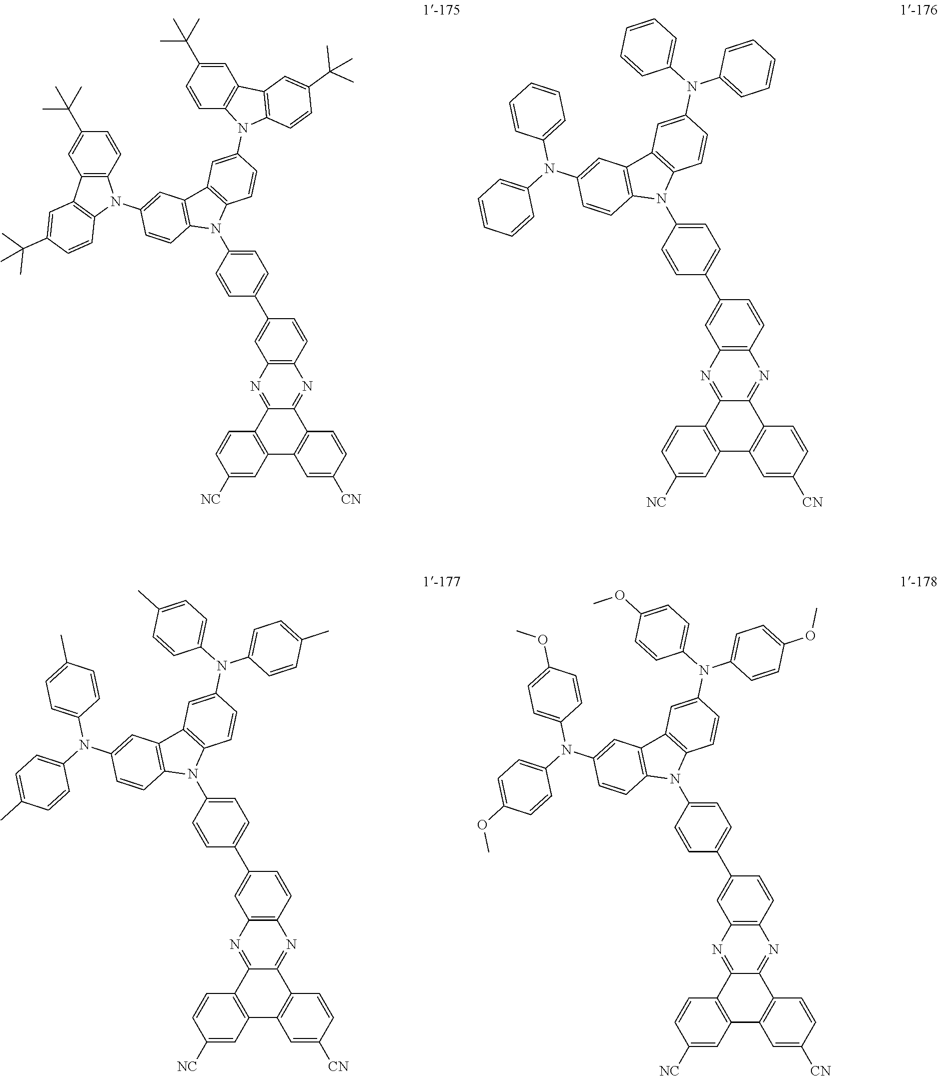

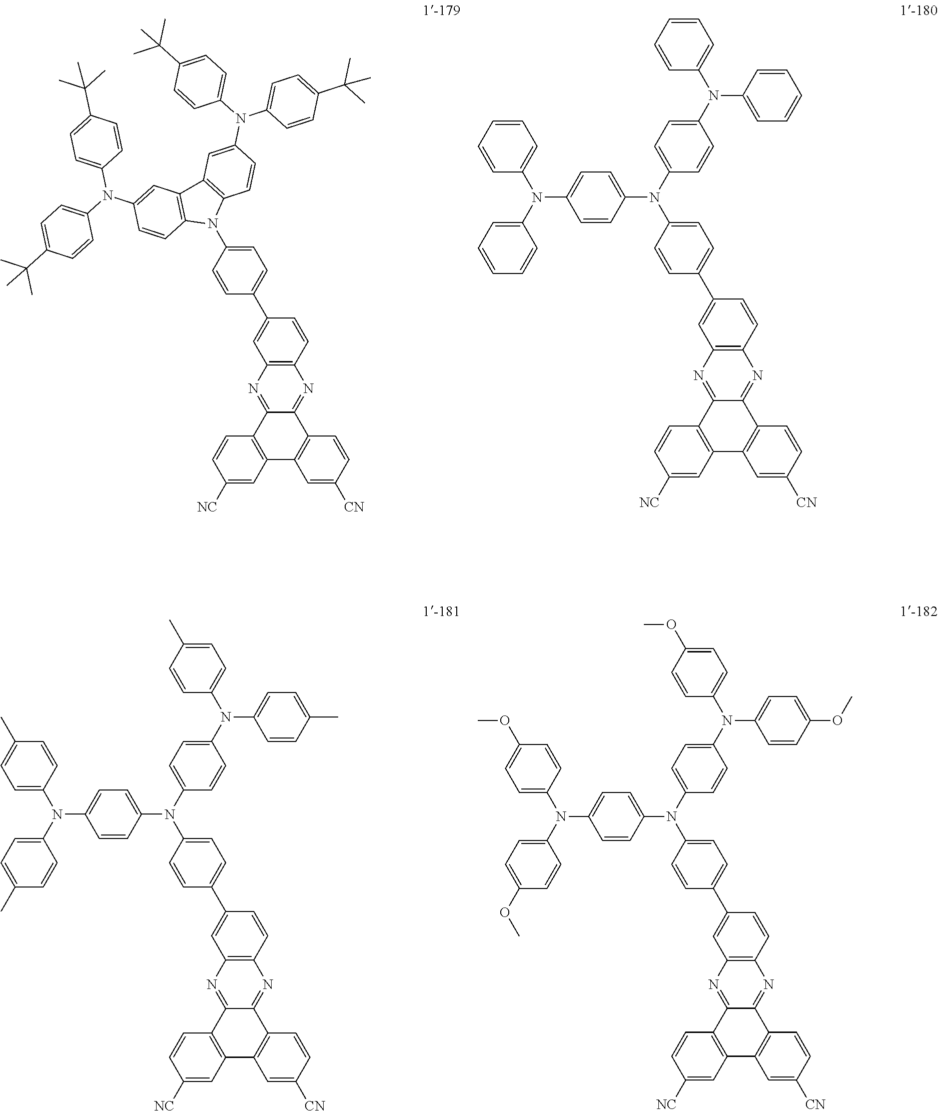

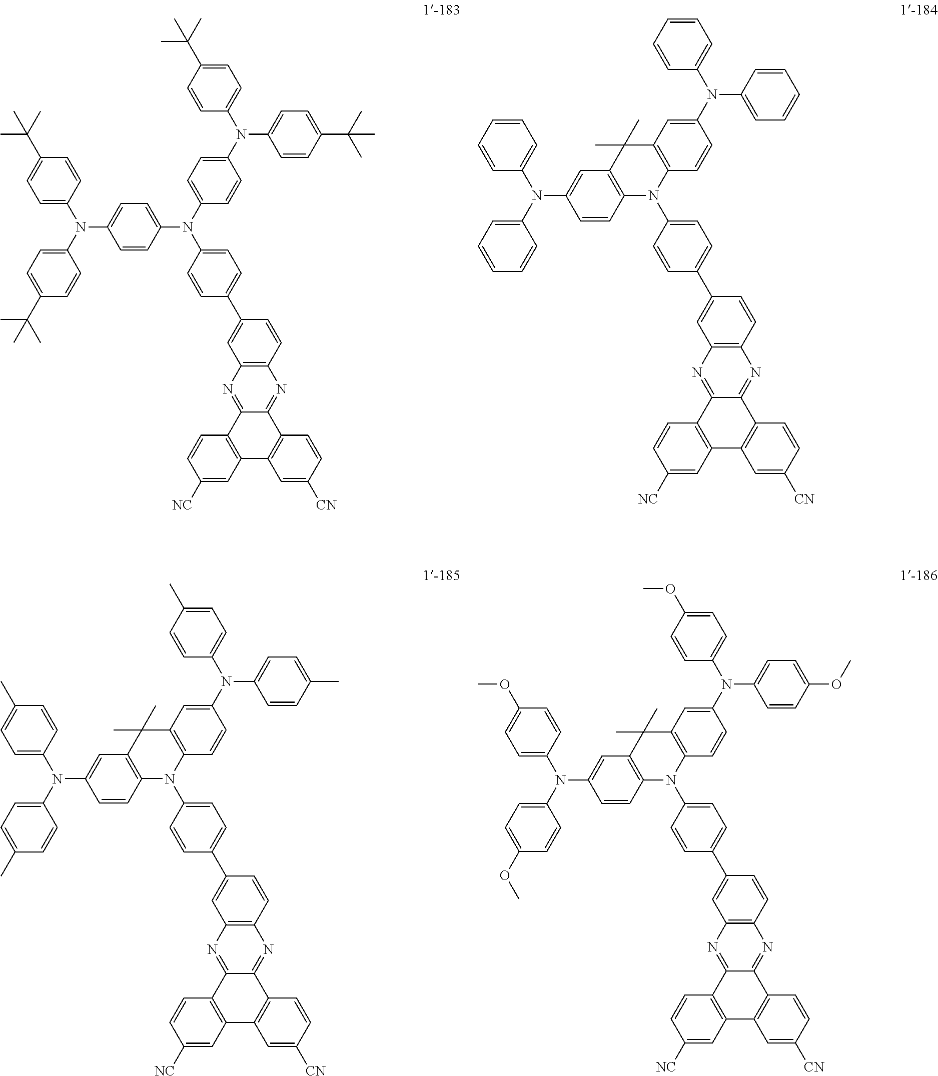

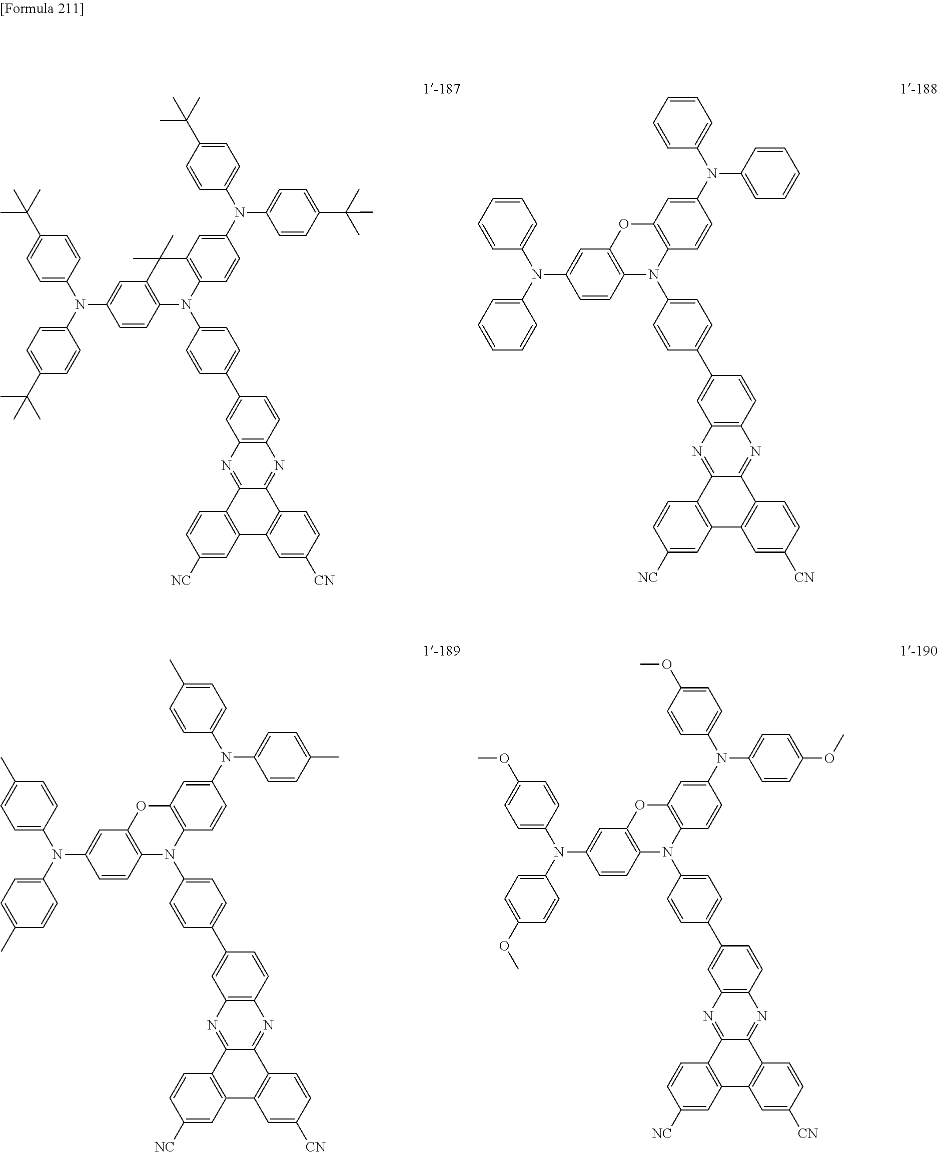

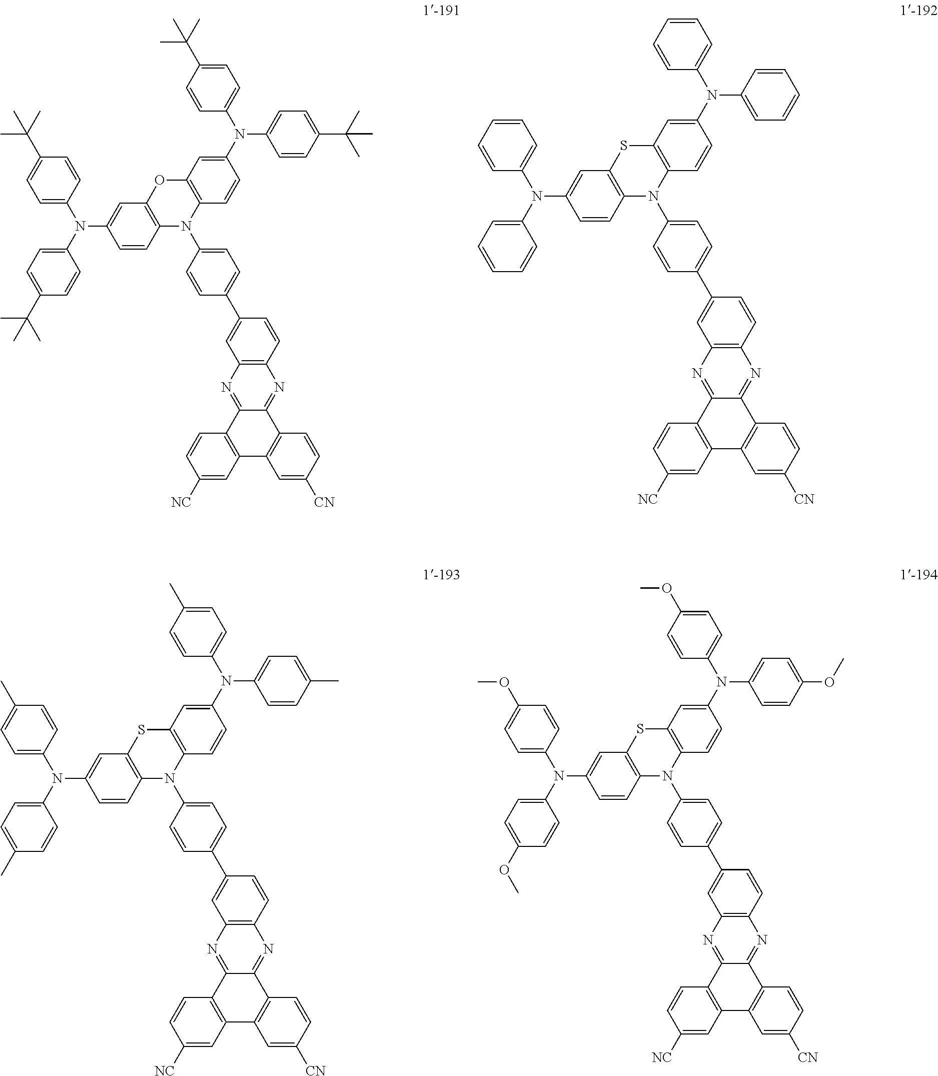

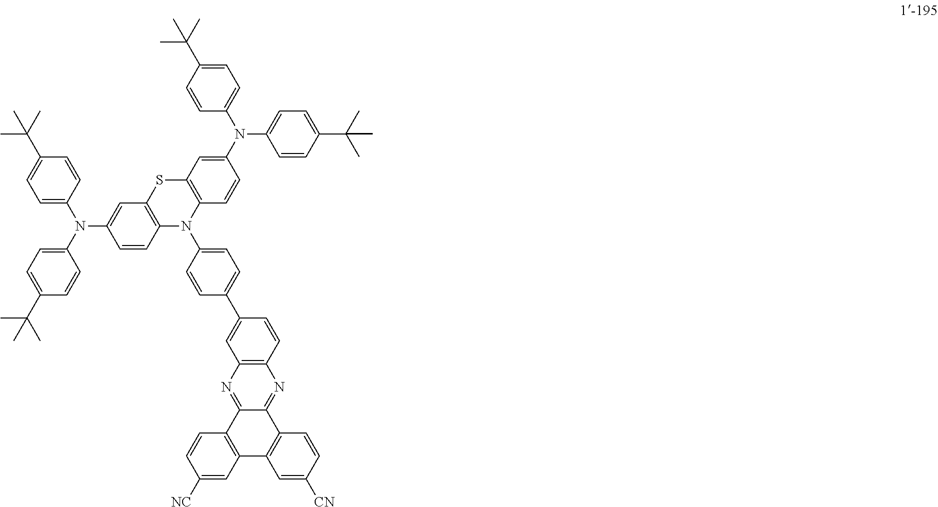 [SMILES: CC(C)(C)c1ccc(N(c2ccc(C(C)(C)C)cc2)c2ccc3c(c2)Sc2cc(N(c4ccc(C(C)(C)C)cc4)c4ccc(C(C)(C)C)cc4)ccc2N3c2ccc(-c3ccc4nc5c6ccc(C#N)cc6c6cc(C#N)ccc6c5nc4c3)cc2)cc1]

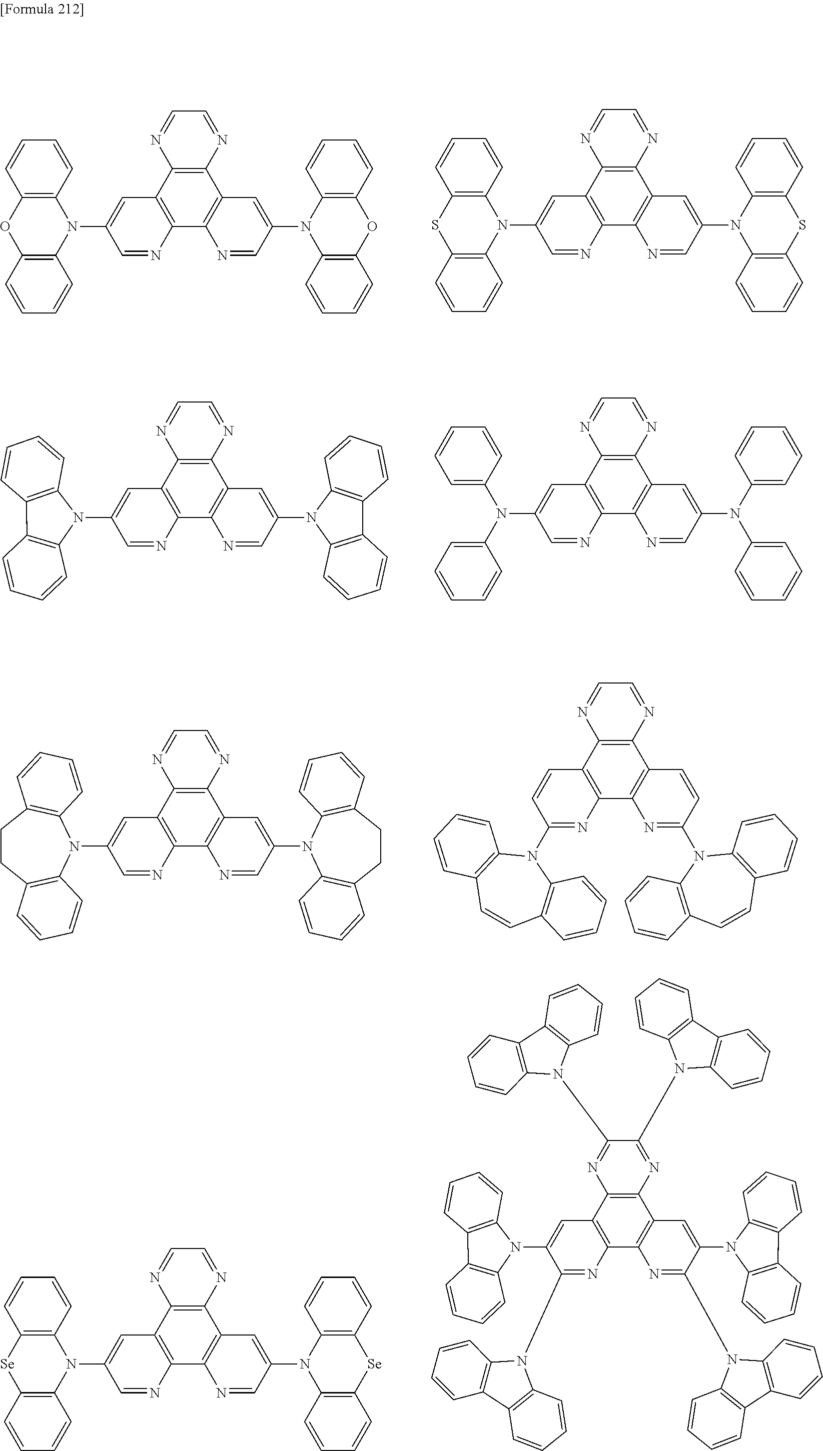

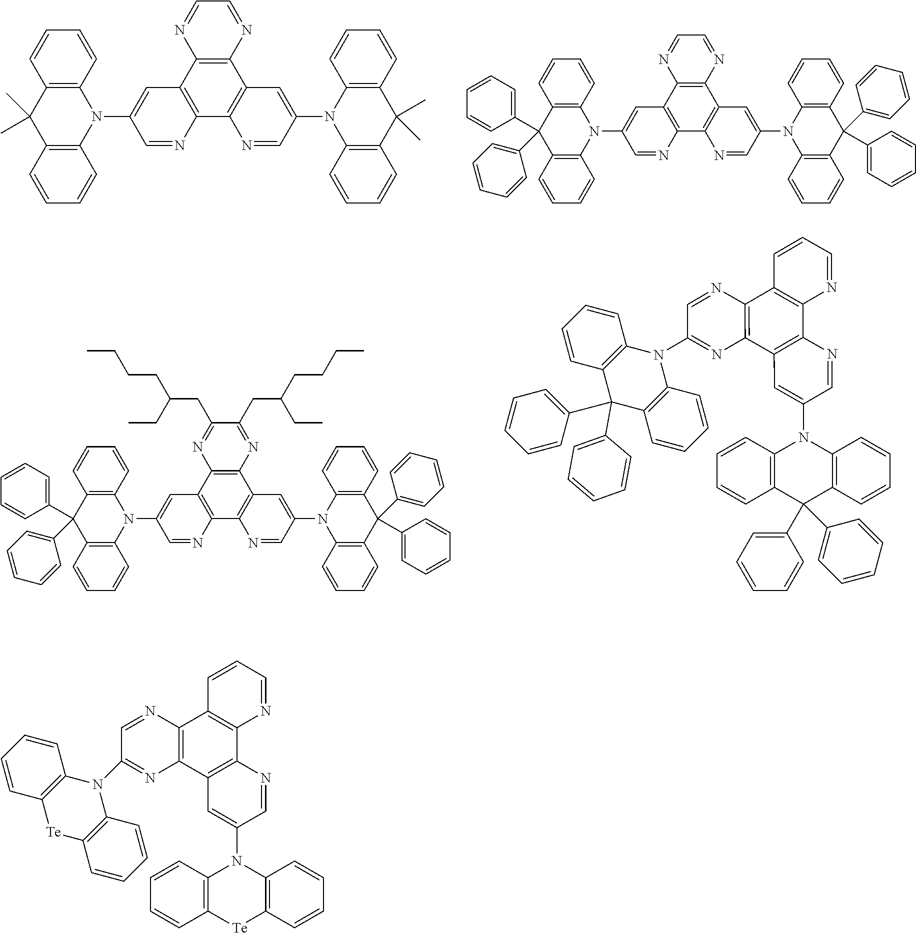

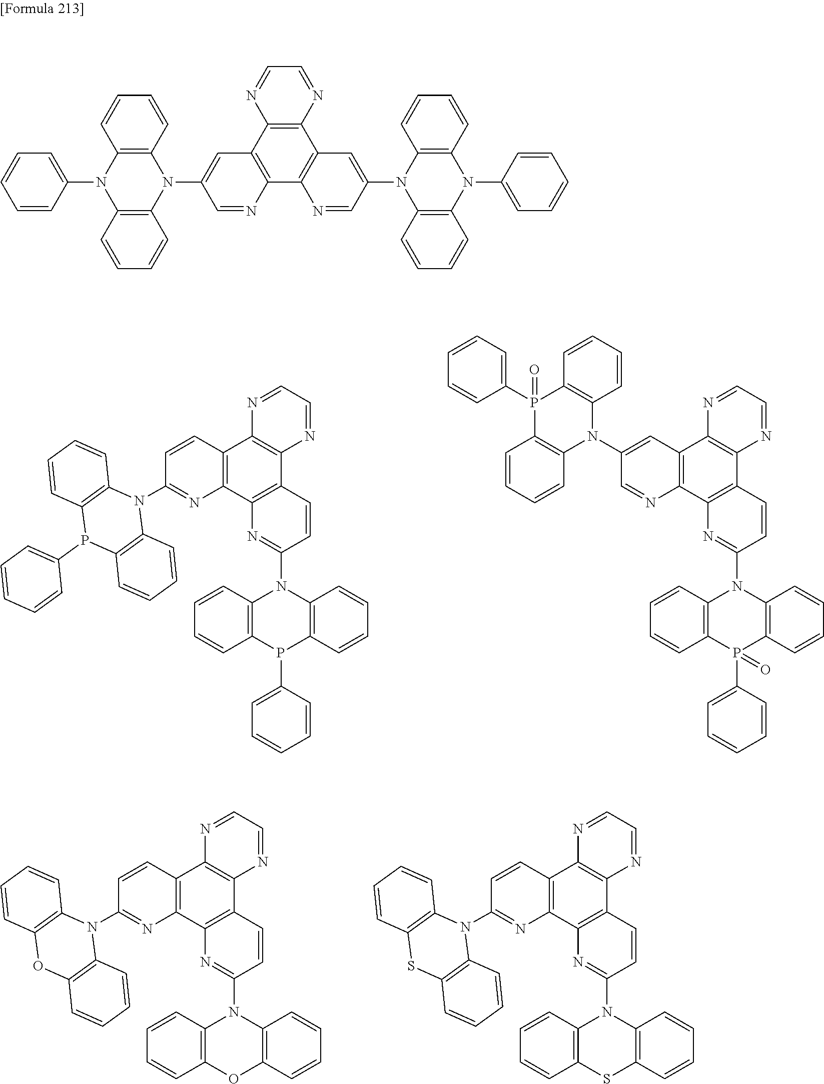 [SMILES: c1ccc(N2c3ccccc3N(c3cnc4c(c3)c3nccnc3c3cc(N5c6ccccc6N(c6ccccc6)c6ccccc65)cnc34)c3ccccc32)cc1 ; c1ccc(P2c3ccccc3N(c3ccc4c5nccnc5c5ccc(N6c7ccccc7P(c7ccccc7)c7ccccc76)nc5c4n3)c3ccccc32)cc1 ; O=P1(c2ccccc2)c2ccccc2N(c2cnc3c(c2)c2nccnc2c2ccc(N4c5ccccc5P(=O)(c5ccccc5)c5ccccc54)nc23)c2ccccc21 ; c1ccc2c(c1)Oc1ccccc1N2c1ccc2c3nccnc3c3ccc(N4c5ccccc5Oc5ccccc54)nc3c2n1 ; c1ccc2c(c1)Sc1ccccc1N2c1ccc2c3nccnc3c3ccc(N4c5ccccc5Sc5ccccc54)nc3c2n1]

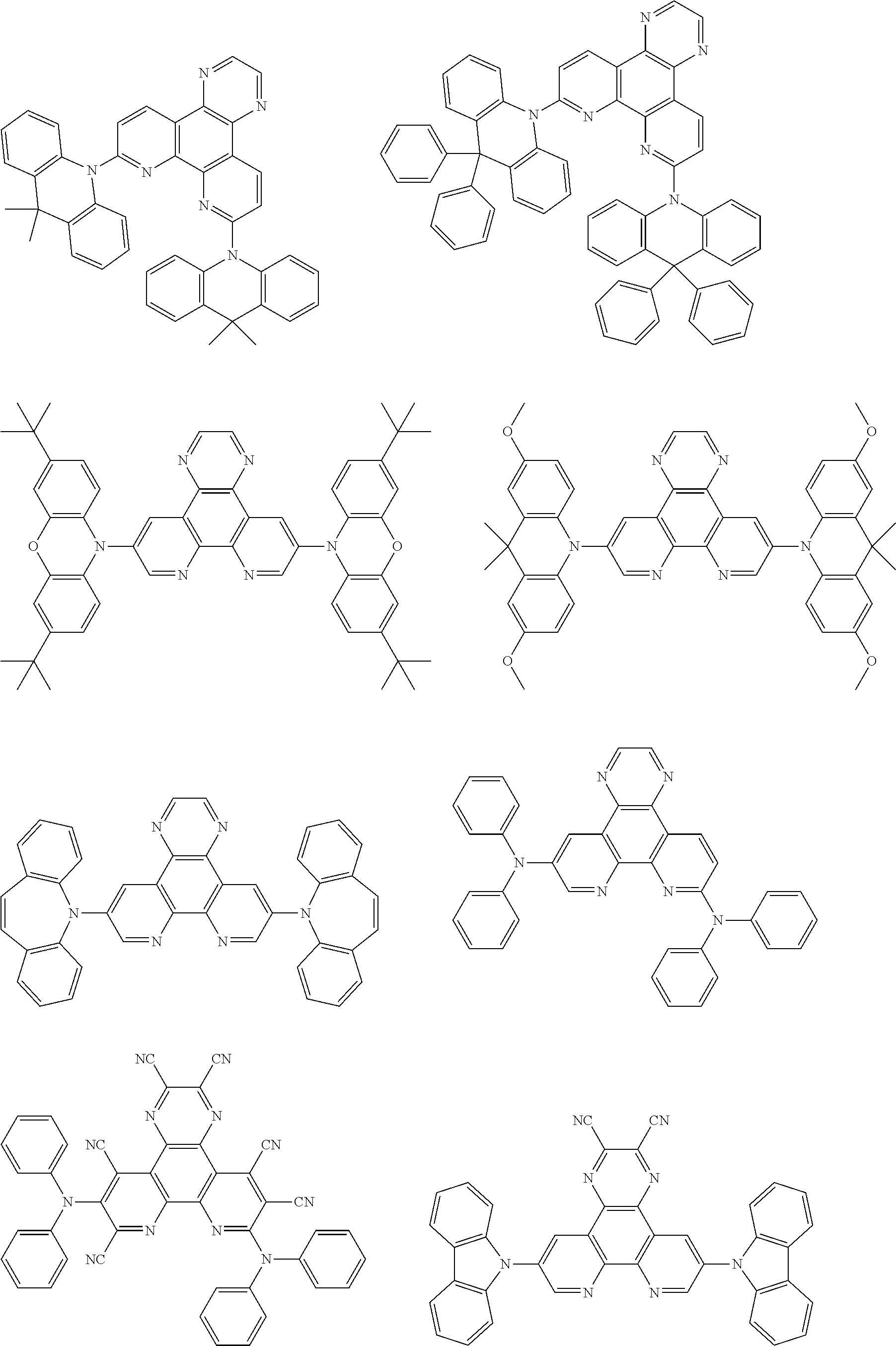

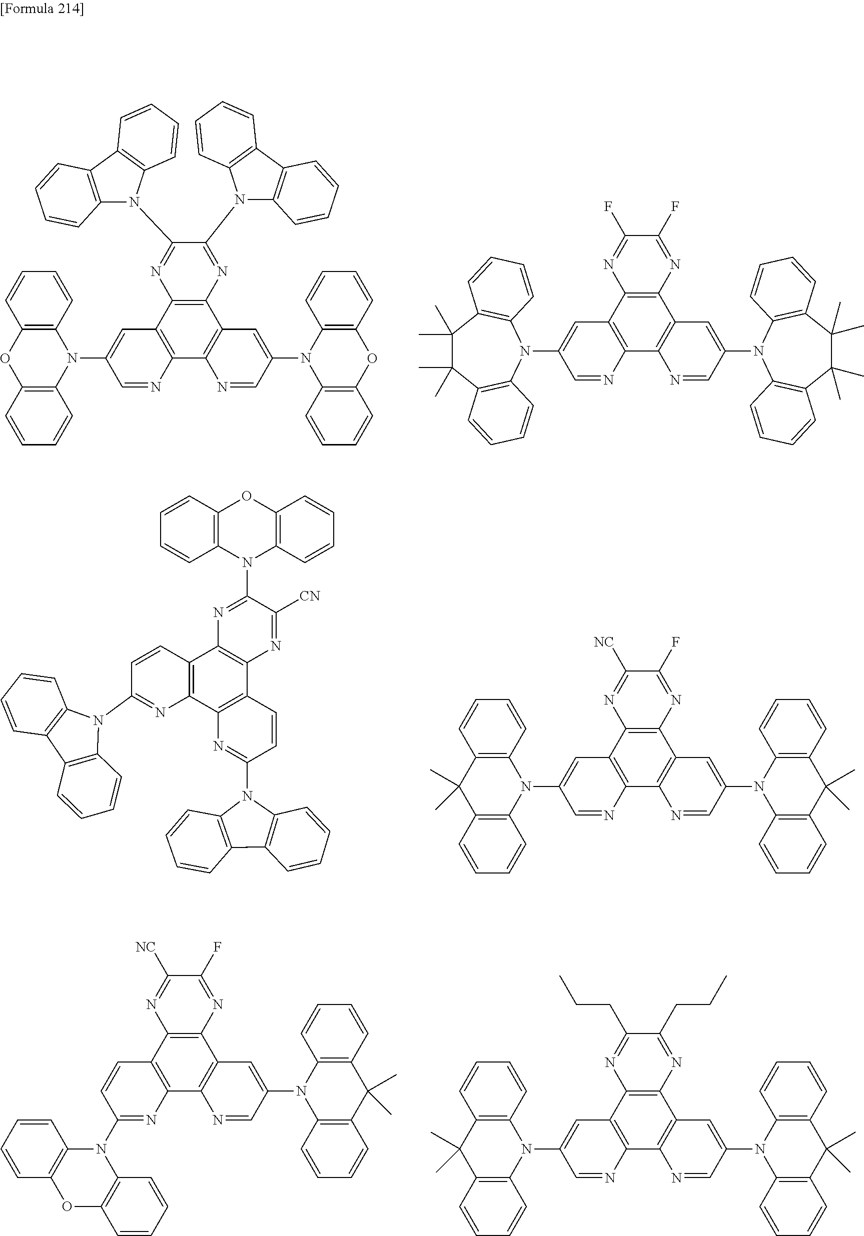

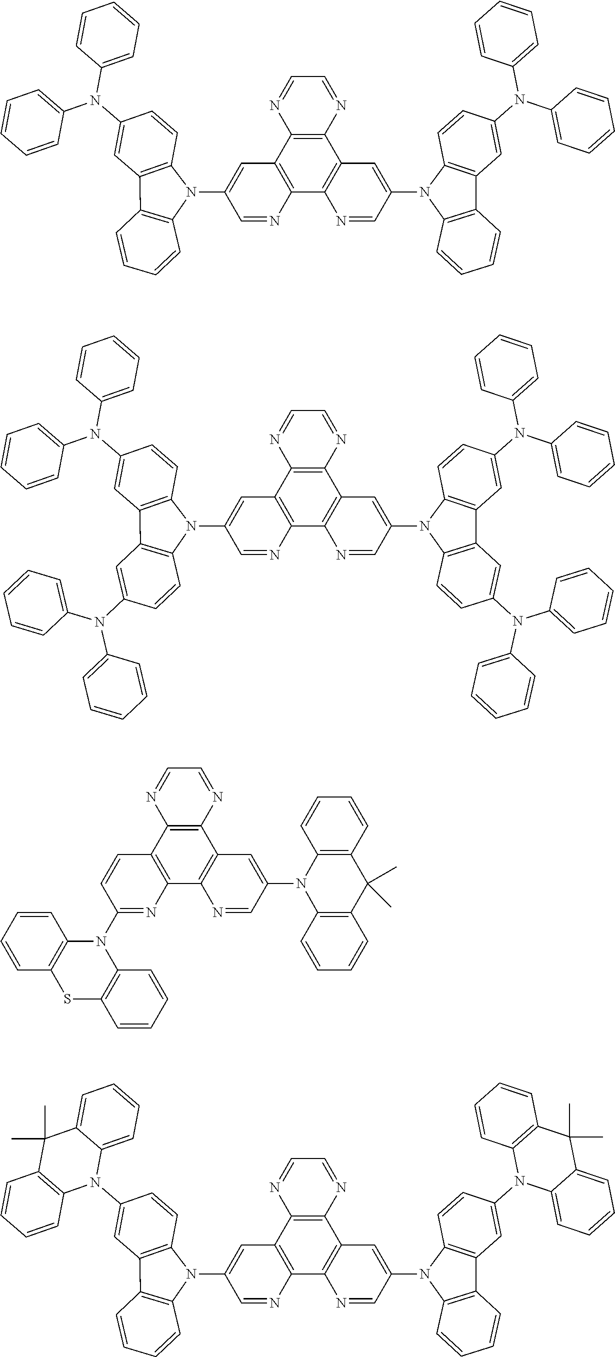 [SMILES: c1ccc(N(c2ccccc2)c2ccc3c(c2)c2ccccc2n3-c2cnc3c(c2)c2nccnc2c2cc(-n4c5ccccc5c5cc(N(c6ccccc6)c6ccccc6)ccc54)cnc23)cc1 ; c1ccc(N(c2ccccc2)c2ccc3c(c2)c2cc(N(c4ccccc4)c4ccccc4)ccc2n3-c2cnc3c(c2)c2nccnc2c2cc(-n4c5ccc(N(c6ccccc6)c6ccccc6)cc5c5cc(N(c6ccccc6)c6ccccc6)ccc54)cnc23)cc1 ; CC1(C)c2ccccc2N(c2cnc3c(c2)c2nccnc2c2ccc(N4c5ccccc5Sc5ccccc54)nc23)c2ccccc21 ; CC1(C)c2ccccc2N(c2ccc3c(c2)c2ccccc2n3-c2cnc3c(c2)c2nccnc2c2cc(-n4c5ccccc5c5cc(N6c7ccccc7C(C)(C)c7ccccc76)ccc54)cnc23)c2ccccc21]

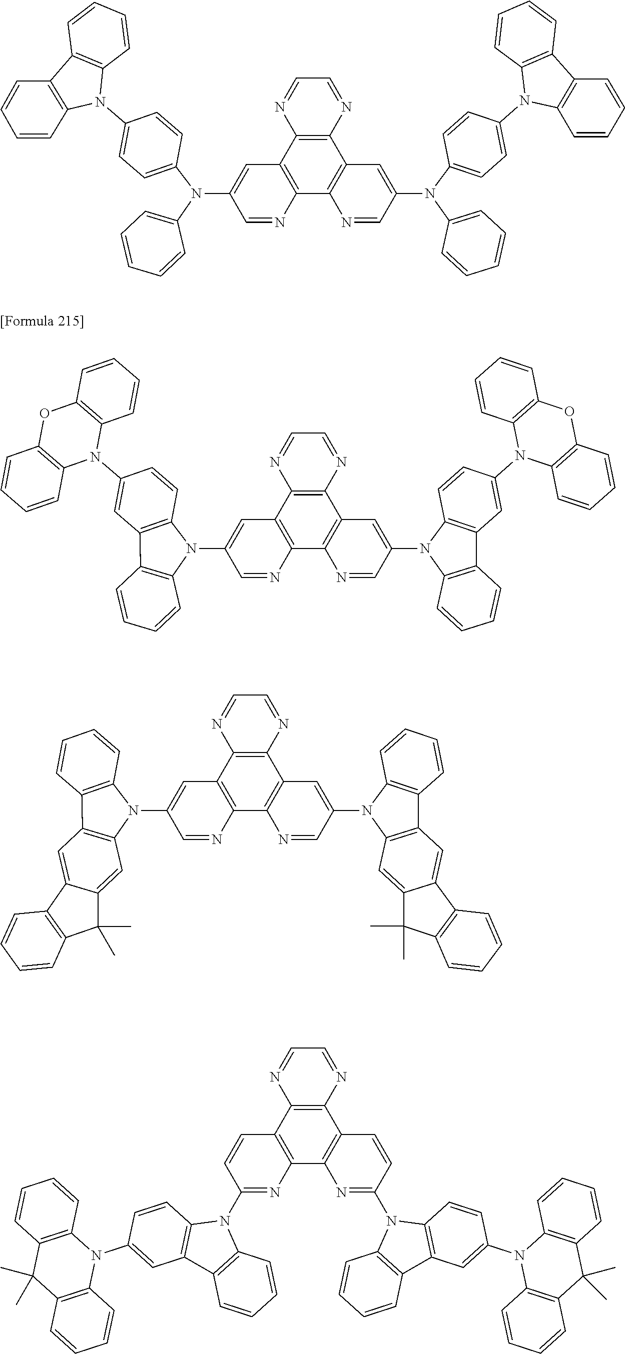

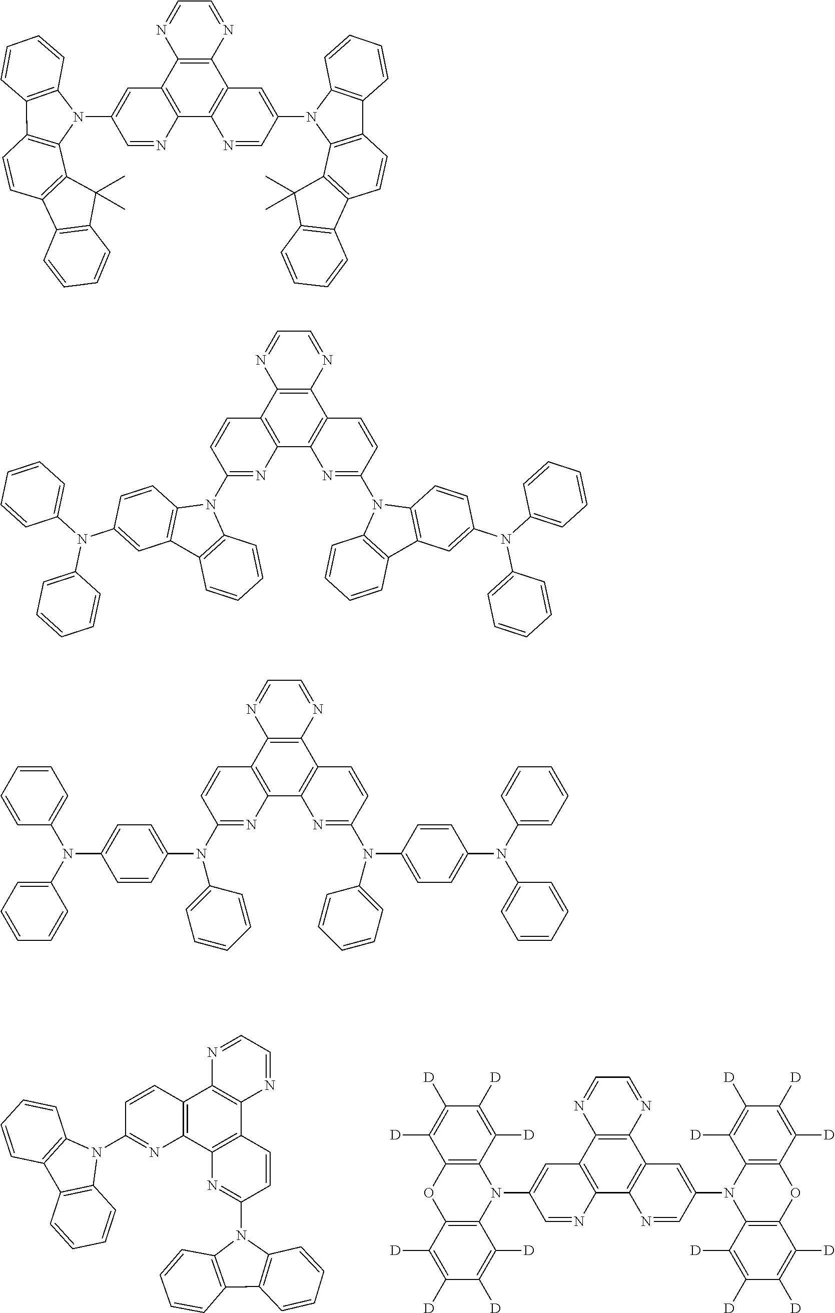

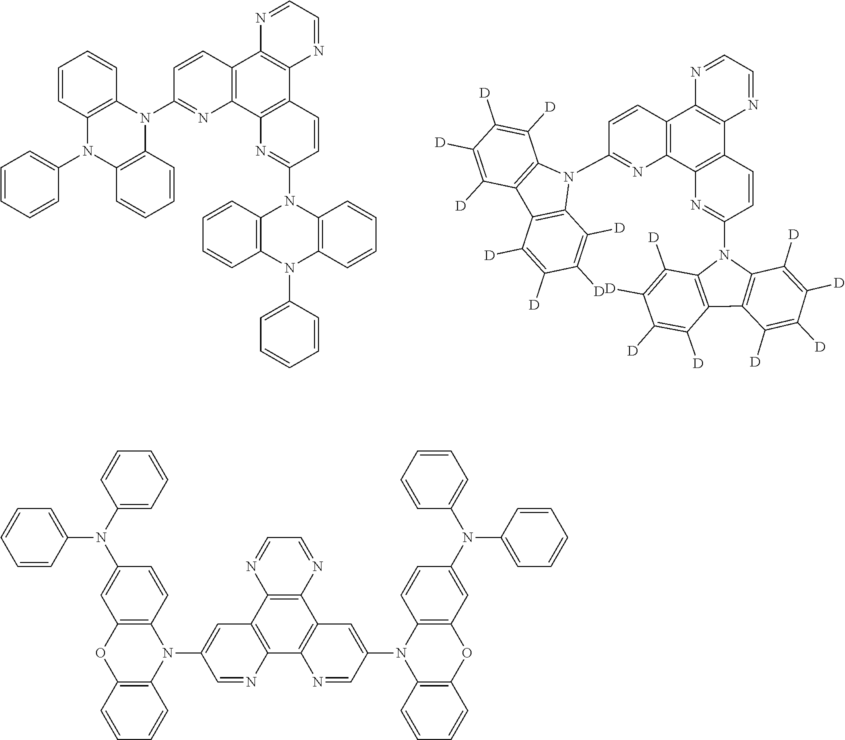 [SMILES: c1ccc(N2c3ccccc3N(c3ccc4c5nccnc5c5ccc(N6c7ccccc7N(c7ccccc7)c7ccccc76)nc5c4n3)c3ccccc32)cc1 ; [2H]c1c([2H])c([2H])c2c(c1[2H])c1c([2H])c([2H])c([2H])c([2H])c1n2-c1ccc2c3nccnc3c3ccc(-n4c5c([2H])c([2H])c([2H])c([2H])c5c5c([2H])c([2H])c([2H])c([2H])c54)nc3c2n1 ; c1ccc(N(c2ccccc2)c2ccc3c(c2)Oc2ccccc2N3c2cnc3c(c2)c2nccnc2c2cc(N4c5ccccc5Oc5cc(N(c6ccccc6)c6ccccc6)ccc54)cnc23)cc1]

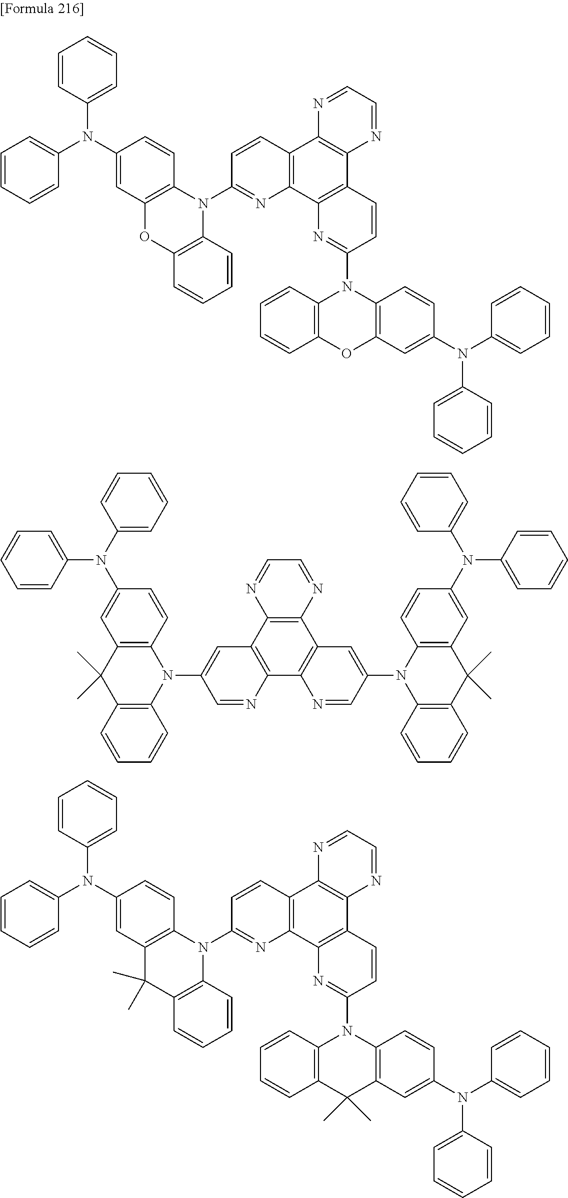

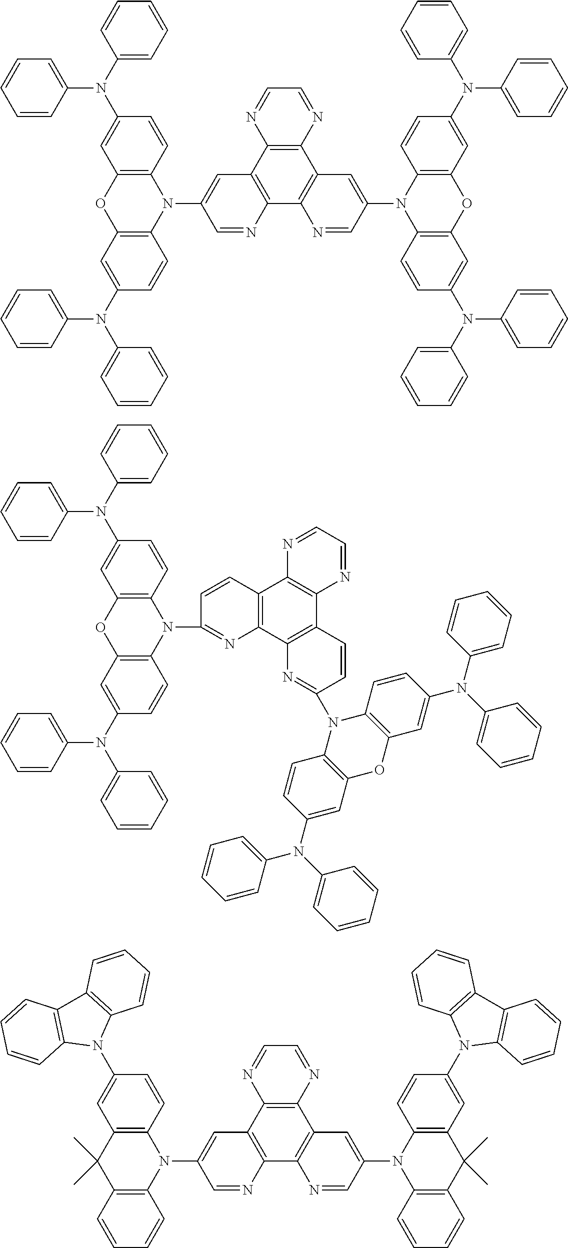

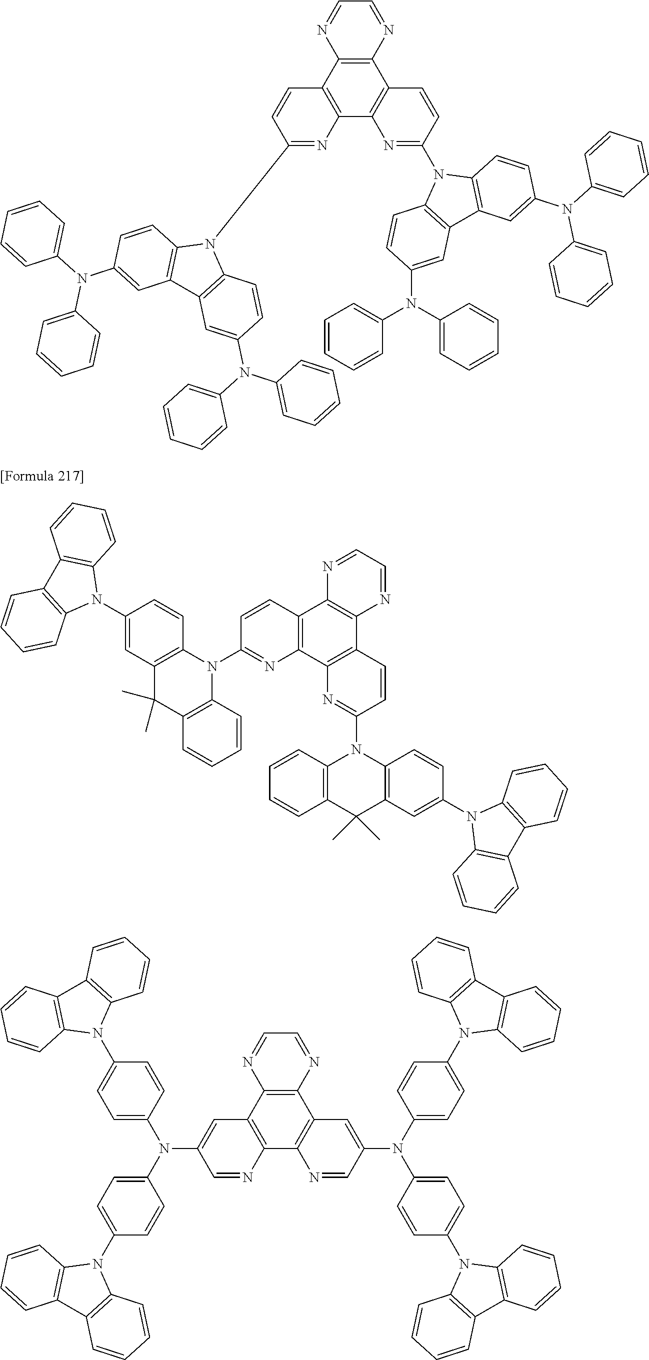

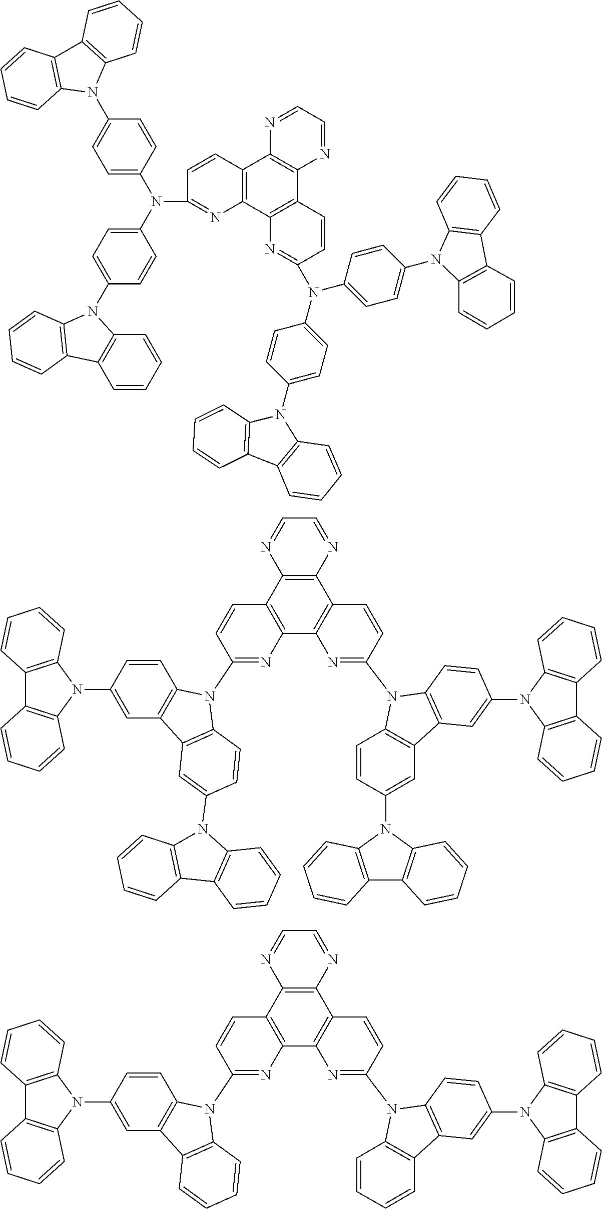

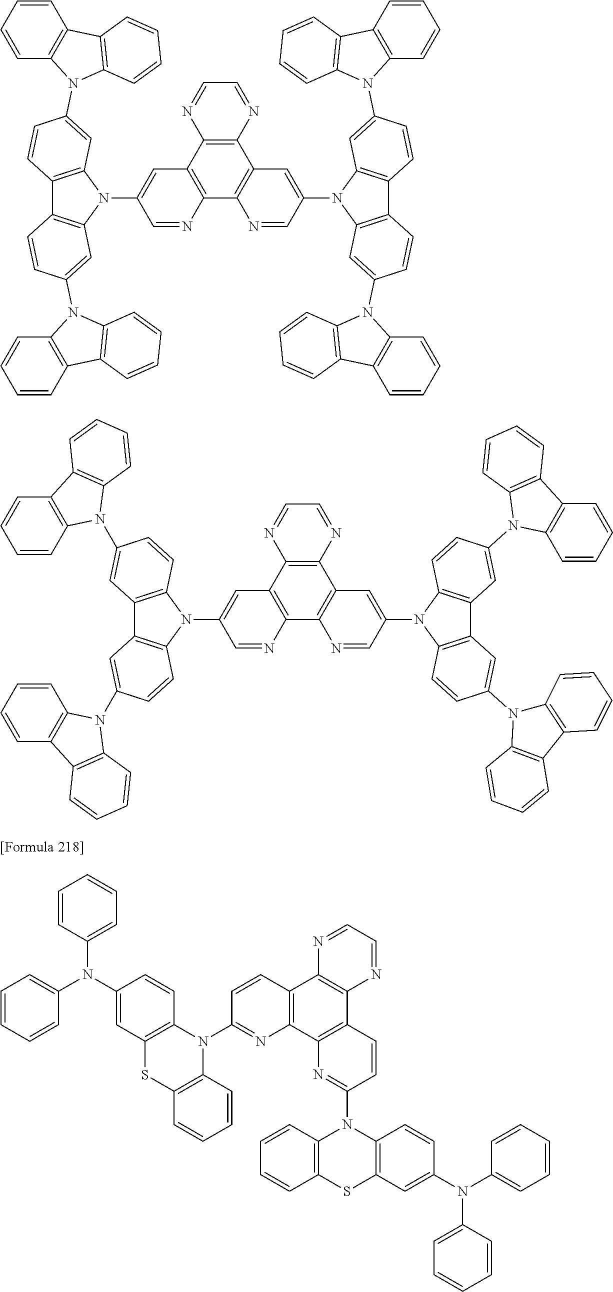 [SMILES: c1ccc2c(c1)c1ccccc1n2-c1ccc2c3ccc(-n4c5ccccc5c5ccccc54)cc3n(-c3cnc4c(c3)c3nccnc3c3cc(-n5c6cc(-n7c8ccccc8c8ccccc87)ccc6c6ccc(-n7c8ccccc8c8ccccc87)cc65)cnc34)c2c1 ; c1ccc2c(c1)c1ccccc1n2-c1ccc2c(c1)c1cc(-n3c4ccccc4c4ccccc43)ccc1n2-c1cnc2c(c1)c1nccnc1c1cc(-n3c4ccc(-n5c6ccccc6c6ccccc65)cc4c4cc(-n5c6ccccc6c6ccccc65)ccc43)cnc12 ; c1ccc(N(c2ccccc2)c2ccc3c(c2)Sc2ccccc2N3c2ccc3c4nccnc4c4ccc(N5c6ccccc6Sc6cc(N(c7ccccc7)c7ccccc7)ccc65)nc4c3n2)cc1]

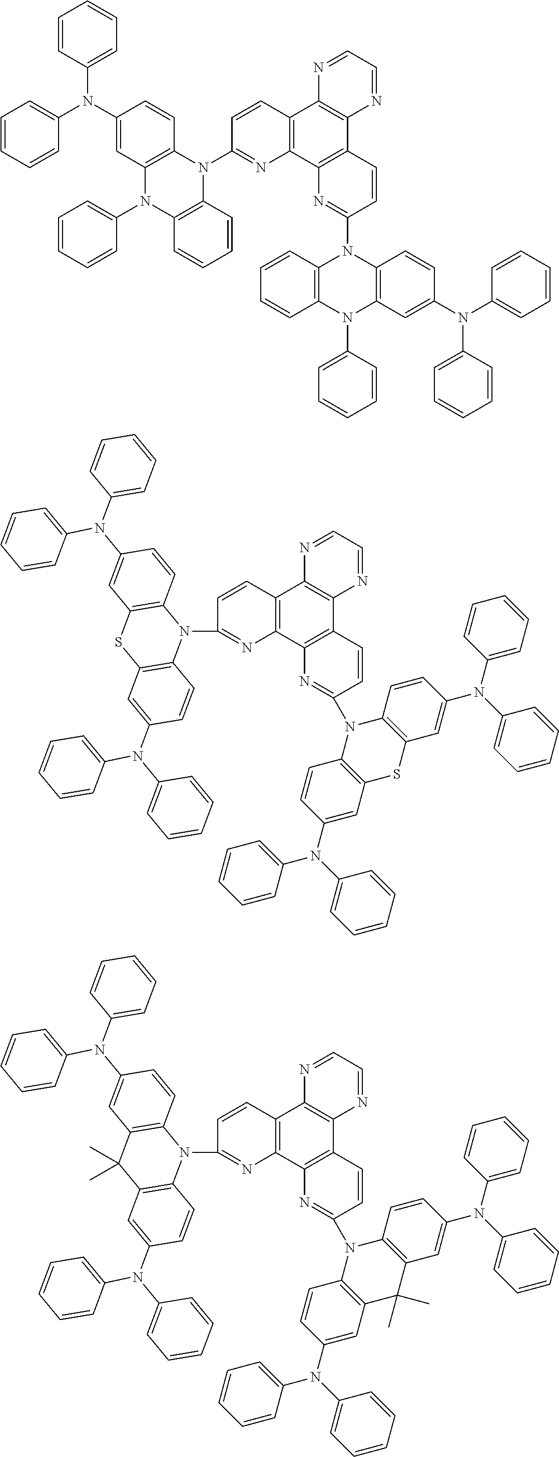 [SMILES: c1ccc(N(c2ccccc2)c2ccc3c(c2)N(c2ccccc2)c2ccccc2N3c2ccc3c4nccnc4c4ccc(N5c6ccccc6N(c6ccccc6)c6cc(N(c7ccccc7)c7ccccc7)ccc65)nc4c3n2)cc1 ; c1ccc(N(c2ccccc2)c2ccc3c(c2)Sc2cc(N(c4ccccc4)c4ccccc4)ccc2N3c2ccc3c4nccnc4c4ccc(N5c6ccc(N(c7ccccc7)c7ccccc7)cc6Sc6cc(N(c7ccccc7)c7ccccc7)ccc65)nc4c3n2)cc1 ; CC1(C)c2cc(N(c3ccccc3)c3ccccc3)ccc2N(c2ccc3c4nccnc4c4ccc(N5c6ccc(N(c7ccccc7)c7ccccc7)cc6C(C)(C)c6cc(N(c7ccccc7)c7ccccc7)ccc65)nc4c3n2)c2ccc(N(c3ccccc3)c3ccccc3)cc21]

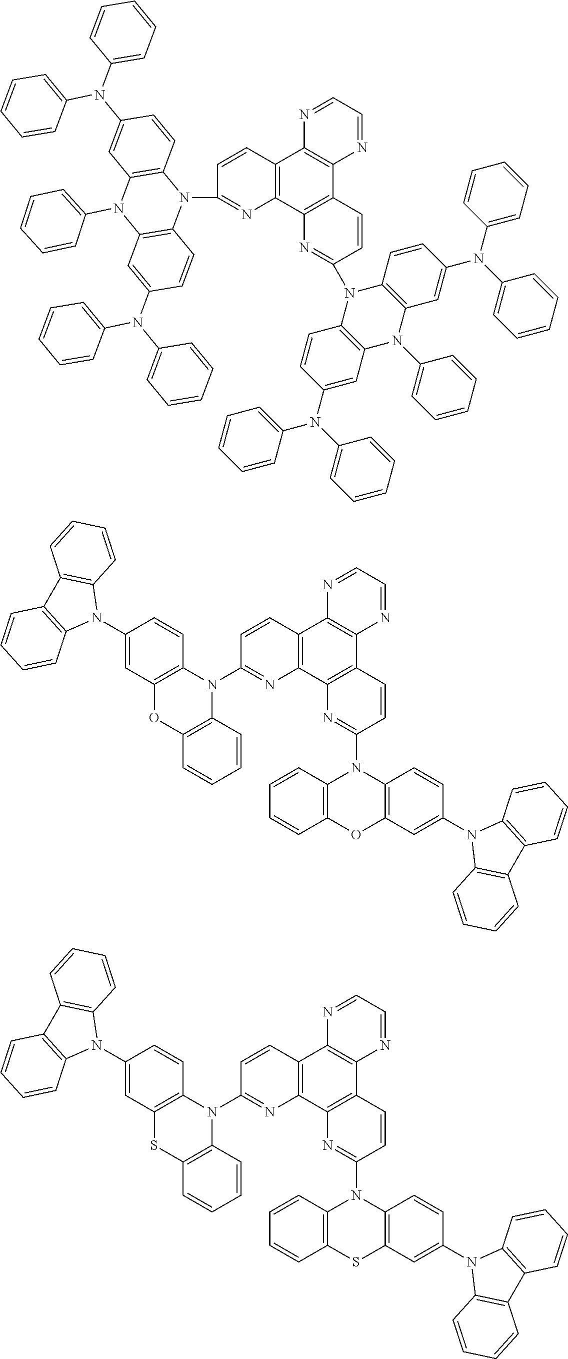 [SMILES: c1ccc(N(c2ccccc2)c2ccc3c(c2)N(c2ccccc2)c2cc(N(c4ccccc4)c4ccccc4)ccc2N3c2ccc3c4nccnc4c4ccc(N5c6ccc(N(c7ccccc7)c7ccccc7)cc6N(c6ccccc6)c6cc(N(c7ccccc7)c7ccccc7)ccc65)nc4c3n2)cc1 ; c1ccc2c(c1)Oc1cc(-n3c4ccccc4c4ccccc43)ccc1N2c1ccc2c3nccnc3c3ccc(N4c5ccccc5Oc5cc(-n6c7ccccc7c7ccccc76)ccc54)nc3c2n1 ; c1ccc2c(c1)Sc1cc(-n3c4ccccc4c4ccccc43)ccc1N2c1ccc2c3nccnc3c3ccc(N4c5ccccc5Sc5cc(-n6c7ccccc7c7ccccc76)ccc54)nc3c2n1]

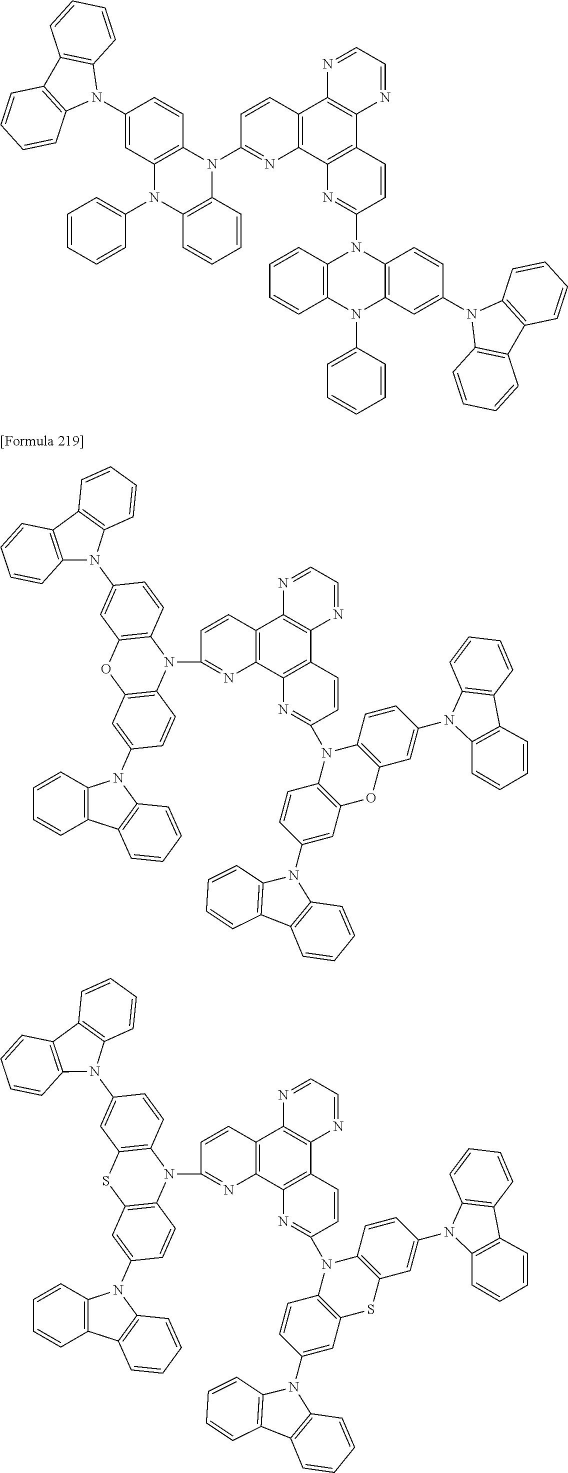 [SMILES: c1ccc(N2c3ccccc3N(c3ccc4c5nccnc5c5ccc(N6c7ccccc7N(c7ccccc7)c7cc(-n8c9ccccc9c9ccccc98)ccc76)nc5c4n3)c3ccc(-n4c5ccccc5c5ccccc54)cc32)cc1 ; c1ccc2c(c1)c1ccccc1n2-c1ccc2c(c1)Oc1cc(-n3c4ccccc4c4ccccc43)ccc1N2c1ccc2c3nccnc3c3ccc(N4c5ccc(-n6c7ccccc7c7ccccc76)cc5Oc5cc(-n6c7ccccc7c7ccccc76)ccc54)nc3c2n1 ; c1ccc2c(c1)c1ccccc1n2-c1ccc2c(c1)Sc1cc(-n3c4ccccc4c4ccccc43)ccc1N2c1ccc2c3nccnc3c3ccc(N4c5ccc(-n6c7ccccc7c7ccccc76)cc5Sc5cc(-n6c7ccccc7c7ccccc76)ccc54)nc3c2n1]

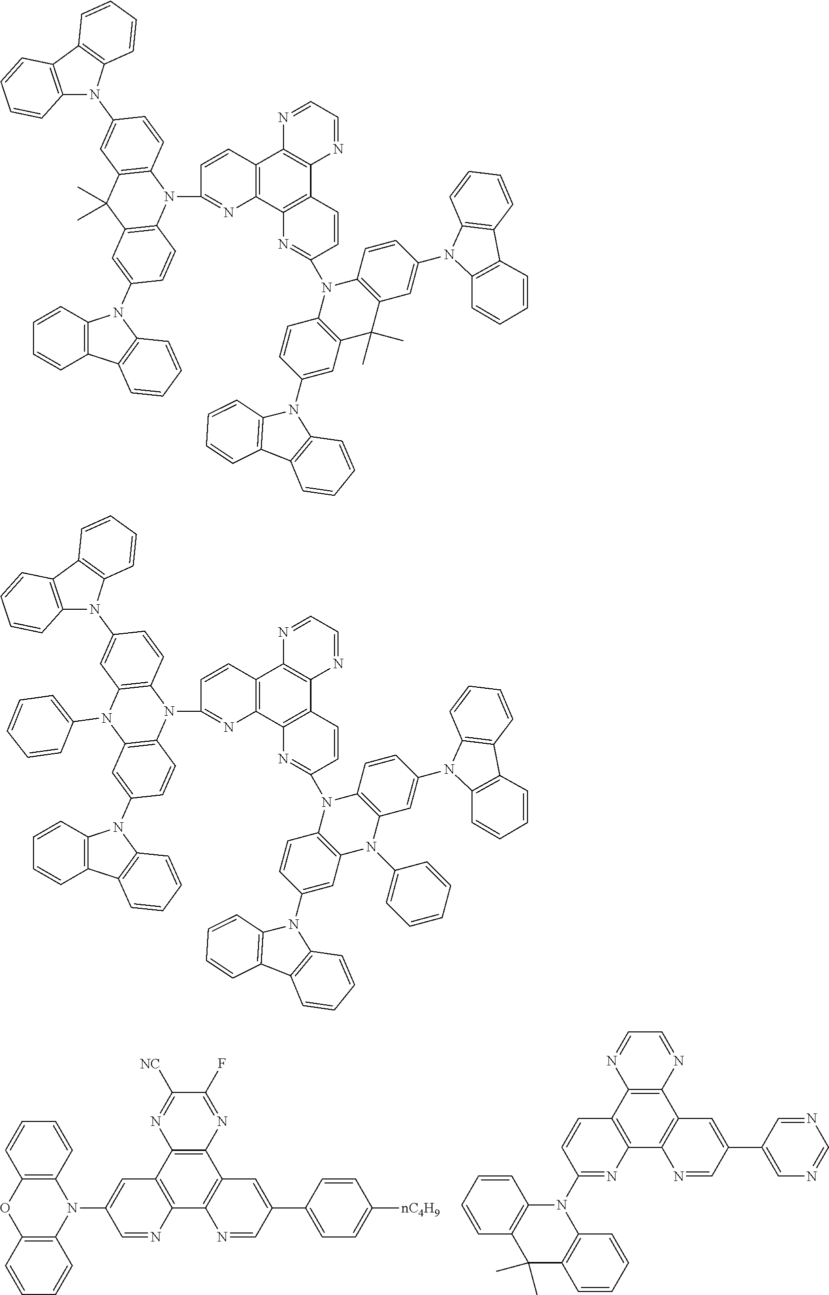

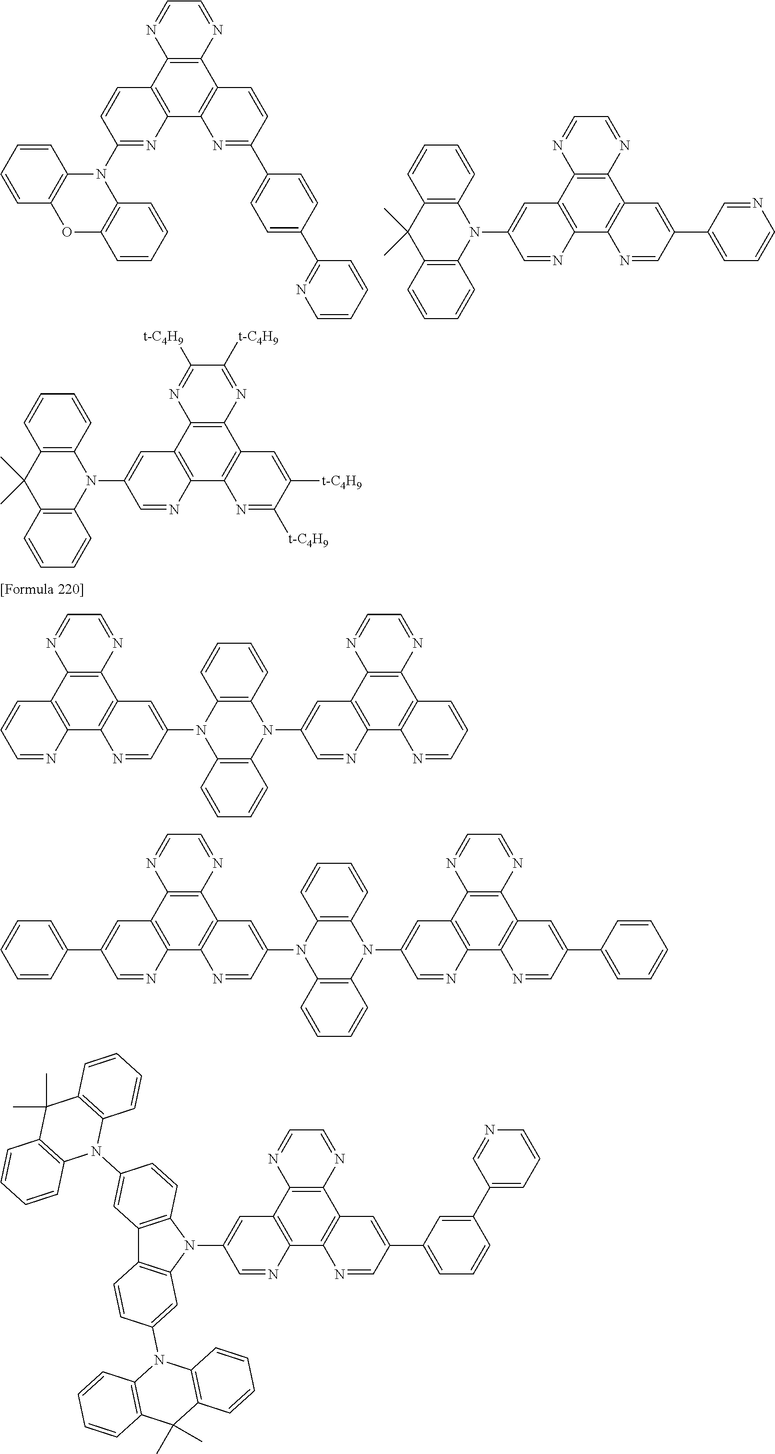

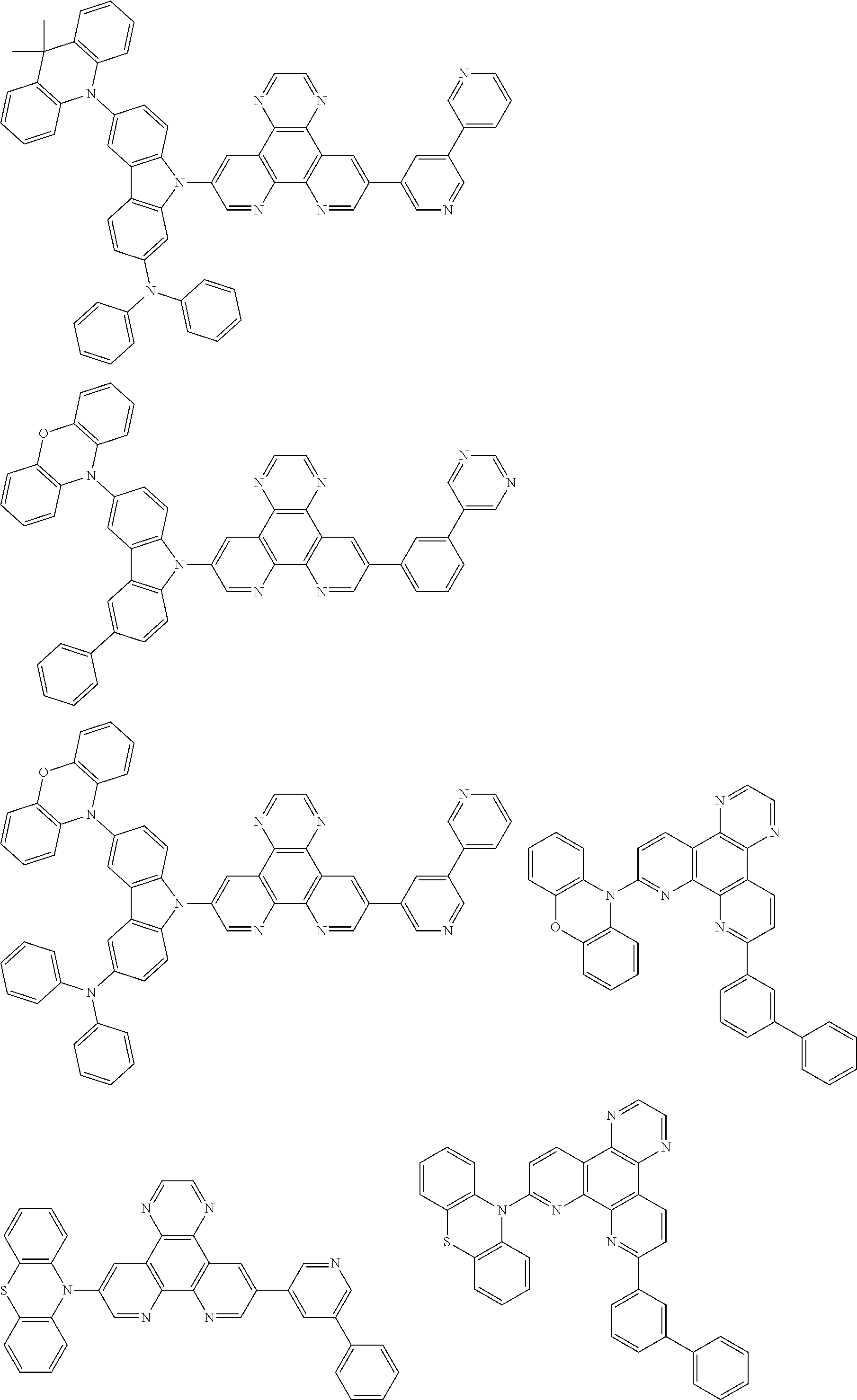

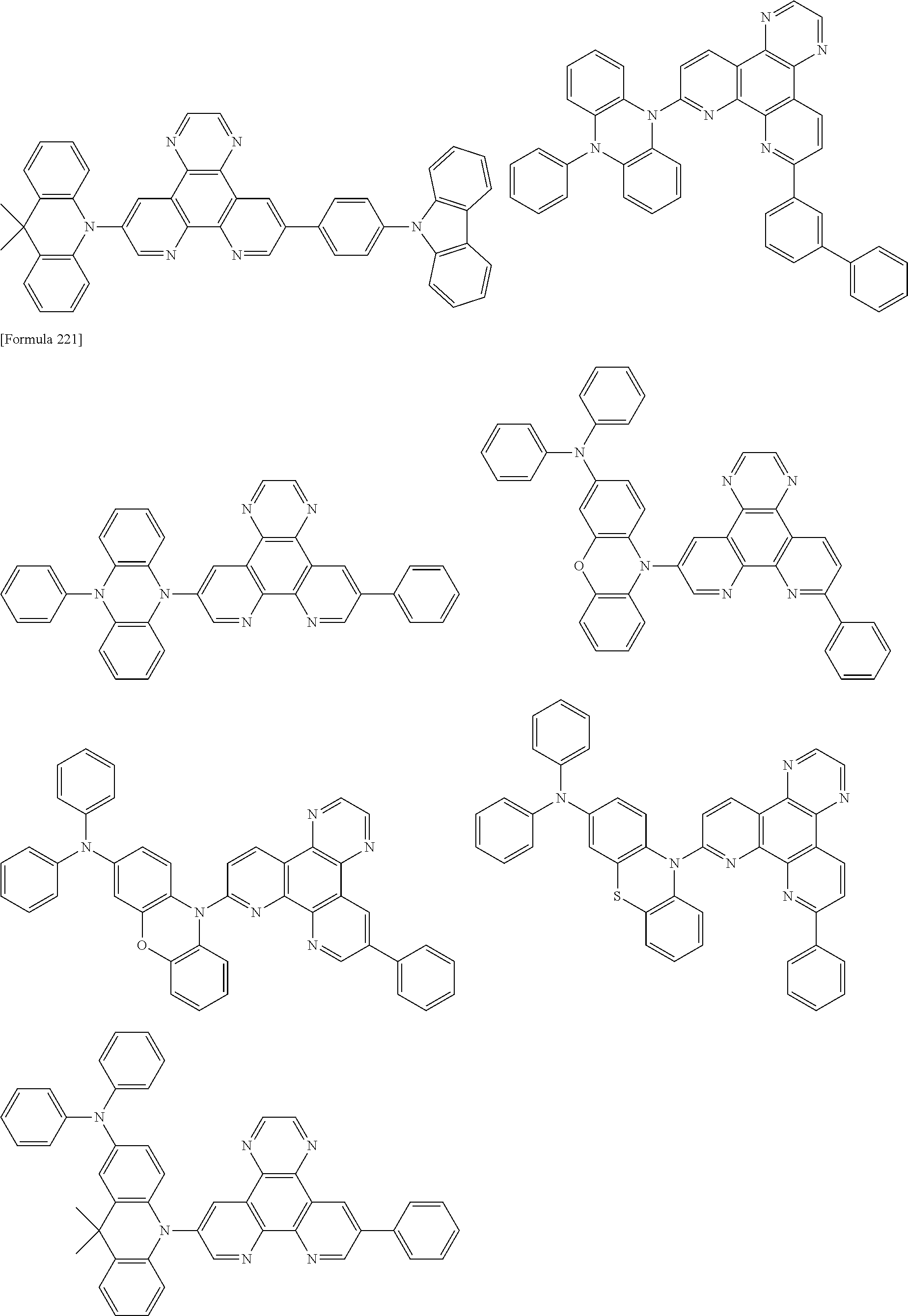

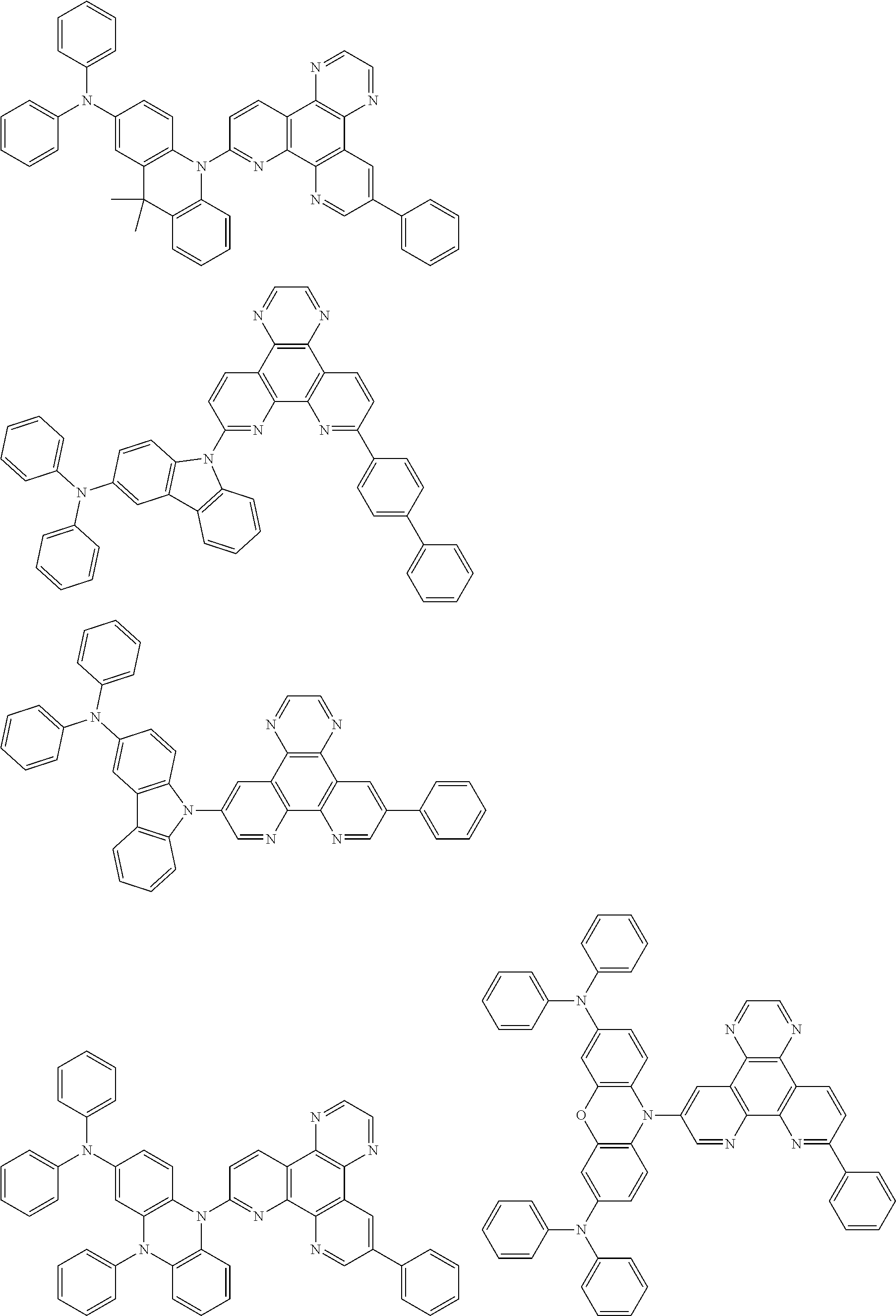

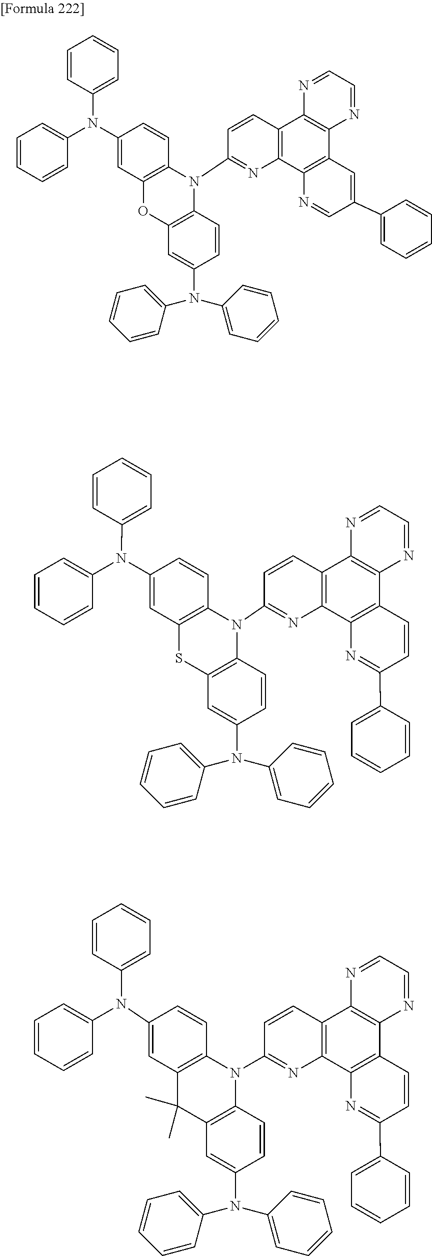 [SMILES: c1ccc(-c2cnc3c(c2)c2nccnc2c2ccc(N4c5ccc(N(c6ccccc6)c6ccccc6)cc5Oc5cc(N(c6ccccc6)c6ccccc6)ccc54)nc23)cc1 ; c1ccc(-c2ccc3c4nccnc4c4ccc(N5c6ccc(N(c7ccccc7)c7ccccc7)cc6Sc6cc(N(c7ccccc7)c7ccccc7)ccc65)nc4c3n2)cc1 ; CC1(C)c2cc(N(c3ccccc3)c3ccccc3)ccc2N(c2ccc3c4nccnc4c4ccc(-c5ccccc5)nc4c3n2)c2ccc(N(c3ccccc3)c3ccccc3)cc21]

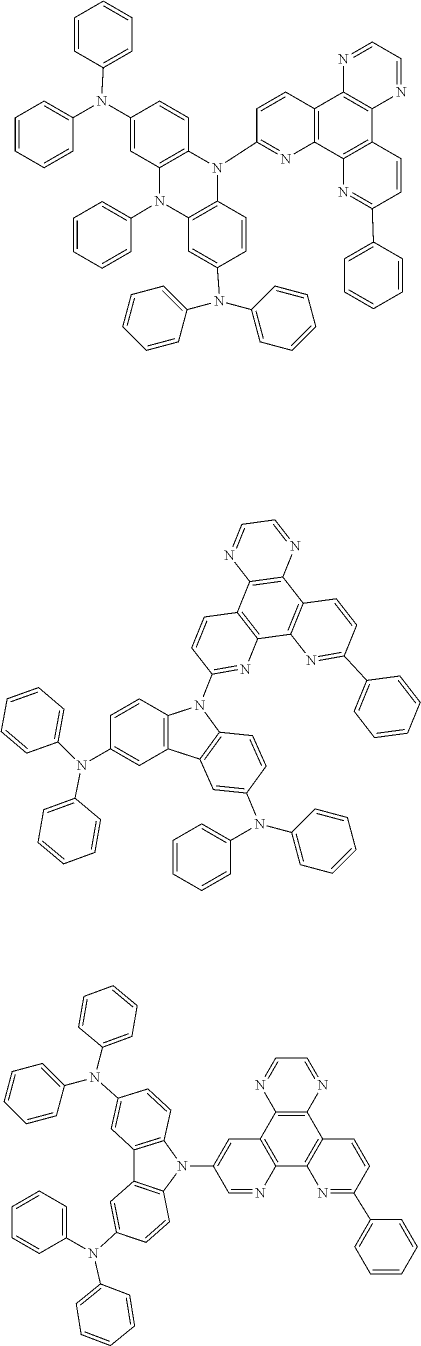 [SMILES: c1ccc(-c2ccc3c4nccnc4c4ccc(N5c6ccc(N(c7ccccc7)c7ccccc7)cc6N(c6ccccc6)c6cc(N(c7ccccc7)c7ccccc7)ccc65)nc4c3n2)cc1 ; c1ccc(-c2ccc3c4nccnc4c4ccc(-n5c6ccc(N(c7ccccc7)c7ccccc7)cc6c6cc(N(c7ccccc7)c7ccccc7)ccc65)nc4c3n2)cc1 ; c1ccc(-c2ccc3c4nccnc4c4cc(-n5c6ccc(N(c7ccccc7)c7ccccc7)cc6c6cc(N(c7ccccc7)c7ccccc7)ccc65)cnc4c3n2)cc1]

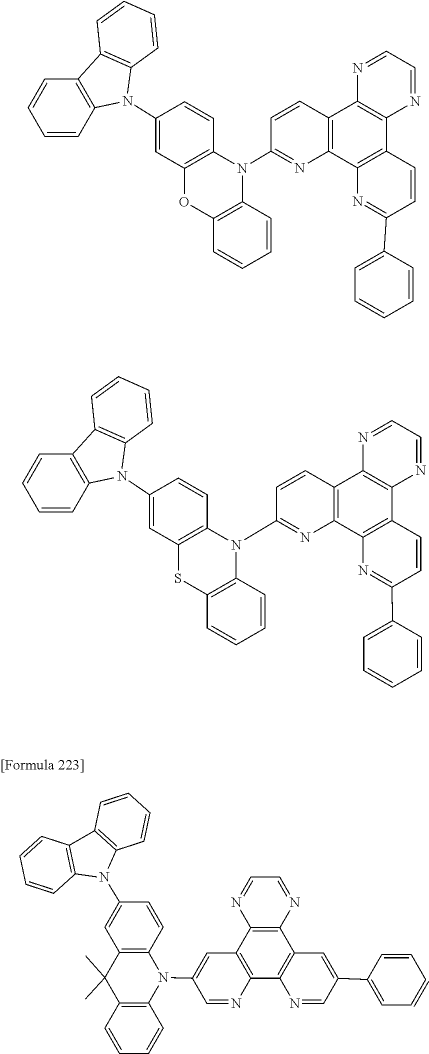 [SMILES: c1ccc(-c2ccc3c4nccnc4c4ccc(N5c6ccccc6Oc6cc(-n7c8ccccc8c8ccccc87)ccc65)nc4c3n2)cc1 ; c1ccc(-c2ccc3c4nccnc4c4ccc(N5c6ccccc6Sc6cc(-n7c8ccccc8c8ccccc87)ccc65)nc4c3n2)cc1 ; CC1(C)c2ccccc2N(c2cnc3c(c2)c2nccnc2c2cc(-c4ccccc4)cnc23)c2ccc(-n3c4ccccc4c4ccccc43)cc21]

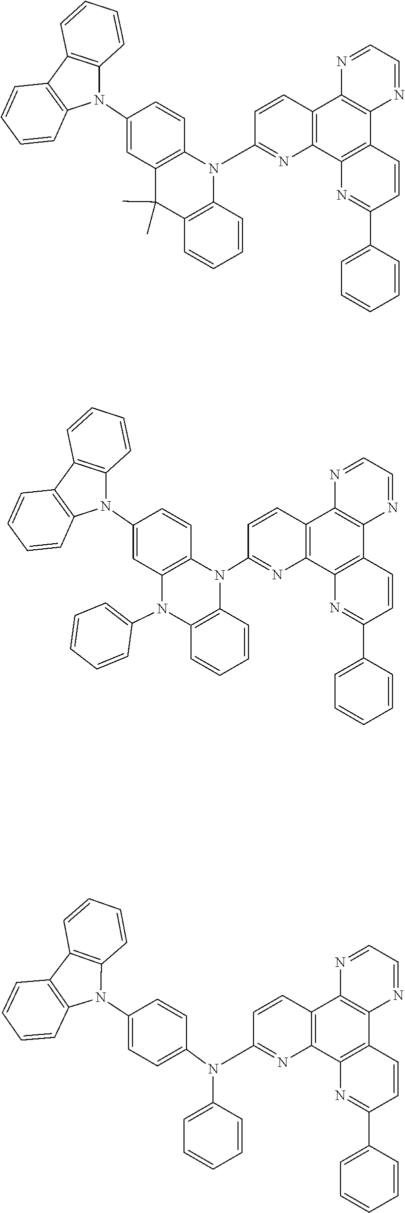 [SMILES: CC1(C)c2ccccc2N(c2ccc3c4nccnc4c4ccc(-c5ccccc5)nc4c3n2)c2ccc(-n3c4ccccc4c4ccccc43)cc21 ; c1ccc(-c2ccc3c4nccnc4c4ccc(N5c6ccccc6N(c6ccccc6)c6cc(-n7c8ccccc8c8ccccc87)ccc65)nc4c3n2)cc1 ; c1ccc(-c2ccc3c4nccnc4c4ccc(N(c5ccccc5)c5ccc(-n6c7ccccc7c7ccccc76)cc5)nc4c3n2)cc1]

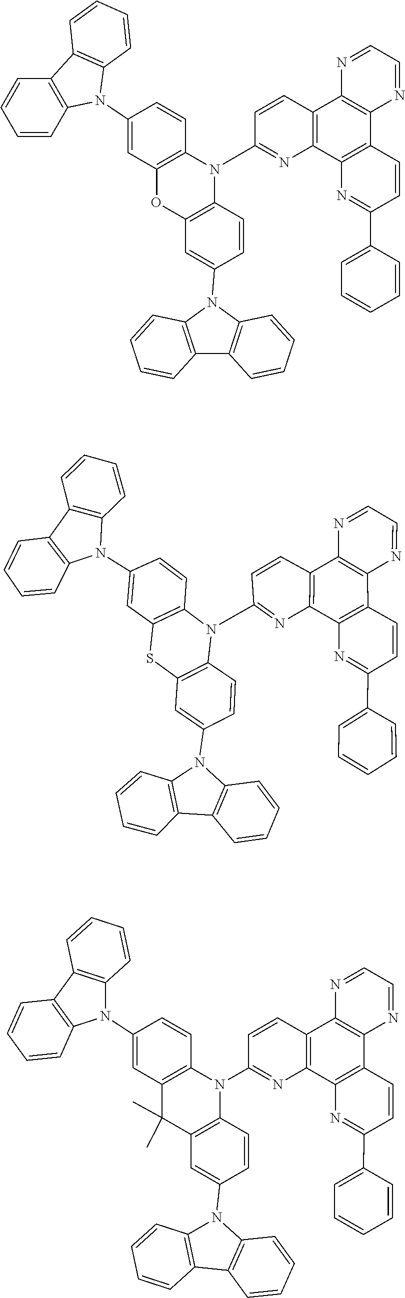 [SMILES: c1ccc(-c2ccc3c4nccnc4c4ccc(N5c6ccc(-n7c8ccccc8c8ccccc87)cc6Oc6cc(-n7c8ccccc8c8ccccc87)ccc65)nc4c3n2)cc1 ; c1ccc(-c2ccc3c4nccnc4c4ccc(N5c6ccc(-n7c8ccccc8c8ccccc87)cc6Sc6cc(-n7c8ccccc8c8ccccc87)ccc65)nc4c3n2)cc1 ; CC1(C)c2cc(-n3c4ccccc4c4ccccc43)ccc2N(c2ccc3c4nccnc4c4ccc(-c5ccccc5)nc4c3n2)c2ccc(-n3c4ccccc4c4ccccc43)cc21]

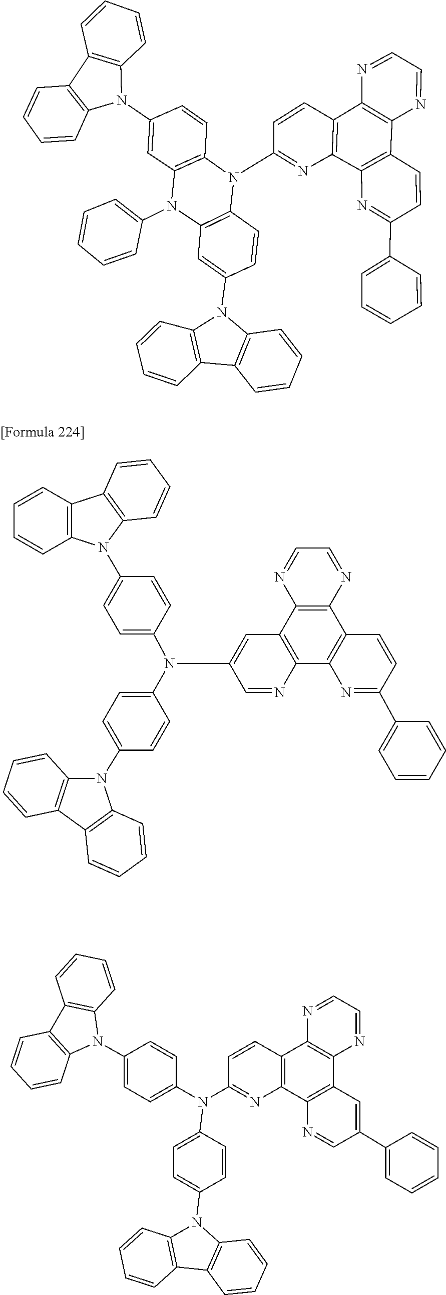 [SMILES: c1ccc(-c2ccc3c4nccnc4c4ccc(N5c6ccc(-n7c8ccccc8c8ccccc87)cc6N(c6ccccc6)c6cc(-n7c8ccccc8c8ccccc87)ccc65)nc4c3n2)cc1 ; c1ccc(-c2ccc3c4nccnc4c4cc(N(c5ccc(-n6c7ccccc7c7ccccc76)cc5)c5ccc(-n6c7ccccc7c7ccccc76)cc5)cnc4c3n2)cc1 ; c1ccc(-c2cnc3c(c2)c2nccnc2c2ccc(N(c4ccc(-n5c6ccccc6c6ccccc65)cc4)c4ccc(-n5c6ccccc6c6ccccc65)cc4)nc23)cc1]

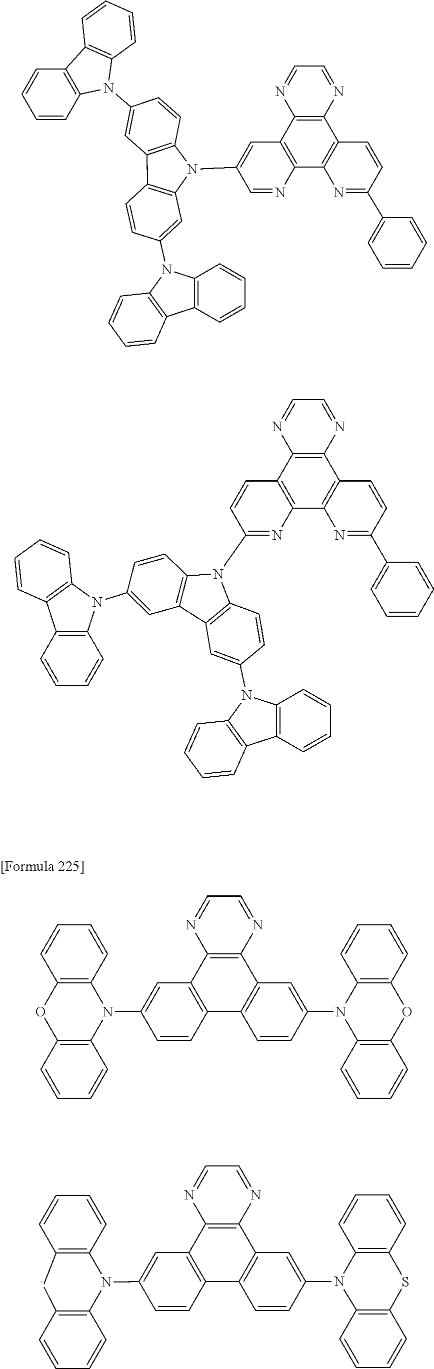 [SMILES: c1ccc(-c2ccc3c4nccnc4c4cc(-n5c6ccc(-n7c8ccccc8c8ccccc87)cc6c6ccc(-n7c8ccccc8c8ccccc87)cc65)cnc4c3n2)cc1 ; c1ccc(-c2ccc3c4nccnc4c4ccc(-n5c6ccc(-n7c8ccccc8c8ccccc87)cc6c6cc(-n7c8ccccc8c8ccccc87)ccc65)nc4c3n2)cc1 ; c1ccc2c(c1)Oc1ccccc1N2c1ccc2c3ccc(N4c5ccccc5Oc5ccccc54)cc3c3nccnc3c2c1 ; Cc1ccccc1N(c1ccc2c3ccc(N4c5ccccc5Sc5ccccc54)cc3c3nccnc3c2c1)c1ccccc1C]

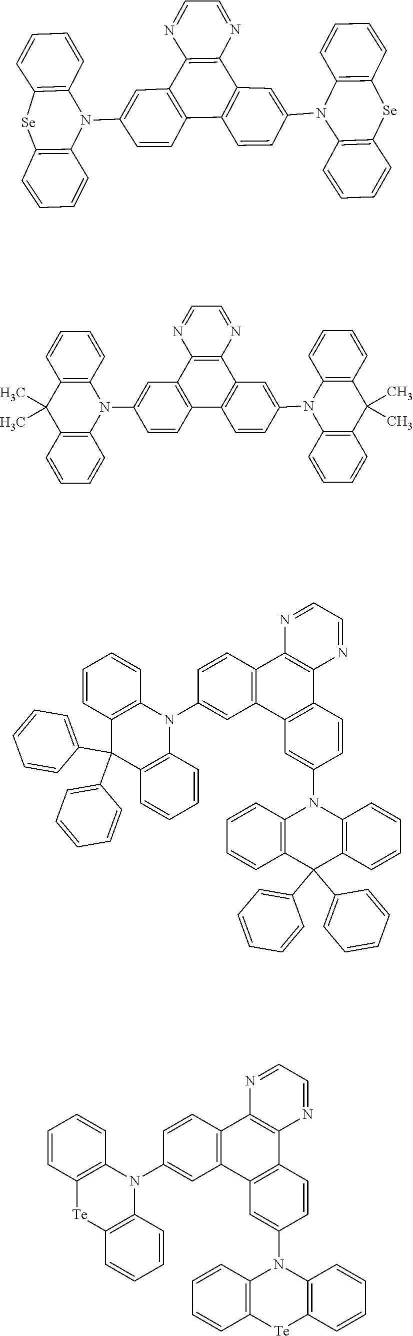

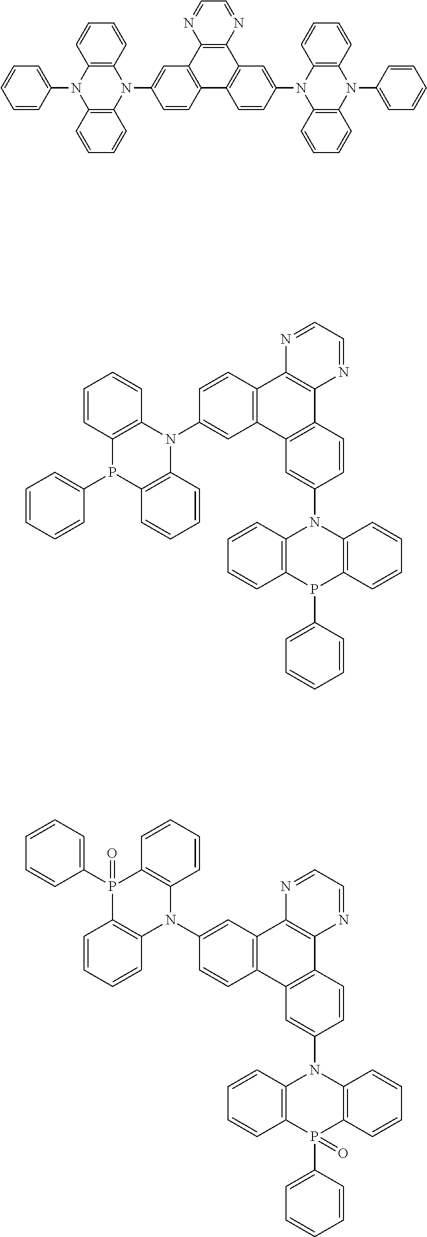

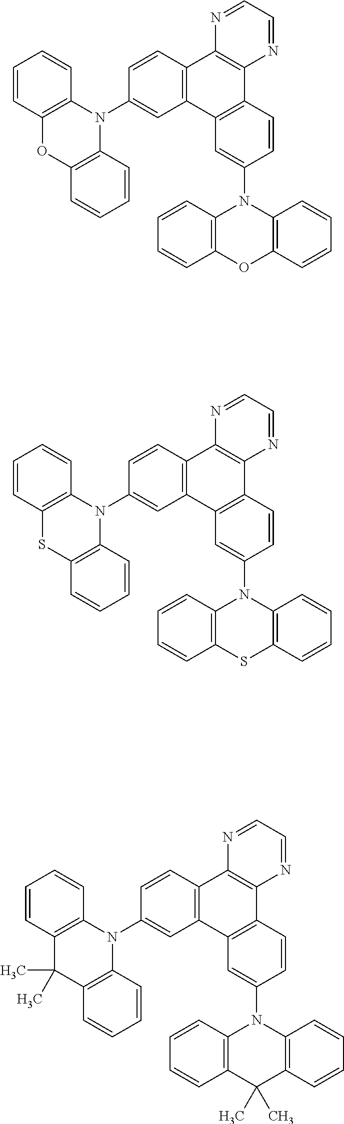 [SMILES: c1ccc2c(c1)Oc1ccccc1N2c1ccc2c(c1)c1cc(N3c4ccccc4Oc4ccccc43)ccc1c1nccnc21 ; c1ccc2c(c1)Sc1ccccc1N2c1ccc2c(c1)c1cc(N3c4ccccc4Sc4ccccc43)ccc1c1nccnc21 ; CC1(C)c2ccccc2N(c2ccc3c(c2)c2cc(N4c5ccccc5C(C)(C)c5ccccc54)ccc2c2nccnc32)c2ccccc21]

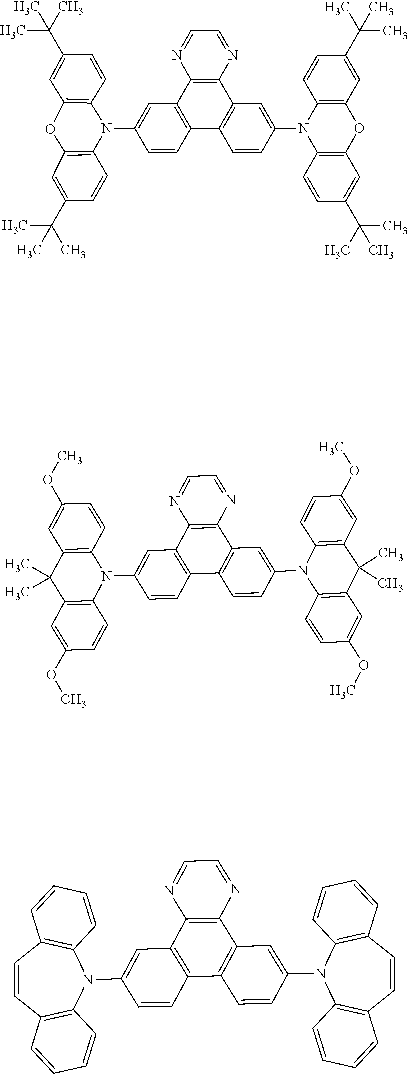

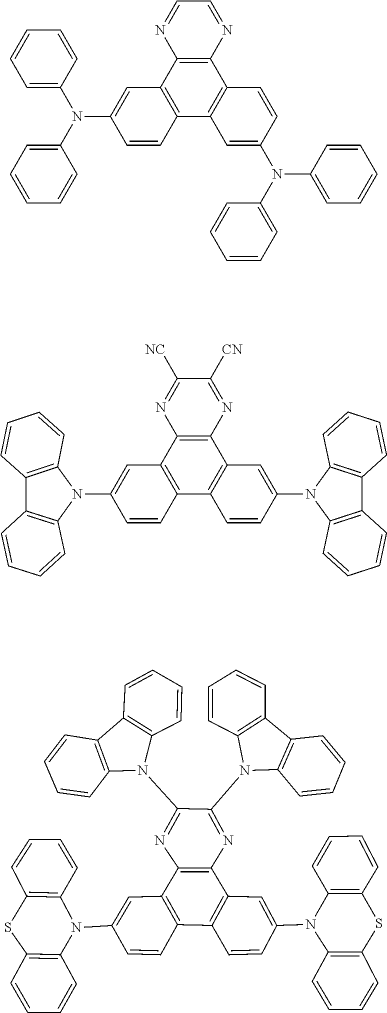 [SMILES: c1ccc(N(c2ccccc2)c2ccc3c(c2)c2ccc(N(c4ccccc4)c4ccccc4)cc2c2nccnc32)cc1 ; N#Cc1nc2c3cc(-n4c5ccccc5c5ccccc54)ccc3c3ccc(-n4c5ccccc5c5ccccc54)cc3c2nc1C#N ; c1ccc2c(c1)Sc1ccccc1N2c1ccc2c3ccc(N4c5ccccc5Sc5ccccc54)cc3c3nc(-n4c5ccccc5c5ccccc54)c(-n4c5ccccc5c5ccccc54)nc3c2c1]

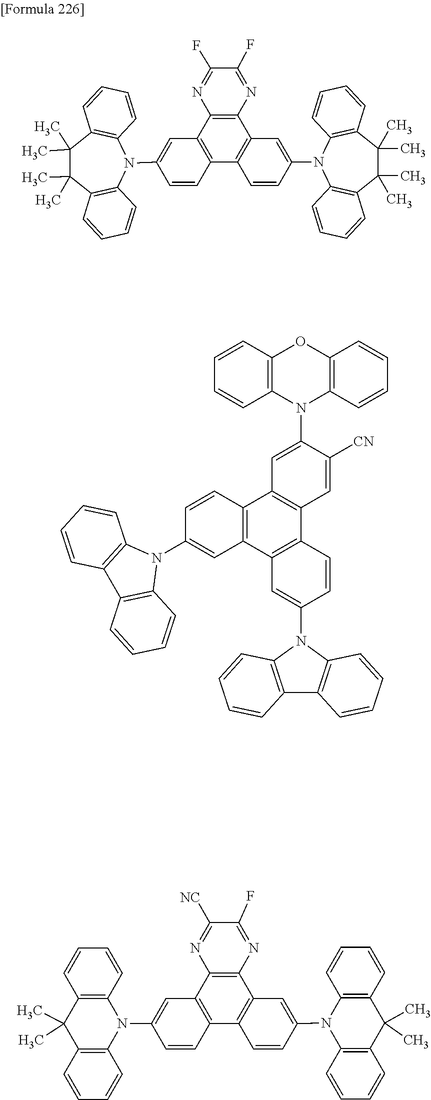

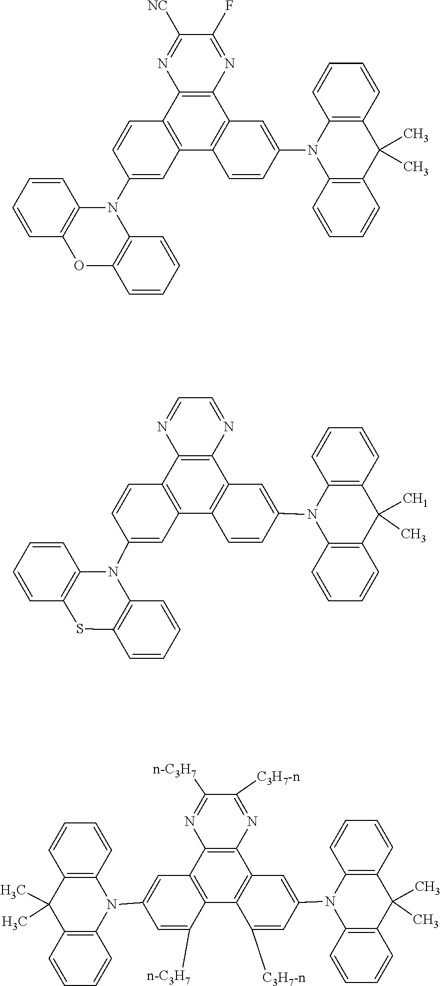

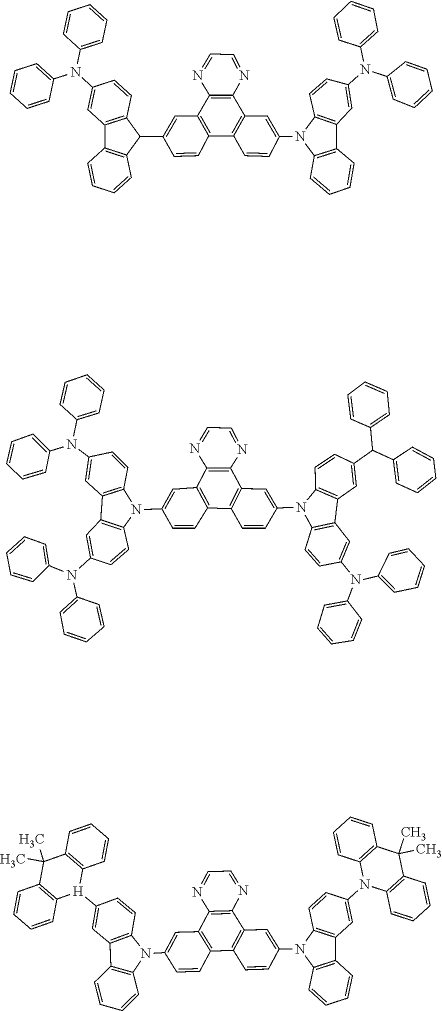

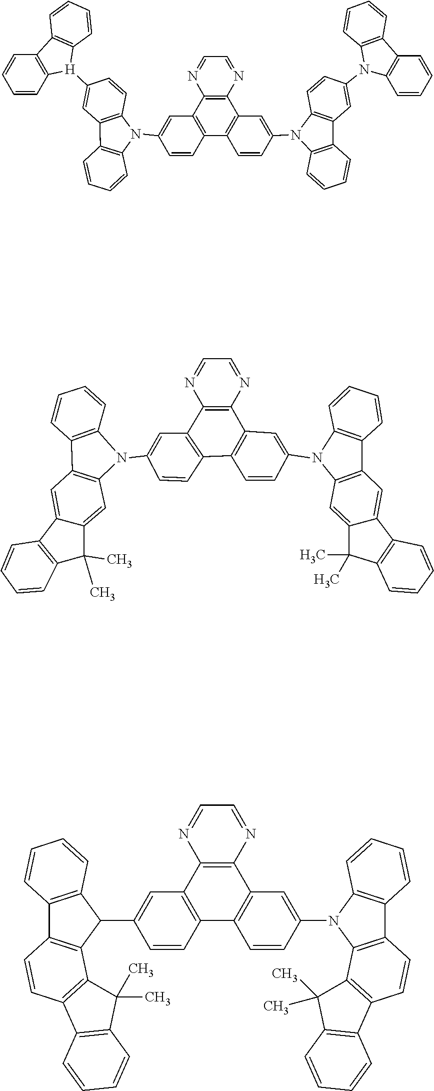

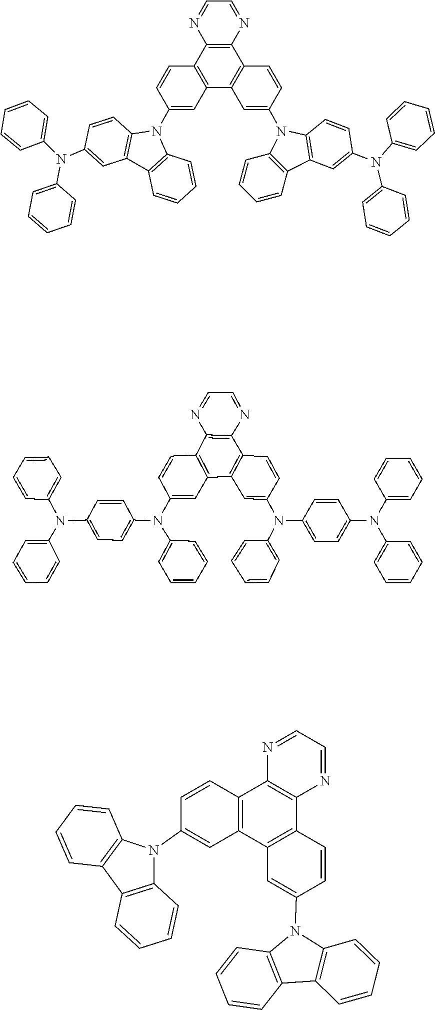 [SMILES: c1ccc(N(c2ccccc2)c2ccc3c(c2)c2ccccc2n3-c2ccc3c(c2)c2cc(-n4c5ccccc5c5cc(N(c6ccccc6)c6ccccc6)ccc54)ccc2c2nccnc32)cc1 ; c1ccc(N(c2ccccc2)c2ccc(N(c3ccccc3)c3ccc4c(c3)c3cc(N(c5ccccc5)c5ccc(N(c6ccccc6)c6ccccc6)cc5)ccc3c3nccnc43)cc2)cc1 ; c1ccc2c(c1)c1ccccc1n2-c1ccc2c(c1)c1cc(-n3c4ccccc4c4ccccc43)ccc1c1nccnc21]

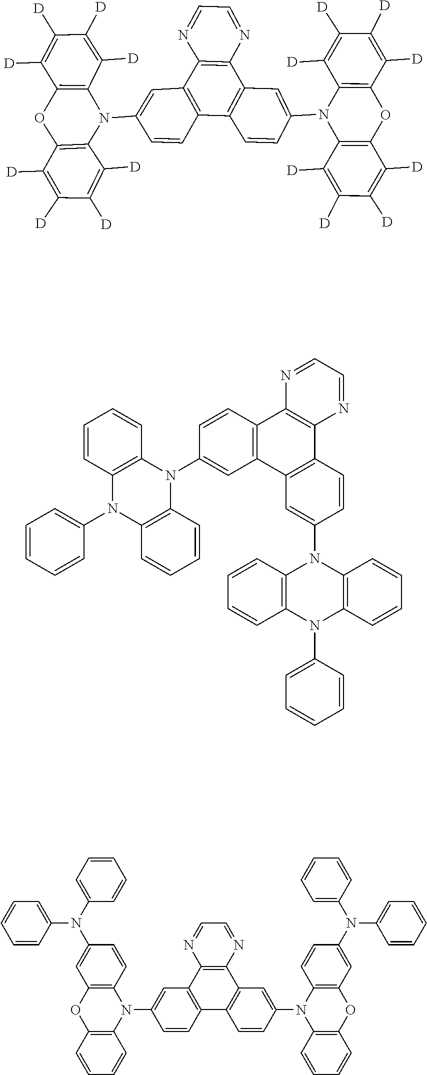 [SMILES: [2H]c1c([2H])c([2H])c2c(c1[2H])Oc1c([2H])c([2H])c([2H])c([2H])c1N2c1ccc2c3ccc(N4c5c([2H])c([2H])c([2H])c([2H])c5Oc5c([2H])c([2H])c([2H])c([2H])c54)cc3c3nccnc3c2c1 ; c1ccc(N2c3ccccc3N(c3ccc4c(c3)c3cc(N5c6ccccc6N(c6ccccc6)c6ccccc65)ccc3c3nccnc43)c3ccccc32)cc1 ; c1ccc(N(c2ccccc2)c2ccc3c(c2)Oc2ccccc2N3c2ccc3c4ccc(N5c6ccccc6Oc6cc(N(c7ccccc7)c7ccccc7)ccc65)cc4c4nccnc4c3c2)cc1]

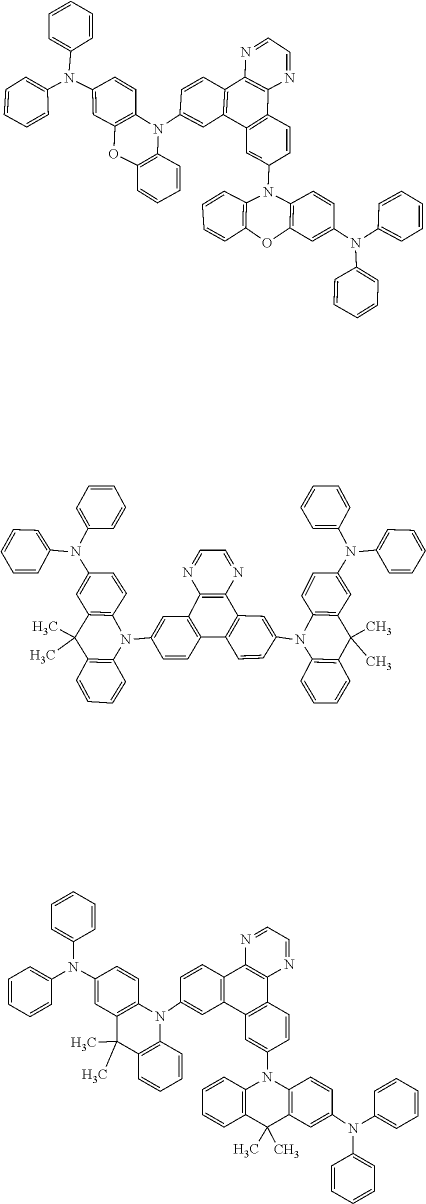 [SMILES: C1=CC(N2c3ccccc3Oc3cc(N(c4ccccc4)c4ccccc4)ccc32)C=Cc2c1c1cc(N3c4ccccc4Oc4cc(N(c5ccccc5)c5ccccc5)ccc43)ccc1c1nccnc21 ; CC1(C)c2ccccc2N(c2ccc3c4ccc(N5c6ccccc6C(C)(C)c6cc(N(c7ccccc7)c7ccccc7)ccc65)cc4c4nccnc4c3c2)c2ccc(N(c3ccccc3)c3ccccc3)cc21 ; CC1(C)c2ccccc2N(c2ccc3c(c2)c2cc(N4c5ccccc5C(C)(C)c5cc(N(c6ccccc6)c6ccccc6)ccc54)ccc2c2nccnc32)c2ccc(N(c3ccccc3)c3ccccc3)cc21]

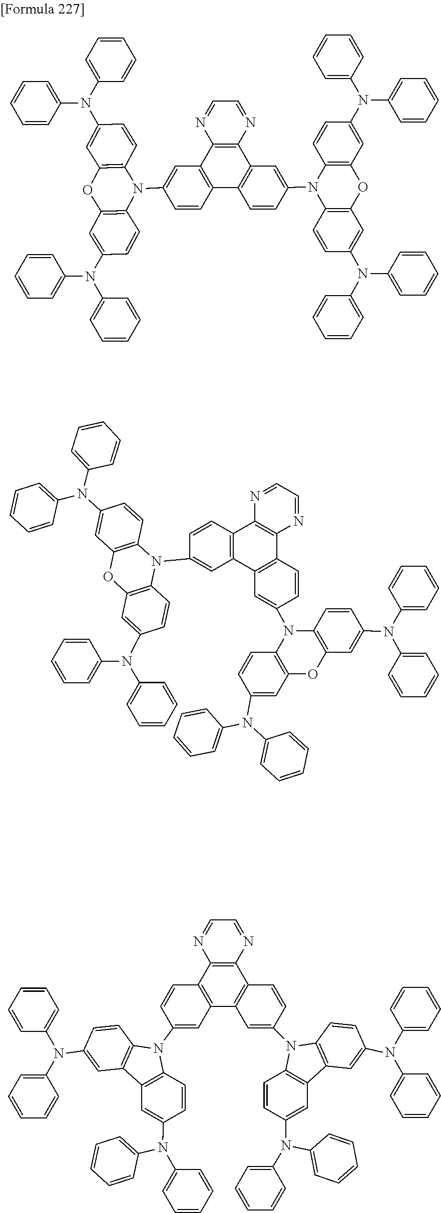 [SMILES: c1ccc(N(c2ccccc2)c2ccc3c(c2)Oc2cc(N(c4ccccc4)c4ccccc4)ccc2N3c2ccc3c4ccc(N5c6ccc(N(c7ccccc7)c7ccccc7)cc6Oc6cc(N(c7ccccc7)c7ccccc7)ccc65)cc4c4nccnc4c3c2)cc1 ; c1ccc(N(c2ccccc2)c2ccc3c(c2)Oc2cc(N(c4ccccc4)c4ccccc4)ccc2N3c2ccc3c(c2)c2cc(N4c5ccc(N(c6ccccc6)c6ccccc6)cc5Oc5cc(N(c6ccccc6)c6ccccc6)ccc54)ccc2c2nccnc32)cc1 ; c1ccc(N(c2ccccc2)c2ccc3c(c2)c2cc(N(c4ccccc4)c4ccccc4)ccc2n3-c2ccc3c(c2)c2cc(-n4c5ccc(N(c6ccccc6)c6ccccc6)cc5c5cc(N(c6ccccc6)c6ccccc6)ccc54)ccc2c2nccnc32)cc1]

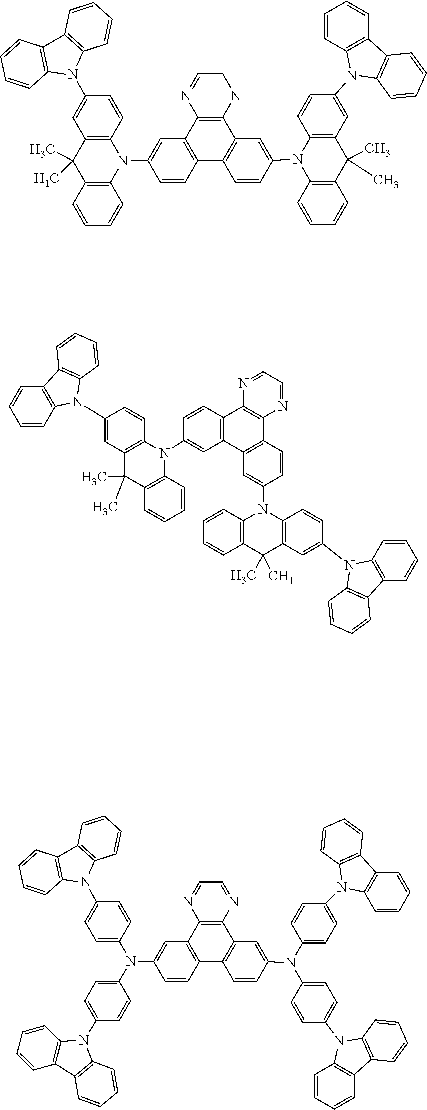

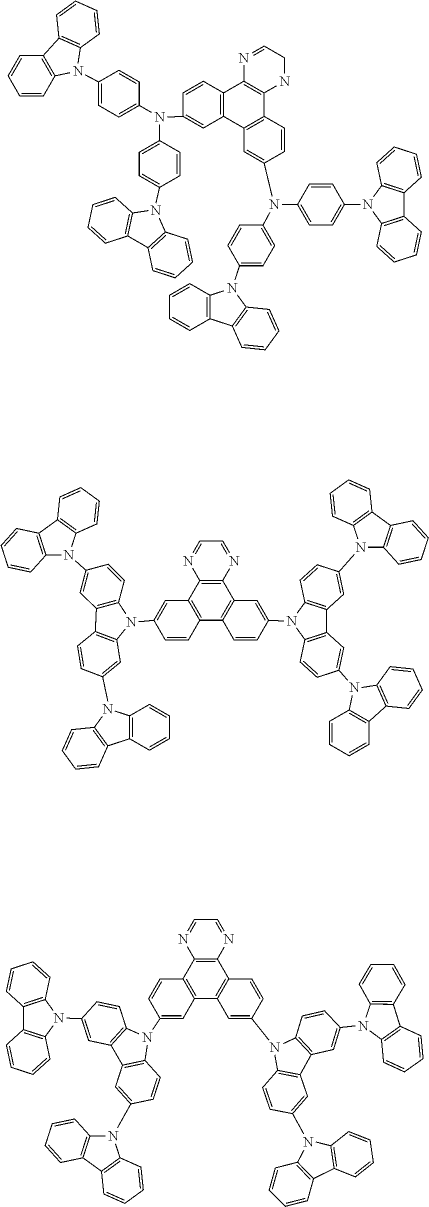 [SMILES: C1=Nc2c(c3ccc(N(c4ccc(-n5c6ccccc6c6ccccc65)cc4)c4ccc(-n5c6ccccc6c6ccccc65)cc4)cc3c3cc(N(c4ccc(-n5c6ccccc6c6ccccc65)cc4)c4ccc(-n5c6ccccc6c6ccccc65)cc4)ccc23)NC1 ; c1ccc2c(c1)c1ccccc1n2-c1ccc2c(c1)c1cc(-n3c4ccccc4c4ccccc43)ccc1n2-c1ccc2c3ccc(-n4c5ccc(-n6c7ccccc7c7ccccc76)cc5c5ccc(-n6c7ccccc7c7ccccc76)cc54)cc3c3nccnc3c2c1 ; c1ccc2c(c1)c1ccccc1n2-c1ccc2c(c1)c1cc(-n3c4ccccc4c4ccccc43)ccc1n2-c1ccc2c(c1)c1cc(-n3c4ccc(-n5c6ccccc6c6ccccc65)cc4c4cc(-n5c6ccccc6c6ccccc65)ccc43)ccc1c1nccnc21]

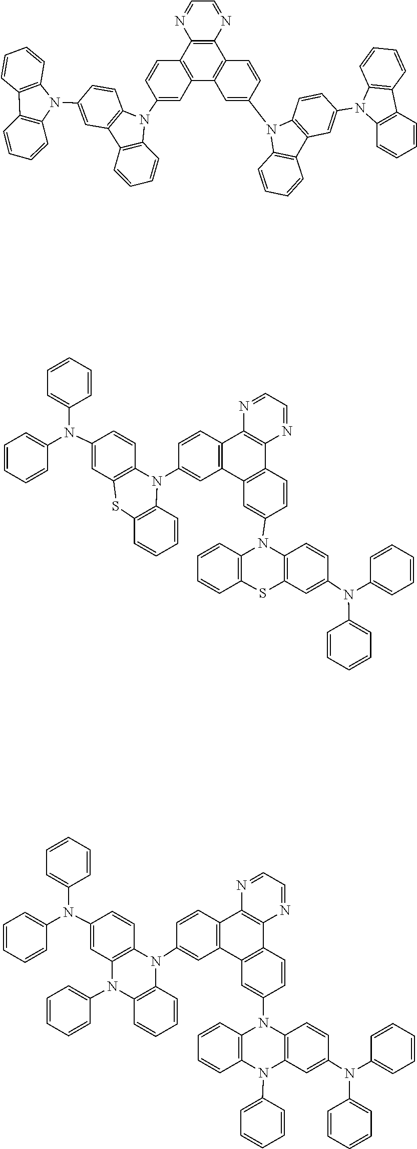 [SMILES: c1ccc2c(c1)c1ccccc1n2-c1ccc2c(c1)c1ccccc1n2-c1ccc2c(c1)c1cc(-n3c4ccccc4c4cc(-n5c6ccccc6c6ccccc65)ccc43)ccc1c1nccnc21 ; c1ccc(N(c2ccccc2)c2ccc3c(c2)Sc2ccccc2N3c2ccc3c(c2)c2cc(N4c5ccccc5Sc5cc(N(c6ccccc6)c6ccccc6)ccc54)ccc2c2nccnc32)cc1 ; c1ccc(N(c2ccccc2)c2ccc3c(c2)N(c2ccccc2)c2ccccc2N3c2ccc3c(c2)c2cc(N4c5ccccc5N(c5ccccc5)c5cc(N(c6ccccc6)c6ccccc6)ccc54)ccc2c2nccnc32)cc1]

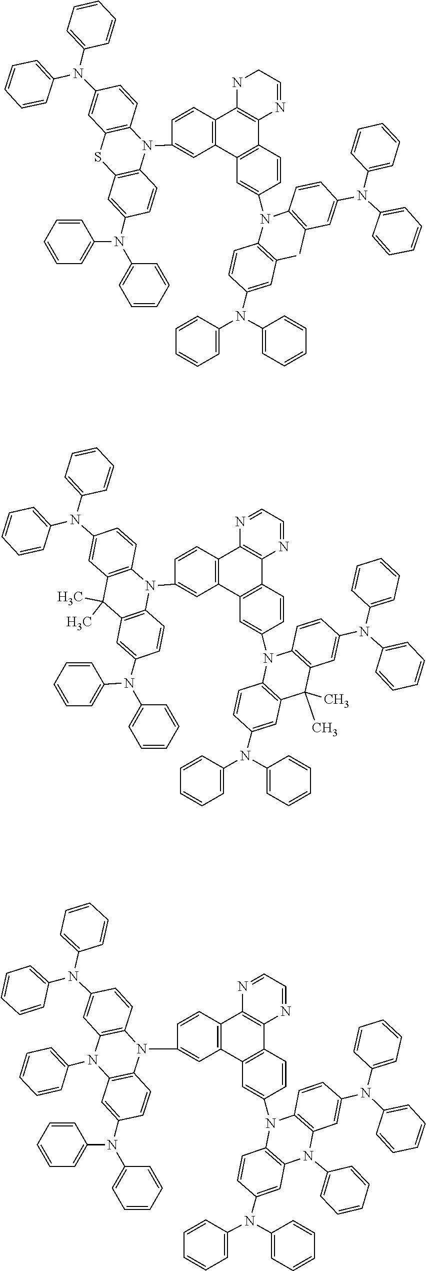

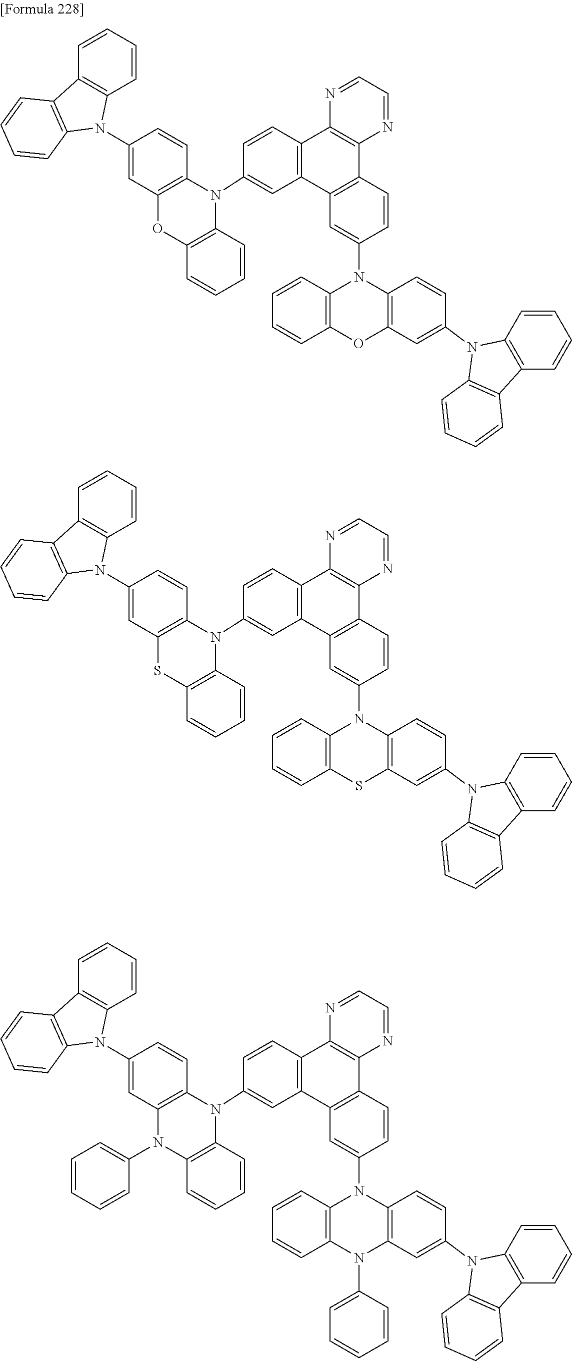 [SMILES: c1ccc2c(c1)Oc1cc(-n3c4ccccc4c4ccccc43)ccc1N2c1ccc2c(c1)c1cc(N3c4ccccc4Oc4cc(-n5c6ccccc6c6ccccc65)ccc43)ccc1c1nccnc21 ; c1ccc2c(c1)Sc1cc(-n3c4ccccc4c4ccccc43)ccc1N2c1ccc2c(c1)c1cc(N3c4ccccc4Sc4cc(-n5c6ccccc6c6ccccc65)ccc43)ccc1c1nccnc21 ; c1ccc(N2c3ccccc3N(c3ccc4c(c3)c3cc(N5c6ccccc6N(c6ccccc6)c6cc(-n7c8ccccc8c8ccccc87)ccc65)ccc3c3nccnc43)c3ccc(-n4c5ccccc5c5ccccc54)cc32)cc1]

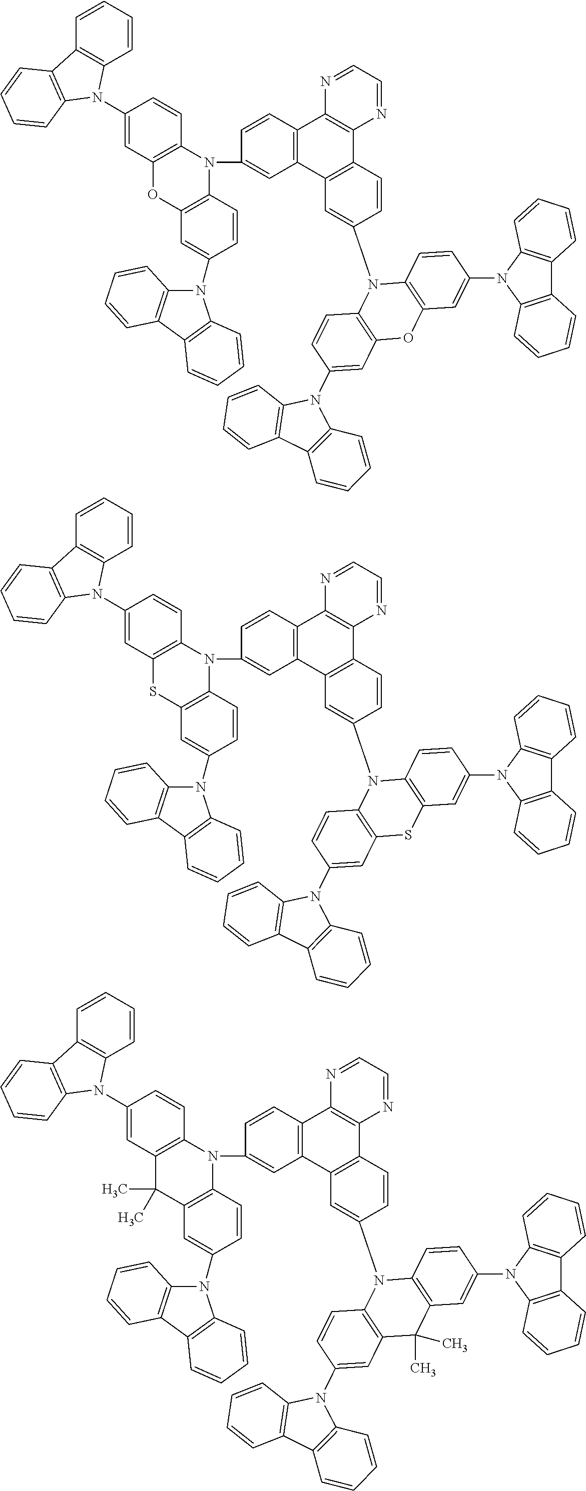 [SMILES: c1ccc2c(c1)c1ccccc1n2-c1ccc2c(c1)Oc1cc(-n3c4ccccc4c4ccccc43)ccc1N2c1ccc2c(c1)c1cc(N3c4ccc(-n5c6ccccc6c6ccccc65)cc4Oc4cc(-n5c6ccccc6c6ccccc65)ccc43)ccc1c1nccnc21 ; c1ccc2c(c1)c1ccccc1n2-c1ccc2c(c1)Sc1cc(-n3c4ccccc4c4ccccc43)ccc1N2c1ccc2c(c1)c1cc(N3c4ccc(-n5c6ccccc6c6ccccc65)cc4Sc4cc(-n5c6ccccc6c6ccccc65)ccc43)ccc1c1nccnc21 ; CC1(C)c2cc(-n3c4ccccc4c4ccccc43)ccc2N(c2ccc3c(c2)c2cc(N4c5ccc(-n6c7ccccc7c7ccccc76)cc5C(C)(C)c5cc(-n6c7ccccc7c7ccccc76)ccc54)ccc2c2nccnc32)c2ccc(-n3c4ccccc4c4ccccc43)cc21]

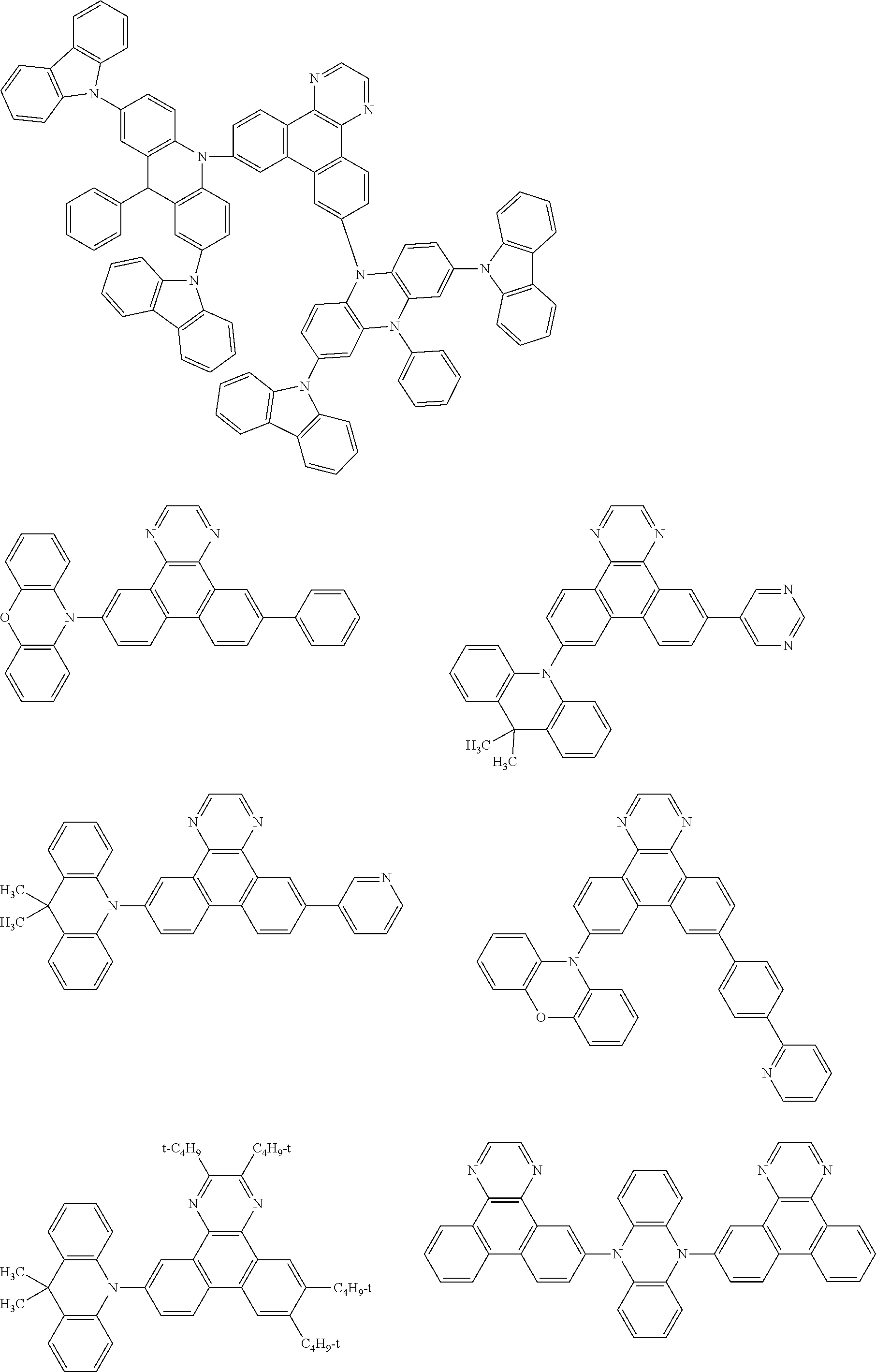

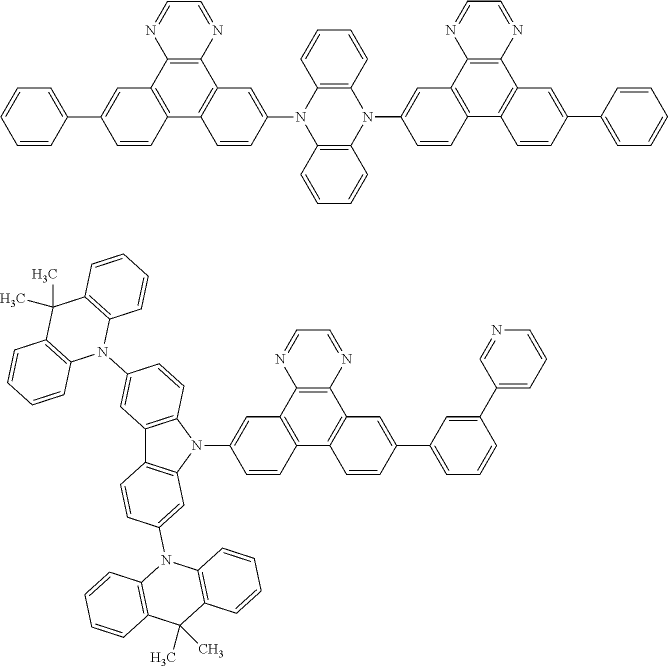 [SMILES: c1ccc(-c2ccc3c4ccc(N5c6ccccc6N(c6ccc7c8ccc(-c9ccccc9)cc8c8nccnc8c7c6)c6ccccc65)cc4c4nccnc4c3c2)cc1 ; CC1(C)c2ccccc2N(c2ccc3c(c2)c2ccc(N4c5ccccc5C(C)(C)c5ccccc54)cc2n3-c2ccc3c4ccc(-c5cccc(-c6cccnc6)c5)cc4c4nccnc4c3c2)c2ccccc21]

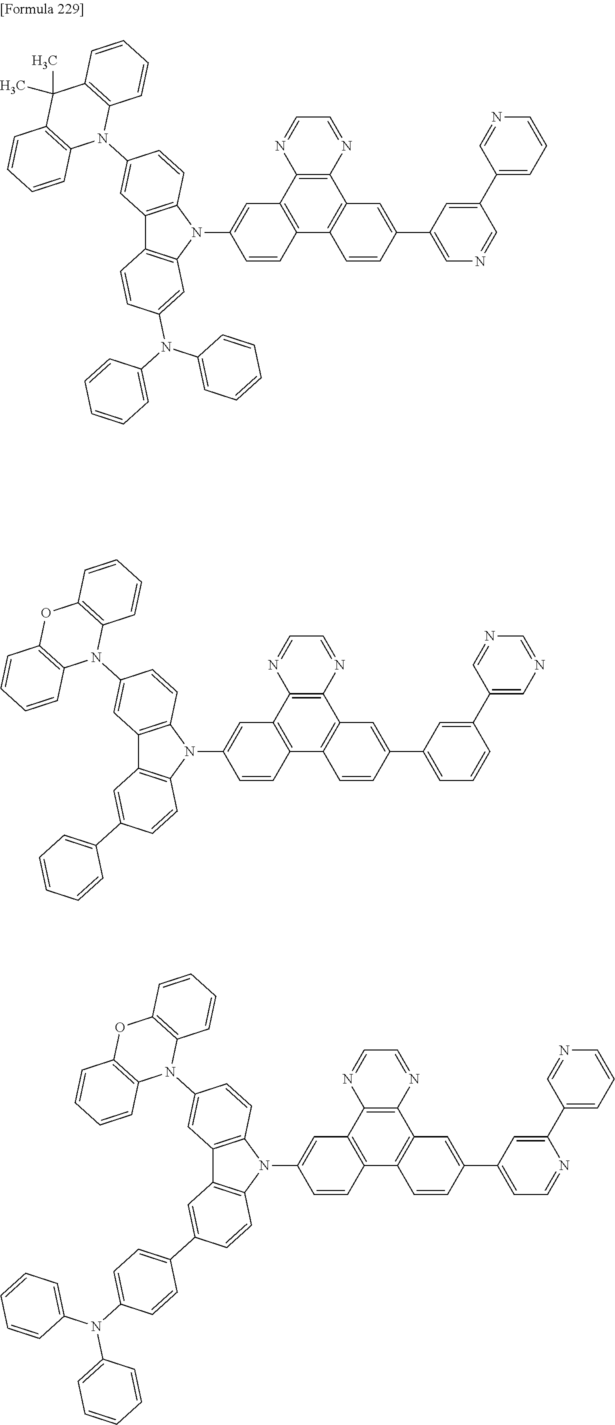 [SMILES: CC1(C)c2ccccc2N(c2ccc3c(c2)c2ccc(N(c4ccccc4)c4ccccc4)cc2n3-c2ccc3c4ccc(-c5cncc(-c6cccnc6)c5)cc4c4nccnc4c3c2)c2ccccc21 ; c1ccc(-c2ccc3c(c2)c2cc(N4c5ccccc5Oc5ccccc54)ccc2n3-c2ccc3c4ccc(-c5cccc(-c6cncnc6)c5)cc4c4nccnc4c3c2)cc1 ; c1ccc(N(c2ccccc2)c2ccc(-c3ccc4c(c3)c3cc(N5c6ccccc6Oc6ccccc65)ccc3n4-c3ccc4c5ccc(-c6ccnc(-c7cccnc7)c6)cc5c5nccnc5c4c3)cc2)cc1]

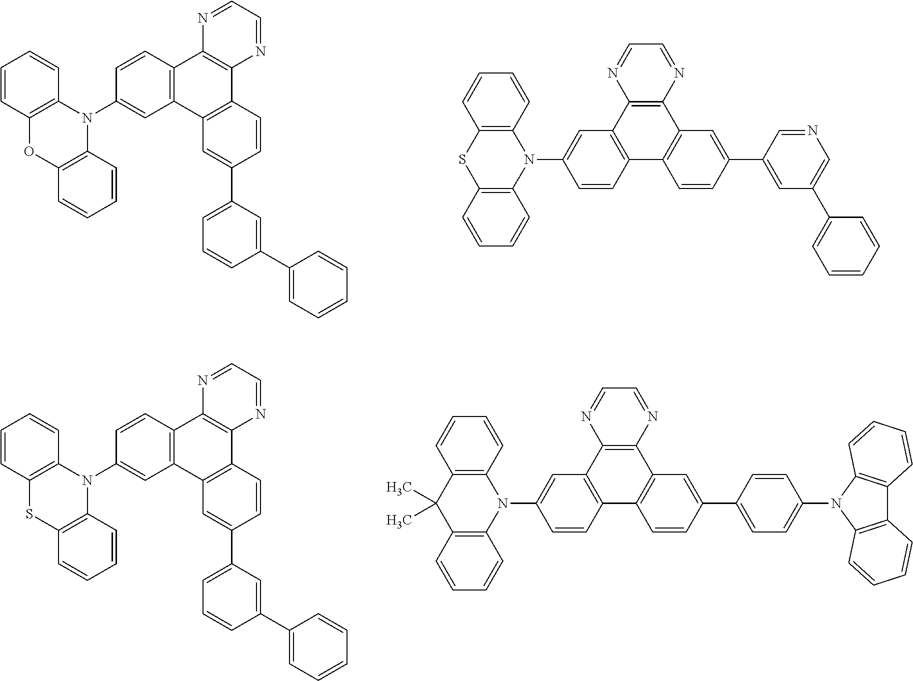 [SMILES: c1ccc(-c2cccc(-c3ccc4c(c3)c3cc(N5c6ccccc6Oc6ccccc65)ccc3c3nccnc43)c2)cc1 ; c1ccc(-c2cncc(-c3ccc4c5ccc(N6c7ccccc7Sc7ccccc76)cc5c5nccnc5c4c3)c2)cc1 ; c1ccc(-c2cccc(-c3ccc4c(c3)c3cc(N5c6ccccc6Sc6ccccc65)ccc3c3nccnc43)c2)cc1 ; CC1(C)c2ccccc2N(c2ccc3c4ccc(-c5ccc(-n6c7ccccc7c7ccccc76)cc5)cc4c4nccnc4c3c2)c2ccccc21]

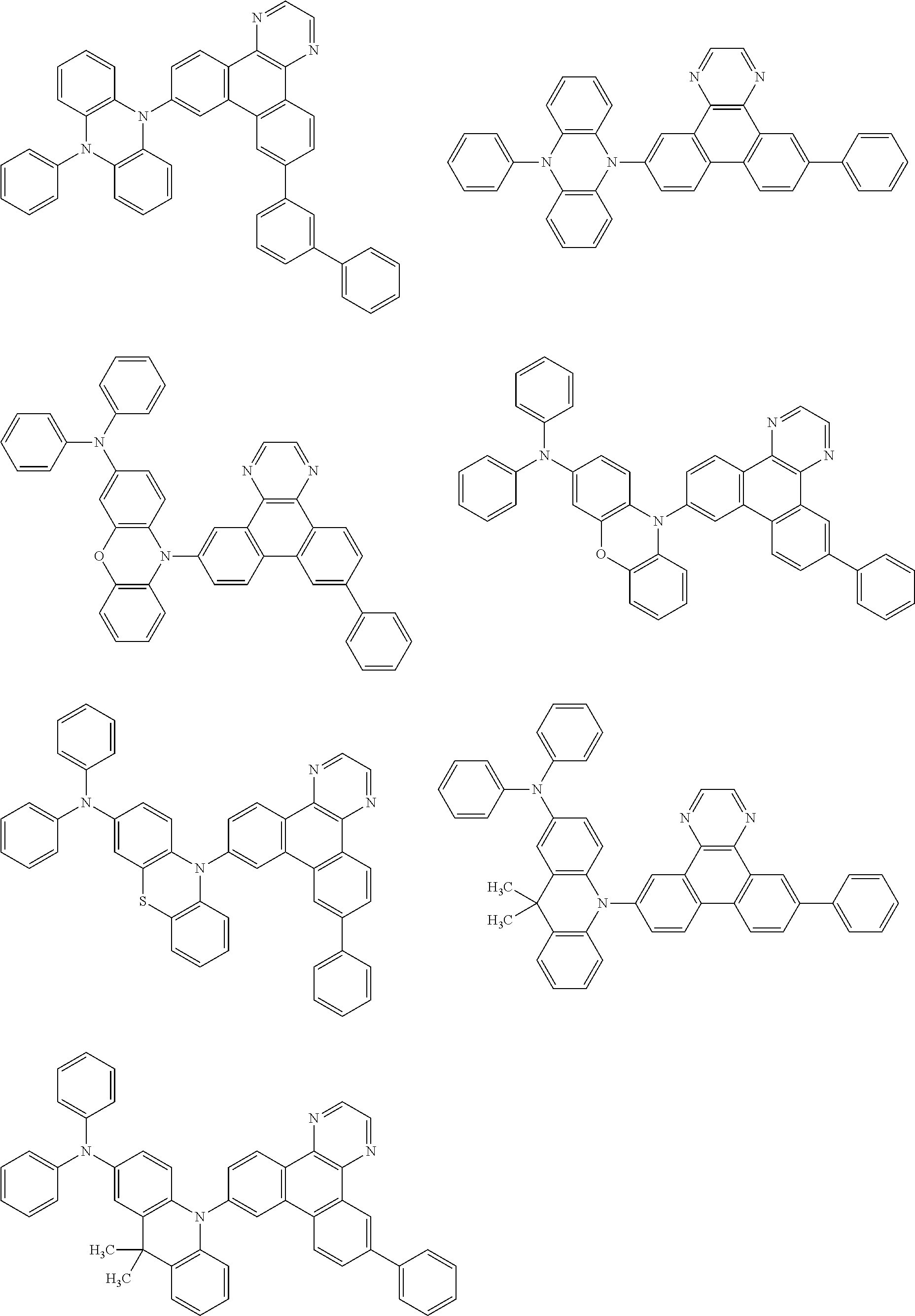

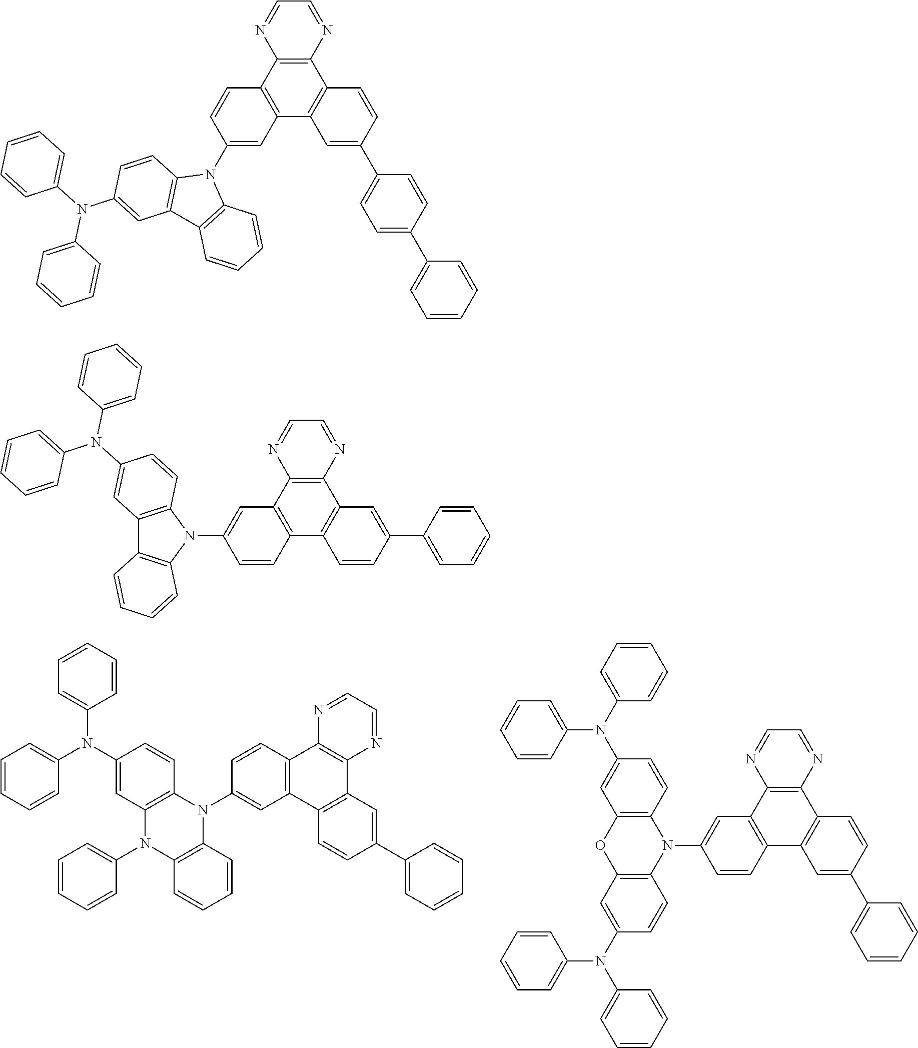 [SMILES: c1ccc(-c2ccc(-c3ccc4c(c3)c3cc(-n5c6ccccc6c6cc(N(c7ccccc7)c7ccccc7)ccc65)ccc3c3nccnc43)cc2)cc1 ; c1ccc(-c2ccc3c4ccc(-n5c6ccccc6c6cc(N(c7ccccc7)c7ccccc7)ccc65)cc4c4nccnc4c3c2)cc1 ; c1ccc(-c2ccc3c4cc(N5c6ccccc6N(c6ccccc6)c6cc(N(c7ccccc7)c7ccccc7)ccc65)ccc4c4nccnc4c3c2)cc1 ; c1ccc(-c2ccc3c(c2)c2ccc(N4c5ccc(N(c6ccccc6)c6ccccc6)cc5Oc5cc(N(c6ccccc6)c6ccccc6)ccc54)cc2c2nccnc32)cc1]

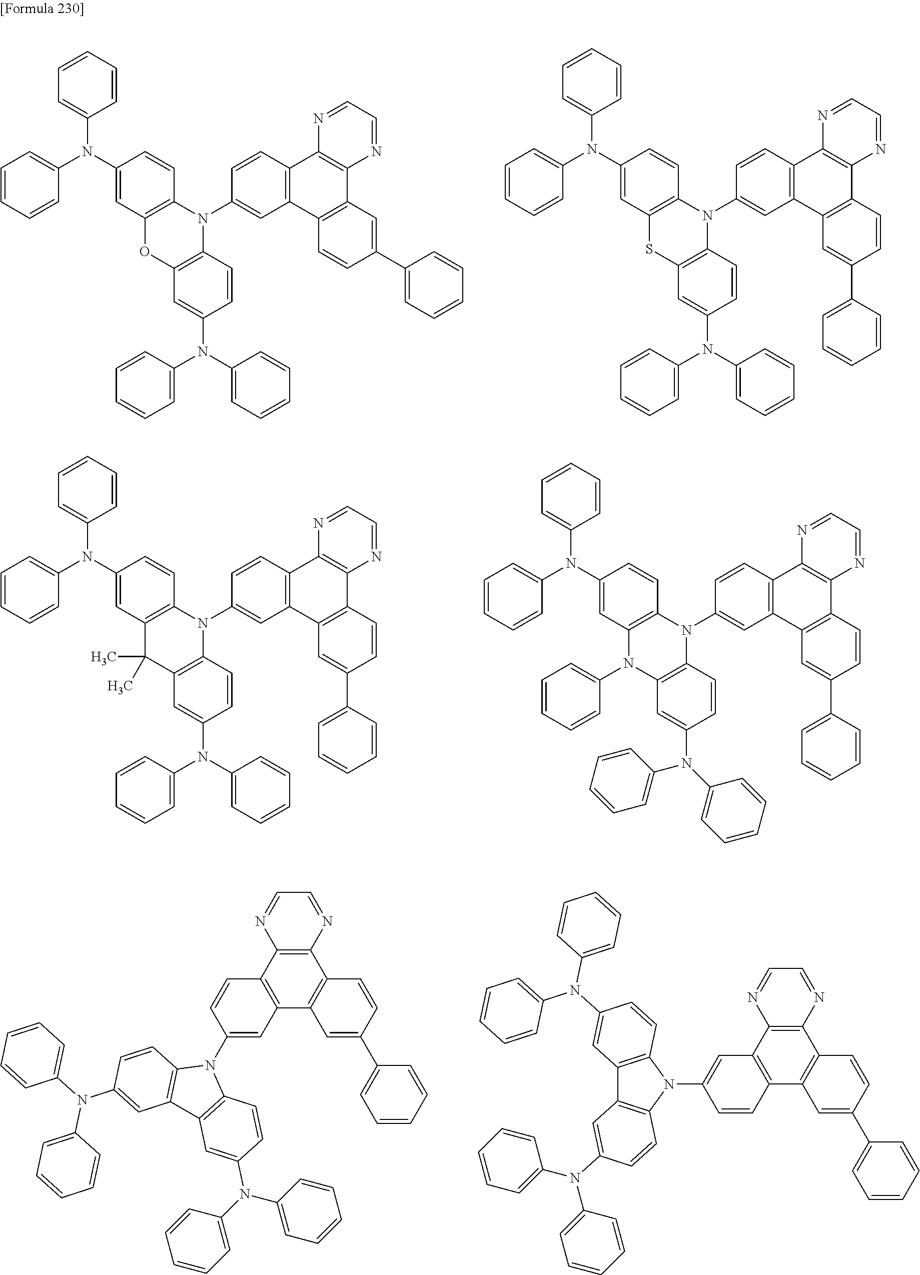

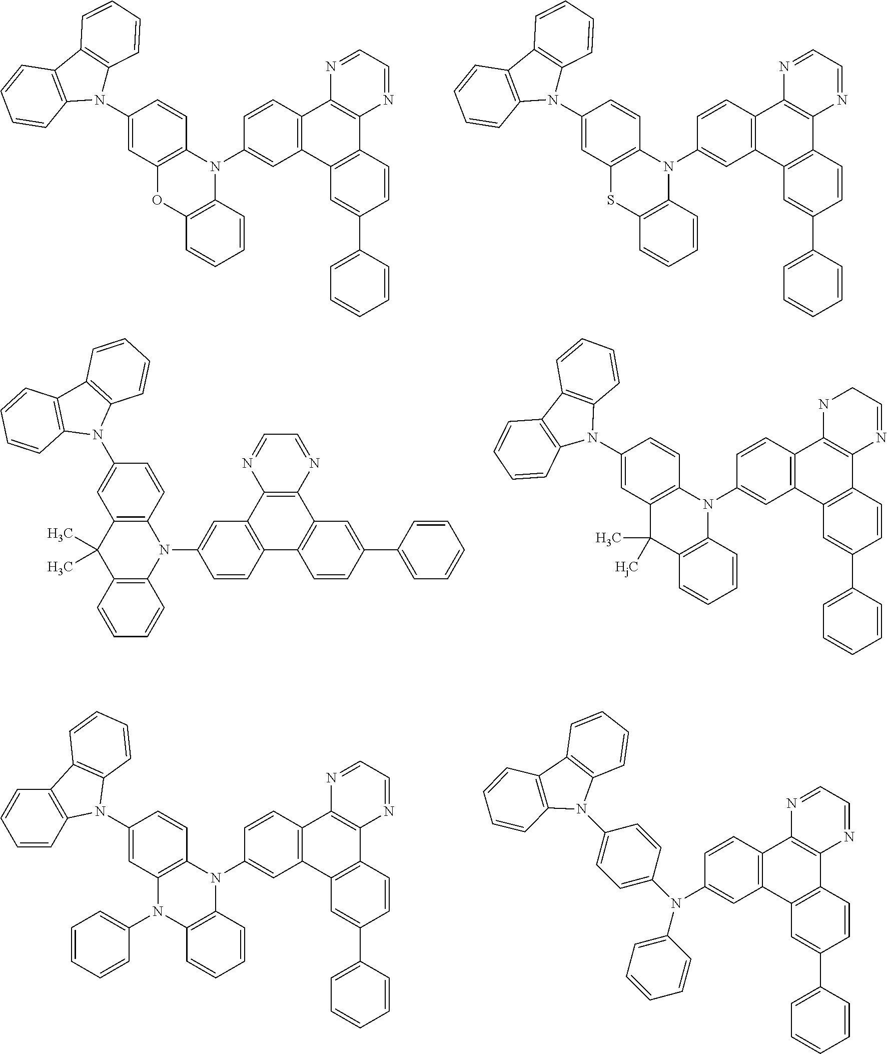

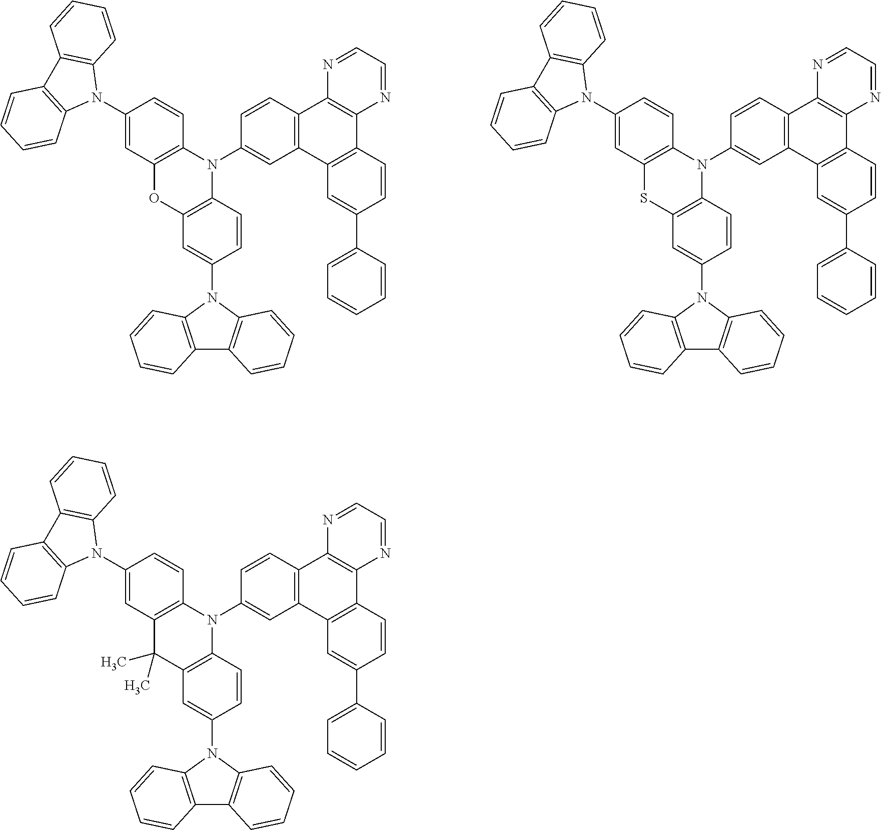 [SMILES: c1ccc(-c2ccc3c(c2)c2cc(N4c5ccc(-n6c7ccccc7c7ccccc76)cc5Oc5cc(-n6c7ccccc7c7ccccc76)ccc54)ccc2c2nccnc32)cc1 ; c1ccc(-c2ccc3c(c2)c2cc(N4c5ccc(-n6c7ccccc7c7ccccc76)cc5Sc5cc(-n6c7ccccc7c7ccccc76)ccc54)ccc2c2nccnc32)cc1 ; CC1(C)c2cc(-n3c4ccccc4c4ccccc43)ccc2N(c2ccc3c(c2)c2cc(-c4ccccc4)ccc2c2nccnc32)c2ccc(-n3c4ccccc4c4ccccc43)cc21]

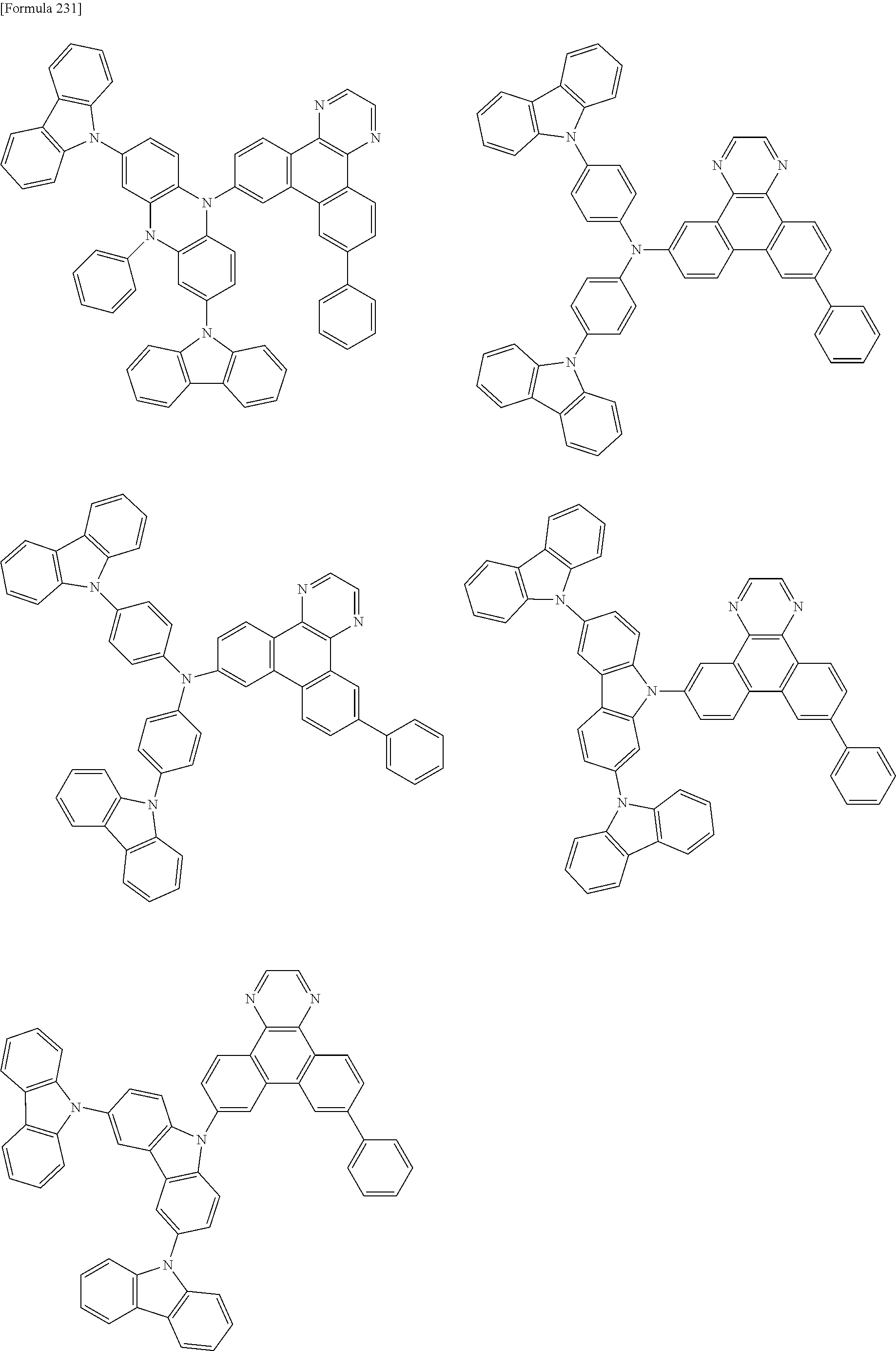

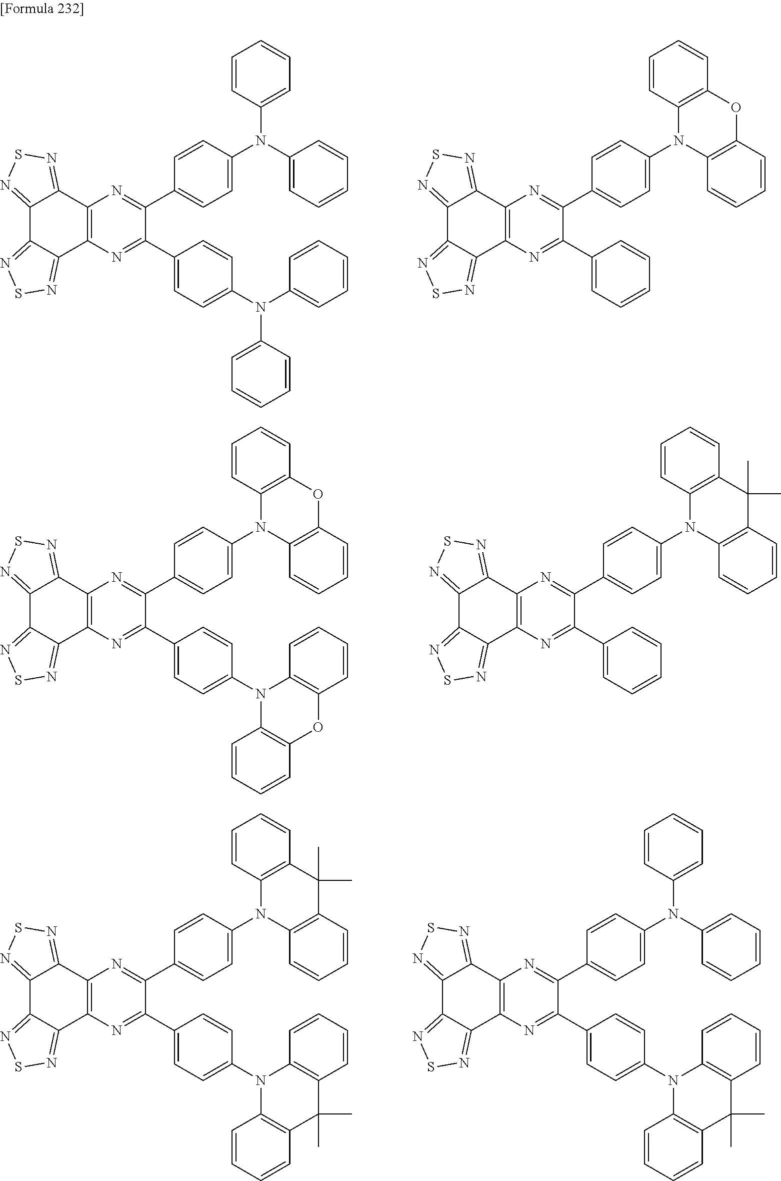

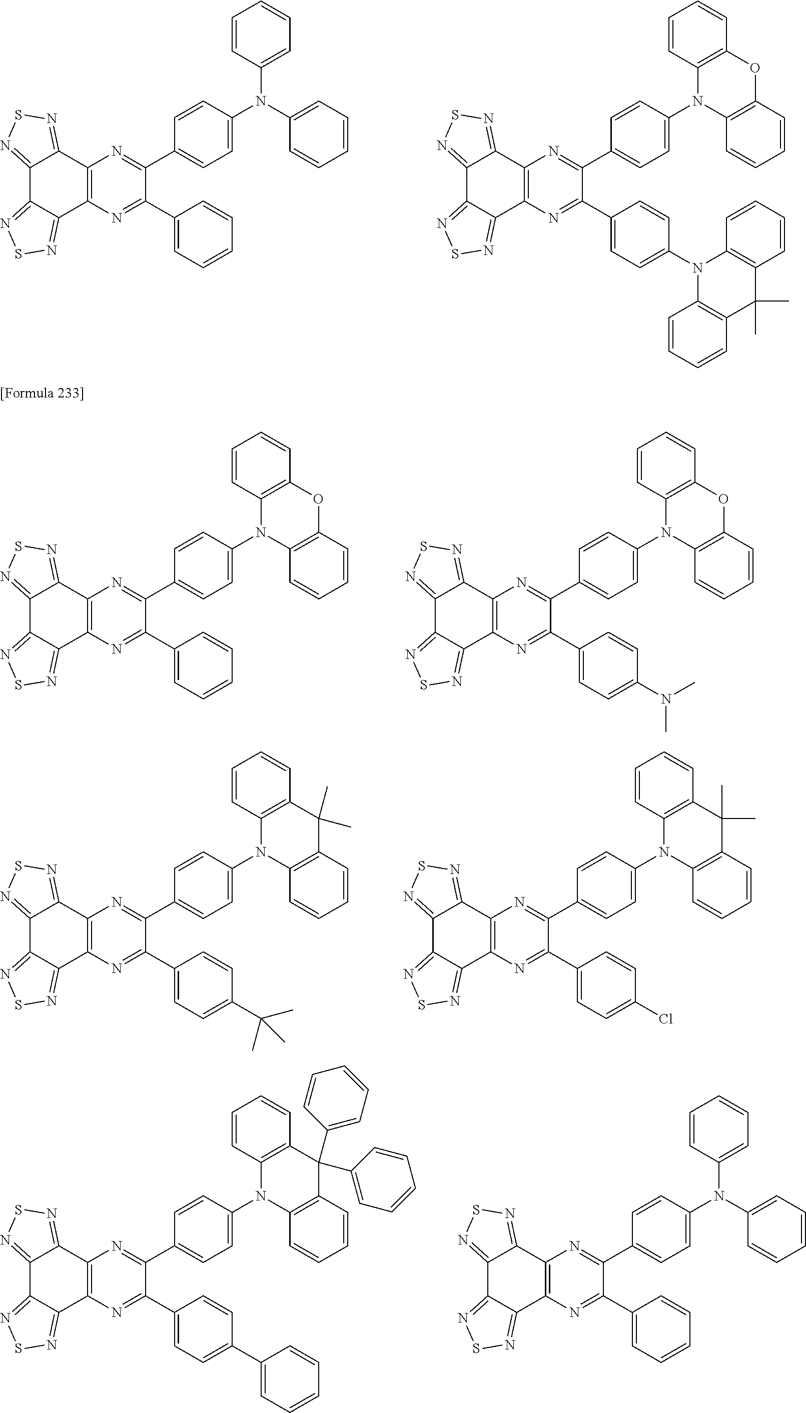

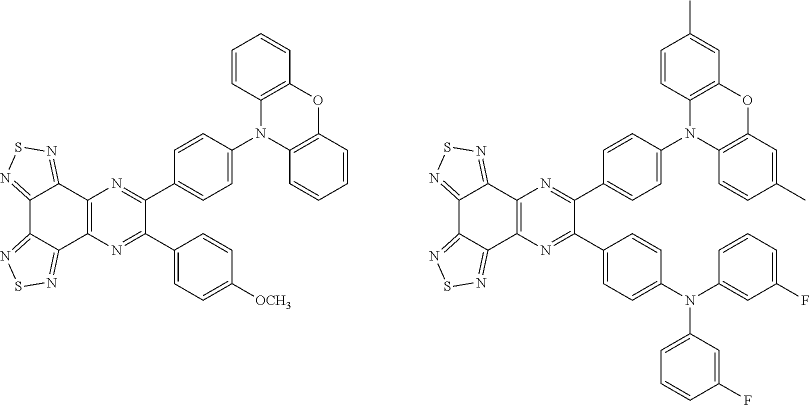 [SMILES: COc1ccc(-c2nc3c4nsnc4c4nsnc4c3nc2-c2ccc(N3c4ccccc4Oc4ccccc43)cc2)cc1 ; Cc1ccc2c(c1)Oc1cc(C)ccc1N2c1ccc(-c2nc3c4nsnc4c4nsnc4c3nc2-c2ccc(N(c3cccc(F)c3)c3cccc(F)c3)cc2)cc1]

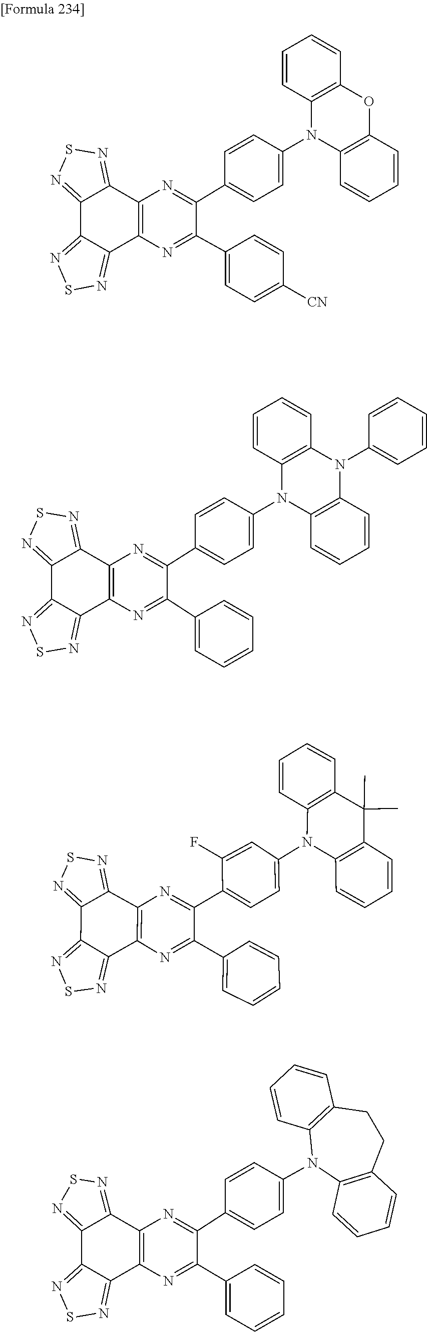

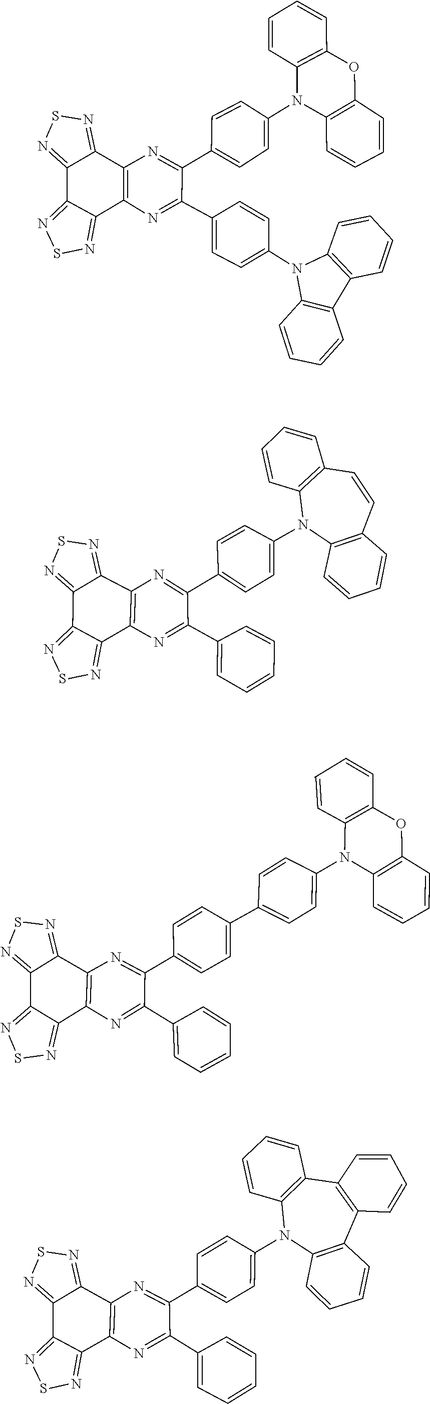 [SMILES: c1ccc2c(c1)Oc1ccccc1N2c1ccc(-c2nc3c4nsnc4c4nsnc4c3nc2-c2ccc(-n3c4ccccc4c4ccccc43)cc2)cc1 ; C1=Cc2ccccc2N(c2ccc(-c3nc4c5nsnc5c5nsnc5c4nc3-c3ccccc3)cc2)c2ccccc21 ; Cc1ccc2c(c1)N(c1ccc(-c3ccc(-c4nc5c6nsnc6c6nsnc6c5nc4-c4ccccc4)cc3)cc1)c1ccccc1O2 ; c1ccc(-c2nc3c4nsnc4c4nsnc4c3nc2-c2ccc(N3c4ccccc4-c4ccccc4-c4ccccc43)cc2)cc1]

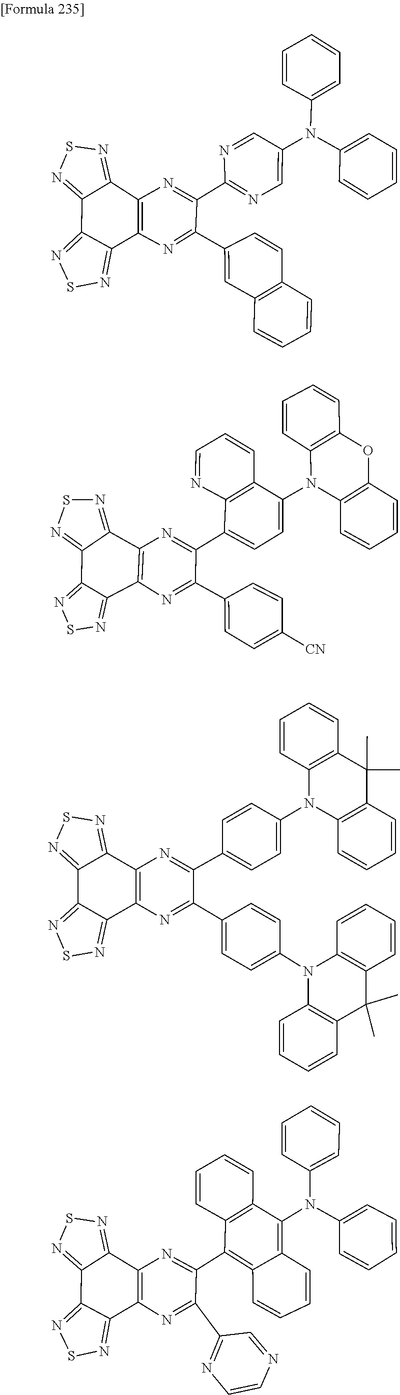

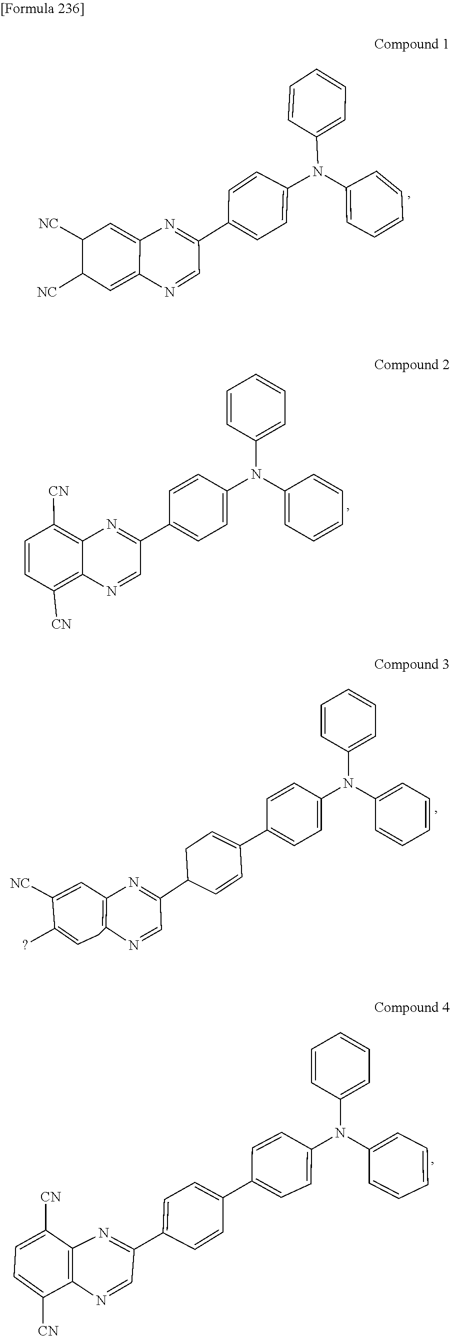

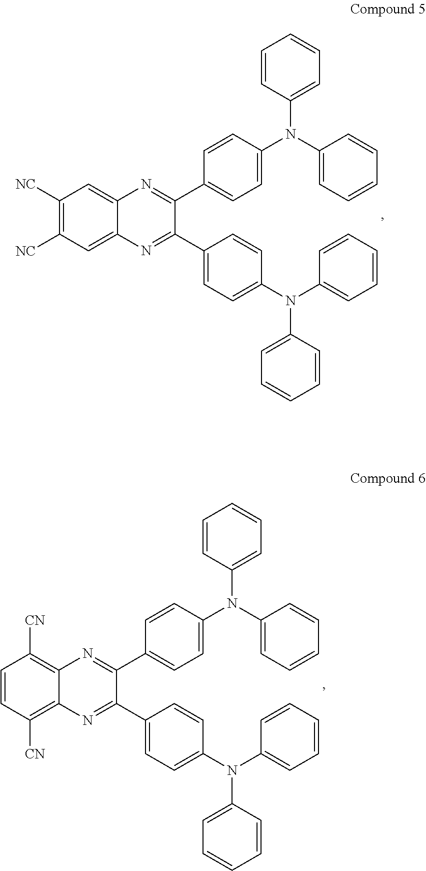 [SMILES: N#Cc1cc2nc(-c3ccc(N(c4ccccc4)c4ccccc4)cc3)c(-c3ccc(N(c4ccccc4)c4ccccc4)cc3)nc2cc1C#N ; N#Cc1ccc(C#N)c2nc(-c3ccc(N(c4ccccc4)c4ccccc4)cc3)c(-c3ccc(N(c4ccccc4)c4ccccc4)cc3)nc12]

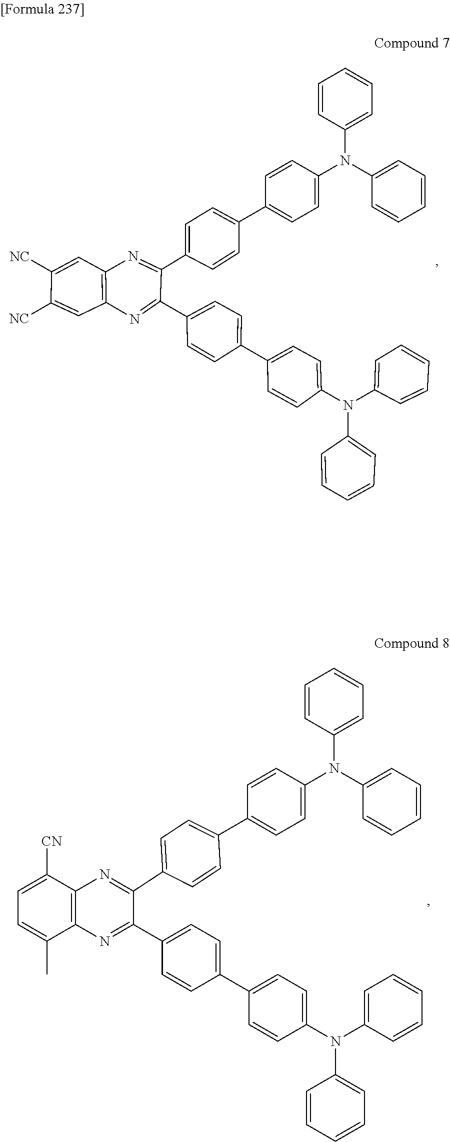 [SMILES: N#Cc1cc2nc(-c3ccc(-c4ccc(N(c5ccccc5)c5ccccc5)cc4)cc3)c(-c3ccc(-c4ccc(N(c5ccccc5)c5ccccc5)cc4)cc3)nc2cc1C#N ; Cc1ccc(C#N)c2nc(-c3ccc(-c4ccc(N(c5ccccc5)c5ccccc5)cc4)cc3)c(-c3ccc(-c4ccc(N(c5ccccc5)c5ccccc5)cc4)cc3)nc12]

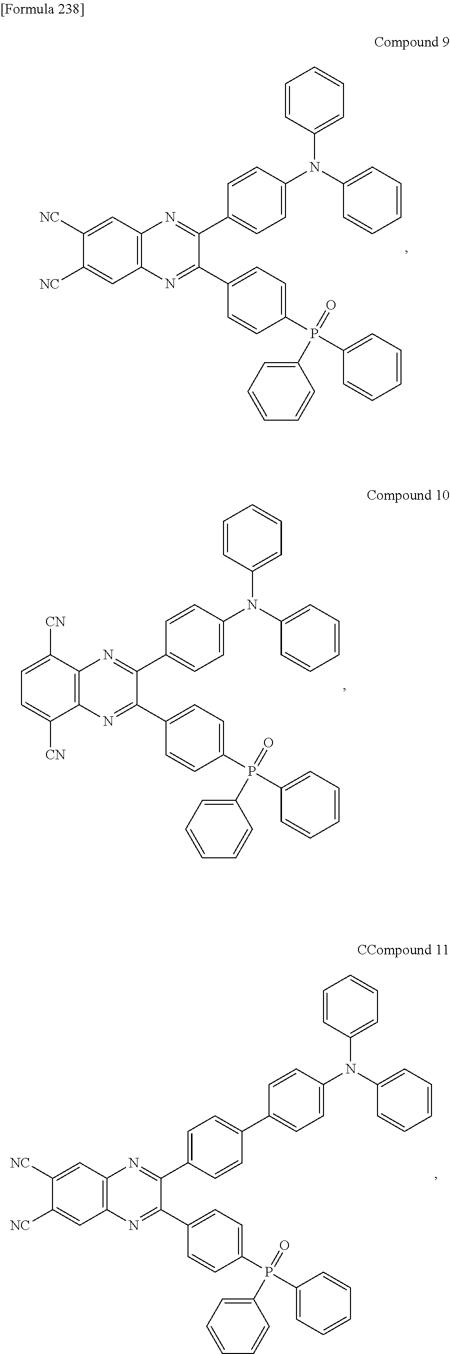 [SMILES: N#Cc1cc2nc(-c3ccc(N(c4ccccc4)c4ccccc4)cc3)c(-c3ccc(P(=O)(c4ccccc4)c4ccccc4)cc3)nc2cc1C#N ; N#Cc1ccc(C#N)c2nc(-c3ccc(P(=O)(c4ccccc4)c4ccccc4)cc3)c(-c3ccc(N(c4ccccc4)c4ccccc4)cc3)nc12 ; N#Cc1cc2nc(-c3ccc(-c4ccc(N(c5ccccc5)c5ccccc5)cc4)cc3)c(-c3ccc(P(=O)(c4ccccc4)c4ccccc4)cc3)nc2cc1C#N]

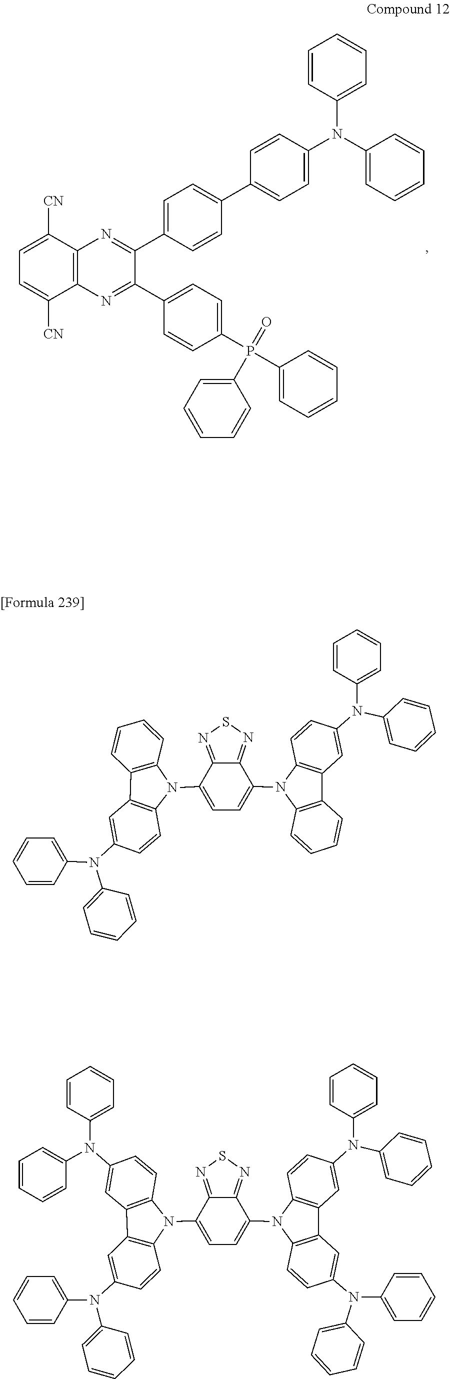

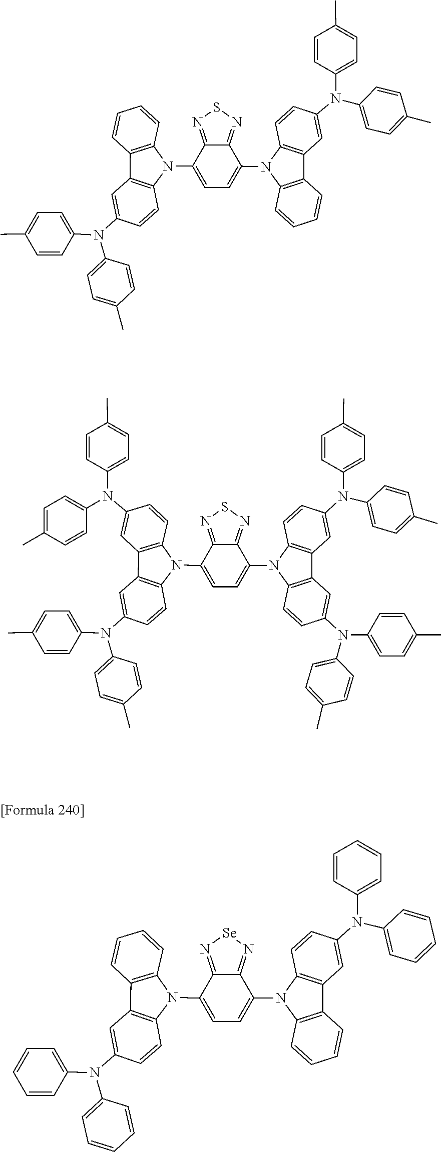

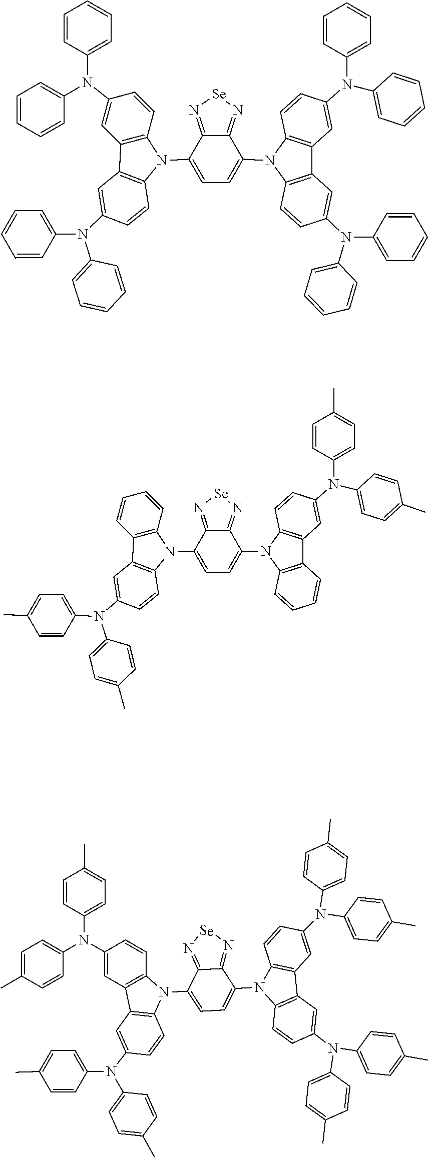

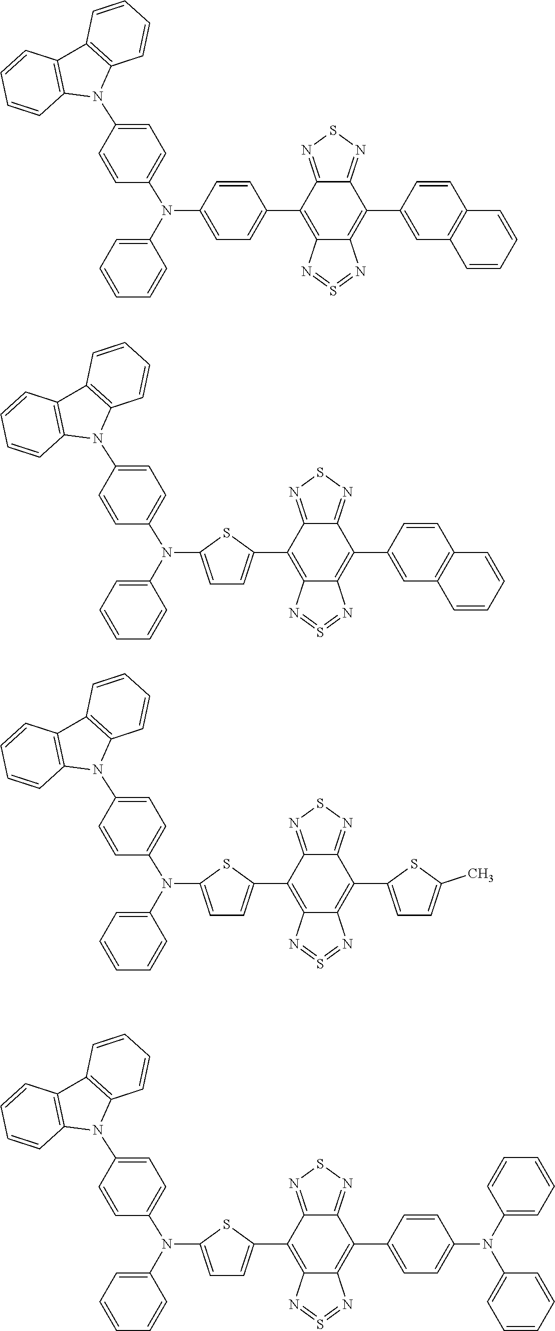

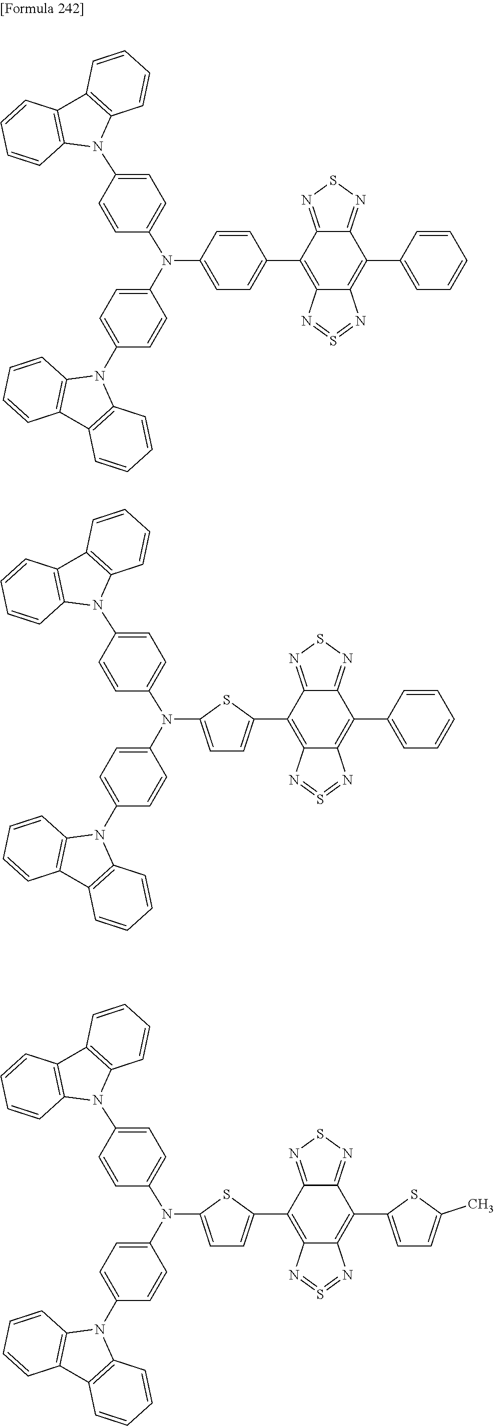

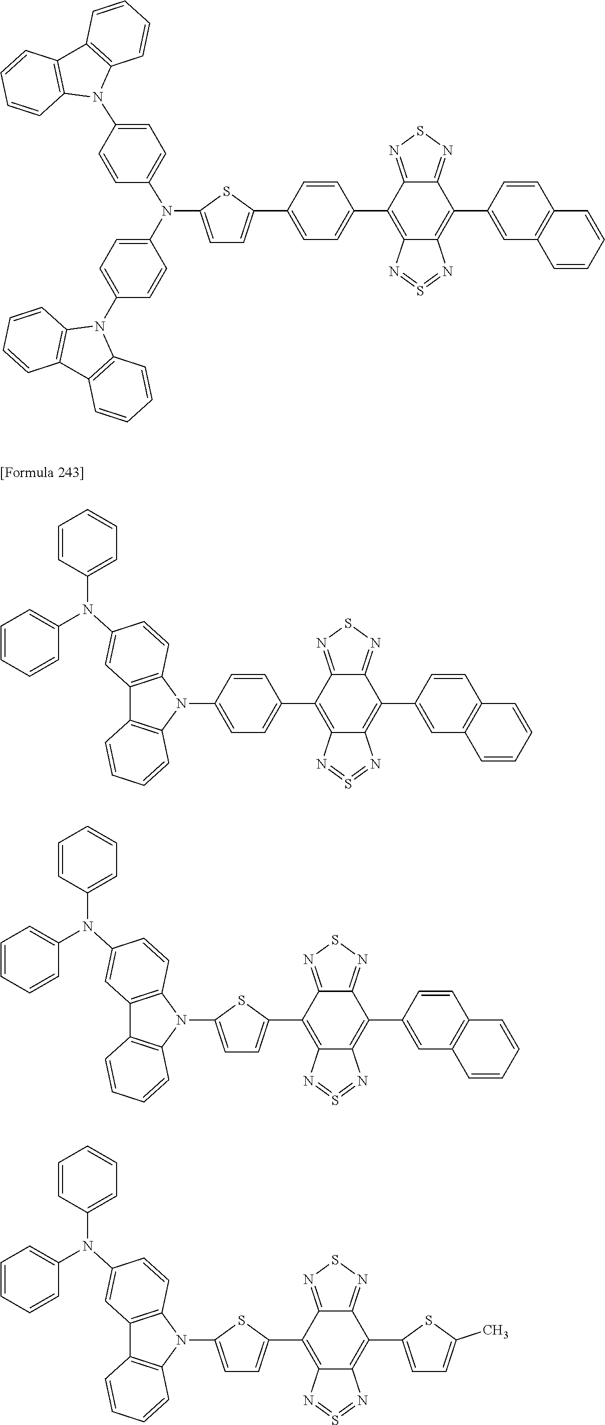 [SMILES: c1ccc2cc(-c3c4c(c(-c5ccc(-c6ccc(N(c7ccc(-n8c9ccccc9c9ccccc98)cc7)c7ccc(-n8c9ccccc9c9ccccc98)cc7)s6)cc5)c5nsnc35)N=S=N4)ccc2c1 ; c1ccc(N(c2ccccc2)c2ccc3c(c2)c2ccccc2n3-c2ccc(-c3c4c(c(-c5ccc6ccccc6c5)c5nsnc35)N=S=N4)cc2)cc1 ; c1ccc(N(c2ccccc2)c2ccc3c(c2)c2ccccc2n3-c2ccc(-c3c4c(c(-c5ccc6ccccc6c5)c5nsnc35)N=S=N4)s2)cc1 ; Cc1ccc(-c2c3c(c(-c4ccc(-n5c6ccccc6c6cc(N(c7ccccc7)c7ccccc7)ccc65)s4)c4nsnc24)N=S=N3)s1]

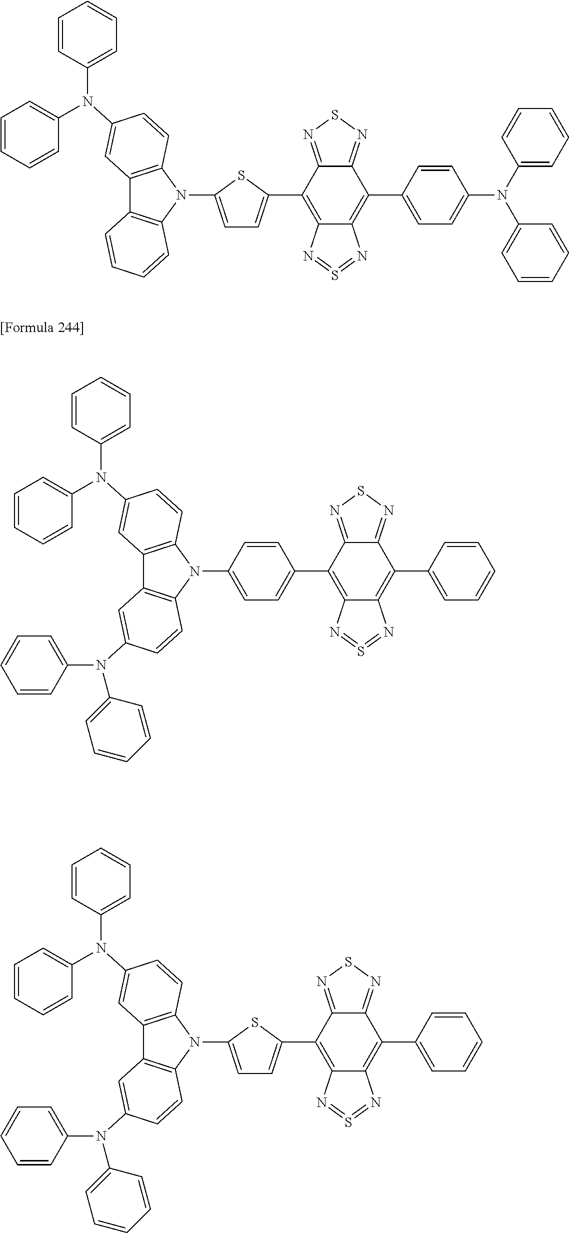 [SMILES: c1ccc(N(c2ccccc2)c2ccc(-c3c4c(c(-c5ccc(-n6c7ccccc7c7cc(N(c8ccccc8)c8ccccc8)ccc76)s5)c5nsnc35)N=S=N4)cc2)cc1 ; c1ccc(-c2c3c(c(-c4ccc(-n5c6ccc(N(c7ccccc7)c7ccccc7)cc6c6cc(N(c7ccccc7)c7ccccc7)ccc65)cc4)c4nsnc24)N=S=N3)cc1 ; c1ccc(-c2c3c(c(-c4ccc(-n5c6ccc(N(c7ccccc7)c7ccccc7)cc6c6cc(N(c7ccccc7)c7ccccc7)ccc65)s4)c4nsnc24)N=S=N3)cc1]

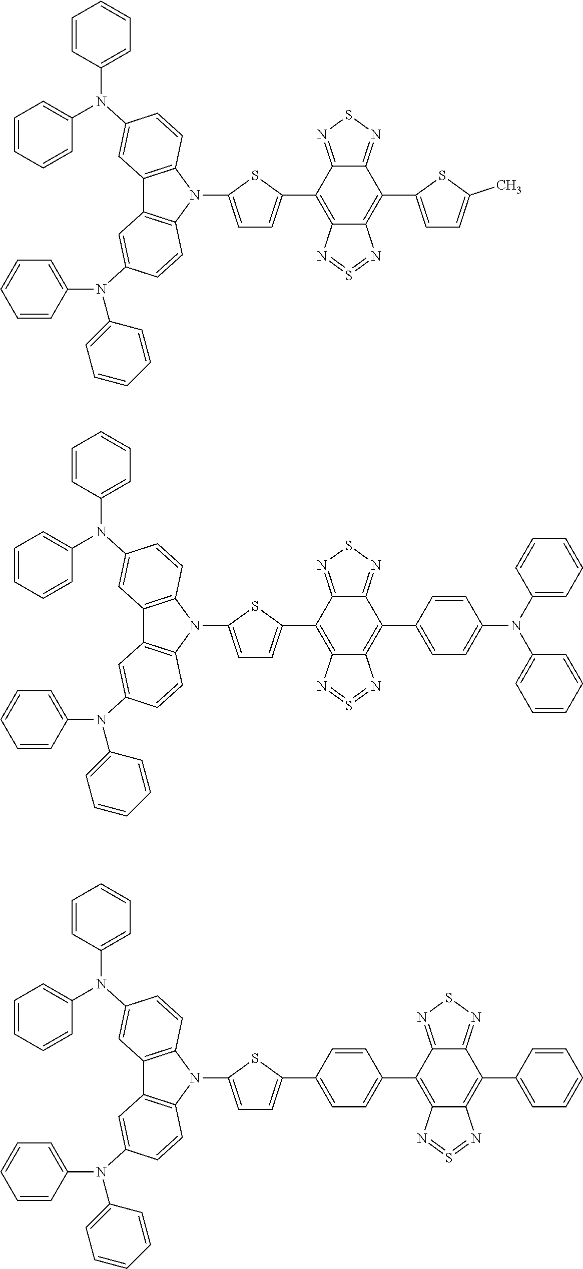 [SMILES: Cc1ccc(-c2c3c(c(-c4ccc(-n5c6ccc(N(c7ccccc7)c7ccccc7)cc6c6cc(N(c7ccccc7)c7ccccc7)ccc65)s4)c4nsnc24)N=S=N3)s1 ; c1ccc(N(c2ccccc2)c2ccc(-c3c4c(c(-c5ccc(-n6c7ccc(N(c8ccccc8)c8ccccc8)cc7c7cc(N(c8ccccc8)c8ccccc8)ccc76)s5)c5nsnc35)N=S=N4)cc2)cc1 ; c1ccc(-c2c3c(c(-c4ccc(-c5ccc(-n6c7ccc(N(c8ccccc8)c8ccccc8)cc7c7cc(N(c8ccccc8)c8ccccc8)ccc76)s5)cc4)c4nsnc24)N=S=N3)cc1]

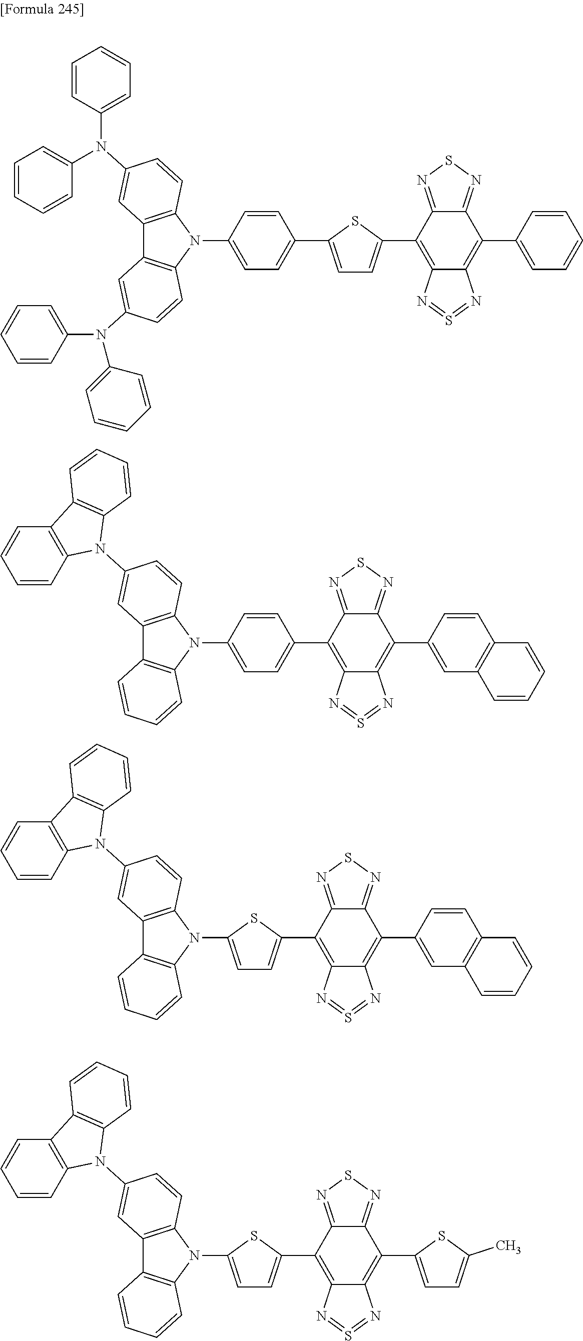

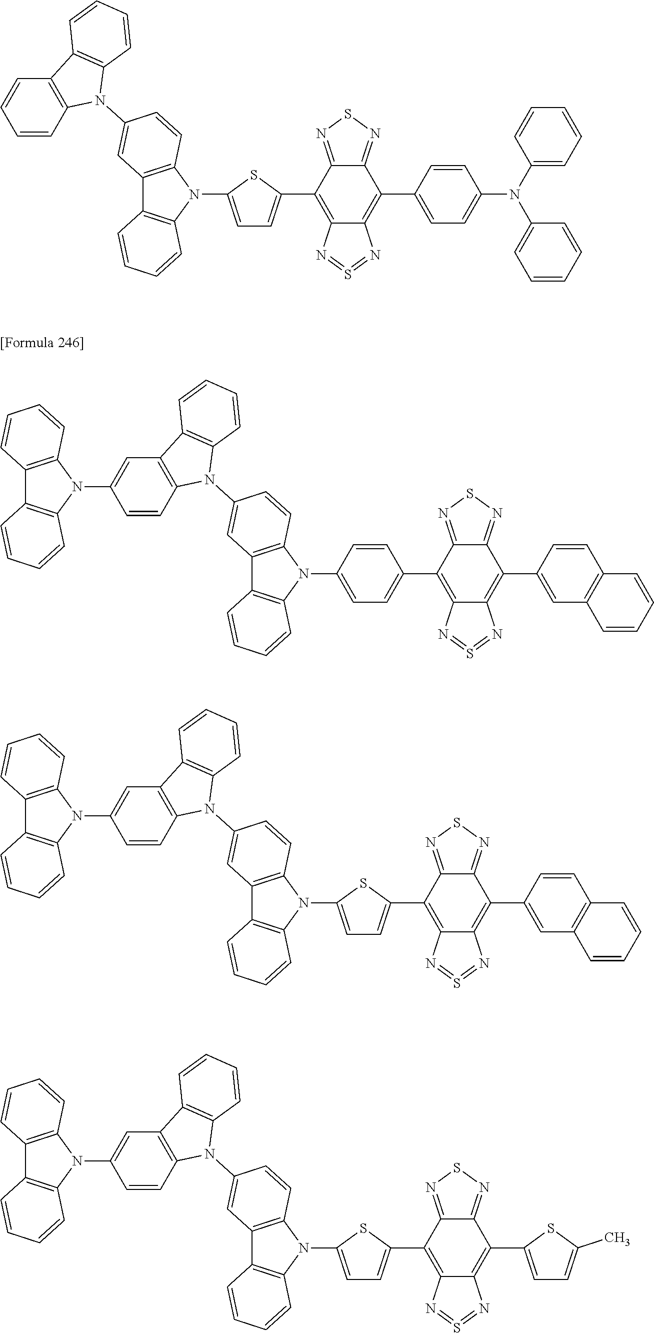 [SMILES: c1ccc(N(c2ccccc2)c2ccc(-c3c4c(c(-c5ccc(-n6c7ccccc7c7cc(-n8c9ccccc9c9ccccc98)ccc76)s5)c5nsnc35)N=S=N4)cc2)cc1 ; c1ccc2cc(-c3c4c(c(-c5ccc(-n6c7ccccc7c7cc(-n8c9ccccc9c9cc(-n%10c%11ccccc%11c%11ccccc%11%10)ccc98)ccc76)cc5)c5nsnc35)N=S=N4)ccc2c1 ; c1ccc2cc(-c3c4c(c(-c5ccc(-n6c7ccccc7c7cc(-n8c9ccccc9c9cc(-n%10c%11ccccc%11c%11ccccc%11%10)ccc98)ccc76)s5)c5nsnc35)N=S=N4)ccc2c1 ; Cc1ccc(-c2c3c(c(-c4ccc(-n5c6ccccc6c6cc(-n7c8ccccc8c8cc(-n9c%10ccccc%10c%10ccccc%109)ccc87)ccc65)s4)c4nsnc24)N=S=N3)s1]

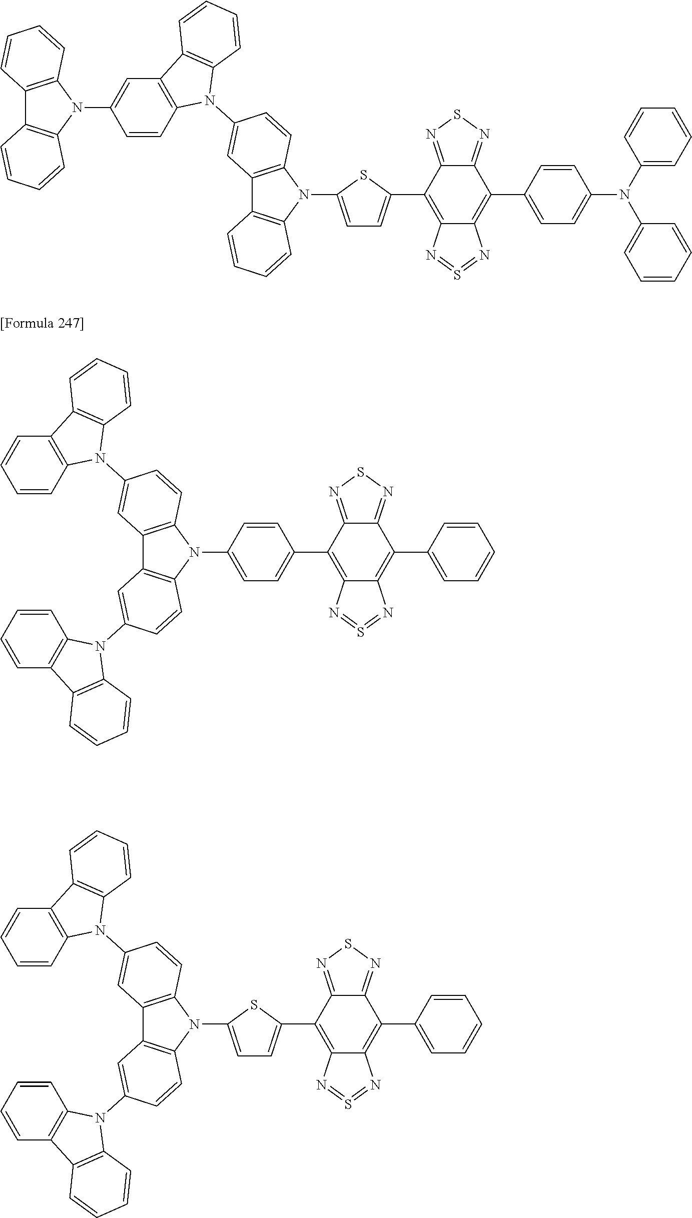 [SMILES: c1ccc(N(c2ccccc2)c2ccc(-c3c4c(c(-c5ccc(-n6c7ccccc7c7cc(-n8c9ccccc9c9cc(-n%10c%11ccccc%11c%11ccccc%11%10)ccc98)ccc76)s5)c5nsnc35)N=S=N4)cc2)cc1 ; c1ccc(-c2c3c(c(-c4ccc(-n5c6ccc(-n7c8ccccc8c8ccccc87)cc6c6cc(-n7c8ccccc8c8ccccc87)ccc65)cc4)c4nsnc24)N=S=N3)cc1 ; c1ccc(-c2c3c(c(-c4ccc(-n5c6ccc(-n7c8ccccc8c8ccccc87)cc6c6cc(-n7c8ccccc8c8ccccc87)ccc65)s4)c4nsnc24)N=S=N3)cc1]

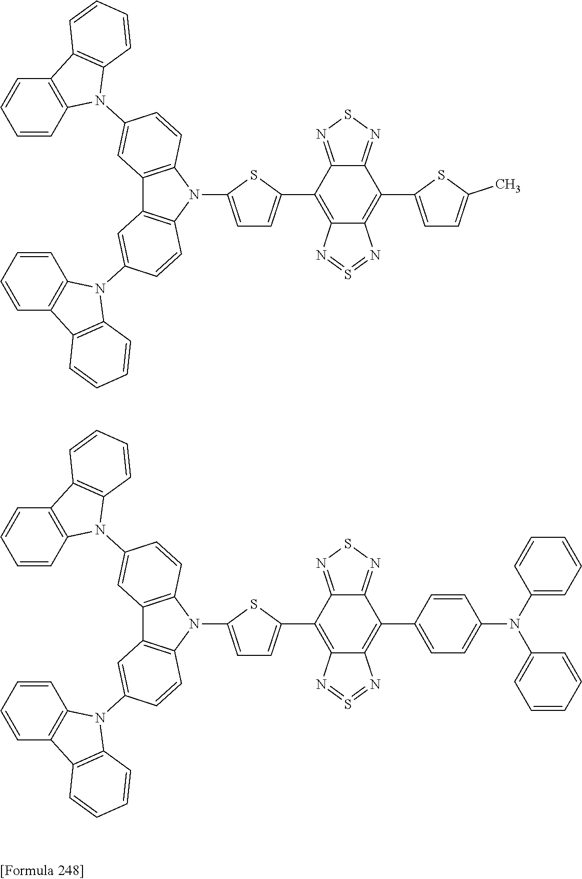

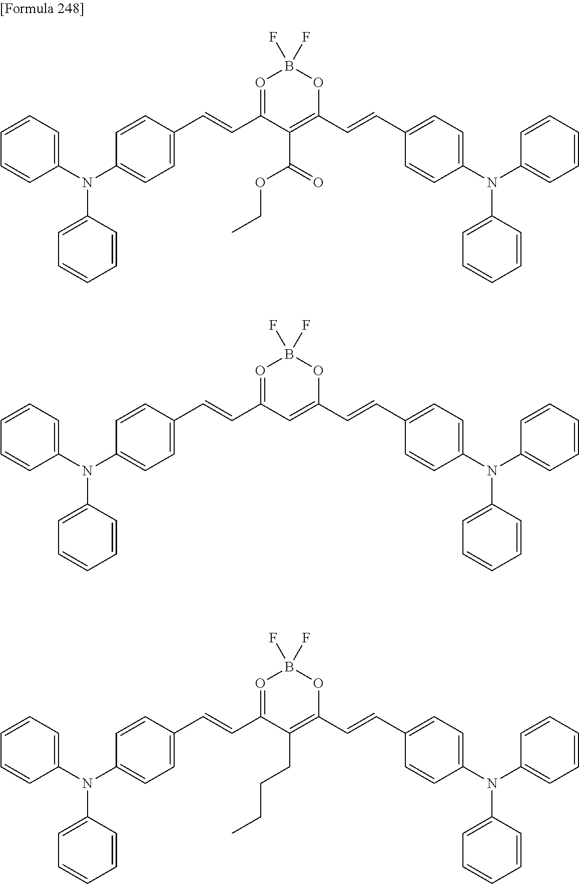

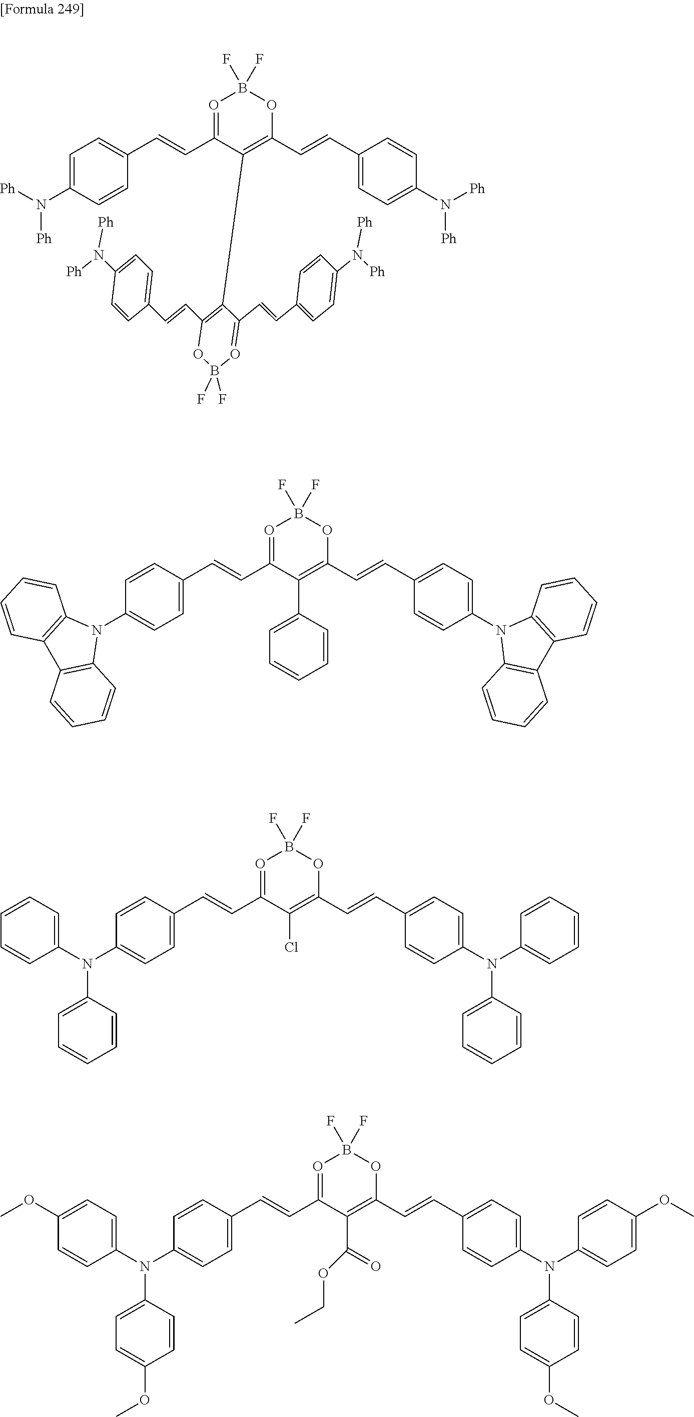

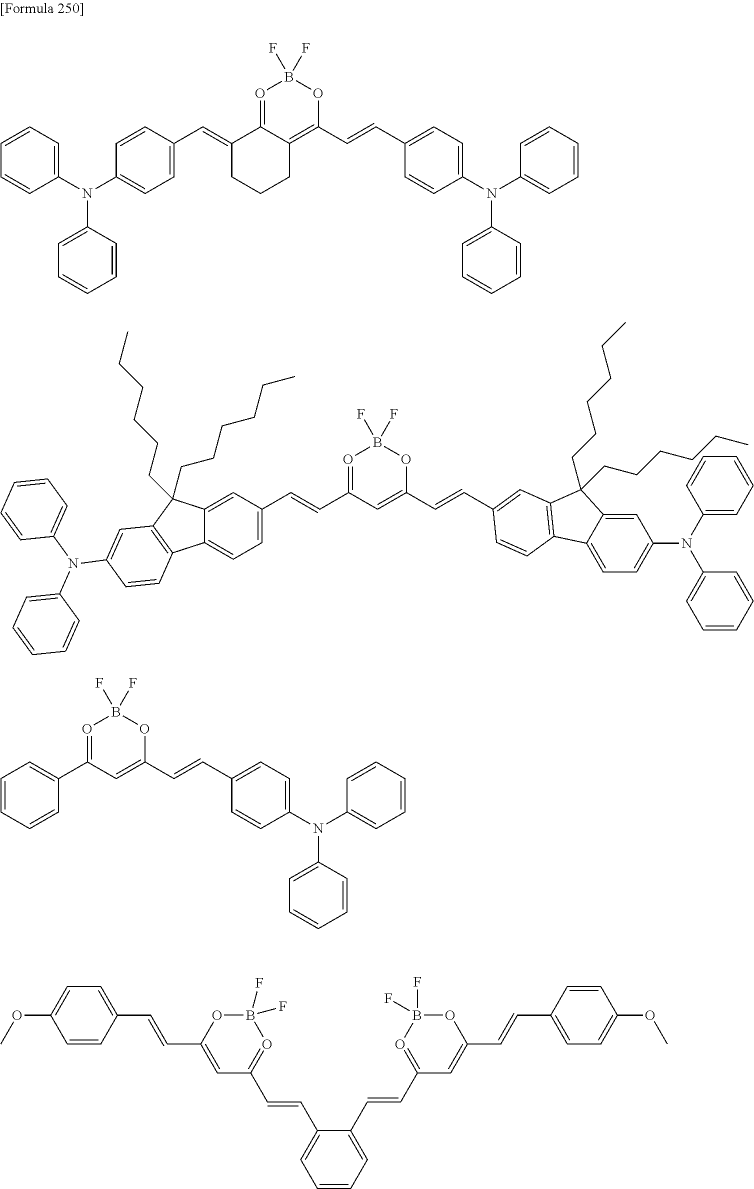

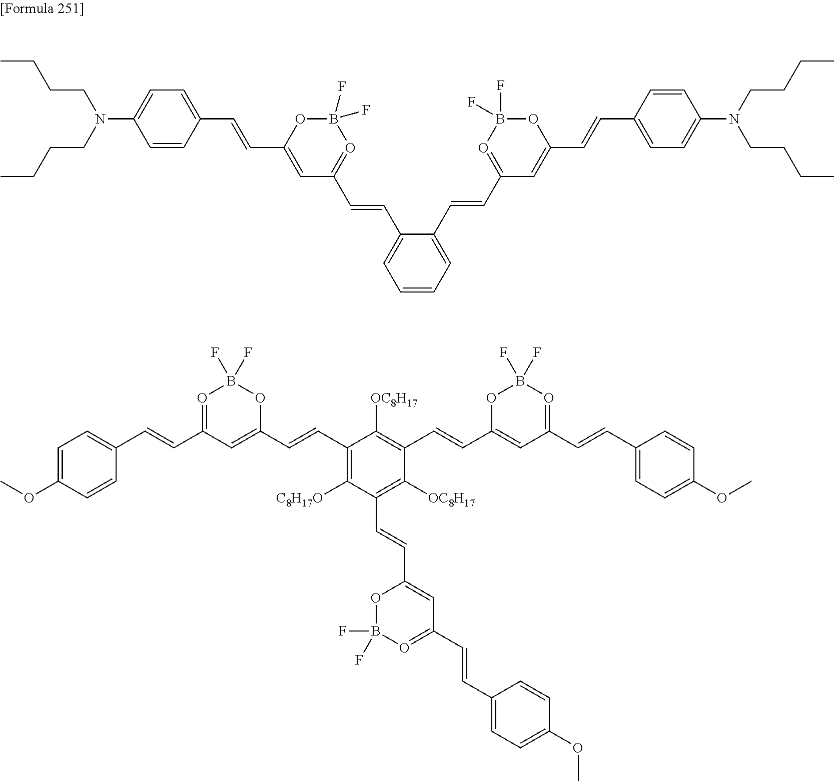

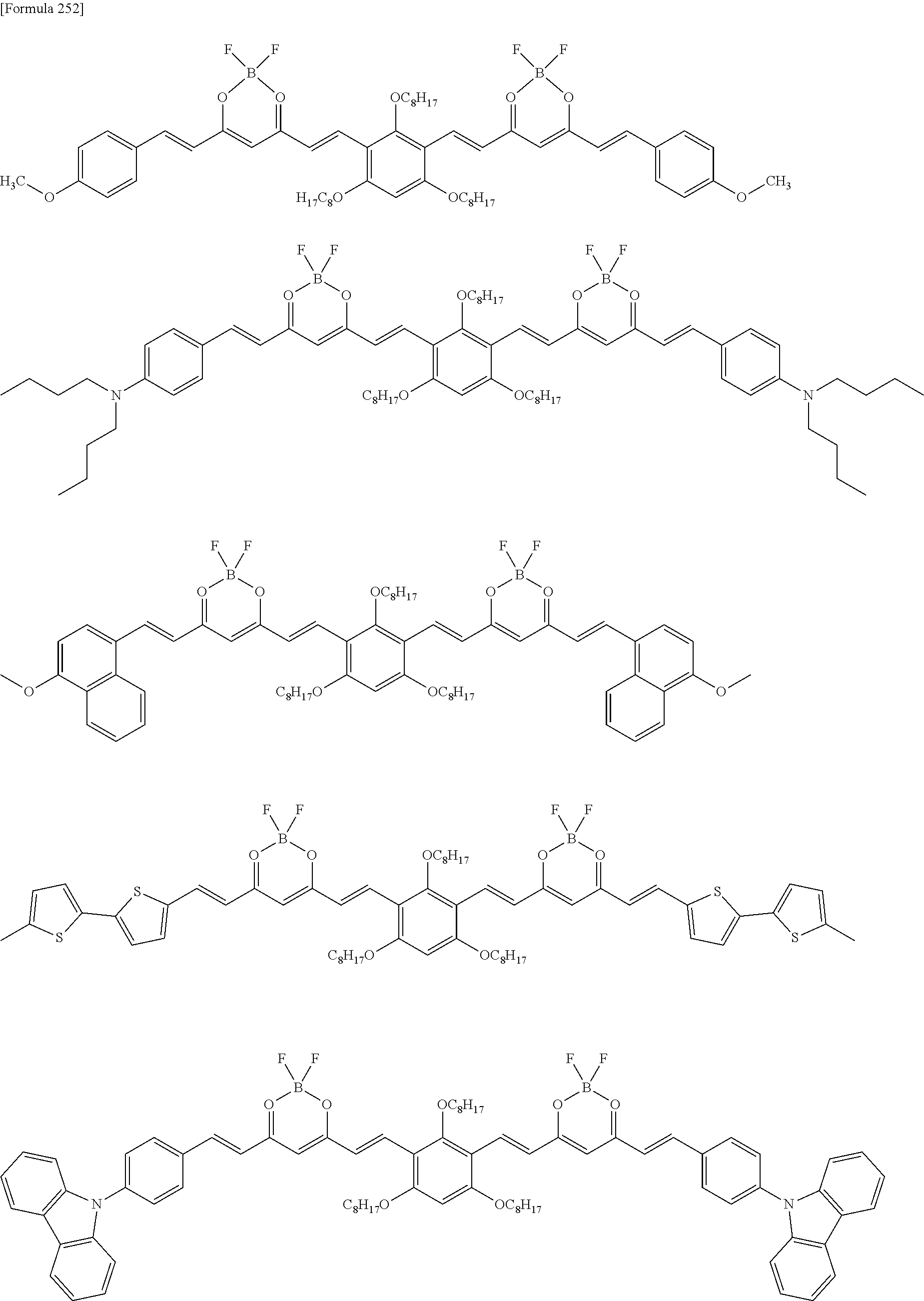

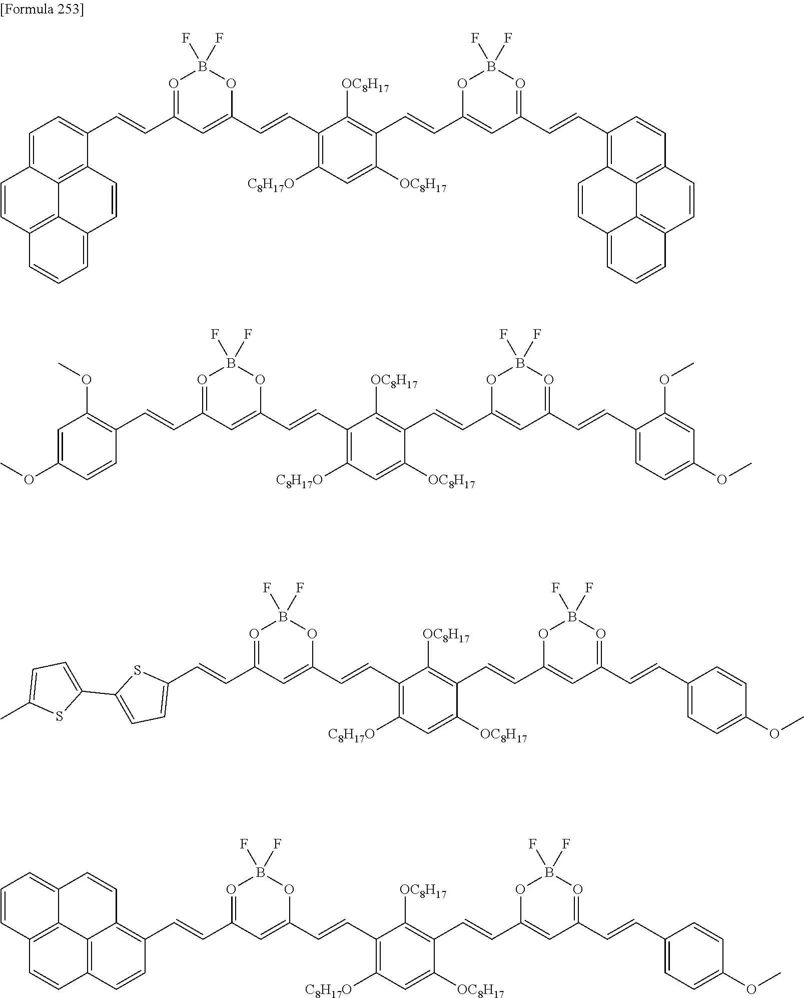

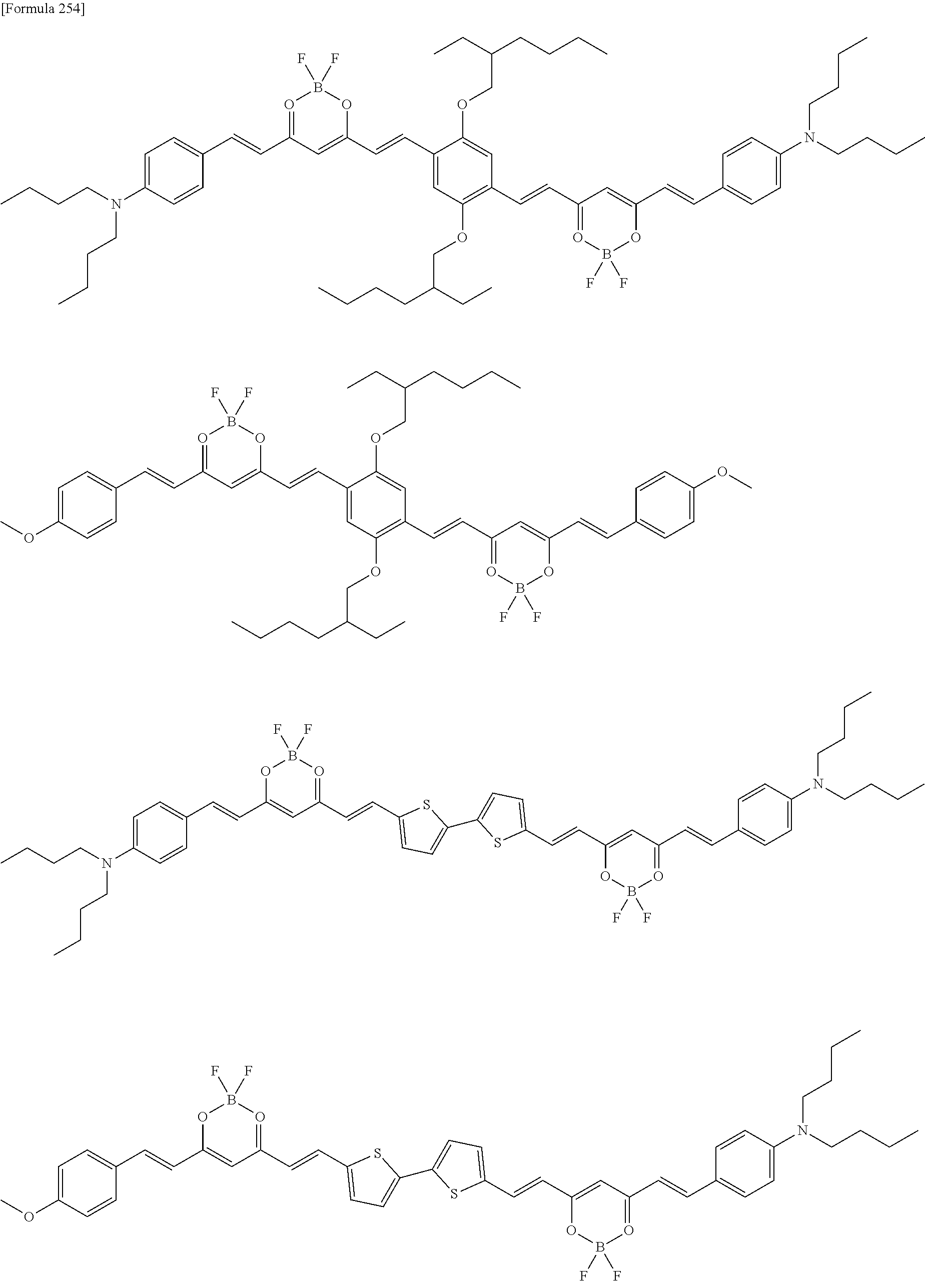

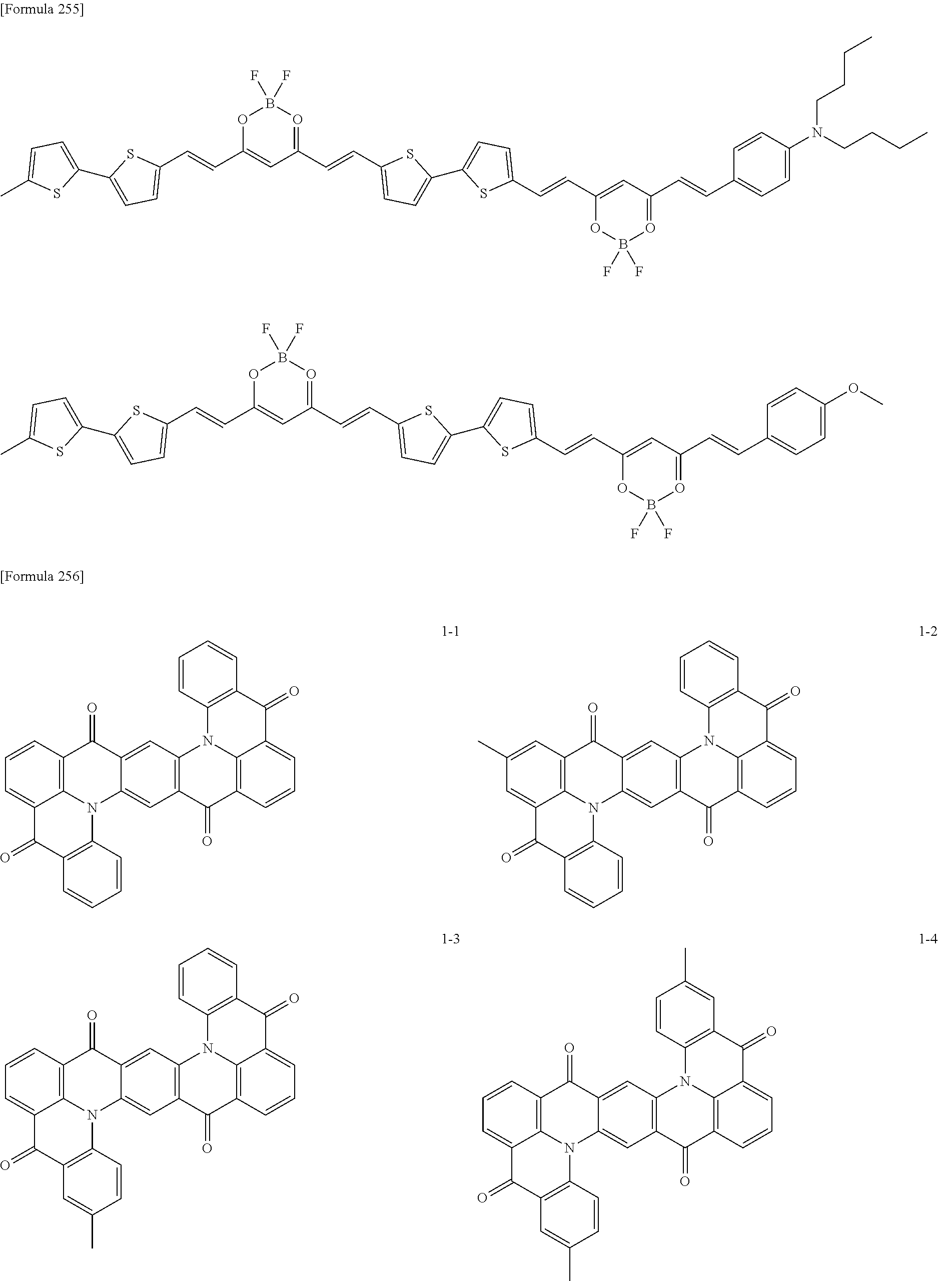

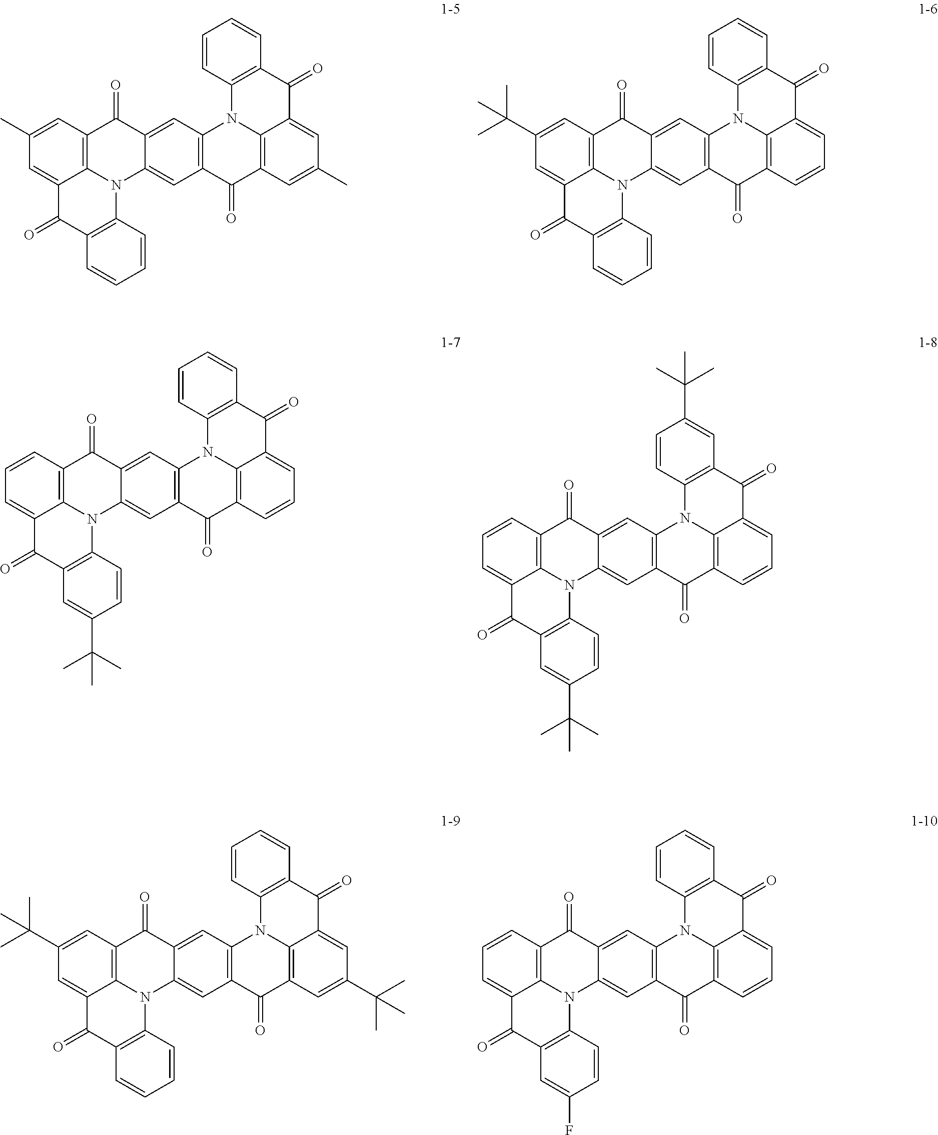

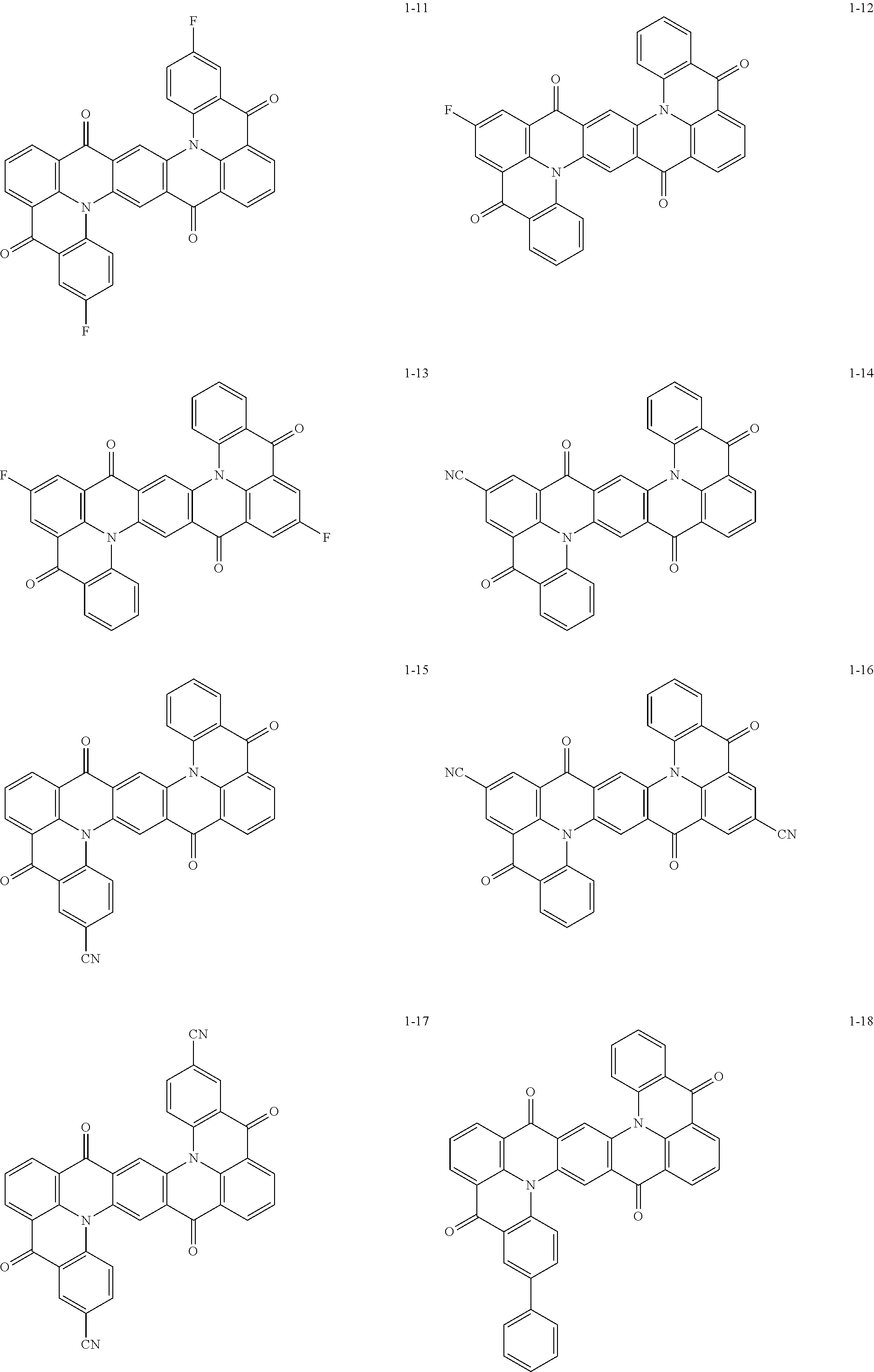

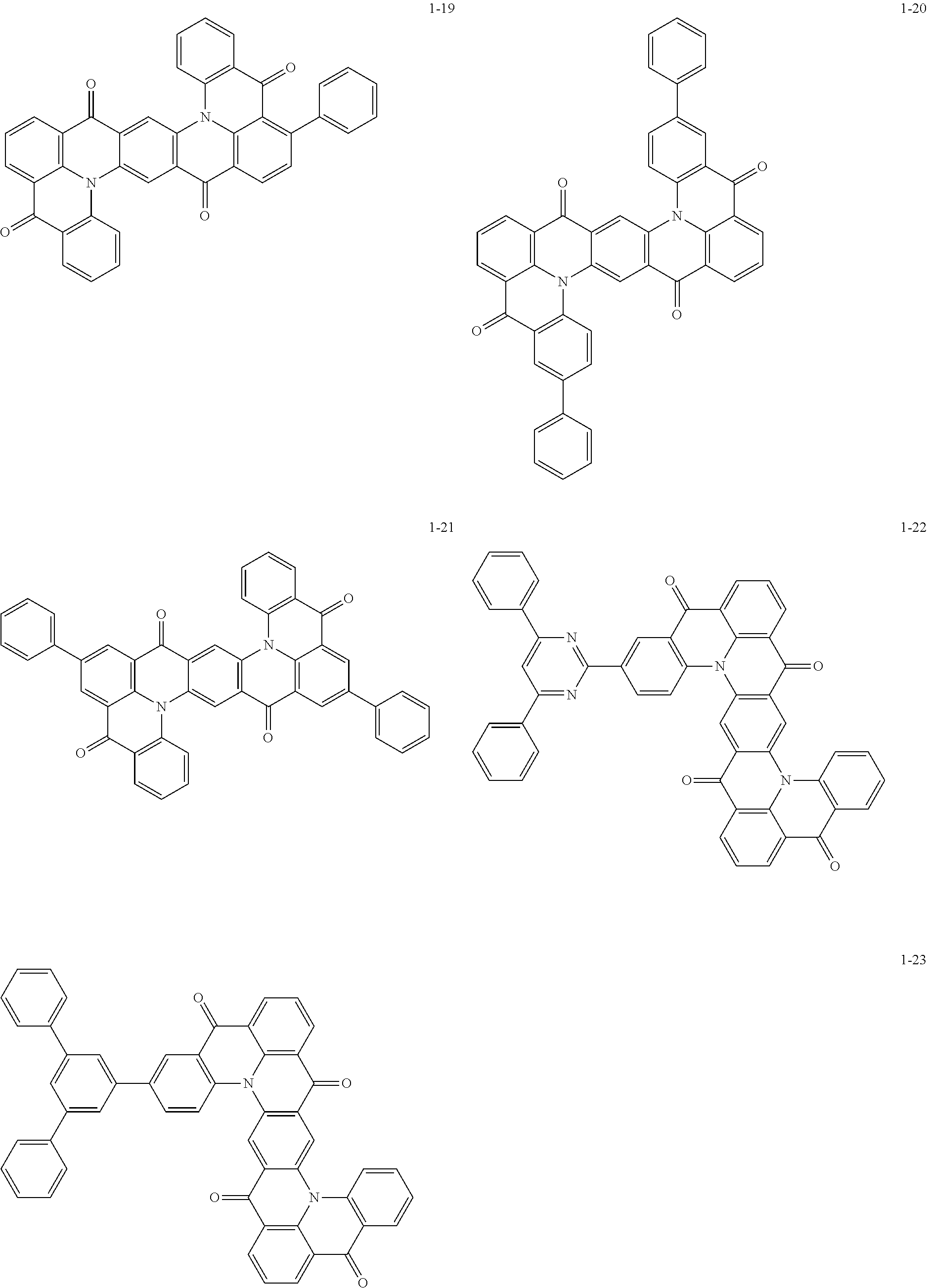

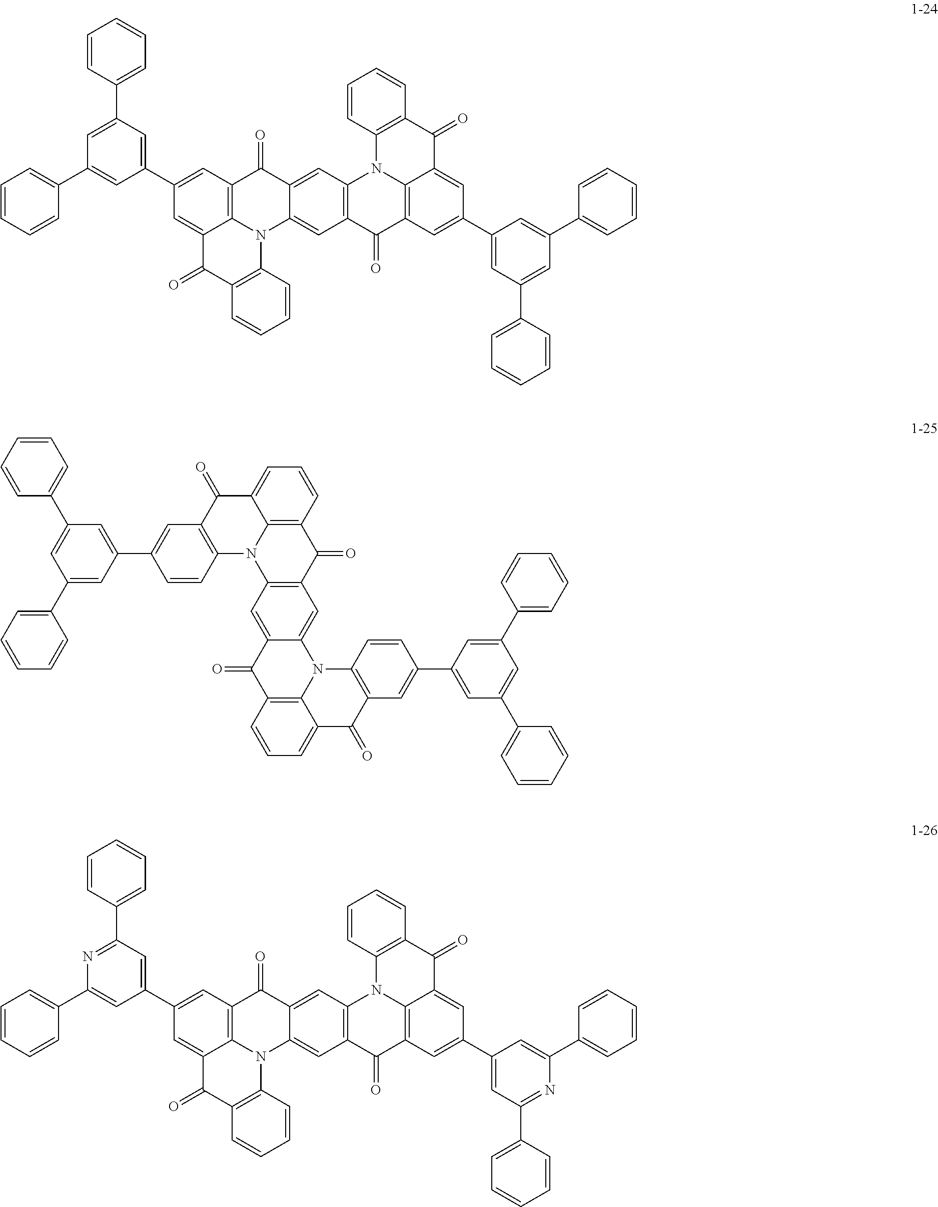 [SMILES: O=c1c2ccccc2n2c3cc4c(=O)c5cc(-c6cc(-c7ccccc7)cc(-c7ccccc7)c6)cc6c(=O)c7ccccc7n(c4cc3c(=O)c3cc(-c4cc(-c7ccccc7)cc(-c7ccccc7)c4)cc1c32)c65 ; O=c1c2cc(-c3cc(-c4ccccc4)cc(-c4ccccc4)c3)ccc2n2c3cc4c(=O)c5cccc6c(=O)c7cc(-c8cc(-c9ccccc9)cc(-c9ccccc9)c8)ccc7n(c4cc3c(=O)c3cccc1c32)c65 ; O=c1c2ccccc2n2c3cc4c(=O)c5cc(-c6cc(-c7ccccc7)nc(-c7ccccc7)c6)cc6c(=O)c7ccccc7n(c4cc3c(=O)c3cc(-c4cc(-c7ccccc7)nc(-c7ccccc7)c4)cc1c32)c65]

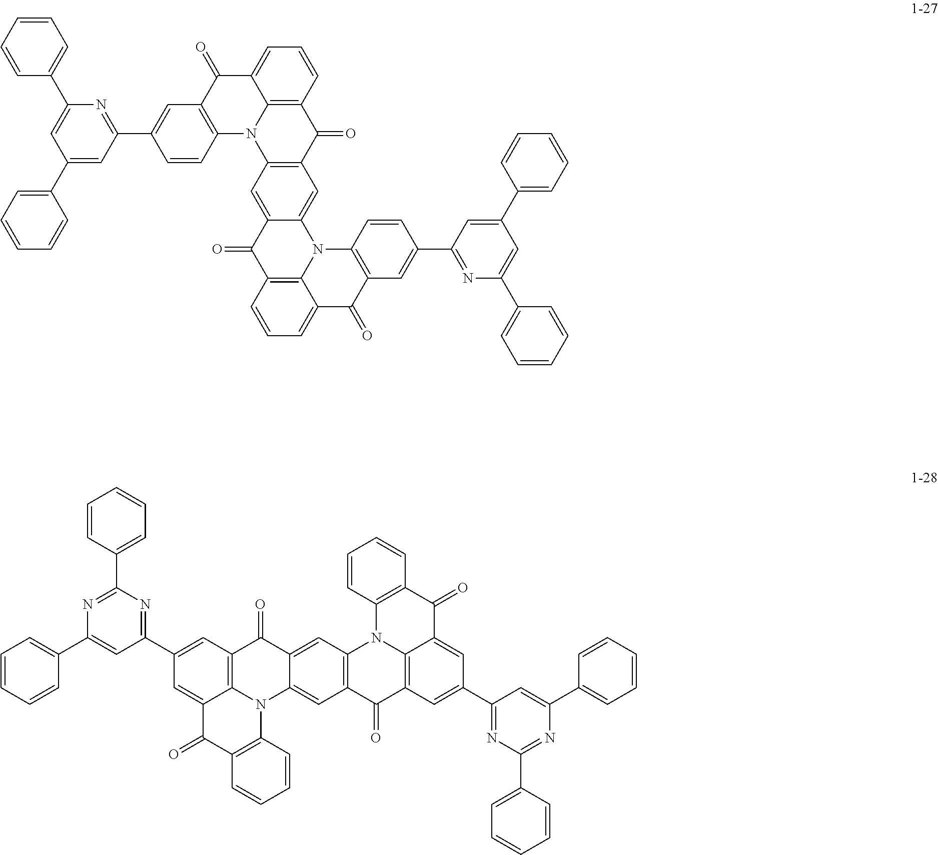 [SMILES: O=c1c2cc(-c3cc(-c4ccccc4)cc(-c4ccccc4)n3)ccc2n2c3cc4c(=O)c5cccc6c(=O)c7cc(-c8cc(-c9ccccc9)cc(-c9ccccc9)n8)ccc7n(c4cc3c(=O)c3cccc1c32)c65 ; O=c1c2ccccc2n2c3cc4c(=O)c5cc(-c6cc(-c7ccccc7)nc(-c7ccccc7)n6)cc6c(=O)c7ccccc7n(c4cc3c(=O)c3cc(-c4cc(-c7ccccc7)nc(-c7ccccc7)n4)cc1c32)c65]

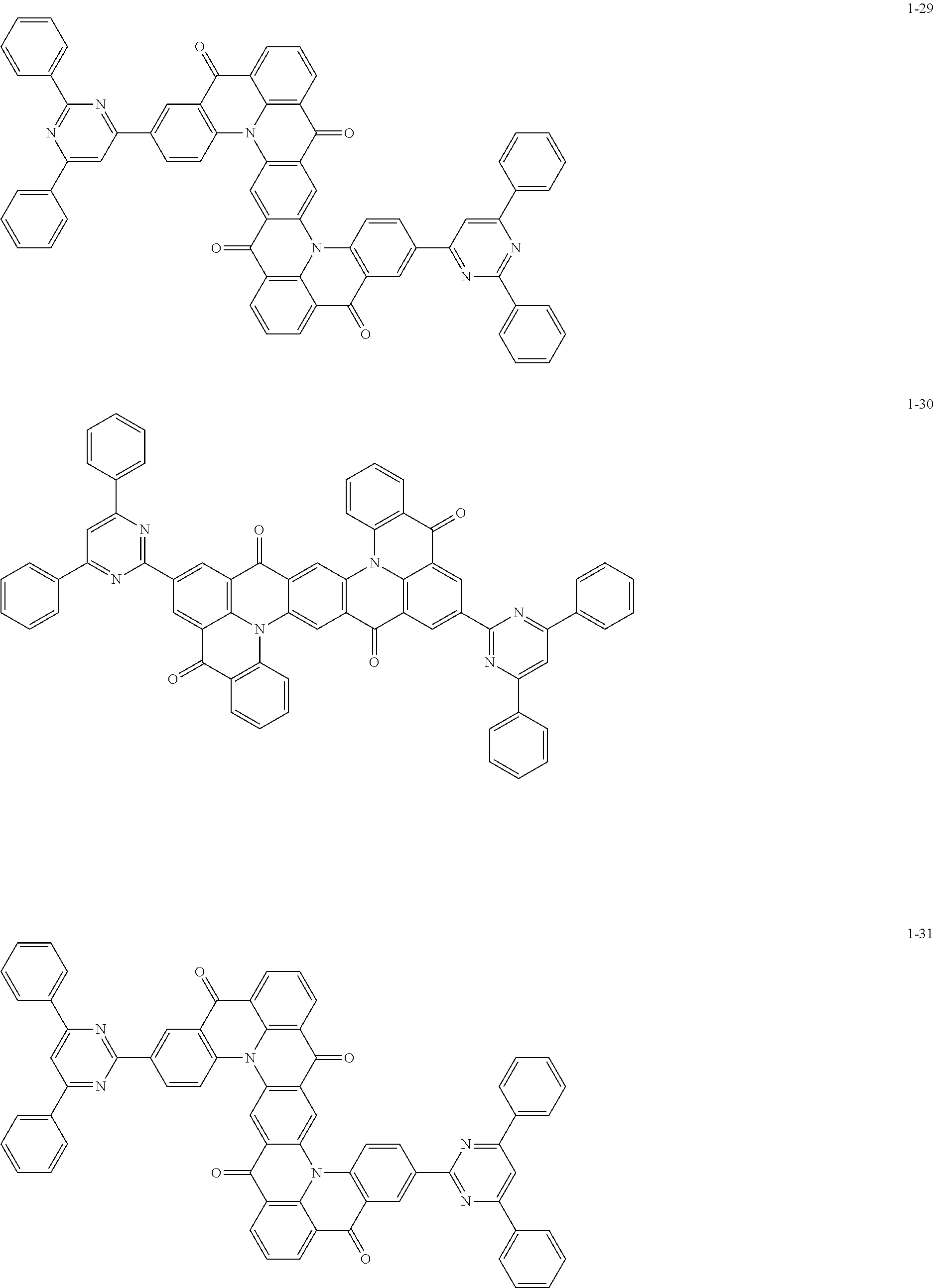 [SMILES: O=c1c2cc(-c3cc(-c4ccccc4)nc(-c4ccccc4)n3)ccc2n2c3cc4c(=O)c5cccc6c(=O)c7cc(-c8cc(-c9ccccc9)nc(-c9ccccc9)n8)ccc7n(c4cc3c(=O)c3cccc1c32)c65 ; O=c1c2ccccc2n2c3cc4c(=O)c5cc(-c6nc(-c7ccccc7)cc(-c7ccccc7)n6)cc6c(=O)c7ccccc7n(c4cc3c(=O)c3cc(-c4nc(-c7ccccc7)cc(-c7ccccc7)n4)cc1c32)c65 ; O=c1c2cc(-c3nc(-c4ccccc4)cc(-c4ccccc4)n3)ccc2n2c3cc4c(=O)c5cccc6c(=O)c7cc(-c8nc(-c9ccccc9)cc(-c9ccccc9)n8)ccc7n(c4cc3c(=O)c3cccc1c32)c65]

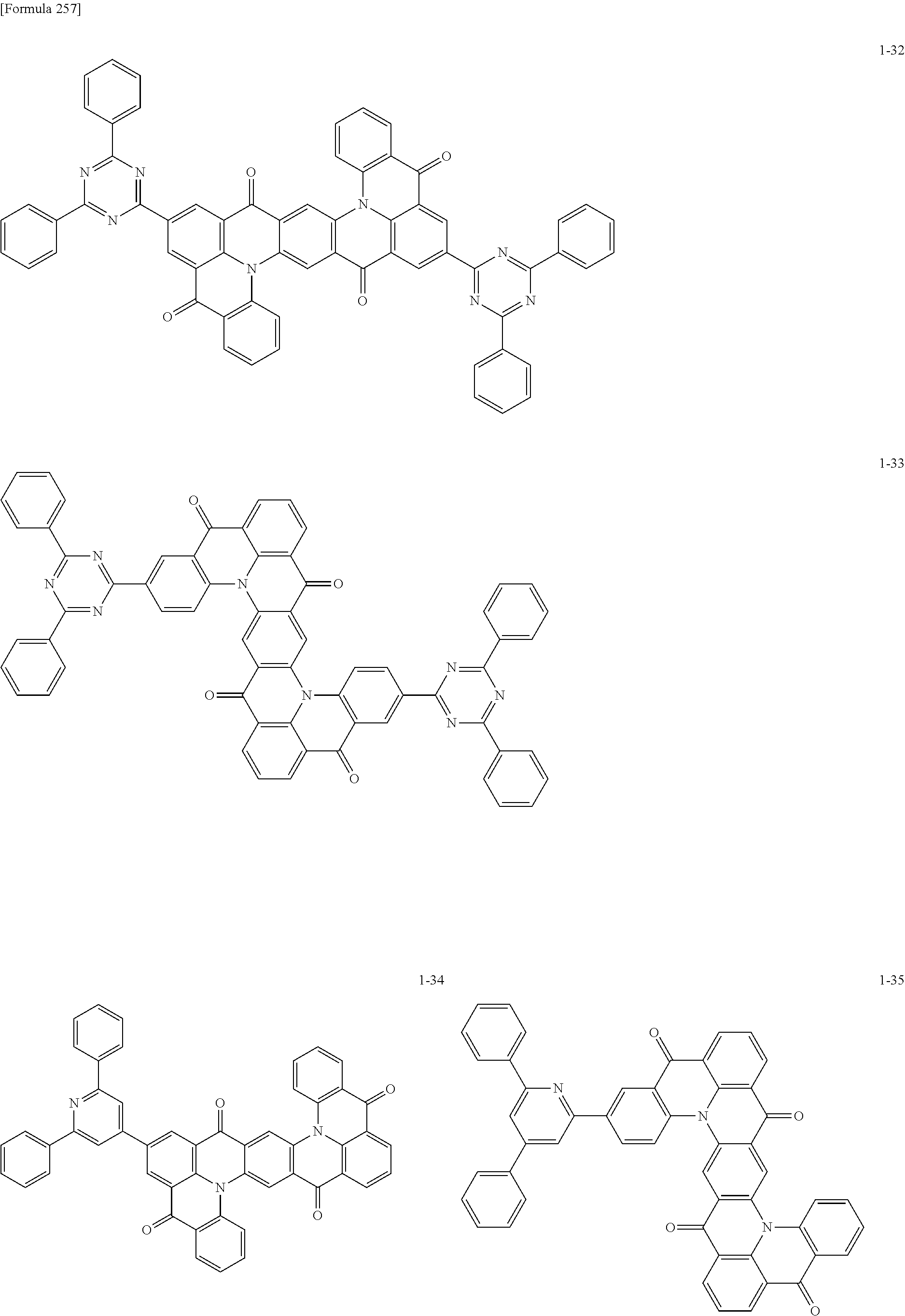 [SMILES: O=c1c2ccccc2n2c3cc4c(=O)c5cc(-c6nc(-c7ccccc7)nc(-c7ccccc7)n6)cc6c(=O)c7ccccc7n(c4cc3c(=O)c3cc(-c4nc(-c7ccccc7)nc(-c7ccccc7)n4)cc1c32)c65 ; O=c1c2cc(-c3nc(-c4ccccc4)nc(-c4ccccc4)n3)ccc2n2c3cc4c(=O)c5cccc6c(=O)c7cc(-c8nc(-c9ccccc9)nc(-c9ccccc9)n8)ccc7n(c4cc3c(=O)c3cccc1c32)c65 ; O=c1c2ccccc2n2c3cc4c(=O)c5cc(-c6cc(-c7ccccc7)nc(-c7ccccc7)c6)cc6c(=O)c7ccccc7n(c4cc3c(=O)c3cccc1c32)c65 ; O=c1c2ccccc2n2c3cc4c(=O)c5cccc6c(=O)c7cc(-c8cc(-c9ccccc9)cc(-c9ccccc9)n8)ccc7n(c4cc3c(=O)c3cccc1c32)c65]

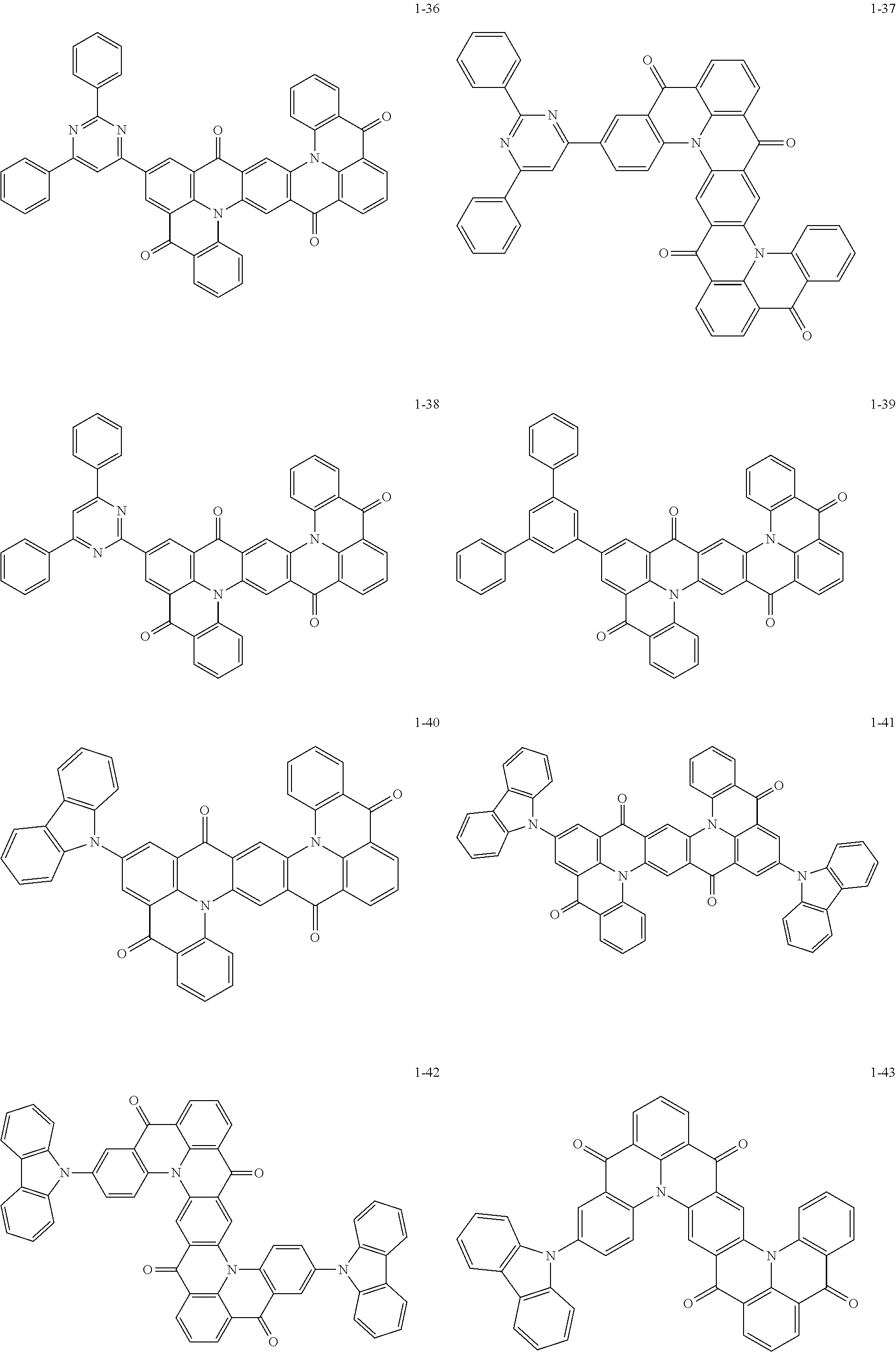

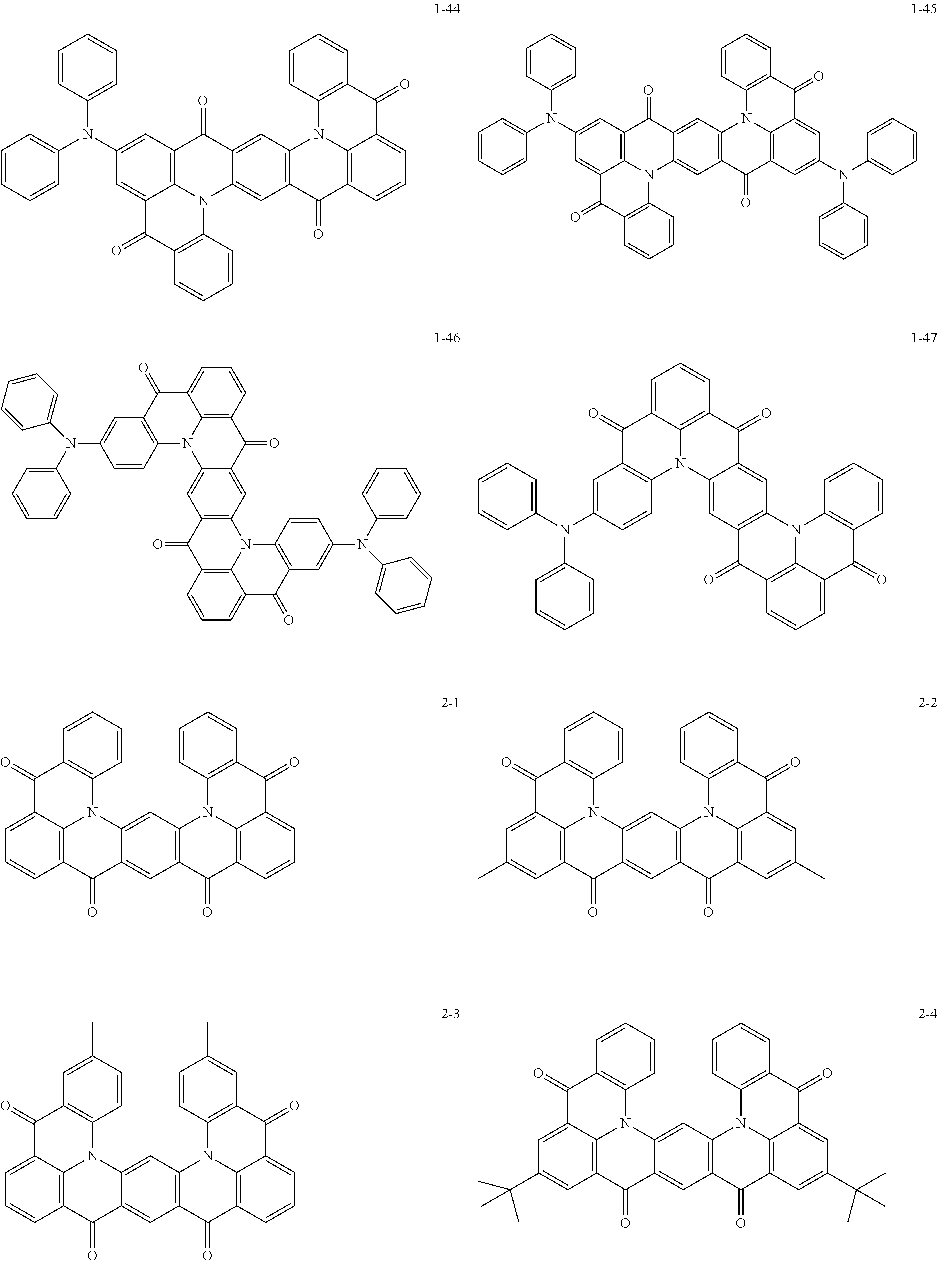

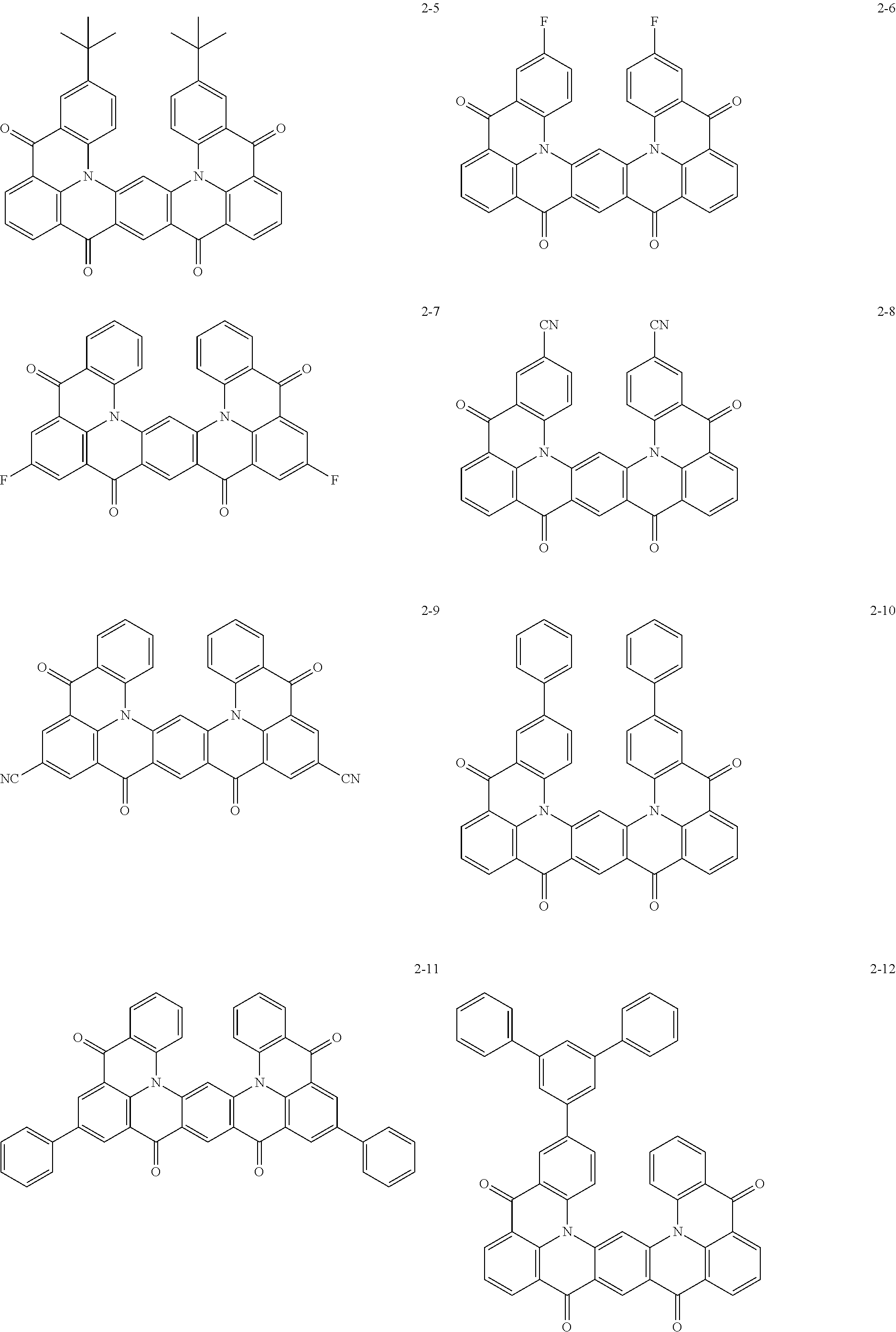

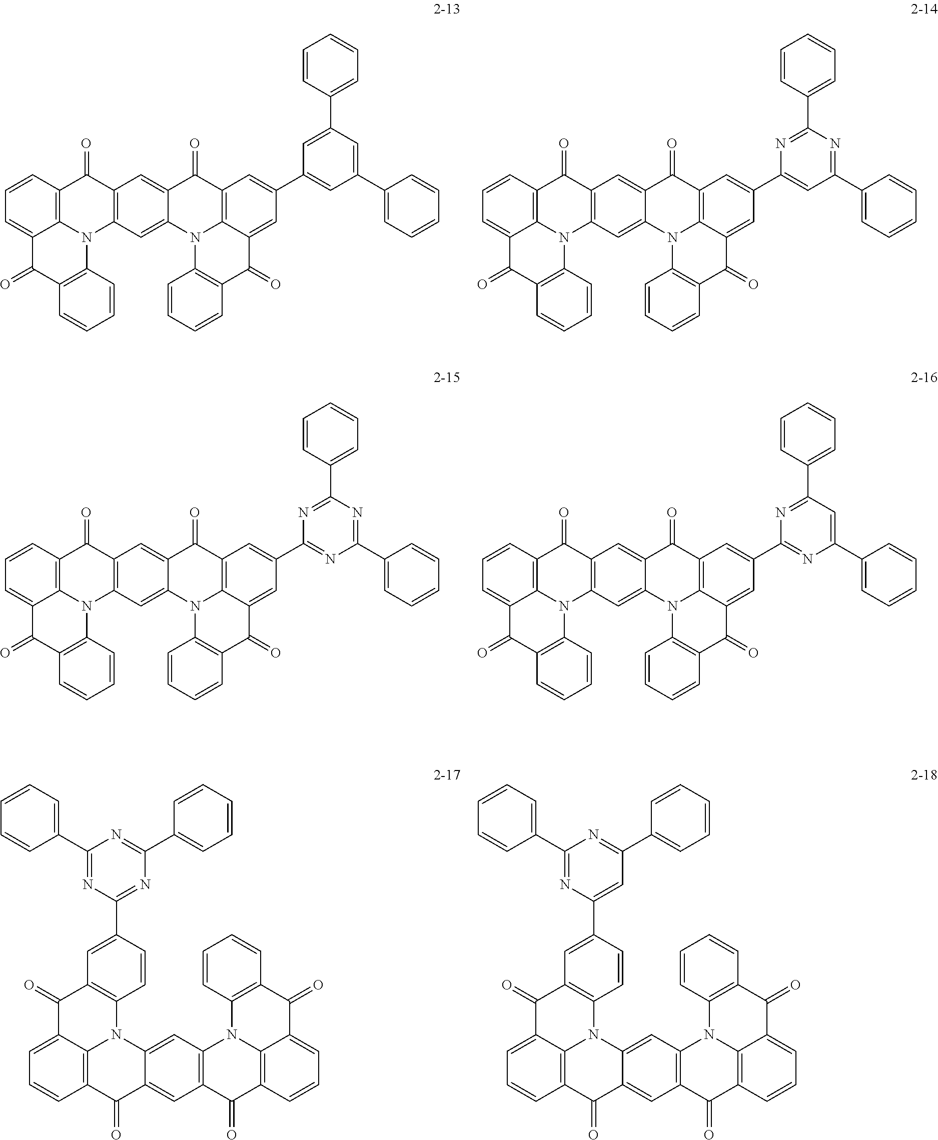

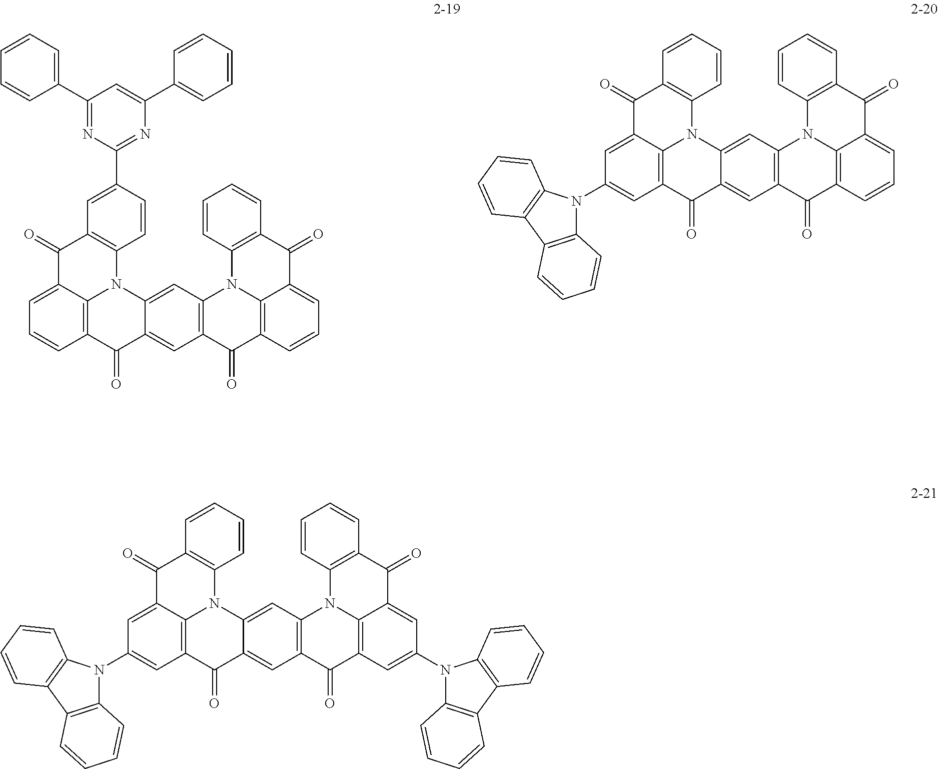 [SMILES: O=c1c2ccccc2n2c3cc4c(cc3c(=O)c3cccc1c32)c(=O)c1cccc2c(=O)c3cc(-c5nc(-c6ccccc6)cc(-c6ccccc6)n5)ccc3n4c21 ; O=c1c2ccccc2n2c3cc4c(cc3c(=O)c3cccc1c32)c(=O)c1cc(-n2c3ccccc3c3ccccc32)cc2c(=O)c3ccccc3n4c21 ; O=c1c2ccccc2n2c3cc4c(cc3c(=O)c3cc(-n5c6ccccc6c6ccccc65)cc1c32)c(=O)c1cc(-n2c3ccccc3c3ccccc32)cc2c(=O)c3ccccc3n4c21]

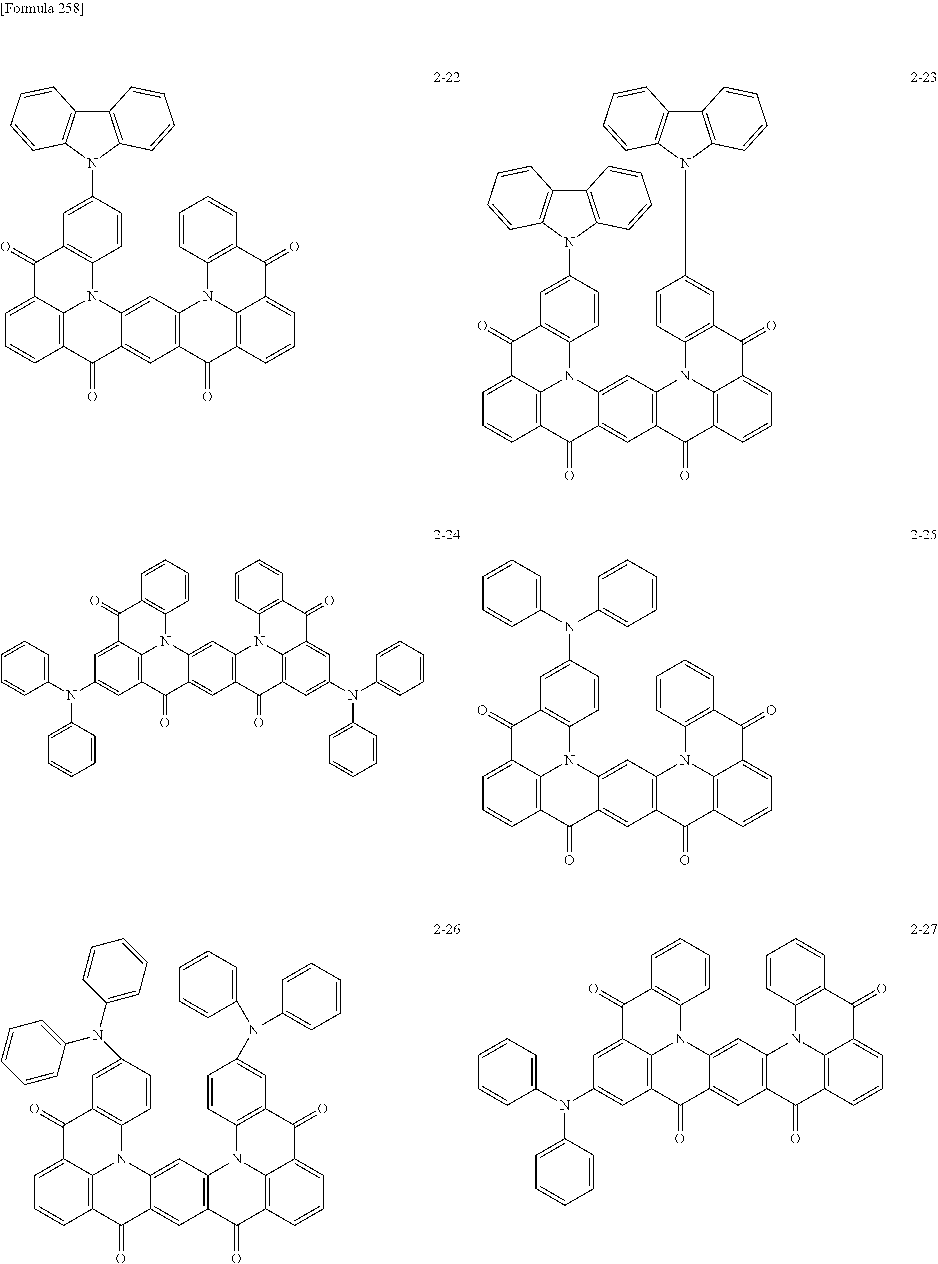

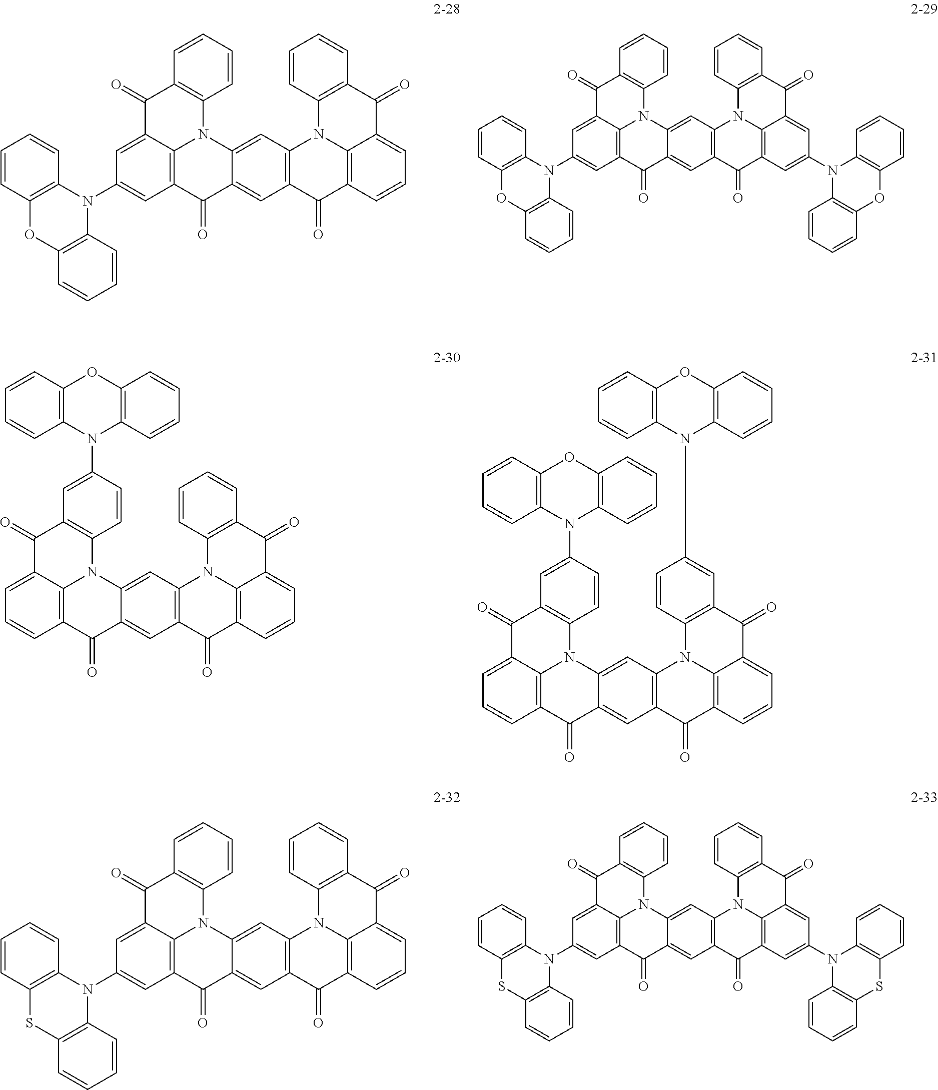

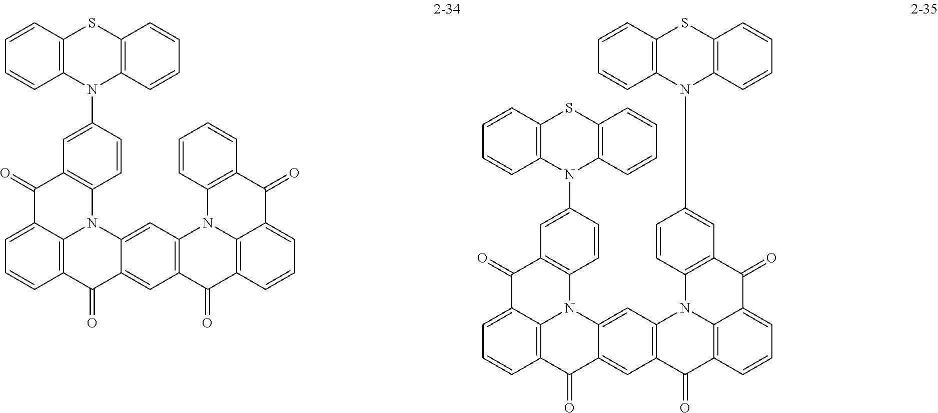 [SMILES: O=c1c2ccccc2n2c3cc4c(cc3c(=O)c3cccc1c32)c(=O)c1cccc2c(=O)c3cc(N5c6ccccc6Sc6ccccc65)ccc3n4c21 ; O=c1c2cc(N3c4ccccc4Sc4ccccc43)ccc2n2c3cc4c(cc3c(=O)c3cccc1c32)c(=O)c1cccc2c(=O)c3cc(N5c6ccccc6Sc6ccccc65)ccc3n4c21]

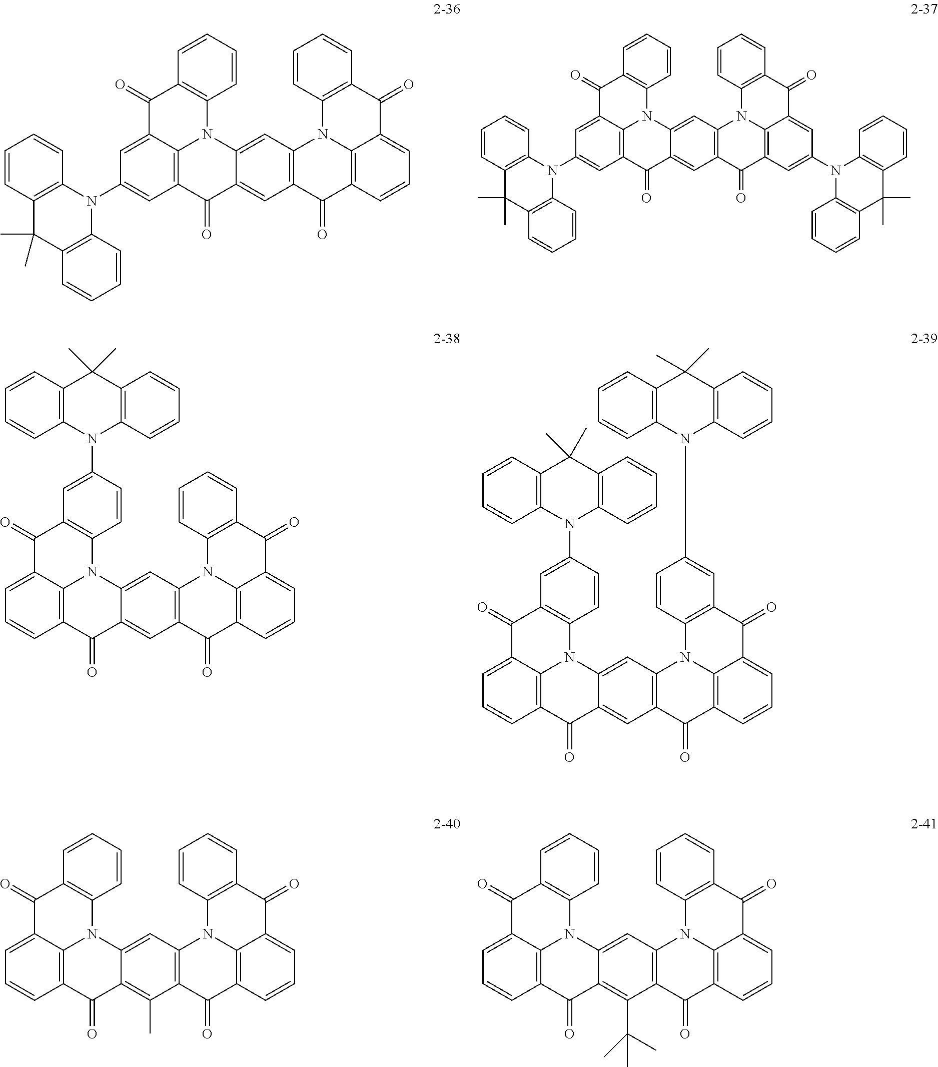

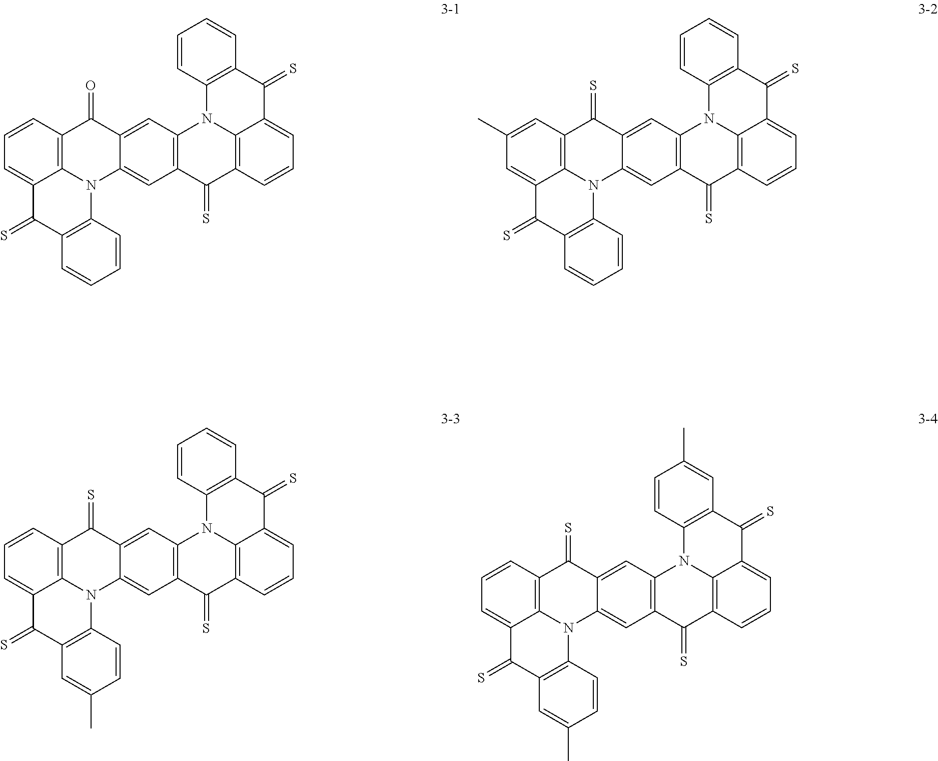 [SMILES: O=c1c2cc3c(cc2n2c4ccccc4c(=S)c4cccc1c42)c(=S)c1cccc2c(=S)c4ccccc4n3c21 ; Cc1cc2c(=S)c3ccccc3n3c4cc5c(=S)c6cccc7c(=S)c8ccccc8n(c5cc4c(=S)c(c1)c23)c76 ; Cc1ccc2c(c1)c(=S)c1cccc3c(=S)c4cc5c(cc4n2c13)c(=S)c1cccc2c(=S)c3ccccc3n5c21 ; Cc1ccc2c(c1)c(=S)c1cccc3c(=S)c4cc5c(cc4n2c13)c(=S)c1cccc2c(=S)c3cc(C)ccc3n5c21]

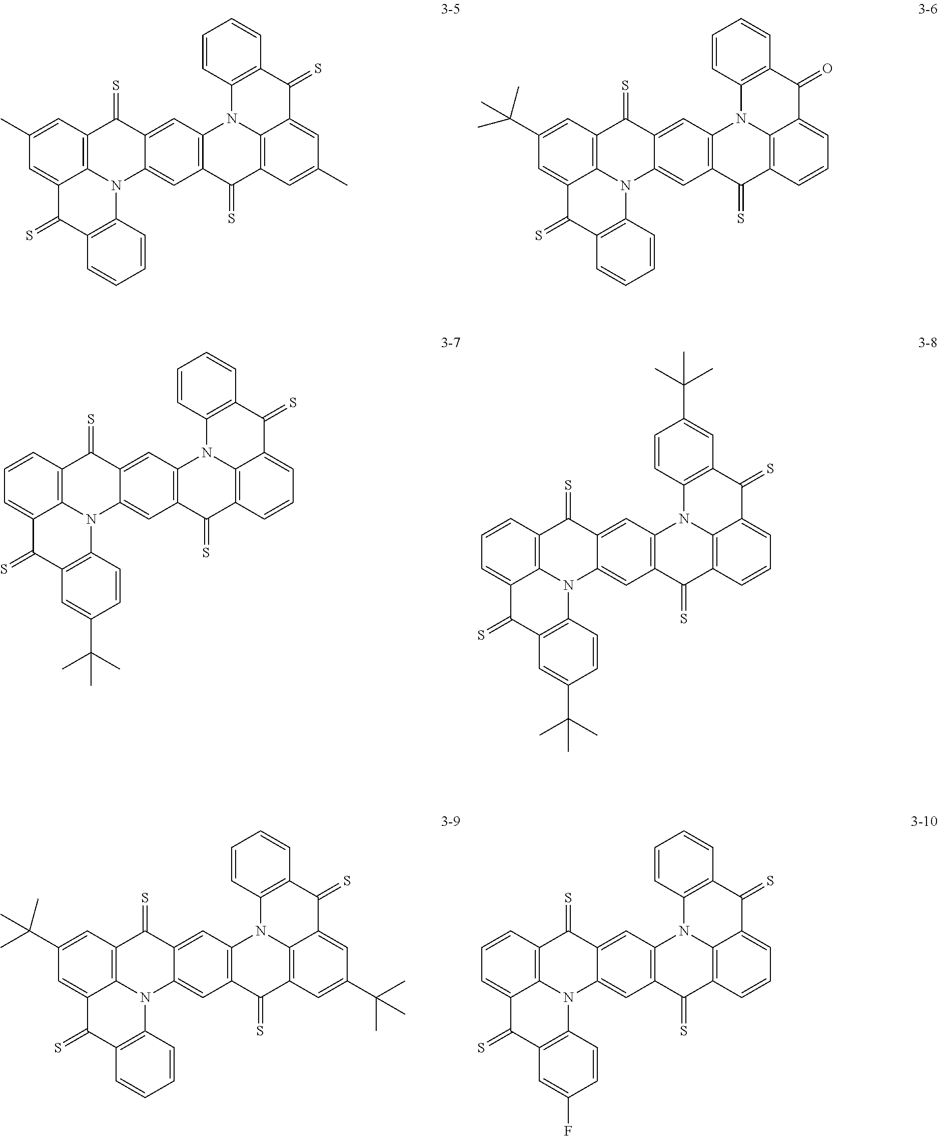

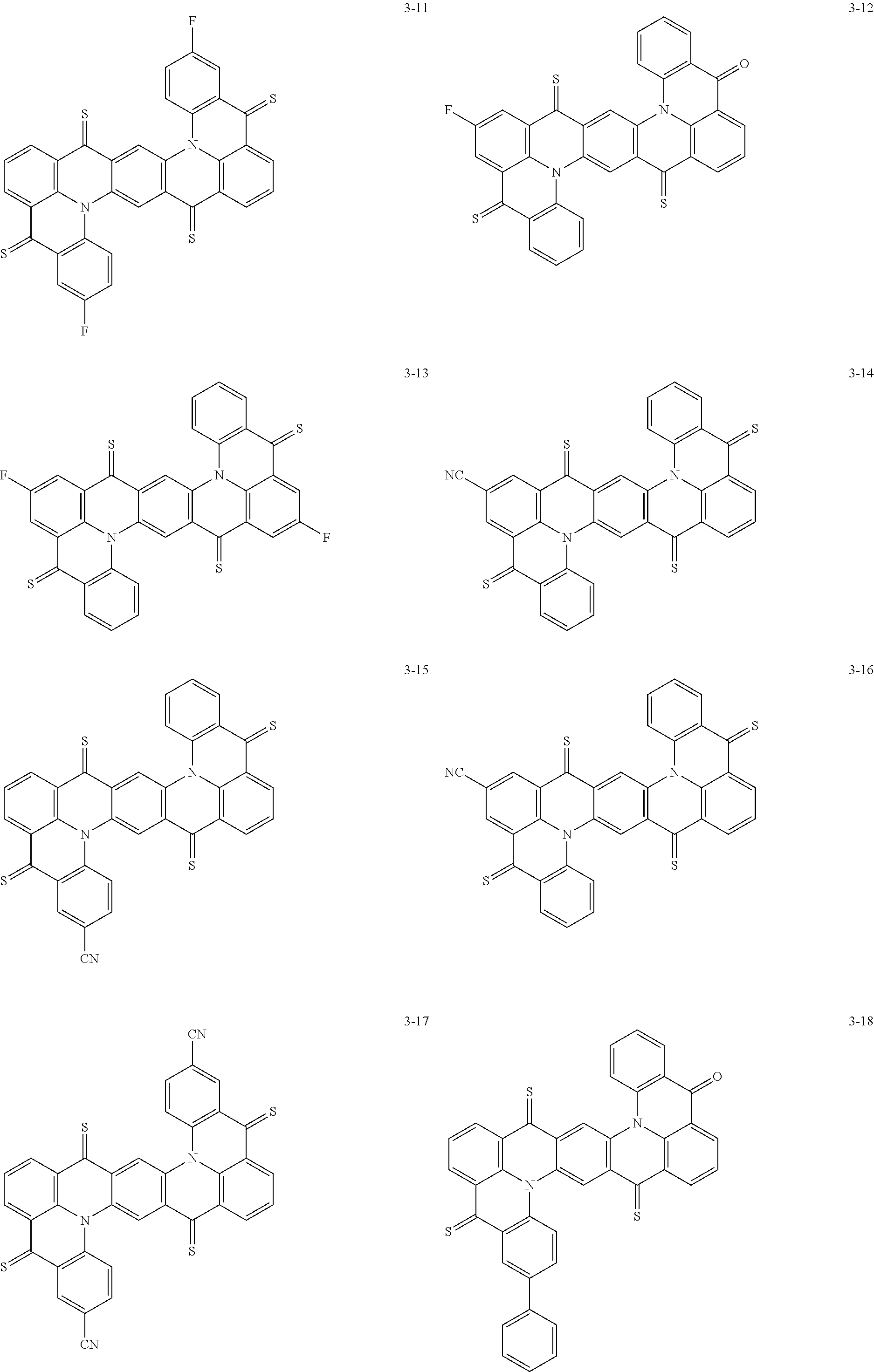

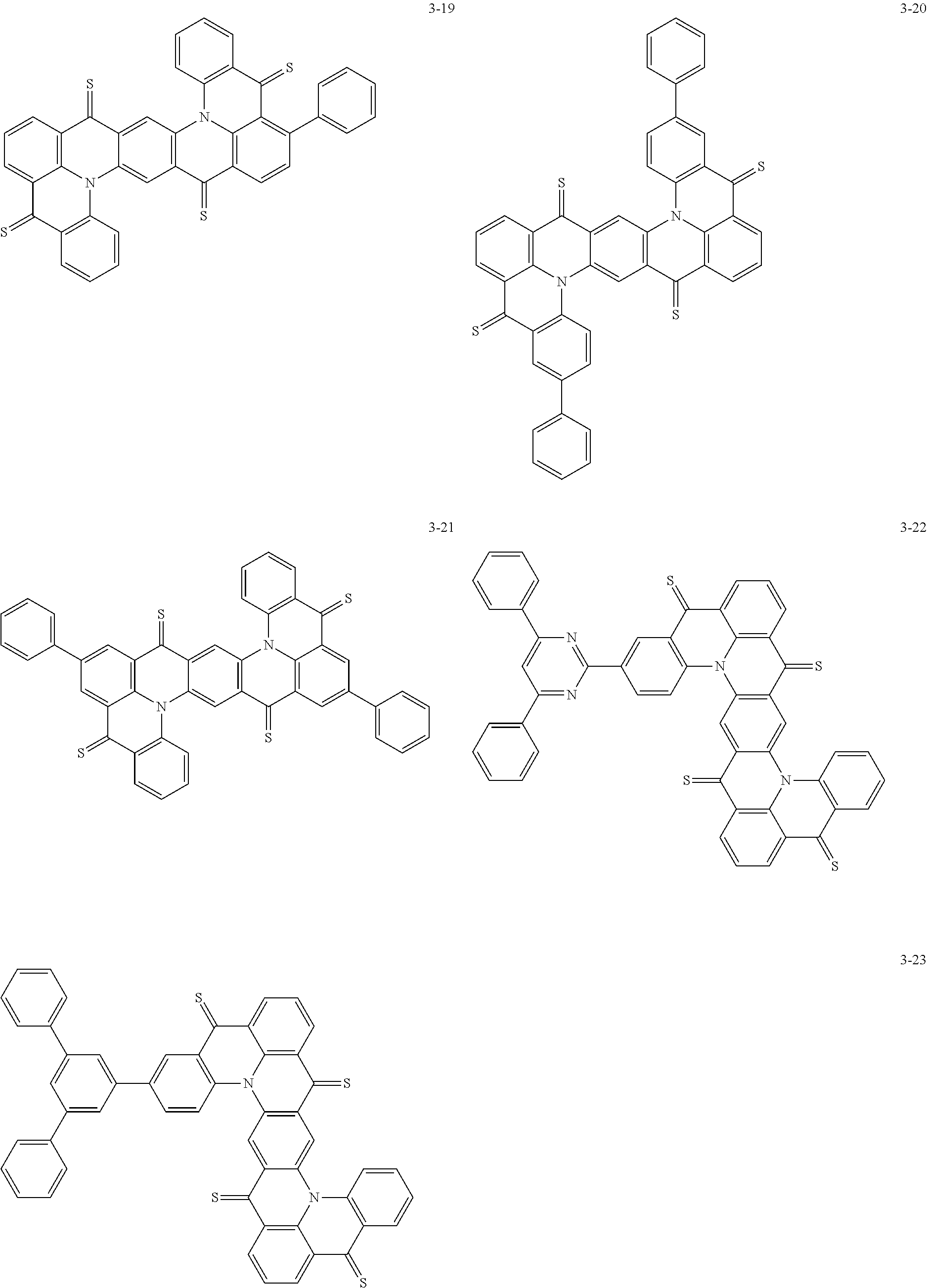

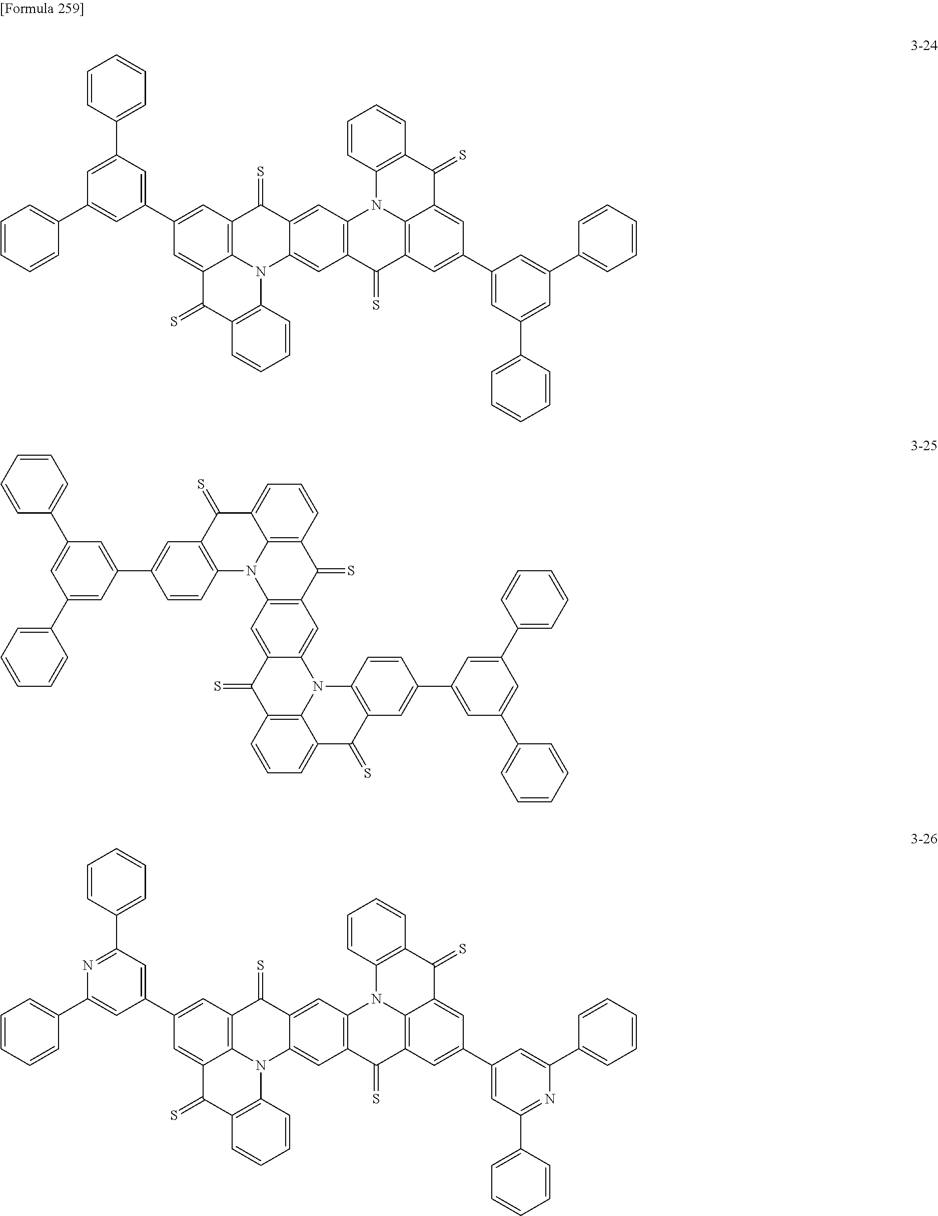 [SMILES: S=c1c2ccccc2n2c3cc4c(=S)c5cc(-c6cc(-c7ccccc7)cc(-c7ccccc7)c6)cc6c(=S)c7ccccc7n(c4cc3c(=S)c3cc(-c4cc(-c7ccccc7)cc(-c7ccccc7)c4)cc1c32)c65 ; S=c1c2cc(-c3cc(-c4ccccc4)cc(-c4ccccc4)c3)ccc2n2c3cc4c(=S)c5cccc6c(=S)c7cc(-c8cc(-c9ccccc9)cc(-c9ccccc9)c8)ccc7n(c4cc3c(=S)c3cccc1c32)c65 ; S=c1c2ccccc2n2c3cc4c(=S)c5cc(-c6cc(-c7ccccc7)nc(-c7ccccc7)c6)cc6c(=S)c7ccccc7n(c4cc3c(=S)c3cc(-c4cc(-c7ccccc7)nc(-c7ccccc7)c4)cc1c32)c65]

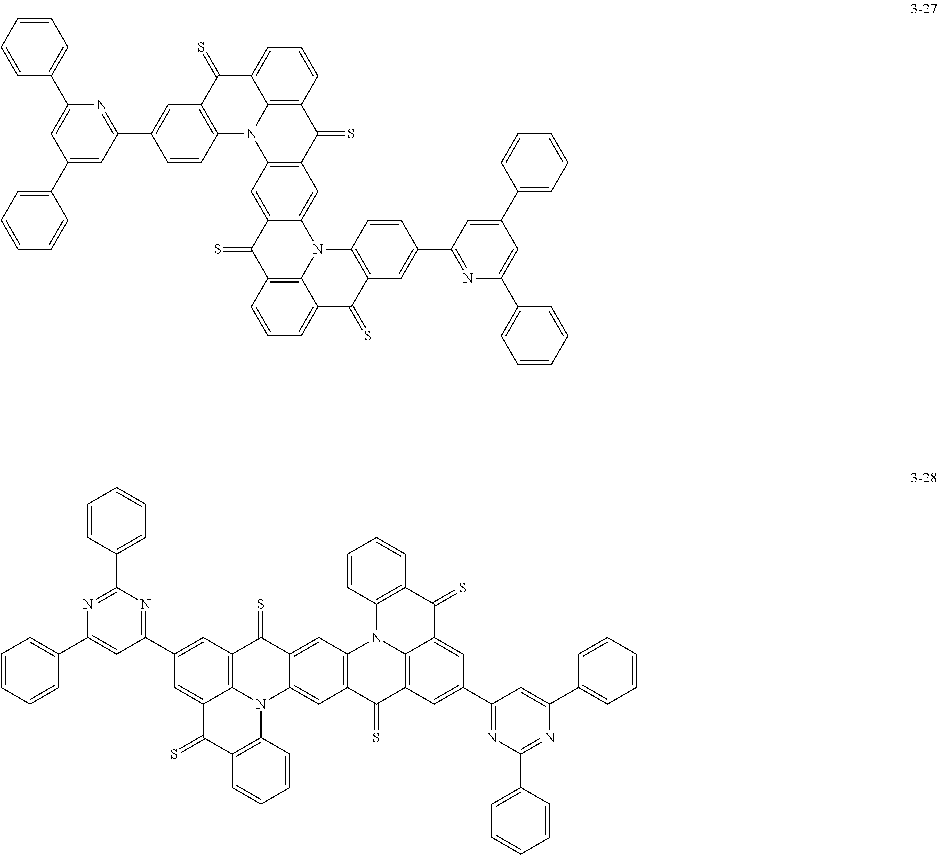 [SMILES: S=c1c2cc(-c3cc(-c4ccccc4)cc(-c4ccccc4)n3)ccc2n2c3cc4c(=S)c5cccc6c(=S)c7cc(-c8cc(-c9ccccc9)cc(-c9ccccc9)n8)ccc7n(c4cc3c(=S)c3cccc1c32)c65 ; S=c1c2ccccc2n2c3cc4c(=S)c5cc(-c6cc(-c7ccccc7)nc(-c7ccccc7)n6)cc6c(=S)c7ccccc7n(c4cc3c(=S)c3cc(-c4cc(-c7ccccc7)nc(-c7ccccc7)n4)cc1c32)c65]

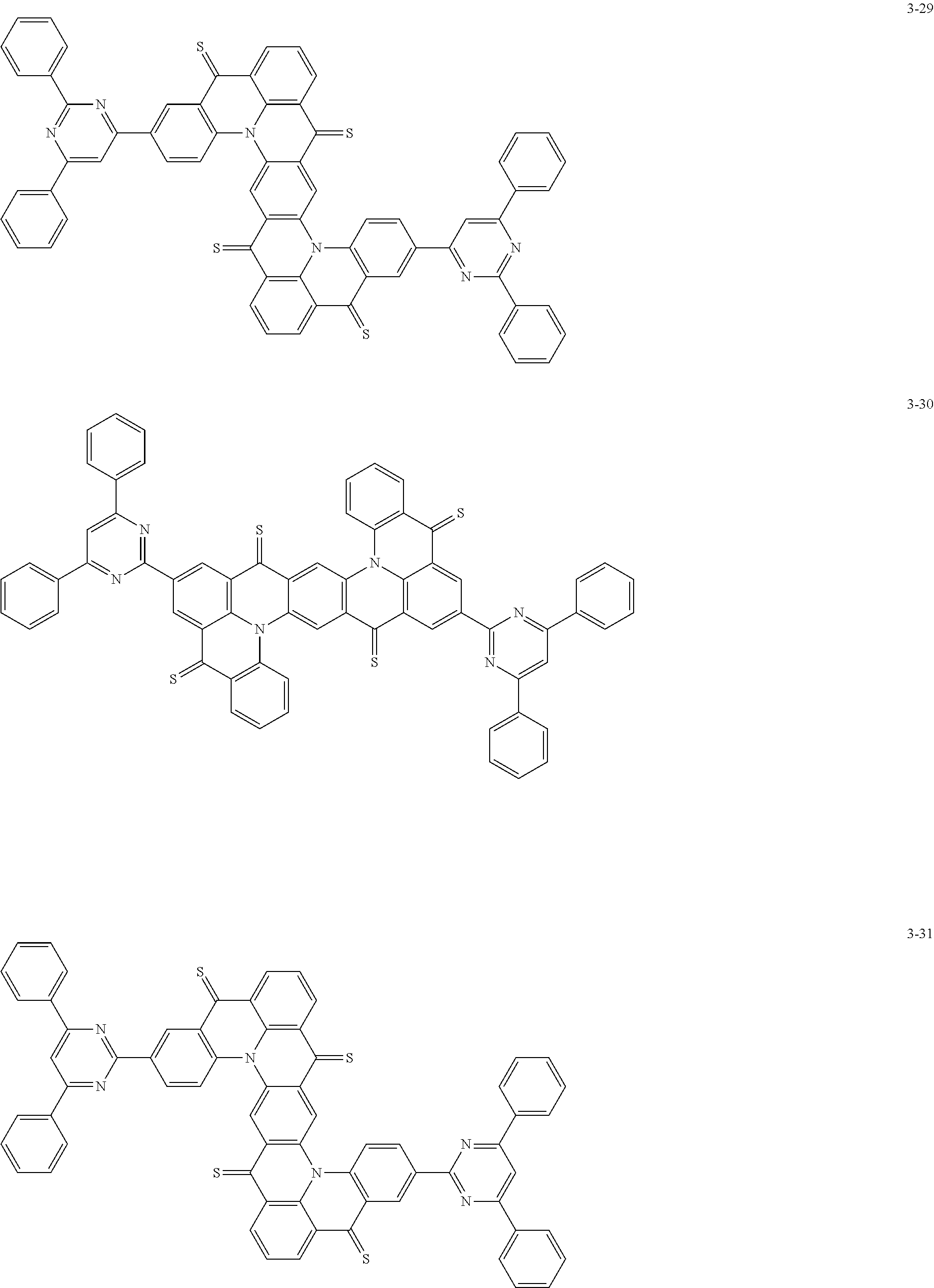 [SMILES: S=c1c2cc(-c3cc(-c4ccccc4)nc(-c4ccccc4)n3)ccc2n2c3cc4c(=S)c5cccc6c(=S)c7cc(-c8cc(-c9ccccc9)nc(-c9ccccc9)n8)ccc7n(c4cc3c(=S)c3cccc1c32)c65 ; S=c1c2ccccc2n2c3cc4c(=S)c5cc(-c6nc(-c7ccccc7)cc(-c7ccccc7)n6)cc6c(=S)c7ccccc7n(c4cc3c(=S)c3cc(-c4nc(-c7ccccc7)cc(-c7ccccc7)n4)cc1c32)c65 ; S=c1c2cc(-c3nc(-c4ccccc4)cc(-c4ccccc4)n3)ccc2n2c3cc4c(=S)c5cccc6c(=S)c7cc(-c8nc(-c9ccccc9)cc(-c9ccccc9)n8)ccc7n(c4cc3c(=S)c3cccc1c32)c65]

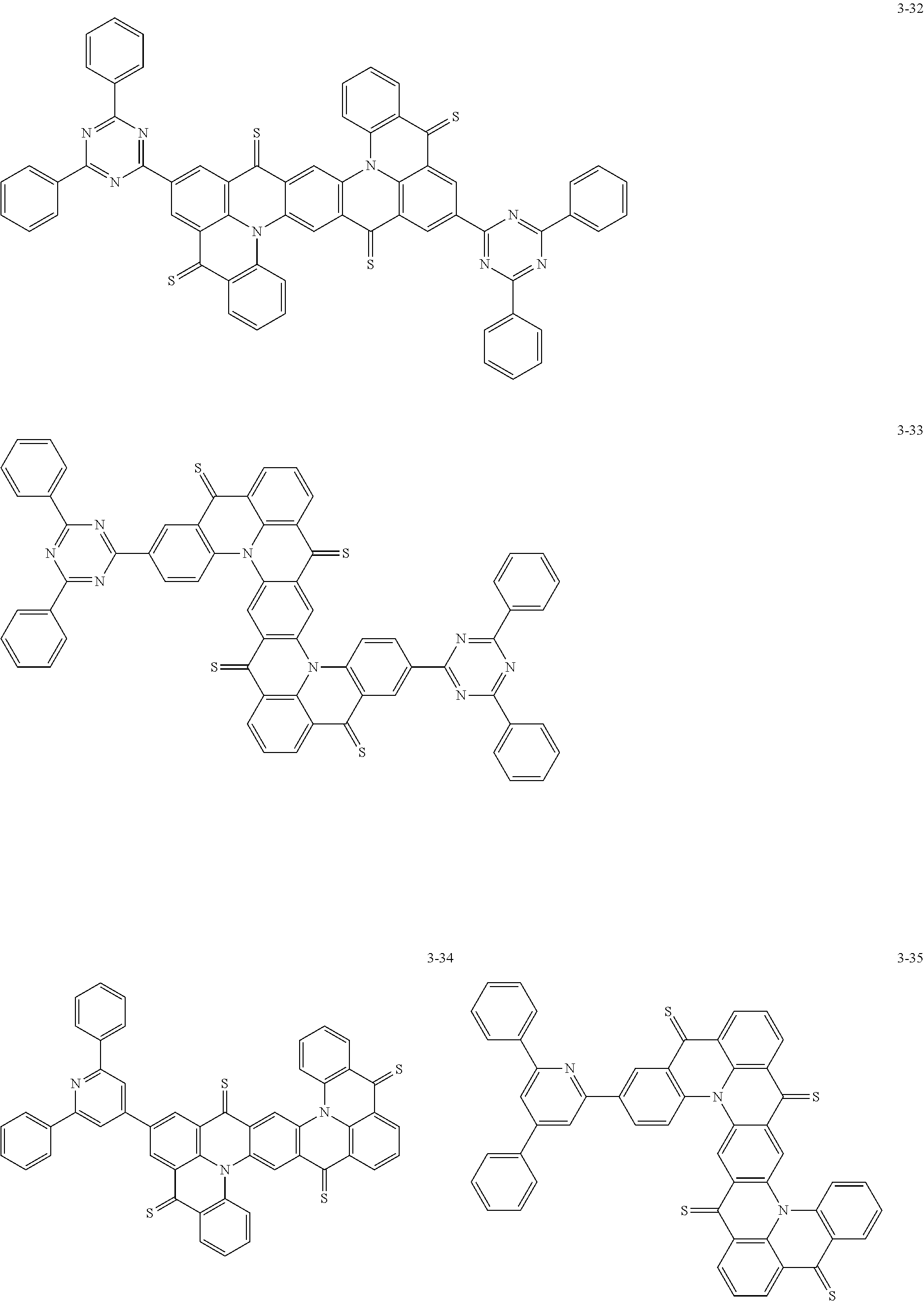 [SMILES: S=c1c2ccccc2n2c3cc4c(=S)c5cc(-c6nc(-c7ccccc7)nc(-c7ccccc7)n6)cc6c(=S)c7ccccc7n(c4cc3c(=S)c3cc(-c4nc(-c7ccccc7)nc(-c7ccccc7)n4)cc1c32)c65 ; S=c1c2cc(-c3nc(-c4ccccc4)nc(-c4ccccc4)n3)ccc2n2c3cc4c(=S)c5cccc6c(=S)c7cc(-c8nc(-c9ccccc9)nc(-c9ccccc9)n8)ccc7n(c4cc3c(=S)c3cccc1c32)c65 ; S=c1c2ccccc2n2c3cc4c(=S)c5cc(-c6cc(-c7ccccc7)nc(-c7ccccc7)c6)cc6c(=S)c7ccccc7n(c4cc3c(=S)c3cccc1c32)c65 ; S=c1c2ccccc2n2c3cc4c(=S)c5cccc6c(=S)c7cc(-c8cc(-c9ccccc9)cc(-c9ccccc9)n8)ccc7n(c4cc3c(=S)c3cccc1c32)c65]

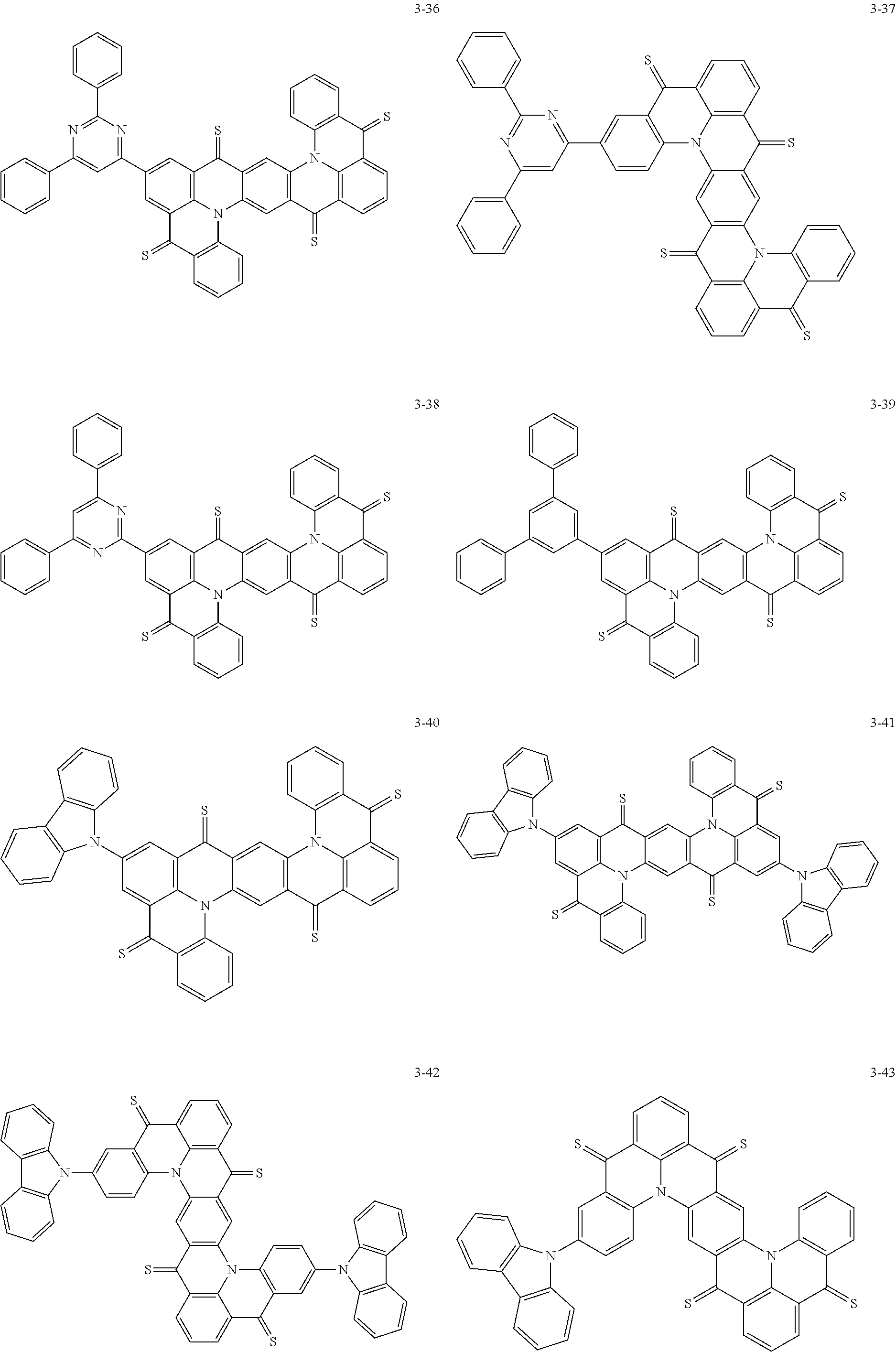

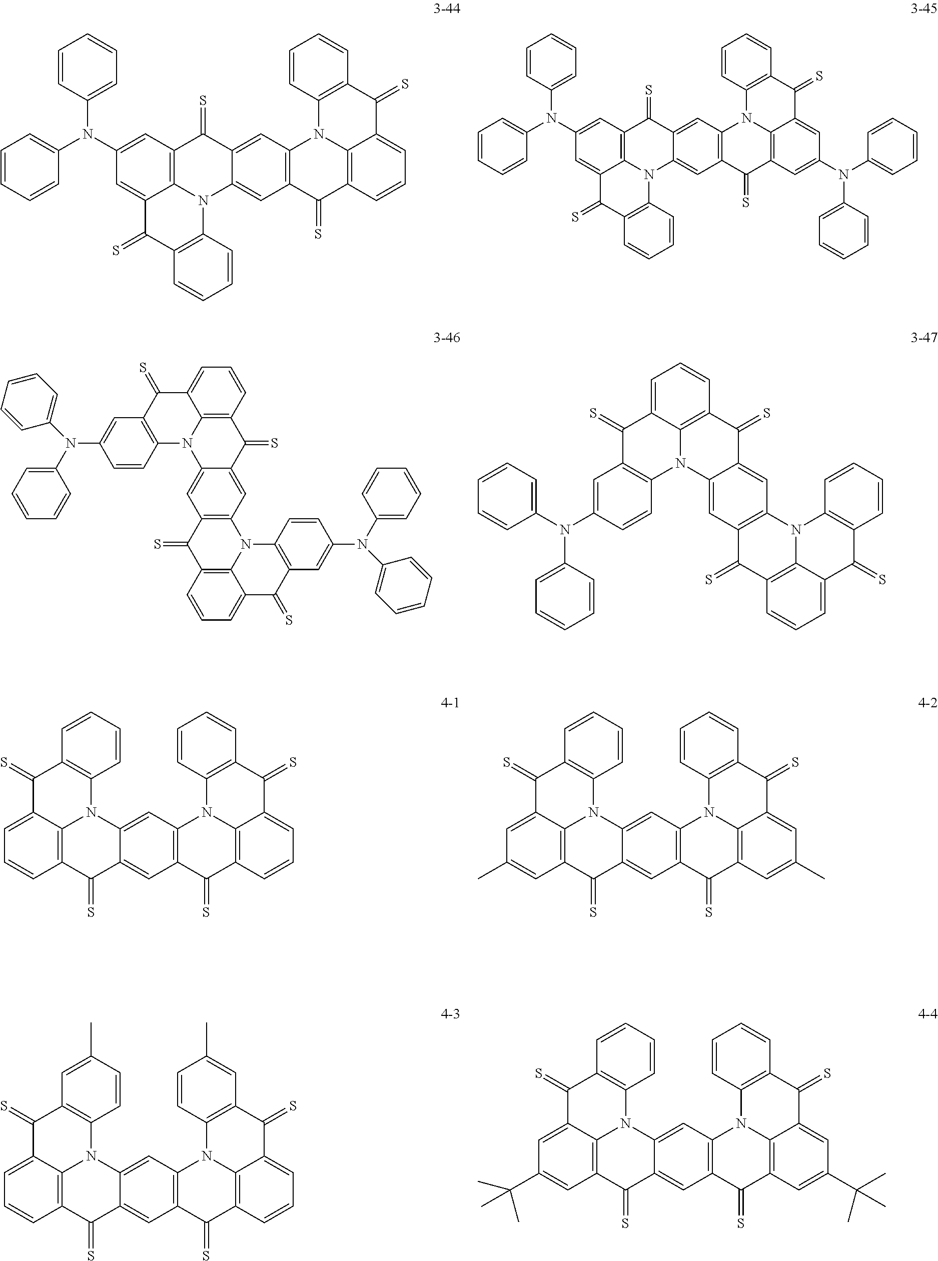

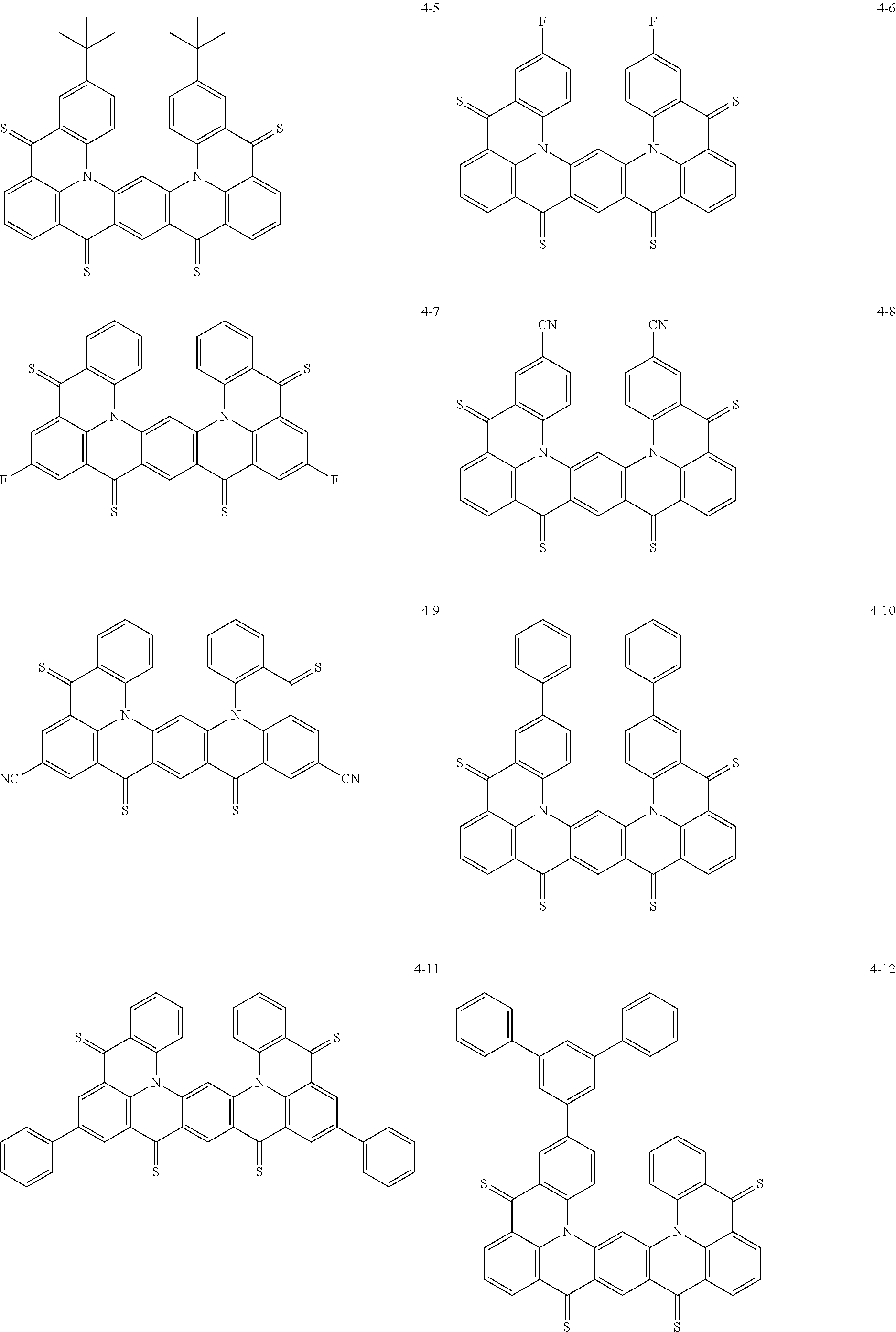

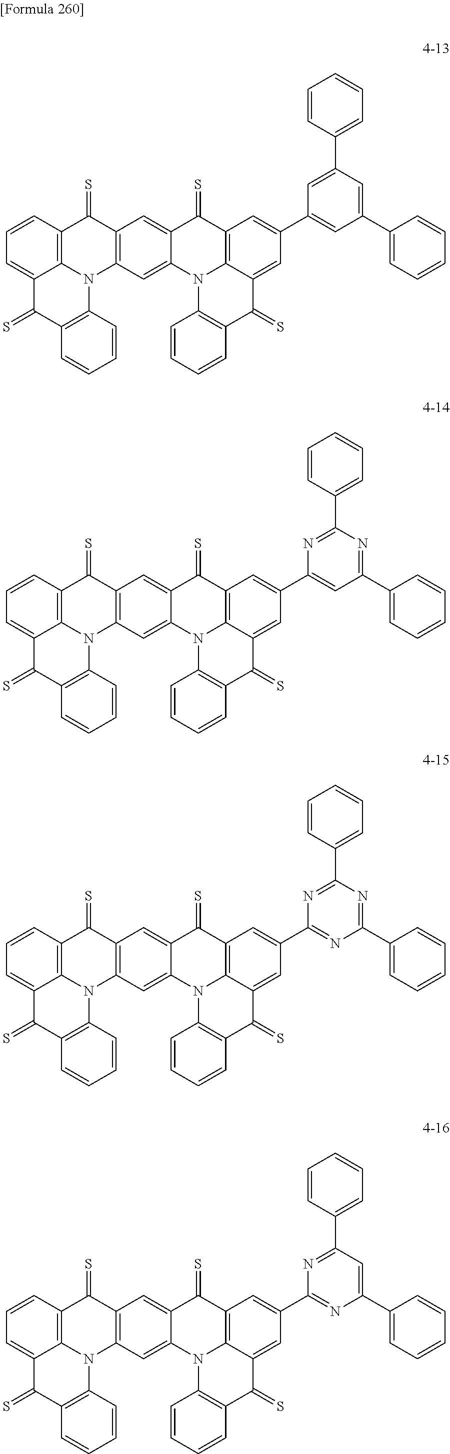 [SMILES: S=c1c2ccccc2n2c3cc4c(cc3c(=S)c3cccc1c32)c(=S)c1cc(-c2cc(-c3ccccc3)cc(-c3ccccc3)c2)cc2c(=S)c3ccccc3n4c21 ; S=c1c2ccccc2n2c3cc4c(cc3c(=S)c3cccc1c32)c(=S)c1cc(-c2cc(-c3ccccc3)nc(-c3ccccc3)n2)cc2c(=S)c3ccccc3n4c21 ; S=c1c2ccccc2n2c3cc4c(cc3c(=S)c3cccc1c32)c(=S)c1cc(-c2nc(-c3ccccc3)nc(-c3ccccc3)n2)cc2c(=S)c3ccccc3n4c21 ; S=c1c2ccccc2n2c3cc4c(cc3c(=S)c3cccc1c32)c(=S)c1cc(-c2nc(-c3ccccc3)cc(-c3ccccc3)n2)cc2c(=S)c3ccccc3n4c21]

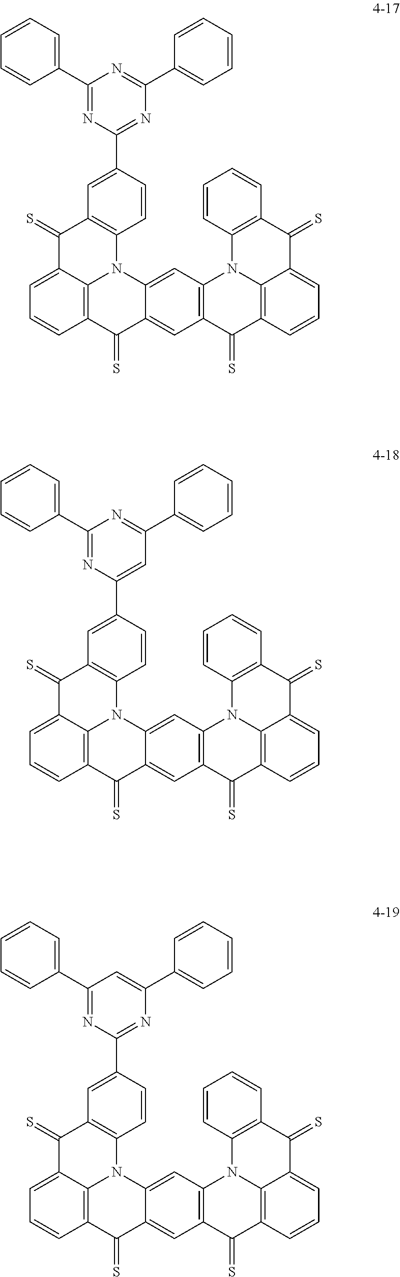 [SMILES: S=c1c2ccccc2n2c3cc4c(cc3c(=S)c3cccc1c32)c(=S)c1cccc2c(=S)c3cc(-c5nc(-c6ccccc6)nc(-c6ccccc6)n5)ccc3n4c21 ; S=c1c2ccccc2n2c3cc4c(cc3c(=S)c3cccc1c32)c(=S)c1cccc2c(=S)c3cc(-c5cc(-c6ccccc6)nc(-c6ccccc6)n5)ccc3n4c21 ; S=c1c2ccccc2n2c3cc4c(cc3c(=S)c3cccc1c32)c(=S)c1cccc2c(=S)c3cc(-c5nc(-c6ccccc6)cc(-c6ccccc6)n5)ccc3n4c21]

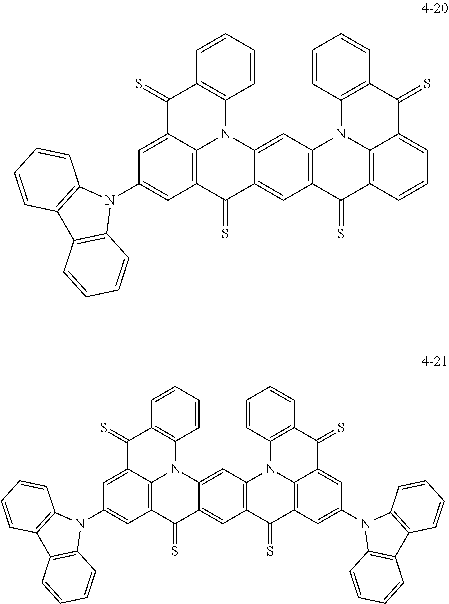 [SMILES: S=c1c2ccccc2n2c3cc4c(cc3c(=S)c3cccc1c32)c(=S)c1cc(-n2c3ccccc3c3ccccc32)cc2c(=S)c3ccccc3n4c21 ; S=c1c2ccccc2n2c3cc4c(cc3c(=S)c3cc(-n5c6ccccc6c6ccccc65)cc1c32)c(=S)c1cc(-n2c3ccccc3c3ccccc32)cc2c(=S)c3ccccc3n4c21]

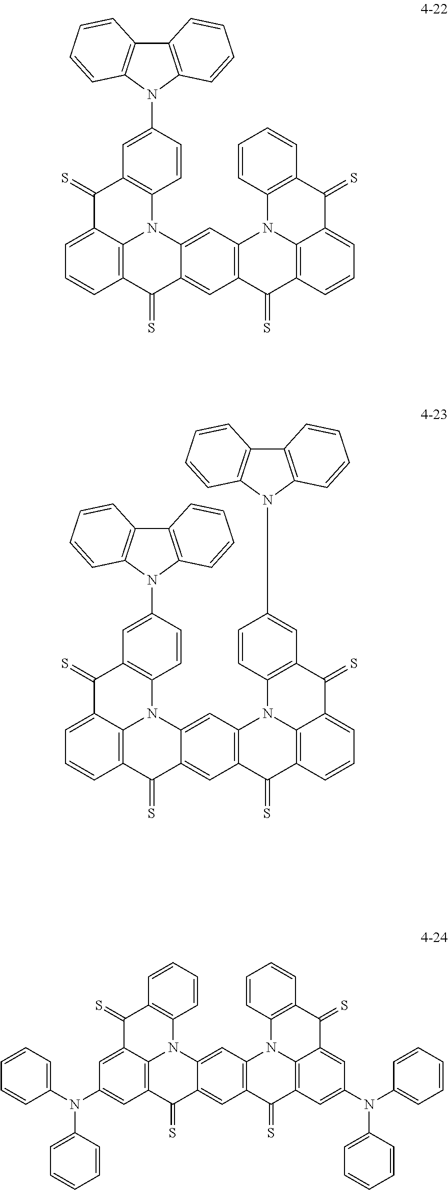 [SMILES: S=c1c2ccccc2n2c3cc4c(cc3c(=S)c3cccc1c32)c(=S)c1cccc2c(=S)c3cc(-n5c6ccccc6c6ccccc65)ccc3n4c21 ; S=c1c2cc(-n3c4ccccc4c4ccccc43)ccc2n2c3cc4c(cc3c(=S)c3cccc1c32)c(=S)c1cccc2c(=S)c3cc(-n5c6ccccc6c6ccccc65)ccc3n4c21 ; S=c1c2ccccc2n2c3cc4c(cc3c(=S)c3cc(N(c5ccccc5)c5ccccc5)cc1c32)c(=S)c1cc(N(c2ccccc2)c2ccccc2)cc2c(=S)c3ccccc3n4c21]

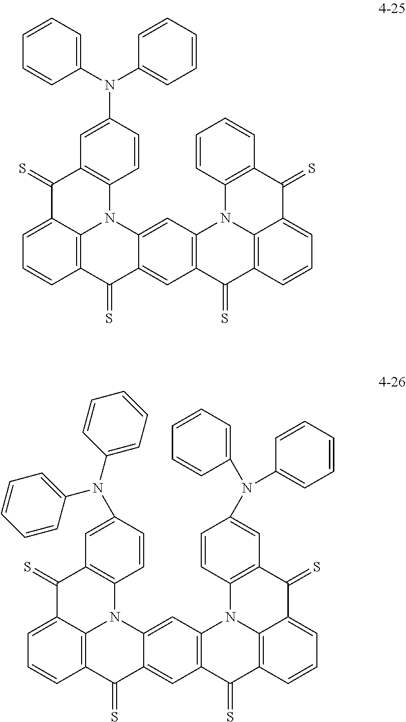 [SMILES: S=c1c2ccccc2n2c3cc4c(cc3c(=S)c3cccc1c32)c(=S)c1cccc2c(=S)c3cc(N(c5ccccc5)c5ccccc5)ccc3n4c21 ; S=c1c2cc(N(c3ccccc3)c3ccccc3)ccc2n2c3cc4c(cc3c(=S)c3cccc1c32)c(=S)c1cccc2c(=S)c3cc(N(c5ccccc5)c5ccccc5)ccc3n4c21]

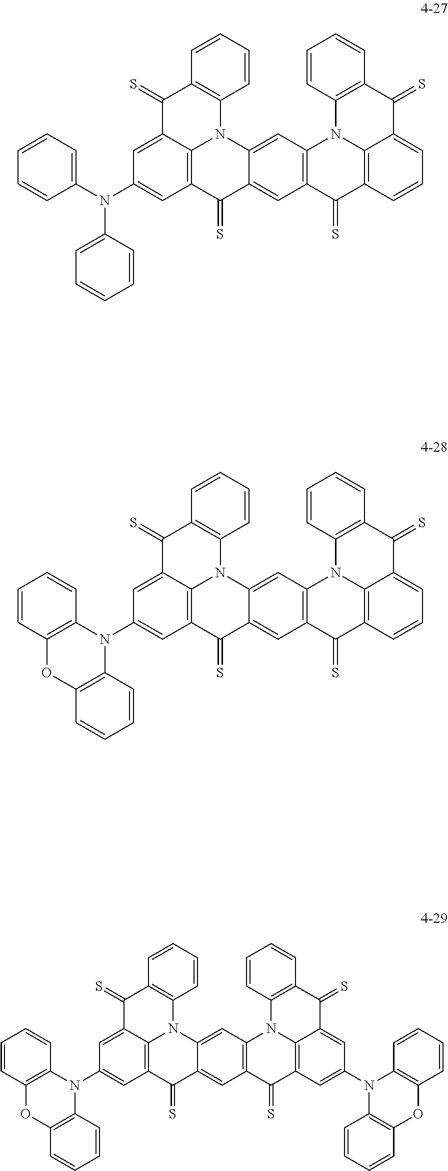 [SMILES: S=c1c2ccccc2n2c3cc4c(cc3c(=S)c3cccc1c32)c(=S)c1cc(N(c2ccccc2)c2ccccc2)cc2c(=S)c3ccccc3n4c21 ; S=c1c2ccccc2n2c3cc4c(cc3c(=S)c3cccc1c32)c(=S)c1cc(N2c3ccccc3Oc3ccccc32)cc2c(=S)c3ccccc3n4c21 ; S=c1c2ccccc2n2c3cc4c(cc3c(=S)c3cc(N5c6ccccc6Oc6ccccc65)cc1c32)c(=S)c1cc(N2c3ccccc3Oc3ccccc32)cc2c(=S)c3ccccc3n4c21]

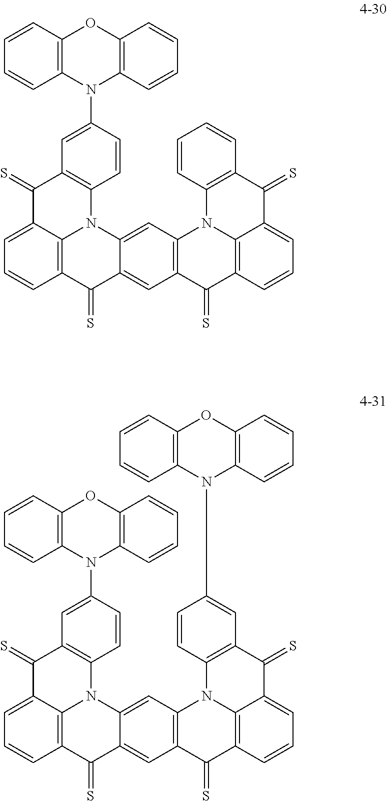 [SMILES: S=c1c2ccccc2n2c3cc4c(cc3c(=S)c3cccc1c32)c(=S)c1cccc2c(=S)c3cc(N5c6ccccc6Oc6ccccc65)ccc3n4c21 ; S=c1c2cc(N3c4ccccc4Oc4ccccc43)ccc2n2c3cc4c(cc3c(=S)c3cccc1c32)c(=S)c1cccc2c(=S)c3cc(N5c6ccccc6Oc6ccccc65)ccc3n4c21]

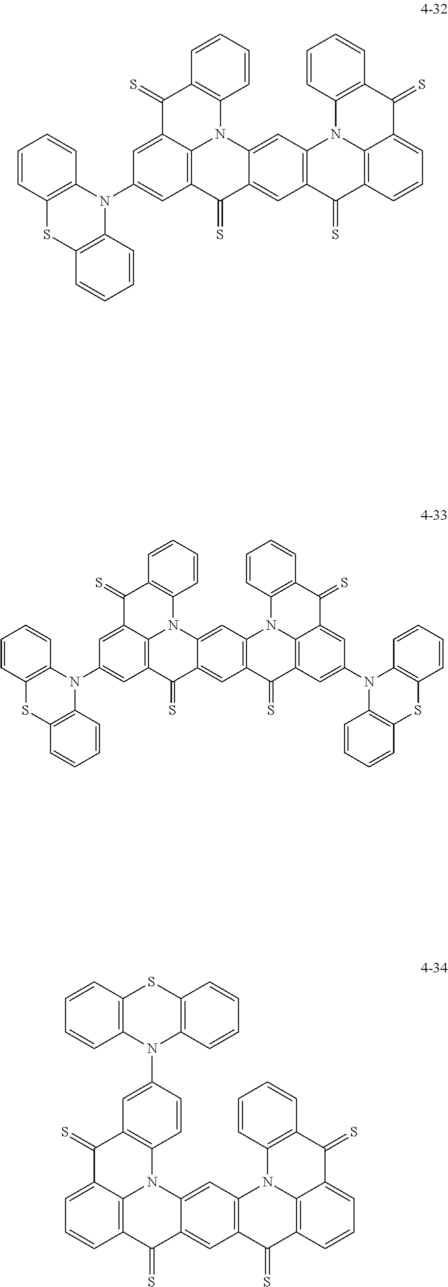 [SMILES: S=c1c2ccccc2n2c3cc4c(cc3c(=S)c3cccc1c32)c(=S)c1cc(N2c3ccccc3Sc3ccccc32)cc2c(=S)c3ccccc3n4c21 ; S=c1c2ccccc2n2c3cc4c(cc3c(=S)c3cc(N5c6ccccc6Sc6ccccc65)cc1c32)c(=S)c1cc(N2c3ccccc3Sc3ccccc32)cc2c(=S)c3ccccc3n4c21 ; S=c1c2ccccc2n2c3cc4c(cc3c(=S)c3cccc1c32)c(=S)c1cccc2c(=S)c3cc(N5c6ccccc6Sc6ccccc65)ccc3n4c21]

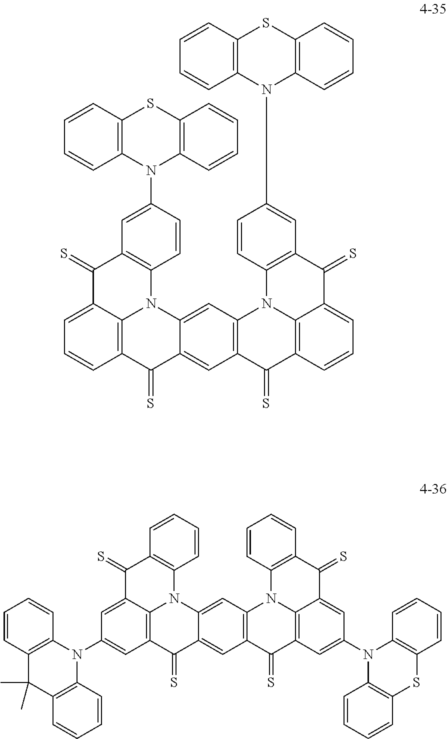 [SMILES: S=c1c2cc(N3c4ccccc4Sc4ccccc43)ccc2n2c3cc4c(cc3c(=S)c3cccc1c32)c(=S)c1cccc2c(=S)c3cc(N5c6ccccc6Sc6ccccc65)ccc3n4c21 ; CC1(C)c2ccccc2N(c2cc3c(=S)c4ccccc4n4c5cc6c(cc5c(=S)c(c2)c34)c(=S)c2cc(N3c4ccccc4Sc4ccccc43)cc3c(=S)c4ccccc4n6c32)c2ccccc21]

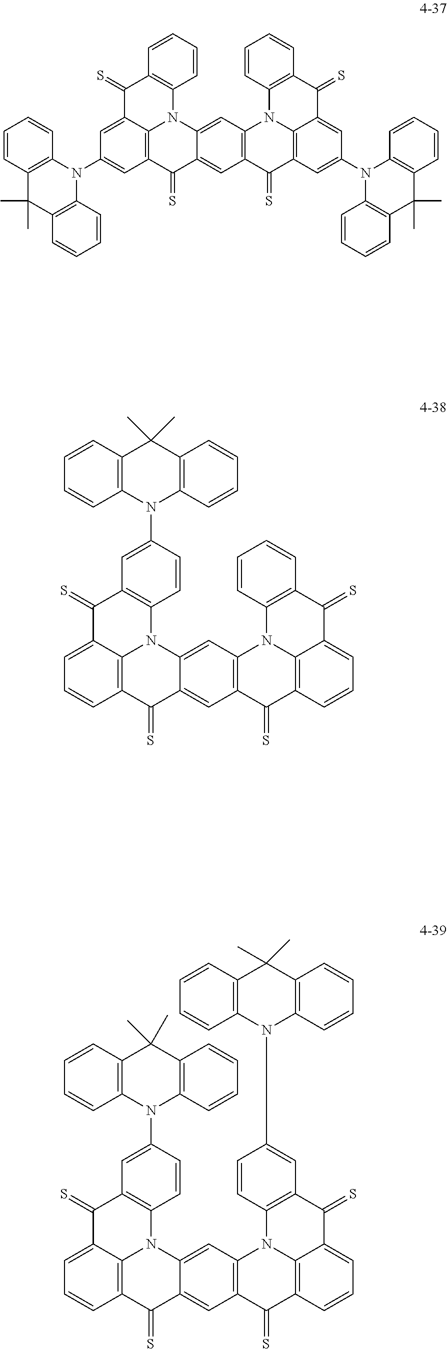

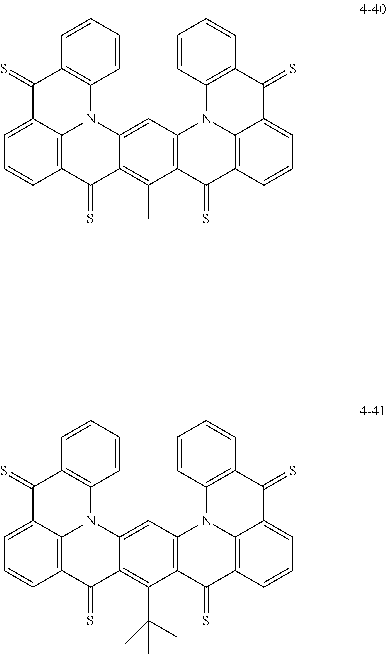 [SMILES: Cc1c2c(=S)c3cccc4c(=S)c5ccccc5n(c2cc2c1c(=S)c1cccc5c(=S)c6ccccc6n2c51)c43 ; CC(C)(C)c1c2c(=S)c3cccc4c(=S)c5ccccc5n(c2cc2c1c(=S)c1cccc5c(=S)c6ccccc6n2c51)c43]

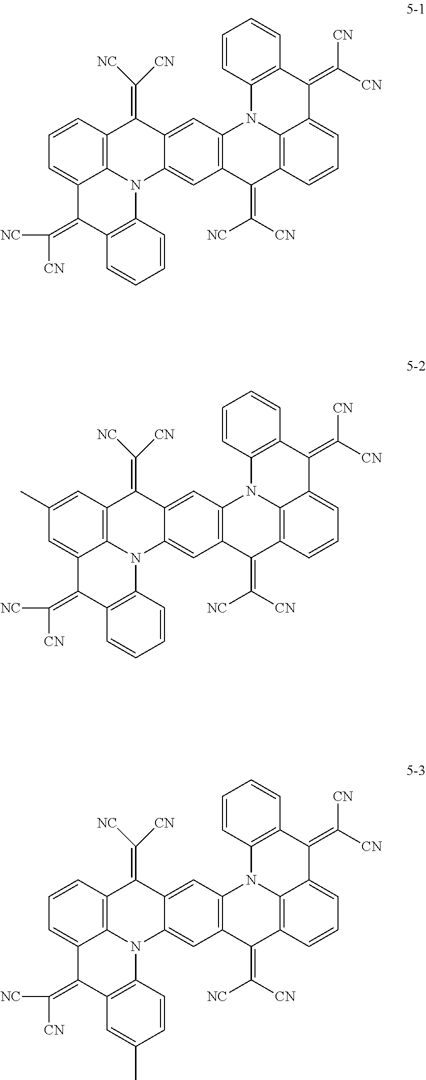 [SMILES: N#CC(C#N)=c1c2ccccc2n2c3cc4c(=C(C#N)C#N)c5cccc6c(=C(C#N)C#N)c7ccccc7n(c4cc3c(=C(C#N)C#N)c3cccc1c32)c65 ; Cc1cc2c(=C(C#N)C#N)c3ccccc3n3c4cc5c(=C(C#N)C#N)c6cccc7c(=C(C#N)C#N)c8ccccc8n(c5cc4c(=C(C#N)C#N)c(c1)c23)c76 ; Cc1ccc2c(c1)c(=C(C#N)C#N)c1cccc3c(=C(C#N)C#N)c4cc5c(cc4n2c13)c(=C(C#N)C#N)c1cccc2c(=C(C#N)C#N)c3ccccc3n5c21]

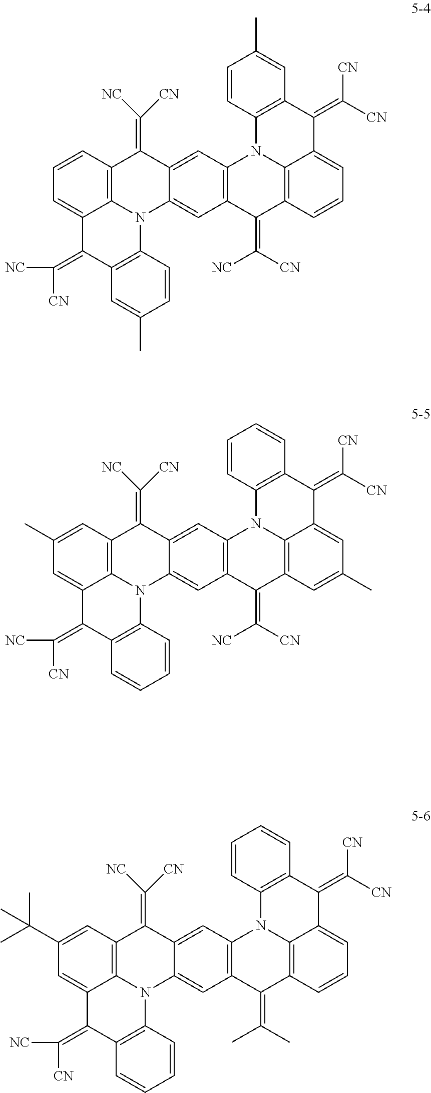 [SMILES: Cc1ccc2c(c1)c(=C(C#N)C#N)c1cccc3c(=C(C#N)C#N)c4cc5c(cc4n2c13)c(=C(C#N)C#N)c1cccc2c(=C(C#N)C#N)c3cc(C)ccc3n5c21 ; Cc1cc2c(=C(C#N)C#N)c3ccccc3n3c4cc5c(=C(C#N)C#N)c6cc(C)cc7c(=C(C#N)C#N)c8ccccc8n(c5cc4c(=C(C#N)C#N)c(c1)c23)c76 ; CC(C)=c1c2cc3c(cc2n2c4ccccc4c(=C(C#N)C#N)c4cccc1c42)c(=C(C#N)C#N)c1cc(C(C)(C)C)cc2c(=C(C#N)C#N)c4ccccc4n3c21]

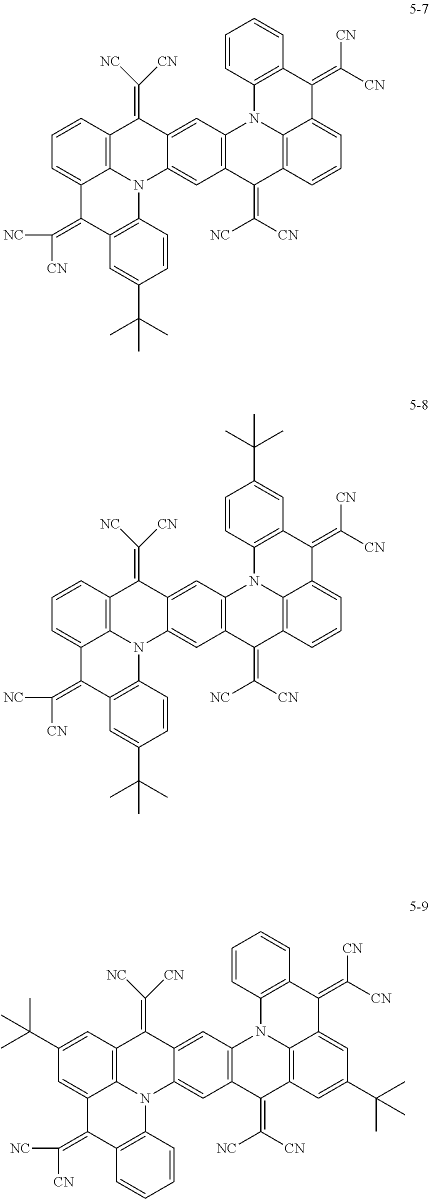 [SMILES: CC(C)(C)c1ccc2c(c1)c(=C(C#N)C#N)c1cccc3c(=C(C#N)C#N)c4cc5c(cc4n2c13)c(=C(C#N)C#N)c1cccc2c(=C(C#N)C#N)c3ccccc3n5c21 ; CC(C)(C)c1ccc2c(c1)c(=C(C#N)C#N)c1cccc3c(=C(C#N)C#N)c4cc5c(cc4n2c13)c(=C(C#N)C#N)c1cccc2c(=C(C#N)C#N)c3cc(C(C)(C)C)ccc3n5c21 ; CC(C)(C)c1cc2c(=C(C#N)C#N)c3ccccc3n3c4cc5c(=C(C#N)C#N)c6cc(C(C)(C)C)cc7c(=C(C#N)C#N)c8ccccc8n(c5cc4c(=C(C#N)C#N)c(c1)c23)c76]

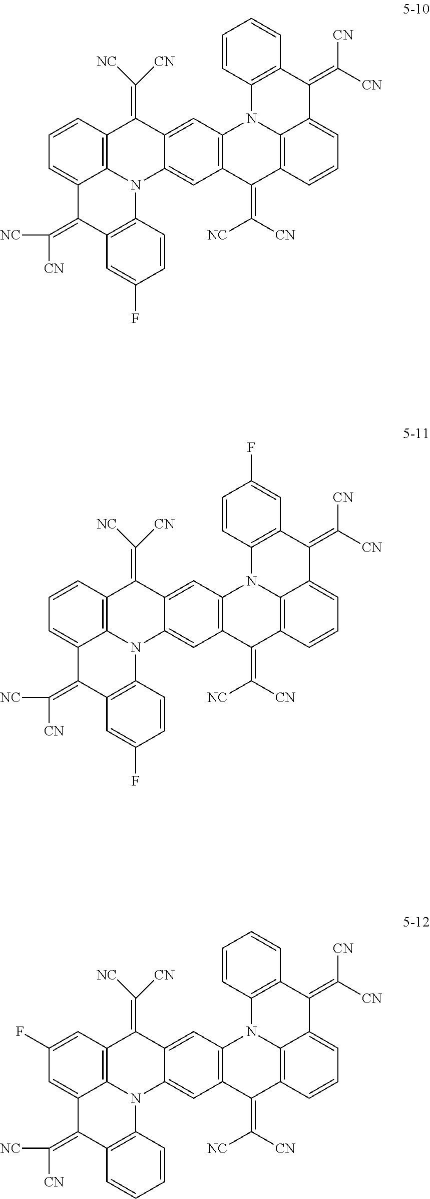 [SMILES: N#CC(C#N)=c1c2ccccc2n2c3cc4c(=C(C#N)C#N)c5cccc6c(=C(C#N)C#N)c7cc(F)ccc7n(c4cc3c(=C(C#N)C#N)c3cccc1c32)c65 ; N#CC(C#N)=c1c2cc(F)ccc2n2c3cc4c(=C(C#N)C#N)c5cccc6c(=C(C#N)C#N)c7cc(F)ccc7n(c4cc3c(=C(C#N)C#N)c3cccc1c32)c65 ; N#CC(C#N)=c1c2ccccc2n2c3cc4c(=C(C#N)C#N)c5cc(F)cc6c(=C(C#N)C#N)c7ccccc7n(c4cc3c(=C(C#N)C#N)c3cccc1c32)c65]

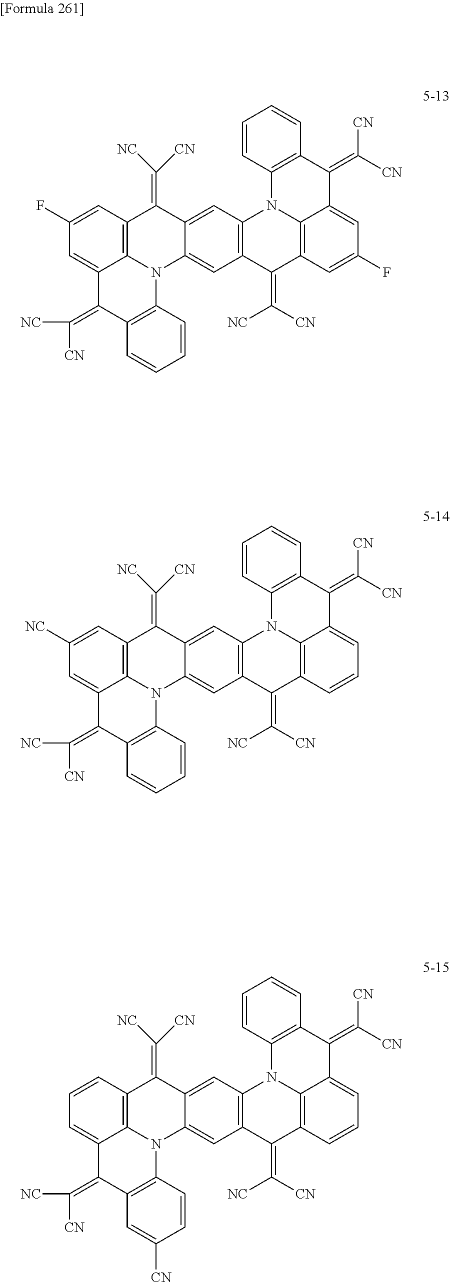 [SMILES: N#CC(C#N)=c1c2ccccc2n2c3cc4c(=C(C#N)C#N)c5cc(F)cc6c(=C(C#N)C#N)c7ccccc7n(c4cc3c(=C(C#N)C#N)c3cc(F)cc1c32)c65 ; N#CC(C#N)=c1c2ccccc2n2c3cc4c(=C(C#N)C#N)c5cc(C#N)cc6c(=C(C#N)C#N)c7ccccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(C#N)ccc7n(c4cc3c(=C(C#N)C#N)c3cccc1c32)c65]

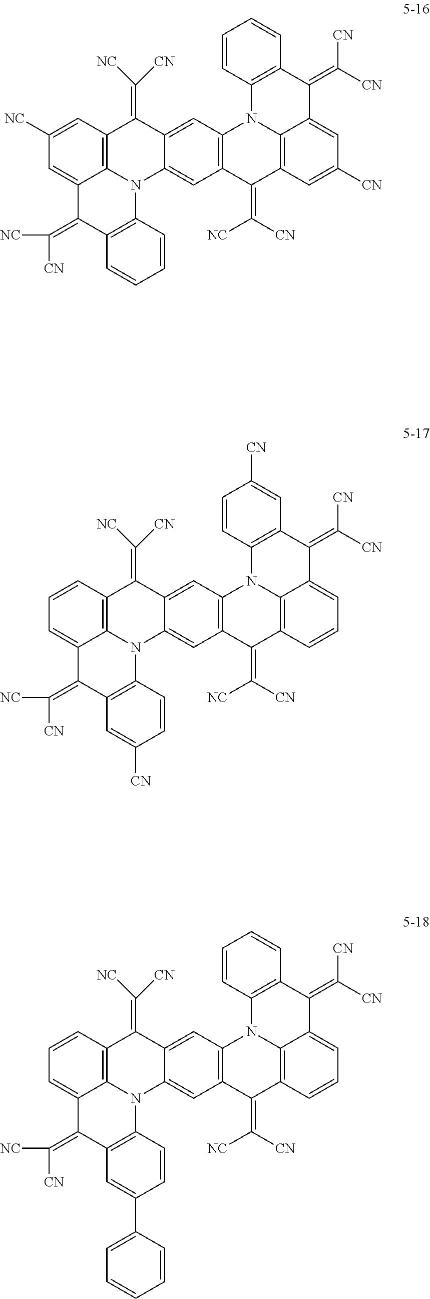 [SMILES: N#CC(C#N)=c1c2ccccc2n2c3cc4c(=C(C#N)C#N)c5cc(C#N)cc6c(=C(C#N)C#N)c7ccccc7n(c4cc3c(=C(C#N)C#N)c3cc(C#N)cc1c32)c65 ; N#CC(C#N)=c1c2cc(C#N)ccc2n2c3cc4c(=C(C#N)C#N)c5cccc6c(=C(C#N)C#N)c7cc(C#N)ccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(-c8ccccc8)ccc7n(c4cc3c(=C(C#N)C#N)c3cccc1c32)c65]

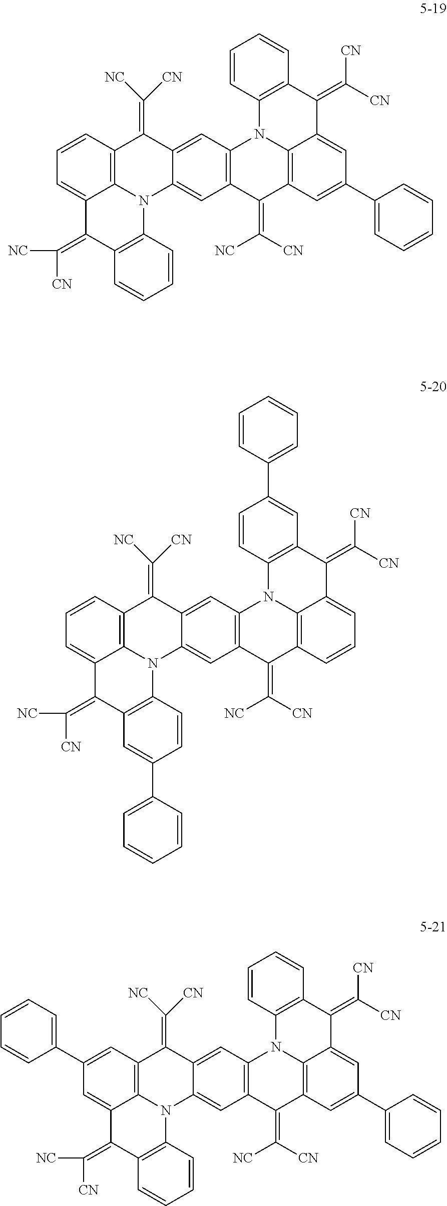 [SMILES: N#CC(C#N)=c1c2ccccc2n2c3cc4c(=C(C#N)C#N)c5cc(-c6ccccc6)cc6c(=C(C#N)C#N)c7ccccc7n(c4cc3c(=C(C#N)C#N)c3cccc1c32)c65 ; N#CC(C#N)=c1c2cc(-c3ccccc3)ccc2n2c3cc4c(=C(C#N)C#N)c5cccc6c(=C(C#N)C#N)c7cc(-c8ccccc8)ccc7n(c4cc3c(=C(C#N)C#N)c3cccc1c32)c65 ; N#CC(C#N)=c1c2ccccc2n2c3cc4c(=C(C#N)C#N)c5cc(-c6ccccc6)cc6c(=C(C#N)C#N)c7ccccc7n(c4cc3c(=C(C#N)C#N)c3cc(-c4ccccc4)cc1c32)c65]

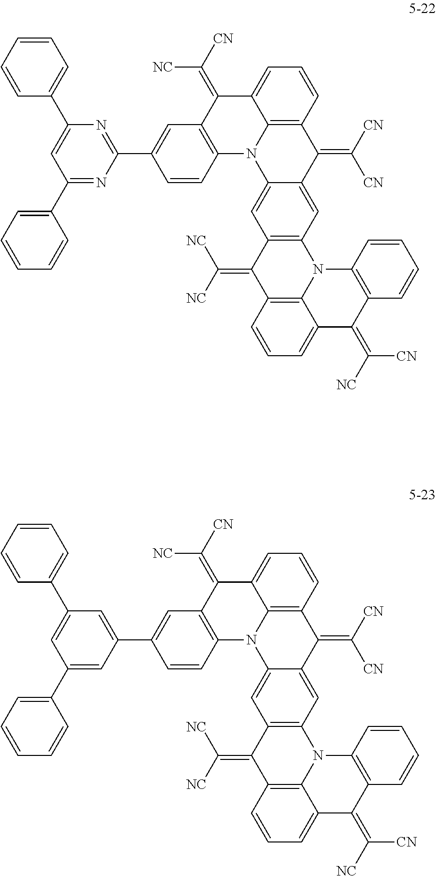 [SMILES: N#CC(C#N)=c1c2ccccc2n2c3cc4c(=C(C#N)C#N)c5cccc6c(=C(C#N)C#N)c7cc(-c8nc(-c9ccccc9)cc(-c9ccccc9)n8)ccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(-c8cc(-c9ccccc9)cc(-c9ccccc9)c8)ccc7n(c4cc3c(=C(C#N)C#N)c3cccc1c32)c65]

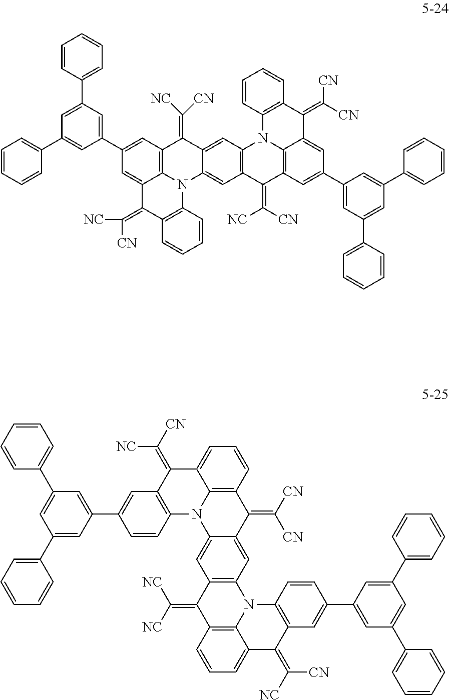 [SMILES: N#CC(C#N)=c1c2ccccc2n2c3cc4c(=C(C#N)C#N)c5cc(-c6cc(-c7ccccc7)cc(-c7ccccc7)c6)cc6c(=C(C#N)C#N)c7ccccc7n(c4cc3c(=C(C#N)C#N)c3cc(-c4cc(-c7ccccc7)cc(-c7ccccc7)c4)cc1c32)c65 ; N#CC(C#N)=c1c2cc(-c3cc(-c4ccccc4)cc(-c4ccccc4)c3)ccc2n2c3cc4c(=C(C#N)C#N)c5cccc6c(=C(C#N)C#N)c7cc(-c8cc(-c9ccccc9)cc(-c9ccccc9)c8)ccc7n(c4cc3c(=C(C#N)C#N)c3cccc1c32)c65]

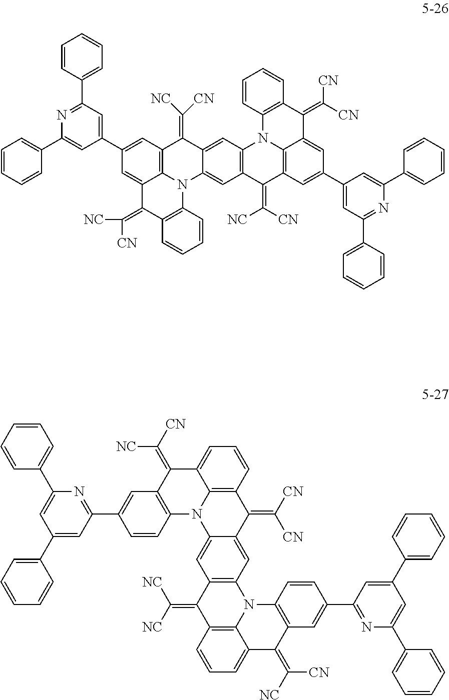 [SMILES: N#CC(C#N)=c1c2ccccc2n2c3cc4c(=C(C#N)C#N)c5cc(-c6cc(-c7ccccc7)nc(-c7ccccc7)c6)cc6c(=C(C#N)C#N)c7ccccc7n(c4cc3c(=C(C#N)C#N)c3cc(-c4cc(-c7ccccc7)nc(-c7ccccc7)c4)cc1c32)c65 ; N#CC(C#N)=c1c2cc(-c3cc(-c4ccccc4)cc(-c4ccccc4)n3)ccc2n2c3cc4c(=C(C#N)C#N)c5cccc6c(=C(C#N)C#N)c7cc(-c8cc(-c9ccccc9)cc(-c9ccccc9)n8)ccc7n(c4cc3c(=C(C#N)C#N)c3cccc1c32)c65]

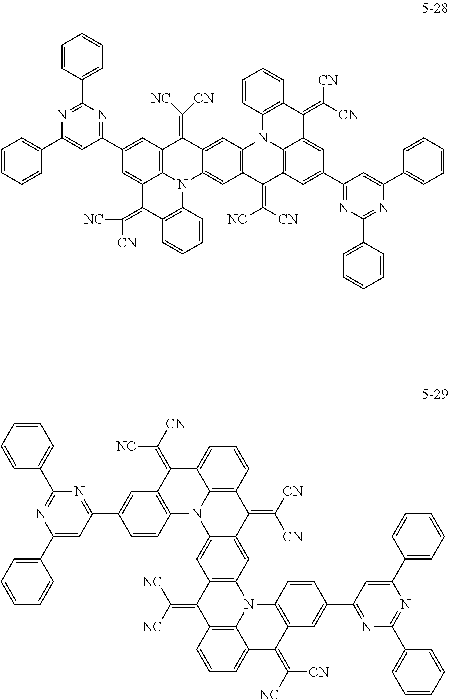 [SMILES: N#CC(C#N)=c1c2ccccc2n2c3cc4c(=C(C#N)C#N)c5cc(-c6cc(-c7ccccc7)nc(-c7ccccc7)n6)cc6c(=C(C#N)C#N)c7ccccc7n(c4cc3c(=C(C#N)C#N)c3cc(-c4cc(-c7ccccc7)nc(-c7ccccc7)n4)cc1c32)c65 ; N#CC(C#N)=c1c2cc(-c3cc(-c4ccccc4)nc(-c4ccccc4)n3)ccc2n2c3cc4c(=C(C#N)C#N)c5cccc6c(=C(C#N)C#N)c7cc(-c8cc(-c9ccccc9)nc(-c9ccccc9)n8)ccc7n(c4cc3c(=C(C#N)C#N)c3cccc1c32)c65]

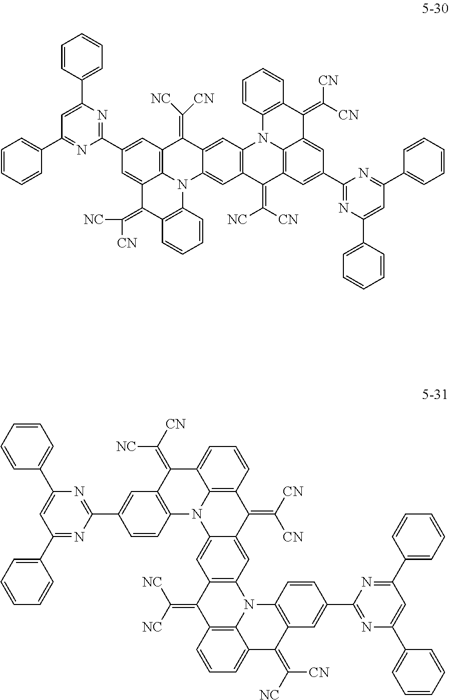 [SMILES: N#CC(C#N)=c1c2ccccc2n2c3cc4c(=C(C#N)C#N)c5cc(-c6nc(-c7ccccc7)cc(-c7ccccc7)n6)cc6c(=C(C#N)C#N)c7ccccc7n(c4cc3c(=C(C#N)C#N)c3cc(-c4nc(-c7ccccc7)cc(-c7ccccc7)n4)cc1c32)c65 ; N#CC(C#N)=c1c2cc(-c3nc(-c4ccccc4)cc(-c4ccccc4)n3)ccc2n2c3cc4c(=C(C#N)C#N)c5cccc6c(=C(C#N)C#N)c7cc(-c8nc(-c9ccccc9)cc(-c9ccccc9)n8)ccc7n(c4cc3c(=C(C#N)C#N)c3cccc1c32)c65]

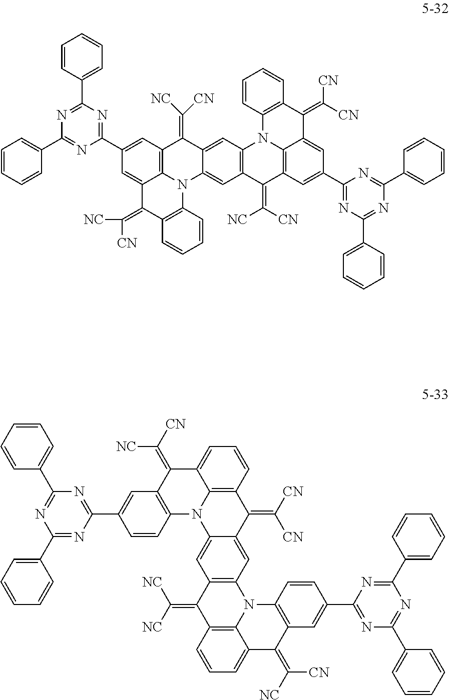 [SMILES: N#CC(C#N)=c1c2ccccc2n2c3cc4c(=C(C#N)C#N)c5cc(-c6nc(-c7ccccc7)nc(-c7ccccc7)n6)cc6c(=C(C#N)C#N)c7ccccc7n(c4cc3c(=C(C#N)C#N)c3cc(-c4nc(-c7ccccc7)nc(-c7ccccc7)n4)cc1c32)c65 ; N#CC(C#N)=c1c2cc(-c3nc(-c4ccccc4)nc(-c4ccccc4)n3)ccc2n2c3cc4c(=C(C#N)C#N)c5cccc6c(=C(C#N)C#N)c7cc(-c8nc(-c9ccccc9)nc(-c9ccccc9)n8)ccc7n(c4cc3c(=C(C#N)C#N)c3cccc1c32)c65]

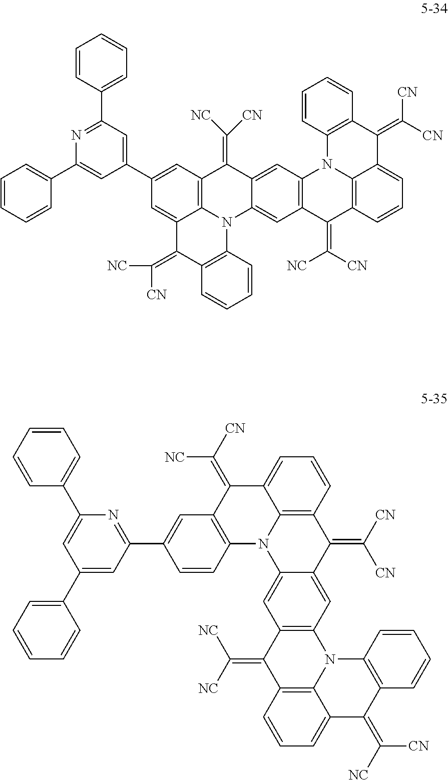 [SMILES: N#CC(C#N)=c1c2ccccc2n2c3cc4c(=C(C#N)C#N)c5cc(-c6cc(-c7ccccc7)nc(-c7ccccc7)c6)cc6c(=C(C#N)C#N)c7ccccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(-c8cc(-c9ccccc9)cc(-c9ccccc9)n8)ccc7n(c4cc3c(=C(C#N)C#N)c3cccc1c32)c65]

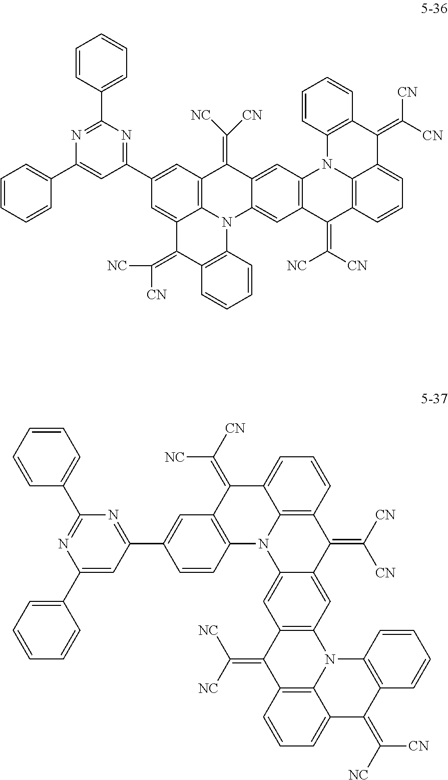 [SMILES: N#CC(C#N)=c1c2ccccc2n2c3cc4c(=C(C#N)C#N)c5cc(-c6cc(-c7ccccc7)nc(-c7ccccc7)n6)cc6c(=C(C#N)C#N)c7ccccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(-c8cc(-c9ccccc9)nc(-c9ccccc9)n8)ccc7n(c4cc3c(=C(C#N)C#N)c3cccc1c32)c65]

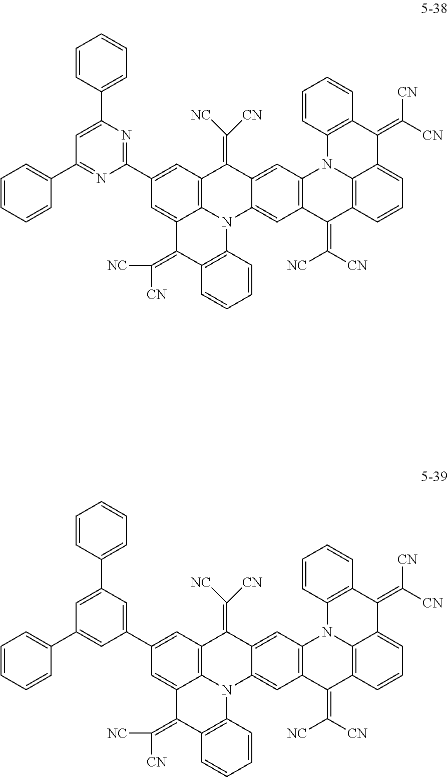 [SMILES: N#CC(C#N)=c1c2ccccc2n2c3cc4c(=C(C#N)C#N)c5cc(-c6nc(-c7ccccc7)cc(-c7ccccc7)n6)cc6c(=C(C#N)C#N)c7ccccc7n(c4cc3c(=C(C#N)C#N)c3cccc1c32)c65 ; N#CC(C#N)=c1c2ccccc2n2c3cc4c(=C(C#N)C#N)c5cc(-c6cc(-c7ccccc7)cc(-c7ccccc7)c6)cc6c(=C(C#N)C#N)c7ccccc7n(c4cc3c(=C(C#N)C#N)c3cccc1c32)c65]

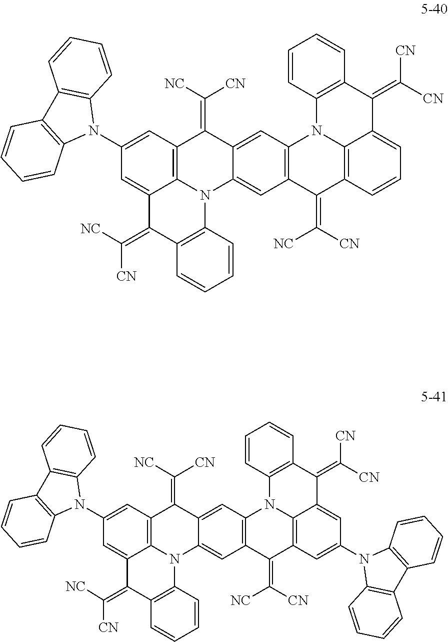 [SMILES: N#CC(C#N)=c1c2ccccc2n2c3cc4c(=C(C#N)C#N)c5cc(-n6c7ccccc7c7ccccc76)cc6c(=C(C#N)C#N)c7ccccc7n(c4cc3c(=C(C#N)C#N)c3cccc1c32)c65 ; N#CC(C#N)=c1c2ccccc2n2c3cc4c(=C(C#N)C#N)c5cc(-n6c7ccccc7c7ccccc76)cc6c(=C(C#N)C#N)c7ccccc7n(c4cc3c(=C(C#N)C#N)c3cc(-n4c7ccccc7c7ccccc74)cc1c32)c65]

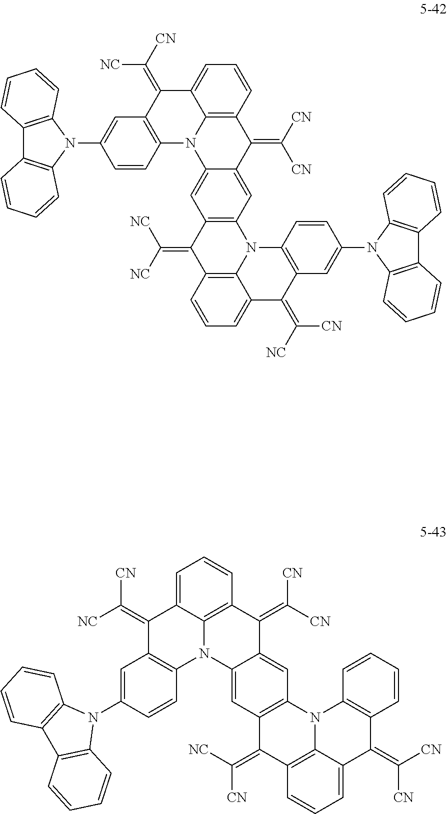 [SMILES: N#CC(C#N)=c1c2cc(-n3c4ccccc4c4ccccc43)ccc2n2c3cc4c(=C(C#N)C#N)c5cccc6c(=C(C#N)C#N)c7cc(-n8c9ccccc9c9ccccc98)ccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(-n8c9ccccc9c9ccccc98)ccc7n(c4cc3c(=C(C#N)C#N)c3cccc1c32)c65]

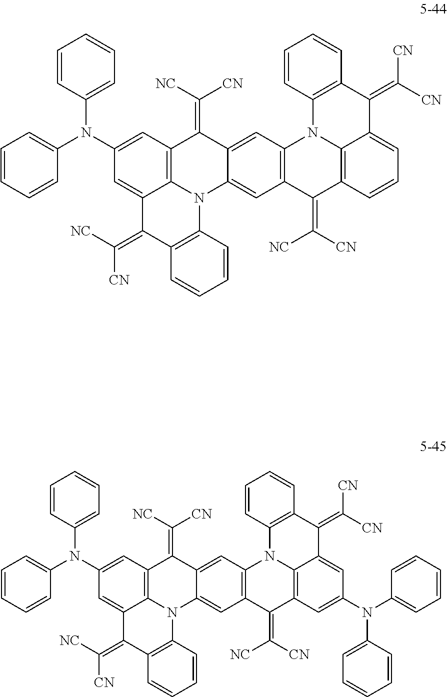 [SMILES: N#CC(C#N)=c1c2ccccc2n2c3cc4c(=C(C#N)C#N)c5cc(N(c6ccccc6)c6ccccc6)cc6c(=C(C#N)C#N)c7ccccc7n(c4cc3c(=C(C#N)C#N)c3cccc1c32)c65 ; N#CC(C#N)=c1c2ccccc2n2c3cc4c(=C(C#N)C#N)c5cc(N(c6ccccc6)c6ccccc6)cc6c(=C(C#N)C#N)c7ccccc7n(c4cc3c(=C(C#N)C#N)c3cc(N(c4ccccc4)c4ccccc4)cc1c32)c65]

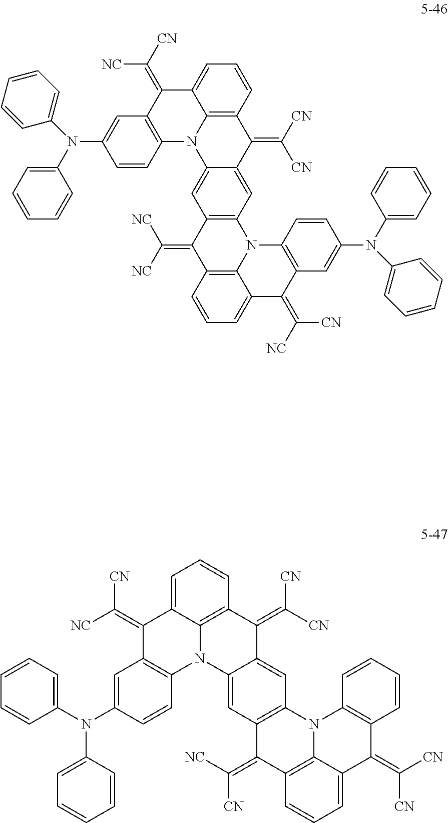 [SMILES: N#CC(C#N)=c1c2cc(N(c3ccccc3)c3ccccc3)ccc2n2c3cc4c(=C(C#N)C#N)c5cccc6c(=C(C#N)C#N)c7cc(N(c8ccccc8)c8ccccc8)ccc7n(c4cc3c(=C(C#N)C#N)c3cccc1c32)c65 ; N#CC(C#N)=c1c2ccccc2n2c3cc4c(=C(C#N)C#N)c5cccc6c(=C(C#N)C#N)c7cc(N(c8ccccc8)c8ccccc8)ccc7n(c4cc3c(=C(C#N)C#N)c3cccc1c32)c65]

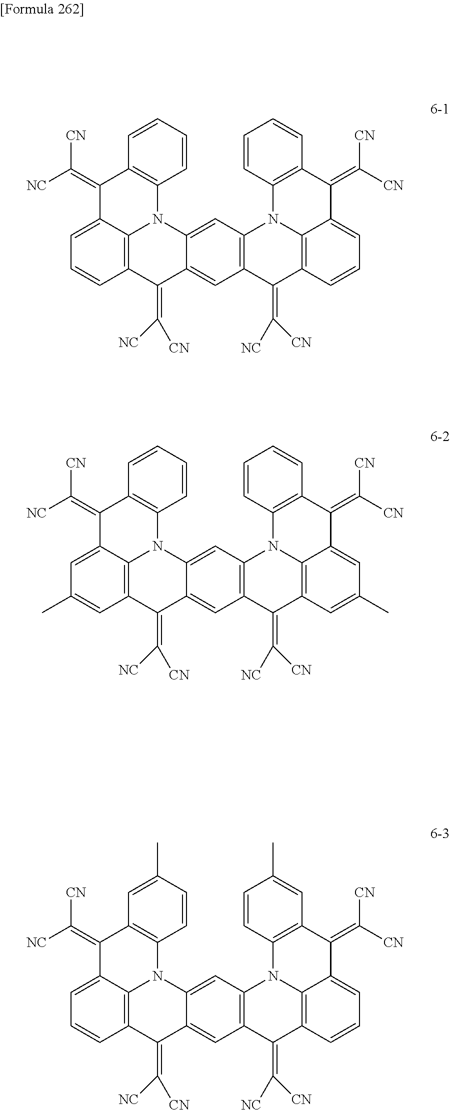 [SMILES: N#CC(C#N)=c1c2ccccc2n2c3cc4c(cc3c(=C(C#N)C#N)c3cccc1c32)c(=C(C#N)C#N)c1cccc2c(=C(C#N)C#N)c3ccccc3n4c21 ; Cc1cc2c(=C(C#N)C#N)c3ccccc3n3c4cc5c(cc4c(=C(C#N)C#N)c(c1)c23)c(=C(C#N)C#N)c1cc(C)cc2c(=C(C#N)C#N)c3ccccc3n5c21 ; Cc1ccc2c(c1)c(=C(C#N)C#N)c1cccc3c(=C(C#N)C#N)c4cc5c(=C(C#N)C#N)c6cccc7c(=C(C#N)C#N)c8cc(C)ccc8n(c5cc4n2c13)c76]

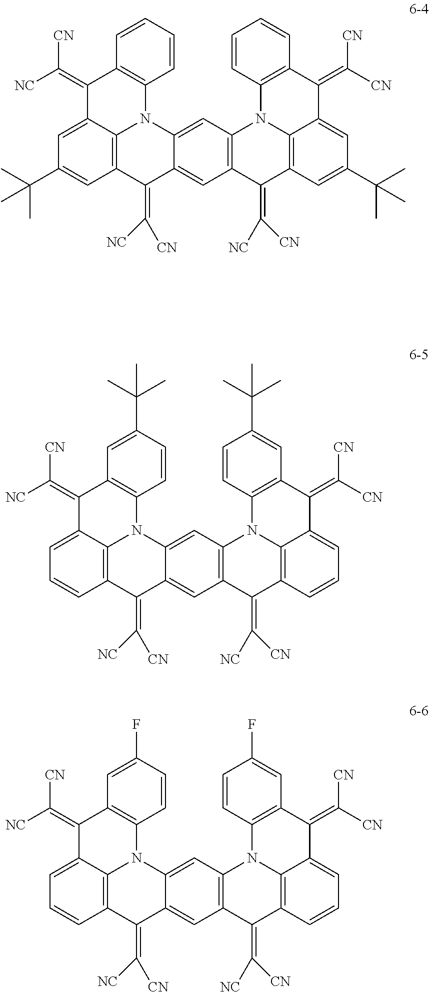 [SMILES: CC(C)(C)c1cc2c(=C(C#N)C#N)c3ccccc3n3c4cc5c(cc4c(=C(C#N)C#N)c(c1)c23)c(=C(C#N)C#N)c1cc(C(C)(C)C)cc2c(=C(C#N)C#N)c3ccccc3n5c21 ; CC(C)(C)c1ccc2c(c1)c(=C(C#N)C#N)c1cccc3c(=C(C#N)C#N)c4cc5c(=C(C#N)C#N)c6cccc7c(=C(C#N)C#N)c8cc(C(C)(C)C)ccc8n(c5cc4n2c13)c76 ; N#CC(C#N)=c1c2cc(F)ccc2n2c3cc4c(cc3c(=C(C#N)C#N)c3cccc1c32)c(=C(C#N)C#N)c1cccc2c(=C(C#N)C#N)c3cc(F)ccc3n4c21]

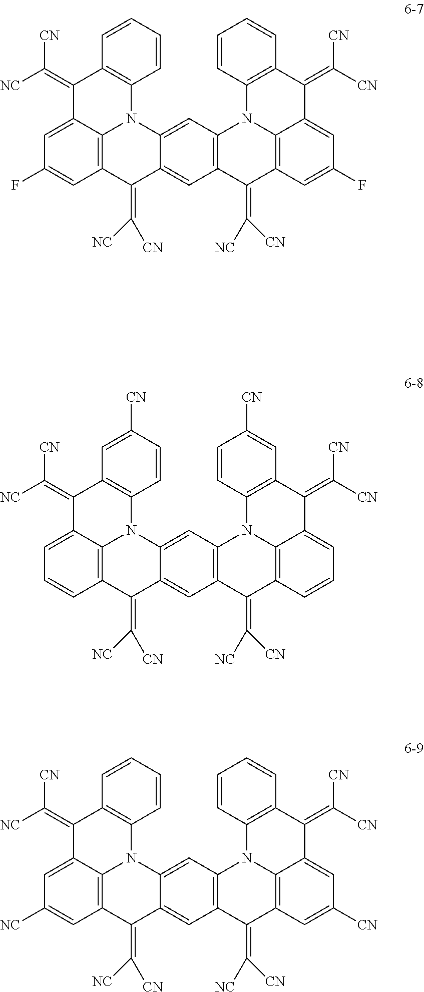 [SMILES: N#CC(C#N)=c1c2ccccc2n2c3cc4c(cc3c(=C(C#N)C#N)c3cc(F)cc1c32)c(=C(C#N)C#N)c1cc(F)cc2c(=C(C#N)C#N)c3ccccc3n4c21 ; N#CC(C#N)=c1c2cc(C#N)ccc2n2c3cc4c(cc3c(=C(C#N)C#N)c3cccc1c32)c(=C(C#N)C#N)c1cccc2c(=C(C#N)C#N)c3cc(C#N)ccc3n4c21 ; N#CC(C#N)=c1c2ccccc2n2c3cc4c(cc3c(=C(C#N)C#N)c3cc(C#N)cc1c32)c(=C(C#N)C#N)c1cc(C#N)cc2c(=C(C#N)C#N)c3ccccc3n4c21]

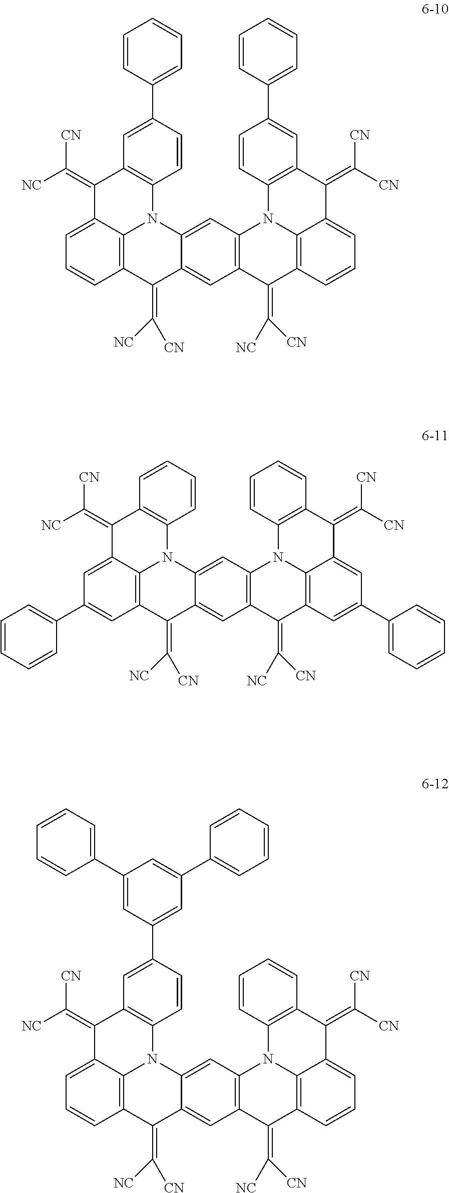 [SMILES: N#CC(C#N)=c1c2cc(-c3ccccc3)ccc2n2c3cc4c(cc3c(=C(C#N)C#N)c3cccc1c32)c(=C(C#N)C#N)c1cccc2c(=C(C#N)C#N)c3cc(-c5ccccc5)ccc3n4c21 ; N#CC(C#N)=c1c2ccccc2n2c3cc4c(cc3c(=C(C#N)C#N)c3cc(-c5ccccc5)cc1c32)c(=C(C#N)C#N)c1cc(-c2ccccc2)cc2c(=C(C#N)C#N)c3ccccc3n4c21 ; N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(-c5cc(-c6ccccc6)cc(-c6ccccc6)c5)ccc3n4c21]

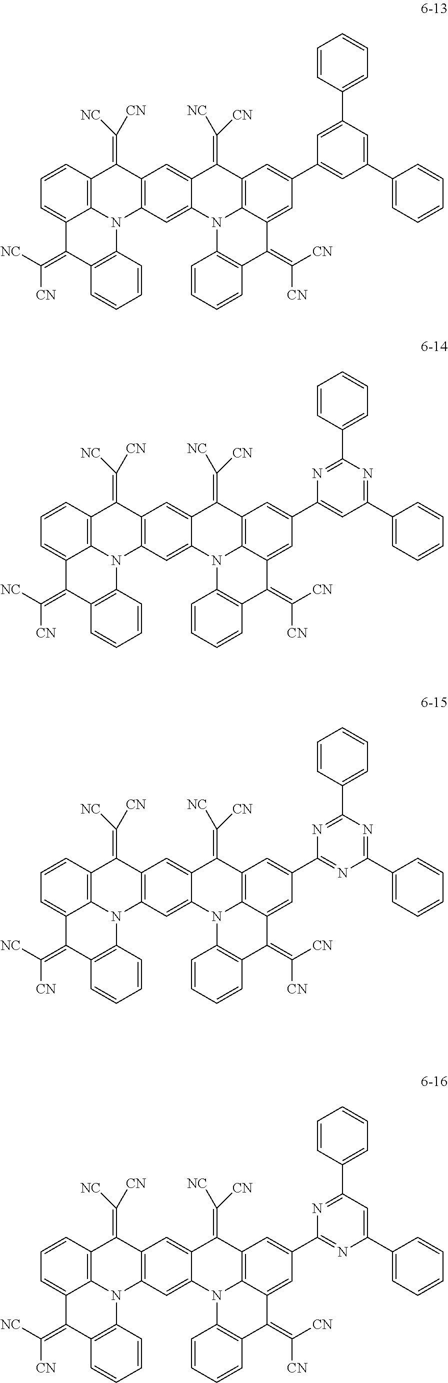

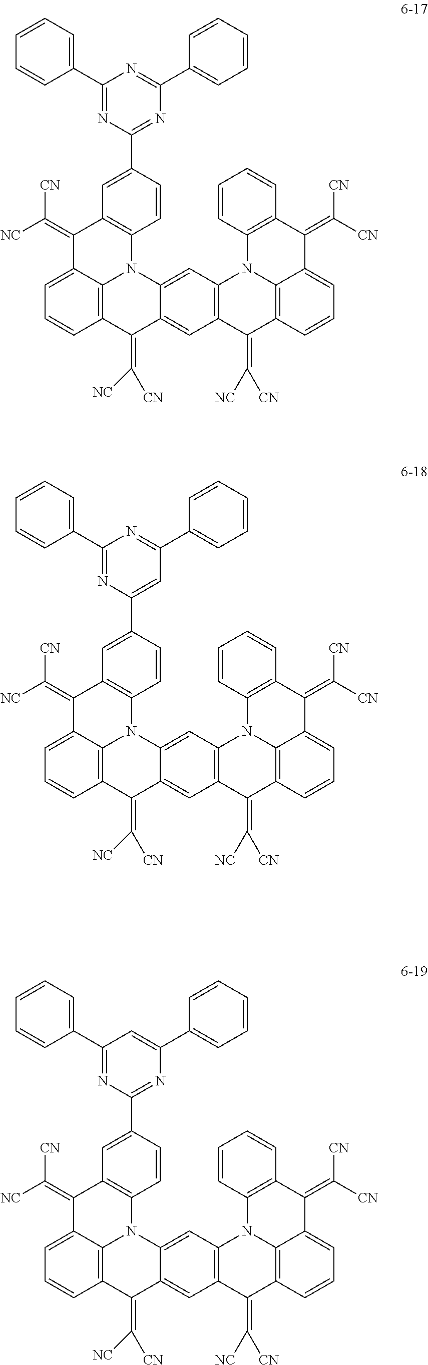 [SMILES: N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(-c5nc(-c6ccccc6)nc(-c6ccccc6)n5)ccc3n4c21 ; N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(-c5cc(-c6ccccc6)nc(-c6ccccc6)n5)ccc3n4c21 ; N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(-c5nc(-c6ccccc6)cc(-c6ccccc6)n5)ccc3n4c21]

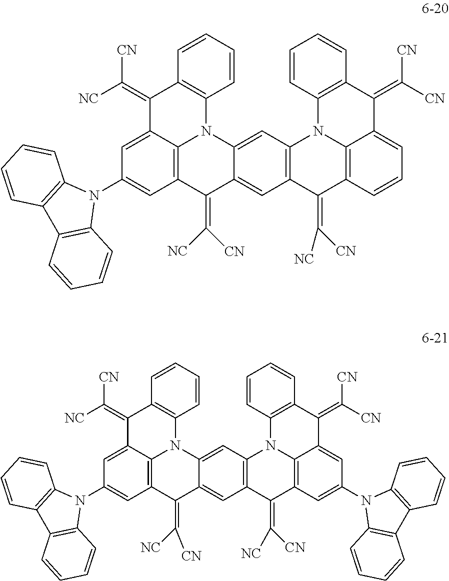 [SMILES: N#CC(C#N)=c1c2ccccc2n2c3cc4c(cc3c(=C(C#N)C#N)c3cccc1c32)c(=C(C#N)C#N)c1cc(-n2c3ccccc3c3ccccc32)cc2c(=C(C#N)C#N)c3ccccc3n4c21 ; N#CC(C#N)=c1c2ccccc2n2c3cc4c(cc3c(=C(C#N)C#N)c3cc(-n5c6ccccc6c6ccccc65)cc1c32)c(=C(C#N)C#N)c1cc(-n2c3ccccc3c3ccccc32)cc2c(=C(C#N)C#N)c3ccccc3n4c21]

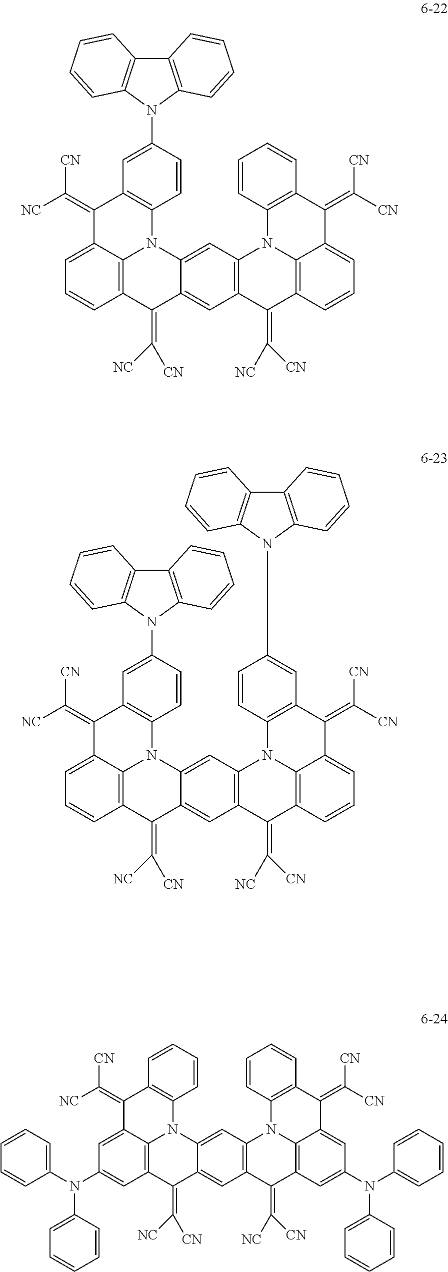 [SMILES: N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(-n5c6ccccc6c6ccccc65)ccc3n4c21 ; N#CC(C#N)=c1c2cc(-n3c4ccccc4c4ccccc43)ccc2n2c3cc4c(cc3c(=C(C#N)C#N)c3cccc1c32)c(=C(C#N)C#N)c1cccc2c(=C(C#N)C#N)c3cc(-n5c6ccccc6c6ccccc65)ccc3n4c21 ; N#CC(C#N)=c1c2ccccc2n2c3cc4c(cc3c(=C(C#N)C#N)c3cc(N(c5ccccc5)c5ccccc5)cc1c32)c(=C(C#N)C#N)c1cc(N(c2ccccc2)c2ccccc2)cc2c(=C(C#N)C#N)c3ccccc3n4c21]

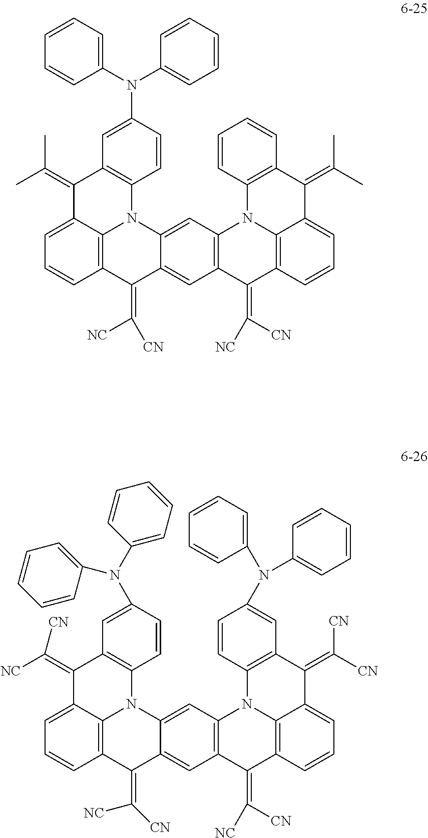 [SMILES: CC(C)=c1c2ccccc2n2c3cc4c(cc3c(=C(C#N)C#N)c3cccc1c32)c(=C(C#N)C#N)c1cccc2c(=C(C)C)c3cc(N(c5ccccc5)c5ccccc5)ccc3n4c21 ; N#CC(C#N)=c1c2cc(N(c3ccccc3)c3ccccc3)ccc2n2c3cc4c(cc3c(=C(C#N)C#N)c3cccc1c32)c(=C(C#N)C#N)c1cccc2c(=C(C#N)C#N)c3cc(N(c5ccccc5)c5ccccc5)ccc3n4c21]

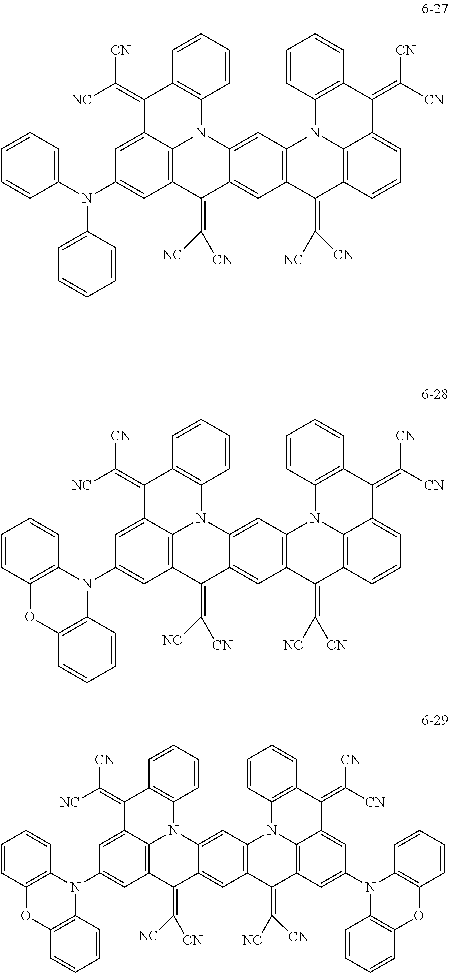 [SMILES: N#CC(C#N)=c1c2ccccc2n2c3cc4c(cc3c(=C(C#N)C#N)c3cccc1c32)c(=C(C#N)C#N)c1cc(N(c2ccccc2)c2ccccc2)cc2c(=C(C#N)C#N)c3ccccc3n4c21 ; N#CC(C#N)=c1c2ccccc2n2c3cc4c(cc3c(=C(C#N)C#N)c3cccc1c32)c(=C(C#N)C#N)c1cc(N2c3ccccc3Oc3ccccc32)cc2c(=C(C#N)C#N)c3ccccc3n4c21 ; N#CC(C#N)=c1c2ccccc2n2c3cc4c(cc3c(=C(C#N)C#N)c3cc(N5c6ccccc6Oc6ccccc65)cc1c32)c(=C(C#N)C#N)c1cc(N2c3ccccc3Oc3ccccc32)cc2c(=C(C#N)C#N)c3ccccc3n4c21]

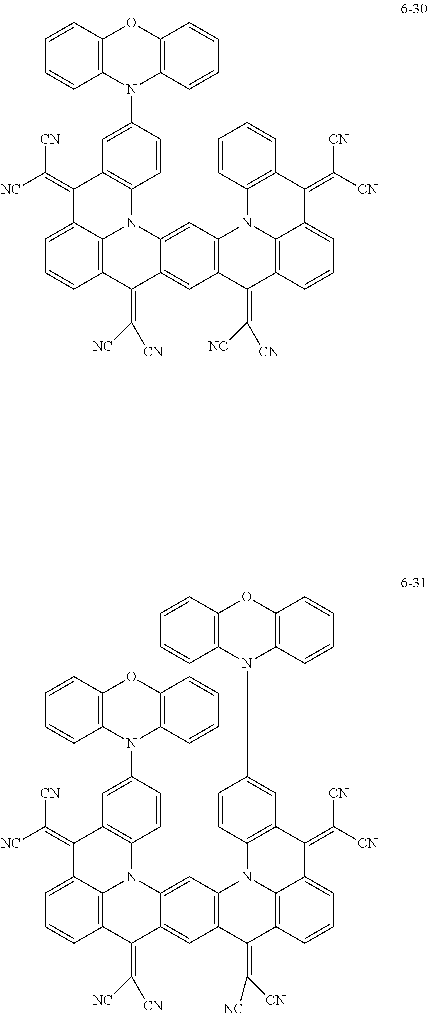 [SMILES: N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(N5c6ccccc6Oc6ccccc65)ccc3n4c21 ; N#CC(C#N)=c1c2cc(N3c4ccccc4Oc4ccccc43)ccc2n2c3cc4c(cc3c(=C(C#N)C#N)c3cccc1c32)c(=C(C#N)C#N)c1cccc2c(=C(C#N)C#N)c3cc(N5c6ccccc6Oc6ccccc65)ccc3n4c21]

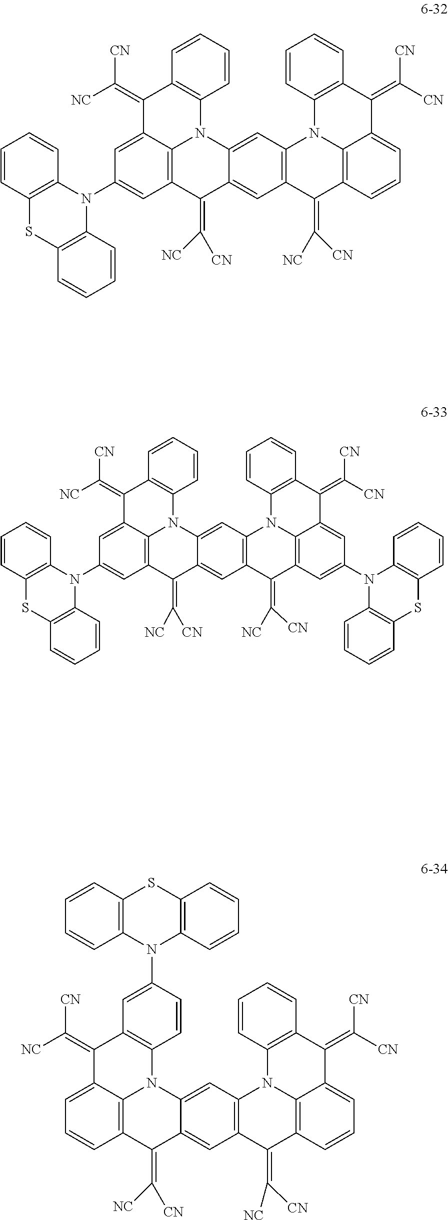 [SMILES: N#CC(C#N)=c1c2ccccc2n2c3cc4c(cc3c(=C(C#N)C#N)c3cccc1c32)c(=C(C#N)C#N)c1cc(N2c3ccccc3Sc3ccccc32)cc2c(=C(C#N)C#N)c3ccccc3n4c21 ; N#CC(C#N)=c1c2ccccc2n2c3cc4c(cc3c(=C(C#N)C#N)c3cc(N5c6ccccc6Sc6ccccc65)cc1c32)c(=C(C#N)C#N)c1cc(N2c3ccccc3Sc3ccccc32)cc2c(=C(C#N)C#N)c3ccccc3n4c21 ; N#CC(C#N)=c1c2ccccc2n2c3cc4c(cc3c(=C(C#N)C#N)c3cccc1c32)c(=C(C#N)C#N)c1cccc2c(=C(C#N)C#N)c3cc(N5c6ccccc6Sc6ccccc65)ccc3n4c21]

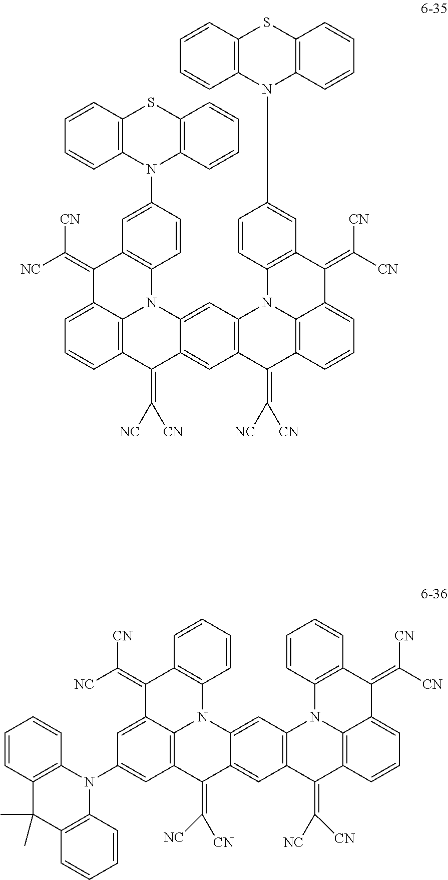 [SMILES: N#CC(C#N)=c1c2cc(N3c4ccccc4Sc4ccccc43)ccc2n2c3cc4c(cc3c(=C(C#N)C#N)c3cccc1c32)c(=C(C#N)C#N)c1cccc2c(=C(C#N)C#N)c3cc(N5c6ccccc6Sc6ccccc65)ccc3n4c21 ; CC1(C)c2ccccc2N(c2cc3c(=C(C#N)C#N)c4ccccc4n4c5cc6c(cc5c(=C(C#N)C#N)c(c2)c34)c(=C(C#N)C#N)c2cccc3c(=C(C#N)C#N)c4ccccc4n6c32)c2ccccc21]

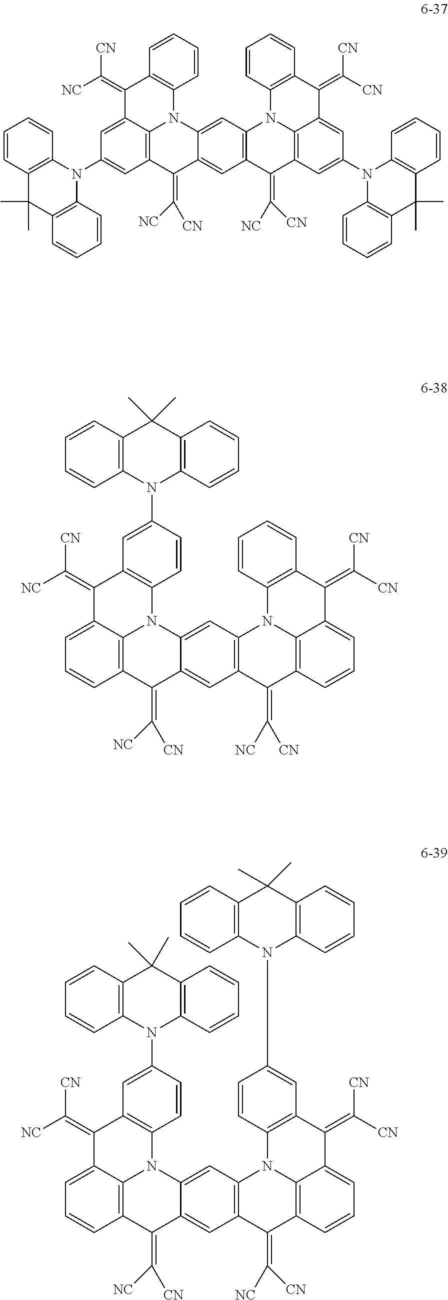

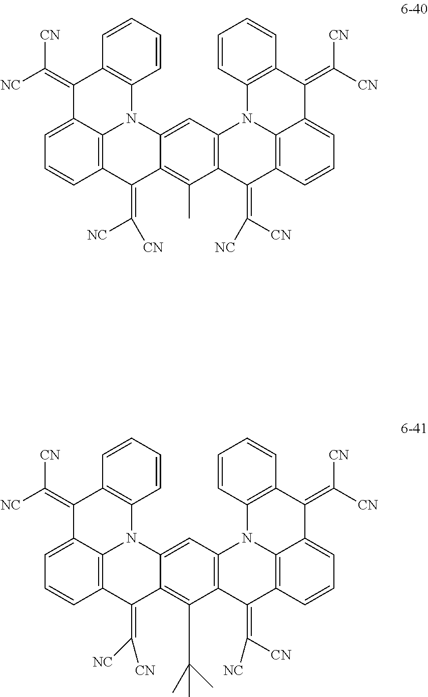 [SMILES: Cc1c2c(=C(C#N)C#N)c3cccc4c(=C(C#N)C#N)c5ccccc5n(c2cc2c1c(=C(C#N)C#N)c1cccc5c(=C(C#N)C#N)c6ccccc6n2c51)c43 ; CC(C)(C)c1c2c(=C(C#N)C#N)c3cccc4c(=C(C#N)C#N)c5ccccc5n(c2cc2c1c(=C(C#N)C#N)c1cccc5c(=C(C#N)C#N)c6ccccc6n2c51)c43]

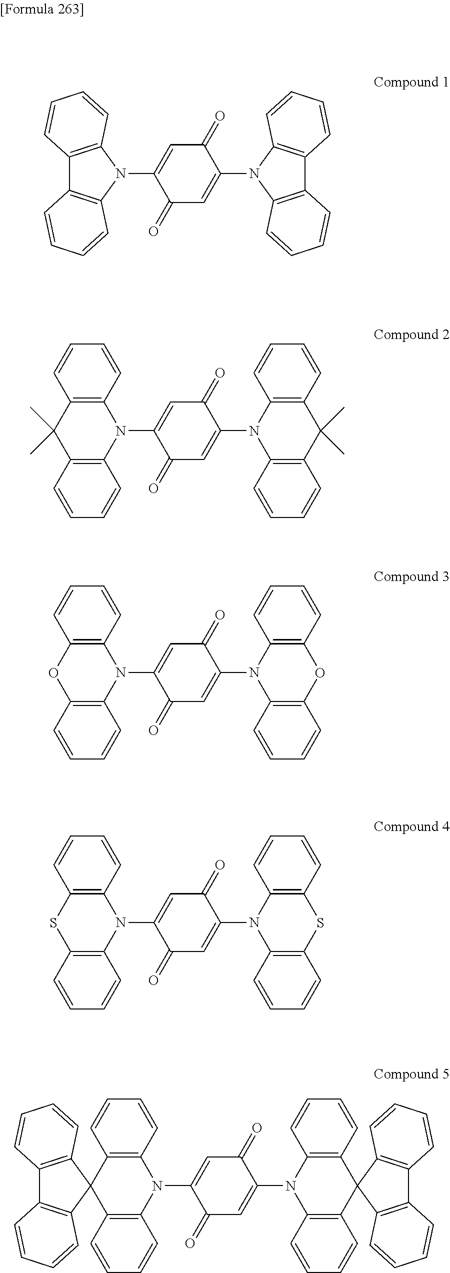

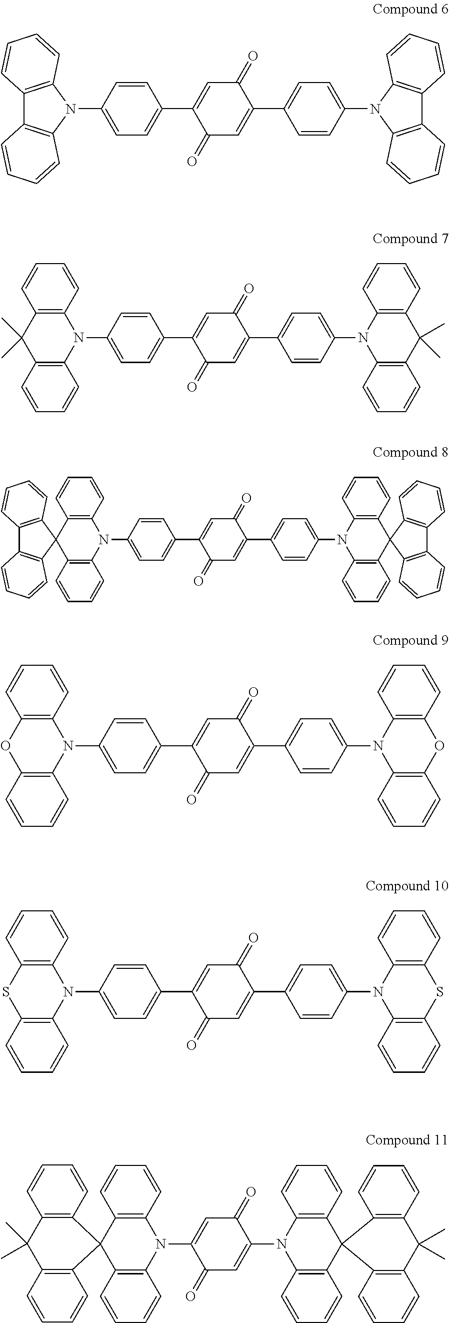

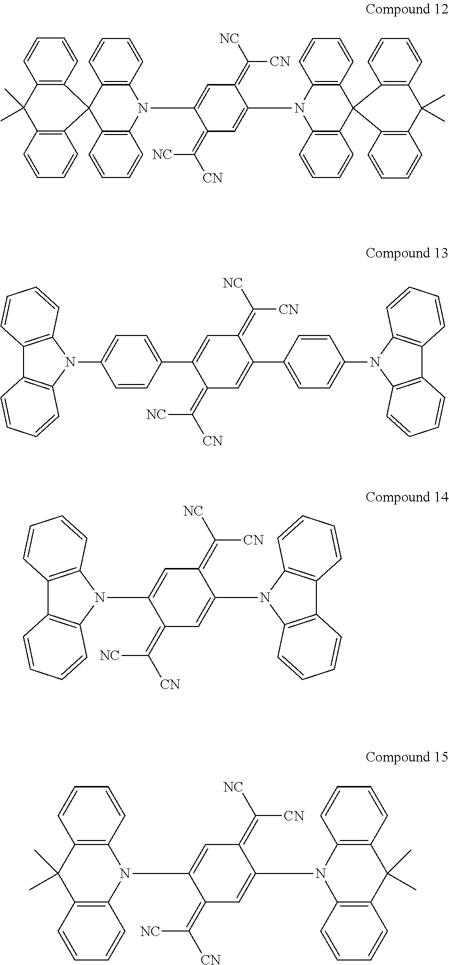

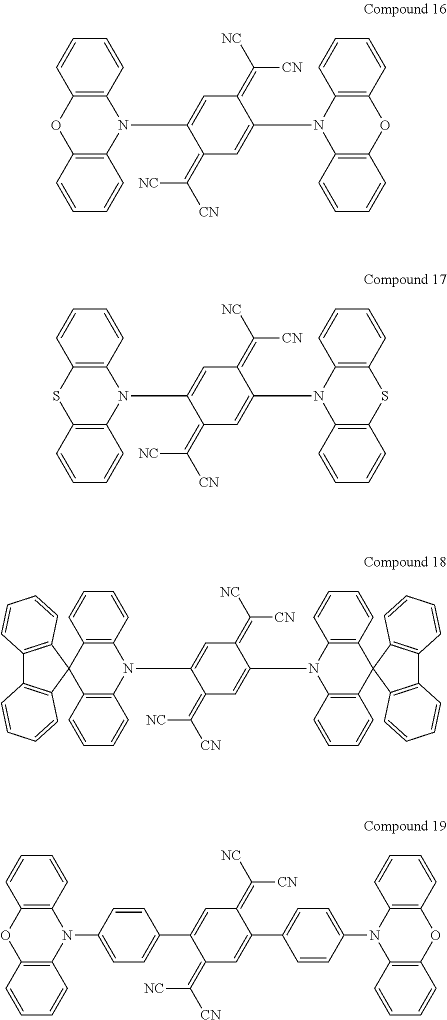 [SMILES: N#CC(C#N)=c1cc(N2c3ccccc3Oc3ccccc32)c(=C(C#N)C#N)cc1N1c2ccccc2Oc2ccccc21 ; N#CC(C#N)=c1cc(N2c3ccccc3Sc3ccccc32)c(=C(C#N)C#N)cc1N1c2ccccc2Sc2ccccc21 ; N#CC(C#N)=c1cc(N2c3ccccc3C3(c4ccccc4-c4ccccc43)c3ccccc32)c(=C(C#N)C#N)cc1N1c2ccccc2C2(c3ccccc3-c3ccccc32)c2ccccc21 ; N#CC(C#N)=c1cc(-c2ccc(N3c4ccccc4Oc4ccccc43)cc2)c(=C(C#N)C#N)cc1-c1ccc(N2c3ccccc3Oc3ccccc32)cc1]

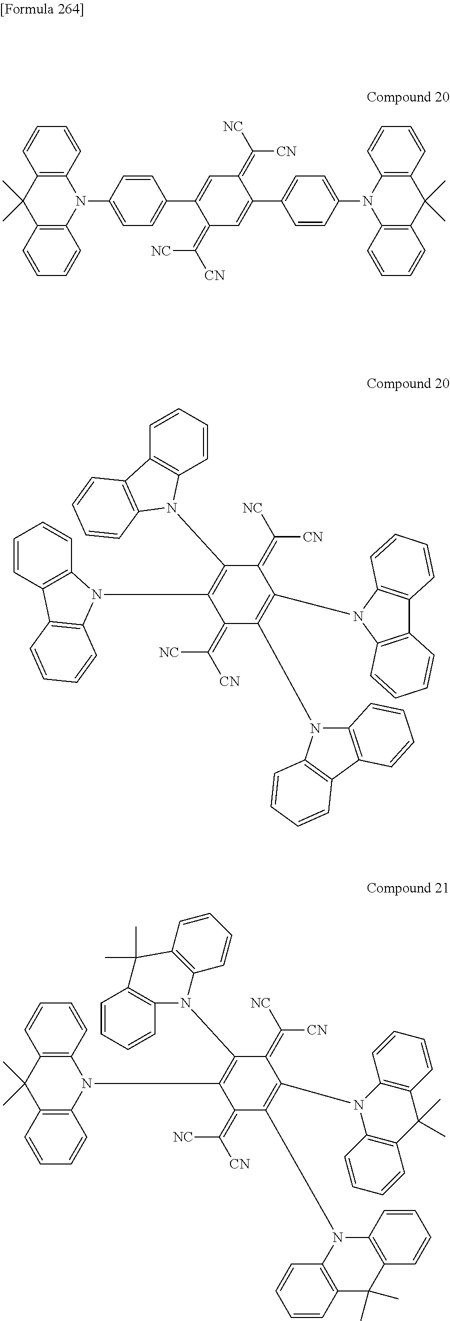

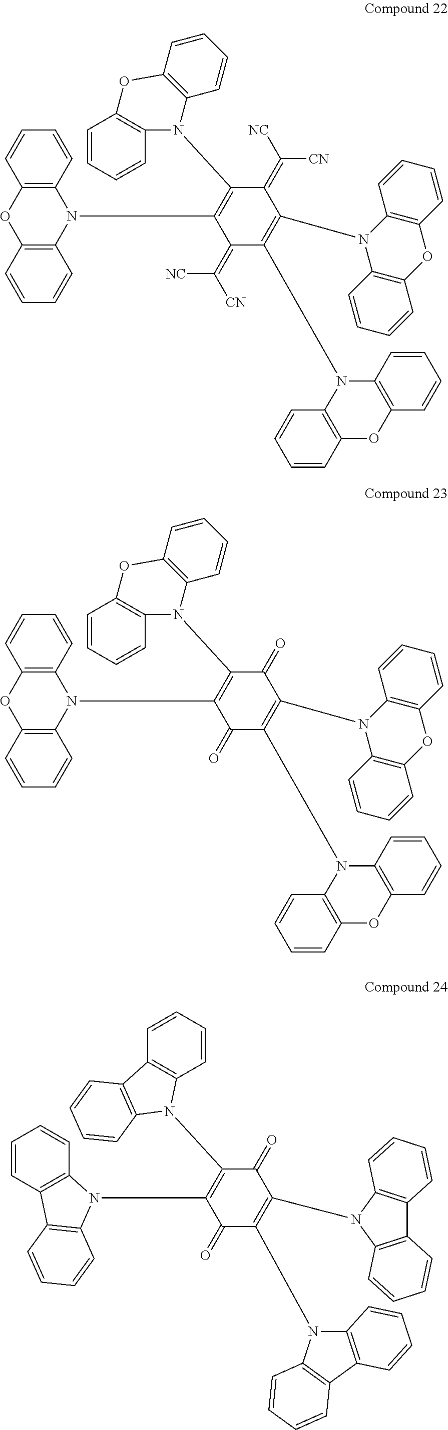 [SMILES: N#CC(C#N)=c1c(N2c3ccccc3Oc3ccccc32)c(N2c3ccccc3Oc3ccccc32)c(=C(C#N)C#N)c(N2c3ccccc3Oc3ccccc32)c1N1c2ccccc2Oc2ccccc21 ; O=C1C(N2c3ccccc3Oc3ccccc32)=C(N2c3ccccc3Oc3ccccc32)C(=O)C(N2c3ccccc3Oc3ccccc32)=C1N1c2ccccc2Oc2ccccc21 ; O=C1C(n2c3ccccc3c3ccccc32)=C(n2c3ccccc3c3ccccc32)C(=O)C(n2c3ccccc3c3ccccc32)=C1n1c2ccccc2c2ccccc21]

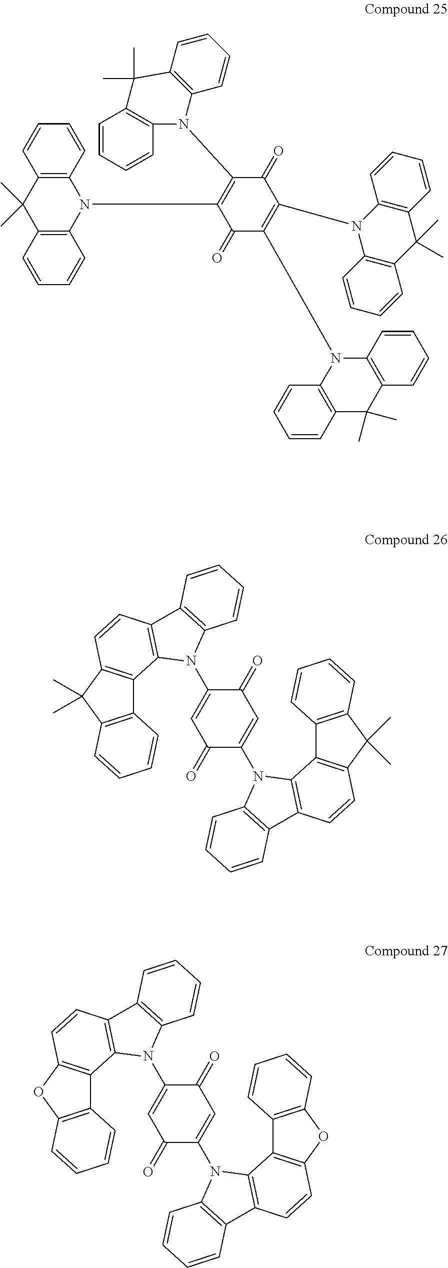

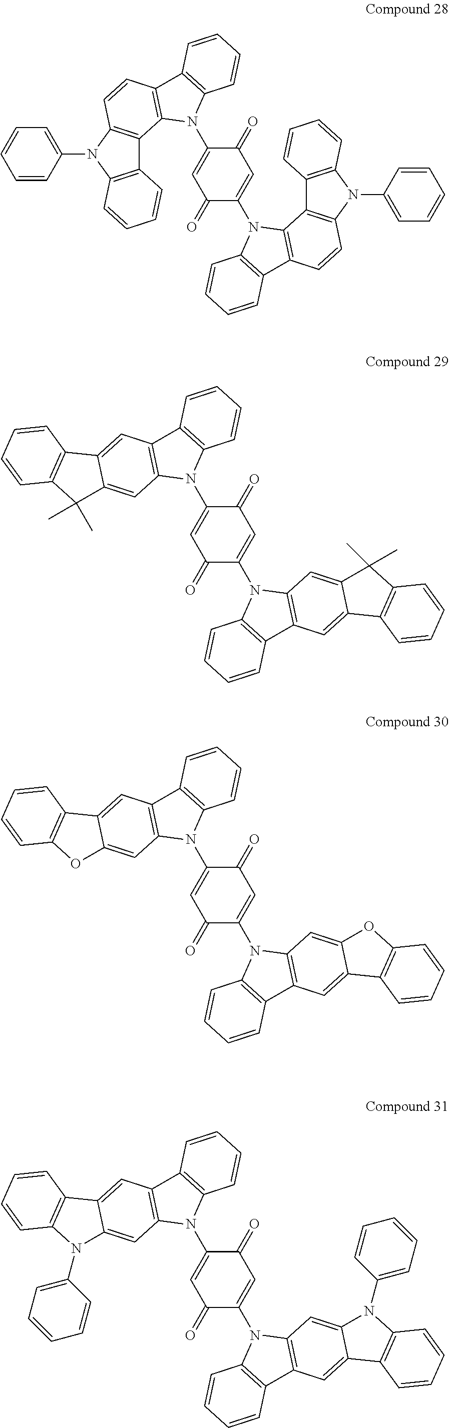 [SMILES: O=C1C=C(n2c3ccccc3c3ccc4c(c5ccccc5n4-c4ccccc4)c32)C(=O)C=C1n1c2ccccc2c2ccc3c(c4ccccc4n3-c3ccccc3)c21 ; CC1(C)c2ccccc2-c2cc3c4ccccc4n(C4=CC(=O)C(n5c6ccccc6c6cc7c(cc65)C(C)(C)c5ccccc5-7)=CC4=O)c3cc21 ; O=C1C=C(n2c3ccccc3c3cc4c(cc32)oc2ccccc24)C(=O)C=C1n1c2ccccc2c2cc3c(cc21)oc1ccccc13 ; O=C1C=C(n2c3ccccc3c3cc4c5ccccc5n(-c5ccccc5)c4cc32)C(=O)C=C1n1c2ccccc2c2cc3c4ccccc4n(-c4ccccc4)c3cc21]

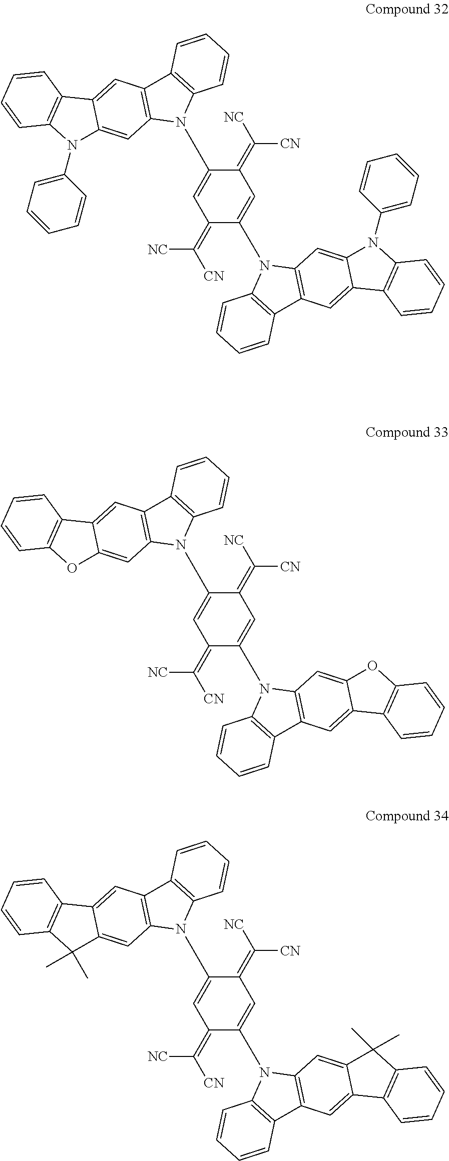 [SMILES: N#CC(C#N)=c1cc(-n2c3ccccc3c3cc4c5ccccc5n(-c5ccccc5)c4cc32)c(=C(C#N)C#N)cc1-n1c2ccccc2c2cc3c4ccccc4n(-c4ccccc4)c3cc21 ; N#CC(C#N)=c1cc(-n2c3ccccc3c3cc4c(cc32)oc2ccccc24)c(=C(C#N)C#N)cc1-n1c2ccccc2c2cc3c(cc21)oc1ccccc13 ; CC1(C)c2ccccc2-c2cc3c4ccccc4n(-c4cc(=C(C#N)C#N)c(-n5c6ccccc6c6cc7c(cc65)C(C)(C)c5ccccc5-7)cc4=C(C#N)C#N)c3cc21]

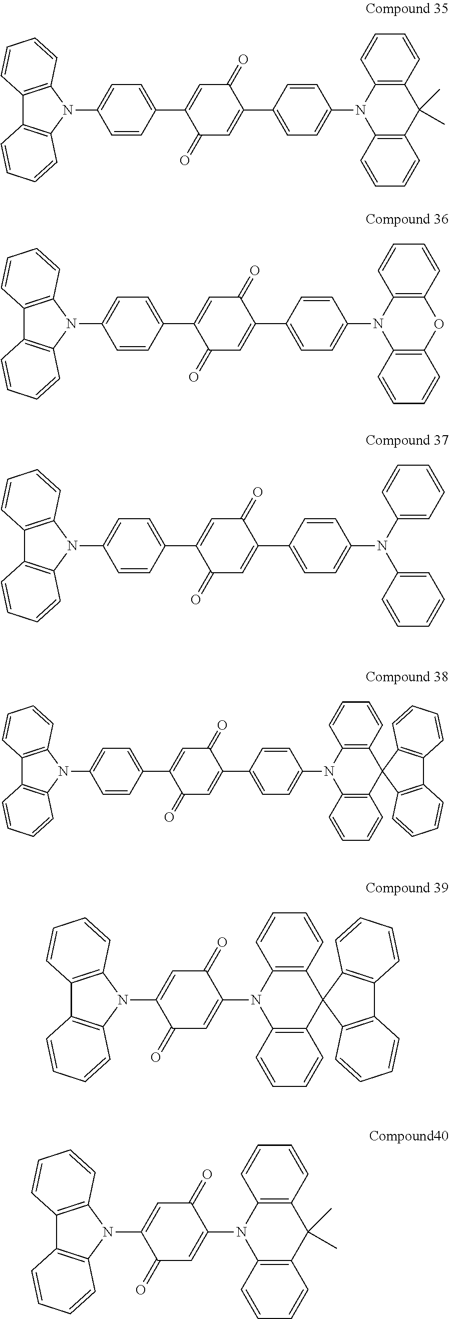 [SMILES: CC1(C)c2ccccc2N(c2ccc(C3=CC(=O)C(c4ccc(-n5c6ccccc6c6ccccc65)cc4)=CC3=O)cc2)c2ccccc21 ; O=C1C=C(c2ccc(-n3c4ccccc4c4ccccc43)cc2)C(=O)C=C1c1ccc(N2c3ccccc3Oc3ccccc32)cc1 ; O=C1C=C(c2ccc(-n3c4ccccc4c4ccccc43)cc2)C(=O)C=C1c1ccc(N(c2ccccc2)c2ccccc2)cc1 ; O=C1C=C(c2ccc(-n3c4ccccc4c4ccccc43)cc2)C(=O)C=C1c1ccc(N2c3ccccc3C3(c4ccccc4-c4ccccc43)c3ccccc32)cc1 ; O=C1C=C(n2c3ccccc3c3ccccc32)C(=O)C=C1N1c2ccccc2C2(c3ccccc3-c3ccccc32)c2ccccc21 ; CC1(C)c2ccccc2N(C2=CC(=O)C(n3c4ccccc4c4ccccc43)=CC2=O)c2ccccc21]

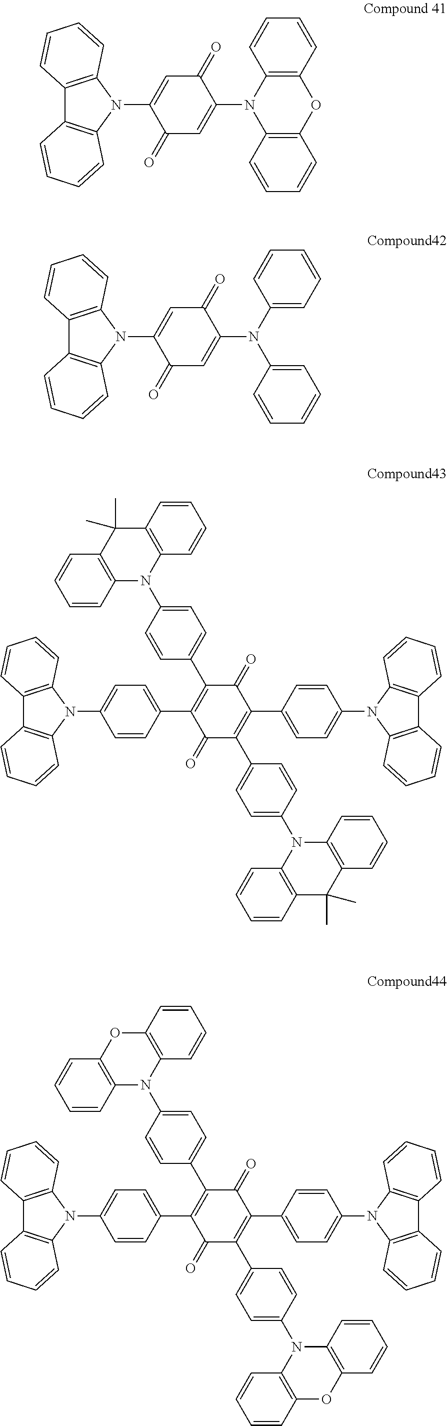 [SMILES: O=C1C=C(n2c3ccccc3c3ccccc32)C(=O)C=C1N1c2ccccc2Oc2ccccc21 ; O=C1C=C(n2c3ccccc3c3ccccc32)C(=O)C=C1N(c1ccccc1)c1ccccc1 ; CC1(C)c2ccccc2N(c2ccc(C3=C(c4ccc(-n5c6ccccc6c6ccccc65)cc4)C(=O)C(c4ccc(N5c6ccccc6C(C)(C)c6ccccc65)cc4)=C(c4ccc(-n5c6ccccc6c6ccccc65)cc4)C3=O)cc2)c2ccccc21 ; O=C1C(c2ccc(N3c4ccccc4Oc4ccccc43)cc2)=C(c2ccc(-n3c4ccccc4c4ccccc43)cc2)C(=O)C(c2ccc(N3c4ccccc4Oc4ccccc43)cc2)=C1c1ccc(-n2c3ccccc3c3ccccc32)cc1]

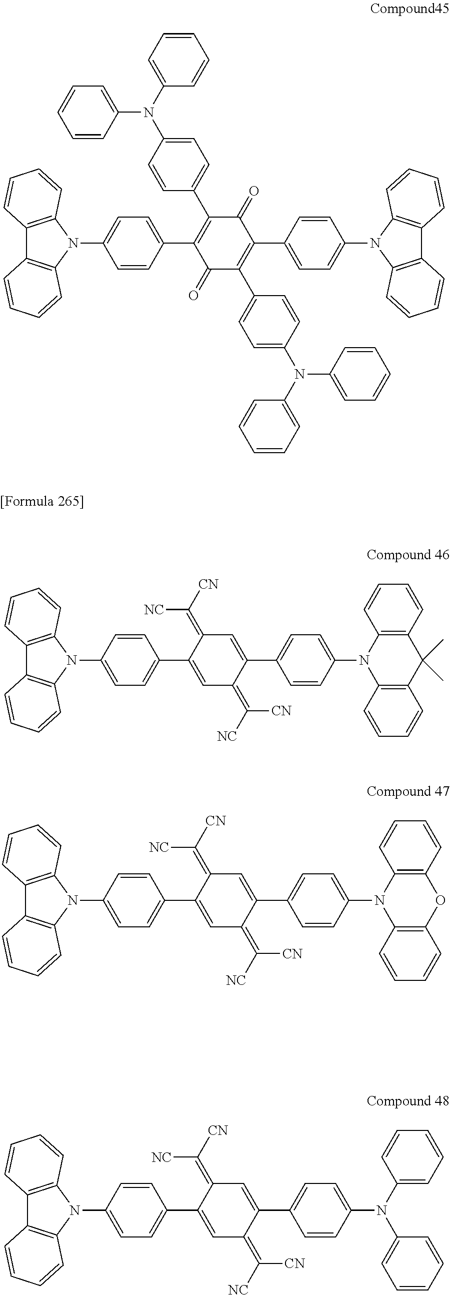 [SMILES: O=C1C(c2ccc(N(c3ccccc3)c3ccccc3)cc2)=C(c2ccc(-n3c4ccccc4c4ccccc43)cc2)C(=O)C(c2ccc(N(c3ccccc3)c3ccccc3)cc2)=C1c1ccc(-n2c3ccccc3c3ccccc32)cc1 ; CC1(C)c2ccccc2N(c2ccc(-c3cc(=C(C#N)C#N)c(-c4ccc(-n5c6ccccc6c6ccccc65)cc4)cc3=C(C#N)C#N)cc2)c2ccccc21 ; N#CC(C#N)=c1cc(-c2ccc(-n3c4ccccc4c4ccccc43)cc2)c(=C(C#N)C#N)cc1-c1ccc(N2c3ccccc3Oc3ccccc32)cc1 ; N#CC(C#N)=c1cc(-c2ccc(-n3c4ccccc4c4ccccc43)cc2)c(=C(C#N)C#N)cc1-c1ccc(N(c2ccccc2)c2ccccc2)cc1]

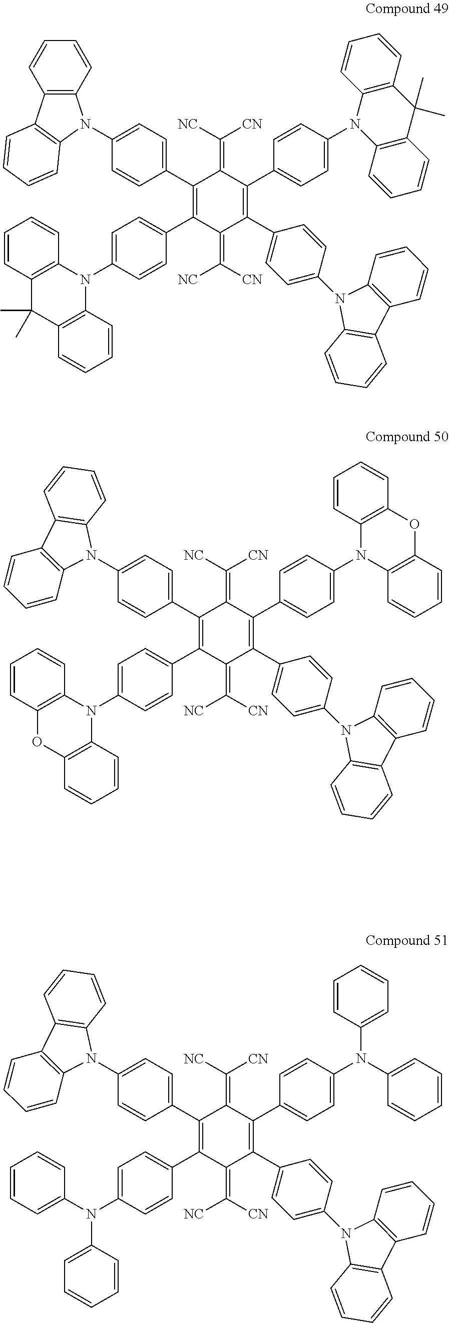

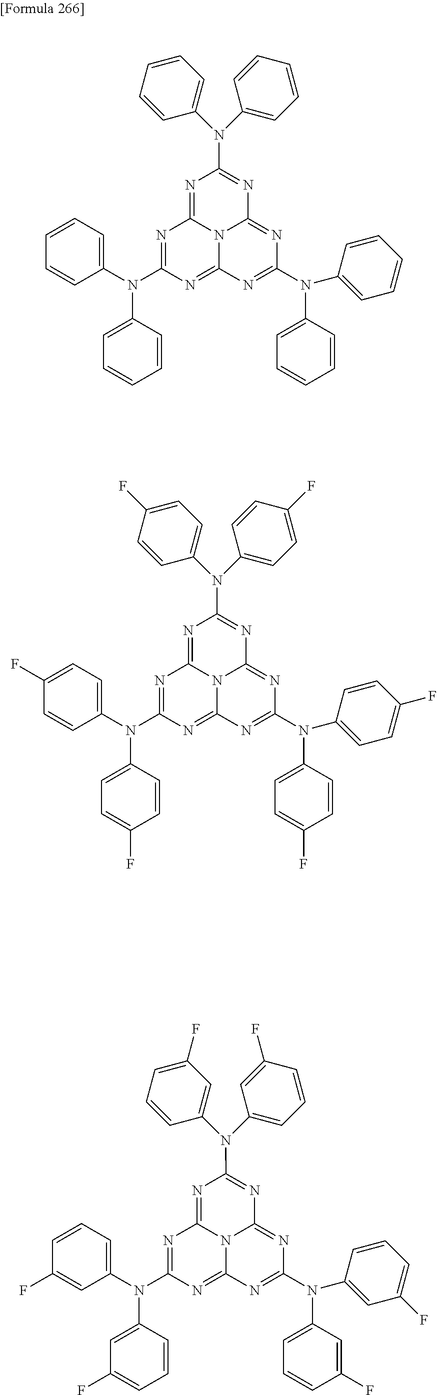 [SMILES: c1ccc(N(C2=NC3=NC(N(c4ccccc4)c4ccccc4)=NC4=NC(N(c5ccccc5)c5ccccc5)=NC(=N2)N34)c2ccccc2)cc1 ; Fc1ccc(N(C2=NC3=NC(N(c4ccc(F)cc4)c4ccc(F)cc4)=NC4=NC(N(c5ccc(F)cc5)c5ccc(F)cc5)=NC(=N2)N34)c2ccc(F)cc2)cc1 ; Fc1cccc(N(C2=NC3=NC(N(c4cccc(F)c4)c4cccc(F)c4)=NC4=NC(N(c5cccc(F)c5)c5cccc(F)c5)=NC(=N2)N34)c2cccc(F)c2)c1]

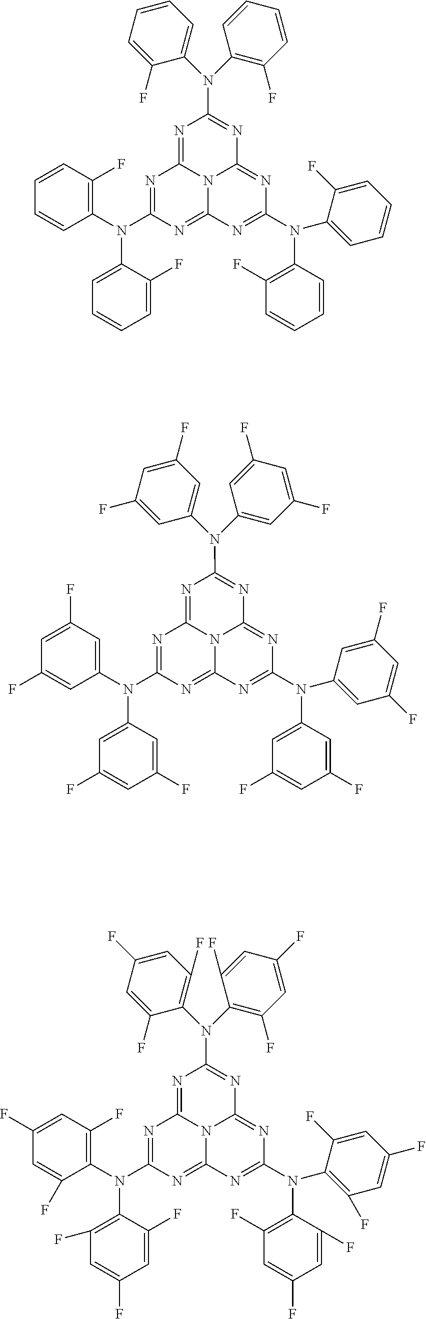 [SMILES: Fc1ccccc1N(C1=NC2=NC(N(c3ccccc3F)c3ccccc3F)=NC3=NC(N(c4ccccc4F)c4ccccc4F)=NC(=N1)N23)c1ccccc1F ; Fc1cc(F)cc(N(C2=NC3=NC(N(c4cc(F)cc(F)c4)c4cc(F)cc(F)c4)=NC4=NC(N(c5cc(F)cc(F)c5)c5cc(F)cc(F)c5)=NC(=N2)N34)c2cc(F)cc(F)c2)c1 ; Fc1cc(F)c(N(C2=NC3=NC(N(c4c(F)cc(F)cc4F)c4c(F)cc(F)cc4F)=NC4=NC(N(c5c(F)cc(F)cc5F)c5c(F)cc(F)cc5F)=NC(=N2)N34)c2c(F)cc(F)cc2F)c(F)c1]

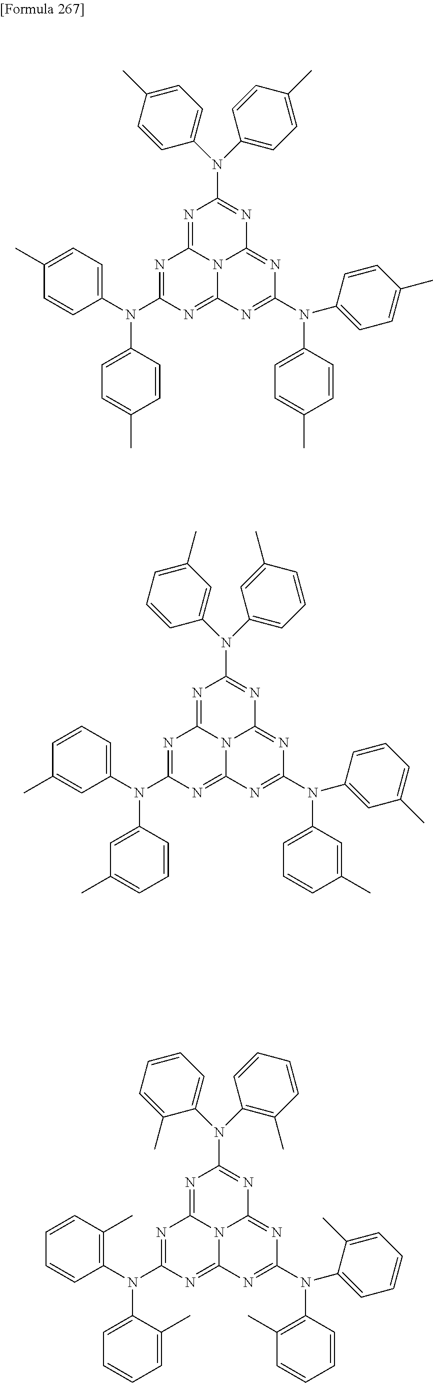

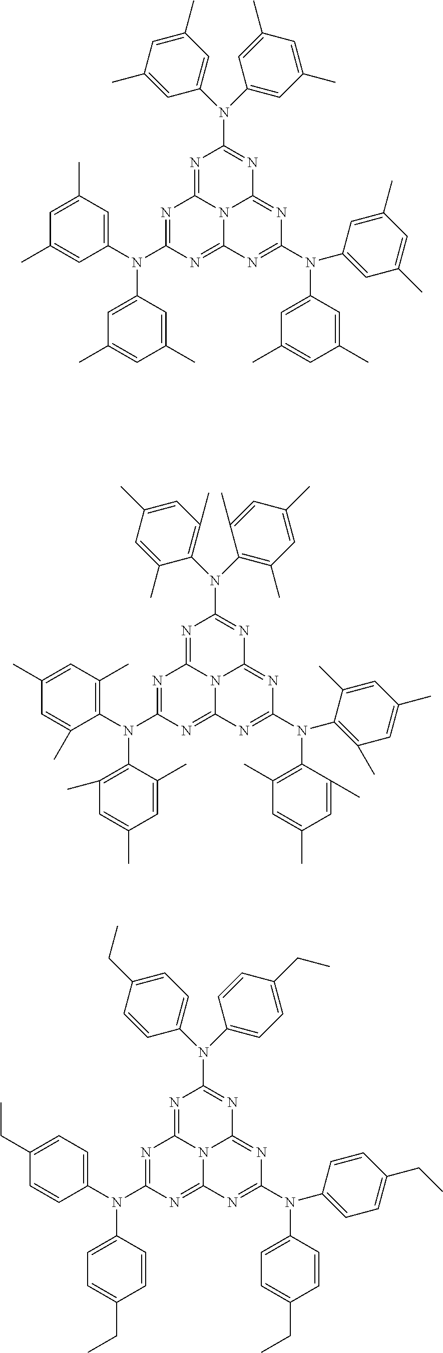

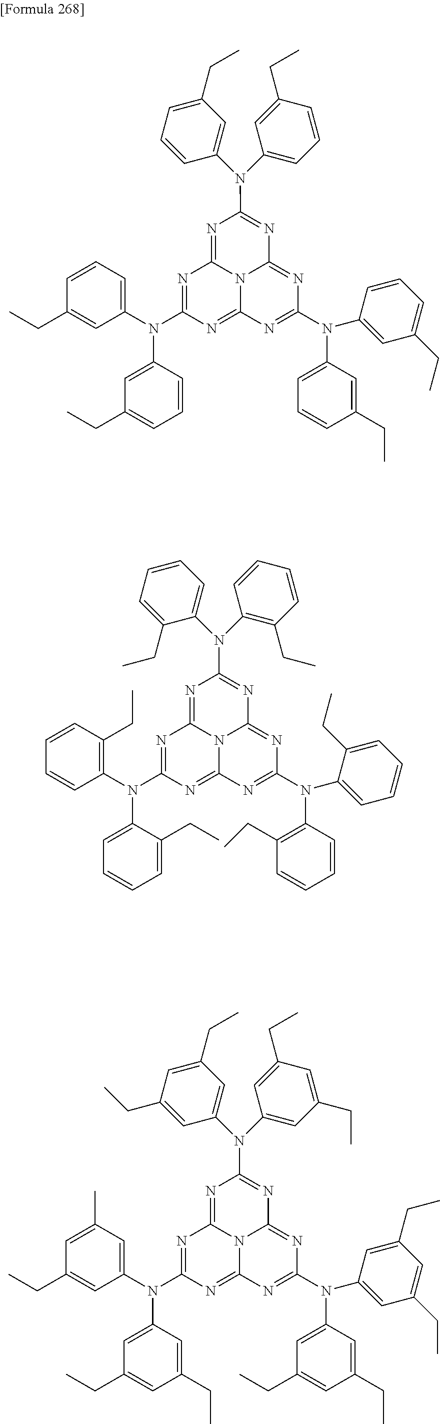 [SMILES: CCc1cccc(N(C2=NC3=NC(N(c4cccc(CC)c4)c4cccc(CC)c4)=NC4=NC(N(c5cccc(CC)c5)c5cccc(CC)c5)=NC(=N2)N34)c2cccc(CC)c2)c1 ; CCc1ccccc1N(C1=NC2=NC(N(c3ccccc3CC)c3ccccc3CC)=NC3=NC(N(c4ccccc4CC)c4ccccc4CC)=NC(=N1)N23)c1ccccc1CC ; CCc1cc(C)cc(N(C2=NC3=NC(N(c4cc(CC)cc(CC)c4)c4cc(CC)cc(CC)c4)=NC4=NC(N(c5cc(CC)cc(CC)c5)c5cc(CC)cc(CC)c5)=NC(=N2)N34)c2cc(CC)cc(CC)c2)c1]

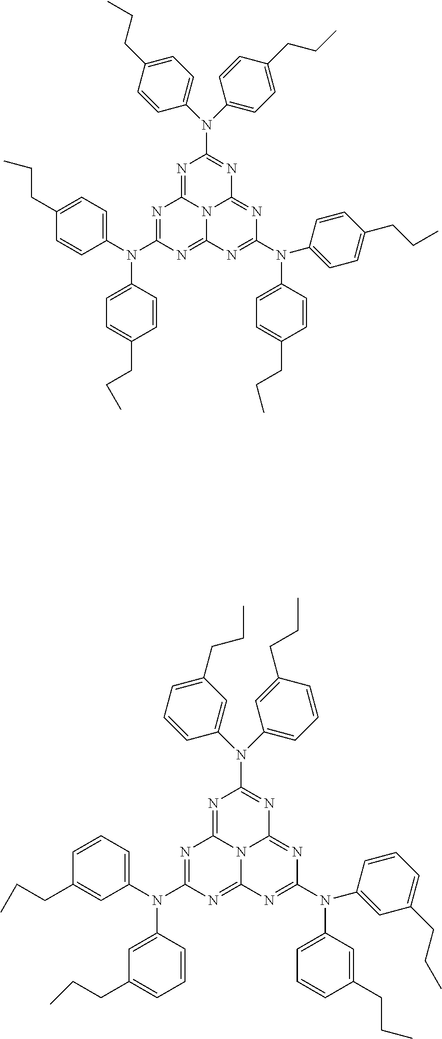

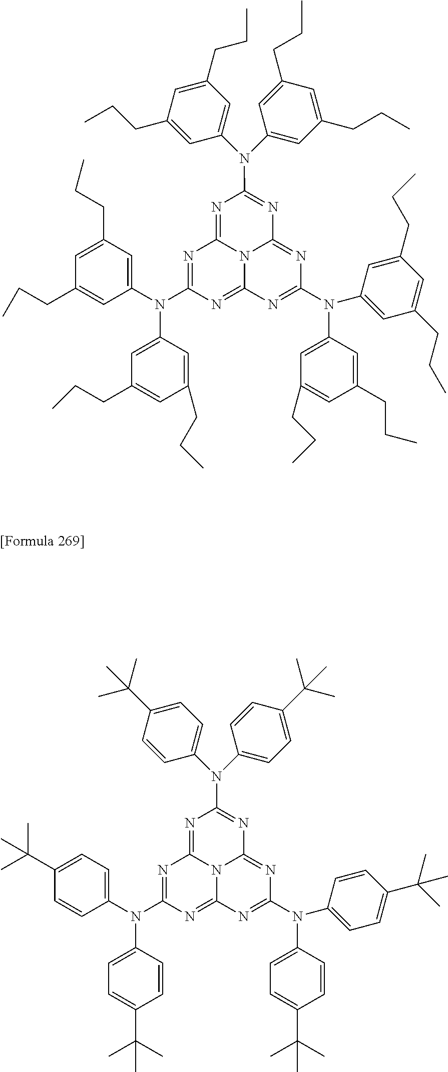

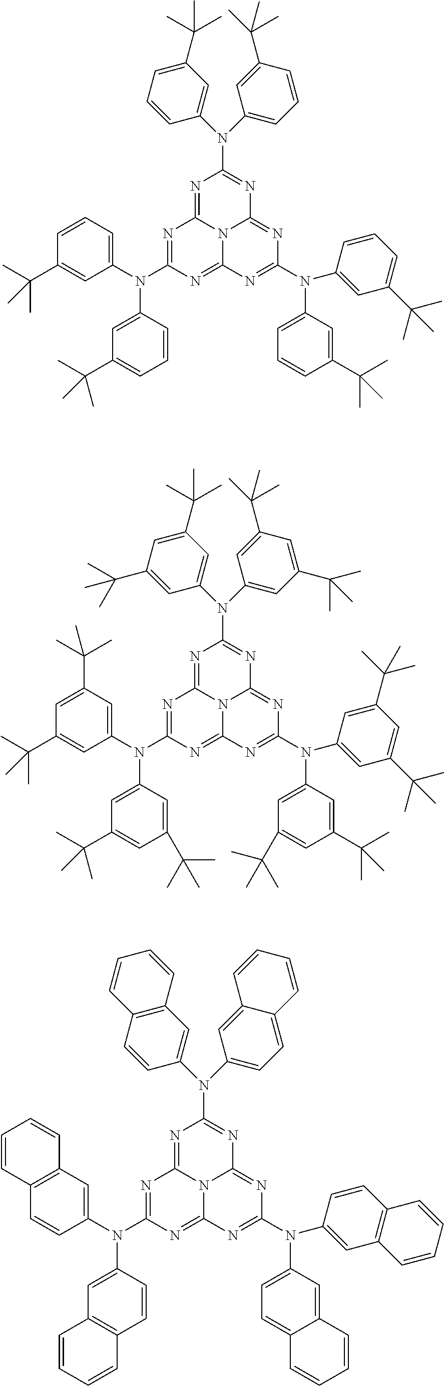

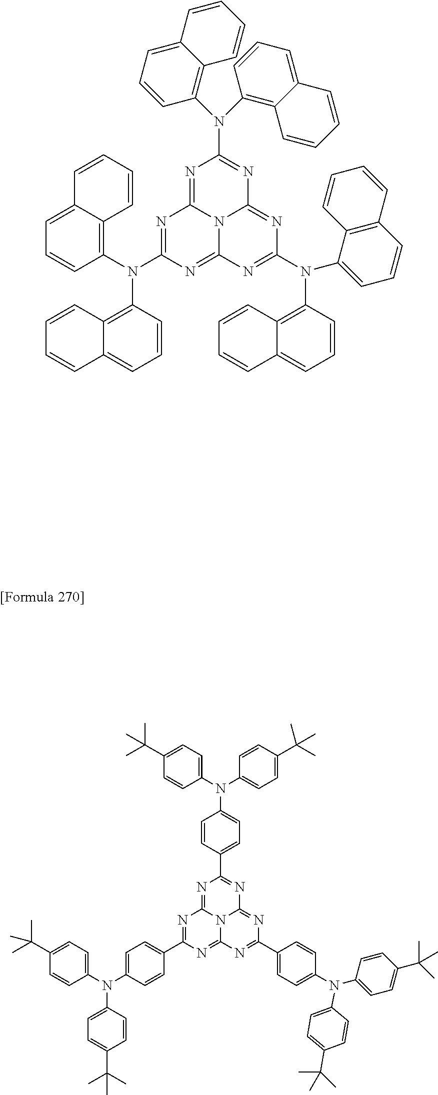 [SMILES: c1ccc2c(N(C3=NC4=NC(N(c5cccc6ccccc56)c5cccc6ccccc56)=NC5=NC(N(c6cccc7ccccc67)c6cccc7ccccc67)=NC(=N3)N45)c3cccc4ccccc34)cccc2c1 ; CC(C)(C)c1ccc(N(c2ccc(C3=NC4=NC(c5ccc(N(c6ccc(C(C)(C)C)cc6)c6ccc(C(C)(C)C)cc6)cc5)=NC5=NC(c6ccc(N(c7ccc(C(C)(C)C)cc7)c7ccc(C(C)(C)C)cc7)cc6)=NC(=N3)N45)cc2)c2ccc(C(C)(C)C)cc2)cc1]

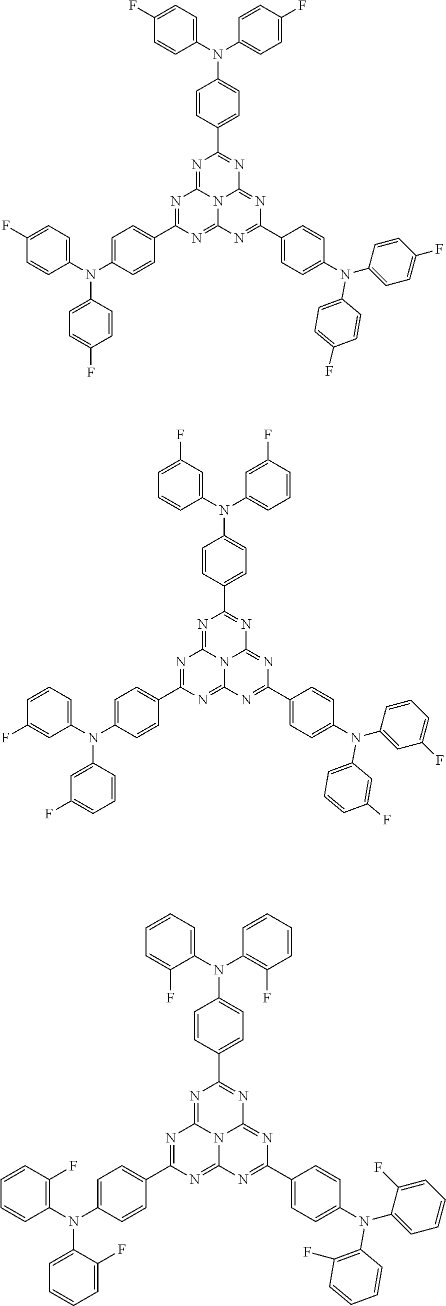 [SMILES: Fc1ccc(N(c2ccc(F)cc2)c2ccc(C3=NC4=NC(c5ccc(N(c6ccc(F)cc6)c6ccc(F)cc6)cc5)=NC5=NC(c6ccc(N(c7ccc(F)cc7)c7ccc(F)cc7)cc6)=NC(=N3)N45)cc2)cc1 ; Fc1cccc(N(c2ccc(C3=NC4=NC(c5ccc(N(c6cccc(F)c6)c6cccc(F)c6)cc5)=NC5=NC(c6ccc(N(c7cccc(F)c7)c7cccc(F)c7)cc6)=NC(=N3)N45)cc2)c2cccc(F)c2)c1 ; Fc1ccccc1N(c1ccc(C2=NC3=NC(c4ccc(N(c5ccccc5F)c5ccccc5F)cc4)=NC4=NC(c5ccc(N(c6ccccc6F)c6ccccc6F)cc5)=NC(=N2)N34)cc1)c1ccccc1F]

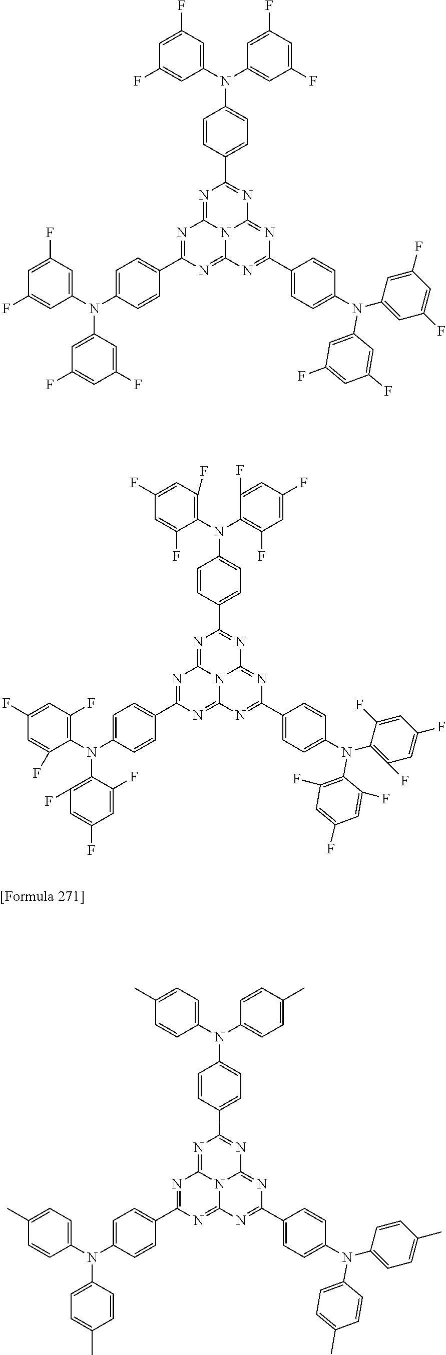

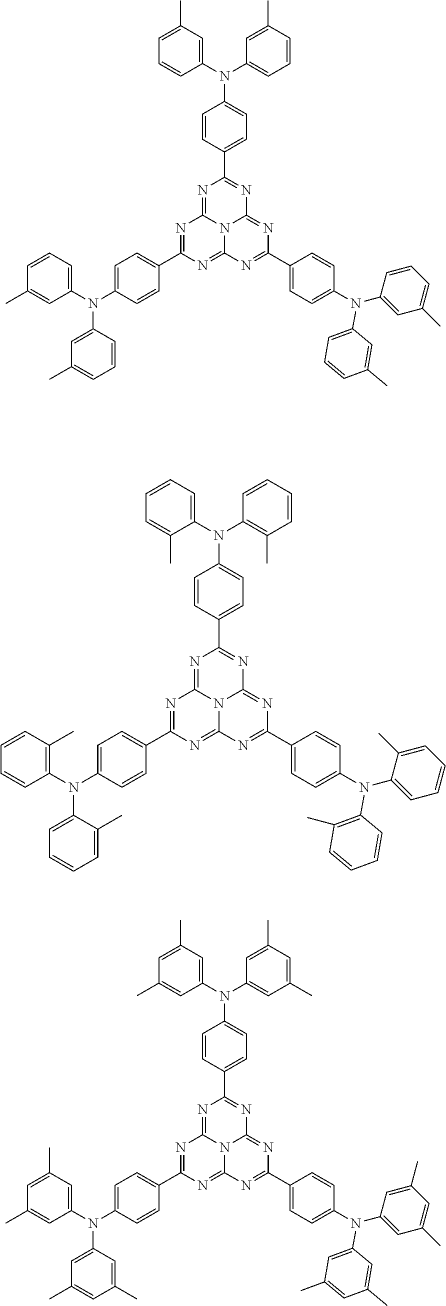

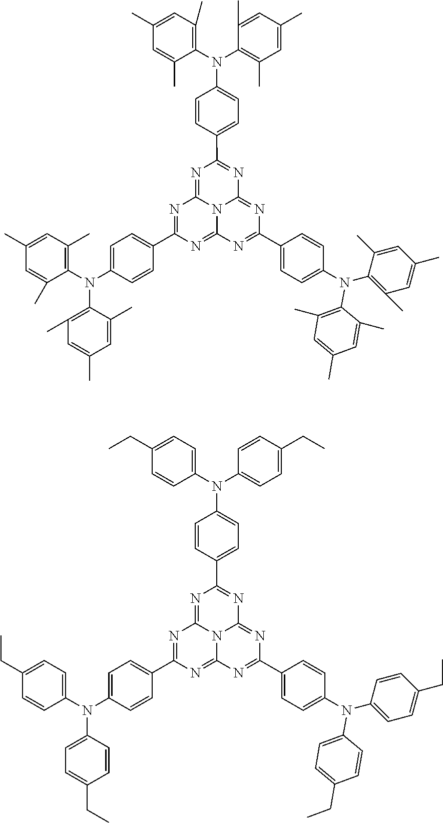

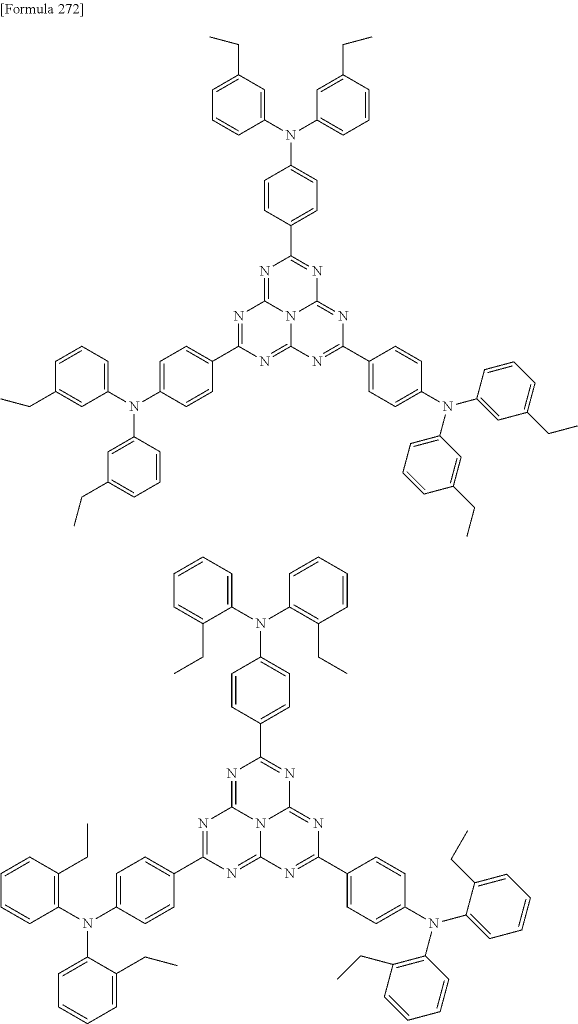 [SMILES: CCc1cccc(N(c2ccc(C3=NC4=NC(c5ccc(N(c6cccc(CC)c6)c6cccc(CC)c6)cc5)=NC5=NC(c6ccc(N(c7cccc(CC)c7)c7cccc(CC)c7)cc6)=NC(=N3)N45)cc2)c2cccc(CC)c2)c1 ; CCc1ccccc1N(c1ccc(C2=NC3=NC(c4ccc(N(c5ccccc5CC)c5ccccc5CC)cc4)=NC4=NC(c5ccc(N(c6ccccc6CC)c6ccccc6CC)cc5)=NC(=N2)N34)cc1)c1ccccc1CC]

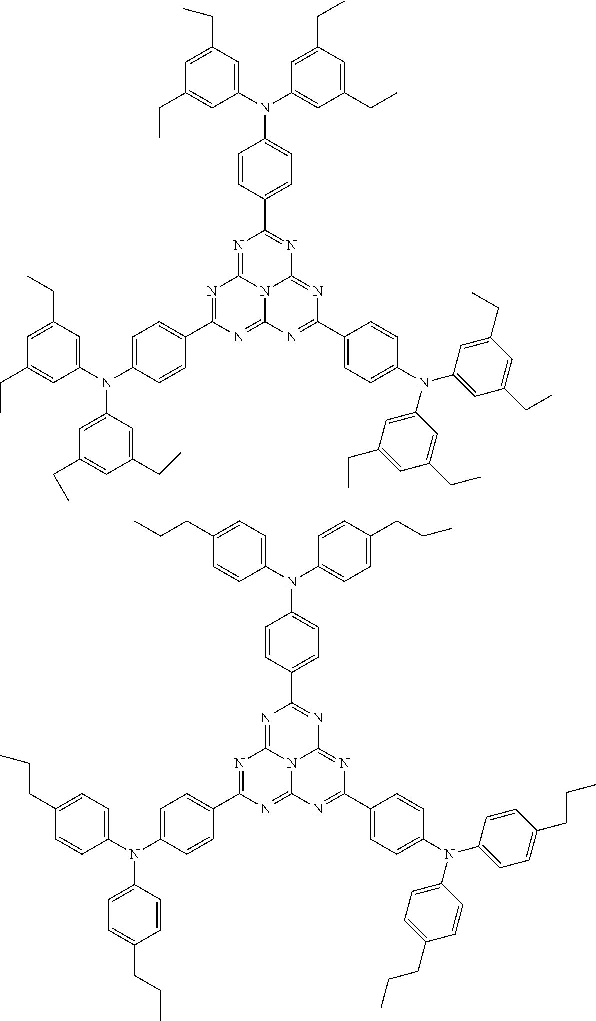

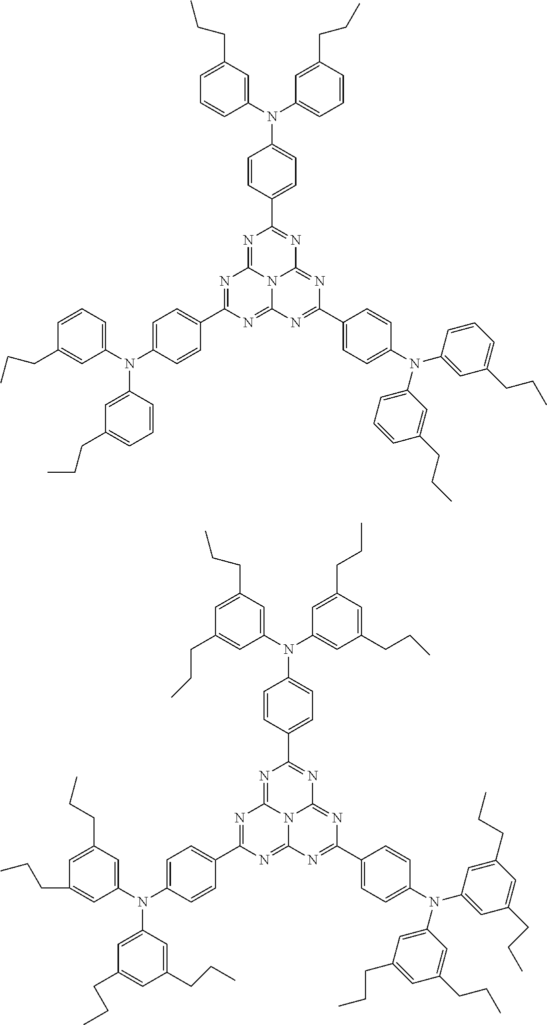

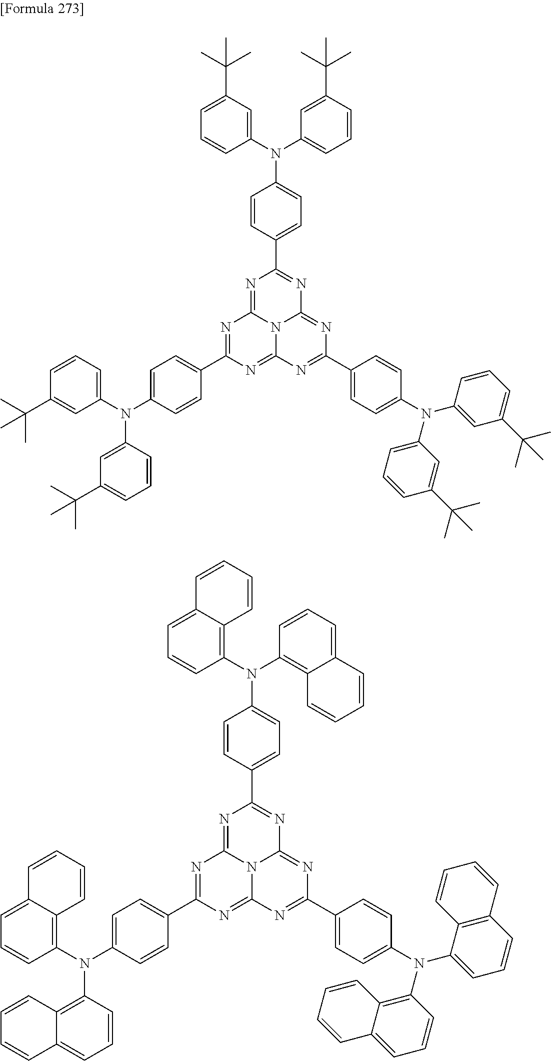 [SMILES: CC(C)(C)c1cccc(N(c2ccc(C3=NC4=NC(c5ccc(N(c6cccc(C(C)(C)C)c6)c6cccc(C(C)(C)C)c6)cc5)=NC5=NC(c6ccc(N(c7cccc(C(C)(C)C)c7)c7cccc(C(C)(C)C)c7)cc6)=NC(=N3)N45)cc2)c2cccc(C(C)(C)C)c2)c1 ; c1ccc2c(N(c3ccc(C4=NC5=NC(c6ccc(N(c7cccc8ccccc78)c7cccc8ccccc78)cc6)=NC6=NC(c7ccc(N(c8cccc9ccccc89)c8cccc9ccccc89)cc7)=NC(=N4)N56)cc3)c3cccc4ccccc34)cccc2c1]

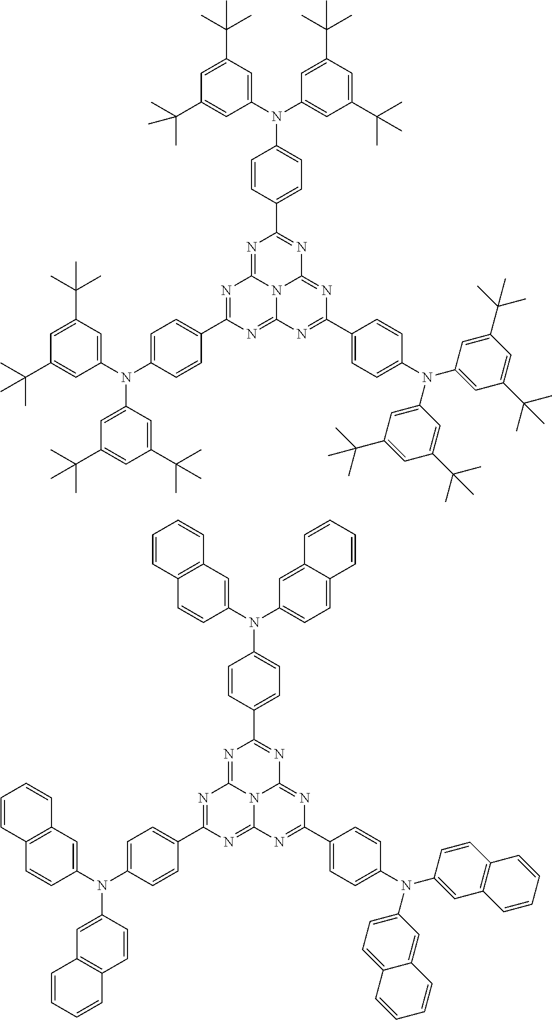

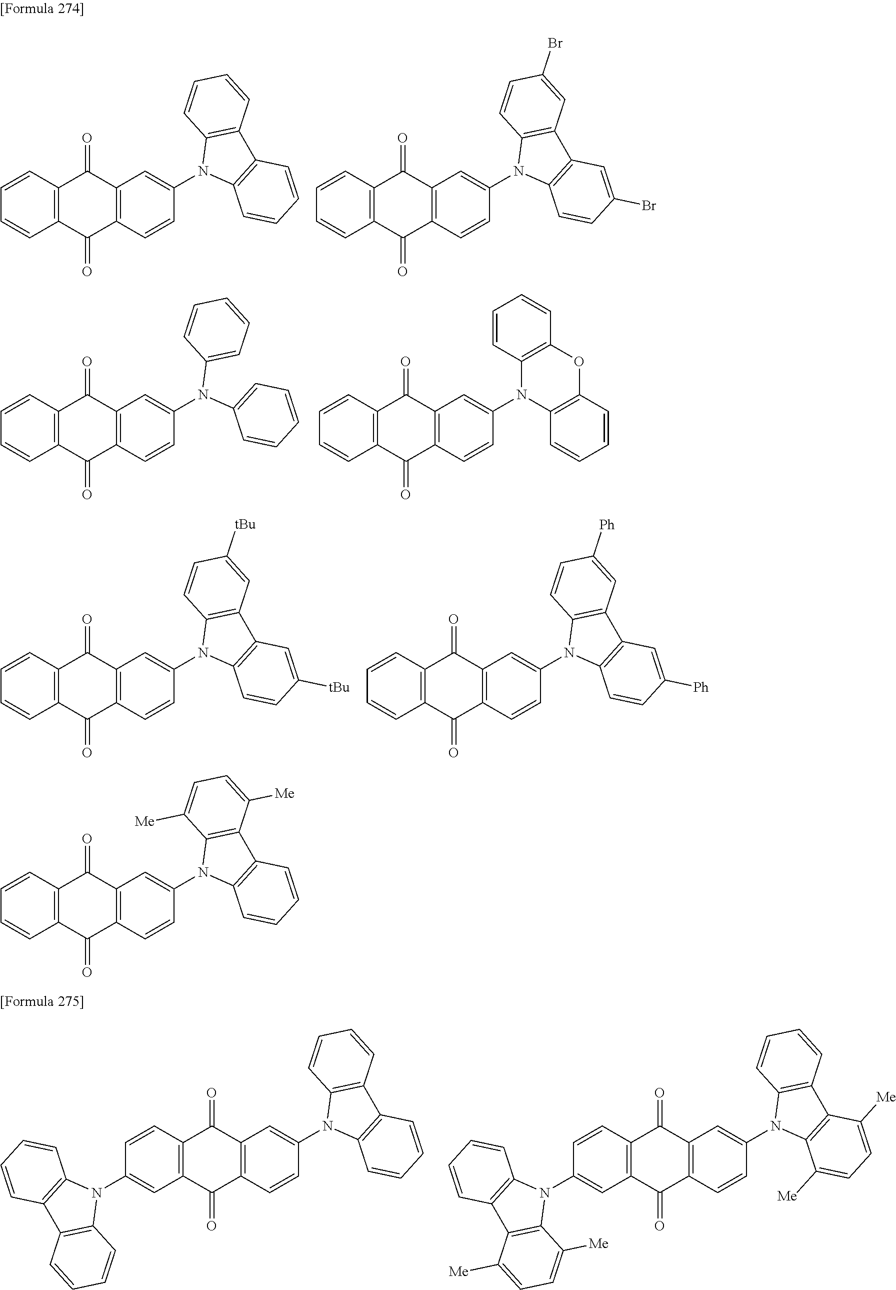

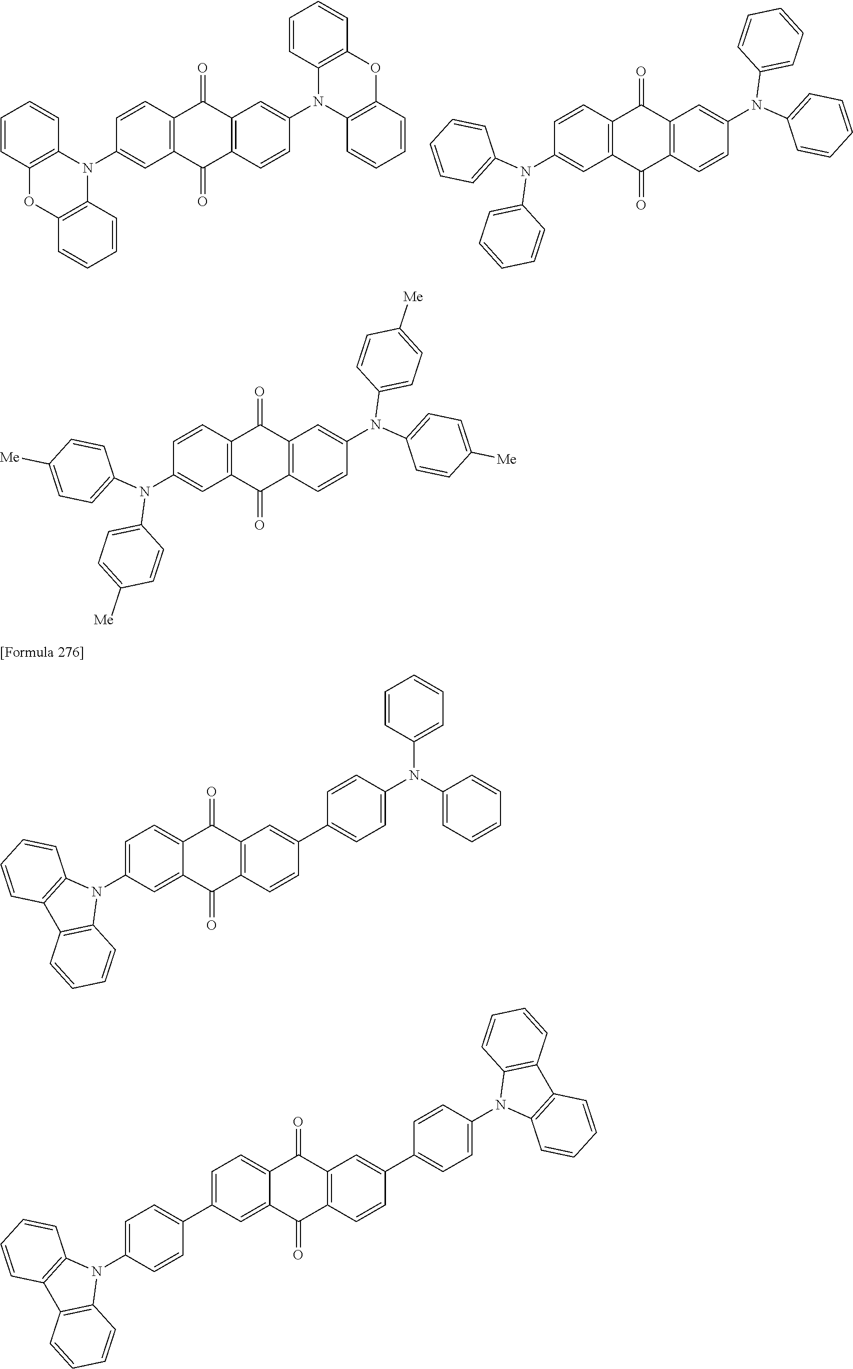

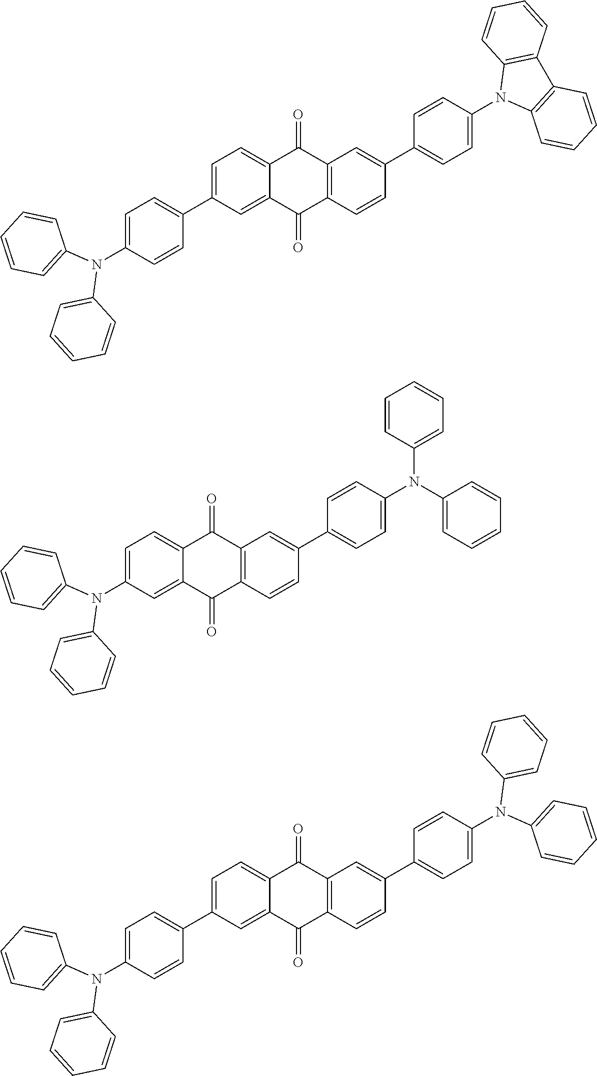 [SMILES: O=C1c2ccc(-c3ccc(-n4c5ccccc5c5ccccc54)cc3)cc2C(=O)c2ccc(-c3ccc(N(c4ccccc4)c4ccccc4)cc3)cc21 ; O=C1c2ccc(N(c3ccccc3)c3ccccc3)cc2C(=O)c2ccc(-c3ccc(N(c4ccccc4)c4ccccc4)cc3)cc21 ; O=C1c2ccc(-c3ccc(N(c4ccccc4)c4ccccc4)cc3)cc2C(=O)c2ccc(-c3ccc(N(c4ccccc4)c4ccccc4)cc3)cc21]

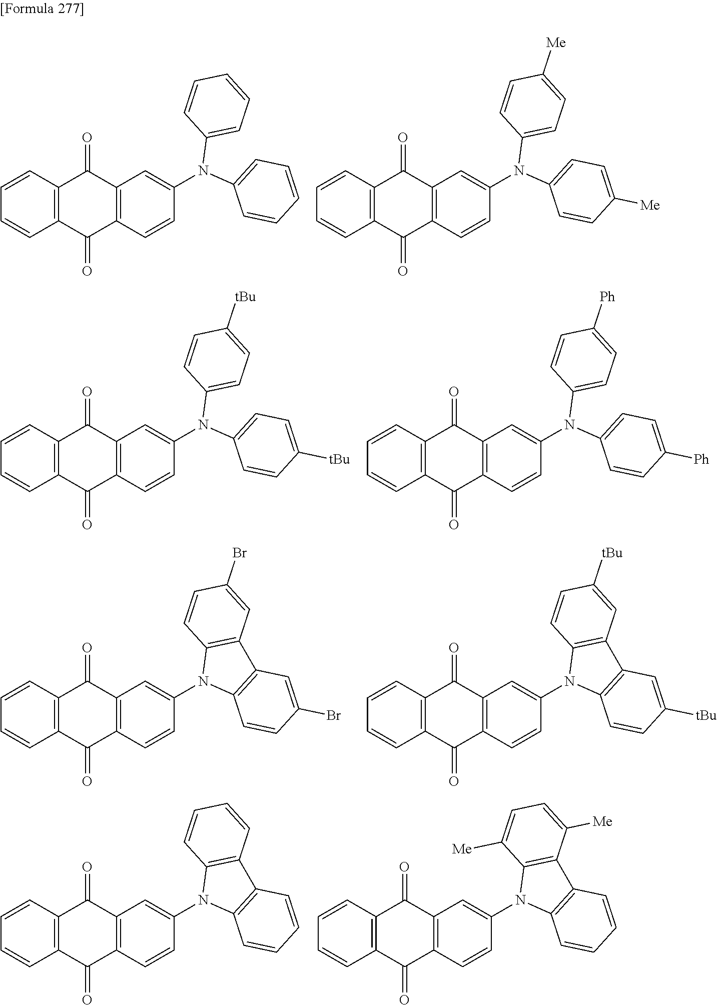

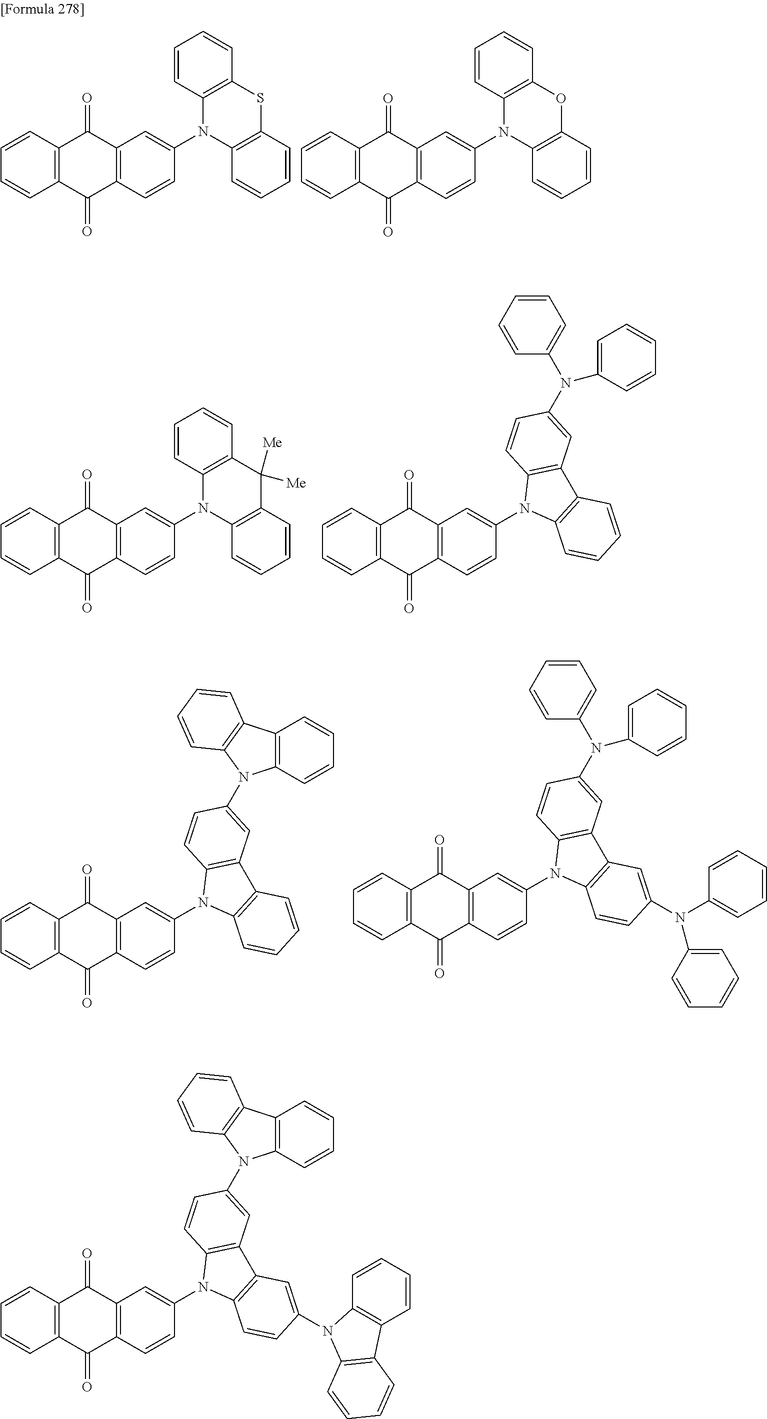

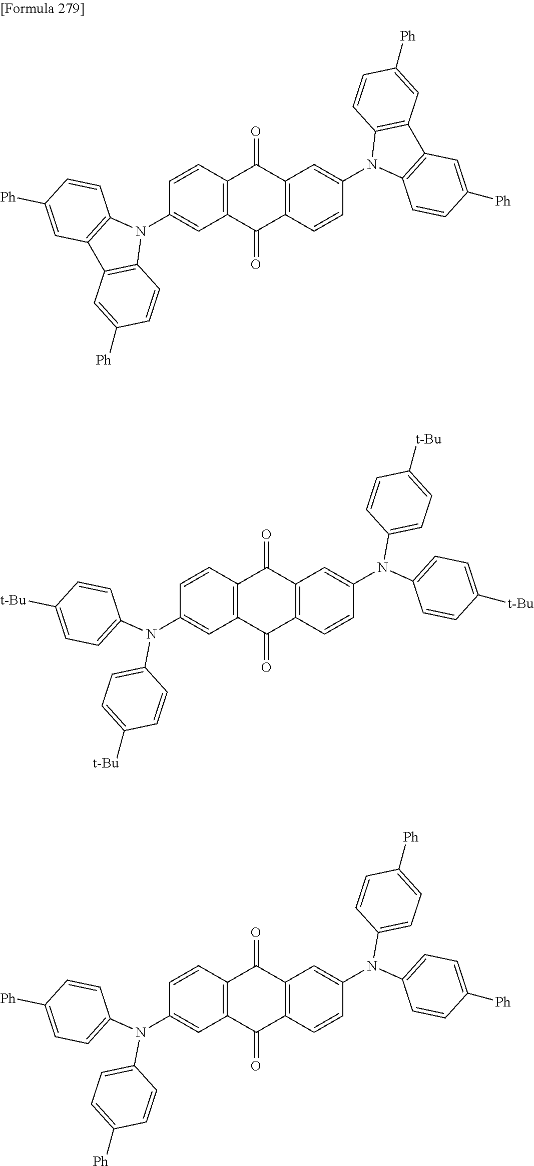 [SMILES: O=C1c2ccc(-n3c4ccc(-c5ccccc5)cc4c4cc(-c5ccccc5)ccc43)cc2C(=O)c2ccc(-n3c4ccc(-c5ccccc5)cc4c4cc(-c5ccccc5)ccc43)cc21 ; CC(C)(C)c1ccc(N(c2ccc(C(C)(C)C)cc2)c2ccc3c(c2)C(=O)c2ccc(N(c4ccc(C(C)(C)C)cc4)c4ccc(C(C)(C)C)cc4)cc2C3=O)cc1 ; O=C1c2ccc(N(c3ccc(-c4ccccc4)cc3)c3ccc(-c4ccccc4)cc3)cc2C(=O)c2ccc(N(c3ccc(-c4ccccc4)cc3)c3ccc(-c4ccccc4)cc3)cc21]

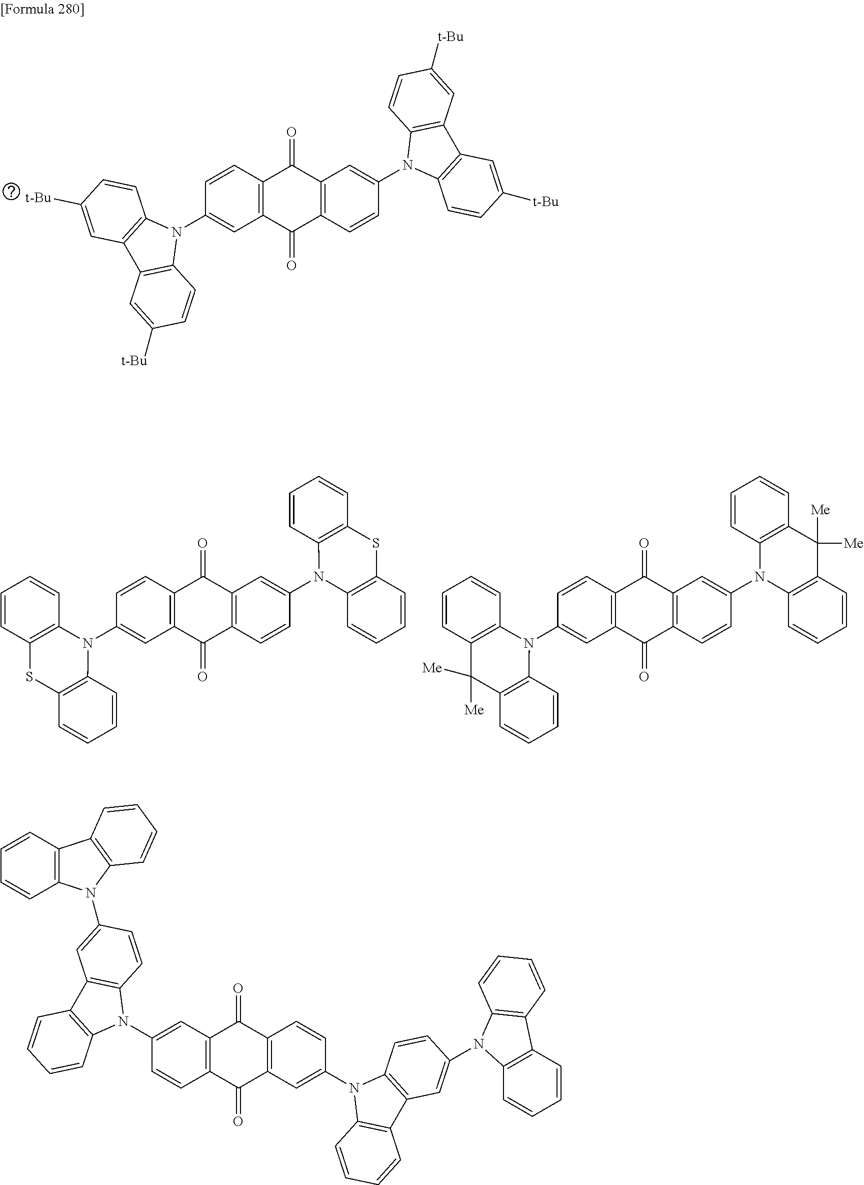

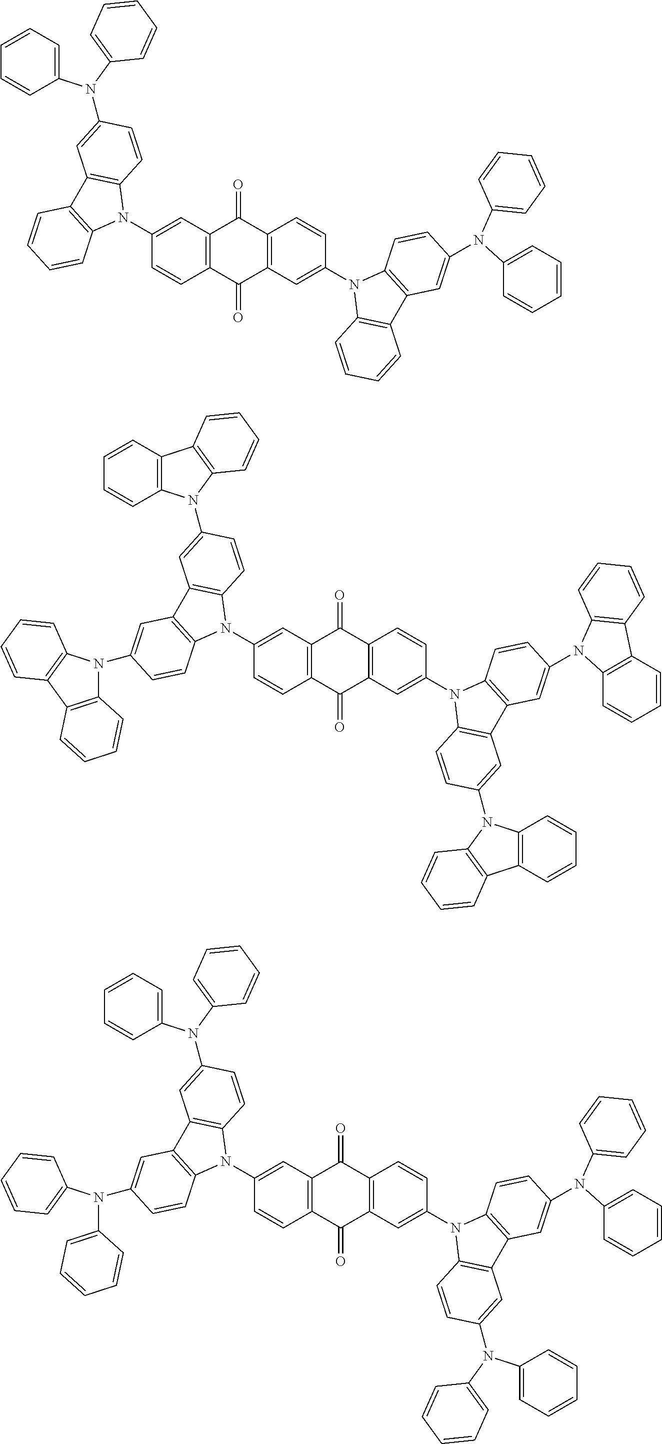 [SMILES: O=C1c2ccc(-n3c4ccccc4c4cc(N(c5ccccc5)c5ccccc5)ccc43)cc2C(=O)c2ccc(-n3c4ccccc4c4cc(N(c5ccccc5)c5ccccc5)ccc43)cc21 ; O=C1c2ccc(-n3c4ccc(-n5c6ccccc6c6ccccc65)cc4c4cc(-n5c6ccccc6c6ccccc65)ccc43)cc2C(=O)c2ccc(-n3c4ccc(-n5c6ccccc6c6ccccc65)cc4c4cc(-n5c6ccccc6c6ccccc65)ccc43)cc21 ; O=C1c2ccc(-n3c4ccc(N(c5ccccc5)c5ccccc5)cc4c4cc(N(c5ccccc5)c5ccccc5)ccc43)cc2C(=O)c2ccc(-n3c4ccc(N(c5ccccc5)c5ccccc5)cc4c4cc(N(c5ccccc5)c5ccccc5)ccc43)cc21]

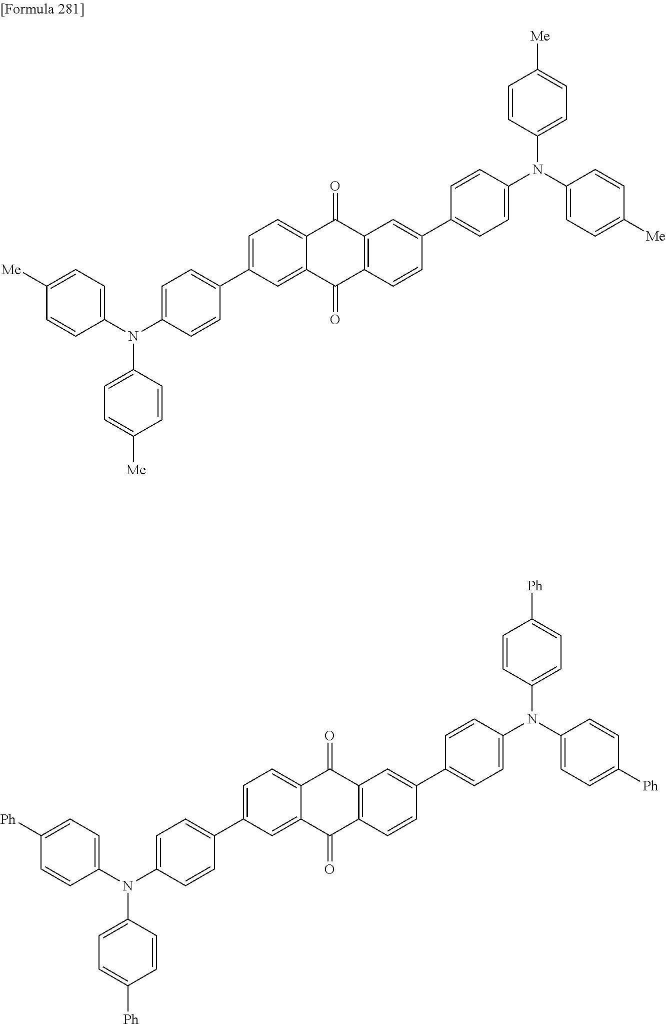 [SMILES: Cc1ccc(N(c2ccc(C)cc2)c2ccc(-c3ccc4c(c3)C(=O)c3ccc(-c5ccc(N(c6ccc(C)cc6)c6ccc(C)cc6)cc5)cc3C4=O)cc2)cc1 ; O=C1c2ccc(-c3ccc(N(c4ccc(-c5ccccc5)cc4)c4ccc(-c5ccccc5)cc4)cc3)cc2C(=O)c2ccc(-c3ccc(N(c4ccc(-c5ccccc5)cc4)c4ccc(-c5ccccc5)cc4)cc3)cc21]

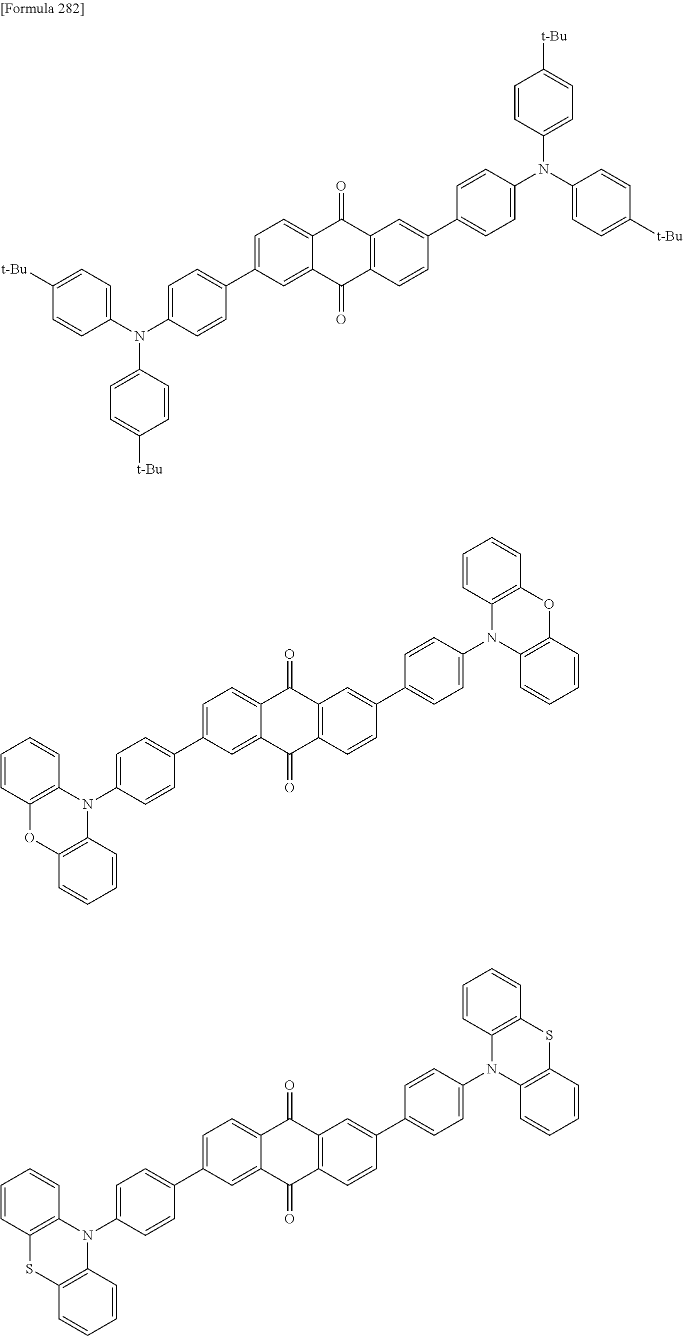 [SMILES: CC(C)(C)c1ccc(N(c2ccc(-c3ccc4c(c3)C(=O)c3ccc(-c5ccc(N(c6ccc(C(C)(C)C)cc6)c6ccc(C(C)(C)C)cc6)cc5)cc3C4=O)cc2)c2ccc(C(C)(C)C)cc2)cc1 ; O=C1c2ccc(-c3ccc(N4c5ccccc5Oc5ccccc54)cc3)cc2C(=O)c2ccc(-c3ccc(N4c5ccccc5Oc5ccccc54)cc3)cc21 ; O=C1c2ccc(-c3ccc(N4c5ccccc5Sc5ccccc54)cc3)cc2C(=O)c2ccc(-c3ccc(N4c5ccccc5Sc5ccccc54)cc3)cc21]

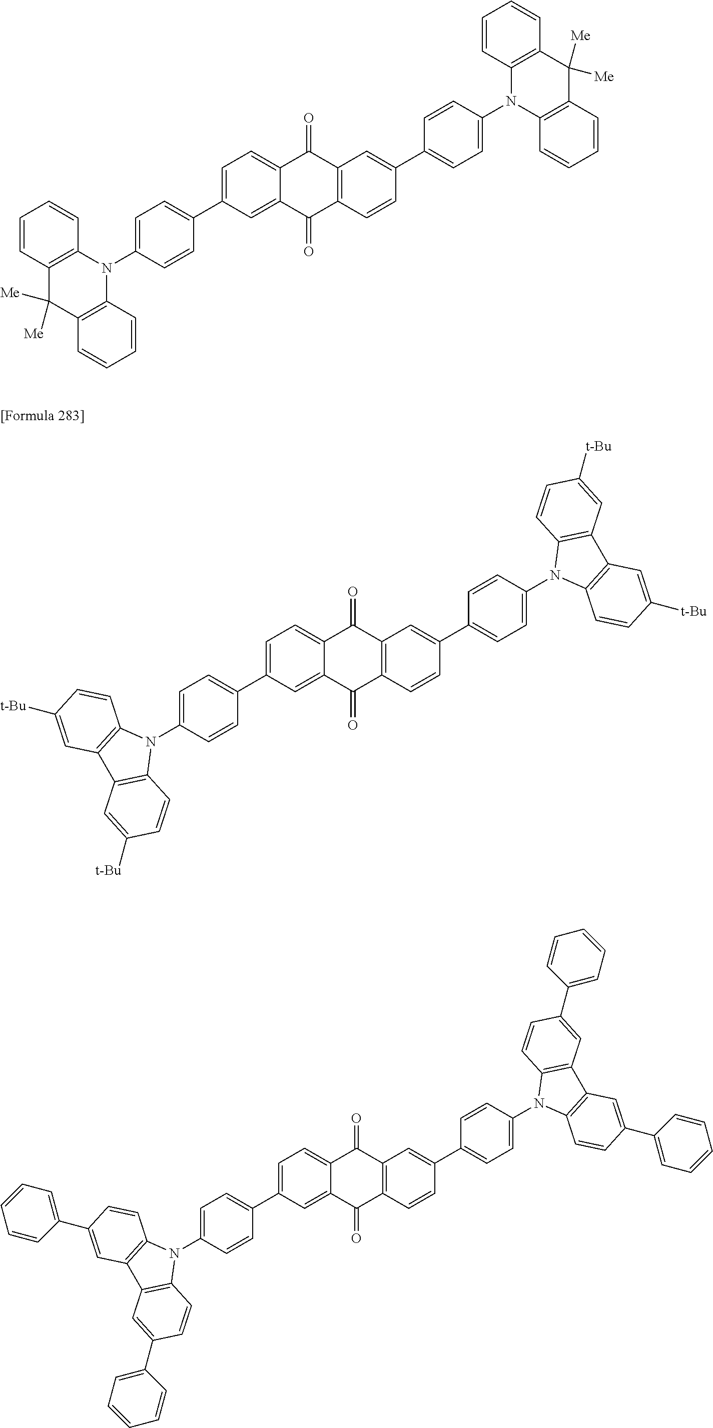 [SMILES: CC1(C)c2ccccc2N(c2ccc(-c3ccc4c(c3)C(=O)c3ccc(-c5ccc(N6c7ccccc7C(C)(C)c7ccccc76)cc5)cc3C4=O)cc2)c2ccccc21 ; CC(C)(C)c1ccc2c(c1)c1cc(C(C)(C)C)ccc1n2-c1ccc(-c2ccc3c(c2)C(=O)c2ccc(-c4ccc(-n5c6ccc(C(C)(C)C)cc6c6cc(C(C)(C)C)ccc65)cc4)cc2C3=O)cc1 ; O=C1c2ccc(-c3ccc(-n4c5ccc(-c6ccccc6)cc5c5cc(-c6ccccc6)ccc54)cc3)cc2C(=O)c2ccc(-c3ccc(-n4c5ccc(-c6ccccc6)cc5c5cc(-c6ccccc6)ccc54)cc3)cc21]

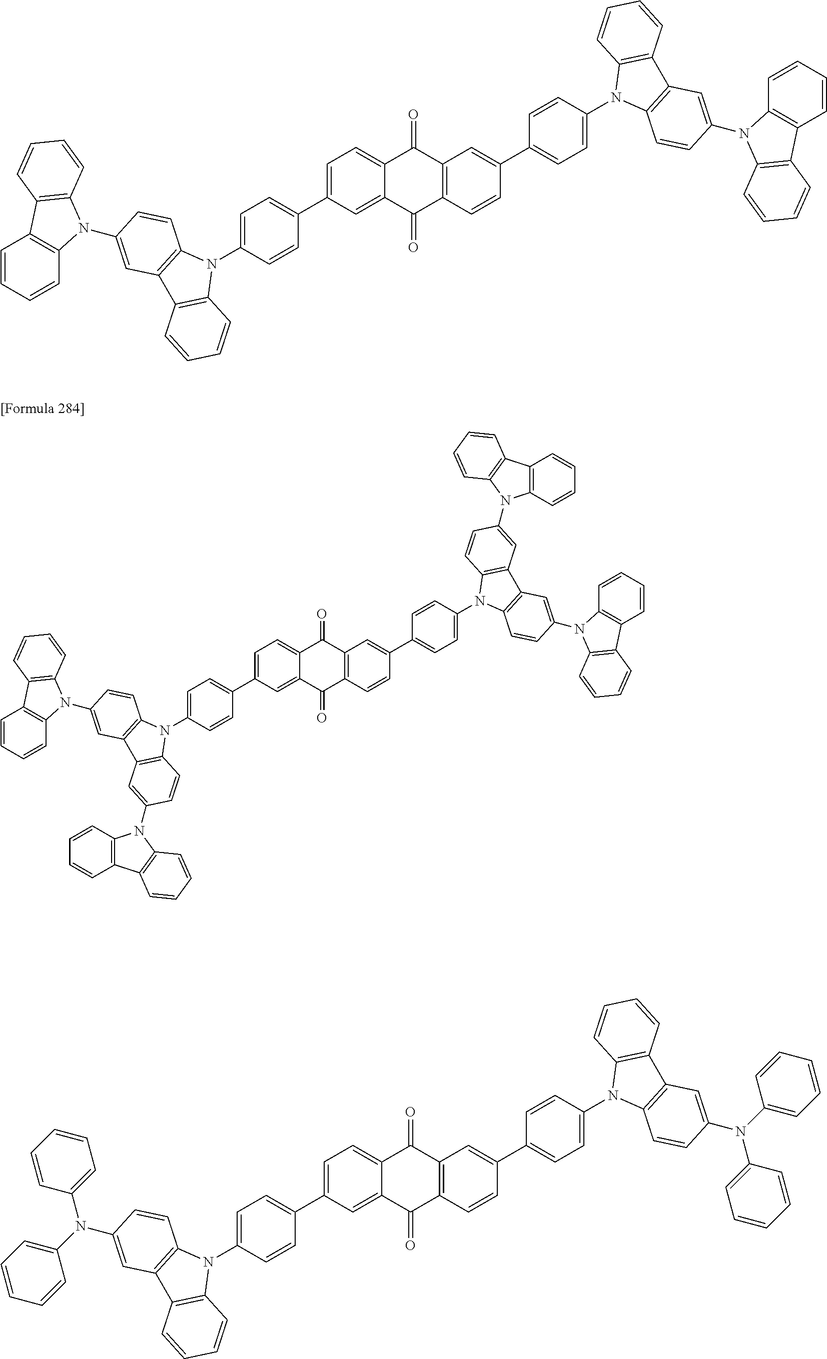 [SMILES: O=C1c2ccc(-c3ccc(-n4c5ccccc5c5cc(-n6c7ccccc7c7ccccc76)ccc54)cc3)cc2C(=O)c2ccc(-c3ccc(-n4c5ccccc5c5cc(-n6c7ccccc7c7ccccc76)ccc54)cc3)cc21 ; O=C1c2ccc(-c3ccc(-n4c5ccc(-n6c7ccccc7c7ccccc76)cc5c5cc(-n6c7ccccc7c7ccccc76)ccc54)cc3)cc2C(=O)c2ccc(-c3ccc(-n4c5ccc(-n6c7ccccc7c7ccccc76)cc5c5cc(-n6c7ccccc7c7ccccc76)ccc54)cc3)cc21 ; O=C1c2ccc(-c3ccc(-n4c5ccccc5c5cc(N(c6ccccc6)c6ccccc6)ccc54)cc3)cc2C(=O)c2ccc(-c3ccc(-n4c5ccccc5c5cc(N(c6ccccc6)c6ccccc6)ccc54)cc3)cc21]

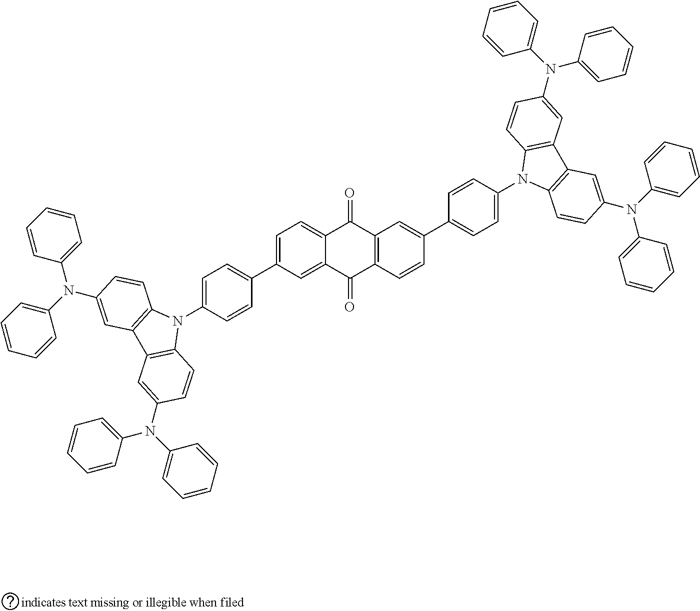 [SMILES: O=C1c2ccc(-c3ccc(-n4c5ccc(N(c6ccccc6)c6ccccc6)cc5c5cc(N(c6ccccc6)c6ccccc6)ccc54)cc3)cc2C(=O)c2ccc(-c3ccc(-n4c5ccc(N(c6ccccc6)c6ccccc6)cc5c5cc(N(c6ccccc6)c6ccccc6)ccc54)cc3)cc21]

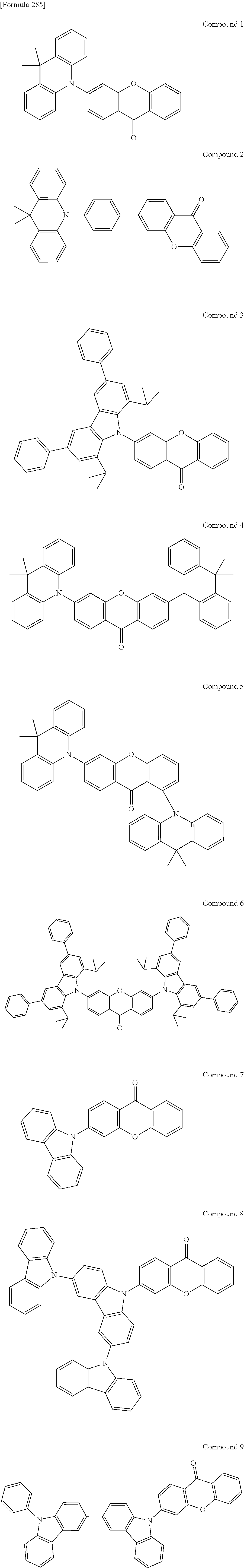

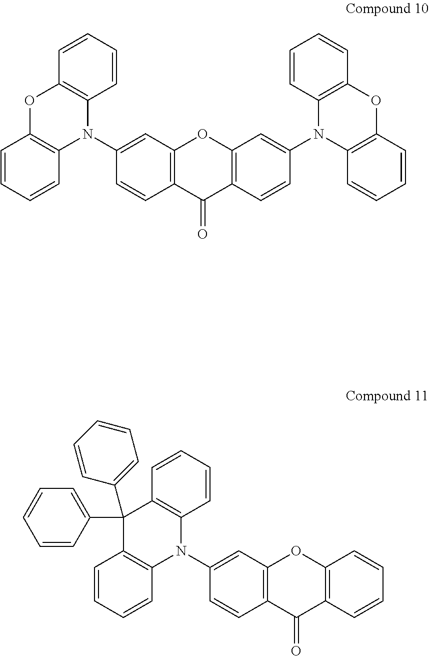 [SMILES: O=c1c2ccc(N3c4ccccc4Oc4ccccc43)cc2oc2cc(N3c4ccccc4Oc4ccccc43)ccc12 ; O=c1c2ccccc2oc2cc(N3c4ccccc4C(c4ccccc4)(c4ccccc4)c4ccccc43)ccc12]

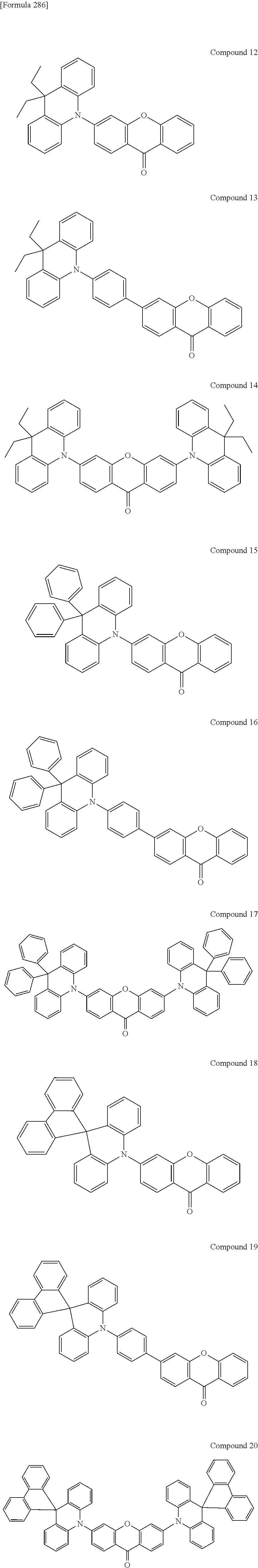

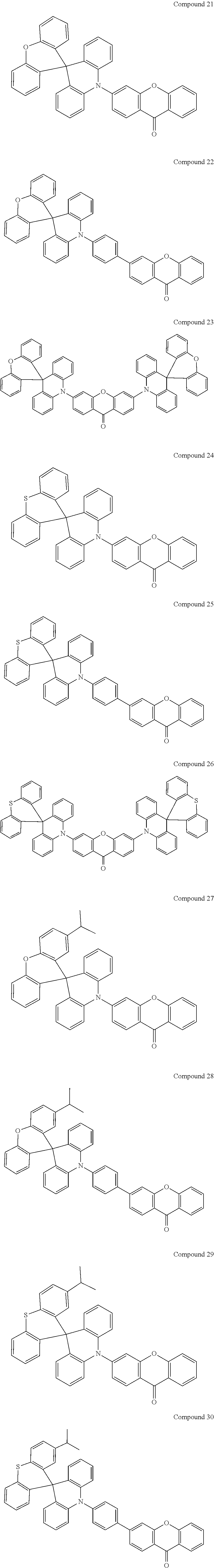

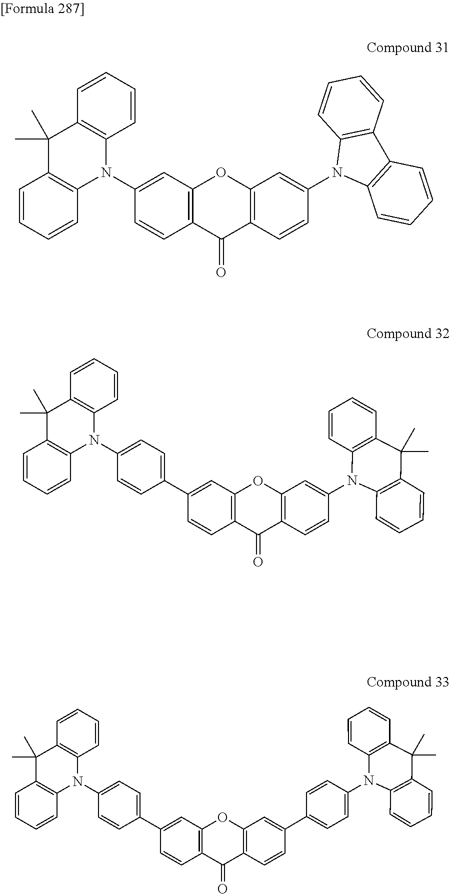

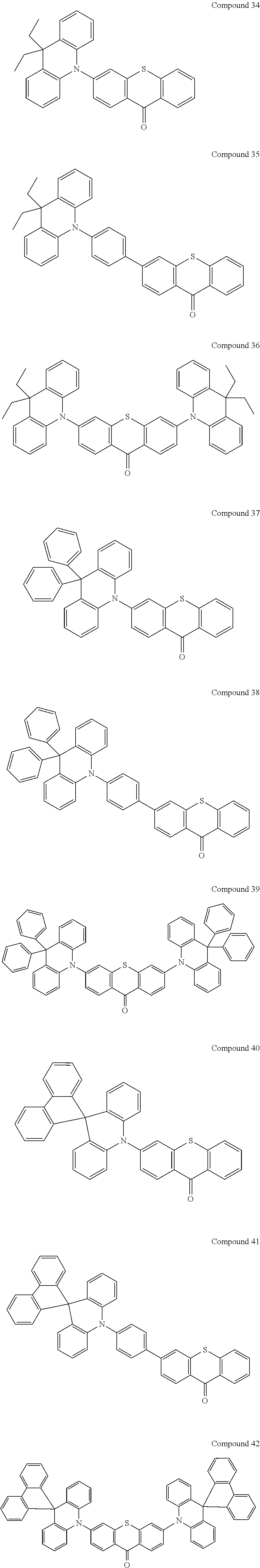

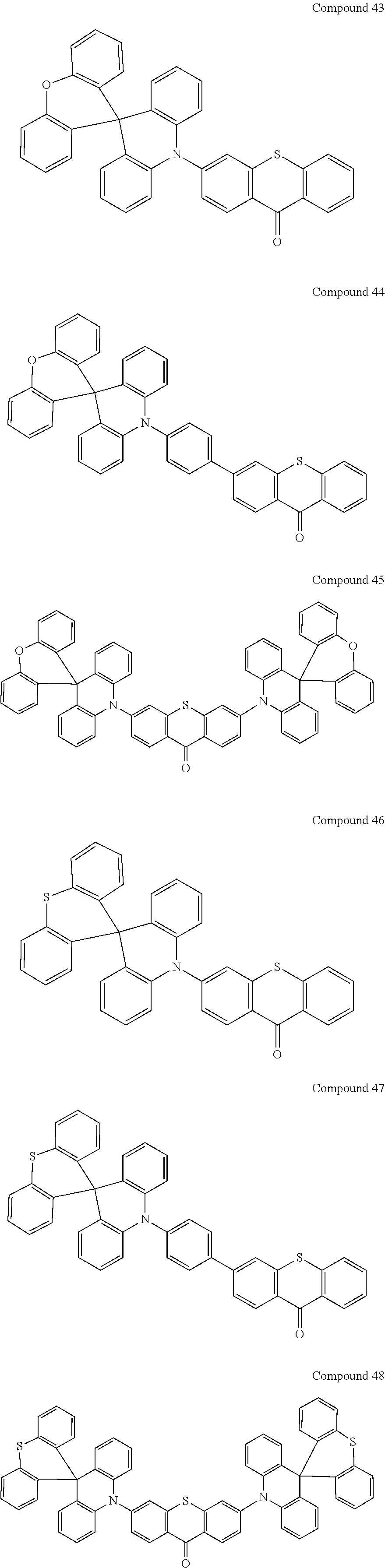

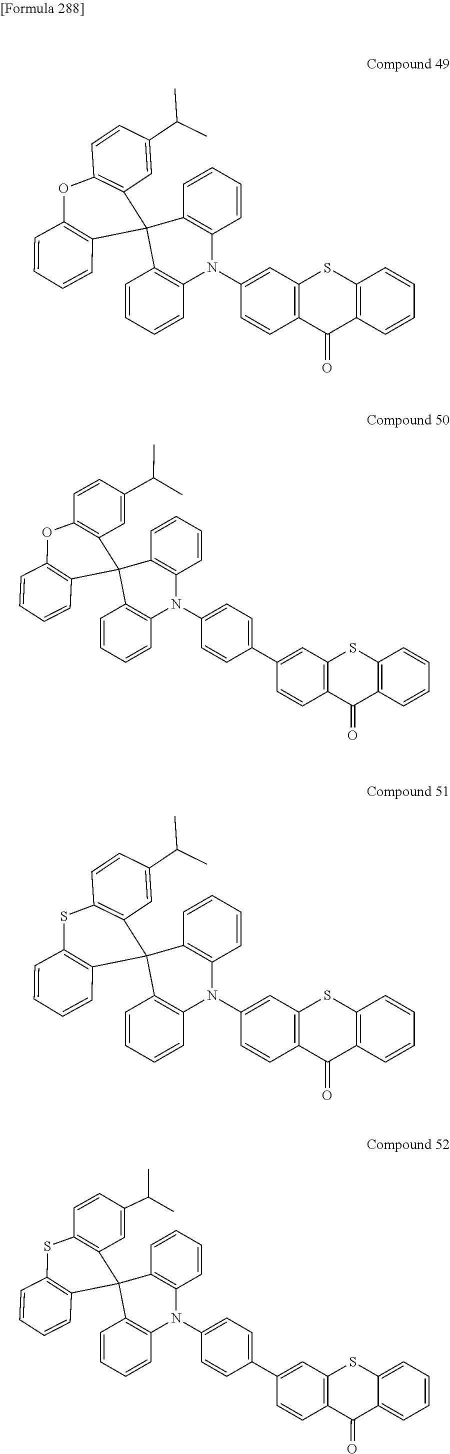 [SMILES: CC(C)c1ccc2c(c1)C1(c3ccccc3O2)c2ccccc2N(c2ccc3c(=O)c4ccccc4sc3c2)c2ccccc21 ; CC(C)c1ccc2c(c1)C1(c3ccccc3O2)c2ccccc2N(c2ccc(-c3ccc4c(=O)c5ccccc5sc4c3)cc2)c2ccccc21 ; CC(C)c1ccc2c(c1)C1(c3ccccc3S2)c2ccccc2N(c2ccc3c(=O)c4ccccc4sc3c2)c2ccccc21 ; CC(C)c1ccc2c(c1)C1(c3ccccc3S2)c2ccccc2N(c2ccc(-c3ccc4c(=O)c5ccccc5sc4c3)cc2)c2ccccc21]

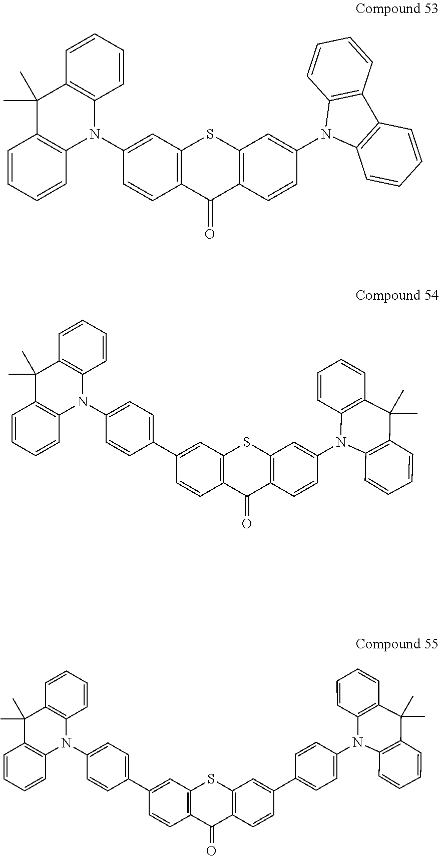

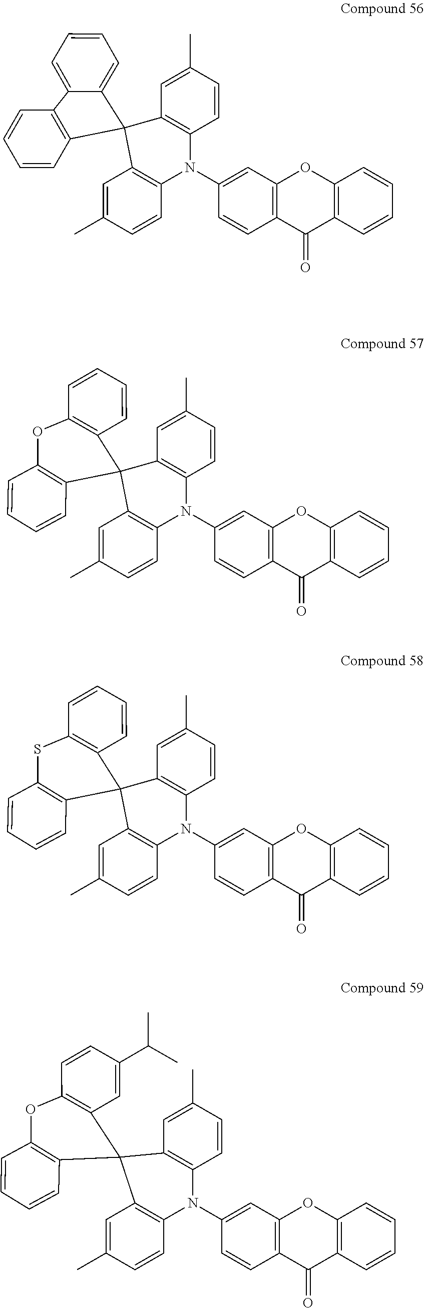 [SMILES: Cc1ccc2c(c1)C1(c3ccccc3-c3ccccc31)c1cc(C)ccc1N2c1ccc2c(=O)c3ccccc3oc2c1 ; Cc1ccc2c(c1)C1(c3ccccc3Oc3ccccc31)c1cc(C)ccc1N2c1ccc2c(=O)c3ccccc3oc2c1 ; Cc1ccc2c(c1)C1(c3ccccc3Sc3ccccc31)c1cc(C)ccc1N2c1ccc2c(=O)c3ccccc3oc2c1 ; Cc1ccc2c(c1)C1(c3ccccc3Oc3ccc(C(C)C)cc31)c1cc(C)ccc1N2c1ccc2c(=O)c3ccccc3oc2c1]

In an exemplary arrangement of the exemplary embodiment, the first sensitizing material is a delayed fluorescent material.

Delayed fluorescence will be described.

### Delayed Fluorescence

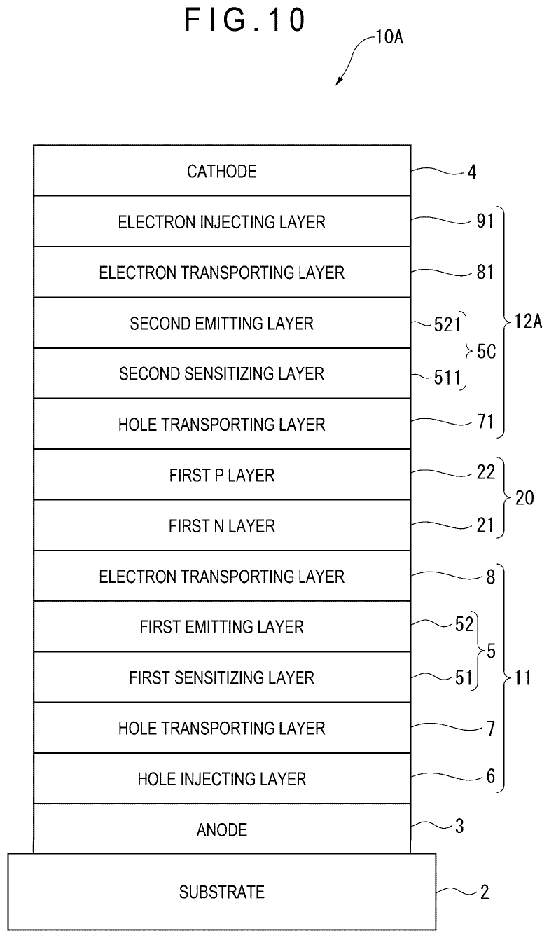

Delayed fluorescence is explained in “Yuki Hando-tai no Debaisu Bussei (Device Physics of Organic Semiconductors)” (edited by ADACHI, Chihaya, published by Kodansha, on pages 261-268). This literature describes that if an energy difference ΔE₁₃ between a singlet state and a triplet state of a fluorescent material can be made small, reverse energy transfer from the triplet state to the singlet state, which normally has a low transition probability, will occur with high efficiency, resulting in expressing thermally activated delayed fluorescence (TADF). Further, a generation mechanism of delayed fluorescence is explained in FIG. 10.38 in the literature.

The first sensitizing material of the exemplary embodiment is preferably a compound exhibiting thermally activated delayed fluorescence generated by this mechanism. In the exemplary embodiment, a compound exhibiting thermally activated delayed fluorescence functions as a sensitizing material.

In general, emission of delayed fluorescence can be confirmed by measuring transient PL (Photoluminescence).

The behavior of delayed fluorescence can also be analyzed based on the decay curve obtained from the transient PL measurement. The transient PL measurement is a method of irradiating a sample with a pulse laser to excite the sample, and measuring the decay behavior (transient characteristics) of PL emission after the irradiation is stopped. PL emission in TADF materials is classified into a light emission component from a singlet exciton generated by the first PL excitation and a light emission component from a singlet exciton generated via a triplet exciton. The lifetime of the singlet exciton generated by the first PL excitation is on the order of nanoseconds and is very short. Therefore, light emission from the singlet exciton rapidly attenuates after irradiation with the pulse laser.

On the other hand, the delayed fluorescence is gradually attenuated due to light emission from a singlet exciton generated via a triplet exciton having a long lifetime. As described above, there is a large temporal difference between the light emission from the singlet exciton generated by the first PL excitation and the light emission from the singlet exciton generated via the triplet exciton. Therefore, the luminous intensity derived from delayed fluorescence can be determined.

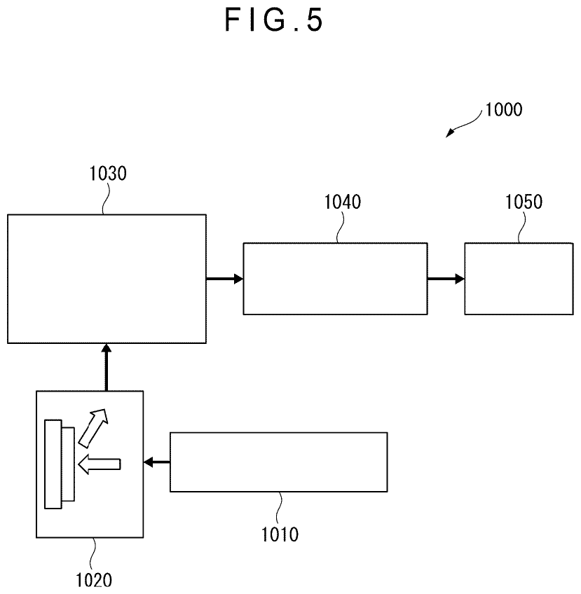

FIG. 5 is a schematic diagram of an exemplary apparatus for measuring the transient PL. A measurement method of the transient PL using the apparatus illustrated in FIG. 5 and an example of behavior analysis of the delayed fluorescence will be described.

A transient PL measuring apparatus 1000 in FIG. 5 includes: a pulse laser 1010 capable of radiating a light having a predetermined wavelength; a sample chamber 1020 configured to house a measurement sample; a spectrometer 1030 configured to divide a light radiated from the measurement sample; a streak camera 1040 configured to provide a two-dimensional image; and a personal computer 1050 configured to import and analyze the two-dimensional image. An apparatus for measuring the transient PL is not limited to the apparatus illustrated in FIG. 5.

The sample housed in the sample chamber 1020 is obtained by forming a thin film, in which a matrix material is doped with a doping material at a concentration of 12 mass %, on the quartz substrate.

The thin film sample housed in the sample chamber 1020 is irradiated with the pulse laser from the pulse laser 1010 to excite the doping material. Emission is extracted in a direction of 90 degrees with respect to a radiation direction of the excited light. The extracted emission is divided by the spectrometer 1030 to form a two-dimensional image in the streak camera 1040. As a result, the two-dimensional image is obtainable in which the ordinate axis represents a time, the abscissa axis represents a wavelength, and a bright spot represents a luminous intensity. When this two-dimensional image is taken out at a predetermined time axis, an emission spectrum in which the ordinate axis represents the luminous intensity and the abscissa axis represents the wavelength is obtainable. Moreover, when this two-dimensional image is taken out at the wavelength axis, a decay curve (transient PL) in which the ordinate axis represents a logarithm of the luminous intensity and the abscissa axis represents the time is obtainable.

For instance, a thin film sample A was prepared as described above from a reference compound H1 as the matrix material and a reference compound D1 as the doping material and was measured in terms of the transient PL.

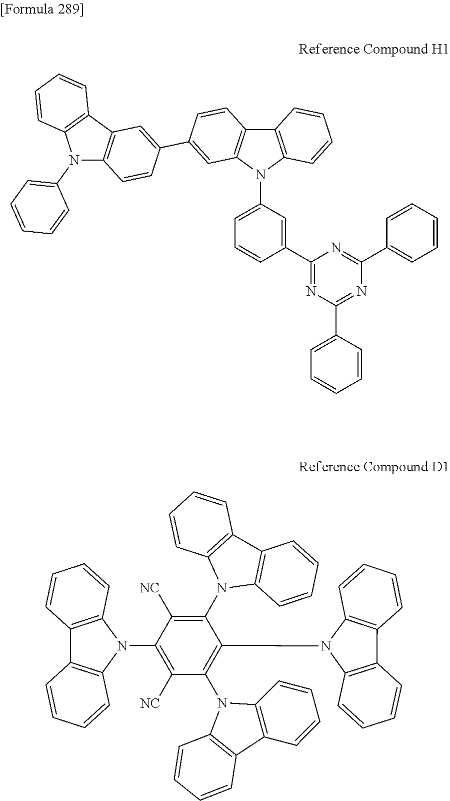 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

Here, decay curves obtained using the respective thin film samples A and B described above were analyzed. The thin film sample B was produced in the same manner as described above from a reference compound H2 as the matrix material and the reference compound D1 as the doping material.

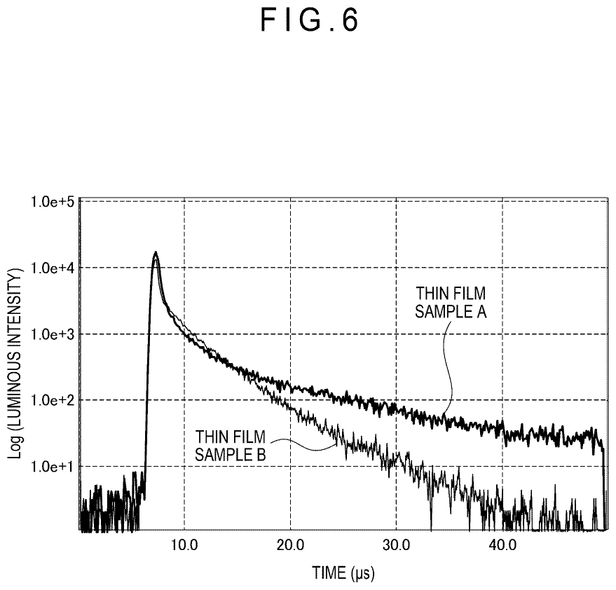

FIG. 6 illustrates decay curves obtained from the measured transient PL of the thin film samples A and B.

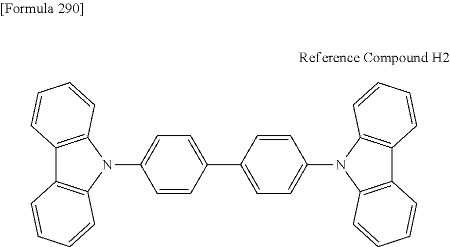 [SMILES: c1ccc2c(c1)c1ccccc1n2-c1ccc(-c2ccc(-n3c4ccccc4c4ccccc43)cc2)cc1]

As described above, an emission decay curve in which the ordinate axis represents the luminous intensity and the abscissa axis represents the time can be obtained by the transient PL measurement. Based on the emission decay curve, a fluorescence intensity ratio between fluorescence emitted from a singlet state generated by photo-excitation and delayed fluorescence emitted from a singlet state generated by reverse energy transfer via a triplet state can be estimated. In a delayed fluorescent material, a ratio of the intensity of the slowly decaying delayed fluorescence to the intensity of the promptly decaying fluorescence is relatively large.

Specifically, Prompt emission and Delay emission are present as emission from the delayed fluorescent material. Prompt emission is observed promptly when the excited state is achieved by exciting the compound of the exemplary embodiment with a pulse beam (i.e., a beam emitted from a pulse laser) having a wavelength absorbable by the delayed fluorescent material. Delay emission is observed not promptly when the excited state is achieved but after the excited state is achieved.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using an apparatus different from one described in Reference Document 1 or one shown in FIG. 5

In a case where the first sensitizing material is a delayed fluorescent material, delayed fluorescence is herein measured using a sample produced by a method described below. For instance, a measurement target compound (first sensitizing material) is dissolved in toluene to prepare a dilute solution with an absorbance of 0.05 or less at an excitation wavelength for removing the contribution of self-absorption. In order to prevent quenching due to oxygen, the sample solution is frozen and degassed and then sealed in a cell with a lid under an argon atmosphere to obtain an oxygen-free sample solution saturated with argon.

The fluorescence spectrum of the sample solution is measured with a spectrofluorometer FP-8600 (produced by JASCO Corporation), and the fluorescence spectrum of a 9,10-diphenylanthracene ethanol solution is measured under the same conditions. Using the fluorescence area intensities of both spectra, the total fluorescence quantum yield is calculated by an equation (1) in Morris et al. J. Phys. Chem. 80 (1976) 969.

In the exemplary embodiment, provided that the amount of Prompt emission of the measurement target compound (first sensitizing material) is denoted by X_{P} and the amount of Delay emission thereof is denoted by X_{D}, a value of X_{D}/X_{P} is preferably 0.05 or more.

An amount of Prompt emission and an amount of Delay emission of each of compounds other than the first sensitizing material and a ratio of the amounts of Prompt emission and Delay emission are also measured in the same manner as the amounts of Prompt emission and Delay emission of the first sensitizing material and the ratio thereof.

### ΔST

In the exemplary embodiment, a difference between the lowest singlet energy S₁ and an energy gap T_{77K} at 77 K is defined as ΔST.

Relationship between Triplet Energy and Energy Gap at 77K

Here, a relationship between a triplet energy and an energy gap at 77K will be described. In the exemplary embodiment, the energy gap at 77K is different from a typical triplet energy in some aspects.

The triplet energy is measured as follows. First, a solution in which a compound (measurement target) is dissolved in an appropriate solvent is encapsulated in a quartz glass tube to prepare a sample. A phosphorescence spectrum (ordinate axis: phosphorescent luminous intensity, abscissa axis: wavelength) of this sample is measured at a low temperature (77K). A tangent is drawn to the rise of the phosphorescence spectrum close to the short-wavelength region. A triplet energy is calculated by a predetermined conversion equation on a basis of a wavelength value at an intersection of the tangent and the abscissa axis.

Here, of the compounds in the exemplary embodiment, a compound exhibiting thermally activated delayed fluorescence is preferably a compound having a small ΔST. When ΔST is small, intersystem crossing and inverse intersystem crossing are likely to occur even at a low temperature (77K), so that the singlet state and the triplet state coexist. As a result, the spectrum to be measured in the same manner as the above includes emission from both the singlet state and the triplet state. Although it is difficult to distinguish from which state, the singlet state or the triplet state, light is emitted, the value of the triplet energy is basically considered dominant.

Accordingly, in the exemplary embodiment, the triplet energy is measured by the same method as a typical triplet energy T, but a value measured in the following manner is referred to as an energy gap T_{77K} in order to differentiate the measured energy from the typical triplet energy in a strict meaning. The measurement target compound is dissolved in EPA (diethylether:isopentane:ethanol=5:5:2 in volume ratio) at a concentration of 10 μmol/L, and the obtained solution is put in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value λ_{edge} [nm] at an intersection of the tangent and the abscissa axis. The calculated energy amount is defined as an energy T_{77K} at 77K.

$${T}_{77 K} [ eV ] = 1239 \text{.85} / {λ}_{edge} \qquad Conversion Equation ( F 1 )$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (manufactured by Hitachi High-Technologies Corporation) is usable. Any device for phosphorescence measurement is usable. A combination of a cooling unit, a low temperature container, an excitation light source and a light-receiving unit may be used for phosphorescence measurement.

### Lowest Singlet Energy S₁

A method of measuring the lowest singlet energy S₁ with use of a solution (occasionally referred to as a solution method) is exemplified by a method below.

A toluene solution of a measurement target compound at a concentration of 10 μmol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λedge (nm) at an intersection of the tangent and the abscissa axis is assigned to a conversion equation (F2) below to calculate the lowest singlet energy.

$${S}_{1} [ eV ] = 1239 \text{.85} / λedge \qquad Conversion Equation ( F 2 )$$

Any device for measuring absorption spectrum is usable. For instance, a spectrophotometer (U3310 manufactured by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In an exemplary arrangement of the exemplary embodiment, a delayed fluorescence ratio is more than 37.5% when the emitting region is caused to emit light.

The delayed fluorescence ratio that is more than 37.5% exceeds the theoretical upper limit of the ratio of delayed fluorescence (TTF ratio) assuming that delayed fluorescence occurs only by the TTF mechanism, thus achieving an organic EL device having higher internal quantum efficiency.

The delayed fluorescence ratio corresponds to a ratio of an emission intensity derived from delayed fluorescence to the total emission intensity. The delayed fluorescence ratio is derived using a calculation method below.

### Calculation Method for Delayed Fluorescence Ratio

A delayed fluorescence ratio is measurable by a transient EL method. The transient EL method is a technique to measure the decay behavior (transient characteristics) of EL emission after the pulse voltage applied to the device is removed. EL emission intensity is classified into two components: the emission component from singlet excitons produced by the initial recombination and the emission component from singlet excitons produced via triplet excitons. The lifetime of the singlet excitons produced in the initial recombination is on the order of nanoseconds, which is very short, and thus the emission decays quickly after the pulse voltage is removed.

On the other hand, delayed fluorescence, which is emission from the singlet excitons produced via long-life triplet excitons, decays slowly. Since there is a large temporal difference between the emission from the singlet excitons produced by the initial recombination and the emission from the singlet excitons produced via the triplet excitons, the intensity of the delayed fluorescence-derived emission can be obtained. Specifically, the intensity of the delayed fluorescence-derived emission can be determined by a method below.

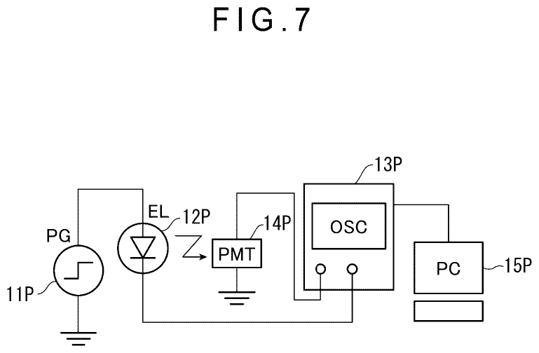

A transient EL waveform is measured as follows (see FIG. 7). A pulse voltage waveform output from a voltage pulse generator (PG) 11 is applied to an organic EL device (EL) 12. The applied voltage waveform is imported into an oscilloscope (OSC) 13P. When a pulse voltage is applied to an organic EL device 12P, the organic EL device 12P produces pulsed emission. This emission is imported into the oscilloscope (OSC) 13P via a photomultiplier tube (PMT) 14P. The voltage waveform and the pulsed emission are synchronized and imported into a personal computer (PC)15P.

By analyzing the transient EL waveform, a ratio of an intensity of the delayed fluorescence-derived emission (delayed fluorescence ratio herein) is defined as follows. The formula for calculating the TTF ratio described in International Publication No. 2010/134352 can be used for calculating the delayed fluorescence-derived emission intensity ratio.

The delayed fluorescence ratio is calculated using a numerical formula (4).

$$\frac{1}{\sqrt{I}} ∝ A + γ \cdot t \qquad ( 4 )$$

In the numerical formula (4), I represents an intensity of the delayed fluorescence-derived emission and A represents a constant. The measured transient EL waveform data is fitted in the numerical formula (4) to obtain the constant A. The emission intensity 1/A² at time t=0, when the pulse voltage is removed, is defined as an intensity ratio of the delayed fluorescence-derived emission.

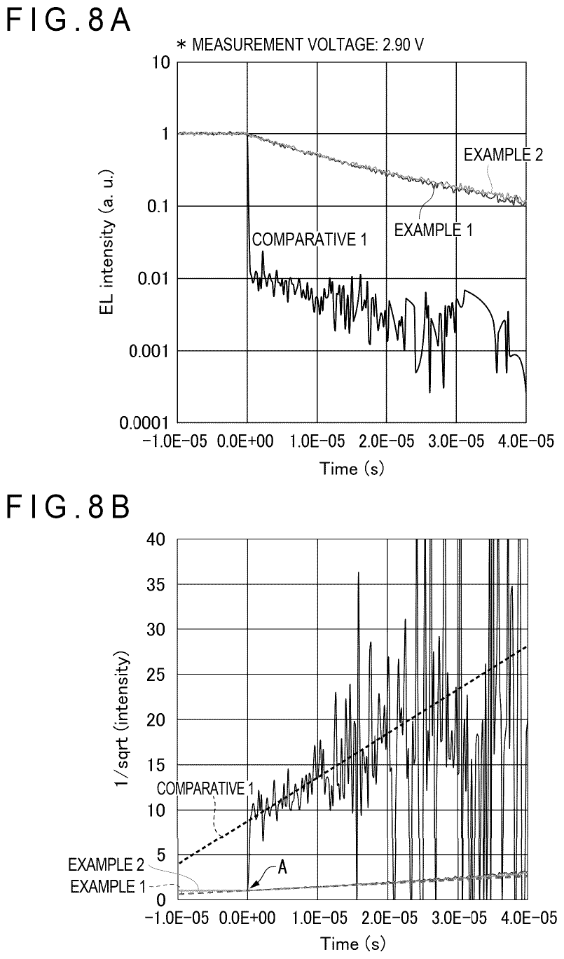

The graph in FIG. 8A illustrates an example of measuring the transient EL waveform when a predetermined pulse voltage is applied to the organic EL devices in Examples 1, 2, and Comparative 1 described below and then the voltage is removed, illustrating a change over time in the emission intensity of each of the organic EL devices.

In the graph in FIG. 8A, the time when the pulse voltage is removed is taken as an origin. The graph in FIG. 8A expresses the luminance when the voltage is removed as 1. A slowly decaying component appears until about 4.0E-05 seconds elapsed after the pulse voltage removal.

The graph in FIG. 8B plots the inverse of the square root of the emission intensity up to 4.0.E-05 seconds elapsed after the pulse voltage removal for the organic EL devices in Examples 1, 2, and Comparative 1, taking the point of the pulse voltage removal as the origin. Fitting is conducted as follows.

For instance, in the case of the organic EL device in Example 1, a value at an intersection point A with the vertical axis when the straight line portion is extended to the time origin is 0.9996. Then, the delayed fluorescence-derived emission intensity ratio obtained from this transient EL waveform exceeds 1/(0.9996)²=0.99. In other words, the emission intensity ratio exceeding 99% means one derived from delayed fluorescence. That is, the delayed fluorescence-derived emission intensity ratio exceeds 37.5% that is considered as the theoretical limit of TTF ratio. A delayed fluorescence-derived emission intensity ratio of each of the organic EL devices produced in Example 2 and Comparative 1 was calculated in the same manner as in Example 1.

Fitting to a straight line is preferably done by the least-squares method. In this case, fitting is preferably done with values ranging from 1.0.E-06 seconds to 1.0E-05 seconds.

### First Emitting Layer

The first emitting layer includes a second host material and a first luminescent compound.

The second host material is a compound different from the first host material. The first luminescent compound is a compound different from the first sensitizing material.

The second host material is exemplified by a compound selected from the group consisting of a first compound and a second compound described below.

The first luminescent compound is exemplified by at least one compound selected from the group consisting of a fluorescent material described below and compounds represented by formulae (5), (6), and (3A).

In an exemplary arrangement of the exemplary embodiment, the first luminescent compound is a compound emitting light having a maximum peak wavelength in a range from 430 nm to 480 nm.

In an exemplary arrangement of the exemplary embodiment, the first luminescent compound is a fluorescent compound emitting fluorescence having a maximum peak wavelength of 500 nm or less.

In an exemplary arrangement of the exemplary embodiment, the first luminescent compound is a fluorescent compound emitting fluorescence having a maximum peak wavelength in a range from 430 nm to 480 nm.

In an exemplary arrangement of the exemplary embodiment, an energy gap T_{77K}(D₁) at 77 K of the first luminescent compound and an energy gap T_{77K}(H2) at 77K of the second host material satisfy a relationship represented by a numerical formula (Numerical Formula 21B) below.

$${T}_{77 K} ( D 1 ) > {T}_{77 K} ( H 2 ) \qquad ( Numerical Formula 21 B )$$

When the first luminescent compound and the second host material satisfy the relationship of the numerical formula (Numerical Formula 21B), in transfer of triplet excitons generated in the first sensitizing layer to the first emitting layer, the triplet excitons energy-transfer not onto the first luminescent compound having higher triplet energy but onto molecules of the second host material.

In addition, triplet excitons generated by recombination of holes and electrons on the second host material do not transfer to the first luminescent compound having higher triplet energy. Triplet excitons generated by recombination on molecules of the first luminescent compound quickly energy-transfer to molecules of the second host material.

Triplet excitons in the second host material do not transfer to the first luminescent compound but efficiently collide with one another on the second host material to generate singlet excitons by the TTF phenomenon.

In an exemplary arrangement of the exemplary embodiment, a lowest singlet energy S₁(H2) of the second host material and a lowest singlet energy S₁(D₁) of the first luminescent compound satisfy a relationship of a numerical formula (Numerical Formula 22B) below.

$${S}_{1} ( H 2 ) > {S}_{1} ( D 1 ) \qquad ( Numerical Formula 22 B )$$

When the first luminescent compound and the second host material satisfy the relationship of the numerical formula (Numerical formula 22B), due to the lowest singlet energy S₁ of the first luminescent compound being smaller than the lowest singlet energy S₁ of the second host material, singlet excitons generated by the TTF phenomenon energy-transfer from the second host material to the first luminescent compound, thereby contributing to fluorescence of the first luminescent compound.

In an exemplary arrangement of the exemplary embodiment, the first luminescent compound is a compound containing no azine ring structure in a molecule.

In an exemplary arrangement of the exemplary embodiment, the first luminescent compound is not a complex.

In an exemplary arrangement of the exemplary embodiment, the first emitting layer contains no metal complex.

In an exemplary arrangement of the exemplary embodiment, the first emitting layer contains no phosphorescent material (dopant material).

In an exemplary arrangement of the exemplary embodiment, the first emitting layer contains no heavy-metal complex and no phosphorescent rare earth metal complex. Examples of the heavy-metal complex herein include iridium complex, osmium complex, and platinum complex.

In an exemplary arrangement of the exemplary embodiment, the first emitting layer contains 0.5 mass % or more, or 1 mass % or more, of the first luminescent compound with respect to a total mass of the first emitting layer.

In an exemplary arrangement of the exemplary embodiment, the first emitting layer contains 10 mass % or less, 7 mass % or less, or 5 mass % or less, of the first luminescent compound with respect to the total mass of the first emitting layer.

In an exemplary arrangement of the exemplary embodiment, the first emitting layer contains 60 mass % or more, 70 mass % or more, 80 mass % or more, 90 mass % or more, or 95 mass % or more, of the second host material with respect to the total mass of the first emitting layer.

In an exemplary arrangement of the exemplary embodiment, the first emitting layer contains 99 mass % or less of the second host material with respect to the total mass of the first emitting layer.

In an exemplary arrangement of the exemplary embodiment, the upper limit of the total of the content ratios of the second host material and the first luminescent compound in the first emitting layer is 100 mass %.

In an exemplary arrangement of the exemplary embodiment, a film thickness of the first emitting layer is 5 nm or more, or 10 nm or more. When the film thickness of the first emitting layer is 5 nm or more, it is easy to inhibit triplet excitons having transferred from the first sensitizing layer to the first emitting layer from returning to the first sensitizing layer. Further, when the film thickness of the first emitting layer is 5 nm or more, triplet excitons can be sufficiently separated from the recombination portion in the first sensitizing layer.

In an exemplary arrangement of the exemplary embodiment, the film thickness of the first emitting layer is 20 nm or less. With the film thickness of the first emitting layer of 20 nm or less, a density of triplet excitons in the first emitting layer is improvable to further facilitate occurrence of the TTF phenomenon.

### First Host Material and Second Host Material

In an exemplary arrangement of the exemplary embodiment, the first host material and the second host material are exemplified by the first compound represented by a formula (1) below, the first compound represented by a formula (1X), (12X), (13X), (14X), (15X), or (16X) below, and the second compound represented by a formula (2) below. Alternatively, the first compound is usable as the first host material and the second host material. In this case, the compound represented by the formula (1), (1X), (12X), (13X), (14X), (15X), or (16X) used as the second host material is sometimes referred to as the second compound for convenience.

In an exemplary arrangement of the exemplary embodiment, the first host material is selected from the first compounds represented by the formulae (1), (1X), (12X), (13X), (14X), (15X), and (16X).

In an exemplary arrangement of the exemplary embodiment, the second host material is selected from a second compound represented by a formula (2) below.

### First Compound

In an exemplary arrangement of the exemplary embodiment, the first compound is a compound represented by the formula (1), (1X), (12X), (13X), (14X), (15X), or (16X) below.

### Compound Represented by Formula (1)

In an exemplary arrangement of the exemplary embodiment, the first compound is also preferably a compound represented by the formula (1) below. The first compound represented by the formula (1) has at least one group represented by a formula (11) below.

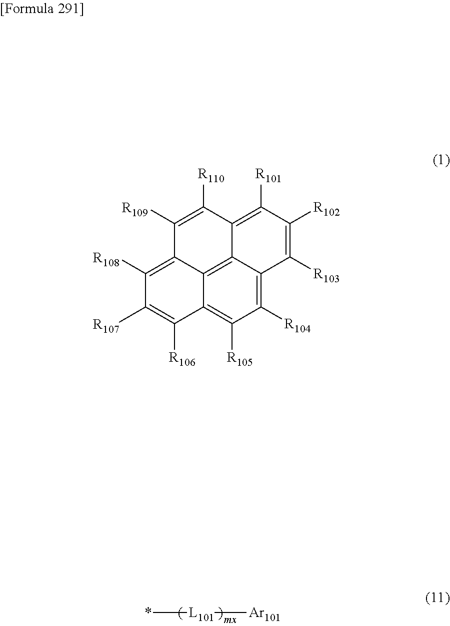

In the formula (1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (11);
at least one of R₁₀₁ to R₁₁₀ is a group represented by the formula (11);
when a plurality of groups represented by the formula (11) are present, the plurality of groups represented by the formula (11) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (11) represents a bonding position to a pyrene ring in the formula (1).

In the first compound represented by the formula (1), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary embodiment, Ar₁₀₁ is preferably a substituted or unsubstituted aryl group having 6 to 50 carbon atoms.

In an exemplary embodiment, Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted pyrenyl group, a substituted or unsubstituted phenanthryl group, or a substituted or unsubstituted fluorenyl group.

In an exemplary embodiment, the first compound is preferably represented by a formula (101) below.

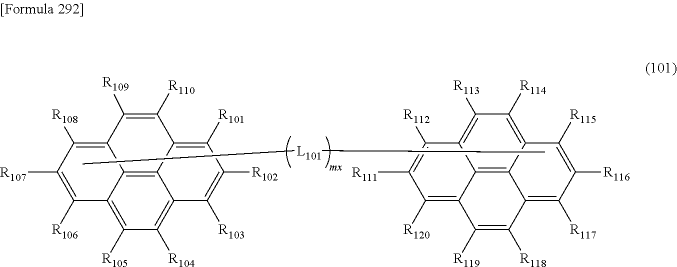

In the formula (101):
R₁₀₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
one of R₁₀₁ to R₁₁₀ represents a bonding position to L₁₀₁, and one of R₁₁₁ to R₁₂₀ represents a bonding position to L₁₀₁;
L₁₀₁ is a single bond, a substituted or unsubstituted arylene group having 6 to 50 ring carbon atoms, or a substituted or unsubstituted divalent heterocyclic group having 5 to 50 ring atoms;
mx is 0, 1, 2, 3, 4, or 5; and
when two or more L₁₀₁ are present, the two or more L₁₀₁ are mutually the same or different.

In an exemplary embodiment, L₁₀₁ is preferably a single bond or a substituted or unsubstituted arylene group having 6 to 50 ring carbon atoms.

In an exemplary embodiment, two or more of R₁₀₁ to R₁₁₀ are each preferably a group represented by the formula (11).

In an exemplary embodiment, it is preferable that two or more of R₁₀₁ to R₁₁₀ are each a group represented by the formula (11) and Ar₁₀₁ is a substituted or unsubstituted aryl group having 6 to 50 ring carbon atoms.

In an exemplary embodiment, it is preferable that Ar₁₀₁ is not a substituted or unsubstituted pyrenyl group, L₁₀₁ is not a substituted or unsubstituted pyrenylene group, and the substituted or unsubstituted aryl group having 6 to 50 ring carbon atoms for R₁₀₁ to R₁₁₀ not being the group represented by the formula (11) is not a substituted or unsubstituted pyrenyl group.

In an exemplary embodiment, R₁₀₁ to R₁₁₀ not being the group represented by the formula (11) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary embodiment, R₁₀₁ to R₁₁₀ not being the group represented by the formula (11) are preferably each independently a hydrogen atom, a substituted or unsubstituted alkyl group having 1 to 50 carbon atoms, or a substituted or unsubstituted cycloalkyl group having 3 to 50 ring carbon atoms.

In an exemplary embodiment, R₁₀₁ to R₁₁₀ not being the group represented by the formula (11) are each preferably a hydrogen atom.

### Compound Represented by Formula (1X)

In an exemplary arrangement of the exemplary embodiment, the first compound is also preferably a compound represented by a formula (1X) below.

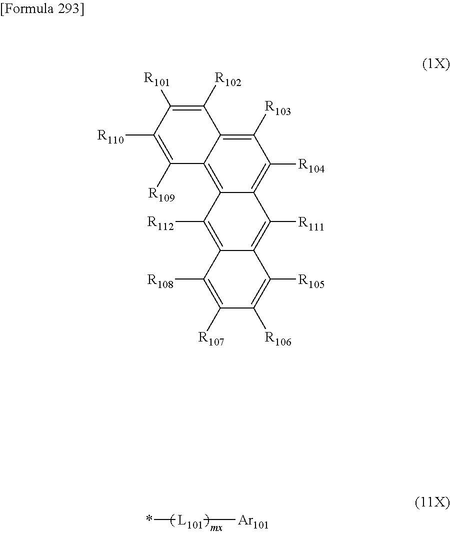

In the formula (1X):
R₁₀₁ to R₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (11X);
at least one of R₁₀₁ to R₁₁₂ is a group represented by the formula (11X);
when a plurality of groups represented by the formula (11X) are present, the plurality of groups represented by the formula (11X) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 1, 2, 3, 4, or 5;
when two or more L₁₁₁ are present, the two or more L₁₁₁ are mutually the same or different;
when two or more Ar₁₀₁ are present, the two or more Ar₁₀₁ are mutually the same or different; and
* in the formula (11X) represents a bonding position to a benz[a]anthracene ring in the formula (1X).

In an exemplary arrangement of the exemplary embodiment, the group represented by the formula (11X) is preferably a group represented by a formula (111X) below.

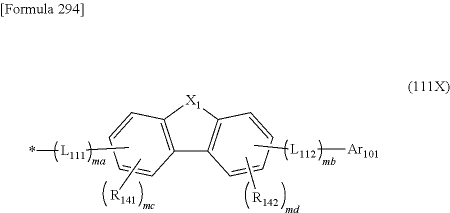

In the formula (111X):
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 1, 2, 3 or 4;
mb is 1, 2, 3 or 4;
ma+mb is 2, 3, or 4;
Ar₁₀₁ represents the same as Ar₁₀₁ in the formula (11); and
R₁₄₁, R₁₄₂, R₁₄₃, R₁₄₄, and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

Among positions *1 to *8 of carbon atoms in a cyclic structure represented by a formula (111aX) below in the group represented by the formula (111X), L₁₁₁ is bonded to one of the positions *1 to *4, R₁₄₁ is bonded to each of three positions of the rest of *1 to *4, L₁₁₂ is bonded to one of the positions *5 to *8, and R₁₄₂ is bonded to each of three positions of the rest of *5 to *8.

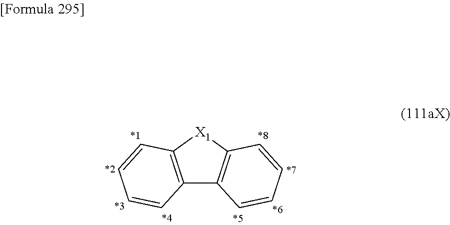

For instance, the group represented by the formula (111X), in which L₁₁₁ is bonded to a carbon atom at *2 in the cyclic structure represented by the formula (111 aX) and L₁₁₂ is bonded to a carbon atom at *7 in the cyclic structure represented by the formula (111aX), is represented by a formula (111bX) below.

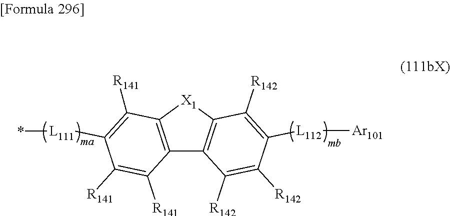

In the formula (111bX):
X₁, L₁₁₁, L₁₁₂, ma, mb, Ar₁₁, R₁₄₁, R₁₄₂, R₁₄₃, R₁₄₄ and R₁₄₅ each independently represent the same as X₁, L₁₁₁, L₁₁₂, ma, mb, Ar₁₀₁, R₁₄₁, R₁₄₂, R₁₄₃, R₁₄₄ and R₁₄₅ in the formula (111X);
a plurality of R₁₄₁ are mutually the same or different; and
a plurality of R₁₄₂ are mutually the same or different.

In an exemplary arrangement of the exemplary embodiment, the group represented by the formula (111X) is preferably a group represented by the formula (111bX).

In the compound represented by the formula (1X), preferably, ma is 1 or 2 and mb is 1 or 2.

In the compound represented by the formula (1X), preferably, ma is 1 and mb is 1.

In the compound represented by the formula (1X), Ar₁₀₁ is preferably a substituted or unsubstituted aryl group having 6 to 50 ring carbon atoms.

In the compound represented by the formula (1X), Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted benz[a]anthryl group, a substituted or unsubstituted pyrenyl group, a substituted or unsubstituted phenanthryl group, or a substituted or unsubstituted fluorenyl group.

The compound represented by the formula (1X) is also preferably represented by a formula (101X) below.

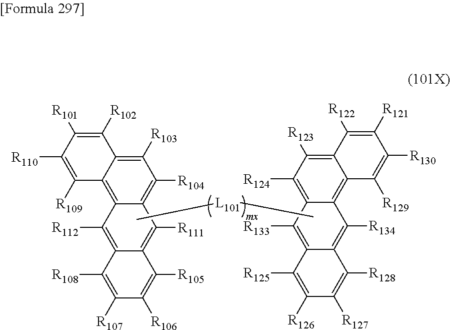

In the formula (101X):
one of R₁₁₁ and R₁₁₂ represents a bonding position to L₁₀₁ and one of R₁₃₃ and R₁₃₄ represents a bonding position to L₁₀₁; R₁₀₁ to R₁₁₀, R₁₂₁ to R₁₃₀, R₁₁₁ or R₁₁₂ not being the bonding position to L₁₀₁, and R₁₃₃ or R₁₃₄ not being the bonding position to L₁₀₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₀₁ is a single bond, a substituted or unsubstituted arylene group having 6 to 50 ring carbon atoms, or a substituted or unsubstituted divalent heterocyclic group having 5 to 50 ring atoms;
mx is 1, 2, 3, 4, or 5; and
when two or more L₁₀₁ are present, the two or more L₁₀₁ are mutually the same or different.

In the compound represented by the formula (1X), L₁₀₁ is preferably a single bond, or a substituted or unsubstituted arylene group having 6 to 50 ring carbon atoms.

The compound represented by the formula (1X) is also preferably represented by a formula (102X) below.

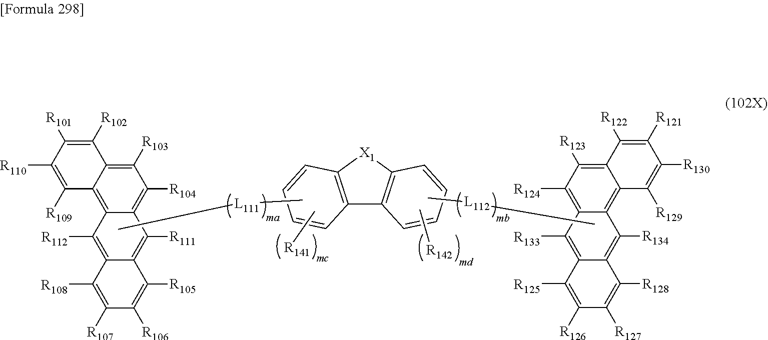

In the formula (102X):
one of R₁₁₁ and R₁₁₂ represents a bonding position to L₁₁₁ and one of R₁₃₃ and R₁₃₄ represents a bonding position to L₁₁₂;
R₁₀₁ to R₁₁₀, R₁₂₁ to R₁₃₀, R₁₁₁ or R₁₁₂ not being the bonding position to L₁₁₁, and R₁₃₃ or R₁₃₄ not being the bonding position to L₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 1, 2, 3 or 4;
mb is 1, 2, 3 or 4;
ma+mb is 2, 3, 4, or 5;
R₁₄₁, R₁₄₂, R₁₄₃, R₁₄₄, and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

In the compound represented by the formula (1X), preferably, ma is 1 or 2 and mb is 1 or 2 in the formula (102X).

In the compound represented by the formula (1X), preferably, ma is 1 and mb is 1 in the formula (102X).

In the compound represented by the formula (1X), the group represented by the formula (11X) is also preferably a group represented by a formula (11AX) or a group represented by a formula (11BX) below.

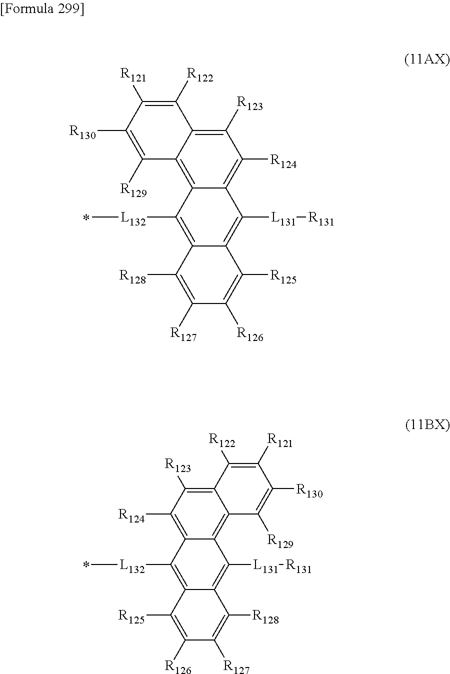

In the formulae (11AX) and (11BX):
R₁₂₁ to R₁₃₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
when a plurality of groups represented by the formula (11AX) are present, the plurality of groups represented by the formula (11AX) are mutually the same or different;
when a plurality of groups represented by the formula (11BX) are present, the plurality of groups represented by the formula (11BX) are mutually the same or different;
L₁₃₁ and L₁₃₂ are each independently a single bond, a substituted or unsubstituted arylene group having 6 to 50 ring carbon atoms, or a substituted or unsubstituted divalent heterocyclic group having 5 to 50 ring atoms; and
* in each of the formulae (11AX) and (11BX) represents a bonding position to a benz[a]anthracene ring in the formula (1X).

The compound represented by the formula (1X) is also preferably represented by a formula (103X) below.

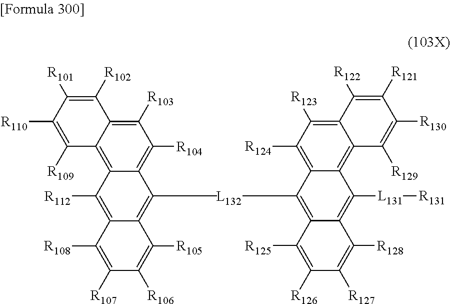

In the formula (103X):
R₁₀₁ to R₁₁₀ and R₁₁₂ respectively represent the same as R₁₀₁ to R₁₁₀ and R₁₁₂ in the formula (1X); and
R₁₂₁ to R₁₃₁, L₁₃₁, and L₁₃₂ respectively represent the same as R₁₂₁ to R₁₃₁, L₁₃₁, and L₁₃₂ in the formula (11BX).

In the compound represented by the formula (1X), L₁₃₁ is also preferably a substituted or unsubstituted arylene group having 6 to 50 ring carbon atoms.

In the compound represented by the formula (1X), L₁₃₂ is also preferably a substituted or unsubstituted arylene group having 6 to 50 ring carbon atoms.

In the compound represented by the formula (1X), it is also preferable that two or more of R₁₀₁ to R₁₁₂ are each a group represented by the formula (11).

In the compound represented by the formula (1X), it is preferable that two or more of R₁₀₁ to R₁₁₂ are each a group represented by the formula (11X) and Ar₁₀₁ in the formula (11X) is a substituted or unsubstituted aryl group having 6 to 50 ring carbon atoms.

In the compound represented by the formula (1X), it is also preferable that Ar₁₀₁ is not a substituted or unsubstituted benz[a]anthryl group, L₁₀₁ is not a substituted or unsubstituted benz[a]anthrylene group, the substituted or unsubstituted aryl group having 6 to 50 ring carbon atoms for R₁₀₁ to R₁₁₀ not being the group represented by the formula (11X) is not a substituted or unsubstituted benz[a]anthryl group.

In the compound represented by the formula (1X), R₁₀₁ to R₁₁₂ not being the group represented by the formula (11X) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound represented by the formula (1X), R₁₀₁ to R₁₁₂ not being the group represented by the formula (11X) are each preferably a hydrogen atom, a substituted or unsubstituted alkyl group having 1 to 50 carbon atoms, or a substituted or unsubstituted cycloalkyl group having 3 to 50 ring carbon atoms.

In the compound represented by the formula (1X), R₁₀₁ to R₁₁₂ not being the group represented by the formula (11X) are each preferably a hydrogen atom.

### Compound Represented by Formula (12X)

In an exemplary arrangement of the exemplary embodiment, the first compound is also preferably a compound represented by a formula (12X) below.

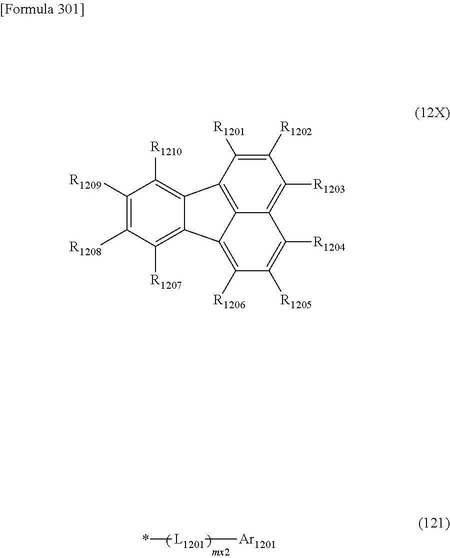

In the formula (12X):
at least one combination of adjacent two or more of R₁₂₀₁ to R₁₂₁₀ are mutually bonded to form a substituted or unsubstituted monocyclic ring, or mutually bonded to form a substituted or unsubstituted fused ring,
R₁₂₀₁ to R₁₂₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (121);
at least one of a substituent, if present, for the substituted or unsubstituted monocyclic ring, a substituent, if present, for the substituted or unsubstituted fused ring, or R₁₂₀₁ to R₁₂₁₀ is a group represented by the formula (121);
when a plurality of groups represented by the formula (121) are present, the plurality of groups represented by the formula (121) are mutually the same or different;
L₁₂₀₁ is a single bond, a substituted or unsubstituted arylene group having 6 to 50 ring carbon atoms, or a substituted or unsubstituted divalent heterocyclic group having 5 to 50 ring atoms;
Ar₁₂₀₁ is a substituted or unsubstituted aryl group having 6 to 50 ring carbon atoms, or a substituted or unsubstituted heterocyclic group having 5 to 50 ring atoms;
mx2 is 0, 1, 2, 3, 4, or 5;
when two or more L₁₂₀₁ are present, the two or more L₁₂₀₁ are mutually the same or different;
when two or more Ar₁₂₀₁ are present, the two or more Ar₁₂₀₁ are mutually the same or different; and
* in the formula (121) represents a bonding position to a ring represented by the formula (12X).

In the formula (12X), combinations of adjacent two of R₁₂₀₁ to R₁₂₁₀ refer to a combination of R₁₂₀₁ and R₁₂₀₂, a combination of R₁₂₀₂ and R₁₂₀₃, a combination of R₁₂₀₃ and R₁₂₀₄, a combination of R₁₂₀₄ and R₁₂₀₅, a combination of R₁₂₀₅ and R₁₂₀₆, a combination of R₁₂₀₇ and R₁₂₀₈, a combination of R₁₂₀₈ and R₁₂₀₉, and a combination of R₁₂₀₉ and R₁₂₁₀.

### Compound Represented by Formula (13X)

In an exemplary arrangement of the exemplary embodiment, the first compound is also preferably a compound represented by a formula (13X) below.

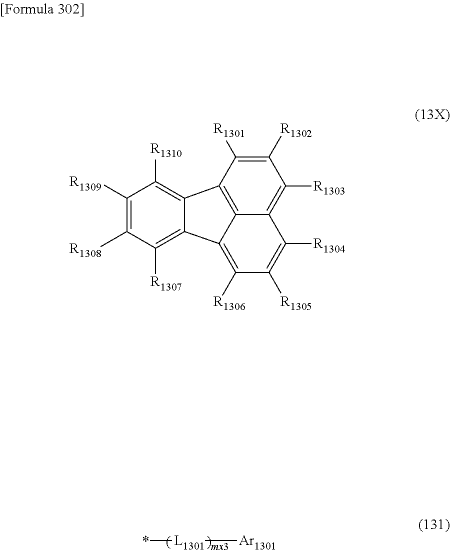

In the formula (13X):
R₁₃₀₁ to R₁₃₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (131);
at least one of R₁₃₀₁ to R₁₃₁₀ is a group represented by the formula (131);
when a plurality of groups represented by the formula (131) are present, the plurality of groups represented by the formula (131) are mutually the same or different;
L₁₃₀₁ is a single bond, a substituted or unsubstituted arylene group having 6 to 50 ring carbon atoms, or a substituted or unsubstituted divalent heterocyclic group having 5 to 50 ring atoms;
Ar₁₃₀₁ is a substituted or unsubstituted aryl group having 6 to 50 ring carbon atoms, or a substituted or unsubstituted heterocyclic group having 5 to 50 ring atoms;
mx3 is 0, 1, 2, 3, 4, or 5;
when two or more L₁₃₀₁ are present, the two or more L₁₃₀₁ are mutually the same or different;
when two or more Ar₁₃₀₁ are present, the two or more Ar₁₃₀₁ are mutually the same or different; and
* in the formula (131) represents a bonding position to a fluoranthene ring represented by the formula (13X).

In an exemplary arrangement of the exemplary embodiment, none of combinations of adjacent two or more of R₁₃₀₁ to R₁₃₁₀ not being a group represented by the formula (131) are not bonded to each other. Combinations of adjacent two of R₁₃₀₁ to R₁₃₁₀ in the formula (13X) refer to a combination of R₁₃₀₁ and R₁₃₀₂, a combination of R₁₃₀₂ and R₁₃₀₃, a combination of R₁₃₀₃ and R₁₃₀₄, a combination of R₁₃₀₄ and R₁₃₀₅, a combination of R₁₃₀₅ and R₁₃₀₆, a combination of R₁₃₀₇ and R₁₃₀₈, a combination of R₁₃₀₈ and R₁₃₀₉, and a combination of R₁₃₀₉ and R₁₃₁₀.

### Compound Represented by Formula (14X)

In an exemplary arrangement of the exemplary embodiment, the first compound is also preferably a compound represented by a formula (14X) below.

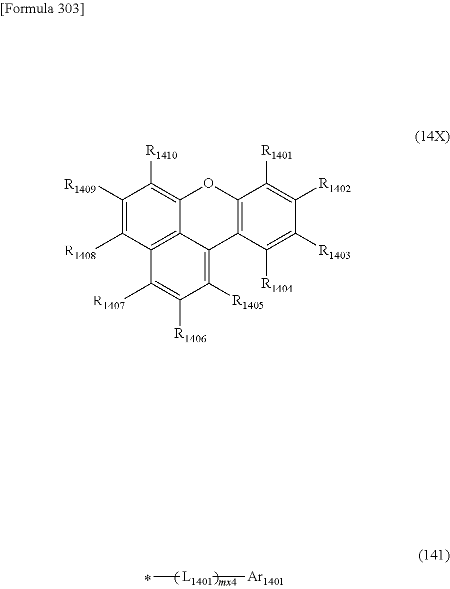

In the formula (14X):
R₁₄₀₁ to R₁₄₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (141);
at least one of R₁₄₀₁ to R₁₄₁₀ is a group represented by the formula (141);
when a plurality of groups represented by the formula (141) are present, the plurality of groups represented by the formula (141) are mutually the same or different;
L₁₄₀₁ is a single bond, a substituted or unsubstituted arylene group having 6 to 50 ring carbon atoms, or a substituted or unsubstituted divalent heterocyclic group having 5 to 50 ring atoms;
Ar₁₄₀₁ is a substituted or unsubstituted aryl group having 6 to 50 ring carbon atoms, or a substituted or unsubstituted heterocyclic group having 5 to 50 ring atoms;
mx4 is 0, 1, 2, 3, 4, or 5;
when two or more L₁₄₀₁ are present, the two or more L₁₄₀₁ are mutually the same or different;
when two or more Ar₁₄₀₁ are present, the two or more Ar₁₄₀₁ are mutually the same or different; and
* in the formula (141) represents a bonding position to a ring represented by the formula (14X).

### Compound Represented by Formula (15X)

In an exemplary arrangement of the exemplary embodiment, the first compound is also preferably a compound represented by a formula (15X) below.

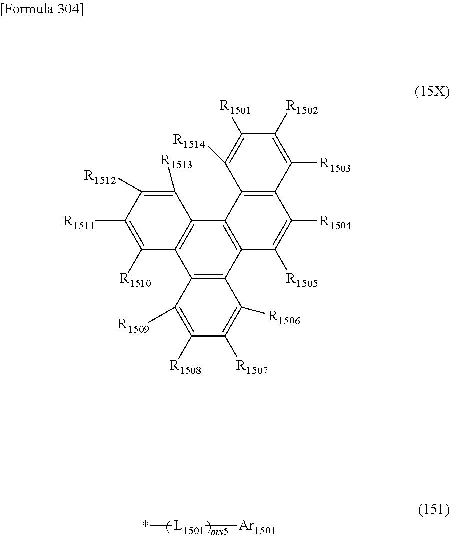

In the formula (15X):
R₁₅₀₁ to R₁₅₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (151);
at least one of R₁₅₀₁ to R₁₅₁₄ is a group represented by the formula (151);
when a plurality of groups represented by the formula (151) are present, the plurality of groups represented by the formula (151) are mutually the same or different;
L₁₅₀₁ is a single bond, a substituted or unsubstituted arylene group having 6 to 50 ring carbon atoms, or a substituted or unsubstituted divalent heterocyclic group having 5 to 50 ring atoms;
Ar₁₅₀₁ is a substituted or unsubstituted aryl group having 6 to 50 ring carbon atoms, or a substituted or unsubstituted heterocyclic group having 5 to 50 ring atoms;
mx5 is 0, 1, 2, 3, 4, or 5;
when two or more L₁₅₀₁ are present, the two or more L₁₅₀₁ are mutually the same or different;
when two or more Ar₁₅₀₁ are present, the two or more Ar₁₅₀₁ are mutually the same or different; and
* in the formula (151) represents a bonding position to a ring represented by the formula (15X).

### Compound Represented by Formula (16X)

In an exemplary arrangement of the exemplary embodiment, the first compound is also preferably a compound represented by a formula (16X) below.

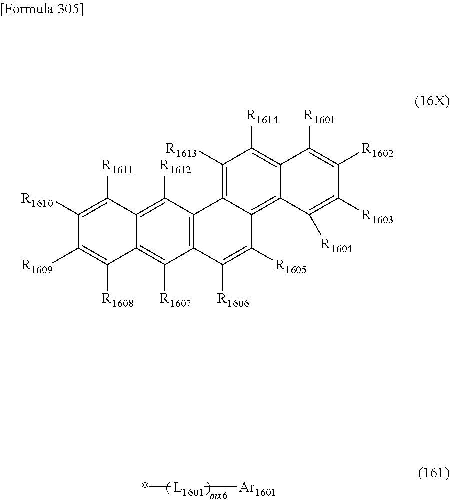

In the formula (16X):
R₁₆₀₁ to R₁₆₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (161);
at least one of R₁₆₀₁ to R₁₆₁₄ is a group represented by the formula (161);
when a plurality of groups represented by the formula (161) are present, the plurality of groups represented by the formula (161) are mutually the same or different;
L₁₆₀₁ is a single bond, a substituted or unsubstituted arylene group having 6 to 50 ring carbon atoms, or a substituted or unsubstituted divalent heterocyclic group having 5 to 50 ring atoms;
Ar₁₆₀₁ is a substituted or unsubstituted aryl group having 6 to 50 ring carbon atoms, or a substituted or unsubstituted heterocyclic group having 5 to 50 ring atoms;
mx6 is 0, 1, 2, 3, 4, or 5;
when two or more L₁₆₀₁ are present, the two or more L₁₆₀₁ are mutually the same or different;
when two or more Ar₁₆₀₁ are present, the two or more Ar₁₆₀₁ are mutually the same or different; and
* in the formula (161) represents a bonding position to a ring represented by the formula (16X).

In an exemplary arrangement of the exemplary embodiment, it is also preferable that the first host material has a linking structure including a benzene ring and a naphthalene ring linked to each other with a single bond in a molecule, the benzene ring and the naphthalene ring in the linking structure are each independently further fused with a monocyclic ring or a fused ring, or not fused, and the benzene ring and the naphthalene ring in the linking structure are further linked by cross-linking at at least one site other than the single bond.

Since the first host material has a linking structure including such cross-linking, it is expected to suppress the chromaticity of the organic EL device from deteriorating.

The first host material in the above case is only required to have a linking structure as the minimum unit in a molecule, the linking structure including a benzene ring and a naphthalene ring linked to each other with a single bond (occasionally referred to as a benzene-naphthalene linking structure), the linking structure being as represented by a formula (X₁) or a formula (X₂) below. Further, the benzene ring may be fused with a monocyclic ring or fused ring, and the naphthalene ring may be fused with a monocyclic ring or fused ring. For instance, also in a case where the first host material has, in a molecule, a linking structure including a naphthalene ring and a naphthalene ring linked to each other with a single bond (occasionally referred to as a naphthalene-naphthalene linking structure) and being as represented by a formula (X₃), a formula (X₄), or a formula (X₅) below, the naphthalene-naphthalene linking structure is regarded as including the benzene-naphthalene linking structure since one of the naphthalene rings includes a benzene ring.

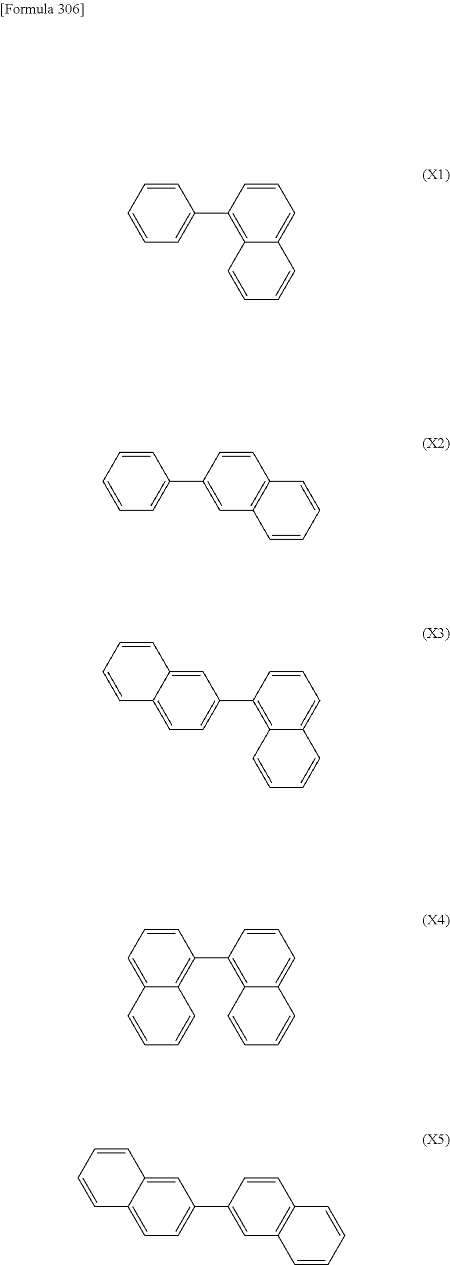

In an exemplary arrangement of the exemplary embodiment, the cross-linking also preferably includes a double bond. Specifically, <<nret>> it is also preferable that the benzene and the naphthalene are further linked to each other by a cross-linking structure including a double bond at one site other than the single bond.

Assuming that the benzene ring and the naphthalene ring in the benzene-naphthalene linking structure are further linked to each other at at least one site other than the single bond by cross-linking, for instance, a linking structure (fused ring) represented by a formula (X₁₁) below is obtained in a case of the formula (X₁), and a linking structure (fused ring) represented by a formula (X₃₁) below is obtained in a case of the formula (X₃).

Assuming that the benzene ring and the naphthalene ring in the benzene-naphthalene linking structure are further linked to each other at any other site than the single bond by cross-linking including a double bond, for instance, a linking structure (fused ring) represented by a formula (X₁₂) below is obtained in a case of the formula (X₁), a linking structure (fused ring) represented by a formula (X₂₁) or formula (X₂₂) below is obtained in a case of the formula (X₂), a linking structure (fused ring) represented by a formula (X₄₁) below is obtained in a case of the formula (X₄), and a linking structure (fused ring) represented by a formula (X₅₁) below is obtained in a case of the formula (X₅).

Assuming that the benzene ring and the naphthalene ring in the benzene-naphthalene linking structure are further linked to each other at at least one site other than the single bond by cross-linking including a hetero atom (e.g., an oxygen atom), for instance, a linking structure (fused ring) represented by a formula (X₁₃) below is obtained in a case of the formula (X₁).

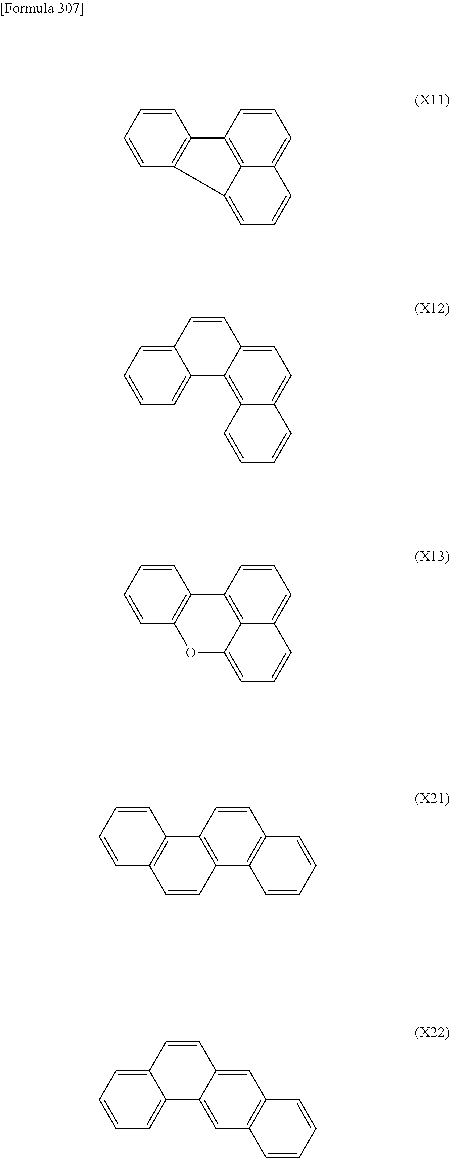

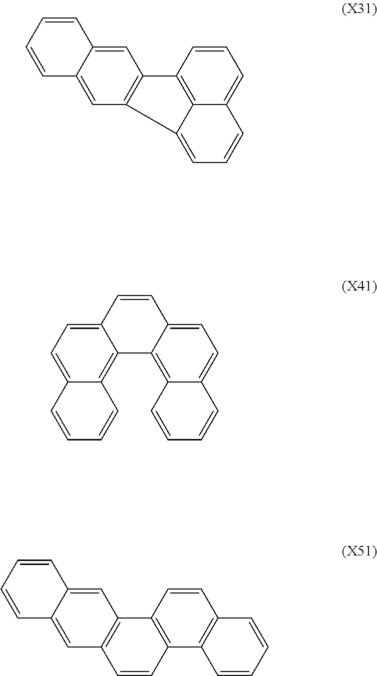

In an exemplary arrangement of the exemplary embodiment, it is also preferable that the first host material has a biphenyl structure in which a first benzene ring and a second benzene ring are linked to each other with a single bond in a molecule, the first benzene ring and the second benzene ring in the biphenyl structure are further linked by cross-linking at at least one site other than the single bond.

In an exemplary arrangement of the exemplary embodiment, the first benzene ring and the second benzene ring in the biphenyl structure are also preferably further linked to each other by the cross-linking at one site other than the single bond. Since the first host material has a biphenyl structure including such cross-linking, it is expected to suppress the chromaticity of the organic EL device from deteriorating.

In an exemplary arrangement of the exemplary embodiment, the cross-linking also preferably includes a double bond.

In an exemplary arrangement of the exemplary embodiment, the cross-linking also preferably includes no double bond.

Also preferably, the first benzene ring and the second benzene ring in the biphenyl structure are further linked to each other by the cross-linking at two sites other than the single bond.

In an exemplary arrangement of the exemplary embodiment, it is also preferable that the first benzene ring and the second benzene ring in the biphenyl structure are further linked to each other by the cross-linking at two sites other than the single bond and the cross-linking includes no double bond. Since the first host material has a biphenyl structure including such cross-linking, it is expected to suppress the chromaticity of the organic EL device from deteriorating.

For instance, assuming that the first benzene ring and the second benzene ring in the biphenyl structure represented by a formula (BP1) below are further linked to each other by cross-linking at at least one site other than the single bond, the biphenyl structure is exemplified by linking structures (fused rings) represented by formulae (BP11) to (BP15) below.

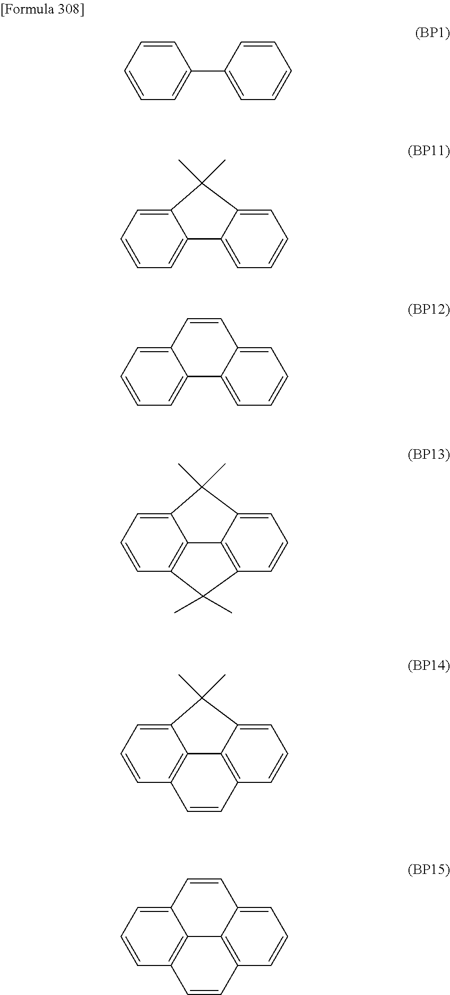

The formula (BP11) represents a linking structure in which the first benzene ring and the second benzene ring are linked to each other at one site other than the single bond by cross-linking including no double bond.

The formula (BP12) represents a linking structure in which the first benzene ring and the second benzene ring are linked to each other at one site other than the single bond by cross-linking including a double bond.

The formula (BP13) represents a linking structure in which the first benzene ring and the second benzene ring are linked to each other at two sites other than the single bond by cross-linking including no double bond.

The formula (BP14) represents a linking structure in which the first benzene ring and the second benzene ring are linked to each other by cross-linking including no double bond at one of two sites other than the single bond, and the first benzene ring and the second benzene ring are linked to each other by cross-linking including a double bond at the other of the two sites other than the single bond.

The formula (BP15) represents a linking structure in which the first benzene ring and the second benzene ring are linked to each other at two sites other than the single bond by cross-linking including a double bond.

In the first compound, the groups specified to be “substituted or unsubstituted” are each preferably an “unsubstituted” group.

### Method of Producing First Compound

The first compound is producible by a known method. The first compound can also be produced based on a known method through a known alternative reaction using a known material(s) tailored for the target compound.

### Specific Examples of First Compound

Specific examples of the first compound includes compound below. It should however be noted that the invention is not limited to the specific examples of the first compound.

In the specific examples of the compound herein, D represents a deuterium atom, Me represents a methyl group, and tBu represents a tert-butyl group.

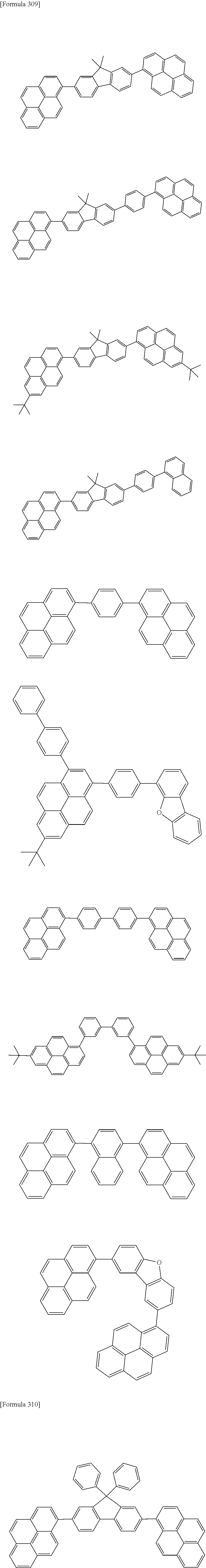

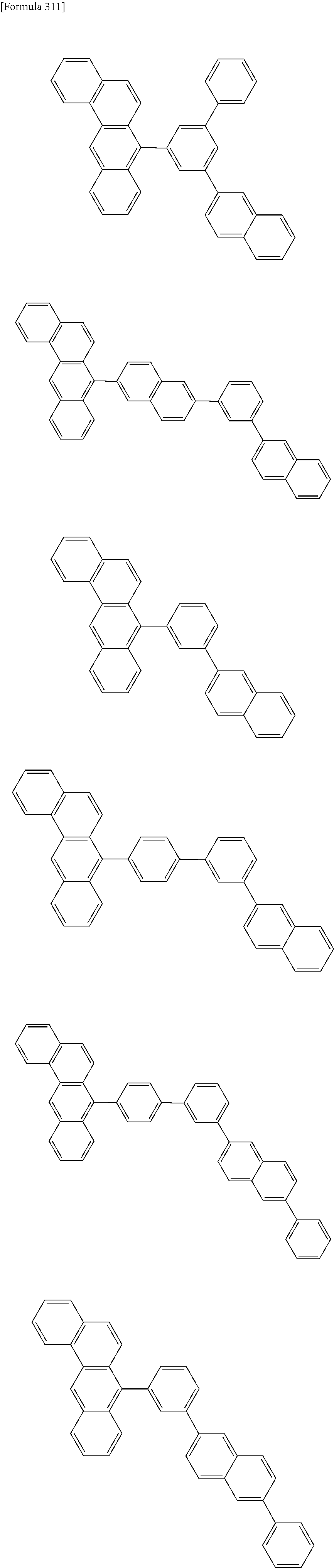

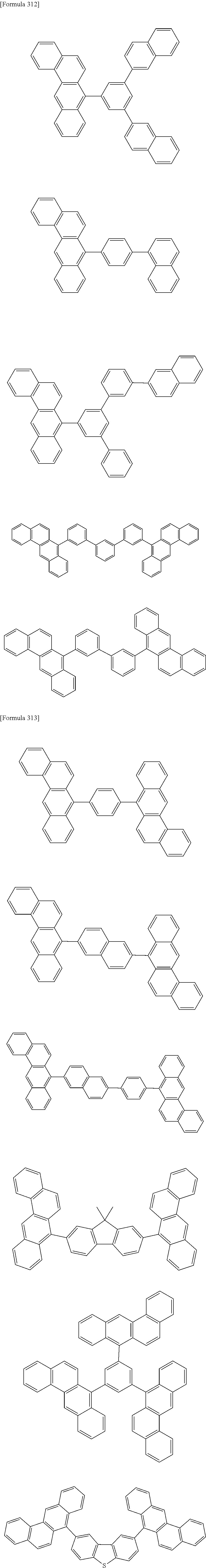

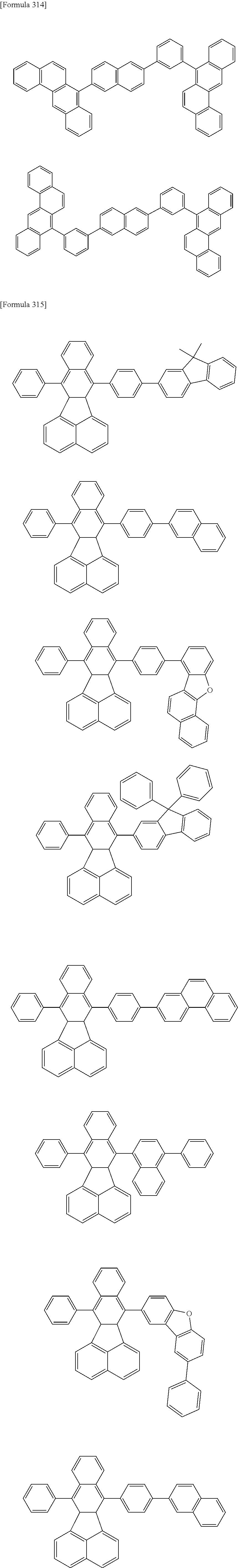

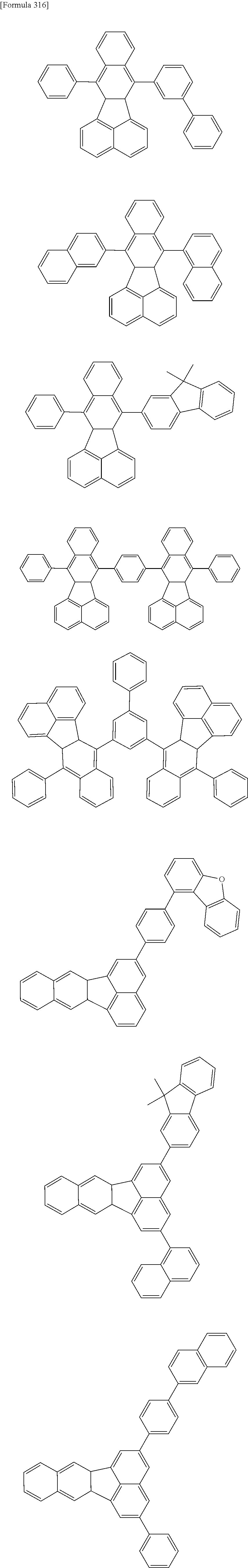

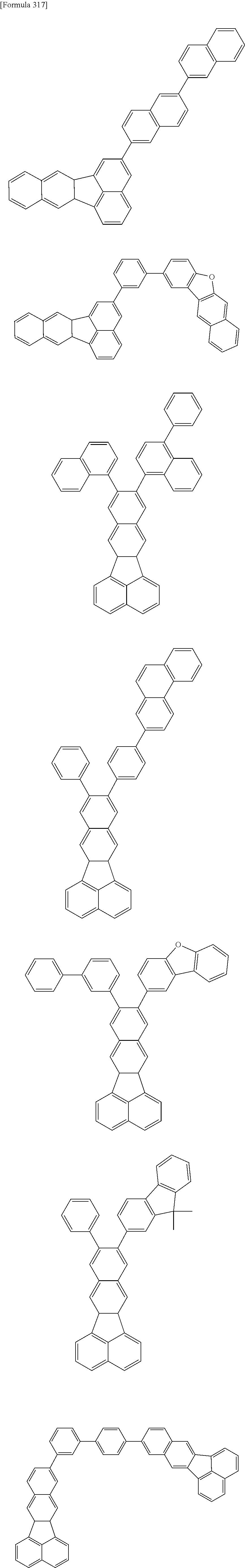

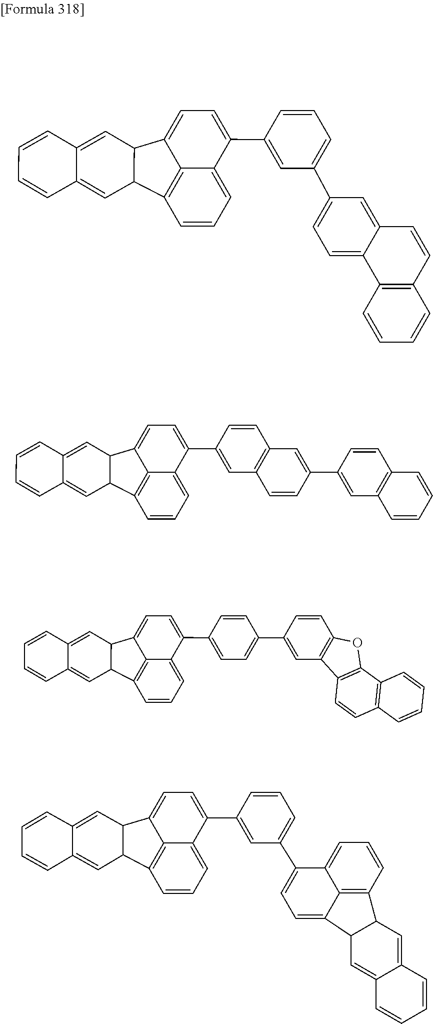

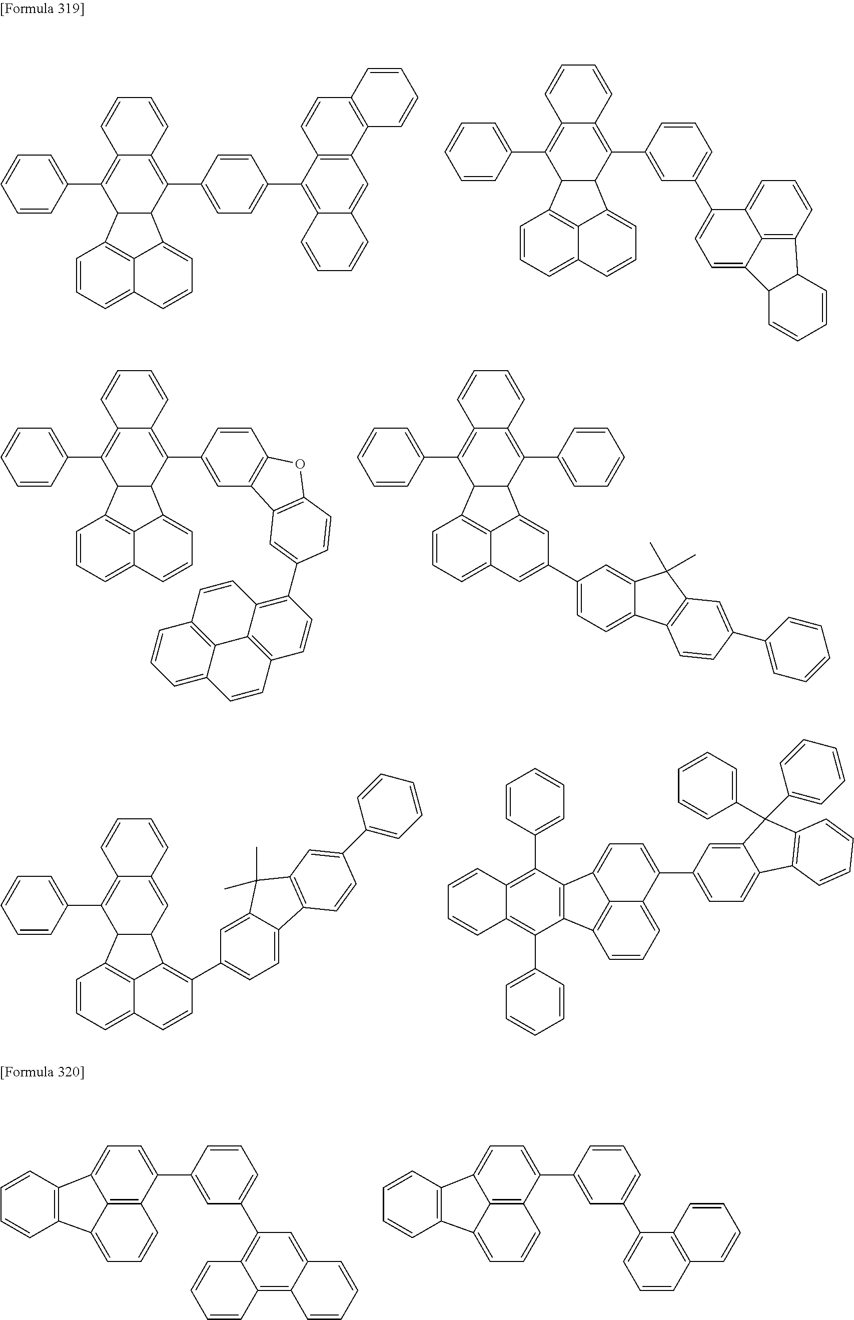

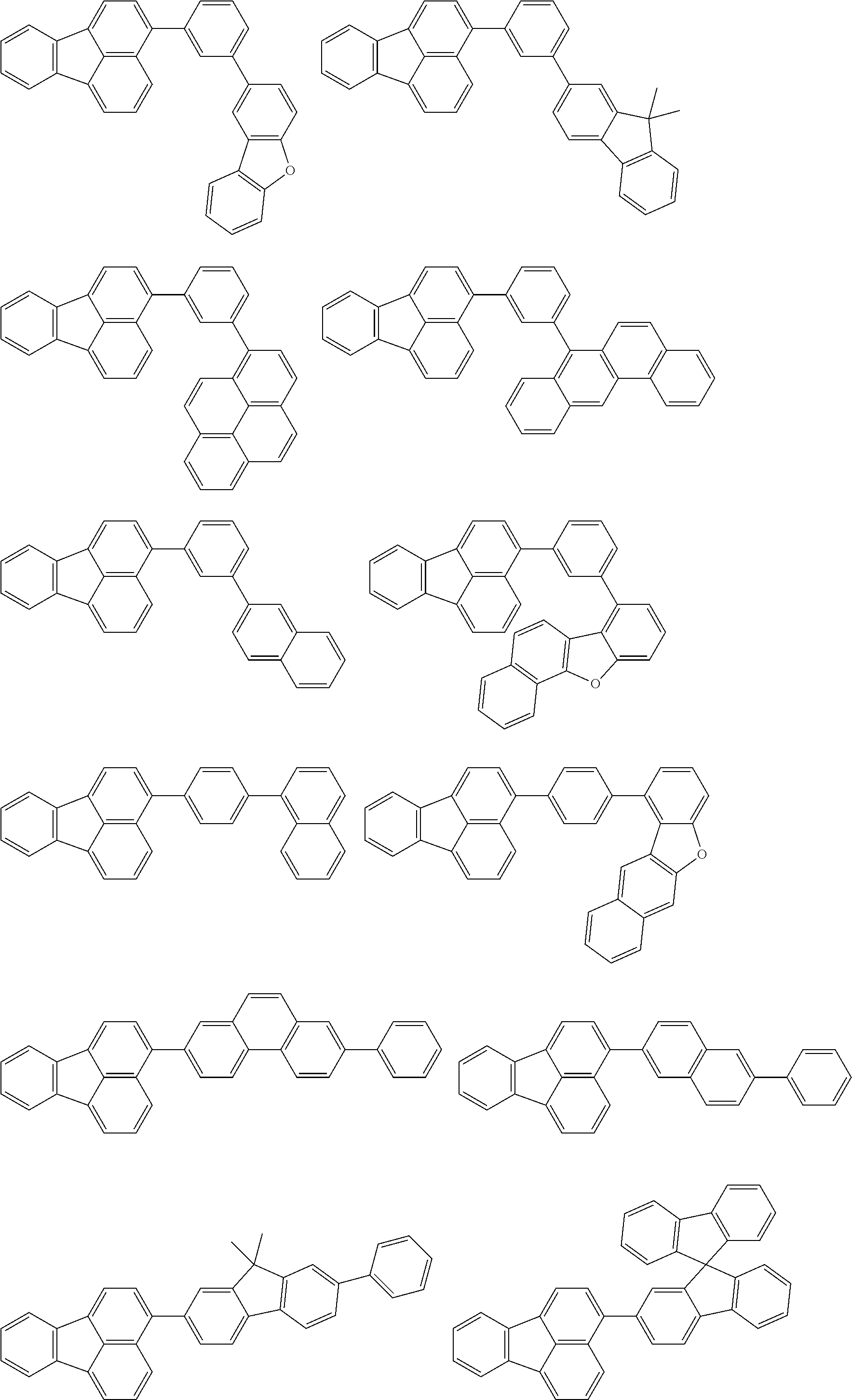

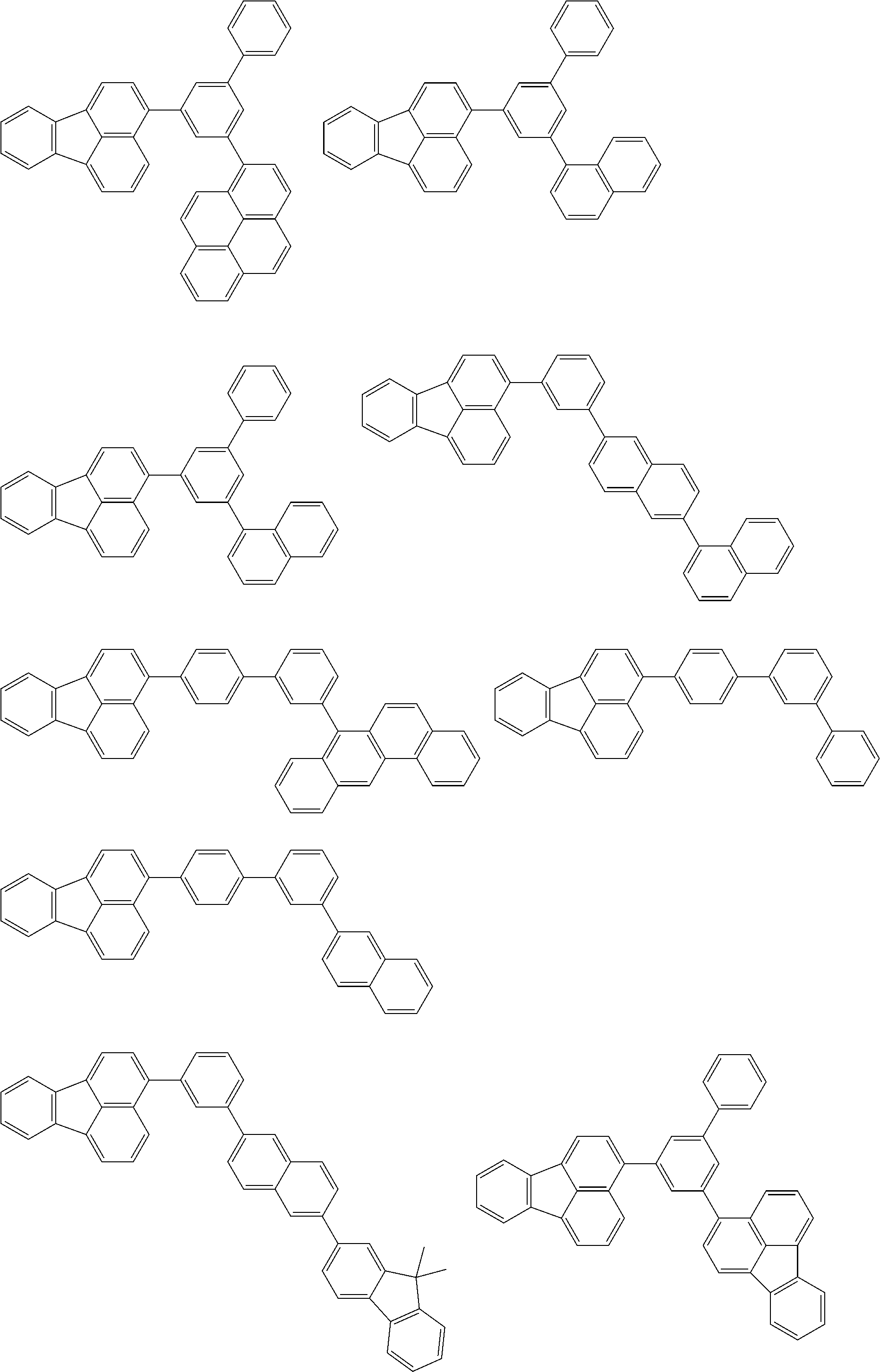

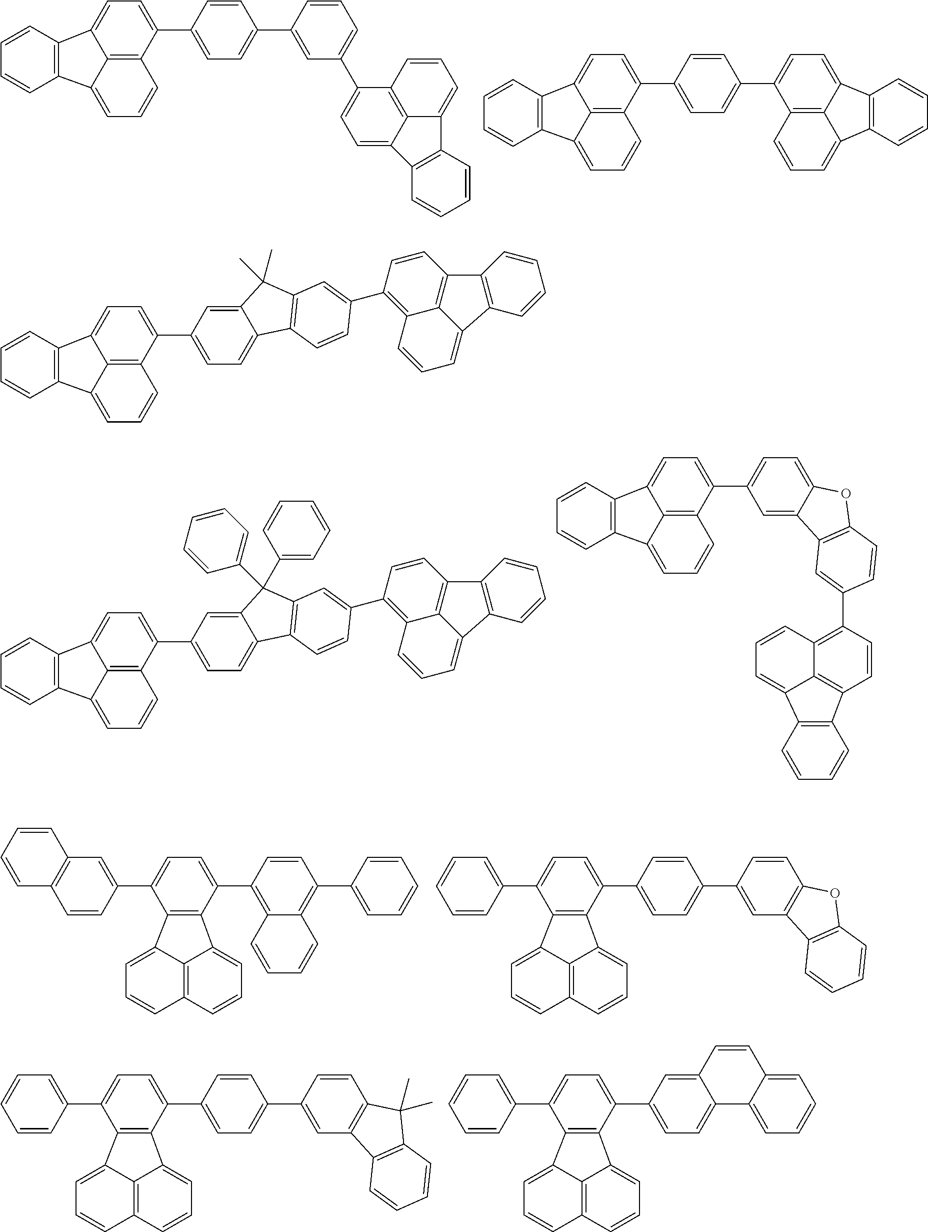

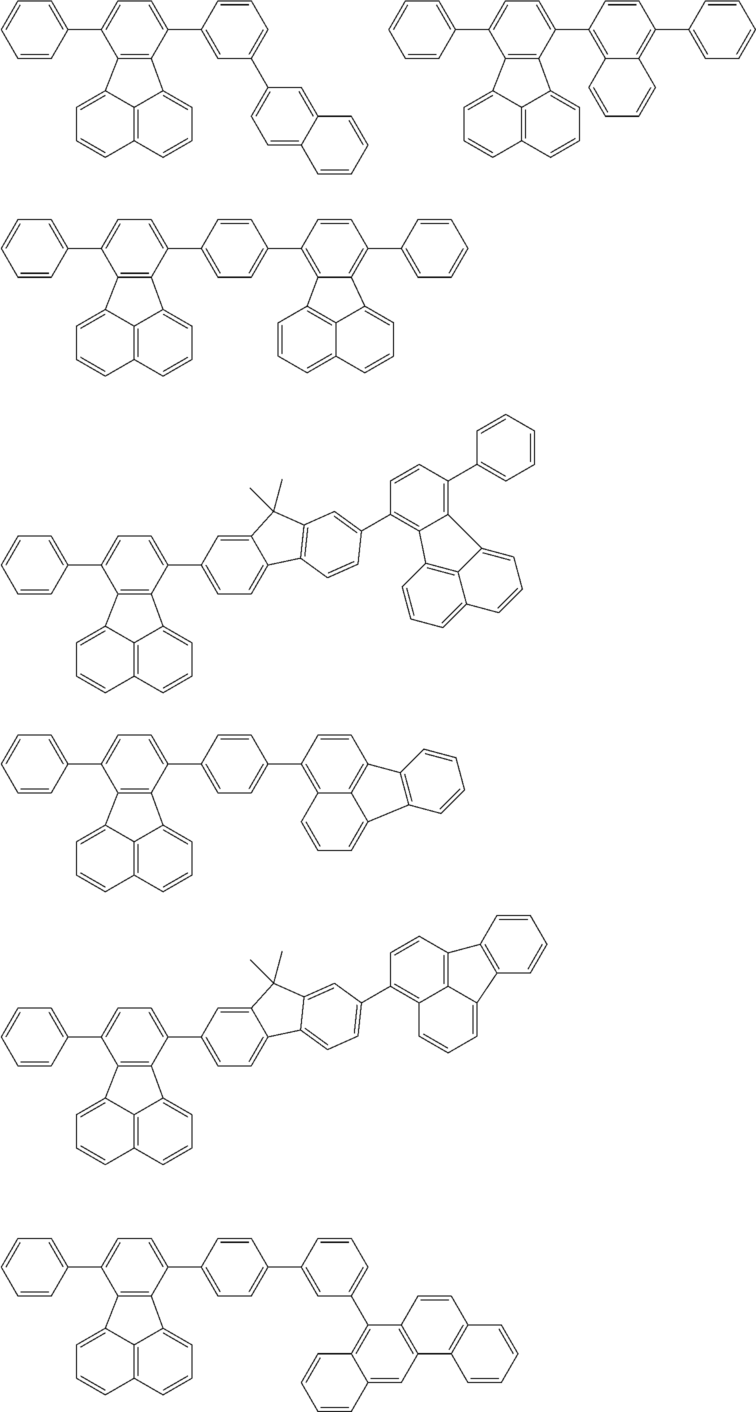

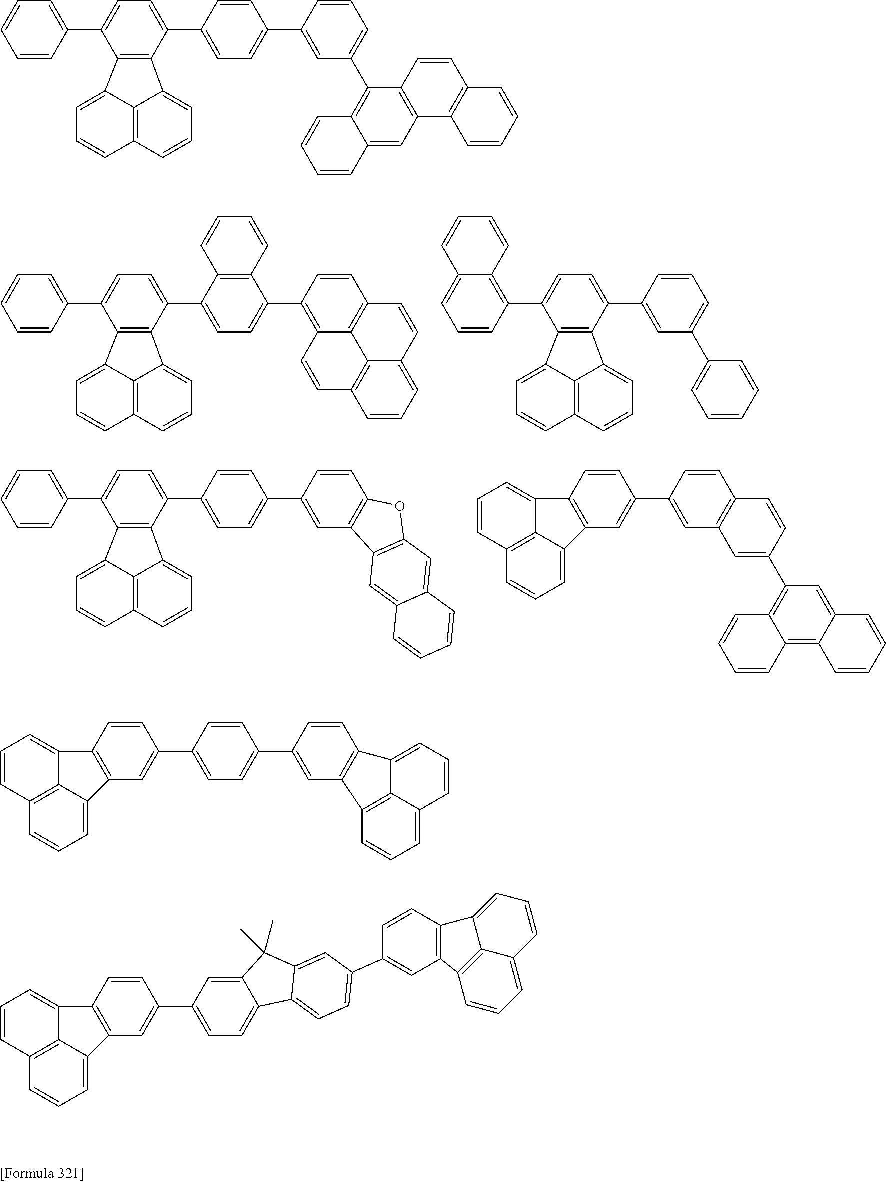

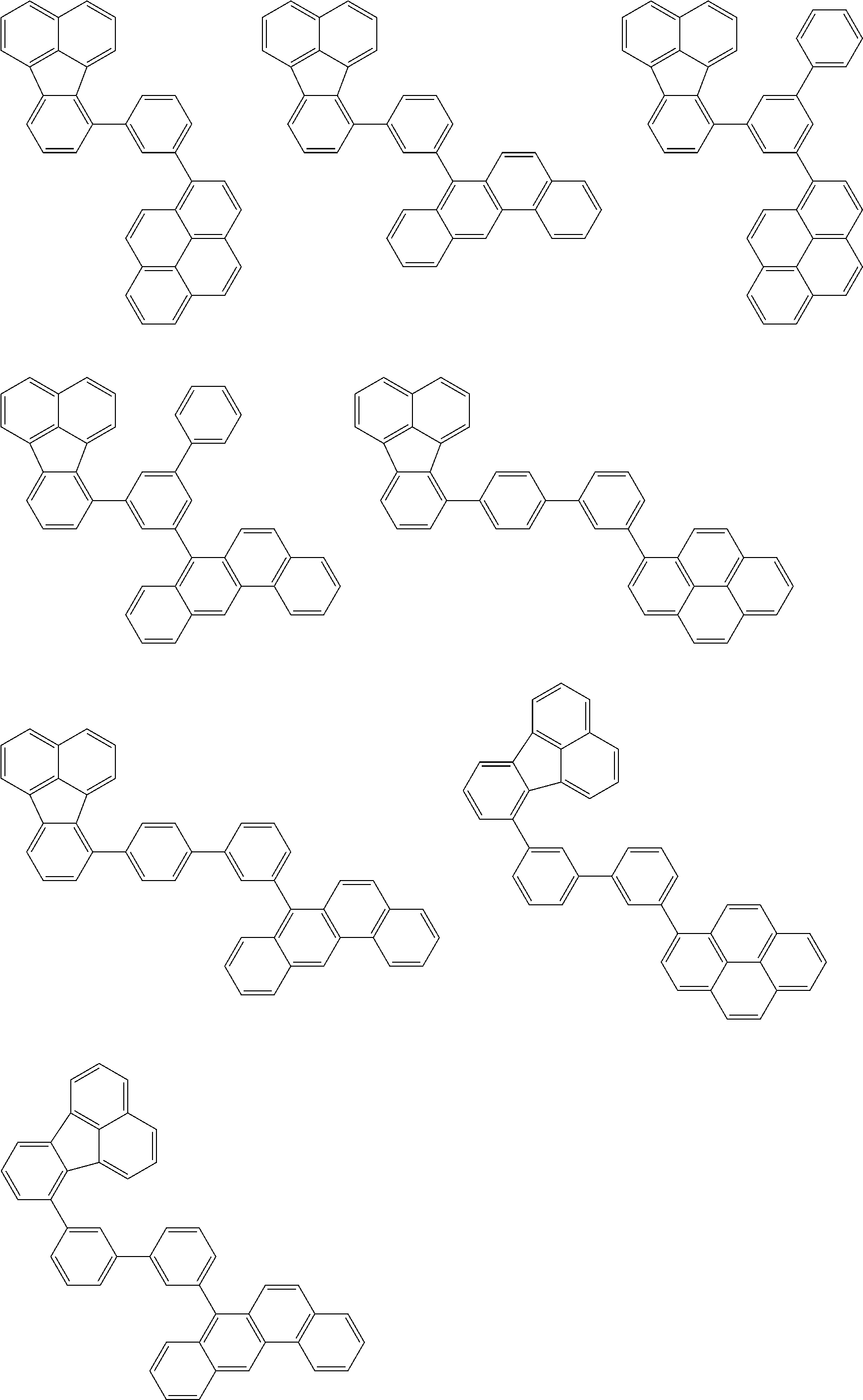

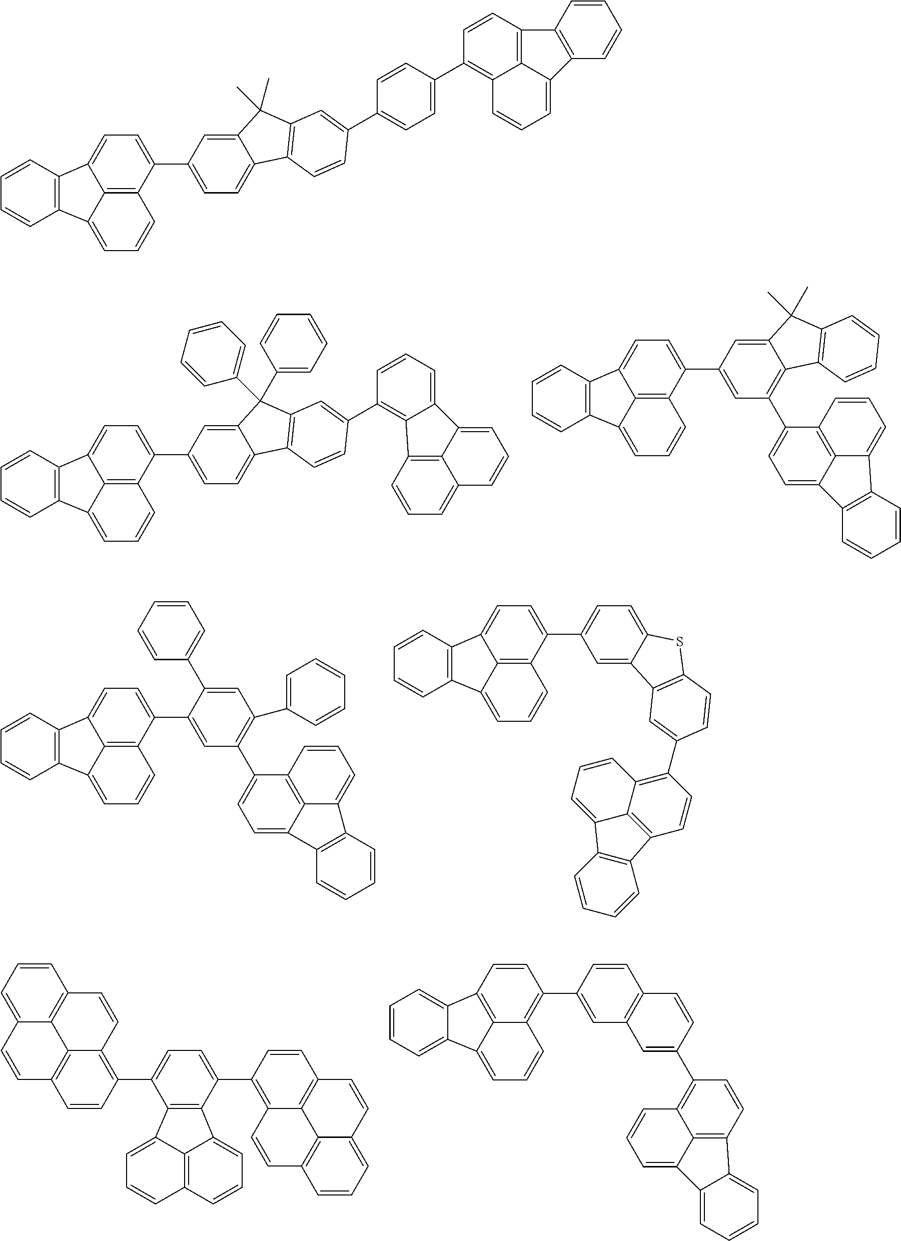

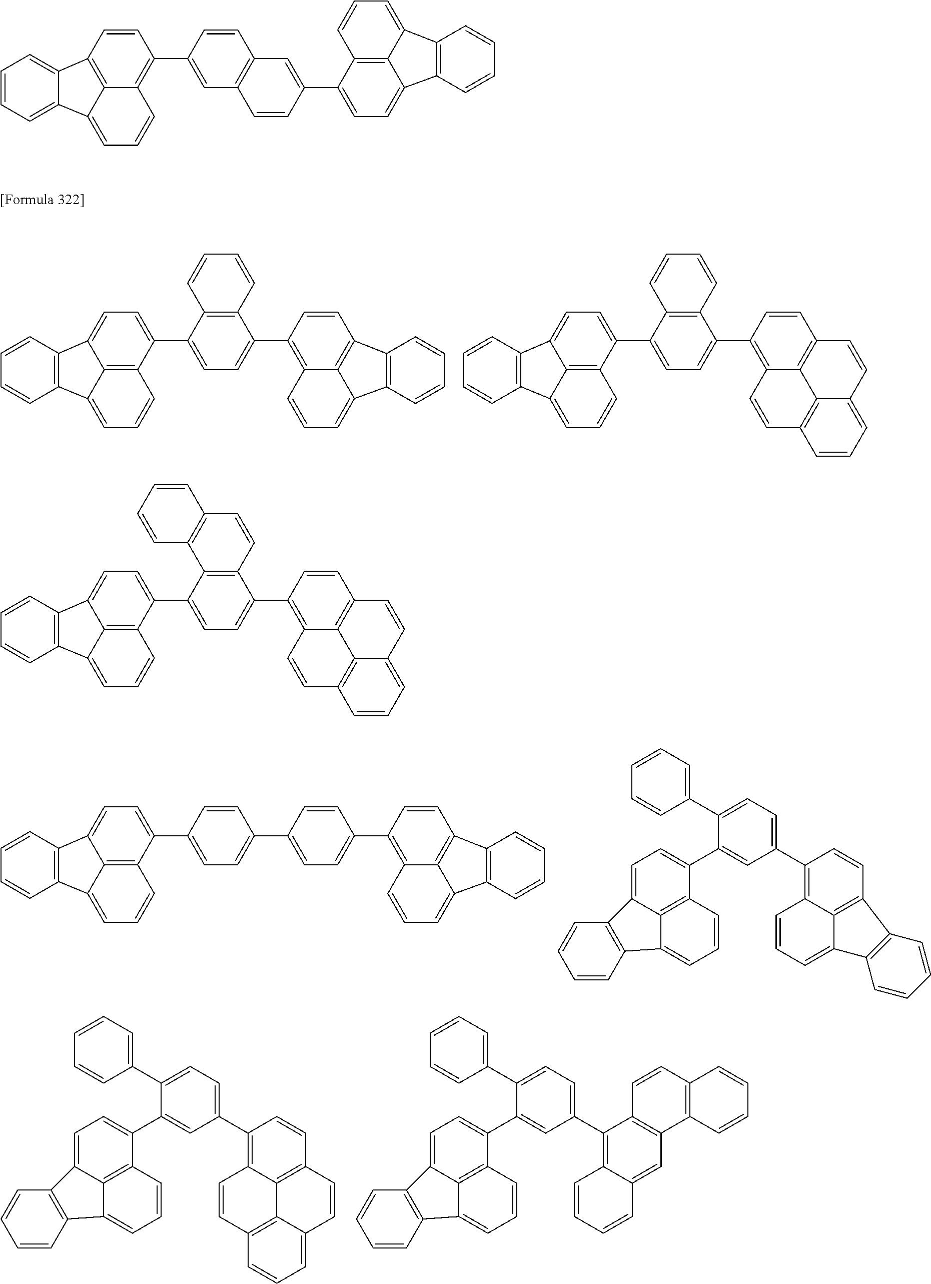

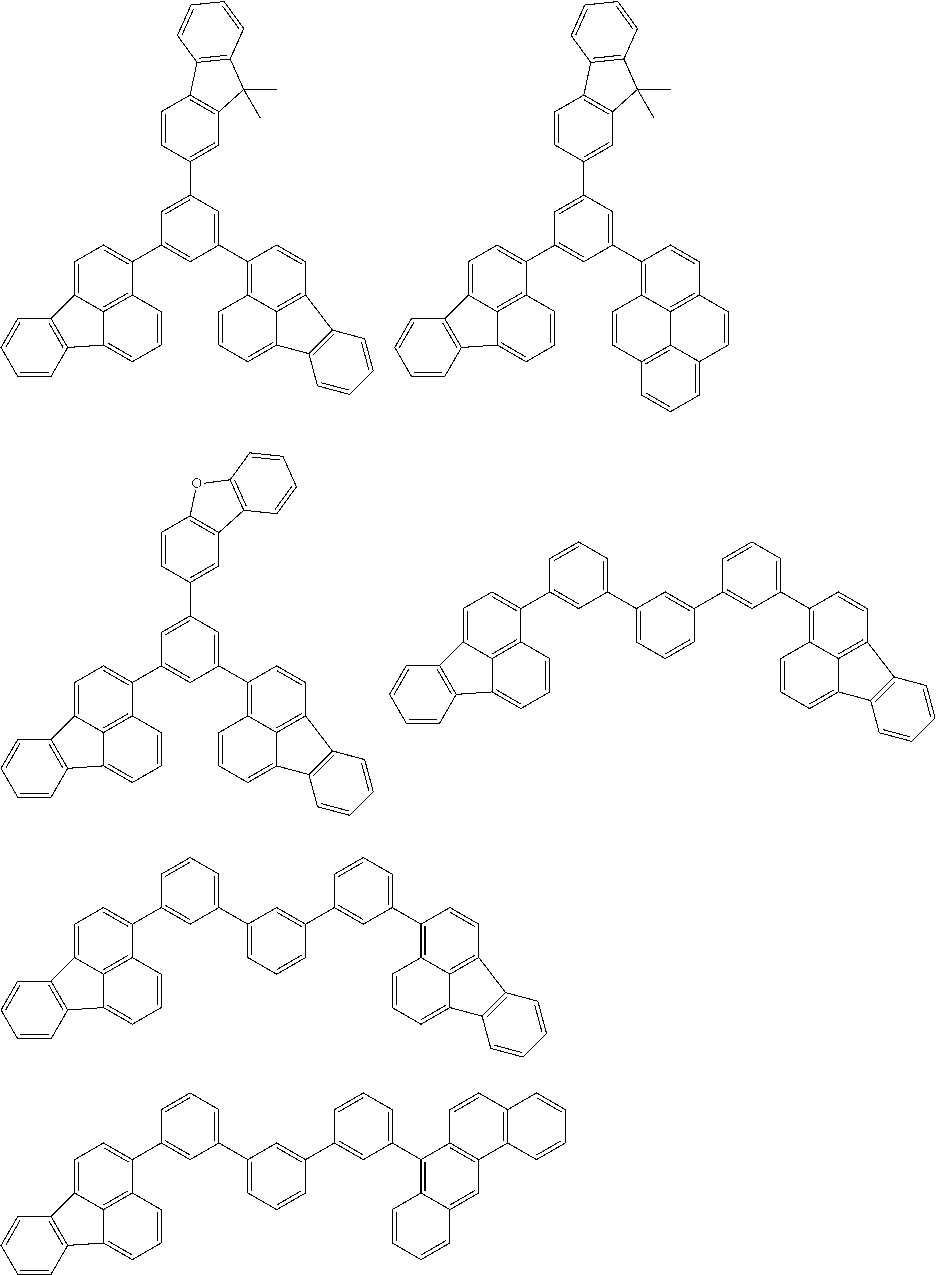

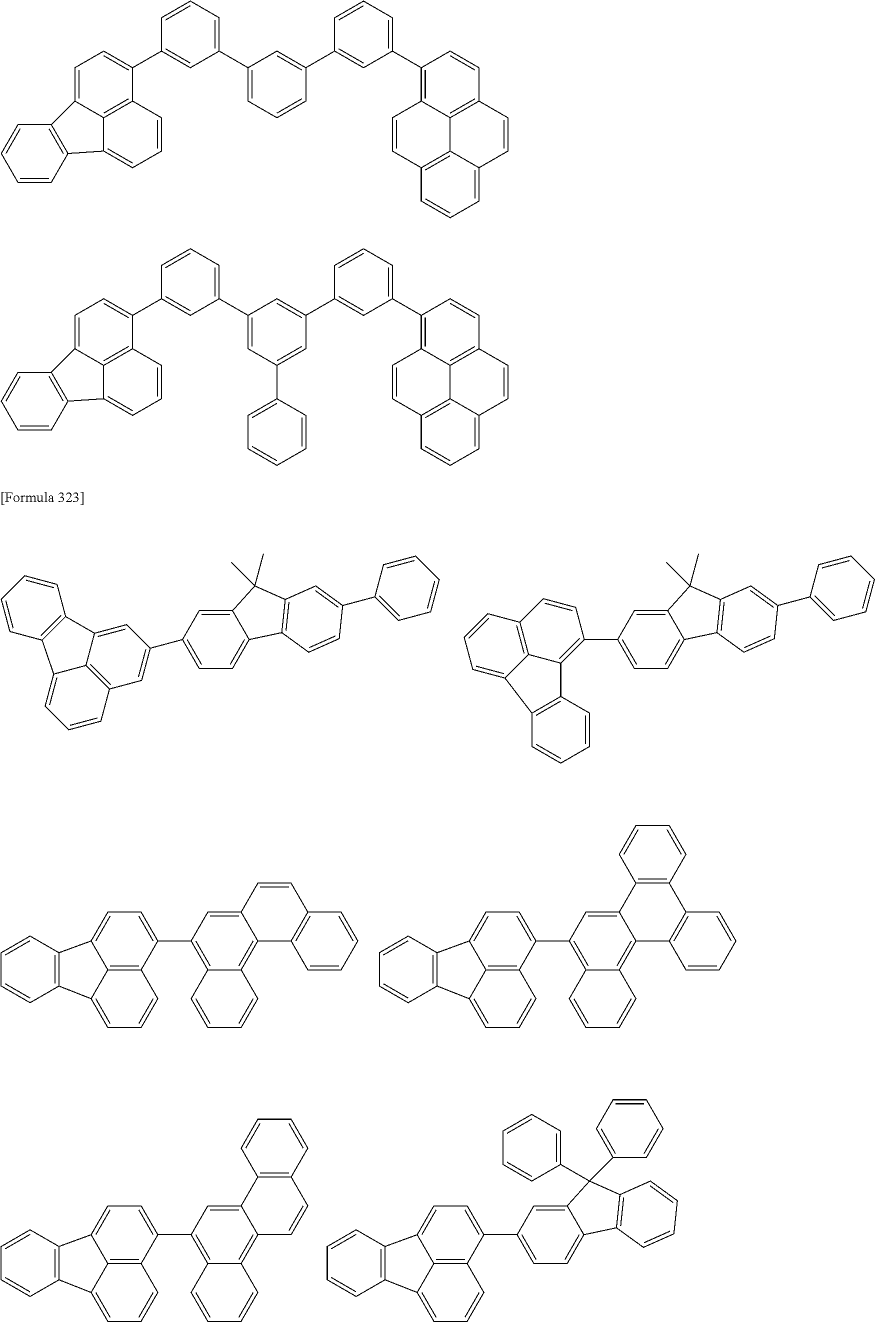

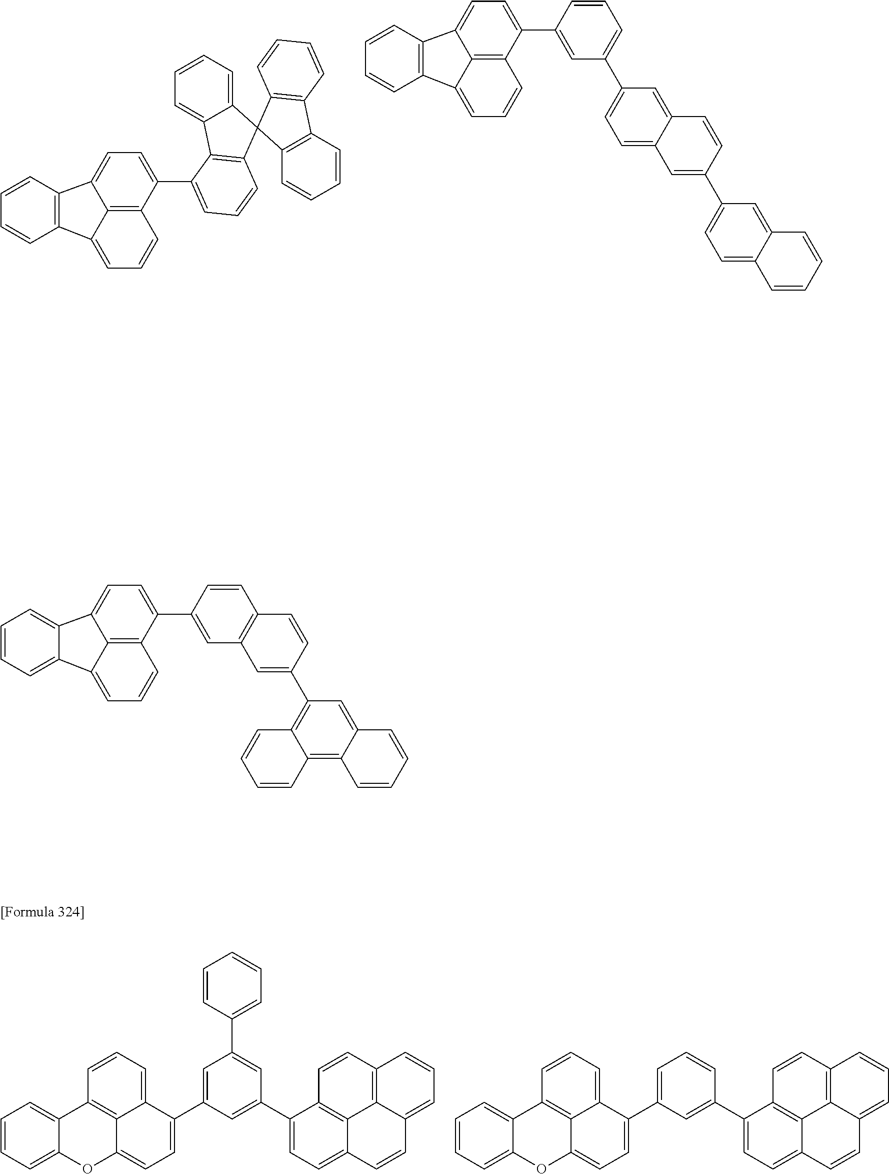

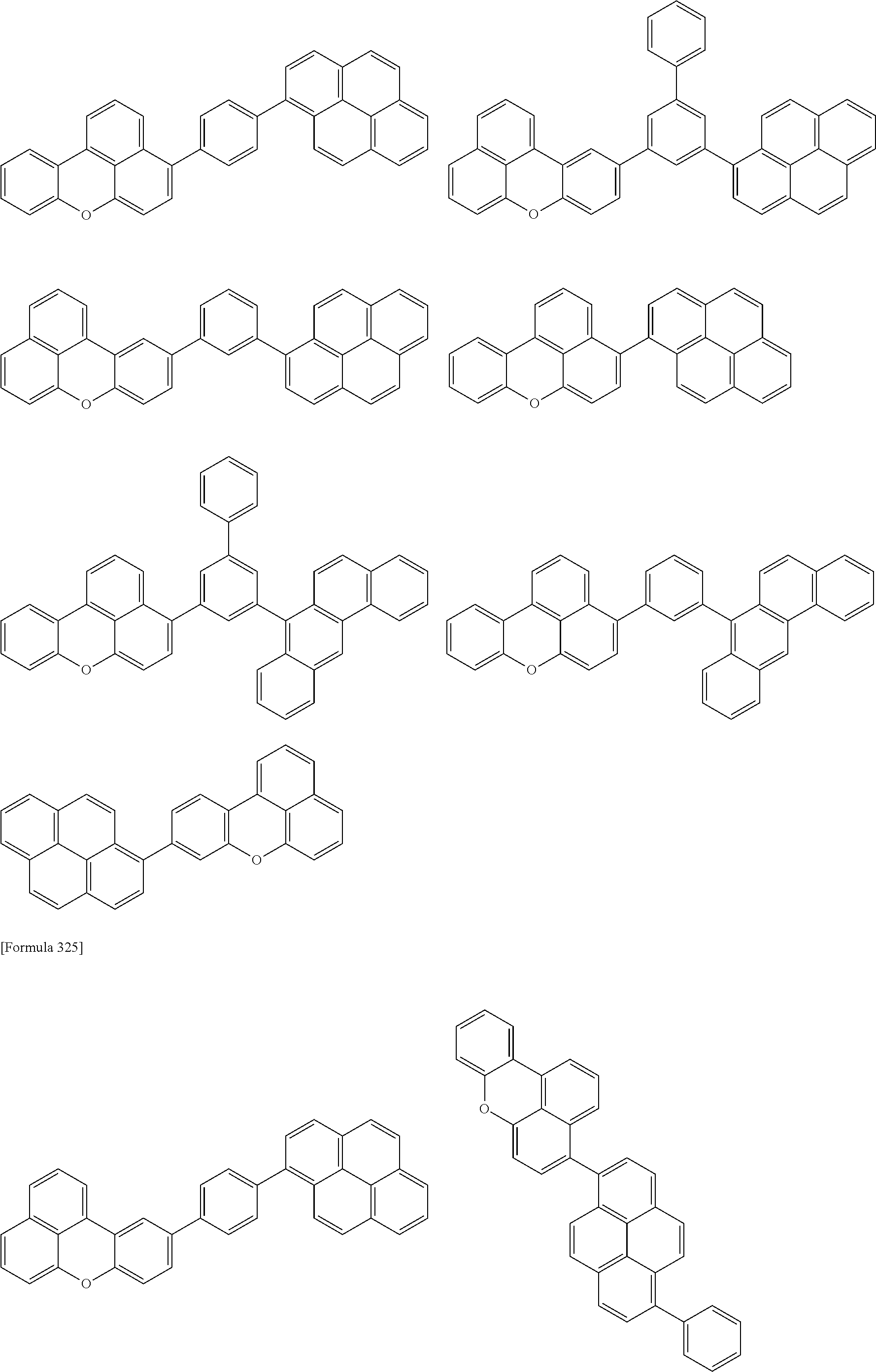

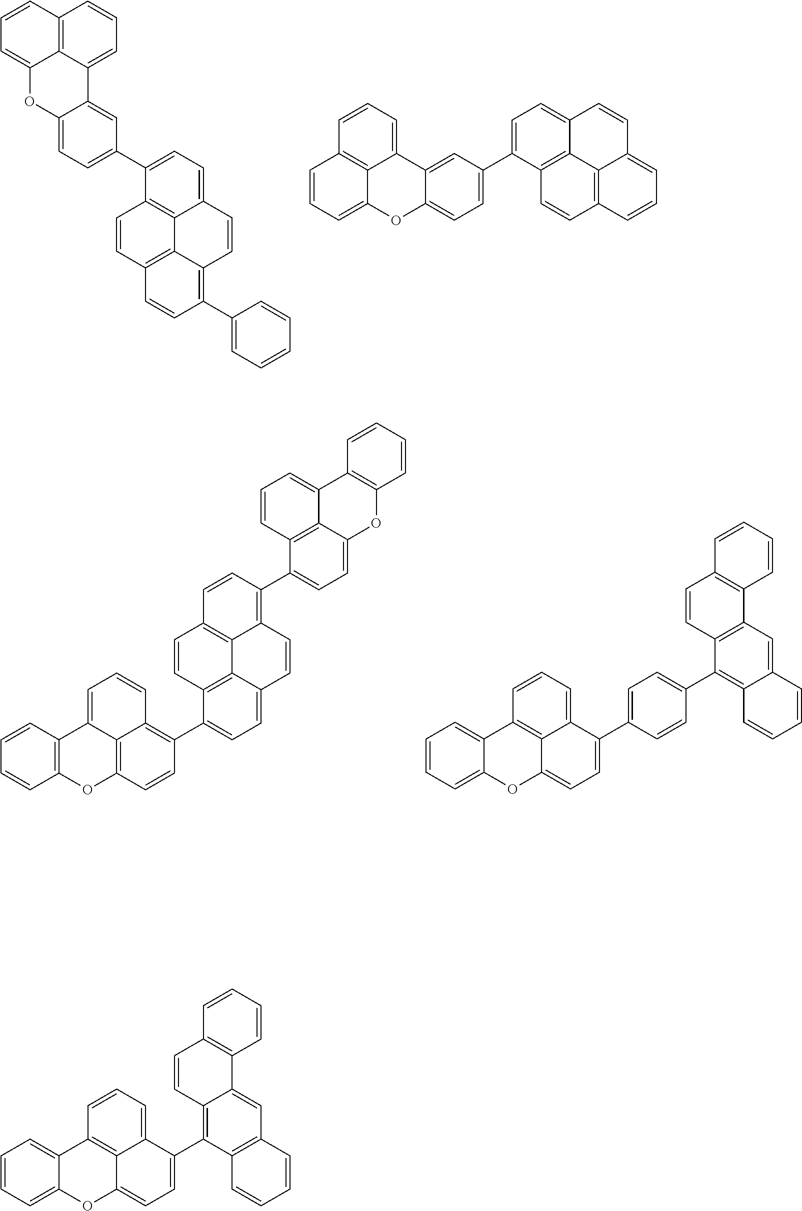 [SMILES: c1ccc(-c2ccc3ccc4c(-c5ccc6c(c5)-c5cccc7cccc(c57)O6)ccc5ccc2c3c54)cc1 ; c1cc2c3c(cccc3c1)-c1cc(-c3ccc4ccc5cccc6ccc3c4c56)ccc1O2 ; c1ccc2c(c1)Oc1ccc(-c3ccc4ccc5c(-c6ccc7c8c(cccc68)-c6ccccc6O7)ccc6ccc3c4c65)c3cccc-2c13 ; c1ccc2c(c1)Oc1ccc(-c3ccc(-c4c5ccccc5cc5c4ccc4ccccc45)cc3)c3cccc-2c13 ; c1ccc2c(c1)Oc1ccc(-c3c4ccccc4cc4c3ccc3ccccc34)c3cccc-2c13]

### Second Compound

In an exemplary arrangement of the exemplary embodiment, the second compound represented by the formula (2) will be described.

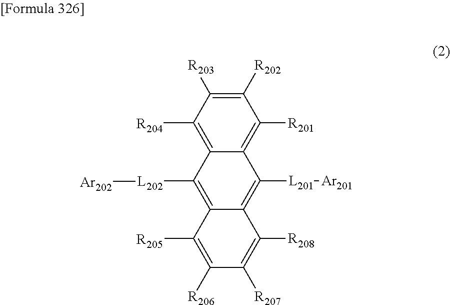

In the formula (2):
R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₂₀₁ and L₂₀₂ are each independently a single bond, a substituted or unsubstituted arylene group having 6 to 50 ring carbon atoms, or a substituted or unsubstituted divalent heterocyclic group having 5 to 50 ring atoms;
Ar₂₀₁ and Ar₂₀₂ are each independently a substituted or unsubstituted aryl group having 6 to 50 ring carbon atoms, or a substituted or unsubstituted heterocyclic group having 5 to 50 ring atoms.

In the second compound according to the exemplary embodiment, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary embodiment,
L₂₀₁ and L₂₀₂ are preferably each independently a single bond, or a substituted or unsubstituted arylene group having 6 to 50 ring carbon atoms; and
Ar₂₀₁ and Ar₂₀₂ are preferably each independently a substituted or unsubstituted aryl group having 6 to 50 ring carbon atoms.

In an exemplary embodiment, Ar₂₀₁ and Ar₂₀₂ are preferably each independently a phenyl group, naphthyl group, phenanthryl group, biphenyl group, terphenyl group, diphenylfluorenyl group, dimethylfluorenyl group, benzodiphenylfluorenyl group, benzodimethylfluorenyl group, dibenzofuranyl group, dibenzothienyl group, naphthobenzofuranyl group, or naphthobenzothienyl group.

In an exemplary embodiment: in the second compound represented by the formula (2), R₂₀₁ to R₂₀₈ are preferably each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary embodiment: L₂₀₁ is preferably a single bond, or an unsubstituted arylene group having 6 to 22 ring carbon atoms; and
Ar₂₀₁ is preferably a substituted or unsubstituted aryl group having 6 to 22 ring carbon atoms.

In an exemplary embodiment: in the second compound represented by the formula (2), R₂₀₁ to R₂₀₈ are preferably each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary embodiment, R₂₀₁ to R₂₀₈ in the second compound represented by the formula (2) are preferably each a hydrogen atom.

In an exemplary embodiment, it is also preferable that the second compound is a compound of the formula (2) in which L₂₀₂ is a single bond and Ar₂₀₂ is an unsubstituted phenyl group.

In an exemplary embodiment, it is also preferable that the second compound is a compound of the formula (2) in which L₂₀₂ is a single bond and Ar₂₀₂ is an unsubstituted 2-naphthyl group.

In an exemplary embodiment, it is also preferable that the second compound is a compound of the formula (2) in which L₂₀₂ is a single bond and Ar₂₀₂ is an unsubstituted 1-naphthyl group.

In an exemplary embodiment, it is also preferable that the second compound is a compound of the formula (2) in which L₂₀₂ is an unsubstituted p-phenylene group and Ar₂₀₂ is an unsubstituted phenyl group.

In an exemplary embodiment, it is also preferable that the second compound is a compound of the formula (2) in which L₂₀₂ is an unsubstituted m-phenylene group and Ar₂₀₂ is an unsubstituted phenyl group.

In an exemplary embodiment, it is also preferable that the second compound is a compound of the formula (2) in which L₂₀₂ is an unsubstituted o-phenylene group and Ar₂₀₂ is an unsubstituted phenyl group.

In an exemplary embodiment, it is also preferable that the second compound is a compound of the formula (2) in which L₂₀₂ is an unsubstituted p-phenylene group and Ar₂₀₂ is an unsubstituted 1-naphthyl group.

In an exemplary embodiment, it is also preferable that the second compound is a compound of the formula (2) in which L₂₀₂ is an unsubstituted p-phenylene group and Ar₂₀₂ is an unsubstituted 2-naphthyl group.

In an exemplary embodiment, it is also preferable that the second compound is a compound of the formula (2) in which L₂₀₂ is an unsubstituted 1,4-naphthalenediyl group and Ar₂₀₂ is an unsubstituted phenyl group.

In an exemplary embodiment, it is also preferable that the second compound is a compound of the formula (2) in which L₂₀₂ is an unsubstituted m-phenylene group and Ar₂₀₂ is an unsubstituted 2-naphthyl group.

In an exemplary embodiment, the second compound is also preferably a compound represented by a formula (2X) below.

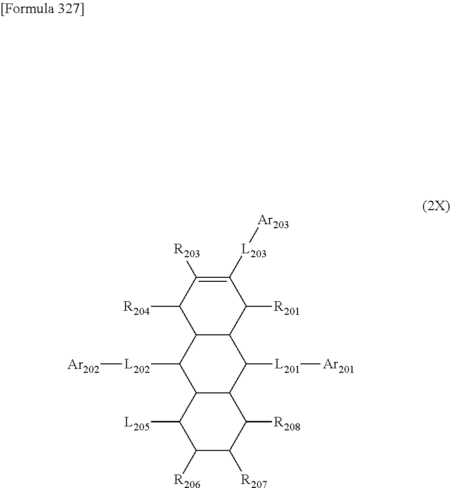

In the formula (2X):
R₂₀₁ and R₂₀₃ to R₂₀₈ each independently represent the same as R₂₀₁ and R₂₀₃ to R₂₀₈ in the formula (2);
L₂₀₁, L₂₀₂, Ar₂₀₁ and Ar₂₀₂ respectively represent the same as L₂₀₁, L₂₀₂, Ar₂₀₁ and Ar₂₀₂ in the formula (2);
L₂₀₃ represents the same as L₂₀₁ in the formula (2);
L₂₀₁, L₂₀₂, and L₂₀₃ are mutually the same or different;
Ar₂₀₃ represents the same as Ar₂₀₁ in the formula (2); and
Ar₂₀₁, Ar₂₀₂, and Ar₂₀₃ are mutually the same or different.

In an exemplary embodiment, it is also preferable that the second compound is a compound of the formula (2X) in which L₂₀₂ is a single bond and Ar₂₀₂ is an unsubstituted phenyl group.

In an exemplary embodiment, it is also preferable that the second compound is a compound of the formula (2X) in which L₂₀₂ is a single bond and Ar₂₀₂ is an unsubstituted 2-naphthyl group.

In an exemplary embodiment, it is also preferable that the second compound is a compound of the formula (2X) in which L₂₀₂ is a single bond and Ar₂₀₂ is an unsubstituted 1-naphthyl group.

In an exemplary embodiment, it is also preferable that the second compound is a compound of the formula (2X) in which L₂₀₂ is an unsubstituted p-phenylene group and Ar₂₀₂ is an unsubstituted phenyl group.

In an exemplary embodiment, it is also preferable that the second compound is a compound of the formula (2X) in which L₂₀₂ is an unsubstituted m-phenylene group and Ar₂₀₂ is an unsubstituted phenyl group.

In an exemplary embodiment, it is also preferable that the second compound is a compound of the formula (2X) in which L₂₀₂ is an unsubstituted o-phenylene group and Ar₂₀₂ is an unsubstituted phenyl group.

In an exemplary embodiment, it is also preferable that the second compound is a compound of the formula (2X) in which L₂₀₂ is an unsubstituted p-phenylene group and Ar₂₀₂ is an unsubstituted 1-naphthyl group.

In an exemplary embodiment, it is also preferable that the second compound is a compound of the formula (2X) in which L₂₀₂ is an unsubstituted p-phenylene group and Ar₂₀₂ is an unsubstituted 2-naphthyl group.

In an exemplary embodiment, it is also preferable that the second compound is a compound of the formula (2X) in which L₂₀₂ is an unsubstituted 1,4-naphthalenediyl group and Ar₂₀₂ is an unsubstituted phenyl group.

In an exemplary embodiment, it is also preferable that the second compound is a compound of the formula (2X) in which L₂₀₂ is an unsubstituted m-phenylene group and Ar₂₀₂ is an unsubstituted 2-naphthyl group.

In an exemplary embodiment, it is also preferable that the second compound is a compound of the formula (2X) in which L₂₀₁ is a single bond and Ar₂₀₁ is an unsubstituted phenyl group.

In an exemplary embodiment, it is also preferable that the second compound is a compound of the formula (2X) in which L₂₀₁ is a single bond and Ar₂₀₁ is an unsubstituted 2-naphthyl group.

In an exemplary embodiment, it is also preferable that the second compound is a compound of the formula (2X) in which L₂₀₁ is a single bond and Ar₂₀₁ is an unsubstituted 1-naphthyl group.

In an exemplary embodiment, it is also preferable that the second compound is a compound of the formula (2X) in which L₂₀₁ is an unsubstituted p-phenylene group and Ar₂₀₁ is an unsubstituted phenyl group.

In an exemplary embodiment, it is also preferable that the second compound is a compound of the formula (2X) in which L₂₀₁ is an unsubstituted m-phenylene group and Ar₂₀₁ is an unsubstituted phenyl group.

In an exemplary embodiment, it is also preferable that the second compound is a compound of the formula (2X) in which L₂₀₁ is an unsubstituted o-phenylene group and Ar₂₀₁ is an unsubstituted phenyl group.

In an exemplary embodiment, it is also preferable that the second compound is a compound of the formula (2X) in which L₂₀₁ is an unsubstituted p-phenylene group and Ar₂₀₁ is an unsubstituted 1-naphthyl group.

In an exemplary embodiment, it is also preferable that the second compound is a compound of the formula (2X) in which L₂₀₁ is an unsubstituted p-phenylene group and Ar₂₀₁ is an unsubstituted 2-naphthyl group.

In an exemplary embodiment, it is also preferable that the second compound is a compound of the formula (2X) in which L₂₀₁ is an unsubstituted 1,4-naphthalenediyl group and Ar₂₀₁ is an unsubstituted phenyl group.

In an exemplary embodiment, it is also preferable that the second compound is a compound of the formula (2X) in which L₂₀₁ is an unsubstituted m-phenylene group and Ar₂₀₁ is an unsubstituted 2-naphthyl group.

In the second compound, the groups specified to be “substituted or unsubstituted” are each preferably an “unsubstituted” group.

In an exemplary embodiment, the second emitting layer preferably contains the second compound represented by the formula (2) as the second host material. Accordingly, for instance, the second emitting layer contains 50 mass % or more of the second compound represented by the formula (2) with respect to the total mass of the second emitting layer.

In an exemplary arrangement of the exemplary embodiment, R₂₀₁ to R₂₀₈ that are substituents of an anthracene skeleton in the second compound represented by the formula (2) are preferably hydrogen atoms in terms of preventing inhibition of intermolecular interaction and inhibiting decrease in electron mobility. However, R₂₀₁ to R₂₀₈ may be a substituted or unsubstituted aryl group having 6 to 50 ring carbon atoms or a substituted or unsubstituted heterocyclic group having 5 to 50 ring atoms.

Assuming that R₂₀₁ to R₂₀₈ are each a bulky substituent such as an alkyl group and a cycloalkyl group, intermolecular interaction may be inhibited to decrease the electron mobility to the first host material. Provided that the electron mobility of the first host material is denoted by μe(H1) and the electron mobility of the second host material is denoted by μe(H2), a relationship of μe(H2)>μe(H1) may not be satisfied. In a case where the second compound is used in the first emitting layer, it can be expected that satisfying the relationship of μe(H2)>μe(H1) inhibits a decrease in a recombination ability between holes and electrons in the first sensitizing layer. It should be noted that substituents, namely, a haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group are likely to be bulky, and an alkyl group and cycloalkyl group are likely to be further bulky.

In the second compound represented by the formula (2), R₂₀₁ to R₂₀₈, which are the substituents on the anthracene skeleton, are each preferably not a bulky substituent and preferably not an alkyl group and cycloalkyl group. More preferably, R₃₀₁ to R₃₀₈ are each not an alkyl group and cycloalkyl group. Still more preferably, R₃₀₁ to R₃₀₈ are each not an alkyl group, cycloalkyl group haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the second compound, examples of the substituent for the “substituted or unsubstituted” group on R₂₀₁ to R₂₀₈ also preferably do not include the above-described substituents that are likely to be bulky, especially a substituted or unsubstituted alkyl group and a substituted or unsubstituted cycloalkyl group. When examples of the substituent for the “substituted or unsubstituted” group on R₂₀₁ to R₂₀₈ do not include a substituted or unsubstituted alkyl group and a substituted or unsubstituted cycloalkyl group, inhibition of intermolecular interaction to be caused by presence of a bulky substituent such as an alkyl group and a cycloalkyl group can be prevented, thereby preventing a decrease in the electron mobility. Moreover, when the second compound described above is used in the first emitting layer, a decrease in a recombination ability between holes and electrons in the first sensitizing layer can be inhibited.

Further preferably, R₂₀₁ to R₂₀₈ that are the substituents on the anthracene skeleton are not bulky substituents and R₂₀₁ to R₂₀₈ as substituents are unsubstituted. Assuming that R₂₀₁ to R₂₀₈ that are the substituents on the anthracene skeleton are not bulky substituents and substituents are bonded to R₂₀₁ to R₂₀₈ that are not bulky substituents, the substituents bonded to R₂₀₁ to R₂₀₈ are preferably not bulky substituents; and the substituents bonded to R₂₀₁ to R₂₀₈ serving as substituents are preferably not an alkyl group and cycloalkyl group, and more preferably not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

### Method of Producing Second Compound

The second compound can be produced by a known method. Further, the second compound can be produced based on a known method through a known alternative reaction using a known material(s) tailored for the target compound.

### Specific Examples of Second Compound

Specific examples of the second compound include the following compounds. However, the invention is not limited to the specific examples of the second compound.

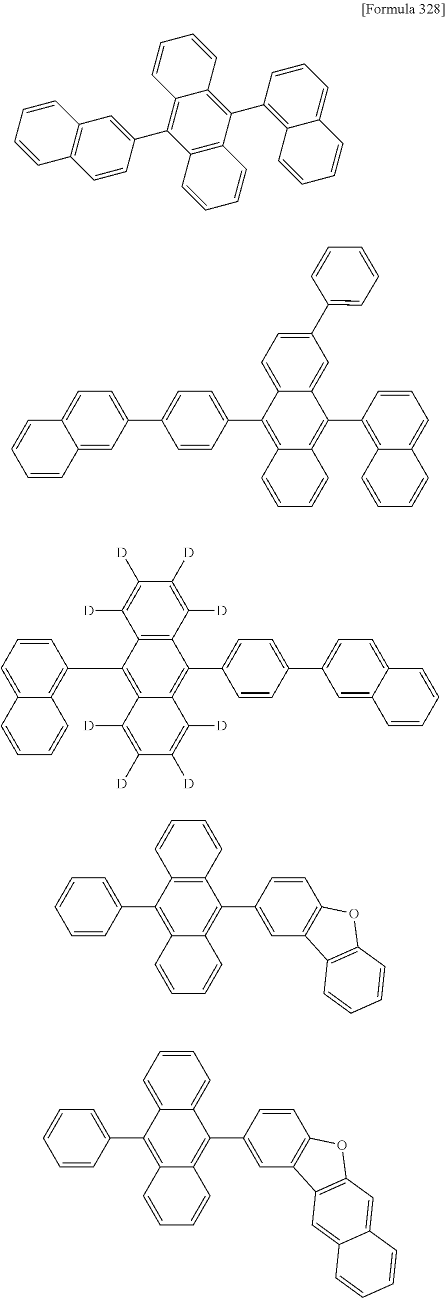

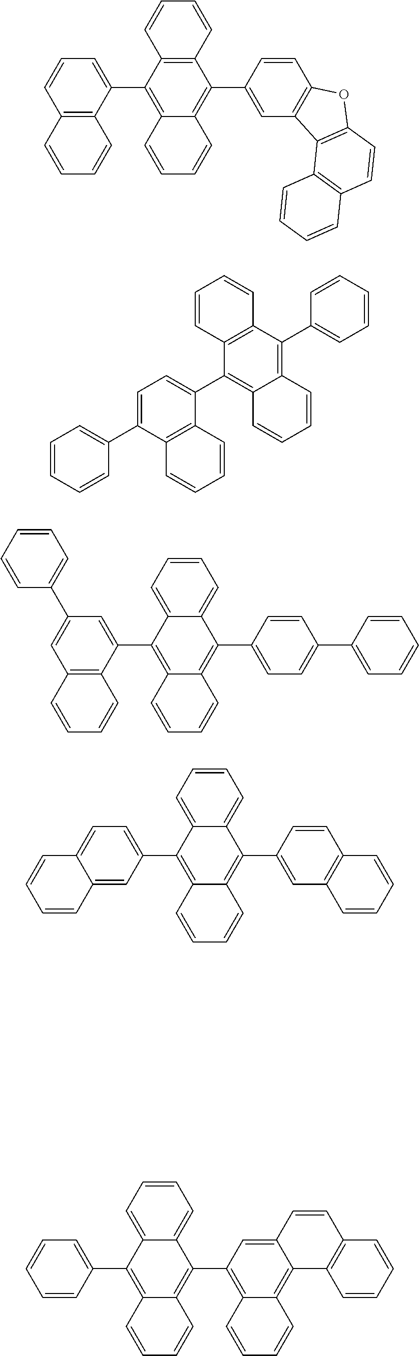

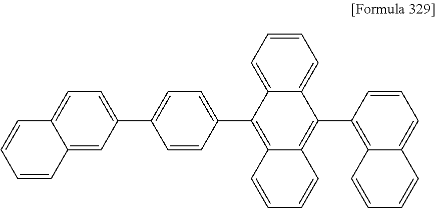 [SMILES: c1ccc2cc(-c3ccc(-c4c5ccccc5c(-c5cccc6ccccc56)c5ccccc45)cc3)ccc2c1]

### First Luminescent Compound

In an exemplary arrangement of the exemplary embodiment, the first luminescent compound is a fluorescent material. Examples of the fluorescent material include bisarylaminonaphthalene derivatives, aryl-substituted naphthalene derivatives, bisarylaminoanthracene derivatives, aryl-substituted anthracene derivatives, bisarylamino pyrene derivatives, aryl-substituted pyrene derivatives, bisarylamino chrysene derivatives, aryl-substituted chrysene derivatives, bisarylamino fluoranthene derivatives, aryl-substituted fluoranthene derivatives, indenoperylene derivatives, acenaphthofluoranthene derivatives, compounds containing boron atoms, pyromethene boron complex compounds, compounds with pyromethene skeleton, metal complexes of compounds with pyromethene skeleton, diketopyrrolopyrrole derivatives, perylene derivatives, and naphthacene derivatives.

In an exemplary arrangement of the exemplary embodiment, the first luminescent compound is exemplified by a compound represented by a formula (5), (6), or (3A) below.

### Compound Represented by Formula (5)

In an exemplary arrangement of the organic EL device according to the exemplary embodiment, the first luminescent compound is a compound represented by the formula (5) below.

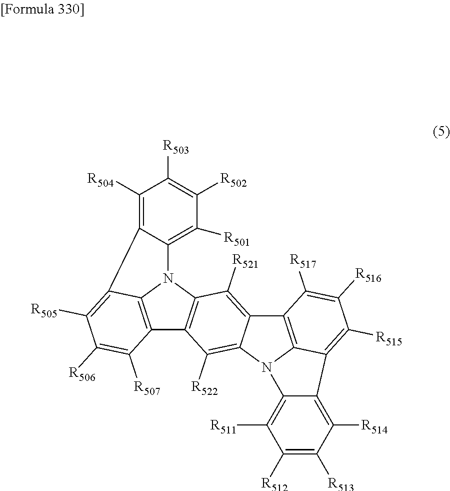

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded;
R₅₀₁ to R₅₀₇ and R₅₁₁ to R₅₁₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₅₂₁ and R₅₂₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the first luminescent compound, R₉₀₁, R₉₀₂, R₉₀₃, R₉₀₄, R₉₀₅, R₉₀₆ and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
preferably, a substituted or unsubstituted alkyl group having 1 to 50 carbon atoms, or a substituted or unsubstituted aryl group having 6 to 50 ring carbon atoms, and when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₉₀₆, a combination of R₅₀₆ and R₅₀₇, and a combination of R₅₀₁, R₅₀₂, and R₅₀₃.

In an exemplary embodiment, the compound represented by the formula (5) is a compound represented by a formula (52) below.

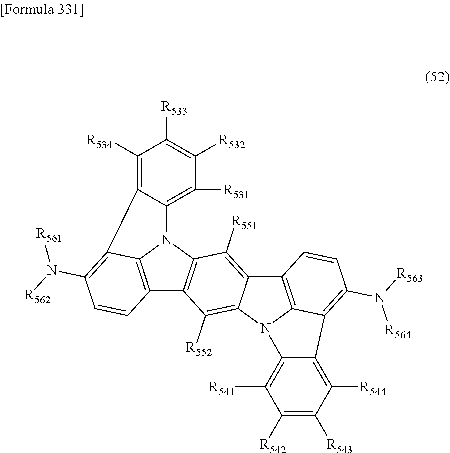

In the formula (52):
at least one combination of adjacent two or more of R₅₃₁ to R₅₃₄ and R₅₄₁ to R₅₄₄ are mutually bonded to form a substituted or unsubstituted monocyclic ring, mutually bonded to form a substituted or unsubstituted fused ring, or not mutually bonded;
R₅₃₁ to R₅₃₄, R₅₄₁ to R₅₄₄, R₅₅₁, and R₅₅₂ forming neither the substituted or unsubstituted monocyclic ring nor the substituted or unsubstituted fused ring are each independently a hydrogen atom, a substituted or unsubstituted aryl group having 6 to 50 ring carbon atoms, or a substituted or unsubstituted heterocyclic group having 5 to 50 ring atoms; and
R₅₆₁ to R₅₆₄ are each independently a substituted or unsubstituted aryl group having 6 to 50 ring carbon atoms, or a substituted or unsubstituted heterocyclic group having 5 to 50 ring atoms.

### Compound Represented by Formula (6)

In an exemplary arrangement of the organic EL device according to the exemplary embodiment, the first luminescent compound is a compound represented by the formula (6) below.

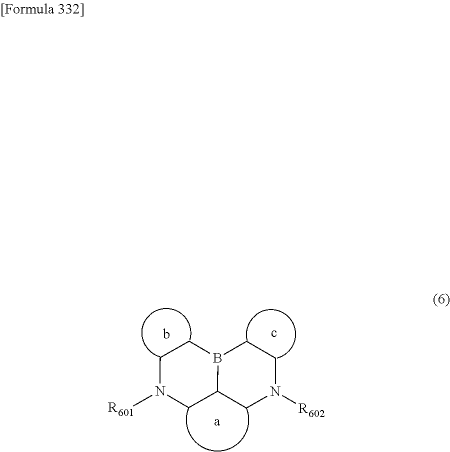

In the formula (6):
a ring a, a ring b and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀₂ are each independently bonded to the ring a, the ring b, or the ring c to form a substituted or unsubstituted heterocycle, or not bonded thereto to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary arrangement of the organic EL device according to the exemplary embodiment, the ring a, ring b and ring c are each a ring (a substituted or unsubstituted aromatic hydrocarbon ring having 6 to 50 ring carbon atoms, or a substituted or unsubstituted heterocycle having 5 to 50 ring atoms) fused with a fused bicyclic structure formed of a boron atom and two nitrogen atoms at the center of the formula (6).

The “aromatic hydrocarbon ring” for the rings a, b, and c has the same structure as a compound formed by introducing a hydrogen atom to an “aryl group”.

Ring atoms of the “aromatic hydrocarbon ring” for the ring a include three carbon atoms on the fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ may be each independently bonded with the ring a, ring b, or ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom. R₆₀₁ and R₆₀₂ being bonded with the ring a, ring b, or ring c specifically means that atoms forming R₆₀₁ and R₆₀₂ are bonded with atoms forming the ring a, ring b, or ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀₂ bonded with the ring a, and R₆₀₂ bonded with the ring c.

R₆₀₁ and R₆₀₂ may be each independently not bonded with the ring a, ring b, or ring c.

In an exemplary embodiment, the ring a, ring b and ring c in the formula (6) are each independently a substituted or unsubstituted aromatic hydrocarbon ring having 6 to 50 ring carbon atoms.

In an exemplary embodiment, the ring a, ring b and ring c in the formula (6) are each independently a substituted or unsubstituted benzene ring or a substituted or unsubstituted naphthalene ring.

In an exemplary embodiment, R₆₀₁ and R₆₀₂ in the formula (6) are each independently a substituted or unsubstituted aryl group having 6 to 50 ring carbon atoms, or a substituted or unsubstituted heterocyclic group having 5 to 50 ring atoms,
preferably a substituted or unsubstituted aryl group having 6 to 50 ring carbon atoms.

In an exemplary embodiment, the compound represented by the formula (6) is a compound represented by a formula (62) below.

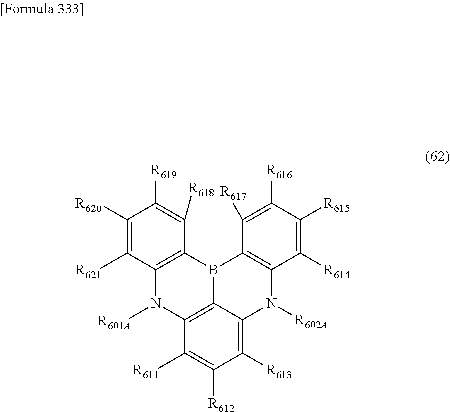

In the formula (62):
R_{601A is} bonded with at least one selected from the group consisting of R₆₁₁ and R₆₂₁ to form a substituted or unsubstituted heterocycle, or not bonded therewith to form no substituted or unsubstituted heterocycle;
R_{602A} is bonded with at least one selected from the group consisting of R₆₁₃ and R₆₁₄ to form a substituted or unsubstituted heterocycle, or not bonded therewith to form no substituted or unsubstituted heterocycle;
R_{601A} and R_{602A} not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one combination of adjacent two or more of R₆₁₁ to R₆₂₁ are mutually bonded to form a substituted or unsubstituted monocyclic ring, mutually bonded to form a substituted or unsubstituted fused ring, or not mutually bonded; and
R₆₁₁ to R₆₂₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (62), R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

R_{601A} and R_{602A} in the formula (62) are groups that respectively correspond to R₆₀₁ and R₆₀₂ in the formula (6).

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₁, R_{602A} bonded with R₆₁₃, and R_{602A} bonded with R₆₁₄.

At least one combination of adjacent two or more of R₆₁₁ to R₆₂₁ may be mutually bonded to form a substituted or unsubstituted monocyclic ring, or mutually bonded to form a substituted or unsubstituted fused ring.

For instance, R₆₁₁ and R₆₁₂ are mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment, the compound represented by the formula (6) is a compound represented by a formula (42-2) below.

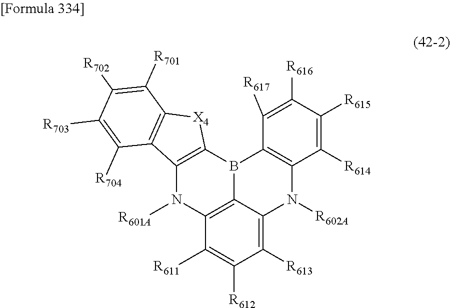

In the formula (42-2): R₆₁₁ to R₆₁₇, R_{601A} and R_{602A} each independently represent the same as R₆₁₁ to R₆₁₇, R_{601A} and R_{602A} in the formula (62);
X₄ is an oxygen atom or a sulfur atom;
at least one combination of adjacent two or more of R₇₀₁ to R₇₀₄ are mutually bonded to form a substituted or unsubstituted monocyclic ring, mutually bonded to form a substituted or unsubstituted fused ring, or not mutually bonded;
R₇₀₁ to R₇₀₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₉₀₁, R₉₀₂, R₉₀₃, R₉₀₄, R₉₀₅, R₉₀₆, and R₉₀₇ in the formula (42-2) each independently represent the same as R₉₀₁, R₉₀₂, R₉₀₃, R₉₀₄, R₉₀₅, R₉₀₆, and R₉₀₇ in the formula (62).

### Compound Represented by Formula (3A)

In an exemplary arrangement of the organic EL device according to the exemplary embodiment, the first luminescent compound is a compound represented by a formula (3A) below.

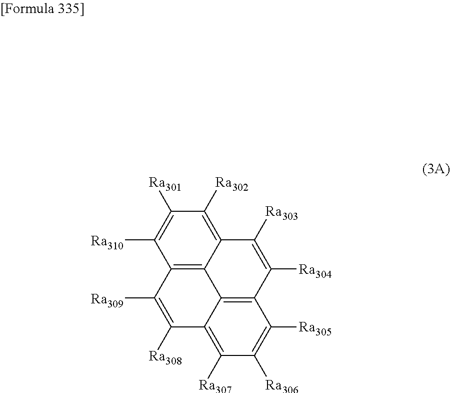

In the formula (3A):
at least one combination of adjacent two or more of Ra₃₀₁, Ra₃₀₂, Ra₃₀₃, Ra₃₀₄, Ra₃₀₅, Ra₃₀₆, Ra₃₀₇, Ra₃₀₈, Ra₃₀₉ and Ra₃₁₀ are mutually bonded to form a substituted or unsubstituted monocyclic ring, mutually bonded to form a substituted or unsubstituted fused ring, or not mutually bonded;
at least one of Ra₃₀₁ to Ra₃₁₀ is a monovalent group represented by a formula (31A) below; and
Ra₃₀₁ to Ra₃₁₀ forming neither the monocyclic ring nor the fused ring and not being the monovalent group represented by the formula (31A) are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

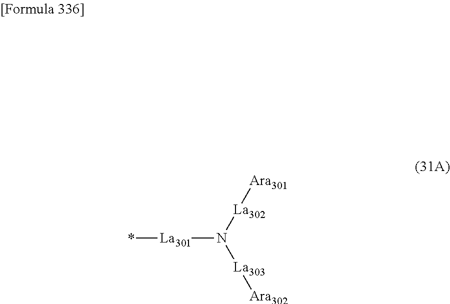

In the formula (31A):
Ara₃₀₁ and Ara₃₀₂ are each independently a substituted or unsubstituted aryl group having 6 to 50 ring carbon atoms, or a substituted or unsubstituted heterocyclic group having 5 to 50 ring atoms;
La₃₀₁, La₃₀₂, and La₃₀₃ are each independently a single bond, a substituted or unsubstituted arylene group having 6 to 30 ring carbon atoms, or a substituted or unsubstituted divalent heterocyclic group having 5 to 30 ring atoms; and
* represents a bonding position to a pyrene ring in the formula (3A).

### Specific Examples of First Luminescent Compound

Specific examples of the first luminescent compound are given below. It should however be noted that these specific examples are merely exemplary and the first luminescent compound is not limited thereto.

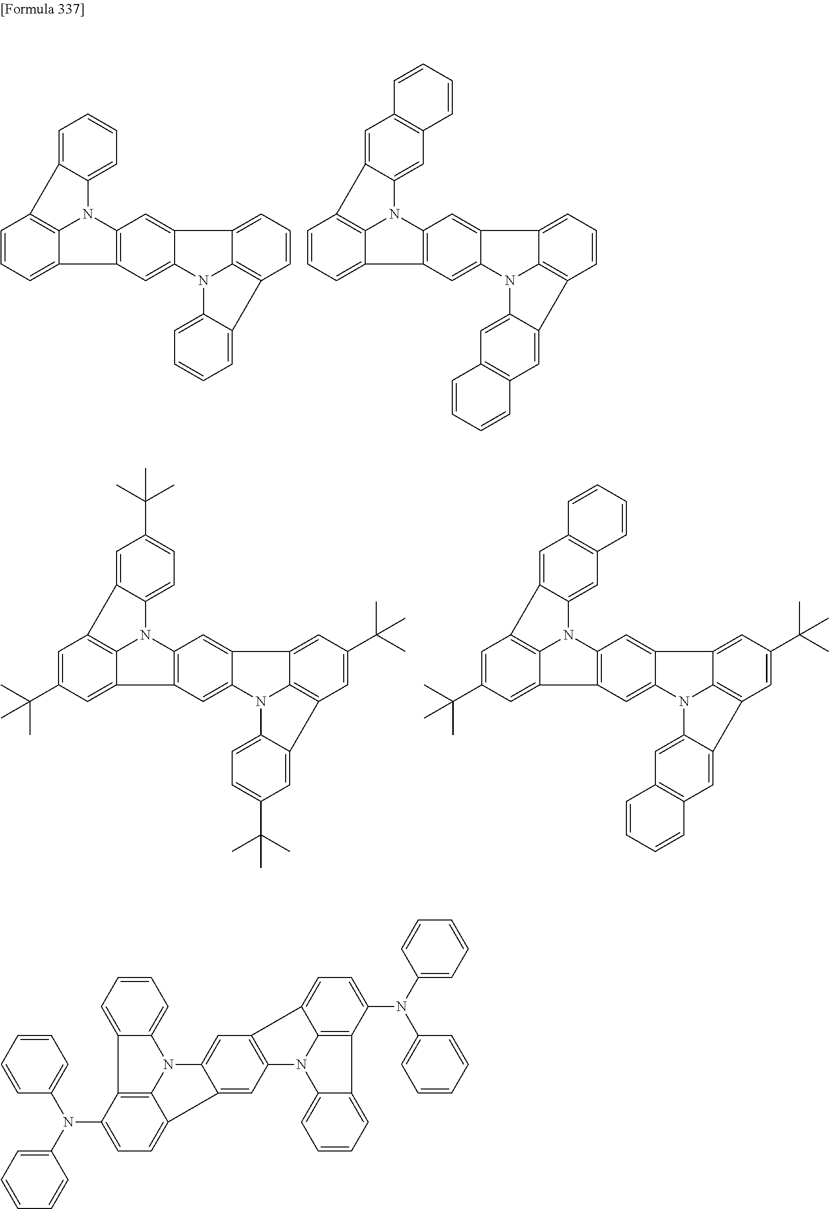

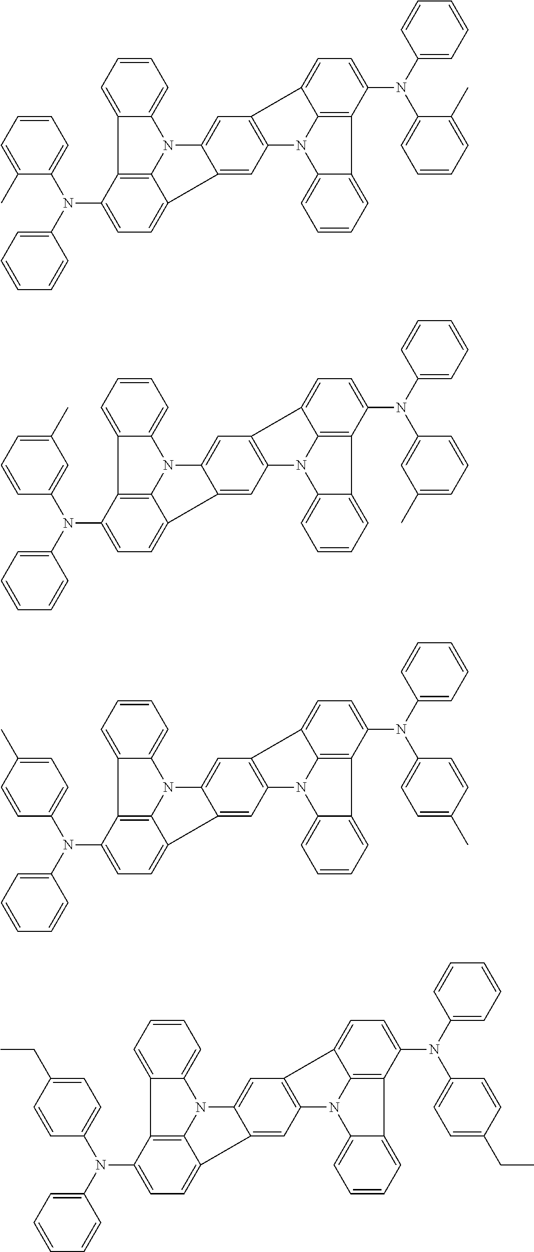

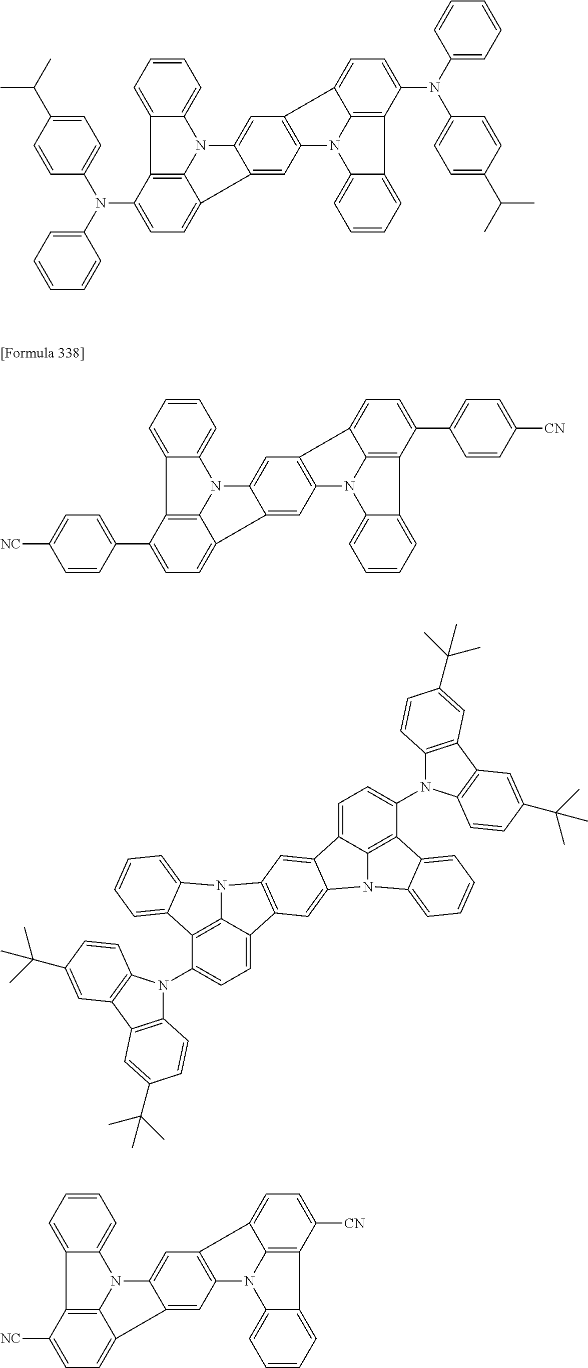

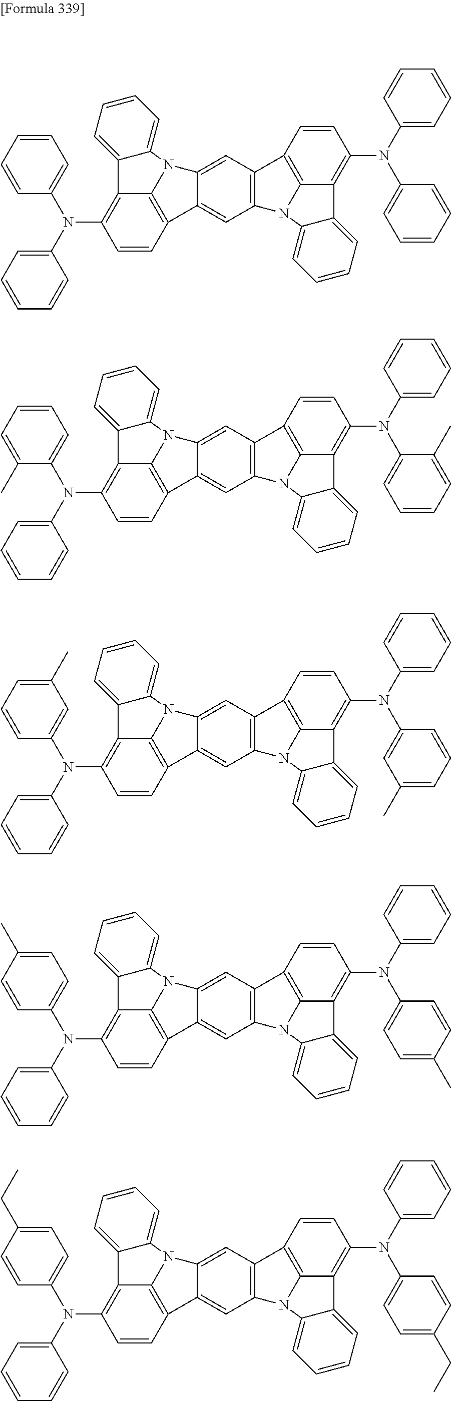

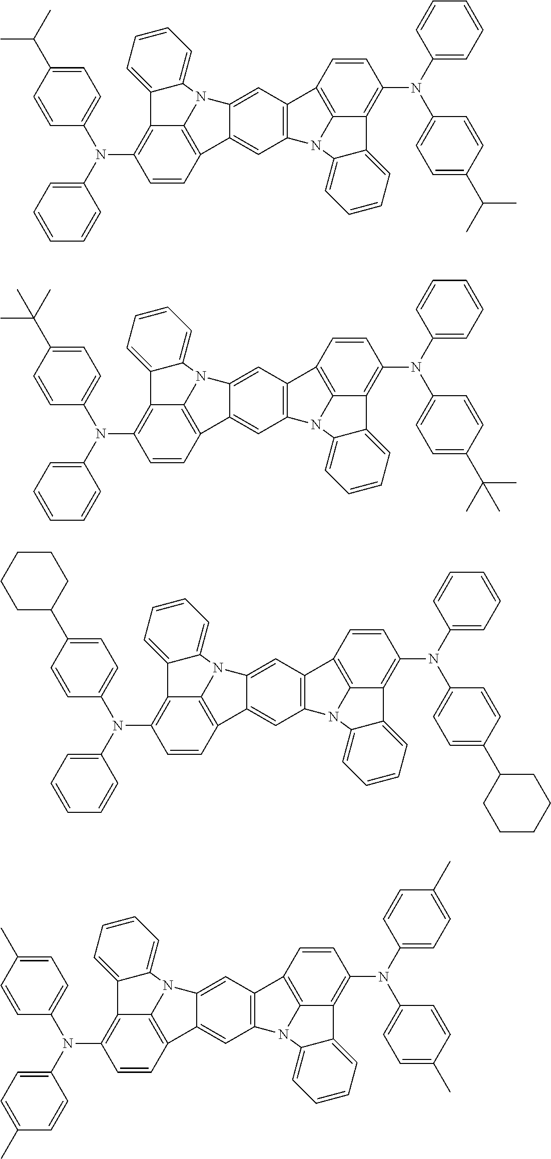

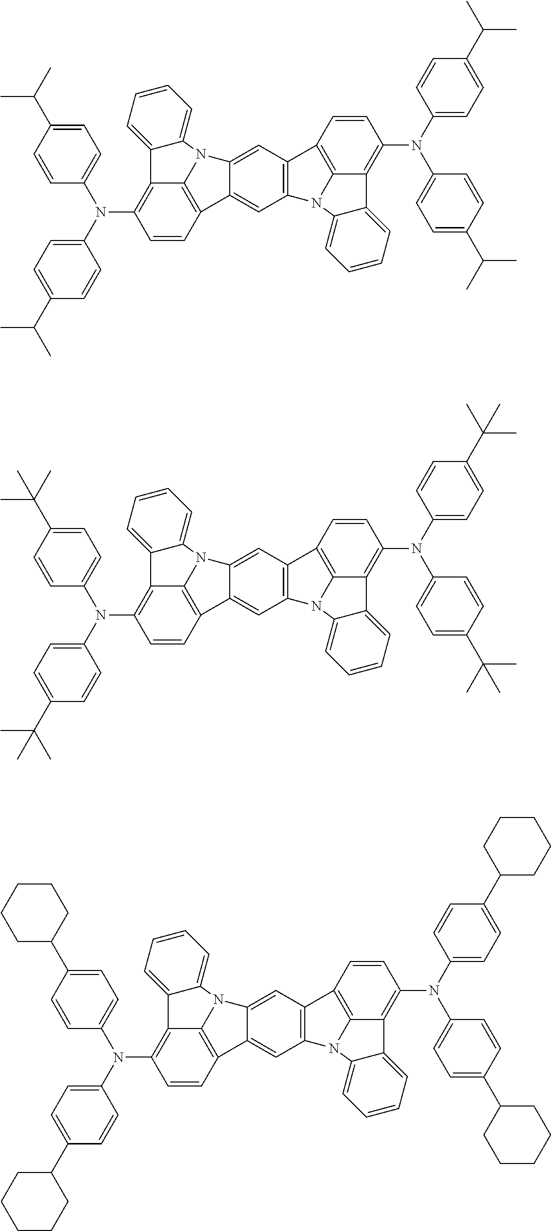

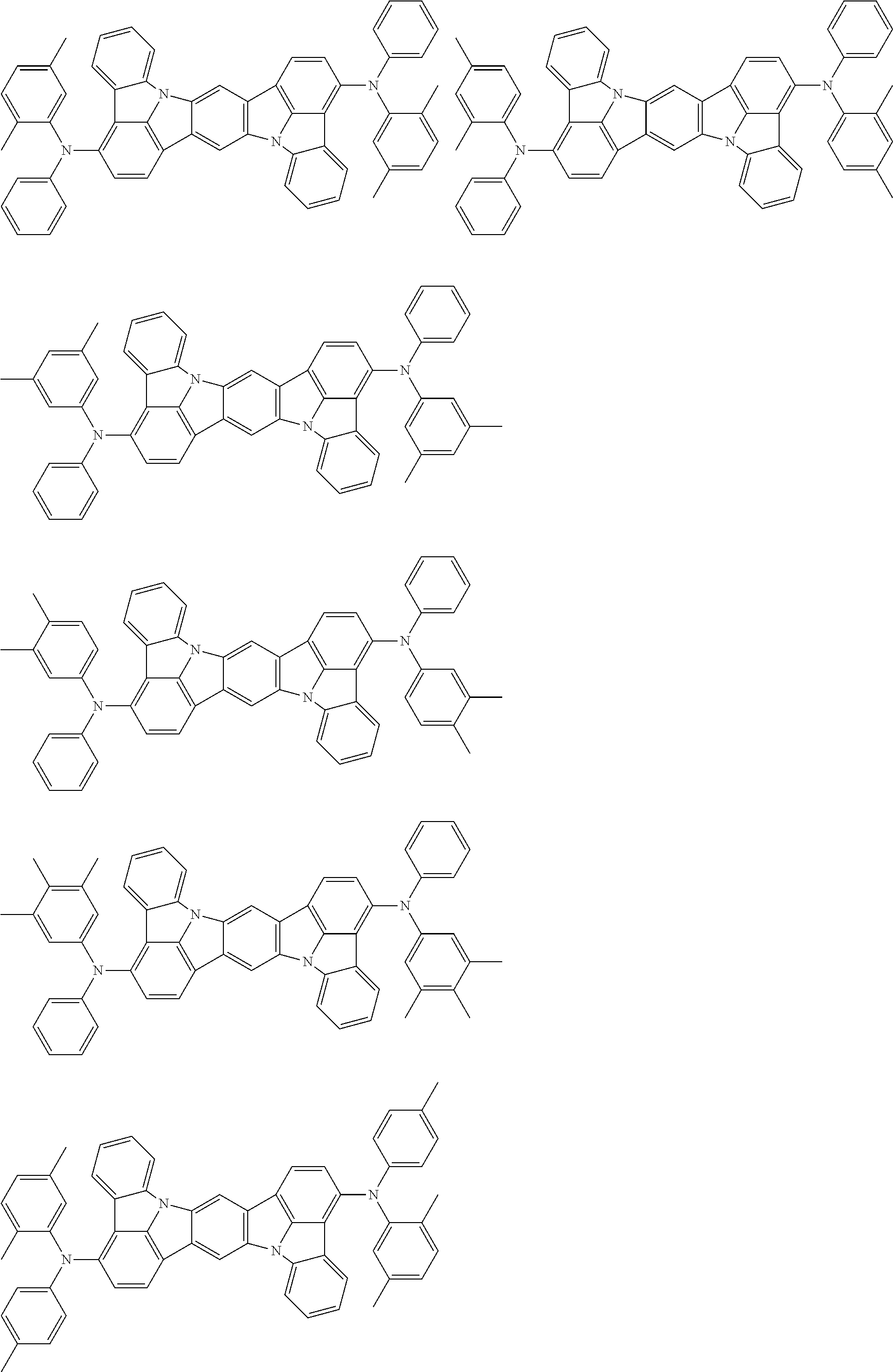

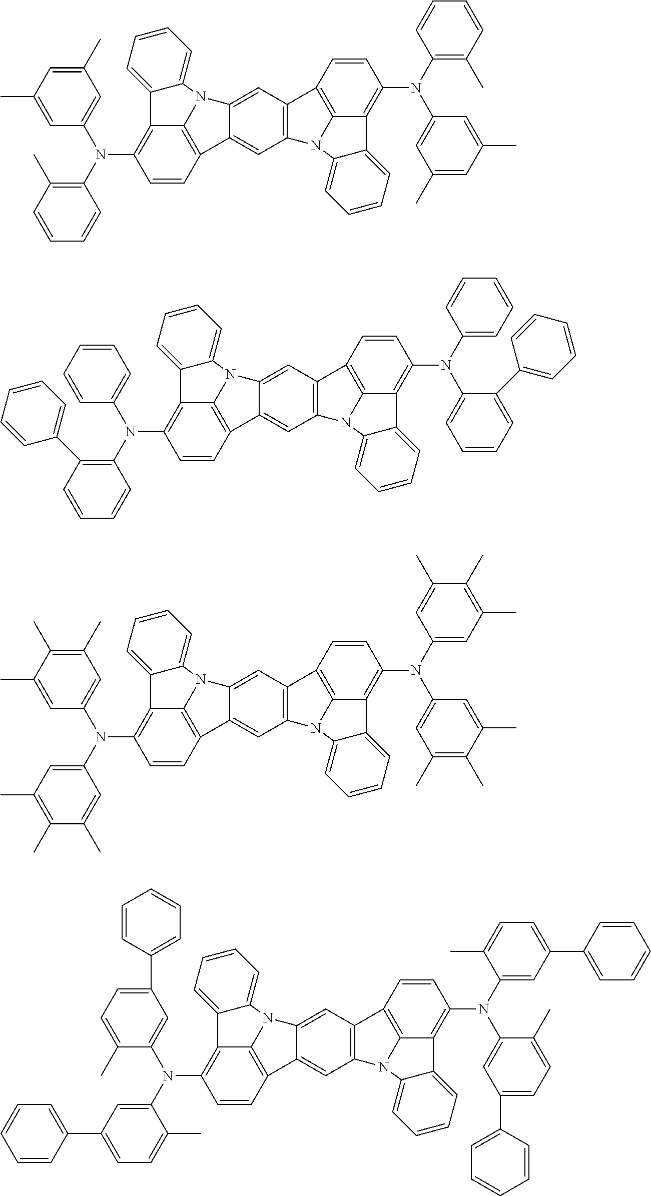

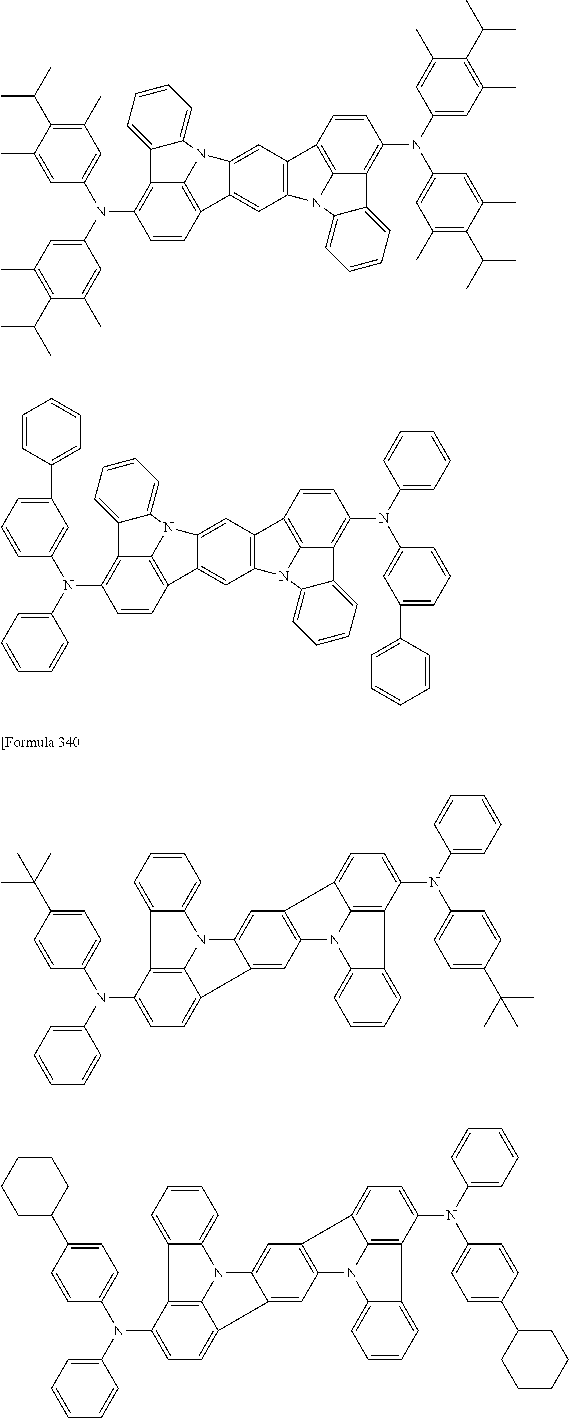

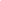

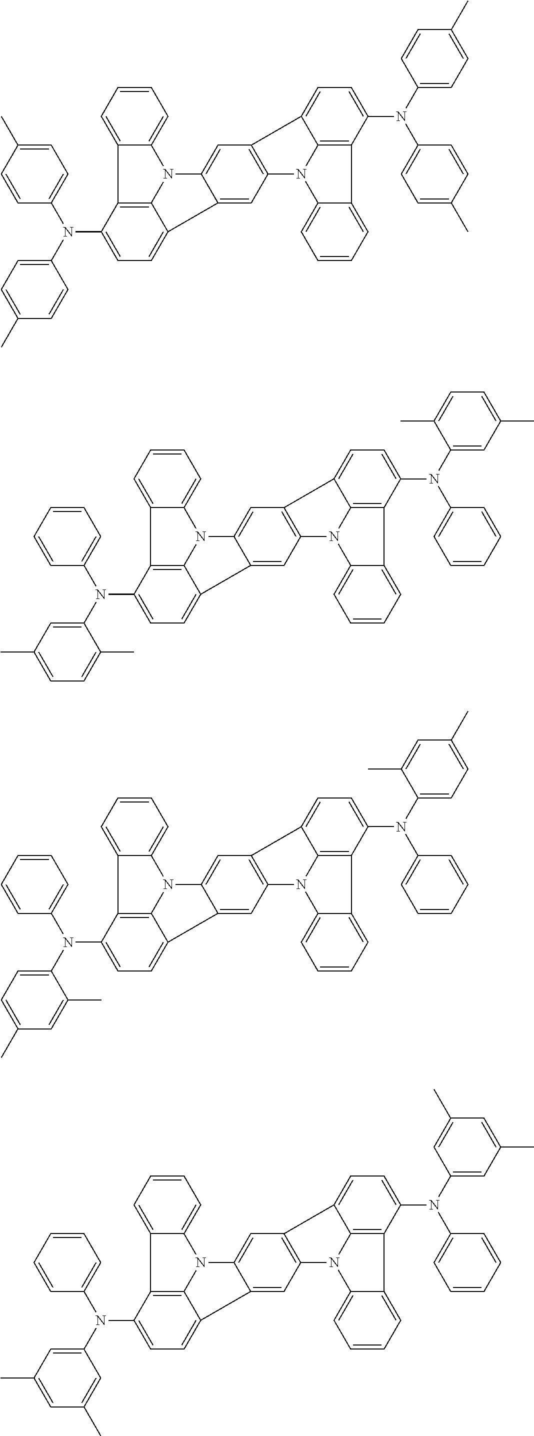

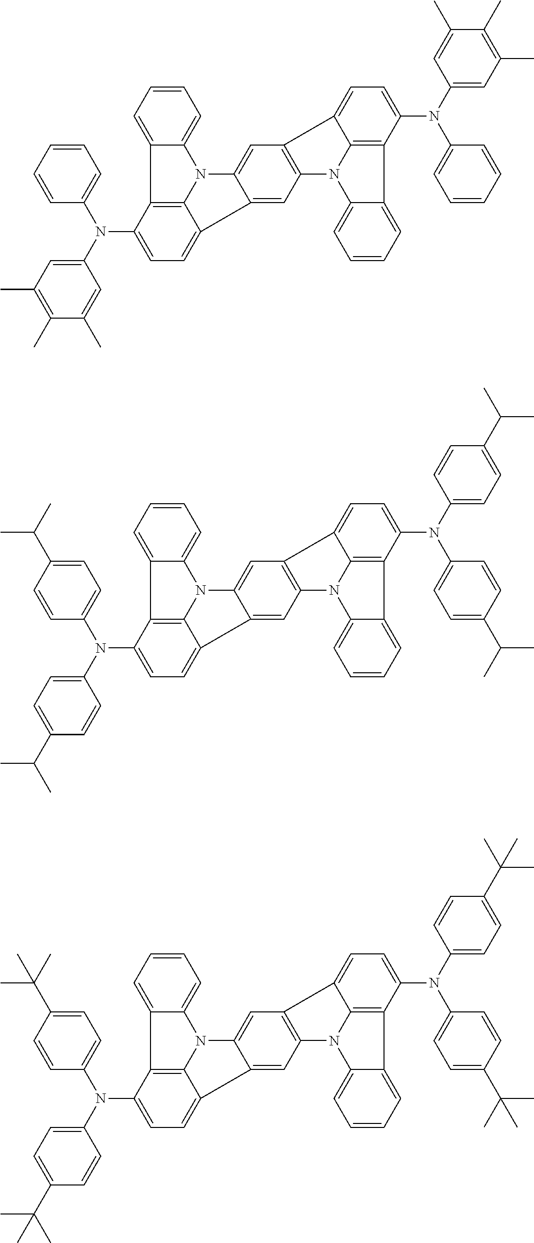

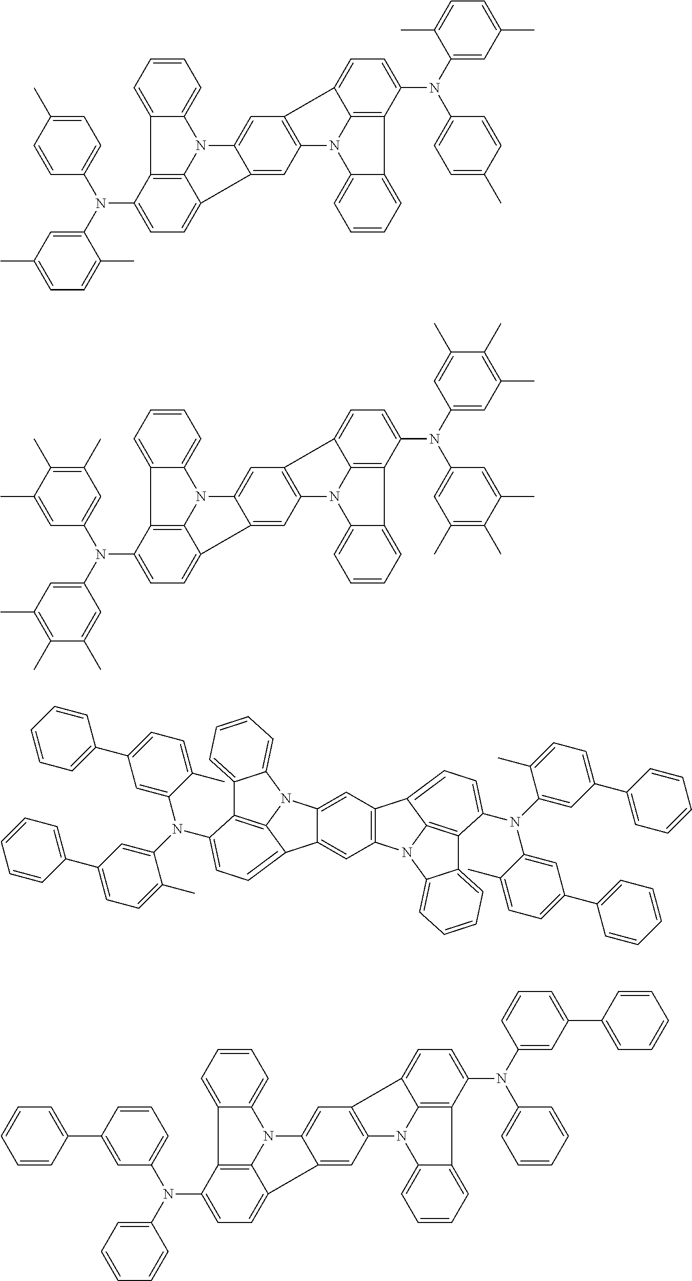

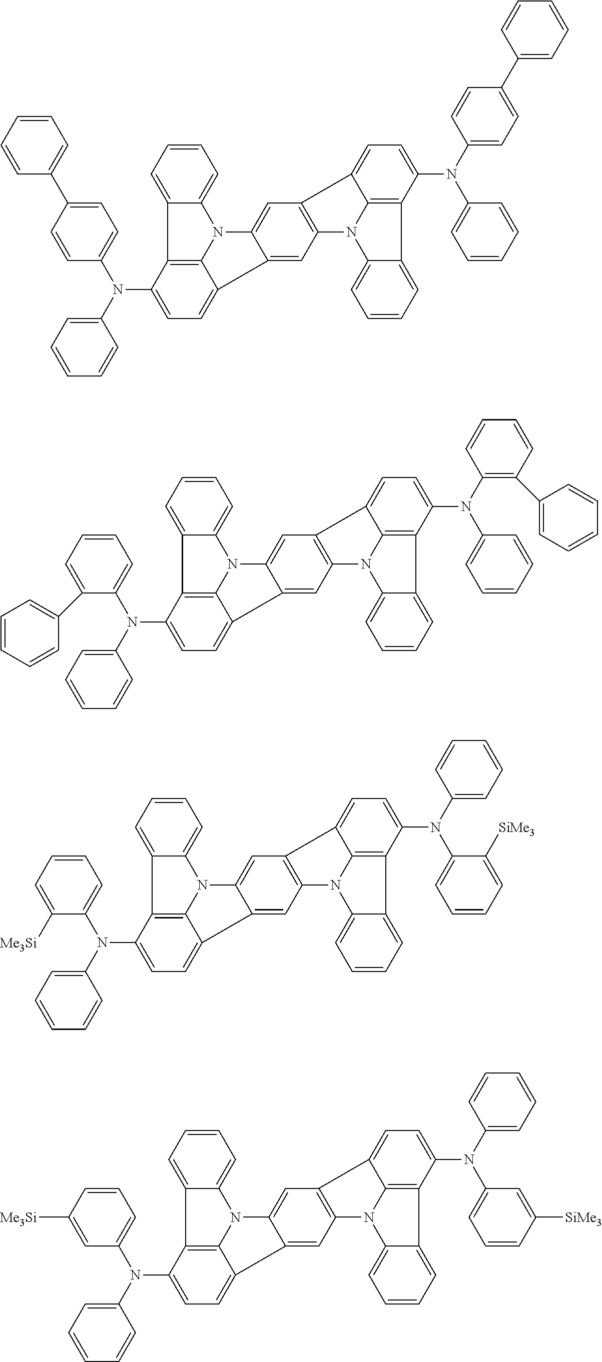 [SMILES: c1ccc(-c2ccc(N(c3ccccc3)c3ccc4c5cc6c(cc5n5c7ccccc7c3c45)c3ccc(N(c4ccccc4)c4ccc(-c5ccccc5)cc4)c4c5ccccc5n6c34)cc2)cc1 ; c1ccc(-c2ccccc2N(c2ccccc2)c2ccc3c4cc5c(cc4n4c6ccccc6c2c34)c2ccc(N(c3ccccc3)c3ccccc3-c3ccccc3)c3c4ccccc4n5c23)cc1 ; C[Si](C)(C)c1ccccc1N(c1ccccc1)c1ccc2c3cc4c(cc3n3c5ccccc5c1c23)c1ccc(N(c2ccccc2)c2ccccc2[Si](C)(C)C)c2c3ccccc3n4c12 ; C[Si](C)(C)c1cccc(N(c2ccccc2)c2ccc3c4cc5c(cc4n4c6ccccc6c2c34)c2ccc(N(c3ccccc3)c3cccc([Si](C)(C)C)c3)c3c4ccccc4n5c23)c1]

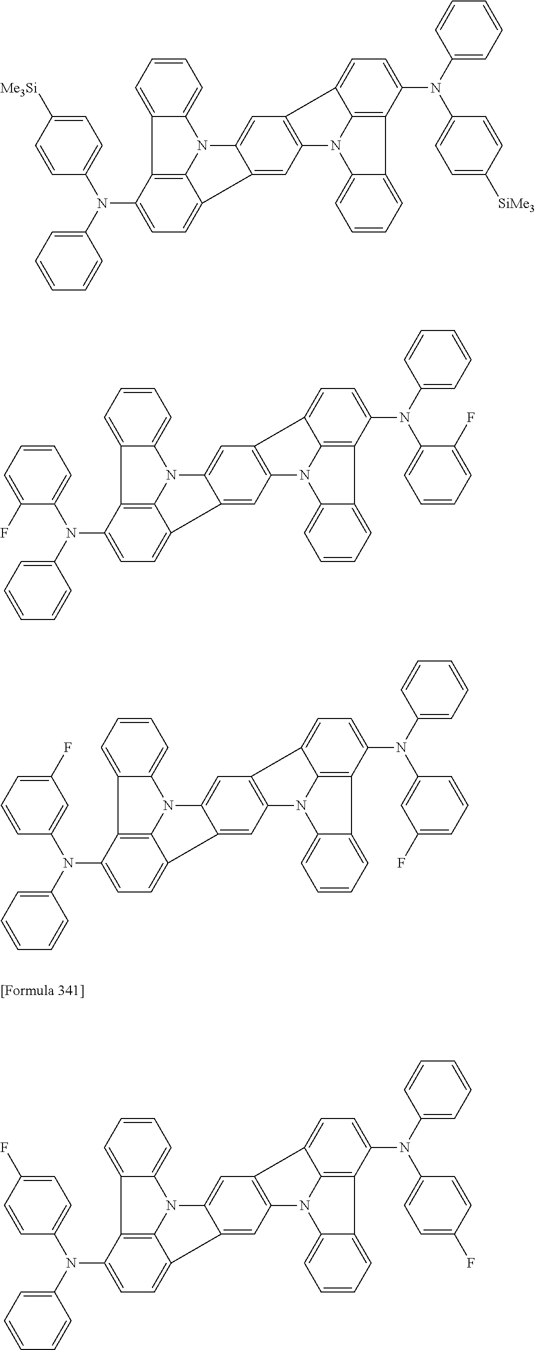 [SMILES: C[Si](C)(C)c1ccc(N(c2ccccc2)c2ccc3c4cc5c(cc4n4c6ccccc6c2c34)c2ccc(N(c3ccccc3)c3ccc([Si](C)(C)C)cc3)c3c4ccccc4n5c23)cc1 ; Fc1ccccc1N(c1ccccc1)c1ccc2c3cc4c(cc3n3c5ccccc5c1c23)c1ccc(N(c2ccccc2)c2ccccc2F)c2c3ccccc3n4c12 ; Fc1cccc(N(c2ccccc2)c2ccc3c4cc5c(cc4n4c6ccccc6c2c34)c2ccc(N(c3ccccc3)c3cccc(F)c3)c3c4ccccc4n5c23)c1 ; Fc1ccc(N(c2ccccc2)c2ccc3c4cc5c(cc4n4c6ccccc6c2c34)c2ccc(N(c3ccccc3)c3ccc(F)cc3)c3c4ccccc4n5c23)cc1]

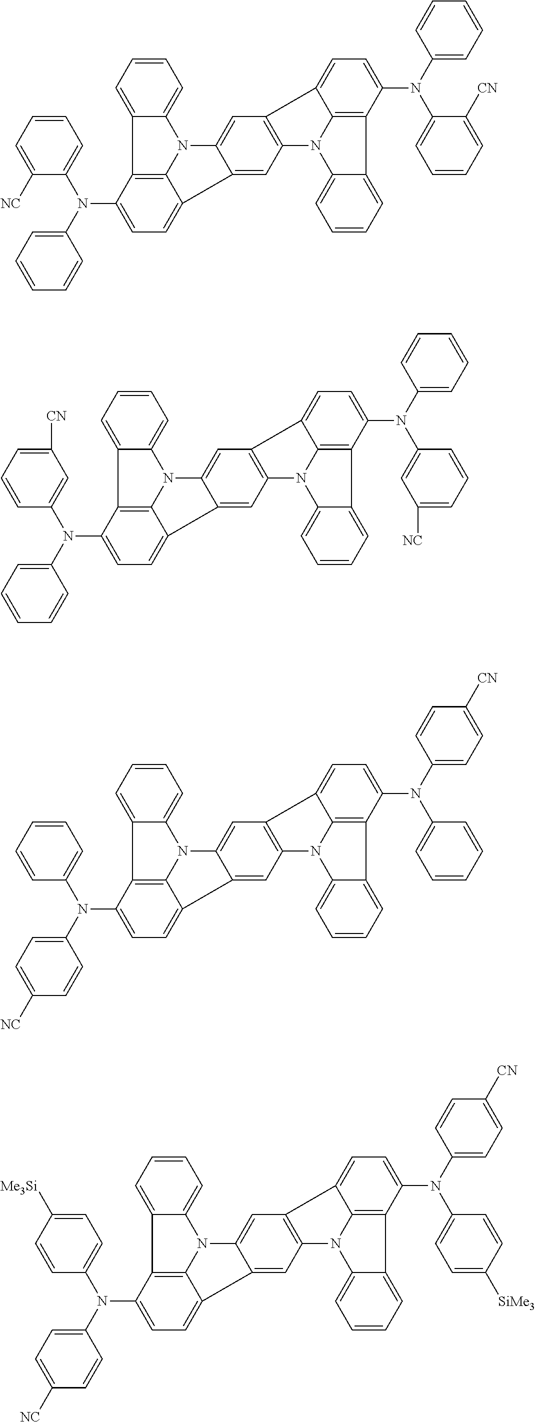 [SMILES: N#Cc1ccccc1N(c1ccccc1)c1ccc2c3cc4c(cc3n3c5ccccc5c1c23)c1ccc(N(c2ccccc2)c2ccccc2C#N)c2c3ccccc3n4c12 ; N#Cc1cccc(N(c2ccccc2)c2ccc3c4cc5c(cc4n4c6ccccc6c2c34)c2ccc(N(c3ccccc3)c3cccc(C#N)c3)c3c4ccccc4n5c23)c1 ; N#Cc1ccc(N(c2ccccc2)c2ccc3c4cc5c(cc4n4c6ccccc6c2c34)c2ccc(N(c3ccccc3)c3ccc(C#N)cc3)c3c4ccccc4n5c23)cc1 ; C[Si](C)(C)c1ccc(N(c2ccc(C#N)cc2)c2ccc3c4cc5c(cc4n4c6ccccc6c2c34)c2ccc(N(c3ccc(C#N)cc3)c3ccc([Si](C)(C)C)cc3)c3c4ccccc4n5c23)cc1]

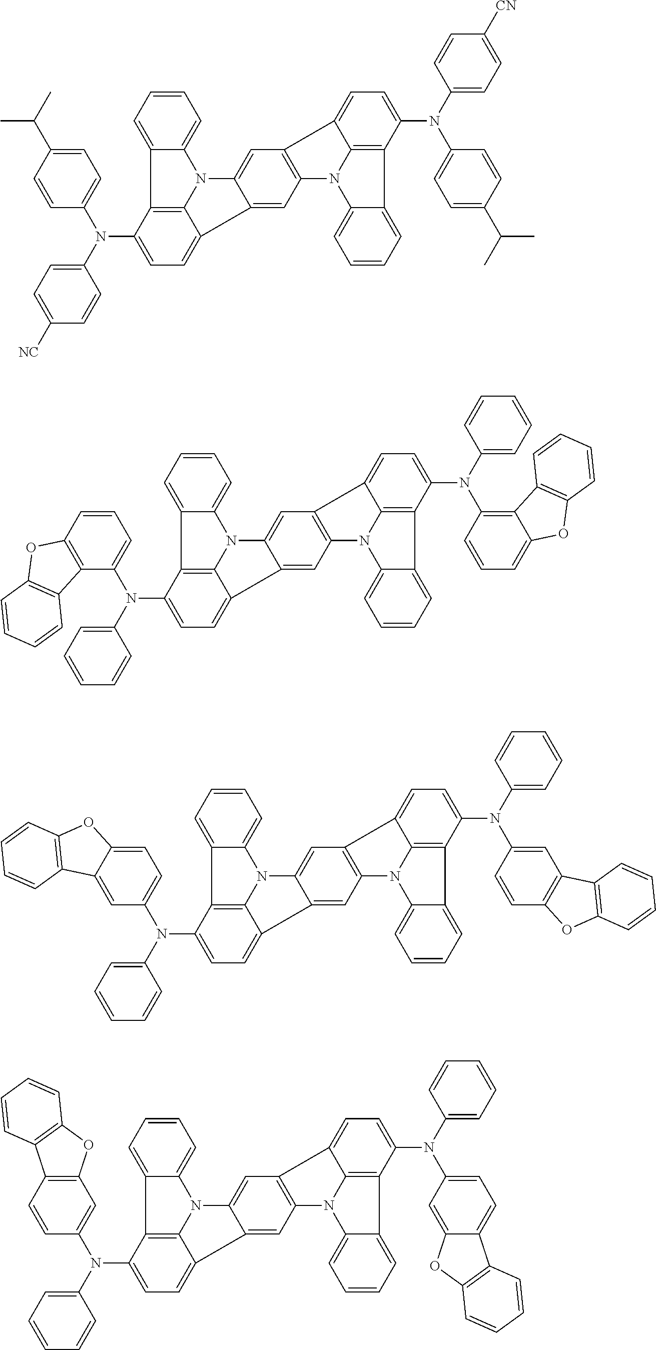 [SMILES: CC(C)c1ccc(N(c2ccc(C#N)cc2)c2ccc3c4cc5c(cc4n4c6ccccc6c2c34)c2ccc(N(c3ccc(C#N)cc3)c3ccc(C(C)C)cc3)c3c4ccccc4n5c23)cc1 ; c1ccc(N(c2cccc3oc4ccccc4c23)c2ccc3c4cc5c(cc4n4c6ccccc6c2c34)c2ccc(N(c3ccccc3)c3cccc4oc6ccccc6c34)c3c4ccccc4n5c23)cc1 ; c1ccc(N(c2ccc3oc4ccccc4c3c2)c2ccc3c4cc5c(cc4n4c6ccccc6c2c34)c2ccc(N(c3ccccc3)c3ccc4oc6ccccc6c4c3)c3c4ccccc4n5c23)cc1 ; c1ccc(N(c2ccc3c(c2)oc2ccccc23)c2ccc3c4cc5c(cc4n4c6ccccc6c2c34)c2ccc(N(c3ccccc3)c3ccc4c(c3)oc3ccccc34)c3c4ccccc4n5c23)cc1]

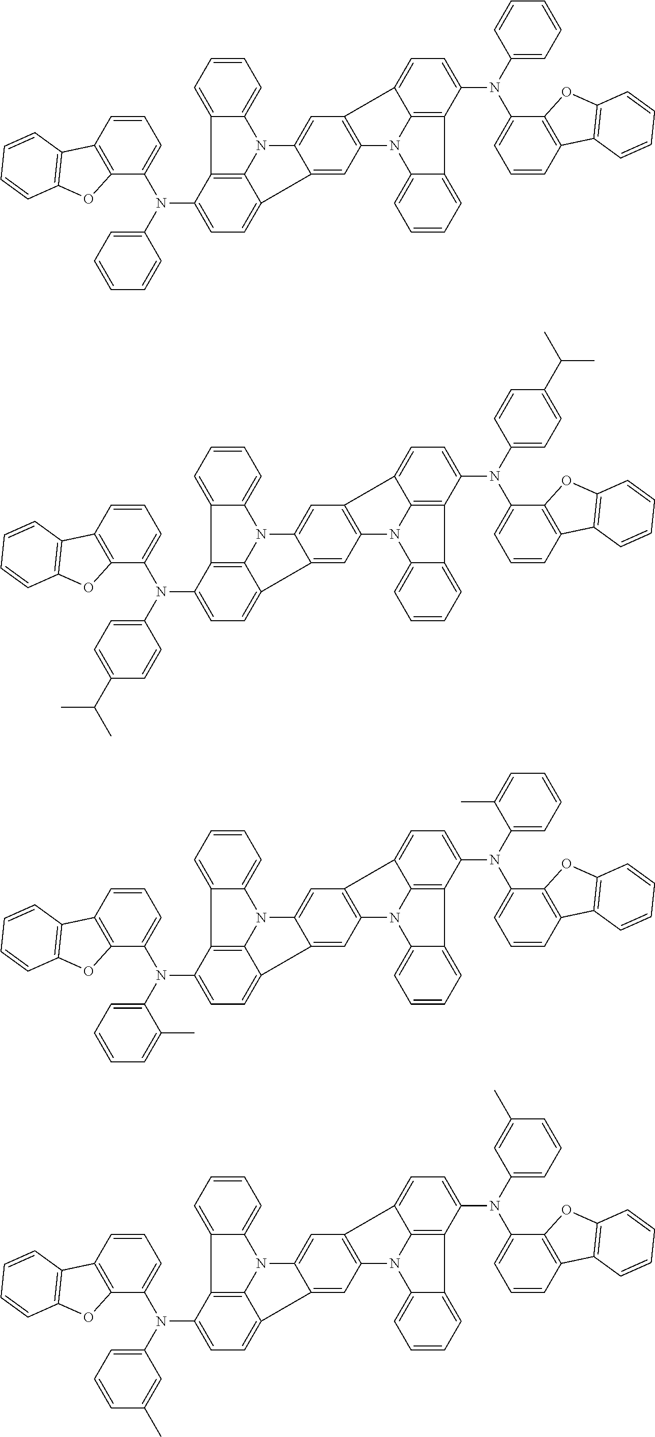 [SMILES: c1ccc(N(c2cccc3c2oc2ccccc23)c2ccc3c4cc5c(cc4n4c6ccccc6c2c34)c2ccc(N(c3ccccc3)c3cccc4c3oc3ccccc34)c3c4ccccc4n5c23)cc1 ; CC(C)c1ccc(N(c2cccc3c2oc2ccccc23)c2ccc3c4cc5c(cc4n4c6ccccc6c2c34)c2ccc(N(c3ccc(C(C)C)cc3)c3cccc4c3oc3ccccc34)c3c4ccccc4n5c23)cc1 ; Cc1ccccc1N(c1cccc2c1oc1ccccc12)c1ccc2c3cc4c(cc3n3c5ccccc5c1c23)c1ccc(N(c2ccccc2C)c2cccc3c2oc2ccccc23)c2c3ccccc3n4c12 ; Cc1cccc(N(c2cccc3c2oc2ccccc23)c2ccc3c4cc5c(cc4n4c6ccccc6c2c34)c2ccc(N(c3cccc(C)c3)c3cccc4c3oc3ccccc34)c3c4ccccc4n5c23)c1]

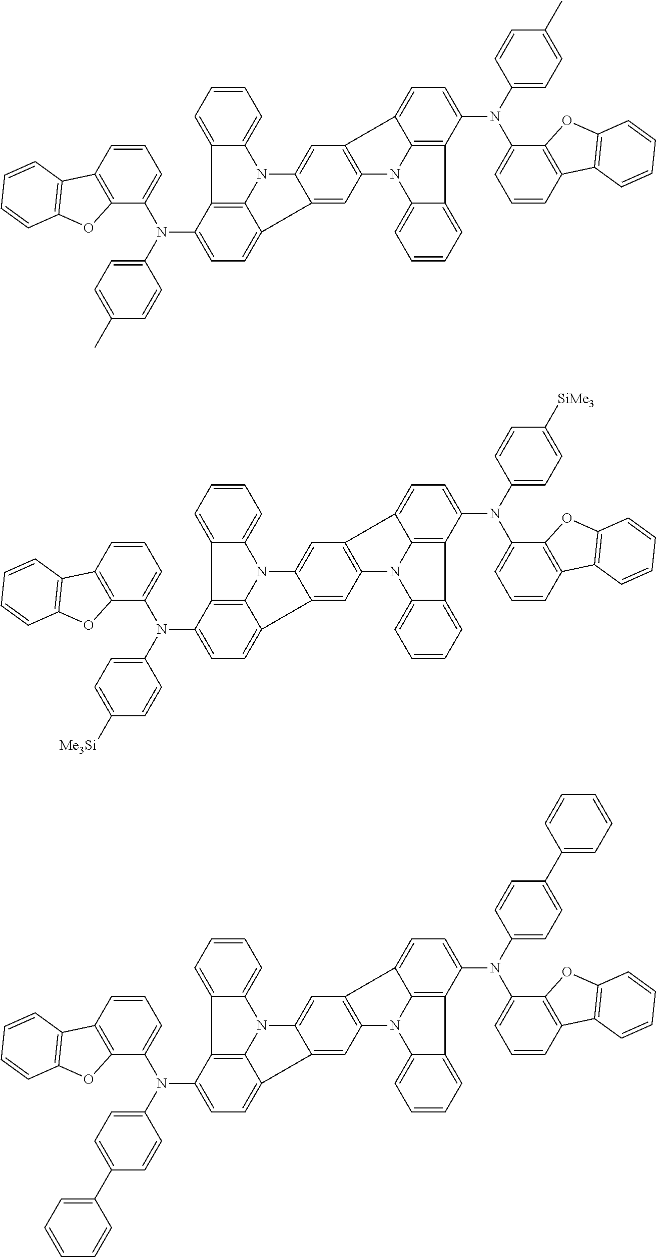 [SMILES: Cc1ccc(N(c2cccc3c2oc2ccccc23)c2ccc3c4cc5c(cc4n4c6ccccc6c2c34)c2ccc(N(c3ccc(C)cc3)c3cccc4c3oc3ccccc34)c3c4ccccc4n5c23)cc1 ; C[Si](C)(C)c1ccc(N(c2cccc3c2oc2ccccc23)c2ccc3c4cc5c(cc4n4c6ccccc6c2c34)c2ccc(N(c3ccc([Si](C)(C)C)cc3)c3cccc4c3oc3ccccc34)c3c4ccccc4n5c23)cc1 ; c1ccc(-c2ccc(N(c3cccc4c3oc3ccccc34)c3ccc4c5cc6c(cc5n5c7ccccc7c3c45)c3ccc(N(c4ccc(-c5ccccc5)cc4)c4cccc5c4oc4ccccc45)c4c5ccccc5n6c34)cc2)cc1]

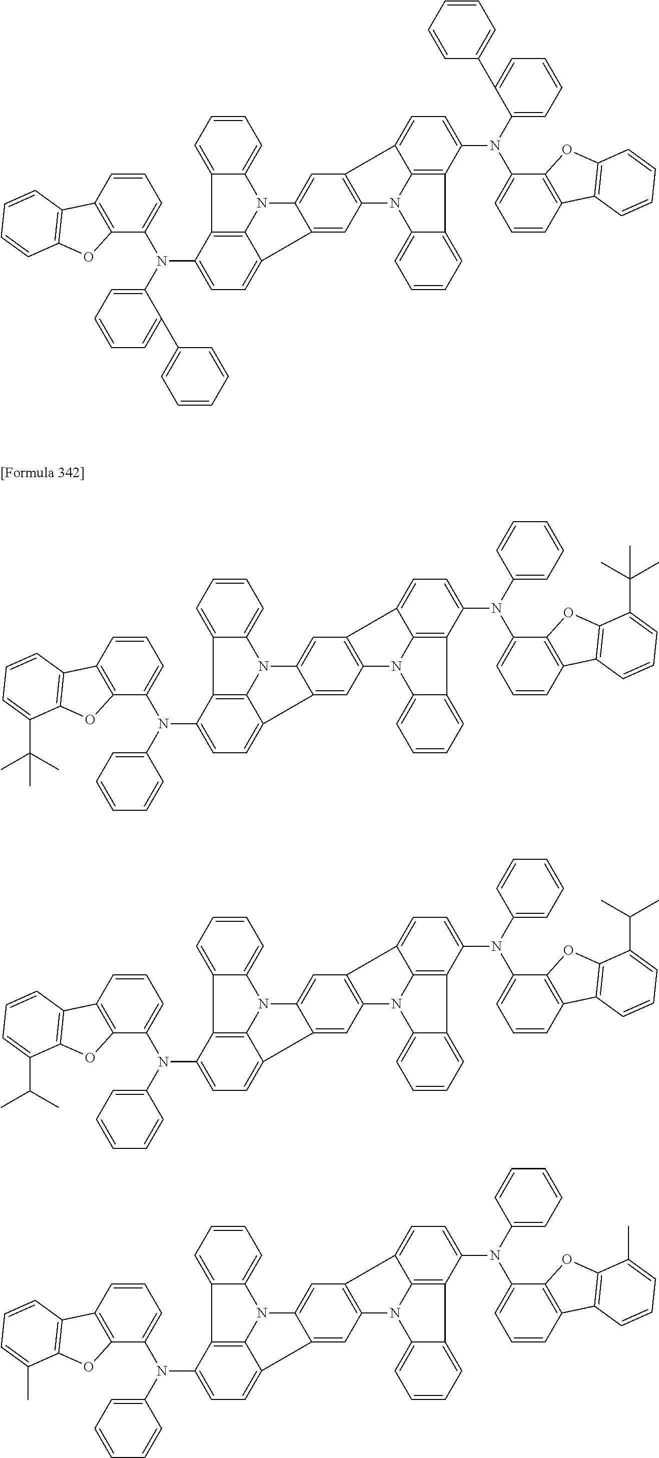

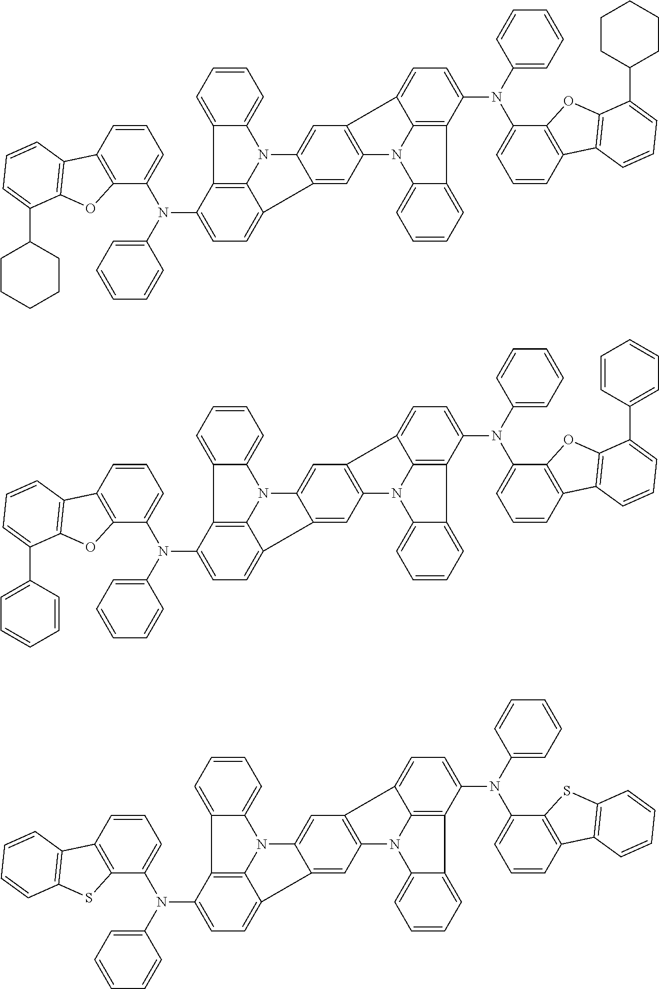 [SMILES: c1ccc(N(c2cccc3c2oc2c(C4CCCCC4)cccc23)c2ccc3c4cc5c(cc4n4c6ccccc6c2c34)c2ccc(N(c3ccccc3)c3cccc4c3oc3c(C6CCCCC6)cccc34)c3c4ccccc4n5c23)cc1 ; c1ccc(-c2cccc3c2oc2c(N(c4ccccc4)c4ccc5c6cc7c(cc6n6c8ccccc8c4c56)c4ccc(N(c5ccccc5)c5cccc6c5oc5c(-c8ccccc8)cccc56)c5c6ccccc6n7c45)cccc23)cc1 ; c1ccc(N(c2cccc3c2sc2ccccc23)c2ccc3c4cc5c(cc4n4c6ccccc6c2c34)c2ccc(N(c3ccccc3)c3cccc4c3sc3ccccc34)c3c4ccccc4n5c23)cc1]

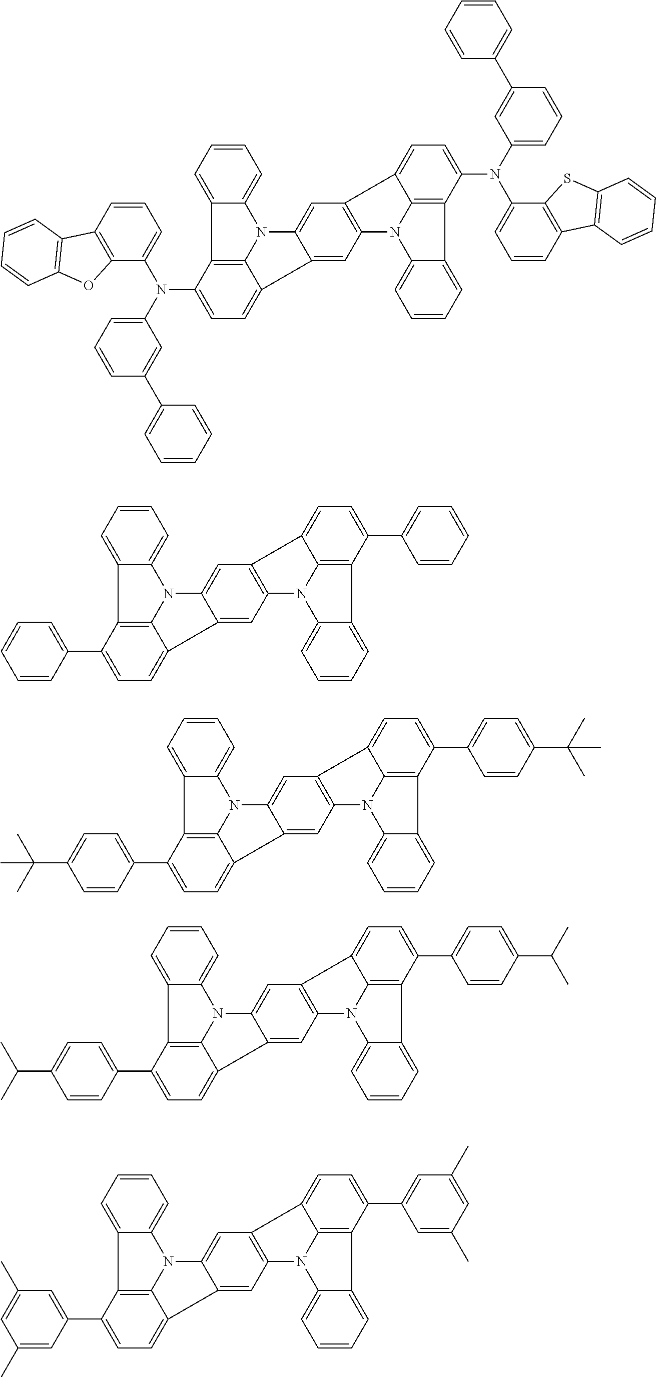

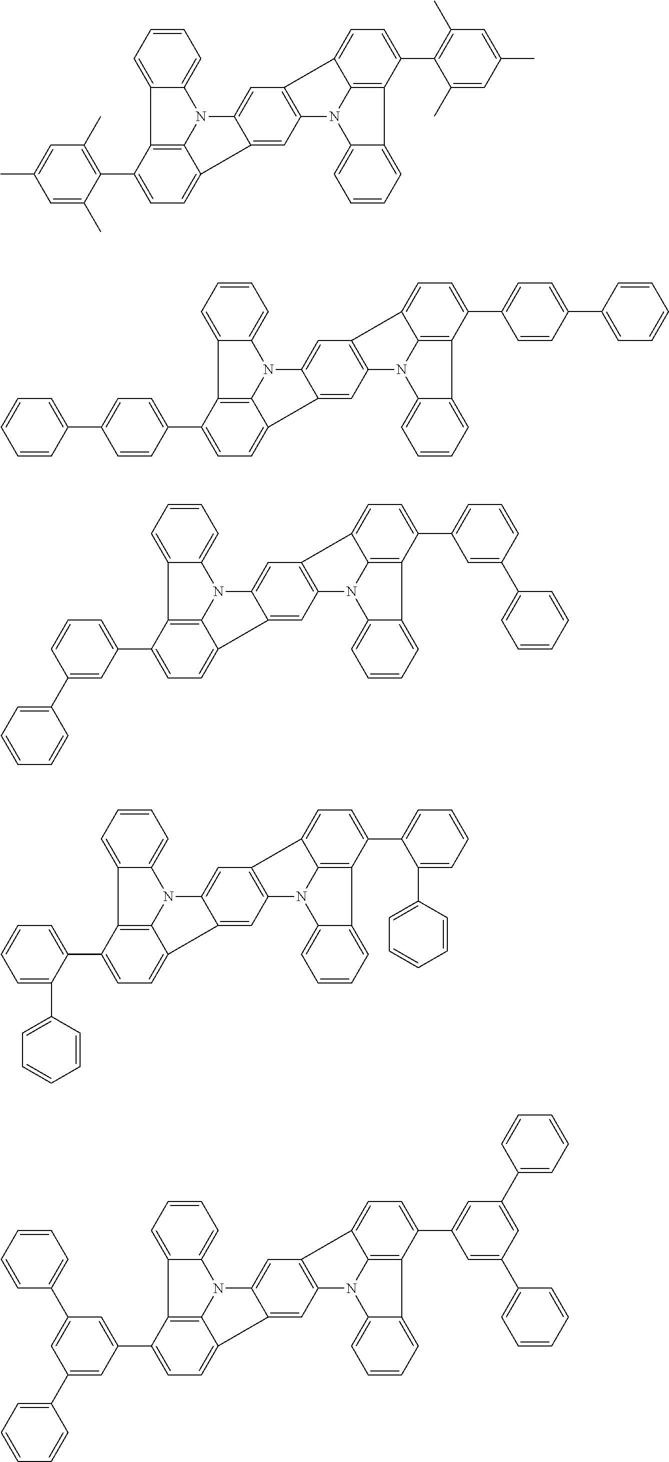

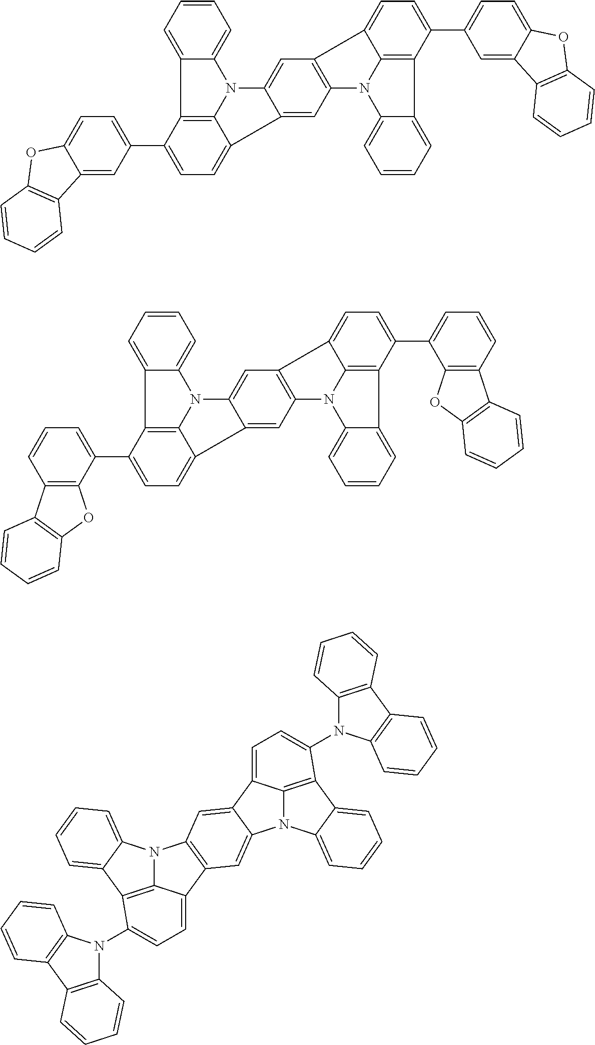 [SMILES: c1ccc2c(c1)oc1ccc(-c3ccc4c5cc6c(cc5n5c7ccccc7c3c45)c3ccc(-c4ccc5oc7ccccc7c5c4)c4c5ccccc5n6c34)cc12 ; c1ccc2c(c1)oc1c(-c3ccc4c5cc6c(cc5n5c7ccccc7c3c45)c3ccc(-c4cccc5c4oc4ccccc45)c4c5ccccc5n6c34)cccc12 ; c1ccc2c(c1)c1ccccc1n2-c1ccc2c3cc4c(cc3n3c5ccccc5c1c23)c1ccc(-n2c3ccccc3c3ccccc32)c2c3ccccc3n4c12]

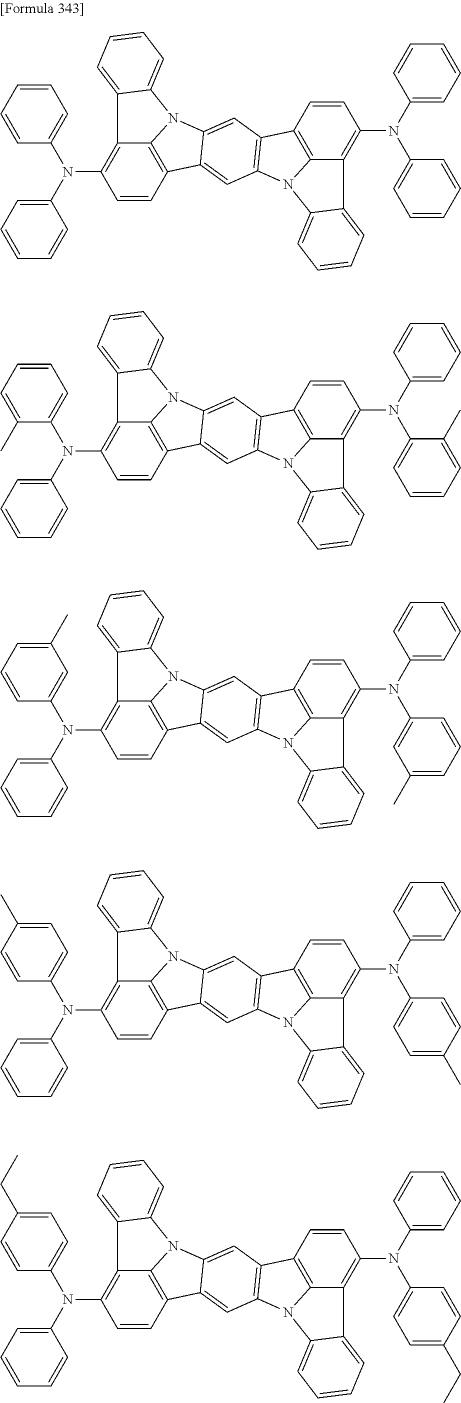 [SMILES: c1ccc(N(c2ccccc2)c2ccc3c4cc5c(cc4n4c6ccccc6c2c34)c2ccc(N(c3ccccc3)c3ccccc3)c3c4ccccc4n5c23)cc1 ; Cc1ccccc1N(c1ccccc1)c1ccc2c3cc4c(cc3n3c5ccccc5c1c23)c1ccc(N(c2ccccc2)c2ccccc2C)c2c3ccccc3n4c12 ; Cc1cccc(N(c2ccccc2)c2ccc3c4cc5c(cc4n4c6ccccc6c2c34)c2ccc(N(c3ccccc3)c3cccc(C)c3)c3c4ccccc4n5c23)c1 ; Cc1ccc(N(c2ccccc2)c2ccc3c4cc5c(cc4n4c6ccccc6c2c34)c2ccc(N(c3ccccc3)c3ccc(C)cc3)c3c4ccccc4n5c23)cc1 ; CCc1ccc(N(c2ccccc2)c2ccc3c4cc5c(cc4n4c6ccccc6c2c34)c2ccc(N(c3ccccc3)c3ccc(CC)cc3)c3c4ccccc4n5c23)cc1]

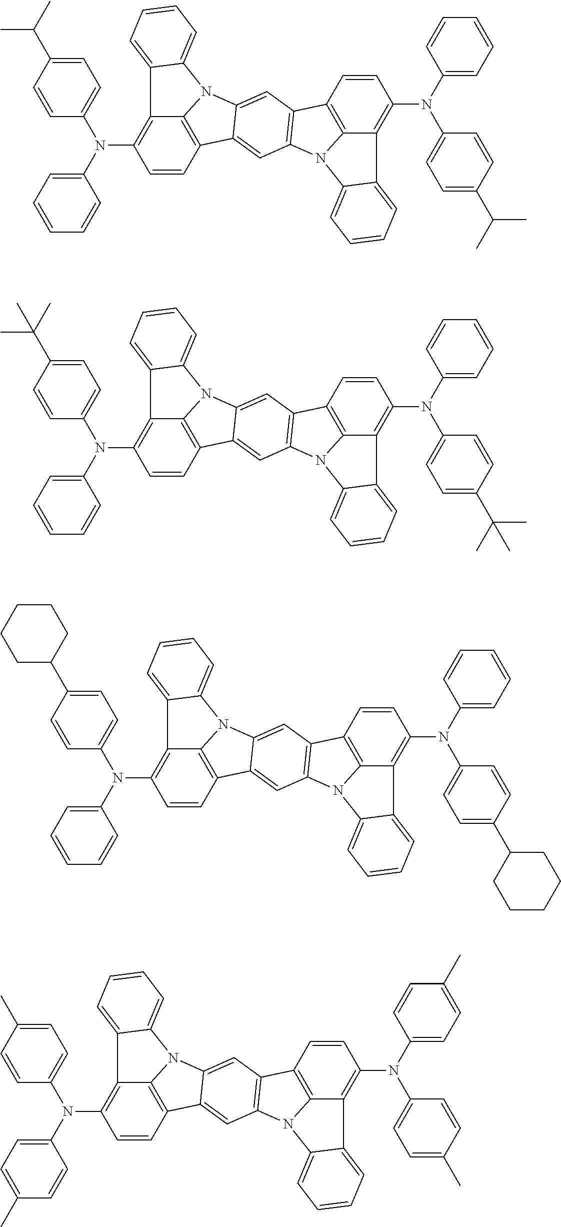

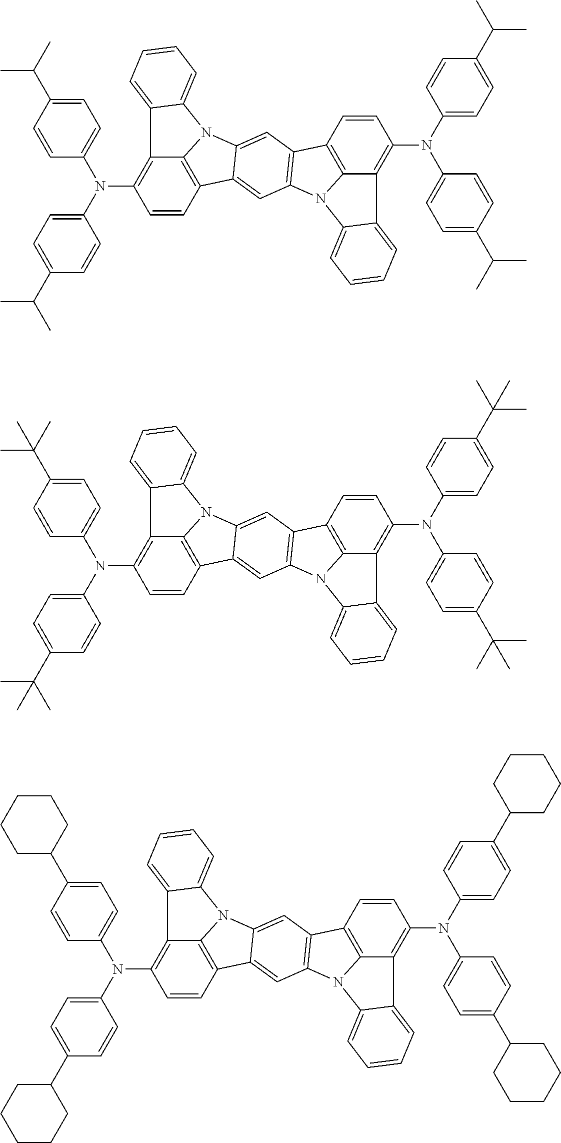

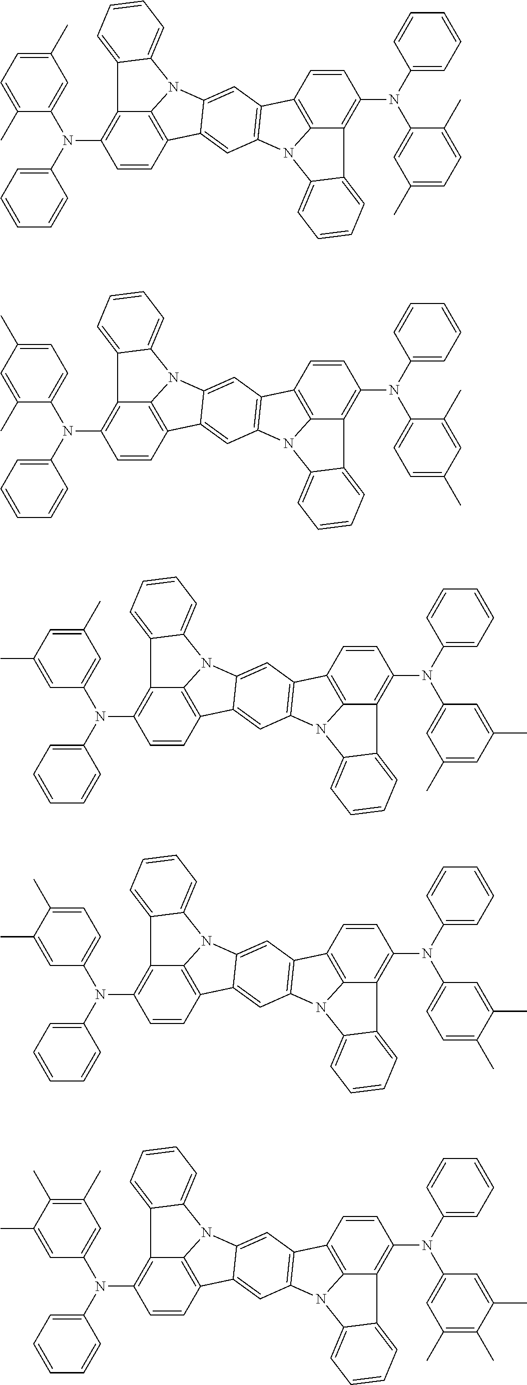

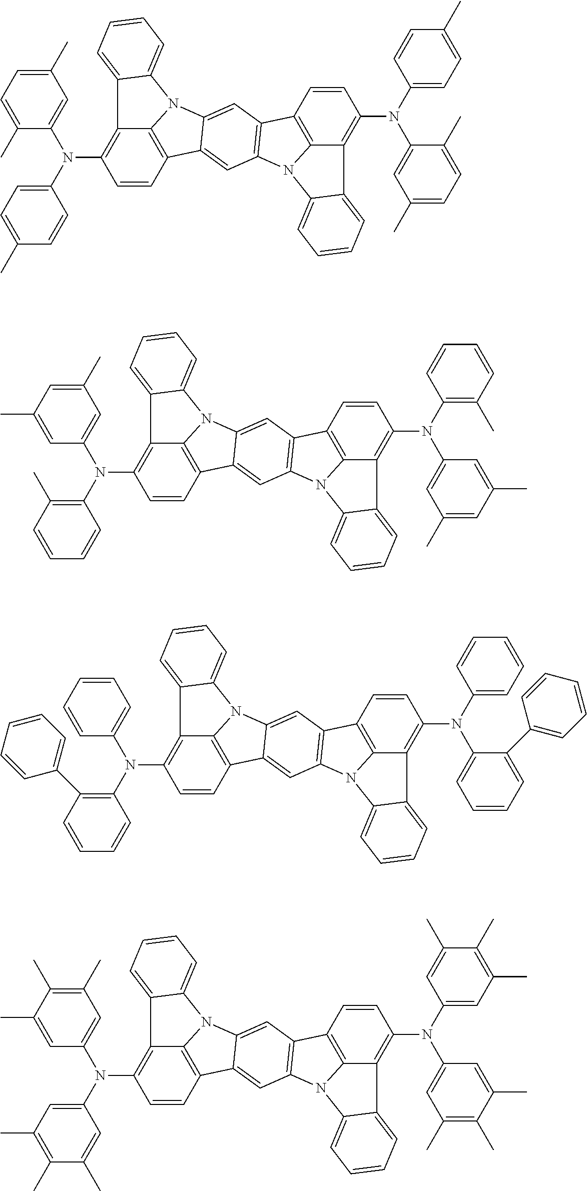

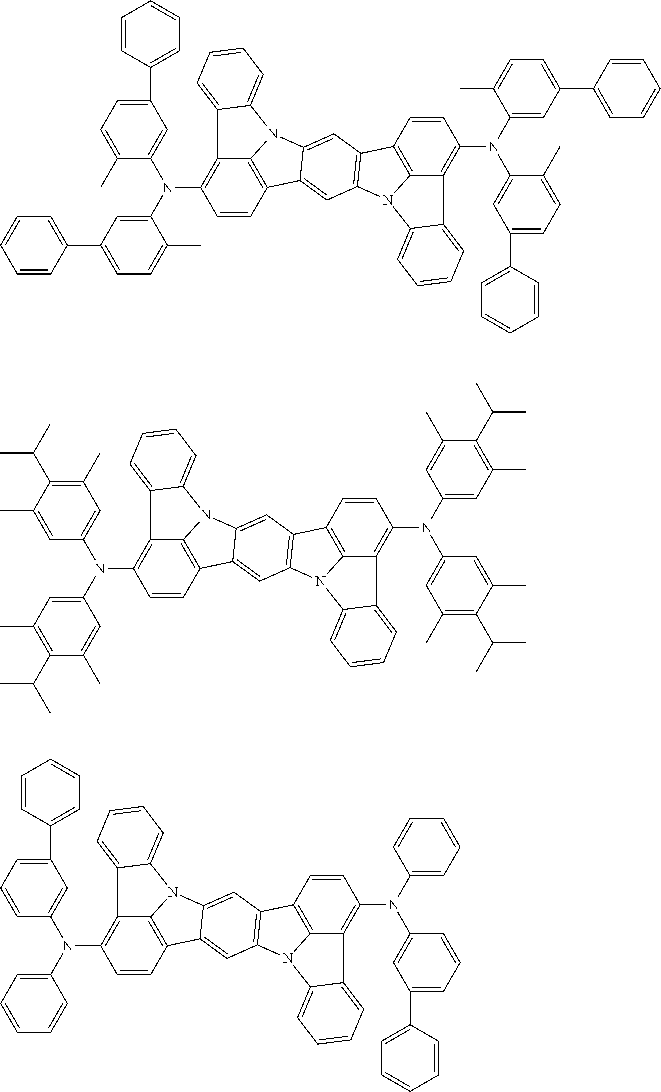

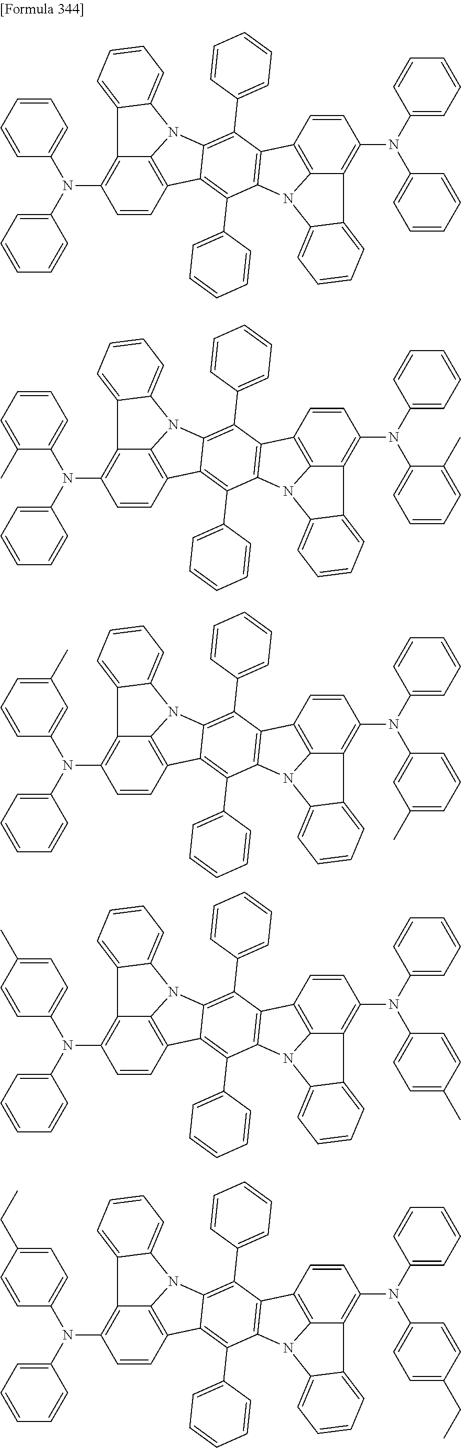

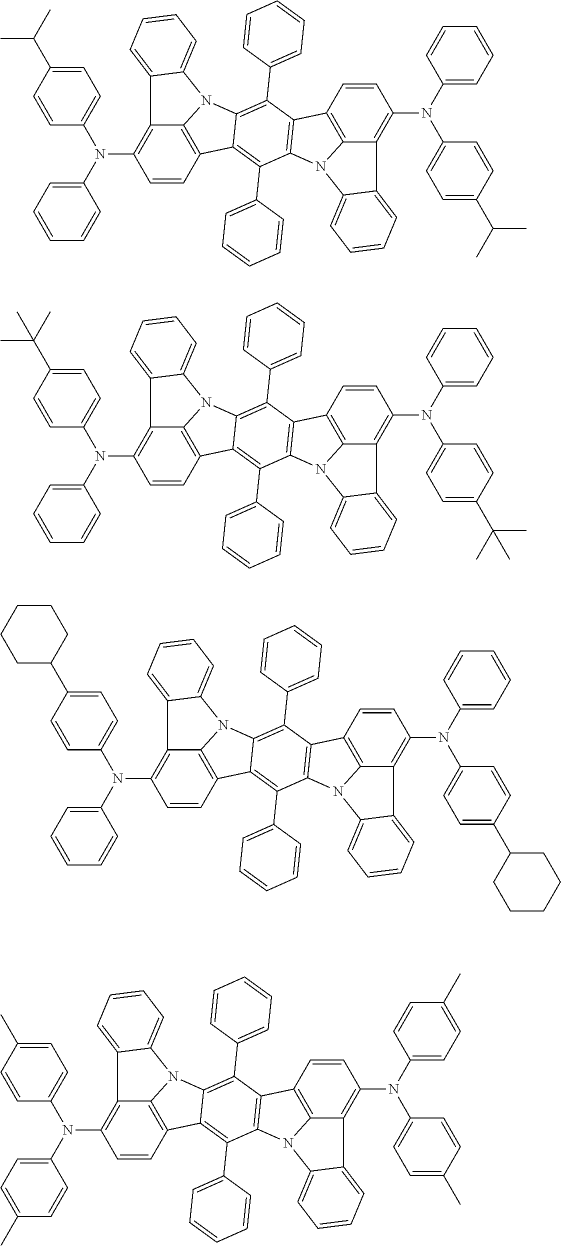

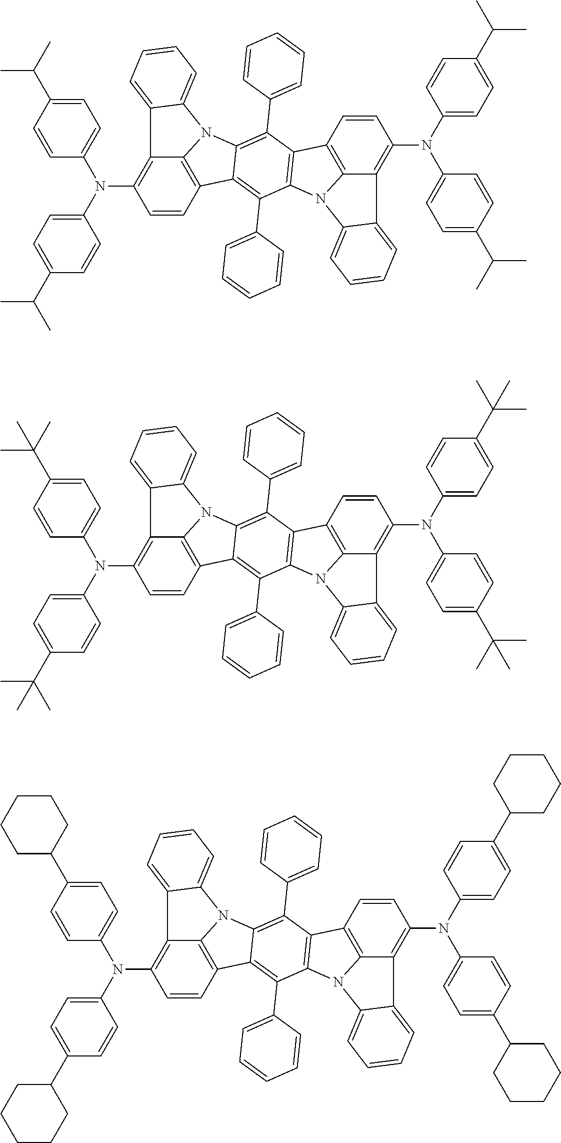

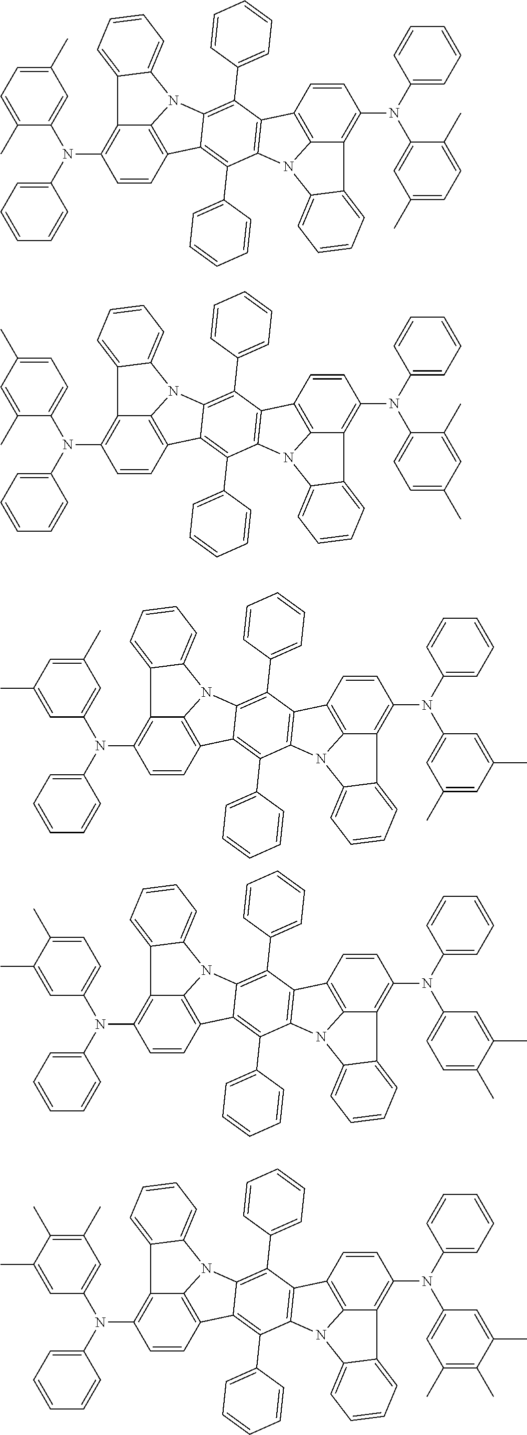

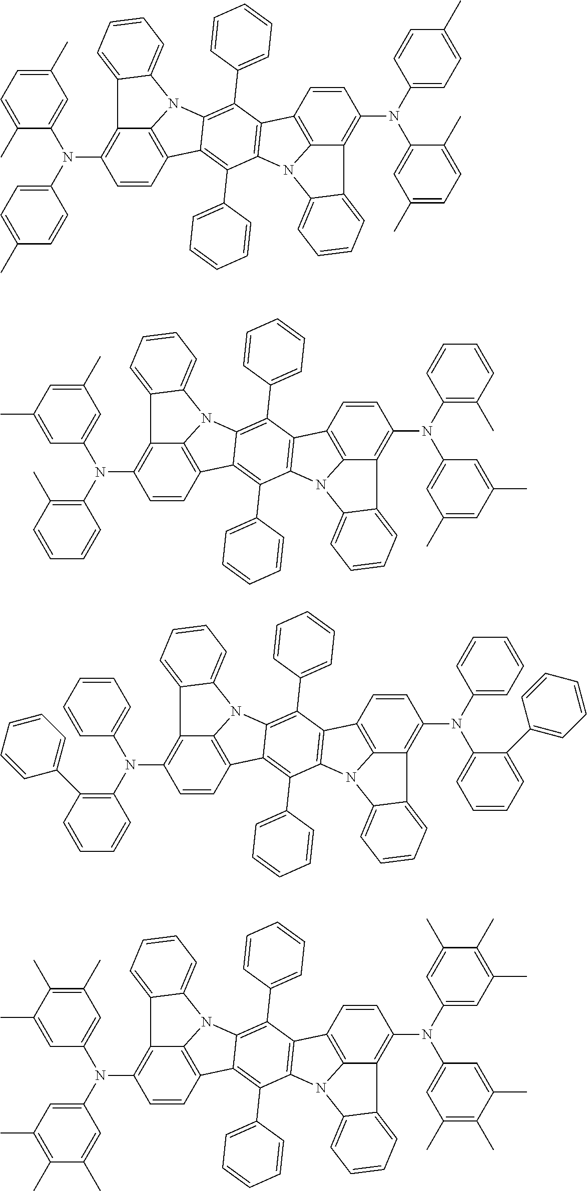

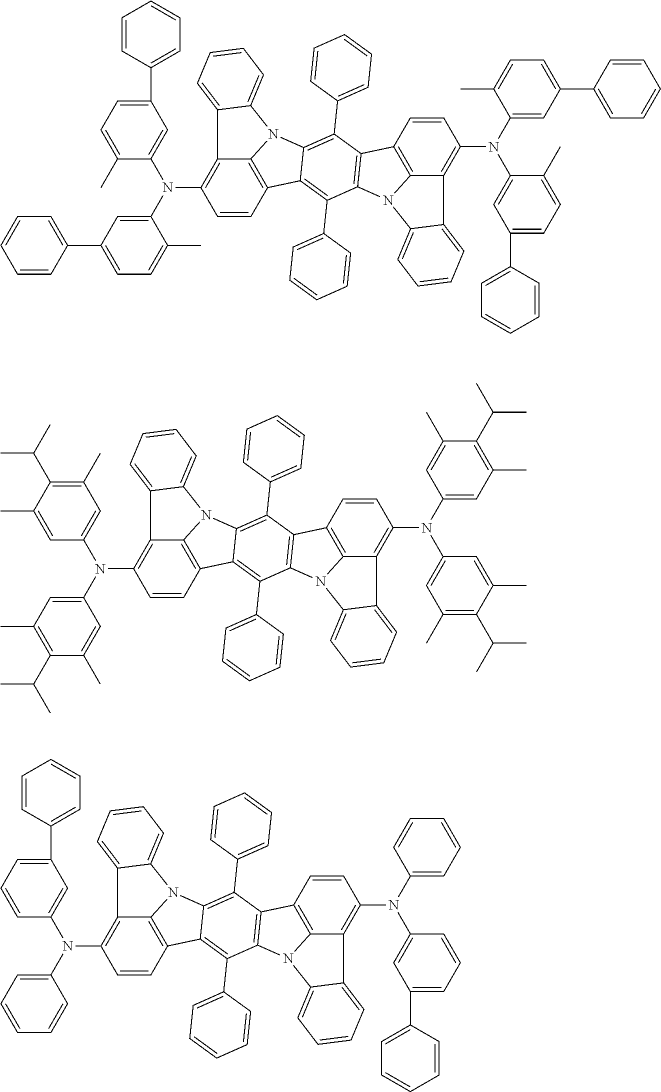

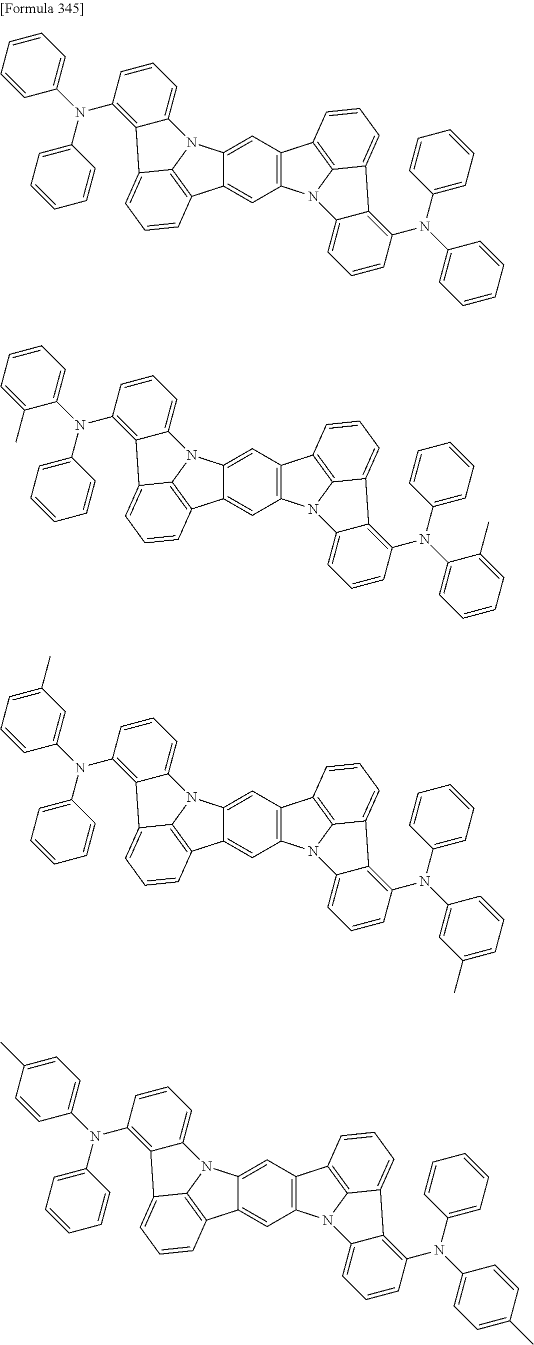

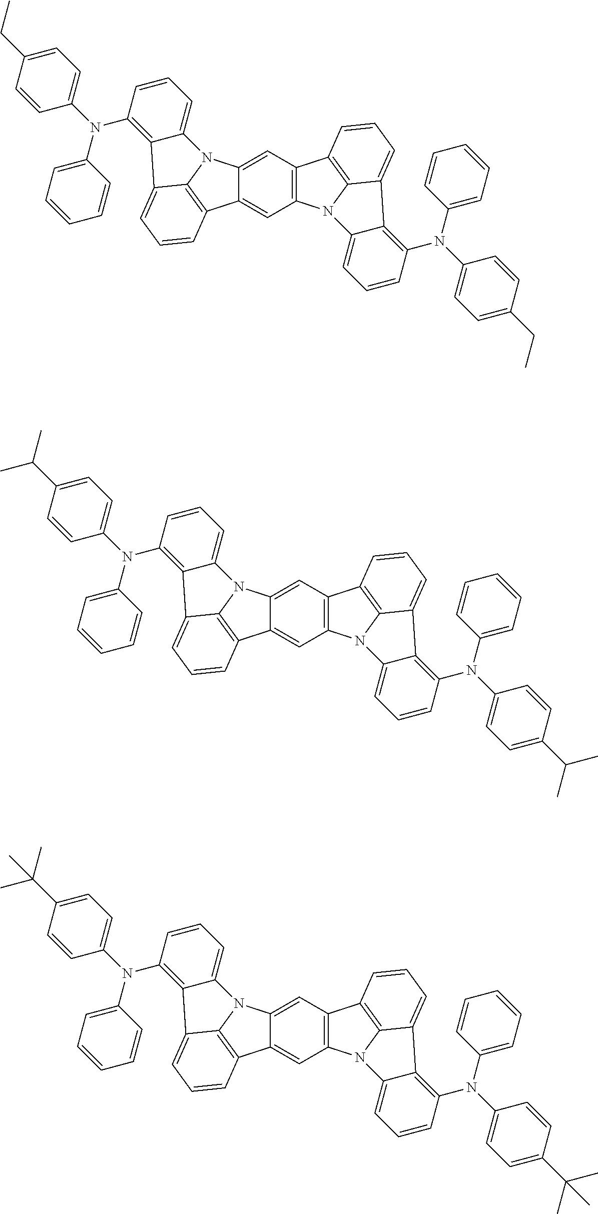

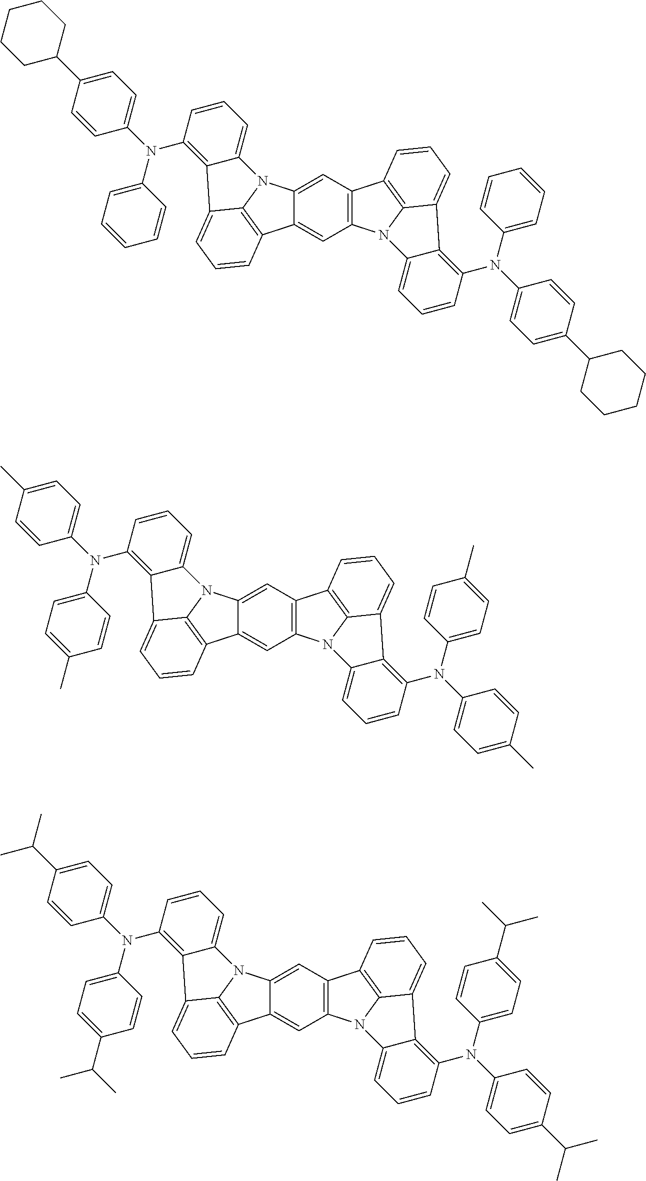

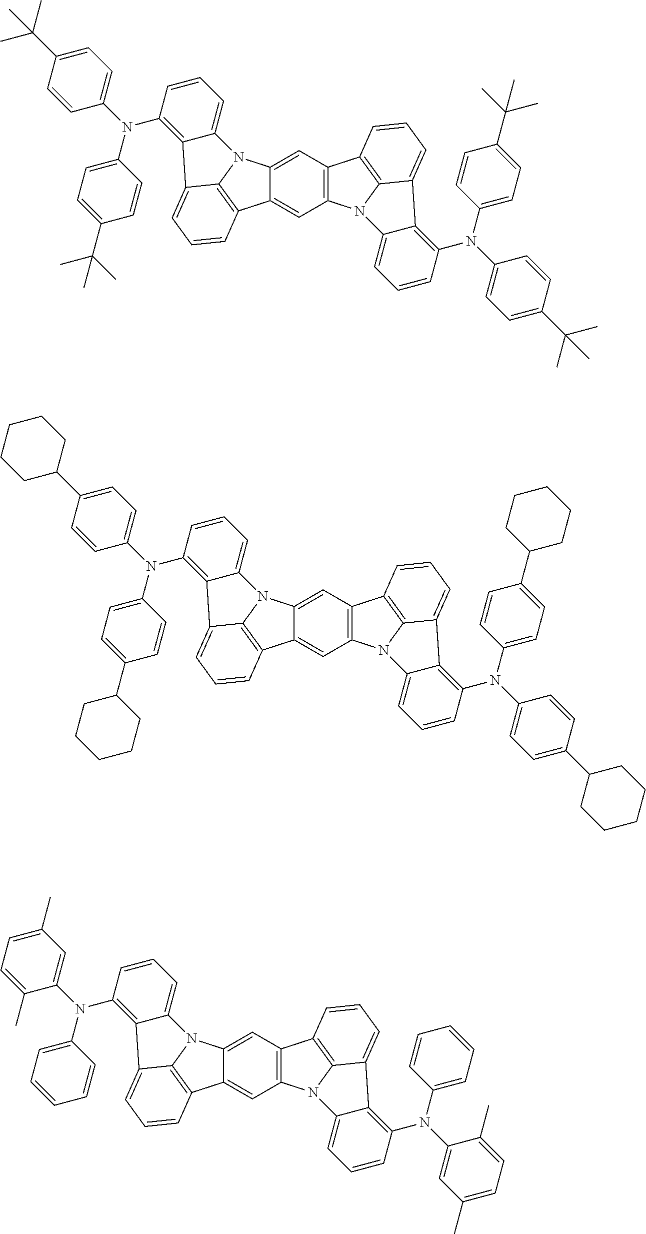 [SMILES: CC(C)(C)c1ccc(N(c2ccc(C(C)(C)C)cc2)c2cccc3c2c2cccc4c5cc6c(cc5n3c42)c2cccc3c4c(N(c5ccc(C(C)(C)C)cc5)c5ccc(C(C)(C)C)cc5)cccc4n6c23)cc1 ; c1cc2c3cc4c(cc3n3c5cccc(N(c6ccc(C7CCCCC7)cc6)c6ccc(C7CCCCC7)cc6)c5c(c1)c23)c1cccc2c3c(N(c5ccc(C6CCCCC6)cc5)c5ccc(C6CCCCC6)cc5)cccc3n4c12 ; Cc1ccc(C)c(N(c2ccccc2)c2cccc3c2c2cccc4c5cc6c(cc5n3c42)c2cccc3c4c(N(c5ccccc5)c5cc(C)ccc5C)cccc4n6c23)c1]

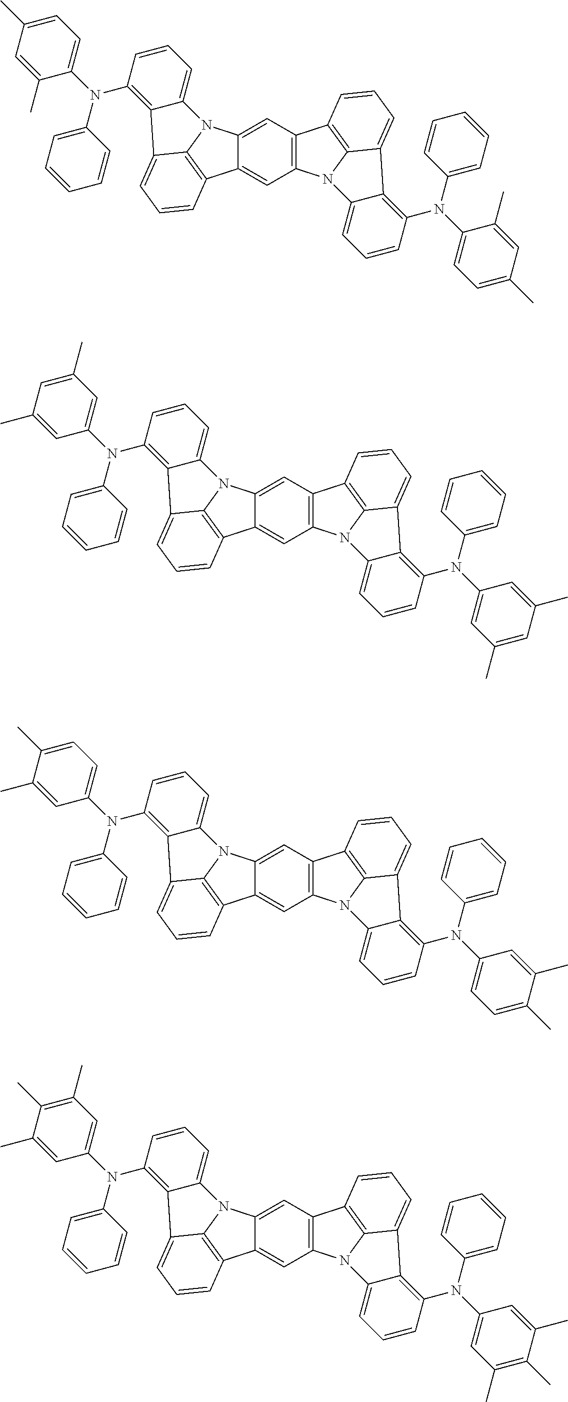

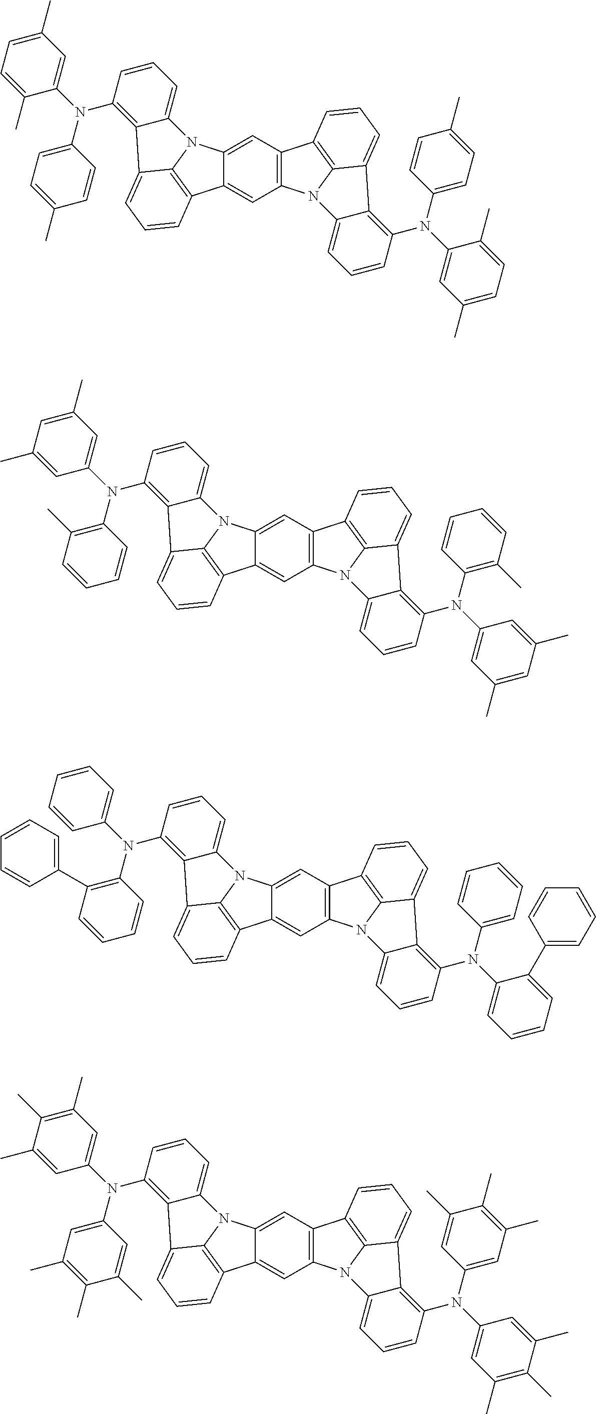

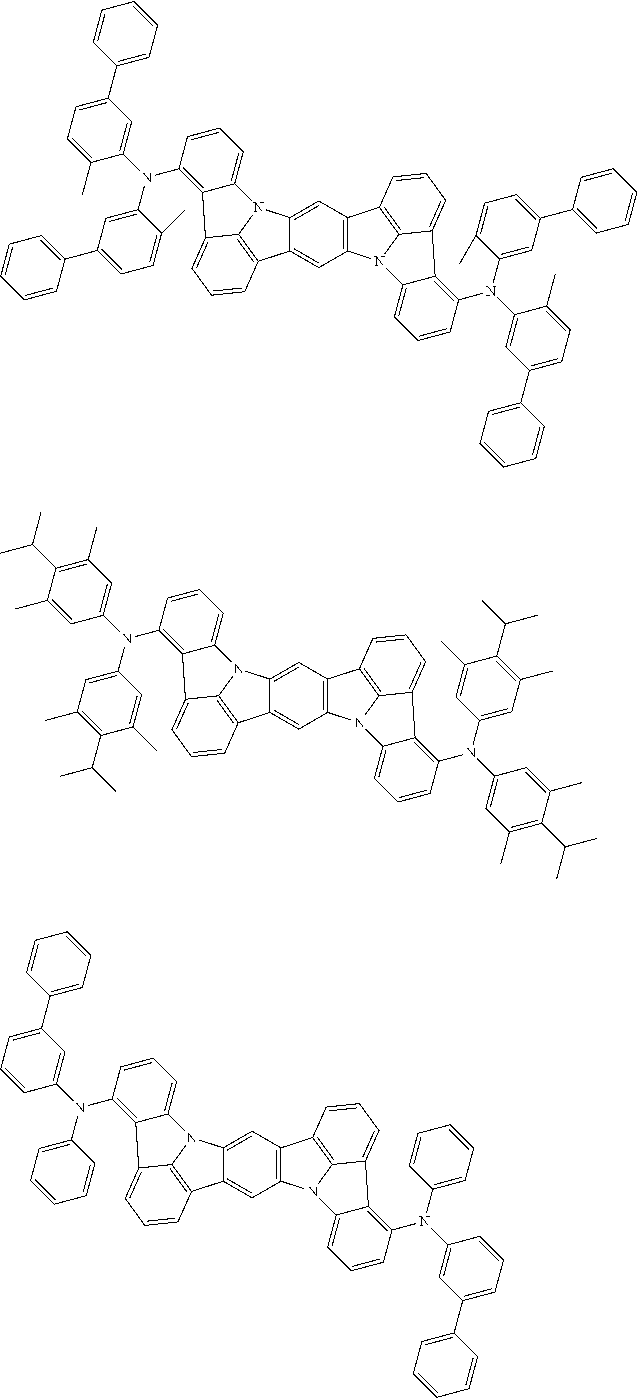 [SMILES: Cc1ccc(-c2ccccc2)cc1N(c1cc(-c2ccccc2)ccc1C)c1cccc2c1c1cccc3c4cc5c(cc4n2c31)c1cccc2c3c(N(c4cc(-c6ccccc6)ccc4C)c4cc(-c6ccccc6)ccc4C)cccc3n5c12 ; Cc1cc(N(c2cc(C)c(C(C)C)c(C)c2)c2cccc3c2c2cccc4c5cc6c(cc5n3c42)c2cccc3c4c(N(c5cc(C)c(C(C)C)c(C)c5)c5cc(C)c(C(C)C)c(C)c5)cccc4n6c23)cc(C)c1C(C)C ; c1ccc(-c2cccc(N(c3ccccc3)c3cccc4c3c3cccc5c6cc7c(cc6n4c53)c3cccc4c5c(N(c6ccccc6)c6cccc(-c8ccccc8)c6)cccc5n7c34)c2)cc1]

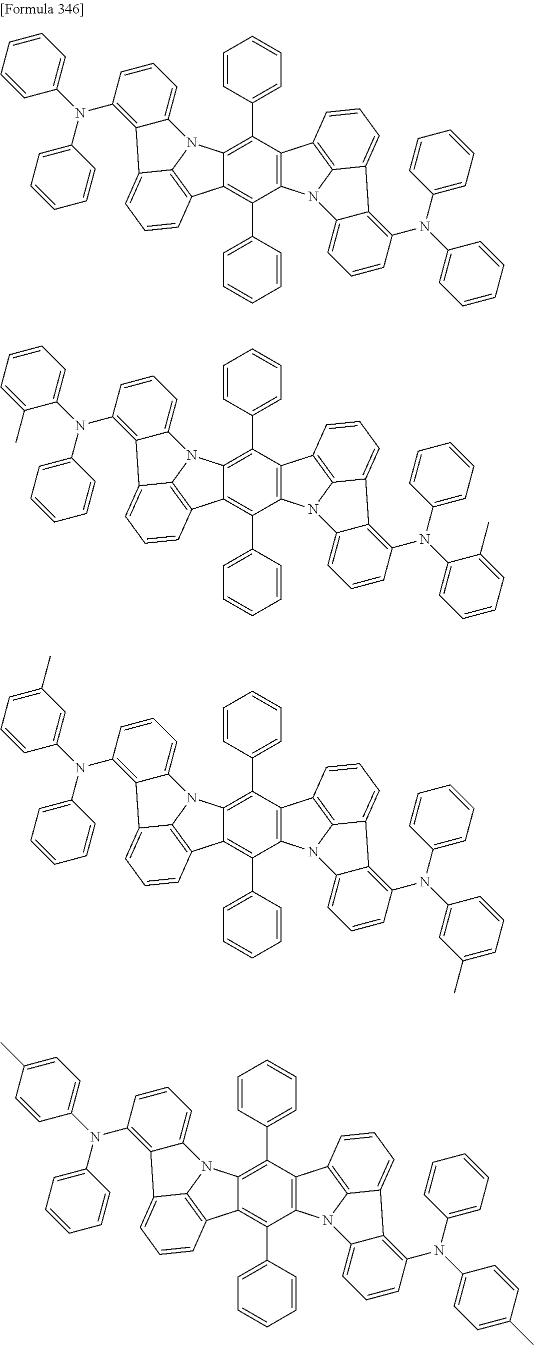

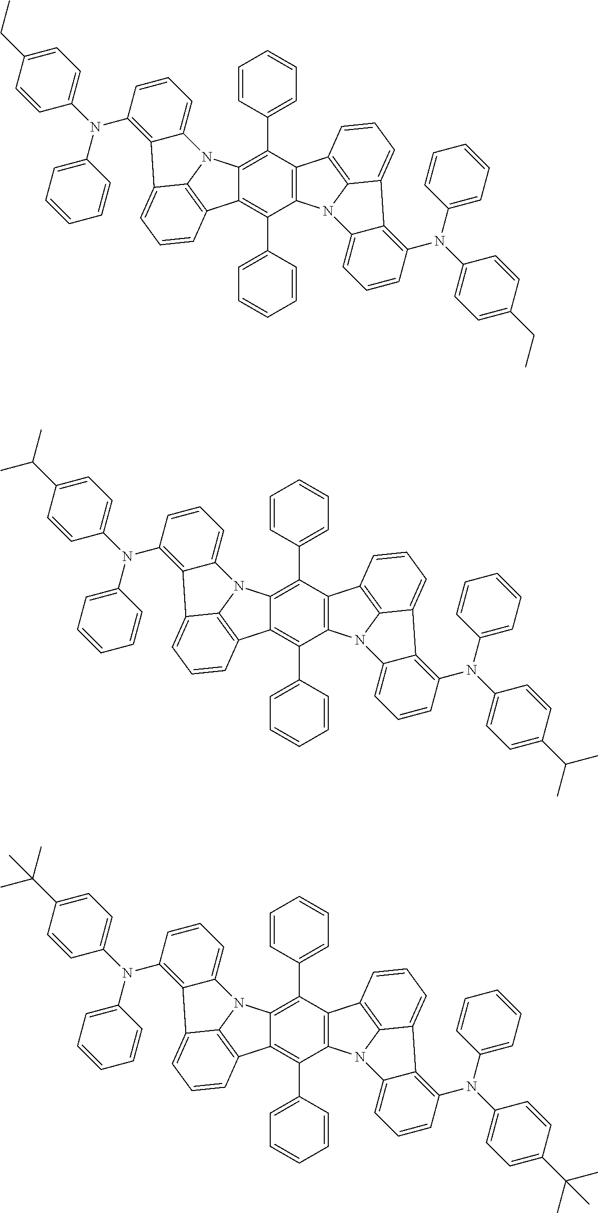

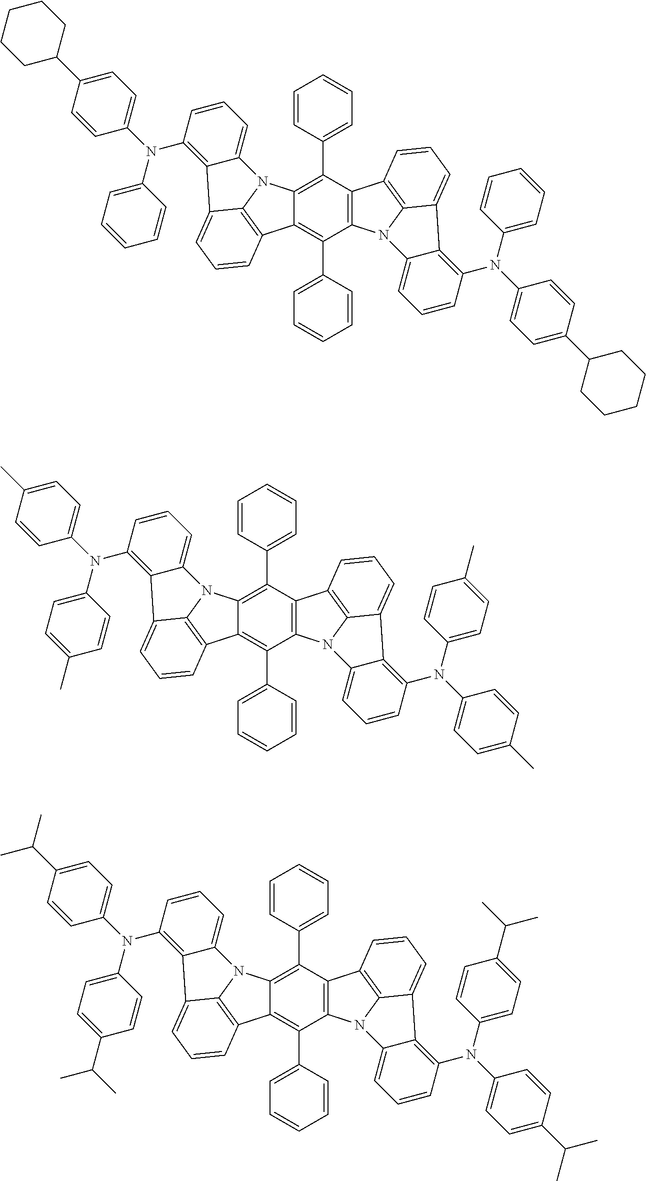

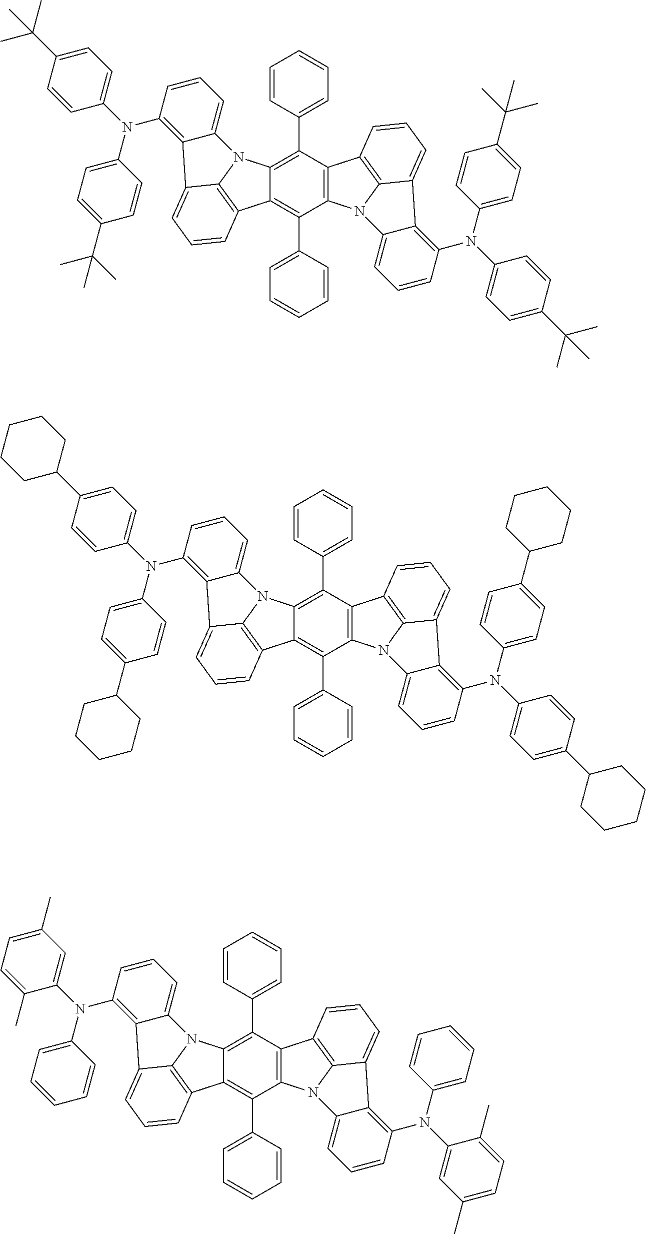 [SMILES: CC(C)(C)c1ccc(N(c2ccc(C(C)(C)C)cc2)c2cccc3c2c2cccc4c5c(-c6ccccc6)c6c(c(-c7ccccc7)c5n3c24)c2cccc3c4c(N(c5ccc(C(C)(C)C)cc5)c5ccc(C(C)(C)C)cc5)cccc4n6c32)cc1 ; c1ccc(-c2c3c4cccc5c6c(N(c7ccc(C8CCCCC8)cc7)c7ccc(C8CCCCC8)cc7)cccc6n(c3c(-c3ccccc3)c3c6cccc7c8c(N(c9ccc(C%10CCCCC%10)cc9)c9ccc(C%10CCCCC%10)cc9)cccc8n(c23)c76)c54)cc1 ; Cc1ccc(C)c(N(c2ccccc2)c2cccc3c2c2cccc4c5c(-c6ccccc6)c6c(c(-c7ccccc7)c5n3c24)c2cccc3c4c(N(c5ccccc5)c5cc(C)ccc5C)cccc4n6c32)c1]

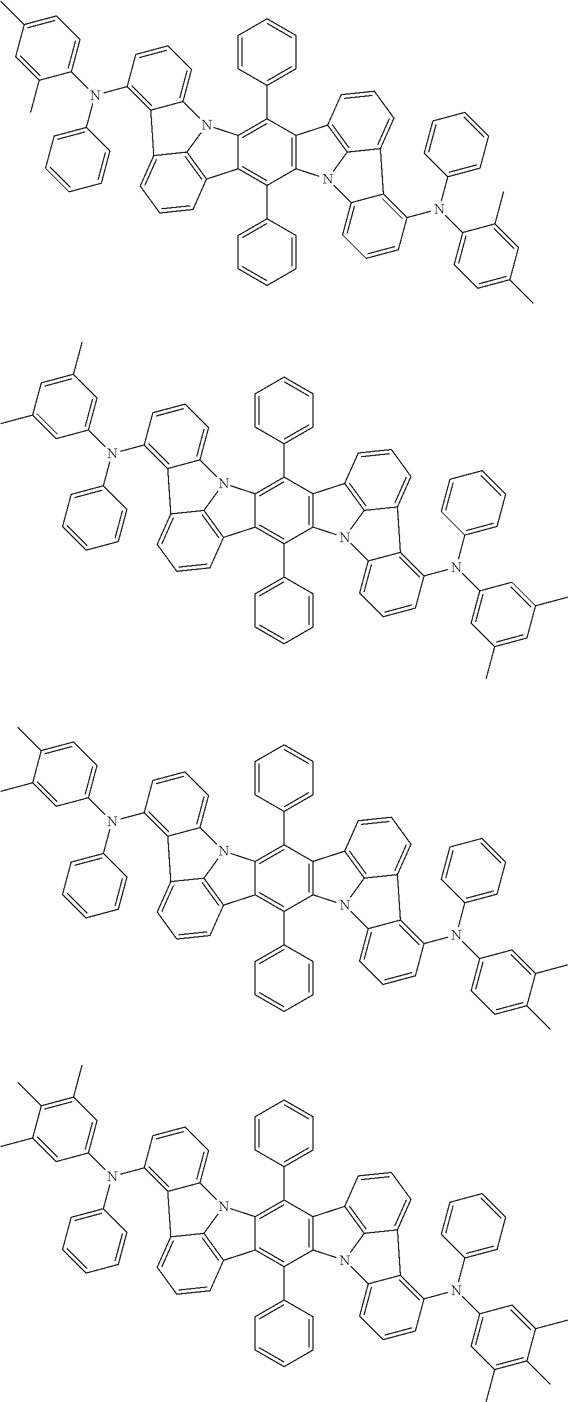

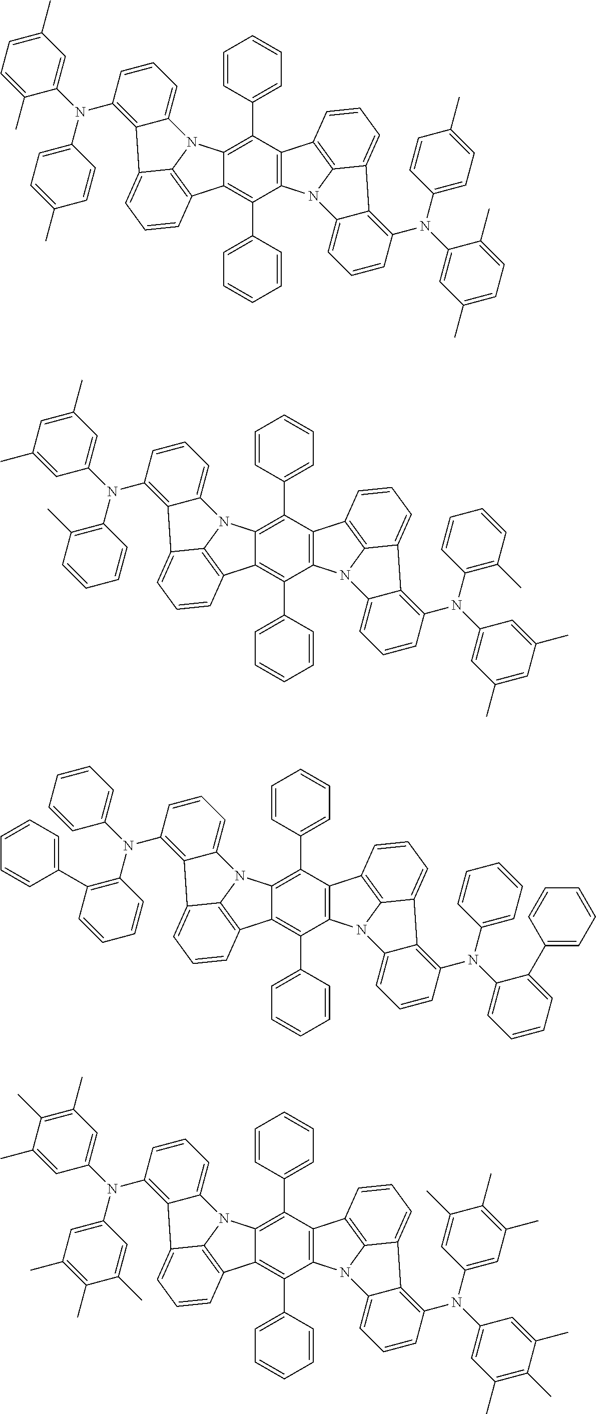

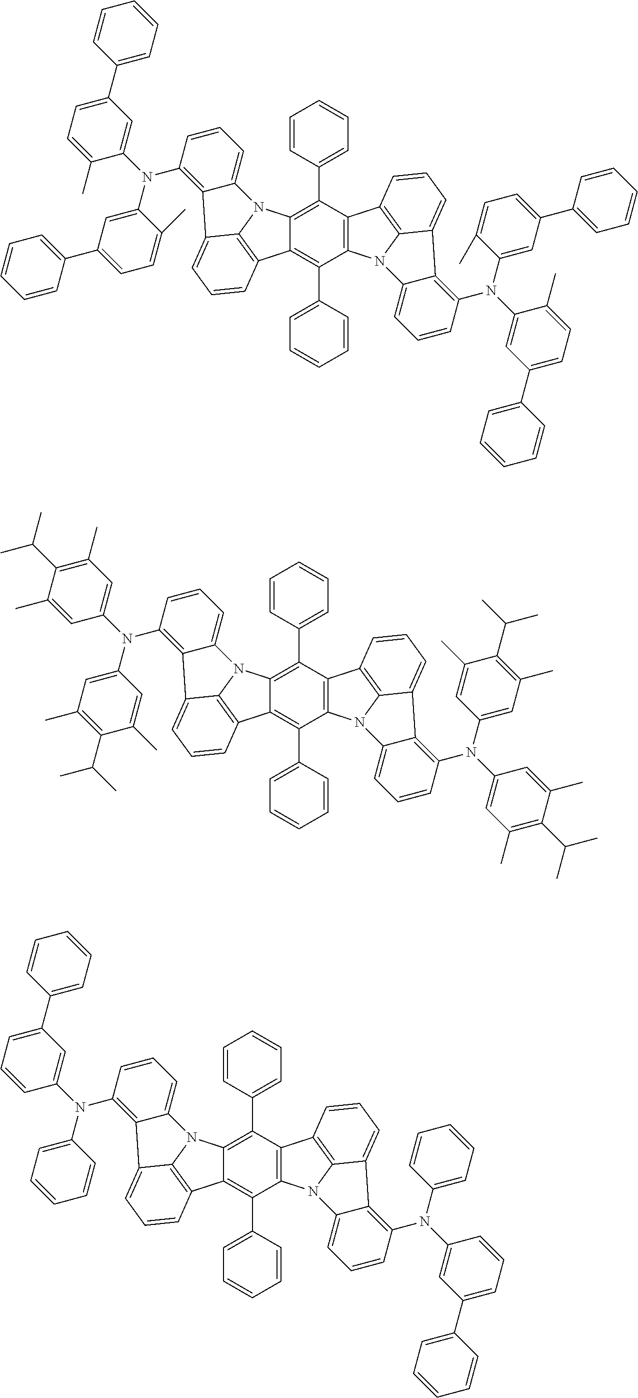 [SMILES: Cc1ccc(-c2ccccc2)cc1N(c1cc(-c2ccccc2)ccc1C)c1cccc2c1c1cccc3c4c(-c5ccccc5)c5c(c(-c6ccccc6)c4n2c13)c1cccc2c3c(N(c4cc(-c6ccccc6)ccc4C)c4cc(-c6ccccc6)ccc4C)cccc3n5c21 ; Cc1cc(N(c2cc(C)c(C(C)C)c(C)c2)c2cccc3c2c2cccc4c5c(-c6ccccc6)c6c(c(-c7ccccc7)c5n3c24)c2cccc3c4c(N(c5cc(C)c(C(C)C)c(C)c5)c5cc(C)c(C(C)C)c(C)c5)cccc4n6c32)cc(C)c1C(C)C ; c1ccc(-c2cccc(N(c3ccccc3)c3cccc4c3c3cccc5c6c(-c7ccccc7)c7c(c(-c8ccccc8)c6n4c35)c3cccc4c5c(N(c6ccccc6)c6cccc(-c8ccccc8)c6)cccc5n7c43)c2)cc1]

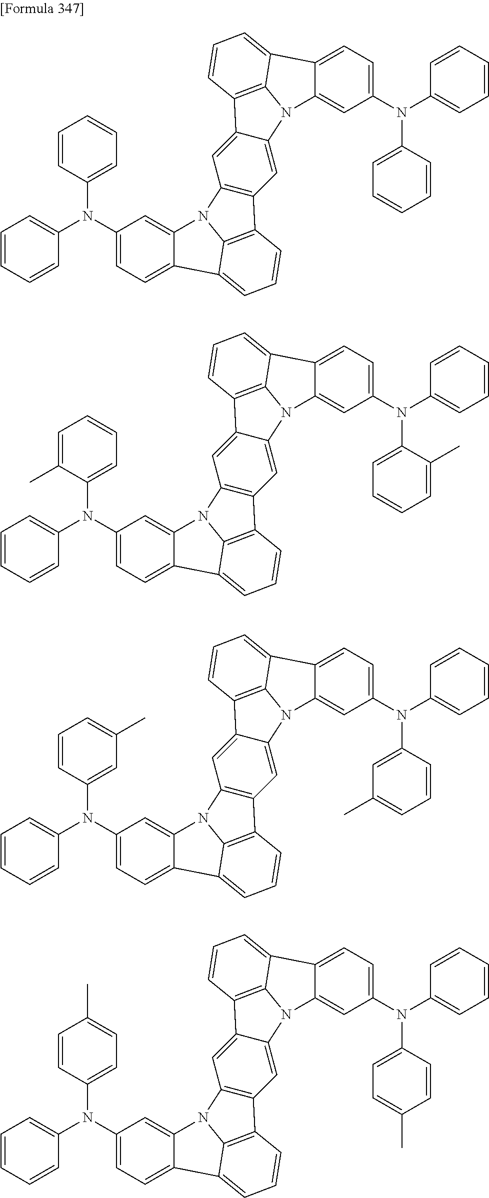

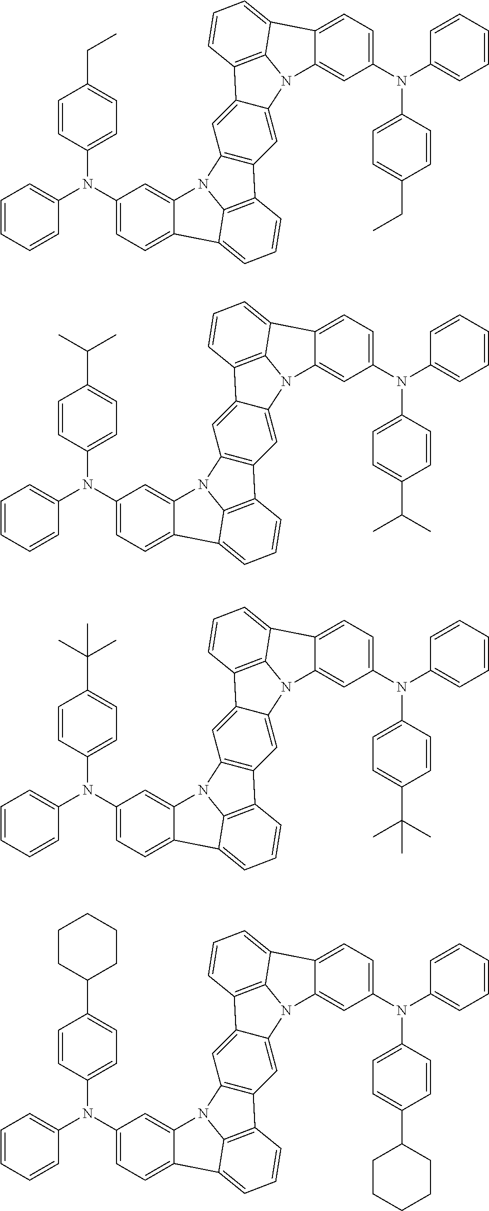

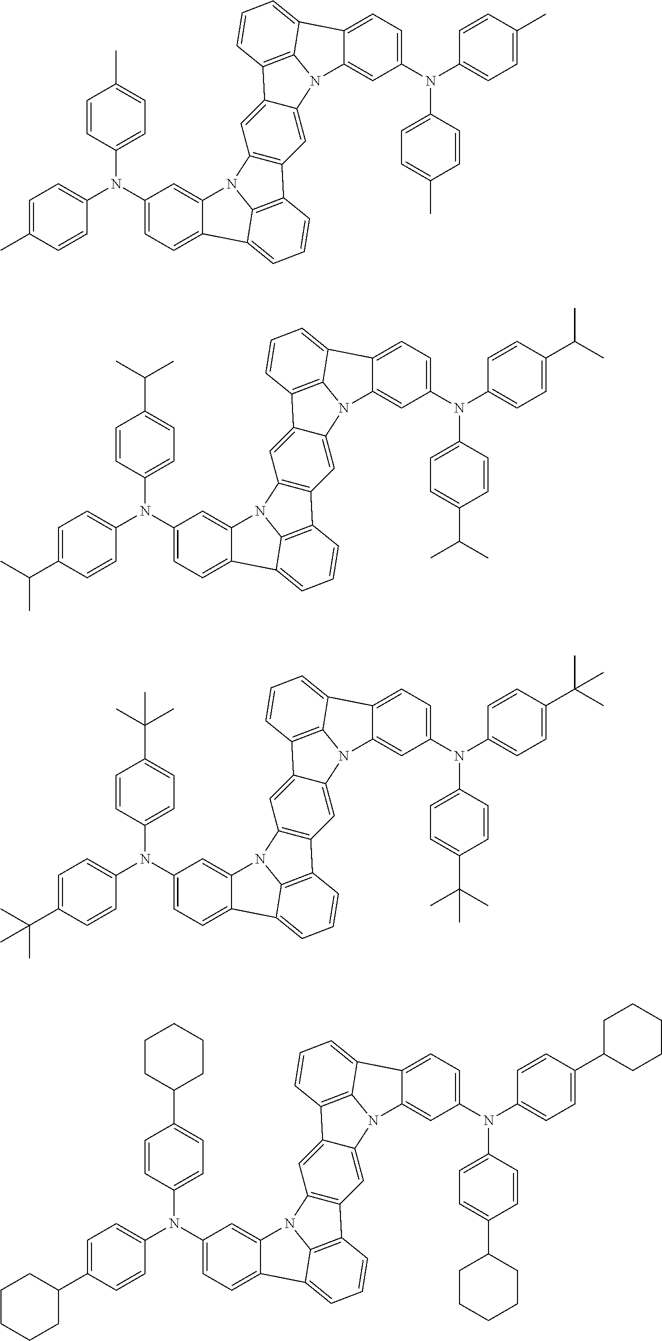

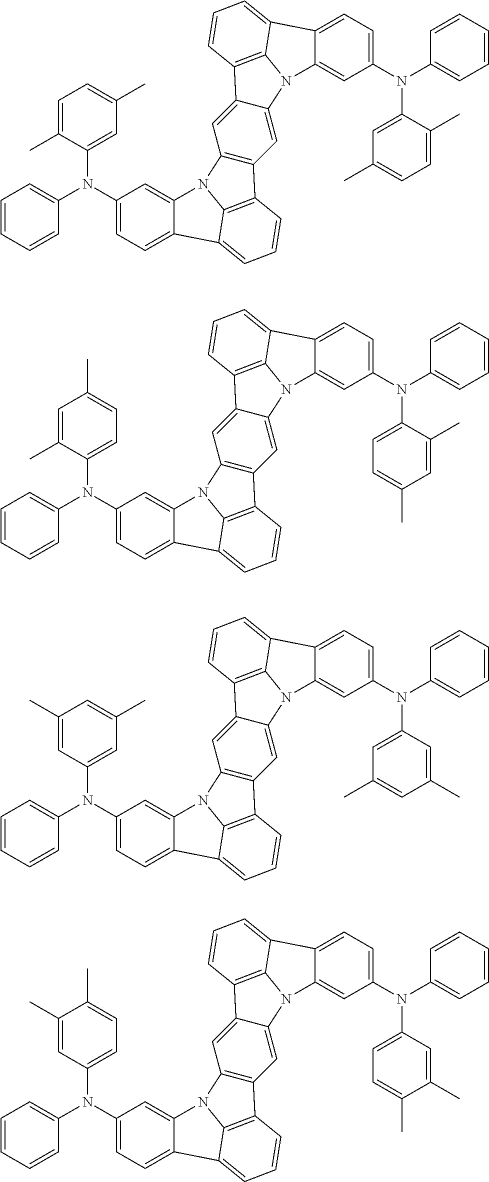

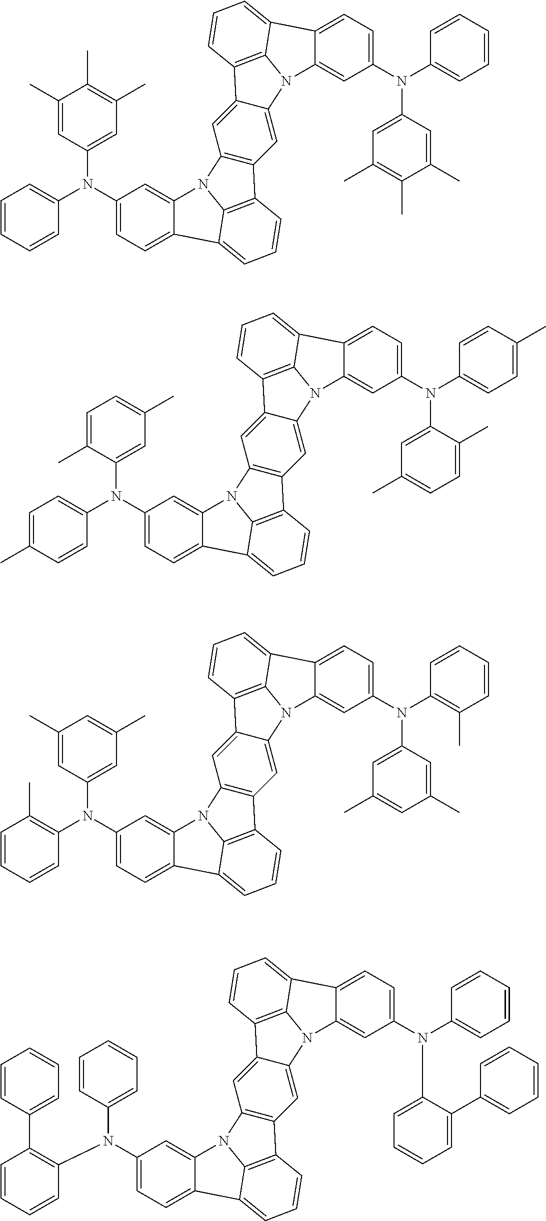

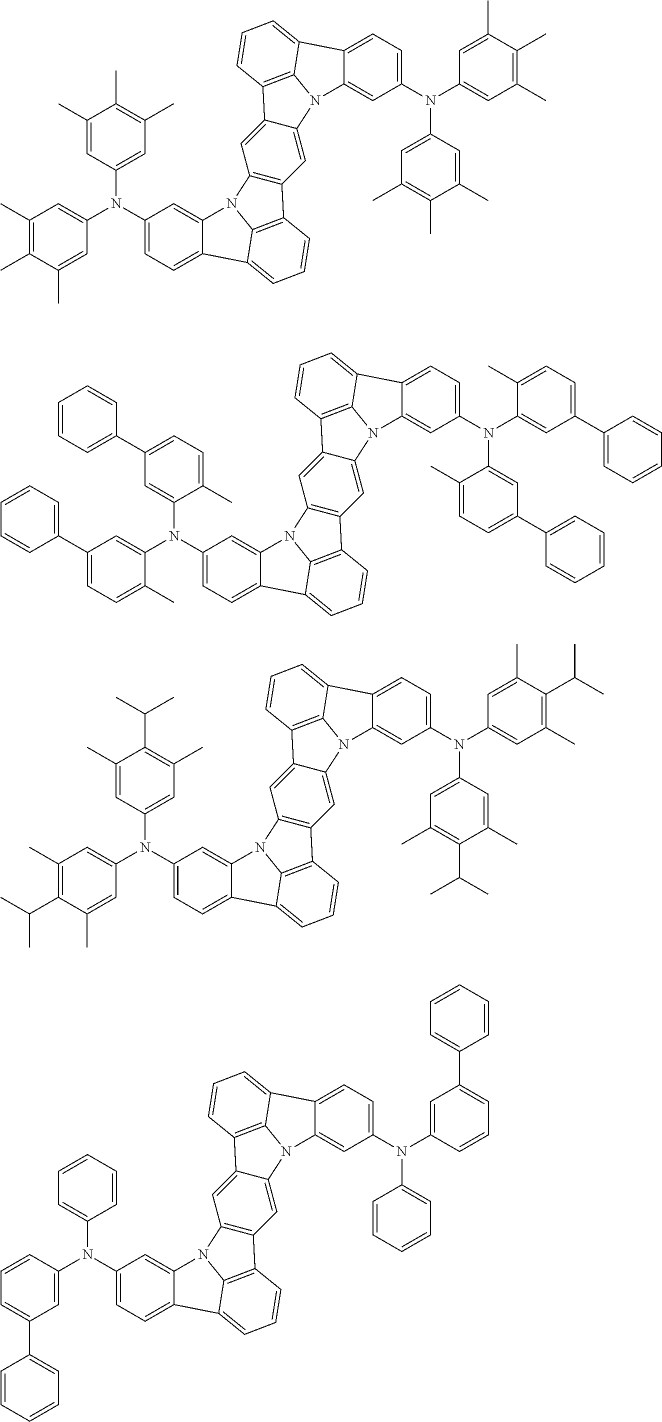

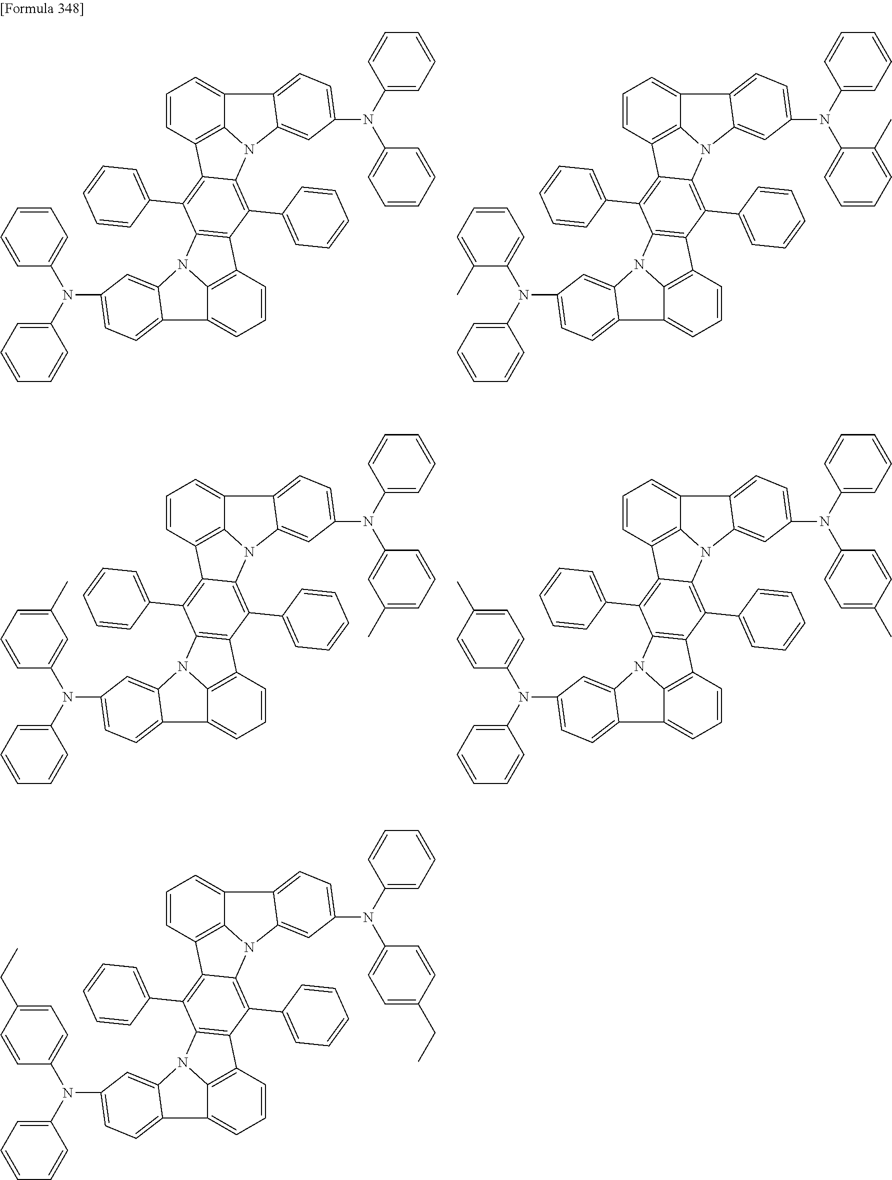

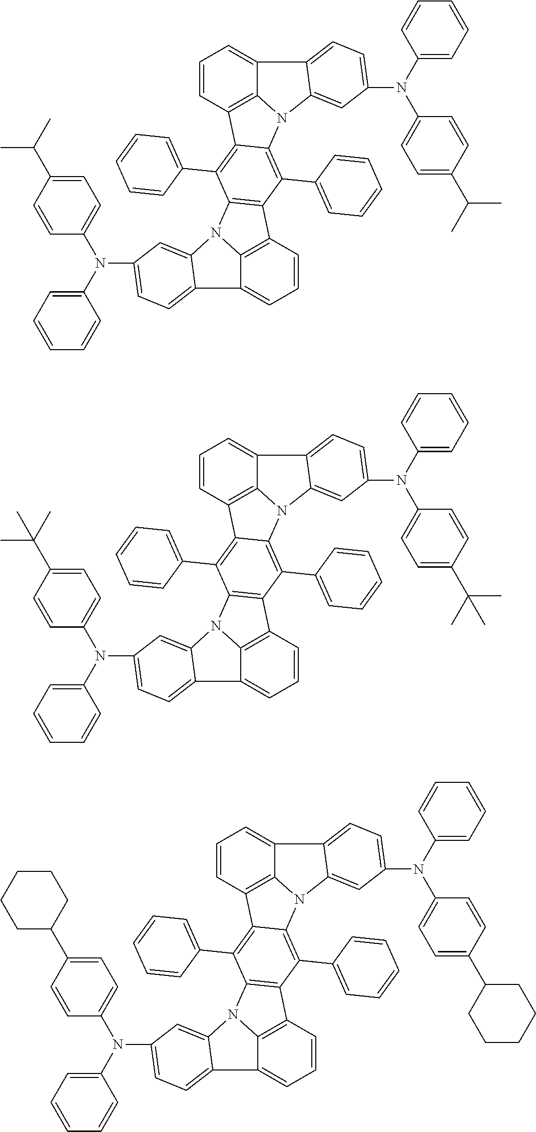

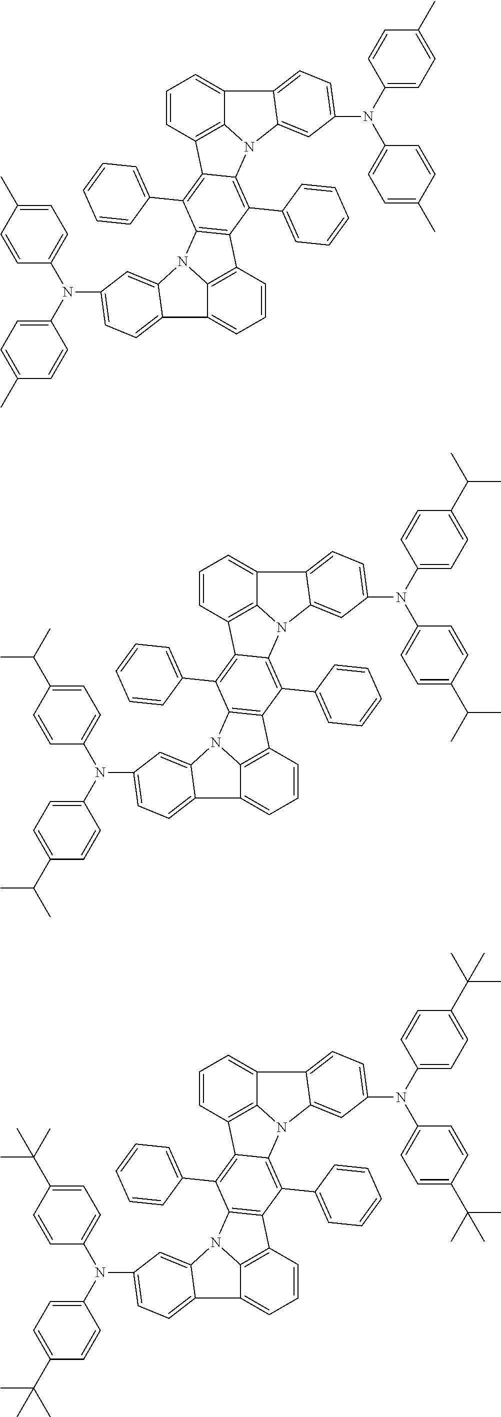

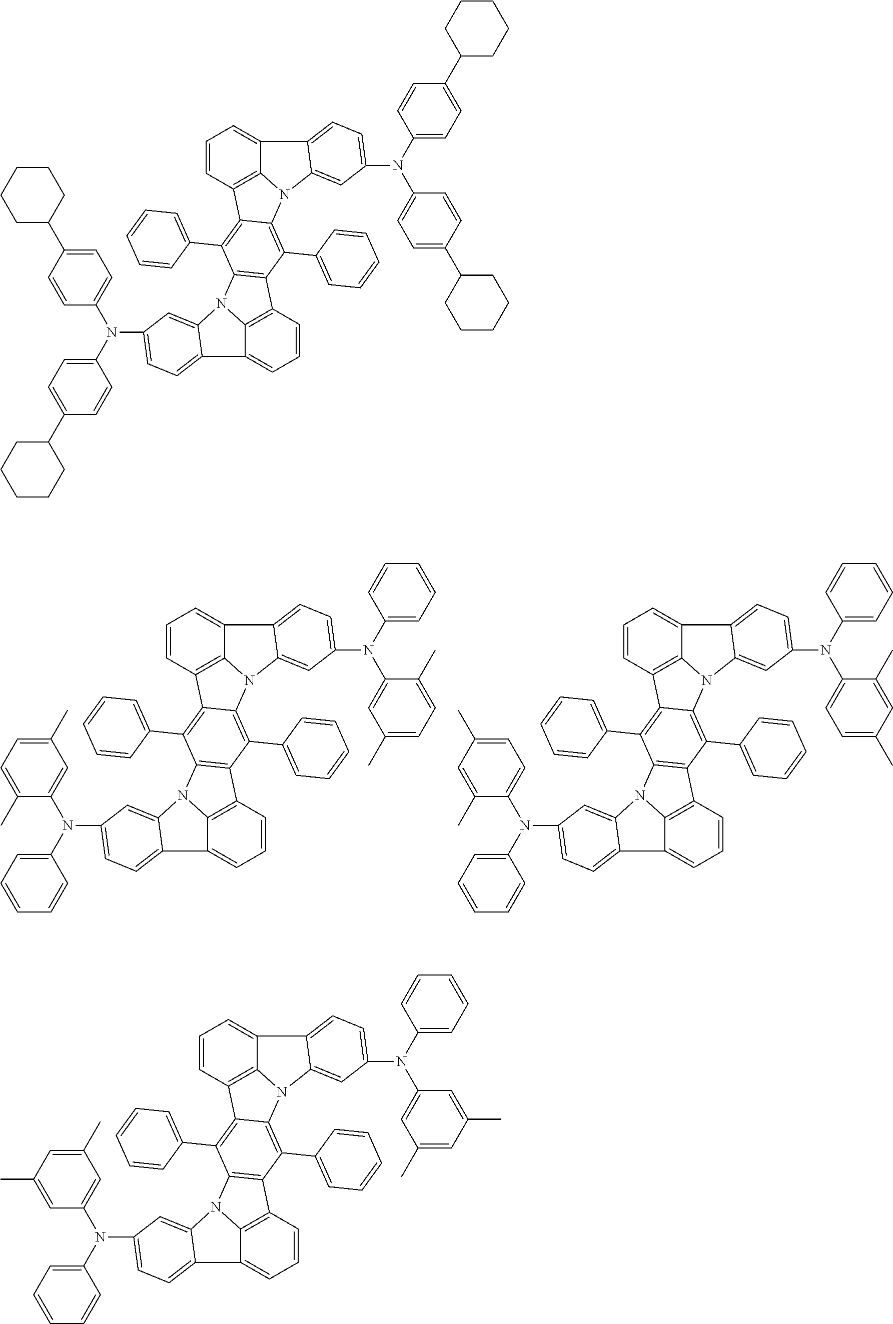

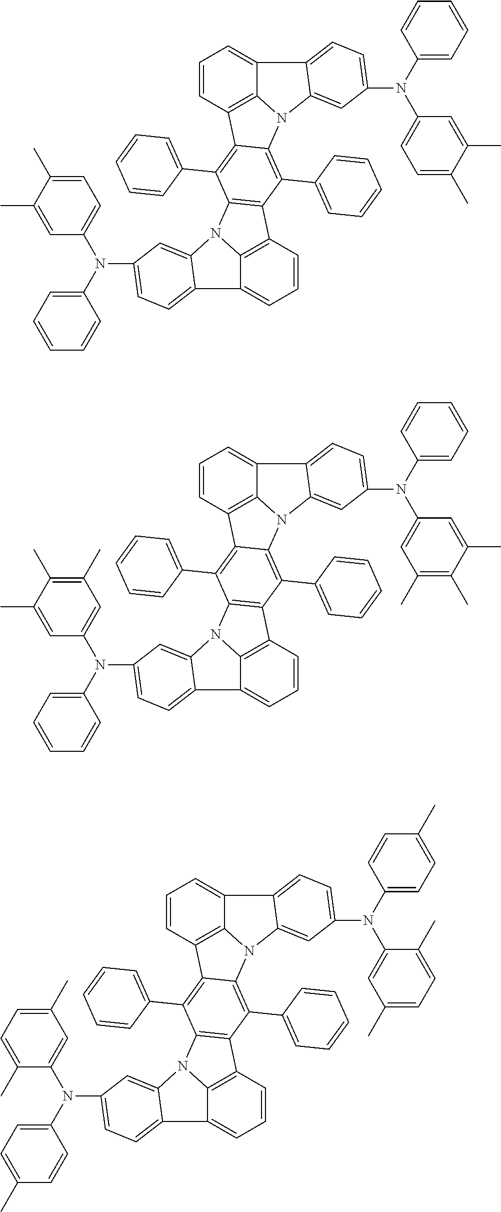

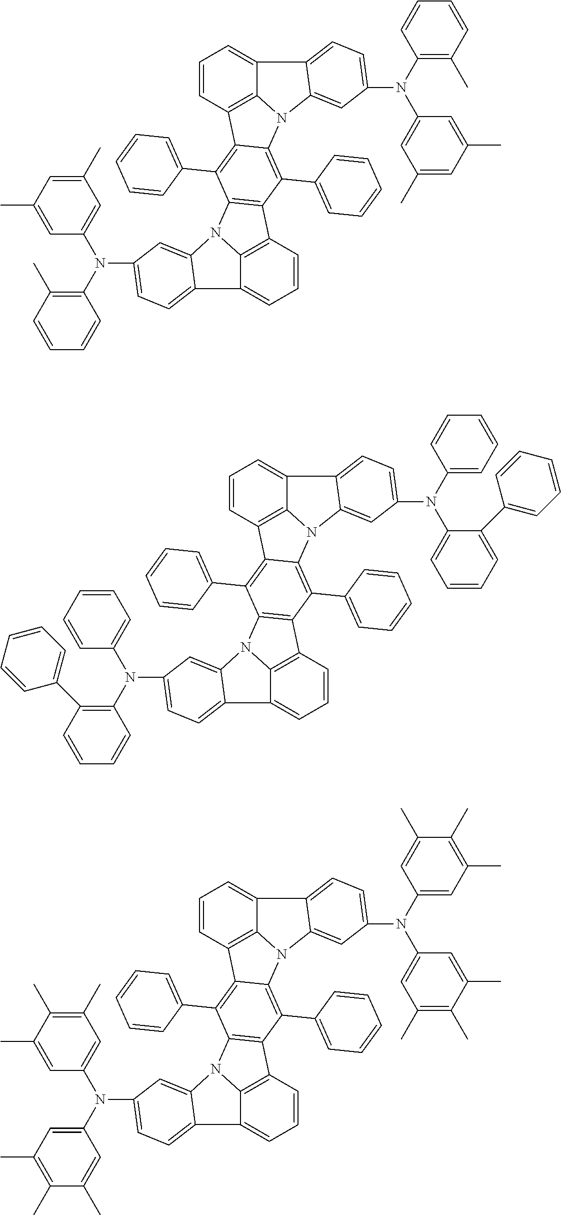

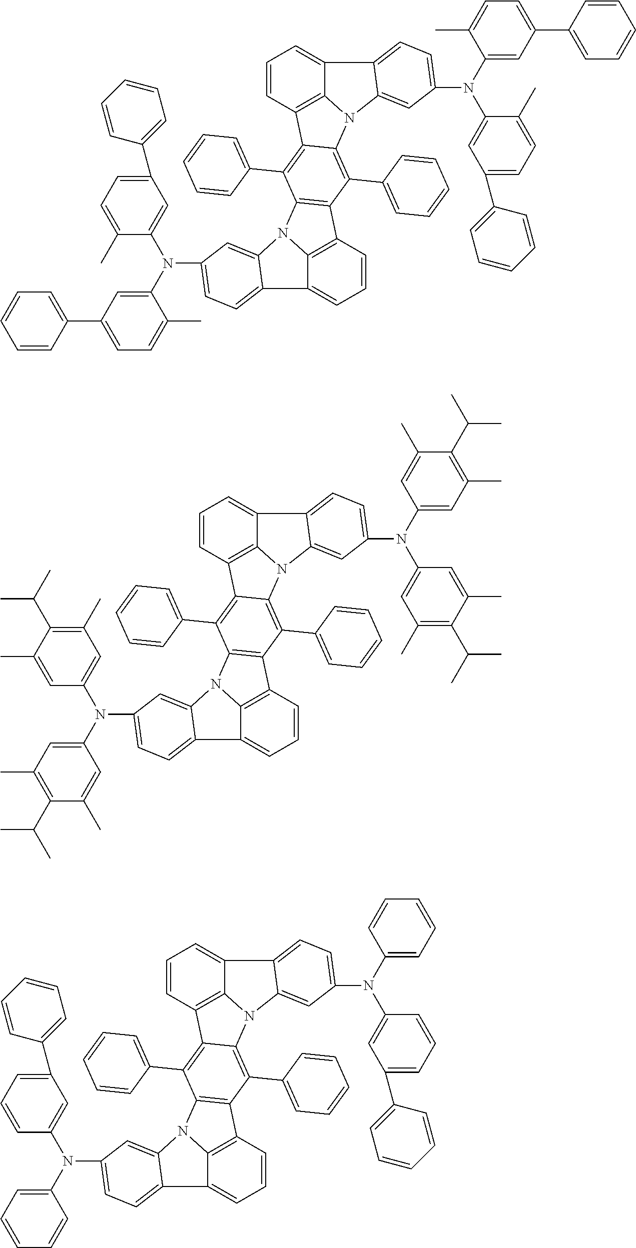 [SMILES: Cc1ccc(-c2ccccc2)cc1N(c1ccc2c3cccc4c5c(-c6ccccc6)c6c(c(-c7ccccc7)c5n(c2c1)c34)c1cccc2c3ccc(N(c4cc(-c5ccccc5)ccc4C)c4cc(-c5ccccc5)ccc4C)cc3n6c21)c1cc(-c2ccccc2)ccc1C ; Cc1cc(N(c2cc(C)c(C(C)C)c(C)c2)c2ccc3c4cccc5c6c(-c7ccccc7)c7c(c(-c8ccccc8)c6n(c3c2)c45)c2cccc3c4ccc(N(c5cc(C)c(C(C)C)c(C)c5)c5cc(C)c(C(C)C)c(C)c5)cc4n7c32)cc(C)c1C(C)C ; c1ccc(-c2cccc(N(c3ccccc3)c3ccc4c5cccc6c7c(-c8ccccc8)c8c(c(-c9ccccc9)c7n(c4c3)c56)c3cccc4c5ccc(N(c6ccccc6)c6cccc(-c7ccccc7)c6)cc5n8c43)c2)cc1]

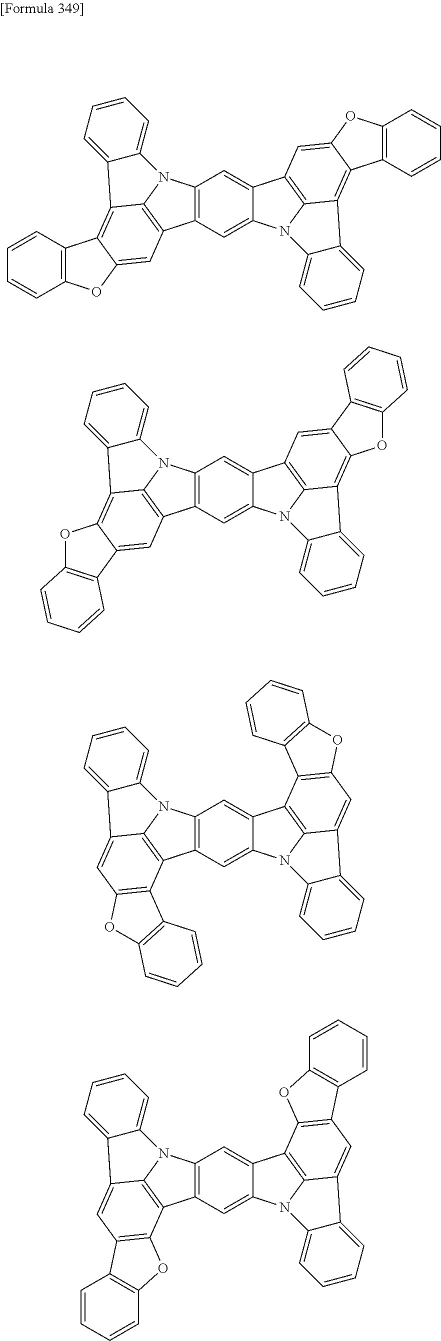 [SMILES: c1ccc2c(c1)oc1cc3c4cc5c(cc4n4c6ccccc6c(c12)c34)c1cc2oc3ccccc3c2c2c3ccccc3n5c12 ; c1ccc2c(c1)oc1c2cc2c3cc4c(cc3n3c5ccccc5c1c23)c1cc2c3ccccc3oc2c2c3ccccc3n4c12 ; c1ccc2c(c1)oc1cc3c4ccccc4n4c5cc6c7c8c(cc9c%10ccccc%10n(c6cc5c(c12)c34)c97)oc1ccccc18 ; c1ccc2c(c1)oc1c2cc2c3ccccc3n3c4cc5c6c7oc8ccccc8c7cc7c8ccccc8n(c5cc4c1c23)c76]

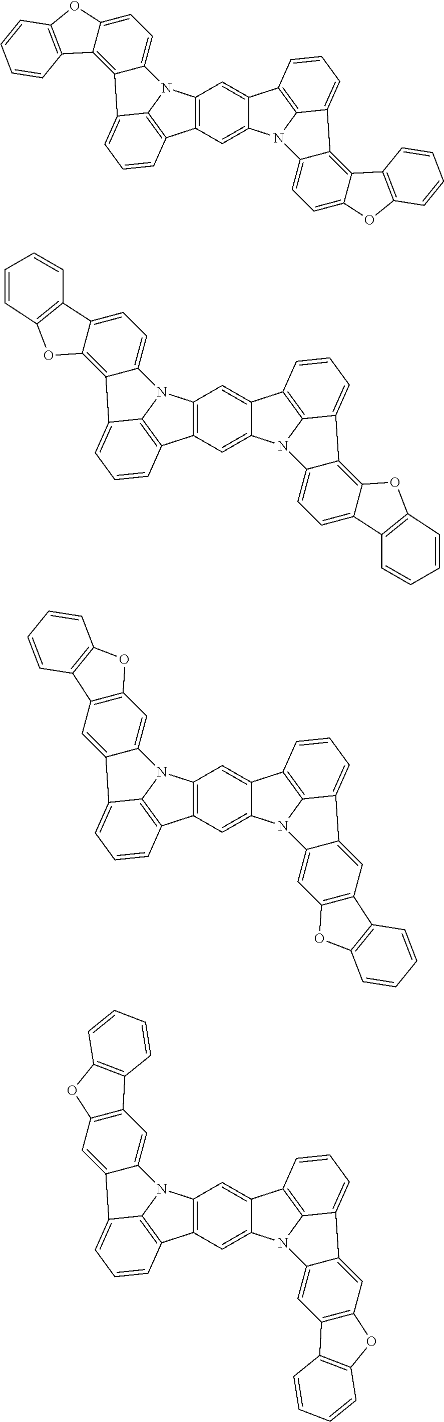 [SMILES: c1ccc2c(c1)oc1ccc3c(c4cccc5c6cc7c(cc6n3c54)c3cccc4c5c6c(ccc5n7c34)oc3ccccc36)c12 ; c1ccc2c(c1)oc1c2ccc2c1c1cccc3c4cc5c(cc4n2c31)c1cccc2c3c4oc6ccccc6c4ccc3n5c12 ; c1ccc2c(c1)oc1cc3c(cc12)c1cccc2c4cc5c(cc4n3c12)c1cccc2c3cc4c(cc3n5c21)oc1ccccc14 ; c1ccc2c(c1)oc1cc3c4cccc5c6cc7c(cc6n(c3cc12)c45)c1cccc2c3cc4oc5ccccc5c4cc3n7c21]

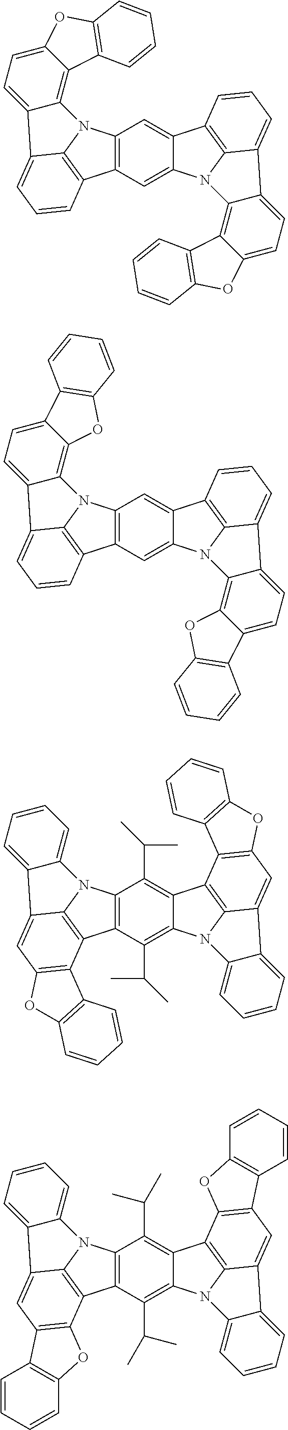

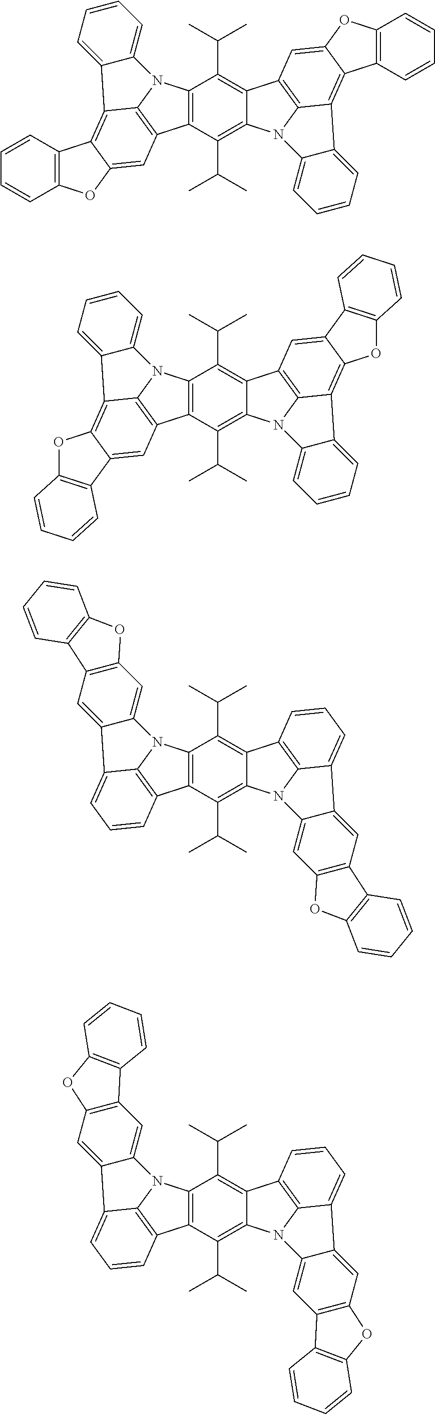

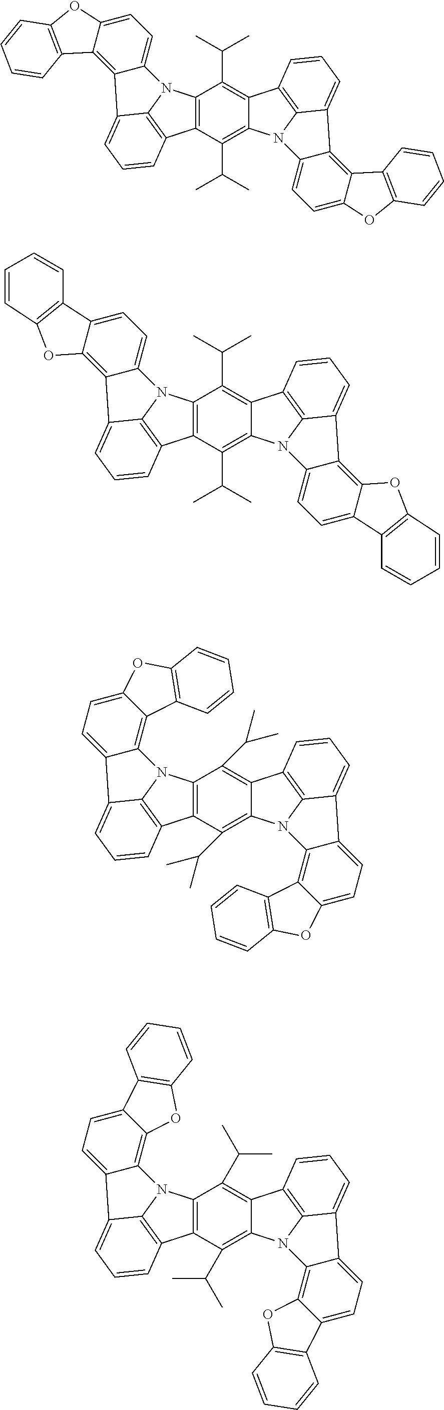 [SMILES: CC(C)c1c2c3cccc4c5c6c(ccc5n(c2c(C(C)C)c2c5cccc7c8c9c(ccc8n(c12)c57)oc1ccccc19)c34)oc1ccccc16 ; CC(C)c1c2c3cccc4c5c6oc7ccccc7c6ccc5n(c2c(C(C)C)c2c5cccc6c7c8oc9ccccc9c8ccc7n(c12)c56)c34 ; CC(C)c1c2c3cccc4c5ccc6oc7ccccc7c6c5n(c2c(C(C)C)c2c5cccc6c7ccc8oc9ccccc9c8c7n(c12)c65)c43 ; CC(C)c1c2c3cccc4c5ccc6c7ccccc7oc6c5n(c2c(C(C)C)c2c5cccc6c7ccc8c9ccccc9oc8c7n(c12)c65)c43]

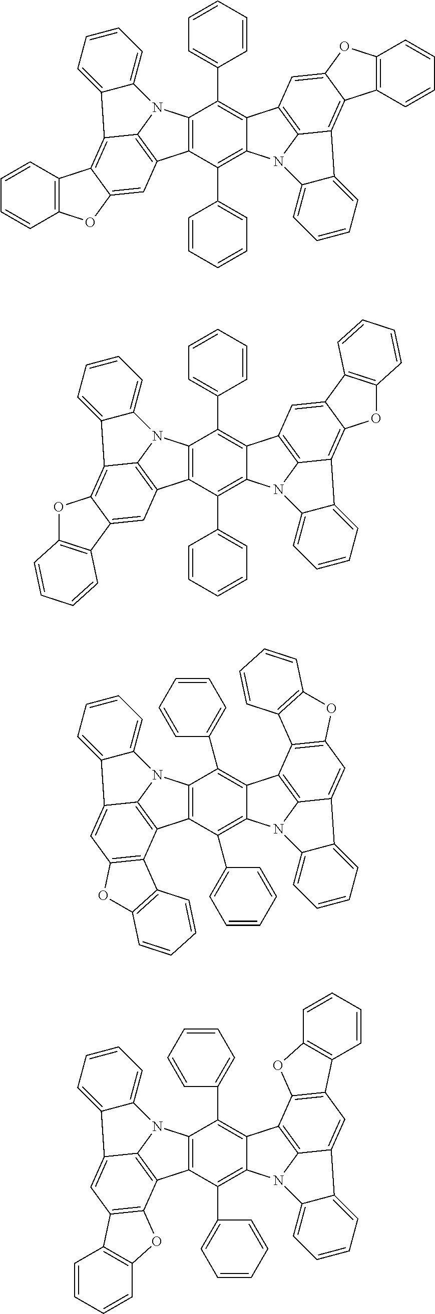 [SMILES: c1ccc(-c2c3c4cc5oc6ccccc6c5c5c6ccccc6n(c3c(-c3ccccc3)c3c6cc7oc8ccccc8c7c7c8ccccc8n(c23)c67)c45)cc1 ; c1ccc(-c2c3c4cc5c6ccccc6oc5c5c6ccccc6n(c3c(-c3ccccc3)c3c6cc7c8ccccc8oc7c7c8ccccc8n(c23)c67)c45)cc1 ; c1ccc(-c2c3c4c5c(cc6c7ccccc7n(c3c(-c3ccccc3)c3c7c8c(cc9c%10ccccc%10n(c23)c97)oc2ccccc28)c64)oc2ccccc25)cc1 ; c1ccc(-c2c3c4c5oc6ccccc6c5cc5c6ccccc6n(c3c(-c3ccccc3)c3c6c7oc8ccccc8c7cc7c8ccccc8n(c23)c76)c54)cc1]

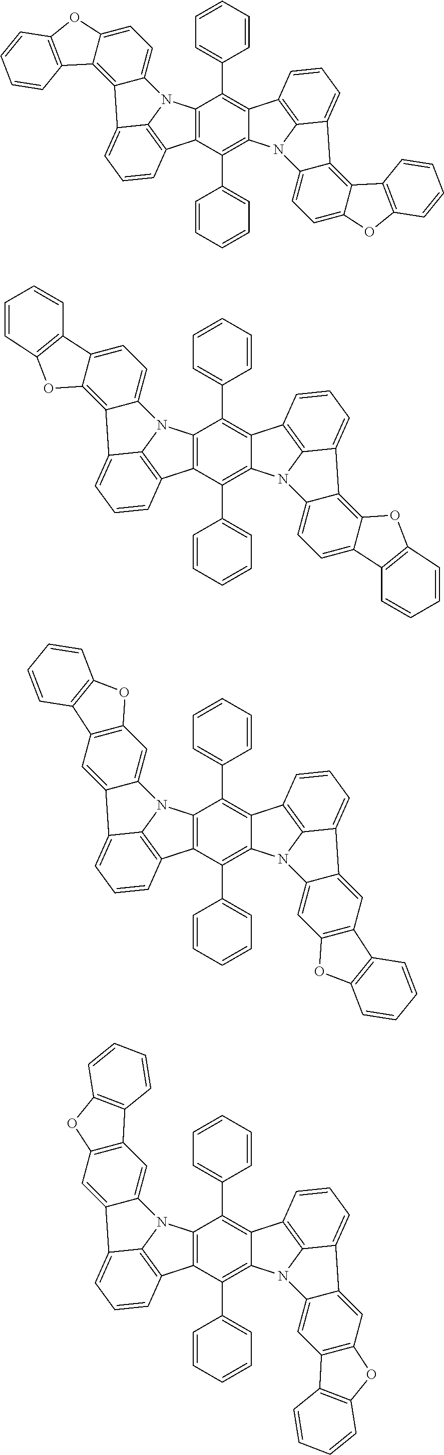 [SMILES: c1ccc(-c2c3c4cccc5c6c7c(ccc6n(c3c(-c3ccccc3)c3c6cccc8c9c%10c(ccc9n(c23)c68)oc2ccccc2%10)c45)oc2ccccc27)cc1 ; c1ccc(-c2c3c4cccc5c6c7oc8ccccc8c7ccc6n(c3c(-c3ccccc3)c3c6cccc7c8c9oc%10ccccc%10c9ccc8n(c23)c67)c45)cc1 ; c1ccc(-c2c3c4cccc5c6cc7c(cc6n(c3c(-c3ccccc3)c3c6cccc8c9cc%10c(cc9n(c23)c86)oc2ccccc2%10)c54)oc2ccccc27)cc1 ; c1ccc(-c2c3c4cccc5c6cc7oc8ccccc8c7cc6n(c3c(-c3ccccc3)c3c6cccc7c8cc9oc%10ccccc%10c9cc8n(c23)c76)c54)cc1]

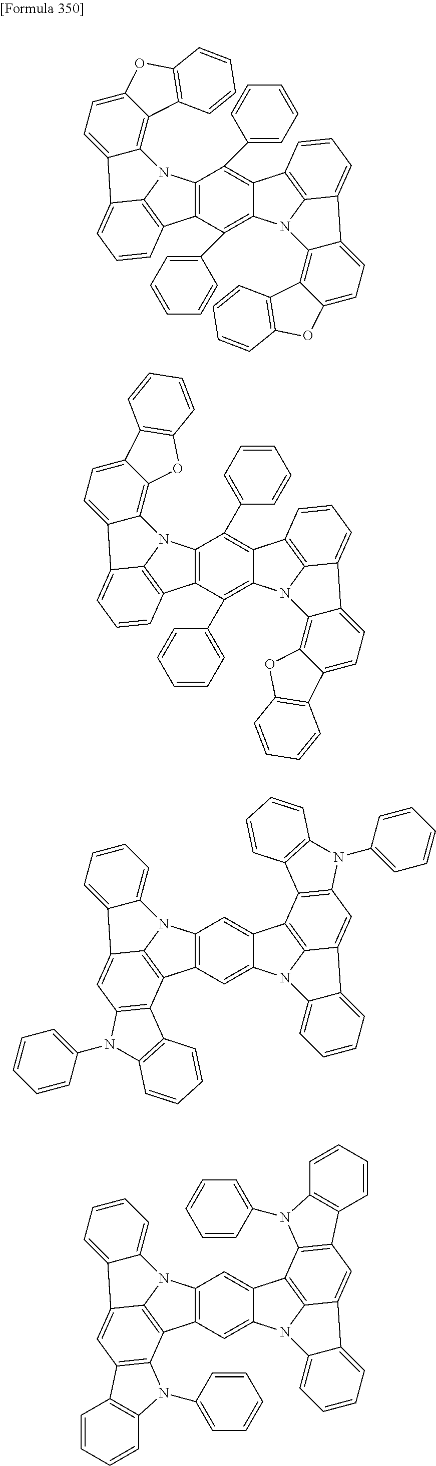

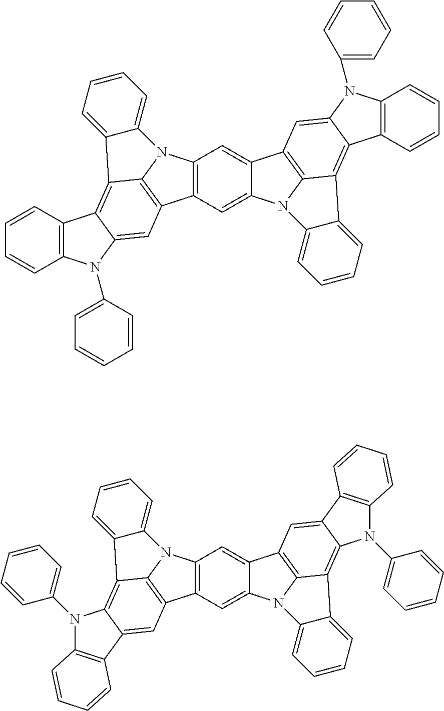 [SMILES: c1ccc(-n2c3ccccc3c3c4c5ccccc5n5c6cc7c8cc9c(c%10ccccc%10n9-c9ccccc9)c9c%10ccccc%10n(c7cc6c(cc32)c45)c89)cc1 ; c1ccc(-n2c3ccccc3c3cc4c5cc6c(cc5n5c7ccccc7c(c32)c45)c2cc3c4ccccc4n(-c4ccccc4)c3c3c4ccccc4n6c23)cc1]

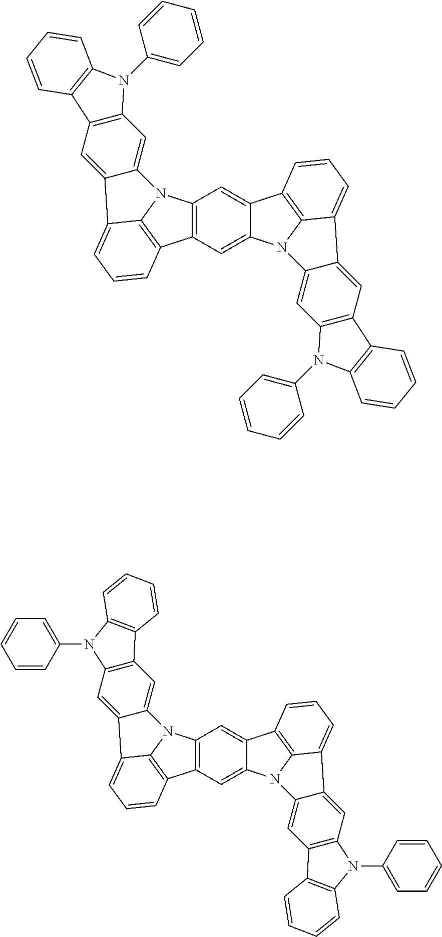 [SMILES: c1ccc(-n2c3ccccc3c3cc4c5cccc6c7cc8c(cc7n(c4cc32)c65)c2cccc3c4cc5c6ccccc6n(-c6ccccc6)c5cc4n8c23)cc1 ; c1ccc(-n2c3ccccc3c3cc4c(cc32)c2cccc3c5cc6c(cc5n4c23)c2cccc3c4cc5c(cc4n6c32)c2ccccc2n5-c2ccccc2)cc1]

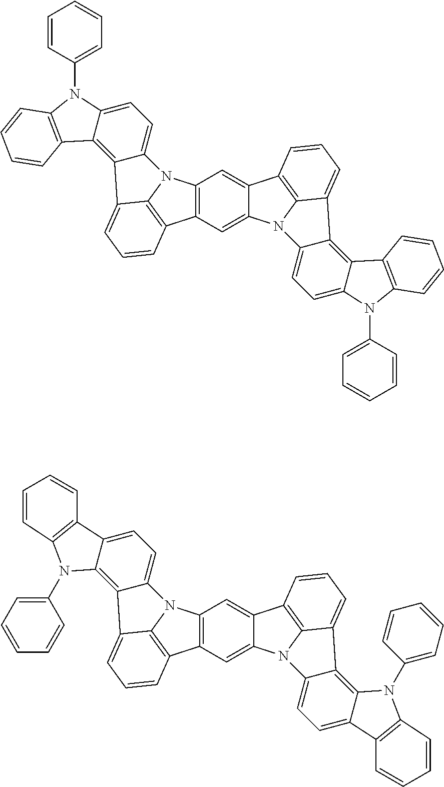 [SMILES: c1ccc(-n2c3ccccc3c3c4c5cccc6c7cc8c(cc7n(c4ccc32)c65)c2cccc3c4c5c6ccccc6n(-c6ccccc6)c5ccc4n8c23)cc1 ; c1ccc(-n2c3ccccc3c3ccc4c(c5cccc6c7cc8c(cc7n4c65)c4cccc5c6c7c(ccc6n8c45)c4ccccc4n7-c4ccccc4)c32)cc1]

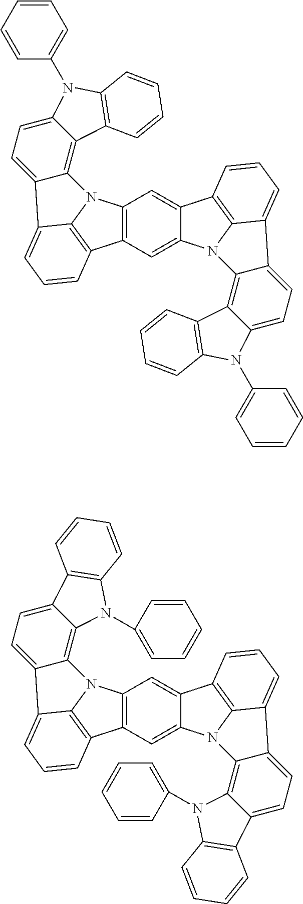 [SMILES: c1ccc(-n2c3ccccc3c3c2ccc2c4cccc5c6cc7c(cc6n(c54)c23)c2cccc3c4ccc5c(c6ccccc6n5-c5ccccc5)c4n7c23)cc1 ; c1ccc(-n2c3ccccc3c3ccc4c5cccc6c7cc8c(cc7n(c65)c4c32)c2cccc3c4ccc5c6ccccc6n(-c6ccccc6)c5c4n8c23)cc1]

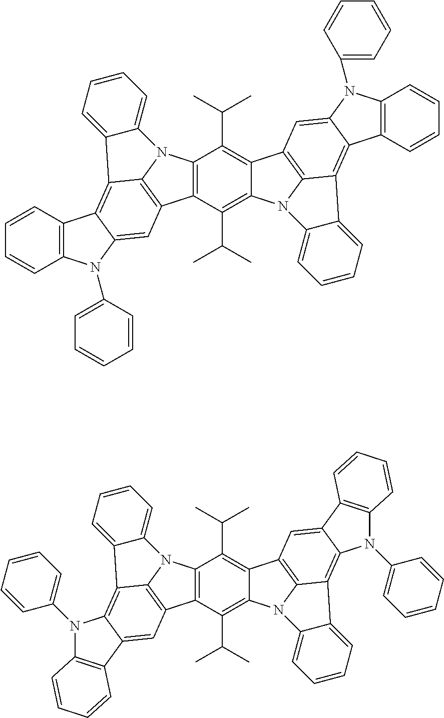 [SMILES: CC(C)c1c2c3cc4c(c5ccccc5n4-c4ccccc4)c4c5ccccc5n(c2c(C(C)C)c2c5cc6c(c7ccccc7n6-c6ccccc6)c6c7ccccc7n(c12)c56)c34 ; CC(C)c1c2c3cc4c5ccccc5n(-c5ccccc5)c4c4c5ccccc5n(c2c(C(C)C)c2c5cc6c7ccccc7n(-c7ccccc7)c6c6c7ccccc7n(c12)c56)c34]

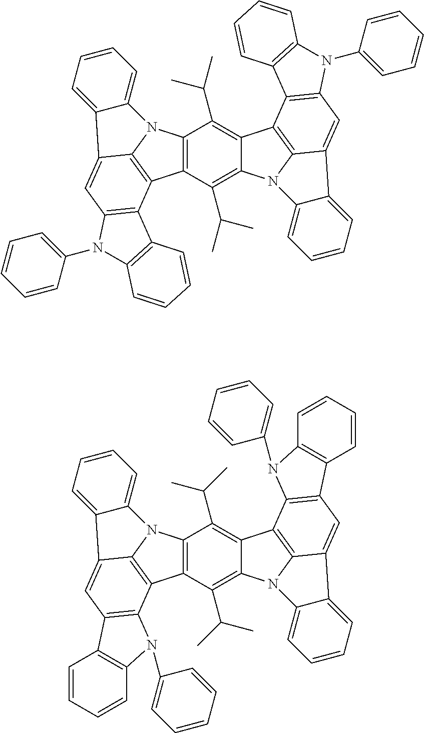 [SMILES: CC(C)c1c2c3c4c5ccccc5n(-c5ccccc5)c4cc4c5ccccc5n(c2c(C(C)C)c2c5c6c7ccccc7n(-c7ccccc7)c6cc6c7ccccc7n(c12)c65)c43 ; CC(C)c1c2c3c4c(cc5c6ccccc6n(c2c(C(C)C)c2c6c7c(cc8c9ccccc9n(c12)c86)c1ccccc1n7-c1ccccc1)c53)c1ccccc1n4-c1ccccc1]

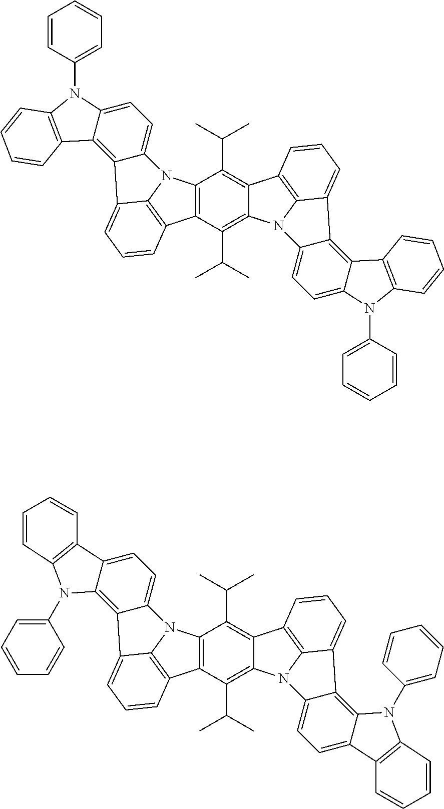 [SMILES: CC(C)c1c2c3cccc4c5c6c7ccccc7n(-c7ccccc7)c6ccc5n(c2c(C(C)C)c2c5cccc6c7c8c9ccccc9n(-c9ccccc9)c8ccc7n(c12)c56)c34 ; CC(C)c1c2c3cccc4c5c6c(ccc5n(c2c(C(C)C)c2c5cccc7c8c9c(ccc8n(c12)c57)c1ccccc1n9-c1ccccc1)c34)c1ccccc1n6-c1ccccc1]

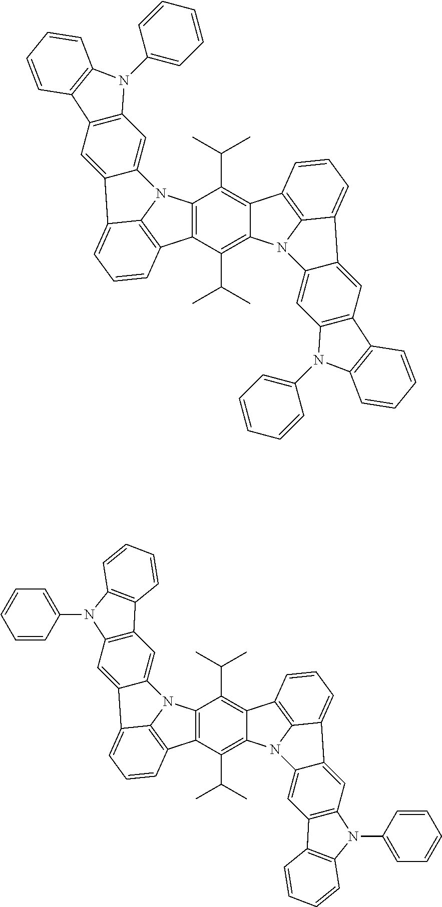 [SMILES: CC(C)c1c2c3cccc4c5cc6c7ccccc7n(-c7ccccc7)c6cc5n(c2c(C(C)C)c2c5cccc6c7cc8c9ccccc9n(-c9ccccc9)c8cc7n(c12)c65)c43 ; CC(C)c1c2c3cccc4c5cc6c(cc5n(c2c(C(C)C)c2c5cccc7c8cc9c(cc8n(c12)c75)c1ccccc1n9-c1ccccc1)c43)c1ccccc1n6-c1ccccc1]

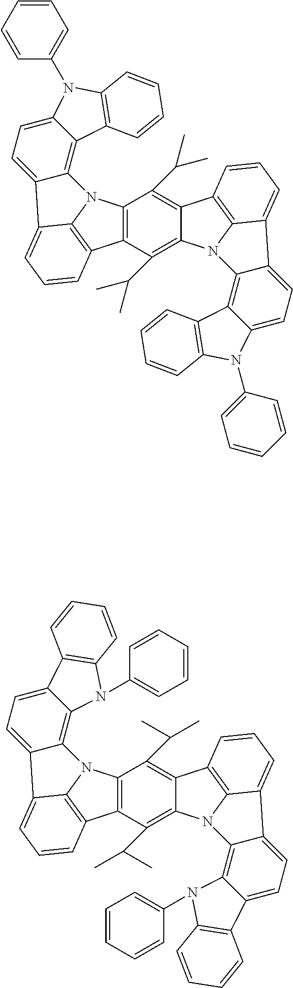 [SMILES: CC(C)c1c2c3cccc4c5ccc6c(c7ccccc7n6-c6ccccc6)c5n(c2c(C(C)C)c2c5cccc6c7ccc8c(c9ccccc9n8-c8ccccc8)c7n(c12)c65)c43 ; CC(C)c1c2c3cccc4c5ccc6c7ccccc7n(-c7ccccc7)c6c5n(c2c(C(C)C)c2c5cccc6c7ccc8c9ccccc9n(-c9ccccc9)c8c7n(c12)c65)c43]

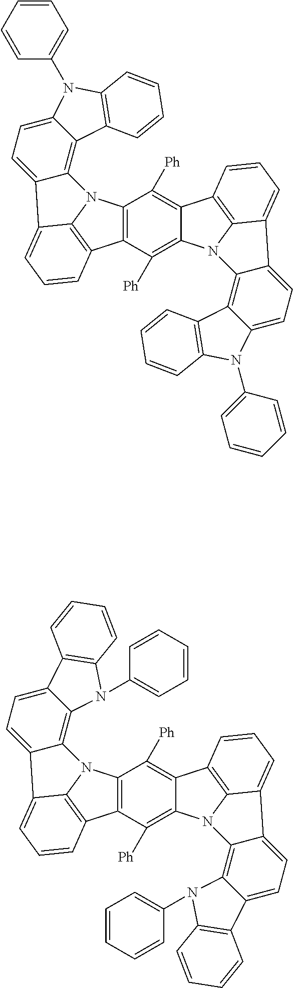 [SMILES: c1ccc(-c2c3c4cccc5c6ccc7c(c8ccccc8n7-c7ccccc7)c6n(c3c(-c3ccccc3)c3c6cccc7c8ccc9c(c%10ccccc%10n9-c9ccccc9)c8n(c23)c76)c54)cc1 ; c1ccc(-c2c3c4cccc5c6ccc7c8ccccc8n(-c8ccccc8)c7c6n(c3c(-c3ccccc3)c3c6cccc7c8ccc9c%10ccccc%10n(-c%10ccccc%10)c9c8n(c23)c76)c54)cc1]

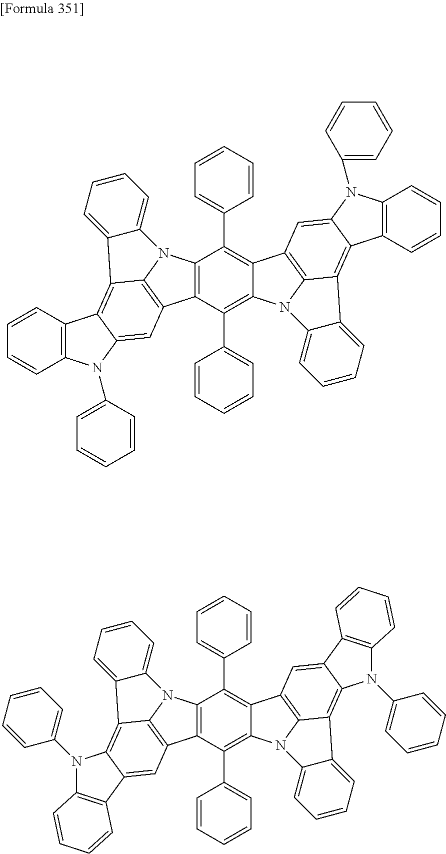 [SMILES: c1ccc(-c2c3c4cc5c(c6ccccc6n5-c5ccccc5)c5c6ccccc6n(c3c(-c3ccccc3)c3c6cc7c(c8ccccc8n7-c7ccccc7)c7c8ccccc8n(c23)c67)c45)cc1 ; c1ccc(-c2c3c4cc5c6ccccc6n(-c6ccccc6)c5c5c6ccccc6n(c3c(-c3ccccc3)c3c6cc7c8ccccc8n(-c8ccccc8)c7c7c8ccccc8n(c23)c67)c45)cc1]

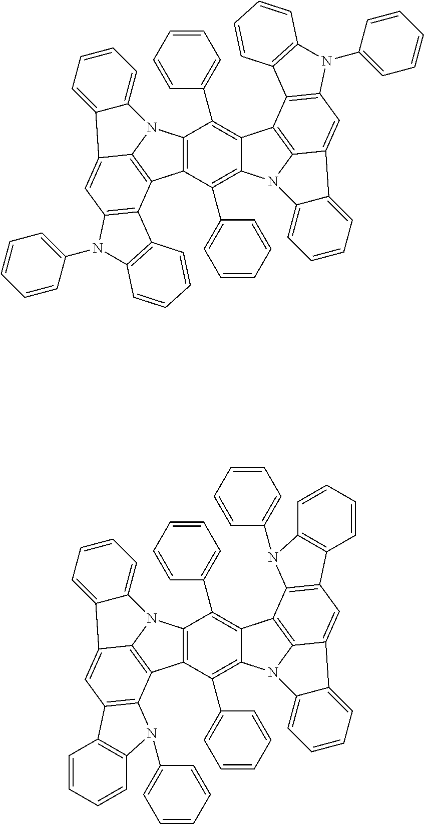 [SMILES: c1ccc(-c2c3c4c5c6ccccc6n(-c6ccccc6)c5cc5c6ccccc6n(c3c(-c3ccccc3)c3c6c7c8ccccc8n(-c8ccccc8)c7cc7c8ccccc8n(c23)c76)c54)cc1 ; c1ccc(-c2c3c4c5c(cc6c7ccccc7n(c3c(-c3ccccc3)c3c7c8c(cc9c%10ccccc%10n(c23)c97)c2ccccc2n8-c2ccccc2)c64)c2ccccc2n5-c2ccccc2)cc1]

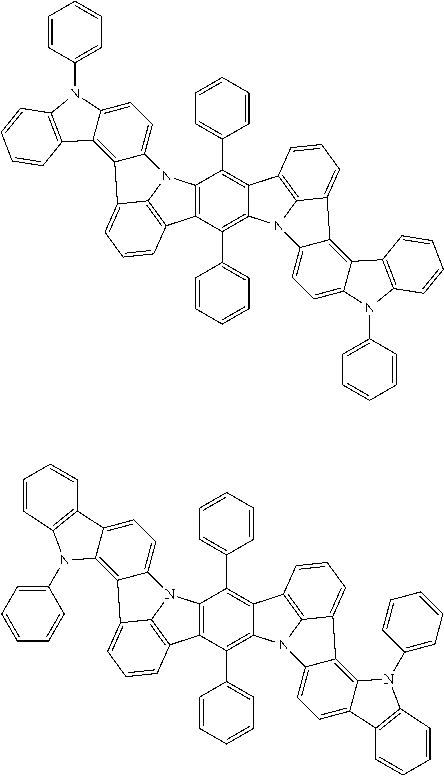 [SMILES: c1ccc(-c2c3c4cccc5c6c7c8ccccc8n(-c8ccccc8)c7ccc6n(c3c(-c3ccccc3)c3c6cccc7c8c9c%10ccccc%10n(-c%10ccccc%10)c9ccc8n(c23)c67)c45)cc1 ; c1ccc(-c2c3c4cccc5c6c7c(ccc6n(c3c(-c3ccccc3)c3c6cccc8c9c%10c(ccc9n(c23)c68)c2ccccc2n%10-c2ccccc2)c45)c2ccccc2n7-c2ccccc2)cc1]

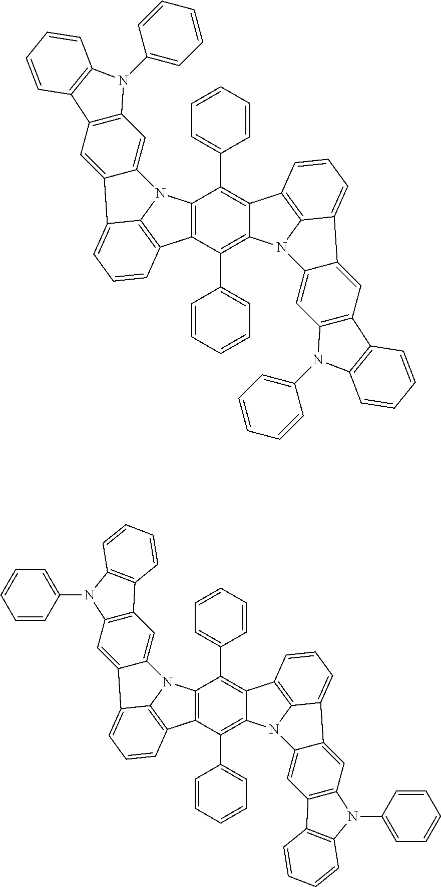 [SMILES: c1ccc(-c2c3c4cccc5c6cc7c8ccccc8n(-c8ccccc8)c7cc6n(c3c(-c3ccccc3)c3c6cccc7c8cc9c%10ccccc%10n(-c%10ccccc%10)c9cc8n(c23)c76)c54)cc1 ; c1ccc(-c2c3c4cccc5c6cc7c(cc6n(c3c(-c3ccccc3)c3c6cccc8c9cc%10c(cc9n(c23)c86)c2ccccc2n%10-c2ccccc2)c54)c2ccccc2n7-c2ccccc2)cc1]

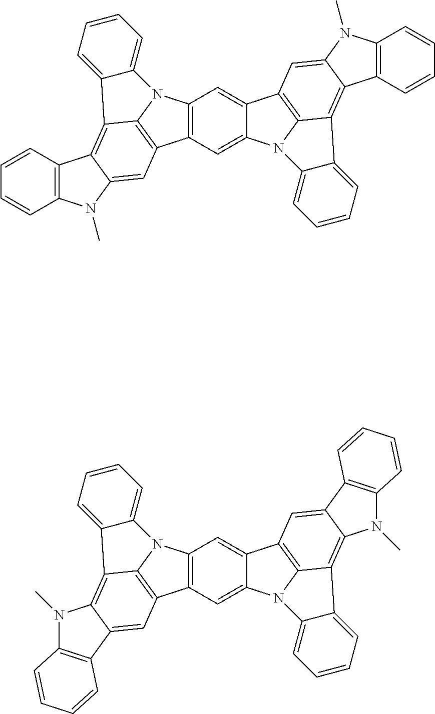 [SMILES: Cn1c2ccccc2c2c3c4ccccc4n4c5cc6c7cc8c(c9ccccc9n8C)c8c9ccccc9n(c6cc5c(cc21)c34)c78 ; Cn1c2ccccc2c2cc3c4cc5c(cc4n4c6ccccc6c(c21)c34)c1cc2c3ccccc3n(C)c2c2c3ccccc3n5c12]

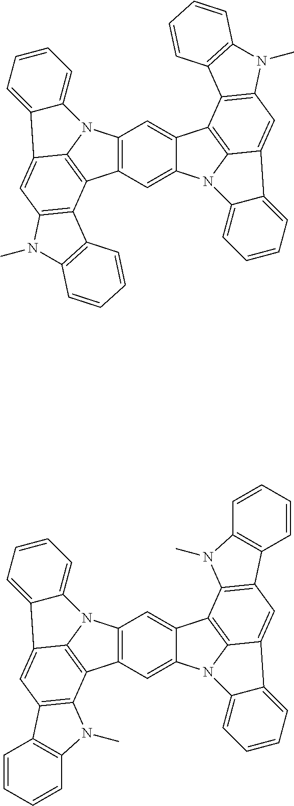

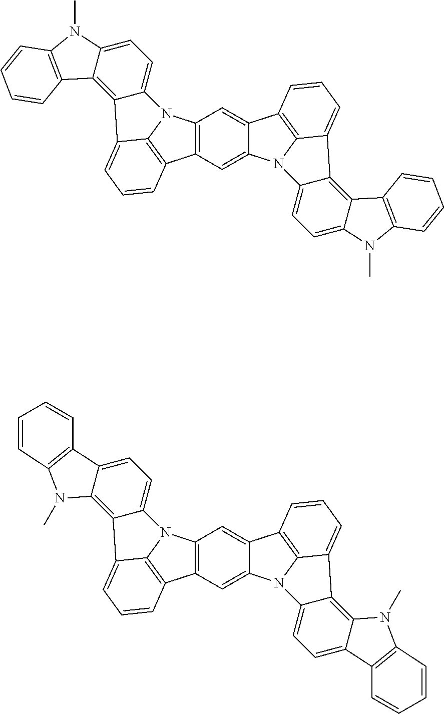 [SMILES: Cn1c2ccccc2c2c3c4cccc5c6cc7c(cc6n(c3ccc21)c54)c1cccc2c3c4c5ccccc5n(C)c4ccc3n7c12 ; Cn1c2ccccc2c2ccc3c(c4cccc5c6cc7c(cc6n3c54)c3cccc4c5c6c(ccc5n7c34)c3ccccc3n6C)c21]

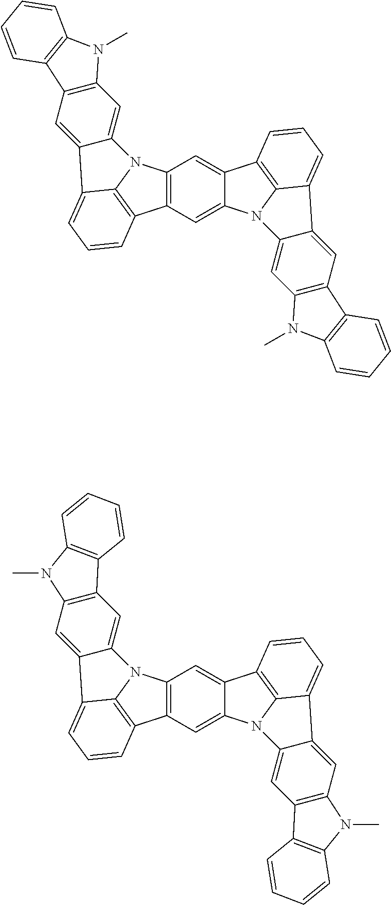

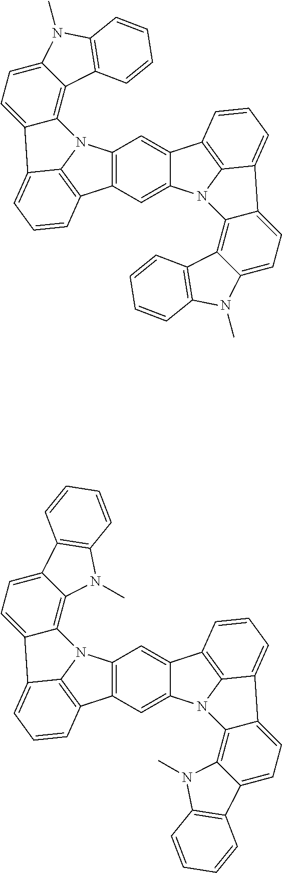 [SMILES: Cn1c2ccccc2c2c1ccc1c3cccc4c5cc6c(cc5n(c43)c12)c1cccc2c3ccc4c(c5ccccc5n4C)c3n6c12 ; Cn1c2ccccc2c2ccc3c4cccc5c6cc7c(cc6n(c54)c3c21)c1cccc2c3ccc4c5ccccc5n(C)c4c3n7c12]

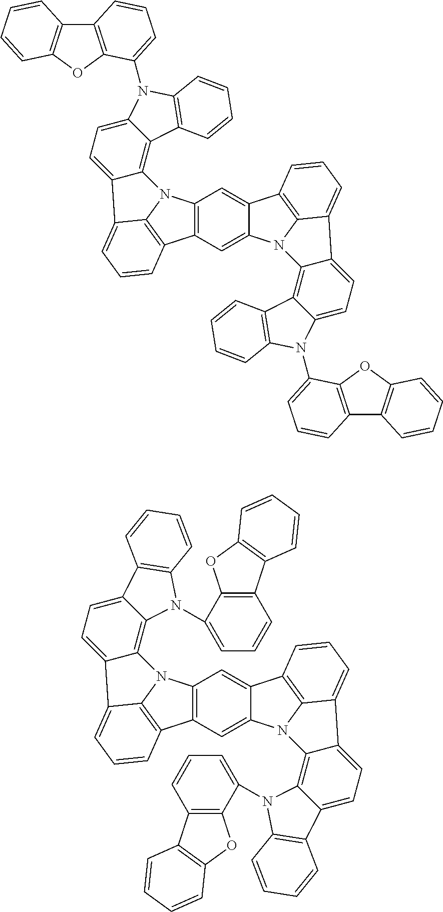 [SMILES: c1ccc2c(c1)oc1c(-n3c4ccccc4c4c3ccc3c5cccc6c7cc8c(cc7n(c65)c34)c3cccc4c5ccc6c(c7ccccc7n6-c6cccc7c6oc6ccccc67)c5n8c34)cccc12 ; c1ccc2c(c1)oc1c(-n3c4ccccc4c4ccc5c6cccc7c8cc9c(cc8n(c76)c5c43)c3cccc4c5ccc6c7ccccc7n(-c7cccc8c7oc7ccccc78)c6c5n9c34)cccc12]

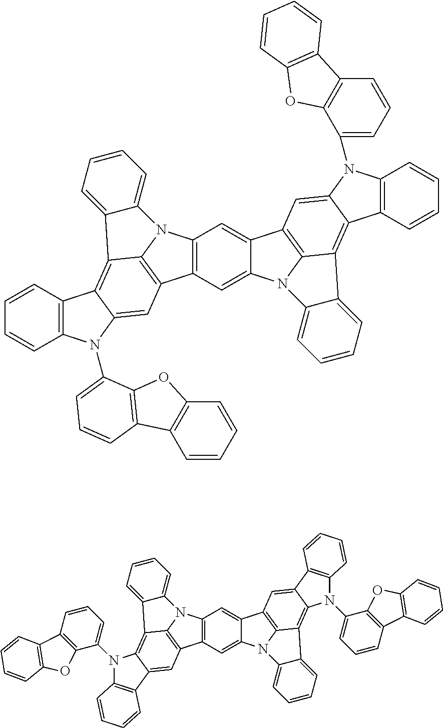 [SMILES: c1ccc2c(c1)oc1c(-n3c4ccccc4c4c5c6ccccc6n6c7cc8c9cc%10c(c%11ccccc%11n%10-c%10cccc%11c%10oc%10ccccc%10%11)c%10c%11ccccc%11n(c8cc7c(cc43)c56)c9%10)cccc12 ; c1ccc2c(c1)oc1c(-n3c4ccccc4c4cc5c6cc7c(cc6n6c8ccccc8c(c43)c56)c3cc4c5ccccc5n(-c5cccc6c5oc5ccccc56)c4c4c5ccccc5n7c34)cccc12]

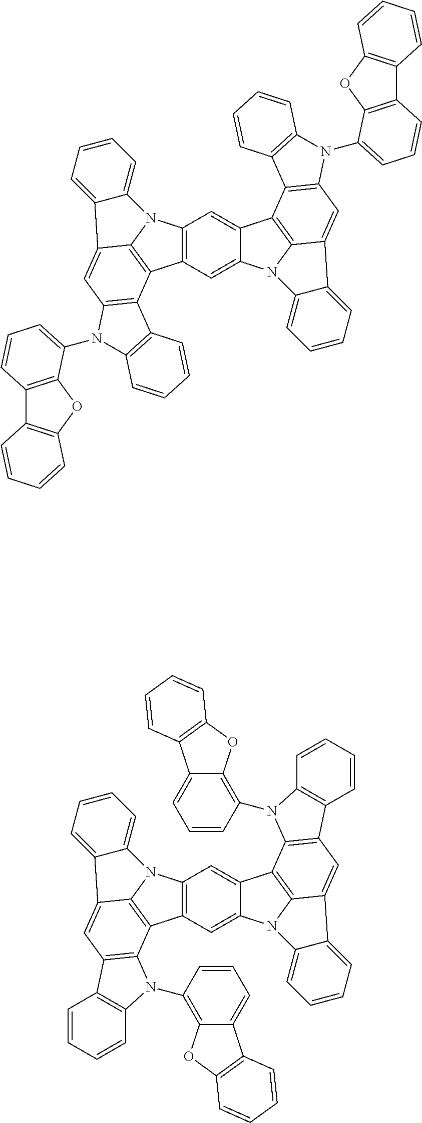 [SMILES: c1ccc2c(c1)oc1c(-n3c4ccccc4c4c5c6cc7c(cc6n6c8ccccc8c(cc43)c56)c3c4c5ccccc5n(-c5cccc6c5oc5ccccc56)c4cc4c5ccccc5n7c43)cccc12 ; c1ccc2c(c1)oc1c(-n3c4ccccc4c4cc5c6ccccc6n6c7cc8c9c%10c(cc%11c%12ccccc%12n(c8cc7c(c43)c56)c%119)c3ccccc3n%10-c3cccc4c3oc3ccccc34)cccc12]

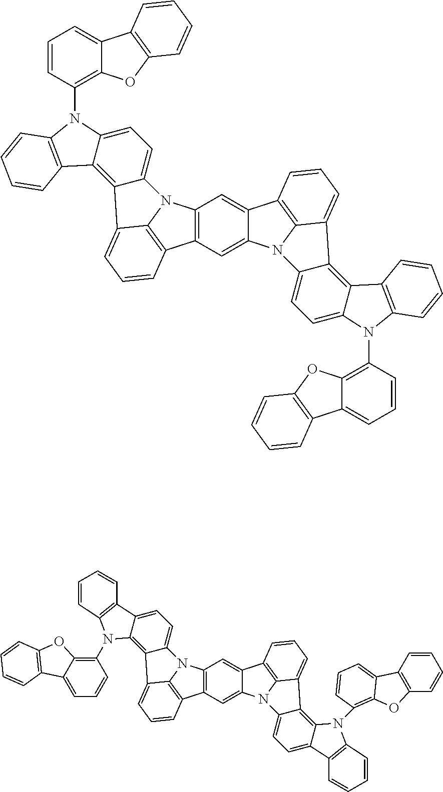 [SMILES: c1ccc2c(c1)oc1c(-n3c4ccccc4c4c5c6cccc7c8cc9c(cc8n(c5ccc43)c76)c3cccc4c5c6c7ccccc7n(-c7cccc8c7oc7ccccc78)c6ccc5n9c34)cccc12 ; c1ccc2c(c1)oc1c(-n3c4ccccc4c4ccc5c(c6cccc7c8cc9c(cc8n5c76)c5cccc6c7c8c(ccc7n9c56)c5ccccc5n8-c5cccc6c5oc5ccccc56)c43)cccc12]

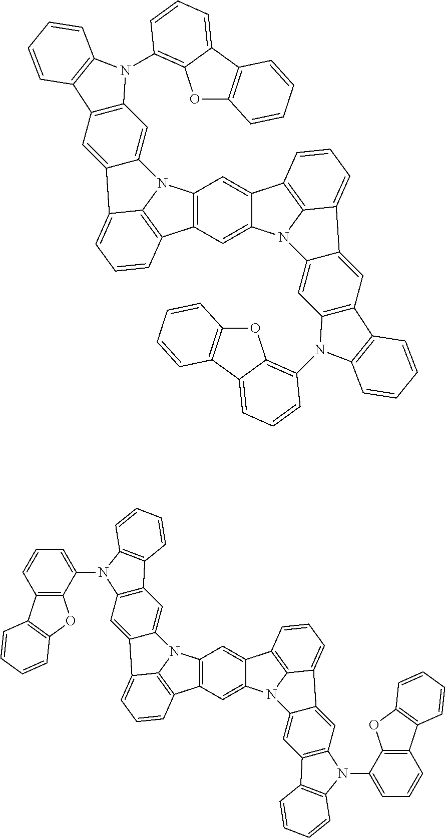 [SMILES: c1ccc2c(c1)oc1c(-n3c4ccccc4c4cc5c6cccc7c8cc9c(cc8n(c5cc43)c76)c3cccc4c5cc6c7ccccc7n(-c7cccc8c7oc7ccccc78)c6cc5n9c34)cccc12 ; c1ccc2c(c1)oc1c(-n3c4ccccc4c4cc5c(cc43)c3cccc4c6cc7c(cc6n5c34)c3cccc4c5cc6c(cc5n7c43)c3ccccc3n6-c3cccc4c3oc3ccccc34)cccc12]

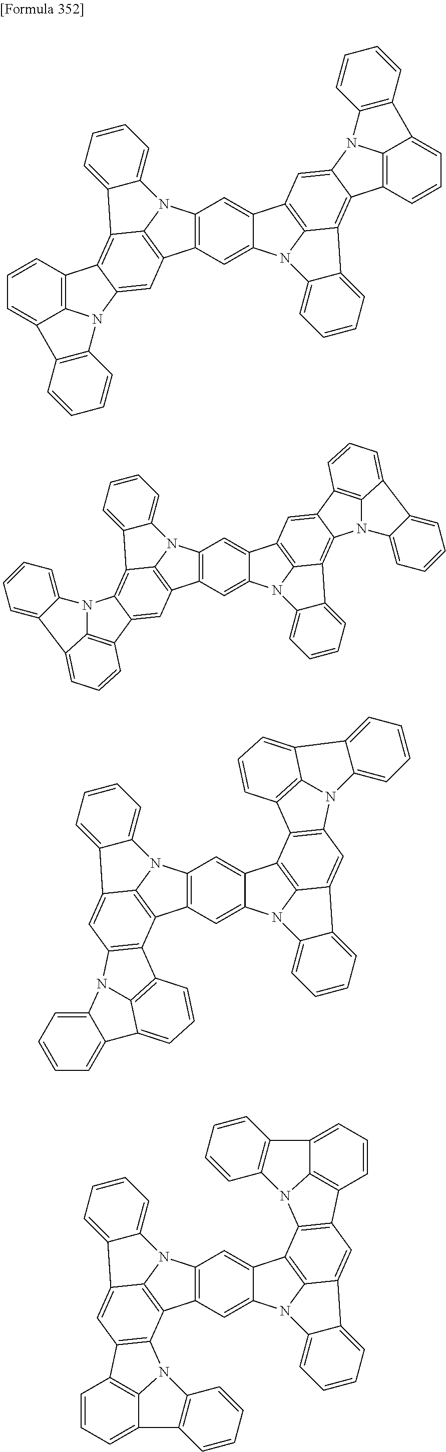 [SMILES: c1ccc2c(c1)c1cccc3c4c5c6ccccc6n6c7cc8c9cc%10c(c%11cccc%12c%13ccccc%13n%10c%12%11)c%10c%11ccccc%11n(c8cc7c(cc4n2c13)c56)c9%10 ; c1ccc2c(c1)c1c3c(cc4c5cccc6c7ccccc7n(c65)c41)c1cc4c(cc1n23)c1cc2c3cccc5c6ccccc6n(c53)c2c2c3ccccc3n4c12 ; c1ccc2c(c1)c1cccc3c4c5c6cc7c(cc6n6c8ccccc8c(cc4n2c13)c56)c1c2c3cccc4c5ccccc5n(c2cc2c5ccccc5n7c21)c43 ; c1ccc2c(c1)c1cc3c4cccc5c6ccccc6n(c54)c3c3c4cc5c(cc4n2c13)c1c2c(cc3c4cccc6c7ccccc7n(c64)c31)c1ccccc1n52]

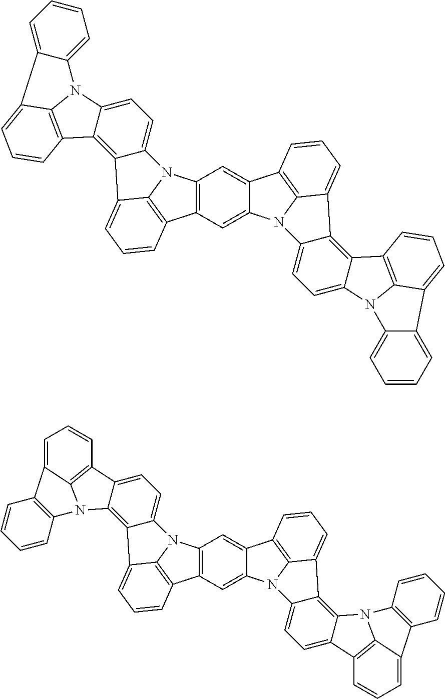 [SMILES: c1ccc2c(c1)c1cccc3c4c5c6cccc7c8cc9c(cc8n(c5ccc4n2c13)c76)c1cccc2c3c4c5cccc6c7ccccc7n(c4ccc3n9c12)c65 ; c1ccc2c(c1)c1cccc3c4ccc5c(c6cccc7c8cc9c(cc8n5c76)c5cccc6c7c(ccc8c%10cccc%11c%12ccccc%12n(c%11%10)c87)n9c56)c4n2c13]

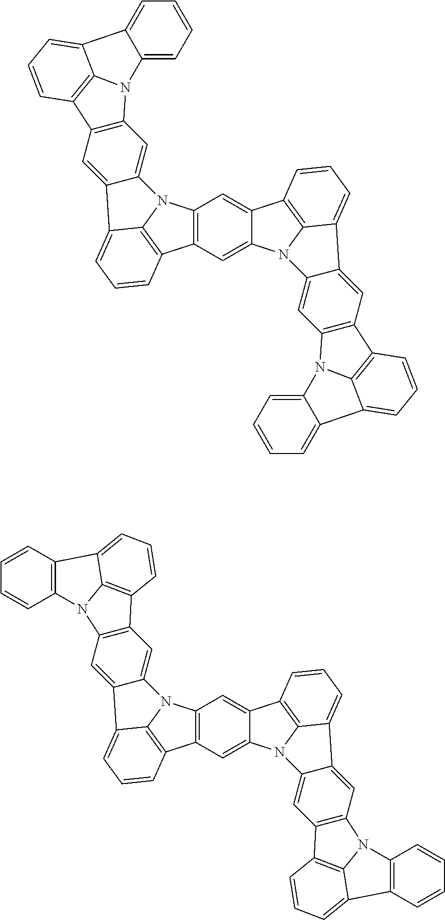 [SMILES: c1ccc2c(c1)c1cccc3c4cc5c6cccc7c8cc9c(cc8n(c5cc4n2c13)c76)c1cccc2c3cc4c5cccc6c7ccccc7n(c4cc3n9c12)c65 ; c1ccc2c(c1)c1cccc3c4cc5c(cc4n2c13)c1cccc2c3cc4c(cc3n5c12)c1cccc2c3cc5c(cc3n4c21)c1cccc2c3ccccc3n5c21]

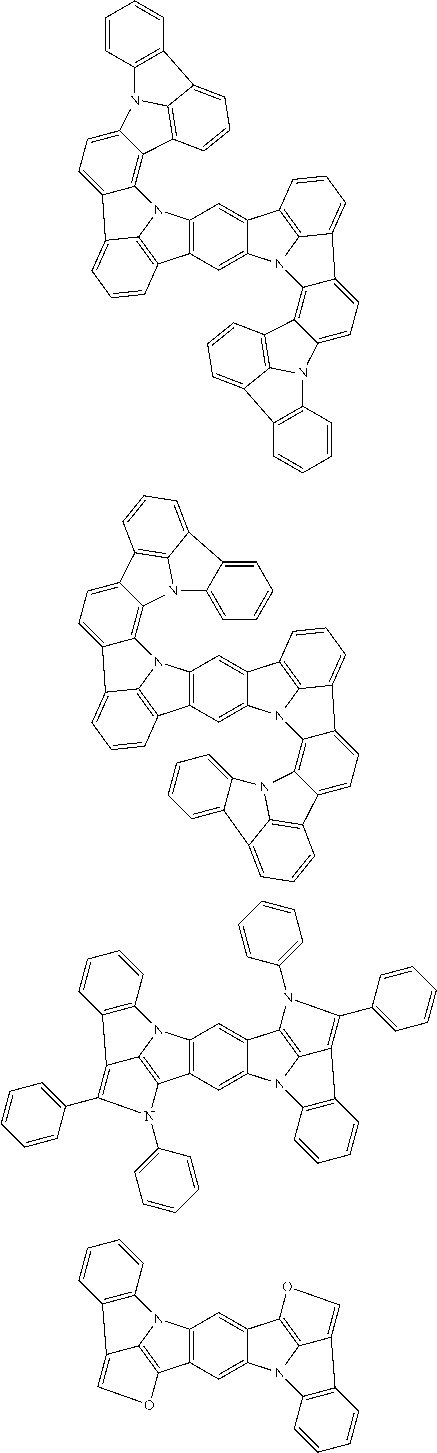

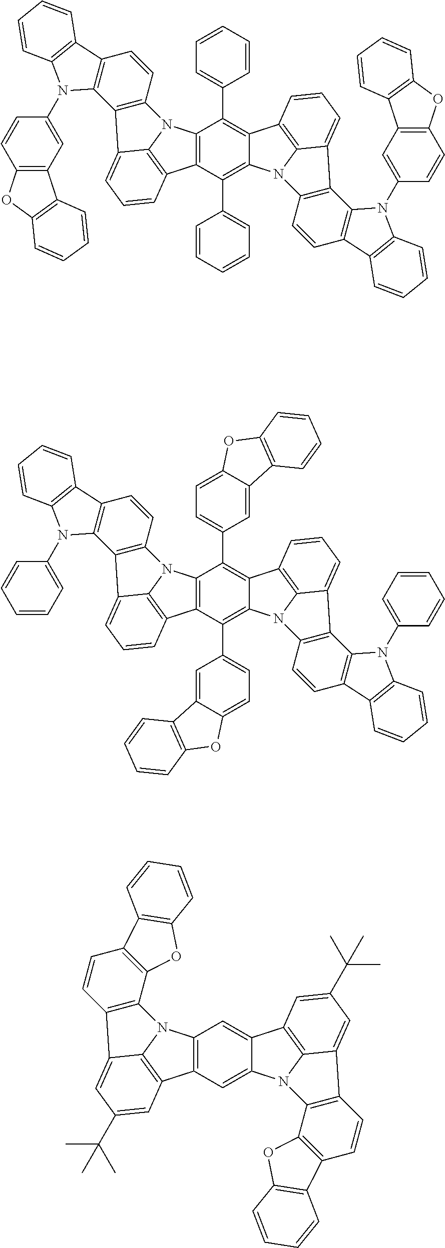 [SMILES: c1ccc(-c2c3c4cccc5c6c7c(ccc6n(c3c(-c3ccccc3)c3c6cccc8c9c%10c(ccc9n(c23)c68)c2ccccc2n%10-c2ccc3oc6ccccc6c3c2)c45)c2ccccc2n7-c2ccc3oc4ccccc4c3c2)cc1 ; c1ccc(-n2c3ccccc3c3ccc4c(c5cccc6c7c(-c8ccc9oc%10ccccc%10c9c8)c8c(c(-c9ccc%10oc%11ccccc%11c%10c9)c7n4c65)c4cccc5c6c7c(ccc6n8c45)c4ccccc4n7-c4ccccc4)c32)cc1 ; CC(C)(C)c1cc2c3cc4c(cc3n3c2c(c1)c1ccc2c5ccccc5oc2c13)c1cc(C(C)(C)C)cc2c3ccc5c6ccccc6oc5c3n4c12]

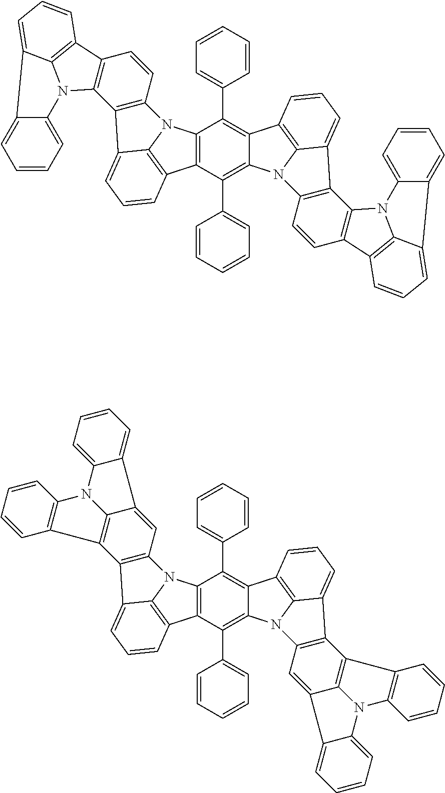 [SMILES: c1ccc(-c2c3c4cccc5c6c(ccc7c8cccc9c%10ccccc%10n(c98)c76)n(c3c(-c3ccccc3)c3c6cccc7c8c(ccc9c%10cccc%11c%12ccccc%12n(c%11%10)c98)n(c23)c67)c45)cc1 ; c1ccc(-c2c3c4cccc5c6c7c8ccccc8n8c9ccccc9c(cc6n(c3c(-c3ccccc3)c3c6cccc9c%10c%11c%12ccccc%12n%12c%13ccccc%13c(cc%10n(c23)c69)c%11%12)c45)c78)cc1]

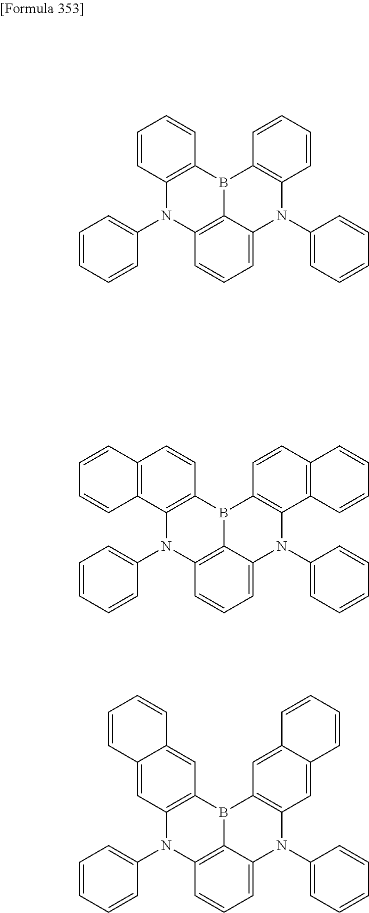 [SMILES: c1ccc(N2c3ccccc3B3c4ccccc4N(c4ccccc4)c4cccc2c43)cc1 ; c1ccc(N2c3cccc4c3B(c3ccc5ccccc5c32)c2ccc3ccccc3c2N4c2ccccc2)cc1 ; c1ccc(N2c3cc4ccccc4cc3B3c4cc5ccccc5cc4N(c4ccccc4)c4cccc2c43)cc1]

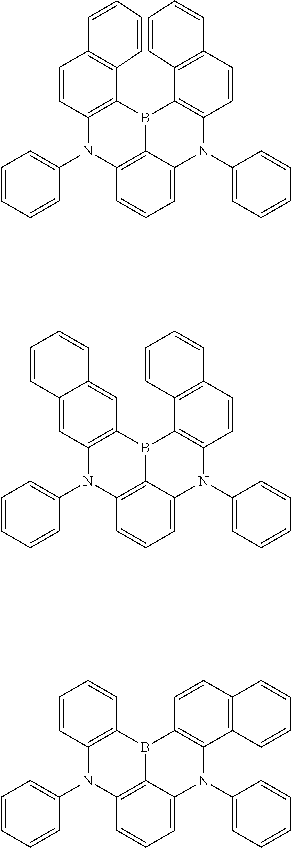 [SMILES: c1ccc(N2c3cccc4c3B(c3c2ccc2ccccc32)c2c(ccc3ccccc23)N4c2ccccc2)cc1 ; c1ccc(N2c3cc4ccccc4cc3B3c4c2cccc4N(c2ccccc2)c2ccc4ccccc4c23)cc1 ; c1ccc(N2c3ccccc3B3c4ccc5ccccc5c4N(c4ccccc4)c4cccc2c43)cc1]

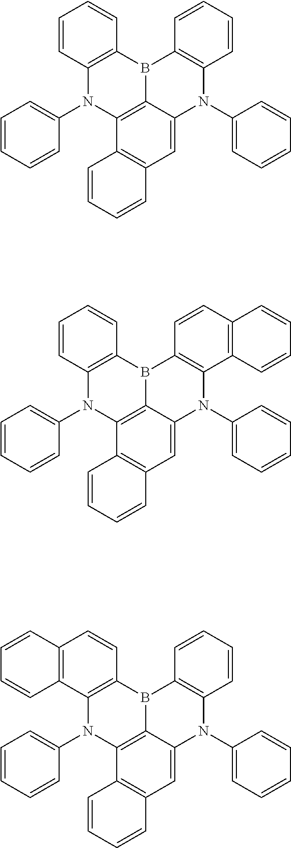 [SMILES: c1ccc(N2c3ccccc3B3c4ccccc4N(c4ccccc4)c4c3c2cc2ccccc42)cc1 ; c1ccc(N2c3cc4ccccc4c4c3B(c3ccccc3N4c3ccccc3)c3ccc4ccccc4c32)cc1 ; c1ccc(N2c3ccccc3B3c4ccc5ccccc5c4N(c4ccccc4)c4c3c2cc2ccccc42)cc1]

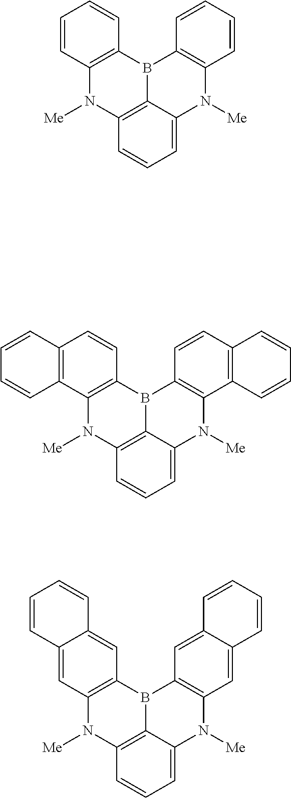 [SMILES: CN1c2ccccc2B2c3ccccc3N(C)c3cccc1c32 ; CN1c2cccc3c2B(c2ccc4ccccc4c21)c1ccc2ccccc2c1N3C ; CN1c2cc3ccccc3cc2B2c3cc4ccccc4cc3N(C)c3cccc1c32]

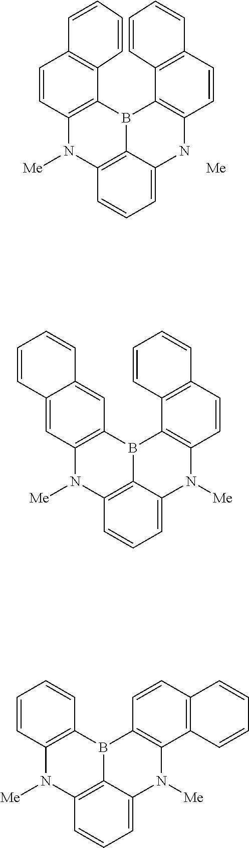 [SMILES: CN1c2cccc3c2B(c2c(ccc4ccccc24)N3)c2c1ccc1ccccc21 ; CN1c2cc3ccccc3cc2B2c3c1cccc3N(C)c1ccc3ccccc3c12 ; "Me" ; CN1c2ccccc2B2c3ccc4ccccc4c3N(C)c3cccc1c32]

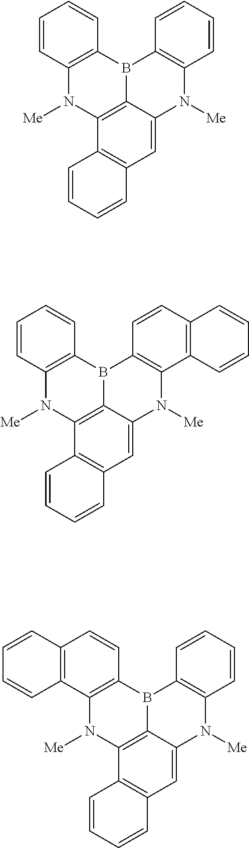 [SMILES: CN1c2ccccc2B2c3ccccc3N(C)c3c2c1cc1ccccc31 ; CN1c2cc3ccccc3c3c2B(c2ccccc2N3C)c2ccc3ccccc3c21 ; CN1c2ccccc2B2c3ccc4ccccc4c3N(C)c3c2c1cc1ccccc31]

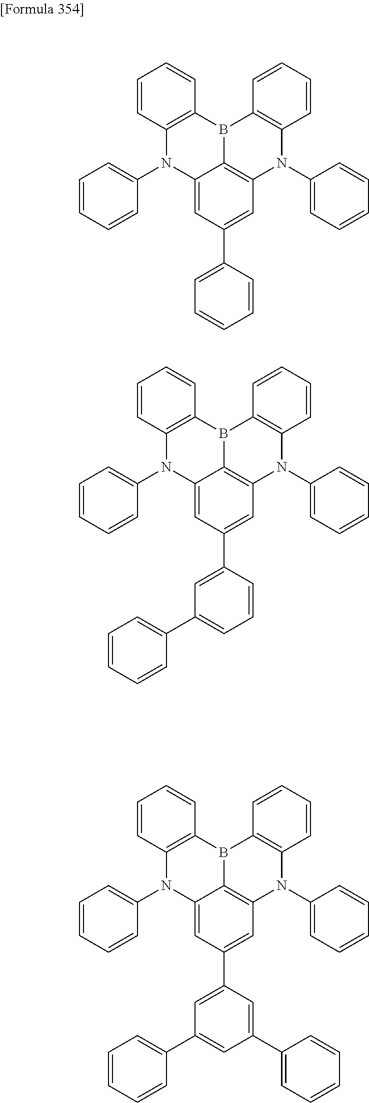 [SMILES: c1ccc(-c2cc3c4c(c2)N(c2ccccc2)c2ccccc2B4c2ccccc2N3c2ccccc2)cc1 ; c1ccc(-c2cccc(-c3cc4c5c(c3)N(c3ccccc3)c3ccccc3B5c3ccccc3N4c3ccccc3)c2)cc1 ; c1ccc(-c2cc(-c3ccccc3)cc(-c3cc4c5c(c3)N(c3ccccc3)c3ccccc3B5c3ccccc3N4c3ccccc3)c2)cc1]

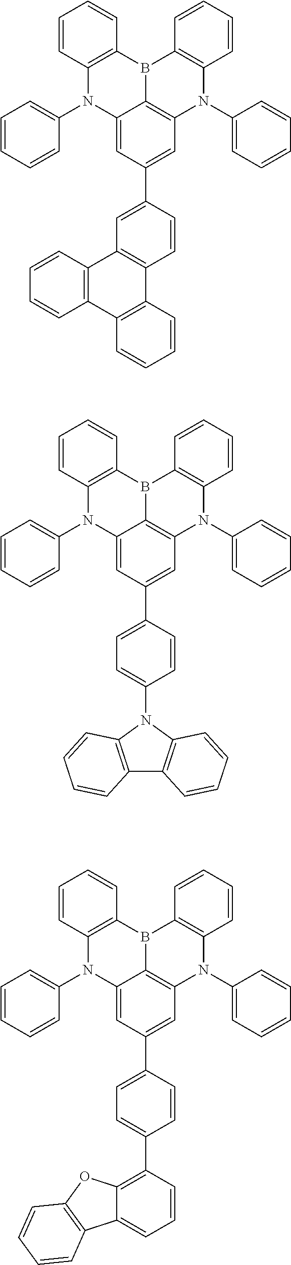 [SMILES: c1ccc(N2c3ccccc3B3c4ccccc4N(c4ccccc4)c4cc(-c5ccc6c7ccccc7c7ccccc7c6c5)cc2c43)cc1 ; c1ccc(N2c3ccccc3B3c4ccccc4N(c4ccccc4)c4cc(-c5ccc(-n6c7ccccc7c7ccccc76)cc5)cc2c43)cc1 ; c1ccc(N2c3ccccc3B3c4ccccc4N(c4ccccc4)c4cc(-c5ccc(-c6cccc7c6oc6ccccc67)cc5)cc2c43)cc1]

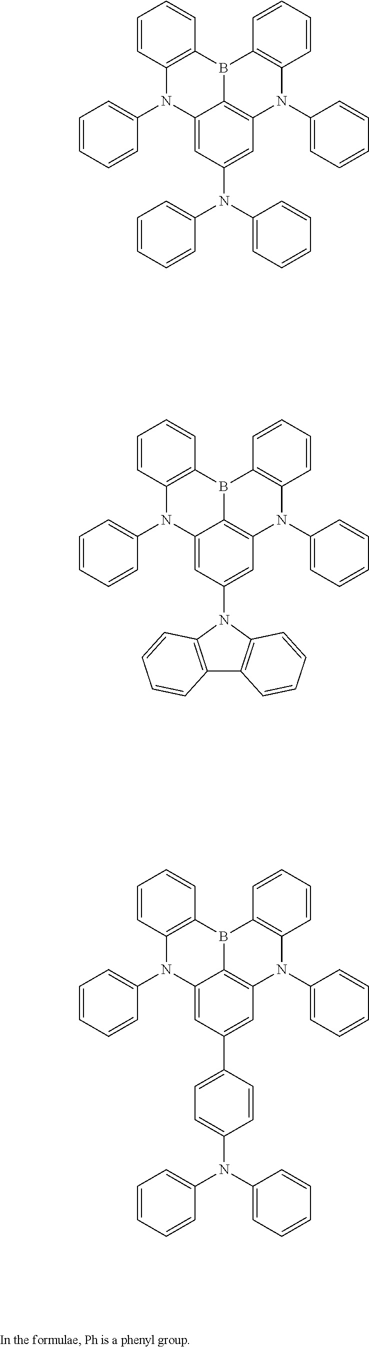 [SMILES: c1ccc(N(c2ccccc2)c2cc3c4c(c2)N(c2ccccc2)c2ccccc2B4c2ccccc2N3c2ccccc2)cc1 ; c1ccc(N2c3ccccc3B3c4ccccc4N(c4ccccc4)c4cc(-n5c6ccccc6c6ccccc65)cc2c43)cc1 ; c1ccc(N(c2ccccc2)c2ccc(-c3cc4c5c(c3)N(c3ccccc3)c3ccccc3B5c3ccccc3N4c3ccccc3)cc2)cc1]

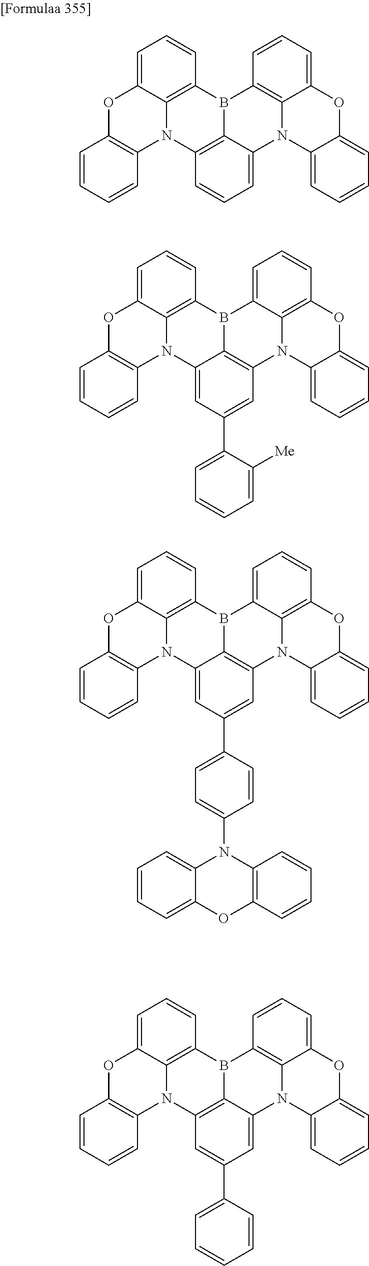

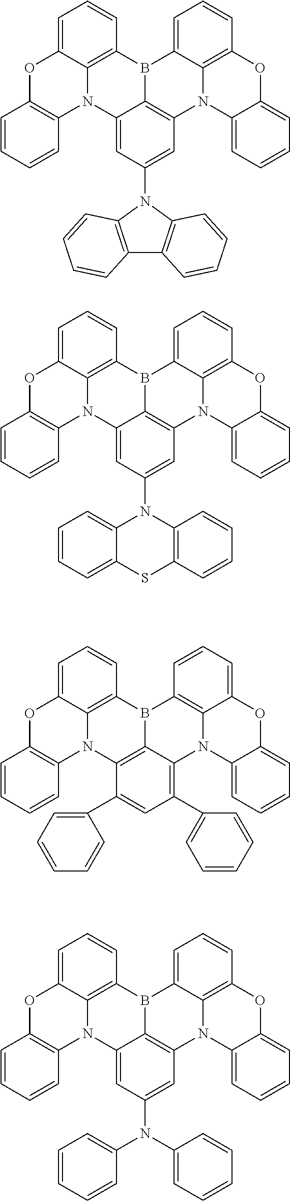

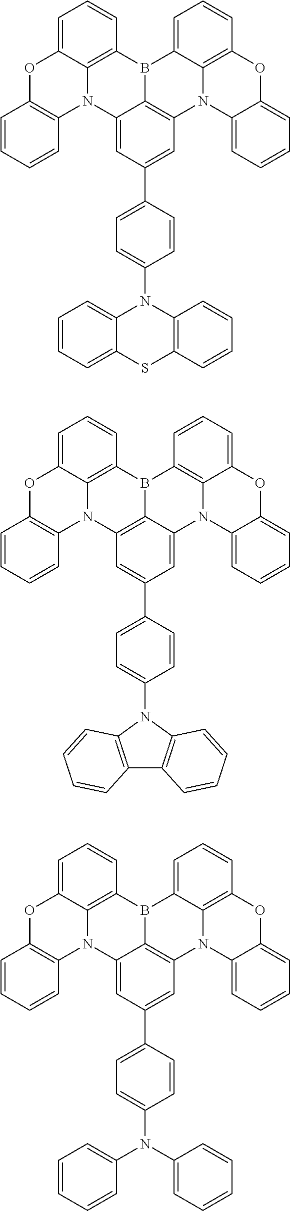

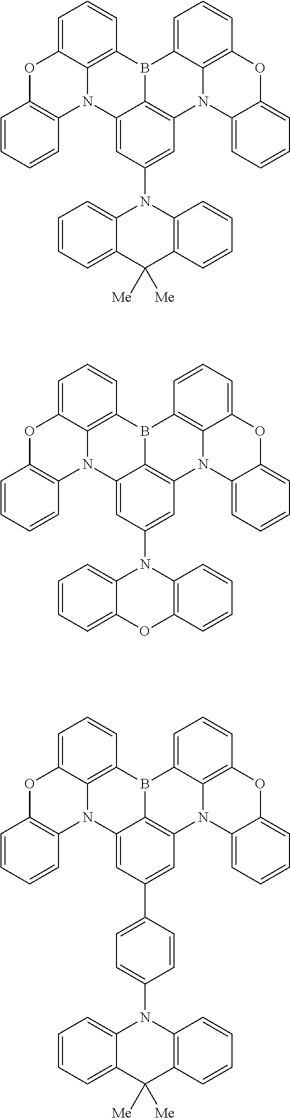

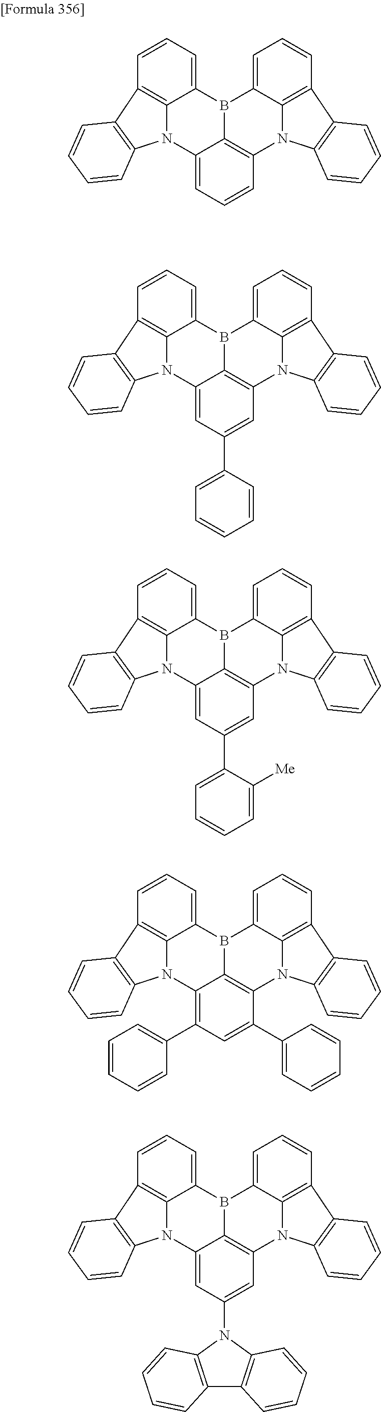 [SMILES: c1cc2c3c(c1)-n1c4ccccc4c4cccc(c41)B3c1cccc3c4ccccc4n-2c13 ; c1ccc(-c2cc3c4c(c2)-n2c5ccccc5c5cccc(c52)B4c2cccc4c5ccccc5n-3c24)cc1 ; Cc1ccccc1-c1cc2c3c(c1)-n1c4ccccc4c4cccc(c41)B3c1cccc3c4ccccc4n-2c13 ; c1ccc(-c2cc(-c3ccccc3)c3c4c2-n2c5ccccc5c5cccc(c52)B4c2cccc4c5ccccc5n-3c24)cc1 ; c1ccc2c(c1)c1ccccc1n2-c1cc2c3c(c1)-n1c4ccccc4c4cccc(c41)B3c1cccc3c4ccccc4n-2c13]

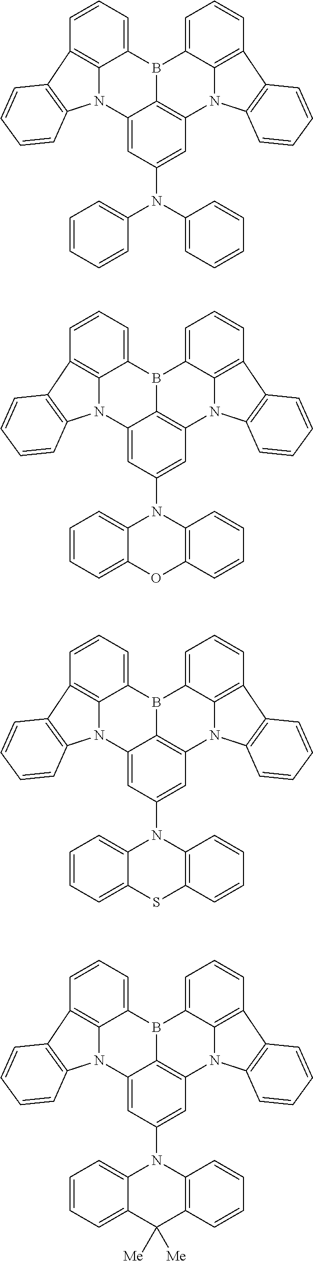

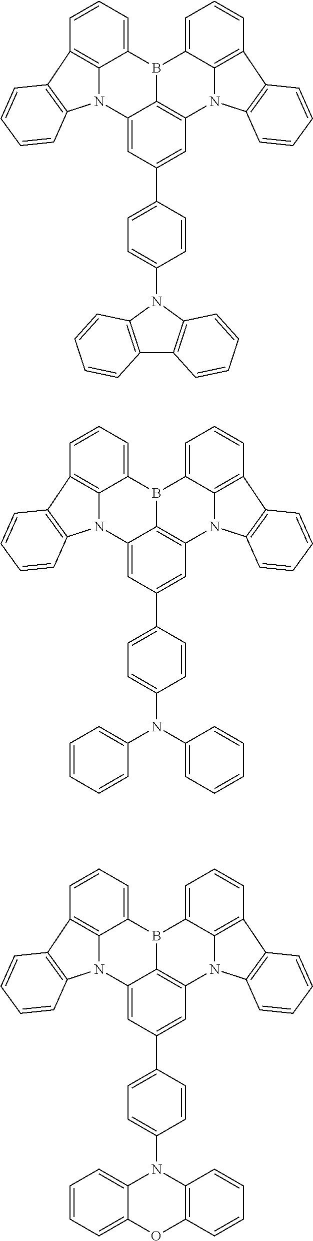 [SMILES: c1ccc2c(c1)c1ccccc1n2-c1ccc(-c2cc3c4c(c2)-n2c5ccccc5c5cccc(c52)B4c2cccc4c5ccccc5n-3c24)cc1 ; c1ccc(N(c2ccccc2)c2ccc(-c3cc4c5c(c3)-n3c6ccccc6c6cccc(c63)B5c3cccc5c6ccccc6n-4c35)cc2)cc1 ; c1ccc2c(c1)Oc1ccccc1N2c1ccc(-c2cc3c4c(c2)-n2c5ccccc5c5cccc(c52)B4c2cccc4c5ccccc5n-3c24)cc1]

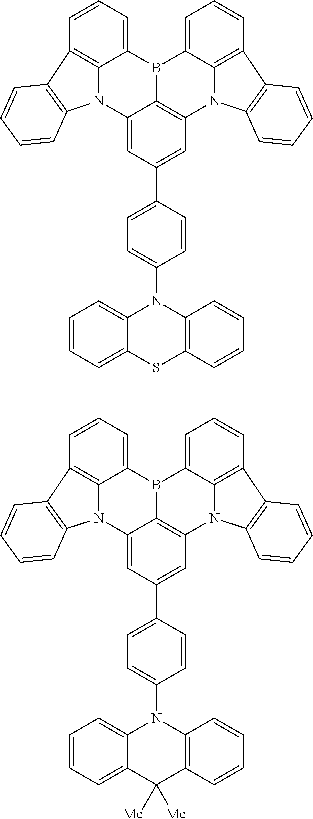 [SMILES: c1ccc2c(c1)Sc1ccccc1N2c1ccc(-c2cc3c4c(c2)-n2c5ccccc5c5cccc(c52)B4c2cccc4c5ccccc5n-3c24)cc1 ; CC1(C)c2ccccc2N(c2ccc(-c3cc4c5c(c3)-n3c6ccccc6c6cccc(c63)B5c3cccc5c6ccccc6n-4c35)cc2)c2ccccc21]

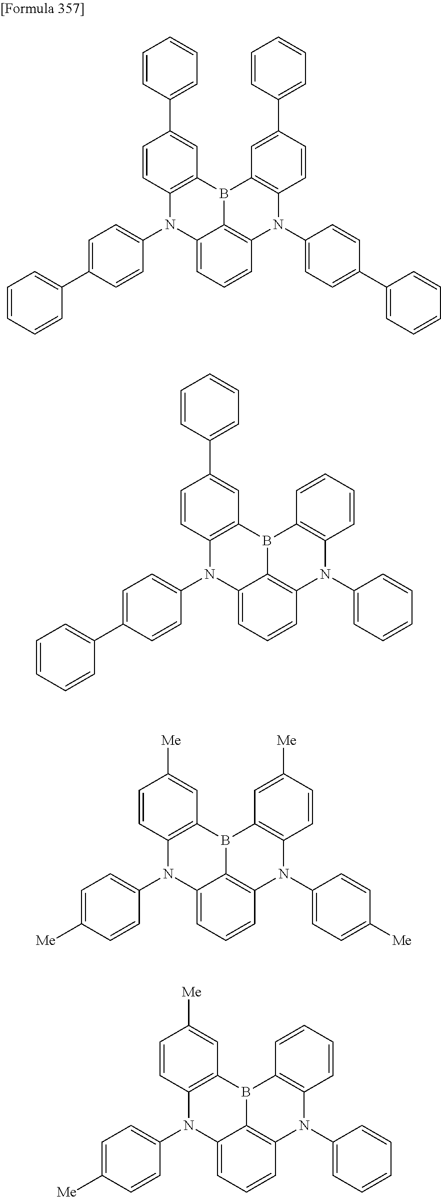 [SMILES: c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5ccccc5N(c5ccccc5)c5cccc3c54)cc2)cc1 ; Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1]

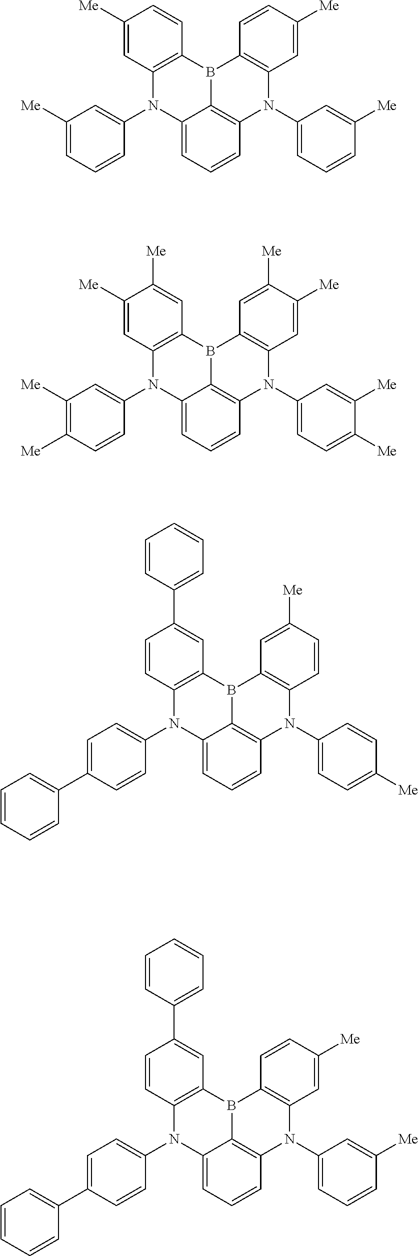 [SMILES: Cc1cccc(N2c3cc(C)ccc3B3c4ccc(C)cc4N(c4cccc(C)c4)c4cccc2c43)c1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1 ; Cc1cccc(N2c3cc(C)ccc3B3c4cc(-c5ccccc5)ccc4N(c4ccc(-c5ccccc5)cc4)c4cccc2c43)c1]

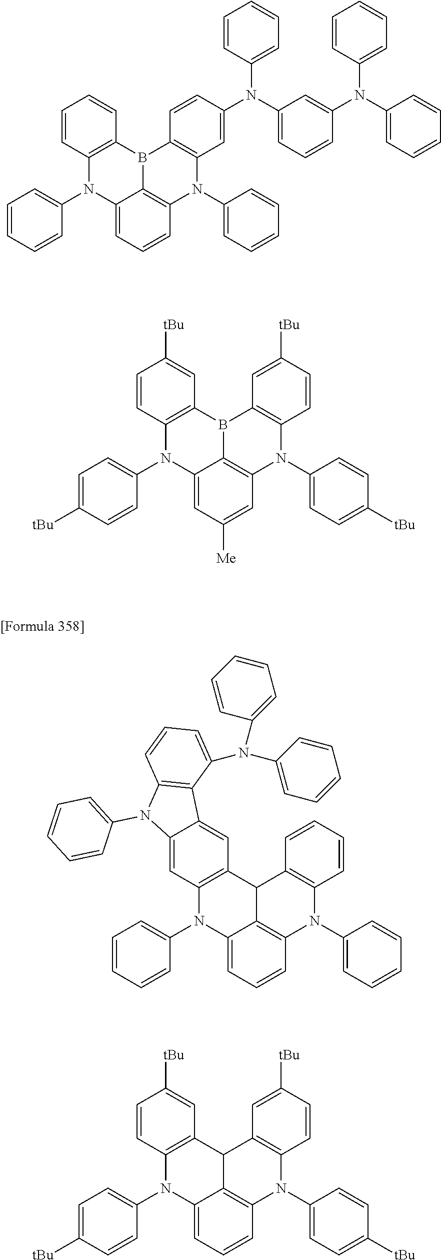 [SMILES: c1ccc(N(c2ccccc2)c2cccc(N(c3ccccc3)c3ccc4c(c3)N(c3ccccc3)c3cccc5c3B4c3ccccc3N5c3ccccc3)c2)cc1 ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(N2c3ccccc3C3c4cc5c6c(N(c7ccccc7)c7ccccc7)cccc6n(-c6ccccc6)c5cc4N(c4ccccc4)c4cccc2c43)cc1 ; CC(C)(C)c1ccc(N2c3ccc(C(C)(C)C)cc3C3c4cc(C(C)(C)C)ccc4N(c4ccc(C(C)(C)C)cc4)c4cccc2c43)cc1]

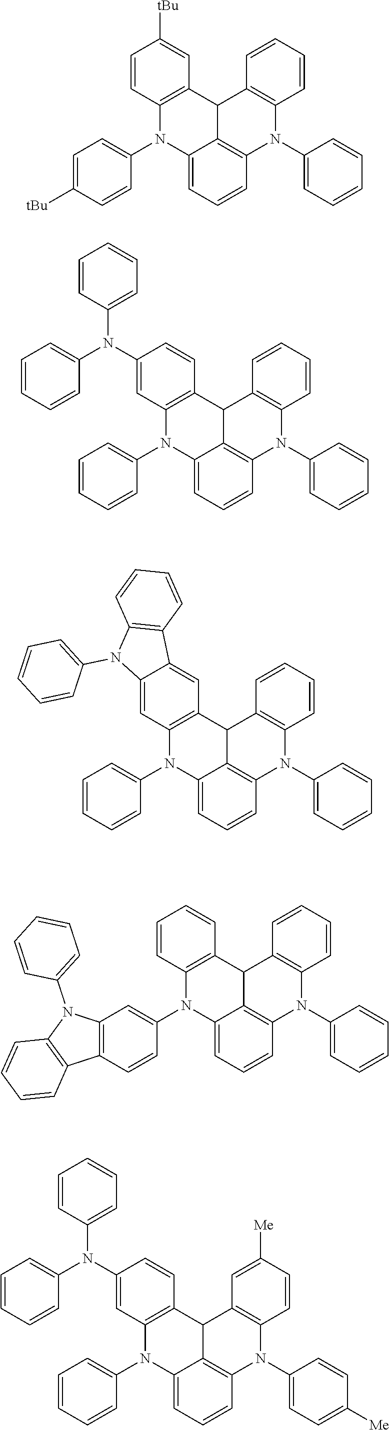

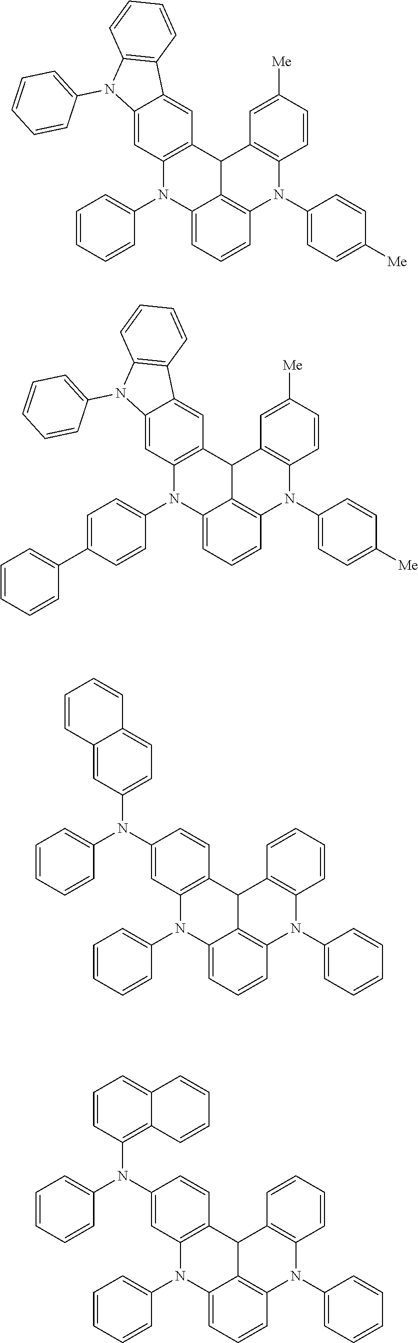 [SMILES: Cc1ccc(N2c3ccc(C)cc3C3c4cc5c6ccccc6n(-c6ccccc6)c5cc4N(c4ccccc4)c4cccc2c43)cc1 ; Cc1ccc(N2c3ccc(C)cc3C3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2C3c2ccccc2N4c2ccccc2)c2ccc3ccccc3c2)cc1 ; c1ccc(N2c3ccccc3C3c4ccc(N(c5ccccc5)c5cccc6ccccc56)cc4N(c4ccccc4)c4cccc2c43)cc1]

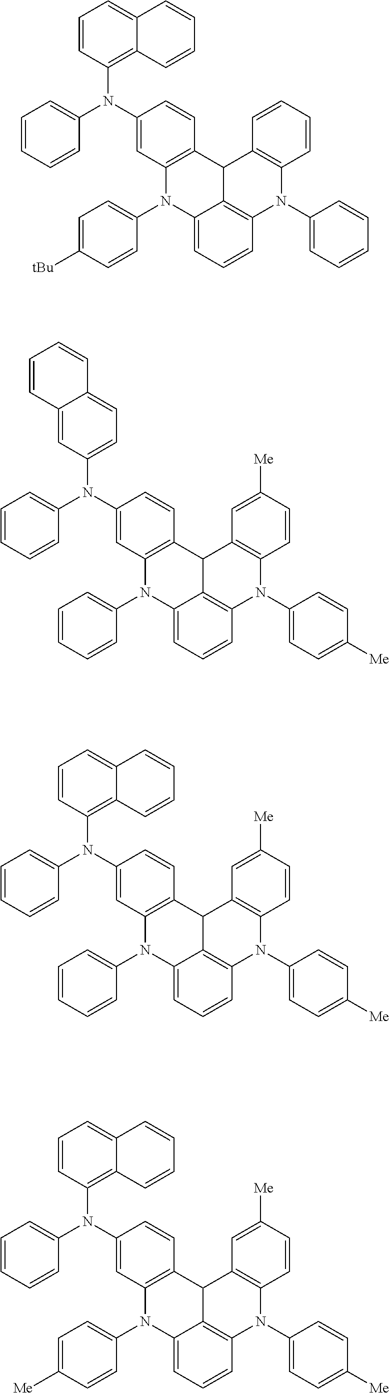 [SMILES: CC(C)(C)c1ccc(N2c3cc(N(c4ccccc4)c4cccc5ccccc45)ccc3C3c4ccccc4N(c4ccccc4)c4cccc2c43)cc1 ; Cc1ccc(N2c3ccc(C)cc3C3c4ccc(N(c5ccccc5)c5ccc6ccccc6c5)cc4N(c4ccccc4)c4cccc2c43)cc1 ; Cc1ccc(N2c3ccc(C)cc3C3c4ccc(N(c5ccccc5)c5cccc6ccccc56)cc4N(c4ccccc4)c4cccc2c43)cc1 ; Cc1ccc(N2c3ccc(C)cc3C3c4ccc(N(c5ccccc5)c5cccc6ccccc56)cc4N(c4ccc(C)cc4)c4cccc2c43)cc1]

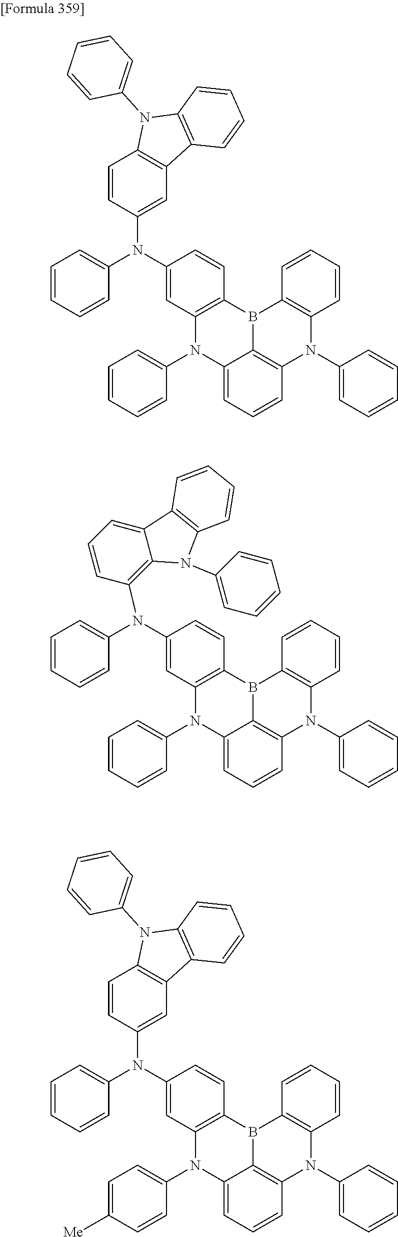 [SMILES: c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

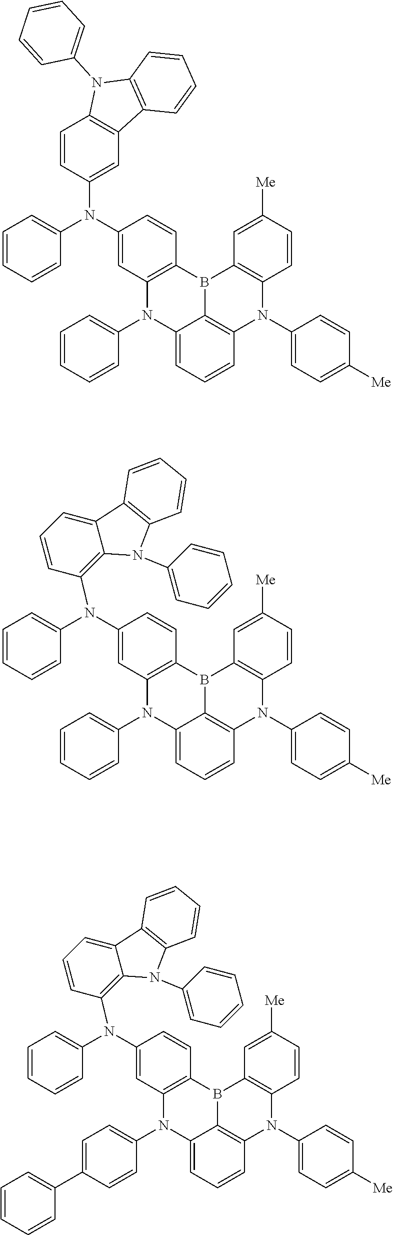 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1]

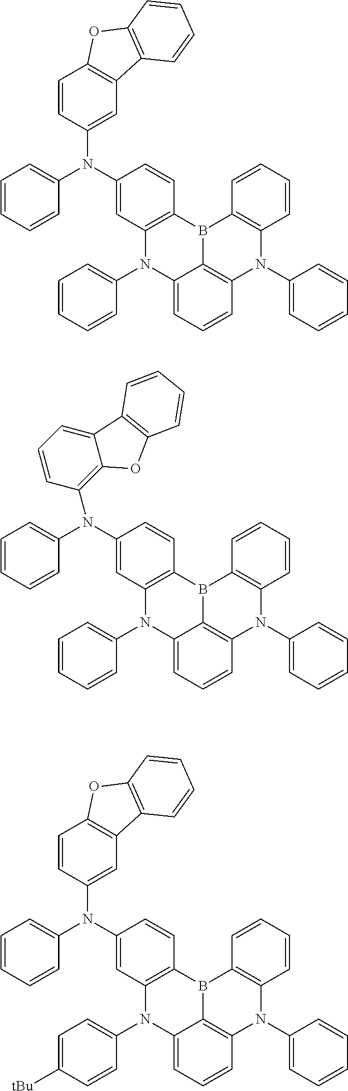 [SMILES: c1ccc(N(c2ccc3c(c2)N(c2ccccc2)c2cccc4c2B3c2ccccc2N4c2ccccc2)c2ccc3oc4ccccc4c3c2)cc1 ; c1ccc(N2c3ccccc3B3c4ccc(N(c5ccccc5)c5cccc6c5oc5ccccc56)cc4N(c4ccccc4)c4cccc2c43)cc1 ; CC(C)(C)c1ccc(N2c3cc(N(c4ccccc4)c4ccc5oc6ccccc6c5c4)ccc3B3c4ccccc4N(c4ccccc4)c4cccc2c43)cc1]

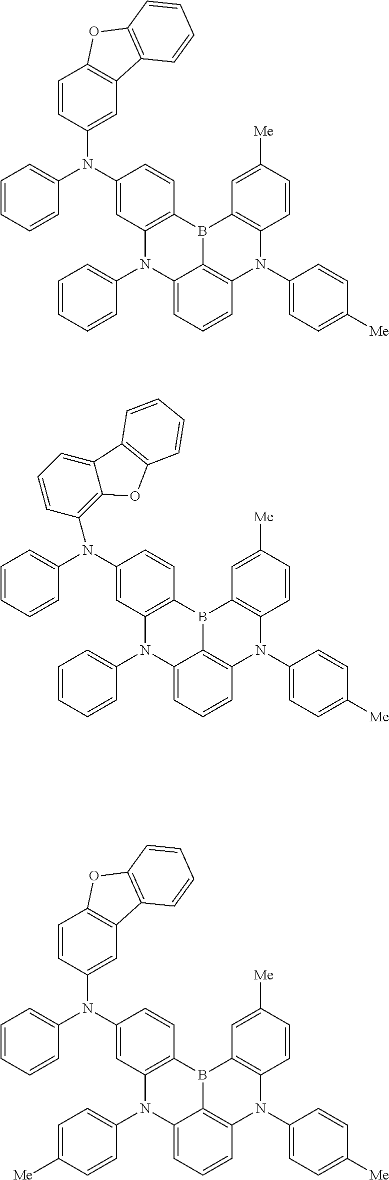 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

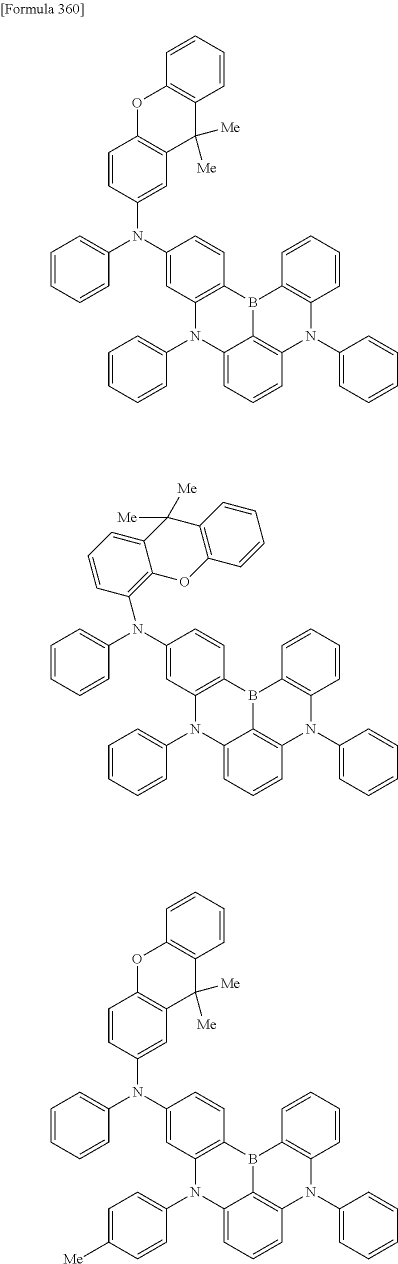 [SMILES: CC1(C)c2ccccc2Oc2ccc(N(c3ccccc3)c3ccc4c(c3)N(c3ccccc3)c3cccc5c3B4c3ccccc3N5c3ccccc3)cc21 ; CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3cc(N(c4ccccc4)c4ccc5c(c4)C(C)(C)c4ccccc4O5)ccc3B3c4ccccc4N(c4ccccc4)c4cccc2c43)cc1]

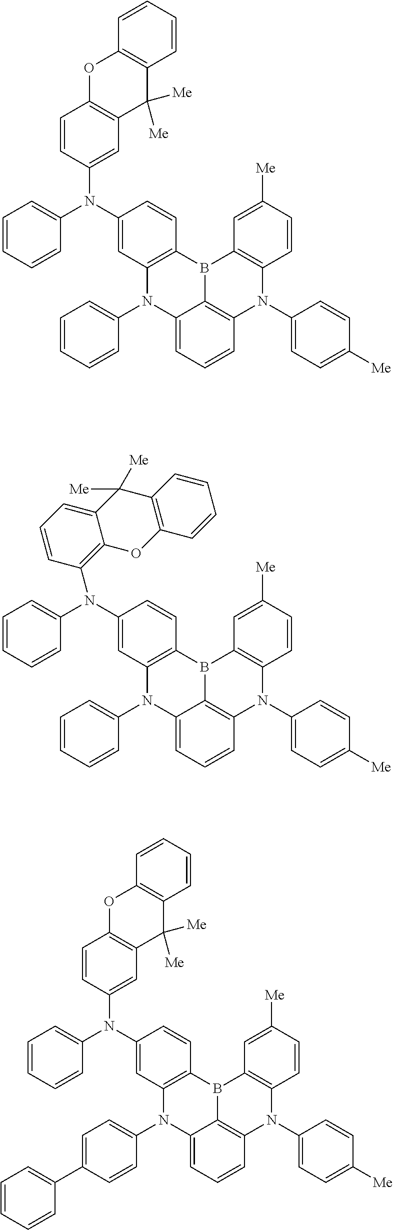 [SMILES: Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1]

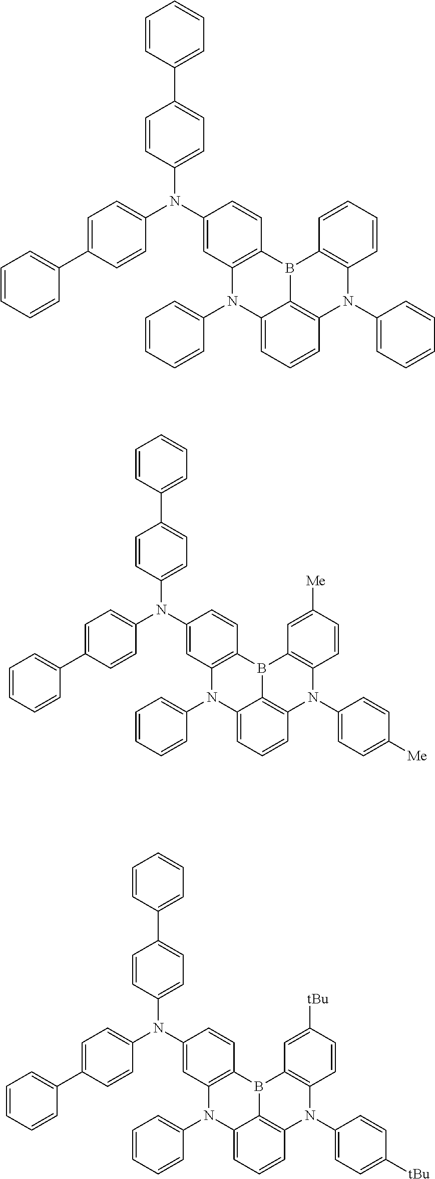 [SMILES: c1ccc(-c2ccc(N(c3ccc(-c4ccccc4)cc3)c3ccc4c(c3)N(c3ccccc3)c3cccc5c3B4c3ccccc3N5c3ccccc3)cc2)cc1 ; Cc1ccc(N2c3ccc(C)cc3B3c4ccc(N(c5ccc(-c6ccccc6)cc5)c5ccc(-c6ccccc6)cc5)cc4N(c4ccccc4)c4cccc2c43)cc1 ; CC(C)(C)c1ccc(N2c3ccc(C(C)(C)C)cc3B3c4ccc(N(c5ccc(-c6ccccc6)cc5)c5ccc(-c6ccccc6)cc5)cc4N(c4ccccc4)c4cccc2c43)cc1]

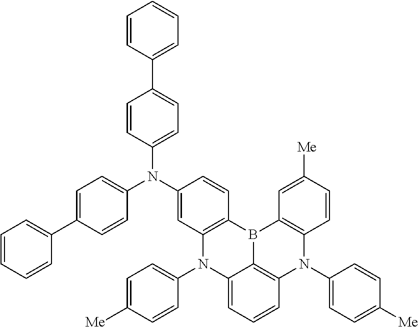 [SMILES: Cc1ccc(N2c3ccc(C)cc3B3c4ccc(N(c5ccc(-c6ccccc6)cc5)c5ccc(-c6ccccc6)cc5)cc4N(c4ccc(C)cc4)c4cccc2c43)cc1]

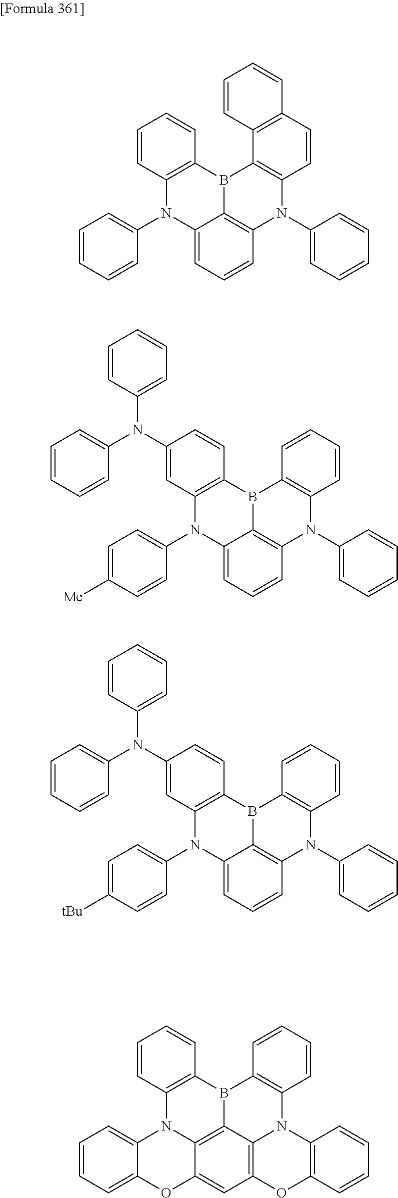 [SMILES: c1ccc(N2c3ccccc3B3c4c2cccc4N(c2ccccc2)c2ccc4ccccc4c23)cc1 ; Cc1ccc(N2c3cc(N(c4ccccc4)c4ccccc4)ccc3B3c4ccccc4N(c4ccccc4)c4cccc2c43)cc1 ; CC(C)(C)c1ccc(N2c3cc(N(c4ccccc4)c4ccccc4)ccc3B3c4ccccc4N(c4ccccc4)c4cccc2c43)cc1 ; c1ccc2c(c1)B1c3ccccc3-n3c4ccccc4oc4cc5oc6ccccc6n-2c5c1c43]

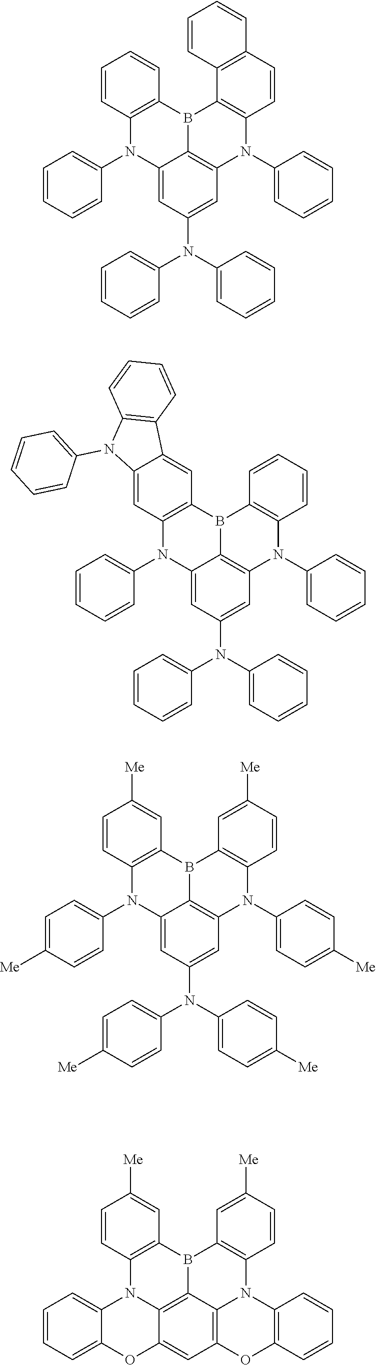

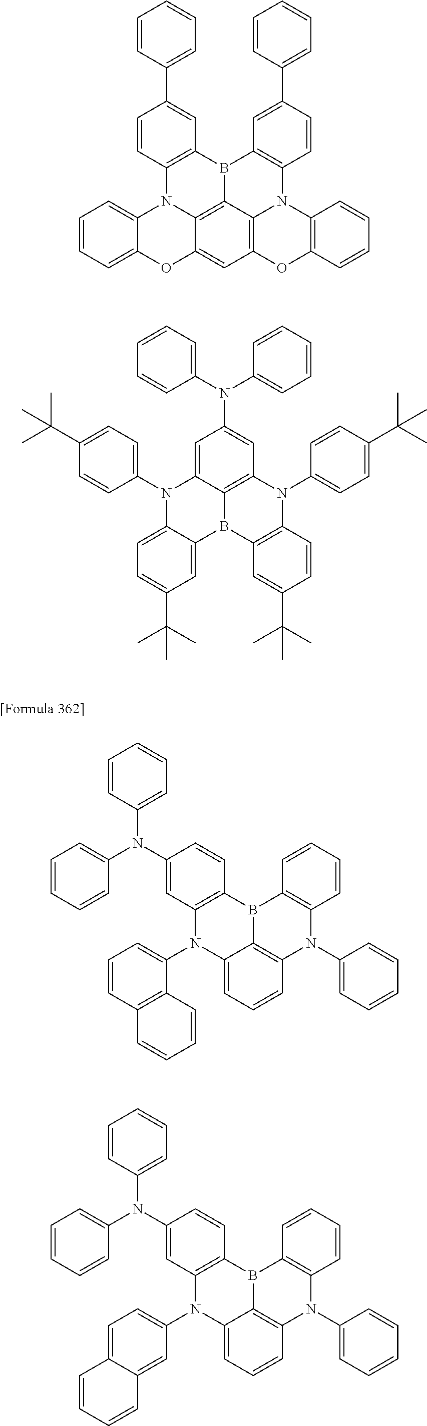 [SMILES: c1ccc(-c2ccc3c(c2)B2c4cc(-c5ccccc5)ccc4-n4c5ccccc5oc5cc6oc7ccccc7n-3c6c2c54)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1 ; c1ccc(N(c2ccccc2)c2ccc3c(c2)N(c2cccc4ccccc24)c2cccc4c2B3c2ccccc2N4c2ccccc2)cc1 ; c1ccc(N(c2ccccc2)c2ccc3c(c2)N(c2ccc4ccccc4c2)c2cccc4c2B3c2ccccc2N4c2ccccc2)cc1]

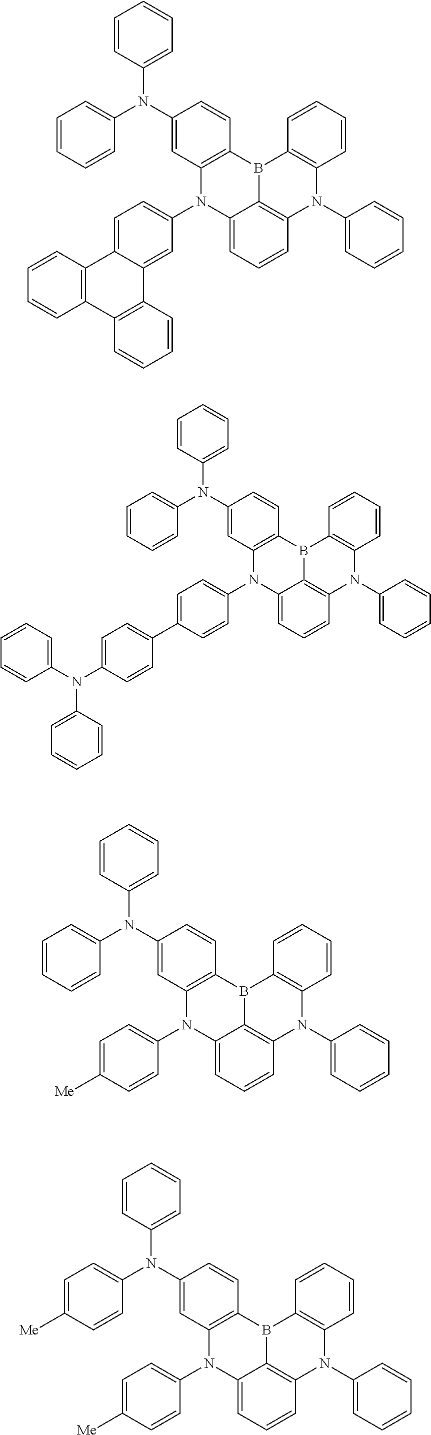 [SMILES: c1ccc(N(c2ccccc2)c2ccc3c(c2)N(c2ccc4c5ccccc5c5ccccc5c4c2)c2cccc4c2B3c2ccccc2N4c2ccccc2)cc1 ; c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1 ; Cc1ccc(N2c3cc(N(c4ccccc4)c4ccccc4)ccc3B3c4ccccc4N(c4ccccc4)c4cccc2c43)cc1 ; Cc1ccc(N(c2ccccc2)c2ccc3c(c2)N(c2ccc(C)cc2)c2cccc4c2B3c2ccccc2N4c2ccccc2)cc1]

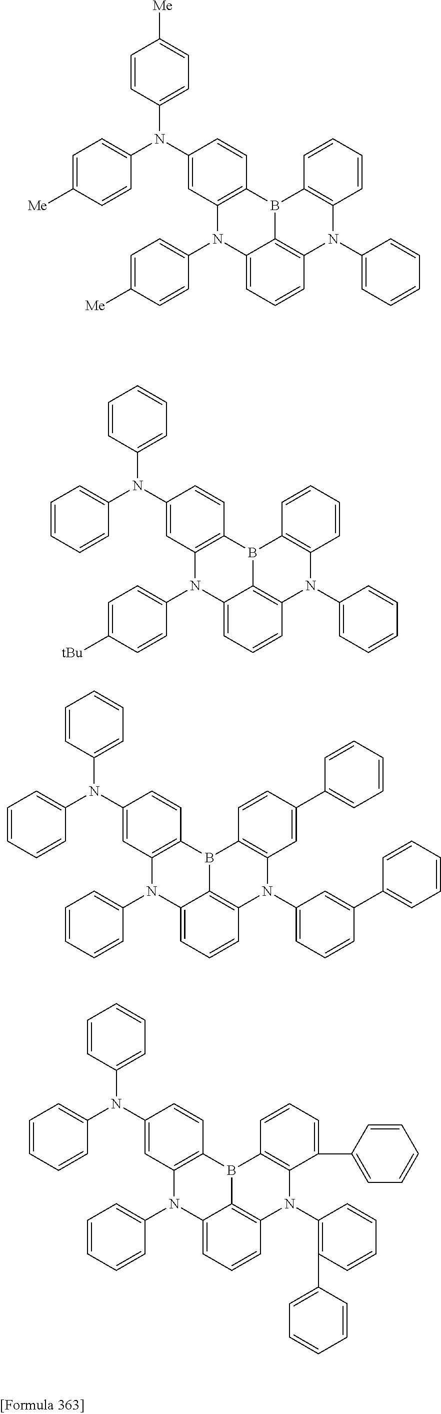

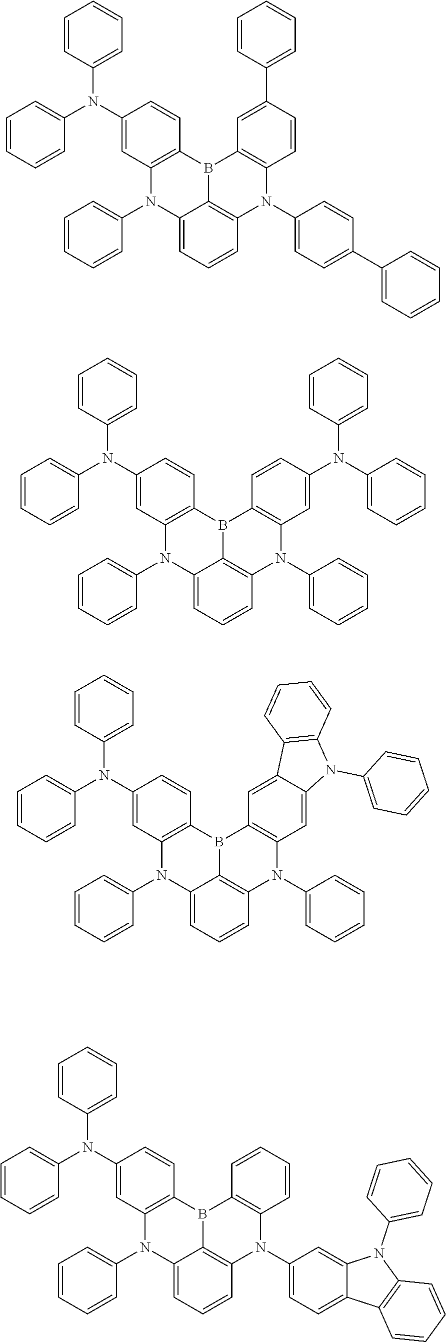 [SMILES: c1ccc(-c2ccc(N3c4ccc(-c5ccccc5)cc4B4c5ccc(N(c6ccccc6)c6ccccc6)cc5N(c5ccccc5)c5cccc3c54)cc2)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; c1ccc(N(c2ccccc2)c2ccc3c(c2)N(c2ccccc2)c2cccc4c2B3c2cc3c5ccccc5n(-c5ccccc5)c3cc2N4c2ccccc2)cc1 ; c1ccc(N(c2ccccc2)c2ccc3c(c2)N(c2ccccc2)c2cccc4c2B3c2ccccc2N4c2ccc3c4ccccc4n(-c4ccccc4)c3c2)cc1]

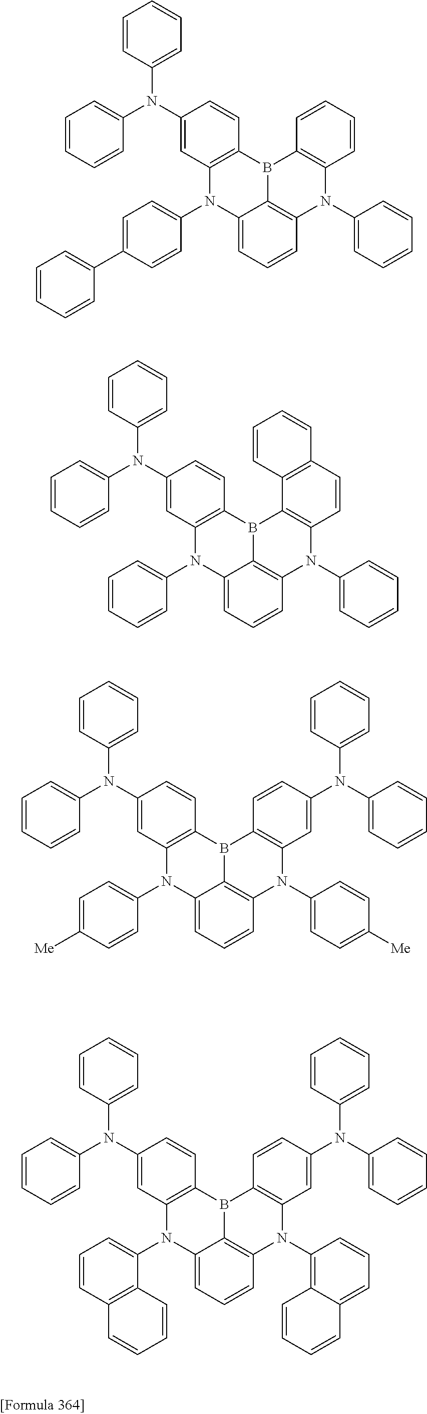 [SMILES: c1ccc(-c2ccc(N3c4cc(N(c5ccccc5)c5ccccc5)ccc4B4c5ccccc5N(c5ccccc5)c5cccc3c54)cc2)cc1 ; c1ccc(N(c2ccccc2)c2ccc3c(c2)N(c2ccccc2)c2cccc4c2B3c2c(ccc3ccccc23)N4c2ccccc2)cc1 ; Cc1ccc(N2c3cc(N(c4ccccc4)c4ccccc4)ccc3B3c4ccc(N(c5ccccc5)c5ccccc5)cc4N(c4ccc(C)cc4)c4cccc2c43)cc1 ; c1ccc(N(c2ccccc2)c2ccc3c(c2)N(c2cccc4ccccc24)c2cccc4c2B3c2ccc(N(c3ccccc3)c3ccccc3)cc2N4c2cccc3ccccc23)cc1]

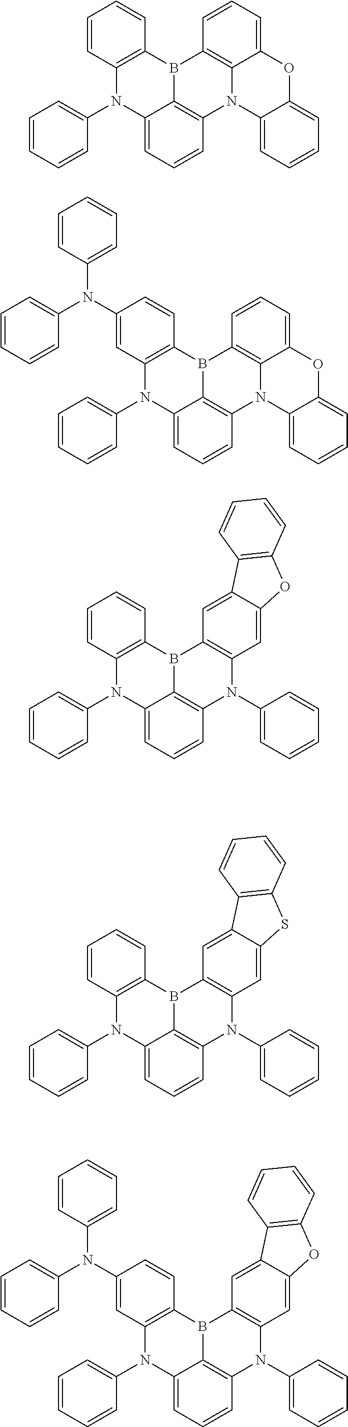

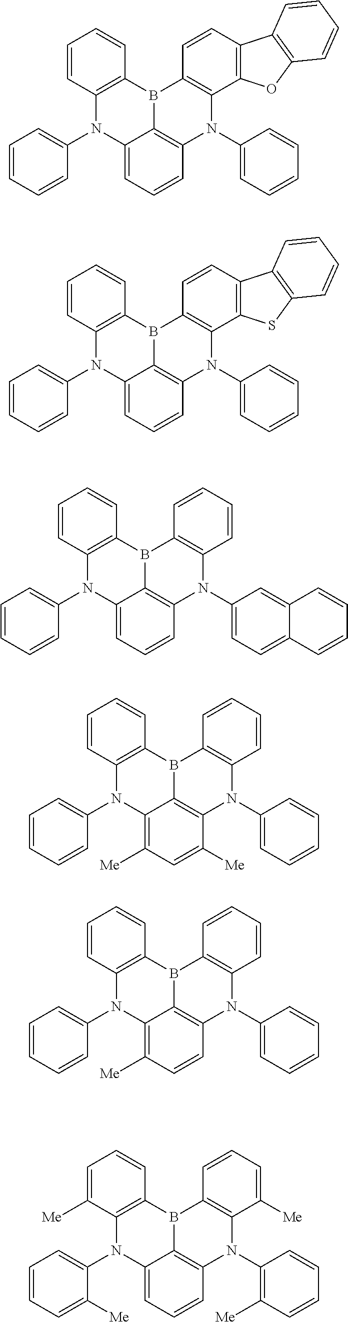

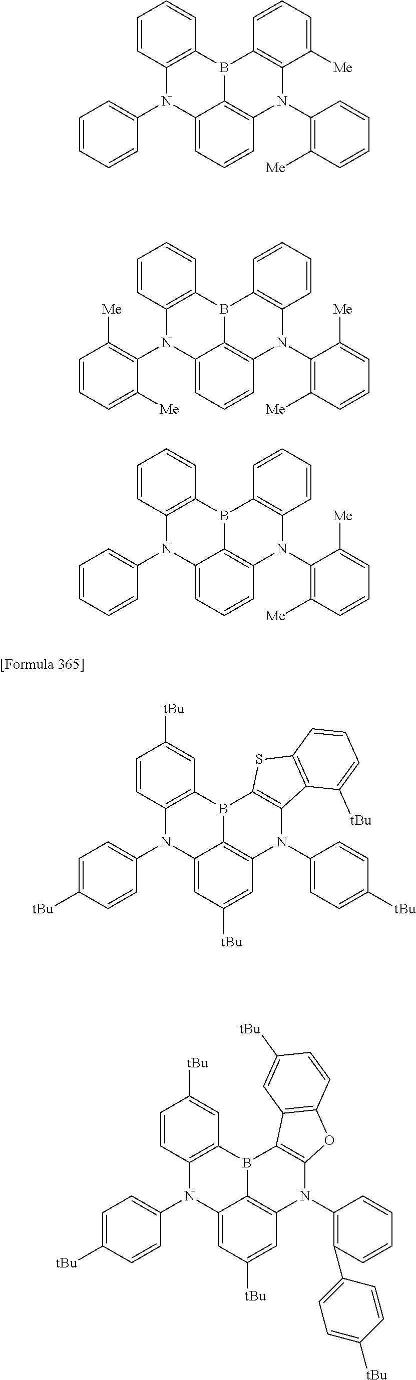

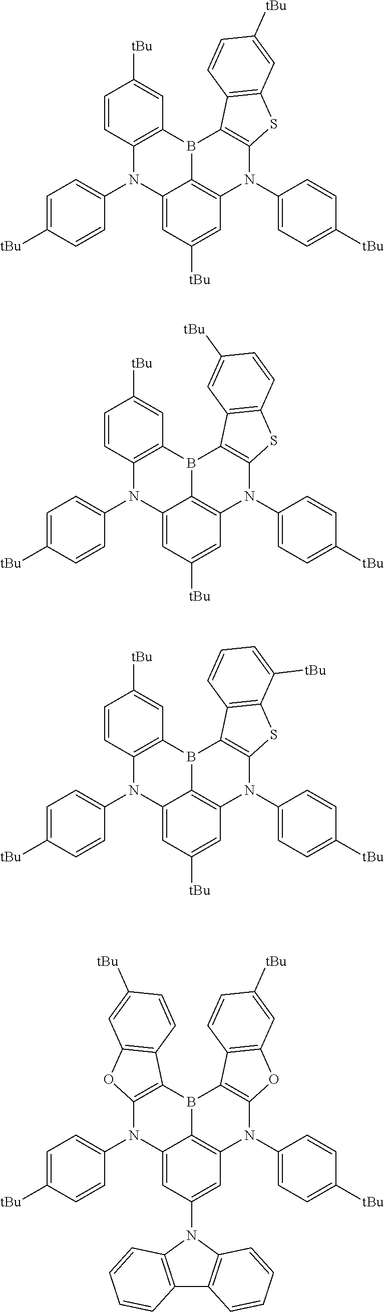 [SMILES: CC(C)(C)c1ccc(N2c3ccc(C(C)(C)C)cc3B3c4c2cc(C(C)(C)C)cc4N(c2ccc(C(C)(C)C)cc2)c2sc4cc(C(C)(C)C)ccc4c23)cc1 ; CC(C)(C)c1ccc(N2c3ccc(C(C)(C)C)cc3B3c4c2cc(C(C)(C)C)cc4N(c2ccc(C(C)(C)C)cc2)c2sc4ccc(C(C)(C)C)cc4c23)cc1 ; CC(C)(C)c1ccc(N2c3ccc(C(C)(C)C)cc3B3c4c2cc(C(C)(C)C)cc4N(c2ccc(C(C)(C)C)cc2)c2sc4c(C(C)(C)C)cccc4c23)cc1 ; CC(C)(C)c1ccc(N2c3cc(-n4c5ccccc5c5ccccc54)cc4c3B(c3c2oc2cc(C(C)(C)C)ccc32)c2c(oc3cc(C(C)(C)C)ccc23)N4c2ccc(C(C)(C)C)cc2)cc1]

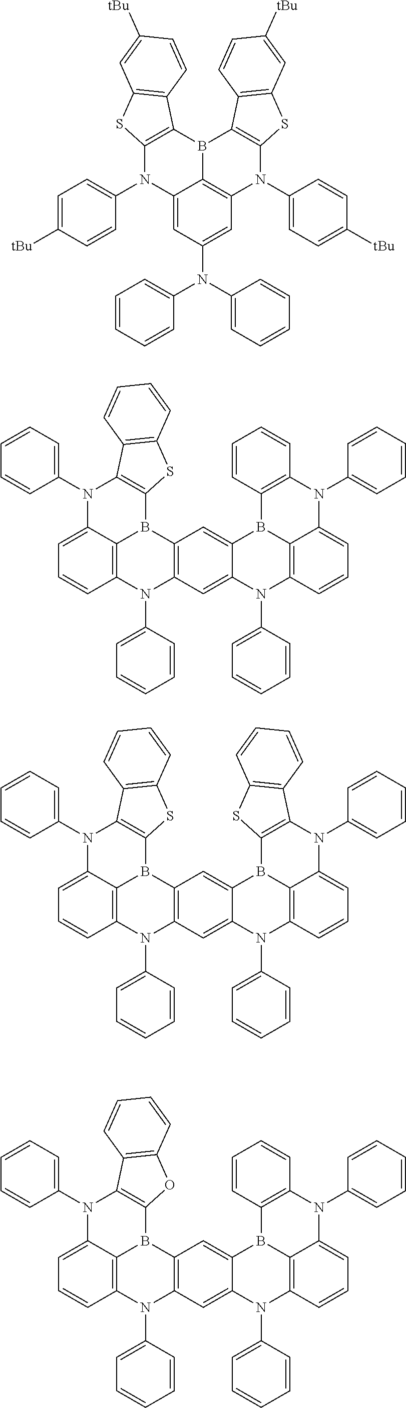

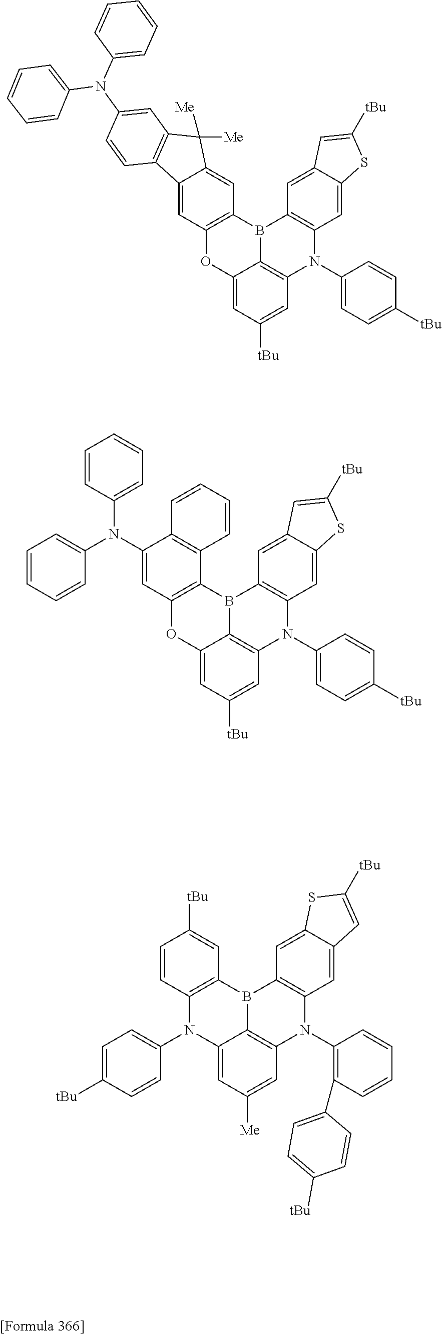 [SMILES: CC(C)(C)c1ccc(N2c3cc4sc(C(C)(C)C)cc4cc3B3c4cc5c(cc4Oc4cc(C(C)(C)C)cc2c43)-c2ccc(N(c3ccccc3)c3ccccc3)cc2C5(C)C)cc1 ; CC(C)(C)c1ccc(N2c3cc4sc(C(C)(C)C)cc4cc3B3c4c(cc(C(C)(C)C)cc42)Oc2cc(N(c4ccccc4)c4ccccc4)c4ccccc4c23)cc1 ; Cc1cc2c3c(c1)N(c1ccccc1-c1ccc(C(C)(C)C)cc1)c1cc4cc(C(C)(C)C)sc4cc1B3c1cc(C(C)(C)C)ccc1N2c1ccc(C(C)(C)C)cc1]

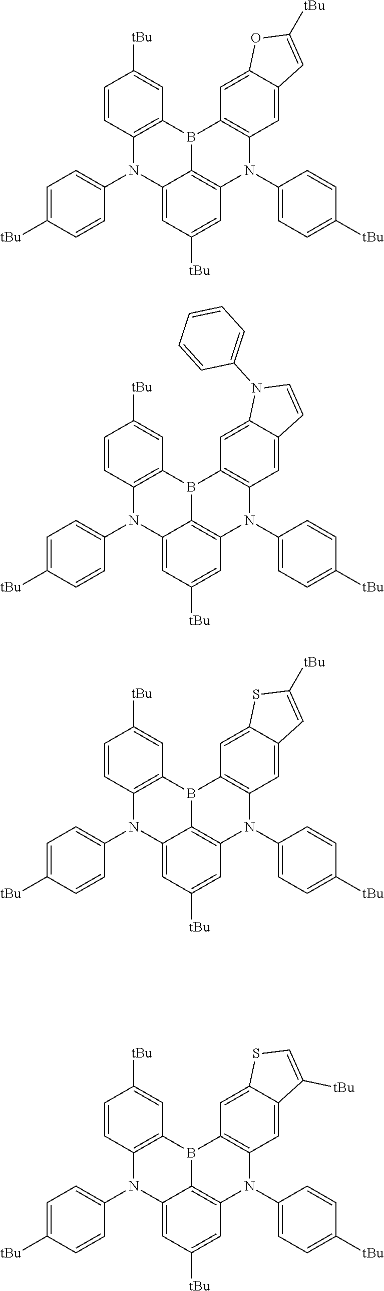

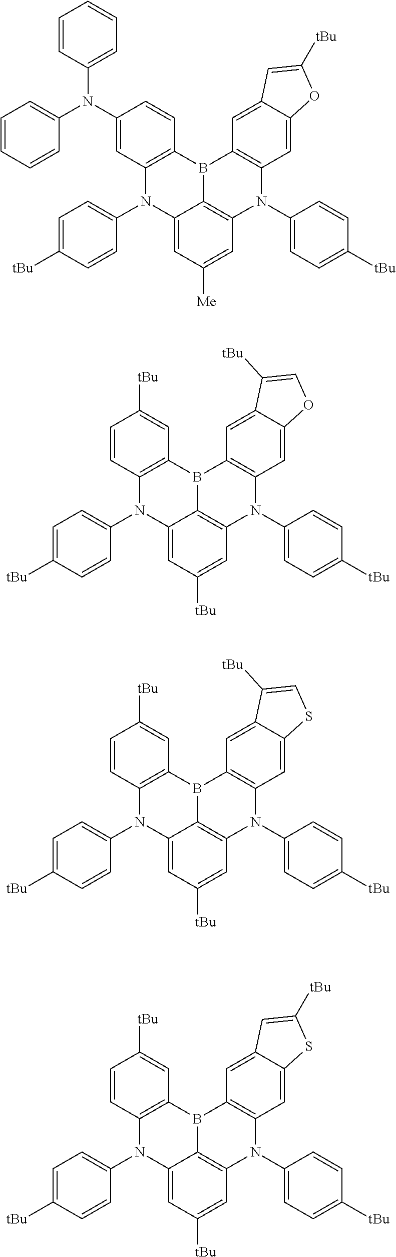 [SMILES: Cc1cc2c3c(c1)N(c1ccc(C(C)(C)C)cc1)c1cc4oc(C(C)(C)C)cc4cc1B3c1ccc(N(c3ccccc3)c3ccccc3)cc1N2c1ccc(C(C)(C)C)cc1 ; CC(C)(C)c1ccc(N2c3ccc(C(C)(C)C)cc3B3c4cc5c(C(C)(C)C)coc5cc4N(c4ccc(C(C)(C)C)cc4)c4cc(C(C)(C)C)cc2c43)cc1 ; CC(C)(C)c1ccc(N2c3ccc(C(C)(C)C)cc3B3c4cc5c(C(C)(C)C)csc5cc4N(c4ccc(C(C)(C)C)cc4)c4cc(C(C)(C)C)cc2c43)cc1 ; CC(C)(C)c1ccc(N2c3ccc(C(C)(C)C)cc3B3c4cc5cc(C(C)(C)C)sc5cc4N(c4ccc(C(C)(C)C)cc4)c4cc(C(C)(C)C)cc2c43)cc1]

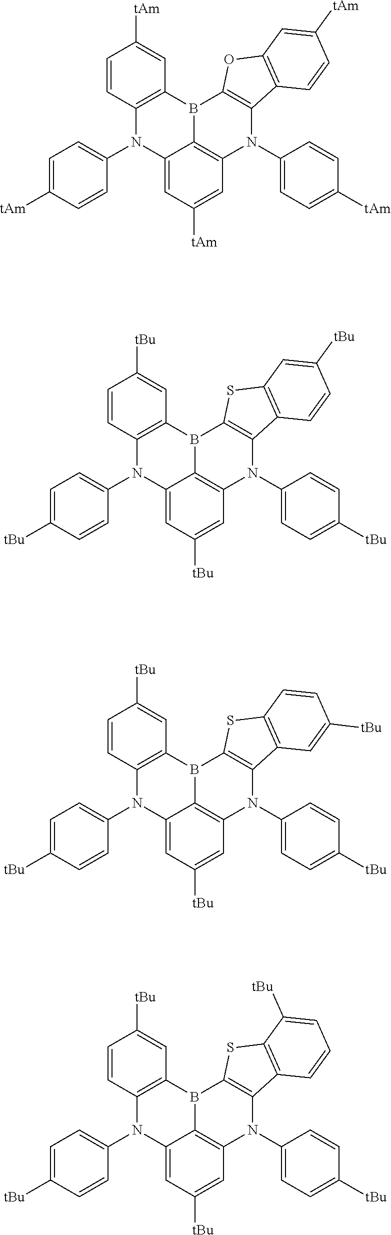

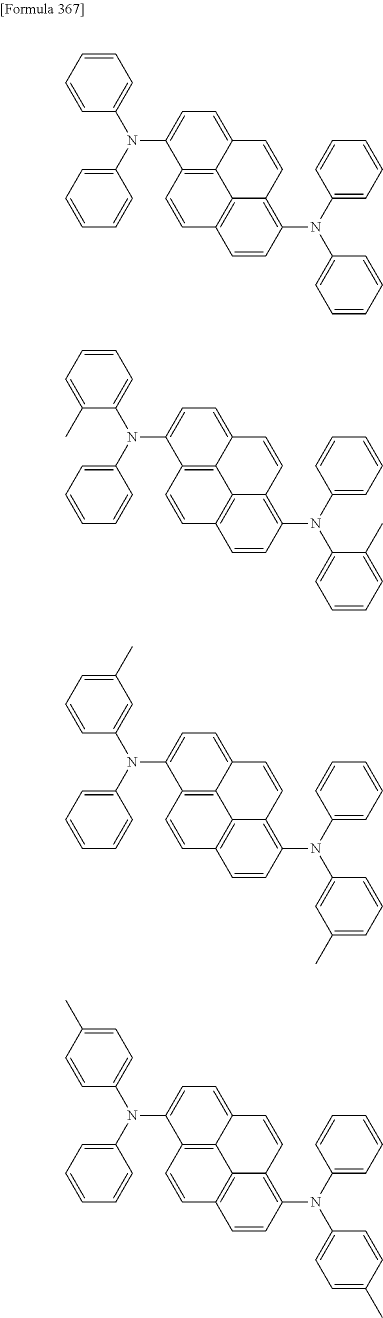 [SMILES: c1ccc(N(c2ccccc2)c2ccc3ccc4c(N(c5ccccc5)c5ccccc5)ccc5ccc2c3c54)cc1 ; Cc1ccccc1N(c1ccccc1)c1ccc2ccc3c(N(c4ccccc4)c4ccccc4C)ccc4ccc1c2c43 ; Cc1cccc(N(c2ccccc2)c2ccc3ccc4c(N(c5ccccc5)c5cccc(C)c5)ccc5ccc2c3c54)c1 ; Cc1ccc(N(c2ccccc2)c2ccc3ccc4c(N(c5ccccc5)c5ccc(C)cc5)ccc5ccc2c3c54)cc1]

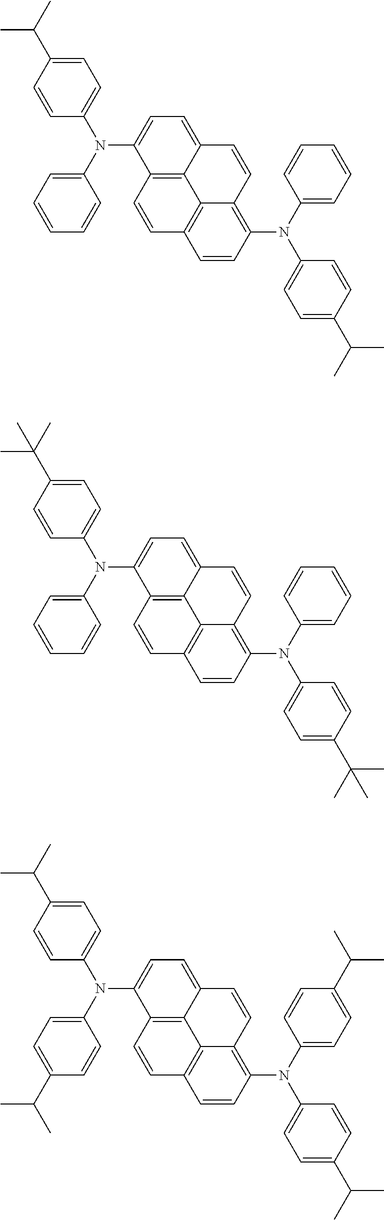

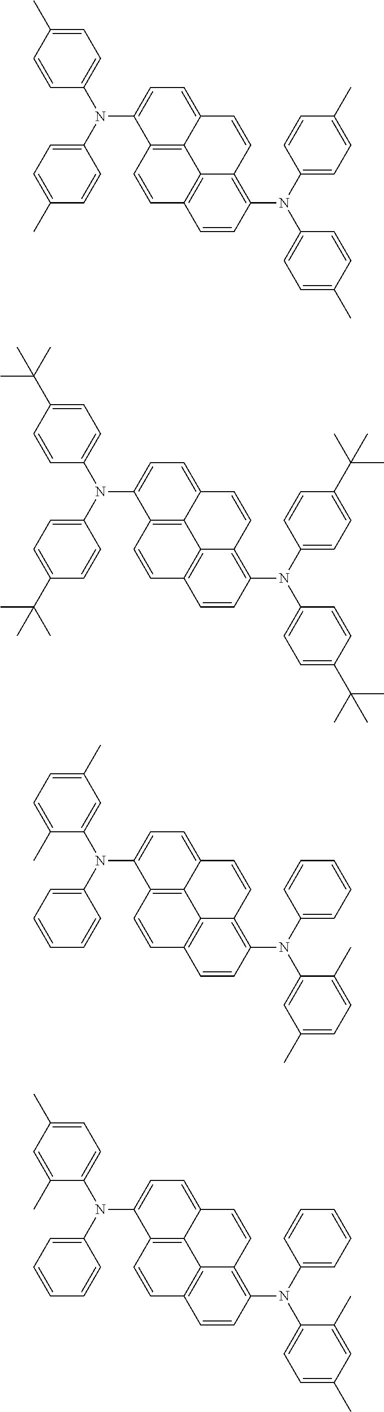

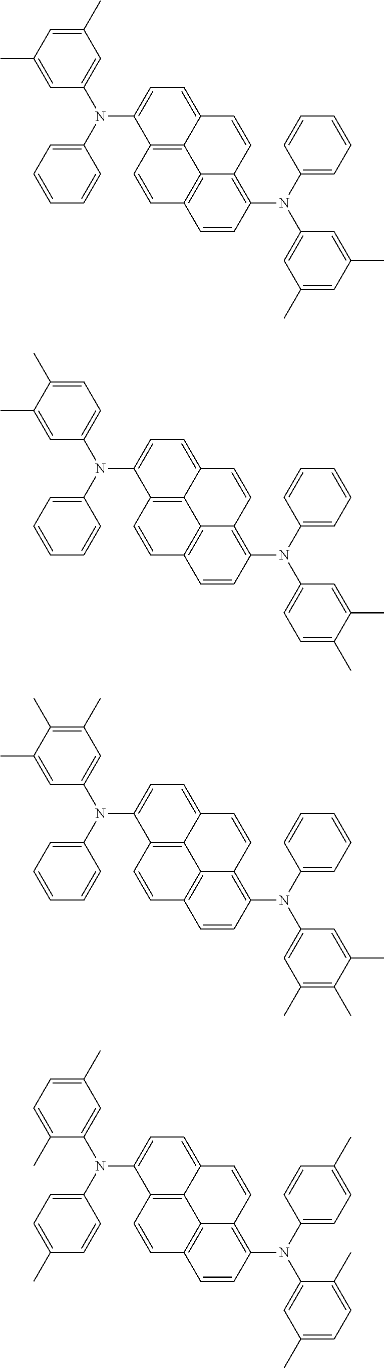

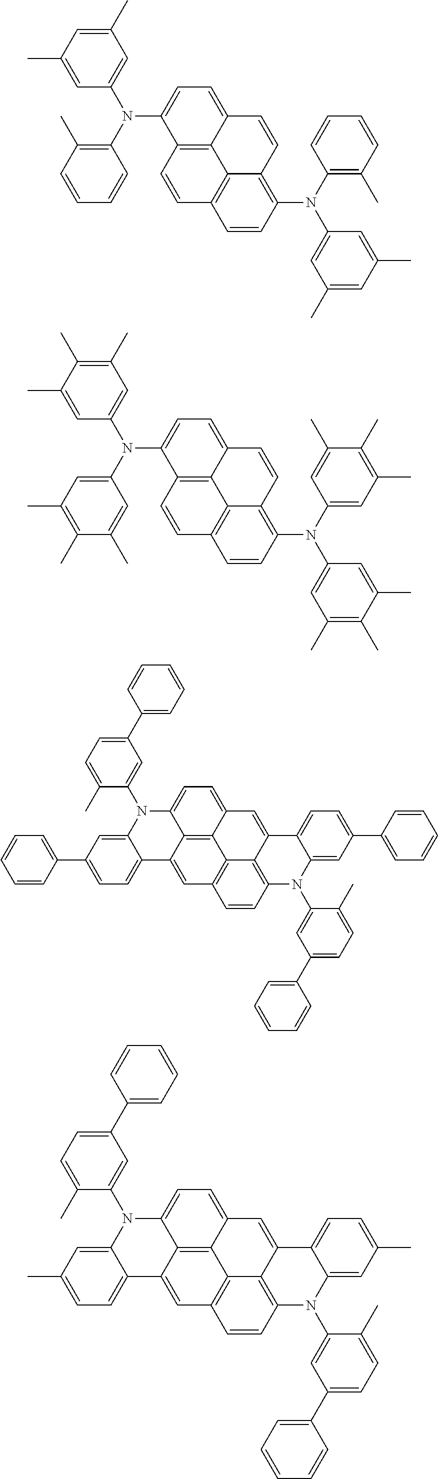

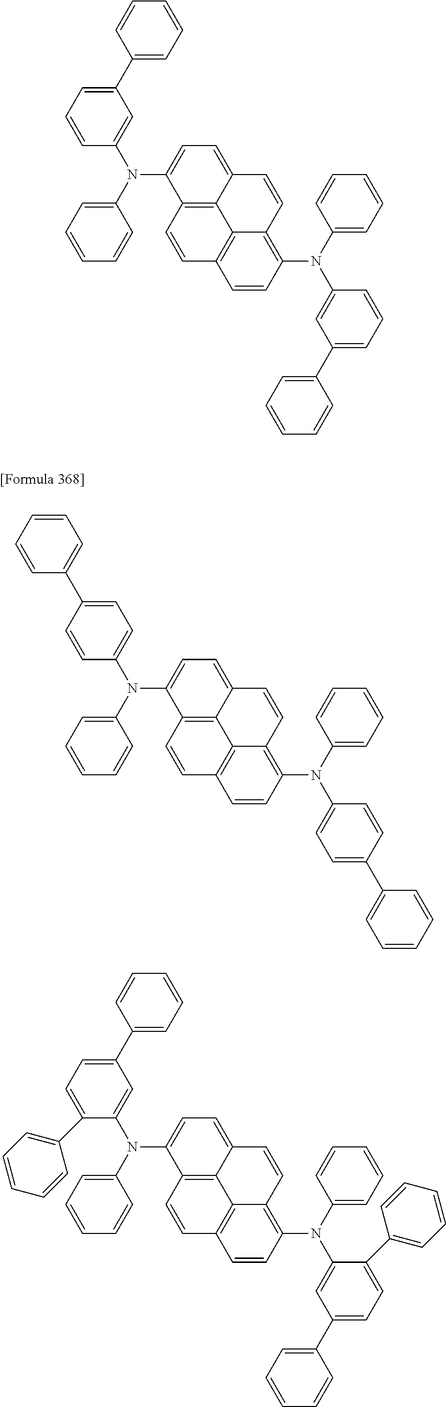 [SMILES: c1ccc(-c2cccc(N(c3ccccc3)c3ccc4ccc5c(N(c6ccccc6)c6cccc(-c7ccccc7)c6)ccc6ccc3c4c65)c2)cc1 ; c1ccc(-c2ccc(N(c3ccccc3)c3ccc4ccc5c(N(c6ccccc6)c6ccc(-c7ccccc7)cc6)ccc6ccc3c4c65)cc2)cc1 ; c1ccc(-c2ccc(-c3ccccc3)c(N(c3ccccc3)c3ccc4ccc5c(N(c6ccccc6)c6cc(-c7ccccc7)ccc6-c6ccccc6)ccc6ccc3c4c65)c2)cc1]

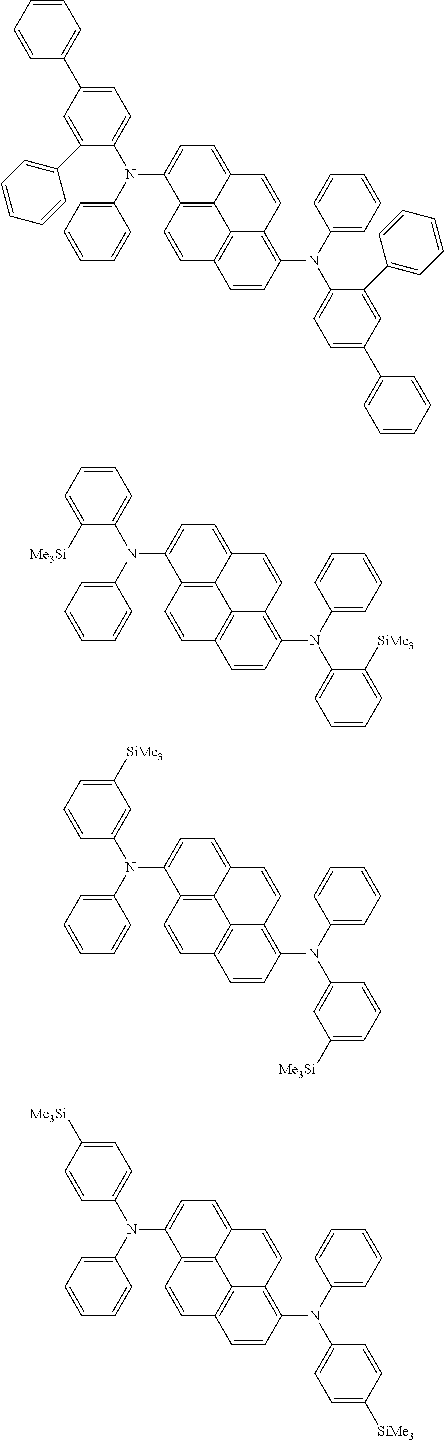 [SMILES: c1ccc(-c2ccc(N(c3ccccc3)c3ccc4ccc5c(N(c6ccccc6)c6ccc(-c7ccccc7)cc6-c6ccccc6)ccc6ccc3c4c65)c(-c3ccccc3)c2)cc1 ; C[Si](C)(C)c1ccccc1N(c1ccccc1)c1ccc2ccc3c(N(c4ccccc4)c4ccccc4[Si](C)(C)C)ccc4ccc1c2c43 ; C[Si](C)(C)c1cccc(N(c2ccccc2)c2ccc3ccc4c(N(c5ccccc5)c5cccc([Si](C)(C)C)c5)ccc5ccc2c3c54)c1 ; C[Si](C)(C)c1ccc(N(c2ccccc2)c2ccc3ccc4c(N(c5ccccc5)c5ccc([Si](C)(C)C)cc5)ccc5ccc2c3c54)cc1]

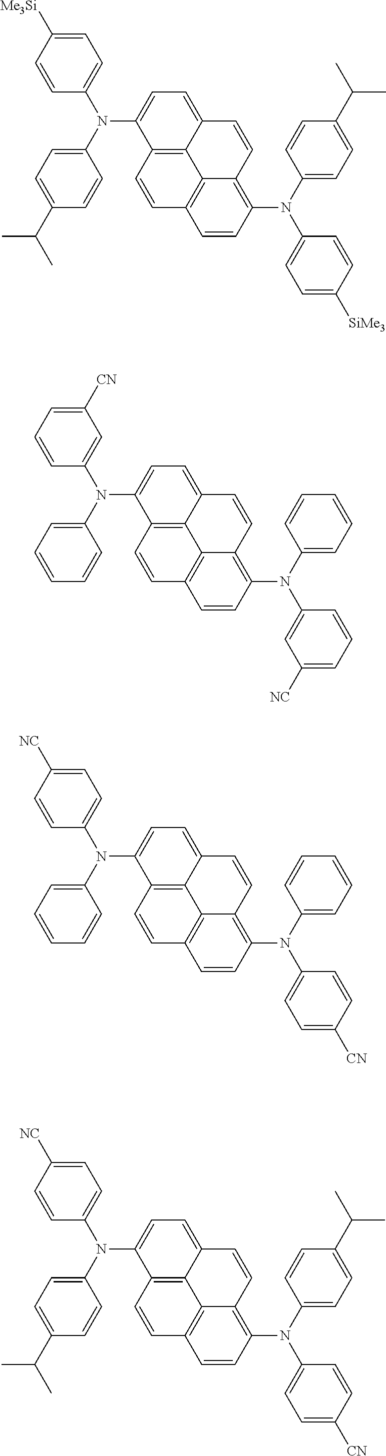

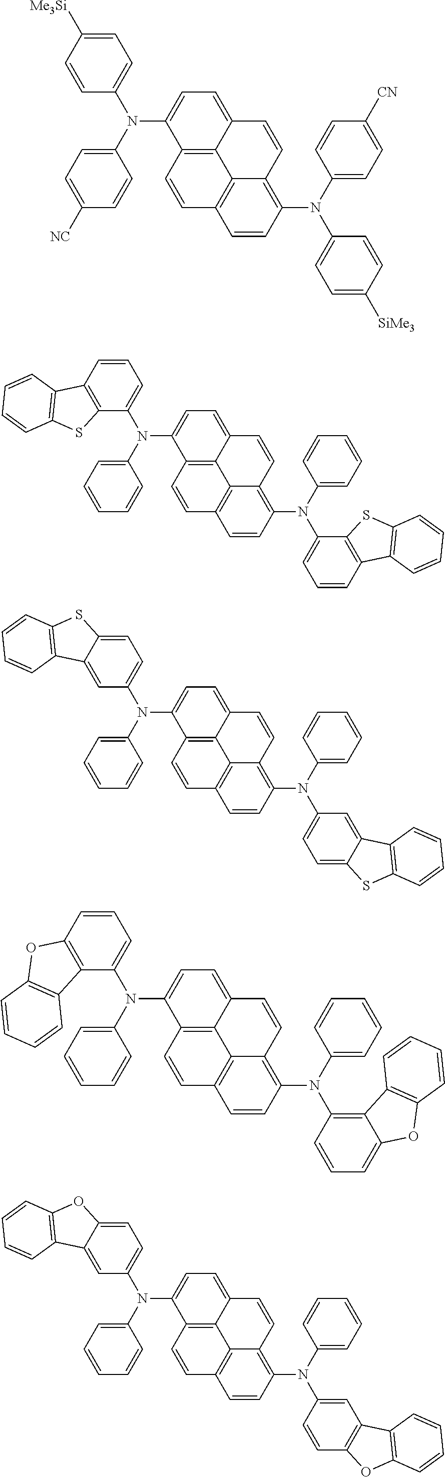 [SMILES: C[Si](C)(C)c1ccc(N(c2ccc(C#N)cc2)c2ccc3ccc4c(N(c5ccc(C#N)cc5)c5ccc([Si](C)(C)C)cc5)ccc5ccc2c3c54)cc1 ; c1ccc(N(c2ccc3ccc4c(N(c5ccccc5)c5cccc6c5sc5ccccc56)ccc5ccc2c3c54)c2cccc3c2sc2ccccc23)cc1 ; c1ccc(N(c2ccc3sc4ccccc4c3c2)c2ccc3ccc4c(N(c5ccccc5)c5ccc6sc7ccccc7c6c5)ccc5ccc2c3c54)cc1 ; c1ccc(N(c2ccc3ccc4c(N(c5ccccc5)c5cccc6oc7ccccc7c56)ccc5ccc2c3c54)c2cccc3oc4ccccc4c23)cc1 ; c1ccc(N(c2ccc3oc4ccccc4c3c2)c2ccc3ccc4c(N(c5ccccc5)c5ccc6oc7ccccc7c6c5)ccc5ccc2c3c54)cc1]

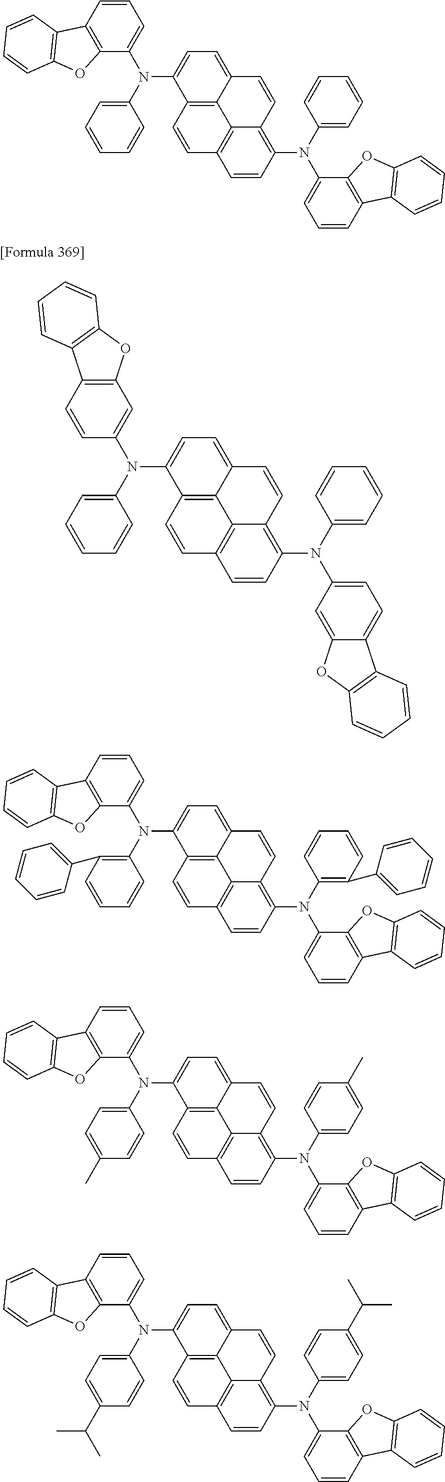 [SMILES: c1ccc(N(c2ccc3ccc4c(N(c5ccccc5)c5cccc6c5oc5ccccc56)ccc5ccc2c3c54)c2cccc3c2oc2ccccc23)cc1 ; c1ccc(N(c2ccc3c(c2)oc2ccccc23)c2ccc3ccc4c(N(c5ccccc5)c5ccc6c(c5)oc5ccccc56)ccc5ccc2c3c54)cc1 ; c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; Cc1ccc(N(c2ccc3ccc4c(N(c5ccc(C)cc5)c5cccc6c5oc5ccccc56)ccc5ccc2c3c54)c2cccc3c2oc2ccccc23)cc1 ; CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1]

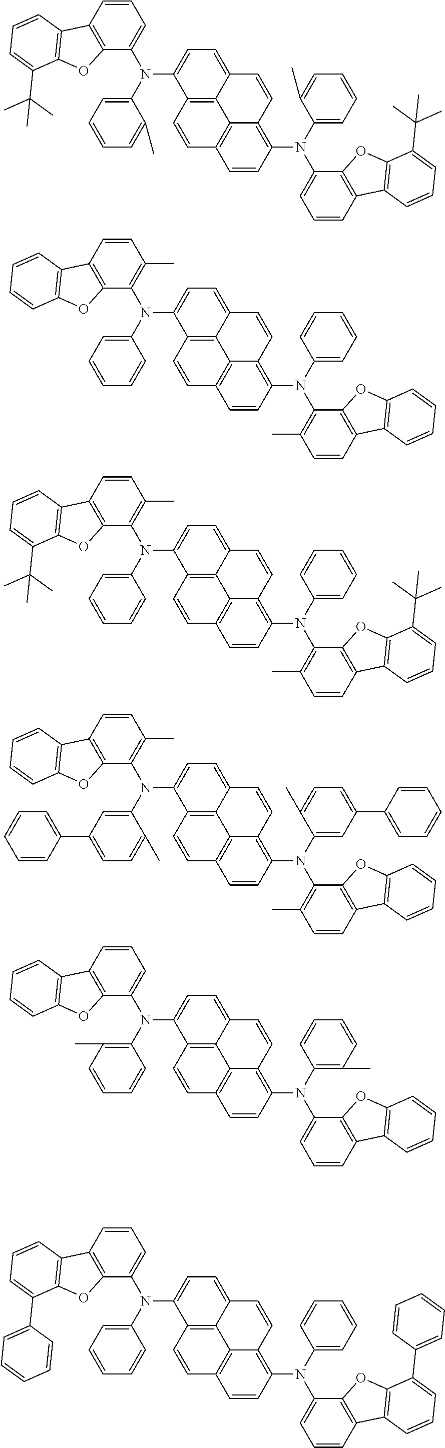

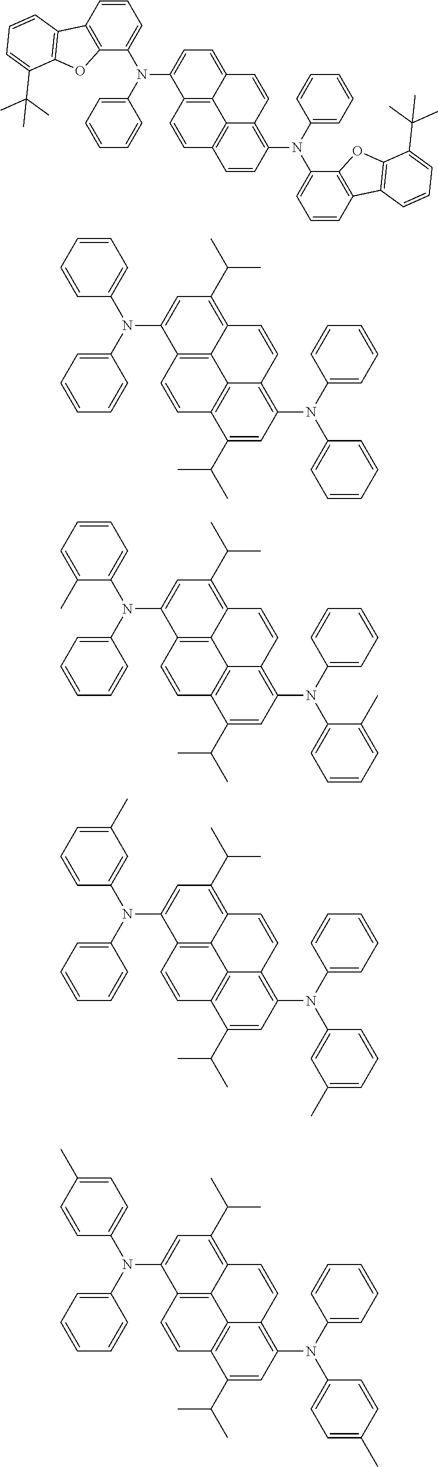

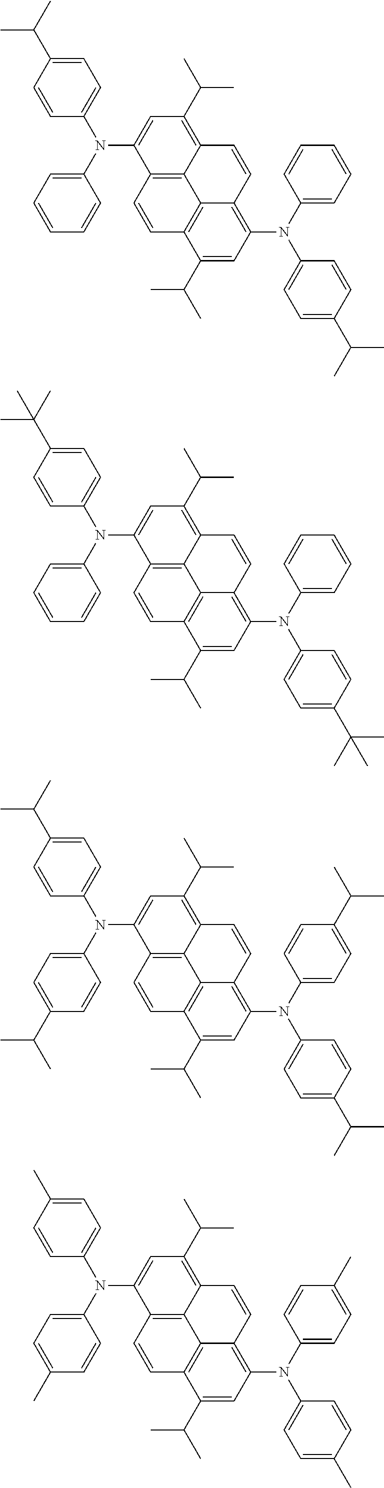

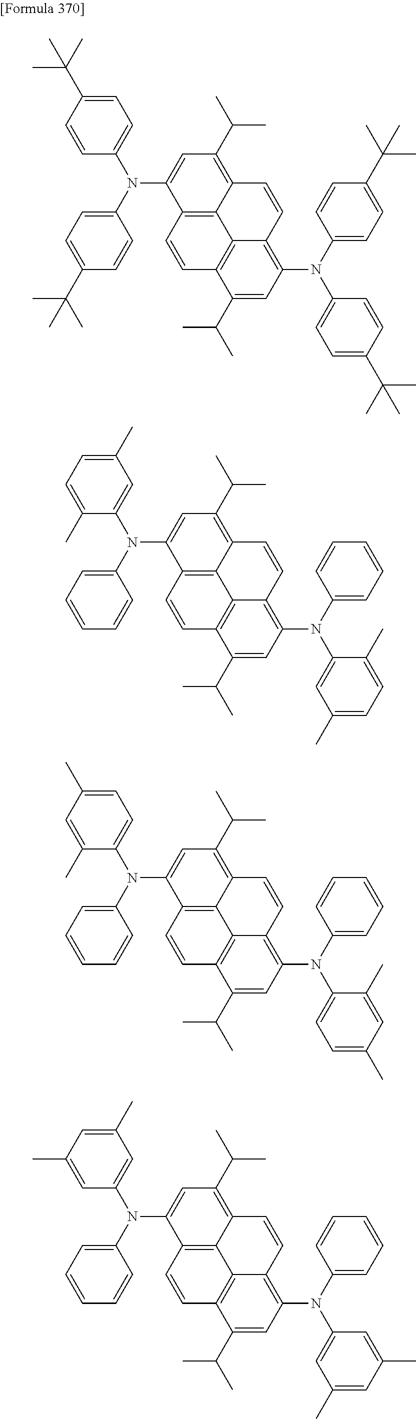

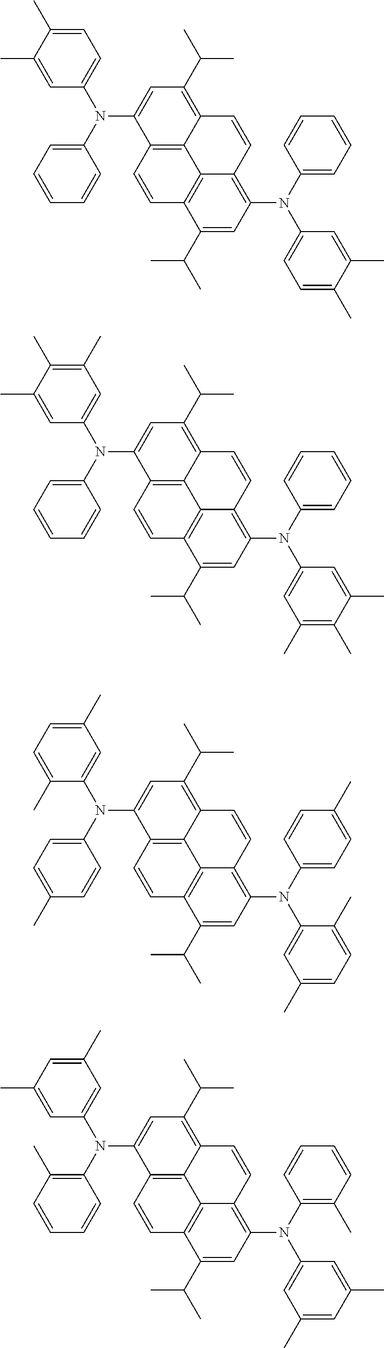

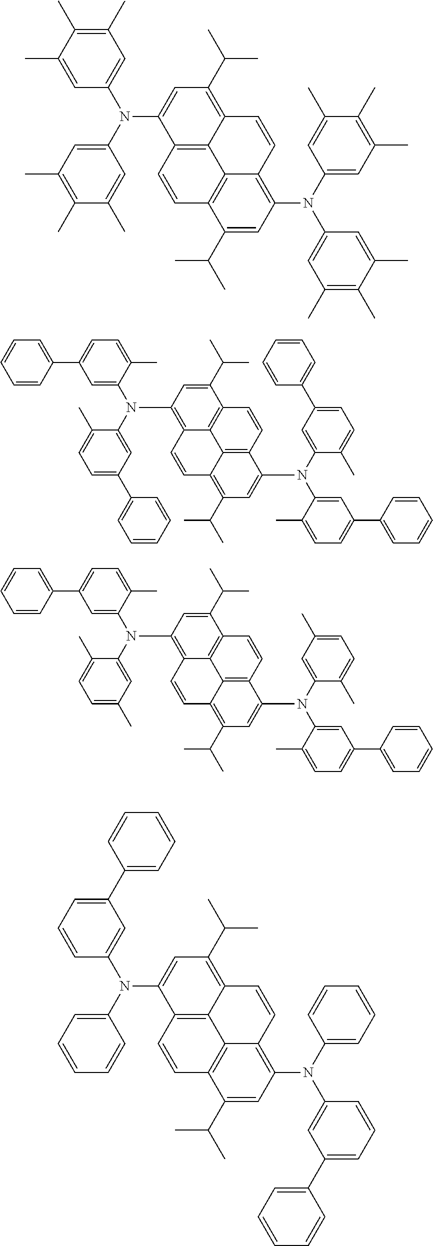

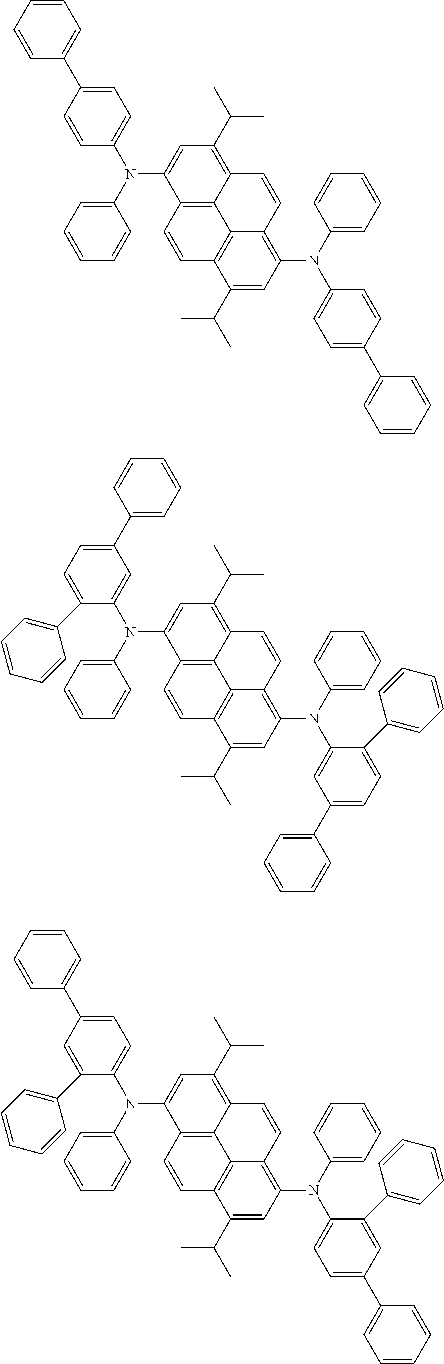 [SMILES: CC(C)c1cc(N(c2ccccc2)c2ccc(-c3ccccc3)cc2)c2ccc3c(C(C)C)cc(N(c4ccccc4)c4ccc(-c5ccccc5)cc4)c4ccc1c2c34 ; CC(C)c1cc(N(c2ccccc2)c2cc(-c3ccccc3)ccc2-c2ccccc2)c2ccc3c(C(C)C)cc(N(c4ccccc4)c4cc(-c5ccccc5)ccc4-c4ccccc4)c4ccc1c2c34 ; CC(C)c1cc(N(c2ccccc2)c2ccc(-c3ccccc3)cc2-c2ccccc2)c2ccc3c(C(C)C)cc(N(c4ccccc4)c4ccc(-c5ccccc5)cc4-c4ccccc4)c4ccc1c2c34]

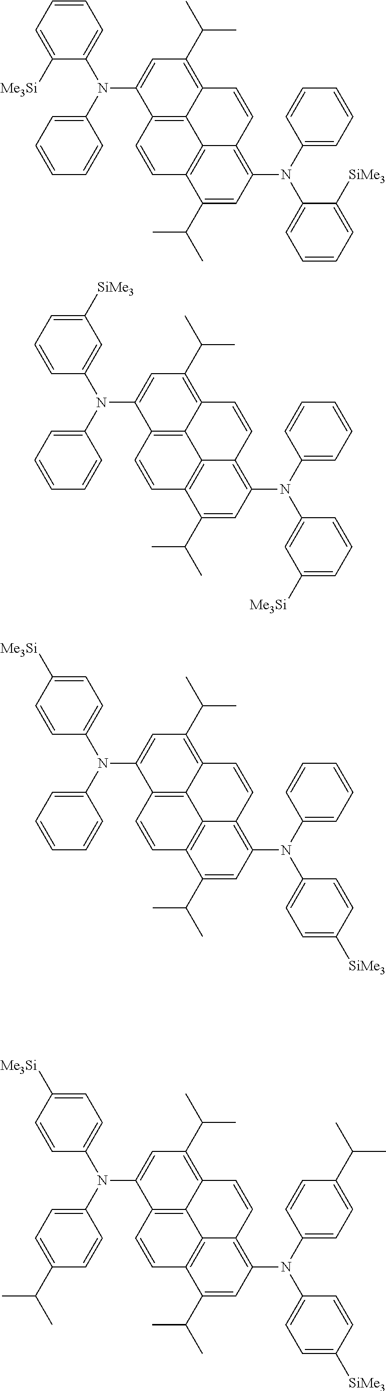 [SMILES: CC(C)c1cc(N(c2ccccc2)c2ccccc2[Si](C)(C)C)c2ccc3c(C(C)C)cc(N(c4ccccc4)c4ccccc4[Si](C)(C)C)c4ccc1c2c34 ; CC(C)c1cc(N(c2ccccc2)c2cccc([Si](C)(C)C)c2)c2ccc3c(C(C)C)cc(N(c4ccccc4)c4cccc([Si](C)(C)C)c4)c4ccc1c2c34 ; CC(C)c1cc(N(c2ccccc2)c2ccc([Si](C)(C)C)cc2)c2ccc3c(C(C)C)cc(N(c4ccccc4)c4ccc([Si](C)(C)C)cc4)c4ccc1c2c34 ; CC(C)c1ccc(N(c2ccc([Si](C)(C)C)cc2)c2cc(C(C)C)c3ccc4c(N(c5ccc(C(C)C)cc5)c5ccc([Si](C)(C)C)cc5)cc(C(C)C)c5ccc2c3c54)cc1]

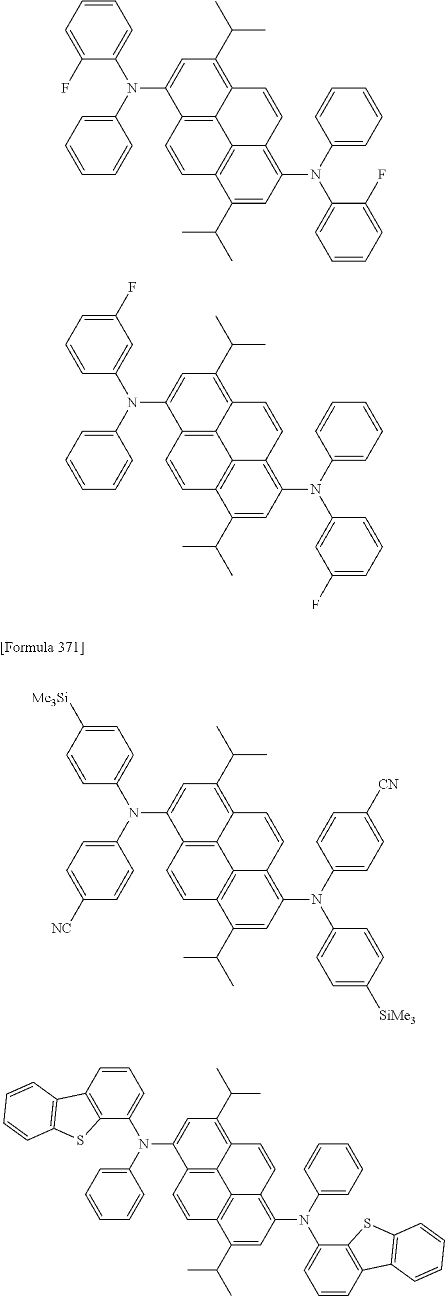 [SMILES: CC(C)c1cc(N(c2ccccc2)c2ccccc2F)c2ccc3c(C(C)C)cc(N(c4ccccc4)c4ccccc4F)c4ccc1c2c34 ; CC(C)c1cc(N(c2ccccc2)c2cccc(F)c2)c2ccc3c(C(C)C)cc(N(c4ccccc4)c4cccc(F)c4)c4ccc1c2c34 ; CC(C)c1cc(N(c2ccc(C#N)cc2)c2ccc([Si](C)(C)C)cc2)c2ccc3c(C(C)C)cc(N(c4ccc(C#N)cc4)c4ccc([Si](C)(C)C)cc4)c4ccc1c2c34 ; CC(C)c1cc(N(c2ccccc2)c2cccc3c2sc2ccccc23)c2ccc3c(C(C)C)cc(N(c4ccccc4)c4cccc5c4sc4ccccc45)c4ccc1c2c34]

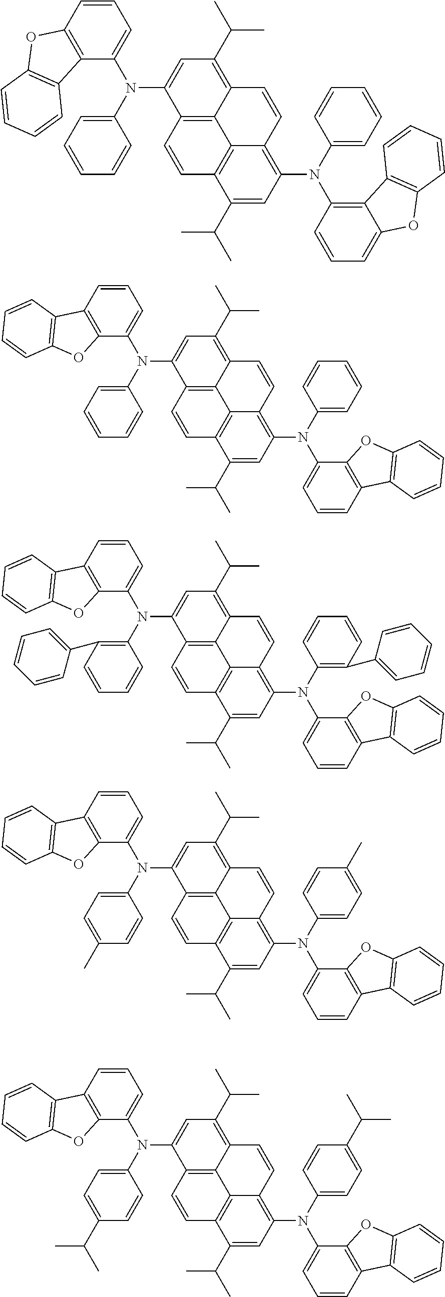

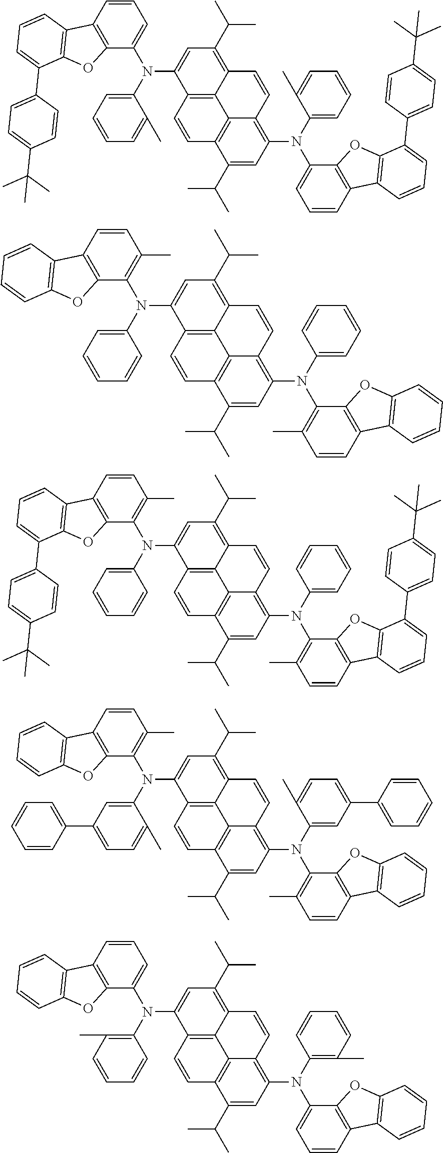

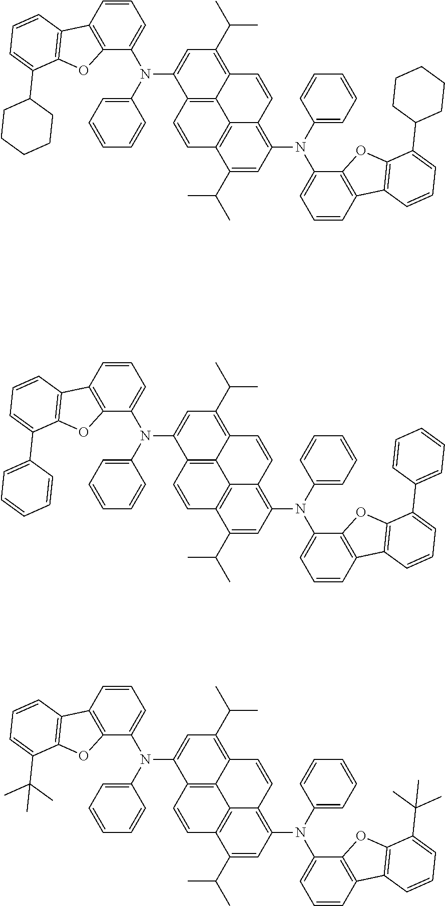 [SMILES: CC(C)c1cc(N(c2ccccc2)c2cccc3c2oc2c(C4CCCCC4)cccc23)c2ccc3c(C(C)C)cc(N(c4ccccc4)c4cccc5c4oc4c(C6CCCCC6)cccc45)c4ccc1c2c34 ; CC(C)c1cc(N(c2ccccc2)c2cccc3c2oc2c(-c4ccccc4)cccc23)c2ccc3c(C(C)C)cc(N(c4ccccc4)c4cccc5c4oc4c(-c6ccccc6)cccc45)c4ccc1c2c34 ; CC(C)c1cc(N(c2ccccc2)c2cccc3c2oc2c(C(C)(C)C)cccc23)c2ccc3c(C(C)C)cc(N(c4ccccc4)c4cccc5c4oc4c(C(C)(C)C)cccc45)c4ccc1c2c34]

### Additional Layers of Organic EL Device

The organic EL device according to the exemplary embodiment may include one or more organic layers in addition to the first sensitizing layer and the first emitting layer. The organic layer is exemplified by at least one layer selected from the group consisting of a hole injecting layer, a hole transporting layer, an electron blocking layer, a hole blocking layer, an electron injecting layer, and an electron transporting layer.

The organic layer of the organic EL device according to the exemplary embodiment may consist of the first sensitizing layer and the first emitting layer, alternatively, may further include, for instance, at least one layer selected from the group consisting of the hole injecting layer, hole transporting layer, electron blocking layer, hole blocking layer, electron injecting layer, and electron transporting layer.

The organic EL device according to the exemplary embodiment may include an interposed layer between the first sensitizing layer and the first emitting layer.

### Interposed Layer

In an exemplary arrangement of the exemplary embodiment, the interposed layer is a non-doped layer. In an exemplary arrangement of the exemplary embodiment, the interposed layer contains no metal atom. The interposed layer contains an interposed layer material. In an exemplary arrangement of the exemplary embodiment, the interposed layer material is not a luminescent compound.

The interposed layer material, which is not particularly limited, is preferably any other material than the luminescent compound.

Examples of the interposed layer material include: 1) a heterocyclic compound such as an oxadiazole derivative, benzimidazole derivative, or phenanthroline derivative; 2) a fused aromatic compound such as a carbazole derivative, anthracene derivative, phenanthrene derivative, pyrene derivative or chrysene derivative; and 3) an aromatic amine compound such as a triarylamine derivative or a fused polycyclic aromatic amine derivative.

In an exemplary arrangement of the exemplary embodiment, the interposed layer material may be one or both of the first host material contained in the first sensitizing layer and the second host material contained in the first emitting layer.

In an exemplary arrangement of the exemplary embodiment, when the interposed layer contains a plurality of interposed layer materials, each of content ratios of the interposed layer materials is 10 mass % or more with respect to the total mass of the interposed layer.

The interposed layer contains the interposed layer material preferably at 60 mass % or more, more preferably at 70 mass % or more, still more preferably at 80 mass % or more, still further more preferably at 90 mass % or more, and yet still further more preferably at 95 mass % or more, with respect to the total mass of the interposed layer.

The interposed layer may contain a single type of interposed layer material or two or more types of interposed layer materials.

When the interposed layer contains two or more types of interposed layer materials, the upper limit of the total of the content ratios of the two or more types of interposed layer materials is 100 mass %.

It should be noted that the interposed layer of the exemplary embodiment may further contain any other material than the interposed layer material.

The interposed layer may be provided in the form of a single layer or a laminate of two or more layers.

A film thickness of the interposed layer, which is not particularly limited, is preferably in a range from 3 nm to 15 nm, more preferably in a range from 5 nm to 10 nm per layer.

### Second Exemplary Embodiment

### Tandem Organic Electroluminescence Device

A tandem organic EL device according to a second exemplary embodiment is an exemplary arrangement of the organic EL device according to the first exemplary embodiment.

An organic electroluminescence device having two or more emitting units provided between the anode and the cathode is referred to as a tandem organic electroluminescence device (tandem organic EL device).

A charge generating layer (corresponding to a first charge generating layer in the second or a third exemplary embodiment) is provided between the emitting units of the tandem organic EL device.

The charge generating layer is also typically referred to as an intermediate layer, intermediate electrode, intermediate conductive layer, electron extraction layer, connecting layer, connector layer, or intermediate insulating layer.

The charge generating layer supplies electrons to a layer disposed closer to the anode than the charge generating layer and supplies holes to a layer disposed closer to the cathode than the charge generating layer. The charge generating layer is made from known materials. The charge generating layer may be a single layer or two or more layers. A unit of two or more charge generating layers is sometimes referred to as a charge generating unit. A plurality of charge generating layers of the charge generating unit are mutually the same or different in composition.

A plurality of layers including the emitting layer, which are disposed between the charge generating layer or the charge generating unit and the anode or the cathode, are sometimes referred to as an emitting unit.

In a case where the charge generating layer includes two layers, sometimes, a layer disposed closer to the anode than the charge generating layer is referred to as an N layer, and a layer disposed closer to the cathode than the charge generating layer is referred to as a P layer.

The arrangement of the tandem organic EL device of the second exemplary embodiment is exemplified by exemplary arrangements 1 to 4 as follows.

### Exemplary Arrangement 1

A tandem organic EL device in the exemplary arrangement 1 includes: a first emitting unit including the emitting region of the first exemplary embodiment as a first emitting region; a first charge generating layer disposed between the first emitting unit and the cathode; and the second emitting unit including the second emitting region disposed between the first charge generating layer and the cathode, in which the first emitting region includes the first sensitizing layer and the first emitting layer; the second emitting region at least includes the second emitting layer; the anode, the second emitting region, the first charge generating layer, the first emitting region, and the cathode are disposed in this order, and the second emitting layer contains a third host material and a second luminescent compound.

### Exemplary Arrangement 2

A tandem organic EL device in the exemplary arrangement 2 has the same arrangement as the exemplary arrangement 1 except that the first emitting region and the second emitting region are switched locationally.

The tandem organic EL device in the exemplary arrangement 2 includes: the first emitting unit including the emitting region of the first exemplary embodiment as the first emitting region; the first charge generating layer disposed between the first emitting unit and the anode; and a second emitting unit including the second emitting region disposed between the first charge generating layer and the anode, in which the first emitting region includes the first sensitizing layer and the first emitting layer; the second emitting region at least includes the second emitting layer; the anode, the first emitting region, the first charge generating layer, the second emitting region, and the cathode are disposed in this order, and the second emitting layer contains the third host material and the second luminescent compound.

### Exemplary Arrangement 3

A tandem organic EL device in an exemplary arrangement 3 has the same arrangement as the exemplary arrangement 1 or 2 except that: the second emitting region further includes a second sensitizing layer; the arrangement of the second sensitizing layer and the second emitting layer is specified in this order of the second sensitizing layer and the second emitting layer from the anode; and the arrangement of the first sensitizing layer and the first emitting layer is specified in this order of the first sensitizing layer and the first emitting layer from the anode.

In the tandem organic EL device in the exemplary arrangement 3, the second emitting region in the exemplary arrangement 1 or 2 includes the second sensitizing layer and the second emitting layer; the first emitting region includes the first sensitizing layer and the first emitting layer in this order from the anode; the second emitting region includes the second sensitizing layer and the second emitting layer in this order from the anode; the second sensitizing layer contains a fourth host material and a second sensitizing material; the third host material and the fourth host material are mutually different; the second sensitizing material and the second luminescent compound are mutually different; and a difference ΔST(G2) between the lowest singlet energy S₁(G2) of the second sensitizing material and an energy gap T_{77K}(G2) at 77K of the second sensitizing material satisfies a numerical formula (Numerical Formula 1A) below.

$$Δ S T ( G 2 ) = {S}_{1} ( G 2 ) - {T}_{77 K} ( G 2 ) < 0.5 eV \qquad ( Numerical Formula 1 A )$$

### Exemplary Arrangement 4

A tandem organic EL device in the exemplary arrangement 4 has the same arrangement as the exemplary arrangement 1 or 2 except that: the second emitting region further includes the second sensitizing layer; the arrangement of the second emitting layer and the second sensitizing layer is specified in this order of the second emitting layer and the second sensitizing layer from the anode; and the arrangement of the first emitting layer and the first sensitizing layer is specified in this order of the first emitting layer and the first sensitizing layer from the anode.

In the tandem organic EL device in the exemplary arrangement 4, the second emitting region in the exemplary arrangement 1 or 2 includes the second sensitizing layer and the second emitting layer; the first emitting region includes the first sensitizing layer and the first emitting layer in this order from the anode; the second emitting region includes the second sensitizing layer and the second emitting layer in this order from the anode; the second sensitizing layer contains the fourth host material and a second sensitizing material; the third host material and the fourth host material are mutually different; the second sensitizing material and the second luminescent compound are mutually different; and a difference ΔST(G2) between the lowest singlet energy S₁(G2) of the second sensitizing material and the energy gap T_{77K}(G2) at 77K of the second sensitizing material satisfies a numerical formula (Numerical Formula 1A) below.

$$Δ S T ( G 2 ) = {S}_{1} ( G 2 ) - {T}_{77 K} ( G 2 ) < 0.5 eV \qquad ( Numerical Formula 1 A )$$

The tandem organic EL device of the second exemplary embodiment includes the emitting region of the first exemplary embodiment (the emitting region including the first sensitizing material and the first emitting layer) as the first emitting region. The first sensitizing material has a small ΔST in principle and a higher light absorption intensity than a phosphorescent complex, resulting in having a suitable performance as the sensitizing material.

Accordingly, the tandem organic EL device of the second exemplary embodiment has a low light-emission start voltage and emits light with high efficiency for the same reason as that in the first exemplary embodiment.

The first sensitizing material and the first emitting layer of the second exemplary embodiment represent the same as the first sensitizing material and the first emitting layer of the first exemplary embodiment.

In the second exemplary embodiment, the third host material and the first host material are mutually the same or different. The third host material and the second host material are mutually the same or different.

In the second exemplary embodiment, the fourth host material and the first host material are mutually the same or different. The fourth host material and the second host material are mutually the same or different.

In the second exemplary arrangement, the second luminescent compound and the first luminescent compound are mutually the same or different. The second luminescent compound and the first sensitizing material are mutually different.

In the second exemplary embodiment, the second sensitizing material and the first sensitizing material are mutually the same or different. The second sensitizing material and the first luminescent compound are mutually different.

Examples of the third host material include the same materials or compounds as the first host material and the second host material described in the first exemplary embodiment.

Examples of the fourth host material include the same materials or compounds as the first host material and the second host material described in the first exemplary embodiment.

Examples of the second sensitizing material include the same materials or compounds as the first sensitizing material described in the first exemplary embodiment.

Examples of the second luminescent compound include the same materials or compounds as the first luminescent compound described in the first exemplary embodiment. In the organic EL device in the exemplary arrangement 1 or 2, the second emitting layer may be a phosphorescent layer. In this arrangement, the second emitting layer contains a phosphorescent compound as the second luminescent compound.

In a case where the tandem organic EL device of the second exemplary embodiment is the tandem organic EL device in the exemplary arrangement 3 or 4, it is preferable that the second emitting region is similar in properties to the first emitting region and emits light with an emitting mechanism illustrated in FIG. 1. Specifically, it is preferable that the second emitting region includes, as the second sensitizing layer, the first sensitizing layer described in the first exemplary embodiment, and includes, as the second emitting layer, the first emitting layer described in the first exemplary embodiment.

In an exemplary arrangement of the organic EL device of the second exemplary embodiment, a difference ΔST(G2) between the lowest singlet energy S₁(G2) of the second sensitizing material and the energy gap T_{77K}(G2) at 77K of the second sensitizing material satisfies any one of relationships represented by numerical formulae (Numerical Formula 12A to Numerical Formula 12D) below.

$$Δ ST ( G 2 ) = {S}_{1} ( G 2 ) - {T}_{77 K} ( G 2 ) < 0.4 eV \qquad ( Numerical Formula 12 A )$$

$$Δ ST ( G 2 ) = {S}_{1} ( G 2 ) - {T}_{77 K} ( G 2 ) < 0.3 eV \qquad ( Numerical Formula 12 B )$$

$$Δ ST ( G 2 ) = {S}_{1} ( G 2 ) - {T}_{77 K} ( G 2 ) < 0.2 eV \qquad ( Numerical Formula 12 C )$$

$$Δ ST ( G 2 ) = {S}_{1} ( G 2 ) - {T}_{77 K} ( G 2 ) < 0.1 eV \qquad ( Numerical Formula 12 D )$$

In an exemplary arrangement of the organic EL device of the second exemplary embodiment, the energy gap T_{77K}(G2) at 77K of the second sensitizing material, an energy gap T_{77K}(H4) at 77K of the fourth host material, and an energy gap T_{77K}(H3) at 77K of the third host material satisfy a relationship represented by a numerical formula (Numerical Formula 2X) below.

$${T}_{77 K} ( G 2 ) > {T}_{77 K} ( H 4 ) > {T}_{77 K} ( H 3 ) \qquad ( Numeric Formula 2 X )$$

In an exemplary arrangement of the organic EL device of the second exemplary embodiment, the energy gap T_{77K}(G2) at 77K of the second sensitizing material and the energy gap T_{77K}(H4) at 77K of the fourth host material satisfy a relationship represented by a numerical formula (Numerical Formula 21X) below.

$${T}_{77 K} ( G 2 ) - {T}_{77 K} ( H 4 ) < 0.5 eV \qquad ( Numeric Formula 21 X )$$

In an exemplary arrangement of the organic EL device of the second exemplary embodiment, the energy gap T_{77K}(G2) at 77 K of the second sensitizing material and the energy gap T_{77K}(H4) at 77K of the fourth host material satisfy a relationship represented by a numerical formula (Numerical Formula 21Y) below.

$${T}_{77 K} ( G 2 ) - {T}_{77 K} ( H 4 ) < 0.4 eV \qquad ( Numeric Formula 21 Y )$$

In an exemplary arrangement of the organic EL device of the second exemplary embodiment, the energy gap T_{77K}(H4) at 77 K of the fourth host material and the energy gap T_{77K}(H3) at 77K of the third host material satisfy a relationship represented by a numerical formula (Numerical Formula 22X) below.

$${T}_{77 K} ( H 4 ) - {T}_{77 K} ( H 3 ) < 0.3 eV \qquad ( Numeric Formula 22 X )$$

In an exemplary arrangement of the organic EL device of the second exemplary embodiment, the energy gap T_{77K}(H4) at 77K of the fourth host material and the energy gap T_{77K}(H3) at 77K of the third host material satisfy a relationship represented by a numerical formula (Numerical Formula 22Y) below.

$${T}_{77 K} ( H 4 ) - {T}_{77 K} ( H 3 ) < 0.3 eV \qquad ( Numeric Formula 22 Y )$$

In an exemplary arrangement of the organic EL device of the second exemplary embodiment, the lowest singlet energy S₁(G2) of the second sensitizing material and the lowest singlet energy S₁(BD2) of the second luminescent compound satisfy a relationship of a numerical formula (Numerical Formula 3X) below.

$${S}_{1} ( BD 2 ) > {S}_{1} ( G 2 ) \qquad ( Numeric Formula 3 X )$$

In an exemplary arrangement of the organic EL device of the second exemplary embodiment, the second sensitizing layer and the second emitting layer are in direct contact with each other.

In an exemplary arrangement of the organic EL device of the second exemplary embodiment, the second sensitizing layer is disposed between the anode and the cathode, and the second emitting layer is disposed between the second sensitizing layer and the cathode. In this arrangement, the second emitting region includes the second sensitizing layer and the second emitting layer in this order from a side close to the anode.

In an exemplary arrangement of the organic EL device of the second exemplary embodiment, when the second emitting region includes the second sensitizing layer and the second emitting layer in this order from a side close to the anode, an absolute value of the energy level LUMO(G2) of the lowest unoccupied molecular orbital of the second sensitizing material and an absolute value of the energy level LUMO(H4) of the lowest unoccupied molecular orbital of the fourth host material satisfy a relationship represented by a numerical formula (Numerical Formula 4X) below.

$$\vert LUMO ( G 2 ) \vert > \vert LUMO ( H 4 ) \vert \qquad ( Numeric Formula 4 X )$$

By the second sensitizing material and the fourth host material satisfying the relationship of the numerical formula (Numerical Formula 4X), electrons are easily trapped in the second sensitizing material in the second sensitizing layer and, consequently, recombination of holes and electrons in the second sensitizing layer is promoted.

In an exemplary arrangement of the organic EL device of the second exemplary embodiment, in a case where the second emitting region includes the second sensitizing layer and the second emitting layer in this order from a side close to the anode, in addition to the second sensitizing material and the fourth host material satisfying the relationship of the numerical formula (Numerical Formula 4X), an absolute value of the energy level LUMO(H3) of the lowest unoccupied molecular orbital of the third host material and an absolute value of the energy level LUMO(BD2) of the lowest unoccupied molecular orbital of the second luminescent compound satisfy a relationship represented by a numerical formula (Numerical Formula 41X) below.

$$\vert LUMO ( H 3 ) \vert > \vert LUMO ( BD 2 ) \vert \qquad ( Numeric Formula 41 X )$$

By the third host material and the second luminescent compound satisfying the relationship of the numerical formula (Numerical Formula 41X), electrons are unlikely to be trapped in the second luminescent compound in the second emitting layer and, consequently, recombination of holes and electrons in the second sensitizing layer is promoted.

In an exemplary arrangement of the organic EL device of the second exemplary embodiment, the second sensitizing layer is disposed between the anode and the cathode, and the second emitting layer is disposed between the second sensitizing layer and the anode. In this arrangement, the second emitting region includes the second emitting layer and the second sensitizing layer in this order from a side close to the anode.

In an exemplary arrangement of the organic EL device of the second exemplary embodiment, in a case where the second emitting region includes the second emitting layer and the second sensitizing layer in this order from a side close to the anode, the absolute value of the energy level HOMO(G2) of the highest occupied molecular orbital of the second sensitizing material and the absolute value of the energy level HOMO(H4) of the highest occupied molecular orbital of the fourth host material satisfy a relationship represented by a numerical formula (Numerical Formula 5X) below.

$$\vert HOMO ( G 2 ) \vert < \vert HOM O ( H 4 ) \vert \qquad ( Numeric Formula 5 X )$$

By the second sensitizing material and the fourth host material satisfying the relationship of the numerical formula (Numerical Formula 5X), holes are easily trapped in the second sensitizing material in the second sensitizing layer and, consequently, recombination of holes and electrons in the second sensitizing layer is promoted.

In an exemplary arrangement of the organic EL device of the second exemplary embodiment, in a case where the second emitting region includes the second emitting layer and the second sensitizing layer in this order from a side close to the anode, in addition to the second sensitizing material and the fourth host material satisfying the relationship of the numerical formula (Numerical Formula 5X), an absolute value of an energy level HOMO(H3) of the highest occupied molecular orbital of the third host material and an absolute value of an energy level HOMO(BD2) of the highest occupied molecular orbital of the second luminescent compound satisfy a relationship represented by a numerical formula (Numerical Formula 51X) below.

$$\vert HOMO ( H 3 ) \vert < \vert HOM O ( BD 2 ) \vert \qquad ( Numeric Formula 51 X )$$

By the third host material and the second luminescent compound satisfying the relationship of the numerical formula (Numerical Formula 51X), holes are unlikely to be trapped in the second luminescent compound in the second emitting layer and, consequently, recombination of holes and electrons in the second sensitizing layer is promoted.

In an exemplary arrangement of the second exemplary embodiment, when a first evaluation device emits light, the first evaluation device including an emitting region that has the same arrangement as the first emitting region and that is interposed between the anode and the cathode, a difference between energy E_{PE1} (eV) at peak of an emission spectrum and energy E_{TH1} (eV) imparted to the first evaluation device when a luminance of 0.01 cd/m² is obtained satisfies a relationship of a numerical formula (Numerical Formula 61) below.

$${E}_{TH 1} - {E}_{PE 1} \leq 0.05 eV \qquad ( Numeric Formula 61 )$$

In an exemplary arrangement of the second exemplary embodiment, when a second evaluation device emits light, the second evaluation device including an emitting region that has the same arrangement as the second emitting region and that is interposed between the anode and the cathode, a difference between energy E_{PE2} (eV) at peak of an emission spectrum and energy E_{TH2} (eV) imparted to the second evaluation device when a luminance of 0.01 cd/m² is obtained satisfies a relationship of a numerical formula (Numerical Formula 62) below.

$${E}_{TH 2} - {E}_{PE 2} \leq 0.05 eV \qquad ( Numeric Formula 62 )$$

A measurement method of E_{TH1} in the numerical formula (Numerical Formula 61) is the same as the measurement method of E_{TH} in the numerical formula (Numerical Formula 6) in the first exemplary embodiment except for using the first evaluation device for the measurement.

A measurement method of E_{TH2} in the numerical formula (Numerical Formula 62) is the same as the measurement method of E_{TH} in the numerical formula (Numerical Formula 6) in the first exemplary embodiment except for using the second evaluation device for the measurement.

As each of E_{PE1} in the numerical formula (Numerical Formula 61) and E_{PE2} in the numerical formula (Numerical Formula 62), a measurement value of the lowest singlet energy S₁ of the luminescent compound contained in the corresponding emitting layer for the measurement is used. The measurement method of the lowest singlet energy S₁ is as described in Examples.

The measurement method of E_{TH1} in the numerical formula (Numerical Formula 61) and E_{TH2} in the numerical formula (Numerical Formula 62) will be described with reference to specific examples.

### Production of First Evaluation Device

A case where the first emitting region included in the first emitting unit has the same arrangement as in Example 13 described later is taken as an example. Specifically, in a case where the first emitting region includes: the first sensitizing layer containing a compound BH-a (first host material) and a compound TADF-a (first sensitizing material); and the first emitting layer containing a compound BH-b (second host material) and a compound BD-a (first luminescent compound), the first evaluation device is produced by the following procedure.

The compound BH-a (first host material) and the compound TADF-a (first sensitizing material) are co-deposited on a glass substrate having an ITO transparent electrode (anode) so as to cover the transparent electrode, thereby forming the first sensitizing layer. The ratios of the compound BH-a and the compound TADF-a in the first sensitizing layer are 75 mass % and 25 mass %, respectively.

The compound BH-b (second host material) and the compound BD-a (first luminescent compound) are co-deposited on the first sensitizing layer to form the first emitting layer. The ratios of the compound BH-b and the compound BD-a in the first emitting layer are 99 mass % and 1 mass %, respectively.

Metal aluminum (Al) is vapor-deposited on the first emitting layer to form a metal cathode.

An arrangement of the first evaluation device is roughly shown as follows. ITO(130)/BH-a:TADF-a (5,75%:25%)/BH-b:BD-a (20,99%:1%)/Al(50)

Numerals in parentheses represent a film thickness (nm).

### Production of Second Evaluation Device

For instance, in a case where the second emitting region included in the second emitting unit has the same arrangement as in Example 13 described later, the second evaluation device is produced by the same procedure as the first evaluation device. Since the first emitting region and the second emitting region in Example 13 described later have the same arrangement, the second evaluation device also has the same arrangement as the first evaluation device.

In an exemplary arrangement of the second exemplary embodiment, when the first evaluation device emits light, the first evaluation device including the emitting region that has the same arrangement as the first emitting region and that is interposed between the anode and the cathode, a delayed fluorescence ratio is larger than 37.5%.

In an exemplary arrangement of the second exemplary embodiment, when the second evaluation device emits light, the second evaluation device including the emitting region that has the same arrangement as the second emitting region and that is interposed between the anode and the cathode, a delayed fluorescence ratio is larger than 37.5%.

The delayed fluorescence ratio is calculated using the first or second evaluation device produced by the above-described procedure according to the “calculation method of the delayed fluorescence ratio” described in the first exemplary embodiment.

In an exemplary arrangement of the second exemplary embodiment, the first sensitizing material is a delayed fluorescent material.

In an exemplary arrangement of the second exemplary embodiment, the second sensitizing material is a delayed fluorescent material.

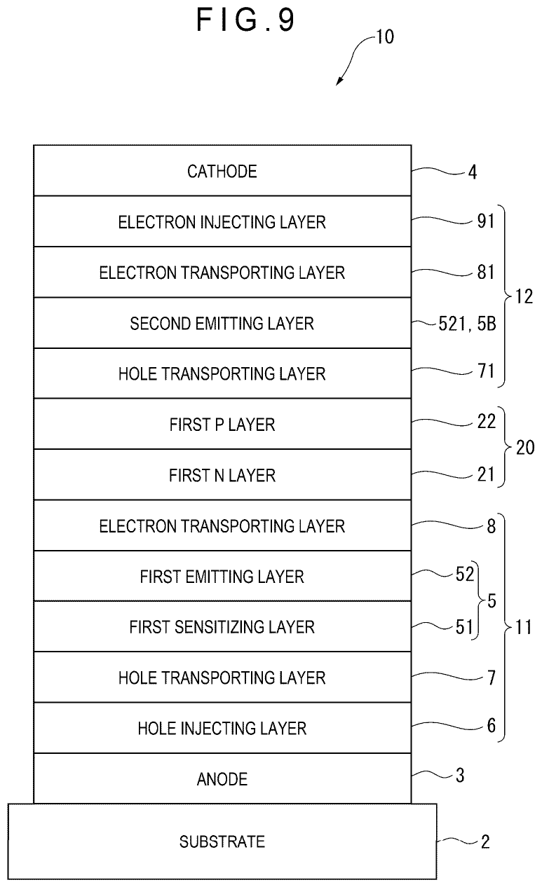

FIG. 9 schematically illustrates an organic EL device 10 as an example (the above exemplary arrangement 1) of the tandem organic EL device according to the second exemplary embodiment. The organic EL device 10, which is a tandem organic EL device, includes a first emitting unit 11 and a second emitting unit 12 as two emitting units. The organic EL device 10 includes a substrate 2, a cathode 4, an anode 3, a first charge generating layer (charge generating unit) 20 interposed between the cathode 4 and the anode 3, the first emitting unit 11 interposed between the first charge generating layer 20 and the anode 3, and the second emitting unit 12 interposed between the first charge generating layer 20 and the cathode 4.

In the organic EL device 10, the first emitting unit 11 and the second emitting unit 12 are connected in series via the first charge generating layer 20. The first charge generating layer 20 includes a first N layer 21 that supplies electrons to a layer disposed close to the anode 3 and a first P layer 22 that supplies holes to a layer disposed close to the cathode. The first emitting region 5 includes a first sensitizing layer 51 close to the anode 3 and a first emitting layer 52 close to the cathode 4. The second emitting region 5B includes a second emitting layer 521.

In a case illustrated in FIG. 9, the first emitting region 5 corresponds to an emitting region of the first exemplary embodiment.

FIG. 10 schematically illustrates an organic EL device 10A as another example (the above exemplary arrangement 3) of a tandem organic EL device according to the second exemplary embodiment.

The organic EL device 10A is different from the organic EL device 10 in that a second emitting region 5C of a second emitting unit 12A further includes a second sensitizing layer 511 close to the anode 3, and otherwise are the same as the organic EL device 10.

The organic layer 10A includes the hole injecting layer 6, the hole transporting layer 7, the first sensitizing layer 51, the first emitting layer 52, the first N layer 21, the first P layer 22, the hole transporting layer 71, the second sensitizing layer 511, the second emitting layer 521, the electron transporting layer 81, and the electron injecting layer 91 that are layered in this order from a side close to the anode 3. The second emitting region 5C includes the second sensitizing layer 511 close to the anode 3 and the second emitting layer 521 close to the cathode 4. The arrangement of the second emitting region 5C may be the same as or different from that of the first emitting region 5.

In a case illustrated in FIG. 10, at least one of the first emitting region 5 or the second emitting region 5C is the emitting region of the first exemplary embodiment.

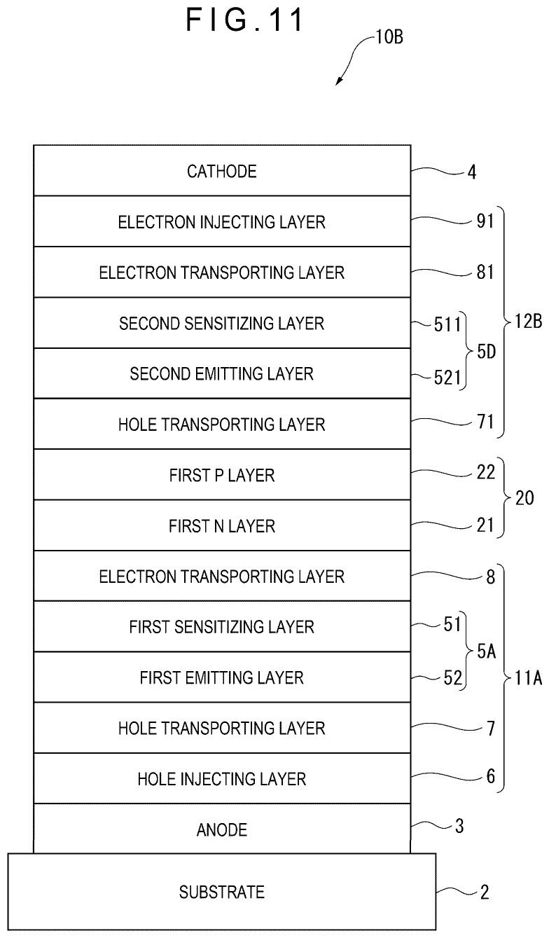

FIG. 11 schematically illustrates an organic EL device 10B as still another example (the above exemplary arrangement 4) of the organic EL device according to the second exemplary embodiment.

The organic EL device 10B is different from the organic EL device 10A in that the first sensitizing layer 51 is provided close to the cathode 4 and the first emitting layer 52 is provided close to the anode 3 in a first emitting region 5A, and the second sensitizing layer 511 is provided close to the cathode 4 and the second emitting layer 521 is provided close to the anode 3 in a second emitting region 5D. The organic EL device 10B is otherwise the same as the organic EL device 10A.

The organic EL device 10B includes the hole injecting layer 6, the hole transporting layer 7, the first emitting layer 52, the first sensitizing layer 51, the first N layer 21, the first P layer 22, the hole transporting layer 71, the second emitting layer 521, the second sensitizing layer 511, the electron transporting layer 81, and the electron injecting layer 91 that are layered in this order from a side close to the anode 3. The second emitting region 5D includes the second sensitizing layer 511 close to the cathode 4 and the second emitting layer 521 close to the anode 3. The arrangement of the second emitting region 5D may be the same as or different from that of the first emitting region 5A.

In a case illustrated in FIG. 11, at least one of the first emitting region 5A or the second emitting region 5D is the emitting region of the first exemplary embodiment.

The invention is not limited to the exemplary arrangements of the organic EL devices illustrated in FIGS. 9 to 11. Another arrangement of the organic EL device is exemplified by, in the organic EL devices illustrated in FIGS. 9 to 11, an arrangement where the first emitting region and the second emitting region are interchanged and an arrangement where a third emitting unit is further included.

For instance, in the arrangement where the third emitting unit is further included in the organic EL devices illustrated in FIGS. 9 to 11, it is sufficient that the emitting region included in at least one of the emitting units is the emitting region of the first exemplary embodiment.

The organic EL device according to any of the above exemplary embodiments may be a bottom emission type organic EL device.

The organic EL device according to any of the above exemplary embodiments may be a top emission type organic EL device.

In the second exemplary embodiment, the organic layer of the first emitting unit may consist of the first sensitizing layer and the first emitting layer, alternatively, may further include, for instance, at least one layer selected from the group consisting of the hole injecting layer, hole transporting layer, electron injecting layer, electron transporting layer, hole blocking layer, and electron blocking layer.

In the second exemplary embodiment, the organic layer of the second emitting unit may consist of the second emitting layer, or may consist of the second sensitizing layer and the second emitting layer, alternatively, may further include, for instance, at least one layer selected from the group consisting of the hole injecting layer, hole transporting layer, electron injecting layer, electron transporting layer, hole blocking layer, and electron blocking layer.

In the second exemplary embodiment, two or more emitting units also preferably include the first emitting unit including the first emitting region (the emitting region of the first exemplary embodiment) and at least one phosphorescent unit different from the first emitting unit. The phosphorescent unit preferably contains a phosphorescent compound that emits phosphorescence. The phosphorescent compound is preferably a metal complex. The metal complex as the phosphorescent compound is preferably an iridium complex, copper complex, platinum complex, osmium complex, or gold complex.

The phosphorescent unit preferably includes at least one phosphorescent layer containing a phosphorescent compound. The phosphorescent unit may have two or more phosphorescent layers. In a case where the phosphorescent unit has two or more phosphorescent layers, the phosphorescent layers may be in direct contact with each other or may not be in contact with each other.

The phosphorescent unit preferably includes a green phosphorescent layer containing a phosphorescent compound that emits green light and a red phosphorescent layer containing a phosphorescent compound that emits red light. Herein, the green light emission refers to light emission in which the maximum peak wavelength of emission spectrum is in a range from 500 nm to 550 nm. Herein, the red light emission refers to light emission in which the maximum peak wavelength of emission spectrum is in a range from 600 nm to 640 nm.

A tandem organic EL device of the second exemplary embodiment also preferably includes the first emitting unit including the first emitting region and one phosphorescent unit.

A tandem organic EL device of the second exemplary embodiment also preferably includes no phosphorescent unit.

### Common Arrangement Among all Exemplary Embodiments

Components applicable in common in all the exemplary embodiments herein will be described below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Moreover, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include indium tin oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

In a case of a bottom emission type organic EL device, the anode is preferably made of a light-transmissive or semi-transmissive metallic material that transmits light emitted from the emitting layer. Herein, the light-transmissive or semi-transmissive property means the property of allowing transmissivity of 50% or more (preferably 80% or more) of the light emitted from the emitting layer. The light-transmissive or semi-transmissive metallic material can be selected in use as needed from the above materials listed in the description regarding the anode.

In a case of a top emission type organic EL device, the anode is a reflective electrode having a reflective layer. The reflective layer is preferably made of a metallic material having light reflectivity. Herein, the light reflectivity means the property of reflecting 50% or more (preferably 80% or more) of the light emitted from the emitting layer. The metallic material having light reflectivity can be selected in use as needed from the above materials listed in the description about the anode.

The anode may consist of the reflective layer, but may have a multilayer structure having the reflective layer and a conductive layer (preferably a transparent conductive layer). In a case where the anode has the reflective layer and the conductive layer, the conductive layer is preferably disposed between the reflective layer and the hole transporting zone. A material of the conductive layer can be selected in use as needed from the above materials listed in the description regarding the anode.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

In a case of a bottom emission type organic EL device, the cathode is a reflective electrode. The reflective electrode is preferably made of a metallic material having light reflectivity. The metallic material having light reflectivity can be selected in use as needed from the above materials listed in the description regarding the cathode.

In a case of a top emission type organic EL device, the cathode is preferably made of a light-transmissive or semi-transmissive metallic material that transmits light emitted from the emitting layer. The light-transmissive or semi-transmissive metallic material can be selected in use as needed from the above materials listed in the description regarding the cathode.

### Capping Layer

In a case of a top emission type organic EL device, the organic EL device usually includes a capping layer on the top of the cathode.

The capping layer may contain, for instance, at least one compound selected from the group consisting of a high polymer compound, metal oxide, metal fluoride, metal boride, silicon nitride, and silicon compound (silicon oxide or the like).

The capping layer may contain, for instance, at least one compound selected from the group consisting of an aromatic amine derivative, an anthracene derivative, a pyrene derivative, a fluorene derivative, and a dibenzofuran derivative.

In addition, a laminate in which layers containing these substances are layered can also be used as the capping layer.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance include: an aromatic amine compound, which is a low-molecule organic compound, such that 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl(abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine](abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) are also usable.

### Hole Transporting Layer

The hole transporting layer is a layer containing a highly hole-transporting substance. An aromatic amine compound, carbazole derivative, anthracene derivative and the like are usable for the hole transporting layer. Specific examples of a material for the hole transporting layer include 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer, a carbazole derivative such as CBP, 9-[4-(N-carbazolyl)]phenyl-10-phenylanthracene (CzPA), and 9-phenyl-3-[4-(10-phenyl-9-anthryl)phenyl]-9H-carbazole (PCzPA) and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

### Electron Transporting Layer

The electron transporting layer is a layer containing a highly electron-transporting substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq3), bis(10-hydroxybenzo[h]quinolinato)beryllium (abbreviation: BeBq2), BAIq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is preferably usable. The above-described substances mostly have an electron mobility of 10⁻⁶ cm²/(V·s) or more. It should be noted that any substance other than the above substance may be used for the electron transporting layer as long as the substance exhibits a higher electron transportability than the hole transportability. The electron transporting layer may be provided in the form of a single layer or a laminate of two or more layers of the above substance(s).

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

The film thickness of each layer of the organic layer of the organic EL device in the exemplary embodiment is not limited unless otherwise specified in the above. In general, the thickness preferably ranges from several nanometers to 1 μm because an excessively small film thickness is likely to cause defects (e.g. pin holes) and an excessively large thickness leads to the necessity of applying high voltage and consequent reduction in efficiency.

### Third Exemplary Embodiment

### Organic Electroluminescence Apparatus

An organic EL apparatus according to a third exemplary embodiment includes an organic EL device according to any one of the above exemplary embodiments and a power source, in which the power source includes a power generating element that generates a potential difference or an electric current by an external stimulus.

Examples of the external stimulus include light, radio waves, heat, pressure, and sound waves.

The power generating element preferably generates a potential difference or an electric current that is less than energy of light emitted from the organic EL device.

The organic EL apparatus according to the third exemplary embodiment functions as an apparatus that converts the above external stimulus into light emission.

The organic EL apparatus according to the third exemplary embodiment, which includes an organic EL device that emits light by only application of a low light-emission start voltage (low voltage), can cause the organic EL device to emit light at a low voltage using an external stimulus of energy, which is previously unavailable, by combining the organic EL device and a power generating element.

In the organic EL apparatus according to the third exemplary embodiment, the power source may further include a power storing element capable of storing electricity.

The power storing element is exemplified by an element capable of charging and discharging electricity repeatedly, such as capacitors and various types of storage batteries.

In an exemplary arrangement according to the third exemplary embodiment, a combination of the organic EL device, the power generating element, and further the power storing element can improve reliability of the organic EL apparatus.

In the organic EL apparatus according to the third exemplary embodiment, the power source may include two or more power generating elements and/or may include two or more power storing elements.

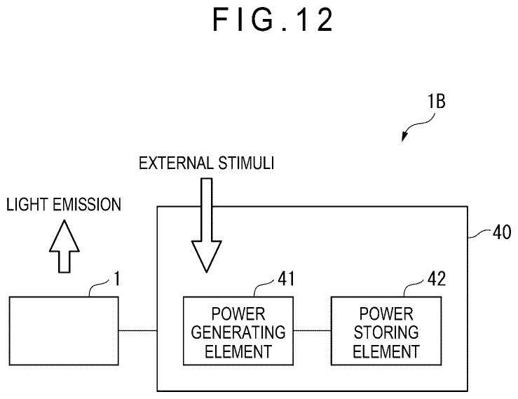

FIG. 12 schematically illustrates an exemplary arrangement of the organic EL apparatus according to the third exemplary embodiment.

An organic EL apparatus 1B includes an organic EL device and a power source 40. The organic EL apparatus 1B illustrated in FIG. 12 includes the organic EL device 1 illustrated in FIG. 3 as an organic EL device.

The power source 40 includes a power generating element 41 and a power storing element 42. The power generating element 41 is connected to the power storing element 42.

The power generating element 41 generates a potential difference or an electric current by an external stimulus. The organic EL apparatus 1B is configured so that the potential difference or the electric current that has been generated by this power generating element 41 is applied to an organic EL device 1.

In a case illustrated in FIG. 12, the potential difference or the electric current that has been generated by the power generating element 41 may be charged in the power storing element 42, thereby being usable as electric power for driving the organic EL device 1. It is also possible that both the power generating element 41 and the power storing element 42 supply electric power simultaneously.

The invention is not limited to a configuration of the organic EL apparatus illustrated in FIG. 12. An organic EL apparatus having another configuration is exemplified by an organic EL apparatus including any one of the organic EL device 1A illustrated in FIG. 4, the organic EL device 10 illustrated in FIG. 9, the organic EL device 10A illustrated in FIG. 10, and the organic EL device 10B illustrated in FIG. 11 in place of the organic EL device 1 in FIG. 12 (the organic EL device 1 illustrated in FIG. 3).

In the organic EL apparatus 1B, it is sufficient that the power source 40 at least includes the power generating element 41. The organic EL apparatus 1B may further include a known power source different from the power source 40 in addition to the power source 40. The organic EL apparatus 1B may include a known power source in place of the power source 40.

### Fourth Exemplary Embodiment

### Electronic Device

An electronic device according to a fourth exemplary embodiment is installed with the organic EL device according to any of the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light. The light-emitting unit also can be used for a display device, for instance, as a backlight of the display device.

### Fifth Exemplary Embodiment

### Light Emitter

A light emitter according to a fifth exemplary embodiment includes a first sensitizing moiety and a first emitting moiety, in which the first sensitizing moiety includes the first host material and the first sensitizing material, the first emitting moiety includes the second host material and the first luminescent compound, the first host material and the second host material are mutually different, the first sensitizing material and the first luminescent compound are mutually different, a difference ΔST(G1) between the lowest singlet energy S₁(G1) of the first sensitizing material and an energy gap T_{77K}(G1) at 77K of the first sensitizing material satisfies a numerical formula (Numerical Formula 1) below,
the energy gap T_{77K}(G1) at 77K of the first sensitizing material, an energy gap T_{77K}(H1) at 77K of the first host material, and an energy gap T_{77K}(H2) at 77K of the second host material satisfy a relationship represented by a numerical formula (Numerical Formula 2) below, and
the lowest singlet energy S₁(G1) of the first sensitizing material and the lowest singlet energy S₁(BD1) of the first luminescent compound satisfy a relationship of a numerical formula (Numerical Formula 3) below.

$$Δ ST ( G 1 ) = {S}_{1} ( G 1 ) - {T}_{77 K} ( G 1 ) < 0.5 eV \qquad ( Numeric Formula 1 )$$

$${T}_{77 K} ( G 1 ) > {T}_{77 K} ( H 1 ) > {T}_{77 K} ( H 2 ) \qquad ( Numeric Formula 2 )$$

$${S}_{1} ( BD 1 ) > {S}_{1} ( G 1 ) \qquad ( Numeric Formula 3 )$$

The first sensitizing moiety in the light emitter of the fifth exemplary embodiment is similar in arrangement to the first sensitizing layer of the first exemplary embodiment except that a form of the first sensitizing moiety is not limited to a layer or a film, unlike the first sensitizing layer of the first exemplary embodiment.

Likewise, the first emitting moiety in the light emitter of the fifth exemplary embodiment is similar in arrangement to the first emitting layer of the first exemplary embodiment except that a form of the first emitting moiety is not limited to a layer or a film, unlike the first emitting layer of the first exemplary embodiment.

The first host material and the first sensitizing material contained in the “first sensitizing moiety” of the fifth exemplary embodiment represent the same as the first host material and the first sensitizing material contained in the “first sensitizing layer” of the first exemplary embodiment. The second host material and the first luminescent compound contained in the “first emitting moiety” of the fifth exemplary embodiment represent the same as the second host material and the first luminescent compound contained in the “first emitting layer” of the first exemplary embodiment.

In the light emitter of the fifth exemplary embodiment, the first sensitizing material contained in the first sensitizing moiety has a small ΔST in principle and a higher light absorption intensity than a phosphorescent complex, resulting in having a suitable performance as the sensitizing material. Accordingly, the light emitter of the fifth exemplary embodiment has a low light-emission start voltage and emits light with high efficiency for the same reason as that in the first exemplary embodiment.

In an exemplary arrangement of the light emitter of the fifth exemplary embodiment, a difference ΔST(G1) between the lowest singlet energy S₁(G1) of the first sensitizing material and the energy gap T_{77K}(G1) at 77K of the first sensitizing material satisfies any one of relationships represented by numerical formulae (Numerical Formula 11A to Numerical Formula 11D) below.

In an exemplary arrangement of the light emitter of the fifth exemplary embodiment, the energy gap T_{77K}(G1) at 77K of the first sensitizing material and the energy gap T_{77K}(H1) at 77K of the first host material satisfy a relationship represented by the numerical formula (Numerical Formula 21).

In an exemplary arrangement of the light emitter of the fifth exemplary embodiment, the energy gap T_{77K}(G1) at 77K of the first sensitizing material and the energy gap T_{77K}(H1) at 77K of the first host material satisfy a relationship represented by the numerical formula (Numerical Formula 21A).

In an exemplary arrangement of the light emitter of the fifth exemplary embodiment, the energy gap T_{77K}(H1) at 77K of the first host material and the energy gap T_{77K}(H2) at 77K of the second host material satisfy a relationship represented by the numerical formula (Numerical Formula 22).

In an exemplary arrangement of the light emitter of the fifth exemplary embodiment, the energy gap T_{77K}(H1) at 77K of the first host material and the energy gap T_{77K}(H2) at 77K of the second host material satisfy a relationship represented by the numerical formula (Numerical Formula 22A).

In an exemplary arrangement of the light emitter of the fifth exemplary embodiment, the first sensitizing layer and the first emitting layer are in direct contact with each other.

In an exemplary arrangement of the light emitter of the fifth exemplary embodiment, the first sensitizing moiety includes the first sensitizing layer and the first emitting moiety includes the first emitting layer.

In an exemplary arrangement of the light emitter of the fifth exemplary embodiment, an interposed region is provided between the first sensitizing moiety and the first emitting moiety.

Since the interposed region with this arrangement is similar in arrangement to the interposed layer described in the first exemplary embodiment, the interposed layer in the fifth exemplary embodiment can be incorporated in place of the interposed region in the first exemplary embodiment.

In an exemplary arrangement of the light emitter of the fifth exemplary embodiment, the light emitter has a layered structure in which the first sensitizing layer and the first emitting layer are regarded as a single repeating unit and two or more repeating units are layered.

### Form of Light Emitter

A form of the light emitter of the fifth exemplary embodiment is not limited to a particular one, but may be, for instance, a film and powder.

A “film” as the form of the light emitter is not limited to a particular one as long as the “film” includes the first sensitizing layer and the first emitting layer in the first exemplary embodiment. “Powder” as the form of the light emitter is obtained by pulverizing the “film” as the form of the light emitter.

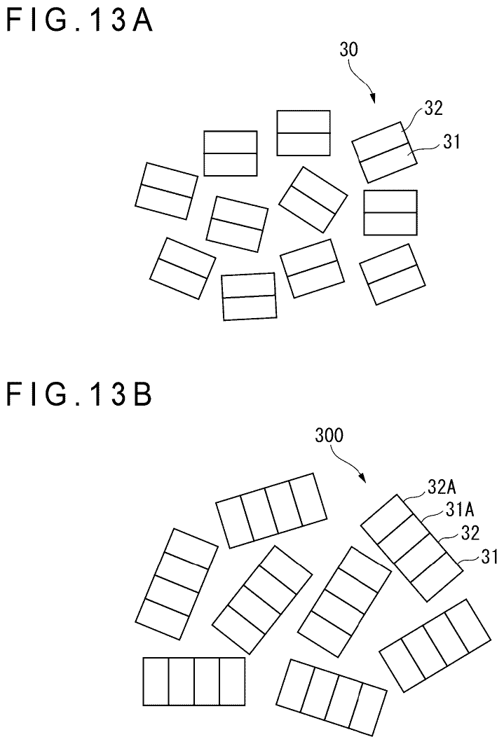

FIG. 13A schematically illustrates an exemplary arrangement of the light emitter according to the fifth exemplary embodiment.

The form of the light emitter in FIG. 13A is powder. Powder 30 as the light emitter includes a first sensitizing moiety 31 and a first emitting moiety 32. The first sensitizing moiety 31 and the first emitting moiety 32 are preferably in direct contact with each other. The first sensitizing moiety 31 and the first emitting moiety 32 form a single repeating unit.

FIG. 13B schematically illustrates another exemplary arrangement of the light emitter according to the fifth exemplary embodiment.

The form of the light emitter in FIG. 13B is powder. Powder 300 as the light emitter has a layered structure in which the first repeating unit formed by the first sensitizing moiety 31 and the first emitting moiety 32 and the second repeating unit formed by a first sensitizing moiety 31A and a first emitting moiety 32A are layered.

The respective opposing surfaces of the first sensitizing moiety 31, the first emitting moiety 32, the first sensitizing moiety 31A, and the first emitting moiety 32A are preferably in direct contact with each other.

The invention is not limited to the forms and the arrangements of the light emitters illustrated in FIGS. 13A and 13B. Examples of another arrangement of the light emitter include an arrangement in which three or more repeating units are layered: the arrangement of FIG. 13A further including an interposed region between the first sensitizing moiety 31 and the first emitting moiety 32; and the arrangement of FIG. 13B further including interposed regions respectively between the first sensitizing moiety 31 and the first emitting moiety 32 and between the first sensitizing moiety 31A and the first emitting moiety 32A.

### Use of Light Emitter

The light emitter of the fifth exemplary embodiment is usable, for instance, as a sensitizing material for a solar cell, a sensitizing material for a light sensor, an emitting region of an organic EL device (where a sensitizing layer and an emitting layer are layered), and a sensitizing material for a photocatalyst. The light emitter of the fifth exemplary embodiment is also usable as a pigment for a special ink that emits light at a specific wavelength.

For instance, coating the surface of a solar cell with “powder” as the form of the light emitter can convert wavelengths unavailable to the solar cell into effective wavelengths, thereby improving conversion efficiency of the solar cell.

Applying “powder” as the form of light emitter to a light receiver of a light sensor can expand a sensing wavelength to improve sensitivity, or add selectivity to a specific wavelength.

Using “powder” as the form of the light emitter can form the emitting region of the organic EL device as a film. Using the light emitter of the fifth exemplary embodiment to form the emitting region of the organic EL device as a film can provide an organic EL device that emits light with a low light-emission start voltage and high efficiency.

Coating a surface of a photocatalyst with “powder” as the form of the light emitter can cause a catalytic action under light irradiation, for instance, at wavelengths ranging from visible light to an infrared region.

### Fifth Exemplary Embodiment

### Solar Cell

A solar cell according to the fifth exemplary embodiment is installed with the light emitter according to the fifth exemplary embodiment.

A solar cell, which is not limited to a particular one, is exemplified by a monocrystalline silicon solar cell, polycrystalline silicon solar cell, thin-film silicon solar cell (e.g., amorphous silicon and microcrystalline silicon), multi-junction solar cell (e.g., heterojunction solar cell and HIT (registered trademark) solar cell), solar cell using a multi-element compound semiconductor (e.g., CIS solar cell and CIGS solar cell), III-V group multi-junction solar cell (e.g., GaAs group solar cell), dye-sensitized solar cell, organic semiconductor solar cell, and quantum dot solar cell.

### Sixth Exemplary Embodiment

### Light Sensor

A light sensor according to a sixth exemplary embodiment is installed with the light emitter according to the fifth exemplary embodiment.

The light sensor, which is not limited to a particular one, is exemplified by a CCD image sensor, CMOS image sensor, photodiode, photo transistor, and photo resistor.

### Modification of Embodiment(s)

In any one of the above exemplary embodiments, for instance, the number of the emitting layer included in the emitting region or the light emitter is not limited to one, but two or more emitting layers may be layered.

For instance, in a case where the emitting region of the first exemplary embodiment includes two or more emitting layers, any other emitting layer(s) than the first emitting layer may be a fluorescent layer or a phosphorescent layer with use of emission caused by electron transfer from the triplet state directly to the ground state.

In a case where the emitting region includes a plurality of emitting layers, these emitting layers may be mutually adjacently provided.

The scope of the invention is not limited by the above-described exemplary embodiments but includes any modification and improvement as long as such modification and improvement are compatible with the invention.

Specific structure, shape and the like of the components in the invention may be designed in any manner as long as an object of the invention can be achieved.

### EXAMPLES

The invention will be described in further detail with reference to Examples. The scope of the invention is by no means limited to Examples.

### Compounds

Structures of the first sensitizing material and the second sensitizing material used for producing organic EL devices in Examples are shown below.

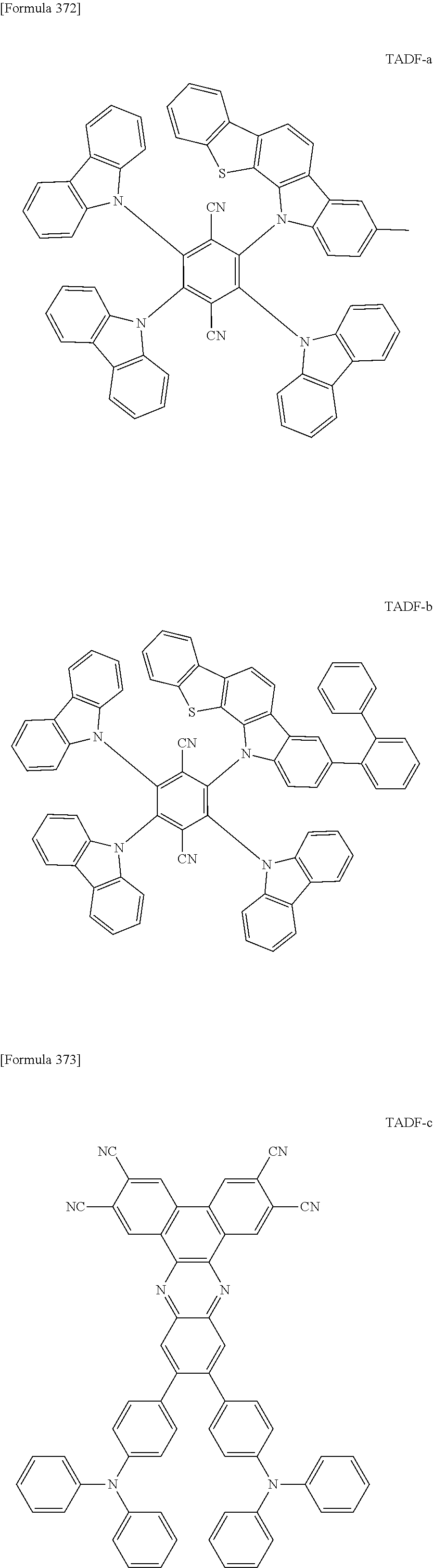 [SMILES: Cc1ccc2c(c1)c1ccc3c4ccccc4sc3c1n2-c1c(C#N)c(-n2c3ccccc3c3ccccc32)c(-n2c3ccccc3c3ccccc32)c(C#N)c1-n1c2ccccc2c2ccccc21 ; N#Cc1c(-n2c3ccccc3c3ccccc32)c(-n2c3ccccc3c3ccccc32)c(C#N)c(-n2c3ccc(-c4ccccc4-c4ccccc4)cc3c3ccc4c5ccccc5sc4c32)c1-n1c2ccccc2c2ccccc21 ; N#Cc1cc2c3cc(C#N)c(C#N)cc3c3nc4cc(-c5ccc(N(c6ccccc6)c6ccccc6)cc5)c(-c5ccc(N(c6ccccc6)c6ccccc6)cc5)cc4nc3c2cc1C#N]

A structure of the sensitizing material used for producing organic EL devices in Comparatives is shown below.

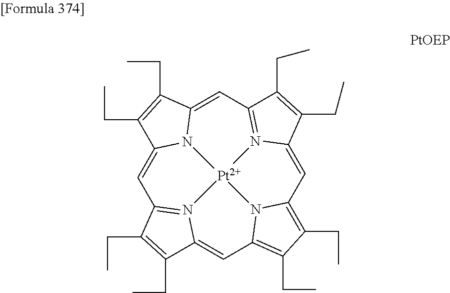

Structures of the first luminescent compound and the second luminescent compound used for producing the organic EL devices in Examples and Comparatives are shown below.

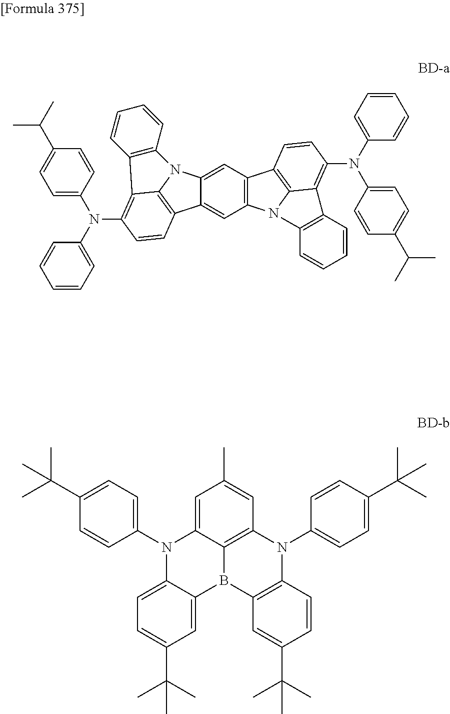

Structures of the first host material and the second host material used for producing the organic EL devices in Examples and Comparatives are shown below.

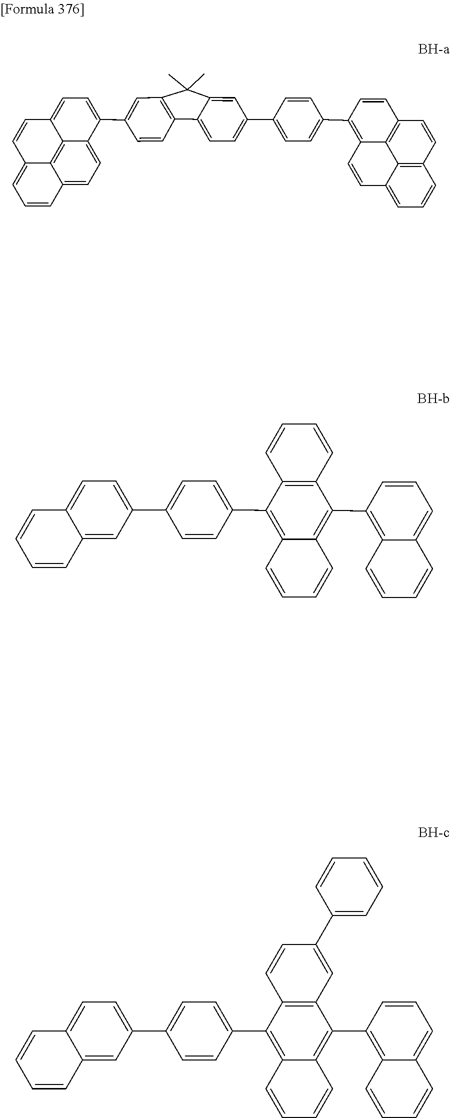

Structures of other compounds used for producing the organic EL devices in Examples and Comparatives are shown below.

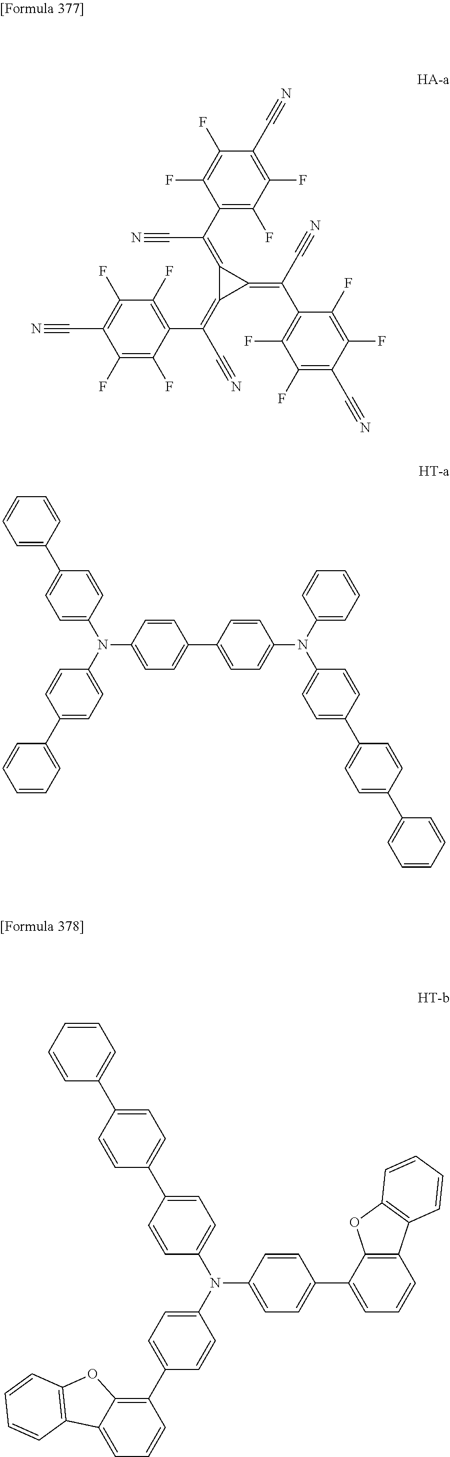 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

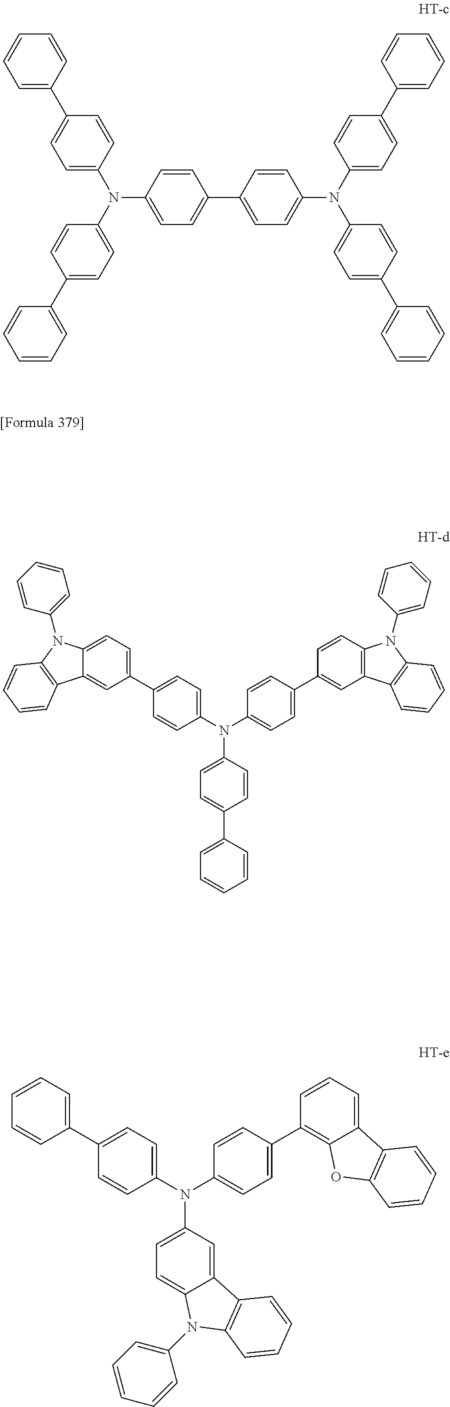 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccc5c(c4)c4ccccc4n5-c4ccccc4)cc3)c3ccc(-c4ccc5c(c4)c4ccccc4n5-c4ccccc4)cc3)cc2)cc1 ; c1ccc(-c2ccc(N(c3ccc(-c4cccc5c4oc4ccccc45)cc3)c3ccc4c(c3)c3ccccc3n4-c3ccccc3)cc2)cc1]

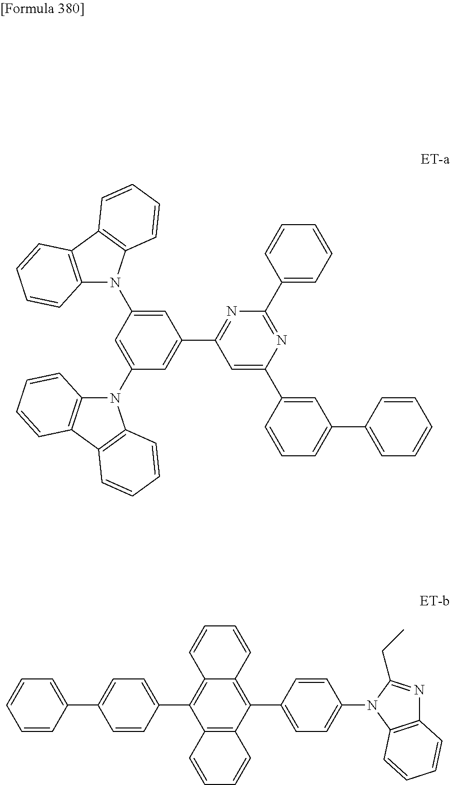 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; CCc1nc2ccccc2n1-c1ccc(-c2c3ccccc3c(-c3ccc(-c4ccccc4)cc3)c3ccccc23)cc1]

### Production 1 of Organic EL Device

### Example 1

A glass substrate (size: 25 mm×75 mm×1.1 mm thick, produced by Geomatec Co., Ltd.) having an indium tin oxide (ITO) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, a compound HT-a and a compound HA-a were co-deposited on a surface of the glass substrate where the transparent electrode line was provided in a manner to cover the transparent electrode, thereby forming a 10-nm-thick hole injecting layer. Ratios of the compound HT-a and the compound HA-a in the hole injecting layer were 97 mass % and 3 mass %, respectively.

The compound HT-a was vapor-deposited on the hole injecting layer to form an 80-nm-thick first hole transporting layer.

A compound HT-b was vapor-deposited on the first hole transporting layer to form a 10-nm-thick second hole transporting layer (occasionally also referred to as an electron blocking layer (EBL)).

A compound BH-a (first host material) and a compound TADF-a (first sensitizing material) were co-deposited on the second hole transporting layer to form a 5-nm-thick first sensitizing layer. Ratios of the compound BH-a and the compound TADF-a in the first sensitizing layer were 75 mass % and 25 mass %, respectively.

A compound BH-b (second host material) and a compound BD-a (first luminescent compound) were co-deposited on the first sensitizing layer to form a 20-nm-thick first emitting layer. Ratios of the compound BH-b and the compound BD-a in the first emitting layer were 99 mass % and 1 mass %, respectively.

A compound ET-a was vapor-deposited on the first emitting layer to form a 10-nm-thick first electron transporting layer (occasionally also referred to as a hole blocking layer (HBL)).

A compound ET-b was vapor-deposited on the first electron transporting layer to form a 15-nm-thick second electron transporting layer (ET).

A compound LiF was vapor-deposited on the second electron transporting layer to form a 1-nm-thick electron injecting layer.

Metal (Al) was vapor-deposited on the electron injecting layer to form a 50-nm-thick cathode.

A device arrangement of the organic EL device in Example 1 is roughly shown as follows.

$$ITO ( 1 \; 30 ) / HT - a : HA - a ( 10.97 \% : 3 \% ) / HT - a ( 80 ) \text{} / HT - b ( 10 ) / BH - a : TADF - a ( 5.75 \% : 25 \% ) / BH - b : BD \text{} - a ( 20.99 \% : 1 \% ) / ET - a ( 10 ) / ET - b ( 15 ) / LiF ( 1 ) / AI ( 50 )$$

Numerals in parentheses represent a film thickness (unit: nm).

The numerals (97%:3%) represented by percentage in the same parentheses indicate a ratio (mass %) between the compound HT-a and the compound HA-a in the hole injecting layer. The numerals (75%:25%) represented by percentage in the same parentheses indicate a ratio (mass %) between the first host material (compound BH-a) and the first sensitizing material (TADF-a) in the first sensitizing layer. The numerals (99%:1%) represented by percentage in the same parentheses indicate a ratio (mass %) between the second host material (compound BH-b) and the first luminescent compound (BD-a) in the first emitting layer. Similar notations apply to the description below.

### Example 2

An organic EL device in Example 2 was produced in the same manner as the organic EL device in Example 1 except that the compound as the first sensitizing material was replaced by a compound listed in Table 1.

### Examples 3 to 4

Organic EL devices in Examples 3 to 4 were produced in the same manner as the organic EL device in Example 1 except that the film thickness of the first sensitizing layer and the film thickness of the first emitting layer were replaced by those listed in Table 1.

### Examples 5 to 6

Organic EL devices in Examples 5 to 6 were produced in the same manner as the organic EL device in Example 1 except that the content of the first host material and the content of the first sensitizing material in the first sensitizing layer were replaced by those listed in Table 1.

### Example 7

An organic EL device in Example 7 was produced in the same manner as the organic EL device in Example 6 except that the film thickness of the first sensitizing layer and the film thickness of the first emitting layer were replaced by those listed in Table 1.

### Example 8

An organic EL device in Example 8 was produced in the same manner as the organic EL device in Example 1 except that the first luminescent compound was replaced by a compound listed in Table 1.

### Example 9

An organic EL device in Example 9 was produced in the same manner as the organic EL device in Example 1 except that the first host material and the second host material were replaced by those as listed in Table 1.

### Examples 10 to 12

Organic EL devices in Examples 10 to 12 were produced in the same manner as the organic EL device in Example 1 except that the arrangement of the electron blocking layer, the film thickness of the first sensitizing layer, and the film thickness of the first emitting layer were replaced by those listed in Table 1.

### Example 14

An organic EL device in Example 14 was produced in the same manner as the organic EL device in Example 1 except that the first sensitizing material was replaced by a compound listed in Table 1.

### Comparative 1

An organic EL device in Comparative 1 was produced in the same manner as the organic EL device in Example 1 except that the compound BH-b (second host material) and the compound BD-a (first luminescent compound) were co-deposited on the electron blocking layer to form a 25-nm-thick first emitting layer.

### Comparative 2

An organic EL device in Comparative 2 was produced in the same manner as the organic EL device in Example 1 except that the first sensitizing material was replaced by a compound listed in Table 1.

### Evaluation of Organic EL Devices

The organic EL devices produced were evaluated as follows. Table 1 shows the evaluation results. In Table 1, values in parentheses in the Name column indicate the respective contents of the materials (unit: mass %). The same also applies to Table 2.

### Light-Emission Start Voltage V_{TH}

Voltage applied to each organic EL device was gradually increased, and a current density and a light-emission start voltage V_{TH} (unit: V) were measured when the voltage exceeded 0.01 cd/m² of a value measured by a spectroradiometer CS-2000 (produced by Konica Minolta, Inc.).

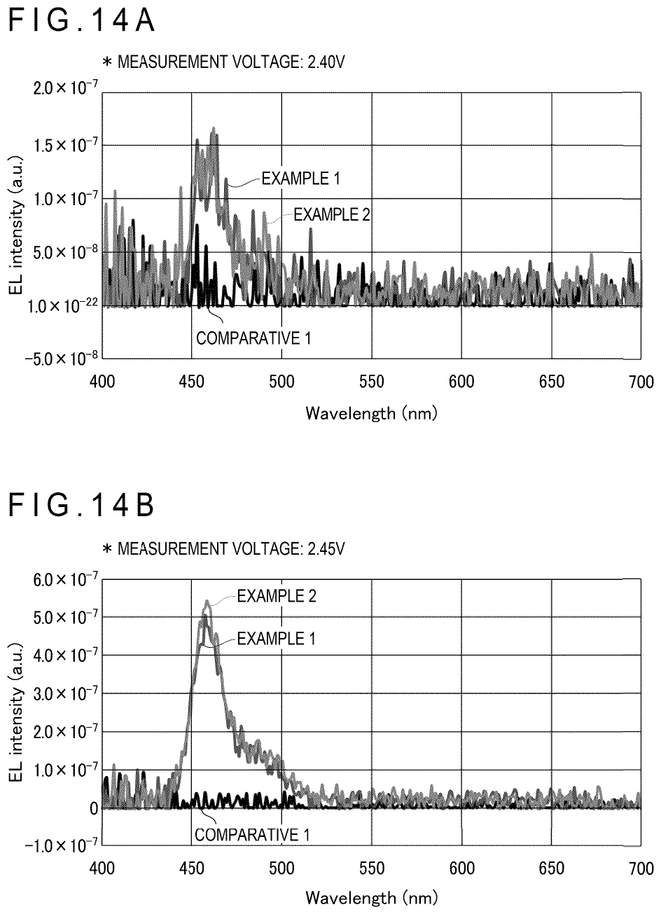

An electric current was applied to each of the organic EL devices in Example 1, Example 2, and Comparative 1 so as to reach 2.40 V and 2.45 V of measurement voltages, where spectral radiance spectra were measured. The obtained spectral radiance spectra are shown in FIGS. 14A and 14B.

### External Quantum Efficiency EQE

Voltage was applied to the organic EL devices such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation.

### Maximum Peak Wavelength λp

Voltage was applied to the organic EL devices such that a current density was 10 mA/cm², where spectral radiance spectrum was measured by a spectroradiometer CS-2000 (produced by Konica Minolta, Inc.). The maximum peak wavelength λp (unit: nm) was calculated from the obtained spectral radiance spectrum.

E_{TH}−E_{PE}

Using the above-described numerical formula (Numerical Formula Y₁), E_{TH} (energy imparted to the device when a luminance of 0.01 cd/m² was obtained) was determined from the light-emission start voltage V_{TH}.

As energy E_{PE} at peak of an emission spectrum, a measurement value of the lowest singlet energy S₁ of the luminescent compound contained in the corresponding emitting layer for the measurement was used.

“E_{TH}−E_{PE} (unit: eV) was calculated from the obtained values of E_{TH} and E_{PE}.

### Delayed Fluorescence Ratio

A delayed fluorescence ratio of each of the organic EL devices produced in Example 1, Example 2, and Comparative 1 was calculated by the following method.

Voltage pulse waveform (pulse width: 500 microseconds, frequency: 20 Hz, voltage: 2.90 V) output from a pulse generator (8114A: manufactured by Agilent Technologies Inc.) was applied, EL emission was input to a photomultiplier tube (R928: manufactured by Hamamatsu Photonics K.K.), the pulse voltage waveform and the EL emission were synchronized and incorporated into an oscilloscope (2440: manufactured by TEKTRONIX, INC.) to obtain a transient EL waveform. This was fitted to a straight line using values up to 4.0E-05 seconds by the least squares method to determine a delayed fluorescence ratio.

Transient EL waveforms obtained when a voltage of 2.90 V was applied under the room temperature to each of the organic EL devices in Example 1, Example 2, and Comparative 1 are shown in FIG. 8A described above.

The graph in FIG. 8B described above plots the inverse of the square root of the light intensity up to 4.0E-05 seconds after the pulse voltage removal, taking the point of the pulse voltage removal as the origin. A delayed fluorescence ratio of each of the organic EL devices produced in Example 1, Example 2, and Comparative 1 was determined by the above-described method. A value of the delayed fluorescence ratio in Example 1 was more than 99% and a value of the delayed fluorescence ratio in Example 2 was 98.8%. Both the values were more than the theoretical limit of 37.5% of the TTF ratio. A value of a delayed fluorescence ratio of the organic EL device in Comparative 1 was 1.3%.

Organic EL devices in other examples were also determined in terms of a delayed fluorescence ratio by the similar method. Table 1 shows the results. In Table 1, “-” in a column of the device evaluation indicates no measurement.

TABLE 1

| | Electron blocking | | First sensitizing layer | | | | | | | | |
|---|---|---|---|---|---|---|---|---|---|---|---|
| | layer | | First host material | | | First sensitizing material | | | | Film | First emitting layer |
| | Compound | \|HOMO\| | | T_{77 K} | \|LUMO\| | | T_{77 K} | S₁ | \|LUMO\| | thickness | Second host material |
| | Name | [eV] | Name | [eV] | [eV] | Name | [eV] | [eV] | [eV] | [nm] | Name |
| Ex. 1 | HT-b | 5.66 | BH-a | 2.10 | 1.91 | TADF-a | 2.45 | 2.32 | 3.73 | 5 | BH-b |
| | | | (75%) | | | (25%) | | | | | (99%) |
| Ex. 2 | HT-b | 5.66 | BH-a | 2.10 | 1.91 | TADF-b | 2.46 | 2.34 | 3.96 | 5 | BH-b |
| | | | (75%) | | | (25%) | | | | | (99%) |
| Ex. 3 | HT-b | 5.66 | BH-a | 2.10 | 1.91 | TADF-a | 2.45 | 2.32 | 3.73 | 3 | BH-b |
| | | | (75%) | | | (25%) | | | | | (99%) |
| Ex. 4 | HT-b | 5.66 | BH-a | 2.10 | 1.91 | TADF-a | 2.45 | 2.32 | 3.73 | 1 | BH-b |
| | | | (75%) | | | (25%) | | | | | (99%) |
| Ex. 5 | HT-b | 5.66 | BH-a | 2.10 | 1.91 | TADF-a | 2.45 | 2.32 | 3.73 | 5 | BH-b |
| | | | (50%) | | | (50%) | | | | | (99%) |
| Ex. 6 | HT-b | 5.66 | BH-a | 2.10 | 1.91 | TADF-a | 2.45 | 2.32 | 3.73 | 5 | BH-b |
| | | | (90%) | | | (10%) | | | | | (99%) |
| Ex. 7 | HT-b | 5.66 | BH-a | 2.10 | 1.91 | TADF-a | 2.45 | 2.32 | 3.73 | 1 | BH-b |
| | | | (90%) | | | (10%) | | | | | (99%) |
| Ex. 8 | HT-b | 5.66 | BH-a | 2.10 | 1.91 | TADF-a | 2.45 | 2.32 | 3.73 | 5 | BH-b |
| | | | (75%) | | | (25%) | | | | | (99%) |
| Ex. 9 | HT-b | 5.66 | BH-b | 1.86 | 2.09 | TADF-a | 2.45 | 2.32 | 3.73 | 5 | BH-c |
| | | | (75%) | | | (25%) | | | | | (99%) |
| Comp. 1 | HT-b | 5.66 | — | — | — | — | — | — | — | 0 | BH-b |
| | | | | | | | | | | | (99%) |
| Comp. 2 | HT-b | 5.66 | BH-a | 2.10 | 1.91 | Pt CEP | 1.94 | 2.30 | 3.20 | 5 | BH-b |
| | | | (75%) | | | (25%) | | | | | (99%) |
| Ex. 10 | HT-c | 5.42 | BH-a | 2.10 | 1.91 | TADF-a | 2.45 | 2.32 | 3.73 | 1 | BH-b |
| | | | (90%) | | | (10%) | | | | | (99%) |
| Ex. 11 | HT-d | 5.40 | BH-a | 2.10 | 1.91 | TADF-a | 2.45 | 2.32 | 3.73 | 1 | BH-b |
| | | | (90%) | | | (10%) | | | | | (99%) |
| Ex. 12 | HT-e | 5.39 | BH-a | 2.10 | 1.91 | TADF-a | 2.45 | 2.32 | 3.73 | 1 | BH-b |
| | | | (90%) | | | (10%) | | | | | (99%) |
| Ex. 14 | HT-b | 5.66 | BH-a | 2.10 | 1.91 | TADF-c | 2.12 | 2.05 | 3.84 | 5 | BH-b |
| | | | (75%) | | | (25%) | | | | | (99%) |

| | First emitting layer | | | | | | Device evaluation | | | | |
|---|---|---|---|---|---|---|---|---|---|---|---|
| | Second host material | | First luminescent compound | | | Film | Delayed | | | | E_{TH} − |
| | T_{77 K} | \|LUMO\| | | S₁ | \|LUMO\| | thickness | fluorescence | V_{TH} | EQE | λ p | E_{FE} |
| | [eV] | [eV] | Name | [eV] | [eV] | [nm] | ratio [%] | [V] | [%] | [nm] | [eV] |
| Ex. 1 | 1.86 | 2.09 | BD-a | 2.73 | 1.91 | 20 | >99 | 2.50 | 3.1 | 458 | −0.20 |
| | | | (1%) | | | | | | | | |
| Ex. 2 | 1.86 | 2.09 | BD-a | 2.73 | 1.91 | 20 | 98.8 | 2.50 | 3.5 | 459 | −0.20 |
| | | | (1%) | | | | | | | | |
| Ex. 3 | 1.86 | 2.09 | BD-a | 2.73 | 1.91 | 22 | >99 | 2.50 | 3.4 | 459 | −0.20 |
| | | | (1%) | | | | | | | | |
| Ex. 4 | 1.86 | 2.09 | BD-a | 2.73 | 1.91 | 24 | >99 | 2.50 | 3.6 | 459 | −0.20 |
| | | | (1%) | | | | | | | | |
| Ex. 5 | 1.86 | 2.09 | BD-a | 2.73 | 1.91 | 20 | >99 | 2.50 | 2.3 | 459 | −0.20 |
| | | | (1%) | | | | | | | | |
| Ex. 6 | 1.86 | 2.09 | BD-a | 2.73 | 1.91 | 20 | >99 | 2.45 | 3.8 | 459 | −0.25 |
| | | | (1%) | | | | | | | | |
| Ex. 7 | 1.86 | 2.09 | BD-a | 2.73 | 1.91 | 24 | >99 | 2.45 | 4.2 | 459 | −0.25 |
| | | | (1%) | | | | | | | | |
| Ex. 8 | 1.86 | 2.09 | BD-b | 2.71 | 1.53 | 20 | >99 | 2.40 | 2.6 | 459 | −0.30 |
| | | | (1%) | | | | | | | | |
| Ex. 9 | 1.82 | 2.15 | BD-a | 2.73 | 1.91 | 20 | >99 | 2.50 | 2.2 | 459 | −0.20 |
| | | | (1%) | | | | | | | | |
| Comp. 1 | 1.86 | 2.09 | BD-a | 2.73 | 1.91 | 25 | 1.3 | 2.80 | 10.0 | 459 | 0.10 |
| | | | (1%) | | | | | | | | |
| Comp. 2 | 1.86 | 2.09 | BD-a | 2.73 | 1.91 | 20 | — | 2.90 | <0.1 | 459 | 0.20 |
| | | | (1%) | | | | | | | | |
| Ex. 10 | 1.86 | 2.09 | BD-a | 2.73 | 1.91 | 24 | >99 | 2.40 | 3.8 | 459 | −0.30 |
| | | | (1%) | | | | | | | | |
| Ex. 11 | 1.86 | 2.09 | BD-a | 2.73 | 1.91 | 24 | >99 | 2.40 | 4.0 | 459 | −0.30 |
| | | | (1%) | | | | | | | | |
| Ex. 12 | 1.86 | 2.09 | BD-a | 2.73 | 1.91 | 24 | >99 | 2.40 | 3.7 | 459 | −0.30 |
| | | | (1%) | | | | | | | | |
| Ex. 14 | 1.86 | 2.09 | BD-a | 2.73 | 1.91 | 20 | >99 | 2.20 | 2.5 | 458 | −0.50 |
| | | | (1%) | | | | | | | | |

It was confirmed from the value of E_{TH}−E_{PE} that upconversion was expressed in each of the organic EL devices of Examples 1 to 12 and 14. In contrast, in each of the organic EL devices in Comparatives 1 and 2, the value of E_{TH}−E_{PE} did not satisfy the numerical formula (Numerical Formula 6).

Each of the organic EL devices in Examples 1 to 12 and 14 exhibited a high value of the delayed fluorescence ratio. In contrast, the organic EL device in Comparative 1 exhibited a low value of the delayed fluorescence ratio. This is considered to be because the emitting region in Comparative 1 containing no sensitizing layer causes an insufficient triplet concentration near the light-emission start voltage V_{TH}, and also because the emitting region in Comparative 1 generating recombination and light-emission in a single layer causes quenching by charge interaction.

In the organic EL device in Comparative 2, the light-emission start voltage V_{TH} was 2.90 V, which was a value exceeding the lowest singlet energy S₁ of the compound BD-a. This suggests that some of the charges are recombined on the compound BD-a in the first light-emitting layer. This is also considered to be because efficient upconversion did not occur due to no occurrence of efficient triplet energy transfer from the first sensitizing layer to the first emitting layer.

Accordingly, the organic EL devices in Examples 1 to 12 and 14 exhibited a low light-emission start voltage V_{TH} and emitted light with high efficiency.

In comparison between Examples 1, 2 and Example 14, Example 14 using the compound TADF-c having a small value of T_{77K}(G1) as the first sensitizing material exhibited a lower light-emission start voltage V_{TH} than that of Examples 1 and 2 using the compounds TADF-a and TADF-b, respectively, as the first sensitizing material.

### Production 2 of Organic EL Device

### Example 13

A glass substrate (size: 25 mm×75 mm×1.1 mm thick, produced by Geomatec Co., Ltd.) having an indium tin oxide (ITO) transparent electrode (anode) was ultrasonic-cleaned in isopropyl alcohol for five minutes, and then UV-ozone-cleaned for 30 minutes. The film thickness of the ITO transparent electrode was 130 nm.

### Formation of First Emitting Unit

After the glass substrate having the transparent electrode line was cleaned, the glass substrate was mounted on a substrate holder of a vacuum deposition apparatus. Firstly, the compound HT-a and the compound HA-a were co-deposited on a surface of the glass substrate where the transparent electrode line was provided in a manner to cover the transparent electrode, thereby forming a 10-nm-thick hole injecting layer. Ratios of the compound HT-a and the compound HA-a in the hole injecting layer were 97 mass % and 3 mass %, respectively.

The compound HT-a was vapor-deposited on the hole injecting layer to form an 80-nm-thick first hole transporting layer.

The compound HT-b was vapor-deposited on the first hole transporting layer to form a 10-nm-thick second hole transporting layer (occasionally also referred to as an electron blocking layer (EBL)).

The compound BH-a (first host material) and the compound TADF-a (first sensitizing material) were co-deposited on the second hole transporting layer to form a 1-nm-thick first sensitizing layer. Ratios of the compound BH-a and the compound TADF-a in the first sensitizing layer were 90 mass % and 10 mass %, respectively.

The compound BH-b (second host material) and the compound BD-a (first luminescent compound) were co-deposited on the first sensitizing layer to form a 24-nm-thick first emitting layer. Ratios of the compound BH-b and the compound BD-a in the first emitting layer were 99 mass % and 1 mass %, respectively.

The compound ET-a was vapor-deposited on the first emitting layer to form a 10-nm-thick first electron transporting layer (occasionally also referred to as a hole blocking layer (HBL)).

The compound ET-b was vapor-deposited on the first electron transporting layer to form a 20-nm-thick second electron transporting layer (ET).

### Formation of Intermediate Unit (First Charge Generating Layer)

Next, lithium (Li) was vapor-deposited on the second electron transporting layer in the first emitting unit to form a 1-nm-thick first N layer.

Then, the compound HT-a and the compound HA-a were co-deposited on the first N layer to form a 10-nm-thick first P layer. Ratios of the compound HT-a and the compound HA-a in the first P layer were 97 mass % and 3 mass %, respectively.

### Formation of Second Emitting Unit

Next, the compound HT-a was vapor-deposited on the first P layer to form an 80-nm-thick first hole transporting layer.

The compound HT-b was vapor-deposited on the first hole transporting layer to form a 10-nm-thick second hole transporting layer (occasionally also referred to as an electron blocking layer (EBL)).

The compound BH-a (fourth host material) and the compound TADF-a (second sensitizing material) were co-deposited on the second hole transporting layer to form a 1-nm-thick second sensitizing layer. Ratios of the compound BH-a and the compound TADF-a in the second sensitizing layer were 90 mass % and 10 mass %, respectively.

The compound BH-b (third host material) and the compound BD-a (second luminescent compound) were co-deposited on the second sensitizing layer to form a 24-nm-thick second emitting layer. Ratios of the compound BH-b and the compound BD-a in the second emitting layer were 99 mass % and 1 mass %, respectively.

The compound ET-a was vapor-deposited on the second emitting layer to form a 10-nm-thick first electron transporting layer (occasionally also referred to as a hole blocking layer (HBL)).

The compound ET-b was vapor-deposited on the first electron transporting layer to form a 20-nm-thick second electron transporting layer (ET).

Next, the compound LiF was vapor-deposited on the second electron transporting layer in the second emitting unit to form a 1-nm-thick electron injecting layer.

Metal (Al) was vapor-deposited on the electron injecting layer to form a 50-nm-thick cathode.

A device arrangement of the organic EL device in Example 13 is roughly shown as follows.

$$ITO ( 1 \; 30 ) / HT - a : HA - a ( 10.97 \% : 3 \% ) / HT - a ( 80 ) / HT - b ( 10 ) \text{} / BH - a : TADF - a ( 1.9 \% : 10 \% ) / BH - b : BD - a ( 24.99 \% : 1 \% ) \text{} / ET - a ( 10 ) / ET - b ( 20 ) / Li ( 1 ) / HT - a : HA - a ( 10.97 \% : 3 \% ) / HT - a ( 80 ) / HT - b ( 10 ) / BH - a : TADF - a ( 1.9 ) : 10 \% ) / BH - b : BD - a ( 24.99 \% : 1 \% ) / ET - a ( 10 ) / ET - b ( 20 ) / LiF ( 1 ) / AI ( 50 )$$

Numerals in parentheses represent a film thickness (unit: nm).

The numerals (90%:10%) represented by percentage in the same parentheses indicate a ratio (mass %) between the fourth host material (compound BH-a) and the second sensitizing material (TADF-a) in the second sensitizing layer. The numerals (99%:1%) represented by percentage in the same parentheses indicate a ratio (mass %) between the third host material (compound BH-b) and the second luminescent compound (BD-a) in the second emitting layer.

### Evaluation of Organic EL Devices

The produced organic EL devices were measured in terms of the light-emission start voltage V_{TH} and the external quantum efficiency EQE by the same method as in Example 1.

A delayed fluorescence ratio, “E_{TH1}−E_{PE1}” and “E_{TH2}−E_{PE2}” were calculated by the same method as in Example 1 using the first evaluation device and the second evaluation device produced by the above-described method. As each of the energy E_{PE1} and the energy E_{PE2} at the peak of the emission spectrum, a measurement value of the lowest singlet energy S₁ of the luminescent compound contained in the corresponding emitting layer for the measurement was used. Table 2 shows the results. In Table 2, the column for the first emitting unit in the “E_{TH}−E_{PE}” row indicates a value of “E_{TH1}−E_{PE1}” and the column for the second emitting unit in the “E_{TH}−E_{PE}” column indicates “E_{TH2}−E_{PE2}.”

TABLE 2

| | | | | Sensitizing layer (first or second) | | | | | | | | |
|---|---|---|---|---|---|---|---|---|---|---|---|---|
| | | Electron blocking | | Host material | | | Sensitizing material | | | | Film | Emitting layer (first or second) |
| | | layer | | (first or fourth) | | | (first or second) | | | | thick- | Host material |
| | | Compound | \|HOMO\| | | T_{77 K} | \|LUMO\| | | T_{77 K} | S₁ | \|LUMO\| | ness | (second or third) |
| | | Name | [eV] | Name | [eV] | [eV] | Name | [eV] | [eV] | [eV] | [nm] | Name |
| Ex. 13 | First | HT-b | 5.66 | BH-a | 2.10 | 1.91 | TADF-a | 2.45 | 2.32 | 3.73 | 1 | BH-b |
| | emitting | | | (75%) | | | (25%) | | | | | (99%) |
| | unit | | | | | | | | | | | |
| | Second | HT-b | 5.66 | BH-a | 2.10 | 1.91 | TADF-a | 2.45 | 2.32 | 3.73 | 1 | BH-b |
| | emitting | | | (75%) | | | (25%) | | | | | (99%) |
| | unit | | | | | | | | | | | |

| | | Emitting layer (first or second) | | | | | | | | | | |
|---|---|---|---|---|---|---|---|---|---|---|---|---|
| | | Host material | | Luminescent compound | | | Film | Device evaluation | | | | |
| | | (second or third) | | (first or second) | | | thick- | | | Delayed | | E_{TH} − |
| | | T_{77 K} | \|LUMO\| | | S₁ | \|LUMO\| | ness | V_{TH} | EQE | fluorescence | λ p | E_{FE} |
| | | [eV] | [eV] | Name | [eV] | [eV] | [nm] | [V] | [%] | ratio [%] | [nm] | [eV] |
| Ex. 13 | First | 1.86 | 2.09 | BD-a | 2.73 | 1.91 | 24 | 5.10 | 8.2 | 100 | 459 | −0.20 |
| | emitting | | | (1%) | | | | | | | | |
| | unit | | | | | | | | | | | |
| | Second | 1.86 | 2.09 | BD-a | 2.73 | 1.91 | 24 | | | 100 | 459 | −0.20 |
| | emitting | | | (1%) | | | | | | | | |
| | unit | | | | | | | | | | | |

It was confirmed from the value of E_{TH1}−E_{PE1} for the first emitting unit and the value of E_{TH2}−E_{PE2} for the second emitting unit that upconversion was expressed in the organic EL device of Example 13. The light-emission start voltage V_{TH} in Example 13 was 2.55 V per emitting unit. A delayed fluorescence ratio of the organic EL device in Example 13 was 100%.

Accordingly, the organic EL device in Example 13 exhibited a low light-emission start voltage V_{TH} and emitted light with high efficiency.

### Evaluation of Compounds

Physical properties of the compounds listed in Tables 1 and 2 were measured by the following method.

### Thermally Activated Delayed Fluorescence

### Delayed Fluorescence of Compound TADF-a

Thermally activated delayed fluorescence was confirmed by measuring transient PL using an apparatus illustrated in FIG. 5. The compound TADF-a was dissolved in toluene to prepare a dilute solution with an absorbance of 0.05 or less at an excitation wavelength for removing the contribution of self-absorption. In order to prevent quenching due to oxygen, the sample solution was frozen and degassed and then sealed in a cell with a lid under an argon atmosphere to obtain an oxygen-free sample solution saturated with argon.

The fluorescence spectrum of the sample solution was measured with a spectrofluorometer FP-8600 (produced by JASCO Corporation), and the fluorescence spectrum of a 9,10-diphenylanthracene ethanol solution was measured under the same conditions. Using the fluorescence area intensities of both spectra, the total fluorescence quantum yield was calculated by an equation (1) in Morris et al. J. Phys. Chem. 80 (1976) 969.

Prompt emission was observed immediately when the excited state was achieved by exciting the compound TADF-a with a pulse beam (i.e., a beam emitted from a pulse laser) having a wavelength to be absorbed by the compound TADF-a, and Delay emission was observed not immediately when the excited state was achieved but after the excited state was achieved. The delayed fluorescence in Examples means that an amount of Delay emission is 5% or more with respect to an amount of Prompt emission. Specifically, provided that the amount of Prompt emission is denoted by X_{P} and the amount of Delay emission is denoted by X_{D}, the delayed fluorescence means that a value of X_{D}/X_{P} is 0.05 or more.

The amounts of Prompt emission and Delay emission and the ratio therebetween can be determined by a method similar to the method described in “Nature 492, 234-238, 2012” (Reference Literature 1). The amount of Prompt emission and the amount of Delay emission may be calculated using an apparatus different from one described in Reference Literature 1 or one illustrated in FIG. 5

For the compound TADF-a, it was confirmed that the amount of Delay emission was 5% or more with respect to the amount of Prompt emission.

Specifically, a value of X_{D}/X_{P} of the compound TADF-a was 0.05 or more.

### Delayed Fluorescence of Compounds TADF-b and TADF-c

Delayed fluorescence of each of the compounds TADF-b and TADF-c was confirmed in the same manner as described above except for using the compounds TADF-b and TADF-c in place of the compound TADF-a.

A value of X_{D}/X_{P} of the compound TADF-b was 0.05 or more.

A value of X_{D}/X_{P} of the compound TADF-c was 0.05 or more.

### Lowest Singlet Energy S₁

The lowest singlet energy S₁ of each of the compounds TADF-a, TADF-b, TADF-c, BD-a, and BD-b was measured by the solution method described above.

### Energy Gap at 77K

An energy gap T_{77K} at 77K of each of the compounds BH-a, BH-b, BH-c, TADF-a, TADF-b, TADF-c, BD-a, and BD-b was measured by the measurement method of an energy gap T_{77K} described in the above “Relationship between Triplet energy and Energy gap at 77K.”

### ΔST

ΔST was calculated based on the measured lowest singlet energy S₁ and energy gap T_{77K} at 77K.

ΔST of the compound TADF-a was −0.13 eV.

ΔST of the compound TADF-b was −0.12 eV.

ΔST of the compound TADF-c was −0.07 eV.

### Maximum Peak Wavelength λ of Compounds

A maximum peak wavelength λ of each compound was measured as follows.

A toluene solution of each measurement target compound at a concentration of 5 μmol/L was prepared and put in a quartz cell. An emission spectrum (ordinate axis: luminous intensity, abscissa axis: wavelength) of the thus-obtained sample was measured at a normal temperature (300K). In Examples, the emission spectrum was measured using a spectrophotometer manufactured by Hitachi, Ltd. (device name: F-7000). It should be noted that the machine for measuring the emission spectrum is not limited to the machine used herein. A peak wavelength of the emission spectrum exhibiting the maximum luminous intensity was defined as the maximum peak wavelength λ.

The maximum peak wavelength λ of the compound BD-a was 453 nm.

The maximum peak wavelength λ of the compound BD-b was 455 nm.

### Energy Level HOMO of Highest Occupied Molecular Orbital

An energy level HOMO of the highest occupied molecular orbital was measured by the method described above.

|HOMO| of the compound BH-a was 5.92 eV.

|HOMO| of the compound BH-b was 6.03 eV.

|HOMO| of the compound BH-c was 5.93 eV.

|HOMO| of the compound TADF-a was 6.05 eV.

|HOMO| of the compound TADF-b was 6.30 eV.

|HOMO| of the compound TADF-c was 5.89 eV.

|HOMO| of the compound BD-a was 5.35 eV.

|HOMO| of the compound BD-b was 5.49 eV.

### Energy Level LUMO of Lowest Unoccupied Molecular Orbital

An energy level LUMO of the lowest unoccupied molecular orbital was measured by the method described above.

### EXPLANATION OF CODES

1, 1A, 10, 10A, 10B . . . organic EL device, 1B . . . organic EL apparatus, 2 . . . substrate, 3 . . . anode, 4 . . . cathode, 5, 5A . . . first emitting region, 5B, 5C, 5D . . . second emitting region, 6 . . . hole injecting layer, 7, 71 . . . hole transporting layer, 8, 81 . . . electron transporting layer, 9, 91 . . . electron injecting layer, 11, 11A . . . first emitting unit, 12, 12A, 12B . . . second emitting unit, 20 . . . charge generating layer, 21 . . . first N layer, 22 . . . first P layer, 30, 300 . . . light emitter, 31, 31A . . . first sensitizing moiety, 32, 32A . . . first emitting moiety, 40 . . . power source, 41 . . . power generating element, 42 . . . power storing element, 51 . . . first sensitizing layer, 52 . . . first emitting layer, 511 . . . second sensitizing layer, 521 . . . second emitting layer.

1: An organic electroluminescence device comprising:
an anode;
a cathode; and
an emitting region provided between the anode and the cathode, wherein
the emitting region comprises a first sensitizing layer and a first emitting layer,
the first sensitizing layer comprises a first host material and a first sensitizing material,
the first emitting layer comprises a second host material and a first luminescent compound,
the first host material and the second host material are mutually different,
the first sensitizing material and the first luminescent compound are mutually different, and
a difference ΔST(G1) between a lowest singlet energy S₁(G1) of the first sensitizing material and an energy gap T_{77K}(G1) at 77K of the first sensitizing material satisfies a relationship represented by (Numerical Formula 1) below:
$$Δ ST ( G 1 ) = {S}_{1} ( G 1 ) - {T}_{77 K} ( G 1 ) < 0.5 eV . \qquad ( Numerical Formula 1 )$$

2: The organic electroluminescence device according to claim 1, wherein the first sensitizing material contains no heavy metal element.

3: The organic electroluminescence device according to claim 1, wherein the energy gap T_{77K}(G1) at 77K of the first sensitizing material, an energy gap T_{77K}(H1) at 77K of the first host material, and an energy gap T_{77K}(H2) at 77K of the second host material satisfy a relationship represented by (Numerical Formula 2) below:
$${T}_{77 K} ( G 1 ) > {T}_{77 K} ( H 1 ) > {T}_{77 K} ( H 2 ) . \qquad ( Numerical Formula 2 )$$

4: The organic electroluminescence device according to claim 3, wherein the energy gap T_{77K}(G1) at 77K of the first sensitizing material and the energy gap T_{77K}(H1) at 77K of the first host material satisfy a relationship represented by (Numerical Formula 21) below:
$${T}_{77 K} ( G 1 ) - {T}_{77 K} ( H 1 ) < 0.5 eV . \qquad ( Numerical Formula 21 )$$

5: The organic electroluminescence device according to claim 3, wherein the energy gap T_{77K}(H1) at 77K of the first host material and the energy gap T_{77K}(H2) at 77K of the second host material satisfy a relationship represented by (Numerical Formula 22) below:
$${T}_{77 K} ( H 1 ) - {T}_{77 K} ( H 2 ) < 0.3 eV . \qquad ( Numerical Formula 22 )$$

6: The organic electroluminescence device according to claim 1, wherein the lowest singlet energy S₁(G1) of the first sensitizing material and a lowest singlet energy S₁(BD1) of the first luminescent compound satisfy a relationship represented by (Numerical Formula 3) below:
$${S}_{1} ( BD 1 ) > {S}_{1} ( G 1 ) . \qquad ( Numerical Formula 3 )$$

7: The organic electroluminescence device according to claim 1, wherein the first sensitizing layer is in direct contact with the first emitting layer.

8: The organic electroluminescence device according to claim 1, wherein
the first sensitizing layer is disposed between the anode and the cathode, and
the first emitting layer is disposed between the first sensitizing layer and the cathode.

9: The organic electroluminescence device according to claim 8, wherein an absolute value of an energy level LUMO(G1) of a lowest unoccupied molecular orbital of the first sensitizing material and an absolute value of an energy level LUMO(H1) of a lowest unoccupied molecular orbital of the first host material satisfy a relationship represented by (Numerical Formula 4) below:
$$\vert LUMO ( G 1 ) \vert > \vert LUMO ( H 1 ) \vert . \qquad ( Numerical Formula 4 )$$

10: The organic electroluminescence device according to claim 8, wherein an absolute value of an energy level LUMO(H2) of a lowest unoccupied molecular orbital of the second host material and an absolute value of an energy level LUMO(BD1) of a lowest unoccupied molecular orbital of the first luminescent compound satisfy a relationship represented by (Numerical Formula 41) below:
$$\vert LUMO ( H 2 ) \vert > \vert LUMO ( BD 1 ) \vert . \qquad ( Numerical Formula 41 )$$

11: The organic electroluminescence device according to claim 1, wherein
the first sensitizing layer is disposed between the anode and the cathode, and
the first emitting layer is disposed between the first sensitizing layer and the anode.

12: The organic electroluminescence device according to claim 11, wherein an absolute value of an energy level HOMO(G1) of a highest occupied molecular orbital of the first sensitizing material and an absolute value of an energy level HOMO(H1) of a highest occupied molecular orbital of the first host material satisfy a relationship represented by (Numerical Formula 5) below:
$$\vert HOMO ( G 1 ) \vert < \vert HOMO ( H 1 ) \vert . \qquad ( Numerical Formula 5 )$$

13: The organic electroluminescence device according to claim 11, wherein an absolute value of an energy level HOMO(H2) of a highest occupied molecular orbital of the second host material and an absolute value of an energy level HOMO(BD1) of a highest occupied molecular orbital of the first luminescent compound satisfy a relationship represented by (Numerical Formula 51) below:
$$\vert HOMO ( H 2 ) \vert < \vert HOMO ( BD 1 ) \vert . \qquad ( Numerical Formula 51 )$$

14: The organic electroluminescence device according to claim 1, wherein a difference between energy E_{PE} (eV) at peak of an emission spectrum and energy E_{TH} (eV) imparted to the device when a luminance of 0.01 cd/m² is obtained satisfies a relationship represented by (Numerical Formula 6) below:
$${E}_{TH} - {E}_{PE} \leq 0.05 eV . \qquad ( Numerical Formula 6 )$$

15: The organic electroluminescence device according to claim 1, wherein a delayed fluorescence ratio is larger than 37.5% when the emitting region emits light.

16: The organic electroluminescence device according to claim 1, further comprising:
a first emitting unit including the emitting region as a first emitting region;
a first charge generating layer disposed between the first emitting unit and the cathode; and
a second emitting unit that is disposed between the first charge generating layer and the cathode and includes a second emitting region, wherein
the first emitting region includes the first sensitizing layer and the first emitting layer,
the second emitting region at least includes a second emitting layer,
the anode, the first emitting region, the first charge generating layer, the second emitting region, and the cathode are disposed in this order, and
the second emitting layer contains a third host material and a second luminescent compound.

17: The organic electroluminescence device according to claim 1, further comprising:
a first emitting unit including the emitting region as a first emitting region;
a first charge generating layer disposed between the first emitting unit and the anode; and
a second emitting unit that is disposed between the first charge generating layer and the anode and includes a second emitting region, wherein
the first emitting region includes the first sensitizing layer and the first emitting layer,
the second emitting region at least includes a second emitting layer,
the anode, the second emitting region, the first charge generating layer, the first emitting region, and the cathode are disposed in this order, and
the second emitting layer contains a third host material and a second luminescent compound.

18: The organic electroluminescence device according to claim 16, wherein
the second emitting region includes a second sensitizing layer and the second emitting layer,
the first sensitizing layer and the first emitting layer in the first emitting region are disposed in this order from a side close to the anode,
the second sensitizing layer and the second emitting layer in the second emitting region are disposed in this order from a side close to the anode,
the second sensitizing layer contains a fourth host material and a second sensitizing material,
the third host material and the fourth host material are mutually different,
the second sensitizing material and the second luminescent compound are mutually different, and
a difference ΔST(G2) between a lowest singlet energy S₁(G2) of the second sensitizing material and an energy gap T_{77K}(G2) at 77K of the second sensitizing material satisfies a relationship represented by (Numerical Formula 1A) below:
$$Δ ST ( G 2 ) = {S}_{1} ( G 2 ) - {T}_{77 K} ( G 2 ) < 0.5 eV . \qquad ( Numerical Formula 1 A )$$

19: The organic electroluminescence device according to claim 16, wherein
the second emitting region includes a second sensitizing layer and the second emitting layer,
the first emitting layer and the first sensitizing layer in the first emitting region are disposed in this order from a side close to the anode,
the second emitting layer and the second sensitizing layer in the second emitting region are disposed in this order from a side close to the anode,
the second sensitizing layer contains a fourth host material and a second sensitizing material,
the third host material and the fourth host material are mutually different,
the second sensitizing material and the second luminescent compound are mutually different, and
a difference ΔST(G2) between a lowest singlet energy S₁(G2) of the second sensitizing material and an energy gap T_{77K}(G2) at 77 K of the second sensitizing material satisfies a relationship represented by (Numerical Formula 1A) below:
$$Δ ST ( G 2 ) = {S}_{1} ( G 2 ) - {T}_{77 K} ( G 2 ) < 0.5 eV . \qquad ( Numerical Formula 1 A )$$

20: The organic electroluminescence device according to claim 18, wherein when a second evaluation device emits light, the second evaluation device including an emitting region that has the same arrangement as the second emitting region and that is interposed between the anode and the cathode, a difference between energy E_{PE2} (eV) at peak of an emission spectrum and energy E_{TH2} (eV) imparted to the second evaluation device when luminance of 0.01 cd/m² is obtained satisfies a relationship a represented by (Numerical Formula 62) below:
$${E}_{TH 2} - {E}_{PE 2} \leq 0.05 eV . \qquad ( Numerical Formula 62 )$$

21: The organic electroluminescence device according to claim 18, wherein when a second evaluation device emits light, the second evaluation device including the emitting region that has the same arrangement as the second emitting region and that is interposed between the anode and the cathode, a delayed fluorescence ratio is larger than 37.5%.

22: The organic electroluminescence device according to claim 18, wherein when a first evaluation device emits light, the first evaluation device including an emitting region that has the same arrangement as the first emitting region and that is interposed between the anode and the cathode, a difference between energy E_{PE1} (eV) at peak of an emission spectrum and energy E_{TH1} (eV) imparted to the first evaluation device when luminance of 0.01 cd/m² is obtained satisfies a relationship represented by (Numerical Formula 61) below:
$${E}_{TH 1} - {E}_{PE 1} \leq 0.05 eV . \qquad ( Numerical Formula 61 )$$

23: The organic electroluminescence device according to claim 18, wherein w % ben a first evaluation device emits light, the first evaluation device including an emitting region that has the same arrangement as the first emitting region and that is interposed between the anode and the cathode, a delayed fluorescene ratio is larger than 37.5%.

24: The organic electroluminescence device according to claim 18, wherein the second sensitizing material is a delayed fluorescent material.

25: The organic electroluminescence device according to claim 1, wherein the first sensitizing material is a delayed fluorescent material.

26: An organic electroluminescence apparatus comprising:
the organic electroluminescence device according to claim 1; and
a power source, wherein
the power source includes a power generating element configured to generate a potential difference or an electric current by an external stimulus.

27: An electronic device comprising the organic electroluminescence device according to claim 1.

28: A light emitter comprising: a first sensitizing moiety and a first emitting moiety, wherein
the first sensitizing moiety comprises a first host material and a first sensitizing material,
the first emitting moiety comprises a second host material and a first luminescent compound,
the first host material and the second host material are mutually different,
the first sensitizing material and the first luminescent compound are mutually different,
a difference ΔST(G1) between a lowest singlet energy S₁(G1) of the first sensitizing material and an energy gap T_{77K}(G1) at 77K of the first sensitizing material satisfies a relationship represented by (Numerical Formula 1) below,
an energy gap T_{77K}(G1) at 77K of the first sensitizing material, an energy gap T_{77K}(H1) at 77K of the first host material, and an energy gap T_{77K}(H2) at 77K of the second host material satisfy a relationship represented by (Numerical Formula 2) below, and
a lowest singlet energy S₁(G1) of the first sensitizing material and a lowest singlet energy S₁(BD1) of the first luminescent compound satisfy a relationship represented by (Numerical Formula 3) below:
$$Δ ST ( G 1 ) = {S}_{1} ( G 1 ) - {T}_{77 K} ( G 1 ) < 0.5 eV \qquad ( Numerical Formula 1 )$$
$${T}_{77 K} ( G 1 ) > {T}_{77 K} ( H 1 ) > {T}_{77 K} ( H 2 ) \qquad ( Numerical Formula 2 )$$
$${S}_{1} ( BD 1 ) > {S}_{1} ( G 1 ) . \qquad ( Numerical Formula 3 )$$

29: The light emitter according to claim 28, wherein the first sensitizing moiety includes the first sensitizing layer and the first emitting moiety includes the first emitting layer.
